(19) United States
(12) Patent Application Publication
(10) Pub. No.: US 2025/0261507 A1
(43) Pub. Date: Aug. 14, 2025

(54) ORGANIC ELECTROLUMINESCENCE DEVICE, AND ELECTRONIC DEVICE

(71) Applicant: IDEMITSU KOSAN CO.,LTD., Tokyo (JP)

(72) Inventors: Satomi TASAKI, Tokyo (JP); Emiko KAMBE, Tokyo (JP); Masato NAKAMURA, Tokyo (JP); Sayaka MIZUTANI, Tokyo (JP); Yusuke TAKAHASHI, Tokyo (JP); Yongguk LEE, Tokyo (JP)

(73) Assignee: IDEMITSU KOSAN CO.,LTD., Tokyo (JP)

(21) Appl. No.: 19/001,790

(22) Filed: Dec. 26, 2024

(30) Foreign Application Priority Data
Dec. 27, 2023 (JP) 2023-221824

(51) Int. Cl. H10K 50/858; H10K 50/115; H10K 50/15; H10K 50/16; H10K 50/18; H10K 50/19; H10K 85/30; H10K 85/40; H10K 85/60; H10K 101/10; H10K 102/00

(52) U.S. Cl. CPC H10K 50/858; H10K 50/115; H10K 50/156; H10K 50/166; H10K 50/18; H10K 50/19; H10K 85/342; H10K 85/40; H10K 85/622; H10K 85/626; H10K 85/633; H10K 85/636; H10K 85/654; H10K 85/6572; H10K 85/6574; H10K 85/6576; H10K 85/658; H10K 2101/10; H10K 2102/351

(57) ABSTRACT

An organic electroluminescence device includes two or more emitting units, where a first emitting unit includes a first emitting zone and a second emitting unit includes a second emitting zone, a high refractive index zone (HN1) and a low refractive index zone (LN1) are disposed between the first and second emitting zones, a total film thickness of one or more high refractive index layers included in the high refractive index zone (HN1) is 20 nm or more, the high refractive index zone (HN1) includes a first high refractive index layer, the low refractive index zone (LN1) includes a first low refractive index layer, the first low refractive index layer contains a first organic material having a refractive index NM₁, the first high refractive index layer contains a second organic material having a refractive index NM₂, and a relationship of Numerical Formula N1 is satisfied, NM₂>NM₁ (Numerical Formula N1).

The entire disclosure of Japanese Patent Application No. 2023-221824, filed Dec. 27, 2023 is expressly incorporated by reference herein.

### TECHNICAL FIELD

The present invention relates to an organic electroluminescence device and an electronic device.

### BACKGROUND ART

An organic electroluminescence device (hereinafter, occasionally referred to as “organic EL device”) has found its application in a full-color display for mobile phones, televisions, and the like. When voltage is applied to an organic EL device, holes are injected from an anode and electrons are injected from a cathode into an emitting layer. The injected holes and electrons are recombined in the emitting layer to form excitons. Specifically, according to the electron spin statistics theory, singlet excitons and triplet excitons are generated at a ratio of 25%:75%.

For instance, studies for improving performance of an organic EL device have been made in Literature 1 (International Publication No. WO2022/154029). Literature 1 describes that light emission loss caused in an evanescent mode is reducible by using a layer formed from a low refractive index material as an organic layer (e.g., hole transporting layer) in a hole transporting zone. Literature 1 also describes that light emission loss in a thin film mode is reducible by arranging, as organic layers (e.g., hole transporting layer) in the hole transporting zone, an organic layer formed close to the anode using a high refractive index material and an organic layer formed close to an emitting layer using a low refractive index material.

A tandem organic EL device in which a plurality of emitting units are layered has been known as an exemplary arrangement of an organic EL device. For instance, Literature 1 also describes a tandem organic EL device. A further improvement in performance (e. g., improvement in external quantum efficiency) of the tandem organic EL device is desired.

### SUMMARY OF THE INVENTION

An object of the invention is to provide a tandem organic electroluminescence device capable of improving external quantum efficiency and an electronic device including the organic electroluminescence device.

An organic electroluminescence device according to an aspect of the invention includes an anode, a cathode, and two or more emitting units disposed between the anode and the cathode, in which the two or more emitting units at least includes a first emitting unit and a second emitting unit, the first emitting unit and the second emitting unit are disposed in this order toward the cathode from the anode, the first emitting unit includes a first emitting zone, the second emitting unit includes a second emitting zone, a high refractive index zone including one or more high refractive index layers and a low refractive index zone including one or more low refractive index layers are disposed between the first emitting zone and the second emitting zone, the high refractive index zone is in direct contact with the low refractive index zone, a total film thickness of the one or more high refractive index layers included in the high refractive index zone is 20 nm or more, the high refractive index zone includes a first high refractive index layer as the high refractive index layer in direct contact with the low refractive index zone, the low refractive index zone includes a first low refractive index layer as the low refractive index layer in direct contact with the first high refractive index layer, the first low refractive index layer contains a first organic material having a refractive index NM₁, the first high refractive index layer contains a second organic material having a refractive index NM₂, at least one of the one or more high refractive index layers contains a third organic material and at least one selected from the group consisting of metal and a metal compound, the third organic material and the second organic material are mutually the same or different, and the refractive index NM₁ of the first organic material and the refractive index NM₂ of the second organic material satisfy a relationship of a numerical formula (Numerical Formula N1) below.

NM₂>NM₁ (Numerical Formula N1)

According to another aspect of the invention, there is provided an electronic device including an organic electroluminescence display apparatus according to the above aspect of the invention.

According to the above aspect of the invention, there can be provided an organic electroluminescence device capable of improving external quantum efficiency. According to the another aspect of the invention, there can be provided an electronic device including the organic electroluminescence device.

### BRIEF DESCRIPTION OF DRAWINGS

FIG. 1 schematically illustrates an exemplary arrangement of an organic electroluminescence device according to a first exemplary embodiment of the invention.

FIG. 2 schematically illustrates another exemplary arrangement of the organic electroluminescence device according to the first exemplary embodiment of the invention.

### DETAILED DESCRIPTION

### Definitions

Herein, a hydrogen atom includes isotope having different numbers of neutrons, specifically, protium, deuterium and tritium.

In chemical formulae herein, it is assumed that a hydrogen atom (i.e. protium, deuterium and tritium) is bonded to each of bondable positions that are not annexed with signs “R” or the like or “D” representing a deuterium.

Herein, the ring carbon atoms refer to the number of carbon atoms among atoms forming a ring of a compound (e.g., a monocyclic compound, fused-ring compound, crosslinking compound, carbon ring compound, and heterocyclic compound) in which the atoms are bonded to each other to form the ring. When the ring is substituted by a substituent(s), carbon atom(s) included in the substituent(s) is not counted in the ring carbon atoms. Unless specifically described, the same applies to the “ring carbon atoms” described later. For instance, a benzene ring has 6 ring carbon atoms, a naphthalene ring has 10 ring carbon atoms, a pyridine ring has 5 ring carbon atoms, and a furan ring 4 ring carbon atoms. For instance, a 9,9-diphenylfluorenyl group has 13 ring carbon atoms and 9,9′-spirobifluorenyl group has 25 ring carbon atoms.

When a benzene ring is substituted by a substituent, e.g., an alkyl group, the number of carbon atoms of the alkyl group is not counted in the number of the ring carbon atoms of the benzene ring. Accordingly, the benzene ring substituted by an alkyl group has 6 ring carbon atoms. When a naphthalene ring is substituted by a substituent in a form of, for instance, an alkyl group, the number of carbon atoms of the alkyl group is not counted in the number of the ring carbon atoms of the naphthalene ring. Accordingly, the naphthalene ring substituted by an alkyl group has 10 ring carbon atoms.

Herein, the ring atoms refer to the number of atoms forming a ring of a compound (e.g., a monocyclic compound, fused-ring compound, cross-linking compound, carbon ring compound, and heterocyclic compound) in which the atoms are bonded to each other to form the ring (e.g., monocyclic ring, fused ring, and ring assembly). Atom(s) not forming the ring (e.g., hydrogen atom(s) for saturating the valence of the atom which forms the ring) and atom(s) in a substituent by which the ring is substituted are not counted as the ring atoms. Unless otherwise specified, the same applies to the “ring atoms” described later. For instance, a pyridine ring has 6 ring atoms, a quinazoline ring has 10 ring atoms, and a furan ring has 5 ring atoms. For instance, the number of hydrogen atom(s) bonded to a pyridine ring or the number of atoms forming a substituent is not counted as ring atoms of the pyridine ring. Accordingly, a pyridine ring bonded to a hydrogen atom(s) or a substituent(s) has 6 ring atoms. For instance, the hydrogen atom(s) bonded to carbon atom(s) of a quinazoline ring or the atoms forming a substituent are not counted as the quinazoline ring atoms. Accordingly, a quinazoline ring bonded to hydrogen atom(s) or a substituent(s) has 10 ring atoms.

Herein, “XX to YY carbon atoms” in the description of “substituted or unsubstituted ZZ group having XX to YY carbon atoms” represent carbon atoms of an unsubstituted ZZ group and do not include carbon atoms of a substituent(s) of the substituted ZZ group. Herein, “YY” is larger than “XX,” “XX” representing an integer of 1 or more and “YY” representing an integer of 2 or more.

Herein, “XX to YY atoms” in the description of “substituted or unsubstituted ZZ group having XX to YY atoms” represent atoms of an unsubstituted ZZ group and does not include atoms of a substituent(s) of the substituted ZZ group. Herein, “YY” is larger than “XX,” “XX” representing an integer of 1 or more and “YY” representing an integer of 2 or more.

Herein, an unsubstituted ZZ group refers to an “unsubstituted ZZ group” in a “substituted or unsubstituted ZZ group,” and a substituted ZZ group refers to a “substituted ZZ group” in a “substituted or unsubstituted ZZ group.”

Herein, the term “unsubstituted” used in a “substituted or unsubstituted ZZ group” means that a hydrogen atom(s) in the ZZ group is not substituted with a substituent(s). The hydrogen atom(s) in the “unsubstituted ZZ group” is protium, deuterium, or tritium.

Herein, the term “substituted” used in a “substituted or unsubstituted ZZ group” means that at least one hydrogen atom in the ZZ group is substituted with a substituent. Similarly, the term “substituted” used in a “BB group substituted by AA group” means that at least one hydrogen atom in the BB group is substituted with the AA group.

### Substituents Described Herein

Substituents described herein will be explained below.

An “unsubstituted aryl group” mentioned herein has, unless otherwise specified herein, 6 to 50, preferably 6 to 30, and more preferably 6 to 18 ring carbon atoms.

An “unsubstituted heterocyclic group” mentioned herein has, unless otherwise specified herein, 5 to 50, preferably 5 to 30, and more preferably 5 to 18 ring atoms.

An “unsubstituted alkyl group” mentioned herein has, unless otherwise specified herein, 1 to 50, preferably 1 to 20, and more preferably 1 to 6 carbon atoms.

An “unsubstituted alkenyl group” mentioned herein has, unless otherwise specified herein, 2 to 50, preferably 2 to 20, and more preferably 2 to 6 carbon atoms.

An “unsubstituted alkynyl group” mentioned herein has, unless otherwise specified herein, 2 to 50, preferably 2 to 20, and more preferably 2 to 6 carbon atoms.

An “unsubstituted cycloalkyl group” mentioned herein has, unless otherwise specified herein, 3 to 50, preferably 3 to 20, and more preferably 3 to 6 ring carbon atoms.

An “unsubstituted arylene group” mentioned herein has, unless otherwise specified herein, 6 to 50, preferably 6 to 30, and more preferably 6 to 18 ring carbon atoms.

An “unsubstituted divalent heterocyclic group” mentioned herein has, unless otherwise specified herein, 5 to 50, preferably 5 to 30, and more preferably 5 to 18 ring atoms.

An “unsubstituted alkylene group” mentioned herein has, unless otherwise specified herein, 1 to 50, preferably 1 to 20, and more preferably 1 to 6 carbon atoms.

### Substituted or Unsubstituted Aryl Group

Specific examples (specific example group G1) of the “substituted or unsubstituted aryl group” mentioned herein include unsubstituted aryl groups (specific example group G1A) below and substituted aryl groups (specific example group G1B). Herein, an unsubstituted aryl group refers to an “unsubstituted aryl group” in a “substituted or unsubstituted aryl group”, and a substituted aryl group refers to a “substituted aryl group” in a “substituted or unsubstituted aryl group.” A simply termed “aryl group” herein includes both of an “unsubstituted aryl group” and a “substituted aryl group”.

The “substituted aryl group” refers to a group derived by substituting at least one hydrogen atom in an “unsubstituted aryl group” with a substituent. Examples of the “substituted aryl group” include a group derived by substituting at least one hydrogen atom in the “unsubstituted aryl group” in the specific example group G1A below with a substituent, and examples of the substituted aryl group in the specific example group G1B below. It should be noted that the examples of the “unsubstituted aryl group” and the “substituted aryl group” mentioned herein are merely exemplary, and the “substituted aryl group” mentioned herein includes a group derived by further substituting a hydrogen atom bonded to a carbon atom of a skeleton of a “substituted aryl group” in the specific example group G1B below with a substituent, and a group derived by further substituting a hydrogen atom of a substituent of the “substituted aryl group” in the specific example group G1B below with a substituent.

### Unsubstituted Aryl Group (Specific Example Group G1A):

a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, benzanthryl group, phenanthryl group, benzophenanthryl group, phenalenyl group, pyrenyl group, chrysenyl group, benzochrysenyl group, triphenylenyl group, benzotriphenylenyl group, tetracenyl group, pentacenyl group, fluorenyl group, 9,9′-spirobifluorenyl group, benzofluorenyl group, dibenzofluorenyl group, fluoranthenyl group, benzofluoranthenyl group, perylenyl group, and monovalent aryl group derived by removing one hydrogen atom from cyclic structures represented by formulae (TEMP-1) to (TEMP-15) below.

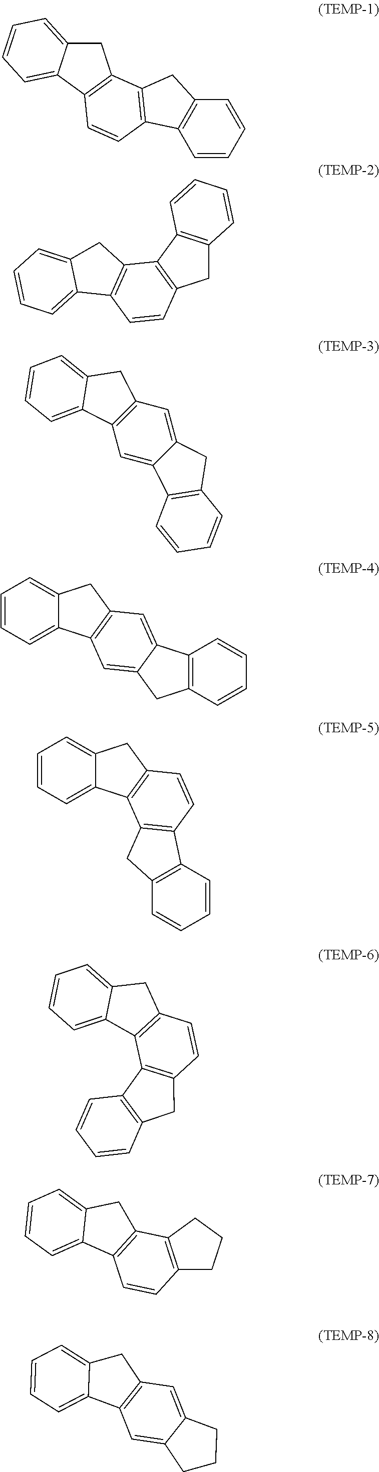

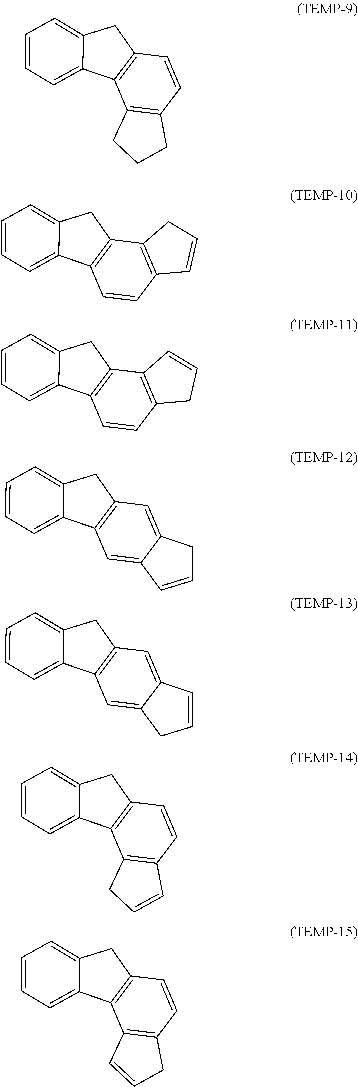

### Substituted Aryl Group (Specific Example Group G1B):

an o-tolyl group, m-tolyl group, p-tolyl group, para-xylyl group, meta-xylyl group, ortho-xylyl group, para-isopropylphenyl group, meta-isopropylphenyl group, ortho-isopropylphenyl group, para-t-butylphenyl group, meta-t-butylphenyl group, ortho-t-butylphenyl group, 3,4,5-trimethylphenyl group, 9,9-dimethylfluorenyl group, 9,9-diphenylfluorenyl group, 9,9-bis(4-methylphenyl) fluorenyl group, 9,9-bis(4-isopropylphenyl) fluorenyl group, 9,9-bis(4-t-butylphenyl) fluorenyl group, cyanophenyl group, triphenylsilylphenyl group, trimethylsilylphenyl group, phenylnaphthyl group, naphthylphenyl group, and group derived by substituting at least one hydrogen atom of a monovalent group derived from one of the cyclic structures represented by the formulae (TEMP-1) to (TEMP-15) with a substituent.

### Substituted or Unsubstituted Heterocyclic Group

The “heterocyclic group” mentioned herein refers to a cyclic group having at least one hetero atom in the ring atoms. Specific examples of the hetero atom include a nitrogen atom, oxygen atom, sulfur atom, silicon atom, phosphorus atom, and boron atom.

The “heterocyclic group” mentioned herein is a monocyclic group or a fused-ring group.

The “heterocyclic group” mentioned herein is an aromatic heterocyclic group or a non-aromatic heterocyclic group.

Specific examples (specific example group G2) of the “substituted or unsubstituted heterocyclic group” mentioned herein include unsubstituted heterocyclic groups (specific example group G2A) and substituted heterocyclic groups (specific example group G2B). (Herein, an unsubstituted heterocyclic group refers to an “unsubstituted heterocyclic group” in a “substituted or unsubstituted heterocyclic group,” and a substituted heterocyclic group refers to a “substituted heterocyclic group” in a “substituted or unsubstituted heterocyclic group.”) A simply termed “heterocyclic group” herein includes both of an “unsubstituted heterocyclic group” and a “substituted heterocyclic group.”

The “substituted heterocyclic group” refers to a group derived by substituting at least one hydrogen atom in an “unsubstituted heterocyclic group” with a substituent. Specific examples of the “substituted heterocyclic group” include examples of a group derived by substituting at least one hydrogen atom in the “unsubstituted heterocyclic group” in the specific example group G2A below with a substituent, and examples of the substituted heterocyclic group in the specific example group G2B below. It should be noted that the examples of the “unsubstituted heterocyclic group” and the “substituted heterocyclic group” mentioned herein are merely exemplary, and the “substituted heterocyclic group” mentioned herein includes a group derived by further substituting a hydrogen atom bonded to a ring atom of a skeleton of a “substituted heterocyclic group” in the specific example group G2B below with a substituent, and a group derived by further substituting a hydrogen atom of a substituent of the “substituted heterocyclic group” in the specific example group G2B below with a substituent.

The specific example group G2A includes, for instance, unsubstituted heterocyclic groups including a nitrogen atom (specific example group G2A1) below, unsubstituted heterocyclic groups including an oxygen atom (specific example group G2A2) below, unsubstituted heterocyclic groups including a sulfur atom (specific example group G2A3) below, and monovalent heterocyclic groups (specific example group G2A4) derived by removing a hydrogen atom from cyclic structures represented by formulae (TEMP-16) to (TEMP-33) below.

The specific example group G2B includes, for instance, substituted heterocyclic groups including a nitrogen atom (specific example group G2B1) below, substituted heterocyclic groups including an oxygen atom (specific example group G2B2) below, substituted heterocyclic groups including a sulfur atom (specific example group G2B3) below, and groups derived by substituting at least one hydrogen atom of the monovalent heterocyclic groups (specific example group G2B4), with a substituent, derived from the cyclic structures represented by formulae (TEMP-16) to (TEMP-33) below.

### Unsubstituted Heterocyclic Groups Including Nitrogen Atom (Specific Example Group G2A1):

a pyrrolyl group, imidazolyl group, pyrazolyl group, triazolyl group, tetrazolyl group, oxazolyl group, isoxazolyl group, oxadiazolyl group, thiazolyl group, isothiazolyl group, thiadiazolyl group, pyridyl group, pyridazinyl group, pyrimidinyl group, pyrazinyl group, triazinyl group, indolyl group, isoindolyl group, indolizinyl group, quinolizinyl group, quinolyl group, isoquinolyl group, cinnolyl group, phthalazinyl group, quinazolinyl group, quinoxalinyl group, benzimidazolyl group, indazolyl group, phenanthrolinyl group, phenanthridinyl group, acridinyl group, phenazinyl group, carbazolyl group, benzocarbazolyl group, morpholino group, phenoxazinyl group, phenothiazinyl group, azacarbazolyl group, and diazacarbazolyl group.

### Unsubstituted Heterocyclic Groups Including Oxygen Atom (Specific Example Group G2A2):

a furyl group, oxazolyl group, isoxazolyl group, oxadiazolyl group, xanthenyl group, benzofuranyl group, isobenzofuranyl group, dibenzofuranyl group, naphthobenzofuranyl group, benzoxazolyl group, benzisoxazolyl group, phenoxazinyl group, morpholino group, dinaphthofuranyl group, azadibenzofuranyl group, diazadibenzofuranyl group, azanaphthobenzofuranyl group, and diazanaphthobenzofuranyl group.

### Unsubstituted Heterocyclic Groups Including Sulfur Atom (Specific Example Group G2A3):

a thienyl group, thiazolyl group, isothiazolyl group, thiadiazolyl group, benzothiophenyl group (benzothienyl group), isobenzothiophenyl group (isobenzothienyl group), dibenzothiophenyl group (dibenzothienyl group), naphthobenzothiophenyl group (naphthobenzothienyl group), benzothiazolyl group, benzisothiazolyl group, phenothiazinyl group, dinaphthothiophenyl group (dinaphthothienyl group), azadibenzothiophenyl group (azadibenzothienyl group), diazadibenzothiophenyl group (diazadibenzothienyl group), azanaphthobenzothiophenyl group (azanaphthobenzothienyl group), and diazanaphthobenzothiophenyl group (diazanaphthobenzothienyl group).

Monovalent Heterocyclic Groups Derived by Removing One Hydrogen Atom from Cyclic Structures Represented by Formulae (TEMP-16) to (TEMP-33) (Specific Example Group G2A4):

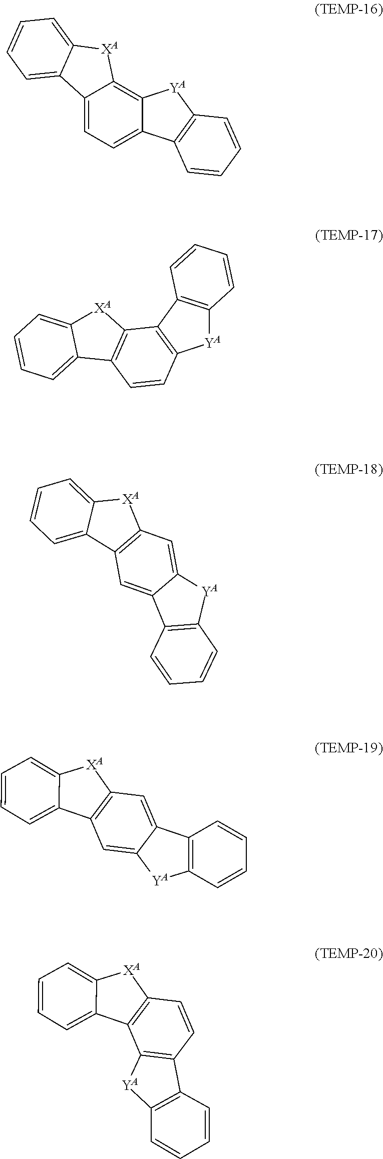

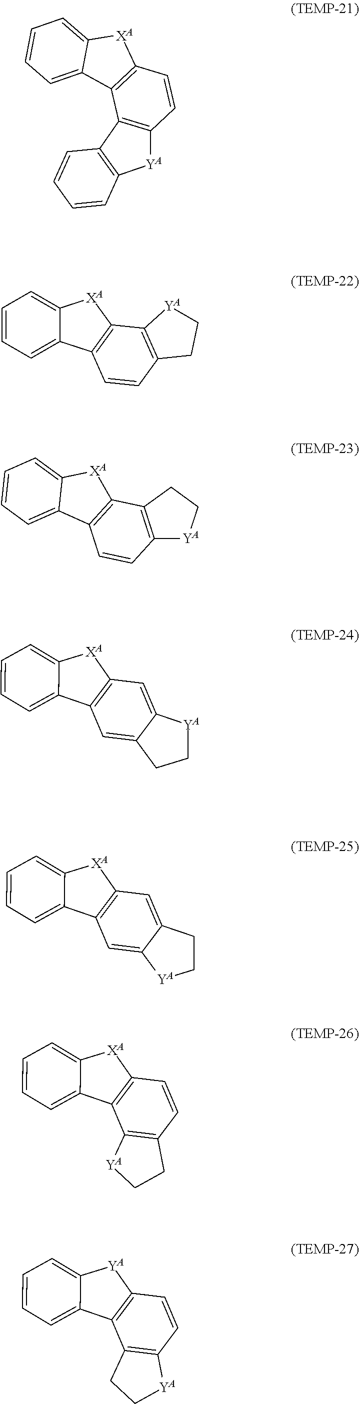

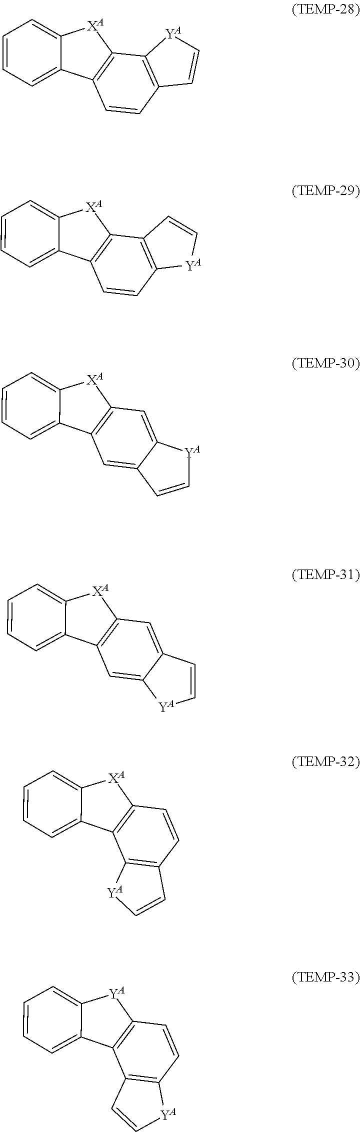

In the formulae (TEMP-16) to (TEMP-33), X_{A} and Y_{A} are each independently an oxygen atom, a sulfur atom, NH or CH₂, and <<nret>> at least one of X_{A} or Y_{A} is an oxygen atom, a sulfur atom, or NH.

When at least one of X_{A} or Y_{A} in the formulae (TEMP-16) to (TEMP-33) is NH or CH₂, the monovalent heterocyclic groups derived from the cyclic structures represented by the formulae (TEMP-16) to (TEMP-33) include a monovalent group derived by removing one hydrogen atom from NH or CH₂.

### Substituted Heterocyclic Groups Including Nitrogen Atom (Specific Example Group G2B1):

a (9-phenyl)carbazolyl group, (9-biphenylyl)carbazolyl group, (9-phenyl)phenylcarbazolyl group, (9-naphthyl)carbazolyl group, diphenylcarbazole-9-phenylcarbazole-9-yl group, group, methylbenzimidazolyl group, ethylbenzimidazolyl group, phenyltriazinyl group, biphenylyltriazinyl group, diphenyltriazinyl group, phenylquinazolinyl group, and biphenylquinazolinyl group.

### Substituted Heterocyclic Groups Including Oxygen Atom (Specific Example Group G2B2):

phenyldibenzofuranyl group, methyldibenzofuranyl group, t-butyldibenzofuranyl group, and monovalent residue of spiro[9H-xanthene-9,9′-[9H]fluorene].

### Substituted Heterocyclic Groups Including Sulfur Atom (Specific Example Group G2B3):

a phenyldibenzothiophenyl group, methyldibenzothiophenyl group, t-butyldibenzothiophenyl group, and monovalent residue of spiro[9H-thioxanthene-9,9′-[9H]fluorene].

Groups Obtained by Substituting at Least One Hydrogen Atom of Monovalent Heterocyclic Group Derived from Cyclic Structures Represented by Formulae (TEMP-16) to (TEMP-33) with Substituent (Specific Example Group G2B4):

The “at least one hydrogen atom of a monovalent heterocyclic group” means at least one hydrogen atom selected from a hydrogen atom bonded to a ring carbon atom of the monovalent heterocyclic group, a hydrogen atom bonded to a nitrogen atom of at least one of X_{A} or Y_{A} in a form of NH, and a hydrogen atom of one of X_{A} and Y_{A} in a form of a methylene group (CH₂).

### Substituted or Unsubstituted Alkyl Group

Specific examples (specific example group G3) of the “substituted or unsubstituted alkyl group” mentioned herein include unsubstituted alkyl groups (specific example group G3A) and substituted alkyl groups (specific example group G3B) below. Herein, an unsubstituted alkyl group refers to an “unsubstituted alkyl group” in a “substituted or unsubstituted alkyl group,” and a substituted alkyl group refers to a “substituted alkyl group” in a “substituted or unsubstituted alkyl group.” A simply termed “alkyl group” herein includes both of an “unsubstituted alkyl group” and a “substituted alkyl group”.

The “substituted alkyl group” refers to a group derived by substituting at least one hydrogen atom in an “unsubstituted alkyl group” with a substituent. Specific examples of the “substituted alkyl group” include a group derived by substituting at least one hydrogen atom of an “unsubstituted alkyl group” (specific example group G3A) below with a substituent, and examples of the substituted alkyl group (specific example group G3B) below. Herein, the alkyl group for the “unsubstituted alkyl group” refers to a chain alkyl group. Accordingly, the “unsubstituted alkyl group” include linear “unsubstituted alkyl group” and branched “unsubstituted alkyl group.” It should be noted that the examples of the “unsubstituted alkyl group” and the “substituted alkyl group” mentioned herein are merely exemplary, and the “substituted alkyl group” mentioned herein includes a group derived by further substituting a hydrogen atom of a skeleton of the “substituted alkyl group” in the specific example group G3B with a substituent, and a group derived by further substituting a hydrogen atom of a substituent of the “substituted alkyl group” in the specific example group G3B with a substituent.

### Unsubstituted Alkyl Group (Specific Example Group G3A):

a methyl group, ethyl group, n-propyl group, isopropyl group, n-butyl group, isobutyl group, s-butyl group, and t-butyl group.

### Substituted Alkyl Group (Specific Example Group G3B):

a heptafluoropropyl group (including isomer thereof), pentafluoroethyl group, 2,2,2-trifluoroethyl group, and trifluoromethyl group.

### Substituted or Unsubstituted Alkenyl Group

Specific examples (specific example group G4) of the “substituted or unsubstituted alkenyl group” mentioned herein include unsubstituted alkenyl groups (specific example group G4A) and substituted alkenyl groups (specific example group G4B). (Herein, an unsubstituted alkenyl group refers to an “unsubstituted alkenyl group” in a “substituted or unsubstituted alkenyl group,” and a substituted alkenyl group refers to a “substituted alkenyl group” in a “substituted or unsubstituted alkenyl group.”) A simply termed “alkenyl group” herein includes both of an “unsubstituted alkenyl group” and a “substituted alkenyl group”.

The “substituted alkenyl group” refers to a group derived by substituting at least one hydrogen atom in an “unsubstituted alkenyl group” with a substituent. Specific examples of the “substituted alkenyl group” include an “unsubstituted alkenyl group” (specific example group G4A) substituted by a substituent, and examples of the substituted alkenyl group (specific example group G4B) below. It should be noted that the examples of the “unsubstituted alkenyl group” and the “substituted alkenyl group” mentioned herein are merely exemplary, and the “substituted alkenyl group” mentioned herein includes a group derived by further substituting a hydrogen atom of a skeleton of the “substituted alkenyl group” in the specific example group G4B with a substituent, and a group derived by further substituting a hydrogen atom of a substituent of the “substituted alkenyl group” in the specific example group G4B with a substituent.

### Unsubstituted Alkenyl Group (Specific Example Group G4A):

a vinyl group, allyl group, 1-butenyl group, 2-butenyl group, and 3-butenyl group.

### Substituted Alkenyl Group (Specific Example Group G4B):

a 1,3-butanedienyl group, 1-methylvinyl group, 1-methylallyl group, 1,1-dimethylallyl group, 2-methylallyl group, and 1,2-dimethylallyl group.

### Substituted or Unsubstituted Alkynyl Group

Specific examples (specific example group G5) of the “substituted or unsubstituted alkynyl group” mentioned herein include unsubstituted alkynyl groups (specific example group G5A) below. Herein, an unsubstituted alkynyl group refers to an “unsubstituted alkynyl group” in a “substituted or unsubstituted alkynyl group.” A simply termed “alkynyl group” herein includes both of “unsubstituted alkynyl group” and “substituted alkynyl group”.

The “substituted alkynyl group” refers to a group derived by substituting at least one hydrogen atom in an “unsubstituted alkynyl group” with a substituent. Specific examples of the “substituted alkynyl group” include a group derived by substituting at least one hydrogen atom of the “unsubstituted alkynyl group” (specific example group G5A) below with a substituent.

### Unsubstituted Alkynyl Group (Specific Example Group G5A):

an ethynyl group.

### Substituted or Unsubstituted Cycloalkyl Group

Specific examples (specific example group G6) of the “substituted or unsubstituted cycloalkyl group” mentioned herein include unsubstituted cycloalkyl groups (specific example group G6A) and substituted cycloalkyl groups (specific example group G6B). Herein, an unsubstituted cycloalkyl group refers to an “unsubstituted cycloalkyl group” in a “substituted or unsubstituted cycloalkyl group,” and a substituted cycloalkyl group refers to a “substituted cycloalkyl group” in a “substituted or unsubstituted cycloalkyl group.” A simply termed “cycloalkyl group” herein includes both of “unsubstituted cycloalkyl group” and “substituted cycloalkyl group”.

The “substituted cycloalkyl group” refers to a group derived by substituting at least one hydrogen atom of an “unsubstituted cycloalkyl group” with a substituent. Specific examples of the “substituted cycloalkyl group” include a group derived by substituting at least one hydrogen atom of the “unsubstituted cycloalkyl group” (specific example group G6A) below with a substituent, and examples of the substituted cycloalkyl group (specific example group G6B) below. It should be noted that the examples of the “unsubstituted cycloalkyl group” and the “substituted cycloalkyl group” mentioned herein are merely exemplary, and the “substituted cycloalkyl group” mentioned herein includes a group derived by substituting at least one hydrogen atom bonded to a carbon atom of a skeleton of the “substituted cycloalkyl group” in the specific example group G6B with a substituent, and a group derived by further substituting a hydrogen atom of a substituent of the “substituted cycloalkyl group” in the specific example group G6B with a substituent.

### Unsubstituted Cycloalkyl Group (Specific Example Group G6A):

a cyclopropyl group, cyclobutyl group, cyclopentyl group, cyclohexyl group, 1-adamantyl group, 2-adamantyl group, 1-norbornyl group, and 2-norbornyl group.

### Substituted Cycloalkyl Group (Specific Example Group G6B):

a 4-methylcyclohexyl group.

Group Represented by —Si(R₉₀₁)(R₉₀₂)(R₉₀₃)

Specific examples (specific example group G7) of the group represented herein by —Si(R₉₀₁)(R₉₀₂)(R₉₀₃) include: —Si(G1)(G1)(G1); —Si(G1)(G2)(G2); —Si(G1)(G1)(G2); —Si(G2)(G2)(G2); —Si(G3)(G3)(G3); and —Si(G6)(G6)(G6);

where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —Si(G1)(G1)(G1) are mutually the same or different;
a plurality of G2 in —Si(G1)(G2)(G2) are mutually the same or different;
a plurality of G1 in —Si(G1)(G1)(G2) are mutually the same or different;
a plurality of G2 in —Si(G2)(G2)(G2) are mutually the same or different;
a plurality of G3 in —Si(G3)(G3)(G3) are mutually the same or different; and
a plurality of G6 in —Si(G6)(G6)(G6) are mutually the same or different.

### Group Represented by —O—(R₉₀₄)

Specific examples (specific example group G8) of a group represented by —O—(R₉₀₄) herein include:—O(G1); —O(G2); —O(G3); and —O(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.

### Group Represented by —S—(R₉₀₅)

Specific examples (specific example group G9) of a group represented herein by —S—(R₉₀₅) include: —S(G1); —S(G2); —S(G3); and —S(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3; and
G6 represents a “substituted or unsubstituted cycloalkyl group” in the specific example group G6.
   Group Represented by —N(R₉₀₆)(R₉₀₇)

Specific examples (specific example group G10) of a group represented herein by —N(R₉₀₆)(R₉₀₇) include: —N(G1)(G1); —N(G2)(G2); —N(G1)(G2); —N(G3)(G3); and —N(G6)(G6);
where:
G1 represents a “substituted or unsubstituted aryl group” in the specific example group G1;
G2 represents a “substituted or unsubstituted heterocyclic group” in the specific example group G2;
G3 represents a “substituted or unsubstituted alkyl group” in the specific example group G3;
G6 represents a “substituted or unsubstituted cycloalkyl group” in the specific example group G6;
a plurality of G1 in —N(G1)(G1) are mutually the same or different;
a plurality of G2 in —N(G2)(G2) are mutually the same or different;
a plurality of G3 in —N(G3)(G3) are mutually the same or different; and
a plurality of G6 in —N(G6)(G6) are mutually the same or different.

### Halogen Atom

Specific examples (specific example group G11) of “halogen atom” mentioned herein include a fluorine atom, chlorine atom, bromine atom, and iodine atom.

### Substituted or Unsubstituted Fluoroalkyl Group

The “substituted or unsubstituted fluoroalkyl group” mentioned herein refers to a group derived by substituting at least one hydrogen atom bonded to at least one of carbon atoms forming an alkyl group in the “substituted or unsubstituted alkyl group” with a fluorine atom, and also includes a group (perfluoro group) derived by substituting all of hydrogen atoms bonded to carbon atoms forming the alkyl group in the “substituted or unsubstituted alkyl group” with fluorine atoms. An “unsubstituted fluoroalkyl group” has, unless otherwise specified herein, 1 to 50, preferably 1 to 30, more preferably 1 to 18 carbon atoms. The “substituted fluoroalkyl group” refers to a group derived by substituting at least one hydrogen atom in a “fluoroalkyl group” with a substituent. It should be noted that the examples of the “substituted fluoroalkyl group” mentioned herein include a group derived by further substituting at least one hydrogen atom bonded to a carbon atom of an alkyl chain of a “substituted fluoroalkyl group” with a substituent, and a group derived by further substituting at least one hydrogen atom of a substituent of the “substituted fluoroalkyl group” with a substituent. Specific examples of the “unsubstituted fluoroalkyl group” include a group derived by substituting at least one hydrogen atom of the “alkyl group” (specific example group G3) with a fluorine atom.

### Substituted or Unsubstituted Haloalkyl Group

The “substituted or unsubstituted haloalkyl group” mentioned herein refers to a group derived by substituting at least one hydrogen atom bonded to carbon atoms forming the alkyl group in the “substituted or unsubstituted alkyl group” with a halogen atom, and also includes a group derived by substituting all hydrogen atoms bonded to carbon atoms forming the alkyl group in the “substituted or unsubstituted alkyl group” with halogen atoms. An “unsubstituted haloalkyl group” has, unless otherwise specified herein, 1 to 50, preferably 1 to 30, and more preferably 1 to 18 carbon atoms. The “substituted haloalkyl group” refers to a group derived by substituting at least one hydrogen atom in a “haloalkyl group” with a substituent. It should be noted that the examples of the “substituted haloalkyl group” mentioned herein include a group derived by further substituting at least one hydrogen atom bonded to a carbon atom of an alkyl chain of a “substituted haloalkyl group” with a substituent, and a group derived by further substituting at least one hydrogen atom of a substituent of the “substituted haloalkyl group” with a substituent. Specific examples of the “unsubstituted haloalkyl group” include a group derived by substituting at least one hydrogen atom of the “alkyl group” (specific example group G3) with a halogen atom. The haloalkyl group is occasionally referred to as a halogenated alkyl group.

### Substituted or Unsubstituted Alkoxy Group

Specific examples of a “substituted or unsubstituted alkoxy group” mentioned herein include a group represented by —O(G3), G3 being the “substituted or unsubstituted alkyl group” in the specific example group G3. An “unsubstituted alkoxy group” has, unless otherwise specified herein, 1 to 50, preferably 1 to 30, more preferably 1 to 18 carbon atoms.

### Substituted or Unsubstituted Alkylthio Group

Specific examples of a “substituted or unsubstituted alkylthio group” mentioned herein include a group represented by —S(G3), G3 being the “substituted or unsubstituted alkyl group” in the specific example group G3. An “unsubstituted alkylthio group” has, unless otherwise specified herein, 1 to 50, preferably 1 to 30, more preferably 1 to 18 carbon atoms.

### Substituted or Unsubstituted Aryloxy Group

Specific examples of a “substituted or unsubstituted aryloxy group” mentioned herein include a group represented by —O(G1), G1 being the “substituted or unsubstituted aryl group” in the specific example group G1. An “unsubstituted aryloxy group” has, unless otherwise specified herein, 6 to 50, preferably 6 to 30, more preferably 6 to 18 ring carbon atoms.

### Substituted or Unsubstituted Arylthio Group

Specific examples of a “substituted or unsubstituted arylthio group” mentioned herein include a group represented by —S(G1), G1 being the “substituted or unsubstituted aryl group” in the specific example group G1. An “unsubstituted arylthio group” has, unless otherwise specified herein, 6 to 50, preferably 6 to 30, more preferably 6 to 18 ring carbon atoms.

### Substituted or Unsubstituted Trialkylsilyl Group

Specific examples of a “trialkylsilyl group” mentioned herein include a group represented by —Si(G3)(G3)(G3), G3 being the “substituted or unsubstituted alkyl group” in the specific example group G3. A plurality of G3 in —Si(G3)(G3)(G3) are mutually the same or different. Each of the alkyl groups in the “trialkylsilyl group” has, unless otherwise specified herein, 1 to 50, preferably 1 to 20, more preferably 1 to 6 carbon atoms.

### Substituted or Unsubstituted Aralkyl Group

Specific examples of a “substituted or unsubstituted aralkyl group” mentioned herein include a group represented by -(G3)-(G1), G3 being the “substituted or unsubstituted alkyl group” in the specific example group G3, G1 being the “substituted or unsubstituted aryl group” in the specific example group G1. Accordingly, the “aralkyl group” is a group derived by substituting a hydrogen atom of the “alkyl group” with a substituent in a form of the “aryl group,” which is an example of the “substituted alkyl group.” An “unsubstituted aralkyl group,” which is an “unsubstituted alkyl group” substituted by an “unsubstituted aryl group,” has, unless otherwise specified herein, 7 to 50 carbon atoms, preferably 7 to 30 carbon atoms, more preferably 7 to 18 carbon atoms.

Specific examples of the “substituted or unsubstituted aralkyl group” include a benzyl group, 1-phenylethyl group, 2-phenylethyl group, 1-phenylisopropyl group, 2-phenylisopropyl group, phenyl-t-butyl group, α-naphthylmethyl group, 1-α-naphthylethyl group, 2-α-naphthylethyl group, 1-α-naphthylisopropyl group, 2-α-naphthylisopropyl group, β-naphthylmethyl group, 1-β-naphthylethyl group, 2-β-naphthylethyl group, 1-β-naphthylisopropyl group, and 2-β-naphthylisopropyl group.

Preferable examples of the substituted or unsubstituted aryl group mentioned herein include, unless otherwise specified herein, a phenyl group, p-biphenyl group, m-biphenyl group, o-biphenyl group, p-terphenyl-4-yl group, p-terphenyl-3-yl group, p-terphenyl-2-yl group, m-terphenyl-4-yl group, m-terphenyl-3-yl group, m-terphenyl-2-yl group, o-terphenyl-4-yl group, o-terphenyl-3-yl group, o-terphenyl-2-yl group, 1-naphthyl group, 2-naphthyl group, anthryl group, phenanthryl group, pyrenyl group, chrysenyl group, triphenylenyl group, fluorenyl group, 9,9′-spirobifluorenyl group, 9,9-dimethylfluorenyl group, and 9,9-diphenylfluorenyl group.

Preferable examples of the substituted or unsubstituted heterocyclic group mentioned herein include, unless otherwise specified herein, a pyridyl group, pyrimidinyl group, triazinyl group, quinolyl group, isoquinolyl group, quinazolinyl group, benzimidazolyl group, phenanthrolinyl group, carbazolyl group (1-carbazolyl group, 2-carbazolyl group, 3-carbazolyl group, 4-carbazolyl group, or 9-carbazolyl group), benzocarbazolyl group, azacarbazolyl group, diazacarbazolyl group, dibenzofuranyl group, naphthobenzofuranyl group, azadibenzofuranyl group, diazadibenzofuranyl group, dibenzothiophenyl group, naphthobenzothiophenyl group, azadibenzothiophenyl group, diazadibenzothiophenyl group, (9-phenyl)carbazolyl group ((9-phenyl)carbazole-1-yl group, (9-phenyl)carbazole-2-yl group, (9-phenyl)carbazole-3-yl group, or (9-phenyl)carbazole-4-yl group), (9-biphenylyl)carbazolyl group, (9-phenyl)phenylcarbazolyl group, diphenylcarbazole-9-yl group, phenylcarbazole-9-yl group, phenyltriazinyl group, biphenylyltriazinyl group, diphenyltriazinyl group, phenyldibenzofuranyl group, and phenyldibenzothiophenyl group.

The carbazolyl group mentioned herein is, unless otherwise specified herein, specifically a group represented by one of formulae below.

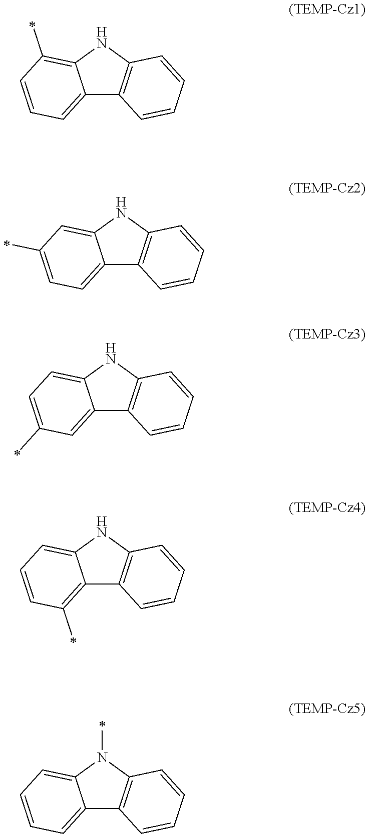

The (9-phenyl)carbazolyl group mentioned herein is, unless otherwise specified herein, specifically a group represented by one of formulae below.

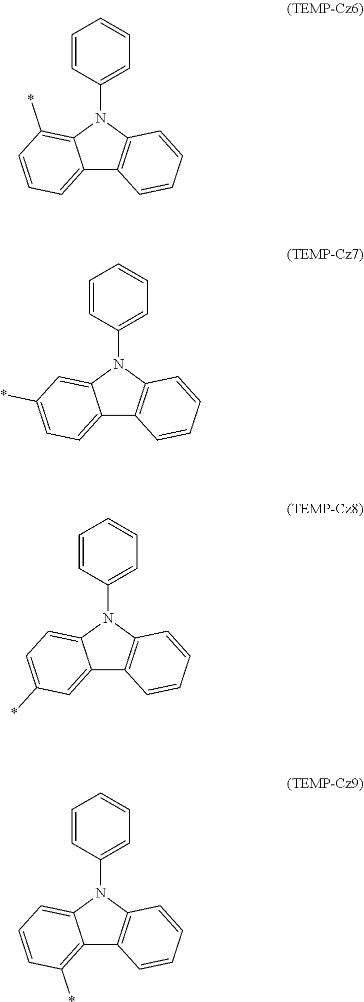 [SMILES: *c1cccc2c3ccccc3n(-c3ccccc3)c12 ; *c1ccc2c3ccccc3n(-c3ccccc3)c2c1 ; *c1ccc2c(c1)c1ccccc1n2-c1ccccc1 ; *c1cccc2c1c1ccccc1n2-c1ccccc1]

In the formulae (TEMP-Cz1) to (TEMP-Cz9), * represents a bonding position.

The dibenzofuranyl group and dibenzothiophenyl group mentioned herein are, unless otherwise specified herein, each specifically represented by one of formulae below.

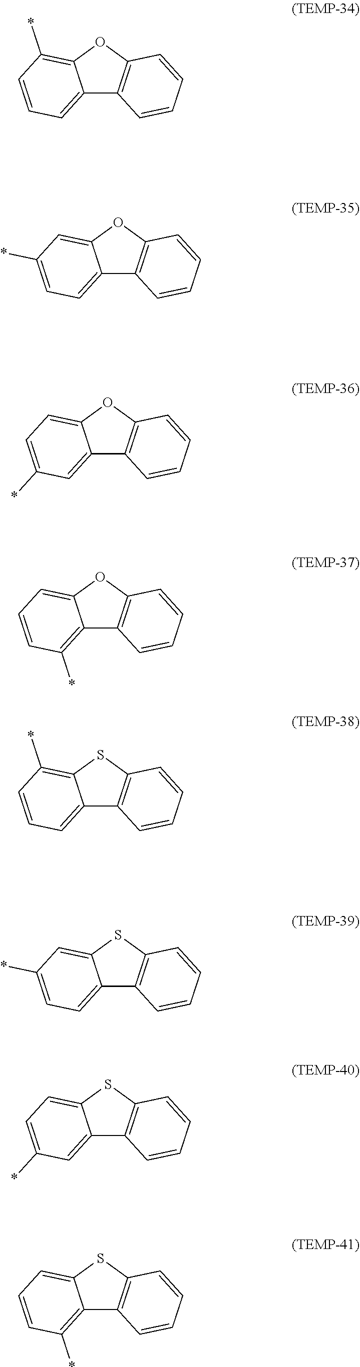

In the formulae (TEMP-34) to (TEMP-41), each * represents a bonding position.

Preferable examples of the substituted or unsubstituted alkyl group mentioned herein include, unless otherwise specified herein, a methyl group, ethyl group, propyl group, isopropyl group, n-butyl group, isobutyl group, and t-butyl group.

### Substituted or Unsubstituted Arylene Group

The “substituted or unsubstituted arylene group” mentioned herein is, unless otherwise specified herein, a divalent group derived by removing one hydrogen atom on an aryl ring of the “substituted or unsubstituted aryl group.” Specific examples of the “substituted or unsubstituted arylene group” (specific example group G12) include a divalent group derived by removing one hydrogen atom on an aryl ring of the “substituted or unsubstituted aryl group” in the specific example group G1.

### Substituted or Unsubstituted Divalent Heterocyclic Group

The substituted or unsubstituted divalent heterocyclic group mentioned herein is, unless otherwise specified herein, a divalent group derived by removing one hydrogen atom on a heterocycle of the “substituted or unsubstituted heterocyclic group.” Specific examples of the “substituted or unsubstituted divalent heterocyclic group” (specific example group G13) include a divalent group derived by removing one hydrogen atom on a heterocycle of the “substituted or unsubstituted heterocyclic group” in the specific example group G2.

### Substituted or Unsubstituted Alkylene Group

The “substituted or unsubstituted alkylene group” mentioned herein is, unless otherwise specified herein, a divalent group derived by removing one hydrogen atom on an alkyl chain of the “substituted or unsubstituted alkyl group.” Specific examples of the “substituted or unsubstituted alkylene group” (specific example group G14) include a divalent group derived by removing one hydrogen atom on an alkyl chain of the “substituted or unsubstituted alkyl group” in the specific example group G3.

The substituted or unsubstituted arylene group mentioned herein is, unless otherwise specified herein, preferably any one of groups represented by formulae (TEMP-42) to (TEMP-68) below.

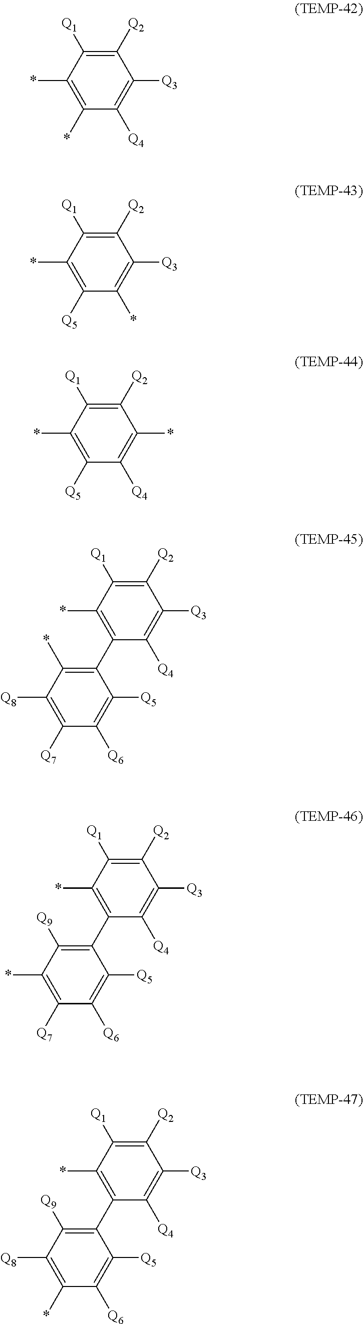

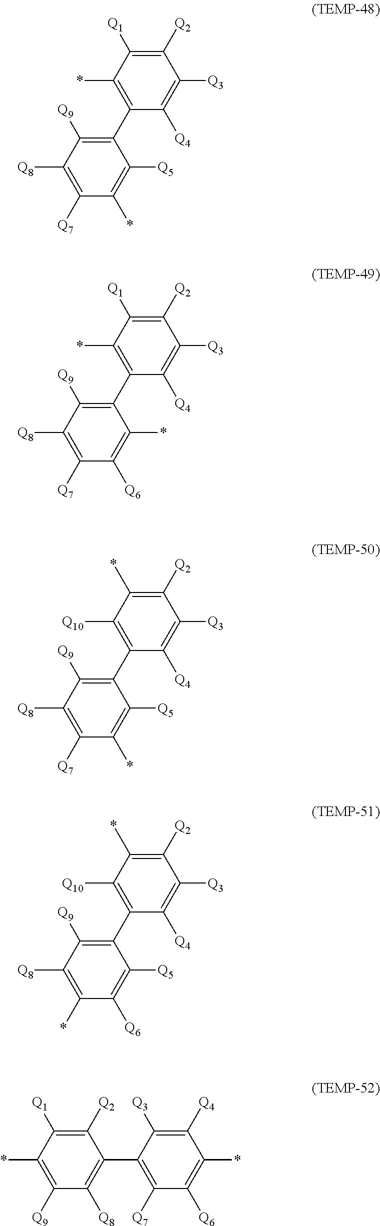

In the formulae (TEMP-42) to (TEMP-52), Q₁ to Q₁₀ are each independently a hydrogen atom or a substituent.

In the formulae (TEMP-42) to (TEMP-52), each * represents a bonding position.

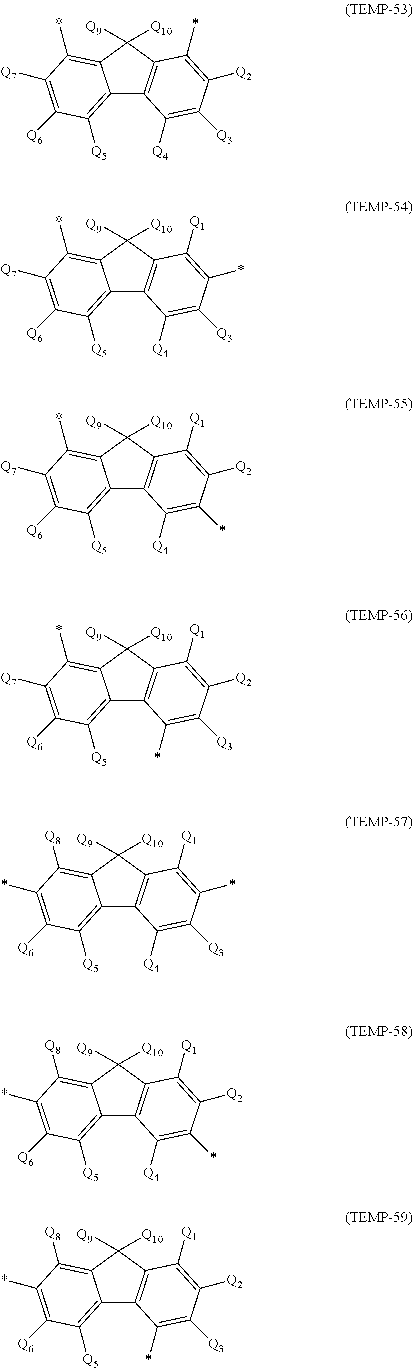

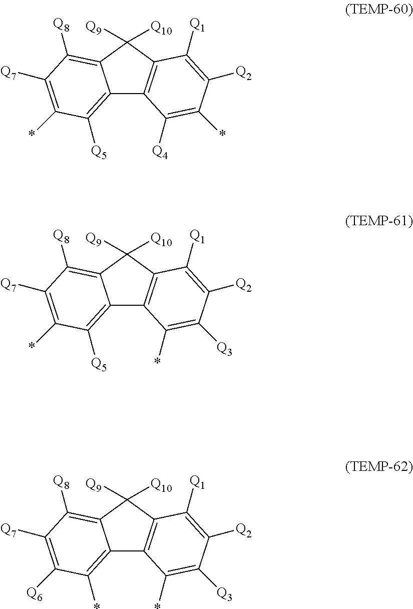

In the formulae (TEMP-53) to (TEMP-62), Q₁ to Q₁₀ are each independently a hydrogen atom or a substituent.

In the formulae, Q₉ and Q₁₀ may be mutually bonded through a single bond to form a ring.

In the formulae (TEMP-53) to (TEMP-62), each * represents a bonding position.

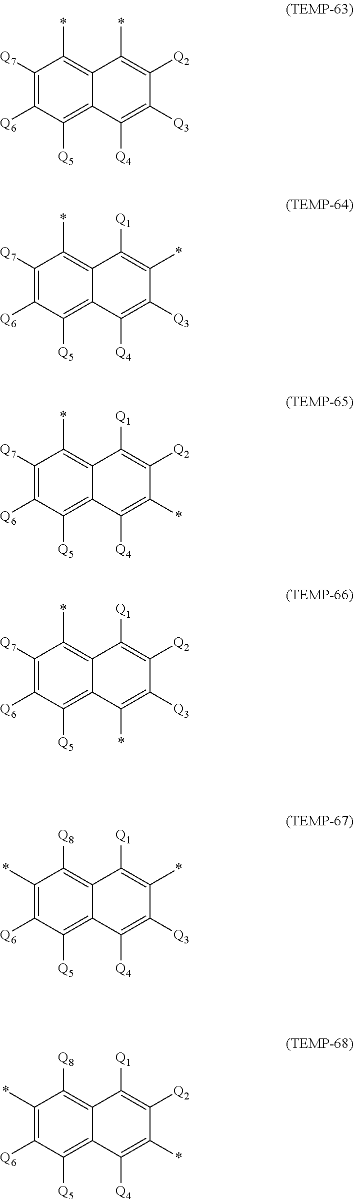

In the formulae (TEMP-63) to (TEMP-68), Q₁ to Q₈ are each independently a hydrogen atom or a substituent.

In the formulae (TEMP-63) to (TEMP-68), each * represents a bonding position.

The substituted or unsubstituted divalent heterocyclic group mentioned herein is, unless otherwise specified herein, preferably a group represented by any one of formulae (TEMP-69) to (TEMP-102) below.

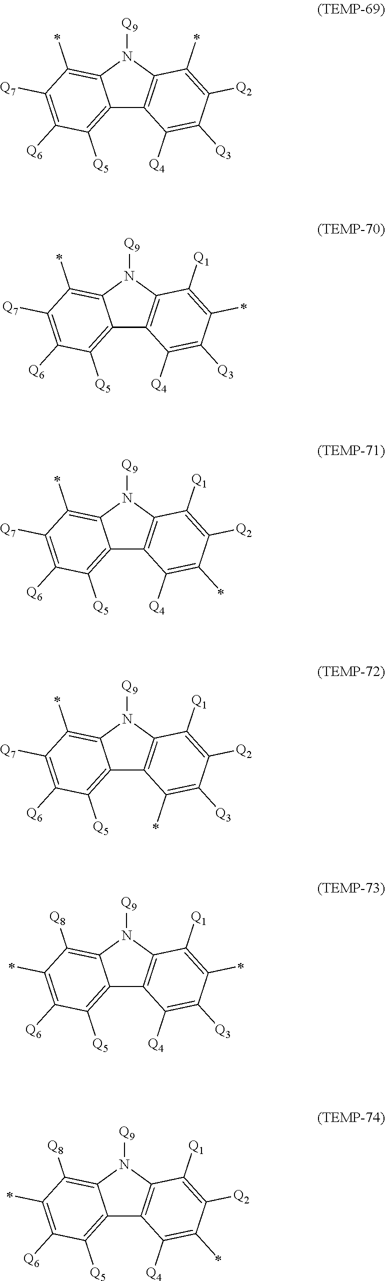

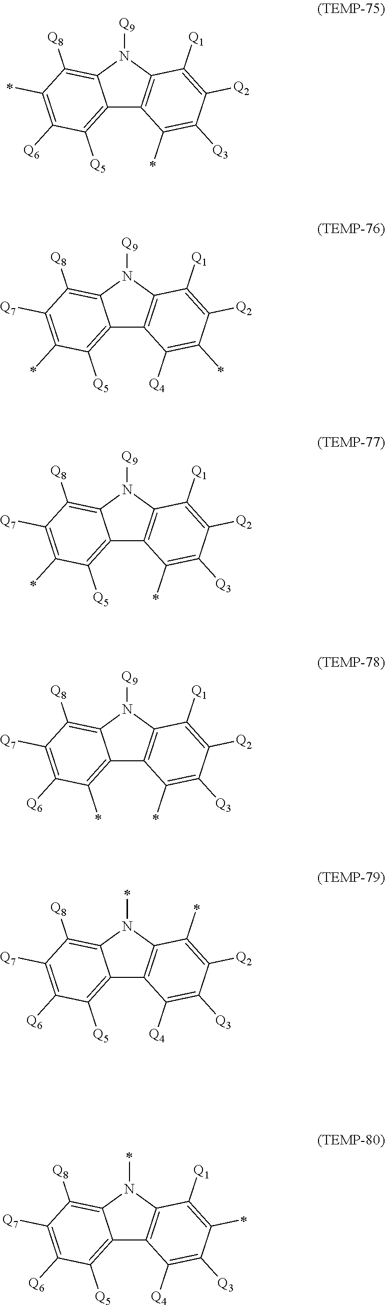

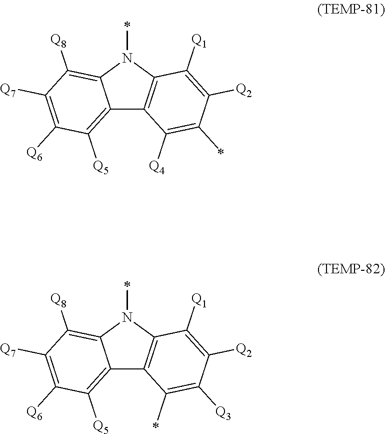

In the formulae (TEMP-69) to (TEMP-82), Q₁ to Q₉ are each independently a hydrogen atom or a substituent.

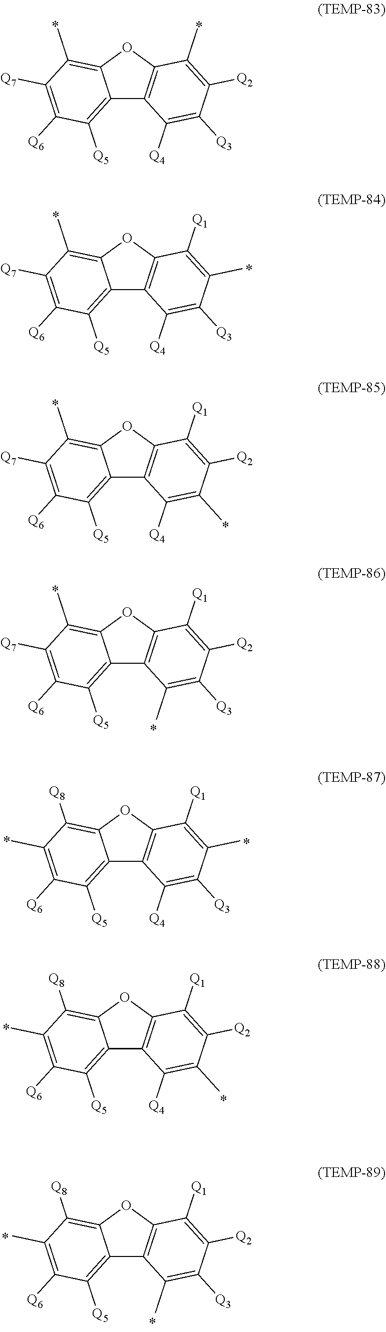

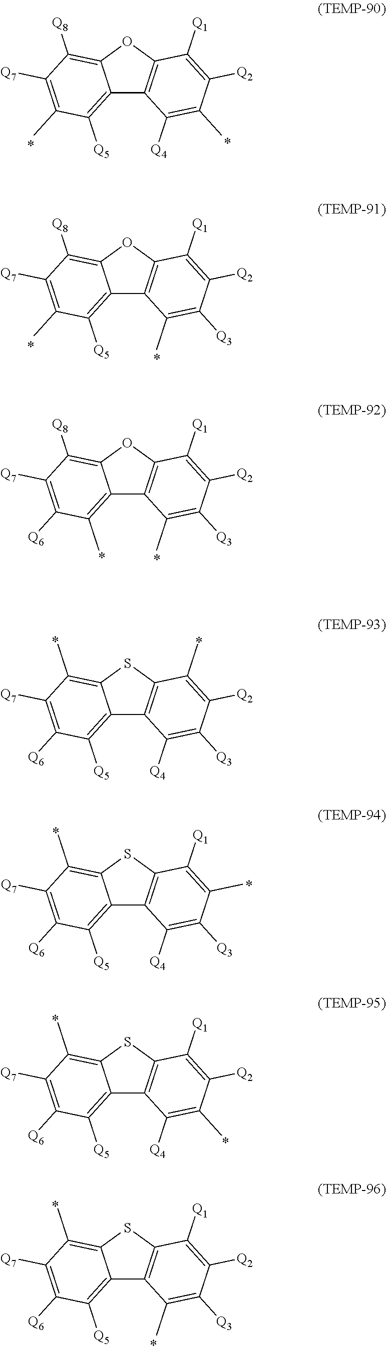

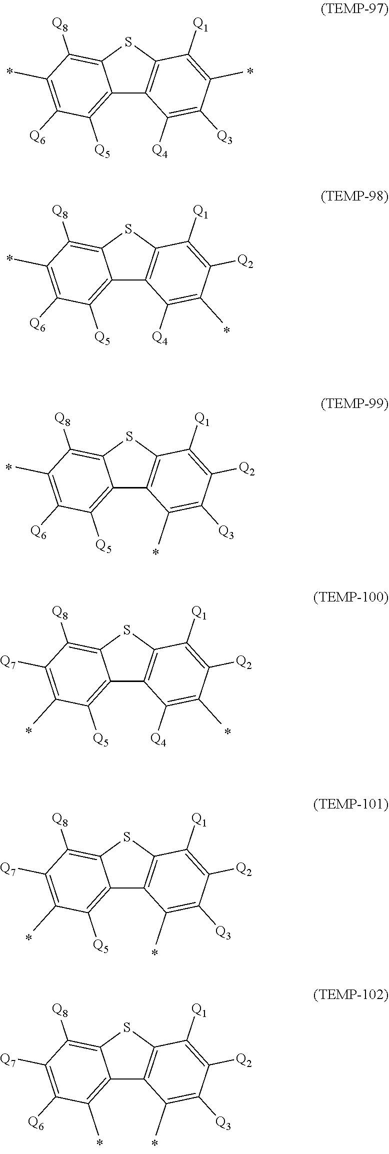

In the formulae (TEMP-83) to (TEMP-102), Q₁ to Q₈ are each independently a hydrogen atom or a substituent.

The substituents mentioned herein have been described above.

### Instance of “Bonded to Form Ring”

Instances where “at least one combination of adjacent two or more (of . . . ) are mutually bonded to form a substituted or unsubstituted monocyclic ring, mutually bonded to form a substituted or unsubstituted fused ring, or not mutually bonded” mentioned herein refer to instances where “at least one combination of adjacent two or more (of . . . ) are mutually bonded to form a substituted or unsubstituted monocyclic ring, “at least one combination of adjacent two or more (of . . . ) are mutually bonded to form a substituted or unsubstituted fused ring,” and “at least one combination of adjacent two or more (of . . . ) are not mutually bonded.”

Instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (these instances will be sometimes collectively referred to as an instance of “bonded to form a ring” hereinafter) will be described below. An anthracene compound having a basic skeleton in a form of an anthracene ring and represented by a formula (TEMP-103) below will be used as an example for the description.

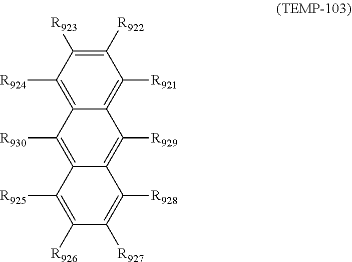

For instance, when “at least one combination of adjacent two or more of R₉₂₁ to R₉₃₀ are mutually bonded to form a ring,” the combination of adjacent ones of R₉₂₁ to R₉₃₀ (i.e. the combination at issue) is a combination of R₉₂₁ and R₉₂₂, a combination of R₉₂₂ and R₉₂₃, a combination of R₉₂₃ and R₉₂₄, a combination of R₉₂₄ and R₉₃₀, a combination of R₉₃₀ and R₉₂₅, a combination of R₉₂₅ and R₉₂₆, a combination of R₉₂₆ and R₉₂₇, a combination of R₉₂₇ and R₉₂₈, a combination of R₉₂₈ and R₉₂₉, or a combination of R₉₂₉ and R₉₂₁.

The term “at least one combination” means that two or more of the above combinations of adjacent two or more of R₉₂₁ to R₉₃₀ may simultaneously form rings. For instance, when R₉₂₁ and R₉₂₂ are mutually bonded to form a ring Q_{A} and R₉₂₅ and R₉₂₆ are simultaneously mutually bonded to form a ring Q_{B}, the anthracene compound represented by the formula (TEMP-103) is represented by a formula (TEMP-104) below.

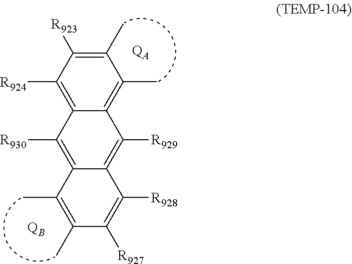

The instance where the “combination of adjacent two or more” form a ring means not only an instance where the “two” adjacent components are bonded but also an instance where adjacent “three or more” are bonded. For instance, R₉₂₁ and R₉₂₂ are mutually bonded to form a ring Q_{A} and R₉₂₂ and R₉₂₃ are mutually bonded to form a ring Q_{C}, and mutually adjacent three components (R₉₂₁, R₉₂₂ and R₉₂₃) are mutually bonded to form a ring fused to the anthracene basic skeleton. In this case, the anthracene compound represented by the formula (TEMP-103) is represented by a formula (TEMP-105) below. In the formula (TEMP-105) below, the ring Q_{A} and the ring Q_{C} share R₉₂₂.

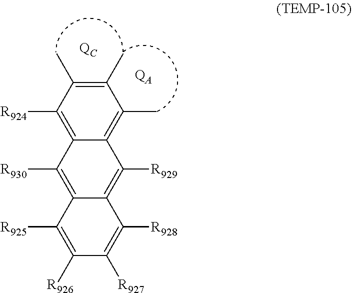

The formed “monocyclic ring” or “fused ring” may be, in terms of the formed ring in itself, a saturated ring or an unsaturated ring. When the “combination of adjacent two” form a “monocyclic ring” or a “fused ring,” the “monocyclic ring” or “fused ring” may be a saturated ring or an unsaturated ring. For instance, the ring Q_{A} and the ring Q_{B} formed in the formula (TEMP-104) are each independently a “monocyclic ring” or a “fused ring.” Further, the ring Q_{A} and the ring Q_{C} formed in the formula (TEMP-105) are each a “fused ring.” The ring Q_{A} and the ring Q_{C} in the formula (TEMP-105) are fused to form a fused ring. When the ring Q_{A} in the formula (TEMP-104) is a benzene ring, the ring Q_{A} is a monocyclic ring. When the ring Q_{A} in the formula (TEMP-104) is a naphthalene ring, the ring Q_{A} is a fused ring.

The “unsaturated ring” represents an aromatic hydrocarbon ring or an aromatic heterocycle. The “saturated ring” represents an aliphatic hydrocarbon ring or a non-aromatic heterocycle.

Specific examples of the aromatic hydrocarbon ring include a ring formed by terminating a bond of a group in the specific examples of the specific example group G1 with a hydrogen atom.

Specific examples of the aromatic heterocycle include a ring formed by terminating a bond of an aromatic heterocyclic group in the specific examples of the specific example group G2 with a hydrogen atom.

Specific examples of the aliphatic hydrocarbon ring include a ring formed by terminating a bond of a group in the specific examples of the specific example group G6 with a hydrogen atom.

The phrase “to form a ring” herein means that a ring is formed only by a plurality of atoms of a basic skeleton, or by a combination of a plurality of atoms of the basic skeleton and one or more optional atoms. For instance, the ring Q_{A} formed by mutually bonding R₉₂₁ and R₉₂₂ shown in the formula (TEMP-104) is a ring formed by a carbon atom of the anthracene skeleton bonded to R₉₂₁, a carbon atom of the anthracene skeleton bonded to R₉₂₂, and one or more optional atoms. Specifically, when the ring Q_{A} is a monocyclic unsaturated ring formed by R₉₂₁ and R₉₂₂, the ring formed by a carbon atom of the anthracene skeleton bonded to R₉₂₁, a carbon atom of the anthracene skeleton bonded to R₉₂₂, and four carbon atoms is a benzene ring.

The “optional atom” is, unless otherwise specified herein, preferably at least one atom selected from the group consisting of a carbon atom, nitrogen atom, oxygen atom, and sulfur atom. A bond of the optional atom (e.g. a carbon atom and a nitrogen atom) not forming a ring may be terminated by a hydrogen atom or the like or may be substituted by an “optional substituent” described later. When the ring includes any other optional element than the carbon atom, the resultant ring is a heterocycle.

The number of “one or more optional atoms” forming the monocyclic ring or fused ring is, unless otherwise specified herein, preferably in a range from 2 to 15, more preferably in a range from 3 to 12, further preferably in a range from 3 to 5.

Unless otherwise specified herein, the ring, which may be a “monocyclic ring” or “fused ring,” is preferably a “monocyclic ring.”

Unless otherwise specified herein, the ring, which may be a “saturated ring” or “unsaturated ring,” is preferably an “unsaturated ring.”

Unless otherwise specified herein, the “monocyclic ring” is preferably a benzene ring.

Unless otherwise specified herein, the “unsaturated ring” is preferably a benzene ring.

When “at least one combination of adjacent two or more” (of . . . ) are “mutually bonded to form a substituted or unsubstituted monocyclic ring” or “mutually bonded to form a substituted or unsubstituted fused ring,” unless otherwise specified herein, at least one combination of adjacent two or more of components are preferably mutually bonded to form a substituted or unsubstituted “unsaturated ring” formed of a plurality of atoms of the basic skeleton, and 1 to 15 atoms of at least one element selected from the group consisting of carbon, nitrogen, oxygen and sulfur.

When the “monocyclic ring” or the “fused ring” has a substituent, the substituent is the substituent described in later-described “optional substituent.” When the “monocyclic ring” or the “fused ring” has a substituent, specific examples of the substituent are the substituents described in the above under the subtitle “Substituents Mentioned Herein.”

When the “saturated ring” or the “unsaturated ring” has a substituent, the substituent is the substituent described in later-described “optional substituent.” When the “monocyclic ring” or the “fused ring” has a substituent, specific examples of the substituent are the substituents described in the above under the subtitle “Substituents Mentioned Herein.”

The above is the description for the instances where “at least one combination of adjacent two or more (of . . . ) are mutually bonded to form a substituted or unsubstituted monocyclic ring” and “at least one combination of adjacent two or more (of . . . ) are mutually bonded to form a substituted or unsubstituted fused ring” mentioned herein (sometimes referred to as an instance of “bonded to form a ring”).

### Substituent for Substituted or Unsubstituted Group

In an exemplary embodiment herein, the substituent for the substituted or unsubstituted group (sometimes referred to as an “optional substituent” hereinafter), is for instance, a group selected from the group consisting of an unsubstituted alkyl group having 1 to 50 carbon atoms, an unsubstituted alkenyl group having 2 to 50 carbon atoms, an unsubstituted alkynyl group having 2 to 50 carbon atoms, an unsubstituted cycloalkyl group having 3 to 50 ring carbon atoms, —Si(R₉₀₁)(R₉₀₂)(R₉₀₃), —O—(R₉₀₄), —S—(R₉₀₅), —N(R₉₀₆)(R₉₀₇), a halogen atom, a cyano group, a nitro group, an unsubstituted aryl group having 6 to 50 ring carbon atoms, and an unsubstituted heterocyclic group having 5 to 50 ring atoms;

R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when two or more R₉₀₁ are present, the two or more R₉₀₁ are mutually the same or different;
when two or more R₉₀₂ are present, the two or more R₉₀₂ are mutually the same or different;
when two or more R₉₀₃ are present, the two or more R₉₀₃ are mutually the same or different;
when two or more R₉₀₄ are present, the two or more R₉₀₄ are mutually the same or different;
when two or more R₉₀₅ are present, the two or more R₉₀₅ are mutually the same or different;
when two or more R₉₀₆ are present, the two or more R₉₀₆ are mutually the same or different; and
when two or more R₉₀₇ are present, the two or more R₉₀₇ are mutually the same or different.

In an exemplary embodiment, the substituent for the substituted or unsubstituted group is a group selected from the group consisting of an alkyl group having 1 to 50 carbon atoms, an aryl group having 6 to 50 ring carbon atoms, and a heterocyclic group having 5 to 50 ring atoms.

In an exemplary embodiment, the substituent for the substituted or unsubstituted group is a group selected from the group consisting of an alkyl group having 1 to 18 carbon atoms, an aryl group having 6 to 18 ring carbon atoms, and a heterocyclic group having 5 to 18 ring atoms.

Specific examples of the above optional substituents are the same as the specific examples of the substituents described in the above under the subtitle “Substituents Mentioned Herein.”

Unless otherwise specified herein, adjacent ones of the optional substituents may form a “saturated ring” or an “unsaturated ring,” preferably a substituted or unsubstituted saturated five-membered ring, a substituted or unsubstituted saturated six-membered ring, a substituted or unsubstituted unsaturated five-membered ring, or a substituted or unsubstituted unsaturated six-membered ring, more preferably a benzene ring.

Unless otherwise specified herein, the optional substituent may further include a substituent. Examples of the substituent for the optional substituent are the same as the examples of the optional substituent.

Herein, numerical ranges represented by “AA to BB” represent a range whose lower limit is the value (AA) recited before “to” and whose upper limit is the value (BB) recited after “to.”

### First Exemplary Embodiment

### Organic Electroluminescence Device

The organic electroluminescence device according to a first exemplary embodiment includes an anode, a cathode, and two or more emitting units disposed between the anode and the cathode, in which the two or more emitting units at least includes a first emitting unit and a second emitting unit,
the first emitting unit and the second emitting unit are arranged in this order toward the cathode from the anode,
the first emitting unit includes a first emitting zone,
the second emitting unit includes a second emitting zone,
a high refractive index zone including one or more high refractive index layers and a low refractive index zone including one or more low refractive index layers are disposed between the first emitting zone and the second emitting zone,
the high refractive index zone is in direct contact with the low refractive index zone,
a total film thickness of the one or more high refractive index layers included in the high refractive index zone is 20 nm or more,
the high refractive index zone includes a first high refractive index layer as the high refractive index layer in direct contact with the low refractive index zone,
the low refractive index zone include a first low refractive index layer as the low refractive index layer in direct contact with the first high refractive index layer,
the first low refractive index layer contains a first organic material having a refractive index NM₁,
the first high refractive index layer contains a second organic material having a refractive index NM₂,
at least one of the one or more high refractive index layers contains a third organic material and at least one selected from the group consisting of metal and a metal compound,
the third organic material and the second organic material are mutually the same or different, and
the refractive index NM₁ of the first organic material and the refractive index NM₂ of the second organic material satisfy a relationship of a numerical formula below (Numerical Formula N1).

$${NM}_{2} > {NM}_{1} \qquad ( Numerical Formula N1 )$$

The emitting units disposed between the anode and cathode may be counted as an Xth-tier emitting unit, (X+1)-tier emitting unit, and (X+2)-tier emitting unit, in an order from the anode (where X is an integer of 1 or more).

According to a tandem organic EL device in which a high refractive index zone including one or more high refractive index layers and a low refractive index zone including one or more low refractive index layers are disposed between two emitting zones, and the high refractive index layers in the high refractive index zone have a total film thickness of 20 nm or more, light extraction efficiency is improved at least from the emitting layer in the emitting unit that is located closer to the cathode than the high refractive index zone. By disposing the above-described high refractive index zone and low refractive index zone between the emitting zone in the X-th emitting unit and the emitting zone in the (X+1)-th emitting unit, light extraction efficiency is improved at least from the emitting layer in the (X+1)-th emitting unit.

Specifically, the organic EL device according to the first exemplary embodiment improves light extraction efficiency from the emitting layer in the second emitting zone of the second emitting unit by satisfying the following conditions (i), (ii), and (iii).

The organic EL device according to the first exemplary embodiment can improve external quantum efficiency by improving the light extraction efficiency.

Condition (i): the high refractive index zone including one or more high refractive index layers and the low refractive index zone including one or more low refractive index layers are disposed between the first emitting zone of the first emitting unit and the second emitting zone of the second emitting unit.

Condition (ii): the first high refractive index layer is in direct contact with the low refractive index zone, the first low refractive index layer is in direct contact with the high refractive index zone, and the refractive index NM₂ of the second organic material contained in the first high refractive index layer and the refractive index NM₁ of the first organic material contained in the first low refractive index layer satisfy the relationship of the numerical formula (Numerical Formula N1).

Condition (iii): a total film thickness of the one or more high refractive index layers included in the high refractive index zone is 20 nm or more.

The refractive index can be measured by a measurement method described in Examples below. Herein, a value of the refractive index at 2.7 eV in the substrate parallel direction (Ordinary direction) measured by multi-incidence angle spectroscopic ellipsometry measurement is defined as a refractive index of the measurement target material. The refractive index at 2.7 eV corresponds to a refractive index at 460 nm.

### Emitting Unit

The organic EL device according to the first exemplary embodiment includes plural emitting units between the anode and the cathode. A tandem organic EL device in which the emitting units are layered is occasionally referred to as a tandem organic EL device.

The organic EL device of the first exemplary embodiment at least includes the first emitting unit and the second emitting unit as the two or more emitting units. In an exemplary arrangement of the organic EL device of the first exemplary embodiment, the first emitting unit is arranged closest to the anode. In an exemplary arrangement of the organic EL device of the first exemplary embodiment, the second emitting unit is arranged closest to the cathode.

In an exemplary arrangement of the organic EL device according to the first exemplary embodiment, the two or more emitting units further includes a third emitting unit.

In an exemplary arrangement of the organic EL device according to the first exemplary embodiment, when the organic EL device includes the first emitting unit, the second emitting unit, and the third emitting unit as the two or more emitting units, the first emitting unit, the second emitting unit, and the third emitting unit may be arranged in this order toward the cathode from the anode. In this arrangement, for instance, the first emitting unit, the second emitting unit, and the third emitting unit may be arranged on the first-tier, the second-tier, and the third-tier, respectively. Alternatively, the third emitting unit, the first emitting unit, and the second emitting unit may be arranged in this order. In this arrangement, for instance, the third emitting unit, the first emitting unit, and the second emitting unit may be arranged on the first-tier, the second-tier, and the third-tier, respectively.

In an exemplary arrangement of the organic EL device according to the first exemplary embodiment, when the organic EL device includes the third emitting unit (the third-tier emitting unit), the third emitting unit includes a third emitting zone, the third emitting zone includes a third emitting layer, and the third emitting layer contains a third host material and a third luminescent compound. Materials used for the third emitting unit, the third emitting zone, and the third emitting layer (the third host material and the third luminescent compound) can be selected from later-described materials used for the first emitting unit, the first emitting zone, and the first emitting layer (a first host material and a first luminescent compound), respectively.

In an exemplary arrangement of the organic EL device according to the first exemplary embodiment, when the organic EL device includes the third emitting unit, the high refractive index zone including one or more high refractive index layers and the low refractive index zone including one or more low refractive index layers are disposed between the second emitting zone and the third emitting zone, the high refractive index zone being in direct contact with the low refractive index zone.

In an exemplary arrangement of the organic EL device according to the first exemplary embodiment, when the organic EL device includes the first emitting unit, the second emitting unit, the third emitting unit, and a fourth emitting unit as four or more emitting units, the first emitting unit (the first-tier emitting unit), the second emitting unit (the second-tier emitting unit), the third emitting unit (the third-tier emitting unit), and the fourth emitting unit (the fourth-tier emitting unit) may be arranged in this order toward the cathode from the anode, or alternatively, the third emitting unit (the first-tier emitting unit), the first emitting unit (the second-tier emitting unit), the second emitting unit (the third-tier emitting unit), and the fourth emitting unit (the fourth-tier emitting unit) may be arranged in this order toward the cathode from the anode.

In an exemplary arrangement of the organic EL device according to the first exemplary embodiment, when the organic EL device includes the fourth emitting unit (the fourth-tier emitting unit), the fourth emitting unit includes a fourth emitting zone, the fourth emitting zone includes a fourth emitting layer, and the fourth emitting layer contains a fourth host material and a fourth luminescent compound. Materials used for the fourth emitting unit, the fourth emitting zone, and the fourth emitting layer (the fourth host material and the fourth luminescent compound) can be selected from later-described materials used for the first emitting unit, the first emitting zone, and the first emitting layer (the first host material and the first luminescent compound), respectively.

In an exemplary arrangement of the organic EL device according to the first exemplary embodiment, when the organic EL device includes the fourth emitting unit, the high refractive index zone including one or more high refractive index layers and the low refractive index zone including one or more low refractive index layers are disposed between the third emitting zone and the fourth emitting zone, the high refractive index zone being in direct contact with the low refractive index zone.

### Emitting Zone

In the organic EL device according to the first exemplary embodiment, two or more emitting units each independently include the emitting zone. In other words, the organic EL device according to the first exemplary embodiment includes two or more emitting zones. In the organic EL device according to the first exemplary embodiment, the first emitting unit includes the first emitting zone and the second emitting unit includes the second emitting zone.

In the organic EL device according to the first exemplary embodiment, the emitting zones each independently include at least one emitting layer. In an exemplary arrangement of the organic EL device according to the first exemplary embodiment, the emitting zones may each independently include only one emitting layer or may each independently include two or more emitting layers. In an exemplary arrangement of the organic EL device according to the first exemplary embodiment, the emitting layers each independently contain a host material. In an exemplary arrangement of the organic EL device according to the first exemplary embodiment, the emitting layers each independently contain a host material and a luminescent compound. In an exemplary arrangement of the organic EL device according to the first exemplary embodiment, the respective luminescent compounds of the emitting layers are each independently a fluorescent compound or a phosphorescent compound. In the organic EL device of the first exemplary embodiment, at least one emitting layer preferably contains a fluorescent compound.

In an exemplary arrangement of the organic EL device according to the first exemplary embodiment, the first emitting zone includes a first emitting layer. In an exemplary arrangement of the organic EL device according to the first exemplary embodiment, the first emitting layer contains a first host material.

In an exemplary arrangement of the organic EL device according to the first exemplary embodiment, the first emitting zone contains the first luminescent compound.

In an exemplary arrangement of the organic EL device according to the first exemplary embodiment, the first emitting layer contains the first luminescent compound.

In an exemplary arrangement of the organic EL device according to the first exemplary embodiment, the first emitting layer contains the first host material and the first luminescent compound.

In an exemplary arrangement of the organic EL device according to the first exemplary embodiment, the second emitting zone contains a second luminescent compound.

In an exemplary arrangement of the organic EL device according to the first exemplary embodiment, the second emitting layer contains the second luminescent compound.

In an exemplary arrangement of the organic EL device according to the first exemplary embodiment, the second emitting layer contains the second host material and the second luminescent compound.

In an exemplary arrangement of the organic EL device according to the first exemplary embodiment, the first luminescent compound and the second luminescent compound are mutually the same or different.

In an exemplary arrangement of the organic EL device according to the first exemplary embodiment, one or both of the first luminescent compound and the second luminescent compound are a compound that emits light having a maximum peak wavelength of 500 nm or less.

In an exemplary arrangement of the organic EL device according to the first exemplary embodiment, one or both of the first luminescent compound and the second luminescent compound are a compound that emits light having a maximum peak wavelength of 480 nm or less.

In an exemplary arrangement of the organic EL device according to the first exemplary embodiment, one or both of the first luminescent compound and the second luminescent compound are a compound that emits light having a maximum peak wavelength of 430 nm or more.

A measurement method of the maximum peak wavelength of a compound is as follows. A toluene solution in which a measurement target compound is dissolved at a concentration ranging from 10⁻⁶ mol/L to 10⁻⁵ mol/L is prepared and put in a quartz cell. An emission spectrum of the thus-obtained sample is measured at a normal temperature (300K). The ordinate axis of the emission spectrum represents a luminous intensity and the abscissa axis thereof represents a wavelength. The emission spectrum can be measured using a spectrophotometer (machine name: F-7000) produced by Hitachi High-Tech Science Corporation. It should be noted that the apparatus for measuring the emission spectrum is not limited to the apparatus used herein.

### Host Material and Dopant Material

In an exemplary arrangement of the organic EL device according to the exemplary embodiment, one or more emitting layers in the emitting zone each independently contain a host material and a dopant material. The host material is occasionally referred to as a matrix material. The dopant material is occasionally referred to as a luminescent compound, guest material, emitter, or luminescent material.

In an exemplary arrangement of the organic EL device according to the exemplary embodiment, one or more emitting layers in the emitting zone each independently contain at least one dopant material selected from the group consisting of dopant materials below and at least one host material selected from the group consisting of host materials below.

### Dopant Material of Emitting Layer

The emitting layer is a layer containing a highly luminescent substance. Various materials are usable for the emitting layer. For instance, a fluorescent compound that fluoresces or a phosphorescent compound that phosphoresces is usable as the highly luminescent substance. The fluorescent compound is a compound that can emit light in a singlet state. The phosphorescent compound is a compound that can emit light in a triplet state.

Examples of a blue fluorescent material usable for the emitting layer include a pyrene derivative, styrylamine derivative, chrysene derivative, fluoranthene derivative, fluorene derivative, diamine derivative, and triarylamine derivative. Specifically, the examples include N,N′-bis[4-(9H-carbazol-9-yl)phenyl]-N,N′-diphenylstilbene-4,4′-diamine (abbreviation: YGA2S), 4-(9H-carbazol-9-yl)-4′-(10-phenyl-9-anthryl)triphenylamine (abbreviation: YGAPA), and 4-(10-phenyl-9-anthryl)-4′-(9-phenyl-9H-carbazol-3-yl)triphenylamine (abbreviation: PCBAPA).

Examples of a green fluorescent material usable for the emitting layer include an aromatic amine derivative. Specifically, the examples include N-(9,10-diphenyl-2-anthryl)-N, 9-diphenyl-9H-carbazole-3-amine (abbreviation: 2PCAPA), N-[9,10-bis(1,1′-biphenyl-2-yl)-2-anthryl]-N,9-diphenyl-9H-carbazole-3-amine (abbreviation: 2PCABPhA), N-(9,10-diphenyl-2-anthryl)-N,N′,N′-triphenyl-1,4-phenylenediamine (abbreviation: 2DPAPA), N-[9,10-bis(1,1′-biphenyl-2-yl)-2-anthryl]-N,N′,N′-triphenyl-1,4-phenylenediamine (abbreviation: 2DPABPhA), N-[9,10-bis(1,1′-biphenyl-2-yl)]-N-[4-(9H-carbazol-9-yl)phenyl]-N-phenylanthracene-2-amine (abbreviation: 2YGABPhA), and N,N,9-triphenylanthracene-9-amine (abbreviation: DPhAPhA)

Examples of a red fluorescent material usable for the emitting layer include a tetracene derivative and a diamine derivative. Specifically, the examples include N,N,N′,N′-tetrakis(4-methylphenyl)tetracene-5,11-diamine (abbreviation: p-mPhTD) and 7,14-diphenyl-N,N,N′,N′-tetrakis(4-methylphenyl)acenaphtho[1,2-a]fluoranthene-3,10-diamine (abbreviation: p-mPhAFD)

Examples of a blue fluorescent material usable for the emitting layer include metal complexes such as an iridium complex, an osmium complex, and a platinum complex. Specifically, the examples include bis[2-(4′,6′-difluorophenyl)pyridinato-N,C2′]iridium (III) tetrakis(1-pyrazolyl) borate (abbreviation: Flr6), bis[2-(4′,6′-difluorophenyl)pyridinato-N,C2′]iridium (III) picolinate (abbreviation: Flrpic), bis[2-(3′,5′-bistrifluoromethylphenyl)pyridinato-N,C2′]iridium (III) piccolinate (abbreviation: Ir(CF₃ppy)₂(pic)), and bis[2-(4′,6′-difluorophenyl)pyridinato-N,C2′]iridium (III) acetylacetonate (abbreviation: Flracac).

Examples of a green phosphorescent material usable for the emitting layer include an iridium complex. The examples include tris(2-phenylpyridinato-N,C2′)iridium (III) (abbreviation: Ir(ppy)₃), bis(2-phenylpyridinato-N,C2′)iridium (III) acetylacetonate (abbreviation: Ir(ppy)₂(acac), bis(1,2-diphenyl-1H-benzoimidazolato)iridium (III) acetylacetonate (abbreviation: Ir(pbi)₂(acac)), and bis(benzo[h]quinolinato)iridium (III) acetylacetonate (abbreviation: Ir(bzq)₂(acac)).

Examples of a red phosphorescent material usable for the emitting layer include metal complexes such as an iridium complex, a platinum complex, a terbium complex, and a europium complex. Specifically, the examples include organometallic complexes such as bis[2-(2′-benzo[4,5-α]thienyl)pyridinato-N,C3′]iridium (III) acetylacetonate (abbreviation: Ir(btp)₂(acac)), bis(1-phenylisoquinolinato-N,C2′)iridium (III) acetylacetonate (abbreviation: Ir(piq)₂(acac)), (acetylacetonato)bis[2,3-bis(4-fluorophenyl)quinoxalinato]iridium (III) (abbreviation: Ir(Fdpq)₂(acac)), and 2,3,7,8,12,13,17,18-octaethyl-21H,23H-porphyrin platinum (II) (abbreviation: PtOEP).

Rare-earth metal complexes such as tris(acetylacetonato)(monophenanthroline)terbium(III) (abbreviation: Tb(acac)₃(Phen)), tris(1,3-diphenyl-1,3-propanedionato)(monophenanthroline)europium (III) (abbreviation: Eu(DBM)₃(Phen)), and tris[1-(2-thenoyl)-3,3,3-trifluoroacetonato](monophenanthroline)europium (III) (abbreviation: Eu(TTA)₃(Phen)), which emit light from rare-earth metal ions (electron transitions between different multiplicities), are usable as a phosphorescent compound.

### Compound Represented by Formula (2)

In an exemplary arrangement of the organic EL device according to the first exemplary embodiment, the dopant material (luminescent compound) is a compound represented by a formula (2) below. In an exemplary arrangement of the organic EL device according to the first exemplary embodiment, the first luminescent compound and the second luminescent compound are each a compound represented by the formula (2) below. The compound represented by the formula (2) below is occasionally referred to as a second compound.

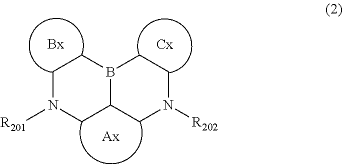

In the formula (2):
a ring Ax, a ring Bx and a ring Cx are each independently a substituted or unsubstituted aromatic hydrocarbon ring having 6 to 50 ring carbon atoms, or a substituted or unsubstituted heterocycle having 5 to 50 ring atoms;
R₂₀₁ and R₂₀₂ are each independently bonded with the ring Ax, the ring Bx or the ring Cx to form a substituted or unsubstituted monocyclic ring, bonded with the ring Ax, the ring Bx or the ring Cx to form a substituted or unsubstituted fused ring, or not bonded with the ring Ax, the ring Bx or the ring Cx, R₂₀₁ and R₂₀₂ forming neither the substituted or unsubstituted monocyclic ring nor the substituted or unsubstituted fused ring are each independently a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, an iminyl group represented by —CR₂₅═N, a substituted or unsubstituted aryl group having 6 to 50 ring carbon atoms, or a substituted or unsubstituted heterocyclic group having 5 to 50 ring atoms;
R₂₅ is a substituted or unsubstituted aryl group having 6 to 60 ring carbon atoms, a substituted or unsubstituted heterocyclic group having 5 to 60 ring atoms, a substituted or unsubstituted alkyl group having 1 to 20 carbon atoms, or a substituted or unsubstituted cycloalkyl group having 3 to 20 ring carbon atoms; and
when a plurality of R₂₅ are present, the plurality of R₂₅ are mutually the same or different.

In an exemplary arrangement of the organic EL device according to the first exemplary embodiment, the second compound is a compound represented by a formula (21) or (22) below.

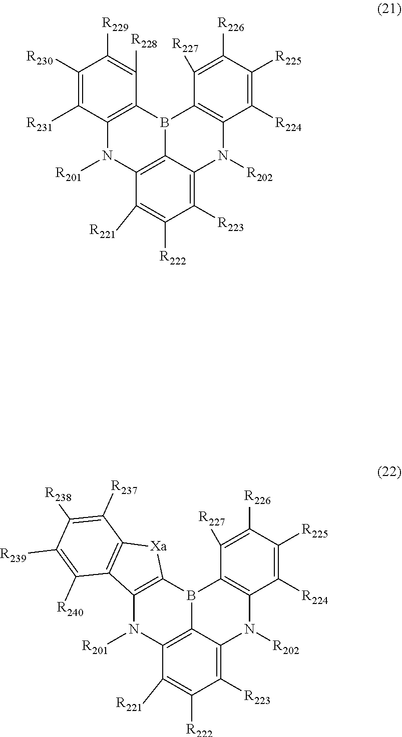

In the formula (21):
at least one combination selected from the group consisting of a combination of R₂₀₁ and R₂₂₁, a combination of adjacent two or more of R₂₂₁ to R₂₂₃, a combination of R₂₂₃ and R₂₀₂, a combination of R₂₀₂ and R₂₂₄, a combination of adjacent two or more of R₂₂₄ to R₂₂₇, a combination of R₂₂₇ and R₂₂₈, a combination of adjacent two or more of R₂₂₈ to R₂₃₁, and a combination of R₂₃₁ and R₂₀₁ are mutually bonded to form a substituted or unsubstituted monocyclic ring, mutually bonded to form a substituted or unsubstituted fused ring, or not mutually bonded; and
R₂₀₁ and R₂₀₂ forming neither the substituted or unsubstituted monocyclic ring nor the substituted or unsubstituted fused ring respectively represent the same as R₂₀₁ and R₂₀₂ in the formula (2);
in the formula (22):
Xa is O, S, Se, C(R₂₀₃)(R₂₀₄), or N(R₂₀₅);
at least one combination selected from the group consisting of a combination of R₂₀₁ and R₂₂₁, a combination of adjacent two or more of R₂₂₁ to R₂₂₃, a combination of R₂₂₃ and R₂₀₂, a combination of R₂₀₂ and R₂₂₄, a combination of adjacent two or more of R₂₂₄ to R₂₂₇, and a combination of adjacent two or more of R₂₃₇ to R₂₄₀ are mutually bonded to form a substituted or unsubstituted monocyclic ring, mutually bonded to form a substituted or unsubstituted fused ring, or not mutually bonded; and
R₂₀₁ and R₂₀₂ forming neither the substituted or unsubstituted monocyclic ring nor the substituted or unsubstituted fused ring each independently represent the same as R₂₀₁ and R₂₀₂ in the formula (2);
in the formula (21) or (22):
R₂₀₃, R₂₀₄ and R₂₀₅, and R₂₂₁, R₂₂₂, R₂₂₃, R₂₂₄, R₂₂₅, R₂₂₆, R₂₂₇, R₂₂₈, R₂₂₉, R₂₃₀, R₂₃₁, R₂₃₇, R₂₃₈, R₂₃₉ and R₂₄₀ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In an exemplary embodiment of the organic EL device according to the first exemplary embodiment, R₂₀₁ and R₂₀₂ in the formula (21) or (22) are each independently a substituted or unsubstituted aryl group having 6 to 50 ring carbon atoms, or a substituted or unsubstituted heterocyclic group having 5 to 50 ring atoms.

In an exemplary embodiment of the organic EL device according to the first exemplary embodiment, R₂₀₁ and R₂₀₂ in the formula (21) or (22) are each independently a substituted or unsubstituted aryl group having 6 to 50 ring carbon atoms.

In an exemplary embodiment of the organic EL device according to the first exemplary embodiment, R₂₀₁ and R₂₀₂ in the formula (21) or (22) are each independently a substituted or unsubstituted aryl group having 6 to 18 ring carbon atoms.

In an exemplary embodiment of the organic EL device according to the first exemplary embodiment, R₂₀₁ and R₂₀₂ in the formula (21) or (22) are each independently a group represented by a formula (23) below.

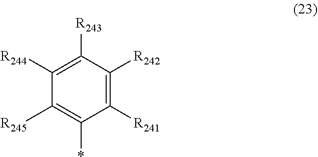

In the formula (23):
at least one combination of adjacent two or more of R₂₄₁, R₂₄₂, R₂₄₃, R₂₄₄, and R₂₄₅ are mutually bonded to form a substituted or unsubstituted monocyclic ring, mutually bonded to form a substituted or unsubstituted fused ring, or not mutually bonded;
R₂₄₁, R₂₄₂, R₂₄₃, R₂₄₄, and R₂₄₅ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
R₉₀₁ to R₉₀₇ each independently represent the same as R₉₀₁ to R₉₀₇ in the formulae (21) and (22);
when a plurality of R₂₄₁ are present, the plurality of R₂₄₁ are mutually the same or different;
when a plurality of R₂₄₂ are present, the plurality of R₂₄₂ are mutually the same or different;
when a plurality of R₂₄₃ are present, the plurality of R₂₄₃ are mutually the same or different;
when a plurality of R₂₄₄ are present, the plurality of R₂₄₄ are mutually the same or different;
when a plurality of R₂₄₅ are present, the plurality of R₂₄₅ are mutually the same or different; and
* represents a bonding position.

In an exemplary arrangement of the organic EL device according to the first exemplary embodiment, the second compound is a compound represented by a formula (211) or (221) below.

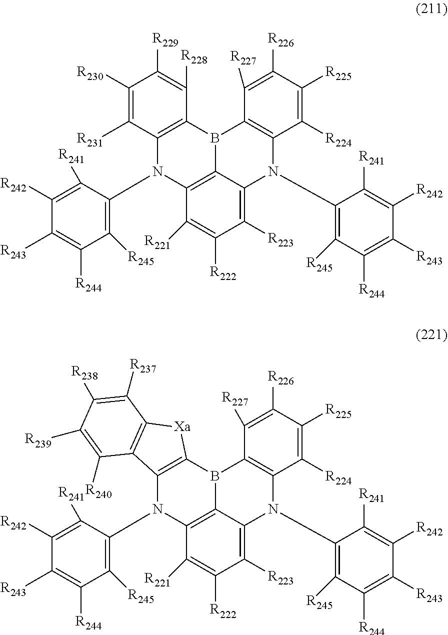

In the formulae (211) and (221): R₂₂₁ to R₂₃₁ and R₂₃₇ to R₂₄₀ respectively represent the same as R₂₂₁ to R₂₃₁ and R₂₃₇ to R₂₄₀ in the formulae (21) and (22); R₂₄₁ to R₂₄₅ respectively represent the same as R₂₄₁ to R₂₄₅ in the formula (23); and Xa in the formula (221) represents the same as Xa in the formula (22).

In an exemplary arrangement of the organic EL device according to the first exemplary embodiment, the second compound is a compound represented by a formula (212) or (222) below.

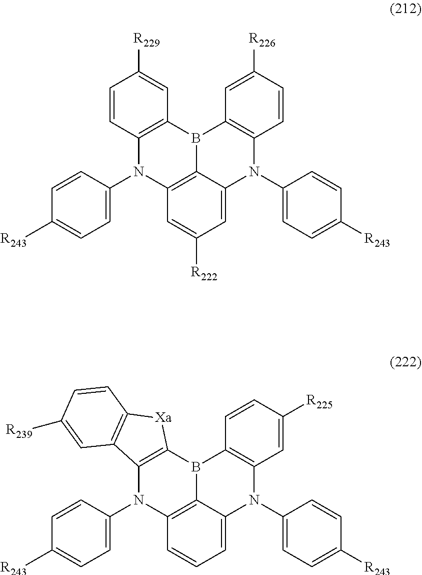

In the formula (212), R₂₂₂, R₂₂₆ and R₂₂₉ respectively represent the same as R₂₂₂, R₂₂₆ and R₂₂₉ in the formula (21).

In the formula (222), Xa, R₂₂₅ and R₂₃₉ respectively represent the same as Xa, R₂₂₅ and R₂₃₉ in the formula (22).

R₂₄₃ in the formulae (212) and (222) each independently represent the same as R₂₄₃ in the formula (23).

In an exemplary arrangement of the organic EL device according to the first exemplary embodiment, Xa in the formulae (22), (221) and (222) is a sulfur atom(S) or an oxygen atom (O).

Herein, the maximum peak wavelength of fluorescence is occasionally referred to as a maximum fluorescence peak wavelength.

In an exemplary arrangement of the first exemplary embodiment, the maximum fluorescence peak wavelength of the second compound is preferably 430 nm or more, more preferably 440 nm or more, and still more preferably 445 nm or more.

In an exemplary arrangement of the first exemplary embodiment, the maximum fluorescence peak wavelength of the second compound is preferably 480 nm or less, more preferably 470 nm or less, and still more preferably 465 nm or less.

When the maximum fluorescence peak wavelength of the second compound in the first exemplary embodiment is 430 nm or more, an electronic device (e.g., display) including the organic EL device including the compound according to the exemplary embodiment easily emits moderate blue light.

When the maximum fluorescence peak wavelength of the second compound in the first exemplary embodiment is 480 nm or less, an electronic device (e.g., display) including the organic EL device including the compound according to the exemplary embodiment easily emits moderate blue light.

Herein, the maximum fluorescence peak wavelength means a peak wavelength of a fluorescence spectrum exhibiting a maximum luminous intensity among fluorescence spectra measured in a toluene solution in which a measurement target compound is dissolved at a concentration ranging from 10⁻⁶ mol/l to 10⁻⁵ mol/l. A fluorescence spectrum measurement apparatus (apparatus name: FP-8300, produced by JASCO Corporation) is usable as a measurement apparatus. It should be noted that the fluorescence spectrum measurement apparatus is not limited to the apparatus listed herein.

In an exemplary arrangement of the organic EL device of the first exemplary embodiment, the groups specified to be “substituted or unsubstituted” are also each preferably an “unsubstituted” group.

Unless otherwise specified herein, the details of the substituents (optional substituents) for “the substituted or unsubstituted group” in the definition of each compound are as described in the section “the substituent for the substituted or unsubstituted group.”

### Producing Method of Second Compound in First Exemplary Embodiment

The second compound according to the first exemplary embodiment is producible by a known method. Further, the second compound according to the first exemplary embodiment can also be produced based on a known method through a known alternative reaction using a known material(s) tailored for the target compound.

### Specific Examples of Second Compound in First Exemplary Embodiment

Specific examples of the second compound according to the first exemplary embodiment include the following compounds. However, the invention is by no means limited to these specific examples.

In the specific examples of the compounds herein, D represents a deuterium atom, Me represents a methyl group, tBu represents a tert-butyl group, and Ph represents a phenyl group.

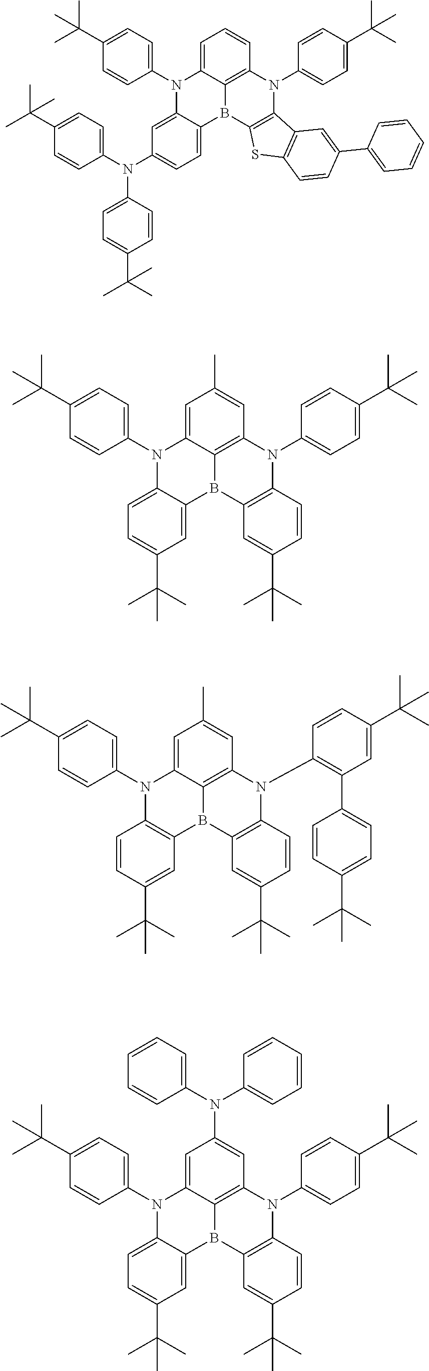

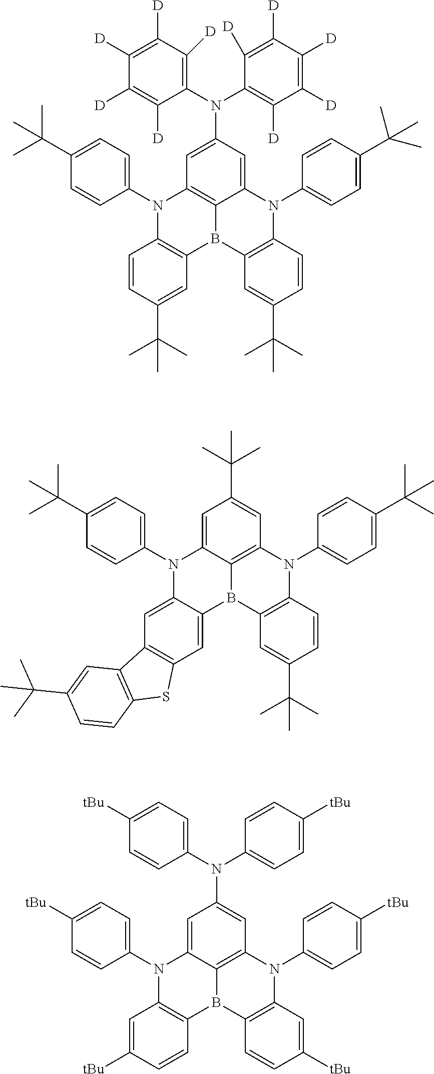

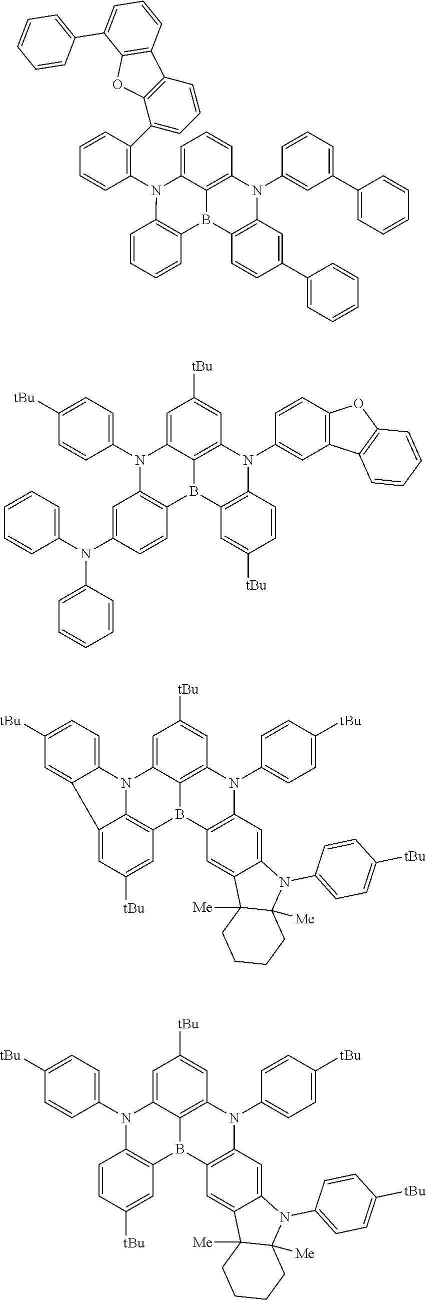 [SMILES: c1ccc(-c2cccc(N3c4cc(-c5ccccc5)ccc4B4c5ccccc5N(c5ccccc5-c5cccc6c5oc5c(-c7ccccc7)cccc56)c5cccc3c54)c2)cc1 ; CC(C)(C)c1ccc(N2c3cc(N(c4ccccc4)c4ccccc4)ccc3B3c4cc(C(C)(C)C)ccc4N(c4ccc5oc6ccccc6c5c4)c4cc(C(C)(C)C)cc2c43)cc1 ; CC(C)(C)c1ccc(N2c3cc4c(cc3B3c5c2cc(C(C)(C)C)cc5-n2c5ccc(C(C)(C)C)cc5c5cc(C(C)(C)C)cc3c52)C2(C)CCCCC2(C)N4c2ccc(C(C)(C)C)cc2)cc1 ; CC(C)(C)c1ccc(N2c3ccc(C(C)(C)C)cc3B3c4cc5c(cc4N(c4ccc(C(C)(C)C)cc4)c4cc(C(C)(C)C)cc2c43)N(c2ccc(C(C)(C)C)cc2)C2(C)CCCCC52C)cc1]

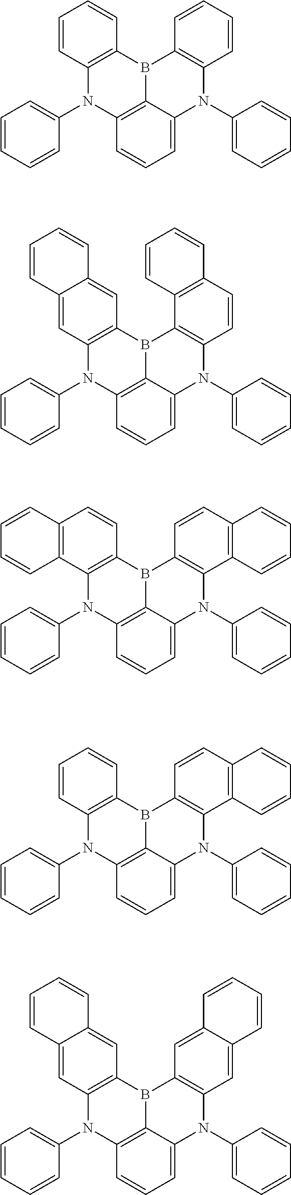 [SMILES: c1ccc(N2c3ccccc3B3c4ccccc4N(c4ccccc4)c4cccc2c43)cc1 ; c1ccc(N2c3cc4ccccc4cc3B3c4c2cccc4N(c2ccccc2)c2ccc4ccccc4c23)cc1 ; c1ccc(N2c3cccc4c3B(c3ccc5ccccc5c32)c2ccc3ccccc3c2N4c2ccccc2)cc1 ; c1ccc(N2c3ccccc3B3c4ccc5ccccc5c4N(c4ccccc4)c4cccc2c43)cc1 ; c1ccc(N2c3cc4ccccc4cc3B3c4cc5ccccc5cc4N(c4ccccc4)c4cccc2c43)cc1]

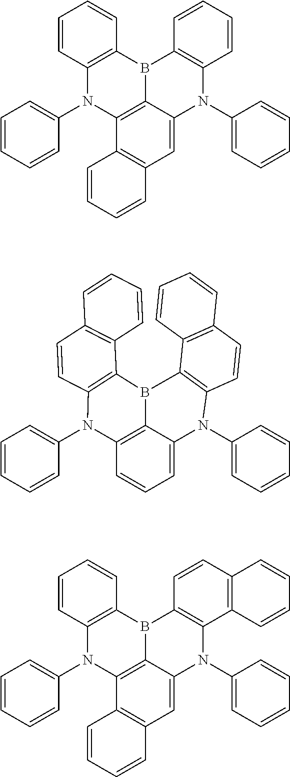 [SMILES: c1ccc(N2c3ccccc3B3c4ccccc4N(c4ccccc4)c4c3c2cc2ccccc42)cc1 ; c1ccc(N2c3cccc4c3B(c3c2ccc2ccccc32)c2c(ccc3ccccc23)N4c2ccccc2)cc1 ; c1ccc(N2c3cc4ccccc4c4c3B(c3ccccc3N4c3ccccc3)c3ccc4ccccc4c32)cc1]

### Host Material of Emitting Layer

The emitting layer may have a structure in which the highly luminescent substance (dopant material) described above is dispersed in another substance (host material).

Various compounds are usable as a substance for dispersing the highly luminescent substance. The substance for dispersing the highly luminescent substance preferably has a higher lowest unoccupied molecular orbital (LUMO) level and a lower highest occupied molecular orbital (HOMO) level than the highly luminescent substance.

The substance (host material) for dispersing the highly luminescent substance is preferably at least one selected from the group consisting of compounds described in the following (1) to (4):
(1) metal complexes such as aluminum complexes, beryllium complexes, or zinc complexes;
(2) heterocyclic compounds such as oxadiazole derivatives, benzimidazole derivatives, or phenanthroline derivatives;
(3) fused aromatic compounds such as carbazole derivatives, anthracene derivatives, phenanthrene derivatives, pyrene derivatives, or chrysene derivatives; and
(4) aromatic amine compounds such as triarylamine derivatives or fused polycyclic aromatic amine derivatives.

Specifically, examples of the metal complexes include tris(8-quinolinolato)aluminum(III) (abbreviation: Alq), tris(4-methyl-8-quinolinolato)aluminum(III) (abbreviation: Almq₃), bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), and bis[2-(2-benzothiazolyl)phenolato]zinc(II) (abbreviation: ZnBTZ).

Examples of the heterocyclic compounds include 2-(4-biphenylyl)-5-(4-tert-butylphenyl)-1,3,4-oxadiazole (abbreviation: PBD), 1,3-bis[5-(p-tert-butylphenyl)-1,3,4-oxadiazol-2-yl]benzene (abbreviation: OXD-7), 3-(4-biphenylyl)-4-phenyl-5-(4-tert-butylphenyl)-1,2,4-triazole (abbreviation: TAZ), 2,2′,2″-(1,3,5-benzenetriyl)tris(1-phenyl-1H-benzimidazole) (abbreviation: TPBI), bathophenanthroline (abbreviation: BPhen), and bathocuproin (abbreviation: BCP).

Examples of the fused aromatic compounds include 9-[4-(10-phenyl-9-anthryl)phenyl]-9H-carbazole (abbreviation: CzPA), 3,6-diphenyl-9-[4-(10-phenyl-9-anthryl)phenyl]-9H-carbazole (abbreviation: DPCzPA), 9,10-bis(3,5-diphenylphenyl)anthracene (abbreviation: DPPA), 9,10-di(2-naphthyl)anthracene (abbreviation: DNA), 2-tert-butyl-9,10-di(2-naphthyl)anthracene (abbreviation: t-BuDNA), 9,9′-biantryl (abbreviation: BANT), 9,9′-(stilbene-3,3′-diyl)diphenanthrene (abbreviation: DPNS), 9,9′-(stilbene-4,4′-diyl)diphenanthrene (abbreviation: DPNS2), 3,3′,3″-(benzene-1,3,5-triyl)tripyrene (abbreviation: TPB3), 9,10-diphenylanthracene (abbreviation: DPAnth), and 6,12-dimethoxy-5,11-diphenylchrysene.

Examples of the aromatic amine compounds include N,N-diphenyl-9-[4-(10-phenyl-9-anthryl)phenyl]-9H-carbazole-3-amine (abbreviation: CzA1PA), 4-(10-phenyl-9-anthryl)triphenylamine (abbreviation: DPhPA), N,9-diphenyl-N-[4-(10-phenyl-9-anthryl)phenyl]-9H-carbazole-3-amine (abbreviation: PCAPA), N,9-diphenyl-N-{4-[4-(10-phenyl-9-anthryl)phenyl]phenyl}-9H-carbazole-3-amine (abbreviation: PCAPBA), N-(9,10-diphenyl-2-anthryl)-N,9-diphenyl-9H-carbazole-3-amine (abbreviation: 2PCAPA), NPB (or α-NPD), TPD, DFLDPBi, and BSPB.

### Compound Represented by Formula (3)

In an exemplary arrangement of the organic EL device according to the first exemplary embodiment, the host material is a compound represented by a formula (3) below. In an exemplary arrangement of the organic EL device according to the first exemplary embodiment, the first host material and the second host material are each a compound represented by the formula (3) below. The compound represented by the formula (3) below is occasionally referred to as a third compound.

In the organic EL device according to the first exemplary embodiment, the third compound is a compound represented by the formula (3) below.

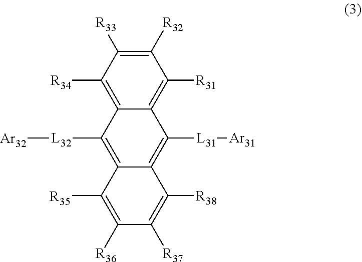

In the formula (3):
R₃₁ to R₃₈ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, or a substituted or unsubstituted heterocyclic group having 5 to 50 ring atoms;
L₃₁ and L₃₂ are each independently a single bond, a substituted or unsubstituted arylene group having 6 to 50 ring carbon atoms, or a substituted or unsubstituted divalent heterocyclic group having 5 to 50 ring atoms; and
Ar₃₁ and Ar₃₂ are each independently a substituted or unsubstituted aryl group having 6 to 50 ring carbon atoms, or a substituted or unsubstituted heterocyclic group having 5 to 50 ring atoms.

In the third compound: R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; when a plurality of R₉₀₁ are present, the plurality of R₉₀₁ are mutually the same or different; when a plurality of R₉₀₂ are present, the plurality of R₉₀₂ are mutually the same or different; when a plurality of R₉₀₃ are present, the plurality of R₉₀₃ are mutually the same or different; when a plurality of R₉₀₄ are present, the plurality of R₉₀₄ are mutually the same or different; when a plurality of R₉₀₅ are present, the plurality of R₉₀₅ are mutually the same or different; when a plurality of R₉₀₆ are present, the plurality of R₉₀₆ are mutually the same or different; and when a plurality of R₉₀₇ are present, the plurality of R₉₀₇ are mutually the same or different.

In an exemplary arrangement of the organic EL device according to the first exemplary embodiment, the third compound is a compound represented by a formula (31) below.

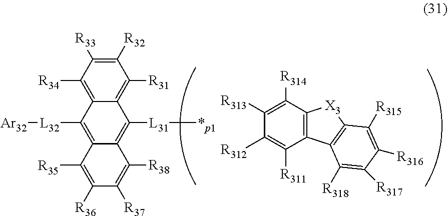

In the formula (31):
R₃₁ to R₃₈ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
X₃ is an oxygen atom or a sulfur atom;
one of R₃₁₁ to R₃₁₈ is a single bond to *p1;
at least one combination of adjacent two or more of R₃₁₁ to R₃₁₈ not being a single bond to *p1 are mutually bonded to form a substituted or unsubstituted monocyclic ring, mutually bonded to form a substituted or unsubstituted fused ring, or not mutually bonded;
R₃₁₁ to R₃₁₈ neither being the single bond to *p1, nor forming the substituted or unsubstituted monocyclic ring, nor forming the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
L₃₁ and L₃₂ are each independently a single bond, a substituted or unsubstituted arylene group having 6 to 50 ring carbon atoms, or a substituted or unsubstituted divalent heterocyclic group having 5 to 50 ring atoms; and
Ar₃₂ is a substituted or unsubstituted aryl group having 6 to 50 ring carbon atoms, or a substituted or unsubstituted heterocyclic group having 5 to 50 ring atoms.

In an exemplary arrangement of the organic EL device according to the first exemplary embodiment, the third compound is a compound represented by a formula (31A), (31B) or (31C) below.

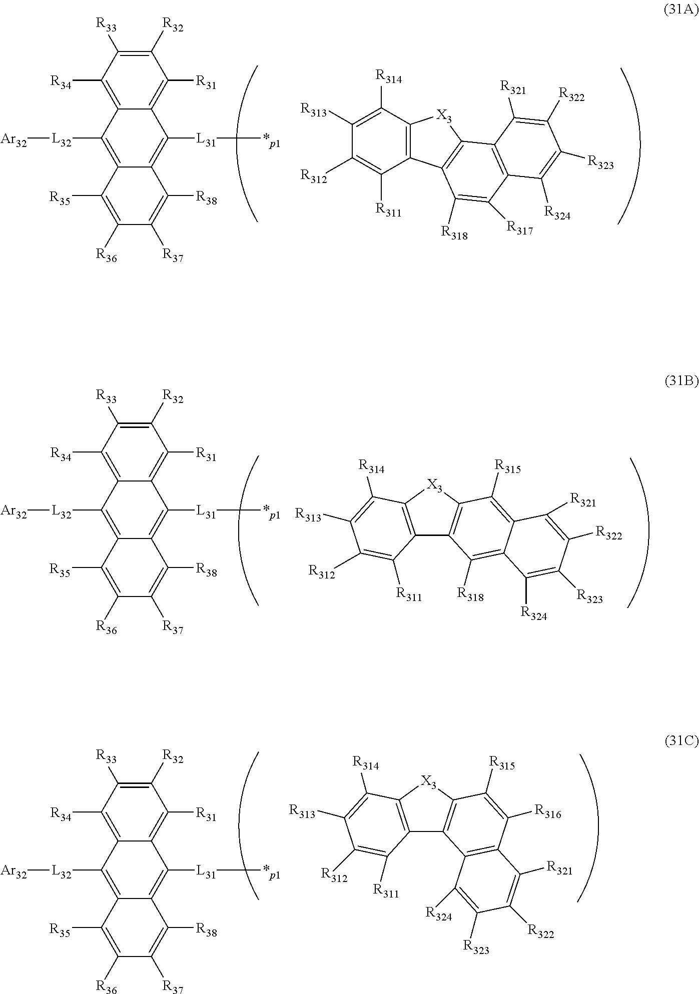

In the formulae (31A), (31B) and (31C):
R₃₁ to R₃₈, L₃₁, L₃₂, and Ar₃₂ respectively represent the same as R₃₁ to R₃₈, L₃₁, L₃₂, and Ar₃₂ in the formula (3);
X₃ represents the same as X₃ in the formula (31);
one of R₃₁₁ to R₃₁₈ and R₃₂₁ to R₃₂₄ is a single bond to *p1;
at least one combination of adjacent two or more of R₃₁₁ to R₃₁₈ and R₃₂₁ to R₃₂₄ not being a single bond to *p1 are mutually bonded to form a substituted or unsubstituted monocyclic ring, mutually bonded to form a substituted or unsubstituted fused ring, or not mutually bonded;
R₃₁₁ to R₃₁₈ and R₃₂₁ to R₃₂₄ neither being the single bond to *p1, nor forming the substituted or unsubstituted monocyclic ring, nor forming the substituted or unsubstituted fused ring are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms.

In an exemplary arrangement of the organic EL device according to the first exemplary embodiment, the third compound is a compound represented by the formula (31A) and R₃₁₁ is a single bond to *p1.

In an exemplary arrangement of the organic EL device according to the first exemplary embodiment, the third compound is a compound represented by the formula (31B) and R₃₁₁ is a single bond to *p1.

In an exemplary arrangement of the organic EL device according to the first exemplary embodiment, a compound represented by the formula (3) is a compound represented by a formula (311), (312), (313), or (314) below.

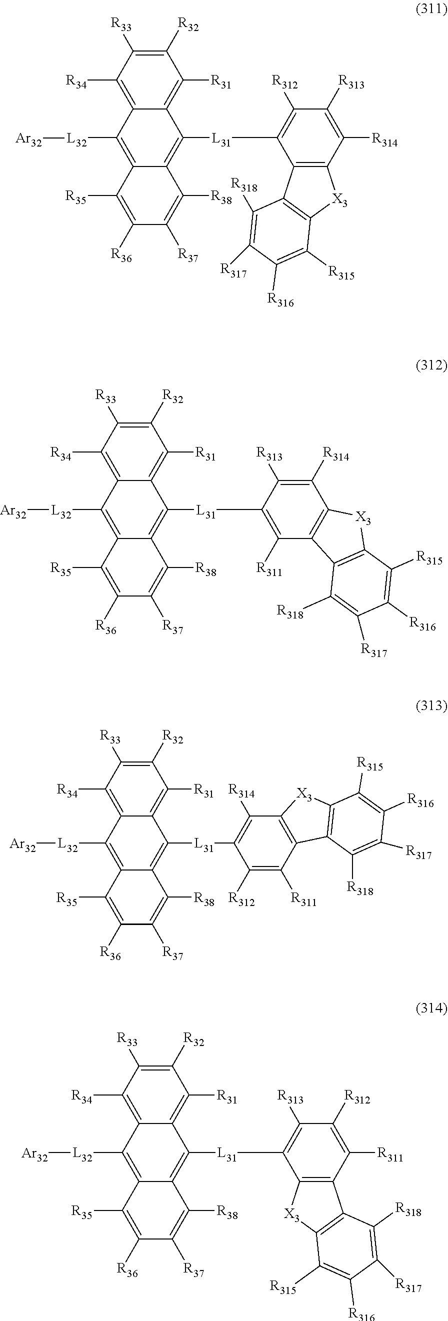

In the formulae (313), (312), (313), and (314), R₃₁ to R₃₈, R₃₁₁ to R₃₁₈, L₃₁, L₃₂, Ar₃₂, and X₃ are each the same as defined in the formula (3) or (31).

In an exemplary arrangement of the organic EL device according to the first exemplary embodiment, at least one combination of adjacent two or more of R₃₁₁ to R₃₁₈ not being a single bond to *p1 are mutually bonded to form a substituted or unsubstituted monocyclic ring, or mutually bonded to form a substituted or unsubstituted fused ring.

In an exemplary arrangement of the organic EL device according to the first exemplary embodiment, at least one combination of adjacent two or more of R₃₁₁ to R₃₁₄ not being a single bond to *p1 are not mutually bonded, and at least one combination of adjacent two or more of R₃₁₅ to R₃₁₈ not being a single bond to *p1 are mutually bonded to form a substituted or unsubstituted monocyclic ring or a substituted or unsubstituted fused ring.

In an exemplary arrangement of the organic EL device according to the first exemplary embodiment, none of combinations of adjacent two or more of R₃₁₁ to R₃₁₈ not being a single bond to *p1 are mutually bonded.

In an exemplary arrangement of the organic EL device of the first exemplary embodiment, L₃₁ and L₃₂ are each independently a single bond or a substituted or unsubstituted arylene group having 6 to 14 ring carbon atoms.

In an exemplary arrangement of the organic EL device of the first exemplary embodiment, L₃₁ and L₃₂ are each independently a single bond, a substituted or unsubstituted phenylene group, or a substituted or unsubstituted naphthylene group.

In an exemplary arrangement of the organic EL device of the first exemplary embodiment, at least one of Ar₃₁ or Ar₃₂ is a substituted or unsubstituted aryl group having 6 to 50 ring carbon atoms.

In an exemplary arrangement of the organic EL device of the first exemplary embodiment, Ar₃₂ is a substituted or unsubstituted aryl group having 6 to 50 ring carbon atoms.

In an exemplary arrangement of the organic EL device of the first exemplary embodiment, at least one of Ar₃₁ or Ar₃₂ is a group represented by a formula (32a), (32b), (32c), or (32d).

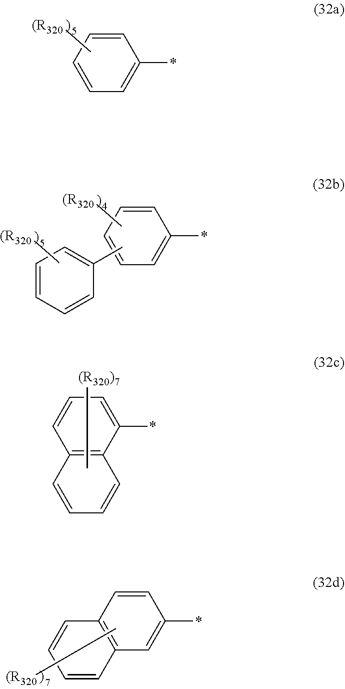

In the formulae (32a), (32b), (32c), and (32d):
at least one combination of adjacent two or more of a plurality of R₃₂₀ are mutually bonded to form a substituted or unsubstituted monocyclic ring, mutually bonded to form a substituted or unsubstituted fused ring, or not mutually bonded;
R₃₂₀ forming neither the substituted or unsubstituted monocyclic ring nor the substituted or unsubstituted fused ring is a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
a plurality of R₃₂₀ are mutually the same or different; and
* represents a single bond to L₃₁ or L₃₂.

In an exemplary arrangement of the organic EL device of the first exemplary embodiment, X₃ is an oxygen atom.

In an exemplary arrangement of the organic EL device of the first exemplary embodiment, Ar₃₂ is a group represented by the formula (32a), (32b), (32c), or (32d).

In an exemplary arrangement of the organic EL device according to the first exemplary embodiment, R₃₁ to R₃₈ are each a hydrogen atom.

In an exemplary arrangement of the organic EL device according to the first exemplary embodiment, a compound represented by the formula (3) is a compound represented by a formula (325), (326), (327), (328), or (329) below.

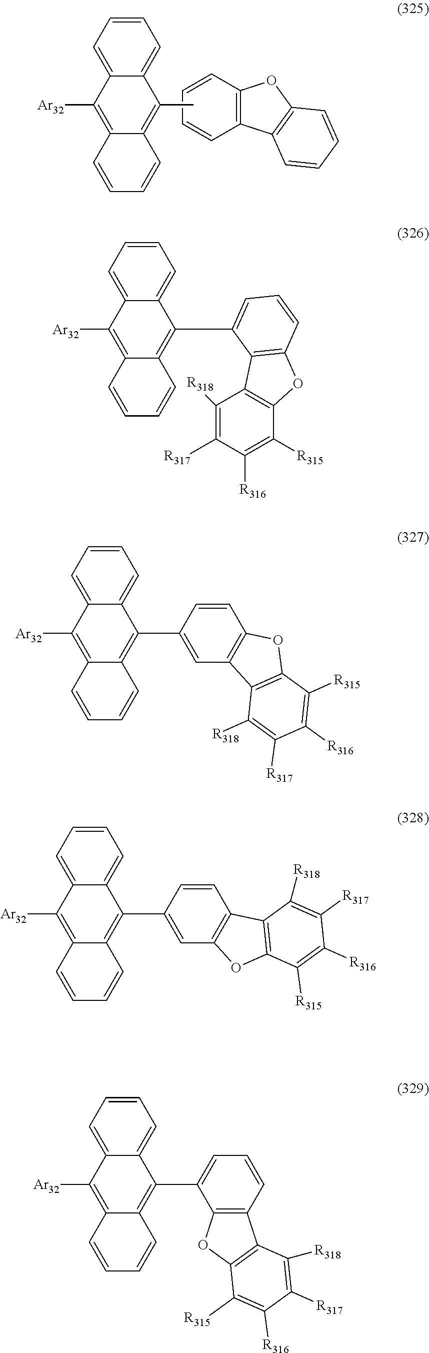

In the formulae (325) to (329), R₃₁₅ to R₃₁₈ and Ar₃₂ respectively represent the same as R₃₁₅ to R₃₁₈ and Ar₃₂ in the formula (3).

In an exemplary arrangement of the organic EL device of the first exemplary embodiment, at least one combination of adjacent two or more of R₃₁₅ to R₃₁₈ are mutually bonded to form a substituted or unsubstituted monocyclic ring.

In an exemplary arrangement of the organic EL device of the first exemplary embodiment, at least one combination of adjacent two or more of R₃₁₅ to R₃₁₈ are mutually bonded to form a substituted or unsubstituted benzene ring.

### Producing Method of Third Compound According to First Exemplary Embodiment

The third compound according to the first exemplary embodiment is producible by a known method. Further, the third compound according to the first exemplary embodiment can also be produced based on a known method through a known alternative reaction using a known material(s) tailored for the target compound.

### Specific Examples of Third Compound in First Exemplary Embodiment

Specific examples of the third compound according to the first exemplary embodiment include the following compounds. However, the invention is by no means limited to these specific examples.

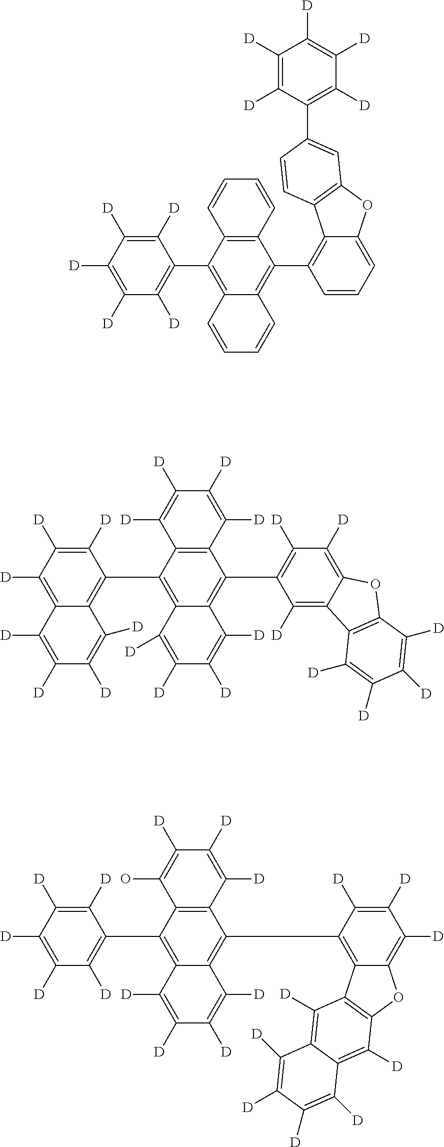 [SMILES: [2H]c1c([2H])c([2H])c(-c2ccc3c(c2)oc2cccc(-c4c5ccccc5c(-c5c([2H])c([2H])c([2H])c([2H])c5[2H])c5ccccc45)c23)c([2H])c1[2H] ; [2H]c1c([2H])c([2H])c2c(oc3c([2H])c([2H])c(-c4c5c([2H])c([2H])c([2H])c([2H])c5c(-c5c([2H])c([2H])c([2H])c6c([2H])c([2H])c([2H])c([2H])c56)c5c([2H])c([2H])c([2H])c([2H])c45)c([2H])c32)c1[2H] ; [2H]c1c([2H])c([2H])c(-c2c3c([2H])c([2H])c([2H])c([2H])c3c(-c3c([2H])c([2H])c([2H])c4oc5c([2H])c6c([2H])c([2H])c([2H])c([2H])c6c([2H])c5c34)c3c([2H])c([2H])c([2H])c(O)c23)c([2H])c1[2H]]

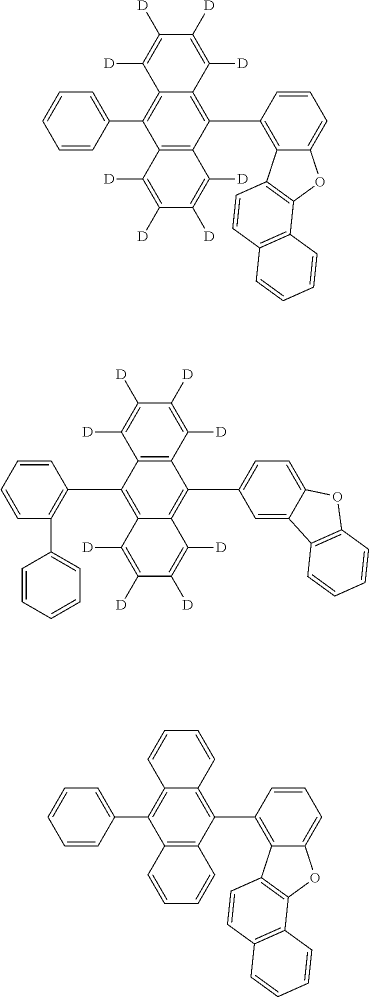 [SMILES: [2H]c1c([2H])c([2H])c2c(-c3cccc4oc5c6ccccc6ccc5c34)c3c([2H])c([2H])c([2H])c([2H])c3c(-c3ccccc3)c2c1[2H] ; [2H]c1c([2H])c([2H])c2c(-c3ccccc3-c3ccccc3)c3c([2H])c([2H])c([2H])c([2H])c3c(-c3ccc4oc5ccccc5c4c3)c2c1[2H] ; c1ccc(-c2c3ccccc3c(-c3cccc4oc5c6ccccc6ccc5c34)c3ccccc23)cc1]

Herein, the “host material” refers to, for instance, a material that accounts for “50 mass % or more of the layer”. Therefore, the emitting layer contains the host material, for instance, at 50 mass % or more with respect to the total mass of the emitting layer. When the organic EL device includes a plurality of emitting layers, each of the emitting layers contains the host material at 50 mass % or more with respect to the total mass thereof. For instance, the “host material” may be contained at 60 mass % or more, 70 mass % or more, 80 mass % or more, 90 mass % or more, 95 mass % or more of the emitting layer. For instance, the “host material” may be contained at 99.5 mass % or less or 99 mass % or less of the emitting layer.

When the emitting layer contains the host material and the dopant material, the upper limit of the total of the content ratios of the host material and the dopant material is 100 mass %.

In an exemplary arrangement of the organic EL device according to the first exemplary embodiment, one or more emitting layers do not contain a metal complex. Moreover, in an exemplary arrangement of the organic EL device according to the first exemplary embodiment, one or more emitting layers do not contain a boron-containing complex.

In an exemplary arrangement of the organic EL device according to the first exemplary embodiment, one or more emitting layers do not contain a phosphorescent material.

In an exemplary arrangement of the organic EL device according to the first exemplary embodiment, one or more emitting layers do not contain a heavy metal complex and a phosphorescent rare-earth metal complex.

In an exemplary arrangement of the organic EL device according to the first exemplary embodiment, one or more emitting layers do not contain a metal complex such as an iridium complex, osmium complex, or platinum complex.

### High Refractive Index Zone and Low Refractive Index Zone

In the organic EL device according to the first exemplary embodiment, of the one or more high refractive index layers in the high refractive index zone, the high refractive index layer in direct contact with the low refractive index zone is a first high refractive index layer. The first high refractive index layer contains the second organic material having the refractive index NM₂.

In the organic EL device according to the first exemplary embodiment, of the one or more low refractive index layers in the low refractive index zone, the low refractive index layer in direct contact with the high refractive index zone is a first low refractive index layer. The first low refractive index layer contains the first organic material having the refractive index NM₁.

In the organic EL device according to the exemplary embodiment, the refractive index NM₁ of the first organic material and the refractive index NM₂ of the second organic material satisfy a relationship of the numerical formula (Numerical Formula N1) below.

$${NM}_{2} > {NM}_{1} \qquad ( Numerical Formula N 1 )$$

In an exemplary arrangement of the organic EL device according to the exemplary embodiment, the refractive index NM₁ of the first organic material and the refractive index NM₂ of the second organic material satisfy a relationship of a numerical formula below (Numerical Formula N2).

$${NM}_{2} - {NM}_{1} > 0.04 \qquad ( Numerical Formula N 2 )$$

In an exemplary arrangement of the organic EL device according to the exemplary embodiment, the refractive index NM₁ of the first organic material and the refractive index NM₂ of the second organic material satisfy a relationship of a numerical formula below (Numerical Formula N3).

$${NM}_{2} - {NM}_{1} > 0.07 \qquad ( Numerical Formula N 3 )$$

In an exemplary arrangement of the organic EL device according to the exemplary embodiment, the refractive index NM₁ of the first organic material and the refractive index NM₂ of the second organic material satisfy a relationship of a numerical formula below (Numerical Formula N4).

$${NM}_{2} - {NM}_{1} > 0.1 \qquad ( Numerical Formula N 4 )$$

In an exemplary arrangement of the organic EL device according to the exemplary embodiment, the refractive index NM₁ of the first organic material and the refractive index NM₂ of the second organic material satisfy a relationship of a numerical formula below (Numerical Formula N5).

$${NM}_{2} - {NM}_{1} > 0.13 \qquad ( Numerical Formula N 5 )$$

In an exemplary arrangement of the organic EL device according to the exemplary embodiment, the refractive index NM₁ of the first organic material and the refractive index NM₂ of the second organic material satisfy a relationship of a numerical formula below (Numerical Formula N6).

$$N {M}_{2} - {NM}_{1} > 0.16 \qquad ( Numerical Formula N 6 )$$

In an exemplary arrangement of the organic EL device according to the exemplary embodiment, the refractive index NM₁ of the first organic material and the refractive index NM₂ of the second organic material satisfy a relationship of a numerical formula below (Numerical Formula N7).

$$N {M}_{2} - {NM}_{1} > 0.18 \qquad ( Numerical Formula N 7 )$$

In an exemplary arrangement of the organic EL device according to the exemplary embodiment, the refractive index NM₁ of the first organic material and the refractive index NM₂ of the second organic material satisfy a relationship of a numerical formula below (Numerical Formula N8).

$$N {M}_{2} - {NM}_{1} > 0.2 \qquad ( Numerical Formula N 8 )$$

In an exemplary arrangement of the organic EL device according to the exemplary embodiment, a total film thickness of the one or more high refractive index layers in the high refractive index zone is smaller than a total film thickness of the one or more low refractive index layers in the low refractive index zone.

In an exemplary arrangement of the organic EL device according to the exemplary embodiment, the total film thickness of the one or more low refractive index layers in the low refractive index zone is 40 nm or more.

In an exemplary arrangement of the organic EL device according to the exemplary embodiment, the total film thickness of the one or more high refractive index layers in the high refractive index zone is 30 nm or less.

### High Refractive Index Layer

In an exemplary arrangement of the organic EL device according to the first exemplary embodiment, one or more high refractive index layers are provided between the first emitting zone and the low refractive index zone.

In an exemplary arrangement of the organic EL device according to the first exemplary embodiment, the one or more high refractive index layers each independently contain an organic material having a refractive index exceeding 1.87.

In an exemplary arrangement of the organic EL device according to the first exemplary embodiment, the respective organic materials having a refractive index exceeding 1.87 of the one or more high refractive index layers may be mutually the same or different in a chemical structure. The organic material having a refractive index exceeding 1.87 is occasionally referred to as a high refractive index organic material.

In the organic EL device according to the first exemplary embodiment, of the one or more high refractive index layers, the high refractive index layer (first high refractive index layer) in direct contact with the low refractive index zone is a layer containing the second organic material. The second organic material is a high refractive index organic material.

In the organic EL device according to the first exemplary embodiment, at least one of the one or more high refractive index layers contains the third organic material and at least one selected from the group consisting of metal and a metal compound. The third organic material is a high refractive index organic material.

The third organic material and the second organic material are mutually the same or different.

In the organic EL device according to the first exemplary embodiment, at least one of the one or more high refractive index layers contains the high refractive index organic material and at least one selected from the group consisting of metal and a metal compound. When the high refractive index zone consists of a single high refractive index layer, the single high refractive index layer is the first high refractive index layer and contains the second organic material (high refractive index organic material) and at least one selected from the group consisting of metal and a metal compound.

In an exemplary arrangement of the organic EL device according to the first exemplary embodiment, the one or more high refractive index layers each independently contain the high refractive index organic material at 50 mass % or more, 60 mass % or more, 70 mass % or more, 80 mass % or more, 90 mass % or more, 95 mass % or more, or 99 mass % or more. In an exemplary arrangement of the organic EL device according to the first exemplary embodiment, the one or more high refractive index layers may contain only the high refractive index organic material.

In an exemplary arrangement of the organic EL device according to the first exemplary embodiment, the refractive index NM₂ of the second organic material (high refractive index organic material) exceeds 1.87.

In an exemplary arrangement of the organic EL device of the first exemplary embodiment, the refractive index NM₂ of the second organic material (high refractive index organic material) is 1.89 or more.

In an exemplary arrangement of the organic EL device of the first exemplary embodiment, the refractive index NM₂ of the second organic material (high refractive index organic material) is 1.90 or more.

In an exemplary arrangement of the organic EL device according to the first exemplary embodiment, at least two high refractive index layers are disposed between the first emitting zone and the low refractive index zone, in which at least two high refractive index layers are in direct contact with each other. Of the at least two high refractive index layers in direct contact, a layer being in direct contact with the low refractive index zone is the first high refractive index layer. The organic EL device in this arrangement is occasionally referred to as an “organic EL device in Arrangement A1.”

In an exemplary arrangement of the organic EL device in Arrangement A1, a total film thickness of the at least two high refractive index layers in direct contact is 20 nm or more, and at least one of the at least two high refractive index layers in direct contact contains the third organic material (high refractive index organic material) and at least one selected from the group consisting of metal and a metal compound.

Hereinafter, “the high refractive index layer containing the high refractive index organic material and at least one selected from the group consisting of metal and a metal compound” is occasionally referred to as a “high refractive index layer containing metal.”

In an exemplary arrangement of the organic EL device in Arrangement A1, the high refractive index layer containing metal may or may not be the first high refractive index layer.

In an exemplary arrangement of the organic EL device in Arrangement A1, the at least two high refractive index layers in direct contact each independently have a film thickness of 22 nm or less, 20 nm or less, 18 nm or less, or 16 nm or less.

In an exemplary arrangement of the organic EL device in Arrangement A1, at least one of the at least two high refractive index layers being direct contact with each other each independently has a film Thickness of 20 nm or less, 15 nm or less, or 10 nm or less.

In an exemplary arrangement of the organic EL device in Arrangement A1, the at least two high refractive index layers in direct contact each independently have a film thickness of 3 nm or more or 5 nm or more.

In an exemplary arrangement of the organic EL device in Arrangement A1, the total film thickness of the at least two high refractive index layers in direct contact is 20 nm or more or 22 nm or more.

In an exemplary arrangement of the organic EL device in Arrangement A1, the total film thickness of the at least two high refractive index layers in direct contact is 60 nm or less, 50 nm or less, 40 nm or less, 35 nm or less, 30 nm or less, or 25 nm or less.

In an exemplary arrangement of the organic EL device according to the first exemplary embodiment, the second high refractive index layer and the first high refractive index layer as two high refractive index layers are disposed in this order from the first emitting zone, between the first emitting zone and the low refractive index zone. The first high refractive index layer is in direct contact with the low refractive index zone. The organic EL device in this arrangement is occasionally referred to as an “organic EL device in Arrangement A2.”

In an exemplary arrangement of the organic EL device in Arrangement A2, the second high refractive index layer is in direct contact with the first high refractive index layer, a total film thickness of the second high refractive index layer and the first high refractive index layer is 20 nm or more, and at least one of the second high refractive index layer or the first high refractive index layer contains metal.

In an exemplary arrangement of the organic EL device according to the first exemplary embodiment, a third high refractive index layer, the second high refractive index layer, and the first high refractive index layer as three high refractive index layers are disposed in this order from the first emitting zone, between the first emitting zone and the low refractive index zone. The first high refractive index layer is in direct contact with the low refractive index zone. The organic EL device in this arrangement is occasionally referred to as an “organic EL device in Arrangement A3.”

In an exemplary arrangement of the organic EL device in Arrangement A3, the third high refractive index layer is in direct contact with the second high refractive index layer, the second high refractive index layer is in direct contact with the first high refractive index layer, a total film thickness of the third high refractive index layer, the second high refractive index layer, and the first high refractive index layer is 20 nm or more, and at least one of the third high refractive index layer, the second high refractive index layer, or the first high refractive index layer contains metal.

In an exemplary arrangement of the organic EL device according to the first exemplary embodiment, a fourth high refractive index layer, the third high refractive index layer, the second high refractive index layer, and the first high refractive index layer as four high refractive index layers are disposed in this order from the first emitting zone, between the first emitting zone and the low refractive index zone. The first high refractive index layer is in direct contact with the low refractive index zone. The organic EL device in this arrangement is occasionally referred to as an “organic EL device in Arrangement A4.”

In an exemplary arrangement of the organic EL device in Arrangement A4, the fourth high refractive index layer is in direct contact with the third high refractive index layer, the third high refractive index layer is in direct contact with the second high refractive index layer, the second high refractive index layer is in direct contact with the second high refractive index layer, the second high refractive index layer is in direct contact with the fourth high refractive index layer, a total film thickness of the fourth high refractive index layer, the third high refractive index layer, the second high refractive index layer, and the first high refractive index layer is 20 nm or more, and at least one of the fourth high refractive index layer, the third high refractive index layer, the second high refractive index layer, or the first high refractive index layer contains metal.

In an exemplary arrangement of the organic EL device in Arrangement A1, the at least two high refractive index layers in direct contact contains mutually different compounds. In an exemplary arrangement of the organic EL device in Arrangement A1, the high refractive index organic materials respectively contained in the at least two high refractive index layers in direct contact are mutually different compounds.

For instance, a case where the organic EL device includes the first high refractive index layer and the second high refractive index layer as two high refractive index layers, the first high refractive index layer containing a single compound AA, the second high refractive index layer containing a single compound BB, corresponds to a case where at least two high refractive index layers (first and second high refractive index layers) in direct contact contain mutually different compounds.

A case where the organic EL device includes the first high refractive index layer and the second high refractive index layer as two high refractive index layers, the first high refractive index layer containing two compounds AA and AB, the second high refractive index layer containing a single compound BB, corresponds to a case where at least two high refractive index layers (first and second high refractive index layers) in direct contact contain mutually different compounds, since the compounds AA and AB are different from the compound BB. The compounds AA, AB, and BB are mutually different compounds.

However, a case where the organic EL device includes the first high refractive index layer and the second high refractive index layer as two high refractive index layers, the first high refractive index layer containing two compounds AA and AB, the second high refractive index layer containing a single compound AA, does not correspond to a case where the two high refractive index layers (first and second high refractive index layers) in direct contact contain mutually different compounds, since the first and second high refractive index layers contain the same compound AA.

The same as the above applies to a case where the organic EL device includes three or more high refractive index layers and a case where the organic EL device includes two or more low refractive index layers, regarding whether the refractive index layers of each case contain mutually different compounds or the same compound.

In an exemplary arrangement of the organic EL device according to the first exemplary embodiment, at least one high refractive index layer having a film thickness of 20 nm or more is disposed between the first emitting zone and the low refractive index zone, and the high refractive index layer having a film thickness of 20 nm or more is in direct contact with the low refractive index zone. That is, the high refractive index layer having a film thickness of 20 nm or more is the first high refractive index layer and contains metal. The organic EL device in this arrangement is occasionally referred to as an “organic EL device in Arrangement B1.”

In an exemplary arrangement of the organic EL device in Arrangement B1, a single high refractive index layer having a film thickness of 20 nm or more is provided as the first high refractive index layer between the first emitting zone and the low refractive index zone.

In an exemplary arrangement of the organic EL device in Arrangement B1, a total film thickness of the single high refractive index layer (first high refractive index layer) is 20 nm or more or 22 nm or more.

In an exemplary arrangement of the organic EL device in Arrangement B1, a film thickness of the single high refractive index layer (first high refractive index layer) is 40 nm or less, 35 nm or less, 30 nm or less, or 25 nm or less.

In an exemplary arrangement of the organic EL device in Arrangement A1, A2, A3, A4 or B1, the high refractive index layer may be or may not be in direct contact with the first emitting zone.

### Low Refractive Index Layer

In an exemplary arrangement of the organic EL device according to the first exemplary embodiment, one or more low refractive index layers are provided between the high refractive index zone and the second emitting zone.

In an exemplary arrangement of the organic EL device according to the first exemplary embodiment, the one or more high refractive index layers each independently contain an organic material having a refractive index of 1.87 or less.

In an exemplary arrangement of the organic EL device according to the first exemplary embodiment, the organic materials each having a refractive index of 1.87 or less of the one or more high refractive index layers may be mutually the same or different in a chemical structure. The organic material having a refractive index of 1.87 or less is occasionally referred to as a low refractive index organic material.

In the organic EL device according to the first exemplary embodiment, of the one or more low refractive index layers, the low refractive index layer (first low refractive index layer) in direct contact with the high refractive index zone contains the first organic material. The first organic material is a low refractive index organic material.

In an exemplary arrangement of the organic EL device according to the first exemplary embodiment, at least one of the one or more low refractive index layers contains the low refractive index organic material and at least one selected from the group consisting of metal and a metal compound.

The first low refractive index layer may contain only the first organic material (low refractive index organic material) or may contain the first organic material (low refractive index organic material) and at least one selected from the group consisting of metal and a metal compound.

In an exemplary arrangement of the organic EL device according to the first exemplary embodiment, the one or more low refractive index layers each independently contain the low refractive index organic material at 50 mass % or more, 60 mass % or more, 70 mass % or more, 80 mass % or more, 90 mass % or more, 95 mass % or more, or 99 mass % or more. In an exemplary arrangement of the organic EL device according to the first exemplary embodiment, the one or more low refractive index layers may contain only the low refractive index organic material.

In an exemplary arrangement of the organic EL device of the first exemplary embodiment, the refractive index NM₁ of the first organic material is 1.87 or less.

In an exemplary arrangement of the organic EL device of the first exemplary embodiment, the refractive index NM₁ of the first organic material is 1.83 or less.

In an exemplary arrangement of the organic EL device of the first exemplary embodiment, the refractive index NM₁ of the first organic material is 1.79 or less.

In an exemplary arrangement of the organic EL device of the first exemplary embodiment, the refractive index NM₁ of the first organic material is 1.75 or less.

In an exemplary arrangement of the organic EL device of the first exemplary embodiment, the refractive index NM₁ of the first organic material is 1.71 or less.

In an exemplary arrangement of the organic EL device of the first exemplary embodiment, the refractive index NM₁ of the first organic material is 1.69 or less.

In an exemplary arrangement of the organic EL device according to the first exemplary embodiment, at least two low refractive index layers are disposed between the high refractive index zone and the second emitting zone, in which at least two low refractive index layers are in direct contact with each other. Of the at least two low refractive index layers in direct contact, a layer being in direct contact with the high refractive index zone is the first low refractive index layer. The organic EL device in this arrangement is occasionally referred to as an “organic EL device in Arrangement C1.”

In an exemplary arrangement of the organic EL device in Arrangement C1, at least one of the at least two low refractive index layers contains the low refractive index organic material and at least one selected from the group consisting of metal and a metal compound.

Hereinafter, “the low refractive index layer containing the low refractive index organic material and at least one selected from the group consisting of metal and a metal compound” is occasionally referred to as a “low refractive index layer containing metal.”

In an exemplary arrangement of the organic EL device in Arrangement C1, the low refractive index layer containing metal may be or may not be the first low refractive index layer.

In an exemplary arrangement of the organic EL device in Arrangement C1, the at least two low refractive index layers in direct contact each independently have a film thickness of 50 nm or less or 45 nm or less.

In an exemplary arrangement of the organic EL device in Arrangement C1, at least one of the at least two low refractive index layers in direct contact each independently has a film thickness of 30 nm or less, 25 nm or less, 20 nm or less, or 15 nm or less.

In an exemplary arrangement of the organic EL device in Arrangement C1, the at least two low refractive index layers in direct contact each independently have a film thickness of 3 nm or more or 5 nm or more.

In an exemplary arrangement of the organic EL device in Arrangement C1, a total film thickness of the at least two low refractive index layers in direct contact is 40 nm or more, or 45 nm or more, or 50 nm or more.

In an exemplary arrangement of the organic EL device in Arrangement C1, the total film thickness of the at least two low refractive index layers in direct contact is 80 nm or less, 70 nm or less, or 60 nm or less.

In an exemplary arrangement of the organic EL device according to the first exemplary embodiment, the second low refractive index layer and the first low refractive index layer as two low refractive index layers are disposed in this order from the second emitting zone, between the high refractive index zone and the second emitting zone. The first low refractive index layer is in direct contact with the high refractive index zone. The organic EL device in this arrangement is occasionally referred to as an “organic EL device in Arrangement C2.”

In an exemplary arrangement of the organic EL device in Arrangement C2, the second low refractive index layer and the first low refractive index layer are in direct contact with each other.

In an exemplary arrangement of the organic EL device in Arrangement C2, at least one of the second low refractive index layer and the first low refractive index layer contains metal.

In an exemplary arrangement of the organic EL device in Arrangement C2, neither the second low refractive index layer nor the first low refractive index layer contain metal

In an exemplary arrangement of the organic EL device according to the first exemplary embodiment, the third low refractive index layer, the second low refractive index layer and the first low refractive index layer as three low refractive index layers are disposed in this order from the first emitting zone, between the high refractive index zone and the second emitting zone. The first low refractive index layer is in direct contact with the high refractive index zone. The organic EL device in this arrangement is occasionally referred to as an “organic EL device in Arrangement C3.”

In an exemplary arrangement of the organic EL device in Arrangement C3, the third low refractive index layer and the second low refractive index layer are in direct contact with each other, and the second low refractive index layer and the first low refractive index layer are in direct contact with each other.

In an exemplary arrangement of the organic EL device in Arrangement C3, at least one of the third high refractive index layer, the second high refractive index layer, or the first high refractive index layer contains metal.

In an exemplary arrangement of the organic EL device in Arrangement C3, none of the third high refractive index layer, the second high refractive index layer, and the first high refractive index layer contains metal.

In an exemplary arrangement of the organic EL device according to the first exemplary embodiment, the fourth low refractive index layer, the third low refractive index layer, the second low refractive index layer, and the first low refractive index layer as four low refractive index layers are disposed in this order from the first emitting zone, between the high refractive index zone and the second emitting zone. The first low refractive index layer is in direct contact with the high refractive index zone. The organic EL device in this arrangement is occasionally referred to as an “organic EL device in Arrangement C4.”

In an exemplary arrangement of the organic EL device in Arrangement C4, the fourth low refractive index layer and the third low refractive index layer are in direct contact with each other, the third low refractive index layer and the second low refractive index layer are in direct contact with each other, the second low refractive index layer and the second low refractive index layer are in direct contact with each other, and the second low refractive index layer and the fourth low refractive index layer are in direct contact with each other.

In an exemplary arrangement of the organic EL device in Arrangement C4, at least one of the fourth low refractive index layer, the third high refractive index layer, the second high refractive index layer, or the first high refractive index layer contains metal.

In an exemplary arrangement of the organic EL device in Arrangement C4, none of the third high refractive index layer, the second high refractive index layer, and the first high refractive index layer contains metal.

In an exemplary arrangement of the organic EL device in Arrangement C1, the at least two low refractive index layers in direct contact contain mutually different compounds. In an exemplary arrangement of the organic EL device in Arrangement C1, the low refractive index organic materials respectively contained in the at least two low refractive index layers in direct contact are different compounds.

In an exemplary arrangement of the organic EL device according to the first exemplary embodiment, at least one low refractive index layer is provided between the high refractive index zone and the second emitting zone. The at least one low refractive index layer is the first low refractive index layer and is in direct contact with the high refractive index zone. The organic EL device in this arrangement is occasionally referred to as an “organic EL device in Arrangement D1.”

In an exemplary arrangement of the organic EL device in Arrangement D1, a single low refractive index layer is disposed between the high refractive index zone and the second emitting zone.

In an exemplary arrangement of the organic EL device in Arrangement D1, the first low refractive index layer contains only the first organic material.

In an exemplary arrangement of the organic EL device in Arrangement D1, the first low refractive index layer contains metal.

In an exemplary arrangement of the organic EL device in Arrangement D1, a film thickness of the single low refractive index layer (first low refractive index layer) is 30 nm or more, 40 nm or more, 45 nm or more, or 50 nm or more.

In an exemplary arrangement of the organic EL device in Arrangement D1, a film thickness of the single low refractive index layer (first low refractive index layer) is 80 nm or less, 70 nm or less, or 60 nm or less.

In an exemplary arrangement of the organic EL device in Arrangement C1, C2, C3, C4, or D1, the low refractive index layer may be or may not be in direct contact with the second emitting zone.

In an exemplary arrangement of the organic EL device according to the first exemplary embodiment, the high refractive index zone in any one of Arrangements A1, A2, A3, A4, B1 and the high refractive index zone in any one of Arrangements C1, C2, C3, C4, and D1 are disposed between an emitting layer of an emitting zone in an emitting unit and an emitting layer of an emitting zone in another emitting unit.

### Charge Generating Zone

In an exemplary arrangement of the organic EL device according to the first exemplary embodiment, a charge generating zone is preferably disposed each between two or more emitting units.

In an exemplary arrangement of the organic EL device according to the first exemplary embodiment, each charge generating zone preferably independently includes at least one charge generating layer. The charge generating layer, which generates holes and electrons upon application of voltage to the organic EL device, supplies electrons to a layer disposed closer to the anode than the charge generating layer and supplies holes to a layer disposed closer to the cathode than the charge generating layer. The charge generating layer is occasionally referred to as an intermediate layer, intermediate electrode, intermediate conductive layer, electron extraction layer, connecting layer, or intermediate insulating layer.

When the charge generating zone includes a plurality of charge generating layers, the charge generating zone preferably includes an N-type charge generating layer disposed close to the anode and through which electrons are injected into the first emitting unit, and a P-type charge generating layer disposed close to the cathode and through which holes are injected into the second emitting unit.

In an exemplary arrangement of the organic EL device of the first exemplary embodiment, one of the N-type charge generating layer and the P-type charge generating layer may be a first charge generating layer. In an exemplary arrangement of the organic EL device according to the first exemplary embodiment, the N-type charge generating layer may be the first charge generating layer and the P-type charge generating layer may be a second charge generating layer.

In an exemplary arrangement of the organic EL device according to the first exemplary embodiment, examples of a material usable for the charge generating layer of the charge generating zone include a known material(s) usable for the charge generating layer in the tandem organic EL device.

In an exemplary arrangement of the organic EL device according to the first exemplary embodiment, at least one charge generating zone includes two or more charge generating layers.

In an exemplary arrangement of the organic EL device according to the first exemplary embodiment, the first charge generating zone is disposed between the first emitting unit and the second emitting unit.

In an exemplary arrangement of the organic EL device according to the first exemplary embodiment, the first emitting zone at least includes the first charge generating layer.

In an exemplary arrangement of the organic EL device according to the first exemplary embodiment, when the first emitting unit, the second emitting unit, and the third emitting unit are disposed in this order toward the cathode from the anode, a second charge generating zone is disposed between the second emitting unit and the third emitting unit.

In an exemplary arrangement of the organic EL device according to the first exemplary embodiment, when the third emitting unit, the first emitting unit, and the second emitting unit are disposed in this order toward the cathode from the anode, the second charge generating zone is disposed between the third emitting unit and the first emitting unit.

In an exemplary arrangement of the organic EL device according to the first exemplary embodiment, when the first emitting unit, the second emitting unit, the third emitting unit, and the fourth emitting unit are disposed toward the cathode from the anode, the first charge generating zone is disposed between the first emitting unit and the second emitting unit, the second charge generating zone is disposed between the second emitting unit and the third emitting unit, and a third charge generating zone is provided between the third emitting unit and the fourth emitting unit.

In an exemplary arrangement of the organic EL device according to the first exemplary embodiment, the first charge generating zone is disposed between the first emitting unit and the second emitting unit, the first charge generating zone at least includes the first charge generating layer, and the first charge generating layer is the first high refractive index layer.

In an exemplary arrangement of the organic EL device in Arrangement A1, one of the at least two high refractive index layers in direct contact is the first charge generating layer and the first charge generating layer is the first high refractive index layer.

In an exemplary arrangement of the organic EL device in Arrangement B1, the first charge generating layer is a high refractive index layer (first high refractive index layer) having a film thickness of 20 nm or more.

In an exemplary arrangement of the organic EL device according to the first exemplary embodiment, the first charge generating zone is disposed between the first emitting unit and the second emitting unit, the first charge generating zone at least includes the first charge generating layer, a first electron transporting zone is disposed between the first emitting zone and the first charge generating layer, and the first electron transporting zone includes one or more layers.

In an exemplary arrangement of the organic EL device of the first exemplary embodiment, each of the one or more layers included in the first electron transporting zone is a high refractive index layer.

In an exemplary arrangement of the organic EL device according to the first exemplary embodiment, the first electron transporting zone includes a first electron transporting layer, and the first charge generating layer is in direct contact with the first electron transporting layer. In an exemplary arrangement of the organic EL device according to the first exemplary embodiment, the first charge generating layer may not be in direct contact with the first electron transporting layer. The first electron transporting layer may be a hole blocking layer.

In an exemplary arrangement of the organic EL device of the first exemplary embodiment, the first electron transporting layer is the high refractive index layer described above.

In an exemplary arrangement of the organic EL device according to the first exemplary embodiment, the first electron transporting layer contains a first electron transporting zone material.

In an exemplary arrangement of the organic EL device of the first exemplary embodiment, an organic material (high refractive index organic material) contained in the first electron transporting layer is the first electron transporting zone material.

In an exemplary arrangement of the organic EL device of the first exemplary embodiment, a total film thickness of the first electron transporting layer and the first charge generating layer is 20 nm or more.

In an exemplary arrangement of the organic EL device in Arrangement A1, the at least two high refractive index layers in direct contact are the first electron transporting layer and the first charge generating layer, the first charge generating layer is the first high refractive index layer, and the total film thickness of the first electron transporting layer and the first charge generating layer is 20 nm or more or 22 nm or more. The total film thickness of the first electron transporting layer and the first charge generating layer is 40 nm or less, 35 nm or less, 30 nm or less, or 25 nm or less.

In an exemplary arrangement of the organic EL device according to the first exemplary embodiment, the first electron transporting zone further includes a first hole blocking layer between the first electron transporting layer and the first emitting zone.

In an exemplary arrangement of the organic EL device according to the first exemplary embodiment, the first electron transporting zone includes the first hole blocking layer and the first electron transporting layer in this order from the first emitting zone.

In an exemplary arrangement of the organic EL device according to the first exemplary embodiment, the first electron transporting zone further includes the first hole blocking layer between the first electron transporting layer and the first emitting layer.

In an exemplary arrangement of the organic EL device according to the first exemplary embodiment, the first emitting layer and the first hole blocking layer are in direct contact with each other.

In an exemplary arrangement of the organic EL device according to the exemplary embodiment, the first electron transporting layer and the first hole blocking layer are in direct contact with each other.

In an exemplary arrangement of the organic EL device of the first exemplary embodiment, the first hole blocking layer is the high refractive index layer.

In an exemplary arrangement of the organic EL device in Arrangement A1, one of the at least two high refractive index layers in direct contact is the first hole blocking layer.

In an exemplary arrangement of the organic EL device according to the first exemplary embodiment, the first hole blocking layer contains the first electron transporting zone material. The first electron transporting zone material contained in the first hole blocking layer and the first electron transporting zone material contained in the first electron transporting layer may be mutually the same compound or different compounds.

In an exemplary arrangement of the organic EL device of the first exemplary embodiment, an organic material (high refractive index organic material) contained in the first hole blocking layer is the first electron transporting zone material.

In an exemplary arrangement of the organic EL device in Arrangement A3, three high refractive index layers in direct contact are the first hole blocking layer, the first electron transporting layer, and the first charge generating layer, the first charge generating layer is the first high refractive index layer, the first electron transporting layer is the second high refractive index layer, the first hole blocking layer is the third high refractive index layer, and a total film thickness of the first hole blocking layer, the first electron transporting layer, and the first charge generating layer is 20 nm or more or 22 nm or more. The total film thickness of the first hole blocking layer, the first electron transporting layer, and the first charge generating layer is 60 nm or less, 50 nm or less, 40 nm or less, 35 nm or less, 30 nm or less, or 25 nm or less.

In an exemplary arrangement of the organic EL device of the first exemplary embodiment, an organic material (high refractive index organic material) contained in the first charge generating layer is occasionally referred to as a first charge generating zone material.

In an exemplary arrangement of the organic EL device according to the first exemplary embodiment, the first charge generating zone material is a later-described electron transporting zone material (preferably, the first electron transporting zone material).

In an exemplary arrangement of the organic EL device according to the first exemplary embodiment, the first charge generating zone material contained in the first charge generating layer and the electron transporting zone material contained in a layer (e.g., the first electron transporting layer and the first hole blocking layer) in the electron transporting zone are mutually different compounds or the same compound.

In an exemplary arrangement of the organic EL device according to the first exemplary embodiment, the first charge generating zone further includes the second charge generating layer.

In an exemplary arrangement of the organic EL device according to the first exemplary embodiment, the second charge generating layer is disposed between the first charge generating layer and the second emitting zone.

In an exemplary arrangement of the organic EL device according to the first exemplary embodiment, the first charge generating zone includes the first charge generating layer and the second charge generating layer in this order from the first emitting unit.

In an exemplary arrangement of the organic EL device according to the first exemplary embodiment, the first charge generating layer is the first high refractive index layer described above and the second charge generating layer is the first low refractive index layer described above. The first charge generating layer is the above-described high refractive index layer containing metal.

In an exemplary arrangement of the organic EL device according to the first exemplary embodiment, the first charge generating zone further includes the second charge generating layer, and the second charge generating layer is disposed between the first charge generating layer and the second emitting zone. In this arrangement, the first charge generating layer and the second charge generating layer are preferably in direct contact with each other.

In an exemplary arrangement of the organic EL device of the first exemplary embodiment, an organic material (low refractive index organic material) contained in the second charge generating layer is occasionally referred to as a second charge generating zone material.

In an exemplary arrangement of the organic EL device according to the first exemplary embodiment, the first charge generating zone material and the second charge generating zone material are mutually different.

In an exemplary arrangement of the organic EL device of the first exemplary embodiment, a refractive index of the second charge generating zone material is 1.87 or less, 1.83 or less, 1.79 or less, 1.75 or less, 1.71 or less, or 1.69 or less.

In an exemplary arrangement of the organic EL device of the first exemplary embodiment, a refractive index of the first charge generating zone material is more than 1.87, 1.89 or more, or 1.90 or more.

In an exemplary arrangement of the organic EL device according to the first exemplary embodiment, the refractive index of the first charge generating zone material is more than 1.87 and the refractive index of the second charge generating zone material is 1.87 or less.

In an exemplary arrangement of the organic EL device according to the first exemplary embodiment, the second charge generating layer contains the second charge generating zone material and a later-described acceptor material.

In an exemplary arrangement of the organic EL device according to the first exemplary embodiment, a content of the acceptor material in the second charge generating layer is less than 50 mass %.

In an exemplary arrangement of the organic EL device according to the first exemplary embodiment, the content of the acceptor material in the second charge generating layer is 10 mass % or less or 5 mass % or less.

In an exemplary arrangement of the organic EL device according to the first exemplary embodiment, the content of the acceptor material in the second charge generating layer is 1 mass % or more or 3 mass % or less.

In an exemplary arrangement of the organic EL device according to the first exemplary embodiment, when the second charge generating layer contains the second charge generating zone material and the acceptor material, a content of the second charge generating zone material in the second charge generating layer is 40 mass % or more, 45 mass % or more, 50 mass % or more, 80 mass % or more, 90 mass % or more, or 95 mass % or more.

In an exemplary arrangement of the organic EL device according to the first exemplary embodiment, the content of the second charge generating zone material in the second charge generating layer is 99.5 mass % or less, 99 mass % or less, or 97 mass % or less. A total content of the acceptor material and the second charge generating zone material in the second charge generating layer is 100 mass % or less.

In an exemplary arrangement of the organic EL device according to the first exemplary embodiment, the second charge generating zone material is a later-described hole transporting zone material (preferably, a second hole transporting zone material).

In an exemplary arrangement of the organic EL device according to the first exemplary embodiment, the second charge generating zone material contained in the second charge generating layer and the hole transporting zone material contained in a layer (e.g., the second hole transporting layer) in the hole transporting zone are mutually the same compound or different compounds.

### Electron Transporting Zone

In an exemplary arrangement of the organic EL device according to the first exemplary embodiment, two or more emitting units each independently include an electron transporting zone.

In the exemplary arrangement of the organic EL device according to the first exemplary embodiment, a first emitting unit includes a first electron transporting zone and a second emitting unit includes a second electron transporting zone.

### First Electron Transporting Zone

In an exemplary arrangement of the organic EL device according to the first exemplary embodiment, the first electron transporting zone is disposed between the first emitting zone and the second emitting unit.

In an exemplary arrangement of the organic EL device according to the first exemplary embodiment, the first electron transporting zone is disposed between the first emitting zone and the first charge generating zone.

In an exemplary arrangement of the organic EL device according to the first exemplary embodiment, the first electron transporting zone is disposed between the first emitting zone and the first charge generating layer.

In an exemplary arrangement of the organic EL device according to the first exemplary embodiment, the first electron transporting zone includes one or more layers. In an exemplary arrangement of the organic EL device according to the first exemplary embodiment, the first electron transporting zone includes the first electron transporting layer.

In an exemplary arrangement of the organic EL device according to the first exemplary embodiment, the first emitting layer and the first electron transporting layer are in direct contact with each other.

In an exemplary arrangement of the organic EL device according to the first exemplary embodiment, the first electron transporting zone includes two or more layers. In an exemplary arrangement of the organic EL device according to the first exemplary embodiment, the first electron transporting zone includes the first hole blocking layer and the first electron transporting layer. In an exemplary arrangement of the organic EL device according to the first exemplary embodiment, the first electron transporting zone includes the first hole blocking layer and the first electron transporting layer in this order from the first emitting zone.

In an exemplary arrangement of the organic EL device according to the first exemplary embodiment, the first electron transporting layer contains the first electron transporting zone material.

In an exemplary arrangement of the organic EL device according to the first exemplary embodiment, an organic material (high refractive index organic material) contained in the first electron transporting layer is the first electron transporting zone material.

In an exemplary arrangement of the organic EL device according to the first exemplary embodiment, triplet energy T₁(H1) of the first host material and triplet energy T₁(E1) of the first electron transporting zone material satisfy a relationship of a numerical formula (Numerical Formula 1) below.

$${T}_{1} ( E 1 ) > {T}_{1} ( H 1 ) \qquad ( Numerical Formula 1 )$$

In an exemplary arrangement of the organic EL device according to the first exemplary embodiment, when the first electron transporting zone includes the first electron transporting layer, the triplet energy T₁(H1) of the first host material and the triplet energy T₁(E_{ET}1) of the first electron transporting zone material contained in the first electron transporting layer satisfy a relationship of a numerical formula (Numerical Formula 1A) below.

$${T}_{1} ( {E}_{ET} 1 ) > {T}_{1} ( H 1 ) \qquad ( Numerical Formula 1 A )$$

In an exemplary arrangement of the organic EL device according to the first exemplary embodiment, when the first electron transporting zone includes the first hole blocking layer, the triplet energy of the first host material T₁(H1) and the triplet energy of the first electron transporting zone material contained in the first hole blocking layer T₁(E_{HB}1) satisfy a relationship of a numerical formula (Numerical Formula 1B) below.

$${T}_{1} ( {E}_{HB} 1 ) > {T}_{1} ( H 1 ) \qquad ( Numerical Formula 1 B )$$

In an exemplary arrangement of the organic EL device according to the first exemplary embodiment, both the relationship of the numerical formula (Numerical Formula 1A) and the relationship of the numerical formula (Numerical Formula 1B) are satisfied.

By satisfying the numerical formula (Numerical Formula 1, Numerical Formula 1A, or Numerical Formula 1B), diffusion of triplet excitons into the first electron transporting zone and the first charge generating zone is suppressed, and triplet excitons of the host material in the emitting layer are efficiently converted into singlet excitons, which then move to the dopant material (luminescent compound), resulting in optical energy quenching. Therefore, TTF efficiency in the first emitting layer is improved and an increase in luminous efficiency can be expected.

Conventionally, triplet-triplet annihilation (occasionally referred to as TTA) is known as a technique for enhancing the luminous efficiency of the organic electroluminescence device. TTA is a mechanism in which triplet excitons collide with one another to generate singlet excitons. The TTA mechanism is occasionally also referred to as a TTF mechanism. TTF is an abbreviation of Triplet-Triplet Fusion.

The TTF phenomenon will be described. Holes injected from an anode and electrons injected from a cathode are recombined in an emitting layer to generate excitons. As for the spin state, as is conventionally known, singlet excitons account for 25% and triplet excitons account for 75%. In a conventionally known fluorescent device, light is emitted when singlet excitons of 25% are relaxed to the ground state. The remaining triplet excitons of 75% are returned to the ground state without emitting light through a thermal deactivation process. Accordingly, the theoretical limit value of the internal quantum efficiency of the conventional fluorescent device is believed to be 25%.

The behavior of triplet excitons generated within an organic substance has been theoretically examined. According to S. M. Bachilo et al. (J. Phys. Chem. A, 104, 7711 (2000)), assuming that high-order excitons such as quintet excitons are quickly returned to triplet excitons, triplet excitons (hereinafter abbreviated as ³A*) collide with one another with an increase in density thereof, whereby a reaction shown by the following formula occurs. In the formula, ¹A represents the ground state and ¹A* represents the lowest singlet excitons.

$${}^{3} {A}^{*} + {}^{3} {A}^{*} \to {( 4 / 9 )}^{1} A + {( 1 / 9 )}^{1} {A}^{*} + ( 13 / 9 ) {}^{3} {A}^{*}$$

In other words, 5³A*→4¹A+1A* is satisfied, and it is expected that, among triplet excitons initially generated, which account for 75%, one fifth thereof (i.e., 20%) is changed to singlet excitons. Accordingly, the amount of singlet excitons which contribute to emission is 40%, which is a value obtained by adding 15% (75%×(⅕)=15%) to 25%, which is the amount ratio of initially generated singlet excitons. At this time, a ratio of luminous intensity derived from TTF (TTF ratio) relative to the total luminous intensity is 15/40, i.e., 37.5%. Assuming that singlet excitons are generated by collision of initially generated triplet excitons accounting for 75% (i.e., one singlet exciton is generated from two triplet excitons), a significantly high internal quantum efficiency of 62.5% is obtained, which is a value obtained by adding 37.5% (75%×(½)=37.5%) to 25% (the amount ratio of initially generated singlet excitons). At this time, the TTF ratio is 37.5/62.5=60%.

### Triplet Energy T₁

A method of measuring a triplet energy T₁ is exemplified by a method below.

A measurement target compound is dissolved in EPA (diethylether:isopentane:ethanol=5:5:2 in volume ratio) so as to fall within a range from 10⁻⁵ mol/L to 10⁻⁴ mol/L to prepare a solution, and the obtained solution is encapsulated in a quartz cell to provide a measurement sample. A phosphorescence spectrum (ordinate axis: phosphorescent luminous intensity, abscissa axis: wavelength) of the measurement sample is measured at a low temperature (77K). A tangent is drawn to the rise of the phosphorescence spectrum close to the short-wavelength region. An energy amount is calculated by a conversion equation (F1) below on a basis of a wavelength value λ_{edge} [nm] at an intersection of the tangent and the abscissa axis. The calculated energy amount is defined as triplet energy T₁.

$$Conversion Equation ( F 1 ) : {T}_{1} [ eV ] = 1239 \text{.85} / {λ}_{e d g e}$$

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 (manufactured by Hitachi High-Technologies Corporation) is usable. Any device for phosphorescence measurement is usable. A combination of a cooling unit, a low temperature container, an excitation light source and a light-receiving unit may be used for phosphorescence measurement.

In an exemplary arrangement of the organic EL device of the first exemplary embodiment, a refractive index of the first charge generating zone material is more than 1.87, 1.89 or more, or 1.90 or more.

In an exemplary arrangement of the organic EL device according to the first exemplary embodiment, the refractive index of the first electron transporting zone material is more than 1.87 and the refractive index of the organic material (first charge generating zone material) contained in the first charge generating layer is more than 1.87.

In an exemplary arrangement of the organic EL device according to the first exemplary embodiment, the first electron transporting zone material and the first charge generating zone material are mutually different.

In an exemplary arrangement of the organic EL device according to the first exemplary embodiment, the first electron transporting zone material and the second charge generating zone material are mutually different.

In an exemplary arrangement of the organic EL device according to the first exemplary embodiment, the first electron transporting zone material is a high refractive index organic material, the first charge generating zone material is a high refractive index organic material, and the second charge generating zone material is a low refractive index organic material.

In an exemplary arrangement of the organic EL device according to the first exemplary embodiment, the refractive index of the first electron transporting zone material is larger than the refractive index of the first charge generating zone material.

### Second Electron Transporting Zone

In an exemplary arrangement of the organic EL device according to the first exemplary embodiment, the second electron transporting zone is disposed between the second emitting zone and the cathode.

In an exemplary arrangement of the organic EL device according to the first exemplary embodiment, the second electron transporting zone includes one or more layers. In an exemplary arrangement of the organic EL device according to the first exemplary embodiment, the second electron transporting zone includes a second electron transporting layer.

In an exemplary arrangement of the organic EL device according to the first exemplary embodiment, the second electron transporting zone includes two or more layers. In an exemplary arrangement of the organic EL device according to the first exemplary embodiment, the second electron transporting zone includes the second electron transporting layer and a second electron injecting layer.

In an exemplary arrangement of the organic EL device according to the first exemplary embodiment, the second electron transporting layer is in direct contact with the second emitting layer in the second emitting zone.

In an exemplary arrangement of the organic EL device according to the first exemplary embodiment, the second electron transporting zone includes three or more layers.

In an exemplary arrangement of the organic EL device according to the first exemplary embodiment, the second electron transporting zone includes three layers, namely, the second hole blocking layer, the second electron transporting layer, and the second electron injecting layer.

In an exemplary arrangement of the organic EL device according to the first exemplary embodiment, the second electron transporting zone includes the second hole blocking layer, the second electron transporting layer, and the second electron injecting layer in this order from the second emitting zone.

In an exemplary arrangement of the organic EL device according to the first exemplary embodiment, the second hole blocking layer is in direct contact with the second emitting layer in the second emitting zone.

In an exemplary arrangement of the organic EL device according to the first exemplary embodiment, the second hole blocking layer and the second electron transporting layer are in direct contact with each other.

In an exemplary arrangement of the organic EL device according to the first exemplary embodiment, the second electron transporting layer and the second electron injecting layer are in direct contact with each other.

In an exemplary arrangement of the organic EL device according to the exemplary embodiment, the second electron injecting layer and the cathode are in direct contact with each other.

In an exemplary arrangement of the organic EL device according to the first exemplary embodiment, the second electron transporting layer contains a second electron transporting zone material.

### High Refractive Index Organic Material

In an exemplary arrangement of the organic EL device according to the first exemplary embodiment, the one or more high refractive index layers each independently contain a high refractive index organic material. In an exemplary arrangement of the organic EL device according to the first exemplary embodiment, the high refractive index organic material contained in each of the one or more high refractive index layers is an organic material having a refractive index exceeding 1.87.

In an exemplary arrangement of the organic EL device of the first exemplary embodiment, the electron transporting zone material is an organic material (high refractive index organic material) having a refractive index exceeding 1.87.

In an exemplary arrangement of the organic EL device of the first exemplary embodiment, the first charge generating zone material is an organic material (high refractive index organic material) having a refractive index exceeding 1.87.

The organic material (high refractive index organic material) having a refractive index exceeding 1.87 is not particularly limited; however, for instance, any organic material having a refractive index exceeding 1.87 (preferably 1.89 or more) can be selected from among known electron transporting zone materials and known charge generating zone materials.

In an exemplary arrangement of the organic EL device of the first exemplary embodiment, the high refractive index organic material is preferably a compound (first electron transporting zone material, second electron transporting zone material, or first charge generating zone material) represented by a later-described formula (E1), (E2), (E3), (E4), (E41), (E42), (E43), (E44), (E5), (E61), (E62), or (E7).

As the high refractive index organic material, the organic material (high refractive index organic material) having a refractive index exceeding 1.87 (preferably 1.89 or more) may be selected for use from among “Compounds Contained in Electron Transporting Layer” described later and “Compounds Contained in Hole Blocking Layer” described later.

### Low Refractive Index Organic Material

In an exemplary arrangement of the organic EL device according to the first exemplary embodiment, the one or more low refractive index layers each independently contain a low refractive index organic material. In an exemplary arrangement of the organic EL device according to the first exemplary embodiment, the low refractive index organic material contained in each of the one or more low refractive index layers is an organic material having a refractive index of 1.87 or less (preferably 1.83 or less).

In an exemplary arrangement of the organic EL device of the first exemplary embodiment, the hole transporting zone material is an organic material (low refractive index organic material) having a refractive index of 1.87 or less.

In an exemplary arrangement of the organic EL device of the first exemplary embodiment, the second charge generating zone material is an organic material (low refractive index organic material) having a refractive index of 1.87 or less.

The organic material (low refractive index organic material) having a refractive index of 1.87 or less is not particularly limited; however, for instance, any organic material having a refractive index of 1.87 or less (preferably 1.83 or less) can be selected from among known hole transporting zone materials and known charge generating zone materials.

In an exemplary arrangement of the organic EL device of the first exemplary embodiment, the low refractive index organic material is preferably a compound (first hole transporting zone material, second hole transporting zone material, or second charge generating zone material) represented by a later-described formula (B1) or (B2).

As the low refractive index organic material, the organic material having a refractive index of 1.87 or less (preferably 1.83 or less) may be selected for use from among “Compounds Contained in Hole Transporting Layer” described later and “Compounds Contained in Electron Blocking Layer” described later.

### Electron Transporting Zone Material

In an exemplary arrangement of the organic EL device according to the first exemplary embodiment, the material contained in the electron transporting zone is referred to as an electron transporting zone material. Examples of the electron transporting zone material include the first electron transporting zone material and the second electron transporting zone material which are described above. The electron transporting zone material is also usable as the first charge generating zone material.

In an exemplary arrangement of the organic EL device according to the first exemplary embodiment, at least one of the layers included in the first electron transporting zone contains, as the first electron transporting zone material, a compound represented by the formula (E1), (E2), (E3), (E4), (E41), (E42), (E43), (E44), (E5), (E61), (E62), or (E7) below.

In an exemplary arrangement of the organic EL device according to the first exemplary embodiment, at least one of the layers included in the second electron transporting zone contains, as the second electron transporting zone material, a compound represented by the formula (E1), (E2), (E3), (E4), (E41), (E42), (E43), (E44), (E5), (E61), (E62), or (E7) below.

In an exemplary arrangement of the organic EL device according to the first exemplary embodiment, the first charge generating layer contains, as the first charge generating zone material, a compound represented by the formula (E1), (E2), (E3), (E4), (E41), (E42), (E43), (E44), (E5), (E61), (E62), or (E7) below.

In an exemplary arrangement of the organic EL device according to the first exemplary embodiment, the electron transporting zone material (first electron transporting zone material or second electron transporting zone material) is a compound represented by the formula (E1) below.

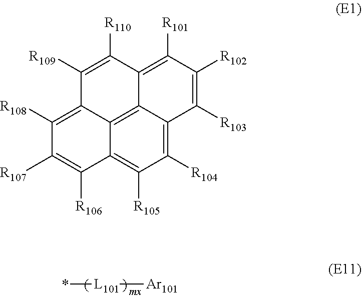

In the formula (E1):
R₁₀₁ to R₁₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (E11);
at least one of R₁₀₁ to R₁₁₀ is a group represented by the formula (E11);
when a plurality of groups represented by the formula (E11) are present, the plurality of groups represented by the formula (E11) are mutually the same or different;
L₁₀₁ is a substituted or unsubstituted arylene group having 6 to 50 ring carbon atoms, or a substituted or unsubstituted divalent heterocyclic group having 5 to 50 ring atoms;
Ar₁₀₁ is a substituted or unsubstituted aryl group having 6 to 50 ring carbon atoms, or a substituted or unsubstituted heterocyclic group having 5 to 50 ring atoms;
mx is 0, 1, 2, 3, 4, or 5, and when mx is 0, -(L₁₀₁)₀- represents a single bond;
when two or more L₁₀₁ are present, the two or more L₁₀₁ are mutually the same or different;
when two or more Ar₁₀₁ are present, the two or more Ar₁₀₁ are mutually the same or different; and
* in the formula (E11) represents a bonding position to a pyrene ring in the formula (E1).

In the formula (E1), R₉₀₁, R₉₀₂, R₉₀₃, R₉₀₄, R₉₀₅, R₈₀₁, and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of Roos are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary arrangement of the organic EL device according to the first exemplary embodiment, the electron transporting zone material (first electron transporting zone material or second electron transporting zone material) is a compound represented by the formula (E2) below.

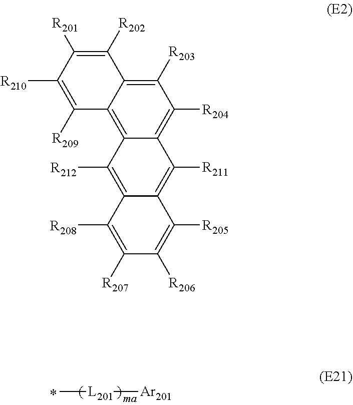

In the formula (E2):
at least one combination of adjacent two or more of R₂₀₁ to R₂₁₂ are mutually bonded to form a substituted or unsubstituted monocyclic ring, mutually bonded to form a substituted or unsubstituted fused ring, or not mutually bonded;
R₂₀₁ to R₂₁₂ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (E21);
at least one of R₂₀₁ to R₂₁₂ forming neither the substituted or unsubstituted monocyclic ring nor the substituted or unsubstituted fused ring is a group represented by the formula (E21) below;
when a plurality of groups represented by the formula (E21) are present, the plurality of groups represented by the formula (E21) are mutually the same or different;
L₂₀₁ is a substituted or unsubstituted arylene group having 6 to 50 ring carbon atoms, or a substituted or unsubstituted divalent heterocyclic group having 5 to 50 ring atoms;
ma is 0, 1, 2, 3, 4, or 5, and when ma is 0, -(L₂₀₁)₀- represents a single bond;
when two or more L₂₀₁ are present, the two or more L₂₀₁ are mutually the same or different;
Ar₂₀₁ is a substituted or unsubstituted aryl group having 6 to 50 ring carbon atoms, or a substituted or unsubstituted heterocyclic group having 5 to 50 ring atoms;
when two or more Ar₂₀₁ are present, the two or more Ar₂₀₁ are mutually the same or different; and
* in the formula (E21) represents a bonding position to a benz[a]anthracene ring in the formula (E2). When at least one combination of adjacent two or more of R₂₀₁ to R₂₁₂ form the substituted or unsubstituted monocyclic ring or the substituted or unsubstituted fused ring, * in the formula (E21) represents a bonding position to a mother skeleton of the formed cyclic structure.

In the formula (E2), R₉₀₁, R₉₀₂, R₉₀₃, R₉₀₄, R₉₀₅, R₈₀₁, and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of Roos are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary arrangement of the organic EL device according to the first exemplary embodiment, the electron transporting zone material (first electron transporting zone material or second electron transporting zone material) is a compound represented by the formula (E3) below.

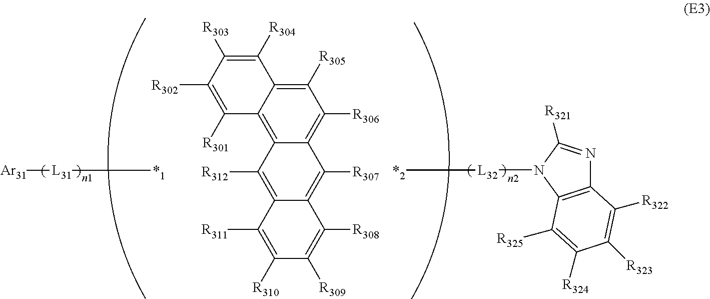

In the formula (E3):
one of R₃₀₇ and R₃₁₂ represents a single bond to *1 and the other of R₃₀₇ and R₃₁₂ represents a single bond to *2;
R₃₀₁ to R₃₀₆, R₃₀₈ to R₃₁₁, and R₃₂₂ to R₃₂₅ are each independently a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a halogen atom, a cyano group, a nitro group, a substituted or unsubstituted aryl group having 6 to 50 ring carbon atoms, or a substituted or unsubstituted heterocyclic group having 5 to 50 ring atoms;
R₃₂₁ is a substituted or unsubstituted alkyl group having 1 to 6 carbon atoms, or a substituted or unsubstituted cycloalkyl group having 3 to 10 ring carbon atoms, and
Ar₃₁ is a hydrogen atom, a substituted or unsubstituted aryl group having 6 to 18 ring carbon atoms, a substituted or unsubstituted oxygen-containing heterocyclic group having 5 to 18 ring atoms, or a substituted or unsubstituted sulfur-containing heterocyclic group having 5 to 18 ring atoms;
L₃₁ and L₃₂ are each independently a substituted or unsubstituted arylene group having 6 to 14 ring carbon atoms, or a substituted or unsubstituted divalent heterocyclic group having 5 to 14 ring atoms;
n1 is 0, 1, 2, or 3;
n2 is 0, 1, 2, or 3;
when n1 is 0, -(L₃₁)₀- represents a single bond;
when n1 is 2 or more, two or more L₃₁ are connected in series with each other; and
when n2 is 2 or more, two or more L₃₁ are mutually the same or different;
when n2 is 0, -(L₃₂)₀- represents a single bond;
when n2 is 2 or more, two or more L₃₂ are connected in series with each other; and
when n2 is 2 or more, two or more L₃₂ are mutually the same or different.

In the formula (E3), R₉₀₁, R₉₀₂, R₉₀₃, R₉₀₄, R₉₀₅, R₉₀₆, and R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of Roos are present, the plurality of Roos are mutually the same or different;
when a plurality of R₉₀₄ are present, the plurality of R₉₀₄ are mutually the same or different;
when a plurality of Roos are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In an exemplary arrangement of the organic EL device according to the first exemplary embodiment, the electron transporting zone material (first electron transporting zone material or second electron transporting zone material) is a compound represented by the formula (E4) below.

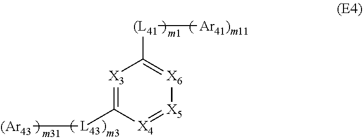

In the formula (E4):
X₂ is N or C-(L₄₂)m₂-(Ar₄₂)m₂₁;
X₄ is N or C-(L₄₄)m₄-(Ar₄₄)m₄₁;
X₅ is N or C-(L₄₅)m₅-(Ar₄₅)m₅₁;
X₆ is N or C-(L₄₆)m₆-(Ar₄₆)m₆₁;
at least one of X₂, X₄, X₅, or X₆ is a nitrogen atom;
L₄₁ to L₄₆ are each independently a substituted or unsubstituted arylene group having 6 to 50 ring carbon atoms, or a substituted or unsubstituted divalent heterocyclic group having 5 to 50 ring atoms;
m₁ is 0, 1, 2, or 3, and when m₁ is 0, -(L₄₁)₀- represents a single bond;
m₂ is 0, 1, 2, or 3, and when m₂ is 0, -(L₄₂)₀- represents a single bond;
m₃ is 0, 1, 2, or 3, and when m₃ is 0, -(L₄₃)₀- represents a single bond;
m₄ is 0, 1, 2, or 3, and when m₄ is 0, -(L₄₄)₀- represents a single bond;
m₅ is 0, 1, 2, or 3, and when m₅ is 0, -(L₄₅)₀- represents a single bond;
m₆ is 0, 1, 2, or 3, and when me is 0, -(L₄₆)₀- represents a single bond;
when m₁ is 2 or more, two or more L₄₁ are mutually the same or different;
when m₂ is 2 or more, two or more L₄₂ are mutually the same or different;
when m₃ is 2 or more, two or more L₄₃ are mutually the same or different;
when m₄ is 2 or more, two or more L₄₄ are mutually the same or different;
when m₅ is 2 or more, two or more L₄₅ are mutually the same or different;
when m₆ is 2 or more, two or more L₄₆ are mutually the same or different;
m₁₁ is 1, 2, 3 or 4;
m₂₁ is 1, 2, 3 or 4;
m₃₁ is 1, 2, 3 or 4;
m₄₁ is 1, 2, 3 or 4;
m₅₁ is 1, 2, 3 or 4;
m₆₁ is 1, 2, 3 or 4;
Ar₄₁ to Ar₄₆ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a group represented by —P(═O)(R₉₁₈)(R₉₁₉), a substituted or unsubstituted aralkyl group having 7 to 50 carbon atoms, a group represented by —C(═O)R₉₂₀, a group represented by —COOR₉₂₁, a halogen atom, a cyano group, a nitro group, a substituted or unsubstituted aryl group having 6 to 50 ring carbon atoms, or a substituted or unsubstituted heterocyclic group having 5 to 50 ring atoms;
at least one of Ar₄₁ to Ar₄₆ is a substituted or unsubstituted aryl group having 13 to 50 ring carbon atoms, or a substituted or unsubstituted heterocyclic group having 13 to 50 ring atoms;
when m₁₁ is 2 or more, two or more Ar₄₁ are mutually the same or different;
when m₂₁ is 2 or more, two or more Ar₄₂ are mutually the same or different;
when m₃₁ is 2 or more, two or more Ar₄₃ are mutually the same or different;
when m₄₁ is 2 or more, two or more Ar₄₄ are mutually the same or different;
when m₅₁ is 2 or more, two or more Ar₄₅ are mutually the same or different; and
when m₆₁ is 2 or more, two or more Ar₄₆ are mutually the same or different.

In the formula (E4): R₉₁₁, R₉₁₂, R₉₁₃, R₉₁₄, R₉₁₅, R₉₁₆, R₉₁₇, R₉₁₈, R₉₁₉, R₉₂₀, and R₉₂₁ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₁₁ are present, the plurality of R₉₁₁ are mutually the same or different;
when a plurality of R₉₁₂ are present, the plurality of R₉₁₂ are mutually the same or different;
when a plurality of R₉₁₃ are present, the plurality of R₉₁₃ are mutually the same or different;
when a plurality of R₉₁₄ are present, the plurality of R₉₁₄ are mutually the same or different;
when a plurality of R₉₁₅ are present, the plurality of R₉₁₅ are mutually the same or different;
when a plurality of R₉₁₆ are present, the plurality of R₉₁₆ are mutually the same or different;
when a plurality of R₉₁₇ are present, the plurality of R₉₁₇ are mutually the same or different;
when a plurality of R₉₁₈ are present, the plurality of R₉₁₈ are mutually the same or different;
when a plurality of R₉₁₉ are present, the plurality of R₉₁₉ are mutually the same or different;
when a plurality of R₉₂₀ are present, the plurality of R₉₂₀ are mutually the same or different; and
when a plurality of R₉₂₁ are present, the plurality of R₉₂₁ are mutually the same or different.

In an exemplary arrangement of the organic EL device according to the first exemplary embodiment, the electron transporting zone material (first electron transporting zone material or second electron transporting zone material) is a compound represented by the formula (E41) below.

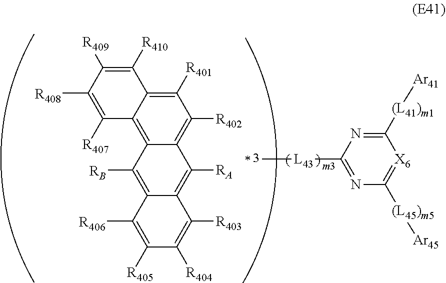

In the formula (E41):
L₄₁, L₄₃, and L₄₅ respectively represent the same as L₄₁, L₄₃, and L₄₅ in the formula (E4), and m₁, m₃, and m₅ respectively represent the same as m₁, m₃, and m₅ in the formula (E4);
one of R_{A} and R_{B} is a single bond to *3 and the other of R_{A} and R_{B}, which is not a single bond to *3, is a hydrogen atom or a substituent S, the substituent S as R_{A} or R_{B} being a “substituted or unsubstituted” group, when the substituent S is a “substituted” group, the substituent S has at least one substituent T;
R₄₀₁ to R₄₀₉ are each independently a hydrogen atom or a substituent R;
the substituent R is selected from the group consisting of a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a group represented by —P(═O)(R₉₁₈)(R₉₁₉), a halogen atom, a cyano group, a nitro group, a substituted or unsubstituted aryl group having 6 to 50 ring carbon atoms, and a substituted or unsubstituted heterocyclic group having 5 to 50 ring atoms;
when two or more substituents R are present, the two or more substituents R are mutually the same or different;
R₄₁₀ is a hydrogen atom;
none of a combination(s) of adjacent two or more of R₄₀₁ to R₄₀₉, and RA or RB that is not a single bond to *3 are bonded to each other;
X₆ is a nitrogen atom or C—Ar₄₆, in which Ar₄₆ is a hydrogen atom, or a substituent V;
at least one of Ar₄₁ or Ar₄₅ is a substituent X, the substituent X as Ar₄₁ and/or Ar₄₅ being a “substituted or unsubstituted” group, when the substituent X is a “substituted” group, the substituent X has at least one substituent U;
Ar₄₁ or Ar₄₅ that is not the substituent X is a substituted or unsubstituted aryl group having 6 to 50 ring carbon atoms, or a substituted or unsubstituted heterocyclic group having 5 to 50 ring atoms and not having a nitrogen atom;
the substituent X is a group selected from the group consisting of a substituted or unsubstituted biphenylyl group, a substituted or unsubstituted terphenylyl group, a substituted or unsubstituted naphthyl group, a substituted or unsubstituted benzoanthryl group, a substituted or unsubstituted phenanthryl group, a substituted or unsubstituted benzophenanthryl group, a substituted or unsubstituted phenalenyl group, a substituted or unsubstituted pyrenyl group, a substituted or unsubstituted chrysenyl group, a substituted or unsubstituted dibenzochrysenyl group, a substituted or unsubstituted triphenylenyl group, a substituted or unsubstituted benzotriphenylenyl group, a substituted or unsubstituted tetracenyl group, a substituted or unsubstituted pentacenyl group, a substituted or unsubstituted fluorenyl group, a substituted or unsubstituted 9,9′-spirobifluorenyl group, a substituted or unsubstituted benzofluorenyl group, a substituted or unsubstituted dibenzofluorenyl group, a substituted or unsubstituted fluoranthenyl group, a substituted or unsubstituted benzofluoranthenyl group, a substituted or unsubstituted perylenyl group, a heterocyclic group represented by a formula (E411) below, and a heterocyclic group represented by a formula (E412) below;
when two or more substituents X are present, the two or more substituents X are mutually the same or different;
when two or more substituents U are present, the two or more substituents U are mutually the same or different;
the substituent S as R_{A} or R_{B}, the substituent T for a “substituted or unsubstituted” group in R_{A} or R_{B}, the substituent U for a “substituted or unsubstituted” group in Ar₄₁ and Ar₄₅, and the substituent V as Ar₄₆ are each independently selected from the group consisting of a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a group represented by —P(═O)(R₉₁₈)(R₉₁₉), a halogen atom, a cyano group, a nitro group, a substituted or unsubstituted aryl group having 6 to 50 ring carbon atoms, and a substituted or unsubstituted heterocyclic group having 5 to 50 ring atoms; and
when two or more substituents T are present, the two or more substituents T are mutually the same or different.

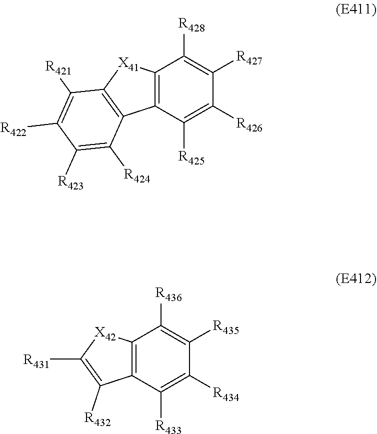

In the formula (E411):
X₄₁ is N(R₄₂₉), an oxygen atom, or a sulfur atom;
one of R₄₂₁ to R₄₂₉ is a single bond to L₄₁ or L₄₅;
at least one combination of adjacent two or more of R₄₂₁ to R₄₂₉ are mutually bonded to form a substituted or unsubstituted monocyclic ring, mutually bonded to form a substituted or unsubstituted fused ring, or not mutually bonded;
R₄₂₁ to R₄₂₉ neither being a single bond to L₄₁ or L₄₅ nor forming the substituted or unsubstituted monocyclic ring nor forming the substituted or unsubstituted fused ring are each independently selected from the group consisting of a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a group represented by —P(═O)(R₉₁₈)(R₉₁₉), a halogen atom, a cyano group, a nitro group, a substituted or unsubstituted aryl group having 6 to 50 ring carbon atoms, and a substituted or unsubstituted heterocyclic group having 5 to 50 ring atoms and not containing a nitrogen atom.

In the formula (E412):
X₄₂ is N(R₄₃₇), an oxygen atom, or a sulfur atom;
one of R₄₃₁ to R₄₃₇ is a single bond to L₄₁ or L₄₅;
at least one combination of adjacent two or more of R₄₃₁ to R₄₃₇ are mutually bonded to form a substituted or unsubstituted monocyclic ring, mutually bonded to form a substituted or unsubstituted fused ring, or not mutually bonded;
R₄₃₁ to R₄₃₇ neither being a single bond to L₄₁ or L₄₅ nor forming the substituted or unsubstituted monocyclic ring nor forming the substituted or unsubstituted fused ring are each independently selected from the group consisting of a hydrogen atom, a substituted or unsubstituted alkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a group represented by —N(R₉₁₆)(R₉₁₇), a group represented by —P(═O)(R₉₁₈)(R₉₁₉), a halogen atom, a cyano group, a nitro group, a substituted or unsubstituted aryl group having 6 to 50 ring carbon atoms, and a substituted or unsubstituted heterocyclic group having 5 to 50 ring atoms and not containing a nitrogen atom.
R₉₁₁ to R₉₁₉ in the formulae (E41), (E411), and (E412) are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms and not having a nitrogen atom;
when a plurality of R₉₁₁ are present, the plurality of R₉₁₁ are mutually the same or different;
when a plurality of R₉₁₂ are present, the plurality of R₉₁₂ are mutually the same or different;
when a plurality of R₉₁₃ are present, the plurality of R₉₁₃ are mutually the same or different;
when a plurality of R₉₁₄ are present, the plurality of R₉₁₄ are mutually the same or different;
when a plurality of R₉₁₅ are present, the plurality of R₉₁₅ are mutually the same or different;
when a plurality of R₉₁₆ are present, the plurality of R₉₁₆ are mutually the same or different;
when a plurality of R₉₁₇ are present, the plurality of R₉₁₇ are mutually the same or different;
when a plurality of R₉₁₈ are present, the plurality of R₉₁₈ are mutually the same or different; and
when a plurality of R₉₁₉ are present, the plurality of R₉₁₉ are mutually the same or different.

In an exemplary arrangement of the organic EL device according to the first exemplary embodiment, the electron transporting zone material (first electron transporting zone material or second electron transporting zone material) is a compound represented by the formula (E42) below.

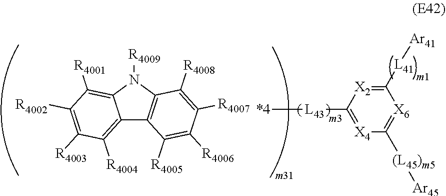

In the formula (E42):
X₂, X₄, X₆, L₄₁, L₄₃, L₄₅, Ar₄₁, and Ar₄₅ respectively represent the same as X₂, X₄, X₆, L₄₁, L₄₃, L₄₅, Ar₄₁, and Ar₄₅ in the formula (E4), and m₁, m₃, m₃₁, and m₅ respectively represent the same as m₁, m₃, m₃₁, and m₅ in the formula (E4);
at least one combination of adjacent two or more of R₄₀₀₁ to R₄₀₀₈ are mutually bonded to form a substituted or unsubstituted monocyclic ring, mutually bonded to form a substituted or unsubstituted fused ring, or not mutually bonded;
R₄₀₀₉, and R₄₀₀₁ to R₄₀₀₈ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a substituted or unsubstituted aralkyl group having 7 to 50 carbon atoms, a group represented by —C(═O)R₉₂₀, a group represented by —COOR₉₂₁, a halogen atom, a cyano group, a nitro group, a substituted or unsubstituted aryl group having 6 to 50 ring carbon atoms, or a substituted or unsubstituted heterocyclic group having 5 to 50 ring atoms;
at least one of R₄₀₀₉ or R₄₀₀₁ to R₄₀₀₈ forming neither the substituted or unsubstituted monocyclic ring nor the substituted or unsubstituted fused ring is a single bond to *4;
*4 represents a bonding position to a carbazole ring in the formula (E42); when at least one combination of adjacent two or more of R₄₀₀₁ to R₄₀₀₈ form the substituted or unsubstituted monocyclic ring or the substituted or unsubstituted fused ring, *4 in the formula (E42) represents a bonding position to a mother skeleton of the formed cyclic structure.
R₉₁₁, R₉₁₂, R₉₁₃, R₉₁₄, R₉₁₅, R₉₂₀, and R₉₂₁ in the formula (E42) respectively represent the same as R₉₁₁, R₉₁₂, R₉₁₃, R₉₁₄, R₉₁₅, R₉₂₀, and R₉₂₁ in the formula (E4).

In an exemplary arrangement of the organic EL device according to the first exemplary embodiment, the electron transporting zone material (first electron transporting zone material or second electron transporting zone material) is a compound represented by the formula (E43) below.

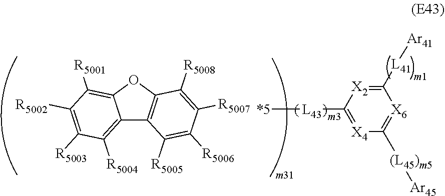

In the formula (E43):
X₂, X₄, X₆, L₄₁, L₄₃, L₄₅, Ar₄₁, and Ar₄₅ respectively represent the same as X₂, X₄, X₆, L₄₁, L₄₃, L₄₅, Ar₄₁, and Ar₄₅ in the formula (E4), and m₁, m₃, m₃₁, and m₅ respectively represent the same as m₁, m₃, m₃₁, and m₅ in the formula (E4);
at least one combination of adjacent two or more of R₅₀₀₁ to R₅₀₀₈ are mutually bonded to form a substituted or unsubstituted monocyclic ring, mutually bonded to form a substituted or unsubstituted fused ring, or not mutually bonded;
R₅₀₀₁ to R₅₀₀₈ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a substituted or unsubstituted aralkyl group having 7 to 50 carbon atoms, a group represented by —C(═O)R₉₂₀, a group represented by —COOR₉₂₁, a halogen atom, a cyano group, a nitro group, a substituted or unsubstituted aryl group having 6 to 50 ring carbon atoms, or a substituted or unsubstituted heterocyclic group having 5 to 50 ring atoms;
at least one of R₅₀₀₁ to R₅₀₀₈ forming neither the substituted or unsubstituted monocyclic ring nor the substituted or unsubstituted fused ring is a single bond to *5;
*5 represents a bonding position to a dibenzofuran ring in the formula (E43); and when at least one combination of adjacent two or more of R₅₀₀₁ to R₅₀₀₈ form the substituted or unsubstituted monocyclic ring or the substituted or unsubstituted fused ring, *5 in the formula (E43) represents a bonding position to a mother skeleton of the formed cyclic structure.

R₉₁₁, R₉₁₂, R₉₁₃, R₉₁₄, R₉₁₅, R₉₂₀, and R₉₂₁ in the formula (E43) respectively represent the same as R₉₁₁, R₉₁₂, R₉₁₃, R₉₁₄, R₉₁₅, R₉₂₀, and R₉₂₁ in the formula (E4).

In an exemplary arrangement of the organic EL device according to the first exemplary embodiment, the electron transporting zone material (first electron transporting zone material or second electron transporting zone material) is a compound represented by the formula (E44) below.

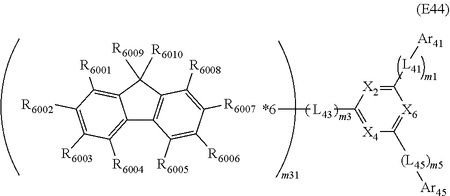

In the formula (E44):
X₂, X₄, X₆, L₄₁, L₄₃, L₄₅, Ar₄₁, and Ar₄₅ respectively represent the same as X₂, X₄, X₆, L₄₁, L₄₃, L₄₅, Ar₄₁, and Ar₄₅ in the formula (E4), and m₁, m₃, m₃₁, and m₅ respectively represent the same as m₁, m₃, m₃₁, and m₅ in the formula (E4);
a combination of R₆₀₀₉ and R₆₀₁₀ are mutually bonded to form a substituted or unsubstituted monocyclic ring, mutually bonded to form a substituted or unsubstituted fused ring, or not mutually bonded;
at least one combination of adjacent two or more of R₆₀₀₁ to R₆₀₀₈ are mutually bonded to form a substituted or unsubstituted monocyclic ring, mutually bonded to form a substituted or unsubstituted fused ring, or not mutually bonded;
R₆₀₀₁ to R₆₀₁₀ forming neither the substituted or unsubstituted monocyclic ring nor the substituted or unsubstituted fused ring are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₁₁)(R₉₁₂)(R₉₁₃), a group represented by —O—(R₉₁₄), a group represented by —S—(R₉₁₅), a substituted or unsubstituted aralkyl group having 7 to 50 carbon atoms, a group represented by —C(═O)R₉₂₀, a group represented by —COOR₉₂₁, a halogen atom, a cyano group, a nitro group, a substituted or unsubstituted aryl group having 6 to 50 ring carbon atoms, or a substituted or unsubstituted heterocyclic group having 5 to 50 ring atoms;
at least one of R₆₀₀₁ to R₆₀₁₀ forming neither the substituted or unsubstituted monocyclic ring nor the substituted or unsubstituted fused ring is a single bond to *6;
*6 represents a bonding position to a fluorene ring in the formula (E44); and when at least one combination of adjacent two or more of R₆₀₀₁ to R₆₀₁₀ form the substituted or unsubstituted monocyclic ring or the substituted or unsubstituted fused ring, *6 in the formula (E44) represents a bonding position to a mother skeleton of the formed cyclic structure.

R₉₁₁, R₉₁₂, R₉₁₃, R₉₁₄, R₉₁₅, R₉₂₀, and R₉₂₁ in the formula (E44) respectively represent the same as R₉₁₁, R₉₁₂, R₉₁₃, R₉₁₄, R₉₁₅, R₉₂₀, and R₉₂₁ in the formula (E4).

In an exemplary arrangement of the organic EL device according to the first exemplary embodiment, the electron transporting zone material (first electron transporting zone material or second electron transporting zone material) is a compound represented by the formula (E5) below.

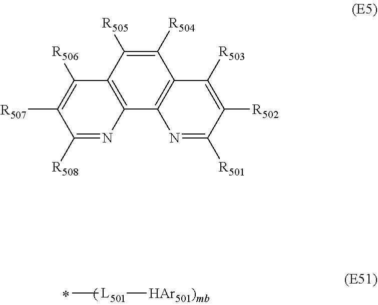

In the formula (E5): at least one combination of adjacent two or more of R₅₀₁ to R₅₀₈ are mutually bonded to form a substituted or unsubstituted monocyclic ring, mutually bonded to form a substituted or unsubstituted fused ring, or not mutually bonded;
R₅₀₁ to R₅₀₈ forming neither the substituted or unsubstituted monocyclic ring nor the substituted or unsubstituted fused ring are each independently a hydrogen atom, a substituted or unsubstituted aryl group having 6 to 50 ring carbon atoms, a substituted or unsubstituted pyridyl group, a substituted or unsubstituted quinolyl group, a substituted or unsubstituted alkyl group having 1 to 50 carbon atoms, a substituted or unsubstituted cycloalkyl group having 3 to 50 ring carbon atoms, a substituted or unsubstituted aralkyl group having 7 to 50 carbon atoms, a group represented by —O—(R₉₀₄), a group represented by —S—(R₉₀₅), a substituted or unsubstituted alkoxycarbonyl group having 1 to 50 carbon atoms, a halogen atom, a cyano group, a nitro group, a carboxy group, a group represented by —N(R_{905N})(R_{906N}), or a group represented by the formula (E51);
when a plurality of groups represented by the formula (E51) are present, the plurality of groups represented by the formula (E51) are mutually the same or different;
L₅₀₁ is a single bond, a substituted or unsubstituted arylene group having 6 to 50 ring carbon atoms, or a substituted or unsubstituted divalent heterocyclic group having 5 to 50 ring atoms;
HAr₅₀₁ is a substituted or unsubstituted aryl group having 6 to 50 ring carbon atoms, or a substituted or unsubstituted heterocyclic group having 5 to 50 ring atoms;
mb is 1, 2, 3 or 4;
when mb is 2, 3 or 4, two or more L₅₀₁ are mutually the same or different, and two or more HAr₅₀₁ are mutually the same or different;
* in the formula (E51) represents a bonding position to a phenanthroline ring in the formula (E5); and when at least one combination of adjacent two or more of R₅₀₁ to R₅₀₈ form the substituted or unsubstituted monocyclic ring or the substituted or unsubstituted fused ring, * in the formula (E51) represents a bonding position to a mother skeleton of the formed cyclic structure.
R₉₀₄ and R₉₀₅ in the formula (E5) are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₄ are present, the plurality of R₉₀₄ are mutually the same or different;
when a plurality of R₉₀₅ are present, the plurality of R₉₀₅ are mutually the same or different;
R_{905N} and R_{906N} are each independently a substituted or unsubstituted aryl group having 6 to 50 ring carbon atoms;
when a plurality of R_{905N} are present, the plurality of R_{905N} are mutually the same or different; and
when a plurality of R_{906N} are present, the plurality of R_{906N} are mutually the same or different.

In an exemplary arrangement of the organic EL device according to the first exemplary embodiment, at least one of R₅₀₁ to R₅₀₈ in the electron transporting zone material (first electron transporting zone material or second electron transporting zone material) is a group represented by the formula (E51), and the group represented by the formula (E51) is a group represented by any one of formulae (E511) to (E515) below.

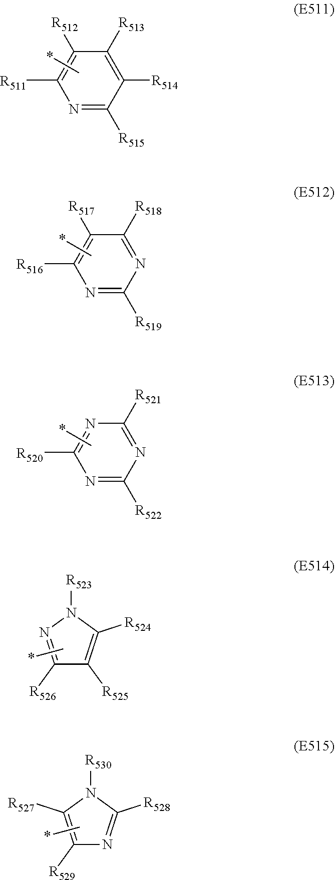

In the formula (E511), one of R₅₁₁, R₅₁₂, R₅₁₃, R₅₁₄, and R₅₁₅ represents a single bond to L₅₀₁.

In the formula (E512), one of R₅₁₆, R₅₁₇, R₅₁₈, and R₅₁₉ represents a single bond to L₅₀₁.

In the formula (E513), one of R₅₂₀, R₅₂₁, and R₅₂₂ represents a single bond to L₅₀₁.

In the formula (E514), one of R₅₂₃, R₅₂₄, R₅₂₅, and R₅₂₆ represents a single bond to L₅₀₁.

In the formula (E515), one of R₅₂₇, R₅₂₈, R₅₂₉, and R₅₃₀ represents a single bond to L₅₀₁.

At least one combination of adjacent two or more of R₅₁₁ to R₅₃₀ are mutually bonded to form a substituted or unsubstituted monocyclic ring, mutually bonded to form a substituted or unsubstituted fused ring, or not mutually bonded;

R₅₁₁ to R₅₃₀ neither being a single bond to L₅₀₁, nor forming the substituted or unsubstituted monocyclic ring, nor forming the substituted or unsubstituted fused ring are each independently a hydrogen atom, a substituted or unsubstituted aryl group having 6 to 50 ring carbon atoms, a substituted or unsubstituted pyridyl group, a substituted or unsubstituted quinolyl group, a substituted or unsubstituted alkyl group having 1 to 50 carbon atoms, a substituted or unsubstituted cycloalkyl group having 3 to 50 ring carbon atoms, a substituted or unsubstituted aralkyl group having 7 to 50 carbon atoms, a group represented by —O—(R₉₀₄), a group represented by —S—(R₉₀₅), a substituted or unsubstituted alkoxycarbonyl group having 1 to 50 carbon atoms, a halogen atom, a cyano group, a nitro group, a carboxy group, or a group represented by —N(R_{905N})(R_{906N});
R₉₀₄, R₉₀₅, R_{905N}, and R_{906N} respectively represent the same as R₉₀₄, R₉₀₅, R_{905N}, and R_{906N} in the formula (E5); and * represents a bonding position.

In an exemplary arrangement of the organic EL device according to the first exemplary embodiment, at least one of R₅₀₁ to R₅₀₈ in the electron transporting zone material (first electron transporting zone material or second electron transporting zone material) is a group represented by the formula (E51), and the group represented by the formula (E51) is a group represented by any one of formulae (E516) to (E526) below.

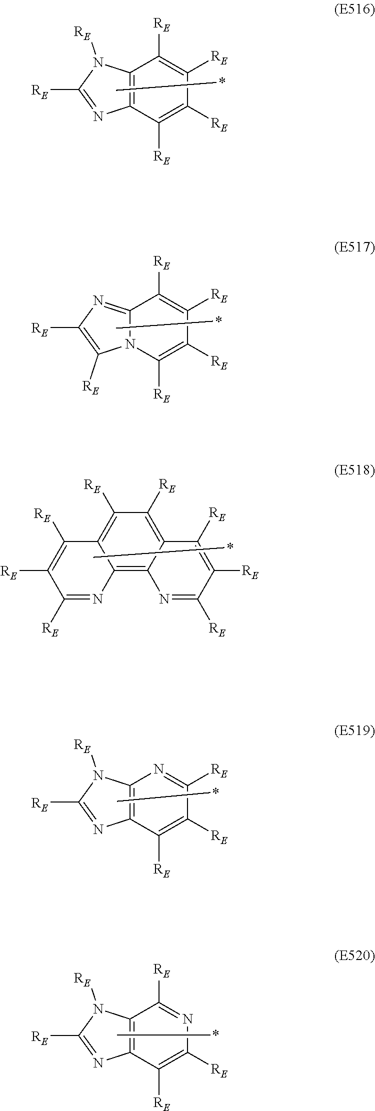

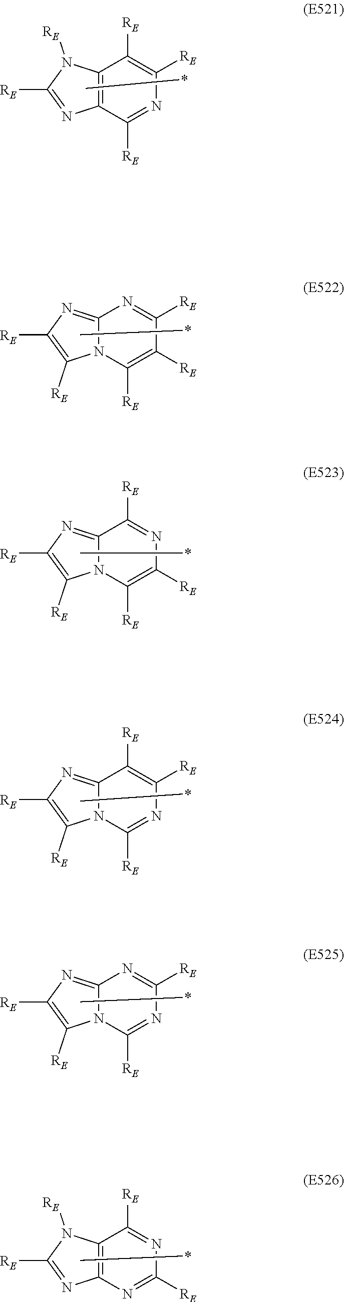

In the formulae (E516) to (E526):
one of R_{E} is a single bond to L₅₀₁;
at least one combination of adjacent two or more of a plurality of R_{E} are mutually bonded to form a substituted or unsubstituted monocyclic ring, mutually bonded to form a substituted or unsubstituted fused ring, or not mutually bonded;
R_{E} neither being a single bond to L₅₀₁ nor forming the substituted or unsubstituted monocyclic ring nor forming the substituted or unsubstituted fused ring are each independently a hydrogen atom, a substituted or unsubstituted aryl group having 6 to 50 ring carbon atoms, a substituted or unsubstituted pyridyl group, a substituted or unsubstituted quinolyl group, a substituted or unsubstituted alkyl group having 1 to 50 carbon atoms, a substituted or unsubstituted cycloalkyl group having 3 to 50 ring carbon atoms, a substituted or unsubstituted aralkyl group having 7 to 50 carbon atoms, a group represented by —O—(R₉₀₄), a group represented by —S—(R₉₀₅), a substituted or unsubstituted alkoxycarbonyl group having 1 to 50 carbon atoms, a halogen atom, a cyano group, a nitro group, a carboxy group, or a group represented by —N(R_{905N})(R_{906N});
R₉₀₄, R₉₀₅, R_{905N}, and R_{906N} respectively represent the same as R₉₀₄, R₉₀₅, R_{905N}, and R_{906N} in the formula (E5);
a plurality of R_{E} are mutually the same or different; and * represents a bonding position.

In an exemplary arrangement of the organic EL device according to the first exemplary embodiment, the electron transporting zone material (first electron transporting zone material or second electron transporting zone material) is a compound represented by a formula (E61) or (E62) below.

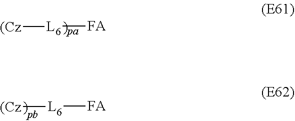

In the formulae (E61) and (E62):
Cz is each independently carbazolyl groups or indolyl groups represented by any one formula selected from the group consisting of formulae (E63), (E64), (E65), (E66), (E67), and (E68) below;
L₆ is each independently a single bond, a substituted or unsubstituted arylene group having 6 to 50 ring carbon atoms, or a substituted or unsubstituted divalent heterocyclic group having 5 to 50 ring atoms;
pa is 0, 1, 2, 3, 4, 5, 6, 7, 8, 9, or 10;
pb is 0, 1, 2, 3, 4, 5, 6, 7, 8, 9, or 10;
when a plurality of L₆ are present, the plurality of L₆ are mutually the same or different;
when a plurality of Cz are present, the plurality of Cz are mutually the same or different; and
FA is each independently a substituted or unsubstituted fused cyclic group having 6 to 50 ring carbon atoms, FA being not an unsubstituted carbazolyl group.

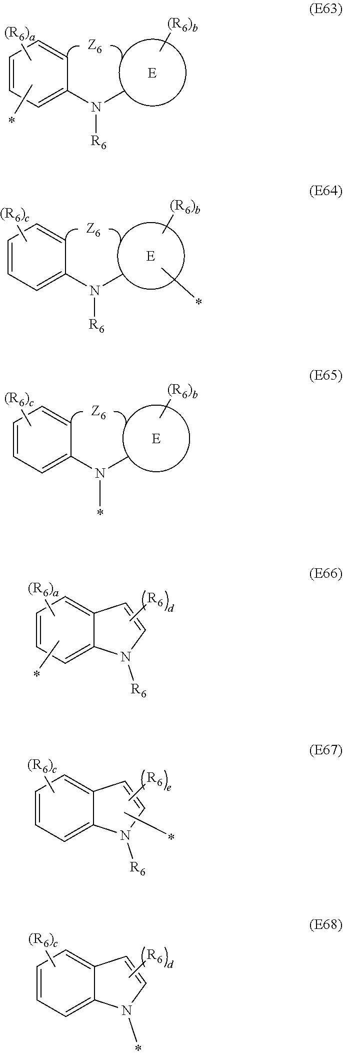

In the formulae (E63), (E64), (E65), (E66), (E67), and (E68):
Z₆ is each independently a single bond, —C(R₆₀₁)(R₆₀₂)—, —Si(R₆₀₃)(R₆₀₄)—, —O—, —CO—, or —N(R₆₀₅)—;
R₆₀₁, R₆₀₂, R₆₀₃, R₆₀₄, and R₆₀₅ are each independently a hydrogen atom, a substituted or unsubstituted aryl group having 6 to 50 ring carbon atoms, a substituted or unsubstituted heterocyclic group having 5 to 50 ring atoms, or a substituted or unsubstituted alkyl group having 1 to 50 carbon atoms;
each ring E is independently a substituted or unsubstituted aliphatic hydrocarbon ring having 3 to 20 ring carbon atoms, a substituted or unsubstituted nitrogen-atom-containing non-aromatic heterocycle having 3 to 20 ring atoms, a substituted or unsubstituted aromatic hydrocarbon ring having 4 to 50 ring carbon atoms, or a substituted or unsubstituted aromatic heterocycle having 4 to 50 ring atoms;
a is 3;
each b is independently 0, 1, 2, 3, or 4;
c is 4;
d is 2;
e is 1;
at least one combination of adjacent two or more of a plurality of R₆ are mutually bonded to form a substituted or unsubstituted monocyclic ring, mutually bonded to form a substituted or unsubstituted fused ring, or not mutually bonded;
each R₆ forming neither the substituted or unsubstituted monocyclic ring nor the substituted or unsubstituted fused ring is independently a hydrogen atom, a substituted or unsubstituted aryl group having 6 to 50 ring carbon atoms, a substituted or unsubstituted heterocyclic group having 5 to 50 ring atoms, a substituted or unsubstituted alkyl group having 1 to 50 carbon atoms, a group represented by —O—(R₉₀₄), a group represented by —S—(R₉₀₅), a substituted or unsubstituted aralkyl group having 7 to 50 carbon atoms, a carboxy group, a halogen atom, a cyano group, or a nitro group;
when a plurality of R₆₀₁ are present, the plurality of R₆₀₁ are mutually the same or different;
when a plurality of R₆₀₂ are present, the plurality of R₆₀₂ are mutually the same or different;
when a plurality of R₆₀₃ are present, the plurality of R₆₀₃ are mutually the same or different;
when a plurality of R₆₀₄ are present, the plurality of R₆₀₄ are mutually the same or different;
when a plurality of R₆₀₅ are present, the plurality of R₆₀₅ are mutually the same or different;
a plurality of R₆ are mutually the same or different; and
* represents a bonding position.

In the compound represented by the formula (E61) or (E62), R₉₀₄ and R₉₀₅ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₄ are present, the plurality of R₉₀₄ are mutually the same or different; and
when a plurality of R₉₀₅ are present, the plurality of Roos are mutually the same or different.

In an exemplary arrangement of the organic EL device according to the first exemplary embodiment, the group represented by the formula (E63) is a group represented by any one formula selected from the group consisting of formulae (E631), (E632), (E633), and (E634) below.

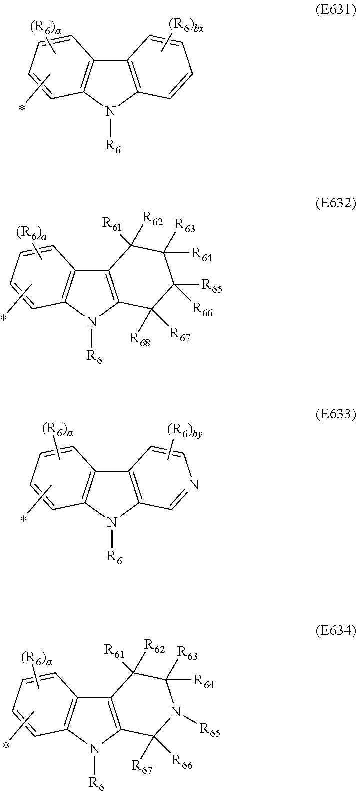

In the formulae (E631), (E632), (E633), and (E634): R₆ and a respectively represent the same as R₆ and a in the formula (E63); bx is 4; by is 3; R₆₁ to R₆₈ each independently represent the same as R₆ in the formula (E63); a plurality of R₆ are mutually the same or different; and * represents a bonding position.

In an exemplary arrangement of the organic EL device according to the first exemplary embodiment, the group represented by the formula (E65) is a group represented by any one formula selected from the group consisting of formulae (E651), (E652), (E653), and (E654) below.

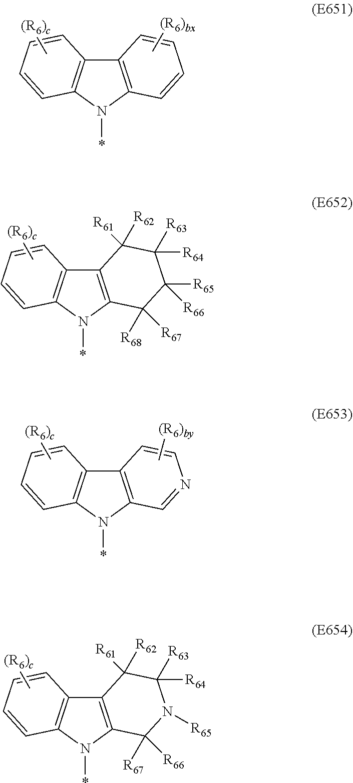

In the formulae (E651), (E652), (E653), and (E654): R₆ and c respectively represent the same as R₆ and c in the formula (E65); bx is 4; by is 3; R₆₁ to R₆₈ each independently represent the same as R₆ in the formula (E65); a plurality of R₆ are mutually the same or different; and * represents a bonding position.

In an exemplary arrangement of the organic EL device according to the first exemplary embodiment, the electron transporting zone material (first electron transporting zone material or second electron transporting zone material) is a compound represented by the formula (E7) below.

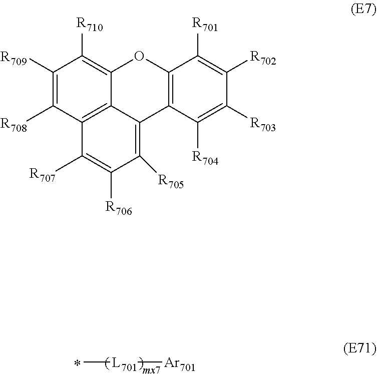

In the formula (E7):
R₇₀₁ to R₇₁₀ are each independently a hydrogen atom, a substituted or unsubstituted alkyl group having 1 to 50 carbon atoms, a substituted or unsubstituted haloalkyl group having 1 to 50 carbon atoms, a substituted or unsubstituted alkenyl group having 2 to 50 carbon atoms, a substituted or unsubstituted alkynyl group having 2 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a substituted or unsubstituted aralkyl group having 7 to 50 carbon atoms, a group represented by —C(═O)R₈₀₁, a group represented by —COOR₈₀₂, a halogen atom, a cyano group, a nitro group, a substituted or unsubstituted aryl group having 6 to 50 ring carbon atoms, a substituted or unsubstituted heterocyclic group having 5 to 50 ring atoms, or a group represented by the formula (E71);
at least one of R₇₀₁ to R₇₁₀ is a group represented by the formula (E71);
when a plurality of groups represented by the formula (E71) are present, the plurality of groups represented by the formula (E71) are mutually the same or different;
L₇₀₁ is a single bond, a substituted or unsubstituted arylene group having 6 to 50 ring carbon atoms, or a substituted or unsubstituted divalent heterocyclic group having 5 to 50 ring atoms;
Ar₇₀₁ is a substituted or unsubstituted aryl group having 6 to 50 ring carbon atoms, or a substituted or unsubstituted heterocyclic group having 5 to 50 ring atoms;
mx7 is 0, 1, 2, 3, 4, or 5, and when mx7 is 0, -(L₇₀₁)₀- is a single bond;
when two or more L₇₀₁ are present, the two or more L₇₀₁ are mutually the same or different;
when two or more Ar₇₀₁ are present, the two or more Ar₇₀₁ are mutually the same or different; and
* in the formula (E71) represents a bonding position to a ring represented by the formula (E7).

In the compound represented by the formula (E7), R₉₀₁, R₉₀₂, R₉₀₃, R₉₀₄, R₉₀₅, R₈₀₁, R₈₀₂, R₈₀₁ and R₈₀₂ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of R₉₀₃ are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₈₀₁ are present, the plurality of R₈₀₁ are mutually the same or different; and
when a plurality of R₈₀₂ are present, the plurality of R₈₀₂ are mutually the same or different.

In an exemplary arrangement of the organic EL device according to the first exemplary embodiment, the first charge generating zone material is not a compound having an anthracene skeleton.

In an exemplary arrangement of the organic EL device according to the first exemplary embodiment, when the first charge generating zone material is a compound represented by the formula (E5) (a compound having a phenanthroline skeleton), the first charge generating zone material has only a single phenanthroline skeleton.

In an exemplary arrangement of the organic EL device according to the first exemplary embodiment, the first electron transporting zone material is not a compound having an anthracene skeleton.

In an exemplary arrangement of the organic EL device according to the first exemplary embodiment, the first electron transporting zone material is a compound represented by the formula (E4) or (E42).

### Method for Producing Electron Transporting Zone Material

The electron transporting zone material is producible by a known method. The electron transporting zone material is also producible based on a known method through a known alternative reaction using a known material(s) tailored for the target compound.

### Specific Examples of Electron Transporting Zone Material

Specific examples of the electron transporting zone material include the following compounds. However, the invention is by no means limited to these specific examples.

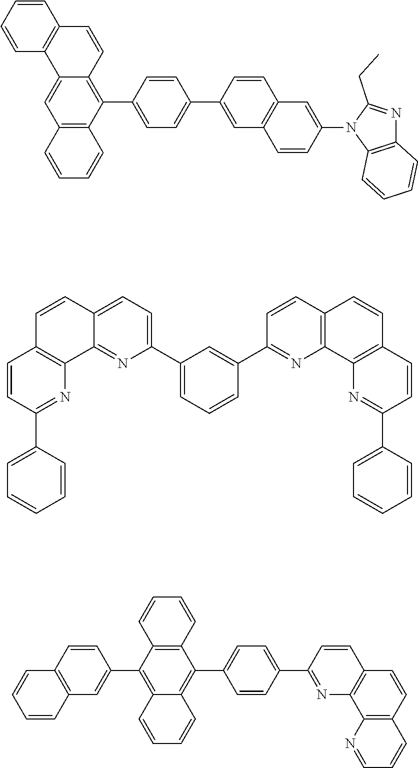 [SMILES: CCc1nc2ccccc2n1-c1ccc2cc(-c3ccc(-c4c5ccccc5cc5c4ccc4ccccc45)cc3)ccc2c1 ; c1ccc(-c2ccc3ccc4ccc(-c5cccc(-c6ccc7ccc8ccc(-c9ccccc9)nc8c7n6)c5)nc4c3n2)cc1 ; c1ccc2cc(-c3c4ccccc4c(-c4ccc(-c5ccc6ccc7cccnc7c6n5)cc4)c4ccccc34)ccc2c1]

### Metal and Metal Compounds

In an exemplary arrangement of the organic EL device according to the first exemplary embodiment, metal contained in the above-described metal-containing high refractive index layer is at least one metal selected from the group consisting of rare-earth metal, alkali metal, and alkaline earth metal. Specifically, metal contained in the high refractive index layer together with an organic material having a refractive index exceeding 1.87 (high refractive index organic material) is at least one metal selected from the group consisting of rare-earth metal, alkali metal, and alkaline earth metal.

In an exemplary arrangement of the organic EL device according to the first exemplary embodiment, metal contained in the high refractive index layer together with an organic material having a refractive index exceeding 1.87 is at least one metal selected from the group consisting of ytterbium, erbium, lithium, cesium, magnesium, and calcium.

In an exemplary arrangement of the organic EL device according to the first exemplary embodiment, a metal compound contained in the high refractive index layer together with the organic material having a refractive index exceeding 1.87 is at least one metal compound selected from the group consisting of an alkali metal compound and alkaline earth metal compound.

In an exemplary arrangement of the organic EL device according to the first exemplary embodiment, the metal compound contained in the high refractive index layer together with the organic material having a refractive index exceeding 1.87 is at least one metal compound selected from the group consisting of 8-(quinolinolato)lithium (abbreviation: Liq), lithium fluoride (LiF), cesium fluoride (CsF), calcium fluoride (CaF₂), 2-(2-pyridyl)phenolatolithium (abbreviation: LiPP)), 2-(2-pyridyl)-3-pyridinolato lithium (abbreviation: LiPPy), 4-phenyl-2-(2-pyridyl)phenolatolithium (abbreviation: LiPPP), lithium oxide (LiOx), and cesium carbonate.

### Hole Transporting Zone

In an exemplary arrangement of the organic EL device according to the first exemplary embodiment, two or more emitting units each independently include a hole transporting zone. In the exemplary arrangement of the organic EL device according to the first exemplary embodiment, a first emitting unit includes a first hole transporting zone and a second emitting unit includes a second hole transporting zone.

### First Hole Transporting Zone

In an exemplary arrangement of the organic EL device according to the first exemplary embodiment, the first hole transporting zone is disposed between the anode and the first emitting zone.

In an exemplary arrangement of the organic EL device according to the first exemplary embodiment, the first hole transporting zone includes one or more layers.

In an exemplary arrangement of the organic EL device according to the first exemplary embodiment, the first hole transporting zone includes two or more layers.

In an exemplary arrangement of the organic EL device according to the first exemplary embodiment, the first hole transporting zone includes the first hole injecting layer and the first hole transporting layer. In an exemplary arrangement of the organic EL device according to the first exemplary embodiment, the first hole transporting zone includes the first hole injecting layer and the first hole transporting layer in this order from the anode. In an exemplary arrangement of the organic EL device according to the first exemplary embodiment, the first hole transporting layer is in direct contact with the first emitting layer in the first emitting zone.

In an exemplary arrangement of the organic EL device according to the first exemplary embodiment, the first hole transporting zone includes three or more layers. In an exemplary arrangement of the organic EL device according to the first exemplary embodiment, the first hole transporting zone includes three layers of the first hole injecting layer, the first hole transporting layer, and a first electron blocking layer. In an exemplary arrangement of the organic EL device according to the first exemplary embodiment, the first hole transporting zone includes the first hole injecting layer, the first hole transporting layer, and the first electron blocking layer in this order from the emitting zone.

In an exemplary arrangement of the organic EL device according to the first exemplary embodiment, the first electron blocking layer is in direct contact with the first emitting layer in the first emitting zone. In an exemplary arrangement of the organic EL device according to the first exemplary embodiment, the first electron blocking layer and the first hole transporting layer are in direct contact with each other. In an exemplary arrangement of the organic EL device according to the first exemplary embodiment, the first hole transporting layer and the first hole injecting layer are in direct contact with each other. In an exemplary arrangement of the organic EL device according to the first exemplary embodiment, the first hole injecting layer and the anode are in direct contact with each other.

In an exemplary arrangement of the organic EL device according to the first exemplary embodiment, the first hole transporting zone contains the first hole transporting zone material.

### Second Hole Transporting Zone

In an exemplary arrangement of the organic EL device according to the first exemplary embodiment, the second hole transporting zone is disposed between the first emitting unit and the second emitting zone.

In an exemplary arrangement of the organic EL device according to the first exemplary embodiment, the second hole transporting zone is disposed between the first charge generating zone and the second emitting zone.

In an exemplary arrangement of the organic EL device according to the first exemplary embodiment, the second hole transporting zone is disposed between the first charge generating layer and the second emitting zone.

In an exemplary arrangement of the organic EL device according to the first exemplary embodiment, the second hole transporting zone is disposed between the second charge generating layer and the second emitting zone.

In an exemplary arrangement of the organic EL device according to the first exemplary embodiment, the second hole transporting zone includes one or more layers.

In an exemplary arrangement of the organic EL device according to the first exemplary embodiment, the second hole transporting zone includes the second hole transporting layer. In an exemplary arrangement of the organic EL device according to the first exemplary embodiment, the second hole transporting layer is in direct contact with the second emitting layer in the second emitting zone.

In an exemplary arrangement of the organic EL device according to the first exemplary embodiment, the second hole transporting zone includes two or more layers. In an exemplary arrangement of the organic EL device according to the first exemplary embodiment, the second hole transporting zone includes the second hole transporting layer and a second electron blocking layer. In an exemplary arrangement of the organic EL device according to the first exemplary embodiment, the second hole transporting zone includes the second hole transporting layer and the second electron blocking layer in this order from the first emitting unit. In an exemplary arrangement of the organic EL device according to the first exemplary embodiment, the second hole transporting layer is in direct contact with the second electron blocking layer. In an exemplary arrangement of the organic EL device according to the first exemplary embodiment, the second electron blocking layer is in direct contact with the second emitting layer in the second emitting zone.

In an exemplary arrangement of the organic EL device of the first exemplary embodiment, the second electron blocking layer may be a layer (low refractive index layer) containing an organic material (low refractive index organic material) having a refractive index of 1.87 or less, or may be a layer (high refractive index layer) containing an organic material (high refractive index organic material) having a refractive index exceeding 1.87.

In an exemplary arrangement of the organic EL device according to the first exemplary embodiment, the second hole transporting layer is disposed between the second charge generating layer and the second emitting zone.

In an exemplary arrangement of the organic EL device according to the first exemplary embodiment, the second charge generating layer is in direct contact with the second hole transporting layer. In an exemplary arrangement of the organic EL device according to the first exemplary embodiment, the second charge generating layer may not be in direct contact with the second hole transporting layer.

In an exemplary arrangement of the organic EL device of the first exemplary embodiment, the second hole transporting layer is a low refractive index layer. When the second hole transporting layer is a low refractive index layer, the second hole transporting layer contains an organic material having a refractive index of 1.87 or less.

In an exemplary arrangement of the organic EL device in Arrangement C1, at least two low refractive index layers in direct contact are the second charge generating layer and the second hole transporting layer, and the second charge generating layer is the first low refractive index layer.

In an exemplary arrangement of the organic EL device according to the first exemplary embodiment, the second hole transporting layer contains the second hole transporting zone material.

In an exemplary arrangement of the organic EL device of the first exemplary embodiment, the second hole transporting zone material is a low refractive index organic material.

In an exemplary arrangement of the organic EL device of the first exemplary embodiment, a refractive index of the second hole transporting zone material is 1.87 or less, 1.83 or less, 1.79 or less, 1.75 or less, 1.71 or less, or 1.69 or less.

In an exemplary arrangement of the organic EL device according to the first exemplary embodiment, the refractive index of the first charge generating zone material is more than 1.87, the refractive index of the second charge generating zone material is 1.87 or less, and the refractive index of the second hole transporting zone material is 1.87 or less.

In an exemplary arrangement of the organic EL device according to the first exemplary embodiment, the first charge generating zone material is a high refractive index organic material, the second charge generating zone material is a low refractive index organic material, and the second hole transporting zone material is a low refractive index organic material.

In an exemplary arrangement of the organic EL device according to the first exemplary embodiment, the first electron transporting zone material is a high refractive index organic material, the first charge generating zone material is a high refractive index organic material, the second charge generating zone material is a low refractive index organic material, and the second hole transporting zone material is a low refractive index organic material.

In an exemplary arrangement of the organic EL device according to the first exemplary embodiment, the second hole transporting zone material and the second charge generating zone material are mutually the same or different.

In an exemplary arrangement of the organic EL device according to the first exemplary embodiment, the second hole transporting zone material and the first charge generating zone material are mutually different.

In an exemplary arrangement of the organic EL device according to the first exemplary embodiment, the second hole transporting zone material and the first electron transporting zone material are mutually different.

In an exemplary arrangement of the organic EL device in Arrangement C1, one of at least two low refractive index layers in direct contact is the second hole transporting layer.

In an exemplary arrangement of the organic EL device in Arrangement C1, the second charge generating layer is the first low refractive index layer described above and the second hole transporting layer is the second low refractive index layer described above.

In an exemplary arrangement of the organic EL device in Arrangement C1, a total film thickness of the second charge generating layer and the second hole transporting layer is 40 nm or more, 45 nm or more, or 50 nm or more.

In an exemplary arrangement of the organic EL device according to the first exemplary embodiment, the first electron transporting layer is a high refractive index layer, the first charge generating layer is a first high refractive index layer, the second charge generating layer is the first low refractive index layer, and the second hole transporting layer is a low refractive index layer.

### Hole Transporting Zone Material

In an exemplary arrangement of the organic EL device according to the first exemplary embodiment, the material contained in the hole transporting zone is referred to as an hole transporting zone material. Examples of the hole transporting zone material include the first hole transporting zone material and the second hole transporting zone material which are described above. The hole transporting zone material is also usable as the second charge generating zone material.

In an exemplary arrangement of the organic EL device according to the first exemplary embodiment, at least one of the layers contained in the first hole transporting zone contains, as the first hole transporting zone material, a compound represented by a formula (B1) or (B2) below.

In an exemplary arrangement of the organic EL device according to the first exemplary embodiment, at least one of the layers contained in the second hole transporting zone contains, as the second hole transporting zone material, a compound represented by the formula (B1) or (B2) below.

In an exemplary arrangement of the organic EL device according to the first exemplary embodiment, the second charge generating layer contains a compound represented by the formula (B1) or (B2) below. In an exemplary arrangement of the organic EL device according to the first exemplary embodiment, the second charge generating layer contains, as the second charge generating zone material, a compound represented by the formula (B1) or (B2) below.

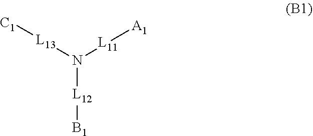

In the formula (B1):
L₁₁, L₁₂, and L₁₃ are each independently a single bond, a substituted or unsubstituted arylene group having 6 to 50 ring carbon atoms, a substituted or unsubstituted divalent heterocyclic group having 5 to 50 ring atoms, or a divalent group formed by bonding two groups selected from the group consisting of a substituted or unsubstituted arylene group having 6 to 50 ring carbon atoms and a substituted or unsubstituted divalent heterocyclic group having 5 to 50 ring atoms;
A₁, B₁, and C₁ are each independently a substituted or unsubstituted aryl group having 6 to 50 ring carbon atoms, a substituted or unsubstituted heterocyclic group having 5 to 50 ring atoms, or a group represented by —Si(R₁₂₁)(R₁₂₂)(R₁₂₃), R₁₂₁, R₁₂₂, and R₁₂₃ are each independently a substituted or unsubstituted aryl group having 6 to 50 ring carbon atoms;
when a plurality of R₁₂₁ are present, the plurality of R₁₂₁ are mutually the same or different;
when a plurality of R₁₂₂ are present, the plurality of R₁₂₂ are mutually the same or different; and
when a plurality of R₁₂₃ are present, the plurality of R₁₂₃ are mutually the same or different.

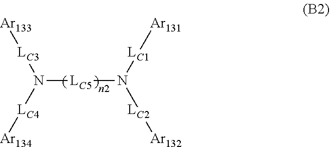

In the formula (B2):
L_{C1}, L_{C2}, L_{C3}, and L_{C4} are each independently a single bond, a substituted or unsubstituted arylene group having 6 to 50 ring carbon atoms, or a substituted or unsubstituted divalent heterocyclic group having 5 to 50 ring atoms;
n2 is 1, 2, 3, or 4;
when n2 is 1, L_{C5} is a substituted or unsubstituted arylene group having 6 to 50 ring carbon atoms, or a substituted or unsubstituted divalent heterocyclic group having 5 to 50 ring atoms;
when n2 is 2, 3, or 4, a plurality of L_{C5} are mutually the same or different;
when n2 is 2, 3, or 4, a plurality of L_{C5} are mutually bonded to form a substituted or unsubstituted monocyclic ring, mutually bonded to form a substituted or unsubstituted fused ring, or not mutually bonded;
L_{C5} forming neither the substituted or unsubstituted monocyclic ring nor the substituted or unsubstituted fused ring is a substituted or unsubstituted arylene group having 6 to 50 ring carbon atoms, or a substituted or unsubstituted divalent heterocyclic group having 5 to 50 ring atoms;
Ar₁₃₁, Ar₁₃₂, Ar₁₃₃, and Ar₁₃₄ are each independently a substituted or unsubstituted aryl group having 6 to 50 ring carbon atoms, a substituted or unsubstituted heterocyclic group having 5 to 50 ring atoms, or a group represented by —Si(R₁₂₁)(R₁₂₂)(R₁₂₃), R₁₂₁, R₁₂₂, and R₁₂₃ are each independently a substituted or unsubstituted aryl group having 6 to 50 ring carbon atoms;
when a plurality of R₁₂₁ are present, the plurality of R₁₂₁ are mutually the same or different;
when a plurality of R₁₂₂ are present, the plurality of R₁₂₂ are mutually the same or different; and
when a plurality of R₁₂₃ are present, the plurality of R₁₂₃ are mutually the same or different.

In an exemplary arrangement of the organic EL device according to the exemplary embodiment, in the compound represented by the formula (B2), a first amino group represented by a formula (B2-1) below and a second amino group represented by a formula (B2-2) below are an identical group.

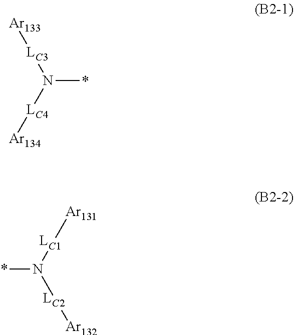

In the formulae (B2-1) and (B2-2), each * represents a bonding position to L_{C5}.

In an exemplary arrangement of the organic EL device according to the exemplary embodiment, the first amino group represented by the formula (B2-1) and the second amino group represented by the formula (B2-2) may be mutually different groups.

In an exemplary arrangement of the organic EL device according to the first exemplary embodiment, A₁, B₁, and C₁ in the formula (B1) and a formula (B100) below are each independently a group represented by any one formula selected from the group consisting of formulae (1A), (1B), (1C), (1D), (1E), (1F), and (1G) below.

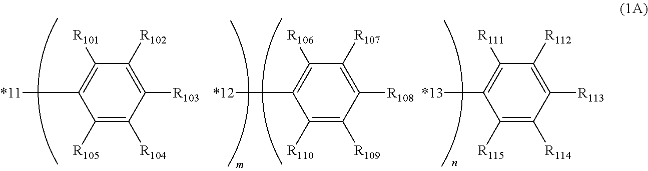

In the formula (1A):
*11 is a bonding position to L₁₁, L₁₂, or L₁₃;
one selected from R₁₀₁ to R₁₀₅ is a single bond to *12, and one selected from R₁₀₆ to R₁₁₀ is a single bond to *13;
R₁₀₁ to R₁₀₅ and R₁₀₆ to R₁₁₀ not being the single bond are each independently a hydrogen atom, an unsubstituted alkyl group having 1 to 10 carbon atoms, or an unsubstituted aryl group having 6 to 12 ring carbon atoms;
none of a combination(s) of adjacent two or more of R₁₀₁ to R₁₀₅ not being the single bond are bonded to each other;
none of a combination(s) of adjacent two or more of R₁₀₆ to R₁₁₀ not being the single bond are bonded to each other;
R₁₁₁ to R₁₁₅ are each independently a hydrogen atom, a substituted or unsubstituted alkyl group having 1 to 10 carbon atoms, a substituted or unsubstituted aryl group having 6 to 12 ring carbon atoms, or a substituted or unsubstituted heterocyclic group having 5 to 13 ring atoms;
none of a combination(s) of adjacent two or more of R₁₁₁ to R₁₁₅ are bonded to each other;
m is 0, 1, or 2; n is 0 or 1;
when m is 0 and n is 0, *13 is a bonding position to L₁₁, L₁₂, or L₁₃;
when m is 0 and n is 1, *12 is a bonding position to L₁₁, L₁₂, or L₁₃; and
when m is 1 and n is 0, one selected from R₁₀₁ to R₁₀₅ is a single bond to *13.

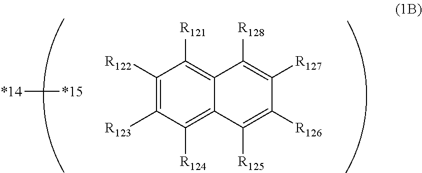

In the formula (1B):
*14 is a bonding position to L₁₁, L₁₂, or L₁₃;
one selected from R₁₂₁ to R₁₂₈ is a single bond to *15;
R₁₂₁ to R₁₂₈ not being the single bond are each independently a hydrogen atom, a substituted or unsubstituted alkyl group having 1 to 10 carbon atoms, or a substituted or unsubstituted aryl group having 6 to 12 ring carbon atoms; and
none of a combination(s) of adjacent two or more of R₁₂₁ to R₁₂₈ not being the single bond are bonded to each other;

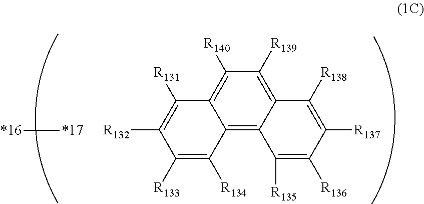

In the formula (1C):
*16 is a bonding position to L₁₁, L₁₂, or L₁₃;
one selected from R₁₃₁ to R₁₄₀ is a single bond to *17;
R₁₃₁ to R₁₄₀ not being the single bond are each independently a hydrogen atom, a substituted or unsubstituted alkyl group having 1 to 10 carbon atoms, or a substituted or unsubstituted aryl group having 6 to 12 ring carbon atoms; and
none of a combination(s) of adjacent two or more of R₁₃₁ to R₁₄₀ not being the single bond are bonded to each other;

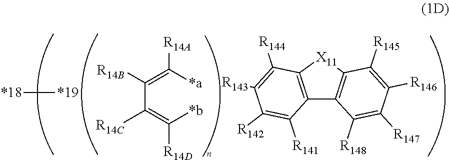

In the formula (1D):
*18 is a bonding position to L₁₁, L₁₂, or L₁₃;
X₁₁ is an oxygen atom, a sulfur atom, C(Ra)(Rb), or N(Rc);
a combination of Ra and Rb are mutually bonded to form a substituted or unsubstituted monocyclic ring, mutually bonded to form a substituted or unsubstituted fused ring, or not mutually bonded;
n is 0 or 1;
when n is 0, one selected from R₁₄₁ to R₁₄₈ and Rc, and Ra and Rb forming neither the substituted or unsubstituted monocyclic ring nor the substituted or unsubstituted fused ring is a single bond to *19;
when n is 1, one of R₁₄₁ and R₁₄₂ is a single bond to *a and the other of R₁₄₁ and R₁₄₂ is a single bond to *b, one of R₁₄₂ and R₁₄₃ is a single bond to *a and the other of R₁₄₂ and R₁₄₃ is a single bond to *b, or one of R₁₄₃ and R₁₄₄ is a single bond to *a and the other of R₁₄₃ and R₁₄₄ is a single bond to *b;
one selected from the group consisting of (i) R₁₄₅ to R₁₄₈, R_{14A}, R_{14B}, R_{14C}, R_{14D}, and Rc, (ii) R₁₄₁ to R₁₄₄ being a single bond to neither *a nor *b, and (iii) Ra and Rb being a single bond to neither *a nor *b, and forming neither the substituted or unsubstituted monocyclic ring nor the substituted or unsubstituted fused ring is a single bond to *19; and
R₁₄₁ to R₁₄₈, R_{14A}, R_{14B}, R_{14C}, R_{14D}, and Rc not being the single bond to *19, Ra and Rb not being the single bond to *19 and forming neither the substituted or unsubstituted monocyclic ring nor the substituted or unsubstituted fused ring are each independently a hydrogen atom, a substituted or unsubstituted alkyl group having 1 to 10 carbon atoms, a substituted or unsubstituted aryl group having 6 to 12 ring carbon atoms, a substituted or unsubstituted heteroaryl group having 5 to 13 ring atoms.

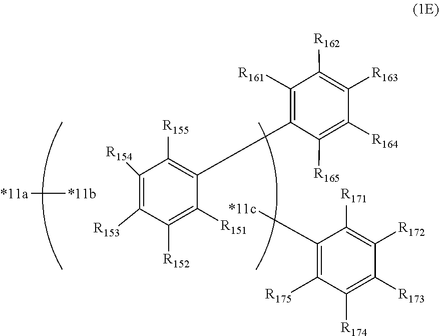

In the formula (1E):
*11a is a bonding position to L₁₁, L₁₂, or L₁₃;
one selected from R₁₅₁ to R₁₅₅ is a single bond to *11b, and another one selected from R₁₅₁ to R₁₅₅ is a single bond to *11c;
R₁₅₁ to R₁₅₅ not being the single bond are each independently a hydrogen atom, an unsubstituted alkyl group having 1 to 10 carbon atoms or an unsubstituted phenyl group;
none of a combination(s) of adjacent two or more of R₁₅₁ to R₁₅₅ not being the single bond are bonded to each other; and
R₁₆₁ to R₁₆₅ and R₁₇₁ to R₁₇₅ are each independently a hydrogen atom or an unsubstituted alkyl group having 1 to 10 carbon atoms.

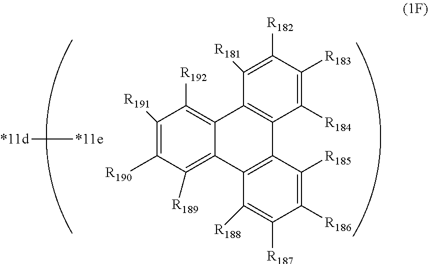

In the formula (1F):
*11d is a bonding position to L₁₁, L₁₂, or L₁₃;
one selected from R₁₈₁ to R₁₉₂ is a single bond to *11e;
R₁₈₁ to R₁₉₂ not being the single bond are each independently a hydrogen atom, a substituted or unsubstituted alkyl group having 1 to 10 carbon atoms, or a substituted or unsubstituted aryl group having 6 to 12 ring carbon atoms; and
none of a combination(s) of adjacent two or more of R₁₈₁ to R₁₉₂ not being the single bond are bonded to each other.

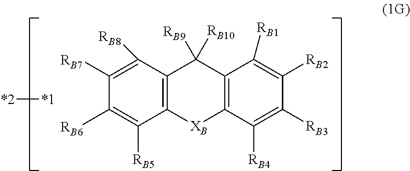

In a formula (1G) above:
X_{B} is a single bond, an oxygen atom, a sulfur atom, N(R_{B11}), or C(R_{B12})(R_{B13});
when a plurality of X_{B} are present, the plurality of X_{B} are mutually the same or different;
when X_{B} is C(R_{B12})(R_{B13}), a combination of R_{B12} and R_{B13} are mutually bonded to form a substituted or unsubstituted monocyclic ring, mutually bonded to form a substituted or unsubstituted fused ring, or not mutually bonded;
one of R_{B1}, R_{B2}, R_{B3}, R_{B4}, R_{B5}, R_{B6}, R_{B7}, R_{B8}, R_{B9}, R_{B10}, R_{B11}, R_{B12}, and R_{B13} is a single bond to *1;
R_{B1}, R_{B2}, R_{B3}, R_{B4}, R_{B5}, R_{B6}, R_{B7}, R_{B8}, and R_{B11} not being the single bond to *1 are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
a combination of R_{B9} and R_{B10} are mutually bonded to form a substituted or unsubstituted monocyclic ring, mutually bonded to form a substituted or unsubstituted fused ring, or not mutually bonded;
R_{B9}, R_{B10}, R_{B12}, and R_{B13} not being the single bond to *1, forming neither the substituted or unsubstituted monocyclic ring nor the substituted or unsubstituted fused ring are each independently a substituted or unsubstituted alkyl group having 1 to 50 carbon atoms, a substituted or unsubstituted cycloalkyl group having 3 to 50 ring carbon atoms, or a substituted or unsubstituted aryl group having 6 to 50 ring carbon atoms; and
*2 is a bonding position to L₁₁, L₁₂, or L₁₃.

In a group represented by the formula (1G): R₉₀₁, R₉₀₂, R₉₀₃, and R₉₀₄ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms; when a plurality of R₉₀₁ are present, the plurality of R₉₀₁ are mutually the same or different; when a plurality of R₉₀₂ are present, the plurality of R₉₀₂ are mutually the same or different; when a plurality of R₉₀₃ are present, the plurality of R₉₀₃ are mutually the same or different; and when a plurality of R₉₀₄ are present, the plurality of R₉₀₄ are mutually the same or different.

In an exemplary arrangement of the organic EL device according to the first exemplary embodiment, at least one of the one or more low refractive index layers contains a compound represented by a formula (B100) below.

In an exemplary arrangement of the organic EL device according to the first exemplary embodiment, the first organic material (low refractive index organic material) contained in the first low refractive index layer is a compound represented by the formula (B100) below.

In an exemplary arrangement of the organic EL device according to the first exemplary embodiment, the low refractive index organic material is a compound represented by the formula (B100) below.

In an exemplary arrangement of the organic EL device according to the first exemplary embodiment, the hole transporting zone material is a compound represented by the formula (B100) below.

In an exemplary arrangement of the organic EL device according to the first exemplary embodiment, the second hole transporting zone material is a compound represented by the formula (B100) below.

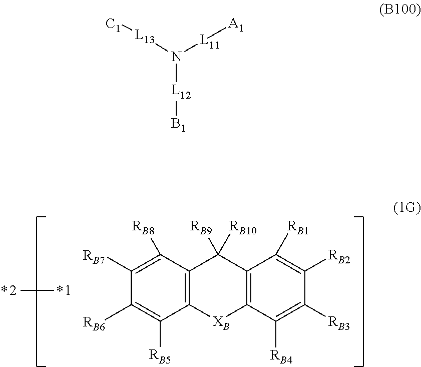

In the formula (B100):
L₁₁, L₁₂, and L₁₃ are each independently a single bond, a substituted or unsubstituted arylene group having 6 to 50 ring carbon atoms, a substituted or unsubstituted divalent heterocyclic group having 5 to 50 ring atoms, or a divalent group formed by bonding two groups selected from the group consisting of a substituted or unsubstituted arylene group having 6 to 50 ring carbon atoms and a substituted or unsubstituted divalent heterocyclic group having 5 to 50 ring atoms;
A₁, B₁, and C₁ are each independently a substituted or unsubstituted aryl group having 6 to 50 ring carbon atoms, a substituted or unsubstituted heterocyclic group having 5 to 50 ring atoms, a group represented by —Si(R_{C1})(R_{C2})(R_{C3}), or a group represented by the formula (1G);
at least one selected from the group consisting of A₁, B₁, and C₁ is a group represented by the formula (1G);
R_{C1}, R_{C2}, and R_{C3} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different.

In the formula (1G):
X_{B} is a single bond, an oxygen atom, a sulfur atom, N(R_{B11}), or C(R_{B12})(R_{B13});
when a plurality of X_{B} are present, the plurality of X_{B} are mutually the same or different;
when X_{B} is C(R_{B12})(R_{B13}), a combination of R_{B12} and R_{B13} are mutually bonded to form a substituted or unsubstituted monocyclic ring, mutually bonded to form a substituted or unsubstituted fused ring, or not mutually bonded;
one of R_{B1}, R_{B2}, R_{B3}, R_{B4}, R_{B5}, R_{B6}, R_{B7}, R_{B8}, R_{B9}, R_{B10}, R_{B11}, R_{B12}, and R_{B13} is a single bond to *1;
R_{B1}, R_{B2}, R_{B3}, R_{B4}, R_{B5}, R_{B6}, R_{B7}, R_{B8}, and R_{B11} not being the single bond to *1 are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
a combination of R_{B9} and R_{B10} are mutually bonded to form a substituted or unsubstituted monocyclic ring, mutually bonded to form a substituted or unsubstituted fused ring, or not mutually bonded;
R_{B9}, R_{B10}, R_{B12}, and R_{B13} not being the single bond to *1, forming neither the substituted or unsubstituted monocyclic ring nor the substituted or unsubstituted fused ring are each independently a substituted or unsubstituted alkyl group having 1 to 50 carbon atoms, a substituted or unsubstituted cycloalkyl group having 3 to 50 ring carbon atoms, or a substituted or unsubstituted aryl group having 6 to 50 ring carbon atoms;
*2 is a bonding position to L₁₁, L₁₂, or L₁₃; and
when two or more groups represented by the formula (1G) are present, the two or more groups represented by the formula (1G) are mutually the same or different.

In the compound represented by the formula (B100), R₉₀₁, R₉₀₂, R₉₀₃, and R₉₀₄ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of Roos are mutually the same or different; and
when a plurality of R₉₀₄ are present, the plurality of R₉₀₄ are mutually the same or different.
In an exemplary arrangement of the organic EL device according to the first exemplary embodiment, the group represented by the formula (1G) is a group represented by any one formula selected from the group consisting of formulae (11G), (12G), and (13G) below.

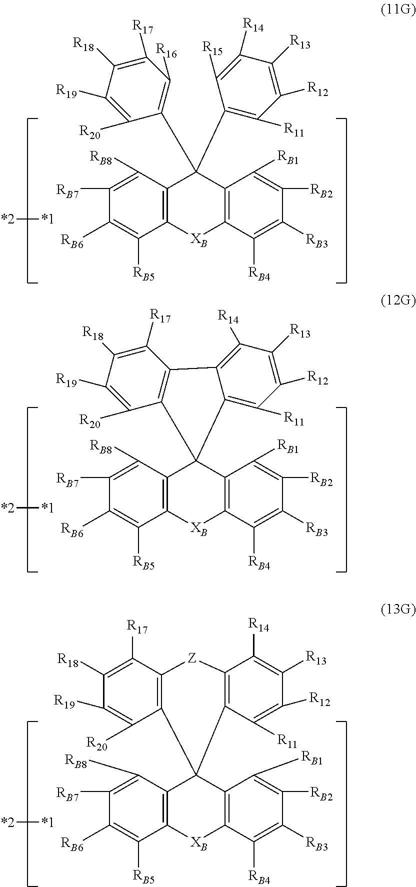

In the formulae (11G), (12G), and (13G):
X_{B}, R_{B1}, R_{B2}, R_{B3}, R_{B4}, R_{B5}, R_{B6}, R_{B7}, R_{B8}, *1, and *2 respectively represent the same as X_{B}, R_{B1}, R_{B2}, R_{B3}, R_{B4}, R_{B5}, R_{B6}, R_{B7}, R_{B8}, *1, and *2 in the formula (1G);
R₁₁, R₁₂, R₁₃, R₁₄, R₁₅, R₁₆, R₁₇, R₁₈, R₁₉, and R₂₀ are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
Z is an oxygen atom, a sulfur atom, or C(R_{Z1})(R_{Z2}); and
R_{Z1} and R_{Z2} are each independently a substituted or unsubstituted alkyl group having 1 to 50 carbon atoms, a substituted or unsubstituted cycloalkyl group having 3 to 50 ring carbon atoms, or a substituted or unsubstituted aryl group having 6 to 50 ring carbon atoms.

In the formulae (11G), (12G), and (13G): R₉₀₁, R₉₀₂, R₉₀₃, and R₉₀₄ respectively represent the same as R₉₀₁, R₉₀₂, R₉₀₃, and R₉₀₄ in the formula (1G).

In an exemplary arrangement of the organic EL device according to the first exemplary embodiment, two of A1, B1, and C1 in the formulae (B1) and (B100) are each a group represented by the formula (12G).

In an exemplary arrangement of the organic EL device according to the first exemplary embodiment, X_{B} in the formulae (1G), (11G), (12G), and (13G) is a single bond or an oxygen atom.

In an exemplary arrangement of the organic EL device of the first exemplary embodiment, R₁₁, R₁₂, R₁₃, R₁₄, R₁₅, R₁₆, R₁₇, R₁₈, R₁₉, and R₂₀ are each independently a hydrogen atom, a substituted or unsubstituted alkyl group having 1 to 18 carbon atoms, a substituted or unsubstituted aryl group having 6 to 18 ring carbon atoms, or a substituted or unsubstituted heterocyclic group having 5 to 18 ring atoms.

In an exemplary arrangement of the organic EL device according to the first exemplary embodiment, the group represented by the formula (1G) is a group represented by any one formula selected from the group consisting of formulae (11G-1), (12G-1), (12G-2), and (13G-1) below.

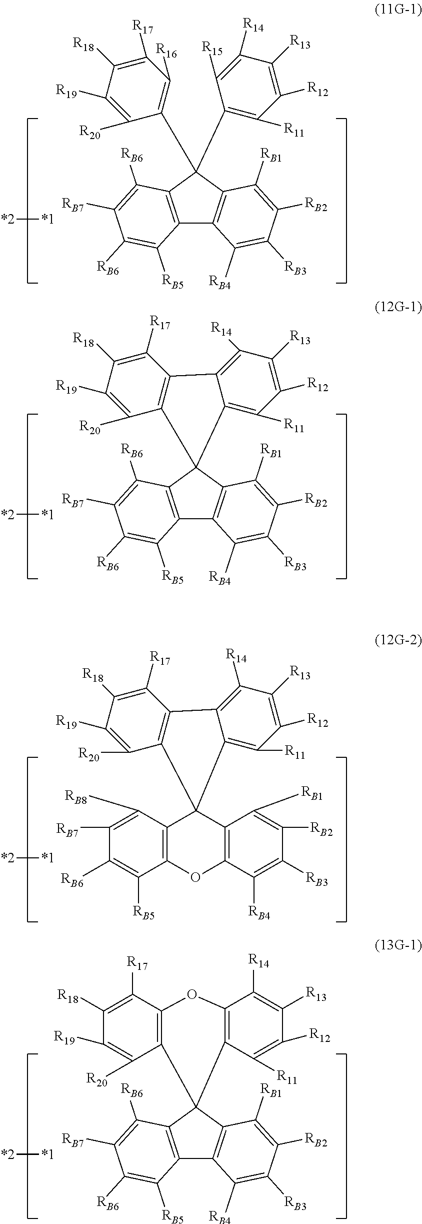

In the formula (11G-1), (12G-1), (12G-2), or (13G-1):
R_{B1}, R_{B2}, R_{B3}, R_{B4}, R_{B5}, R_{B6}, R_{B7}, R_{B8}, *1, and *2 respectively represent the same as R_{B1}, R_{B2}, R_{B3}, R_{B4}, R_{B5}, R_{B6}, R_{B7}, R_{B8}, *1, and *2 in the formula (1G);
R₁₁, R₁₂, R₁₃, R₁₄, R₁₅, R₁₆, R₁₇, R₁₈, R₁₉, and R₂₀ are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms.
R₁₁, R₁₃, R₁₄, R₁₅, R₁₆, R₁₇, R₁₈, and R₂₀ in the formulae (11G), (12G), (13G), (11G-1), (12G-1), (12G-2), and (13G-1) are each a hydrogen atom.
R₁₂ and R₁₉ in the formulae (11G), (12G), (13G), (11G-1), (12G-1), (12G-2), and (13G-1) are each independently a substituent other than a hydrogen atom.
R₁₁, R₁₃, R₁₄, R₁₅, R₁₆, R₁₇, R₁₈, and R₂₀ in the formulae (11G), (12G), (13G), (11G-1), (12G-1), (12G-2), and (13G-1) are each a hydrogen atom, and R₁₂ and R₁₉ are each independently a substituted or unsubstituted alkyl group having 1 to 50 carbon atoms, or a substituted or unsubstituted cycloalkyl group having 3 to 50 ring carbon atoms.

In an exemplary arrangement of the organic EL device according to the exemplary embodiment, in the formula (1D) where n is 1:
when one of R₁₄₁ and R₁₄₂ is a single bond to *a and the other of R₁₄₁ and R₁₄₂ is a single bond to *b, the formula (1D) is represented by a formula (13D) below;
when one of R₁₄₂ and R₁₄₃ is a single bond to *a and the other of R₁₄₂ and R₁₄₃ is a single bond to *b, the formula (1D) is represented by a formula (12D) below; and
when one of R₁₄₃ and R₁₄₄ is a single bond to *a and the other of R₁₄₃ and R₁₄₄ is a single bond to *b, the formula (1D) is represented by a formula (11D) below.

In an exemplary arrangement of the organic EL device according to the first exemplary embodiment, at least one selected from the group consisting of A1, B1, and C1 in the formula (B1) or (B100) is a group represented by any one formula selected from the group consisting of the formulae (11D), (12D), and (13D) below.

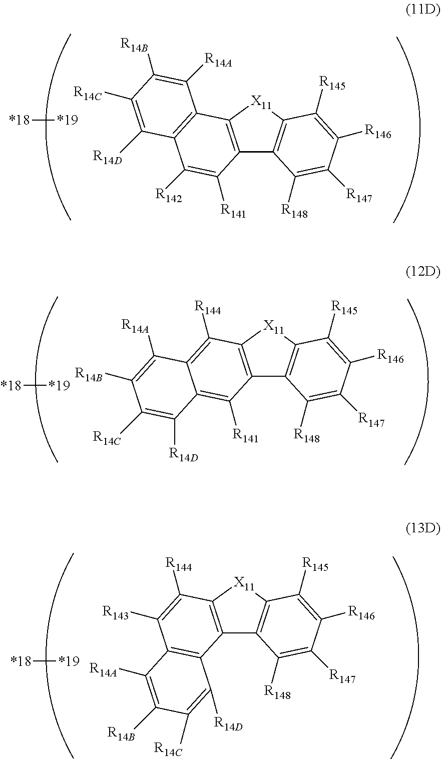

In the formulae (11D), (12D), and (13D):
*18 is a bonding position to L₁₁, L₁₂, or L₁₃;
X₁₁ represents the same as X₁₁ in the formula (1D);
one selected from the group consisting of (iv) R₁₄₁ to R₁₄₈, R_{14A}, R_{14B}, R_{14C}, R_{14D}, and Rc, and (v) Ra and Rb forming neither the substituted or unsubstituted monocyclic ring nor the substituted or unsubstituted fused ring is a single bond to *19;
R₁₄₁ to R₁₄₈, R_{14A}, R_{14B}, R_{14C}, R_{14D}, and Rc not being the single bond to *19, Ra and Rb not being the single bond to *19 and forming neither the substituted or unsubstituted monocyclic ring nor the substituted or unsubstituted fused ring are each independently a hydrogen atom, a substituted or unsubstituted alkyl group having 1 to 10 carbon atoms, a substituted or unsubstituted aryl group having 6 to 12 ring carbon atoms, a substituted or unsubstituted heteroaryl group having 5 to 13 ring atoms.

In an exemplary arrangement of the organic EL device according to the first exemplary embodiment, R₁₄₈ in the formula (11D) is a single bond to *19.

In an exemplary arrangement of the organic EL device of the first exemplary embodiment, X₁₁ in the formula (11D) is an oxygen atom.

In an exemplary arrangement of the organic EL device according to the first exemplary embodiment, n in the formula (1D) is 0.

In an exemplary arrangement of the organic EL device according to the first exemplary embodiment, at least one selected from the group consisting of A₁, B₁, and C₁ in the formula (B1) or (B100) is a group represented by any one formula selected from the group consisting of formulae (14D), (15D), (16D), and (17D) below.

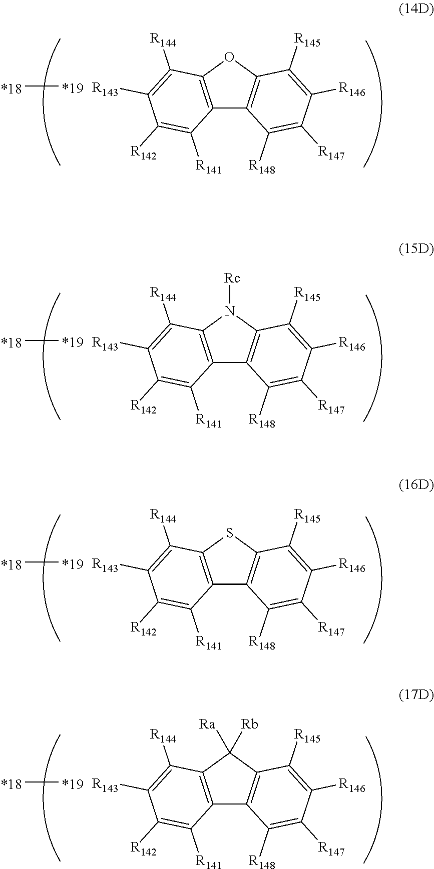

In the formulae (14D), (15D), (16D), and (17D):
*18 is a bonding position to L₁₁, L₁₂, or L₁₃;
one selected from the group consisting of (iv) R₁₄₁ to R₁₄₈, and Rc, and (vii) Ra and Rb forming neither the substituted or unsubstituted monocyclic ring nor the substituted or unsubstituted fused ring is a single bond to *19;
R₁₄₁ to R₁₄₈ and Rc not being the single bond to *19, and Ra and Rb neither being the single bond to *19, nor forming the substituted or unsubstituted monocyclic ring, nor forming the substituted or unsubstituted fused ring are each independently a hydrogen atom, a substituted or unsubstituted alkyl group having 1 to 10 carbon atoms, a substituted or unsubstituted aryl group having 6 to 12 ring carbon atoms, a substituted or unsubstituted heteroaryl group having 5 to 13 ring atoms.

In an exemplary arrangement of the organic EL device according to the first exemplary embodiment, R₁₄₁, R₁₄₄, R₁₄₅, or R₁₄₈ in the formula (14D) is a single bond to *19.

In an exemplary arrangement of the organic EL device according to the first exemplary embodiment, Rc in the formula (15D) is a single bond to *19.

In an exemplary arrangement of the organic EL device according to the first exemplary embodiment, L₁₁, L₁₂, and L₁₃ in the formula (B1) or (B100) are each independently a single bond or a group represented by a formula (L₁), (L₂), (L₃), (L₄), (L₅), (L₆), (L₇), (L₈), (L₉), or (L₁₀) below.

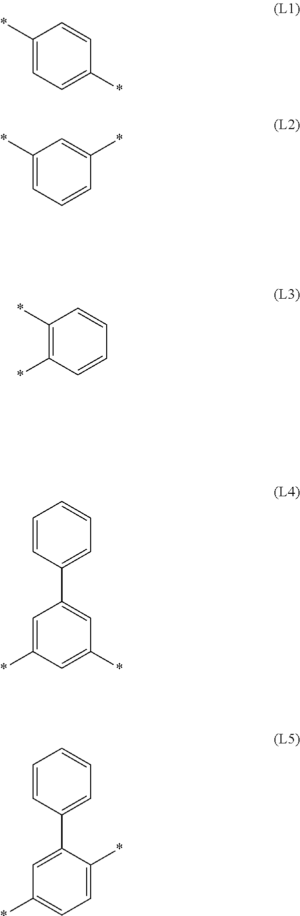 [SMILES: *c1ccc(*)cc1 ; *c1cccc(*)c1 ; *c1ccccc1* ; *c1cc(*)cc(-c2ccccc2)c1 ; *c1ccc(*)c(-c2ccccc2)c1]

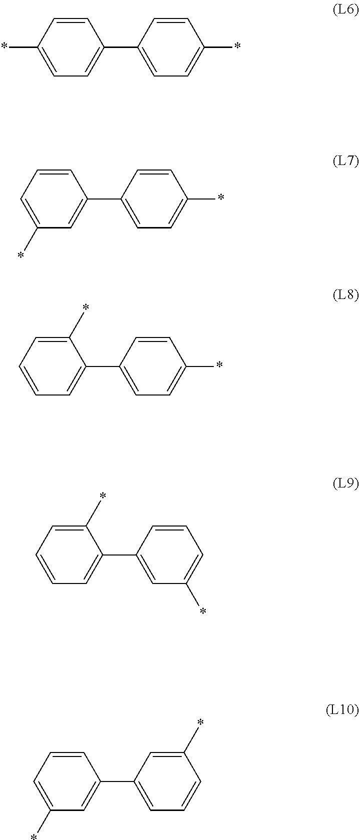 [SMILES: *c1ccc(-c2ccc(*)cc2)cc1 ; *c1ccc(-c2cccc(*)c2)cc1 ; *c1ccc(-c2ccccc2*)cc1 ; *c1cccc(-c2ccccc2*)c1 ; *c1cccc(-c2cccc(*)c2)c1]

In the formulae (L₁) to (L₁₀), each * represents a bonding position. The groups represented by the formulae (L₁) to (L₁₀) each independently may or may not have at least one “optional substituent” described above. The groups represented by the formulae (L₁) to (L₁₀) each independently may have at least one deuterium atom.

In an exemplary arrangement of the organic EL device according to the first exemplary embodiment, when L₁₁ is a single bond, A1 is directly bonded to a nitrogen atom of an amino group in the formula (B1) or (B100); when L₁₂ is a single bond, B1 is directly bonded to a nitrogen atom of an amino group in the formula (B1) or (B100); and when L₁₃ is a single bond, C1 is directly bonded to a nitrogen atom of an amino group in the formula (B1) or (B100).

In an exemplary arrangement of the organic EL device according to the first exemplary embodiment, the hole transporting zone materials (e.g., first hole transporting zone material and second hole transporting zone material) are each independently a compound represented by a formula (B10), (B11), (B12), (B13), (B14), or (B15) below.

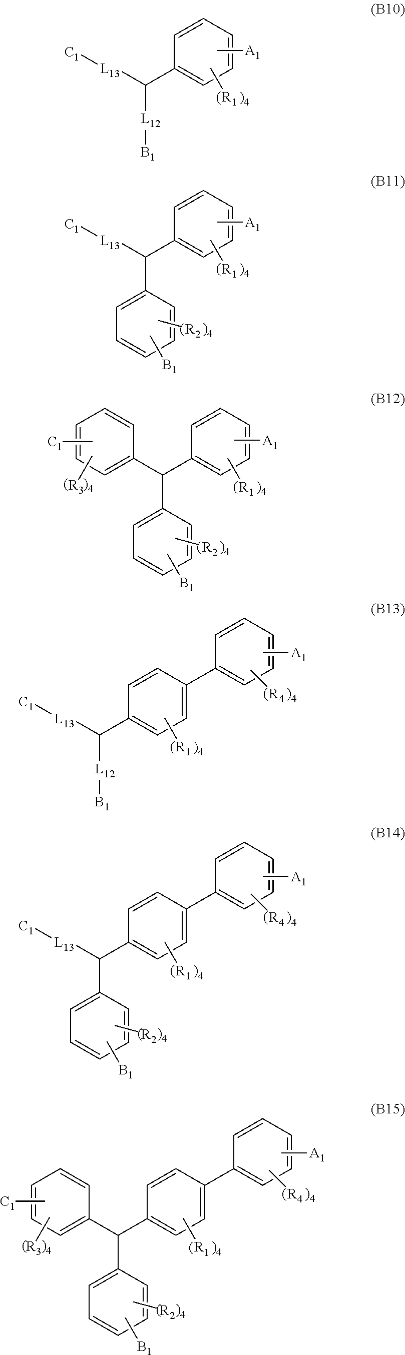

In the formulae (B10), (B11), (B12), (B13), (B14), and (B15):
L₁₁, L₁₂, L₁₃, A1, B1, and C₁ respectively represent the same as L₁₁, L₁₂, L₁₃, A1, B1, and C1 in the formula (B1) or (B100);
R₁, R₂, R₃, and R⁴ are each independently a hydrogen atom, a substituted or unsubstituted alkyl group having 1 to 10 carbon atoms, a substituted or unsubstituted aryl group having 6 to 13 ring carbon atoms, or a substituted or unsubstituted heteroaryl group having 5 to 13 ring atoms;
four R₁ are mutually the same or different;
four R₂ are mutually the same or different;
four R₃ are mutually the same or different; and
four R₄ are mutually the same or different.

In an exemplary arrangement of the organic EL device according to the first exemplary embodiment, the hole transporting zone materials (e.g., first hole transporting zone material and second hole transporting zone material) are each independently a compound represented by a formula (B16), (B17), (B18), (B19), or (B20) below.

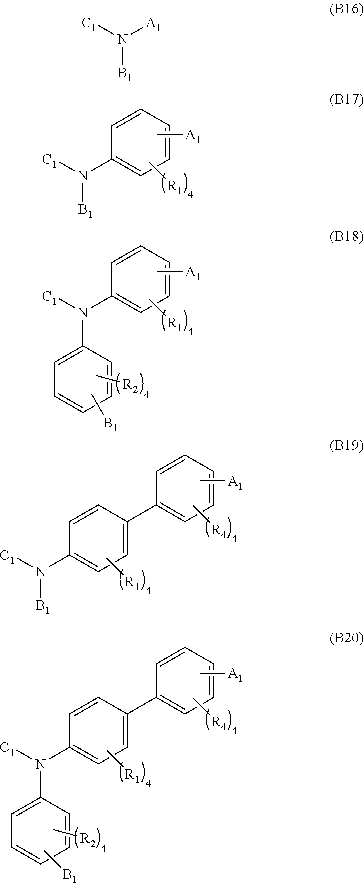

In the formulae (B16), (B17), (B18), (B19), and (B20):
A₁, B₁, and C₁ respectively represent the same as A₁, B₁, and C₁ in the formula (B1) or (B100);
R₁, R₂, R₃, and R₄ are each independently a hydrogen atom, a substituted or unsubstituted alkyl group having 1 to 10 carbon atoms, a substituted or unsubstituted aryl group having 6 to 13 ring carbon atoms, or a substituted or unsubstituted heteroaryl group having 5 to 13 ring atoms; four R₁ are mutually the same or different; four R₂ are mutually the same or different; four R₁ are mutually the same or different; and four R₄ are mutually the same or different.

In an exemplary arrangement of the organic EL device according to the first exemplary embodiment, R₁, R₂, and R₃ in the first hole transporting zone material and the second hole transporting zone material are each a deuterium atom.

In an exemplary arrangement of the organic EL device according to the first exemplary embodiment, at least one selected from the group consisting of A1, B1, and C1 in the formulae (B1), (B100), (B10), (B11), (B12), (B13), (B14), (B15), (B16), (B17), (B18), (B19), and (B20) includes at least one group selected from the group consisting of groups represented by the formulae (1A) and (1B). Hereinafter, “(B10), (B11), (B12), (B13), (B14), (B15), (B16), (B17), (B18), (B19), and (B20)” are occasionally abbreviated as “(B10) to (B20).”

In an exemplary arrangement of the organic EL device according to the first exemplary embodiment, one selected from the group consisting of A1, B1, and C1 in the formulae (B1) and (B10) to (B20) includes at least one group selected from the group consisting of groups represented by the formulae (1A) and (1B), and the remaining two selected from the group consisting of A1, B1, and C1 include at least one group selected from the group consisting of groups represented by the formulae (1D), (11D), (12D), (13D), (14D), (15D), (16D), and (17D).

In an exemplary arrangement of the organic EL device according to the first exemplary embodiment, two selected from the group consisting of A₁, B₁, and C₁ in the formulae (B1), (B100), and (B10) to (B20) include at least one group selected from the group consisting of groups represented by the formulae (1A) and (1B).

In an exemplary arrangement of the organic EL device according to the first exemplary embodiment, two selected from the group consisting of A₁, B₁, and C₁ in the formulae (B1) and (B10) to (B20) each include at least one group selected from the group consisting of groups represented by the formulae (1A) and (1B), and the remaining one selected from the group consisting of A₁, B₁, and C₁ includes at least one group selected from the group consisting of groups represented by the formulae (1D), (11D), (12D), (13D), (14D), (15D), (16D), and (17D).

In an exemplary arrangement of the organic EL device according to the first exemplary embodiment, at least one selected from the group consisting of A₁, B₁, and C₁ in the formulae (B1), (B100), and (B10) to (B20) is a group represented by the formula (1G) and X_{B} is an oxygen atom.

In an exemplary arrangement of the organic EL device according to the first exemplary embodiment, two selected from the group consisting of A₁, B₁, and C₁ in the formulae (B1), (B100), and (B10) to (B20) are each a group represented by the formula (1G) and X_{B} is an oxygen atom.

In an exemplary arrangement of the organic EL device according to the first exemplary embodiment, at least one selected from the group consisting of A₁, B₁, and C₁ in the formulae (B1), (B100), and (B10) to (B20) includes at least one group selected from the group consisting of groups represented by the formulae (11G), (12G), and (13G).

In an exemplary arrangement of the organic EL device according to the first exemplary embodiment, two selected from the group consisting of A₁, B₁, and C₁ in the formulae (B1), (B100), and (B10) to (B20) each include at least one group selected from the group consisting of groups represented by the formulae (11G), (12G), and (13G).

In an exemplary arrangement of the organic EL device according to the first exemplary embodiment, at least one selected from the group consisting of A₁, B₁, and C₁ in the formulae (B1), (B100), and (B10) to (B20) includes at least one group selected from the group consisting of groups represented by the formulae (11G-1), (12G-1), (12G-2), and (13G-1).

In an exemplary arrangement of the organic EL device according to the first exemplary embodiment, two selected from the group consisting of A1, B1, and C1 in the formulae (B1), (B100), and (B10) to (B20) each include at least one group selected from the group consisting of groups represented by the formulae (11G-1), (12G-1), (12G-2), and (13G-1).

In an exemplary arrangement of the organic EL device according to the first exemplary embodiment, at least one selected from the group consisting of A1, B1, and C1 in the formulae (B1), (B100), and (B10) to (B20) has at least one substituted or unsubstituted alkyl group having 1 to 20 carbon atoms (preferably 1 to 6 carbon atoms) as a substituent.

In an exemplary arrangement of the organic EL device according to the first exemplary embodiment, at least one selected from the group consisting of A₁, B₁, and C₁ in the formulae (B1), (B100), and (B10) to (B20) has at least one alkyl group including a branched chain as a substituent.

In an exemplary arrangement of the organic EL device according to the first exemplary embodiment, at least one selected from the group consisting of A₁, B₁, and C₁ in the formulae (B1), (B100), and (B10) to (B20) has at least one tert-butyl group as a substituent.

In an exemplary arrangement of the organic EL device of the first exemplary embodiment, the hole transporting zone material is at least one amine compound selected from the group consisting of a monoamine compound having one substituted or unsubstituted amino group in a molecule, a diamine compound having two substituted or unsubstituted amino groups in a molecule, a triamine compound having three substituted or unsubstituted amino groups in a molecule, and a tetraamine compound having four substituted or unsubstituted amino groups in a molecule.

In an exemplary arrangement of the organic EL device according to the first exemplary embodiment, the first hole transporting zone material and the second hole transporting zone material are each independently a monoamine compound or a diamine compound.

In an exemplary arrangement of the organic EL device according to the first exemplary embodiment, the first hole transporting zone material and the second hole transporting zone material are each independently a monoamine compound.

### Method for Producing Hole Transporting Zone Material According to the Exemplary Embodiment

The hole transporting zone material according to the exemplary embodiment is producible by a known method. The hole transporting zone material according to the exemplary embodiment is also producible based on a known method through a known alternative reaction using a known material(s) tailored for the target compound. Specific Example of Hole Transporting Zone Material according to the Exemplary

### EMBODIMENT

Specific examples of the hole transporting zone material according to the exemplary embodiment include the following compounds. However, the invention is by no means limited to these specific examples.

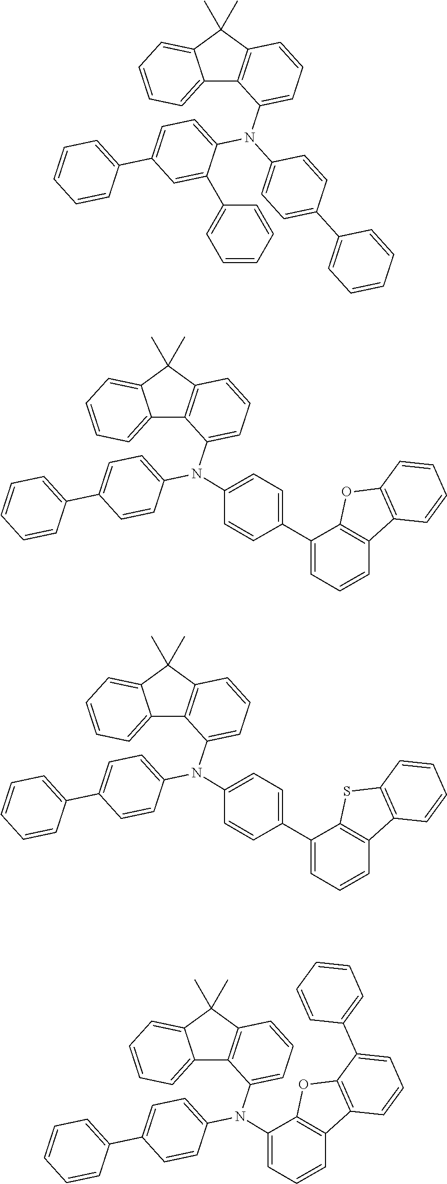 [SMILES: CC1(C)c2ccccc2-c2c(N(c3ccc(-c4ccccc4)cc3)c3ccc(-c4ccccc4)cc3-c3ccccc3)cccc21 ; CC1(C)c2ccccc2-c2c(N(c3ccc(-c4ccccc4)cc3)c3ccc(-c4cccc5c4oc4ccccc45)cc3)cccc21 ; CC1(C)c2ccccc2-c2c(N(c3ccc(-c4ccccc4)cc3)c3ccc(-c4cccc5c4sc4ccccc45)cc3)cccc21 ; CC1(C)c2ccccc2-c2c(N(c3ccc(-c4ccccc4)cc3)c3cccc4c3oc3c(-c5ccccc5)cccc34)cccc21]

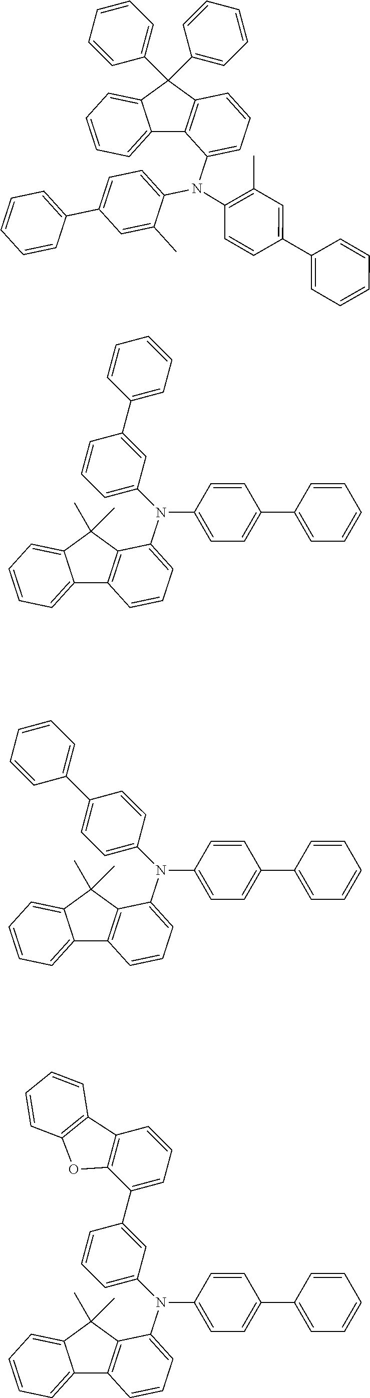

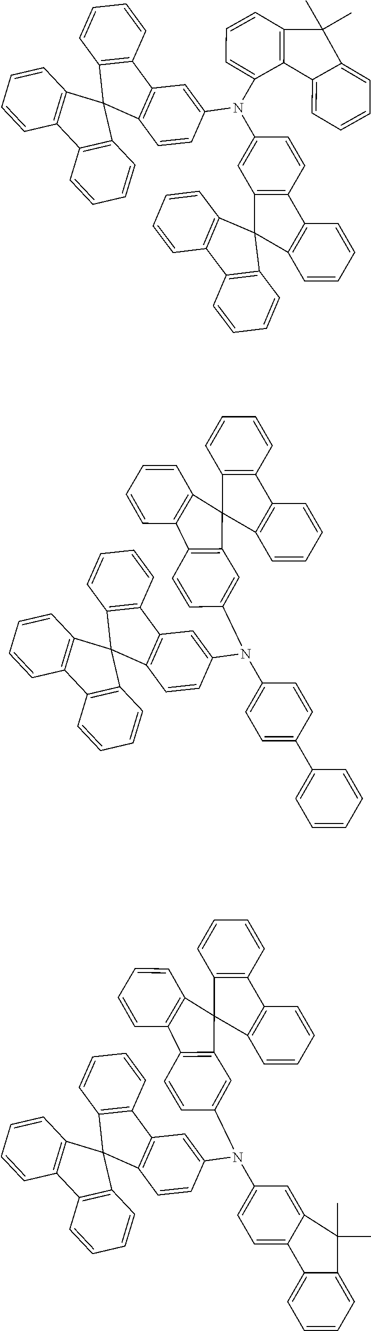 [SMILES: CC1(C)c2ccccc2-c2c(N(c3ccc4c(c3)-c3ccccc3C43c4ccccc4-c4ccccc43)c3ccc4c(c3)C3(c5ccccc5-c5ccccc53)c3ccccc3-4)cccc21 ; c1ccc(-c2ccc(N(c3ccc4c(c3)-c3ccccc3C43c4ccccc4-c4ccccc43)c3ccc4c(c3)C3(c5ccccc5-c5ccccc53)c3ccccc3-4)cc2)cc1 ; CC1(C)c2ccccc2-c2ccc(N(c3ccc4c(c3)-c3ccccc3C43c4ccccc4-c4ccccc43)c3ccc4c(c3)C3(c5ccccc5-c5ccccc53)c3ccccc3-4)cc21]

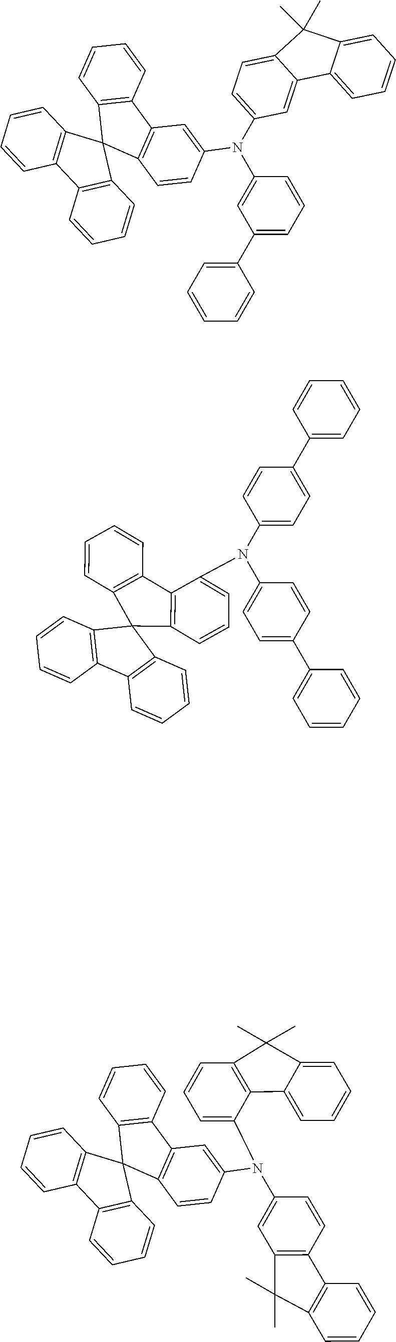 [SMILES: CC1(C)c2ccccc2-c2cc(N(c3cccc(-c4ccccc4)c3)c3ccc4c(c3)-c3ccccc3C43c4ccccc4-c4ccccc43)ccc21 ; c1ccc(-c2ccc(N(c3ccc(-c4ccccc4)cc3)c3cccc4c3-c3ccccc3C43c4ccccc4-c4ccccc43)cc2)cc1 ; CC1(C)c2ccccc2-c2ccc(N(c3ccc4c(c3)-c3ccccc3C43c4ccccc4-c4ccccc43)c3cccc4c3-c3ccccc3C4(C)C)cc21]

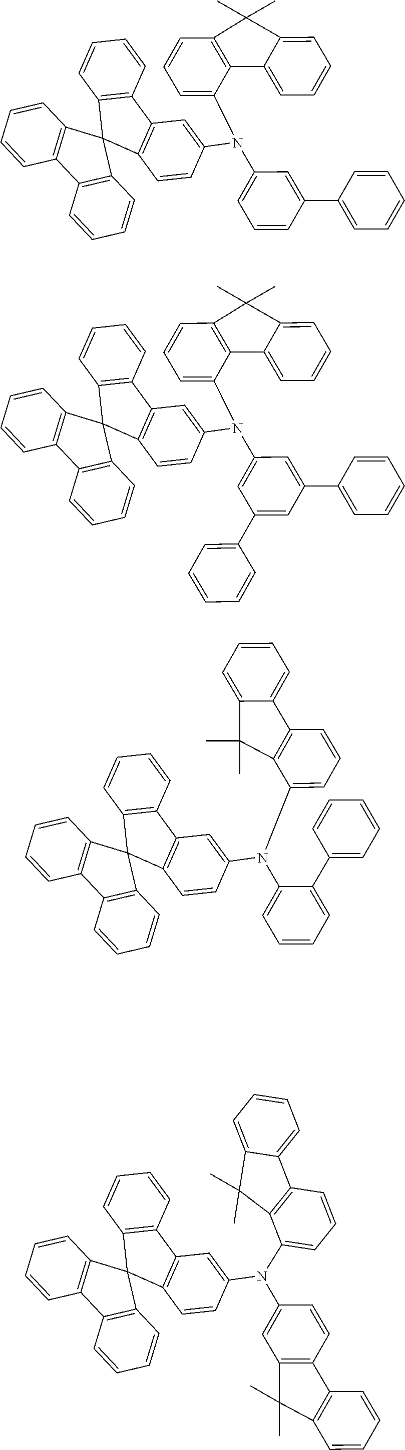

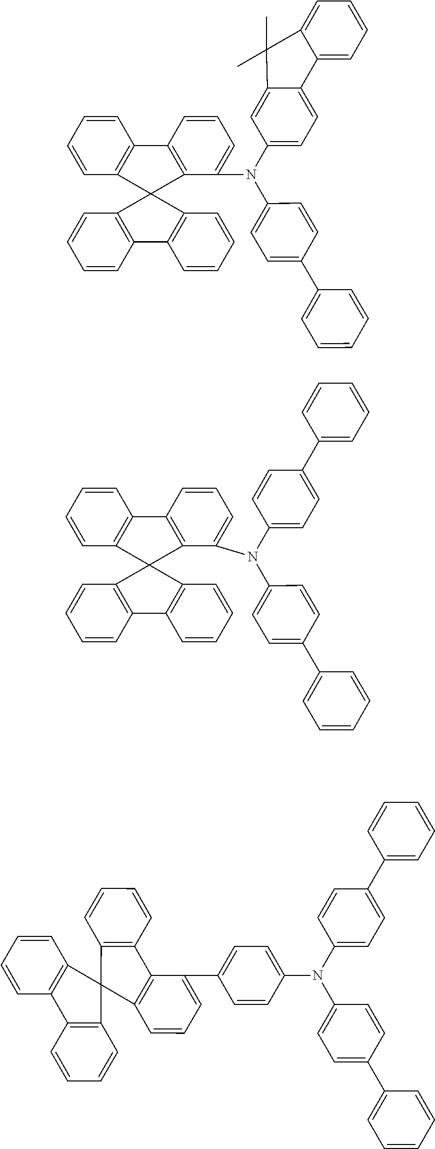

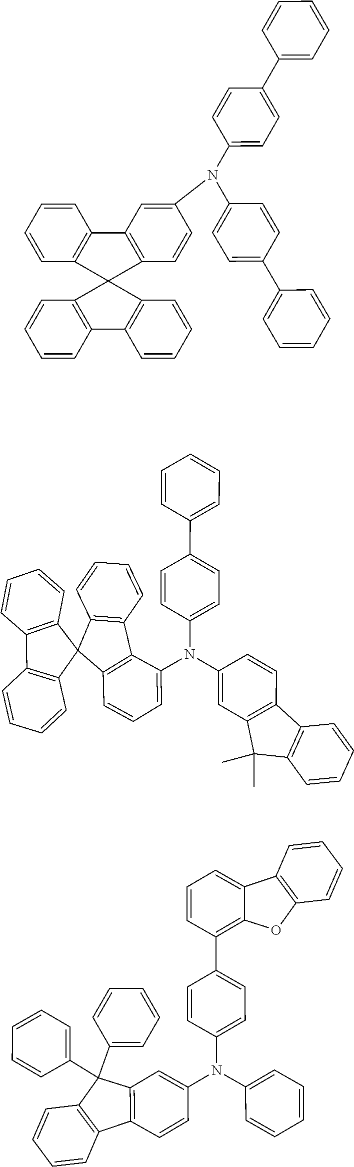 [SMILES: c1ccc(-c2ccc(N(c3ccc(-c4ccccc4)cc3)c3ccc4c(c3)-c3ccccc3C43c4ccccc4-c4ccccc43)cc2)cc1 ; CC1(C)c2ccccc2-c2ccc(N(c3ccc(-c4ccccc4)cc3)c3cccc4c3-c3ccccc3C43c4ccccc4-c4ccccc43)cc21 ; c1ccc(N(c2ccc(-c3cccc4c3oc3ccccc34)cc2)c2ccc3c(c2)C(c2ccccc2)(c2ccccc2)c2ccccc2-3)cc1]

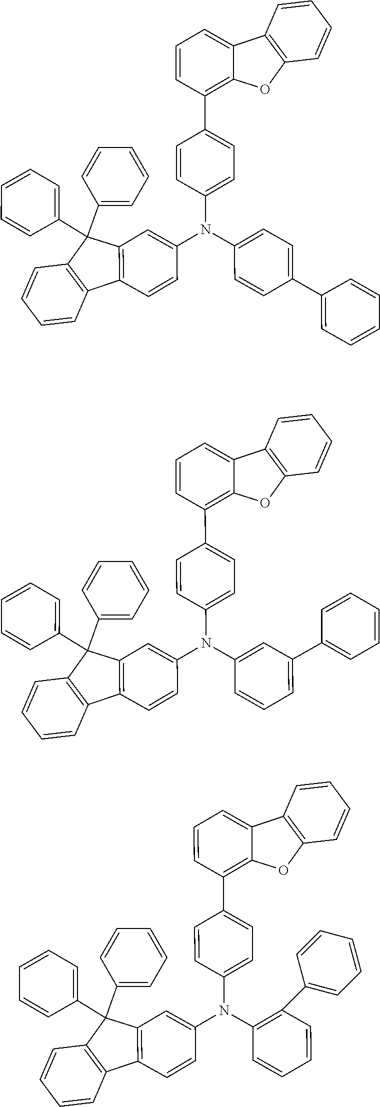 [SMILES: c1ccc(-c2ccc(N(c3ccc(-c4cccc5c4oc4ccccc45)cc3)c3ccc4c(c3)C(c3ccccc3)(c3ccccc3)c3ccccc3-4)cc2)cc1 ; c1ccc(-c2cccc(N(c3ccc(-c4cccc5c4oc4ccccc45)cc3)c3ccc4c(c3)C(c3ccccc3)(c3ccccc3)c3ccccc3-4)c2)cc1 ; c1ccc(-c2ccccc2N(c2ccc(-c3cccc4c3oc3ccccc34)cc2)c2ccc3c(c2)C(c2ccccc2)(c2ccccc2)c2ccccc2-3)cc1]

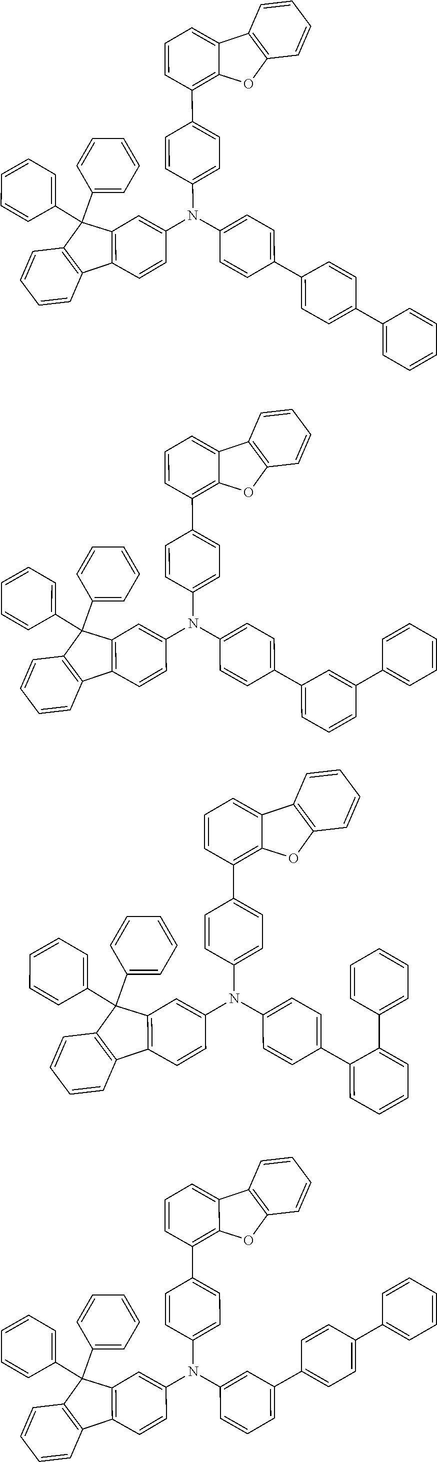

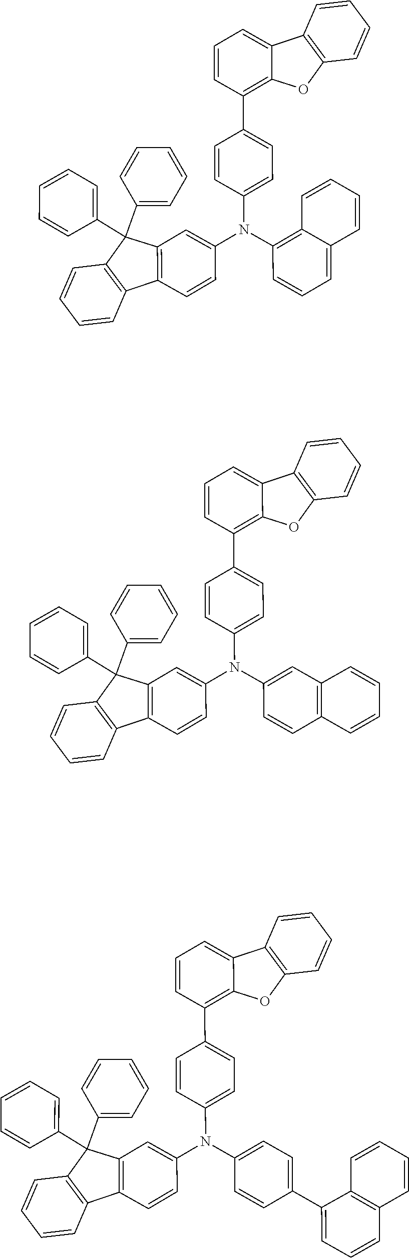 [SMILES: c1ccc(C2(c3ccccc3)c3ccccc3-c3ccc(N(c4ccc(-c5cccc6c5oc5ccccc56)cc4)c4cccc5ccccc45)cc32)cc1 ; c1ccc(C2(c3ccccc3)c3ccccc3-c3ccc(N(c4ccc(-c5cccc6c5oc5ccccc56)cc4)c4ccc5ccccc5c4)cc32)cc1 ; c1ccc(C2(c3ccccc3)c3ccccc3-c3ccc(N(c4ccc(-c5cccc6ccccc56)cc4)c4ccc(-c5cccc6c5oc5ccccc56)cc4)cc32)cc1]

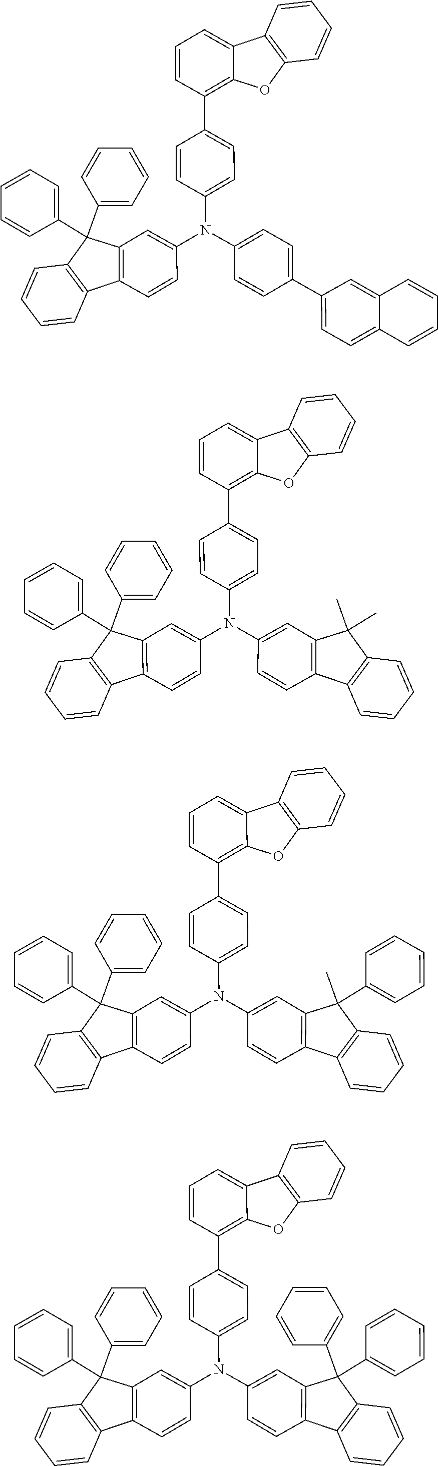 [SMILES: c1ccc(C2(c3ccccc3)c3ccccc3-c3ccc(N(c4ccc(-c5ccc6ccccc6c5)cc4)c4ccc(-c5cccc6c5oc5ccccc56)cc4)cc32)cc1 ; CC1(C)c2ccccc2-c2ccc(N(c3ccc(-c4cccc5c4oc4ccccc45)cc3)c3ccc4c(c3)C(c3ccccc3)(c3ccccc3)c3ccccc3-4)cc21 ; CC1(c2ccccc2)c2ccccc2-c2ccc(N(c3ccc(-c4cccc5c4oc4ccccc45)cc3)c3ccc4c(c3)C(c3ccccc3)(c3ccccc3)c3ccccc3-4)cc21 ; c1ccc(C2(c3ccccc3)c3ccccc3-c3ccc(N(c4ccc(-c5cccc6c5oc5ccccc56)cc4)c4ccc5c(c4)C(c4ccccc4)(c4ccccc4)c4ccccc4-5)cc32)cc1]

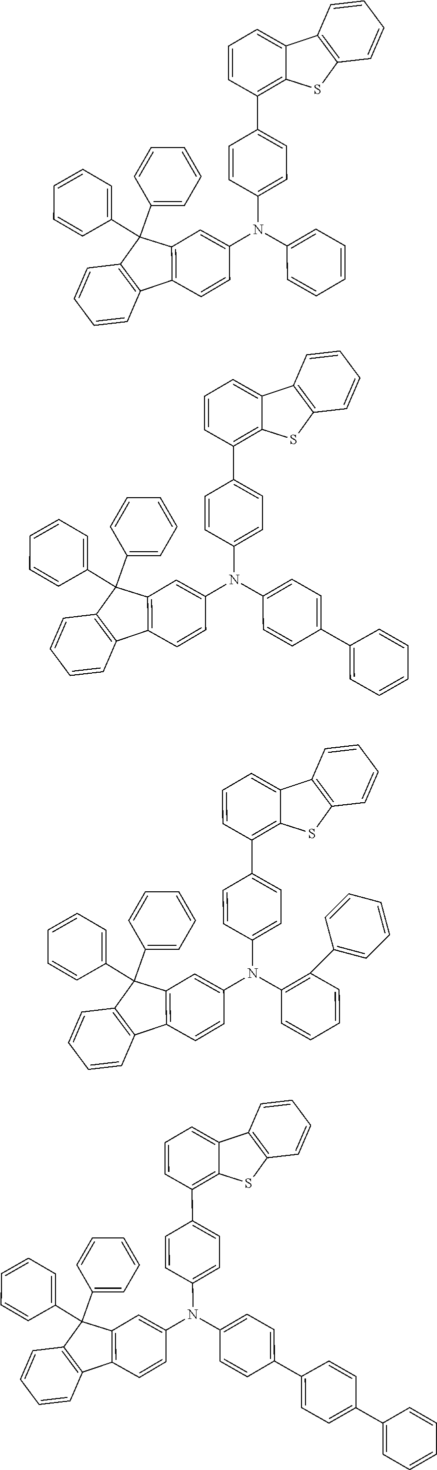 [SMILES: c1ccc(N(c2ccc(-c3cccc4c3sc3ccccc34)cc2)c2ccc3c(c2)C(c2ccccc2)(c2ccccc2)c2ccccc2-3)cc1 ; c1ccc(-c2ccc(N(c3ccc(-c4cccc5c4sc4ccccc45)cc3)c3ccc4c(c3)C(c3ccccc3)(c3ccccc3)c3ccccc3-4)cc2)cc1 ; c1ccc(-c2ccccc2N(c2ccc(-c3cccc4c3sc3ccccc34)cc2)c2ccc3c(c2)C(c2ccccc2)(c2ccccc2)c2ccccc2-3)cc1 ; c1ccc(-c2ccc(-c3ccc(N(c4ccc(-c5cccc6c5sc5ccccc56)cc4)c4ccc5c(c4)C(c4ccccc4)(c4ccccc4)c4ccccc4-5)cc3)cc2)cc1]

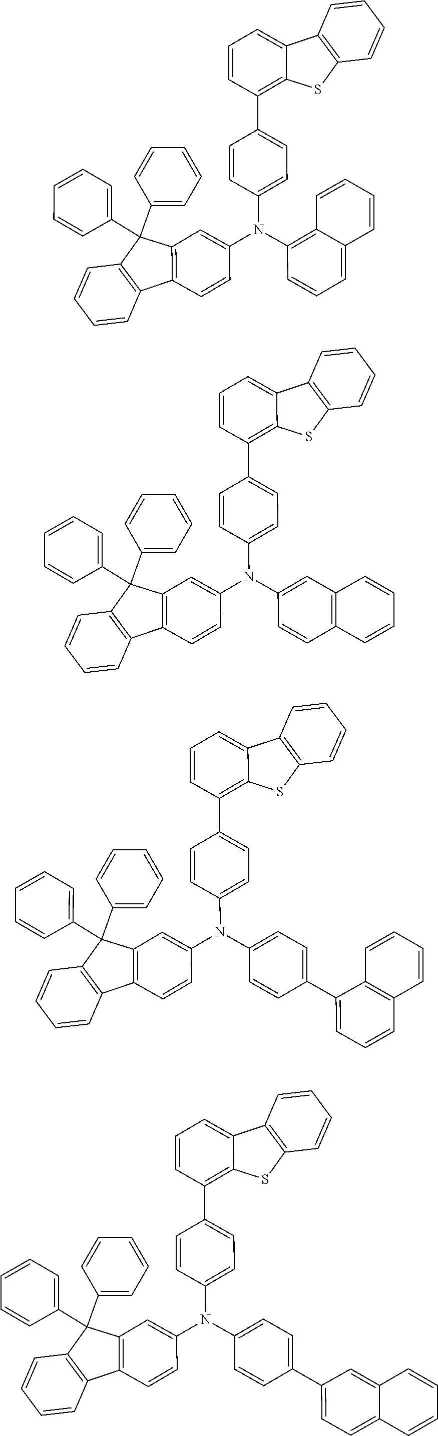 [SMILES: c1ccc(C2(c3ccccc3)c3ccccc3-c3ccc(N(c4ccc(-c5cccc6c5sc5ccccc56)cc4)c4cccc5ccccc45)cc32)cc1 ; c1ccc(C2(c3ccccc3)c3ccccc3-c3ccc(N(c4ccc(-c5cccc6c5sc5ccccc56)cc4)c4ccc5ccccc5c4)cc32)cc1 ; c1ccc(C2(c3ccccc3)c3ccccc3-c3ccc(N(c4ccc(-c5cccc6ccccc56)cc4)c4ccc(-c5cccc6c5sc5ccccc56)cc4)cc32)cc1 ; c1ccc(C2(c3ccccc3)c3ccccc3-c3ccc(N(c4ccc(-c5ccc6ccccc6c5)cc4)c4ccc(-c5cccc6c5sc5ccccc56)cc4)cc32)cc1]

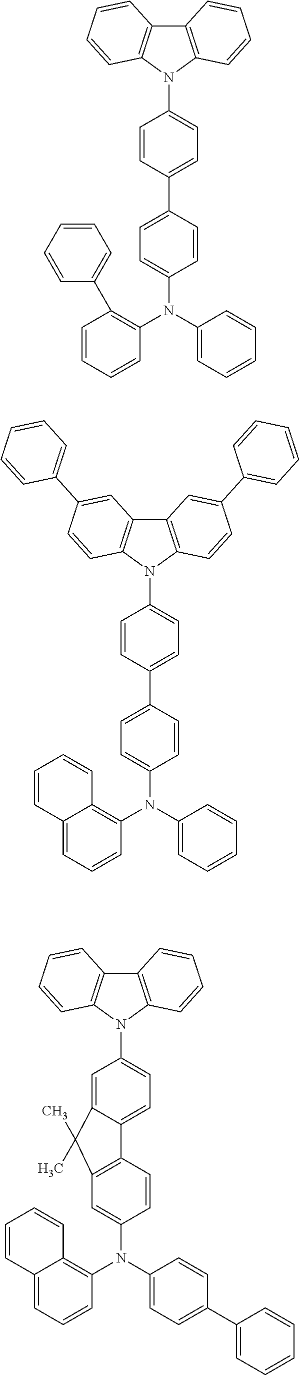 [SMILES: c1ccc(-c2ccccc2N(c2ccccc2)c2ccc(-c3ccc(-n4c5ccccc5c5ccccc54)cc3)cc2)cc1 ; c1ccc(-c2ccc3c(c2)c2cc(-c4ccccc4)ccc2n3-c2ccc(-c3ccc(N(c4ccccc4)c4cccc5ccccc45)cc3)cc2)cc1 ; CC1(C)c2cc(N(c3ccc(-c4ccccc4)cc3)c3cccc4ccccc34)ccc2-c2ccc(-n3c4ccccc4c4ccccc43)cc21]

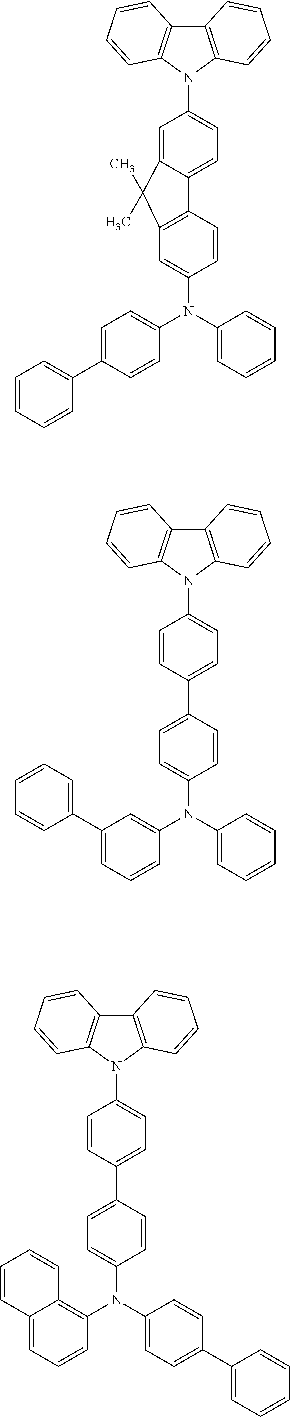 [SMILES: CC1(C)c2cc(N(c3ccccc3)c3ccc(-c4ccccc4)cc3)ccc2-c2ccc(-n3c4ccccc4c4ccccc43)cc21 ; c1ccc(-c2cccc(N(c3ccccc3)c3ccc(-c4ccc(-n5c6ccccc6c6ccccc65)cc4)cc3)c2)cc1 ; c1ccc(-c2ccc(N(c3ccc(-c4ccc(-n5c6ccccc6c6ccccc65)cc4)cc3)c3cccc4ccccc34)cc2)cc1]

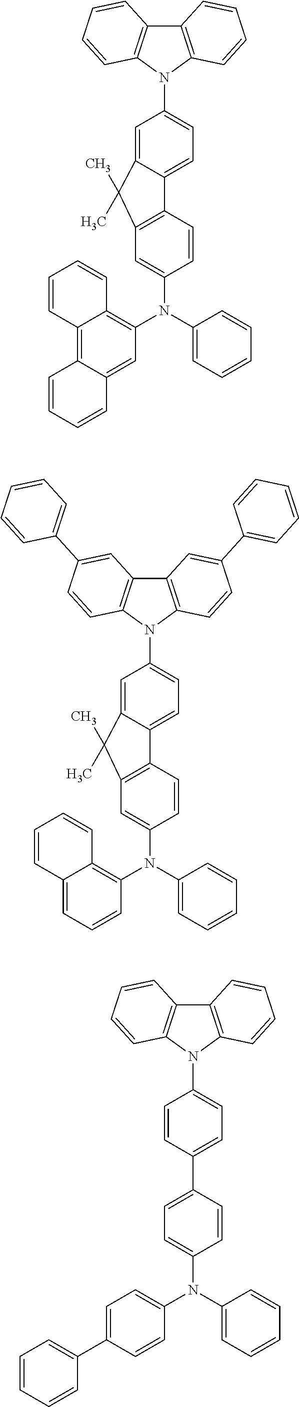 [SMILES: CC1(C)c2cc(N(c3ccccc3)c3cc4ccccc4c4ccccc34)ccc2-c2ccc(-n3c4ccccc4c4ccccc43)cc21 ; CC1(C)c2cc(N(c3ccccc3)c3cccc4ccccc34)ccc2-c2ccc(-n3c4ccc(-c5ccccc5)cc4c4cc(-c5ccccc5)ccc43)cc21 ; c1ccc(-c2ccc(N(c3ccccc3)c3ccc(-c4ccc(-n5c6ccccc6c6ccccc65)cc4)cc3)cc2)cc1]

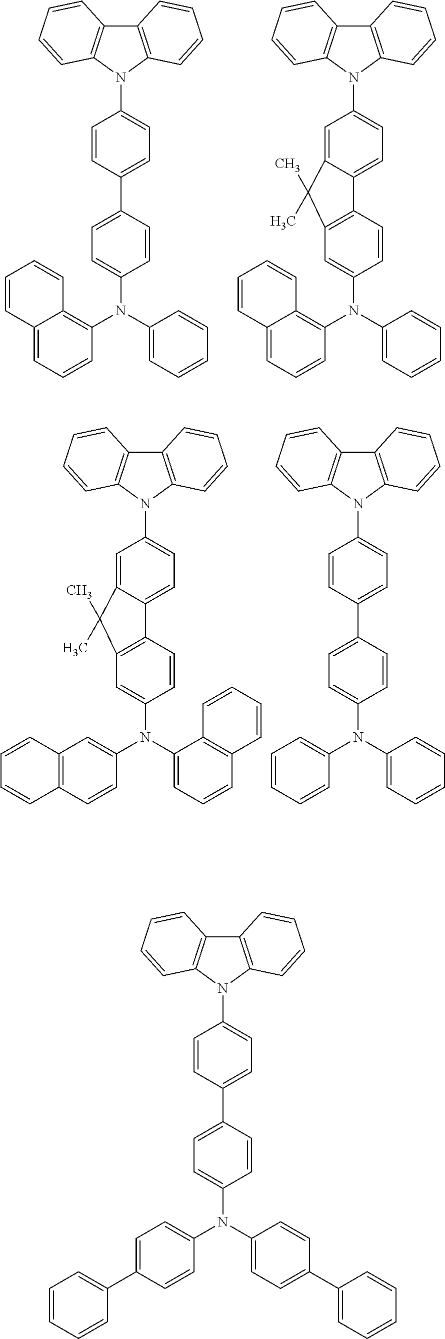

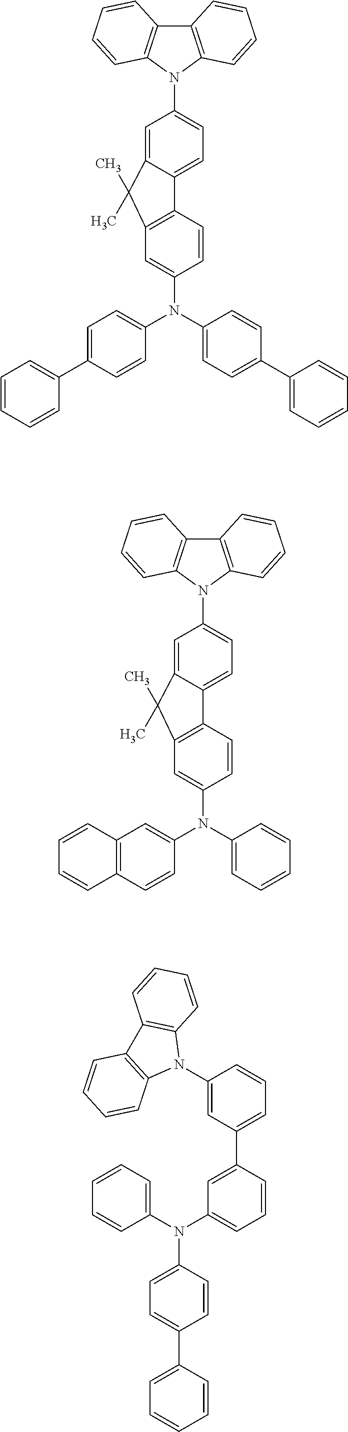 [SMILES: CC1(C)c2cc(N(c3ccc(-c4ccccc4)cc3)c3ccc(-c4ccccc4)cc3)ccc2-c2ccc(-n3c4ccccc4c4ccccc43)cc21 ; CC1(C)c2cc(N(c3ccccc3)c3ccc4ccccc4c3)ccc2-c2ccc(-n3c4ccccc4c4ccccc43)cc21 ; c1ccc(-c2ccc(N(c3ccccc3)c3cccc(-c4cccc(-n5c6ccccc6c6ccccc65)c4)c3)cc2)cc1]

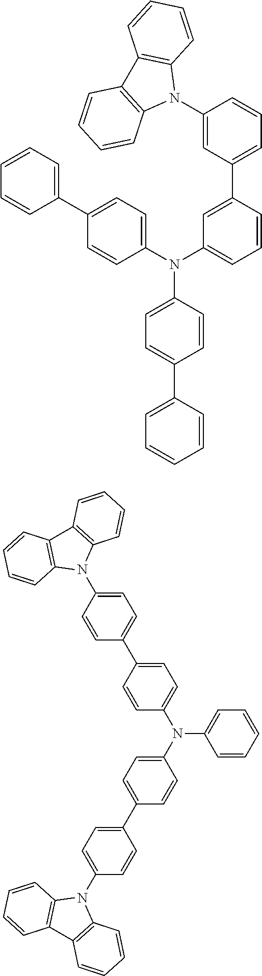 [SMILES: c1ccc(-c2ccc(N(c3ccc(-c4ccccc4)cc3)c3cccc(-c4cccc(-n5c6ccccc6c6ccccc65)c4)c3)cc2)cc1 ; c1ccc(N(c2ccc(-c3ccc(-n4c5ccccc5c5ccccc54)cc3)cc2)c2ccc(-c3ccc(-n4c5ccccc5c5ccccc54)cc3)cc2)cc1]

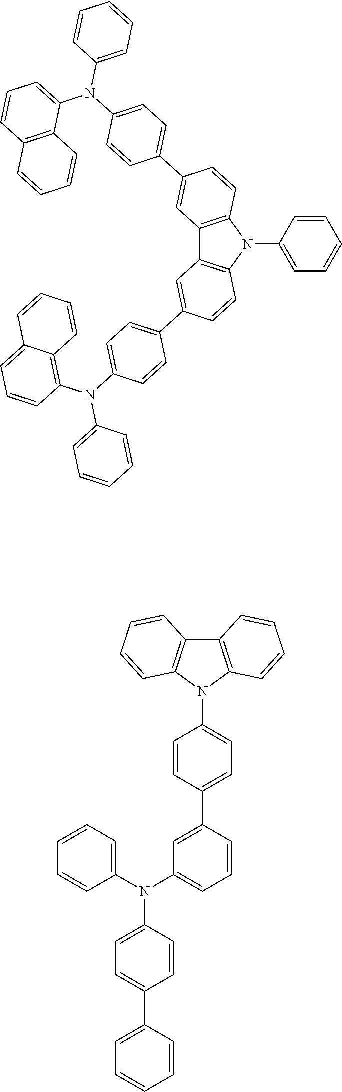 [SMILES: c1ccc(N(c2ccc(-c3ccc4c(c3)c3cc(-c5ccc(N(c6ccccc6)c6cccc7ccccc67)cc5)ccc3n4-c3ccccc3)cc2)c2cccc3ccccc23)cc1 ; c1ccc(-c2ccc(N(c3ccccc3)c3cccc(-c4ccc(-n5c6ccccc6c6ccccc65)cc4)c3)cc2)cc1]

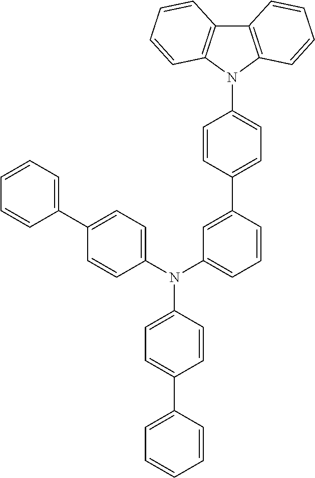 [SMILES: c1ccc(-c2ccc(N(c3ccc(-c4ccccc4)cc3)c3cccc(-c4ccc(-n5c6ccccc6c6ccccc65)cc4)c3)cc2)cc1]

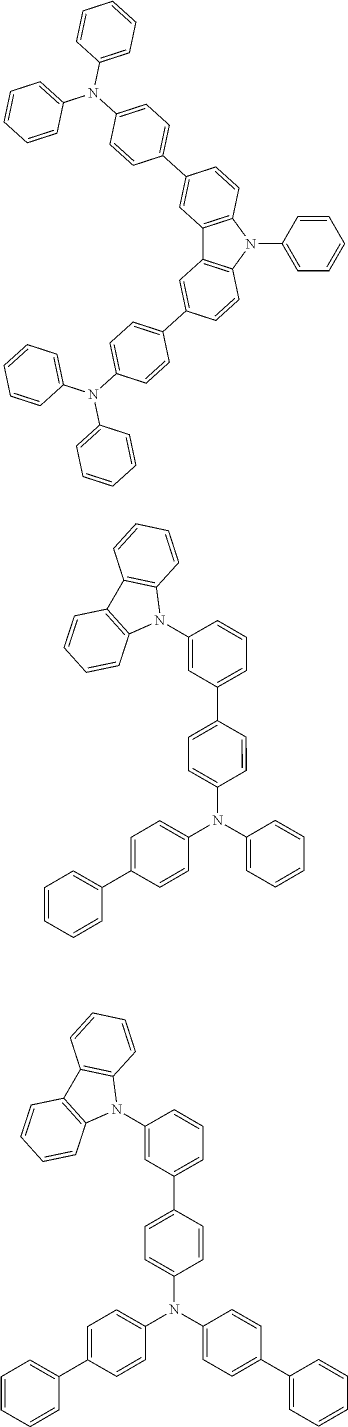

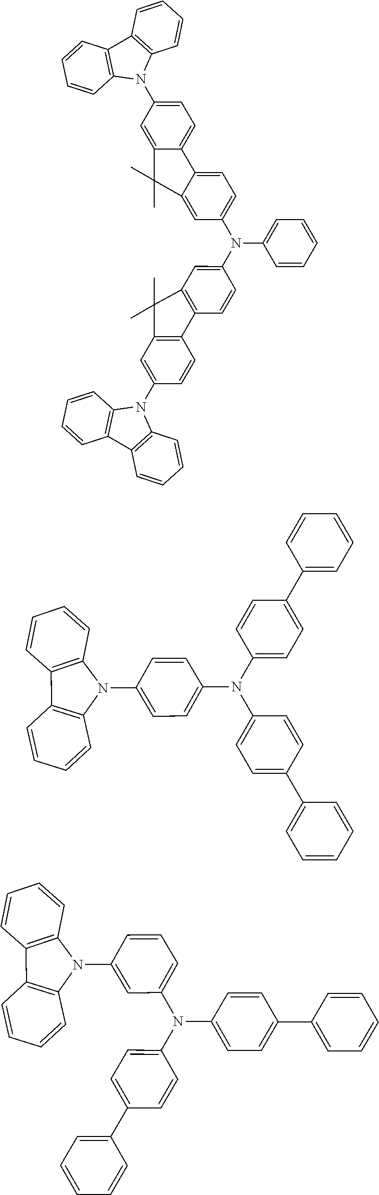 [SMILES: CC1(C)c2cc(N(c3ccccc3)c3ccc4c(c3)C(C)(C)c3cc(-n5c6ccccc6c6ccccc65)ccc3-4)ccc2-c2ccc(-n3c4ccccc4c4ccccc43)cc21 ; c1ccc(-c2ccc(N(c3ccc(-c4ccccc4)cc3)c3ccc(-n4c5ccccc5c5ccccc54)cc3)cc2)cc1 ; c1ccc(-c2ccc(N(c3ccc(-c4ccccc4)cc3)c3cccc(-n4c5ccccc5c5ccccc54)c3)cc2)cc1]

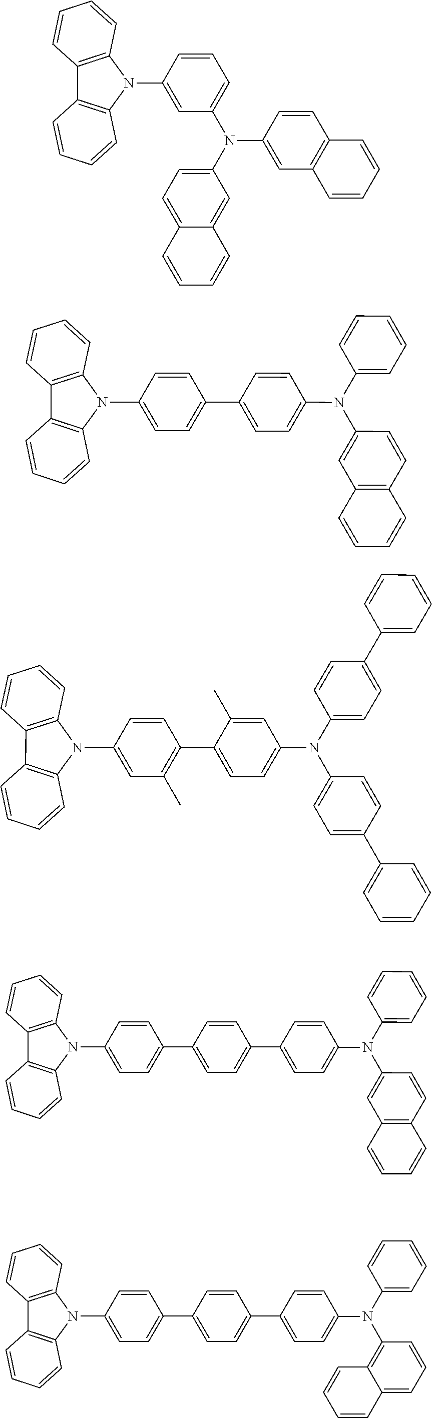

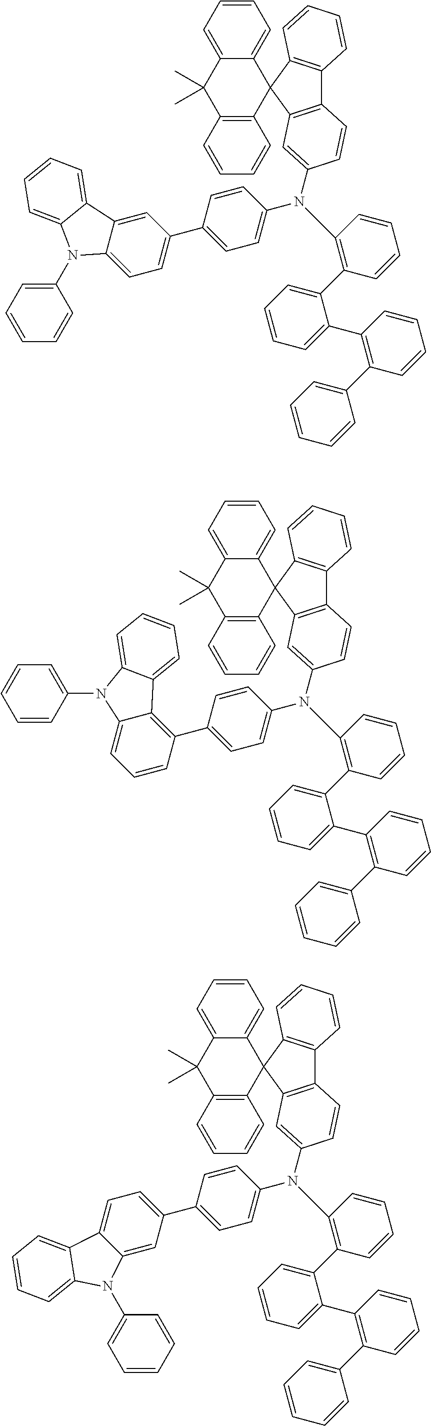 [SMILES: CC1(C)c2ccccc2C2(c3ccccc3-c3ccc(N(c4ccc(-c5ccc6c(c5)c5ccccc5n6-c5ccccc5)cc4)c4ccccc4-c4ccccc4-c4ccccc4-c4ccccc4)cc32)c2ccccc21 ; CC1(C)c2ccccc2C2(c3ccccc3-c3ccc(N(c4ccc(-c5cccc6c5c5ccccc5n6-c5ccccc5)cc4)c4ccccc4-c4ccccc4-c4ccccc4-c4ccccc4)cc32)c2ccccc21 ; CC1(C)c2ccccc2C2(c3ccccc3-c3ccc(N(c4ccc(-c5ccc6c7ccccc7n(-c7ccccc7)c6c5)cc4)c4ccccc4-c4ccccc4-c4ccccc4-c4ccccc4)cc32)c2ccccc21]

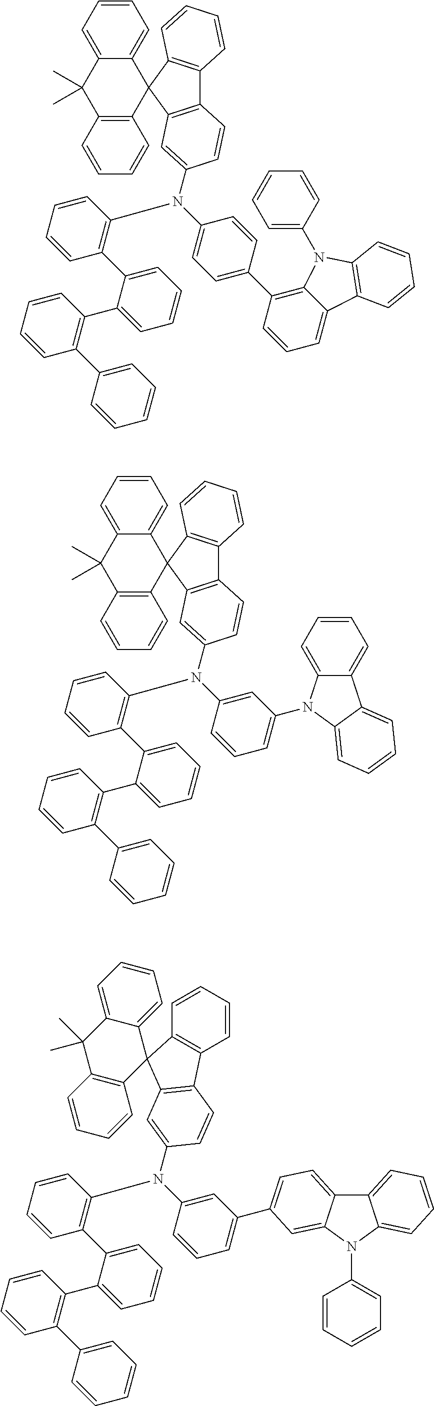 [SMILES: CC1(C)c2ccccc2C2(c3ccccc3-c3ccc(N(c4ccc(-c5cccc6c7ccccc7n(-c7ccccc7)c56)cc4)c4ccccc4-c4ccccc4-c4ccccc4-c4ccccc4)cc32)c2ccccc21 ; CC1(C)c2ccccc2C2(c3ccccc3-c3ccc(N(c4cccc(-n5c6ccccc6c6ccccc65)c4)c4ccccc4-c4ccccc4-c4ccccc4-c4ccccc4)cc32)c2ccccc21 ; CC1(C)c2ccccc2C2(c3ccccc3-c3ccc(N(c4cccc(-c5ccc6c7ccccc7n(-c7ccccc7)c6c5)c4)c4ccccc4-c4ccccc4-c4ccccc4-c4ccccc4)cc32)c2ccccc21]

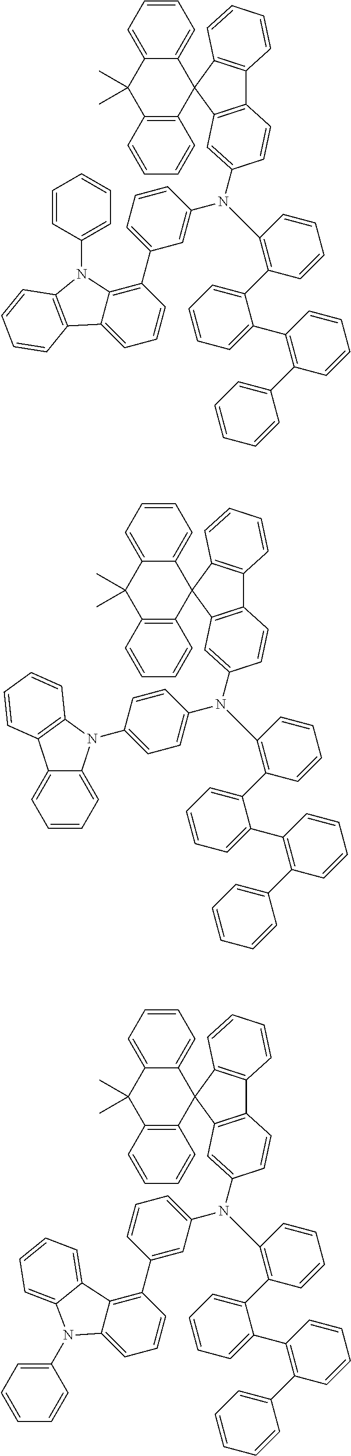 [SMILES: CC1(C)c2ccccc2C2(c3ccccc3-c3ccc(N(c4cccc(-c5cccc6c7ccccc7n(-c7ccccc7)c56)c4)c4ccccc4-c4ccccc4-c4ccccc4-c4ccccc4)cc32)c2ccccc21 ; CC1(C)c2ccccc2C2(c3ccccc3-c3ccc(N(c4ccc(-n5c6ccccc6c6ccccc65)cc4)c4ccccc4-c4ccccc4-c4ccccc4-c4ccccc4)cc32)c2ccccc21 ; CC1(C)c2ccccc2C2(c3ccccc3-c3ccc(N(c4cccc(-c5cccc6c5c5ccccc5n6-c5ccccc5)c4)c4ccccc4-c4ccccc4-c4ccccc4-c4ccccc4)cc32)c2ccccc21]

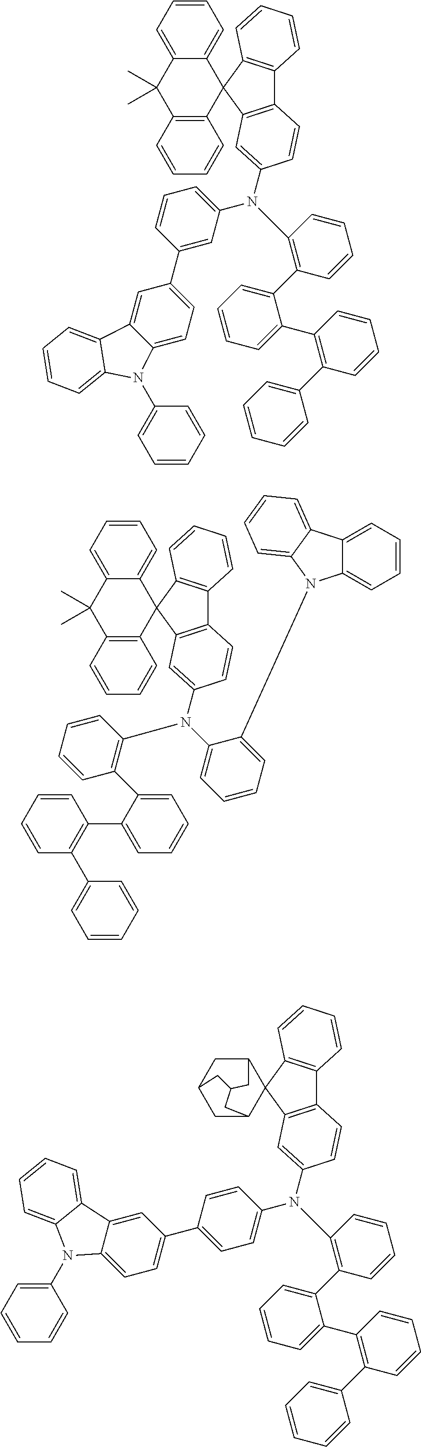 [SMILES: CC1(C)c2ccccc2C2(c3ccccc3-c3ccc(N(c4cccc(-c5ccc6c(c5)c5ccccc5n6-c5ccccc5)c4)c4ccccc4-c4ccccc4-c4ccccc4-c4ccccc4)cc32)c2ccccc21 ; CC1(C)c2ccccc2C2(c3ccccc3-c3ccc(N(c4ccccc4-c4ccccc4-c4ccccc4-c4ccccc4)c4ccccc4-n4c5ccccc5c5ccccc54)cc32)c2ccccc21 ; c1ccc(-c2ccccc2-c2ccccc2-c2ccccc2N(c2ccc(-c3ccc4c(c3)c3ccccc3n4-c3ccccc3)cc2)c2ccc3c(c2)C2(c4ccccc4-3)C3CC4CC(C3)CC2C4)cc1]

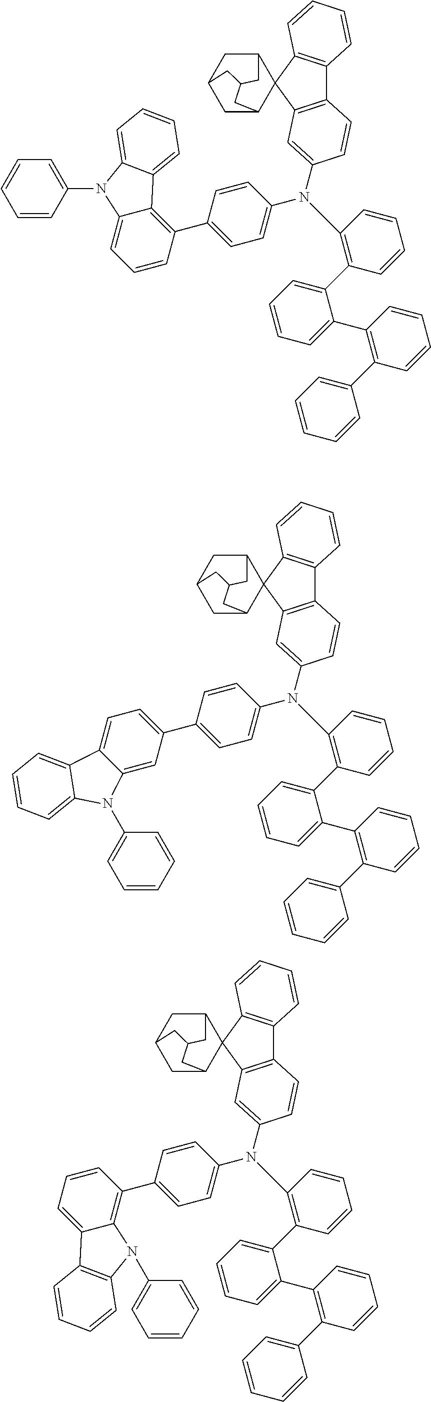

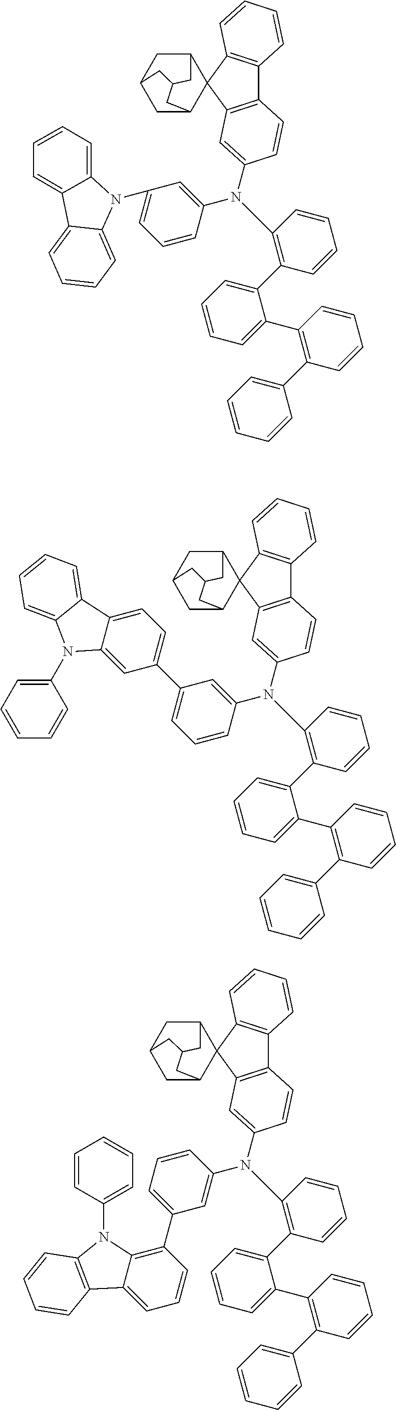

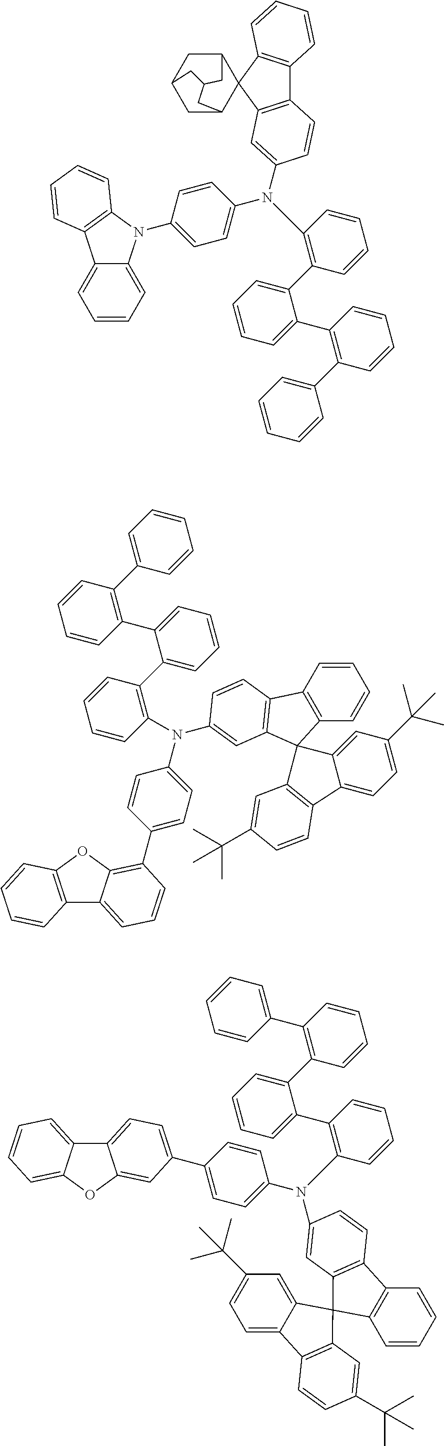 [SMILES: c1ccc(-c2ccccc2-c2ccccc2-c2ccccc2N(c2ccc(-n3c4ccccc4c4ccccc43)cc2)c2ccc3c(c2)C2(c4ccccc4-3)C3CC4CC(C3)CC2C4)cc1 ; CC(C)(C)c1ccc2c(c1)C1(c3ccccc3-c3ccc(N(c4ccc(-c5cccc6c5oc5ccccc56)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5ccc6c(c5)oc5ccccc56)cc4)c4ccccc4-c4ccccc4-c4ccccc4-c4ccccc4)cc31)c1cc(C(C)(C)C)ccc1-2]

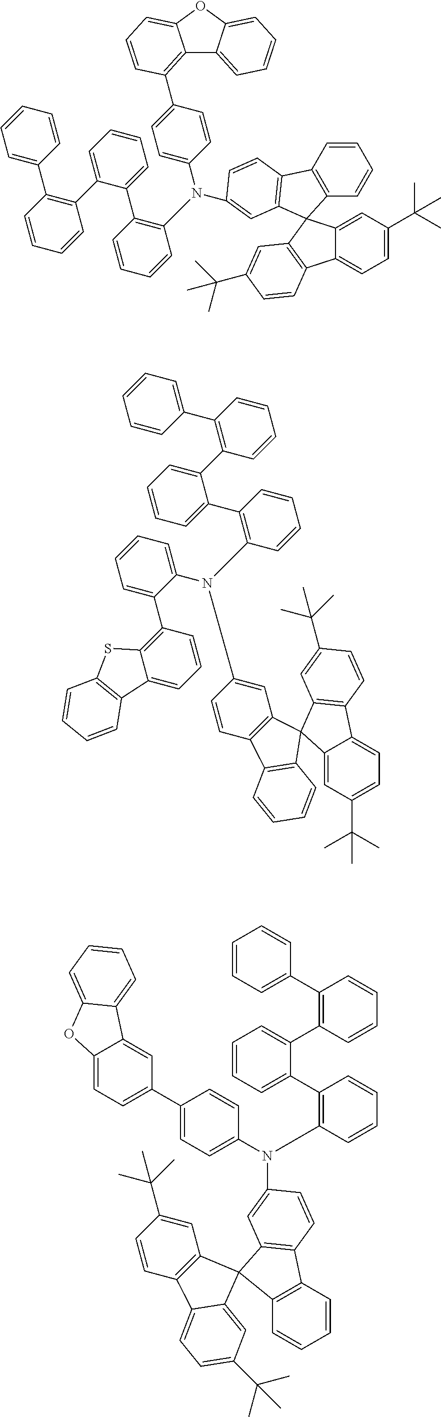 [SMILES: CC(C)(C)c1ccc2c(c1)C1(c3ccccc3-c3ccc(N(c4ccc(-c5cccc6oc7ccccc7c56)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccccc4-c4ccccc4-c4ccccc4-c4ccccc4)c4ccccc4-c4cccc5c4sc4ccccc45)cc31)c1cc(C(C)(C)C)ccc1-2 ; CC(C)(C)c1ccc2c(c1)C1(c3ccccc3-c3ccc(N(c4ccc(-c5ccc6oc7ccccc7c6c5)cc4)c4ccccc4-c4ccccc4-c4ccccc4-c4ccccc4)cc31)c1cc(C(C)(C)C)ccc1-2]

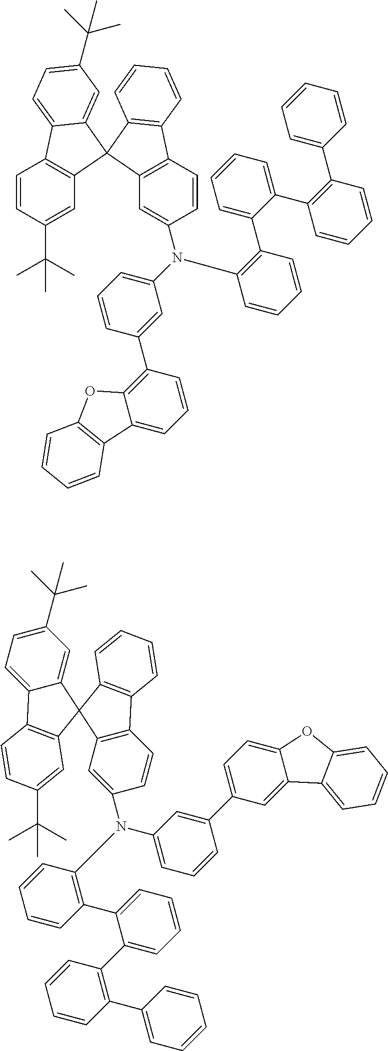 [SMILES: CC(C)(C)c1ccc2c(c1)C1(c3ccccc3-c3ccc(N(c4cccc(-c5cccc6c5oc5ccccc56)c4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4cccc(-c5ccc6oc7ccccc7c6c5)c4)c4ccccc4-c4ccccc4-c4ccccc4-c4ccccc4)cc31)c1cc(C(C)(C)C)ccc1-2]

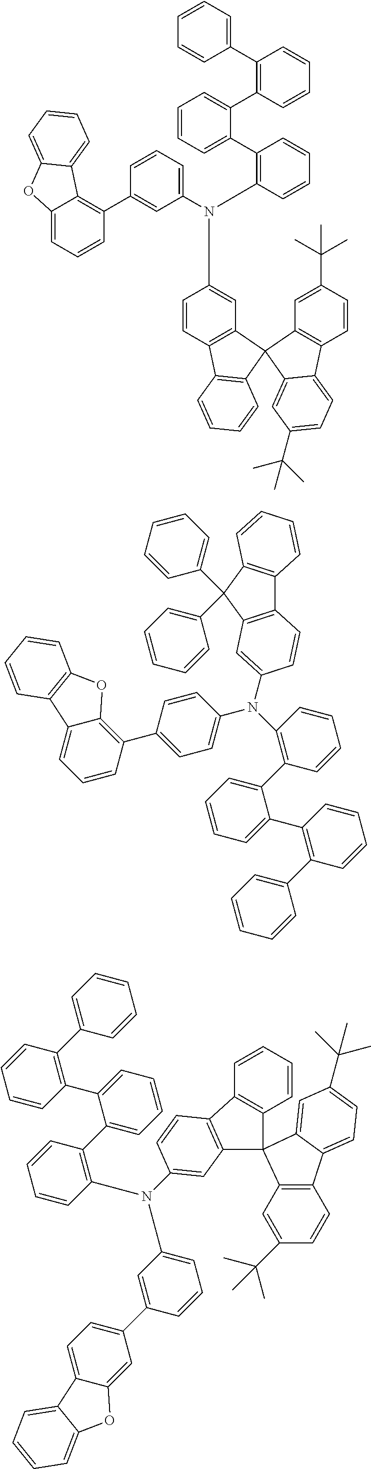

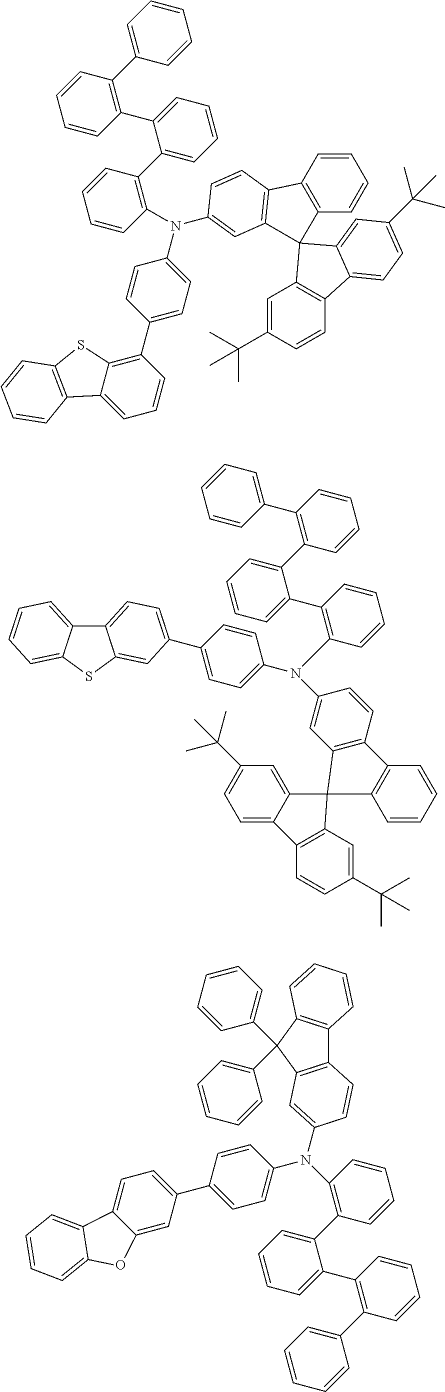 [SMILES: CC(C)(C)c1ccc2c(c1)C1(c3ccccc3-c3ccc(N(c4ccc(-c5cccc6c5sc5ccccc56)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5ccc6c(c5)sc5ccccc56)cc4)c4ccccc4-c4ccccc4-c4ccccc4-c4ccccc4)cc31)c1cc(C(C)(C)C)ccc1-2 ; c1ccc(-c2ccccc2-c2ccccc2-c2ccccc2N(c2ccc(-c3ccc4c(c3)oc3ccccc34)cc2)c2ccc3c(c2)C(c2ccccc2)(c2ccccc2)c2ccccc2-3)cc1]

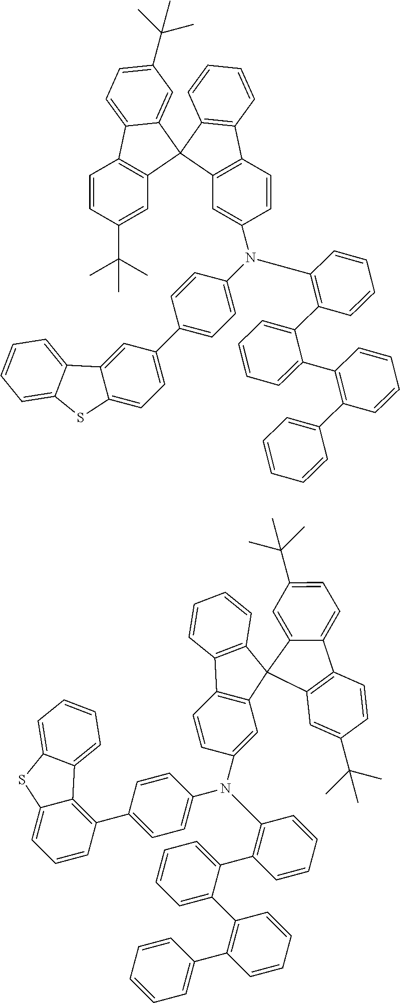

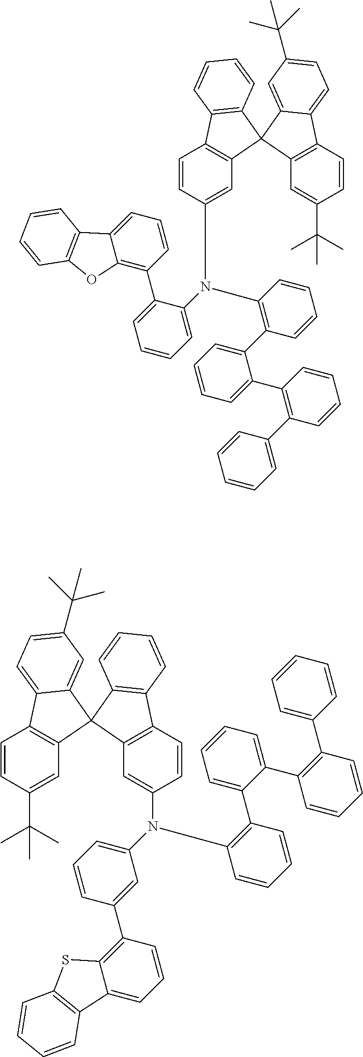 [SMILES: CC(C)(C)c1ccc2c(c1)C1(c3ccccc3-c3ccc(N(c4ccccc4-c4ccccc4-c4ccccc4-c4ccccc4)c4ccccc4-c4cccc5c4oc4ccccc45)cc31)c1cc(C(C)(C)C)ccc1-2 ; CC(C)(C)c1ccc2c(c1)C1(c3ccccc3-c3ccc(N(c4cccc(-c5cccc6c5sc5ccccc56)c4)c4ccccc4-c4ccccc4-c4ccccc4-c4ccccc4)cc31)c1cc(C(C)(C)C)ccc1-2]

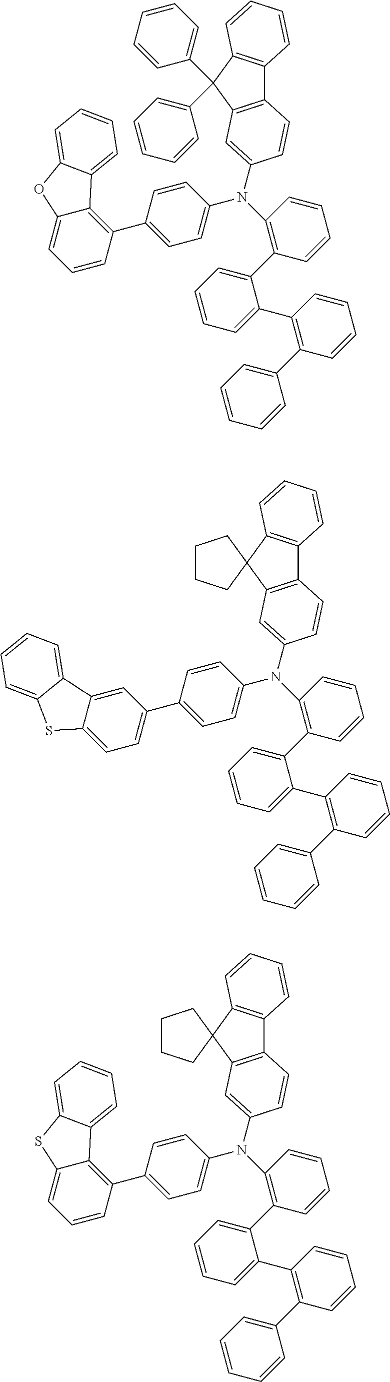 [SMILES: c1ccc(-c2ccccc2-c2ccccc2-c2ccccc2N(c2ccc(-c3cccc4oc5ccccc5c34)cc2)c2ccc3c(c2)C(c2ccccc2)(c2ccccc2)c2ccccc2-3)cc1 ; c1ccc(-c2ccccc2-c2ccccc2-c2ccccc2N(c2ccc(-c3ccc4sc5ccccc5c4c3)cc2)c2ccc3c(c2)C2(CCCC2)c2ccccc2-3)cc1 ; c1ccc(-c2ccccc2-c2ccccc2-c2ccccc2N(c2ccc(-c3cccc4sc5ccccc5c34)cc2)c2ccc3c(c2)C2(CCCC2)c2ccccc2-3)cc1]

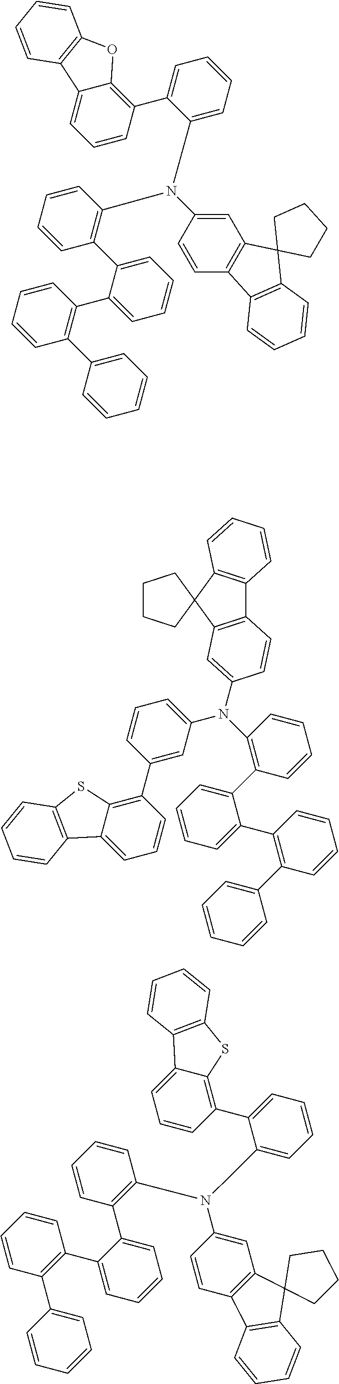

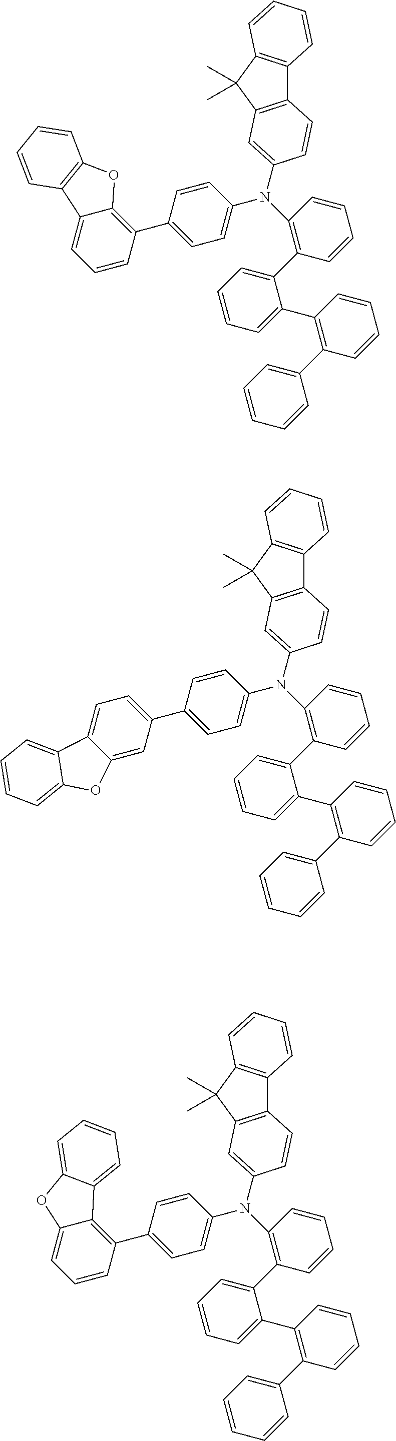 [SMILES: CC1(C)c2ccccc2-c2ccc(N(c3ccc(-c4cccc5c4oc4ccccc45)cc3)c3ccccc3-c3ccccc3-c3ccccc3-c3ccccc3)cc21 ; CC1(C)c2ccccc2-c2ccc(N(c3ccc(-c4ccc5c(c4)oc4ccccc45)cc3)c3ccccc3-c3ccccc3-c3ccccc3-c3ccccc3)cc21 ; CC1(C)c2ccccc2-c2ccc(N(c3ccc(-c4cccc5oc6ccccc6c45)cc3)c3ccccc3-c3ccccc3-c3ccccc3-c3ccccc3)cc21]

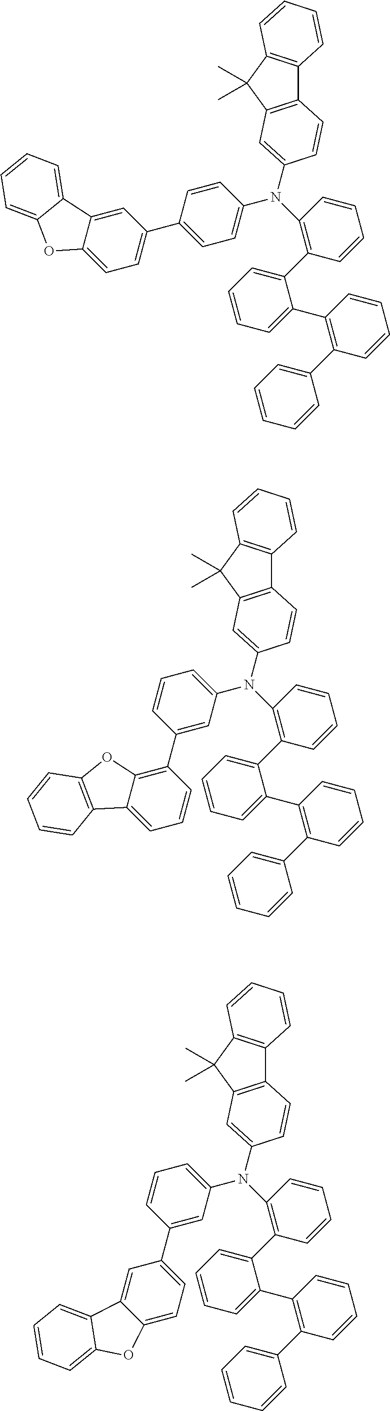 [SMILES: CC1(C)c2ccccc2-c2ccc(N(c3ccc(-c4ccc5oc6ccccc6c5c4)cc3)c3ccccc3-c3ccccc3-c3ccccc3-c3ccccc3)cc21 ; CC1(C)c2ccccc2-c2ccc(N(c3cccc(-c4cccc5c4oc4ccccc45)c3)c3ccccc3-c3ccccc3-c3ccccc3-c3ccccc3)cc21 ; CC1(C)c2ccccc2-c2ccc(N(c3cccc(-c4ccc5oc6ccccc6c5c4)c3)c3ccccc3-c3ccccc3-c3ccccc3-c3ccccc3)cc21]

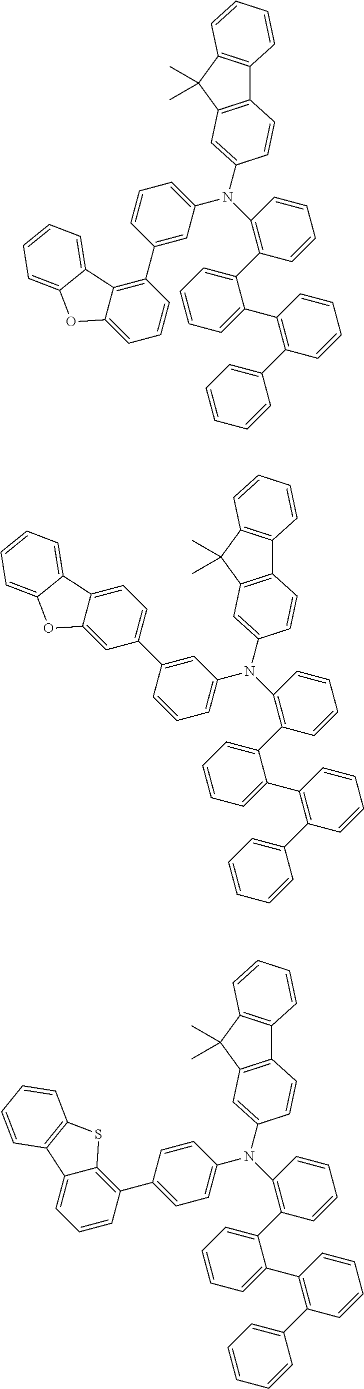 [SMILES: CC1(C)c2ccccc2-c2ccc(N(c3cccc(-c4cccc5oc6ccccc6c45)c3)c3ccccc3-c3ccccc3-c3ccccc3-c3ccccc3)cc21 ; CC1(C)c2ccccc2-c2ccc(N(c3cccc(-c4ccc5c(c4)oc4ccccc45)c3)c3ccccc3-c3ccccc3-c3ccccc3-c3ccccc3)cc21 ; CC1(C)c2ccccc2-c2ccc(N(c3ccc(-c4cccc5c4sc4ccccc45)cc3)c3ccccc3-c3ccccc3-c3ccccc3-c3ccccc3)cc21]

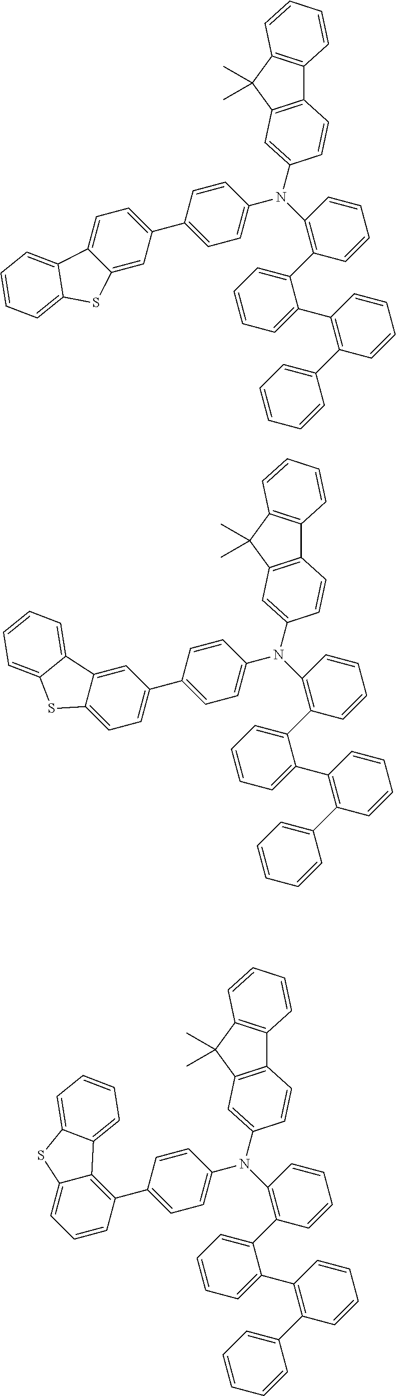

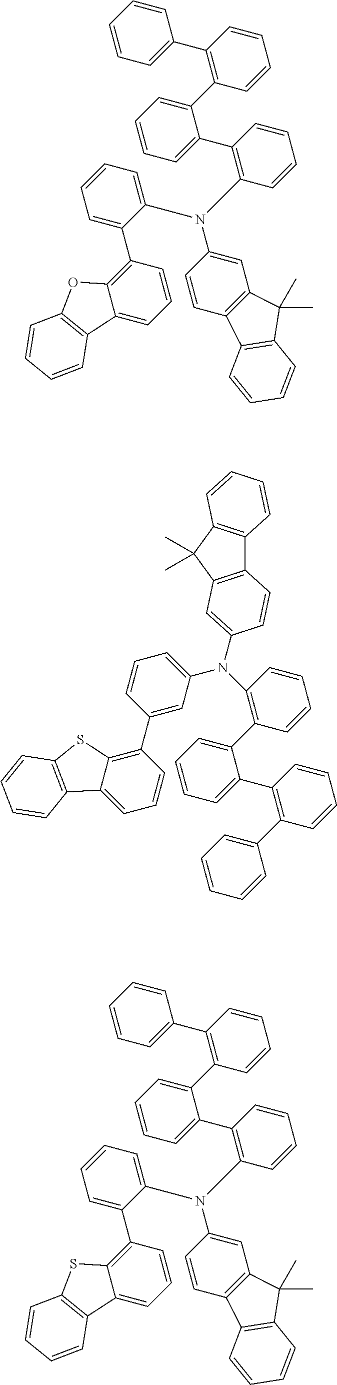 [SMILES: CC1(C)c2ccccc2-c2ccc(N(c3ccccc3-c3ccccc3-c3ccccc3-c3ccccc3)c3ccccc3-c3cccc4c3oc3ccccc34)cc21 ; CC1(C)c2ccccc2-c2ccc(N(c3cccc(-c4cccc5c4sc4ccccc45)c3)c3ccccc3-c3ccccc3-c3ccccc3-c3ccccc3)cc21 ; CC1(C)c2ccccc2-c2ccc(N(c3ccccc3-c3ccccc3-c3ccccc3-c3ccccc3)c3ccccc3-c3cccc4c3sc3ccccc34)cc21]

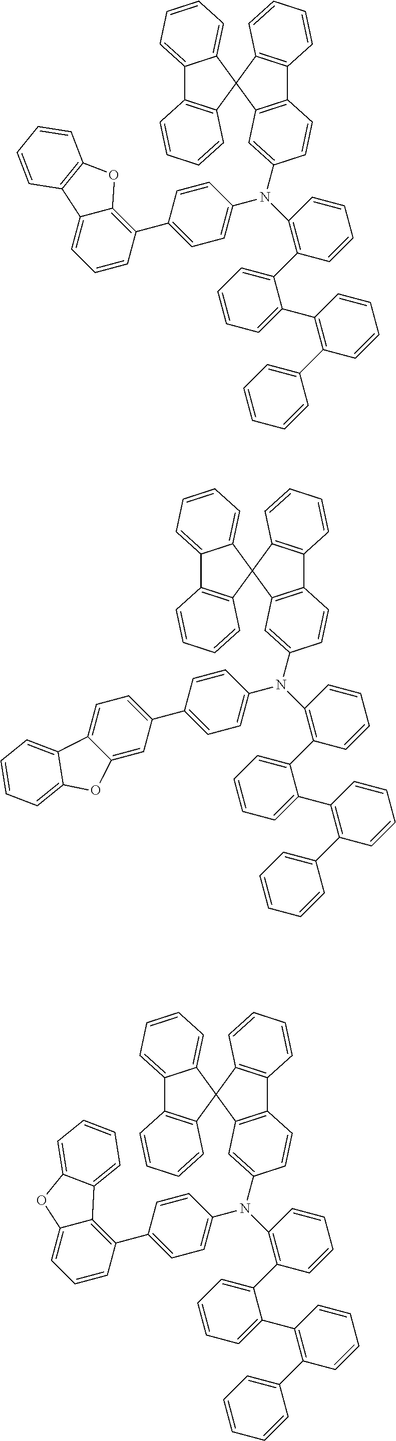 [SMILES: c1ccc(-c2ccccc2-c2ccccc2-c2ccccc2N(c2ccc(-c3cccc4c3oc3ccccc34)cc2)c2ccc3c(c2)C2(c4ccccc4-c4ccccc42)c2ccccc2-3)cc1 ; c1ccc(-c2ccccc2-c2ccccc2-c2ccccc2N(c2ccc(-c3ccc4c(c3)oc3ccccc34)cc2)c2ccc3c(c2)C2(c4ccccc4-c4ccccc42)c2ccccc2-3)cc1 ; c1ccc(-c2ccccc2-c2ccccc2-c2ccccc2N(c2ccc(-c3cccc4oc5ccccc5c34)cc2)c2ccc3c(c2)C2(c4ccccc4-c4ccccc42)c2ccccc2-3)cc1]

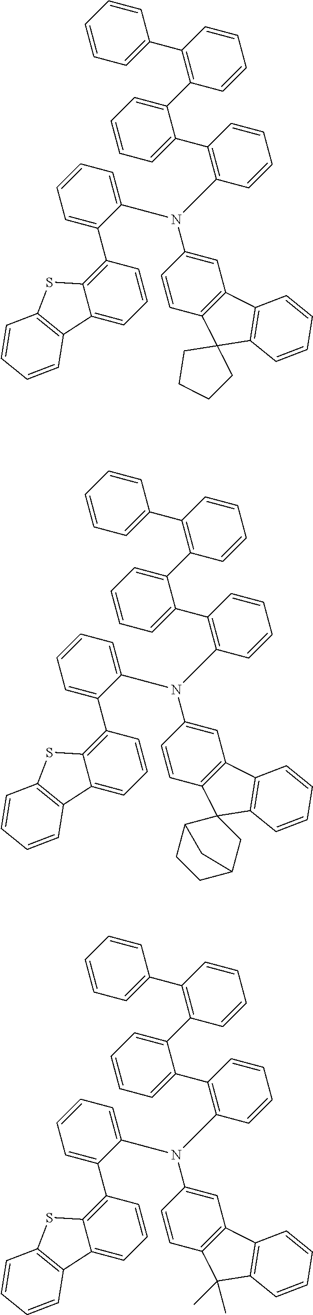 [SMILES: c1ccc(-c2ccccc2-c2ccccc2-c2ccccc2N(c2ccc3c(c2)-c2ccccc2C32CCCC2)c2ccccc2-c2cccc3c2sc2ccccc23)cc1 ; c1ccc(-c2ccccc2-c2ccccc2-c2ccccc2N(c2ccc3c(c2)-c2ccccc2C32CC3CCC2C3)c2ccccc2-c2cccc3c2sc2ccccc23)cc1 ; CC1(C)c2ccccc2-c2cc(N(c3ccccc3-c3ccccc3-c3ccccc3-c3ccccc3)c3ccccc3-c3cccc4c3sc3ccccc34)ccc21]

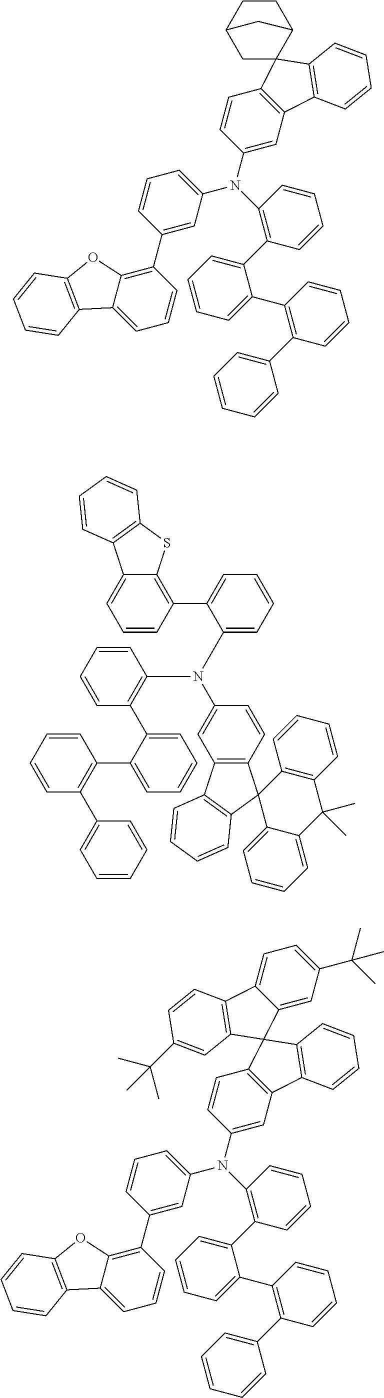 [SMILES: c1ccc(-c2ccccc2-c2ccccc2-c2ccccc2N(c2cccc(-c3cccc4c3oc3ccccc34)c2)c2ccc3c(c2)-c2ccccc2C32CC3CCC2C3)cc1 ; CC1(C)c2ccccc2C2(c3ccccc3-c3cc(N(c4ccccc4-c4ccccc4-c4ccccc4-c4ccccc4)c4ccccc4-c4cccc5c4sc4ccccc45)ccc32)c2ccccc21 ; CC(C)(C)c1ccc2c(c1)C1(c3ccccc3-c3cc(N(c4cccc(-c5cccc6c5oc5ccccc56)c4)c4ccccc4-c4ccccc4-c4ccccc4-c4ccccc4)ccc31)c1cc(C(C)(C)C)ccc1-2]

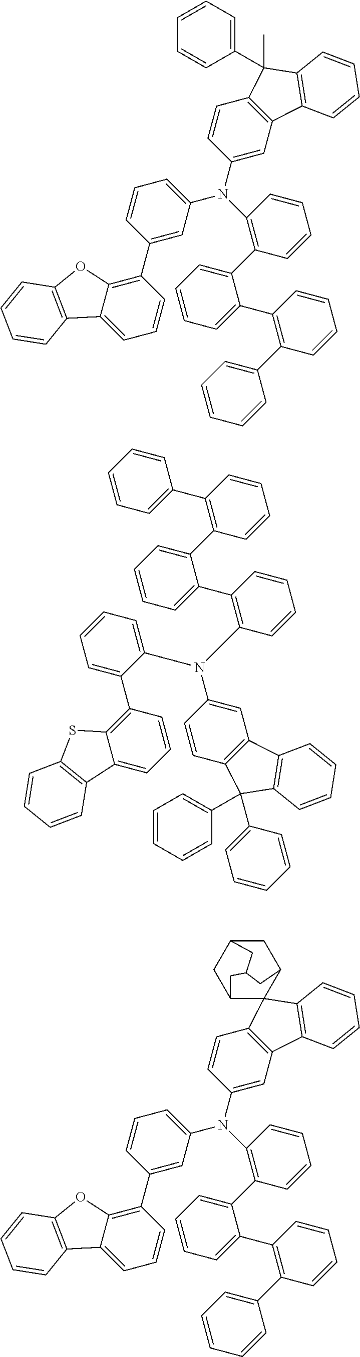 [SMILES: CC1(c2ccccc2)c2ccccc2-c2cc(N(c3cccc(-c4cccc5c4oc4ccccc45)c3)c3ccccc3-c3ccccc3-c3ccccc3-c3ccccc3)ccc21 ; c1ccc(-c2ccccc2-c2ccccc2-c2ccccc2N(c2ccc3c(c2)-c2ccccc2C3(c2ccccc2)c2ccccc2)c2ccccc2-c2cccc3c2sc2ccccc23)cc1 ; c1ccc(-c2ccccc2-c2ccccc2-c2ccccc2N(c2cccc(-c3cccc4c3oc3ccccc34)c2)c2ccc3c(c2)-c2ccccc2C32C3CC4CC(C3)CC2C4)cc1]

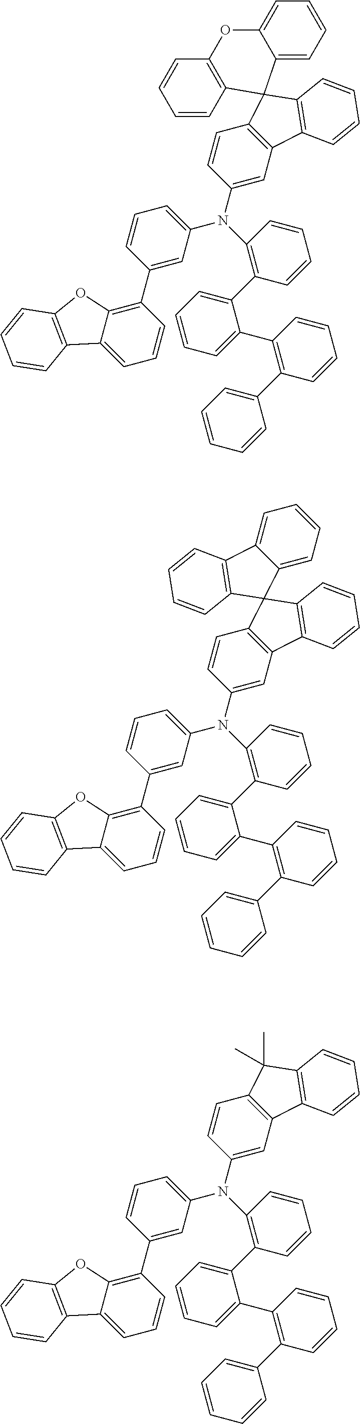 [SMILES: c1ccc(-c2ccccc2-c2ccccc2-c2ccccc2N(c2cccc(-c3cccc4c3oc3ccccc34)c2)c2ccc3c(c2)-c2ccccc2C32c3ccccc3Oc3ccccc32)cc1 ; c1ccc(-c2ccccc2-c2ccccc2-c2ccccc2N(c2cccc(-c3cccc4c3oc3ccccc34)c2)c2ccc3c(c2)-c2ccccc2C32c3ccccc3-c3ccccc32)cc1 ; CC1(C)c2ccccc2-c2cc(N(c3cccc(-c4cccc5c4oc4ccccc45)c3)c3ccccc3-c3ccccc3-c3ccccc3-c3ccccc3)ccc21]

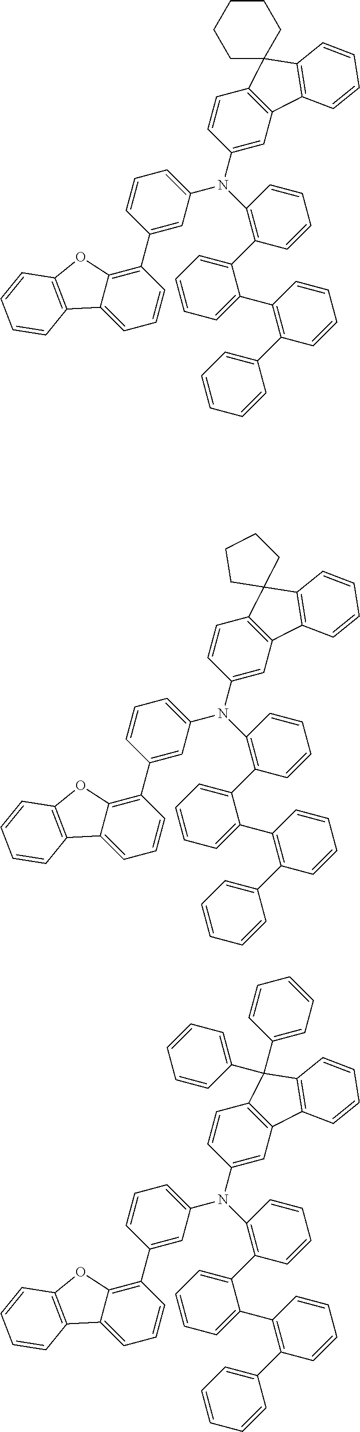

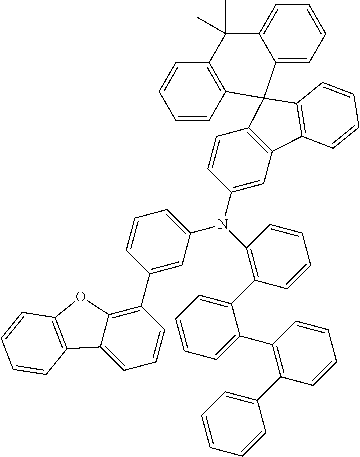 [SMILES: CC1(C)c2ccccc2C2(c3ccccc3-c3cc(N(c4cccc(-c5cccc6c5oc5ccccc56)c4)c4ccccc4-c4ccccc4-c4ccccc4-c4ccccc4)ccc32)c2ccccc21]

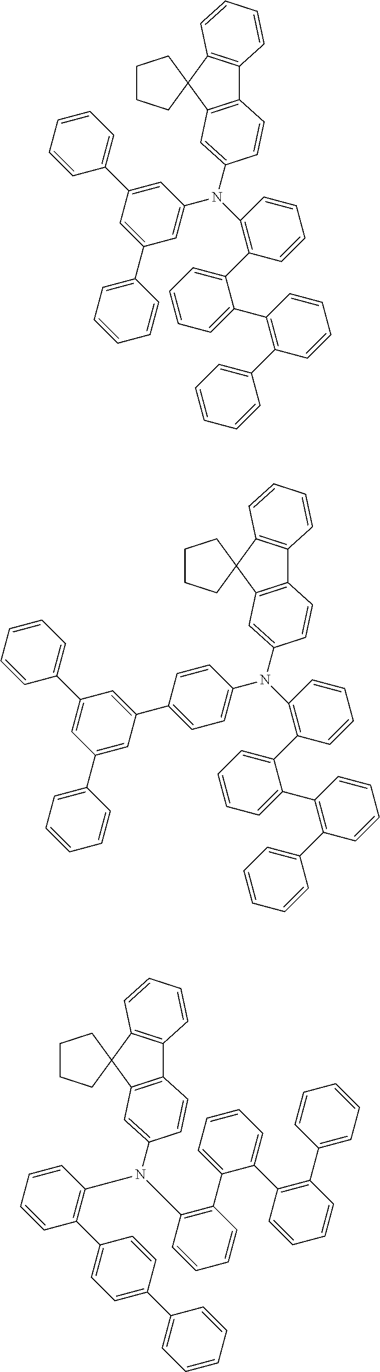 [SMILES: c1ccc(-c2cc(-c3ccccc3)cc(N(c3ccc4c(c3)C3(CCCC3)c3ccccc3-4)c3ccccc3-c3ccccc3-c3ccccc3-c3ccccc3)c2)cc1 ; c1ccc(-c2cc(-c3ccccc3)cc(-c3ccc(N(c4ccc5c(c4)C4(CCCC4)c4ccccc4-5)c4ccccc4-c4ccccc4-c4ccccc4-c4ccccc4)cc3)c2)cc1 ; c1ccc(-c2ccc(-c3ccccc3N(c3ccc4c(c3)C3(CCCC3)c3ccccc3-4)c3ccccc3-c3ccccc3-c3ccccc3-c3ccccc3)cc2)cc1]

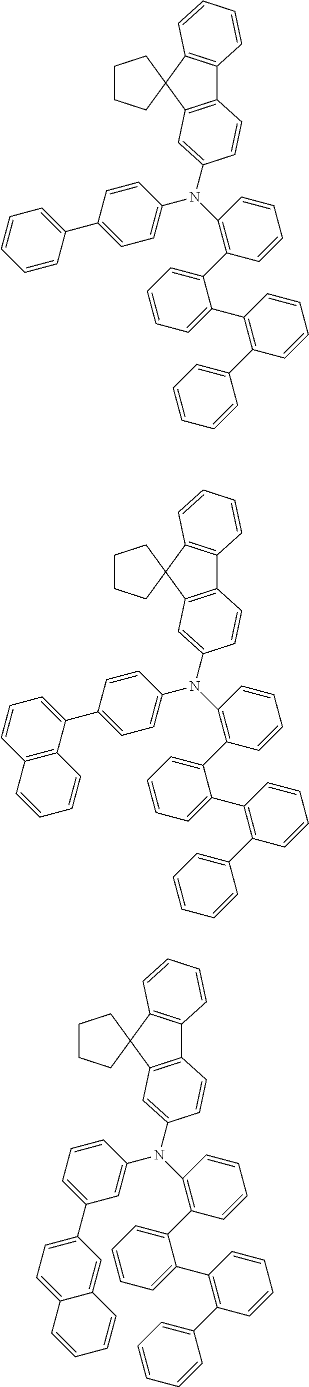 [SMILES: c1ccc(-c2ccc(N(c3ccc4c(c3)C3(CCCC3)c3ccccc3-4)c3ccccc3-c3ccccc3-c3ccccc3-c3ccccc3)cc2)cc1 ; c1ccc(-c2ccccc2-c2ccccc2-c2ccccc2N(c2ccc(-c3cccc4ccccc34)cc2)c2ccc3c(c2)C2(CCCC2)c2ccccc2-3)cc1 ; c1ccc(-c2ccccc2-c2ccccc2-c2ccccc2N(c2cccc(-c3ccc4ccccc4c3)c2)c2ccc3c(c2)C2(CCCC2)c2ccccc2-3)cc1]

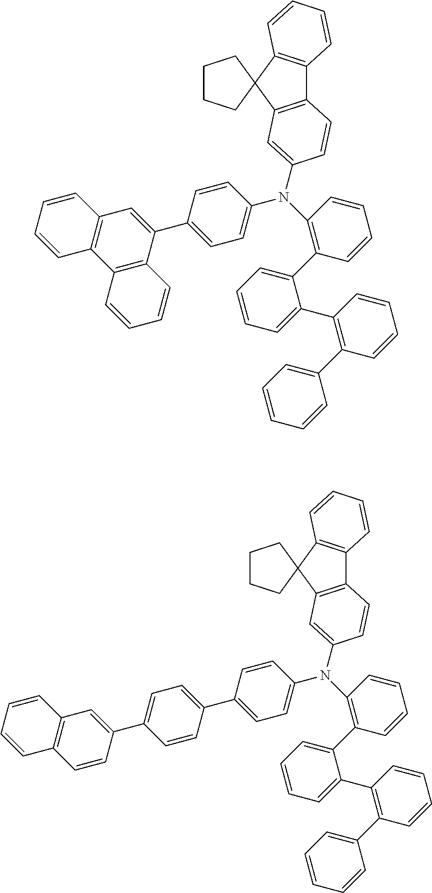 [SMILES: c1ccc(-c2ccccc2-c2ccccc2-c2ccccc2N(c2ccc(-c3cc4ccccc4c4ccccc34)cc2)c2ccc3c(c2)C2(CCCC2)c2ccccc2-3)cc1 ; c1ccc(-c2ccccc2-c2ccccc2-c2ccccc2N(c2ccc(-c3ccc(-c4ccc5ccccc5c4)cc3)cc2)c2ccc3c(c2)C2(CCCC2)c2ccccc2-3)cc1]

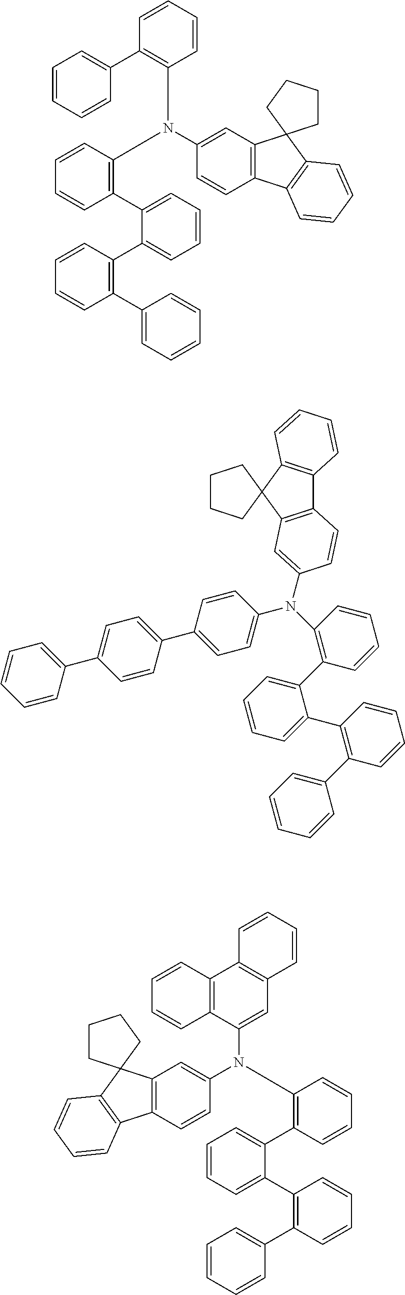 [SMILES: c1ccc(-c2ccccc2-c2ccccc2-c2ccccc2N(c2ccc3c(c2)C2(CCCC2)c2ccccc2-3)c2ccccc2-c2ccccc2)cc1 ; c1ccc(-c2ccc(-c3ccc(N(c4ccc5c(c4)C4(CCCC4)c4ccccc4-5)c4ccccc4-c4ccccc4-c4ccccc4-c4ccccc4)cc3)cc2)cc1 ; c1ccc(-c2ccccc2-c2ccccc2-c2ccccc2N(c2ccc3c(c2)C2(CCCC2)c2ccccc2-3)c2cc3ccccc3c3ccccc23)cc1]

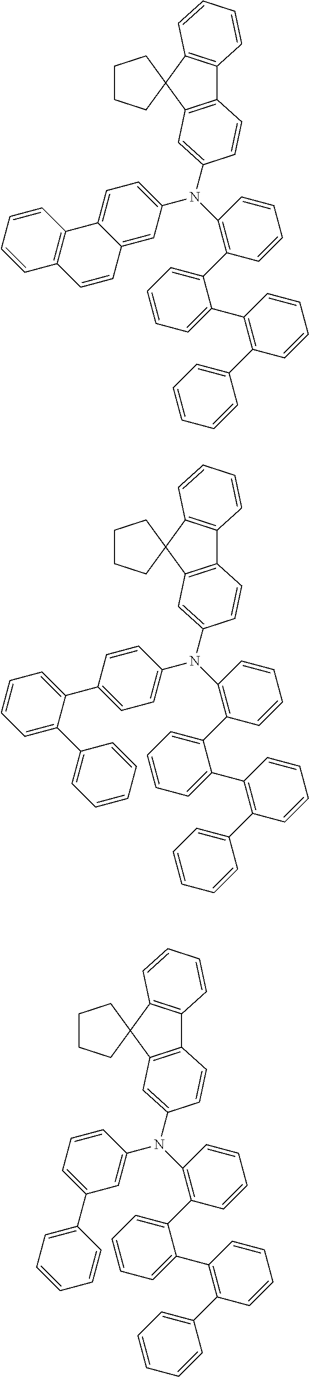

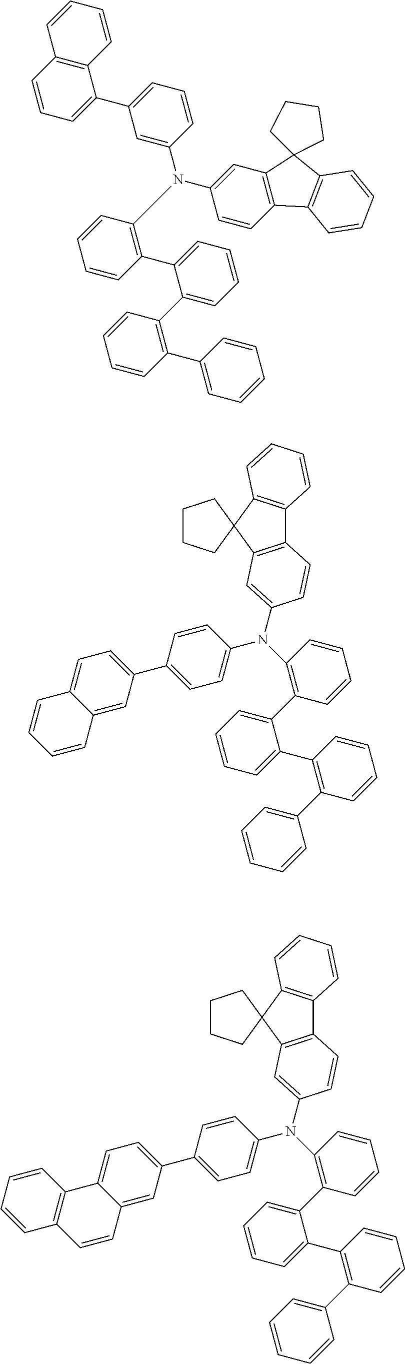 [SMILES: c1ccc(-c2ccccc2-c2ccccc2-c2ccccc2N(c2cccc(-c3cccc4ccccc34)c2)c2ccc3c(c2)C2(CCCC2)c2ccccc2-3)cc1 ; c1ccc(-c2ccccc2-c2ccccc2-c2ccccc2N(c2ccc(-c3ccc4ccccc4c3)cc2)c2ccc3c(c2)C2(CCCC2)c2ccccc2-3)cc1 ; c1ccc(-c2ccccc2-c2ccccc2-c2ccccc2N(c2ccc(-c3ccc4c(ccc5ccccc54)c3)cc2)c2ccc3c(c2)C2(CCCC2)c2ccccc2-3)cc1]

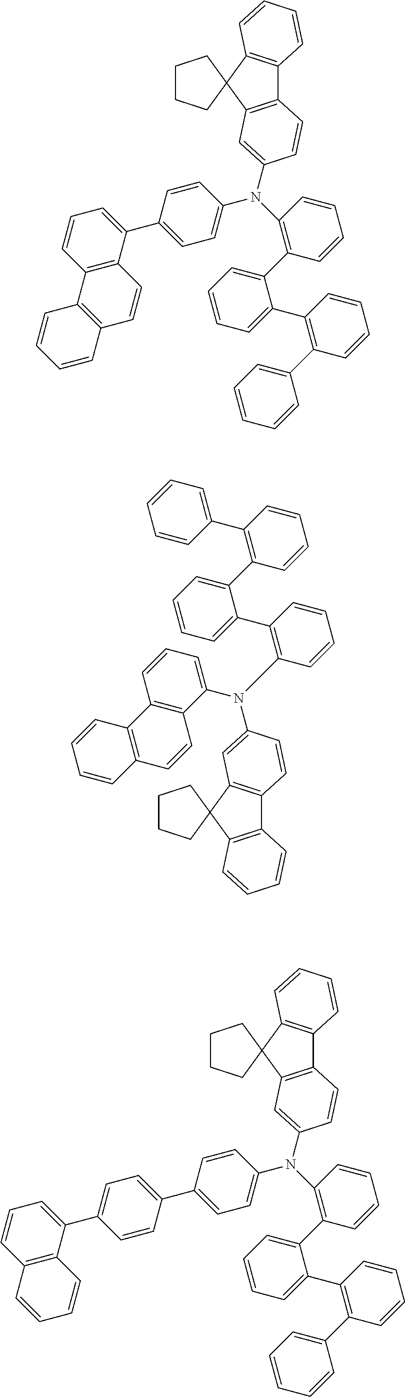 [SMILES: c1ccc(-c2ccccc2-c2ccccc2-c2ccccc2N(c2ccc(-c3cccc4c3ccc3ccccc34)cc2)c2ccc3c(c2)C2(CCCC2)c2ccccc2-3)cc1 ; c1ccc(-c2ccccc2-c2ccccc2-c2ccccc2N(c2ccc3c(c2)C2(CCCC2)c2ccccc2-3)c2cccc3c2ccc2ccccc23)cc1 ; c1ccc(-c2ccccc2-c2ccccc2-c2ccccc2N(c2ccc(-c3ccc(-c4cccc5ccccc45)cc3)cc2)c2ccc3c(c2)C2(CCCC2)c2ccccc2-3)cc1]

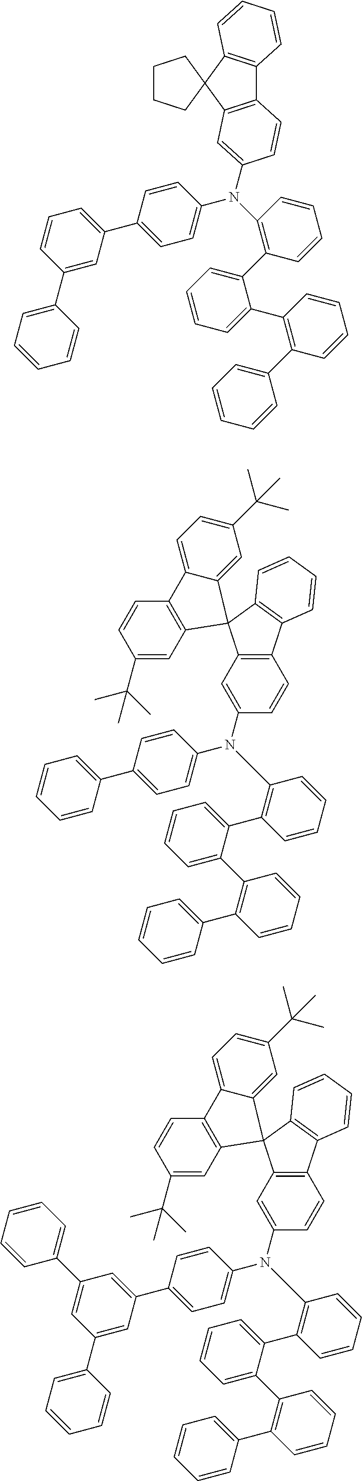

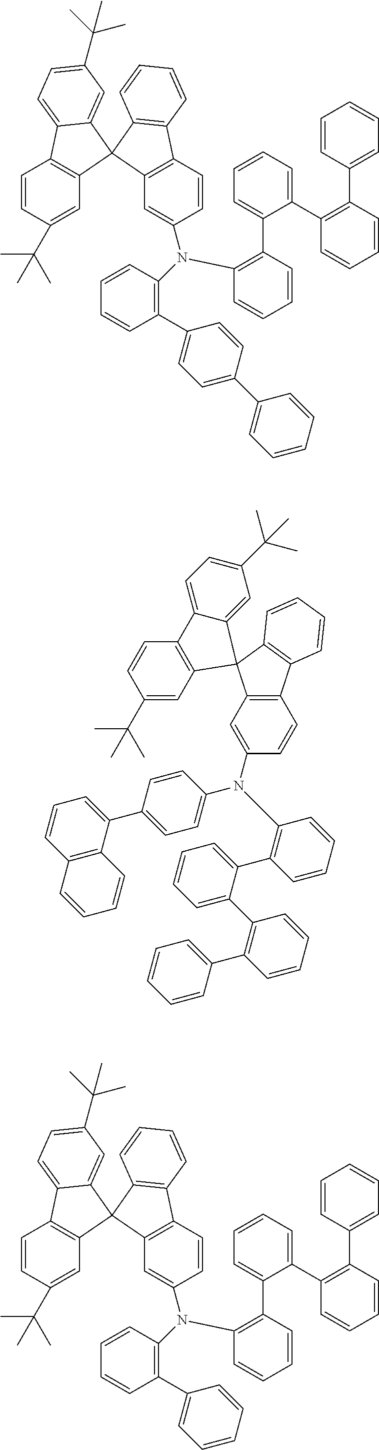 [SMILES: CC(C)(C)c1ccc2c(c1)C1(c3ccccc3-c3ccc(N(c4ccccc4-c4ccc(-c5ccccc5)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5cccc6ccccc56)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccccc4-c4ccccc4)c4ccccc4-c4ccccc4-c4ccccc4-c4ccccc4)cc31)c1cc(C(C)(C)C)ccc1-2]

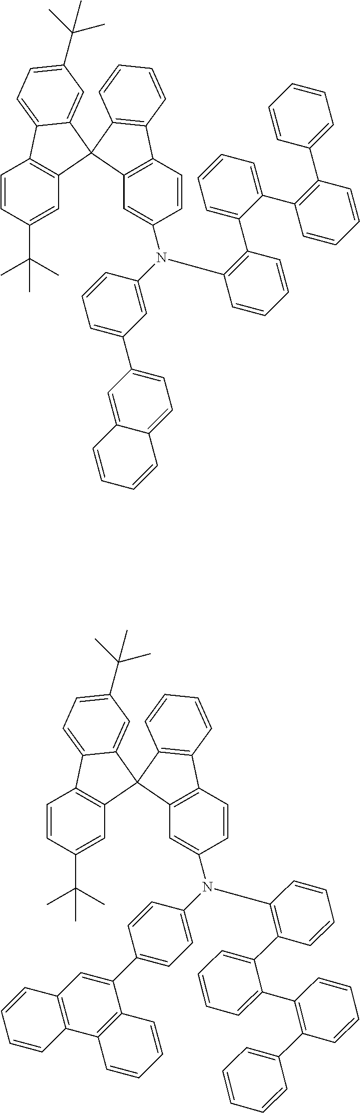 [SMILES: CC(C)(C)c1ccc2c(c1)C1(c3ccccc3-c3ccc(N(c4cccc(-c5ccc6ccccc6c5)c4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5cc6ccccc6c6ccccc56)cc4)c4ccccc4-c4ccccc4-c4ccccc4-c4ccccc4)cc31)c1cc(C(C)(C)C)ccc1-2]

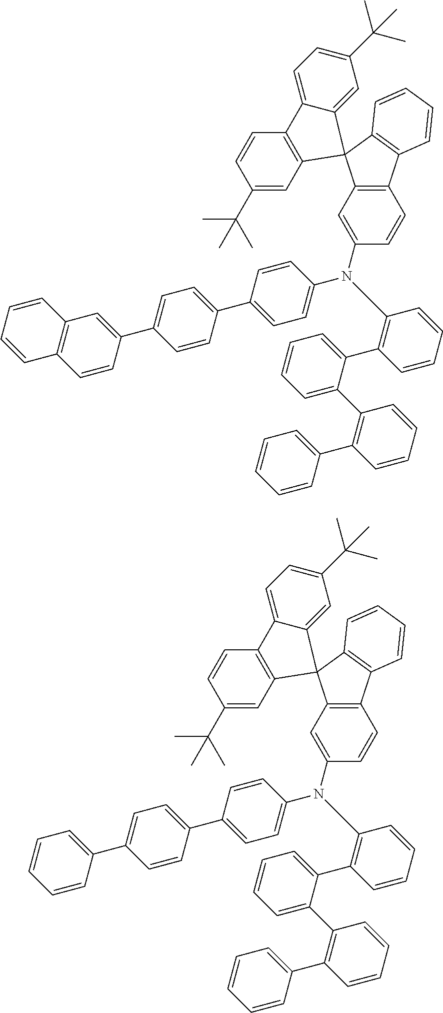

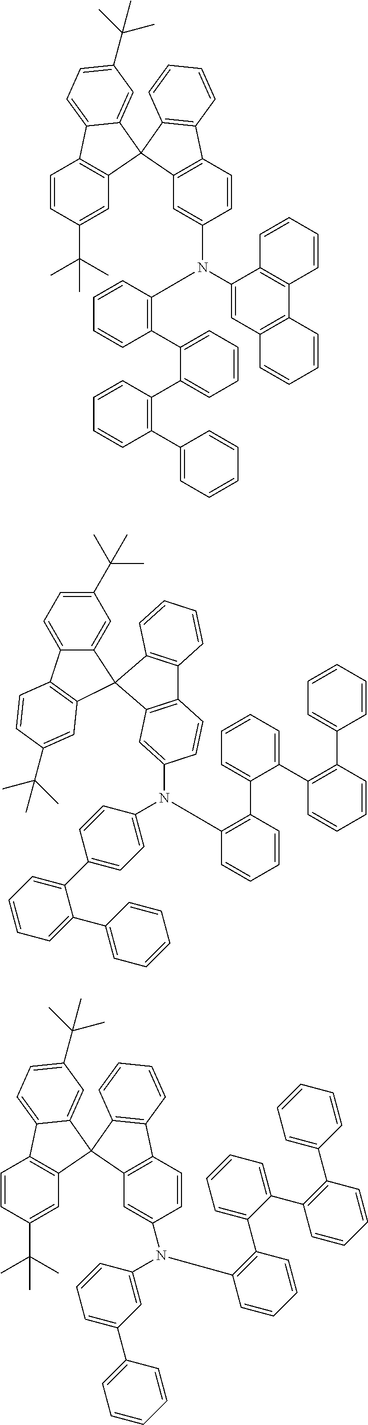 [SMILES: CC(C)(C)c1ccc2c(c1)C1(c3ccccc3-c3ccc(N(c4ccccc4-c4ccccc4-c4ccccc4-c4ccccc4)c4cc5ccccc5c5ccccc45)cc31)c1cc(C(C)(C)C)ccc1-2 ; CC(C)(C)c1ccc2c(c1)C1(c3ccccc3-c3ccc(N(c4ccc(-c5ccccc5-c5ccccc5)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4cccc(-c5ccccc5)c4)c4ccccc4-c4ccccc4-c4ccccc4-c4ccccc4)cc31)c1cc(C(C)(C)C)ccc1-2]

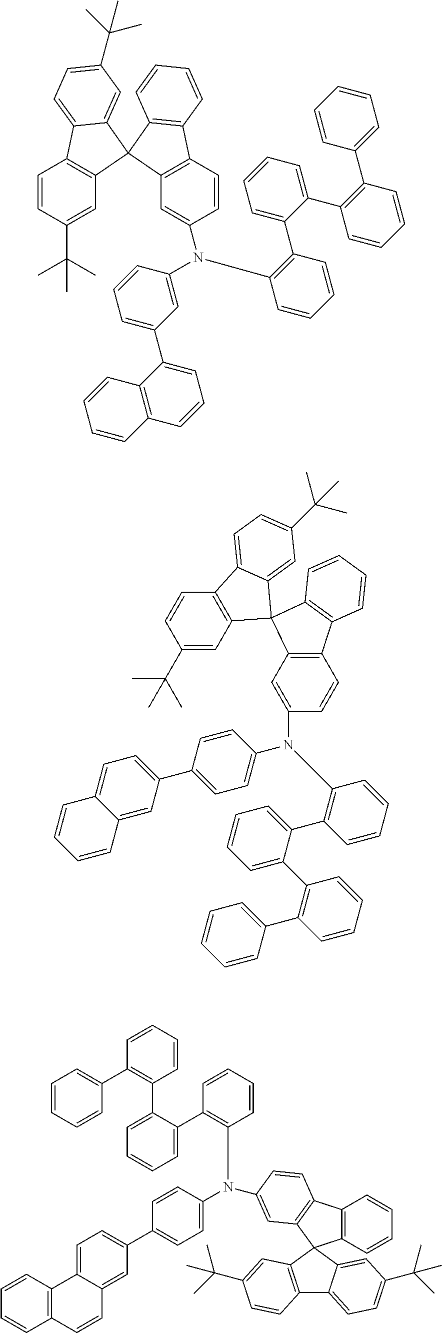 [SMILES: CC(C)(C)c1ccc2c(c1)C1(c3ccccc3-c3ccc(N(c4cccc(-c5cccc6ccccc56)c4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5ccc6ccccc6c5)cc4)c4ccccc4-c4ccccc4-c4ccccc4-c4ccccc4)cc31)c1cc(C(C)(C)C)ccc1-2 ; CC(C)(C)c1ccc2c(c1)C1(c3ccccc3-c3ccc(N(c4ccc(-c5ccc6c(ccc7ccccc76)c5)cc4)c4ccccc4-c4ccccc4-c4ccccc4-c4ccccc4)cc31)c1cc(C(C)(C)C)ccc1-2]

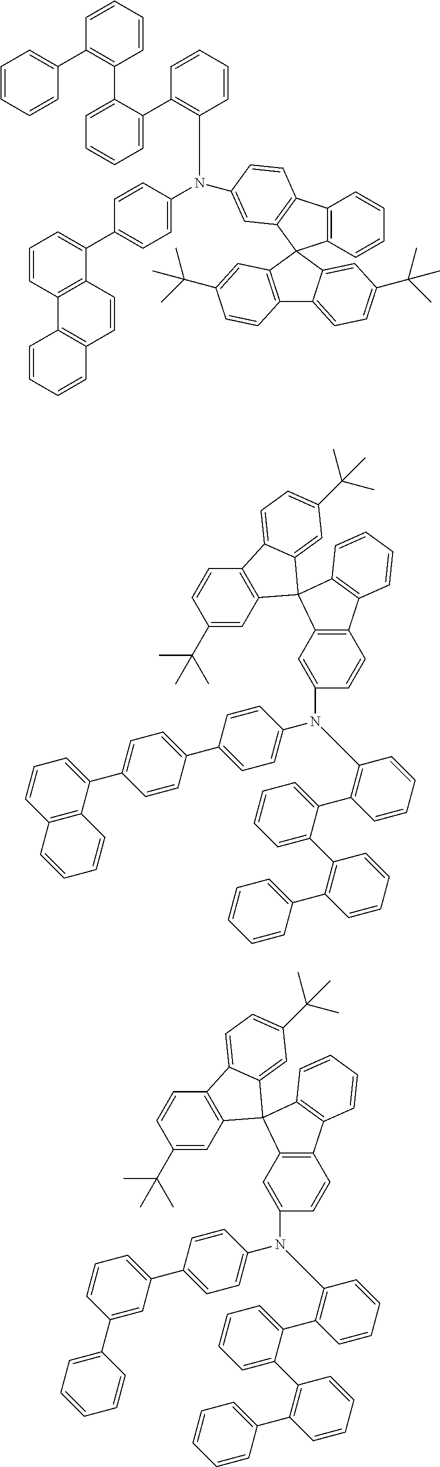

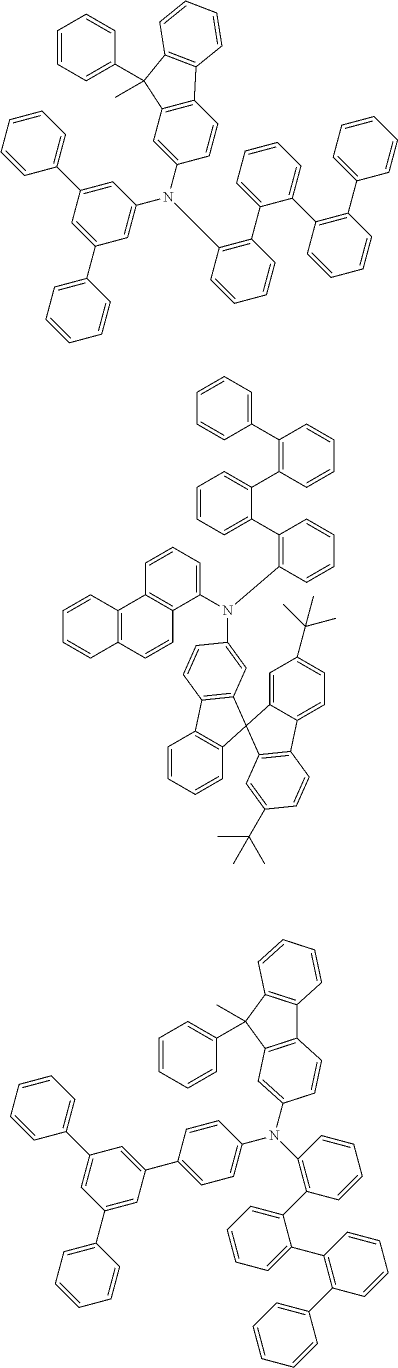 [SMILES: CC1(c2ccccc2)c2ccccc2-c2ccc(N(c3cc(-c4ccccc4)cc(-c4ccccc4)c3)c3ccccc3-c3ccccc3-c3ccccc3-c3ccccc3)cc21 ; CC(C)(C)c1ccc2c(c1)C1(c3ccccc3-c3ccc(N(c4ccccc4-c4ccccc4-c4ccccc4-c4ccccc4)c4cccc5c4ccc4ccccc45)cc31)c1cc(C(C)(C)C)ccc1-2 ; CC1(c2ccccc2)c2ccccc2-c2ccc(N(c3ccc(-c4cc(-c5ccccc5)cc(-c5ccccc5)c4)cc3)c3ccccc3-c3ccccc3-c3ccccc3-c3ccccc3)cc21]

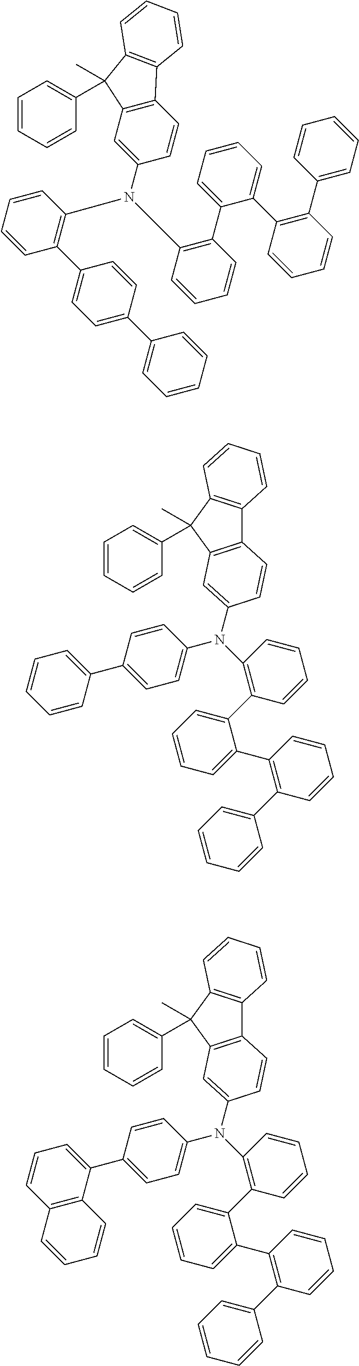 [SMILES: CC1(c2ccccc2)c2ccccc2-c2ccc(N(c3ccccc3-c3ccc(-c4ccccc4)cc3)c3ccccc3-c3ccccc3-c3ccccc3-c3ccccc3)cc21 ; CC1(c2ccccc2)c2ccccc2-c2ccc(N(c3ccc(-c4ccccc4)cc3)c3ccccc3-c3ccccc3-c3ccccc3-c3ccccc3)cc21 ; CC1(c2ccccc2)c2ccccc2-c2ccc(N(c3ccc(-c4cccc5ccccc45)cc3)c3ccccc3-c3ccccc3-c3ccccc3-c3ccccc3)cc21]

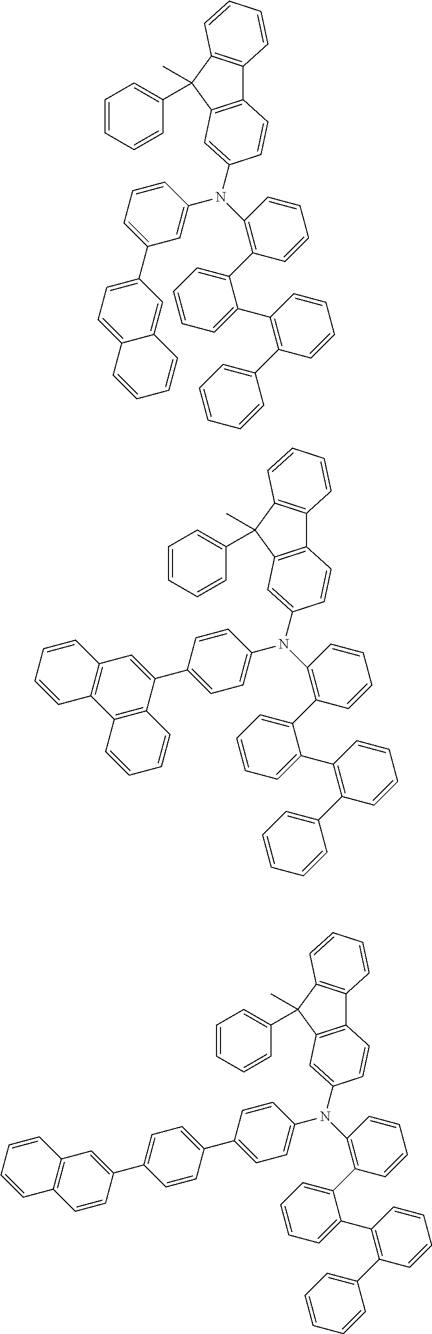 [SMILES: CC1(c2ccccc2)c2ccccc2-c2ccc(N(c3cccc(-c4ccc5ccccc5c4)c3)c3ccccc3-c3ccccc3-c3ccccc3-c3ccccc3)cc21 ; CC1(c2ccccc2)c2ccccc2-c2ccc(N(c3ccc(-c4cc5ccccc5c5ccccc45)cc3)c3ccccc3-c3ccccc3-c3ccccc3-c3ccccc3)cc21 ; CC1(c2ccccc2)c2ccccc2-c2ccc(N(c3ccc(-c4ccc(-c5ccc6ccccc6c5)cc4)cc3)c3ccccc3-c3ccccc3-c3ccccc3-c3ccccc3)cc21]

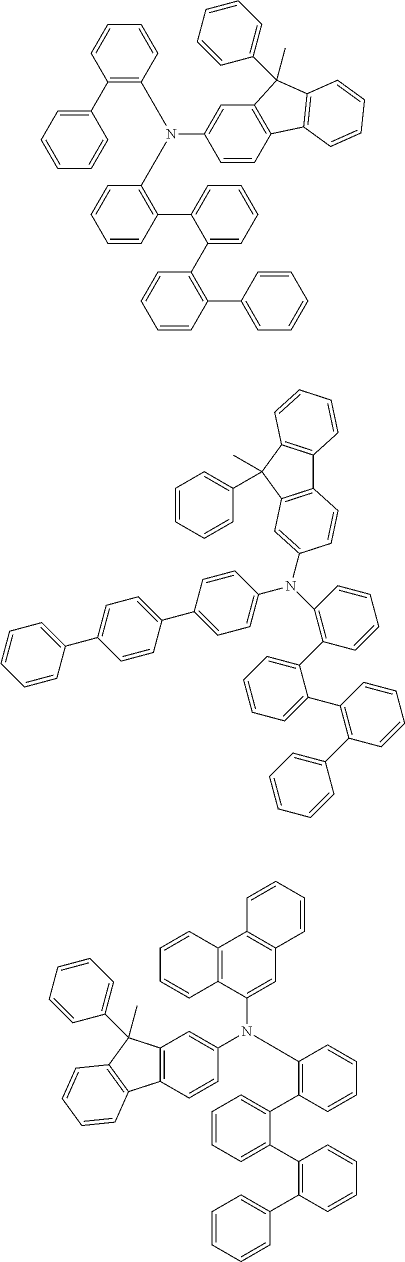 [SMILES: CC1(c2ccccc2)c2ccccc2-c2ccc(N(c3ccccc3-c3ccccc3)c3ccccc3-c3ccccc3-c3ccccc3-c3ccccc3)cc21 ; CC1(c2ccccc2)c2ccccc2-c2ccc(N(c3ccc(-c4ccc(-c5ccccc5)cc4)cc3)c3ccccc3-c3ccccc3-c3ccccc3-c3ccccc3)cc21 ; CC1(c2ccccc2)c2ccccc2-c2ccc(N(c3ccccc3-c3ccccc3-c3ccccc3-c3ccccc3)c3cc4ccccc4c4ccccc34)cc21]

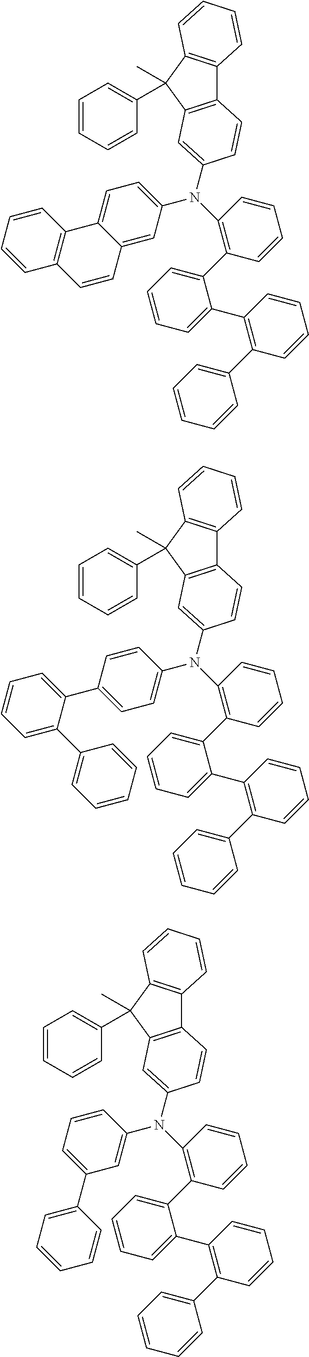

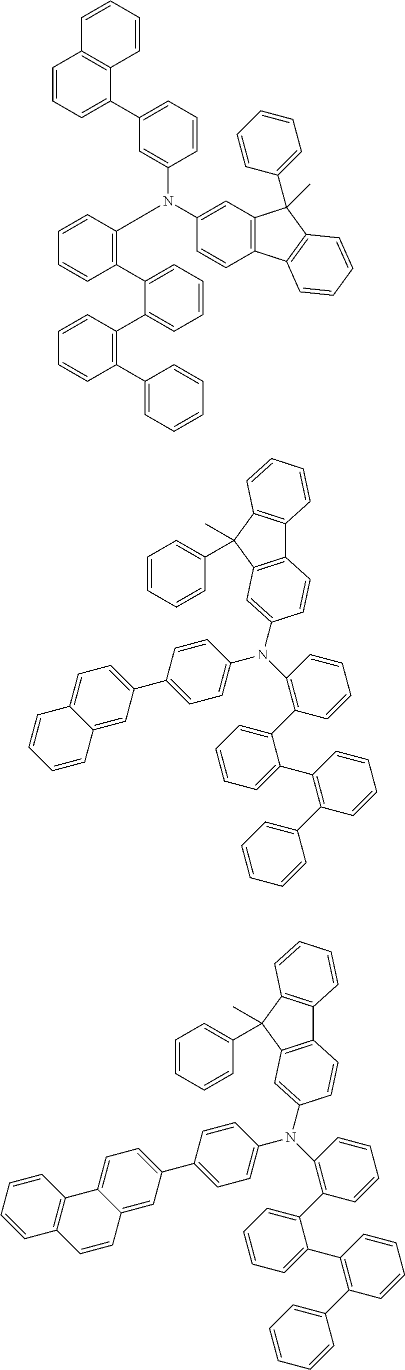 [SMILES: CC1(c2ccccc2)c2ccccc2-c2ccc(N(c3cccc(-c4cccc5ccccc45)c3)c3ccccc3-c3ccccc3-c3ccccc3-c3ccccc3)cc21 ; CC1(c2ccccc2)c2ccccc2-c2ccc(N(c3ccc(-c4ccc5ccccc5c4)cc3)c3ccccc3-c3ccccc3-c3ccccc3-c3ccccc3)cc21 ; CC1(c2ccccc2)c2ccccc2-c2ccc(N(c3ccc(-c4ccc5c(ccc6ccccc65)c4)cc3)c3ccccc3-c3ccccc3-c3ccccc3-c3ccccc3)cc21]

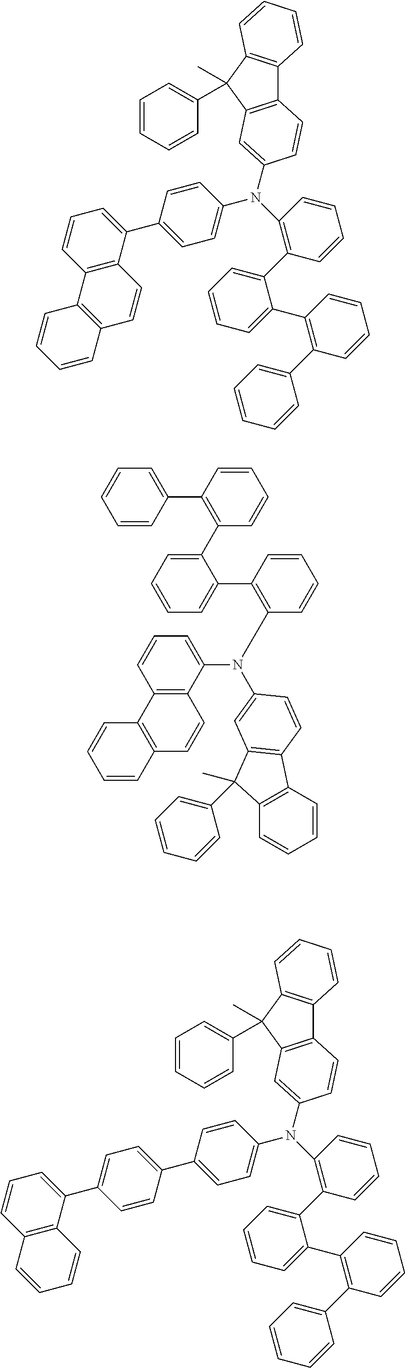

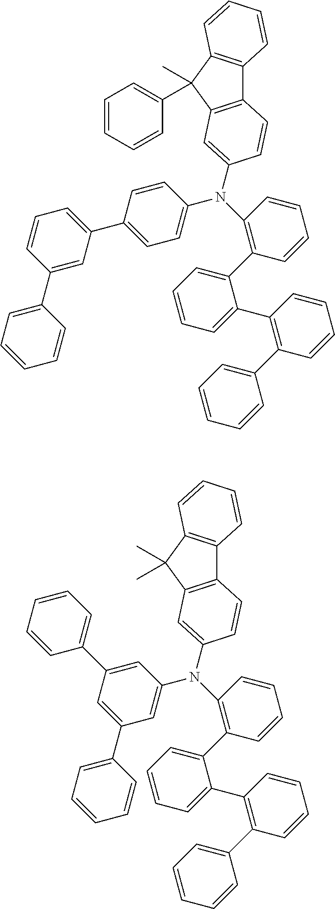 [SMILES: CC1(c2ccccc2)c2ccccc2-c2ccc(N(c3ccc(-c4cccc(-c5ccccc5)c4)cc3)c3ccccc3-c3ccccc3-c3ccccc3-c3ccccc3)cc21 ; CC1(C)c2ccccc2-c2ccc(N(c3cc(-c4ccccc4)cc(-c4ccccc4)c3)c3ccccc3-c3ccccc3-c3ccccc3-c3ccccc3)cc21]

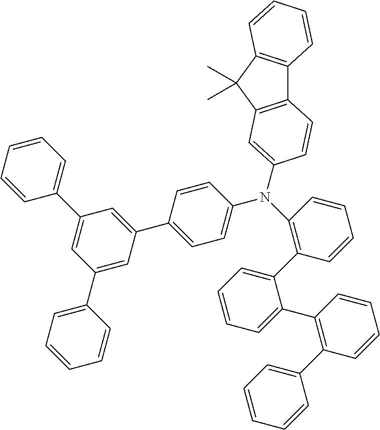 [SMILES: CC1(C)c2ccccc2-c2ccc(N(c3ccc(-c4cc(-c5ccccc5)cc(-c5ccccc5)c4)cc3)c3ccccc3-c3ccccc3-c3ccccc3-c3ccccc3)cc21]

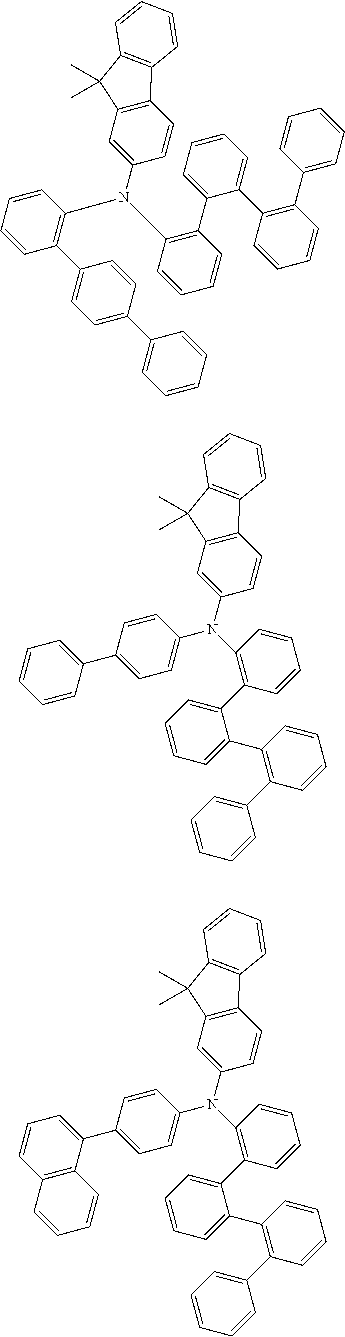 [SMILES: CC1(C)c2ccccc2-c2ccc(N(c3ccccc3-c3ccc(-c4ccccc4)cc3)c3ccccc3-c3ccccc3-c3ccccc3-c3ccccc3)cc21 ; CC1(C)c2ccccc2-c2ccc(N(c3ccc(-c4ccccc4)cc3)c3ccccc3-c3ccccc3-c3ccccc3-c3ccccc3)cc21 ; CC1(C)c2ccccc2-c2ccc(N(c3ccc(-c4cccc5ccccc45)cc3)c3ccccc3-c3ccccc3-c3ccccc3-c3ccccc3)cc21]

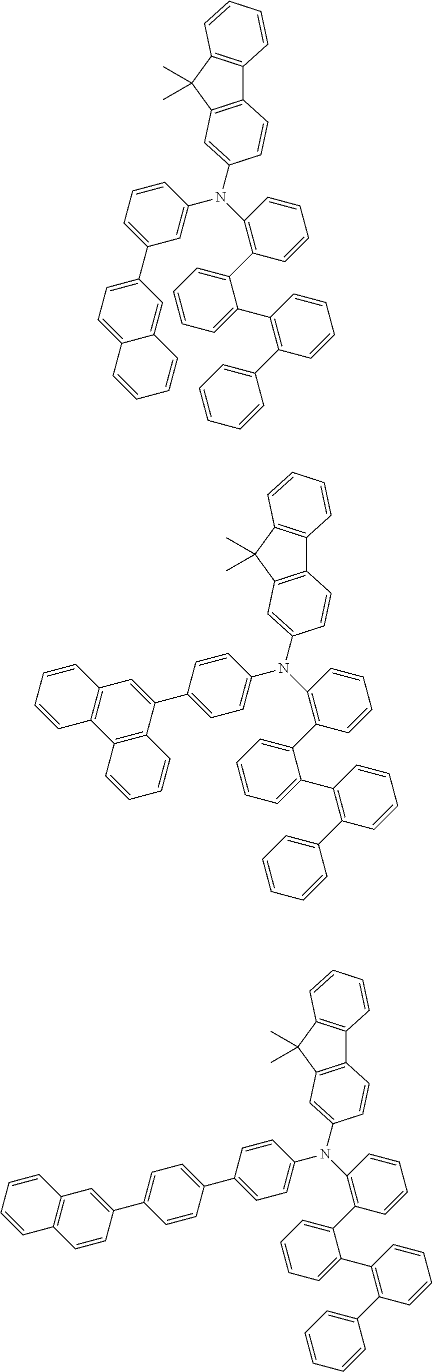 [SMILES: CC1(C)c2ccccc2-c2ccc(N(c3cccc(-c4ccc5ccccc5c4)c3)c3ccccc3-c3ccccc3-c3ccccc3-c3ccccc3)cc21 ; CC1(C)c2ccccc2-c2ccc(N(c3ccc(-c4cc5ccccc5c5ccccc45)cc3)c3ccccc3-c3ccccc3-c3ccccc3-c3ccccc3)cc21 ; CC1(C)c2ccccc2-c2ccc(N(c3ccc(-c4ccc(-c5ccc6ccccc6c5)cc4)cc3)c3ccccc3-c3ccccc3-c3ccccc3-c3ccccc3)cc21]

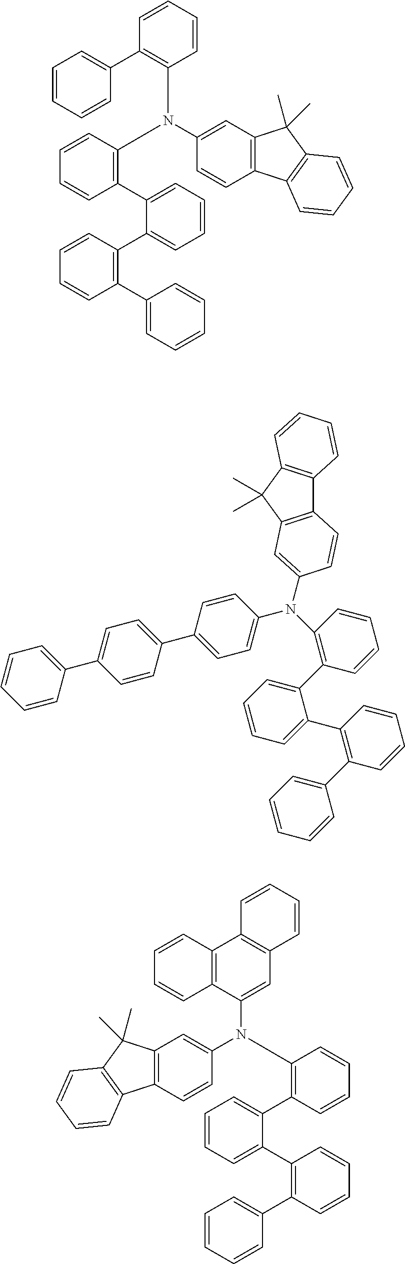 [SMILES: CC1(C)c2ccccc2-c2ccc(N(c3ccccc3-c3ccccc3)c3ccccc3-c3ccccc3-c3ccccc3-c3ccccc3)cc21 ; CC1(C)c2ccccc2-c2ccc(N(c3ccc(-c4ccc(-c5ccccc5)cc4)cc3)c3ccccc3-c3ccccc3-c3ccccc3-c3ccccc3)cc21 ; CC1(C)c2ccccc2-c2ccc(N(c3ccccc3-c3ccccc3-c3ccccc3-c3ccccc3)c3cc4ccccc4c4ccccc34)cc21]

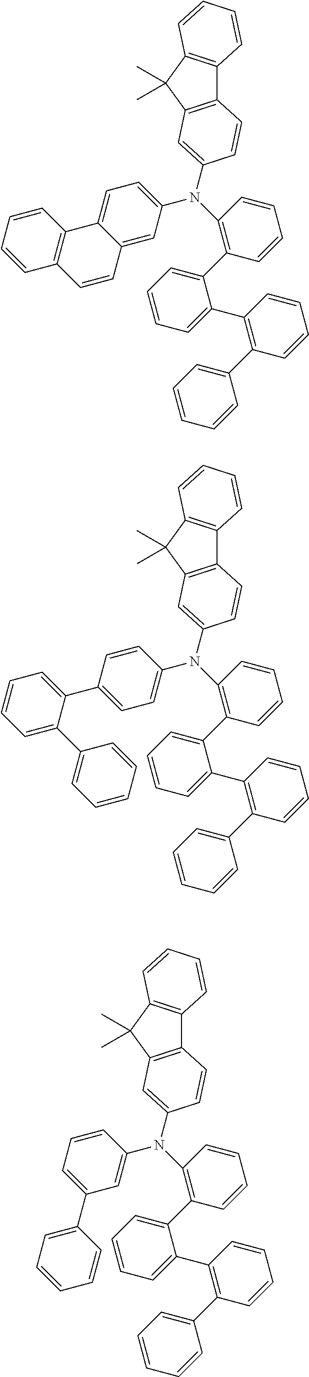

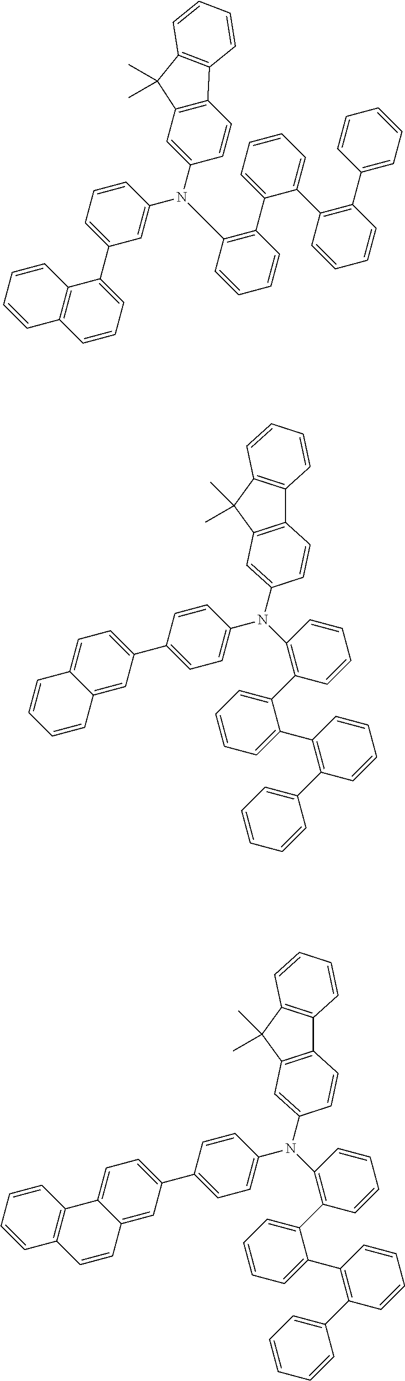 [SMILES: CC1(C)c2ccccc2-c2ccc(N(c3cccc(-c4cccc5ccccc45)c3)c3ccccc3-c3ccccc3-c3ccccc3-c3ccccc3)cc21 ; CC1(C)c2ccccc2-c2ccc(N(c3ccc(-c4ccc5ccccc5c4)cc3)c3ccccc3-c3ccccc3-c3ccccc3-c3ccccc3)cc21 ; CC1(C)c2ccccc2-c2ccc(N(c3ccc(-c4ccc5c(ccc6ccccc65)c4)cc3)c3ccccc3-c3ccccc3-c3ccccc3-c3ccccc3)cc21]

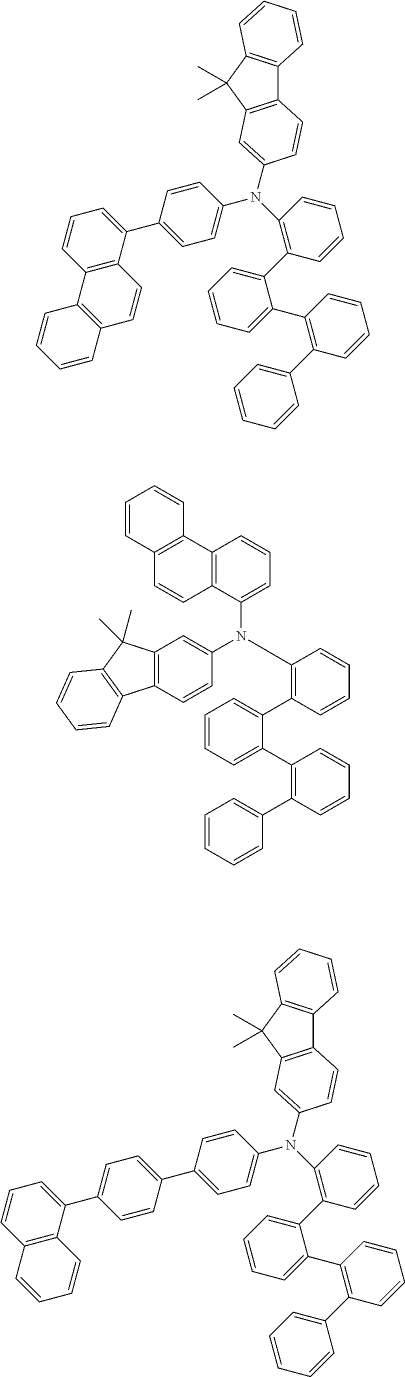 [SMILES: CC1(C)c2ccccc2-c2ccc(N(c3ccc(-c4cccc5c4ccc4ccccc45)cc3)c3ccccc3-c3ccccc3-c3ccccc3-c3ccccc3)cc21 ; CC1(C)c2ccccc2-c2ccc(N(c3ccccc3-c3ccccc3-c3ccccc3-c3ccccc3)c3cccc4c3ccc3ccccc34)cc21 ; CC1(C)c2ccccc2-c2ccc(N(c3ccc(-c4ccc(-c5cccc6ccccc56)cc4)cc3)c3ccccc3-c3ccccc3-c3ccccc3-c3ccccc3)cc21]

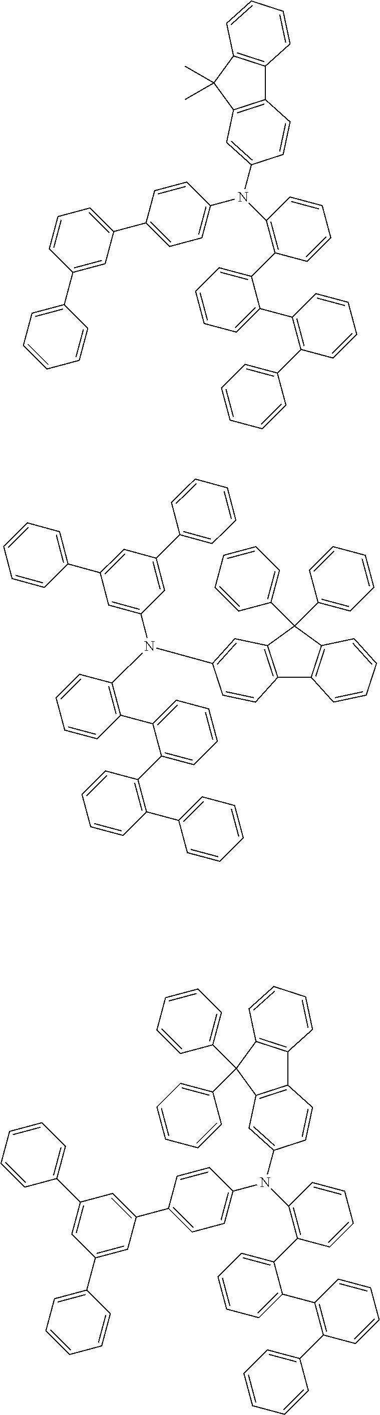 [SMILES: CC1(C)c2ccccc2-c2ccc(N(c3ccc(-c4cccc(-c5ccccc5)c4)cc3)c3ccccc3-c3ccccc3-c3ccccc3-c3ccccc3)cc21 ; c1ccc(-c2cc(-c3ccccc3)cc(N(c3ccc4c(c3)C(c3ccccc3)(c3ccccc3)c3ccccc3-4)c3ccccc3-c3ccccc3-c3ccccc3-c3ccccc3)c2)cc1 ; c1ccc(-c2cc(-c3ccccc3)cc(-c3ccc(N(c4ccc5c(c4)C(c4ccccc4)(c4ccccc4)c4ccccc4-5)c4ccccc4-c4ccccc4-c4ccccc4-c4ccccc4)cc3)c2)cc1]

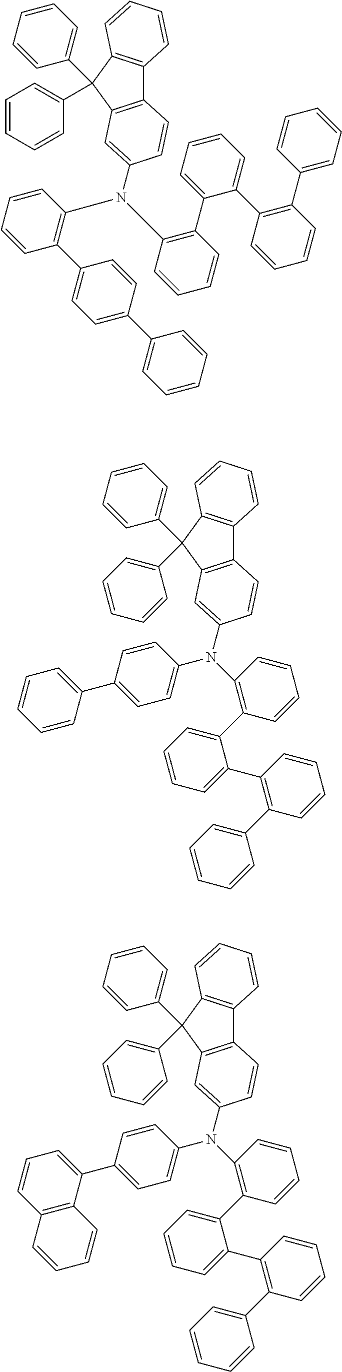 [SMILES: c1ccc(-c2ccc(-c3ccccc3N(c3ccc4c(c3)C(c3ccccc3)(c3ccccc3)c3ccccc3-4)c3ccccc3-c3ccccc3-c3ccccc3-c3ccccc3)cc2)cc1 ; c1ccc(-c2ccc(N(c3ccc4c(c3)C(c3ccccc3)(c3ccccc3)c3ccccc3-4)c3ccccc3-c3ccccc3-c3ccccc3-c3ccccc3)cc2)cc1 ; c1ccc(-c2ccccc2-c2ccccc2-c2ccccc2N(c2ccc(-c3cccc4ccccc34)cc2)c2ccc3c(c2)C(c2ccccc2)(c2ccccc2)c2ccccc2-3)cc1]

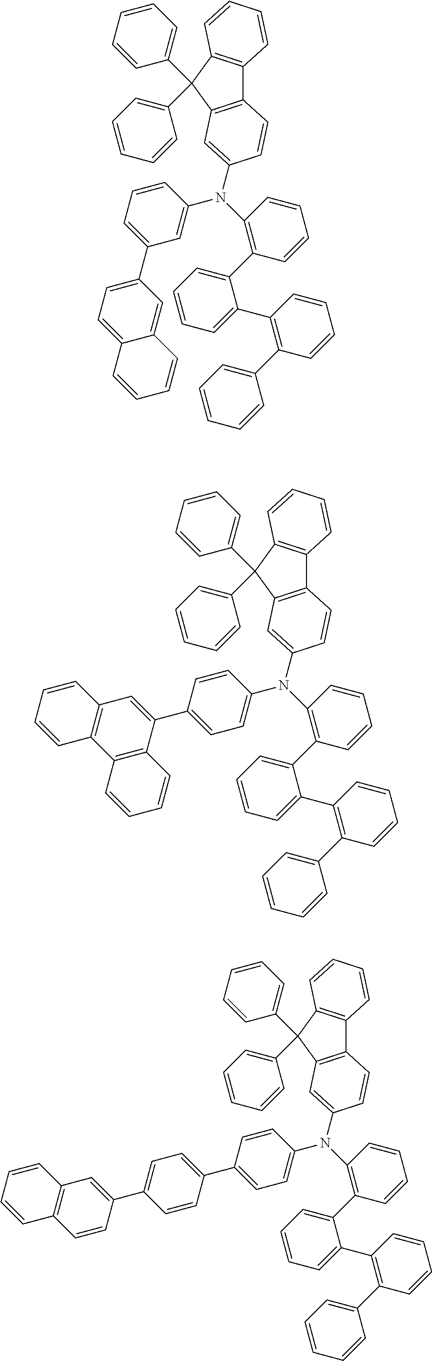 [SMILES: c1ccc(-c2ccccc2-c2ccccc2-c2ccccc2N(c2cccc(-c3ccc4ccccc4c3)c2)c2ccc3c(c2)C(c2ccccc2)(c2ccccc2)c2ccccc2-3)cc1 ; c1ccc(-c2ccccc2-c2ccccc2-c2ccccc2N(c2ccc(-c3cc4ccccc4c4ccccc34)cc2)c2ccc3c(c2)C(c2ccccc2)(c2ccccc2)c2ccccc2-3)cc1 ; c1ccc(-c2ccccc2-c2ccccc2-c2ccccc2N(c2ccc(-c3ccc(-c4ccc5ccccc5c4)cc3)cc2)c2ccc3c(c2)C(c2ccccc2)(c2ccccc2)c2ccccc2-3)cc1]

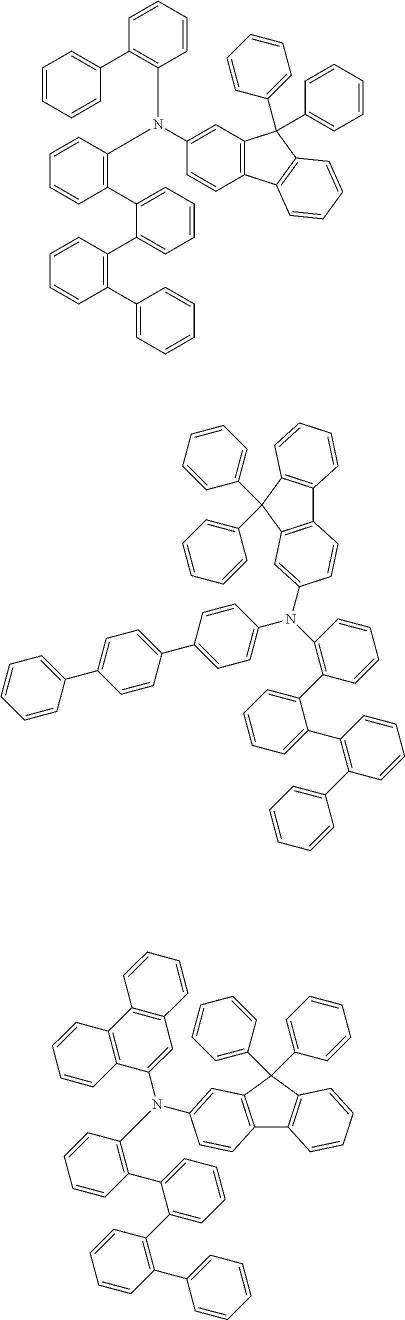 [SMILES: c1ccc(-c2ccccc2-c2ccccc2-c2ccccc2N(c2ccc3c(c2)C(c2ccccc2)(c2ccccc2)c2ccccc2-3)c2ccccc2-c2ccccc2)cc1 ; c1ccc(-c2ccc(-c3ccc(N(c4ccc5c(c4)C(c4ccccc4)(c4ccccc4)c4ccccc4-5)c4ccccc4-c4ccccc4-c4ccccc4-c4ccccc4)cc3)cc2)cc1 ; c1ccc(-c2ccccc2-c2ccccc2-c2ccccc2N(c2ccc3c(c2)C(c2ccccc2)(c2ccccc2)c2ccccc2-3)c2cc3ccccc3c3ccccc23)cc1]

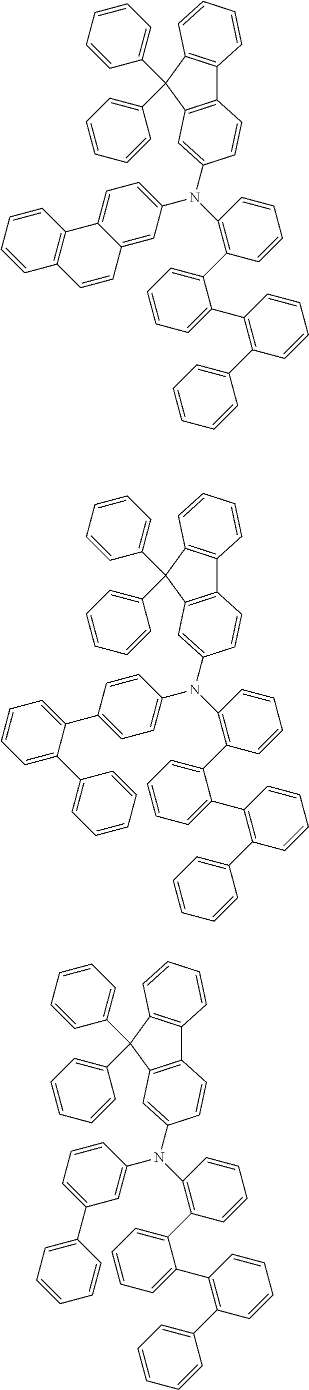 [SMILES: c1ccc(-c2ccccc2-c2ccccc2-c2ccccc2N(c2ccc3c(c2)C(c2ccccc2)(c2ccccc2)c2ccccc2-3)c2ccc3c(ccc4ccccc43)c2)cc1 ; c1ccc(-c2ccccc2-c2ccc(N(c3ccc4c(c3)C(c3ccccc3)(c3ccccc3)c3ccccc3-4)c3ccccc3-c3ccccc3-c3ccccc3-c3ccccc3)cc2)cc1 ; c1ccc(-c2cccc(N(c3ccc4c(c3)C(c3ccccc3)(c3ccccc3)c3ccccc3-4)c3ccccc3-c3ccccc3-c3ccccc3-c3ccccc3)c2)cc1]

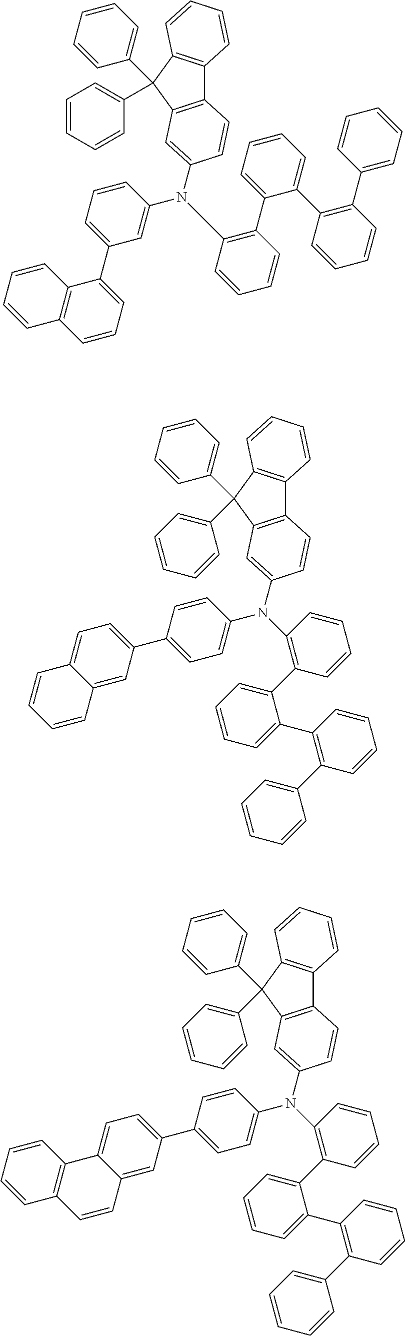 [SMILES: c1ccc(-c2ccccc2-c2ccccc2-c2ccccc2N(c2cccc(-c3cccc4ccccc34)c2)c2ccc3c(c2)C(c2ccccc2)(c2ccccc2)c2ccccc2-3)cc1 ; c1ccc(-c2ccccc2-c2ccccc2-c2ccccc2N(c2ccc(-c3ccc4ccccc4c3)cc2)c2ccc3c(c2)C(c2ccccc2)(c2ccccc2)c2ccccc2-3)cc1 ; c1ccc(-c2ccccc2-c2ccccc2-c2ccccc2N(c2ccc(-c3ccc4c(ccc5ccccc54)c3)cc2)c2ccc3c(c2)C(c2ccccc2)(c2ccccc2)c2ccccc2-3)cc1]

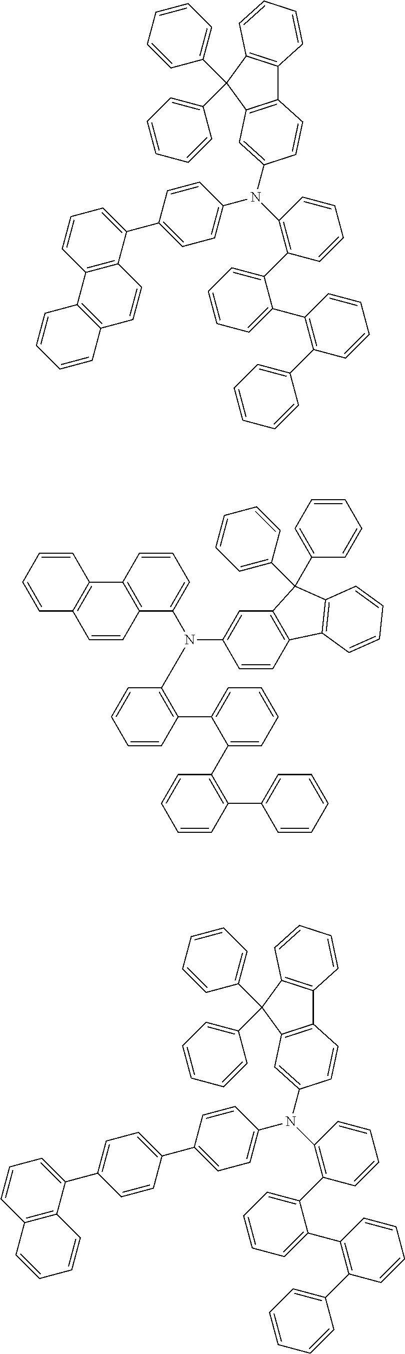 [SMILES: c1ccc(-c2ccccc2-c2ccccc2-c2ccccc2N(c2ccc(-c3cccc4c3ccc3ccccc34)cc2)c2ccc3c(c2)C(c2ccccc2)(c2ccccc2)c2ccccc2-3)cc1 ; c1ccc(-c2ccccc2-c2ccccc2-c2ccccc2N(c2ccc3c(c2)C(c2ccccc2)(c2ccccc2)c2ccccc2-3)c2cccc3c2ccc2ccccc23)cc1 ; c1ccc(-c2ccccc2-c2ccccc2-c2ccccc2N(c2ccc(-c3ccc(-c4cccc5ccccc45)cc3)cc2)c2ccc3c(c2)C(c2ccccc2)(c2ccccc2)c2ccccc2-3)cc1]

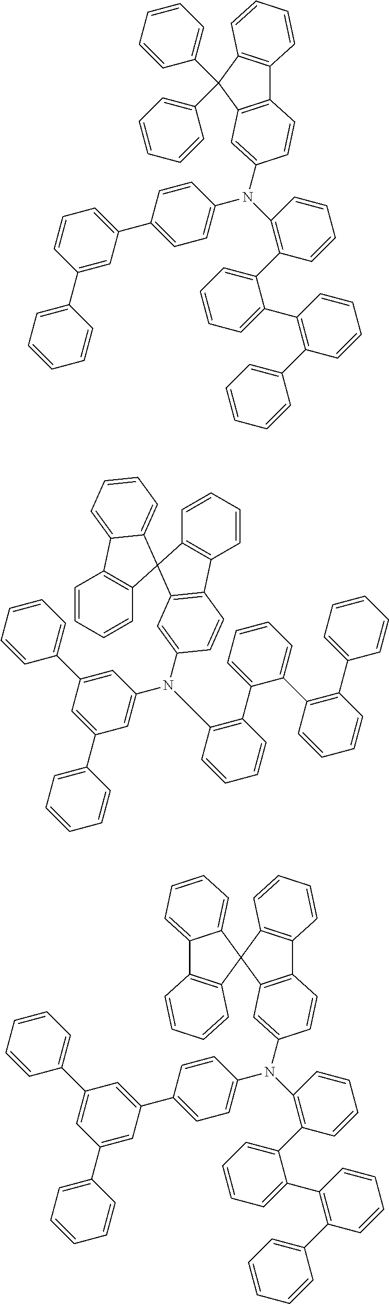 [SMILES: c1ccc(-c2cccc(-c3ccc(N(c4ccc5c(c4)C(c4ccccc4)(c4ccccc4)c4ccccc4-5)c4ccccc4-c4ccccc4-c4ccccc4-c4ccccc4)cc3)c2)cc1 ; c1ccc(-c2cc(-c3ccccc3)cc(N(c3ccc4c(c3)C3(c5ccccc5-c5ccccc53)c3ccccc3-4)c3ccccc3-c3ccccc3-c3ccccc3-c3ccccc3)c2)cc1 ; c1ccc(-c2cc(-c3ccccc3)cc(-c3ccc(N(c4ccc5c(c4)C4(c6ccccc6-c6ccccc64)c4ccccc4-5)c4ccccc4-c4ccccc4-c4ccccc4-c4ccccc4)cc3)c2)cc1]

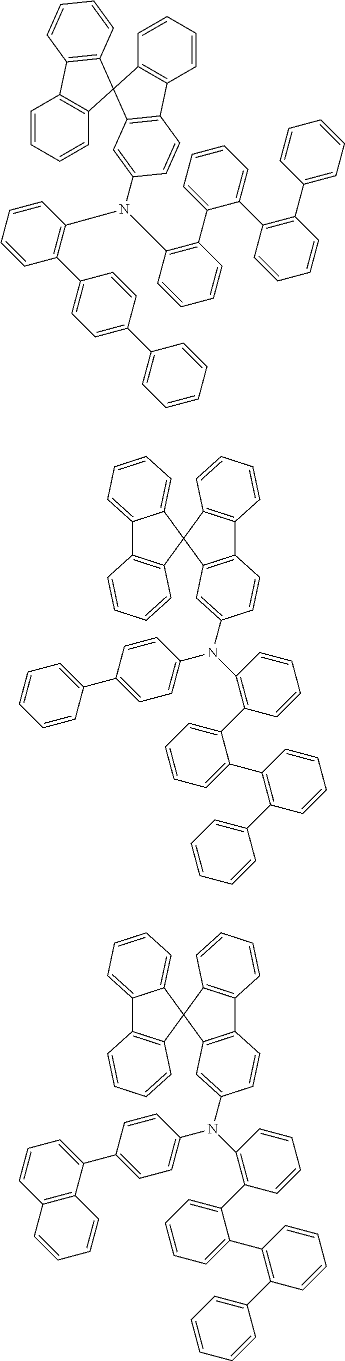 [SMILES: c1ccc(-c2ccc(-c3ccccc3N(c3ccc4c(c3)C3(c5ccccc5-c5ccccc53)c3ccccc3-4)c3ccccc3-c3ccccc3-c3ccccc3-c3ccccc3)cc2)cc1 ; c1ccc(-c2ccc(N(c3ccc4c(c3)C3(c5ccccc5-c5ccccc53)c3ccccc3-4)c3ccccc3-c3ccccc3-c3ccccc3-c3ccccc3)cc2)cc1 ; c1ccc(-c2ccccc2-c2ccccc2-c2ccccc2N(c2ccc(-c3cccc4ccccc34)cc2)c2ccc3c(c2)C2(c4ccccc4-c4ccccc42)c2ccccc2-3)cc1]

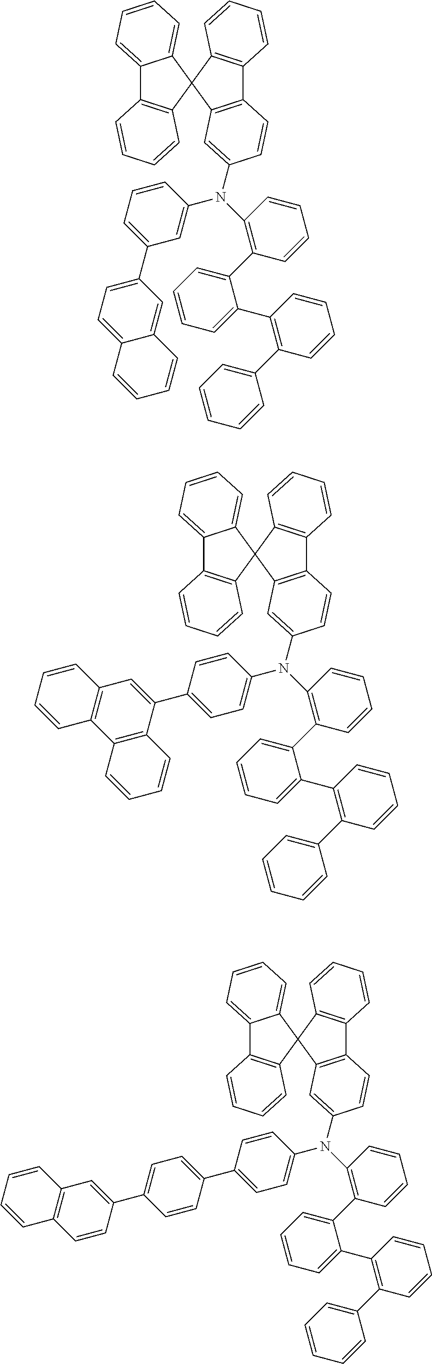 [SMILES: c1ccc(-c2ccccc2-c2ccccc2-c2ccccc2N(c2cccc(-c3ccc4ccccc4c3)c2)c2ccc3c(c2)C2(c4ccccc4-c4ccccc42)c2ccccc2-3)cc1 ; c1ccc(-c2ccccc2-c2ccccc2-c2ccccc2N(c2ccc(-c3cc4ccccc4c4ccccc34)cc2)c2ccc3c(c2)C2(c4ccccc4-c4ccccc42)c2ccccc2-3)cc1 ; c1ccc(-c2ccccc2-c2ccccc2-c2ccccc2N(c2ccc(-c3ccc(-c4ccc5ccccc5c4)cc3)cc2)c2ccc3c(c2)C2(c4ccccc4-c4ccccc42)c2ccccc2-3)cc1]

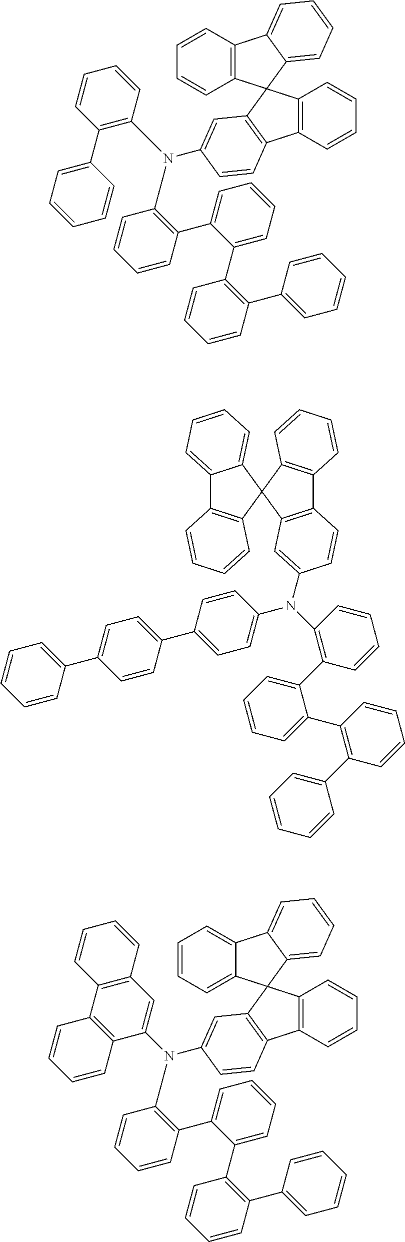 [SMILES: c1ccc(-c2ccccc2-c2ccccc2-c2ccccc2N(c2ccc3c(c2)C2(c4ccccc4-c4ccccc42)c2ccccc2-3)c2ccccc2-c2ccccc2)cc1 ; c1ccc(-c2ccc(-c3ccc(N(c4ccc5c(c4)C4(c6ccccc6-c6ccccc64)c4ccccc4-5)c4ccccc4-c4ccccc4-c4ccccc4-c4ccccc4)cc3)cc2)cc1 ; c1ccc(-c2ccccc2-c2ccccc2-c2ccccc2N(c2ccc3c(c2)C2(c4ccccc4-c4ccccc42)c2ccccc2-3)c2cc3ccccc3c3ccccc23)cc1]

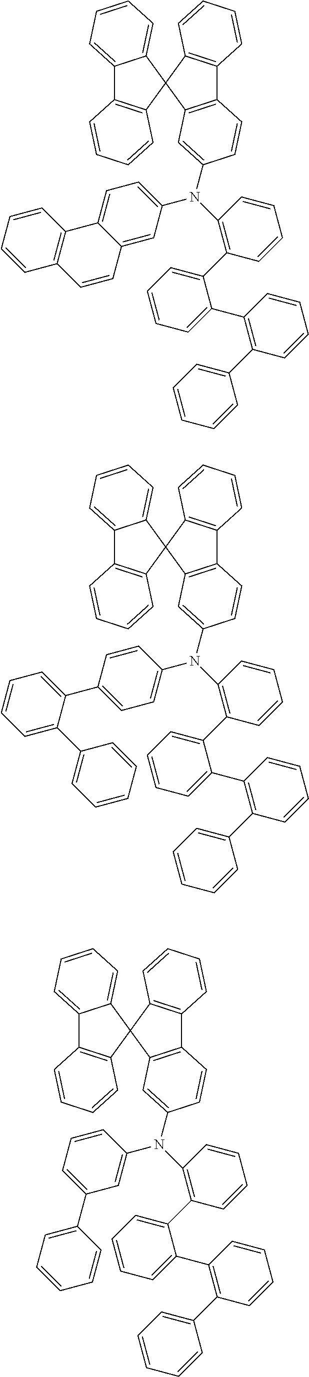

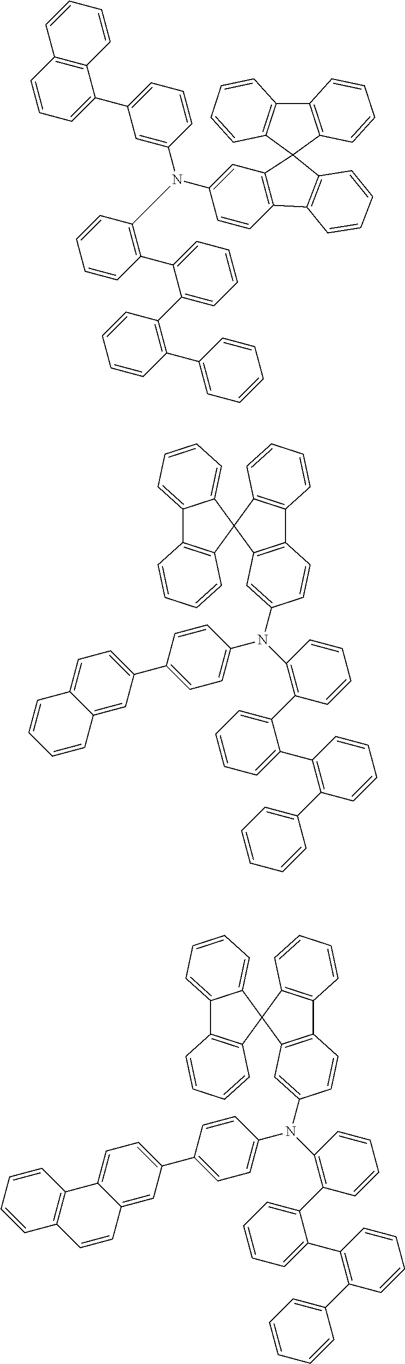 [SMILES: c1ccc(-c2ccccc2-c2ccccc2-c2ccccc2N(c2cccc(-c3cccc4ccccc34)c2)c2ccc3c(c2)C2(c4ccccc4-c4ccccc42)c2ccccc2-3)cc1 ; c1ccc(-c2ccccc2-c2ccccc2-c2ccccc2N(c2ccc(-c3ccc4ccccc4c3)cc2)c2ccc3c(c2)C2(c4ccccc4-c4ccccc42)c2ccccc2-3)cc1 ; c1ccc(-c2ccccc2-c2ccccc2-c2ccccc2N(c2ccc(-c3ccc4c(ccc5ccccc54)c3)cc2)c2ccc3c(c2)C2(c4ccccc4-c4ccccc42)c2ccccc2-3)cc1]

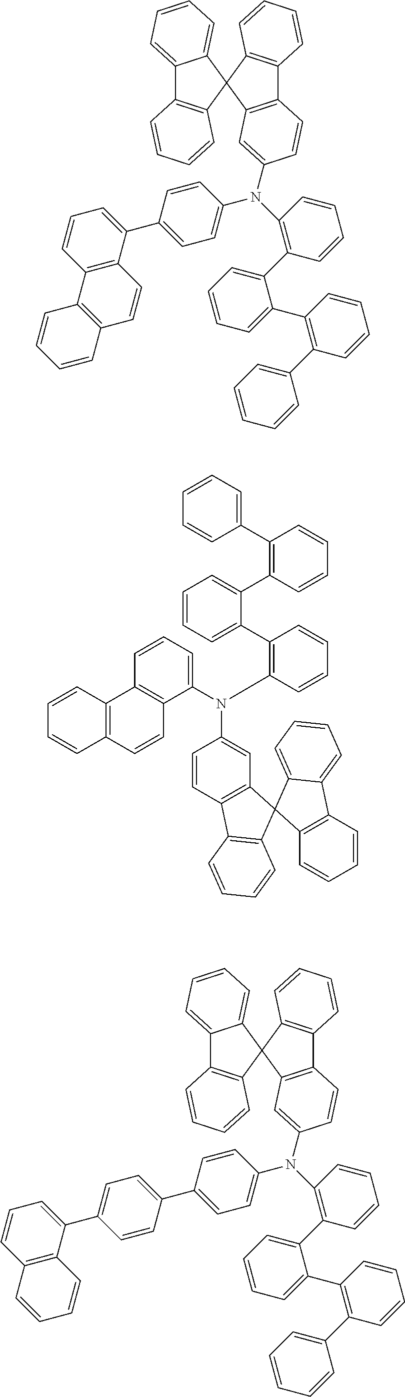 [SMILES: c1ccc(-c2ccccc2-c2ccccc2-c2ccccc2N(c2ccc(-c3cccc4c3ccc3ccccc34)cc2)c2ccc3c(c2)C2(c4ccccc4-c4ccccc42)c2ccccc2-3)cc1 ; c1ccc(-c2ccccc2-c2ccccc2-c2ccccc2N(c2ccc3c(c2)C2(c4ccccc4-c4ccccc42)c2ccccc2-3)c2cccc3c2ccc2ccccc23)cc1 ; c1ccc(-c2ccccc2-c2ccccc2-c2ccccc2N(c2ccc(-c3ccc(-c4cccc5ccccc45)cc3)cc2)c2ccc3c(c2)C2(c4ccccc4-c4ccccc42)c2ccccc2-3)cc1]

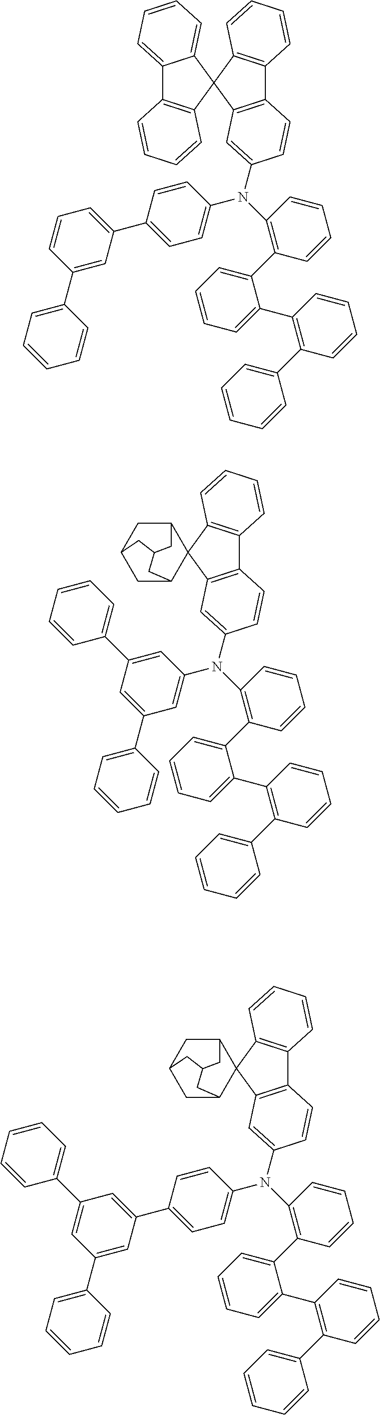 [SMILES: c1ccc(-c2cccc(-c3ccc(N(c4ccc5c(c4)C4(c6ccccc6-c6ccccc64)c4ccccc4-5)c4ccccc4-c4ccccc4-c4ccccc4-c4ccccc4)cc3)c2)cc1 ; c1ccc(-c2cc(-c3ccccc3)cc(N(c3ccc4c(c3)C3(c5ccccc5-4)C4CC5CC(C4)CC3C5)c3ccccc3-c3ccccc3-c3ccccc3-c3ccccc3)c2)cc1 ; c1ccc(-c2cc(-c3ccccc3)cc(-c3ccc(N(c4ccc5c(c4)C4(c6ccccc6-5)C5CC6CC(C5)CC4C6)c4ccccc4-c4ccccc4-c4ccccc4-c4ccccc4)cc3)c2)cc1]

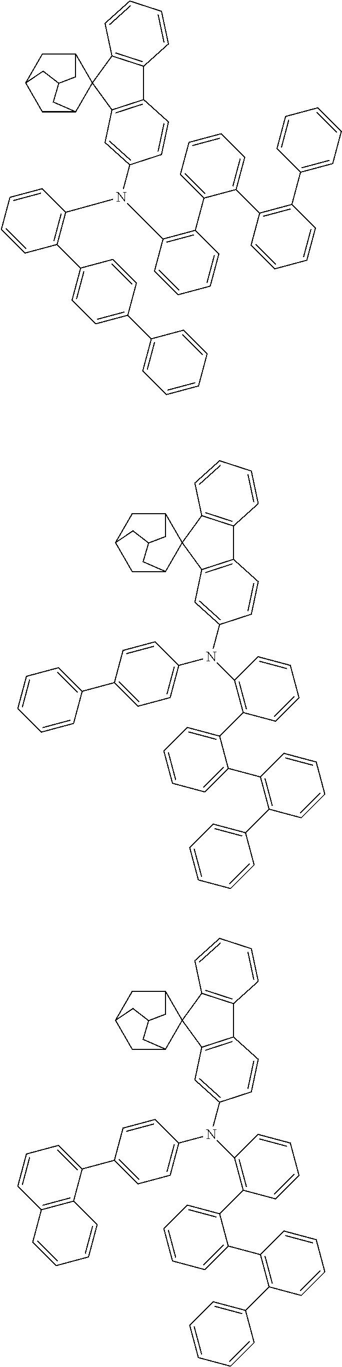 [SMILES: c1ccc(-c2ccc(-c3ccccc3N(c3ccc4c(c3)C3(c5ccccc5-4)C4CC5CC(C4)CC3C5)c3ccccc3-c3ccccc3-c3ccccc3-c3ccccc3)cc2)cc1 ; c1ccc(-c2ccc(N(c3ccc4c(c3)C3(c5ccccc5-4)C4CC5CC(C4)CC3C5)c3ccccc3-c3ccccc3-c3ccccc3-c3ccccc3)cc2)cc1 ; c1ccc(-c2ccccc2-c2ccccc2-c2ccccc2N(c2ccc(-c3cccc4ccccc34)cc2)c2ccc3c(c2)C2(c4ccccc4-3)C3CC4CC(C3)CC2C4)cc1]

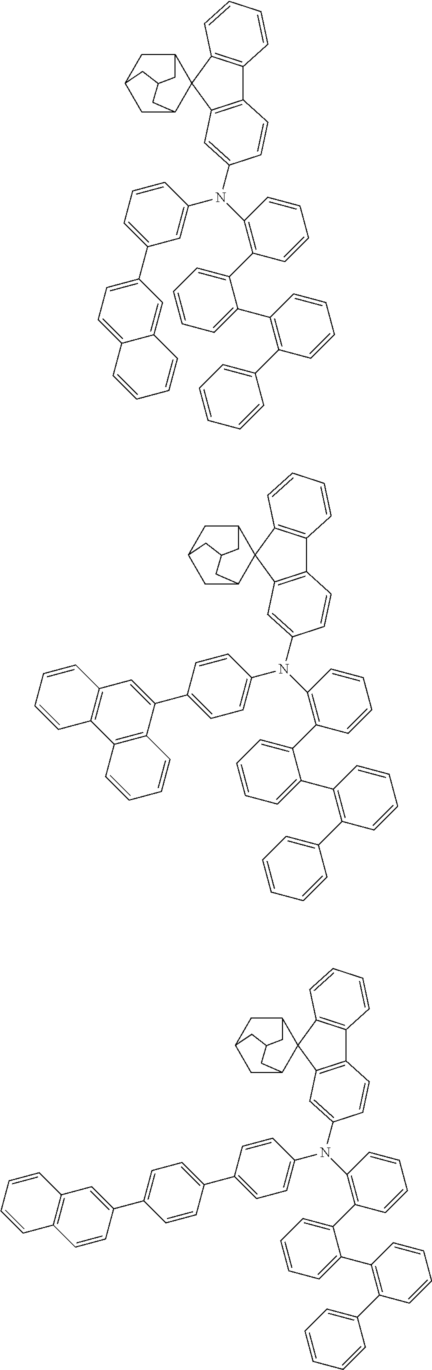 [SMILES: c1ccc(-c2ccccc2-c2ccccc2-c2ccccc2N(c2cccc(-c3ccc4ccccc4c3)c2)c2ccc3c(c2)C2(c4ccccc4-3)C3CC4CC(C3)CC2C4)cc1 ; c1ccc(-c2ccccc2-c2ccccc2-c2ccccc2N(c2ccc(-c3cc4ccccc4c4ccccc34)cc2)c2ccc3c(c2)C2(c4ccccc4-3)C3CC4CC(C3)CC2C4)cc1 ; c1ccc(-c2ccccc2-c2ccccc2-c2ccccc2N(c2ccc(-c3ccc(-c4ccc5ccccc5c4)cc3)cc2)c2ccc3c(c2)C2(c4ccccc4-3)C3CC4CC(C3)CC2C4)cc1]

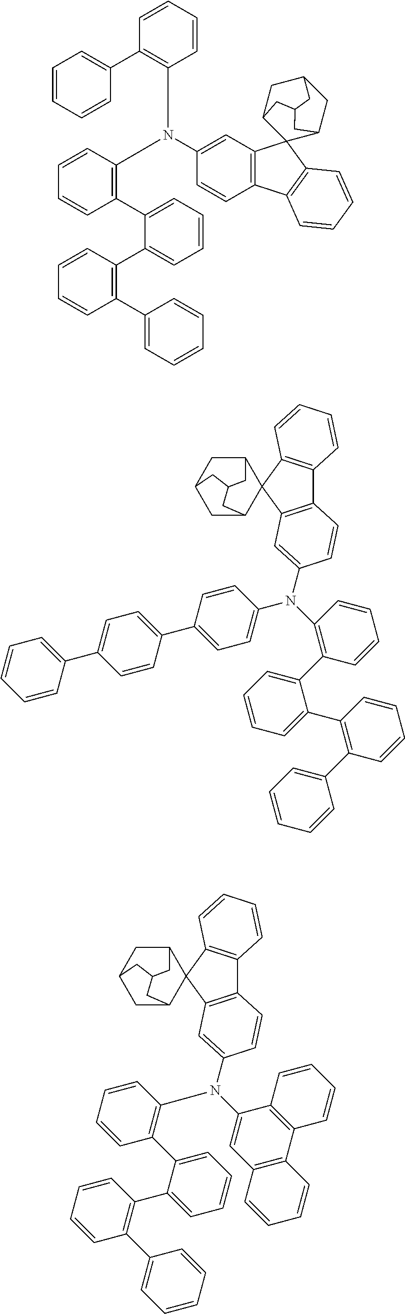 [SMILES: c1ccc(-c2ccccc2-c2ccccc2-c2ccccc2N(c2ccc3c(c2)C2(c4ccccc4-3)C3CC4CC(C3)CC2C4)c2ccccc2-c2ccccc2)cc1 ; c1ccc(-c2ccc(-c3ccc(N(c4ccc5c(c4)C4(c6ccccc6-5)C5CC6CC(C5)CC4C6)c4ccccc4-c4ccccc4-c4ccccc4-c4ccccc4)cc3)cc2)cc1 ; c1ccc(-c2ccccc2-c2ccccc2-c2ccccc2N(c2ccc3c(c2)C2(c4ccccc4-3)C3CC4CC(C3)CC2C4)c2cc3ccccc3c3ccccc23)cc1]

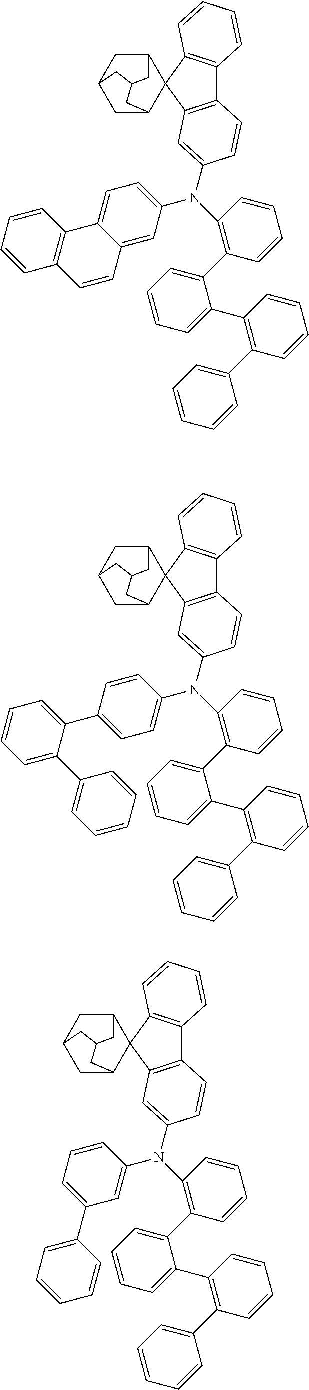 [SMILES: c1ccc(-c2ccccc2-c2ccccc2-c2ccccc2N(c2ccc3c(c2)C2(c4ccccc4-3)C3CC4CC(C3)CC2C4)c2ccc3c(ccc4ccccc43)c2)cc1 ; c1ccc(-c2ccccc2-c2ccc(N(c3ccc4c(c3)C3(c5ccccc5-4)C4CC5CC(C4)CC3C5)c3ccccc3-c3ccccc3-c3ccccc3-c3ccccc3)cc2)cc1 ; c1ccc(-c2cccc(N(c3ccc4c(c3)C3(c5ccccc5-4)C4CC5CC(C4)CC3C5)c3ccccc3-c3ccccc3-c3ccccc3-c3ccccc3)c2)cc1]

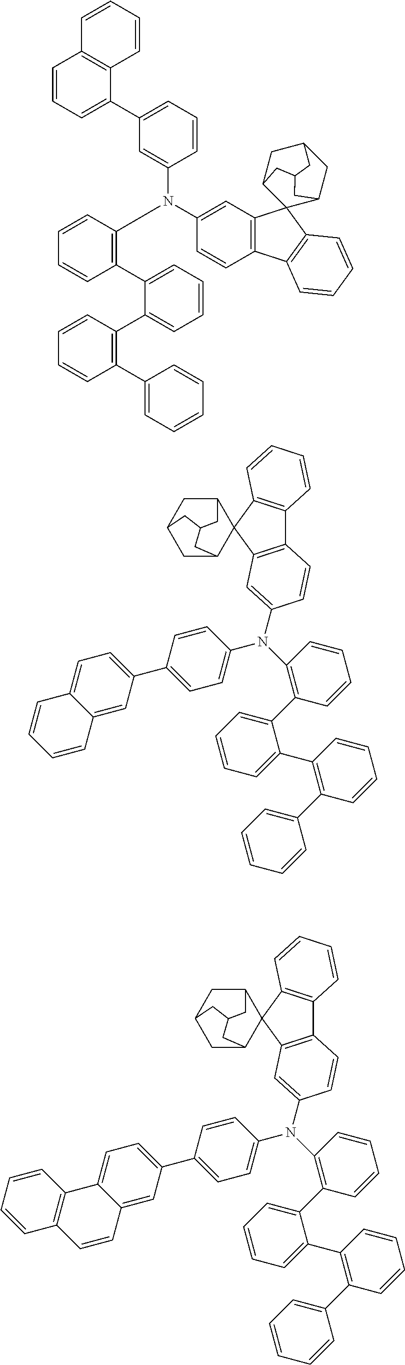 [SMILES: c1ccc(-c2ccccc2-c2ccccc2-c2ccccc2N(c2cccc(-c3cccc4ccccc34)c2)c2ccc3c(c2)C2(c4ccccc4-3)C3CC4CC(C3)CC2C4)cc1 ; c1ccc(-c2ccccc2-c2ccccc2-c2ccccc2N(c2ccc(-c3ccc4ccccc4c3)cc2)c2ccc3c(c2)C2(c4ccccc4-3)C3CC4CC(C3)CC2C4)cc1 ; c1ccc(-c2ccccc2-c2ccccc2-c2ccccc2N(c2ccc(-c3ccc4c(ccc5ccccc54)c3)cc2)c2ccc3c(c2)C2(c4ccccc4-3)C3CC4CC(C3)CC2C4)cc1]

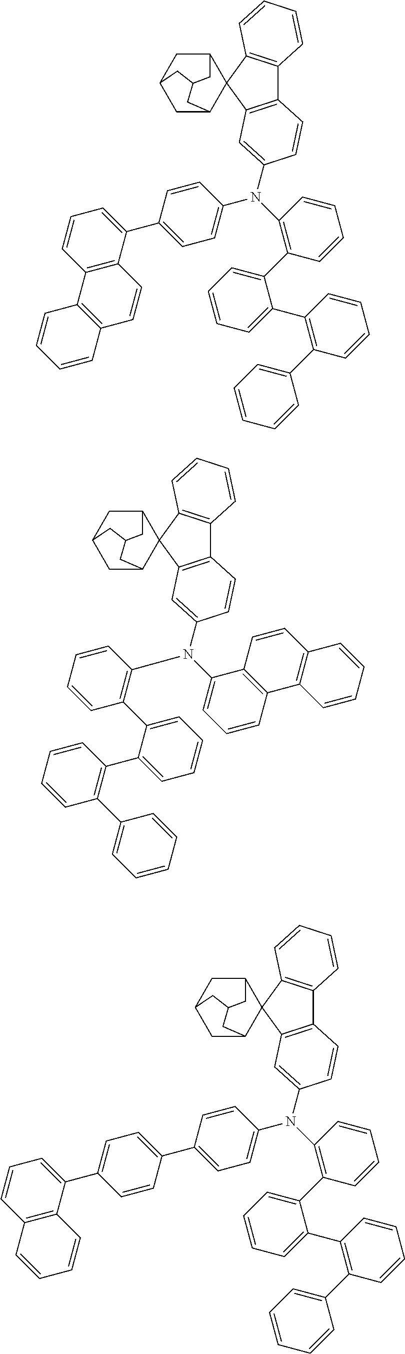 [SMILES: c1ccc(-c2ccccc2-c2ccccc2-c2ccccc2N(c2ccc(-c3cccc4c3ccc3ccccc34)cc2)c2ccc3c(c2)C2(c4ccccc4-3)C3CC4CC(C3)CC2C4)cc1 ; c1ccc(-c2ccccc2-c2ccccc2-c2ccccc2N(c2ccc3c(c2)C2(c4ccccc4-3)C3CC4CC(C3)CC2C4)c2cccc3c2ccc2ccccc23)cc1 ; c1ccc(-c2ccccc2-c2ccccc2-c2ccccc2N(c2ccc(-c3ccc(-c4cccc5ccccc45)cc3)cc2)c2ccc3c(c2)C2(c4ccccc4-3)C3CC4CC(C3)CC2C4)cc1]

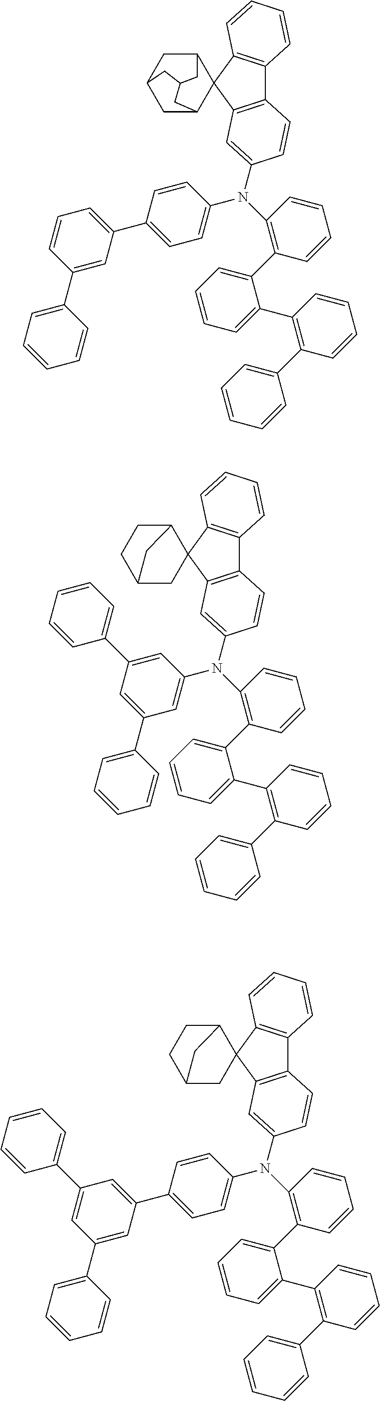 [SMILES: c1ccc(-c2cccc(-c3ccc(N(c4ccc5c(c4)C4(c6ccccc6-5)C5CC6CC(C5)CC4C6)c4ccccc4-c4ccccc4-c4ccccc4-c4ccccc4)cc3)c2)cc1 ; c1ccc(-c2cc(-c3ccccc3)cc(N(c3ccc4c(c3)C3(CC5CCC3C5)c3ccccc3-4)c3ccccc3-c3ccccc3-c3ccccc3-c3ccccc3)c2)cc1 ; c1ccc(-c2cc(-c3ccccc3)cc(-c3ccc(N(c4ccc5c(c4)C4(CC6CCC4C6)c4ccccc4-5)c4ccccc4-c4ccccc4-c4ccccc4-c4ccccc4)cc3)c2)cc1]

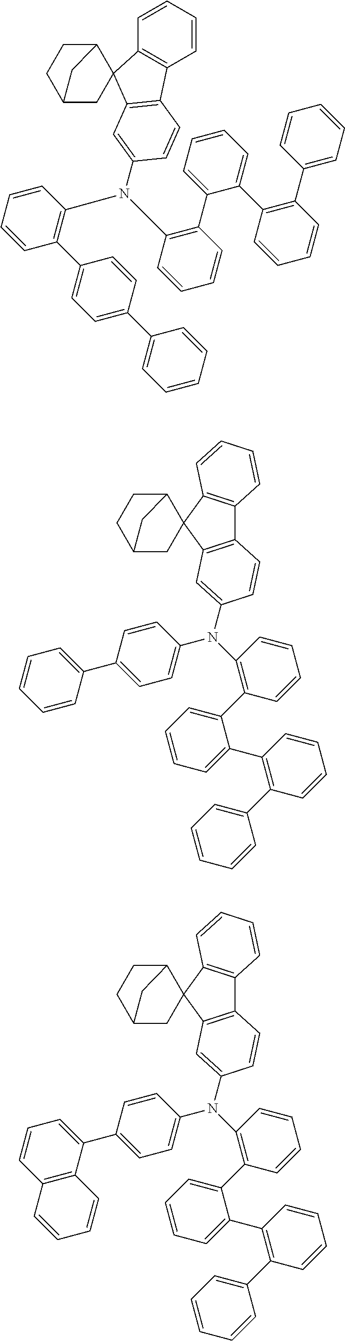

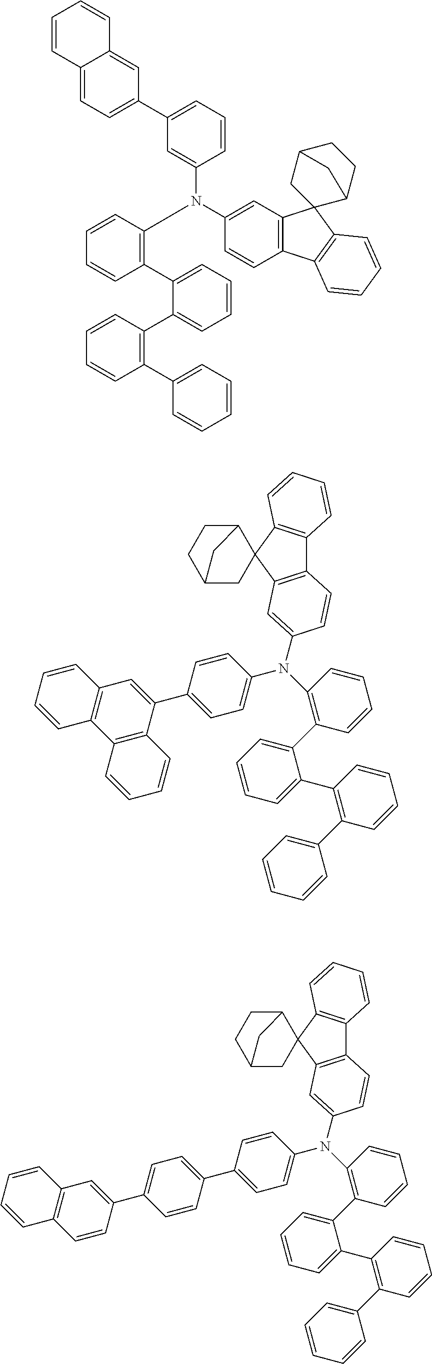 [SMILES: c1ccc(-c2ccccc2-c2ccccc2-c2ccccc2N(c2cccc(-c3ccc4ccccc4c3)c2)c2ccc3c(c2)C2(CC4CCC2C4)c2ccccc2-3)cc1 ; c1ccc(-c2ccccc2-c2ccccc2-c2ccccc2N(c2ccc(-c3cc4ccccc4c4ccccc34)cc2)c2ccc3c(c2)C2(CC4CCC2C4)c2ccccc2-3)cc1 ; c1ccc(-c2ccccc2-c2ccccc2-c2ccccc2N(c2ccc(-c3ccc(-c4ccc5ccccc5c4)cc3)cc2)c2ccc3c(c2)C2(CC4CCC2C4)c2ccccc2-3)cc1]

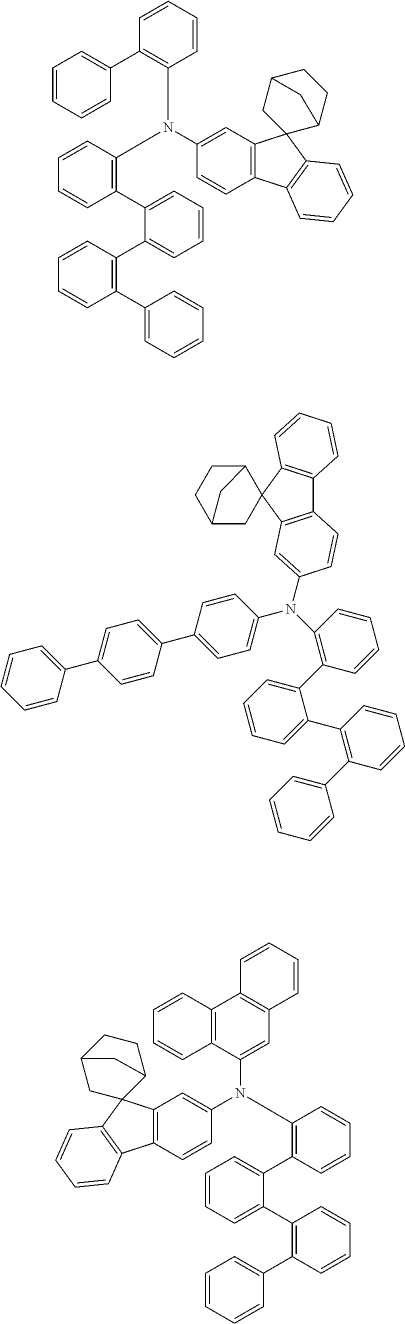 [SMILES: c1ccc(-c2ccccc2-c2ccccc2-c2ccccc2N(c2ccc3c(c2)C2(CC4CCC2C4)c2ccccc2-3)c2ccccc2-c2ccccc2)cc1 ; c1ccc(-c2ccc(-c3ccc(N(c4ccc5c(c4)C4(CC6CCC4C6)c4ccccc4-5)c4ccccc4-c4ccccc4-c4ccccc4-c4ccccc4)cc3)cc2)cc1 ; c1ccc(-c2ccccc2-c2ccccc2-c2ccccc2N(c2ccc3c(c2)C2(CC4CCC2C4)c2ccccc2-3)c2cc3ccccc3c3ccccc23)cc1]

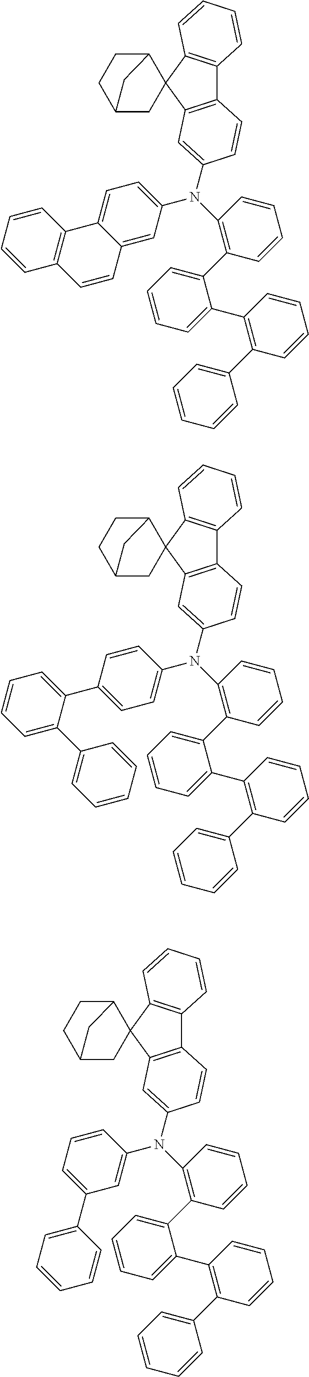

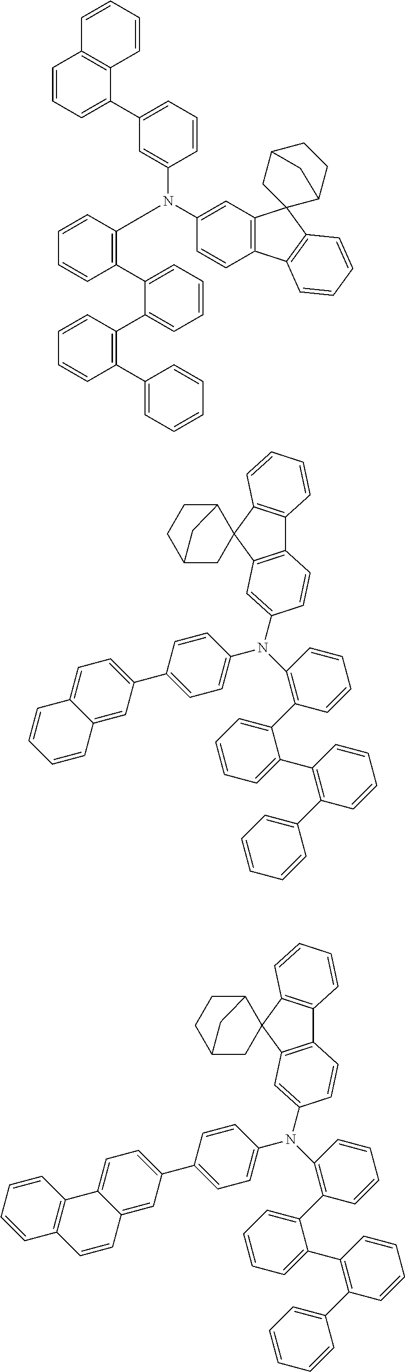 [SMILES: c1ccc(-c2ccccc2-c2ccccc2-c2ccccc2N(c2cccc(-c3cccc4ccccc34)c2)c2ccc3c(c2)C2(CC4CCC2C4)c2ccccc2-3)cc1 ; c1ccc(-c2ccccc2-c2ccccc2-c2ccccc2N(c2ccc(-c3ccc4ccccc4c3)cc2)c2ccc3c(c2)C2(CC4CCC2C4)c2ccccc2-3)cc1 ; c1ccc(-c2ccccc2-c2ccccc2-c2ccccc2N(c2ccc(-c3ccc4c(ccc5ccccc54)c3)cc2)c2ccc3c(c2)C2(CC4CCC2C4)c2ccccc2-3)cc1]

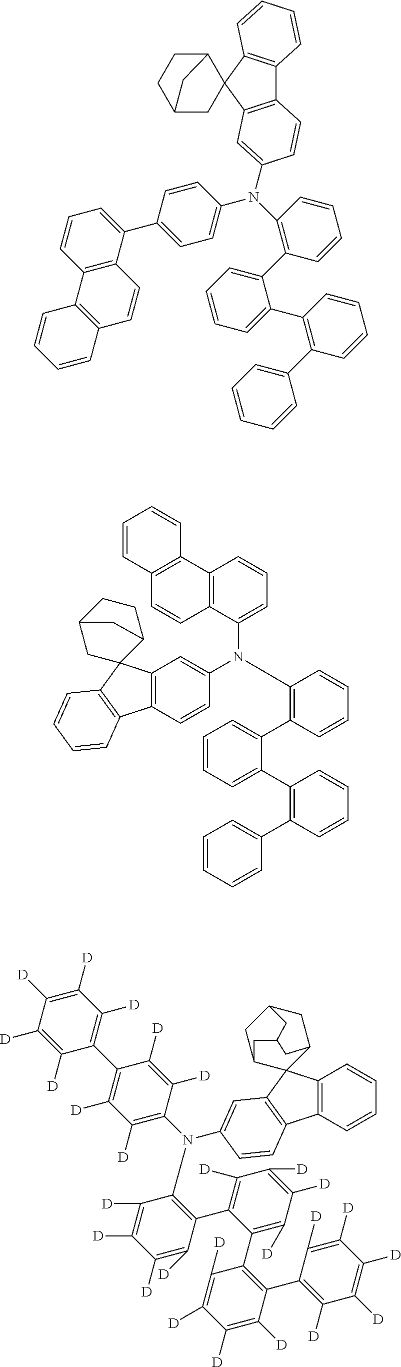 [SMILES: c1ccc(-c2ccccc2-c2ccccc2-c2ccccc2N(c2ccc(-c3cccc4c3ccc3ccccc34)cc2)c2ccc3c(c2)C2(CC4CCC2C4)c2ccccc2-3)cc1 ; c1ccc(-c2ccccc2-c2ccccc2-c2ccccc2N(c2ccc3c(c2)C2(CC4CCC2C4)c2ccccc2-3)c2cccc3c2ccc2ccccc23)cc1 ; [2H]c1c([2H])c([2H])c(-c2c([2H])c([2H])c(N(c3ccc4c(c3)C3(c5ccccc5-4)C4CC5CC(C4)CC3C5)c3c([2H])c([2H])c([2H])c([2H])c3-c3c([2H])c([2H])c([2H])c([2H])c3-c3c([2H])c([2H])c([2H])c([2H])c3-c3c([2H])c([2H])c([2H])c([2H])c3[2H])c([2H])c2[2H])c([2H])c1[2H]]

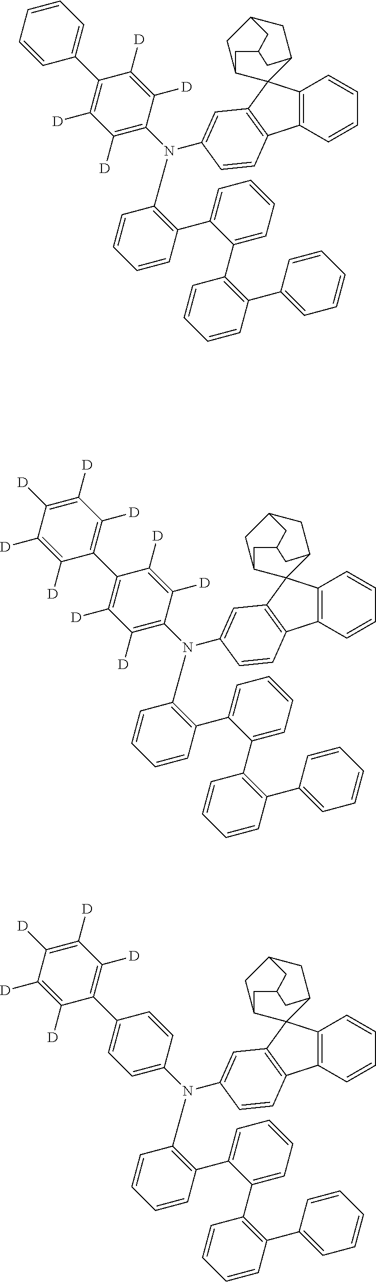 [SMILES: [2H]c1c([2H])c(N(c2ccc3c(c2)C2(c4ccccc4-3)C3CC4CC(C3)CC2C4)c2ccccc2-c2ccccc2-c2ccccc2-c2ccccc2)c([2H])c([2H])c1-c1ccccc1 ; [2H]c1c([2H])c([2H])c(-c2c([2H])c([2H])c(N(c3ccc4c(c3)C3(c5ccccc5-4)C4CC5CC(C4)CC3C5)c3ccccc3-c3ccccc3-c3ccccc3-c3ccccc3)c([2H])c2[2H])c([2H])c1[2H] ; [2H]c1c([2H])c([2H])c(-c2ccc(N(c3ccc4c(c3)C3(c5ccccc5-4)C4CC5CC(C4)CC3C5)c3ccccc3-c3ccccc3-c3ccccc3-c3ccccc3)cc2)c([2H])c1[2H]]

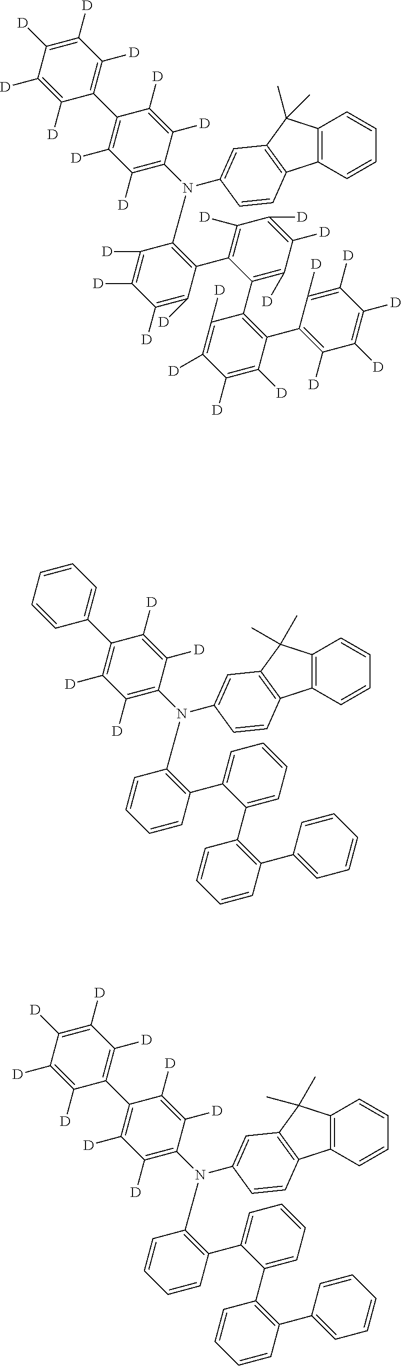 [SMILES: [2H]c1c([2H])c([2H])c(-c2c([2H])c([2H])c(N(c3ccc4c(c3)C(C)(C)c3ccccc3-4)c3c([2H])c([2H])c([2H])c([2H])c3-c3c([2H])c([2H])c([2H])c([2H])c3-c3c([2H])c([2H])c([2H])c([2H])c3-c3c([2H])c([2H])c([2H])c([2H])c3[2H])c([2H])c2[2H])c([2H])c1[2H] ; [2H]c1c([2H])c(N(c2ccc3c(c2)C(C)(C)c2ccccc2-3)c2ccccc2-c2ccccc2-c2ccccc2-c2ccccc2)c([2H])c([2H])c1-c1ccccc1 ; [2H]c1c([2H])c([2H])c(-c2c([2H])c([2H])c(N(c3ccc4c(c3)C(C)(C)c3ccccc3-4)c3ccccc3-c3ccccc3-c3ccccc3-c3ccccc3)c([2H])c2[2H])c([2H])c1[2H]]

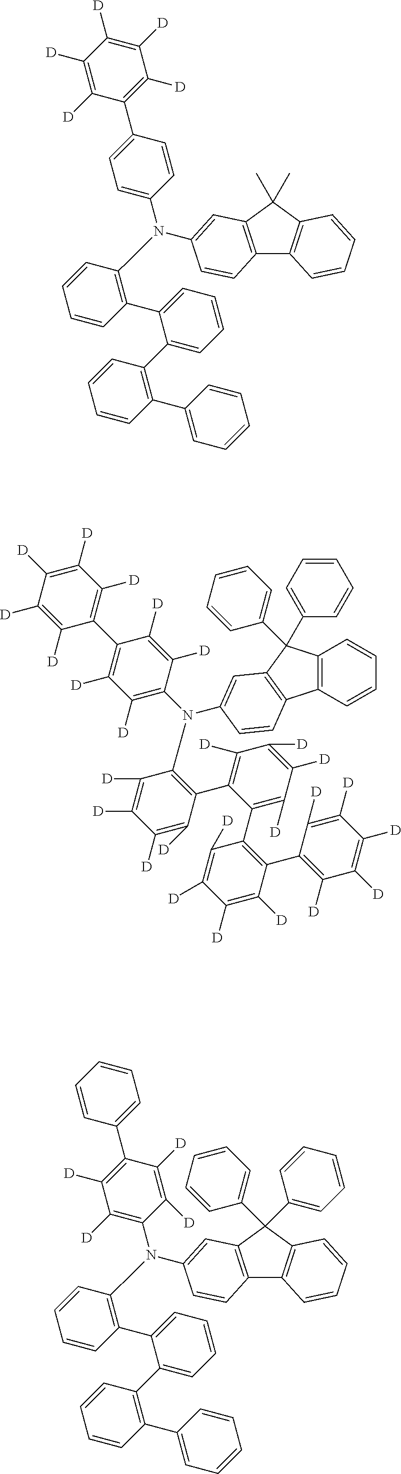 [SMILES: [2H]c1c([2H])c([2H])c(-c2ccc(N(c3ccc4c(c3)C(C)(C)c3ccccc3-4)c3ccccc3-c3ccccc3-c3ccccc3-c3ccccc3)cc2)c([2H])c1[2H] ; [2H]c1c([2H])c([2H])c(-c2c([2H])c([2H])c(N(c3ccc4c(c3)C(c3ccccc3)(c3ccccc3)c3ccccc3-4)c3c([2H])c([2H])c([2H])c([2H])c3-c3c([2H])c([2H])c([2H])c([2H])c3-c3c([2H])c([2H])c([2H])c([2H])c3-c3c([2H])c([2H])c([2H])c([2H])c3[2H])c([2H])c2[2H])c([2H])c1[2H] ; [2H]c1c([2H])c(N(c2ccc3c(c2)C(c2ccccc2)(c2ccccc2)c2ccccc2-3)c2ccccc2-c2ccccc2-c2ccccc2-c2ccccc2)c([2H])c([2H])c1-c1ccccc1]

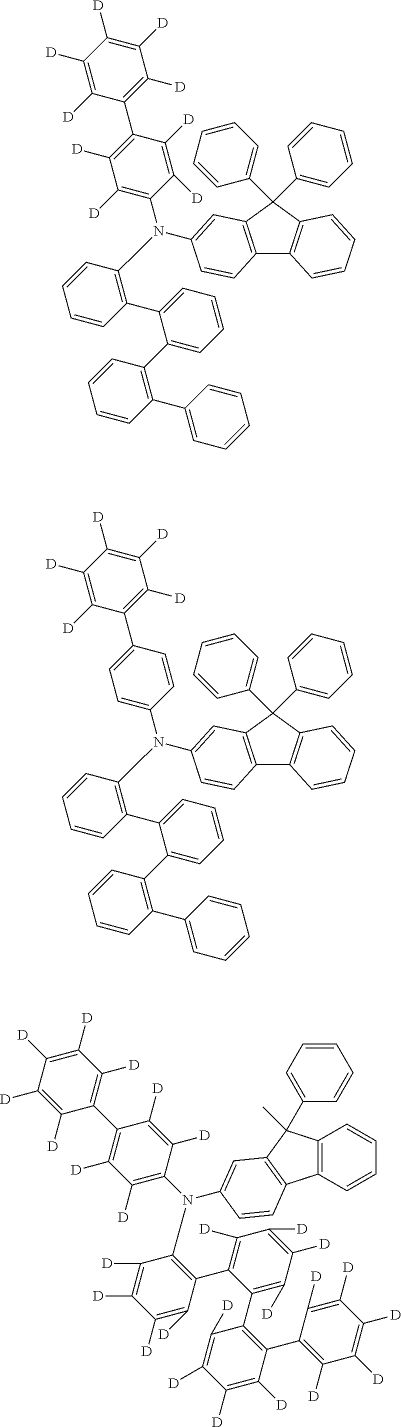

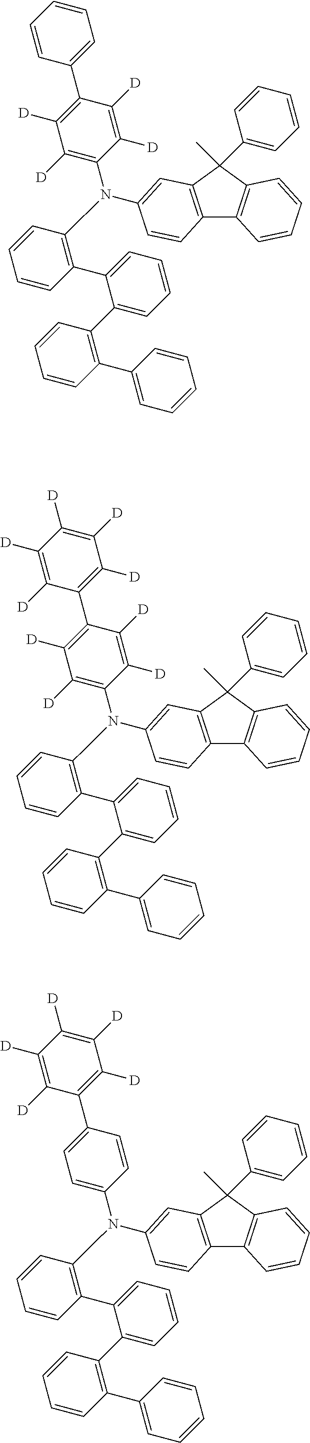 [SMILES: [2H]c1c([2H])c(N(c2ccc3c(c2)C(C)(c2ccccc2)c2ccccc2-3)c2ccccc2-c2ccccc2-c2ccccc2-c2ccccc2)c([2H])c([2H])c1-c1ccccc1 ; [2H]c1c([2H])c([2H])c(-c2c([2H])c([2H])c(N(c3ccc4c(c3)C(C)(c3ccccc3)c3ccccc3-4)c3ccccc3-c3ccccc3-c3ccccc3-c3ccccc3)c([2H])c2[2H])c([2H])c1[2H] ; [2H]c1c([2H])c([2H])c(-c2ccc(N(c3ccc4c(c3)C(C)(c3ccccc3)c3ccccc3-4)c3ccccc3-c3ccccc3-c3ccccc3-c3ccccc3)cc2)c([2H])c1[2H]]

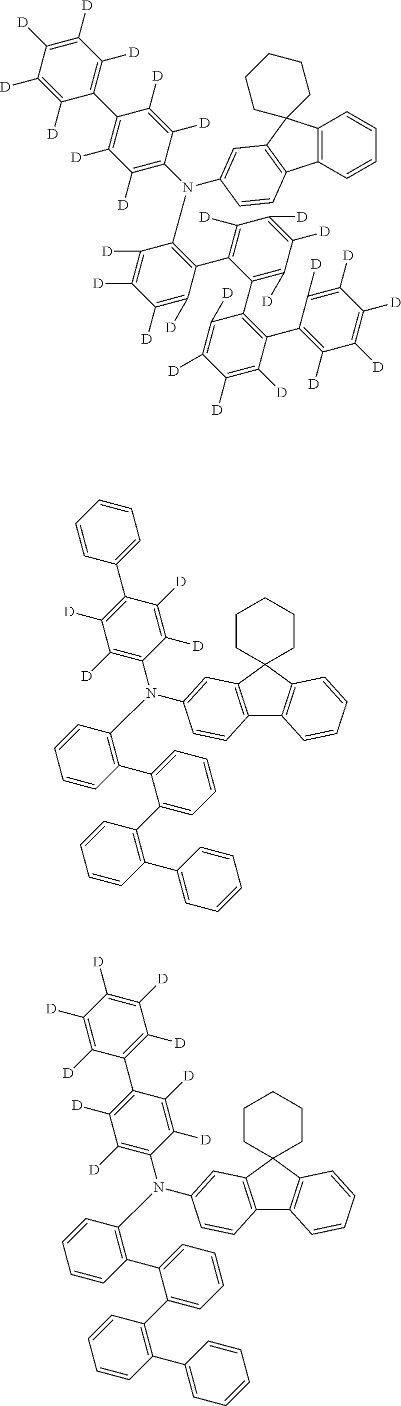 [SMILES: [2H]c1c([2H])c([2H])c(-c2c([2H])c([2H])c(N(c3ccc4c(c3)C3(CCCCC3)c3ccccc3-4)c3c([2H])c([2H])c([2H])c([2H])c3-c3c([2H])c([2H])c([2H])c([2H])c3-c3c([2H])c([2H])c([2H])c([2H])c3-c3c([2H])c([2H])c([2H])c([2H])c3[2H])c([2H])c2[2H])c([2H])c1[2H] ; [2H]c1c([2H])c(N(c2ccc3c(c2)C2(CCCCC2)c2ccccc2-3)c2ccccc2-c2ccccc2-c2ccccc2-c2ccccc2)c([2H])c([2H])c1-c1ccccc1 ; [2H]c1c([2H])c([2H])c(-c2c([2H])c([2H])c(N(c3ccc4c(c3)C3(CCCCC3)c3ccccc3-4)c3ccccc3-c3ccccc3-c3ccccc3-c3ccccc3)c([2H])c2[2H])c([2H])c1[2H]]

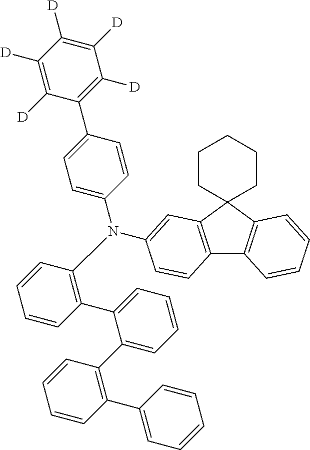 [SMILES: [2H]c1c([2H])c([2H])c(-c2ccc(N(c3ccc4c(c3)C3(CCCCC3)c3ccccc3-4)c3ccccc3-c3ccccc3-c3ccccc3-c3ccccc3)cc2)c([2H])c1[2H]]

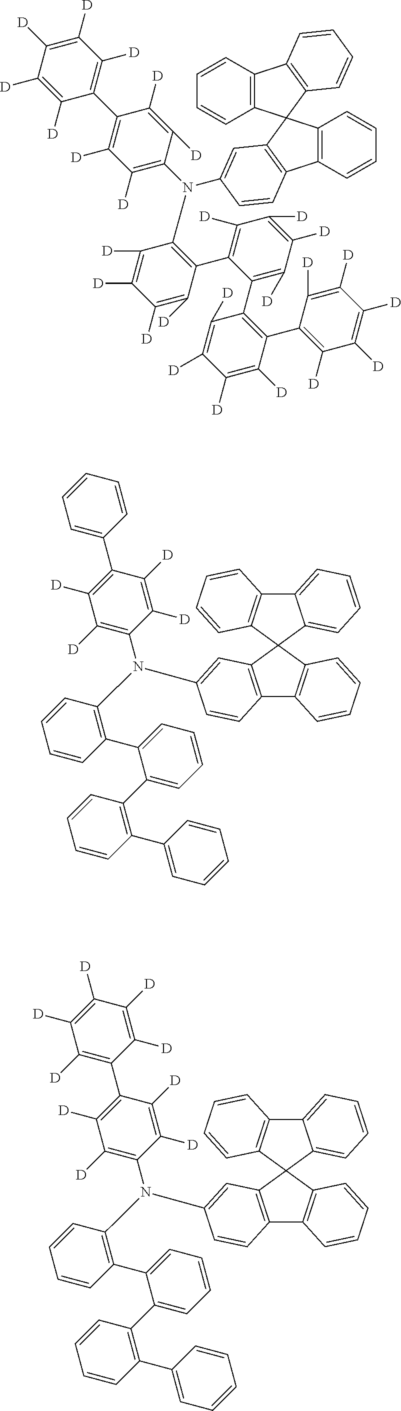

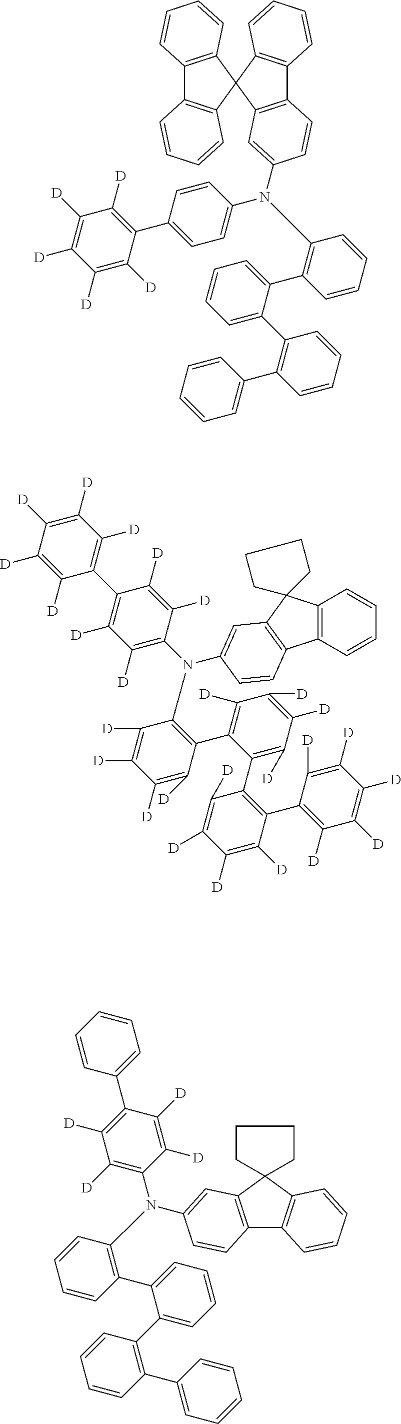 [SMILES: [2H]c1c([2H])c([2H])c(-c2ccc(N(c3ccc4c(c3)C3(c5ccccc5-c5ccccc53)c3ccccc3-4)c3ccccc3-c3ccccc3-c3ccccc3-c3ccccc3)cc2)c([2H])c1[2H] ; [2H]c1c([2H])c([2H])c(-c2c([2H])c([2H])c(N(c3ccc4c(c3)C3(CCCC3)c3ccccc3-4)c3c([2H])c([2H])c([2H])c([2H])c3-c3c([2H])c([2H])c([2H])c([2H])c3-c3c([2H])c([2H])c([2H])c([2H])c3-c3c([2H])c([2H])c([2H])c([2H])c3[2H])c([2H])c2[2H])c([2H])c1[2H] ; [2H]c1c([2H])c(N(c2ccc3c(c2)C2(CCCC2)c2ccccc2-3)c2ccccc2-c2ccccc2-c2ccccc2-c2ccccc2)c([2H])c([2H])c1-c1ccccc1]

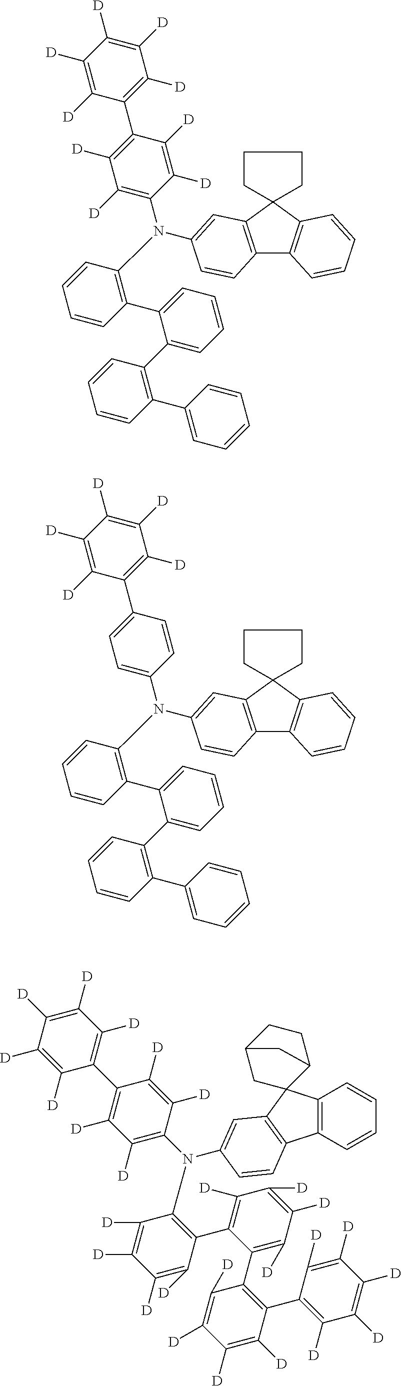 [SMILES: [2H]c1c([2H])c([2H])c(-c2c([2H])c([2H])c(N(c3ccc4c(c3)C3(CCCC3)c3ccccc3-4)c3ccccc3-c3ccccc3-c3ccccc3-c3ccccc3)c([2H])c2[2H])c([2H])c1[2H] ; [2H]c1c([2H])c([2H])c(-c2ccc(N(c3ccc4c(c3)C3(CCCC3)c3ccccc3-4)c3ccccc3-c3ccccc3-c3ccccc3-c3ccccc3)cc2)c([2H])c1[2H] ; [2H]c1c([2H])c([2H])c(-c2c([2H])c([2H])c(N(c3ccc4c(c3)C3(CC5CCC3C5)c3ccccc3-4)c3c([2H])c([2H])c([2H])c([2H])c3-c3c([2H])c([2H])c([2H])c([2H])c3-c3c([2H])c([2H])c([2H])c([2H])c3-c3c([2H])c([2H])c([2H])c([2H])c3[2H])c([2H])c2[2H])c([2H])c1[2H]]

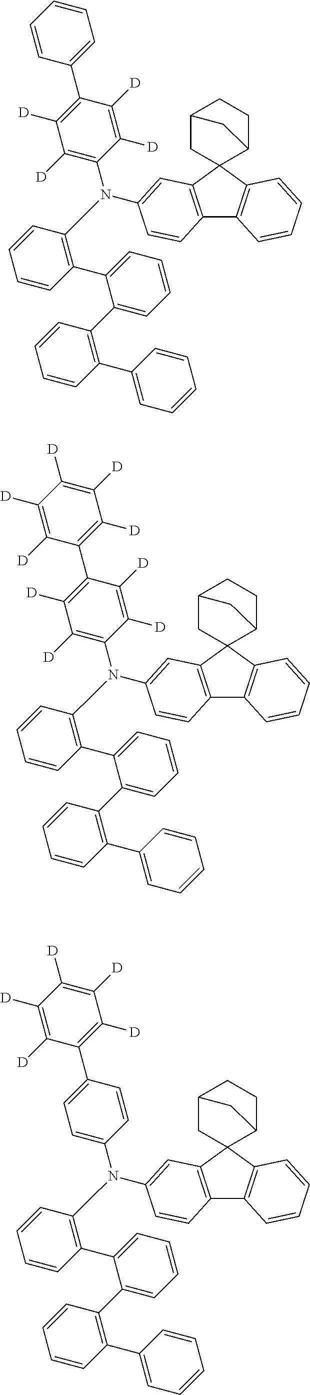 [SMILES: [2H]c1c([2H])c(N(c2ccc3c(c2)C2(CC4CCC2C4)c2ccccc2-3)c2ccccc2-c2ccccc2-c2ccccc2-c2ccccc2)c([2H])c([2H])c1-c1ccccc1 ; [2H]c1c([2H])c([2H])c(-c2c([2H])c([2H])c(N(c3ccc4c(c3)C3(CC5CCC3C5)c3ccccc3-4)c3ccccc3-c3ccccc3-c3ccccc3-c3ccccc3)c([2H])c2[2H])c([2H])c1[2H] ; [2H]c1c([2H])c([2H])c(-c2ccc(N(c3ccc4c(c3)C3(CC5CCC3C5)c3ccccc3-4)c3ccccc3-c3ccccc3-c3ccccc3-c3ccccc3)cc2)c([2H])c1[2H]]

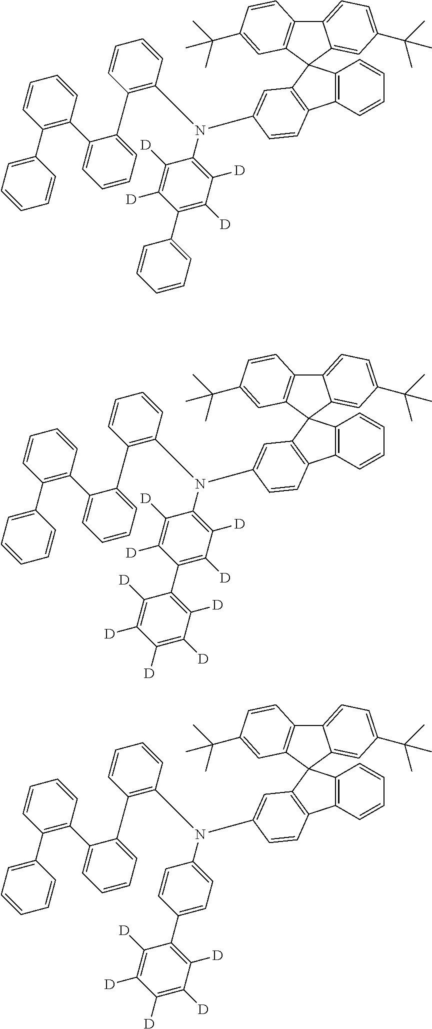 [SMILES: [2H]c1c([2H])c(N(c2ccc3c(c2)C2(c4ccccc4-3)c3cc(C(C)(C)C)ccc3-c3ccc(C(C)(C)C)cc32)c2ccccc2-c2ccccc2-c2ccccc2-c2ccccc2)c([2H])c([2H])c1-c1ccccc1 ; [2H]c1c([2H])c([2H])c(-c2c([2H])c([2H])c(N(c3ccc4c(c3)C3(c5ccccc5-4)c4cc(C(C)(C)C)ccc4-c4ccc(C(C)(C)C)cc43)c3ccccc3-c3ccccc3-c3ccccc3-c3ccccc3)c([2H])c2[2H])c([2H])c1[2H] ; [2H]c1c([2H])c([2H])c(-c2ccc(N(c3ccc4c(c3)C3(c5ccccc5-4)c4cc(C(C)(C)C)ccc4-c4ccc(C(C)(C)C)cc43)c3ccccc3-c3ccccc3-c3ccccc3-c3ccccc3)cc2)c([2H])c1[2H]]

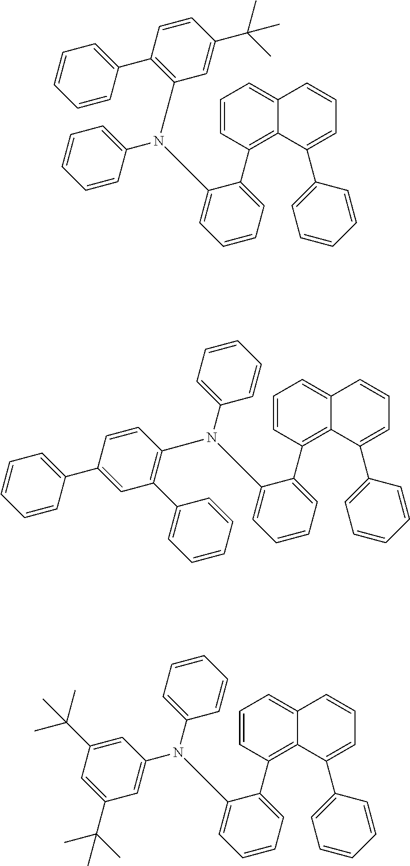 [SMILES: CC(C)(C)c1ccc(-c2ccccc2)c(N(c2ccccc2)c2ccccc2-c2cccc3cccc(-c4ccccc4)c23)c1 ; c1ccc(-c2ccc(N(c3ccccc3)c3ccccc3-c3cccc4cccc(-c5ccccc5)c34)c(-c3ccccc3)c2)cc1 ; CC(C)(C)c1cc(N(c2ccccc2)c2ccccc2-c2cccc3cccc(-c4ccccc4)c23)cc(C(C)(C)C)c1]

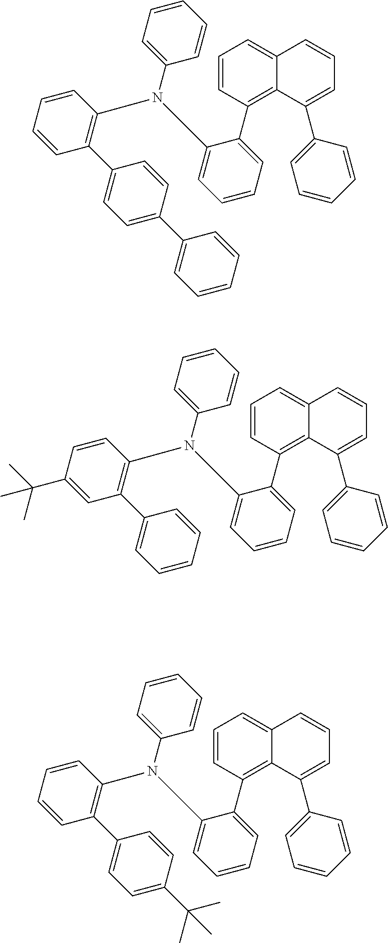 [SMILES: c1ccc(-c2ccc(-c3ccccc3N(c3ccccc3)c3ccccc3-c3cccc4cccc(-c5ccccc5)c34)cc2)cc1 ; CC(C)(C)c1ccc(N(c2ccccc2)c2ccccc2-c2cccc3cccc(-c4ccccc4)c23)c(-c2ccccc2)c1 ; CC(C)(C)c1ccc(-c2ccccc2N(c2ccccc2)c2ccccc2-c2cccc3cccc(-c4ccccc4)c23)cc1]

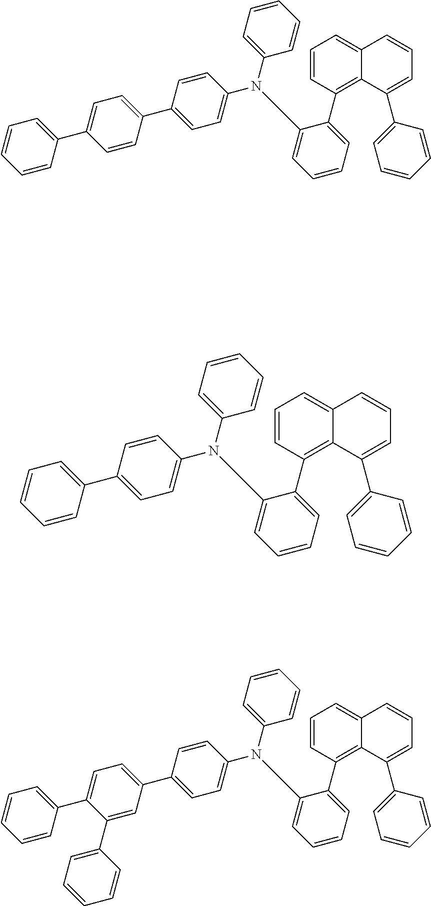 [SMILES: c1ccc(-c2ccc(-c3ccc(N(c4ccccc4)c4ccccc4-c4cccc5cccc(-c6ccccc6)c45)cc3)cc2)cc1 ; c1ccc(-c2ccc(N(c3ccccc3)c3ccccc3-c3cccc4cccc(-c5ccccc5)c34)cc2)cc1 ; c1ccc(-c2ccc(-c3ccc(N(c4ccccc4)c4ccccc4-c4cccc5cccc(-c6ccccc6)c45)cc3)cc2-c2ccccc2)cc1]

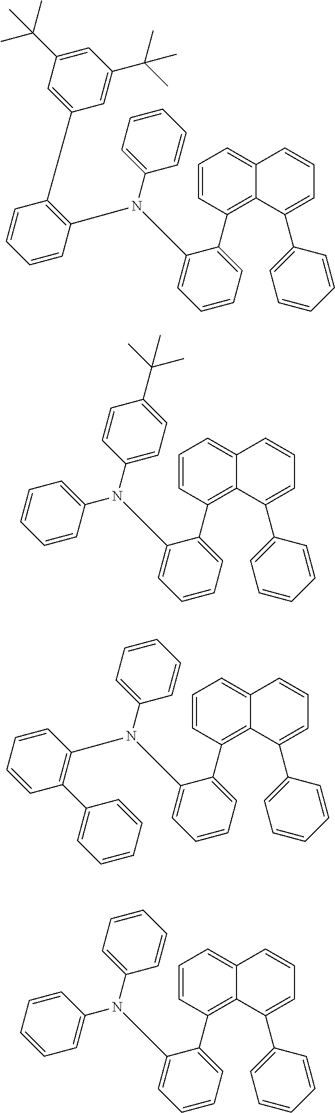

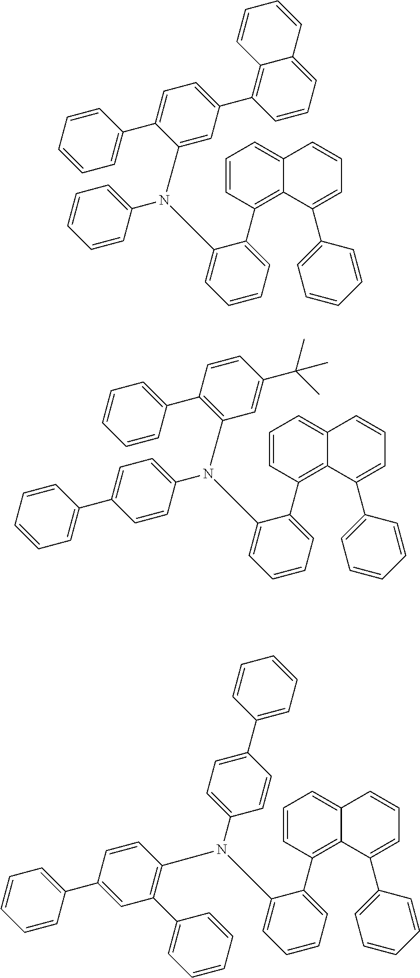

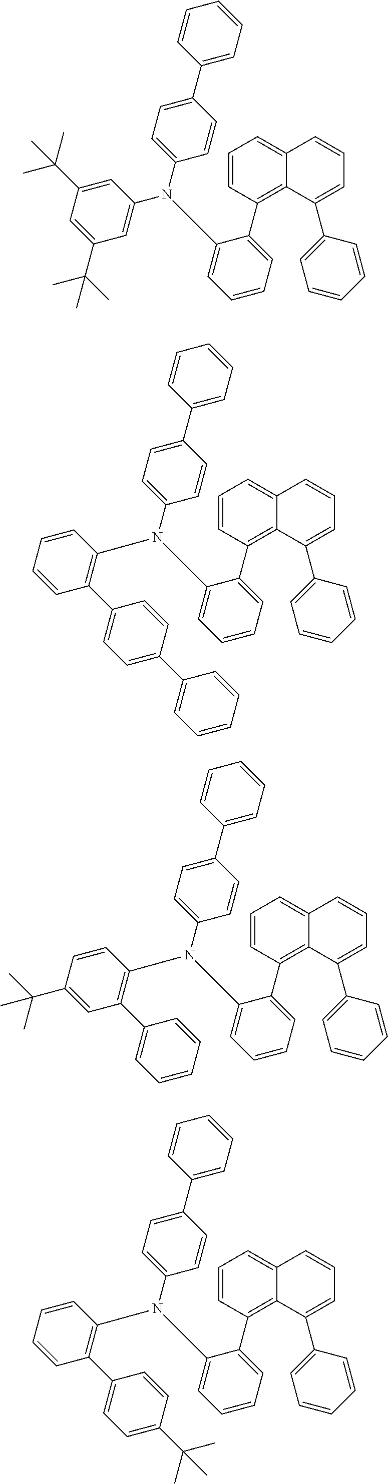

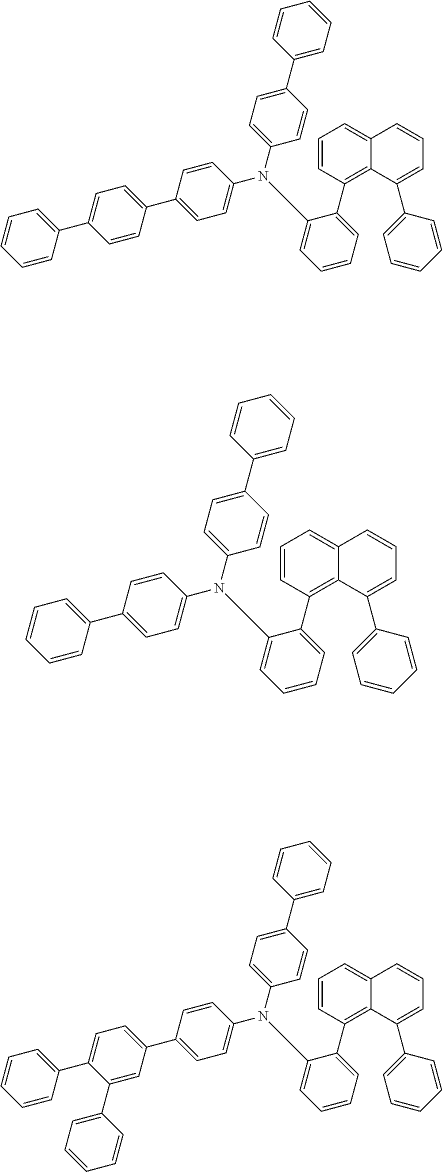 [SMILES: c1ccc(-c2ccc(-c3ccc(N(c4ccc(-c5ccccc5)cc4)c4ccccc4-c4cccc5cccc(-c6ccccc6)c45)cc3)cc2)cc1 ; c1ccc(-c2ccc(N(c3ccc(-c4ccccc4)cc3)c3ccccc3-c3cccc4cccc(-c5ccccc5)c34)cc2)cc1 ; c1ccc(-c2ccc(N(c3ccc(-c4ccc(-c5ccccc5)c(-c5ccccc5)c4)cc3)c3ccccc3-c3cccc4cccc(-c5ccccc5)c34)cc2)cc1]

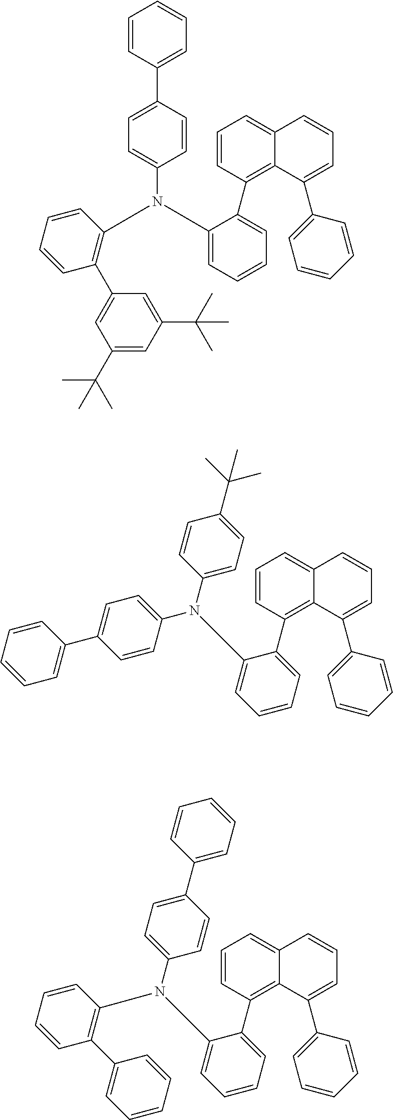 [SMILES: CC(C)(C)c1cc(-c2ccccc2N(c2ccc(-c3ccccc3)cc2)c2ccccc2-c2cccc3cccc(-c4ccccc4)c23)cc(C(C)(C)C)c1 ; CC(C)(C)c1ccc(N(c2ccc(-c3ccccc3)cc2)c2ccccc2-c2cccc3cccc(-c4ccccc4)c23)cc1 ; c1ccc(-c2ccc(N(c3ccccc3-c3ccccc3)c3ccccc3-c3cccc4cccc(-c5ccccc5)c34)cc2)cc1]

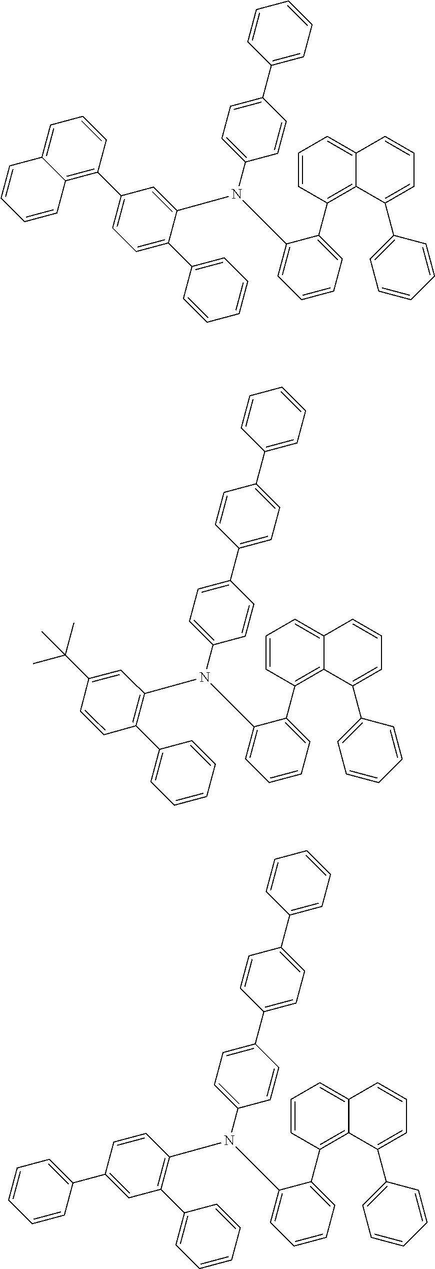 [SMILES: c1ccc(-c2ccc(N(c3cc(-c4cccc5ccccc45)ccc3-c3ccccc3)c3ccccc3-c3cccc4cccc(-c5ccccc5)c34)cc2)cc1 ; CC(C)(C)c1ccc(-c2ccccc2)c(N(c2ccc(-c3ccc(-c4ccccc4)cc3)cc2)c2ccccc2-c2cccc3cccc(-c4ccccc4)c23)c1 ; c1ccc(-c2ccc(-c3ccc(N(c4ccc(-c5ccccc5)cc4-c4ccccc4)c4ccccc4-c4cccc5cccc(-c6ccccc6)c45)cc3)cc2)cc1]

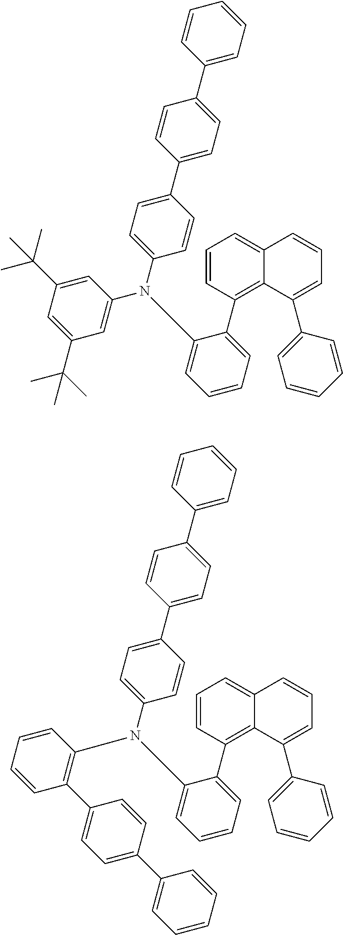 [SMILES: CC(C)(C)c1cc(N(c2ccc(-c3ccc(-c4ccccc4)cc3)cc2)c2ccccc2-c2cccc3cccc(-c4ccccc4)c23)cc(C(C)(C)C)c1 ; c1ccc(-c2ccc(-c3ccc(N(c4ccccc4-c4ccc(-c5ccccc5)cc4)c4ccccc4-c4cccc5cccc(-c6ccccc6)c45)cc3)cc2)cc1]

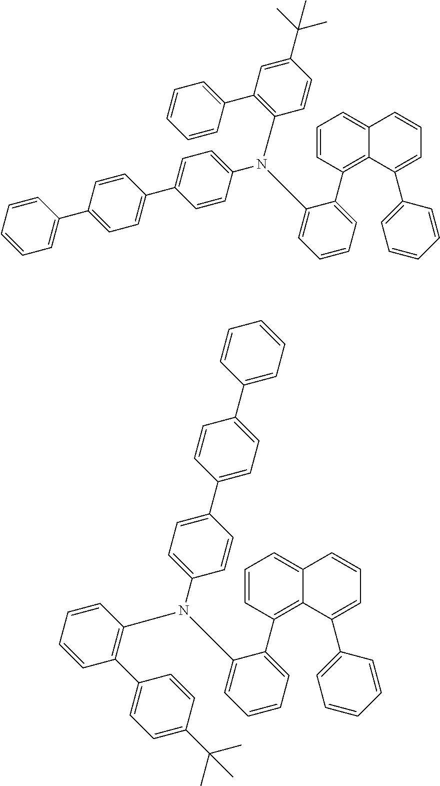 [SMILES: CC(C)(C)c1ccc(N(c2ccc(-c3ccc(-c4ccccc4)cc3)cc2)c2ccccc2-c2cccc3cccc(-c4ccccc4)c23)c(-c2ccccc2)c1 ; CC(C)(C)c1ccc(-c2ccccc2N(c2ccc(-c3ccc(-c4ccccc4)cc3)cc2)c2ccccc2-c2cccc3cccc(-c4ccccc4)c23)cc1]

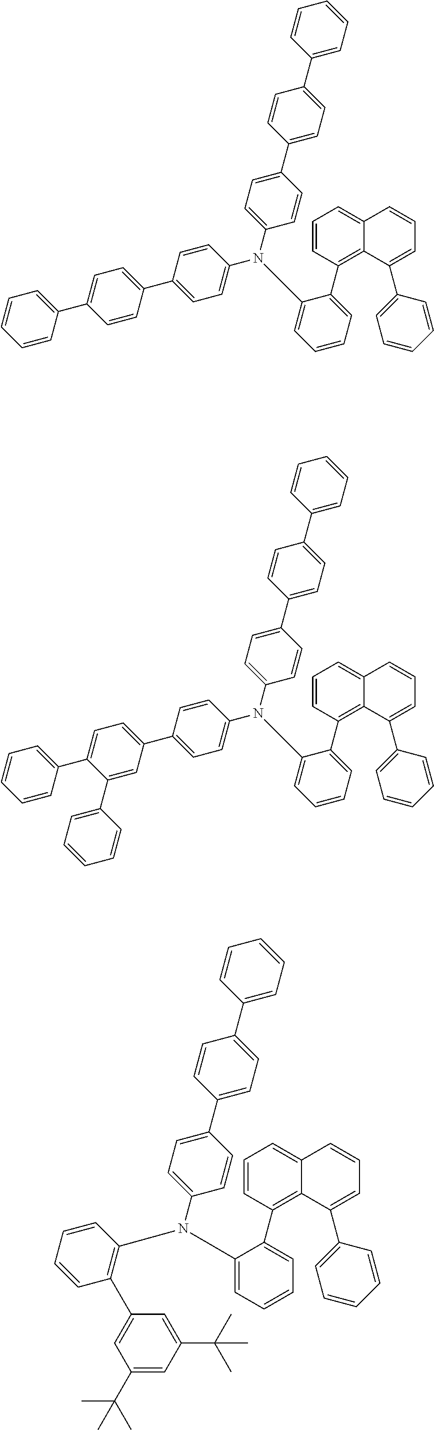 [SMILES: c1ccc(-c2ccc(-c3ccc(N(c4ccc(-c5ccc(-c6ccccc6)cc5)cc4)c4ccccc4-c4cccc5cccc(-c6ccccc6)c45)cc3)cc2)cc1 ; c1ccc(-c2ccc(-c3ccc(N(c4ccc(-c5ccc(-c6ccccc6)c(-c6ccccc6)c5)cc4)c4ccccc4-c4cccc5cccc(-c6ccccc6)c45)cc3)cc2)cc1 ; CC(C)(C)c1cc(-c2ccccc2N(c2ccc(-c3ccc(-c4ccccc4)cc3)cc2)c2ccccc2-c2cccc3cccc(-c4ccccc4)c23)cc(C(C)(C)C)c1]

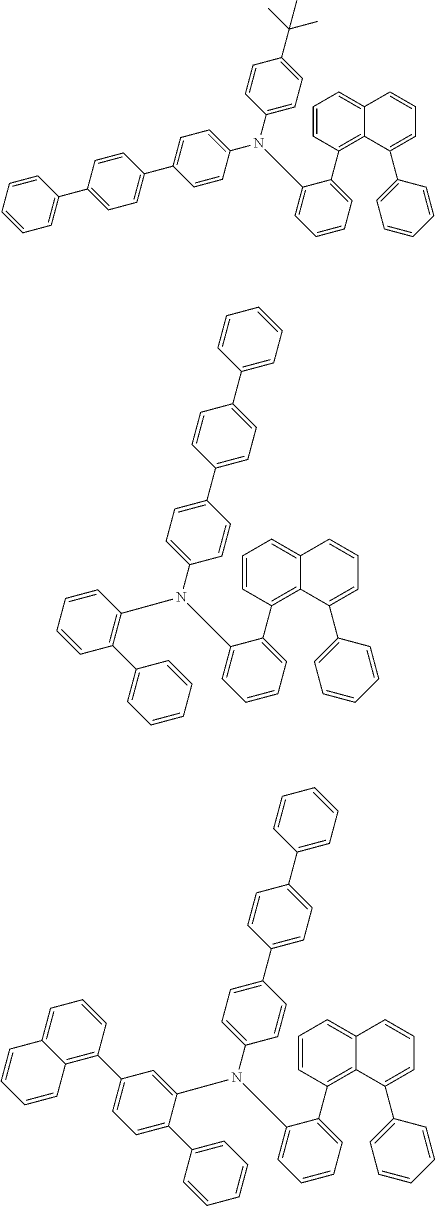 [SMILES: CC(C)(C)c1ccc(N(c2ccc(-c3ccc(-c4ccccc4)cc3)cc2)c2ccccc2-c2cccc3cccc(-c4ccccc4)c23)cc1 ; c1ccc(-c2ccc(-c3ccc(N(c4ccccc4-c4ccccc4)c4ccccc4-c4cccc5cccc(-c6ccccc6)c45)cc3)cc2)cc1 ; c1ccc(-c2ccc(-c3ccc(N(c4cc(-c5cccc6ccccc56)ccc4-c4ccccc4)c4ccccc4-c4cccc5cccc(-c6ccccc6)c45)cc3)cc2)cc1]

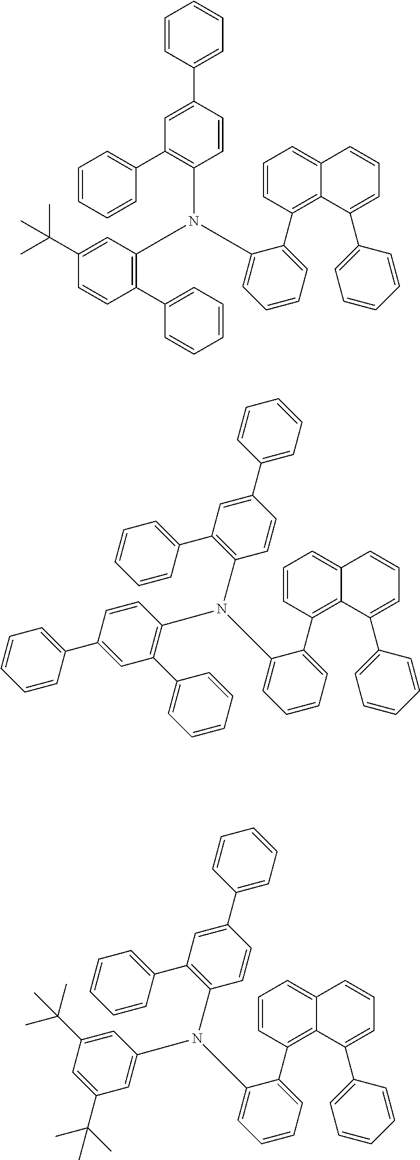 [SMILES: CC(C)(C)c1ccc(-c2ccccc2)c(N(c2ccc(-c3ccccc3)cc2-c2ccccc2)c2ccccc2-c2cccc3cccc(-c4ccccc4)c23)c1 ; c1ccc(-c2ccc(N(c3ccc(-c4ccccc4)cc3-c3ccccc3)c3ccccc3-c3cccc4cccc(-c5ccccc5)c34)c(-c3ccccc3)c2)cc1 ; CC(C)(C)c1cc(N(c2ccc(-c3ccccc3)cc2-c2ccccc2)c2ccccc2-c2cccc3cccc(-c4ccccc4)c23)cc(C(C)(C)C)c1]

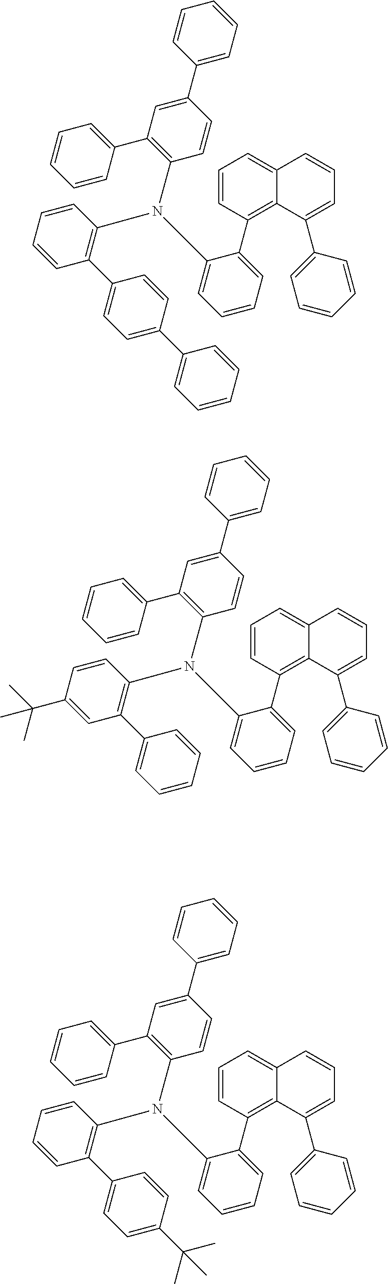 [SMILES: c1ccc(-c2ccc(-c3ccccc3N(c3ccc(-c4ccccc4)cc3-c3ccccc3)c3ccccc3-c3cccc4cccc(-c5ccccc5)c34)cc2)cc1 ; CC(C)(C)c1ccc(N(c2ccc(-c3ccccc3)cc2-c2ccccc2)c2ccccc2-c2cccc3cccc(-c4ccccc4)c23)c(-c2ccccc2)c1 ; CC(C)(C)c1ccc(-c2ccccc2N(c2ccc(-c3ccccc3)cc2-c2ccccc2)c2ccccc2-c2cccc3cccc(-c4ccccc4)c23)cc1]

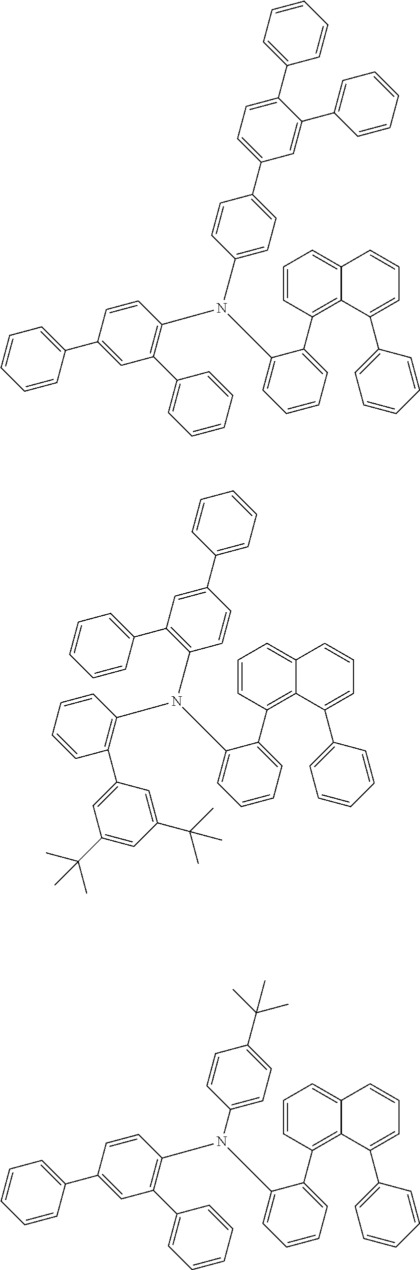 [SMILES: c1ccc(-c2ccc(N(c3ccc(-c4ccc(-c5ccccc5)c(-c5ccccc5)c4)cc3)c3ccccc3-c3cccc4cccc(-c5ccccc5)c34)c(-c3ccccc3)c2)cc1 ; CC(C)(C)c1cc(-c2ccccc2N(c2ccc(-c3ccccc3)cc2-c2ccccc2)c2ccccc2-c2cccc3cccc(-c4ccccc4)c23)cc(C(C)(C)C)c1 ; CC(C)(C)c1ccc(N(c2ccc(-c3ccccc3)cc2-c2ccccc2)c2ccccc2-c2cccc3cccc(-c4ccccc4)c23)cc1]

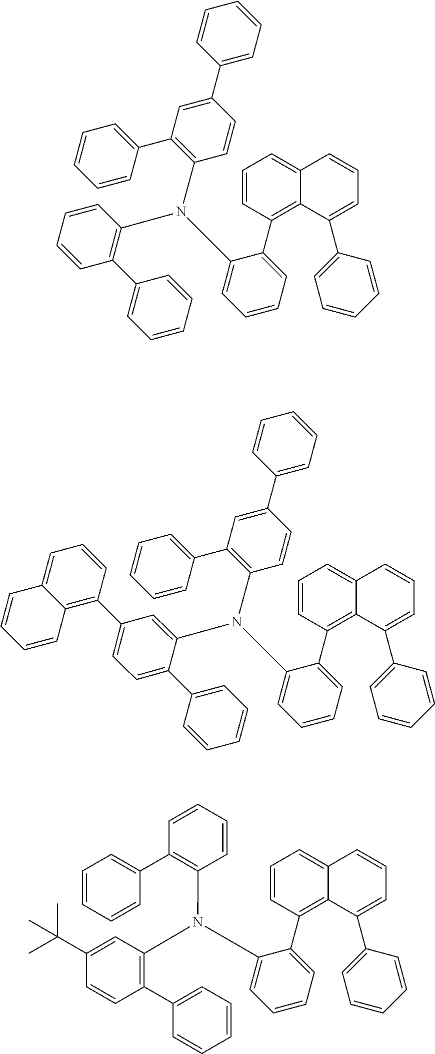 [SMILES: c1ccc(-c2ccc(N(c3ccccc3-c3ccccc3)c3ccccc3-c3cccc4cccc(-c5ccccc5)c34)c(-c3ccccc3)c2)cc1 ; c1ccc(-c2ccc(N(c3cc(-c4cccc5ccccc45)ccc3-c3ccccc3)c3ccccc3-c3cccc4cccc(-c5ccccc5)c34)c(-c3ccccc3)c2)cc1 ; CC(C)(C)c1ccc(-c2ccccc2)c(N(c2ccccc2-c2ccccc2)c2ccccc2-c2cccc3cccc(-c4ccccc4)c23)c1]

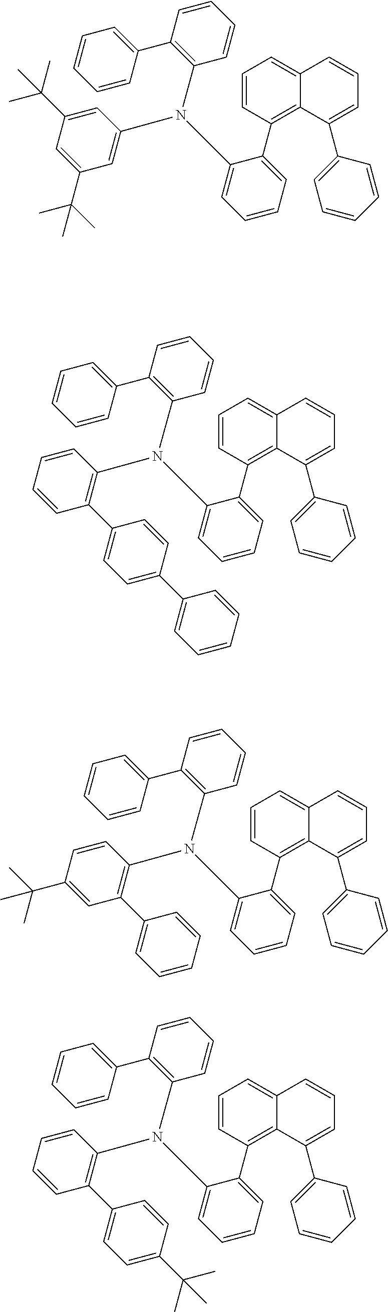 [SMILES: CC(C)(C)c1cc(N(c2ccccc2-c2ccccc2)c2ccccc2-c2cccc3cccc(-c4ccccc4)c23)cc(C(C)(C)C)c1 ; c1ccc(-c2ccc(-c3ccccc3N(c3ccccc3-c3ccccc3)c3ccccc3-c3cccc4cccc(-c5ccccc5)c34)cc2)cc1 ; CC(C)(C)c1ccc(N(c2ccccc2-c2ccccc2)c2ccccc2-c2cccc3cccc(-c4ccccc4)c23)c(-c2ccccc2)c1 ; CC(C)(C)c1ccc(-c2ccccc2N(c2ccccc2-c2ccccc2)c2ccccc2-c2cccc3cccc(-c4ccccc4)c23)cc1]

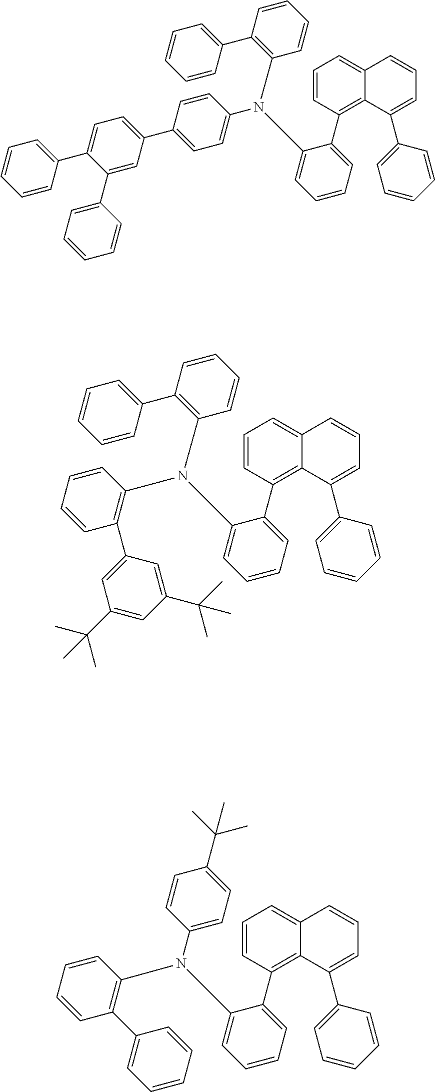 [SMILES: c1ccc(-c2ccc(-c3ccc(N(c4ccccc4-c4ccccc4)c4ccccc4-c4cccc5cccc(-c6ccccc6)c45)cc3)cc2-c2ccccc2)cc1 ; CC(C)(C)c1cc(-c2ccccc2N(c2ccccc2-c2ccccc2)c2ccccc2-c2cccc3cccc(-c4ccccc4)c23)cc(C(C)(C)C)c1 ; CC(C)(C)c1ccc(N(c2ccccc2-c2ccccc2)c2ccccc2-c2cccc3cccc(-c4ccccc4)c23)cc1]

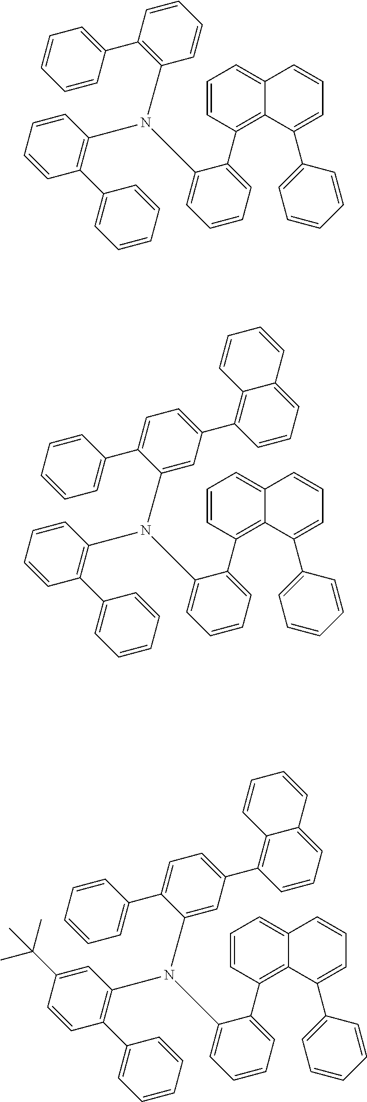 [SMILES: c1ccc(-c2ccccc2N(c2ccccc2-c2ccccc2)c2ccccc2-c2cccc3cccc(-c4ccccc4)c23)cc1 ; c1ccc(-c2ccccc2N(c2cc(-c3cccc4ccccc34)ccc2-c2ccccc2)c2ccccc2-c2cccc3cccc(-c4ccccc4)c23)cc1 ; CC(C)(C)c1ccc(-c2ccccc2)c(N(c2cc(-c3cccc4ccccc34)ccc2-c2ccccc2)c2ccccc2-c2cccc3cccc(-c4ccccc4)c23)c1]

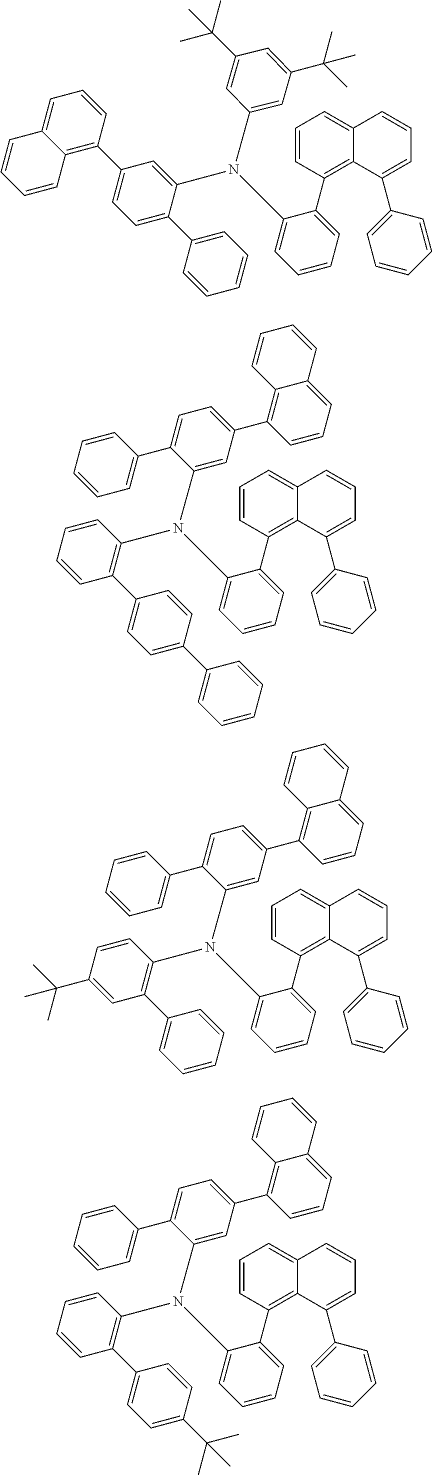 [SMILES: CC(C)(C)c1cc(N(c2cc(-c3cccc4ccccc34)ccc2-c2ccccc2)c2ccccc2-c2cccc3cccc(-c4ccccc4)c23)cc(C(C)(C)C)c1 ; c1ccc(-c2ccc(-c3ccccc3N(c3cc(-c4cccc5ccccc45)ccc3-c3ccccc3)c3ccccc3-c3cccc4cccc(-c5ccccc5)c34)cc2)cc1 ; CC(C)(C)c1ccc(N(c2cc(-c3cccc4ccccc34)ccc2-c2ccccc2)c2ccccc2-c2cccc3cccc(-c4ccccc4)c23)c(-c2ccccc2)c1 ; CC(C)(C)c1ccc(-c2ccccc2N(c2cc(-c3cccc4ccccc34)ccc2-c2ccccc2)c2ccccc2-c2cccc3cccc(-c4ccccc4)c23)cc1]

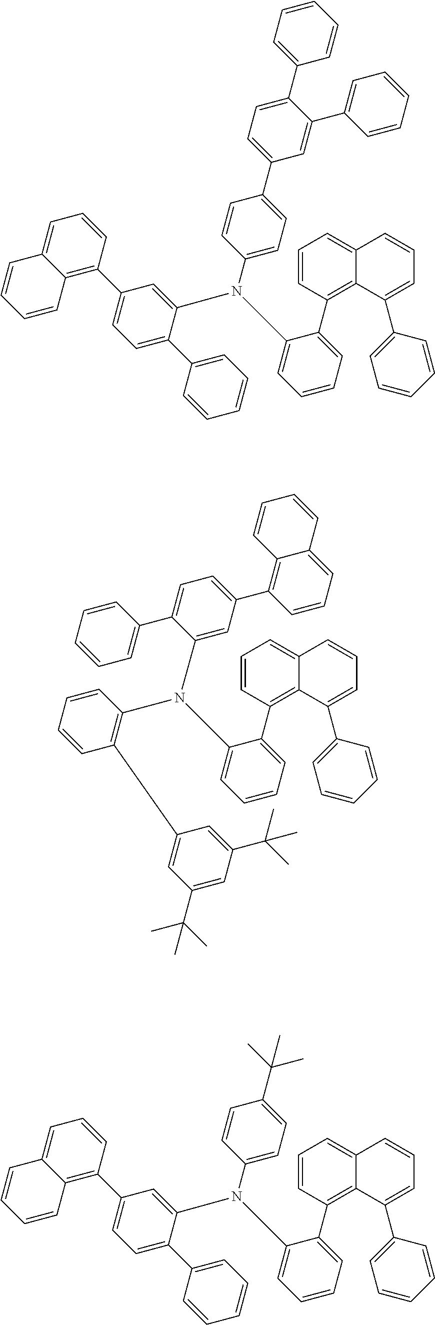 [SMILES: c1ccc(-c2ccc(-c3ccc(N(c4cc(-c5cccc6ccccc56)ccc4-c4ccccc4)c4ccccc4-c4cccc5cccc(-c6ccccc6)c45)cc3)cc2-c2ccccc2)cc1 ; CC(C)(C)c1cc(-c2ccccc2N(c2cc(-c3cccc4ccccc34)ccc2-c2ccccc2)c2ccccc2-c2cccc3cccc(-c4ccccc4)c23)cc(C(C)(C)C)c1 ; CC(C)(C)c1ccc(N(c2cc(-c3cccc4ccccc34)ccc2-c2ccccc2)c2ccccc2-c2cccc3cccc(-c4ccccc4)c23)cc1]

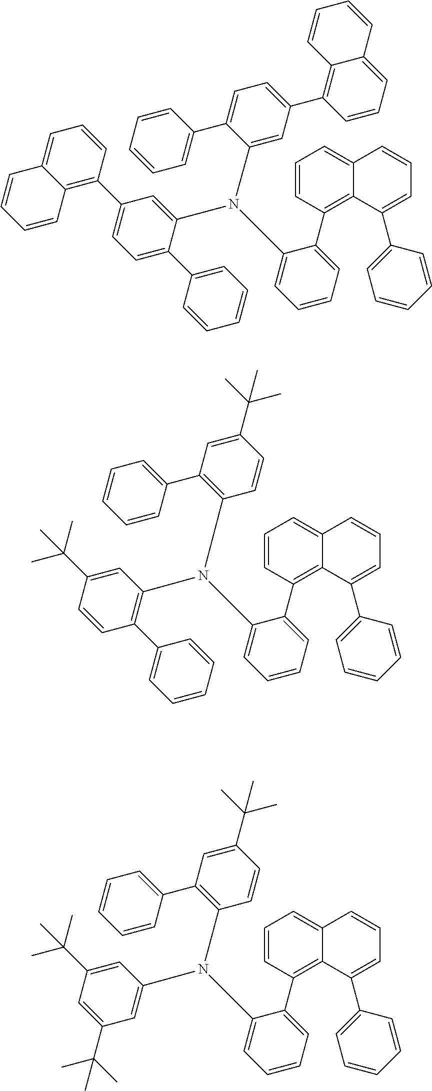 [SMILES: c1ccc(-c2ccc(-c3cccc4ccccc34)cc2N(c2cc(-c3cccc4ccccc34)ccc2-c2ccccc2)c2ccccc2-c2cccc3cccc(-c4ccccc4)c23)cc1 ; CC(C)(C)c1ccc(N(c2cc(C(C)(C)C)ccc2-c2ccccc2)c2ccccc2-c2cccc3cccc(-c4ccccc4)c23)c(-c2ccccc2)c1 ; CC(C)(C)c1cc(N(c2ccc(C(C)(C)C)cc2-c2ccccc2)c2ccccc2-c2cccc3cccc(-c4ccccc4)c23)cc(C(C)(C)C)c1]

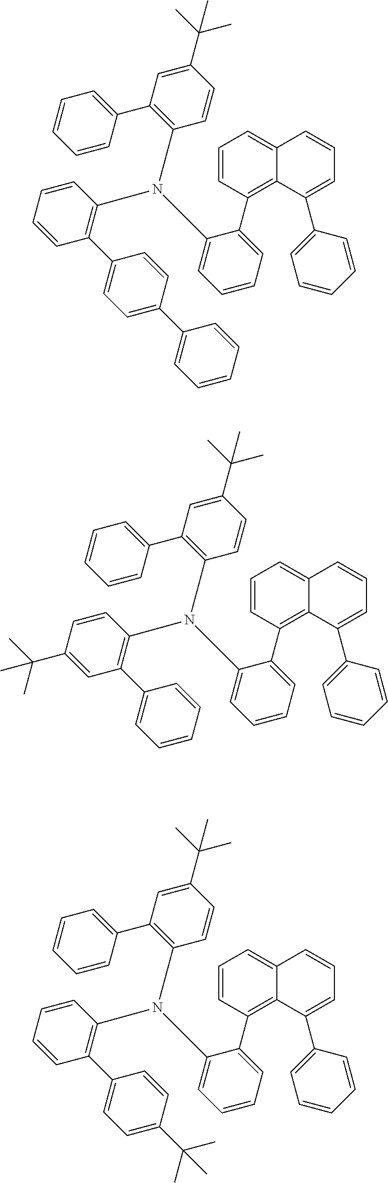 [SMILES: CC(C)(C)c1ccc(N(c2ccccc2-c2ccc(-c3ccccc3)cc2)c2ccccc2-c2cccc3cccc(-c4ccccc4)c23)c(-c2ccccc2)c1 ; CC(C)(C)c1ccc(N(c2ccc(C(C)(C)C)cc2-c2ccccc2)c2ccccc2-c2cccc3cccc(-c4ccccc4)c23)c(-c2ccccc2)c1 ; CC(C)(C)c1ccc(-c2ccccc2N(c2ccc(C(C)(C)C)cc2-c2ccccc2)c2ccccc2-c2cccc3cccc(-c4ccccc4)c23)cc1]

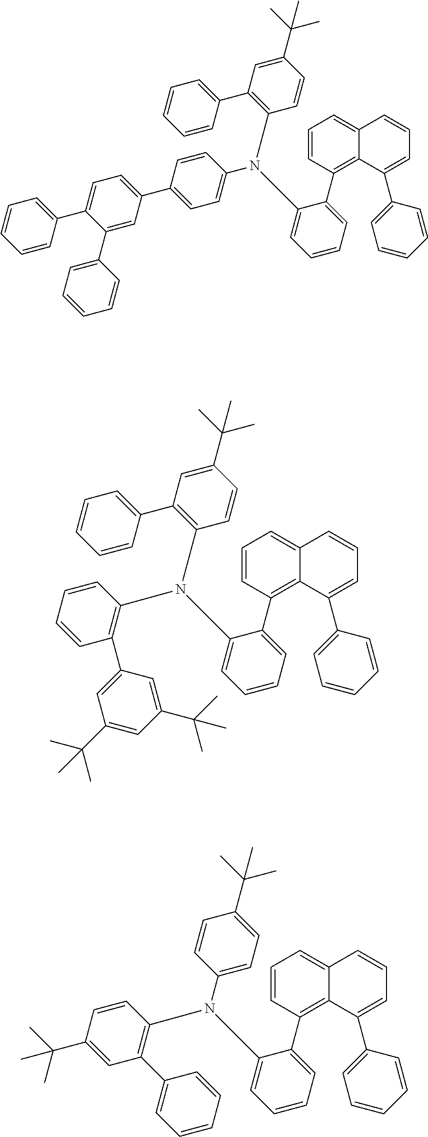 [SMILES: CC(C)(C)c1ccc(N(c2ccc(-c3ccc(-c4ccccc4)c(-c4ccccc4)c3)cc2)c2ccccc2-c2cccc3cccc(-c4ccccc4)c23)c(-c2ccccc2)c1 ; CC(C)(C)c1cc(-c2ccccc2N(c2ccc(C(C)(C)C)cc2-c2ccccc2)c2ccccc2-c2cccc3cccc(-c4ccccc4)c23)cc(C(C)(C)C)c1 ; CC(C)(C)c1ccc(N(c2ccc(C(C)(C)C)cc2-c2ccccc2)c2ccccc2-c2cccc3cccc(-c4ccccc4)c23)cc1]

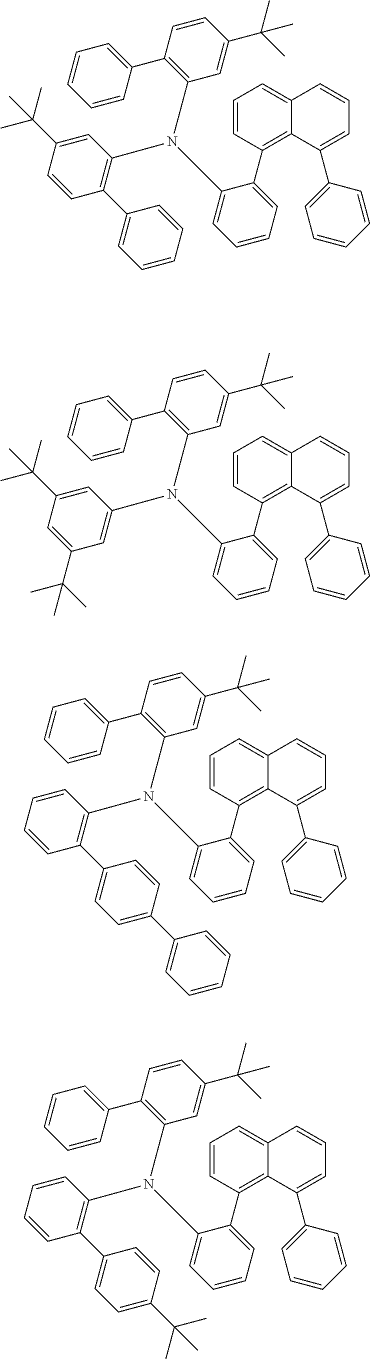 [SMILES: CC(C)(C)c1ccc(-c2ccccc2)c(N(c2cc(C(C)(C)C)ccc2-c2ccccc2)c2ccccc2-c2cccc3cccc(-c4ccccc4)c23)c1 ; CC(C)(C)c1cc(N(c2cc(C(C)(C)C)ccc2-c2ccccc2)c2ccccc2-c2cccc3cccc(-c4ccccc4)c23)cc(C(C)(C)C)c1 ; CC(C)(C)c1ccc(-c2ccccc2)c(N(c2ccccc2-c2ccc(-c3ccccc3)cc2)c2ccccc2-c2cccc3cccc(-c4ccccc4)c23)c1 ; CC(C)(C)c1ccc(-c2ccccc2N(c2cc(C(C)(C)C)ccc2-c2ccccc2)c2ccccc2-c2cccc3cccc(-c4ccccc4)c23)cc1]

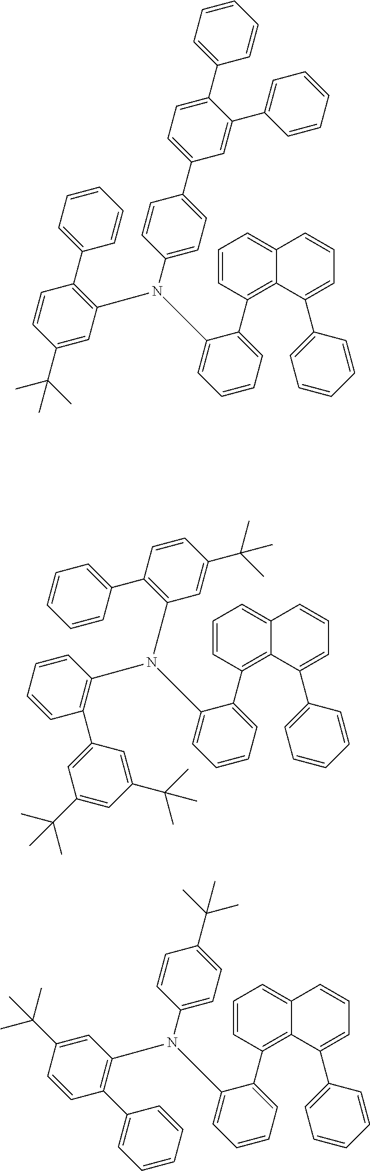 [SMILES: CC(C)(C)c1ccc(-c2ccccc2)c(N(c2ccc(-c3ccc(-c4ccccc4)c(-c4ccccc4)c3)cc2)c2ccccc2-c2cccc3cccc(-c4ccccc4)c23)c1 ; CC(C)(C)c1cc(-c2ccccc2N(c2cc(C(C)(C)C)ccc2-c2ccccc2)c2ccccc2-c2cccc3cccc(-c4ccccc4)c23)cc(C(C)(C)C)c1 ; CC(C)(C)c1ccc(N(c2cc(C(C)(C)C)ccc2-c2ccccc2)c2ccccc2-c2cccc3cccc(-c4ccccc4)c23)cc1]

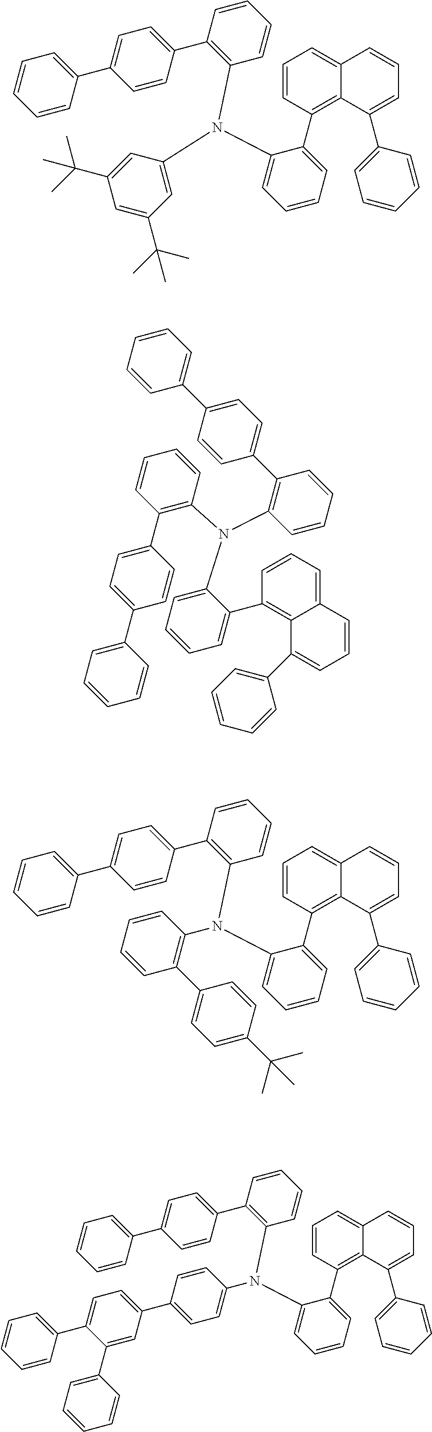 [SMILES: CC(C)(C)c1cc(N(c2ccccc2-c2ccc(-c3ccccc3)cc2)c2ccccc2-c2cccc3cccc(-c4ccccc4)c23)cc(C(C)(C)C)c1 ; c1ccc(-c2ccc(-c3ccccc3N(c3ccccc3-c3ccc(-c4ccccc4)cc3)c3ccccc3-c3cccc4cccc(-c5ccccc5)c34)cc2)cc1 ; CC(C)(C)c1ccc(-c2ccccc2N(c2ccccc2-c2ccc(-c3ccccc3)cc2)c2ccccc2-c2cccc3cccc(-c4ccccc4)c23)cc1 ; c1ccc(-c2ccc(-c3ccccc3N(c3ccc(-c4ccc(-c5ccccc5)c(-c5ccccc5)c4)cc3)c3ccccc3-c3cccc4cccc(-c5ccccc5)c34)cc2)cc1]

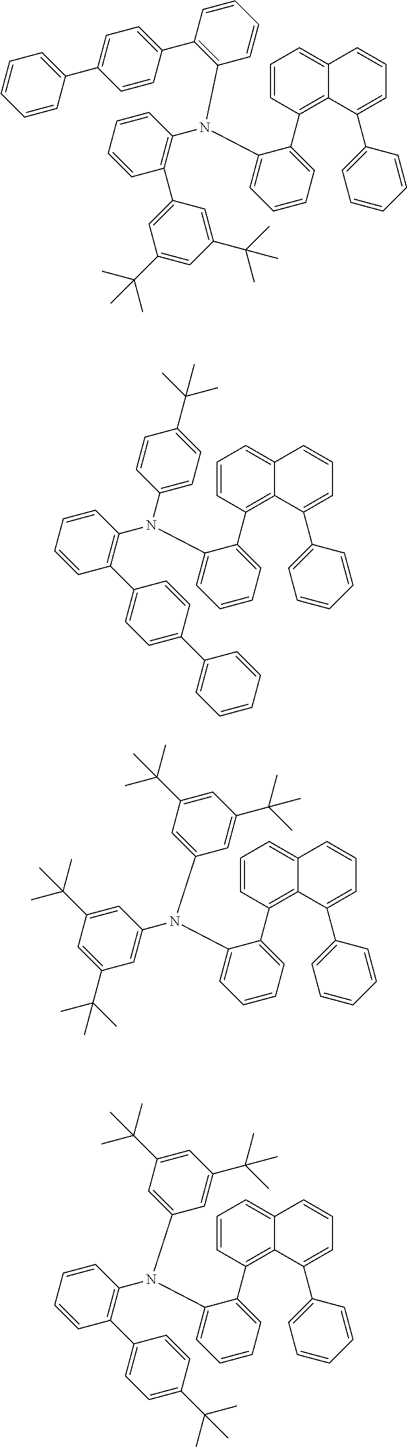 [SMILES: CC(C)(C)c1cc(-c2ccccc2N(c2ccccc2-c2ccc(-c3ccccc3)cc2)c2ccccc2-c2cccc3cccc(-c4ccccc4)c23)cc(C(C)(C)C)c1 ; CC(C)(C)c1ccc(N(c2ccccc2-c2ccc(-c3ccccc3)cc2)c2ccccc2-c2cccc3cccc(-c4ccccc4)c23)cc1 ; CC(C)(C)c1cc(N(c2cc(C(C)(C)C)cc(C(C)(C)C)c2)c2ccccc2-c2cccc3cccc(-c4ccccc4)c23)cc(C(C)(C)C)c1 ; CC(C)(C)c1ccc(-c2ccccc2N(c2cc(C(C)(C)C)cc(C(C)(C)C)c2)c2ccccc2-c2cccc3cccc(-c4ccccc4)c23)cc1]

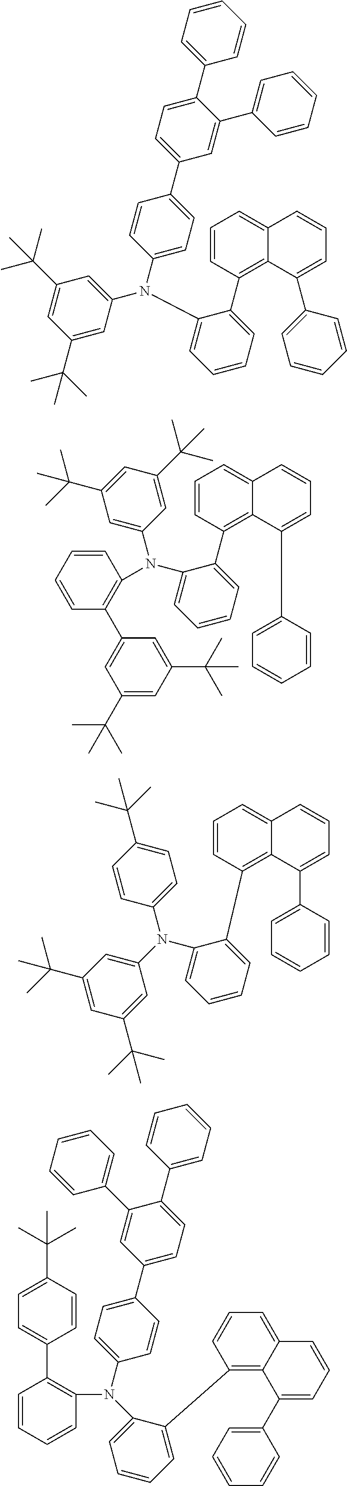

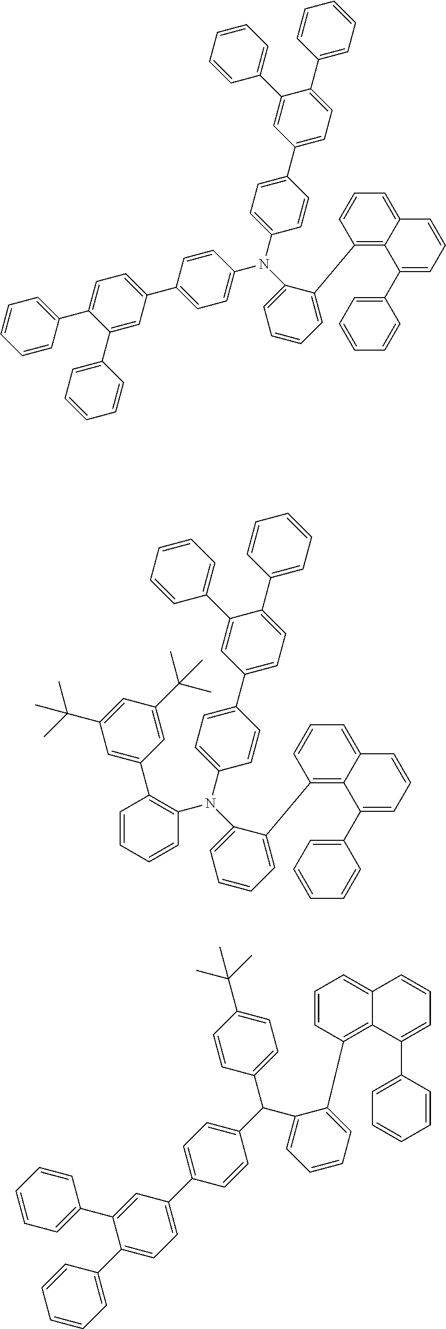

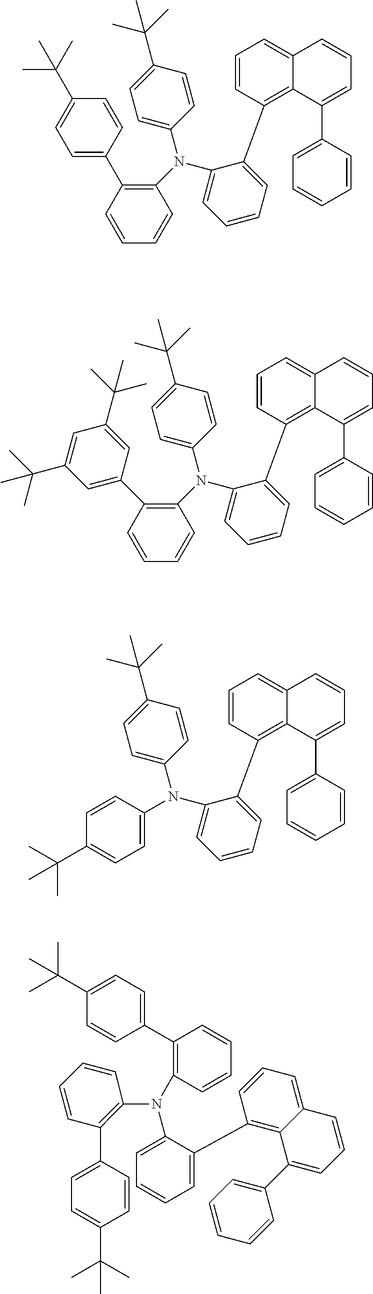

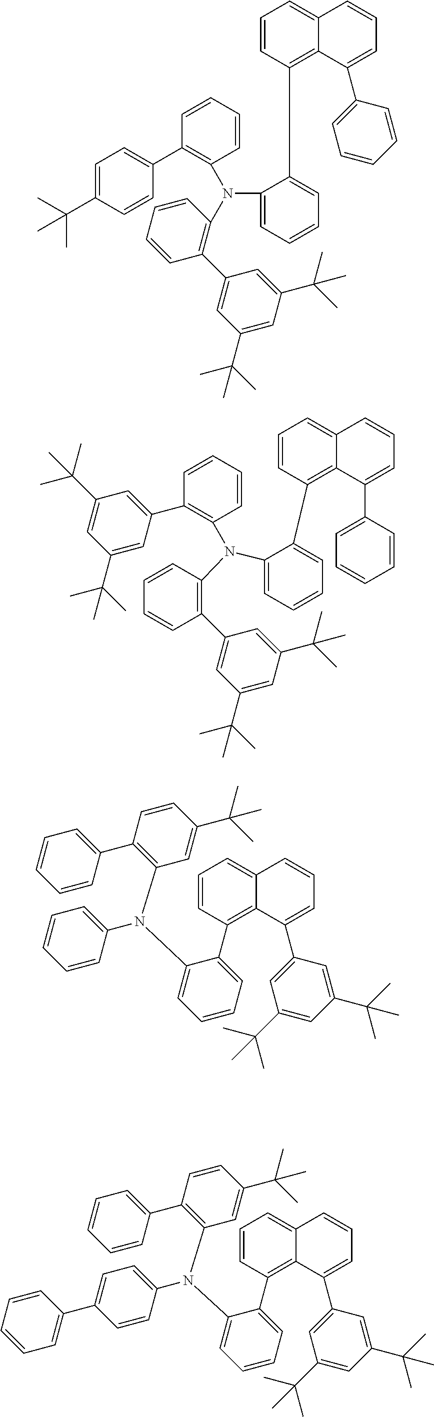

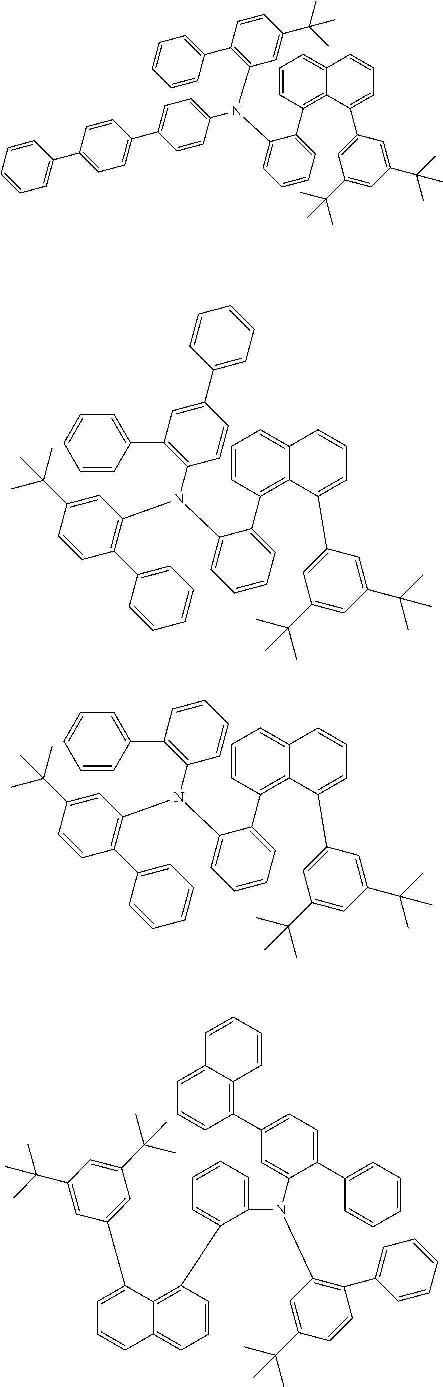

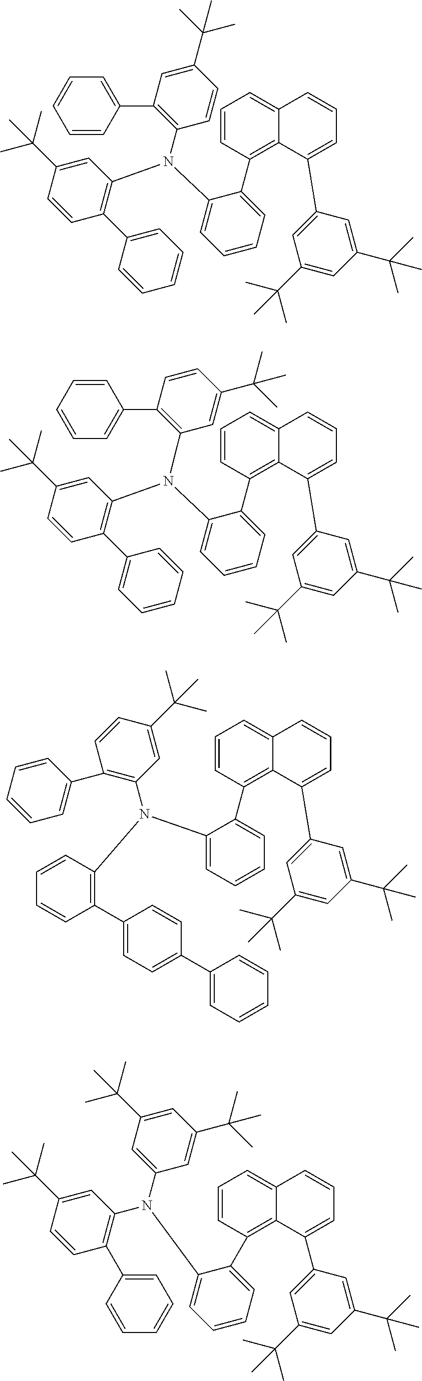

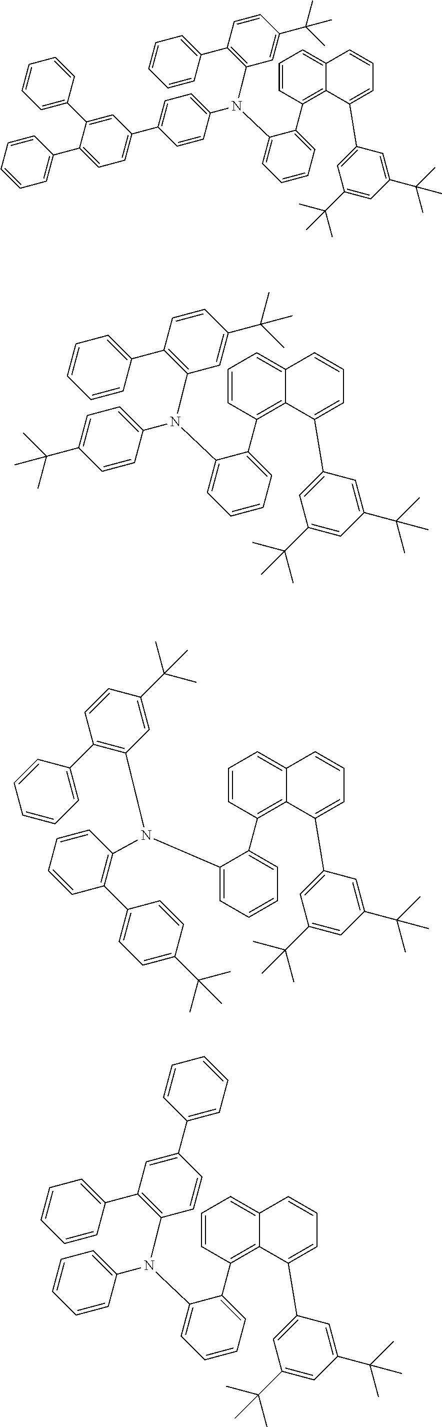

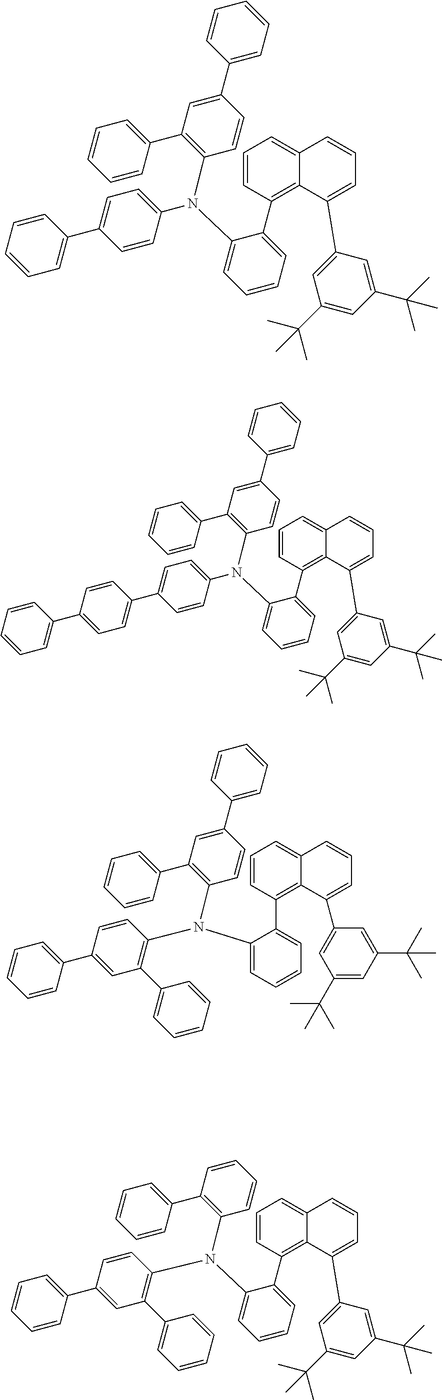 [SMILES: CC(C)(C)c1cc(-c2cccc3cccc(-c4ccccc4N(c4ccc(-c5ccccc5)cc4)c4ccc(-c5ccccc5)cc4-c4ccccc4)c23)cc(C(C)(C)C)c1 ; CC(C)(C)c1cc(-c2cccc3cccc(-c4ccccc4N(c4ccc(-c5ccc(-c6ccccc6)cc5)cc4)c4ccc(-c5ccccc5)cc4-c4ccccc4)c23)cc(C(C)(C)C)c1 ; CC(C)(C)c1cc(-c2cccc3cccc(-c4ccccc4N(c4ccc(-c5ccccc5)cc4-c4ccccc4)c4ccc(-c5ccccc5)cc4-c4ccccc4)c23)cc(C(C)(C)C)c1 ; CC(C)(C)c1cc(-c2cccc3cccc(-c4ccccc4N(c4ccccc4-c4ccccc4)c4ccc(-c5ccccc5)cc4-c4ccccc4)c23)cc(C(C)(C)C)c1]

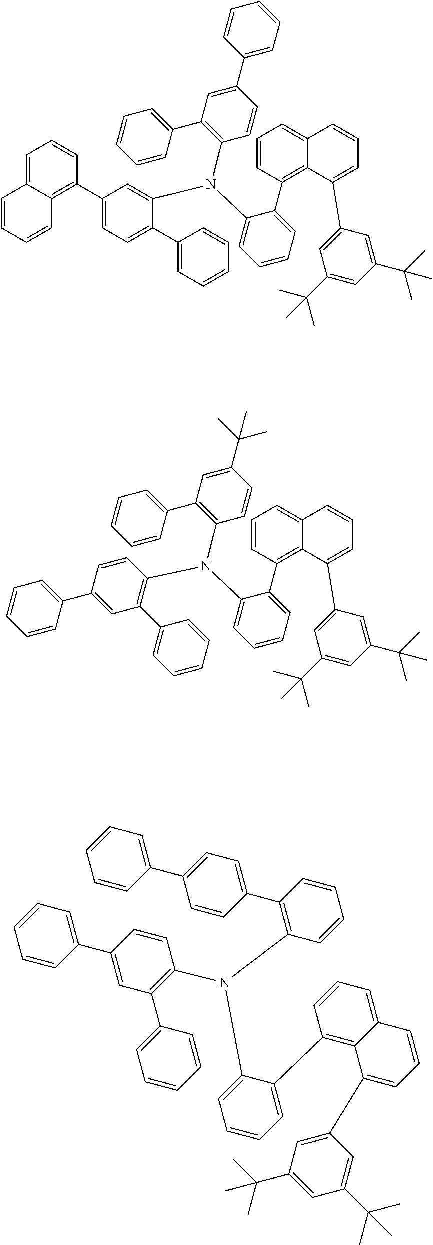 [SMILES: CC(C)(C)c1cc(-c2cccc3cccc(-c4ccccc4N(c4ccc(-c5ccccc5)cc4-c4ccccc4)c4cc(-c5cccc6ccccc56)ccc4-c4ccccc4)c23)cc(C(C)(C)C)c1 ; CC(C)(C)c1cc(-c2cccc3cccc(-c4ccccc4N(c4ccc(-c5ccccc5)cc4-c4ccccc4)c4ccc(C(C)(C)C)cc4-c4ccccc4)c23)cc(C(C)(C)C)c1 ; CC(C)(C)c1cc(-c2cccc3cccc(-c4ccccc4N(c4ccccc4-c4ccc(-c5ccccc5)cc4)c4ccc(-c5ccccc5)cc4-c4ccccc4)c23)cc(C(C)(C)C)c1]

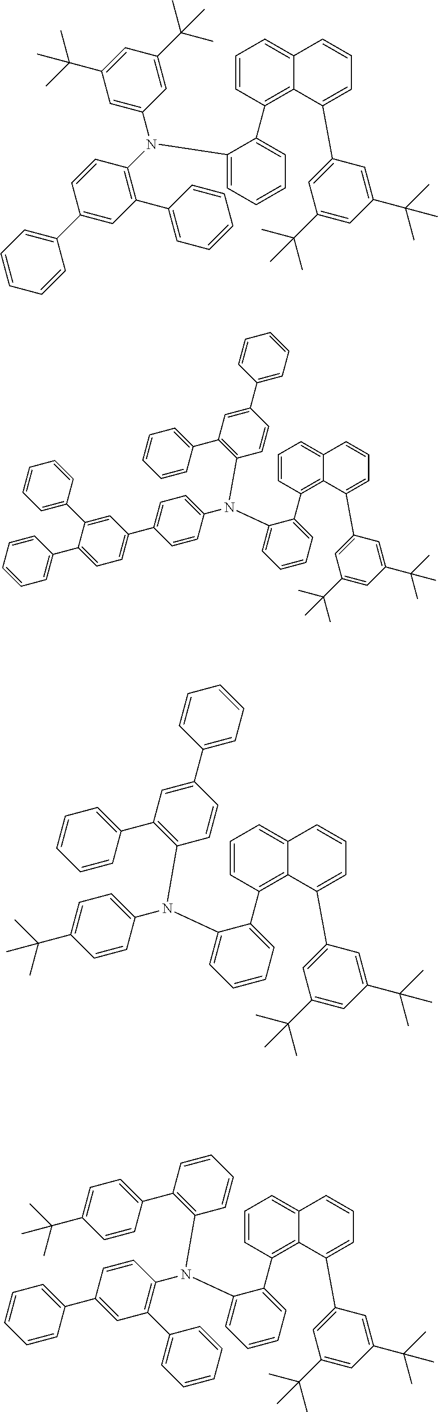

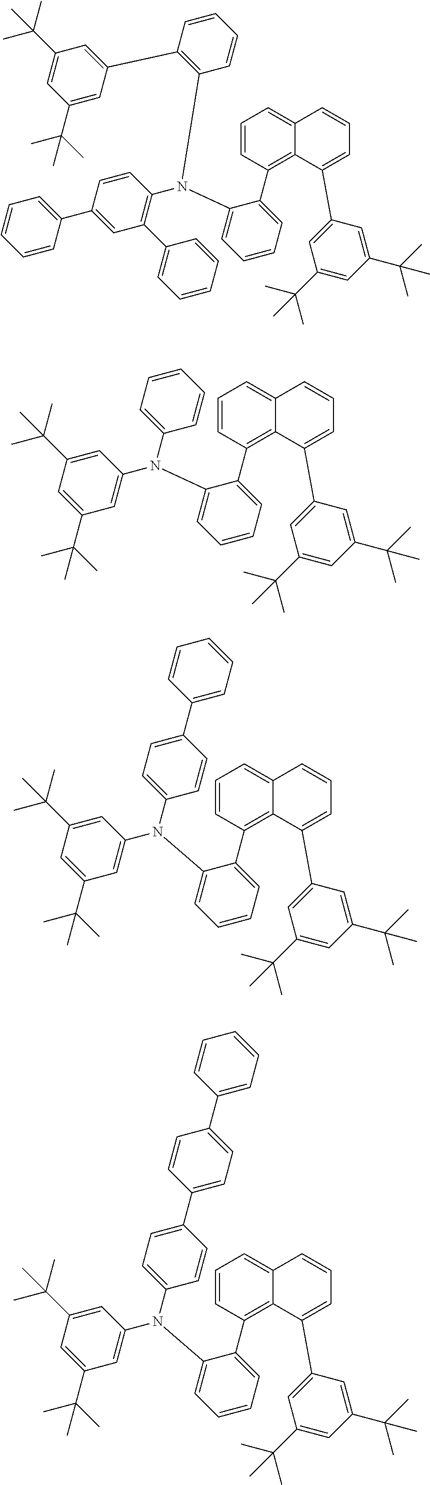

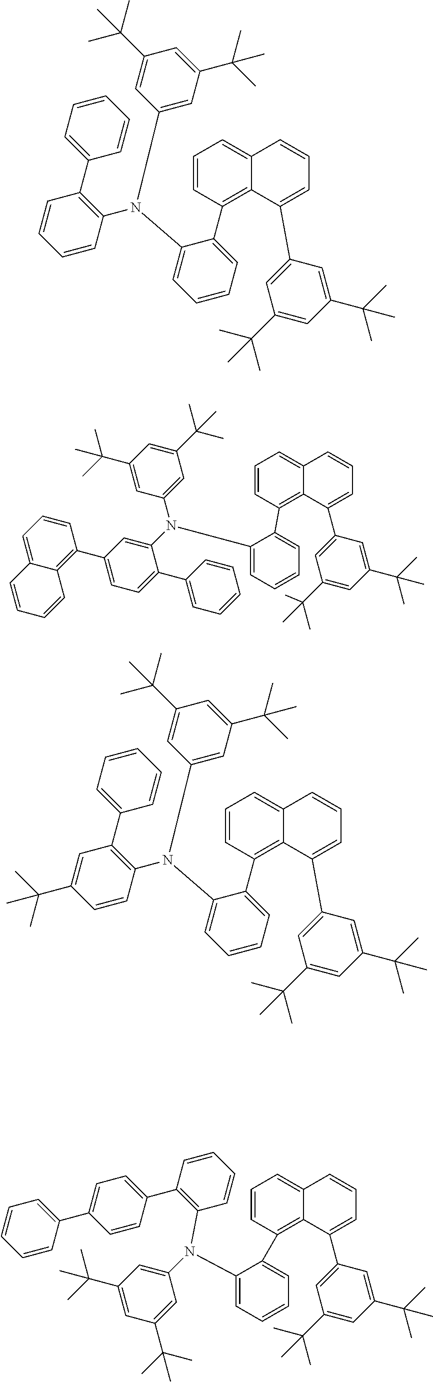

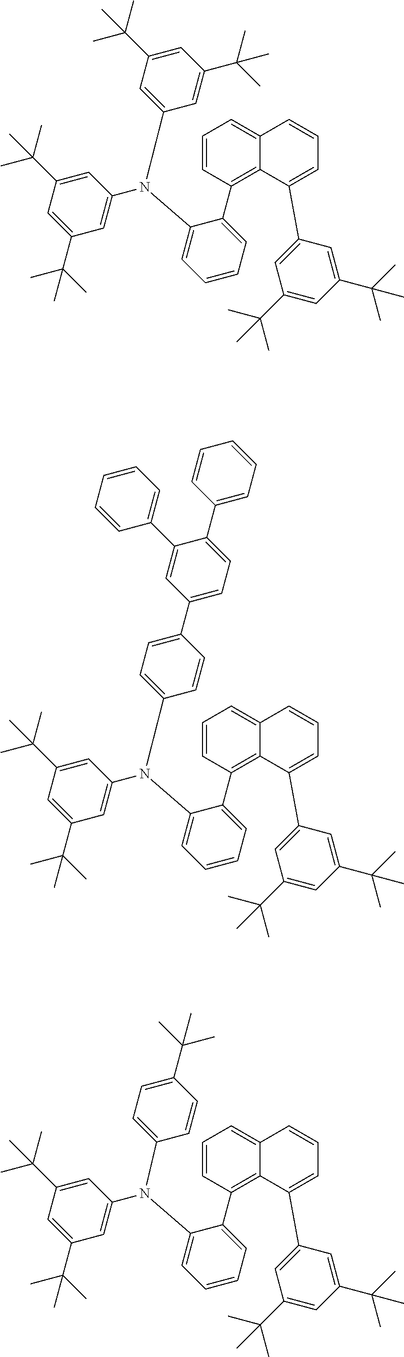

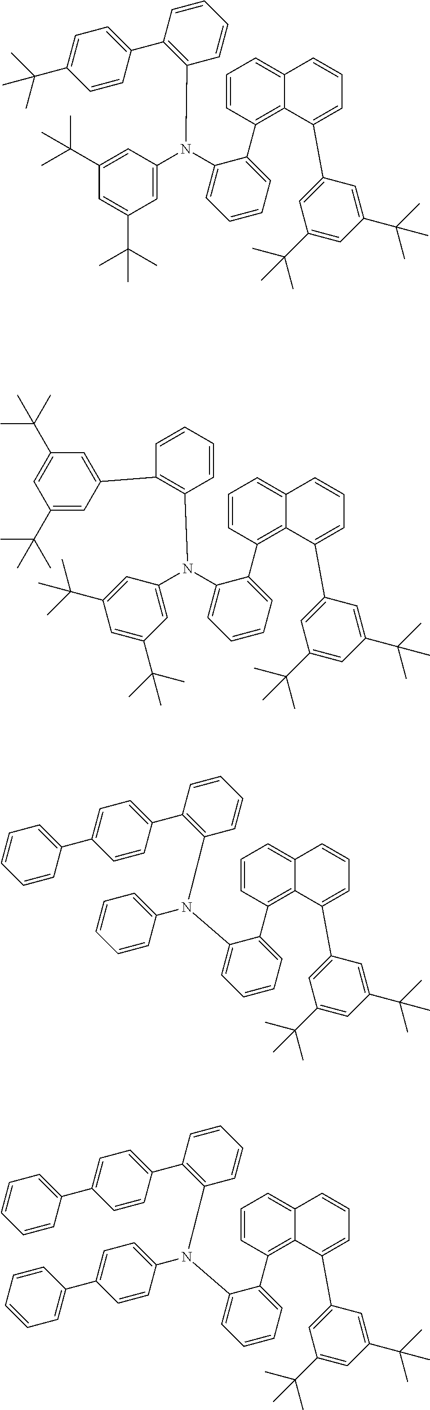

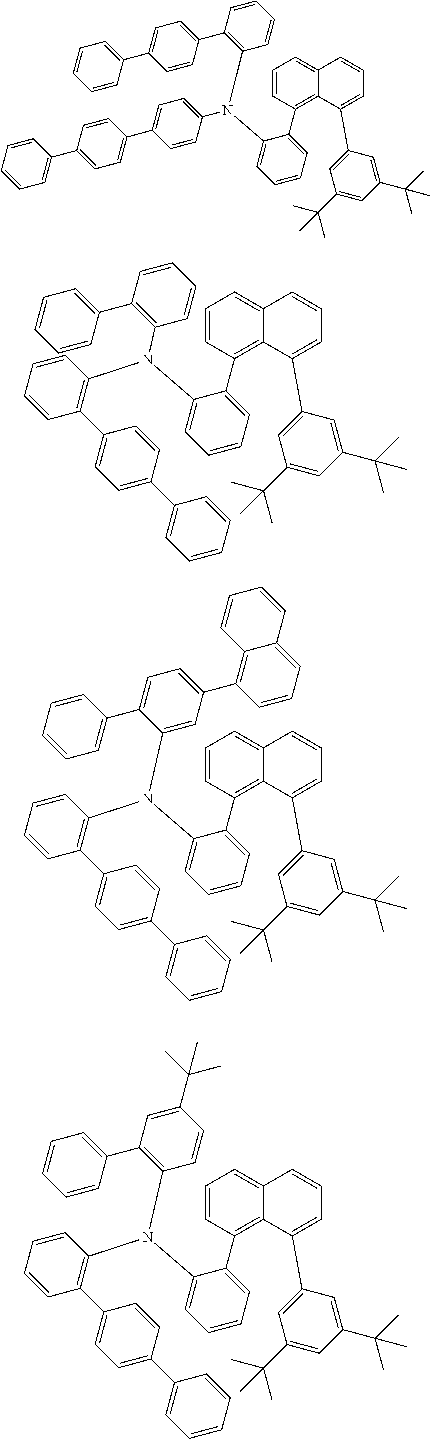

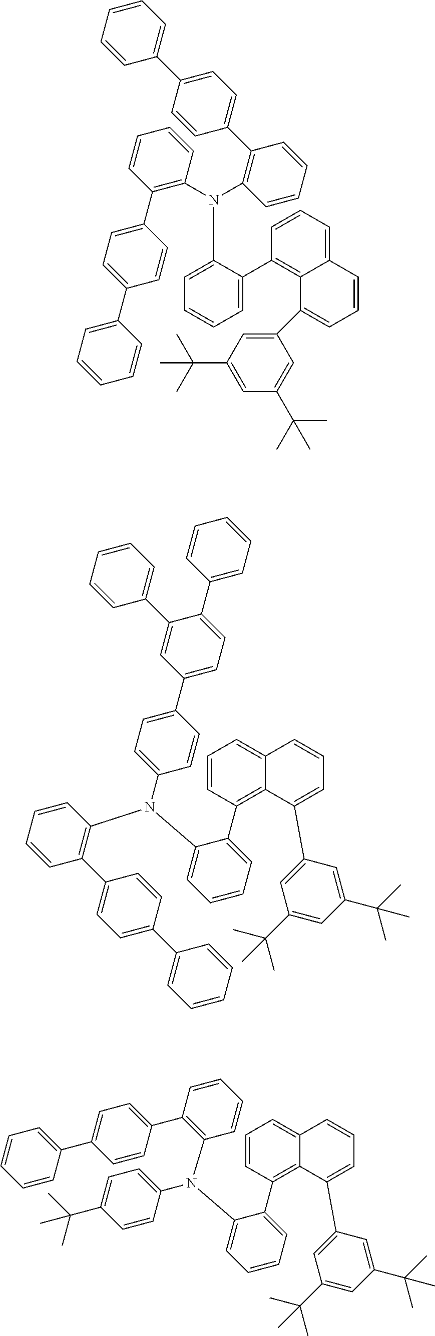 [SMILES: CC(C)(C)c1cc(-c2cccc3cccc(-c4ccccc4N(c4ccccc4-c4ccc(-c5ccccc5)cc4)c4ccccc4-c4ccc(-c5ccccc5)cc4)c23)cc(C(C)(C)C)c1 ; CC(C)(C)c1cc(-c2cccc3cccc(-c4ccccc4N(c4ccc(-c5ccc(-c6ccccc6)c(-c6ccccc6)c5)cc4)c4ccccc4-c4ccc(-c5ccccc5)cc4)c23)cc(C(C)(C)C)c1 ; CC(C)(C)c1ccc(N(c2ccccc2-c2ccc(-c3ccccc3)cc2)c2ccccc2-c2cccc3cccc(-c4cc(C(C)(C)C)cc(C(C)(C)C)c4)c23)cc1]

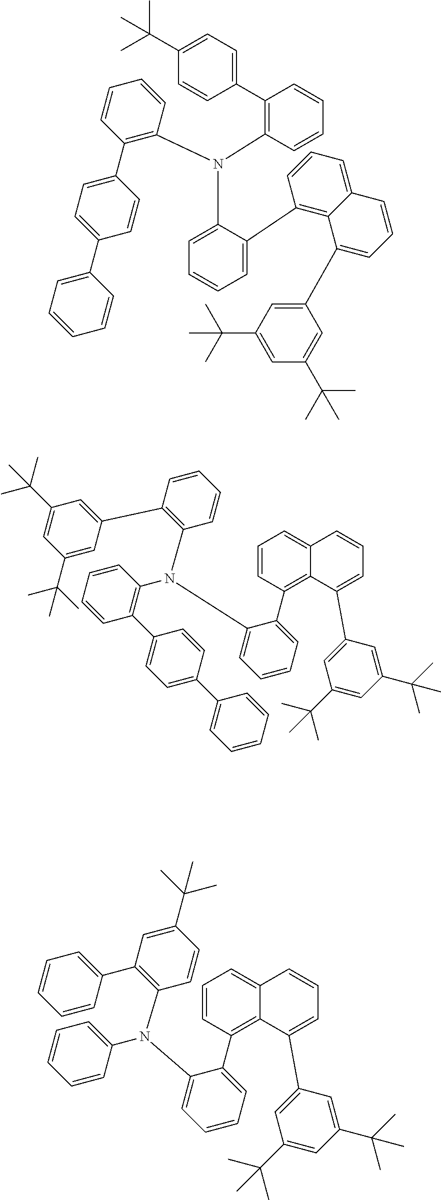 [SMILES: CC(C)(C)c1ccc(-c2ccccc2N(c2ccccc2-c2ccc(-c3ccccc3)cc2)c2ccccc2-c2cccc3cccc(-c4cc(C(C)(C)C)cc(C(C)(C)C)c4)c23)cc1 ; CC(C)(C)c1cc(-c2ccccc2N(c2ccccc2-c2ccc(-c3ccccc3)cc2)c2ccccc2-c2cccc3cccc(-c4cc(C(C)(C)C)cc(C(C)(C)C)c4)c23)cc(C(C)(C)C)c1 ; CC(C)(C)c1cc(-c2cccc3cccc(-c4ccccc4N(c4ccccc4)c4ccc(C(C)(C)C)cc4-c4ccccc4)c23)cc(C(C)(C)C)c1]

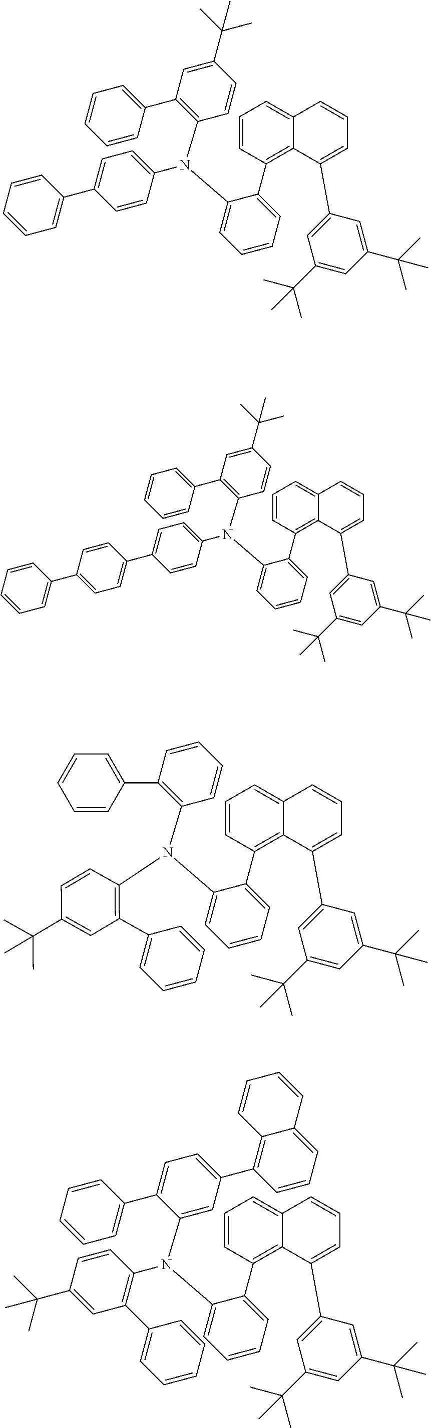

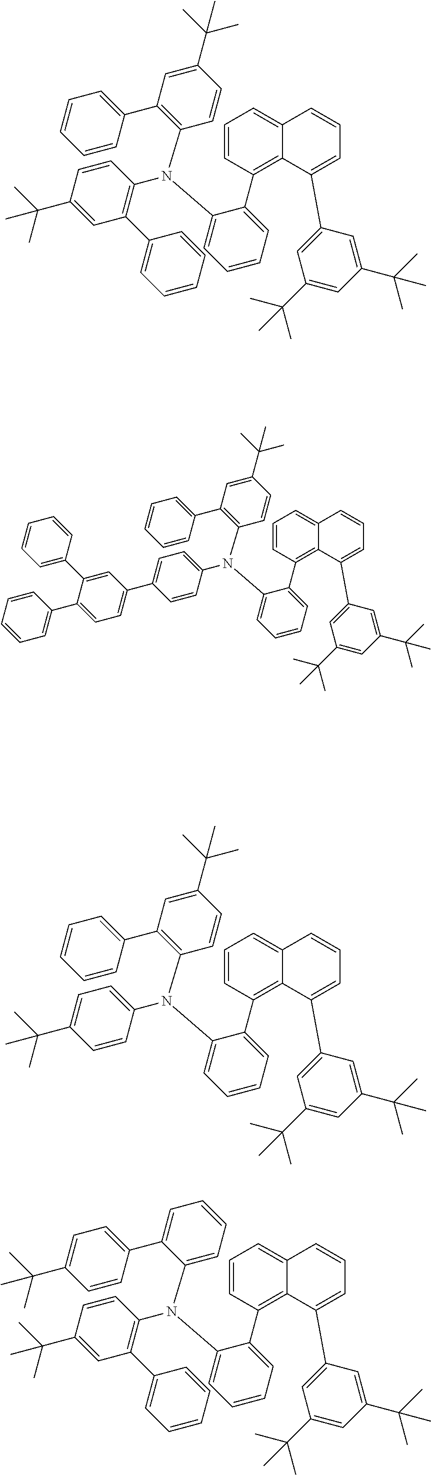

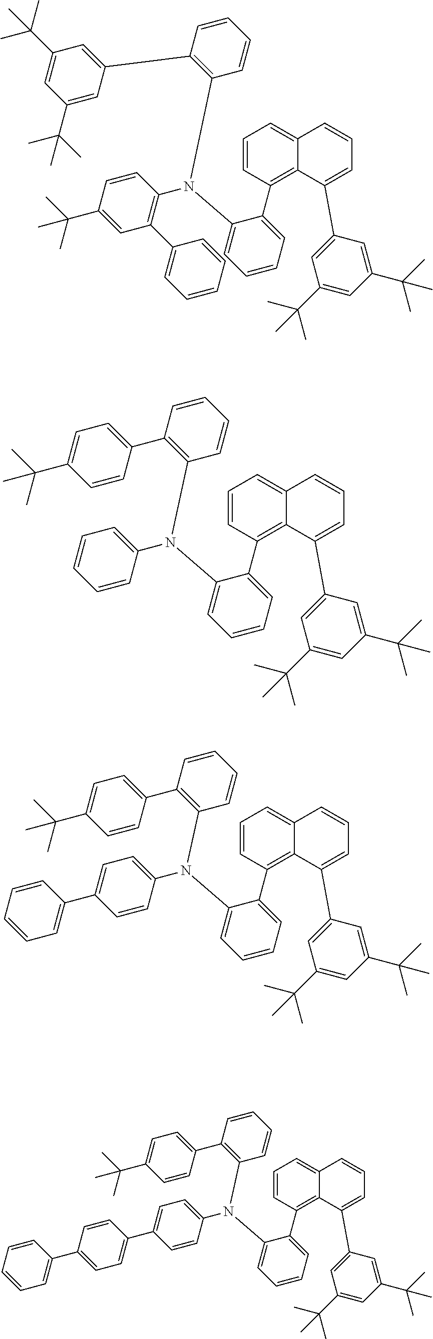

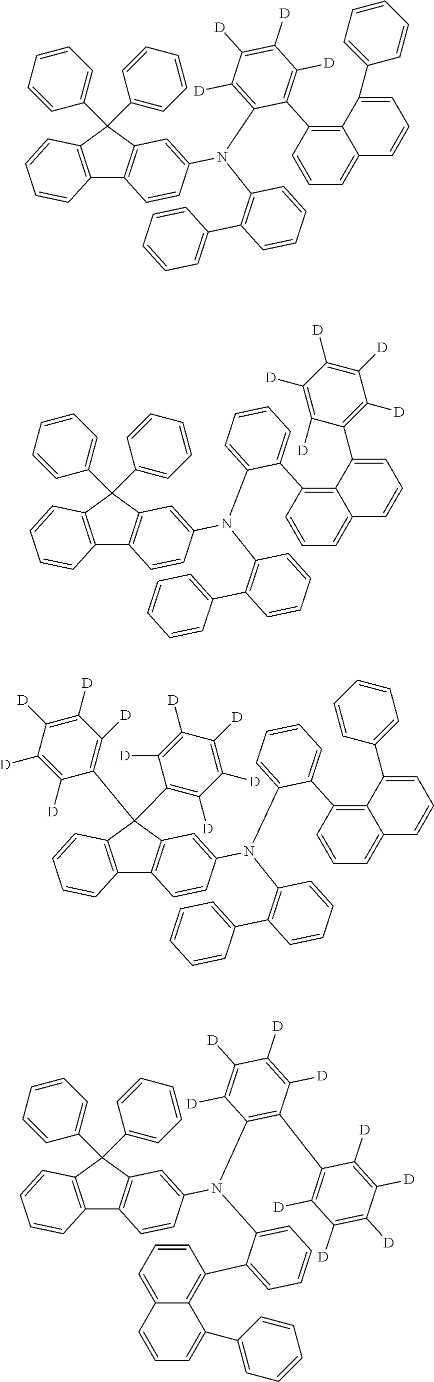

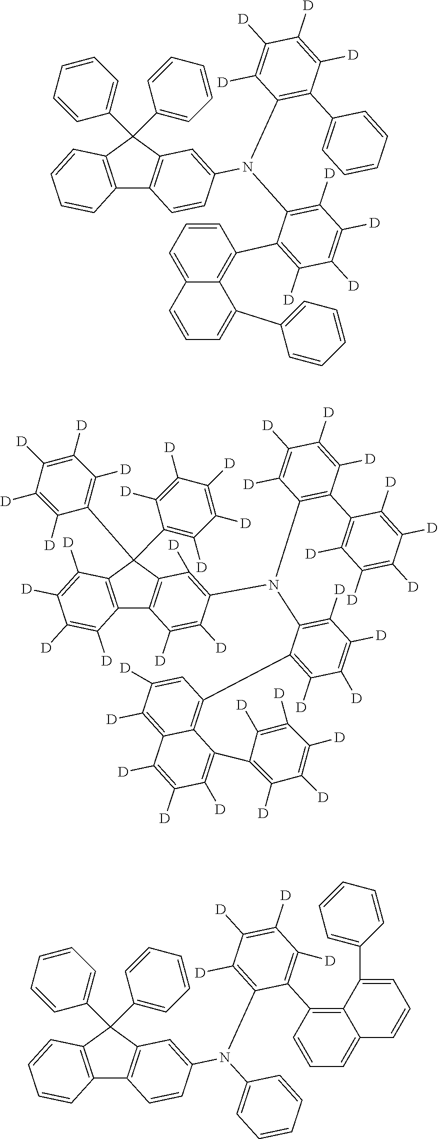

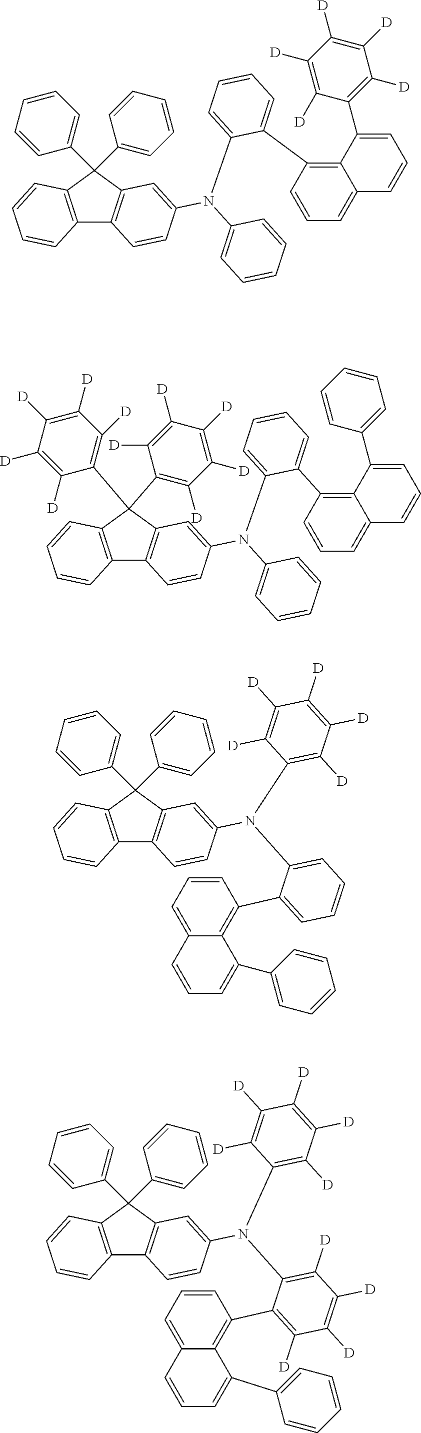

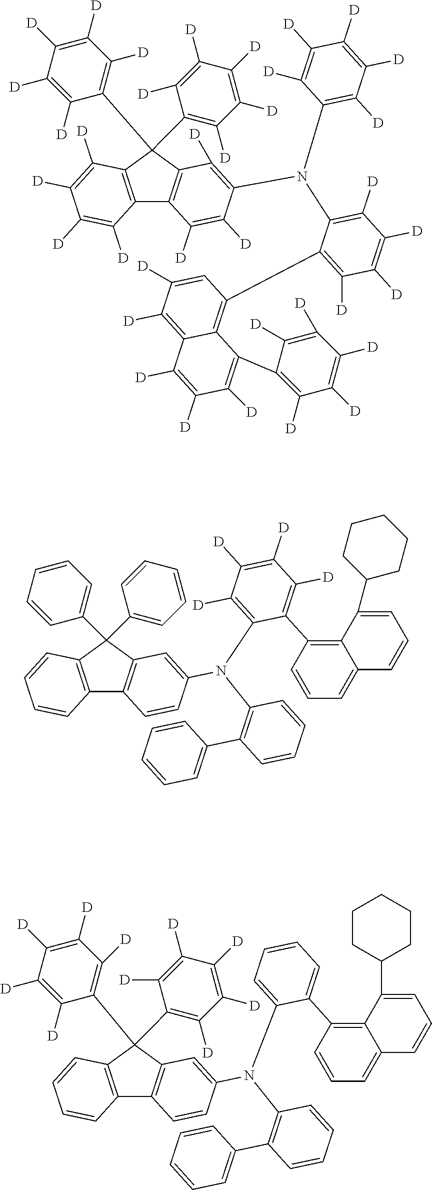

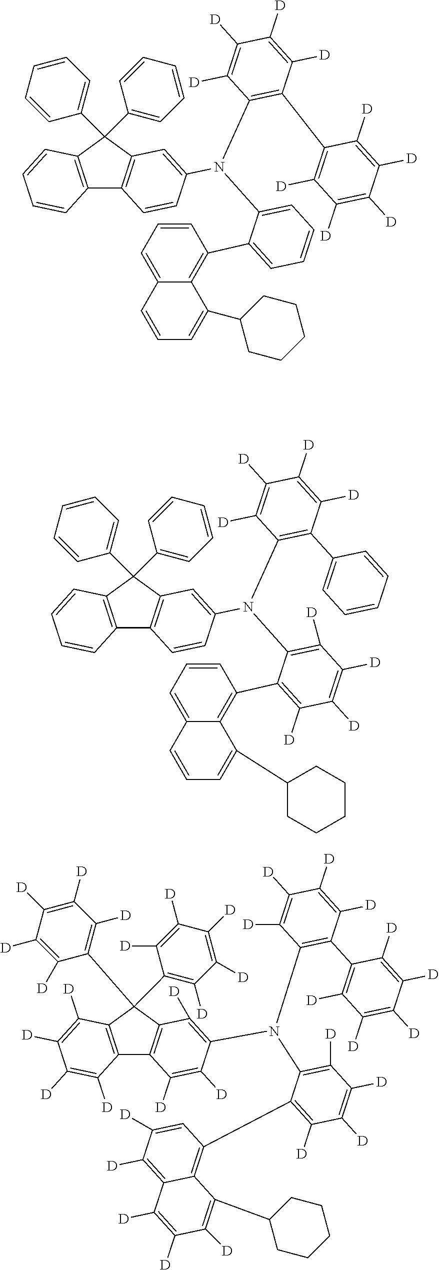

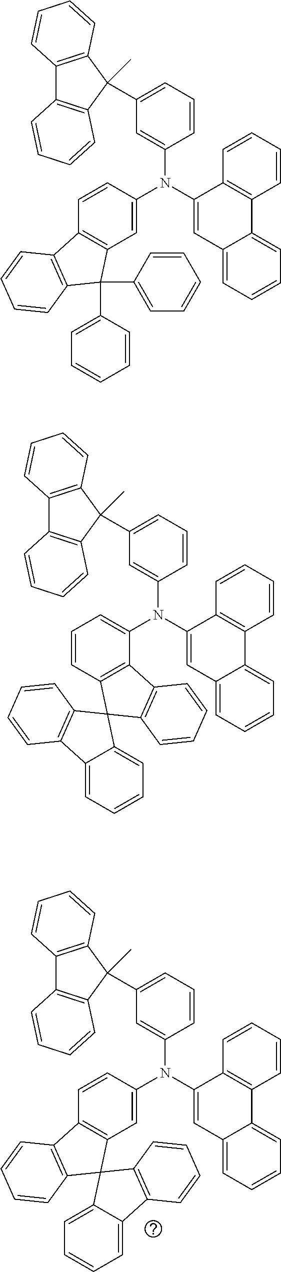 [SMILES: CC1(c2cccc(N(c3ccc4c(c3)C(c3ccccc3)(c3ccccc3)c3ccccc3-4)c3cc4ccccc4c4ccccc34)c2)c2ccccc2-c2ccccc21 ; CC1(c2cccc(N(c3cccc4c3-c3ccccc3C43c4ccccc4-c4ccccc43)c3cc4ccccc4c4ccccc34)c2)c2ccccc2-c2ccccc21 ; CC1(c2cccc(N(c3ccc4c(c3)C3(c5ccccc5-c5ccccc53)c3ccccc3-4)c3cc4ccccc4c4ccccc34)c2)c2ccccc2-c2ccccc21]

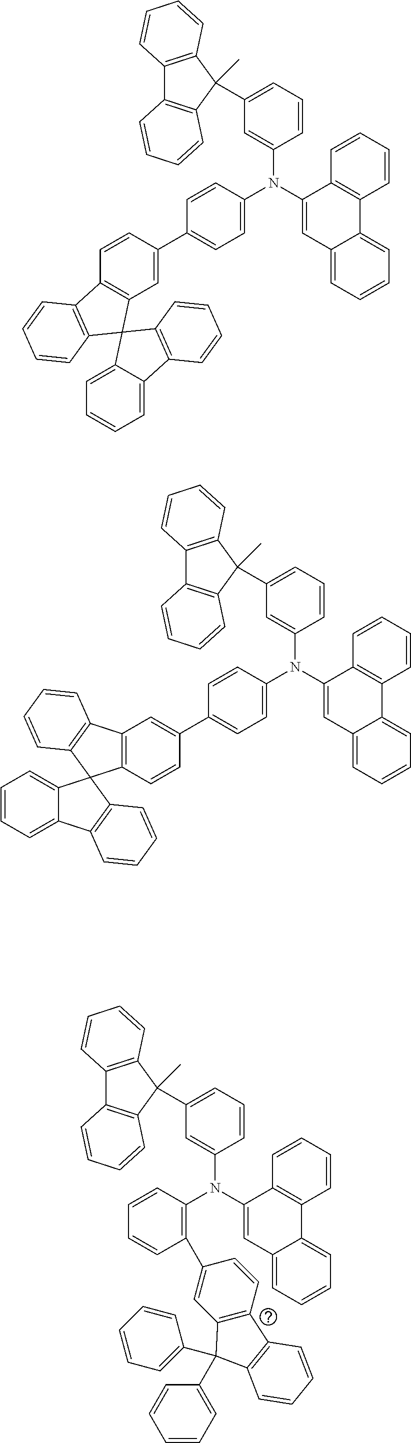 [SMILES: CC1(c2cccc(N(c3ccc(-c4ccc5c(c4)C4(c6ccccc6-c6ccccc64)c4ccccc4-5)cc3)c3cc4ccccc4c4ccccc34)c2)c2ccccc2-c2ccccc21 ; CC1(c2cccc(N(c3ccc(-c4ccc5c(c4)-c4ccccc4C54c5ccccc5-c5ccccc54)cc3)c3cc4ccccc4c4ccccc34)c2)c2ccccc2-c2ccccc21 ; CC1(c2cccc(N(c3ccccc3-c3ccc4c(c3)C(c3ccccc3)(c3ccccc3)c3ccccc3-4)c3cc4ccccc4c4ccccc34)c2)c2ccccc2-c2ccccc21]

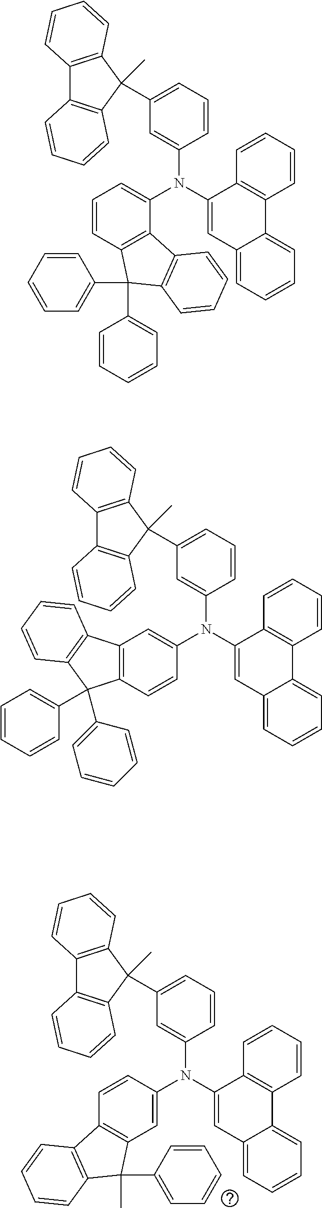 [SMILES: CC1(c2cccc(N(c3cccc4c3-c3ccccc3C4(c3ccccc3)c3ccccc3)c3cc4ccccc4c4ccccc34)c2)c2ccccc2-c2ccccc21 ; CC1(c2cccc(N(c3ccc4c(c3)-c3ccccc3C4(c3ccccc3)c3ccccc3)c3cc4ccccc4c4ccccc34)c2)c2ccccc2-c2ccccc21 ; CC1(c2cccc(N(c3ccc4c(c3)C(C)(c3ccccc3)c3ccccc3-4)c3cc4ccccc4c4ccccc34)c2)c2ccccc2-c2ccccc21]

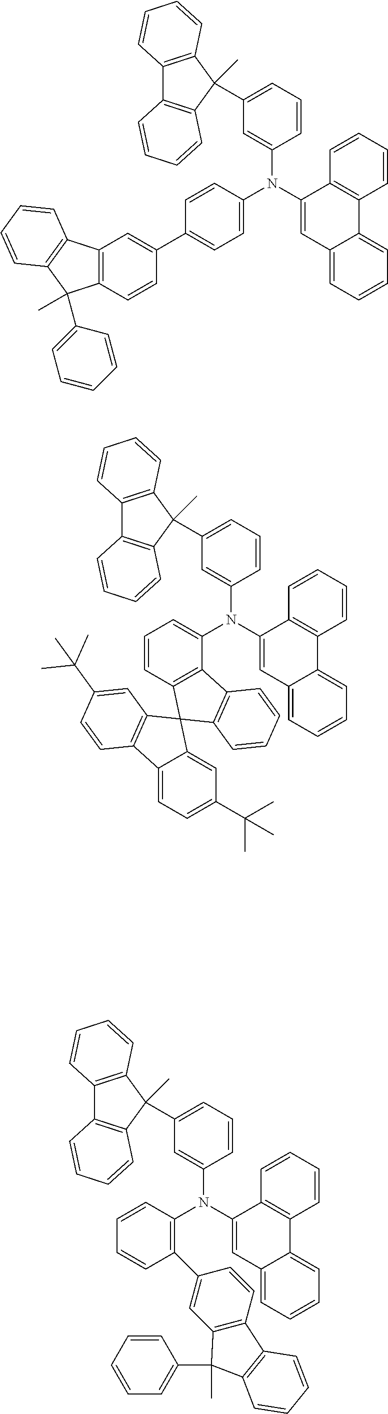 [SMILES: CC1(c2cccc(N(c3ccc(-c4ccc5c(c4)-c4ccccc4C5(C)c4ccccc4)cc3)c3cc4ccccc4c4ccccc34)c2)c2ccccc2-c2ccccc21 ; CC(C)(C)c1ccc2c(c1)C1(c3cc(C(C)(C)C)ccc3-2)c2ccccc2-c2c(N(c3cccc(C4(C)c5ccccc5-c5ccccc54)c3)c3cc4ccccc4c4ccccc34)cccc21 ; CC1(c2cccc(N(c3ccccc3-c3ccc4c(c3)C(C)(c3ccccc3)c3ccccc3-4)c3cc4ccccc4c4ccccc34)c2)c2ccccc2-c2ccccc21]

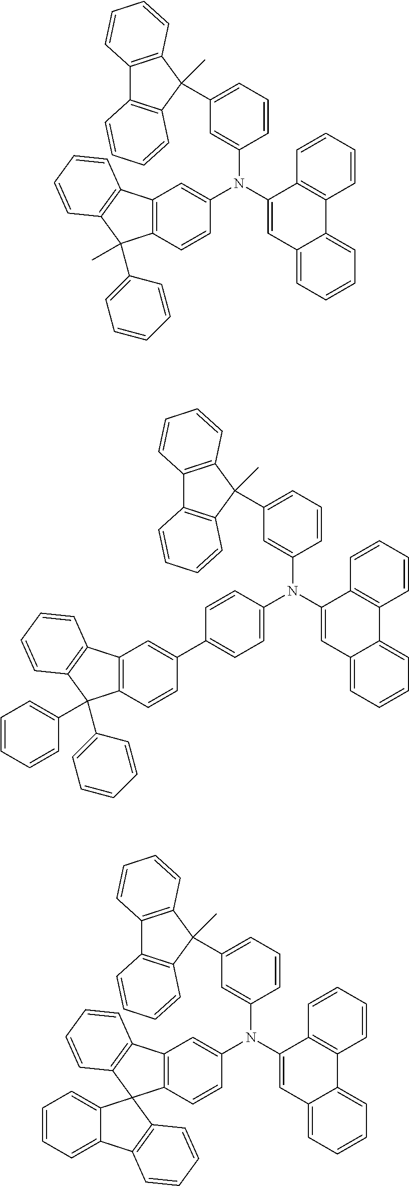 [SMILES: CC1(c2cccc(N(c3ccc4c(c3)-c3ccccc3C4(C)c3ccccc3)c3cc4ccccc4c4ccccc34)c2)c2ccccc2-c2ccccc21 ; CC1(c2cccc(N(c3ccc(-c4ccc5c(c4)-c4ccccc4C5(c4ccccc4)c4ccccc4)cc3)c3cc4ccccc4c4ccccc34)c2)c2ccccc2-c2ccccc21 ; CC1(c2cccc(N(c3ccc4c(c3)-c3ccccc3C43c4ccccc4-c4ccccc43)c3cc4ccccc4c4ccccc34)c2)c2ccccc2-c2ccccc21]

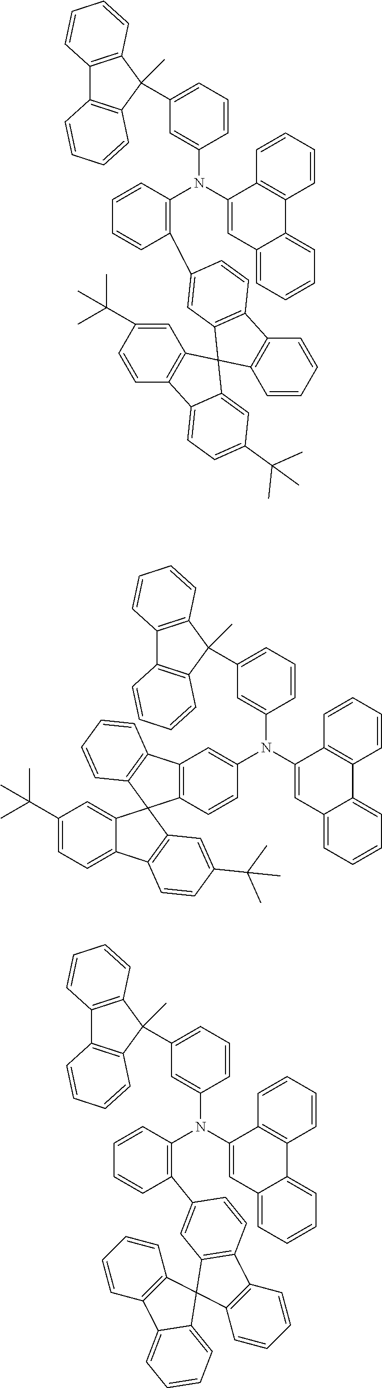 [SMILES: CC(C)(C)c1ccc2c(c1)C1(c3ccccc3-c3ccc(-c4ccccc4N(c4cccc(C5(C)c6ccccc6-c6ccccc65)c4)c4cc5ccccc5c5ccccc45)cc31)c1cc(C(C)(C)C)ccc1-2 ; CC(C)(C)c1ccc2c(c1)C1(c3ccccc3-c3cc(N(c4cccc(C5(C)c6ccccc6-c6ccccc65)c4)c4cc5ccccc5c5ccccc45)ccc31)c1cc(C(C)(C)C)ccc1-2 ; CC1(c2cccc(N(c3ccccc3-c3ccc4c(c3)C3(c5ccccc5-c5ccccc53)c3ccccc3-4)c3cc4ccccc4c4ccccc34)c2)c2ccccc2-c2ccccc21]

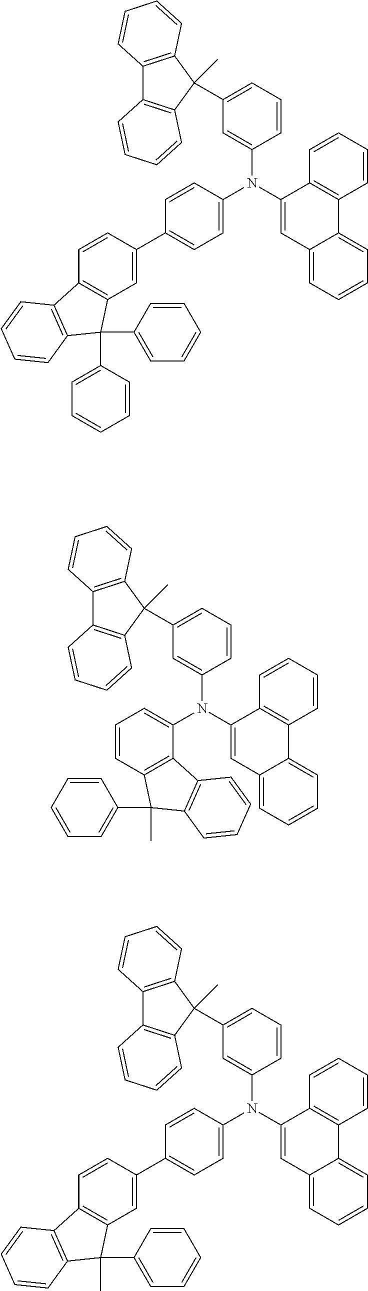 [SMILES: CC1(c2cccc(N(c3ccc(-c4ccc5c(c4)C(c4ccccc4)(c4ccccc4)c4ccccc4-5)cc3)c3cc4ccccc4c4ccccc34)c2)c2ccccc2-c2ccccc21 ; CC1(c2cccc(N(c3cccc4c3-c3ccccc3C4(C)c3ccccc3)c3cc4ccccc4c4ccccc34)c2)c2ccccc2-c2ccccc21 ; CC1(c2cccc(N(c3ccc(-c4ccc5c(c4)C(C)(c4ccccc4)c4ccccc4-5)cc3)c3cc4ccccc4c4ccccc34)c2)c2ccccc2-c2ccccc21]

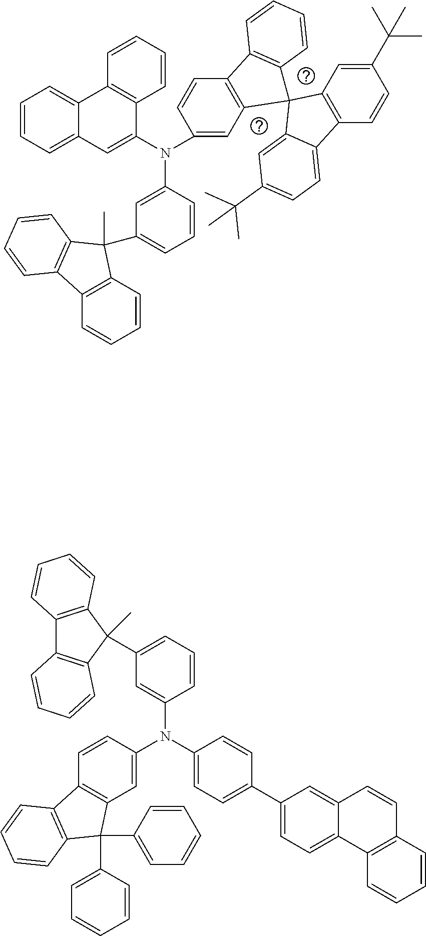 [SMILES: CC(C)(C)c1ccc2c(c1)C1(c3ccccc3-c3ccc(N(c4cccc(C5(C)c6ccccc6-c6ccccc65)c4)c4cc5ccccc5c5ccccc45)cc31)c1cc(C(C)(C)C)ccc1-2 ; CC1(c2cccc(N(c3ccc(-c4ccc5c(ccc6ccccc65)c4)cc3)c3ccc4c(c3)C(c3ccccc3)(c3ccccc3)c3ccccc3-4)c2)c2ccccc2-c2ccccc21]

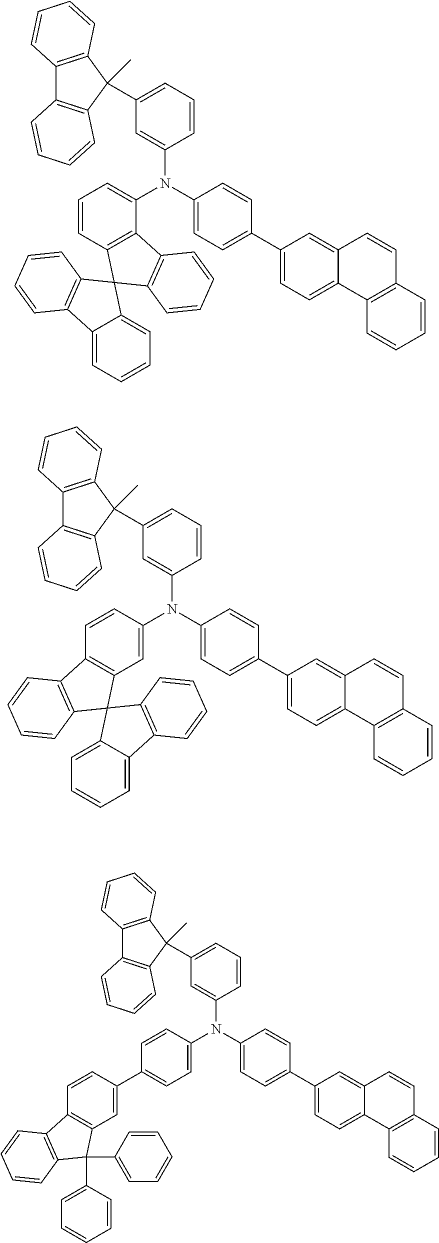 [SMILES: CC1(c2cccc(N(c3ccc(-c4ccc5c(ccc6ccccc65)c4)cc3)c3cccc4c3-c3ccccc3C43c4ccccc4-c4ccccc43)c2)c2ccccc2-c2ccccc21 ; CC1(c2cccc(N(c3ccc(-c4ccc5c(ccc6ccccc65)c4)cc3)c3ccc4c(c3)C3(c5ccccc5-c5ccccc53)c3ccccc3-4)c2)c2ccccc2-c2ccccc21 ; CC1(c2cccc(N(c3ccc(-c4ccc5c(c4)C(c4ccccc4)(c4ccccc4)c4ccccc4-5)cc3)c3ccc(-c4ccc5c(ccc6ccccc65)c4)cc3)c2)c2ccccc2-c2ccccc21]

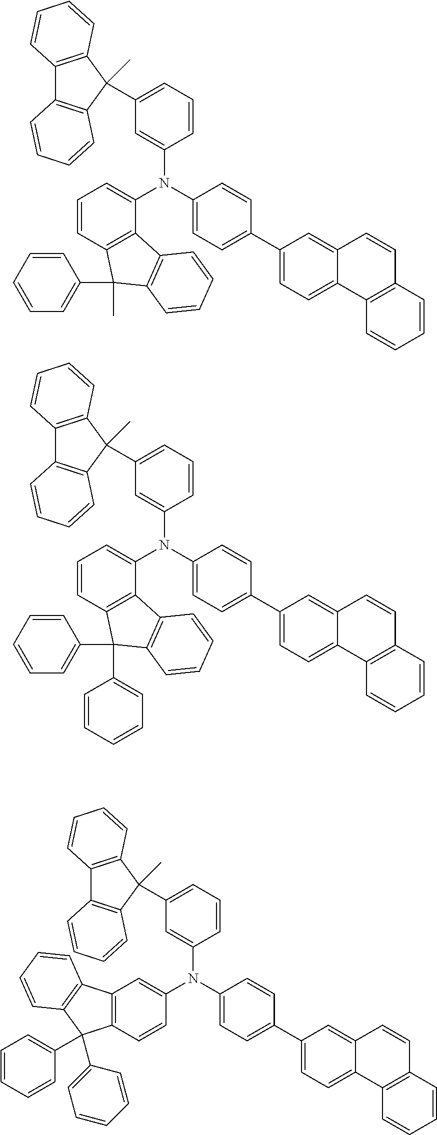 [SMILES: CC1(c2cccc(N(c3ccc(-c4ccc5c(ccc6ccccc65)c4)cc3)c3cccc4c3-c3ccccc3C4(C)c3ccccc3)c2)c2ccccc2-c2ccccc21 ; CC1(c2cccc(N(c3ccc(-c4ccc5c(ccc6ccccc65)c4)cc3)c3cccc4c3-c3ccccc3C4(c3ccccc3)c3ccccc3)c2)c2ccccc2-c2ccccc21 ; CC1(c2cccc(N(c3ccc(-c4ccc5c(ccc6ccccc65)c4)cc3)c3ccc4c(c3)-c3ccccc3C4(c3ccccc3)c3ccccc3)c2)c2ccccc2-c2ccccc21]

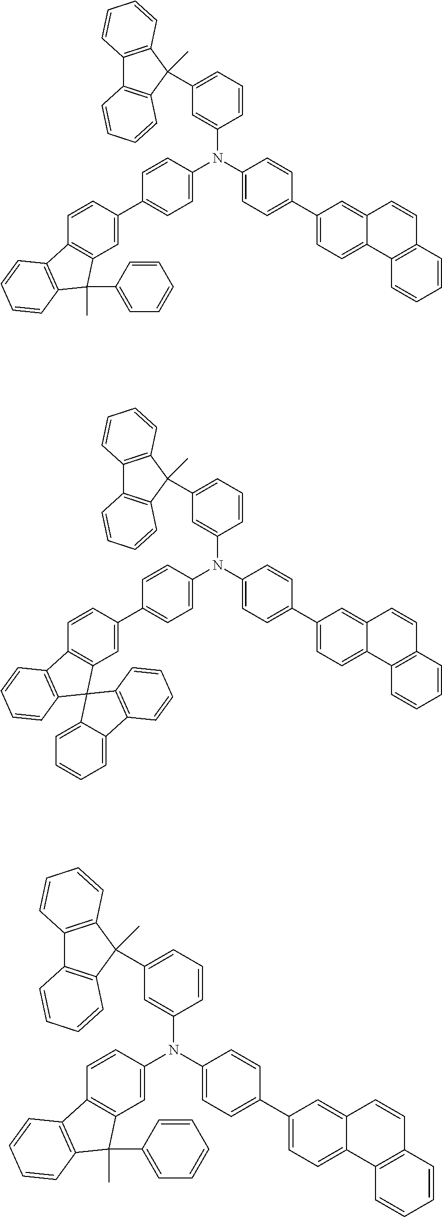 [SMILES: CC1(c2cccc(N(c3ccc(-c4ccc5c(c4)C(C)(c4ccccc4)c4ccccc4-5)cc3)c3ccc(-c4ccc5c(ccc6ccccc65)c4)cc3)c2)c2ccccc2-c2ccccc21 ; CC1(c2cccc(N(c3ccc(-c4ccc5c(c4)C4(c6ccccc6-c6ccccc64)c4ccccc4-5)cc3)c3ccc(-c4ccc5c(ccc6ccccc65)c4)cc3)c2)c2ccccc2-c2ccccc21 ; CC1(c2cccc(N(c3ccc(-c4ccc5c(ccc6ccccc65)c4)cc3)c3ccc4c(c3)C(C)(c3ccccc3)c3ccccc3-4)c2)c2ccccc2-c2ccccc21]

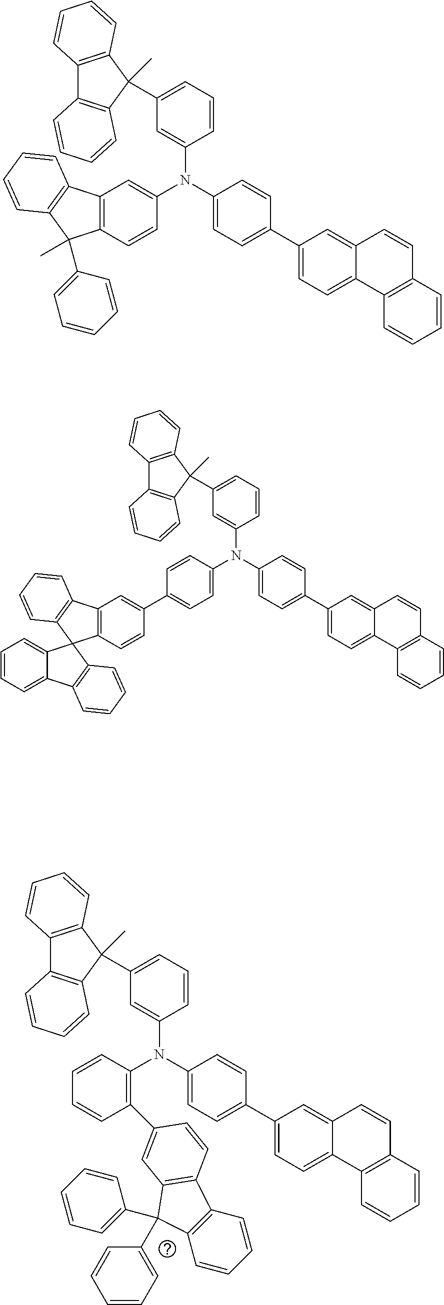 [SMILES: CC1(c2cccc(N(c3ccc(-c4ccc5c(ccc6ccccc65)c4)cc3)c3ccc4c(c3)-c3ccccc3C4(C)c3ccccc3)c2)c2ccccc2-c2ccccc21 ; CC1(c2cccc(N(c3ccc(-c4ccc5c(c4)-c4ccccc4C54c5ccccc5-c5ccccc54)cc3)c3ccc(-c4ccc5c(ccc6ccccc65)c4)cc3)c2)c2ccccc2-c2ccccc21 ; CC1(c2cccc(N(c3ccc(-c4ccc5c(ccc6ccccc65)c4)cc3)c3ccccc3-c3ccc4c(c3)C(c3ccccc3)(c3ccccc3)c3ccccc3-4)c2)c2ccccc2-c2ccccc21]

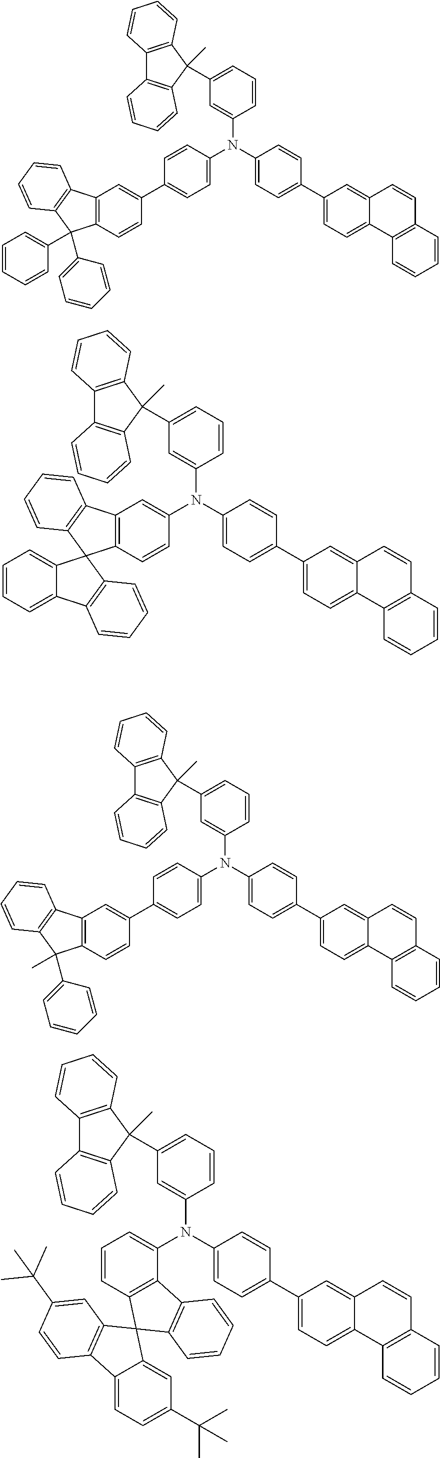

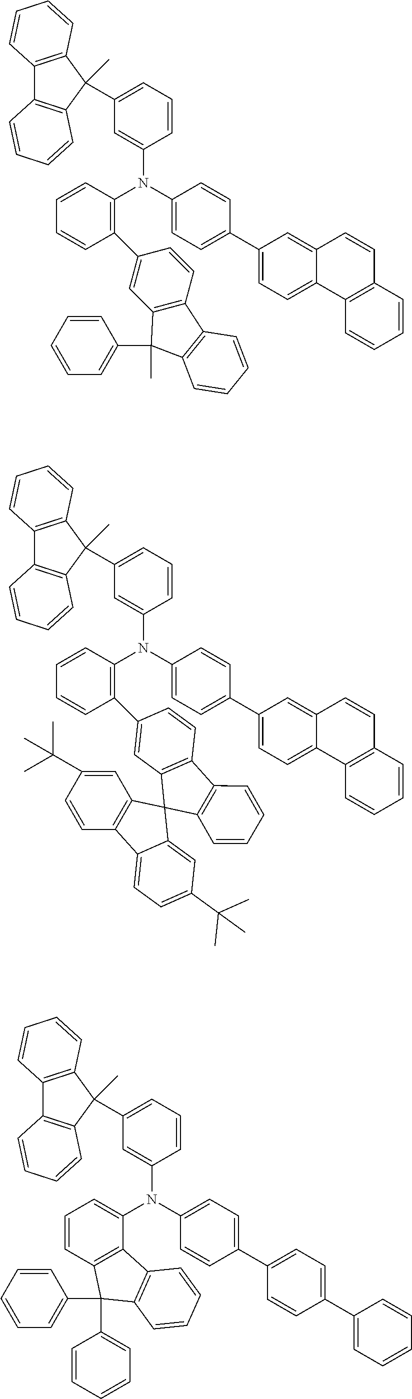 [SMILES: CC1(c2cccc(N(c3ccc(-c4ccc5c(ccc6ccccc65)c4)cc3)c3ccccc3-c3ccc4c(c3)C(C)(c3ccccc3)c3ccccc3-4)c2)c2ccccc2-c2ccccc21 ; CC(C)(C)c1ccc2c(c1)C1(c3ccccc3-c3ccc(-c4ccccc4N(c4ccc(-c5ccc6c(ccc7ccccc76)c5)cc4)c4cccc(C5(C)c6ccccc6-c6ccccc65)c4)cc31)c1cc(C(C)(C)C)ccc1-2 ; CC1(c2cccc(N(c3ccc(-c4ccc(-c5ccccc5)cc4)cc3)c3cccc4c3-c3ccccc3C4(c3ccccc3)c3ccccc3)c2)c2ccccc2-c2ccccc21]

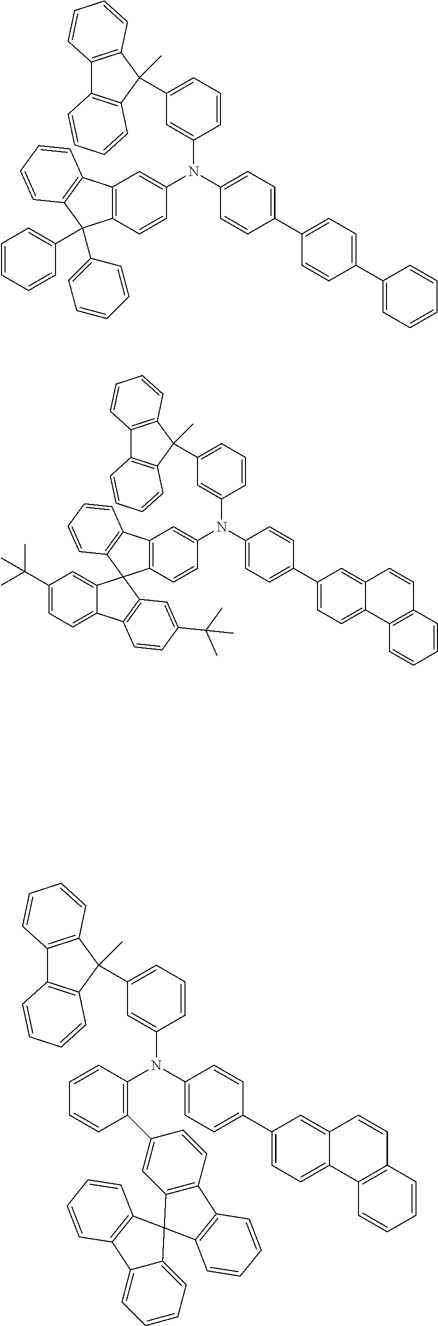 [SMILES: CC1(c2cccc(N(c3ccc(-c4ccc(-c5ccccc5)cc4)cc3)c3ccc4c(c3)-c3ccccc3C4(c3ccccc3)c3ccccc3)c2)c2ccccc2-c2ccccc21 ; CC(C)(C)c1ccc2c(c1)C1(c3ccccc3-c3cc(N(c4ccc(-c5ccc6c(ccc7ccccc76)c5)cc4)c4cccc(C5(C)c6ccccc6-c6ccccc65)c4)ccc31)c1cc(C(C)(C)C)ccc1-2 ; CC1(c2cccc(N(c3ccc(-c4ccc5c(ccc6ccccc65)c4)cc3)c3ccccc3-c3ccc4c(c3)C3(c5ccccc5-c5ccccc53)c3ccccc3-4)c2)c2ccccc2-c2ccccc21]

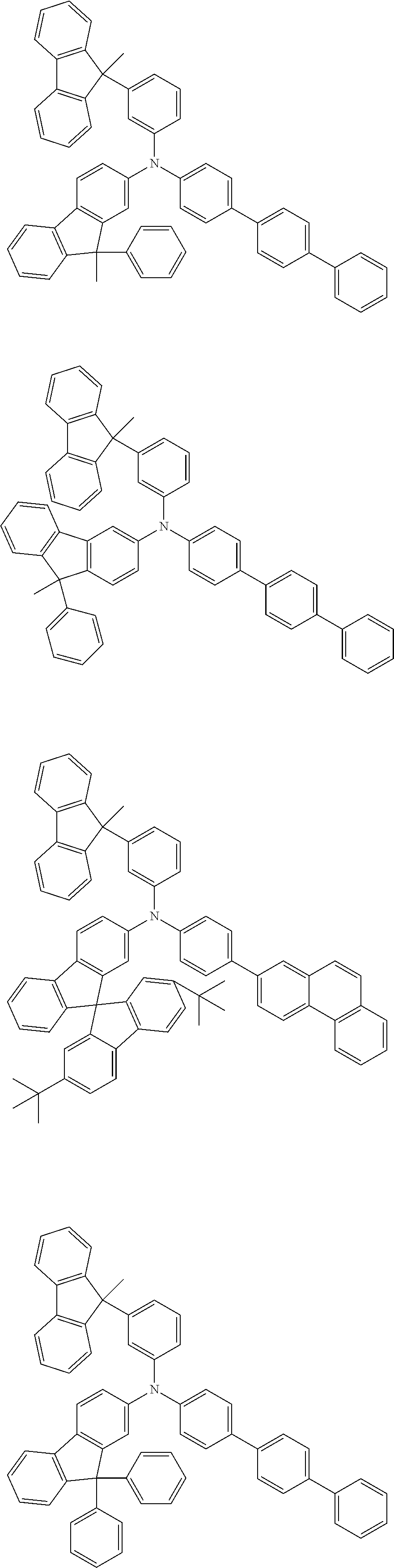 [SMILES: CC1(c2cccc(N(c3ccc(-c4ccc(-c5ccccc5)cc4)cc3)c3ccc4c(c3)C(C)(c3ccccc3)c3ccccc3-4)c2)c2ccccc2-c2ccccc21 ; CC1(c2cccc(N(c3ccc(-c4ccc(-c5ccccc5)cc4)cc3)c3ccc4c(c3)-c3ccccc3C4(C)c3ccccc3)c2)c2ccccc2-c2ccccc21 ; CC(C)(C)c1ccc2c(c1)C1(c3ccccc3-c3ccc(N(c4ccc(-c5ccc6c(ccc7ccccc76)c5)cc4)c4cccc(C5(C)c6ccccc6-c6ccccc65)c4)cc31)c1cc(C(C)(C)C)ccc1-2 ; CC1(c2cccc(N(c3ccc(-c4ccc(-c5ccccc5)cc4)cc3)c3ccc4c(c3)C(c3ccccc3)(c3ccccc3)c3ccccc3-4)c2)c2ccccc2-c2ccccc21]

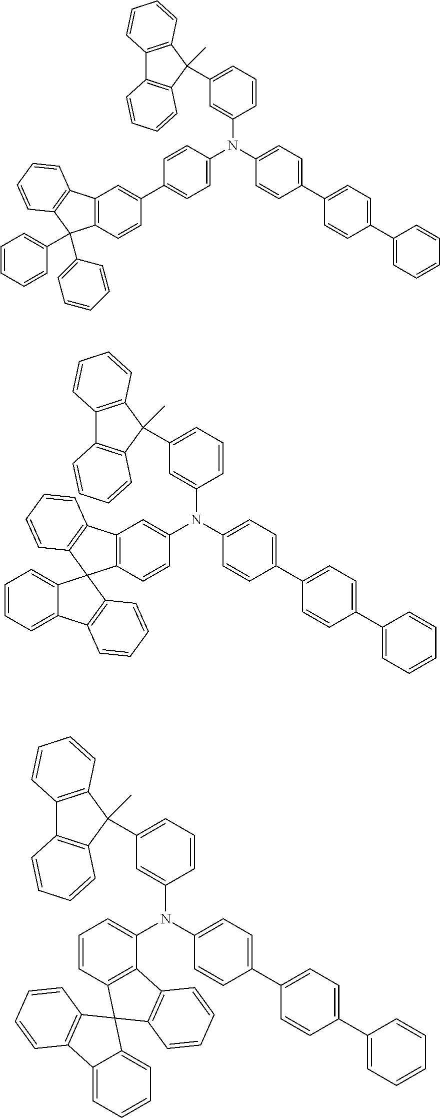 [SMILES: CC1(c2cccc(N(c3ccc(-c4ccc(-c5ccccc5)cc4)cc3)c3ccc(-c4ccc5c(c4)-c4ccccc4C5(c4ccccc4)c4ccccc4)cc3)c2)c2ccccc2-c2ccccc21 ; CC1(c2cccc(N(c3ccc(-c4ccc(-c5ccccc5)cc4)cc3)c3ccc4c(c3)-c3ccccc3C43c4ccccc4-c4ccccc43)c2)c2ccccc2-c2ccccc21 ; CC1(c2cccc(N(c3ccc(-c4ccc(-c5ccccc5)cc4)cc3)c3cccc4c3-c3ccccc3C43c4ccccc4-c4ccccc43)c2)c2ccccc2-c2ccccc21]

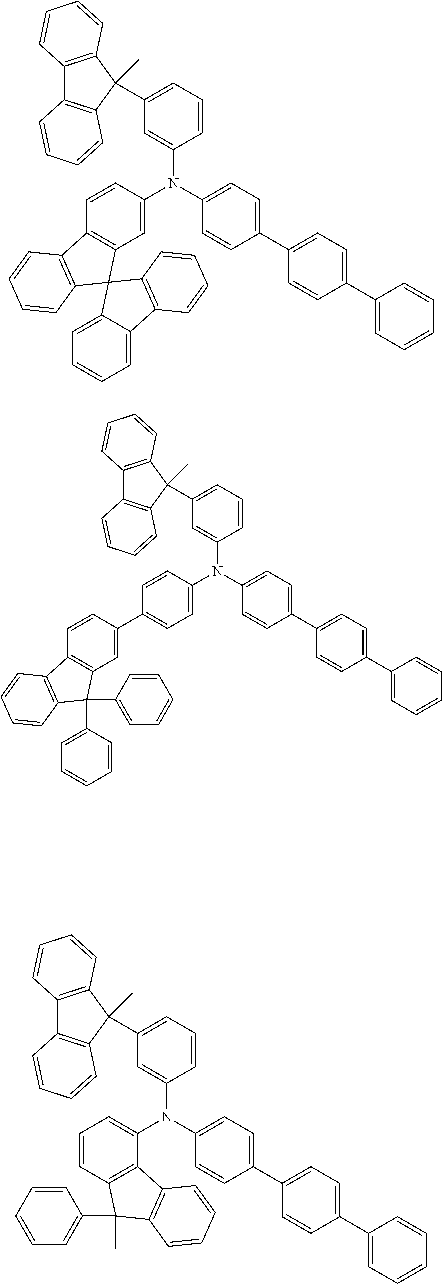

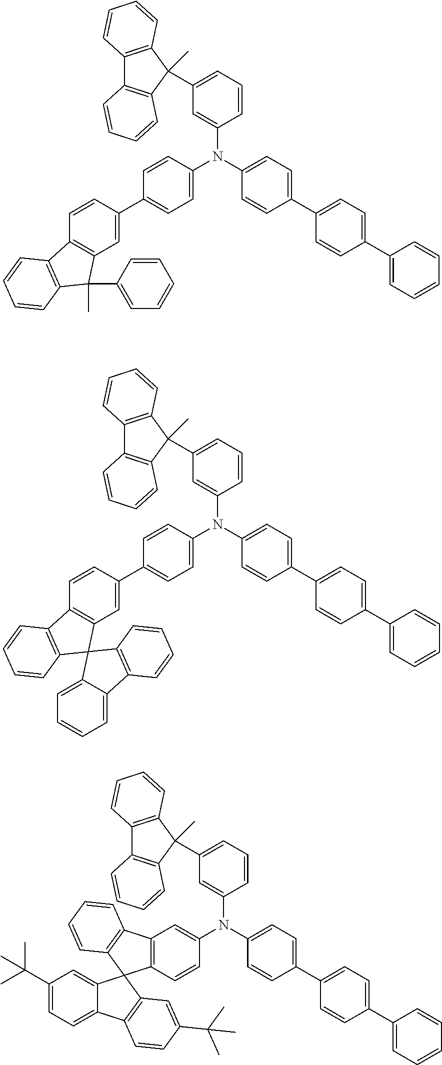 [SMILES: CC1(c2cccc(N(c3ccc(-c4ccc(-c5ccccc5)cc4)cc3)c3ccc(-c4ccc5c(c4)C(C)(c4ccccc4)c4ccccc4-5)cc3)c2)c2ccccc2-c2ccccc21 ; CC1(c2cccc(N(c3ccc(-c4ccc(-c5ccccc5)cc4)cc3)c3ccc(-c4ccc5c(c4)C4(c6ccccc6-c6ccccc64)c4ccccc4-5)cc3)c2)c2ccccc2-c2ccccc21 ; CC(C)(C)c1ccc2c(c1)C1(c3ccccc3-c3cc(N(c4ccc(-c5ccc(-c6ccccc6)cc5)cc4)c4cccc(C5(C)c6ccccc6-c6ccccc65)c4)ccc31)c1cc(C(C)(C)C)ccc1-2]

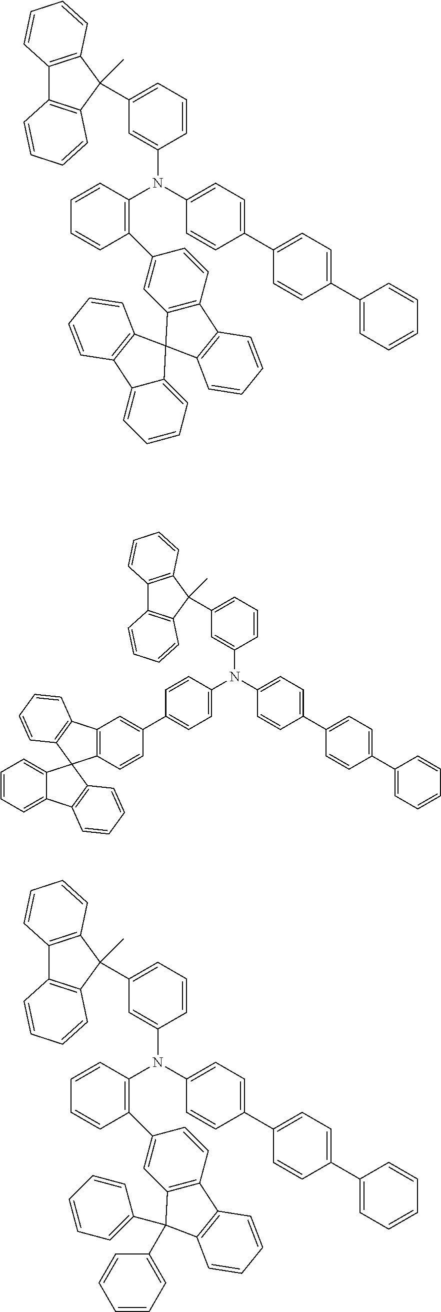 [SMILES: CC1(c2cccc(N(c3ccc(-c4ccc(-c5ccccc5)cc4)cc3)c3ccccc3-c3ccc4c(c3)C3(c5ccccc5-c5ccccc53)c3ccccc3-4)c2)c2ccccc2-c2ccccc21 ; CC1(c2cccc(N(c3ccc(-c4ccc(-c5ccccc5)cc4)cc3)c3ccc(-c4ccc5c(c4)-c4ccccc4C54c5ccccc5-c5ccccc54)cc3)c2)c2ccccc2-c2ccccc21 ; CC1(c2cccc(N(c3ccc(-c4ccc(-c5ccccc5)cc4)cc3)c3ccccc3-c3ccc4c(c3)C(c3ccccc3)(c3ccccc3)c3ccccc3-4)c2)c2ccccc2-c2ccccc21]

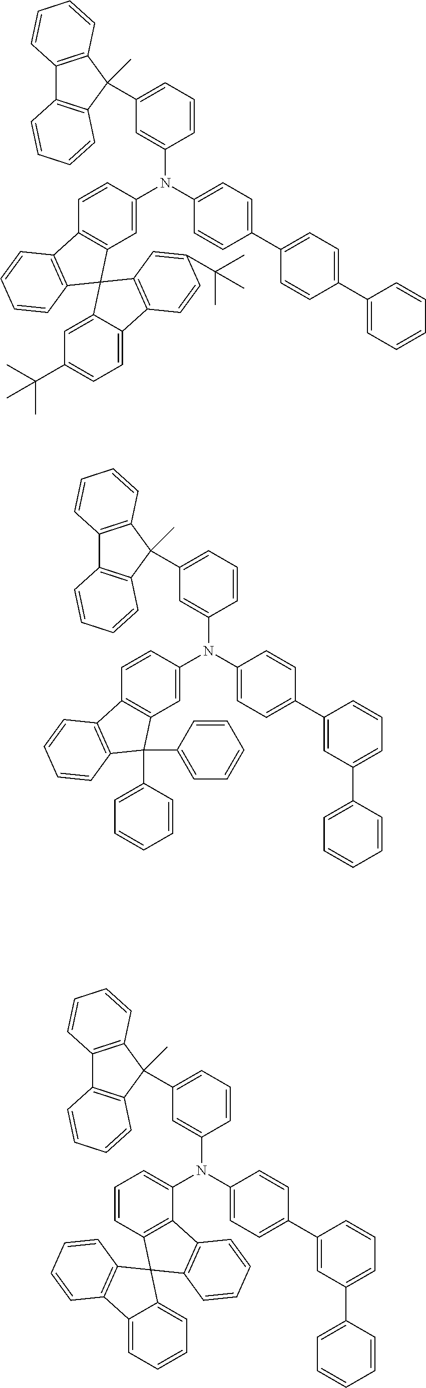 [SMILES: CC(C)(C)c1ccc2c(c1)C1(c3ccccc3-c3ccc(N(c4ccc(-c5ccc(-c6ccccc6)cc5)cc4)c4cccc(C5(C)c6ccccc6-c6ccccc65)c4)cc31)c1cc(C(C)(C)C)ccc1-2 ; CC1(c2cccc(N(c3ccc(-c4cccc(-c5ccccc5)c4)cc3)c3ccc4c(c3)C(c3ccccc3)(c3ccccc3)c3ccccc3-4)c2)c2ccccc2-c2ccccc21 ; CC1(c2cccc(N(c3ccc(-c4cccc(-c5ccccc5)c4)cc3)c3cccc4c3-c3ccccc3C43c4ccccc4-c4ccccc43)c2)c2ccccc2-c2ccccc21]

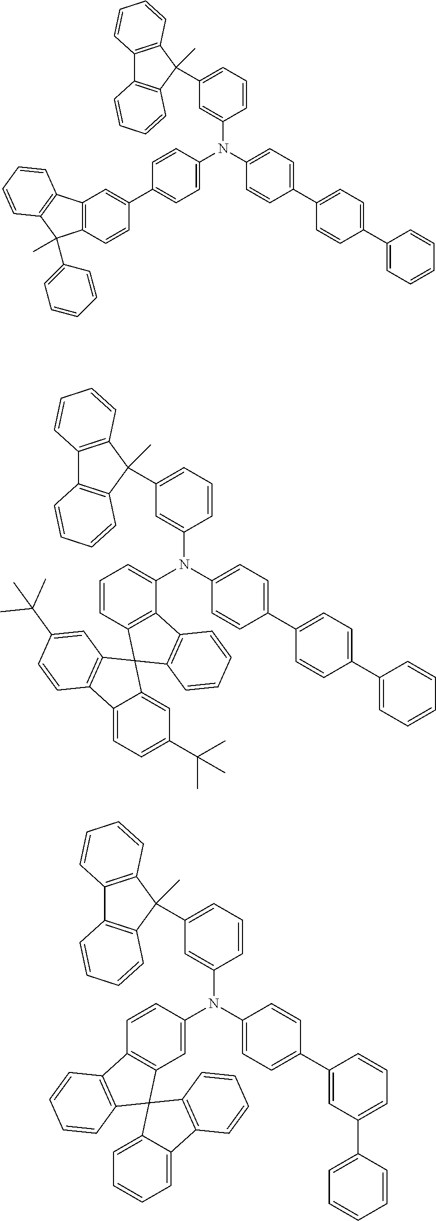 [SMILES: CC1(c2cccc(N(c3ccc(-c4ccc(-c5ccccc5)cc4)cc3)c3ccc(-c4ccc5c(c4)-c4ccccc4C5(C)c4ccccc4)cc3)c2)c2ccccc2-c2ccccc21 ; CC(C)(C)c1ccc2c(c1)C1(c3cc(C(C)(C)C)ccc3-2)c2ccccc2-c2c(N(c3ccc(-c4ccc(-c5ccccc5)cc4)cc3)c3cccc(C4(C)c5ccccc5-c5ccccc54)c3)cccc21 ; CC1(c2cccc(N(c3ccc(-c4cccc(-c5ccccc5)c4)cc3)c3ccc4c(c3)C3(c5ccccc5-c5ccccc53)c3ccccc3-4)c2)c2ccccc2-c2ccccc21]

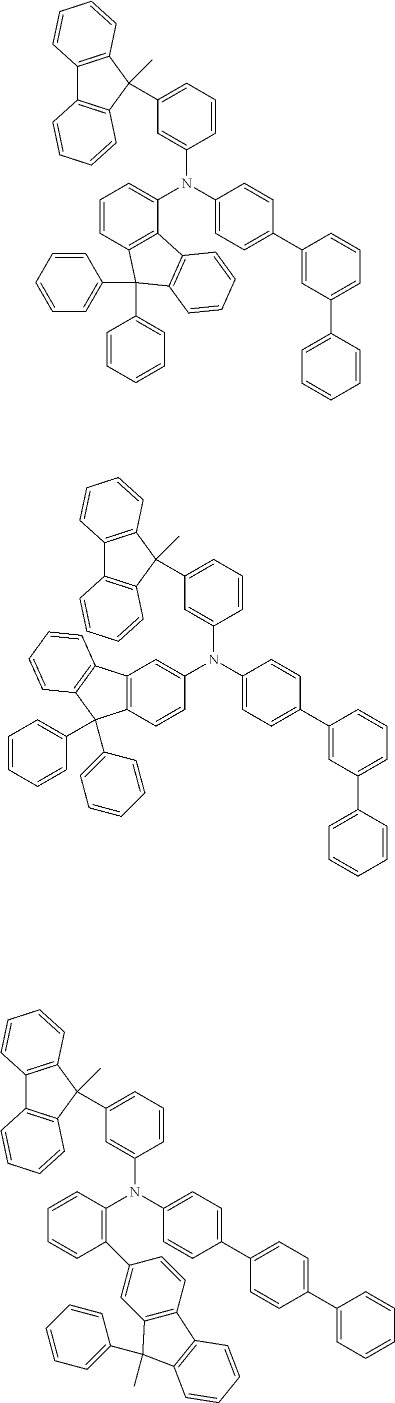 [SMILES: CC1(c2cccc(N(c3ccc(-c4cccc(-c5ccccc5)c4)cc3)c3cccc4c3-c3ccccc3C4(c3ccccc3)c3ccccc3)c2)c2ccccc2-c2ccccc21 ; CC1(c2cccc(N(c3ccc(-c4cccc(-c5ccccc5)c4)cc3)c3ccc4c(c3)-c3ccccc3C4(c3ccccc3)c3ccccc3)c2)c2ccccc2-c2ccccc21 ; CC1(c2cccc(N(c3ccc(-c4ccc(-c5ccccc5)cc4)cc3)c3ccccc3-c3ccc4c(c3)C(C)(c3ccccc3)c3ccccc3-4)c2)c2ccccc2-c2ccccc21]

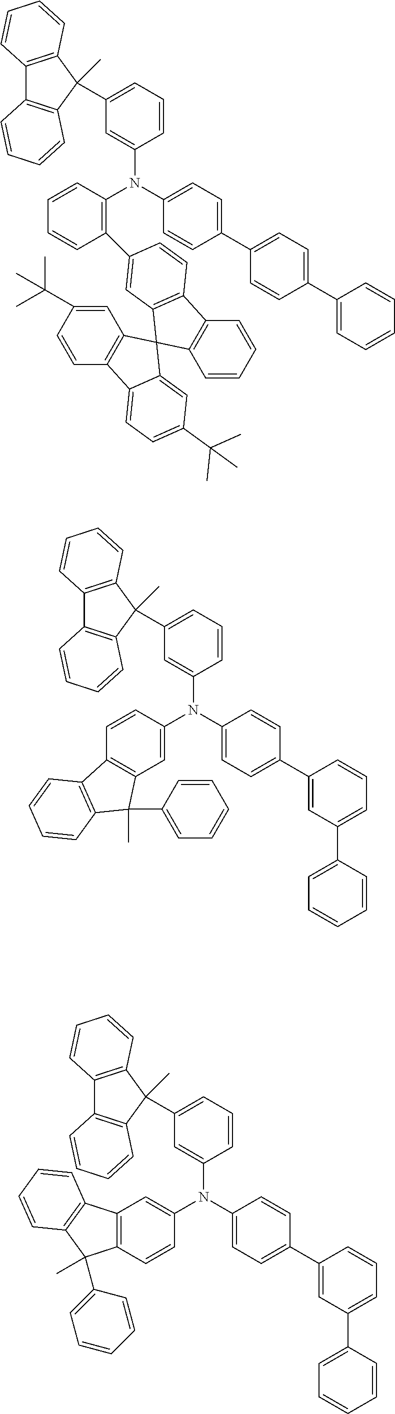 [SMILES: CC(C)(C)c1ccc2c(c1)C1(c3ccccc3-c3ccc(-c4ccccc4N(c4ccc(-c5ccc(-c6ccccc6)cc5)cc4)c4cccc(C5(C)c6ccccc6-c6ccccc65)c4)cc31)c1cc(C(C)(C)C)ccc1-2 ; CC1(c2cccc(N(c3ccc(-c4cccc(-c5ccccc5)c4)cc3)c3ccc4c(c3)C(C)(c3ccccc3)c3ccccc3-4)c2)c2ccccc2-c2ccccc21 ; CC1(c2cccc(N(c3ccc(-c4cccc(-c5ccccc5)c4)cc3)c3ccc4c(c3)-c3ccccc3C4(C)c3ccccc3)c2)c2ccccc2-c2ccccc21]

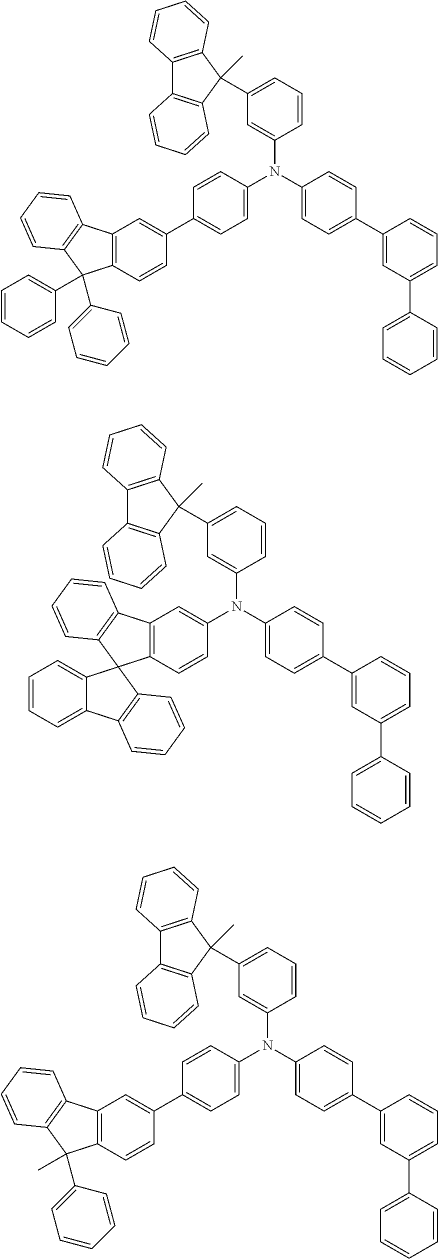 [SMILES: CC1(c2cccc(N(c3ccc(-c4cccc(-c5ccccc5)c4)cc3)c3ccc(-c4ccc5c(c4)-c4ccccc4C5(c4ccccc4)c4ccccc4)cc3)c2)c2ccccc2-c2ccccc21 ; CC1(c2cccc(N(c3ccc(-c4cccc(-c5ccccc5)c4)cc3)c3ccc4c(c3)-c3ccccc3C43c4ccccc4-c4ccccc43)c2)c2ccccc2-c2ccccc21 ; CC1(c2cccc(N(c3ccc(-c4cccc(-c5ccccc5)c4)cc3)c3ccc(-c4ccc5c(c4)-c4ccccc4C5(C)c4ccccc4)cc3)c2)c2ccccc2-c2ccccc21]

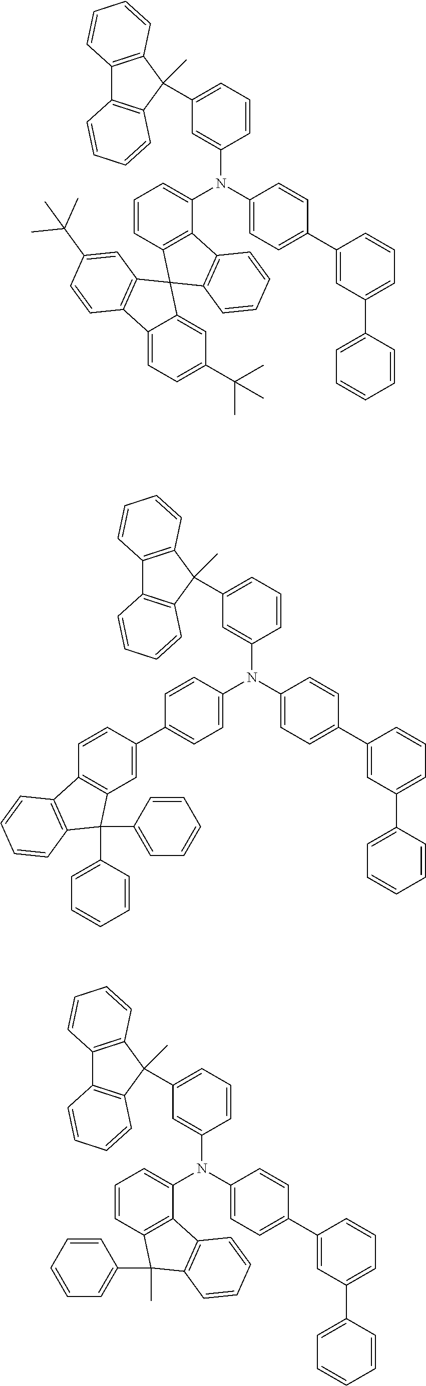 [SMILES: CC(C)(C)c1ccc2c(c1)C1(c3cc(C(C)(C)C)ccc3-2)c2ccccc2-c2c(N(c3ccc(-c4cccc(-c5ccccc5)c4)cc3)c3cccc(C4(C)c5ccccc5-c5ccccc54)c3)cccc21 ; CC1(c2cccc(N(c3ccc(-c4cccc(-c5ccccc5)c4)cc3)c3ccc(-c4ccc5c(c4)C(c4ccccc4)(c4ccccc4)c4ccccc4-5)cc3)c2)c2ccccc2-c2ccccc21 ; CC1(c2cccc(N(c3ccc(-c4cccc(-c5ccccc5)c4)cc3)c3cccc4c3-c3ccccc3C4(C)c3ccccc3)c2)c2ccccc2-c2ccccc21]

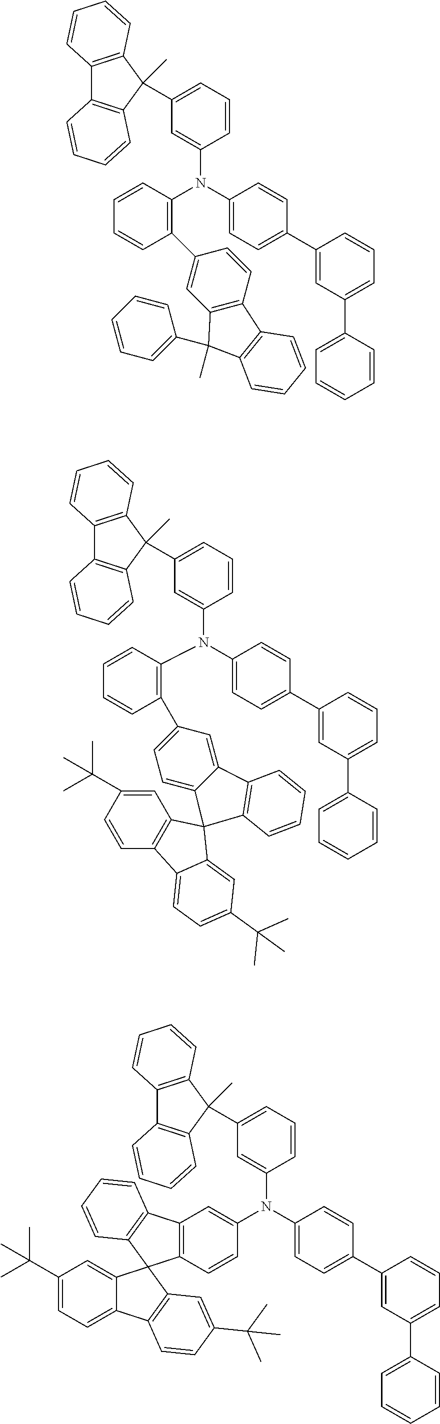 [SMILES: CC1(c2cccc(N(c3ccc(-c4cccc(-c5ccccc5)c4)cc3)c3ccccc3-c3ccc4c(c3)C(C)(c3ccccc3)c3ccccc3-4)c2)c2ccccc2-c2ccccc21 ; CC(C)(C)c1ccc2c(c1)C1(c3ccccc3-c3cc(-c4ccccc4N(c4ccc(-c5cccc(-c6ccccc6)c5)cc4)c4cccc(C5(C)c6ccccc6-c6ccccc65)c4)ccc31)c1cc(C(C)(C)C)ccc1-2 ; CC(C)(C)c1ccc2c(c1)C1(c3ccccc3-c3cc(N(c4ccc(-c5cccc(-c6ccccc6)c5)cc4)c4cccc(C5(C)c6ccccc6-c6ccccc65)c4)ccc31)c1cc(C(C)(C)C)ccc1-2]

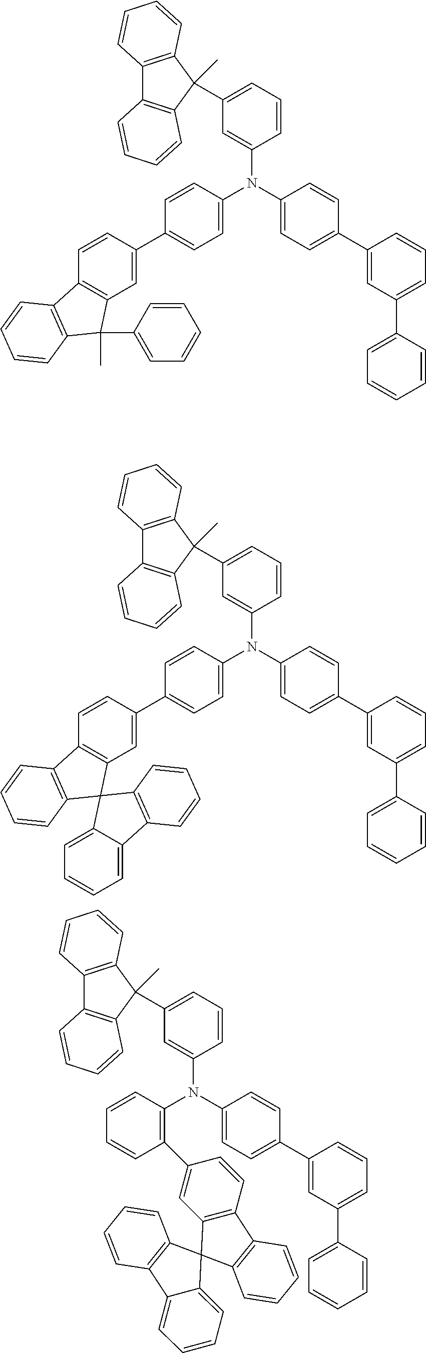

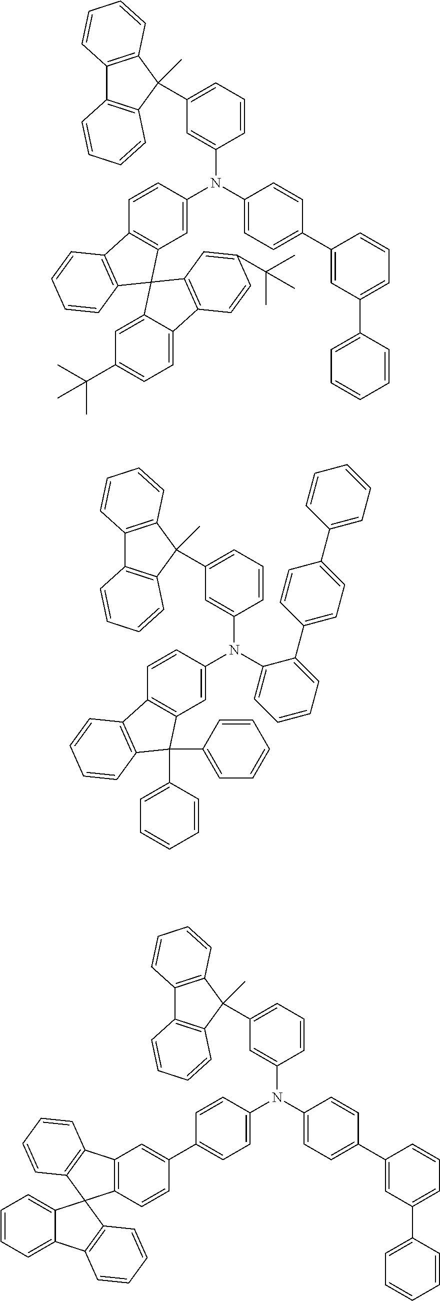 [SMILES: CC(C)(C)c1ccc2c(c1)C1(c3ccccc3-c3ccc(N(c4ccc(-c5cccc(-c6ccccc6)c5)cc4)c4cccc(C5(C)c6ccccc6-c6ccccc65)c4)cc31)c1cc(C(C)(C)C)ccc1-2 ; CC1(c2cccc(N(c3ccc4c(c3)C(c3ccccc3)(c3ccccc3)c3ccccc3-4)c3ccccc3-c3ccc(-c4ccccc4)cc3)c2)c2ccccc2-c2ccccc21 ; CC1(c2cccc(N(c3ccc(-c4cccc(-c5ccccc5)c4)cc3)c3ccc(-c4ccc5c(c4)-c4ccccc4C54c5ccccc5-c5ccccc54)cc3)c2)c2ccccc2-c2ccccc21]

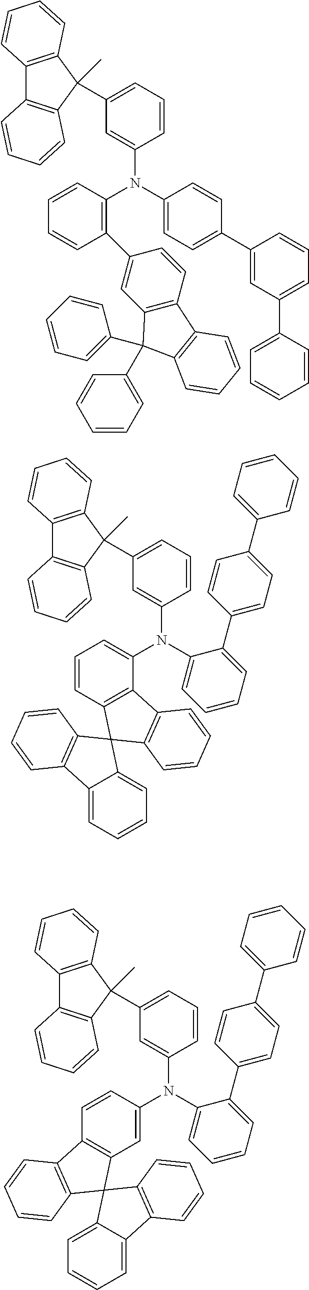

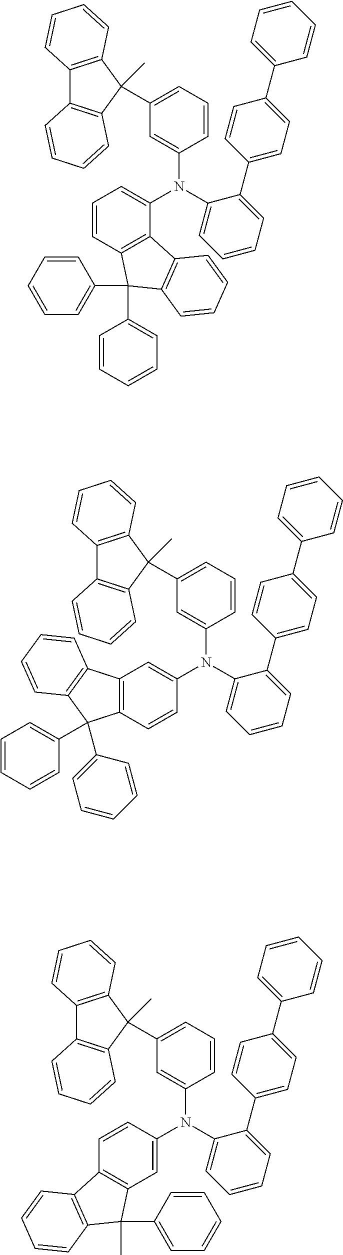 [SMILES: CC1(c2cccc(N(c3ccccc3-c3ccc(-c4ccccc4)cc3)c3cccc4c3-c3ccccc3C4(c3ccccc3)c3ccccc3)c2)c2ccccc2-c2ccccc21 ; CC1(c2cccc(N(c3ccc4c(c3)-c3ccccc3C4(c3ccccc3)c3ccccc3)c3ccccc3-c3ccc(-c4ccccc4)cc3)c2)c2ccccc2-c2ccccc21 ; CC1(c2cccc(N(c3ccc4c(c3)C(C)(c3ccccc3)c3ccccc3-4)c3ccccc3-c3ccc(-c4ccccc4)cc3)c2)c2ccccc2-c2ccccc21]

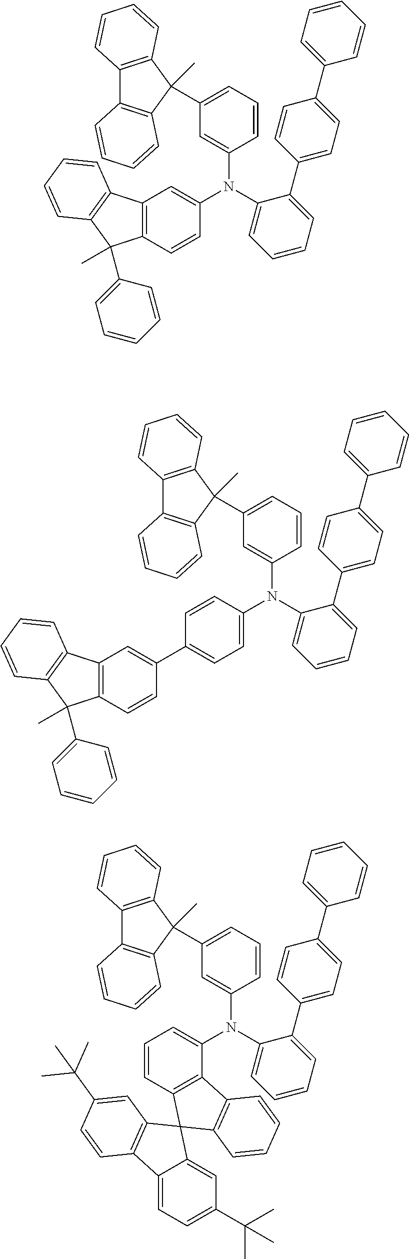 [SMILES: CC1(c2cccc(N(c3ccc4c(c3)-c3ccccc3C4(C)c3ccccc3)c3ccccc3-c3ccc(-c4ccccc4)cc3)c2)c2ccccc2-c2ccccc21 ; CC1(c2cccc(N(c3ccc(-c4ccc5c(c4)-c4ccccc4C5(C)c4ccccc4)cc3)c3ccccc3-c3ccc(-c4ccccc4)cc3)c2)c2ccccc2-c2ccccc21 ; CC(C)(C)c1ccc2c(c1)C1(c3cc(C(C)(C)C)ccc3-2)c2ccccc2-c2c(N(c3cccc(C4(C)c5ccccc5-c5ccccc54)c3)c3ccccc3-c3ccc(-c4ccccc4)cc3)cccc21]

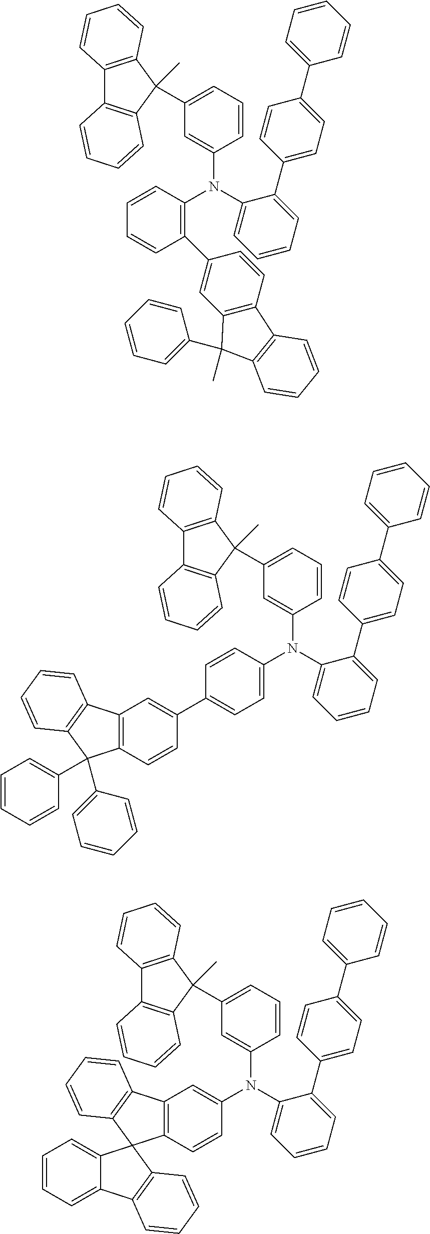 [SMILES: CC1(c2cccc(N(c3ccccc3-c3ccc(-c4ccccc4)cc3)c3ccccc3-c3ccc4c(c3)C(C)(c3ccccc3)c3ccccc3-4)c2)c2ccccc2-c2ccccc21 ; CC1(c2cccc(N(c3ccc(-c4ccc5c(c4)-c4ccccc4C5(c4ccccc4)c4ccccc4)cc3)c3ccccc3-c3ccc(-c4ccccc4)cc3)c2)c2ccccc2-c2ccccc21 ; CC1(c2cccc(N(c3ccc4c(c3)-c3ccccc3C43c4ccccc4-c4ccccc43)c3ccccc3-c3ccc(-c4ccccc4)cc3)c2)c2ccccc2-c2ccccc21]

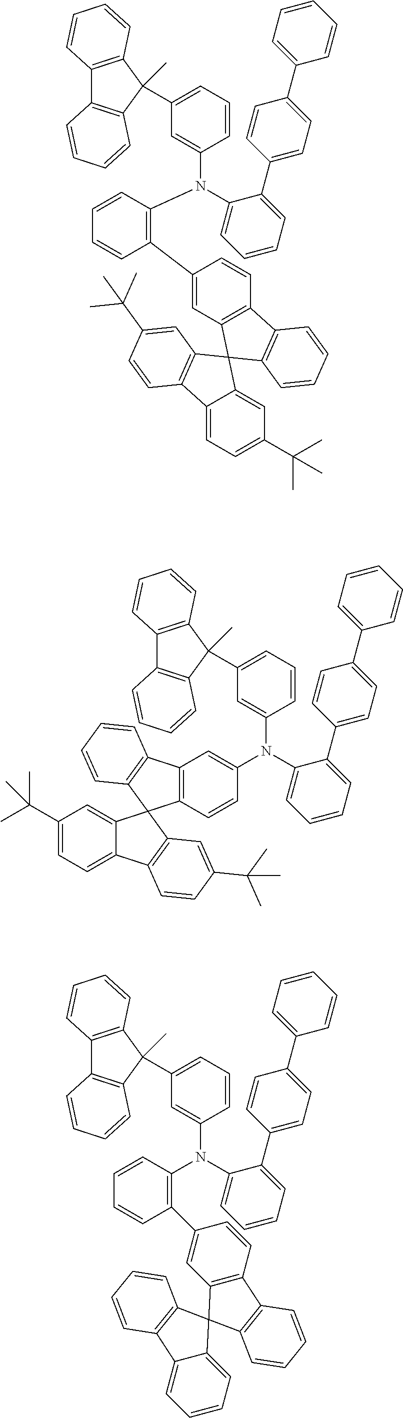 [SMILES: CC(C)(C)c1ccc2c(c1)C1(c3ccccc3-c3ccc(-c4ccccc4N(c4cccc(C5(C)c6ccccc6-c6ccccc65)c4)c4ccccc4-c4ccc(-c5ccccc5)cc4)cc31)c1cc(C(C)(C)C)ccc1-2 ; CC(C)(C)c1ccc2c(c1)C1(c3ccccc3-c3cc(N(c4cccc(C5(C)c6ccccc6-c6ccccc65)c4)c4ccccc4-c4ccc(-c5ccccc5)cc4)ccc31)c1cc(C(C)(C)C)ccc1-2 ; CC1(c2cccc(N(c3ccccc3-c3ccc(-c4ccccc4)cc3)c3ccccc3-c3ccc4c(c3)C3(c5ccccc5-c5ccccc53)c3ccccc3-4)c2)c2ccccc2-c2ccccc21]

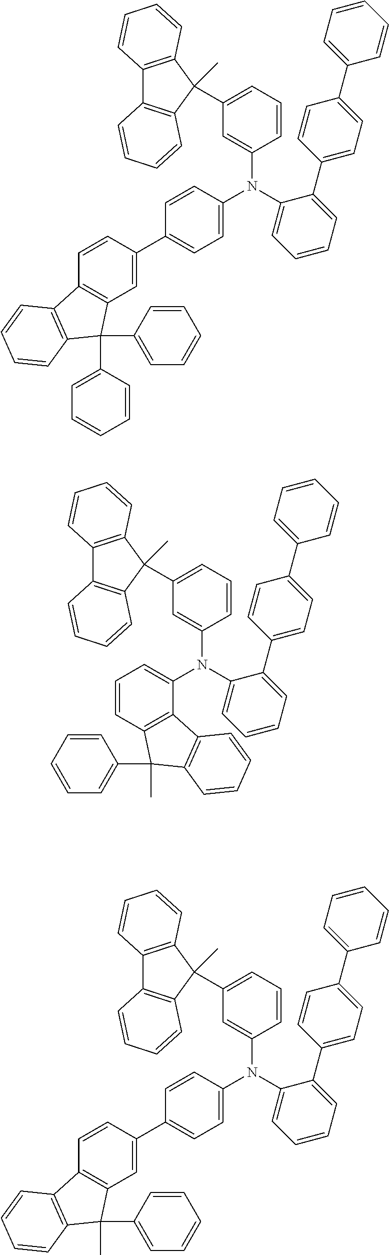 [SMILES: CC1(c2cccc(N(c3ccc(-c4ccc5c(c4)C(c4ccccc4)(c4ccccc4)c4ccccc4-5)cc3)c3ccccc3-c3ccc(-c4ccccc4)cc3)c2)c2ccccc2-c2ccccc21 ; CC1(c2cccc(N(c3ccccc3-c3ccc(-c4ccccc4)cc3)c3cccc4c3-c3ccccc3C4(C)c3ccccc3)c2)c2ccccc2-c2ccccc21 ; CC1(c2cccc(N(c3ccc(-c4ccc5c(c4)C(C)(c4ccccc4)c4ccccc4-5)cc3)c3ccccc3-c3ccc(-c4ccccc4)cc3)c2)c2ccccc2-c2ccccc21]

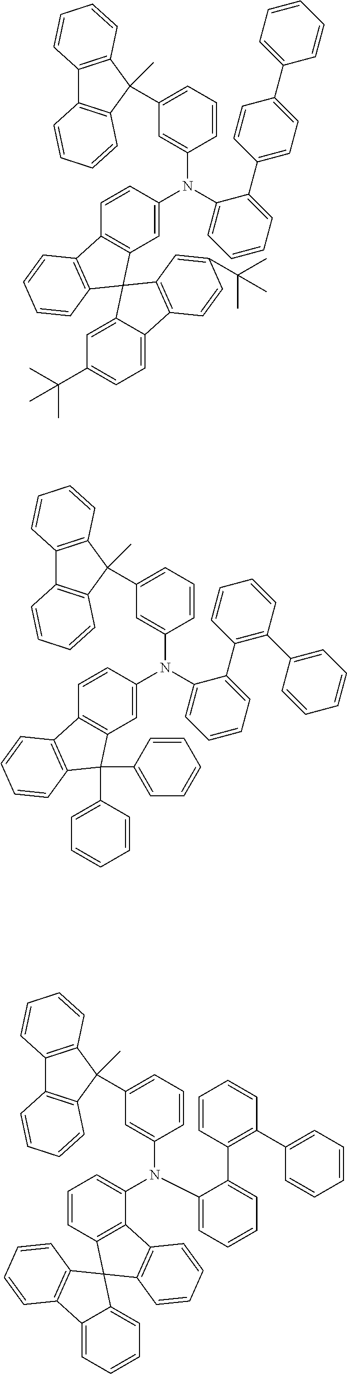 [SMILES: CC(C)(C)c1ccc2c(c1)C1(c3ccccc3-c3ccc(N(c4cccc(C5(C)c6ccccc6-c6ccccc65)c4)c4ccccc4-c4ccc(-c5ccccc5)cc4)cc31)c1cc(C(C)(C)C)ccc1-2 ; CC1(c2cccc(N(c3ccc4c(c3)C(c3ccccc3)(c3ccccc3)c3ccccc3-4)c3ccccc3-c3ccccc3-c3ccccc3)c2)c2ccccc2-c2ccccc21 ; CC1(c2cccc(N(c3ccccc3-c3ccccc3-c3ccccc3)c3cccc4c3-c3ccccc3C43c4ccccc4-c4ccccc43)c2)c2ccccc2-c2ccccc21]

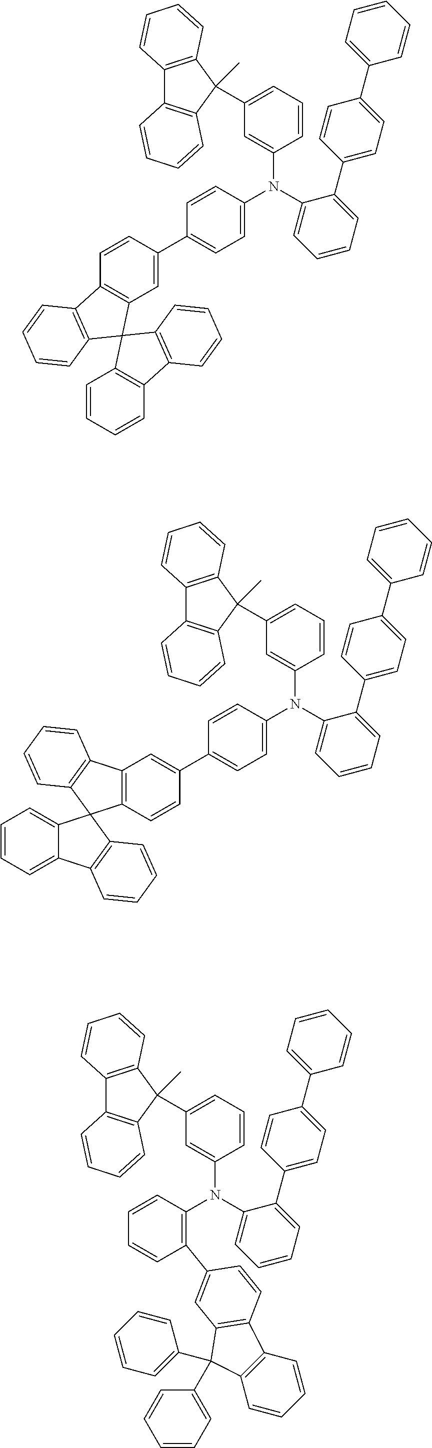 [SMILES: CC1(c2cccc(N(c3ccc(-c4ccc5c(c4)C4(c6ccccc6-c6ccccc64)c4ccccc4-5)cc3)c3ccccc3-c3ccc(-c4ccccc4)cc3)c2)c2ccccc2-c2ccccc21 ; CC1(c2cccc(N(c3ccc(-c4ccc5c(c4)-c4ccccc4C54c5ccccc5-c5ccccc54)cc3)c3ccccc3-c3ccc(-c4ccccc4)cc3)c2)c2ccccc2-c2ccccc21 ; CC1(c2cccc(N(c3ccccc3-c3ccc(-c4ccccc4)cc3)c3ccccc3-c3ccc4c(c3)C(c3ccccc3)(c3ccccc3)c3ccccc3-4)c2)c2ccccc2-c2ccccc21]

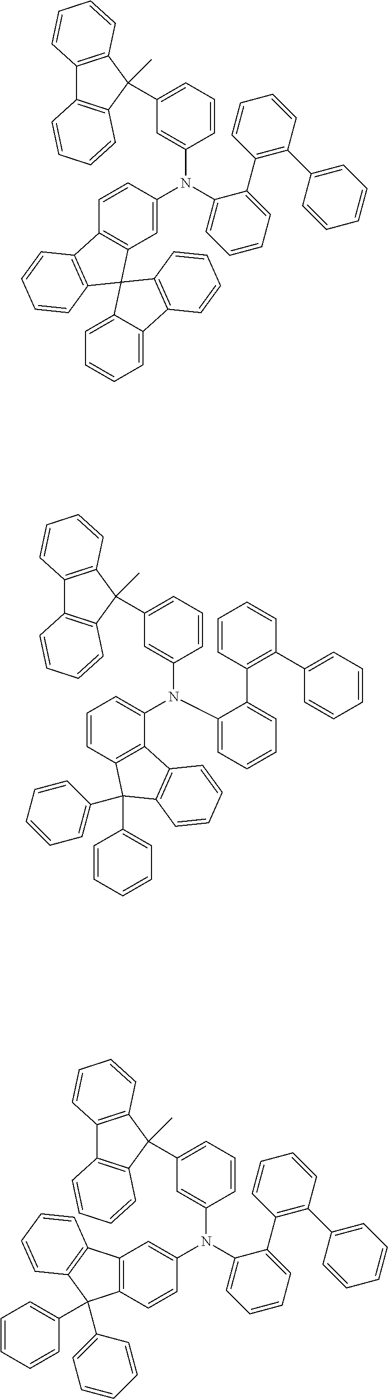 [SMILES: CC1(c2cccc(N(c3ccc4c(c3)C3(c5ccccc5-c5ccccc53)c3ccccc3-4)c3ccccc3-c3ccccc3-c3ccccc3)c2)c2ccccc2-c2ccccc21 ; CC1(c2cccc(N(c3ccccc3-c3ccccc3-c3ccccc3)c3cccc4c3-c3ccccc3C4(c3ccccc3)c3ccccc3)c2)c2ccccc2-c2ccccc21 ; CC1(c2cccc(N(c3ccc4c(c3)-c3ccccc3C4(c3ccccc3)c3ccccc3)c3ccccc3-c3ccccc3-c3ccccc3)c2)c2ccccc2-c2ccccc21]

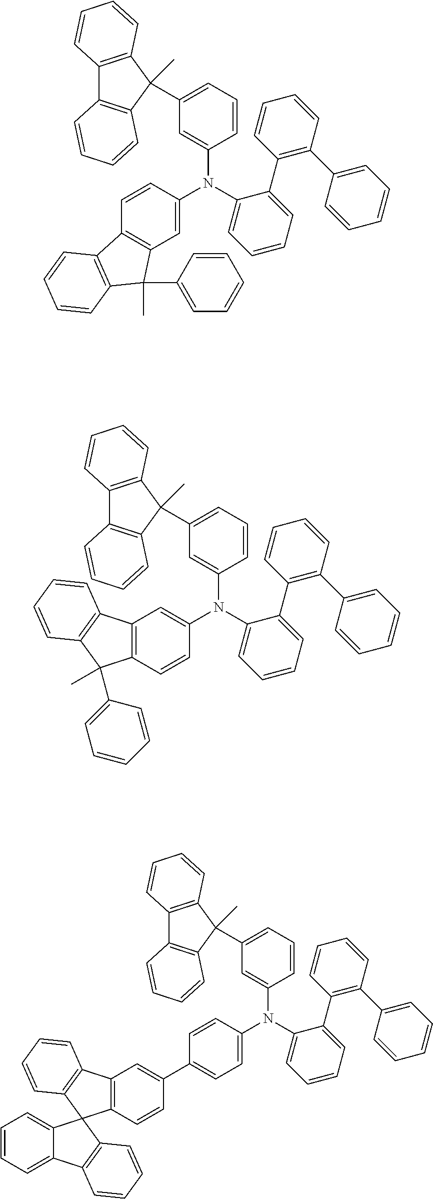 [SMILES: CC1(c2cccc(N(c3ccc4c(c3)C(C)(c3ccccc3)c3ccccc3-4)c3ccccc3-c3ccccc3-c3ccccc3)c2)c2ccccc2-c2ccccc21 ; CC1(c2cccc(N(c3ccc4c(c3)-c3ccccc3C4(C)c3ccccc3)c3ccccc3-c3ccccc3-c3ccccc3)c2)c2ccccc2-c2ccccc21 ; CC1(c2cccc(N(c3ccc(-c4ccc5c(c4)-c4ccccc4C54c5ccccc5-c5ccccc54)cc3)c3ccccc3-c3ccccc3-c3ccccc3)c2)c2ccccc2-c2ccccc21]

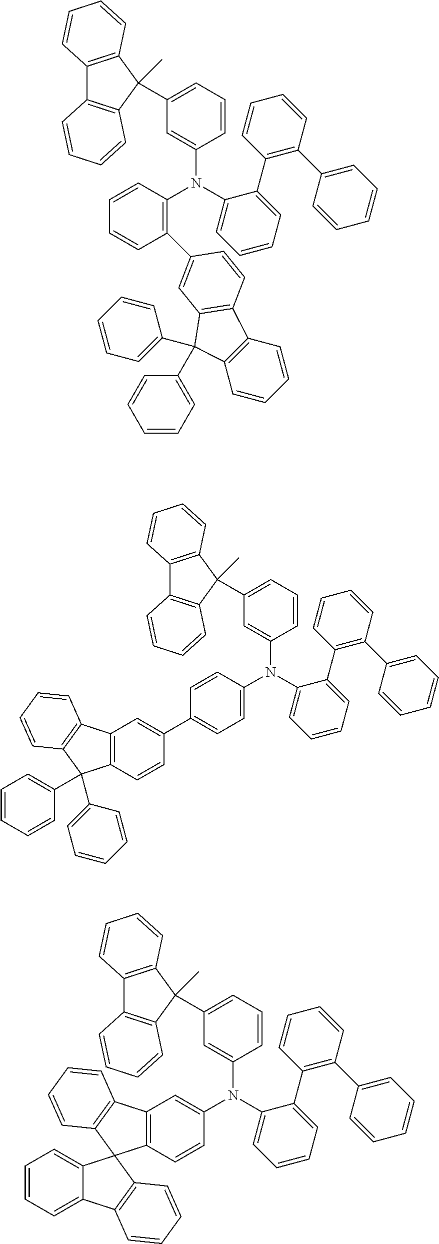 [SMILES: CC1(c2cccc(N(c3ccccc3-c3ccc4c(c3)C(c3ccccc3)(c3ccccc3)c3ccccc3-4)c3ccccc3-c3ccccc3-c3ccccc3)c2)c2ccccc2-c2ccccc21 ; CC1(c2cccc(N(c3ccc(-c4ccc5c(c4)-c4ccccc4C5(c4ccccc4)c4ccccc4)cc3)c3ccccc3-c3ccccc3-c3ccccc3)c2)c2ccccc2-c2ccccc21 ; CC1(c2cccc(N(c3ccc4c(c3)-c3ccccc3C43c4ccccc4-c4ccccc43)c3ccccc3-c3ccccc3-c3ccccc3)c2)c2ccccc2-c2ccccc21]

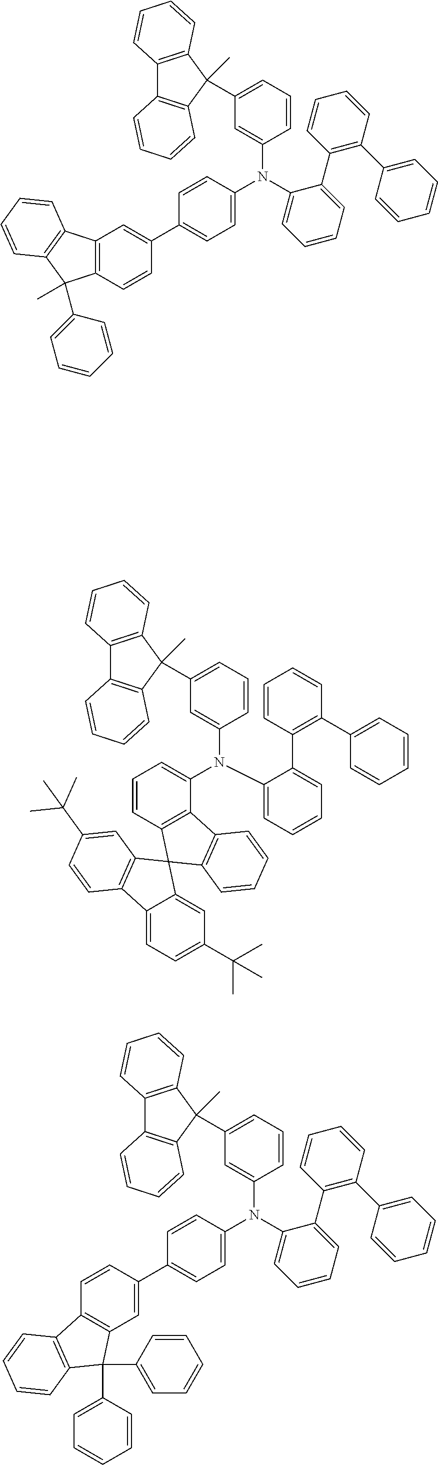 [SMILES: CC1(c2cccc(N(c3ccc(-c4ccc5c(c4)-c4ccccc4C5(C)c4ccccc4)cc3)c3ccccc3-c3ccccc3-c3ccccc3)c2)c2ccccc2-c2ccccc21 ; CC(C)(C)c1ccc2c(c1)C1(c3cc(C(C)(C)C)ccc3-2)c2ccccc2-c2c(N(c3cccc(C4(C)c5ccccc5-c5ccccc54)c3)c3ccccc3-c3ccccc3-c3ccccc3)cccc21 ; CC1(c2cccc(N(c3ccc(-c4ccc5c(c4)C(c4ccccc4)(c4ccccc4)c4ccccc4-5)cc3)c3ccccc3-c3ccccc3-c3ccccc3)c2)c2ccccc2-c2ccccc21]

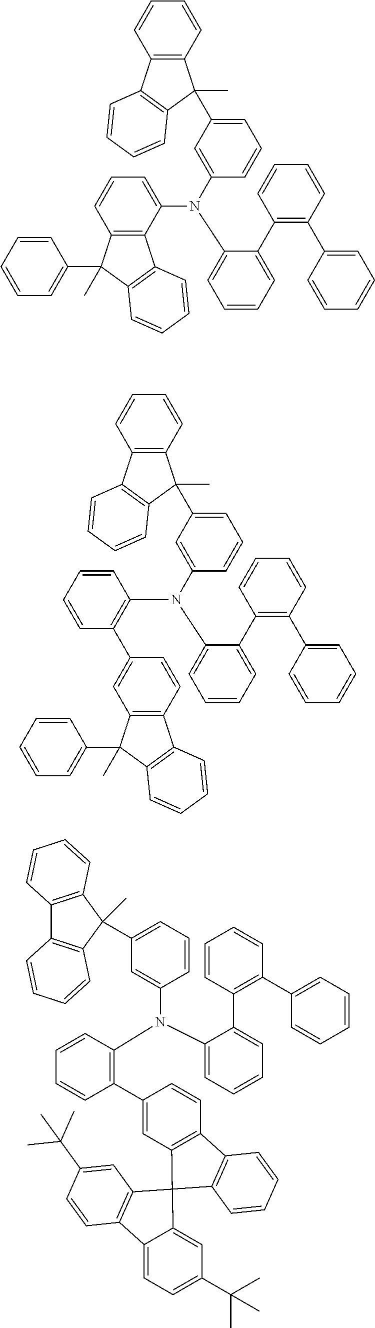 [SMILES: CC1(c2cccc(N(c3ccccc3-c3ccccc3-c3ccccc3)c3cccc4c3-c3ccccc3C4(C)c3ccccc3)c2)c2ccccc2-c2ccccc21 ; CC1(c2cccc(N(c3ccccc3-c3ccc4c(c3)C(C)(c3ccccc3)c3ccccc3-4)c3ccccc3-c3ccccc3-c3ccccc3)c2)c2ccccc2-c2ccccc21 ; CC(C)(C)c1ccc2c(c1)C1(c3ccccc3-c3ccc(-c4ccccc4N(c4cccc(C5(C)c6ccccc6-c6ccccc65)c4)c4ccccc4-c4ccccc4-c4ccccc4)cc31)c1cc(C(C)(C)C)ccc1-2]

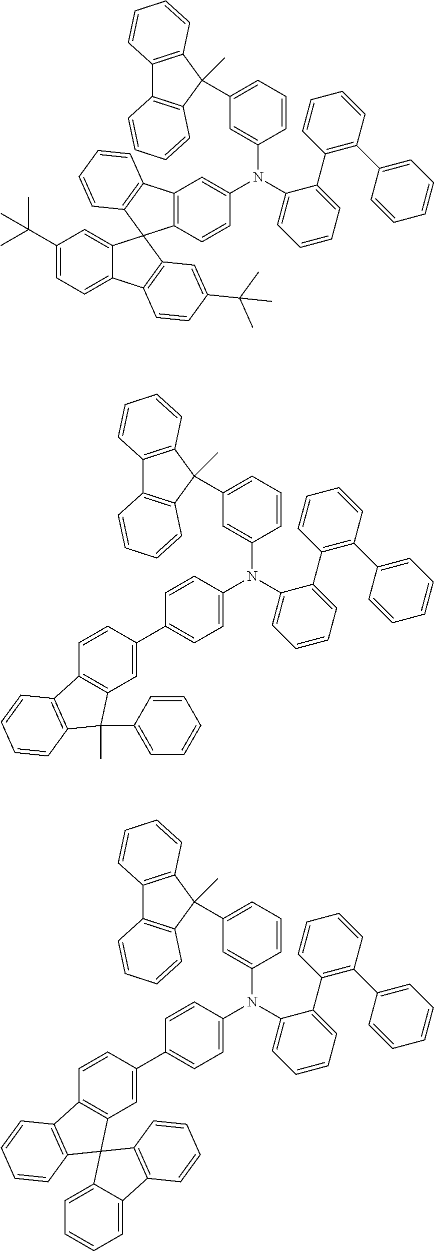 [SMILES: CC(C)(C)c1ccc2c(c1)C1(c3ccccc3-c3cc(N(c4cccc(C5(C)c6ccccc6-c6ccccc65)c4)c4ccccc4-c4ccccc4-c4ccccc4)ccc31)c1cc(C(C)(C)C)ccc1-2 ; CC1(c2cccc(N(c3ccc(-c4ccc5c(c4)C(C)(c4ccccc4)c4ccccc4-5)cc3)c3ccccc3-c3ccccc3-c3ccccc3)c2)c2ccccc2-c2ccccc21 ; CC1(c2cccc(N(c3ccc(-c4ccc5c(c4)C4(c6ccccc6-c6ccccc64)c4ccccc4-5)cc3)c3ccccc3-c3ccccc3-c3ccccc3)c2)c2ccccc2-c2ccccc21]

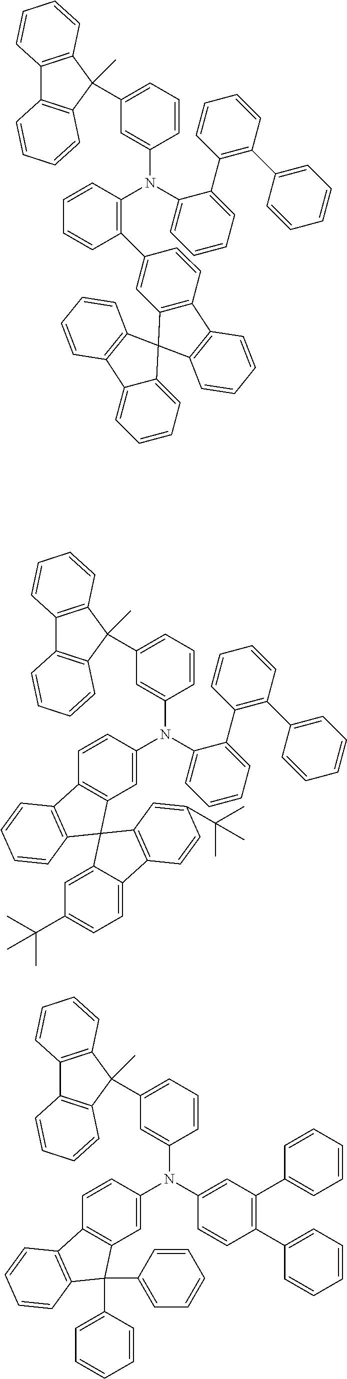

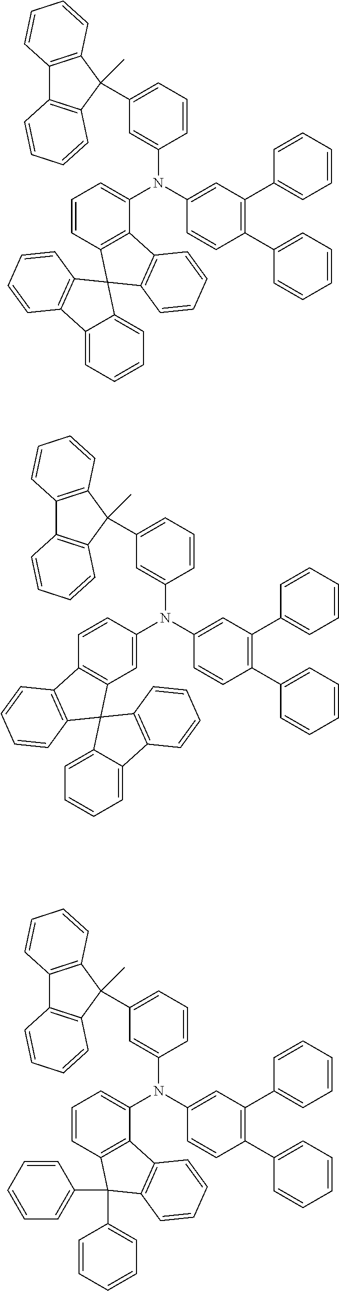 [SMILES: CC1(c2cccc(N(c3ccc(-c4ccccc4)c(-c4ccccc4)c3)c3cccc4c3-c3ccccc3C43c4ccccc4-c4ccccc43)c2)c2ccccc2-c2ccccc21 ; CC1(c2cccc(N(c3ccc(-c4ccccc4)c(-c4ccccc4)c3)c3ccc4c(c3)C3(c5ccccc5-c5ccccc53)c3ccccc3-4)c2)c2ccccc2-c2ccccc21 ; CC1(c2cccc(N(c3ccc(-c4ccccc4)c(-c4ccccc4)c3)c3cccc4c3-c3ccccc3C4(c3ccccc3)c3ccccc3)c2)c2ccccc2-c2ccccc21]

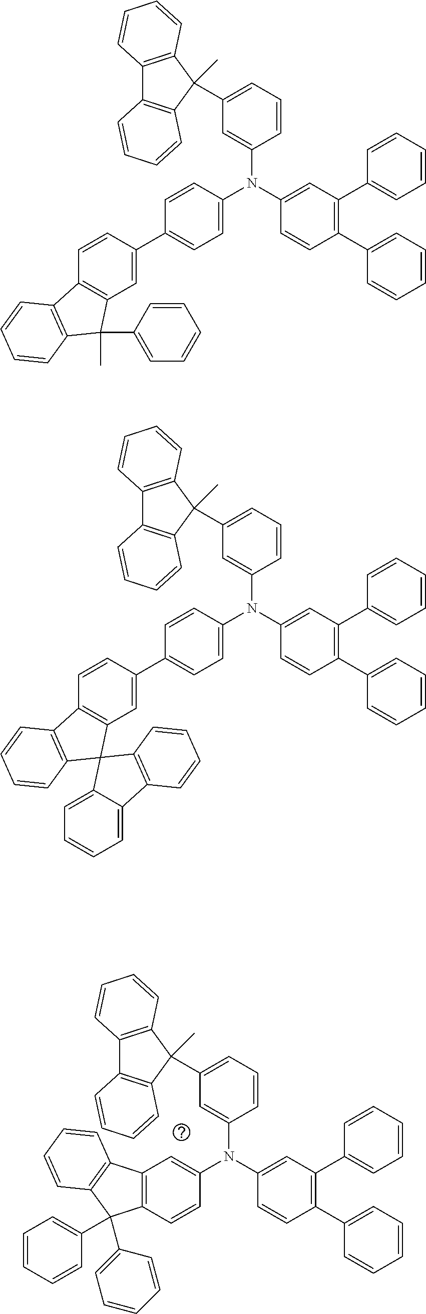 [SMILES: CC1(c2cccc(N(c3ccc(-c4ccc5c(c4)C(C)(c4ccccc4)c4ccccc4-5)cc3)c3ccc(-c4ccccc4)c(-c4ccccc4)c3)c2)c2ccccc2-c2ccccc21 ; CC1(c2cccc(N(c3ccc(-c4ccc5c(c4)C4(c6ccccc6-c6ccccc64)c4ccccc4-5)cc3)c3ccc(-c4ccccc4)c(-c4ccccc4)c3)c2)c2ccccc2-c2ccccc21 ; CC1(c2cccc(N(c3ccc(-c4ccccc4)c(-c4ccccc4)c3)c3ccc4c(c3)-c3ccccc3C4(c3ccccc3)c3ccccc3)c2)c2ccccc2-c2ccccc21]

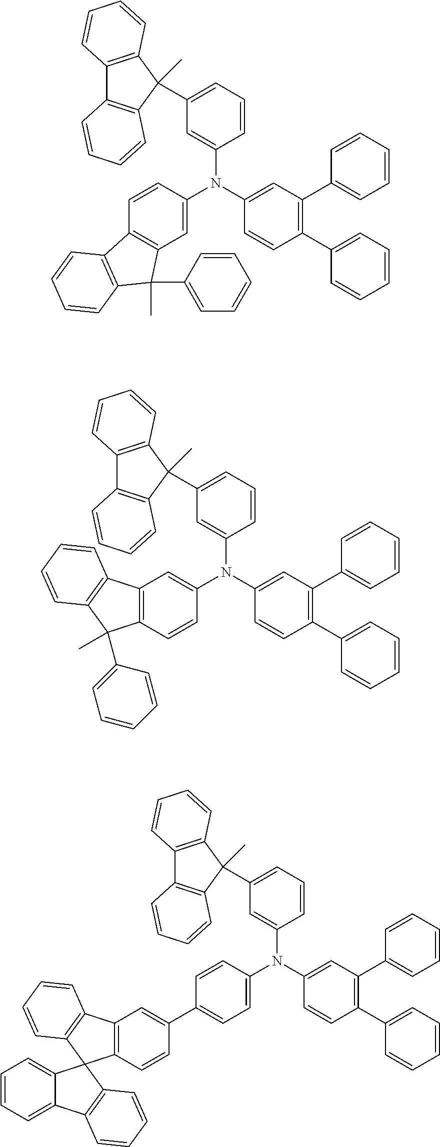 [SMILES: CC1(c2cccc(N(c3ccc(-c4ccccc4)c(-c4ccccc4)c3)c3ccc4c(c3)C(C)(c3ccccc3)c3ccccc3-4)c2)c2ccccc2-c2ccccc21 ; CC1(c2cccc(N(c3ccc(-c4ccccc4)c(-c4ccccc4)c3)c3ccc4c(c3)-c3ccccc3C4(C)c3ccccc3)c2)c2ccccc2-c2ccccc21 ; CC1(c2cccc(N(c3ccc(-c4ccc5c(c4)-c4ccccc4C54c5ccccc5-c5ccccc54)cc3)c3ccc(-c4ccccc4)c(-c4ccccc4)c3)c2)c2ccccc2-c2ccccc21]

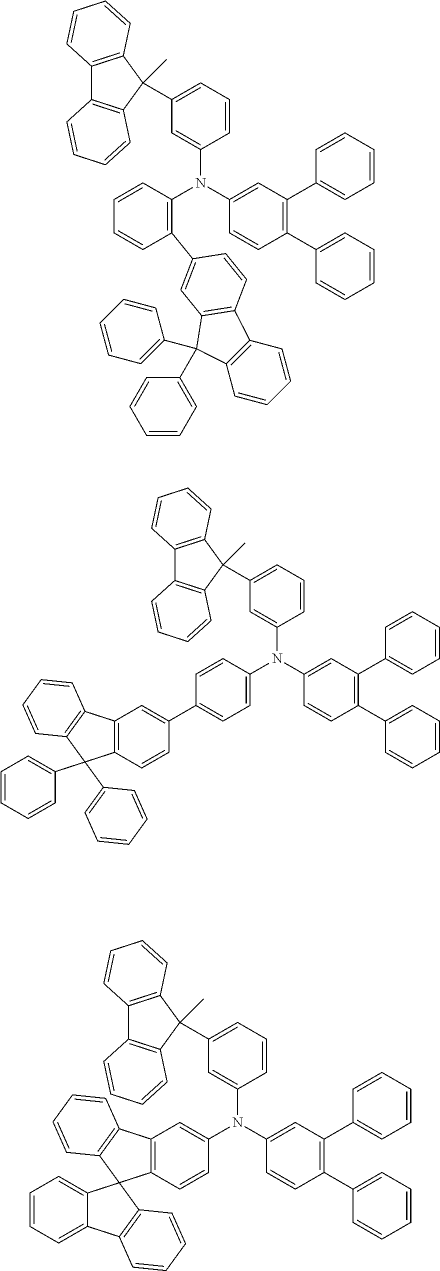 [SMILES: CC1(c2cccc(N(c3ccc(-c4ccccc4)c(-c4ccccc4)c3)c3ccccc3-c3ccc4c(c3)C(c3ccccc3)(c3ccccc3)c3ccccc3-4)c2)c2ccccc2-c2ccccc21 ; CC1(c2cccc(N(c3ccc(-c4ccc5c(c4)-c4ccccc4C5(c4ccccc4)c4ccccc4)cc3)c3ccc(-c4ccccc4)c(-c4ccccc4)c3)c2)c2ccccc2-c2ccccc21 ; CC1(c2cccc(N(c3ccc(-c4ccccc4)c(-c4ccccc4)c3)c3ccc4c(c3)-c3ccccc3C43c4ccccc4-c4ccccc43)c2)c2ccccc2-c2ccccc21]

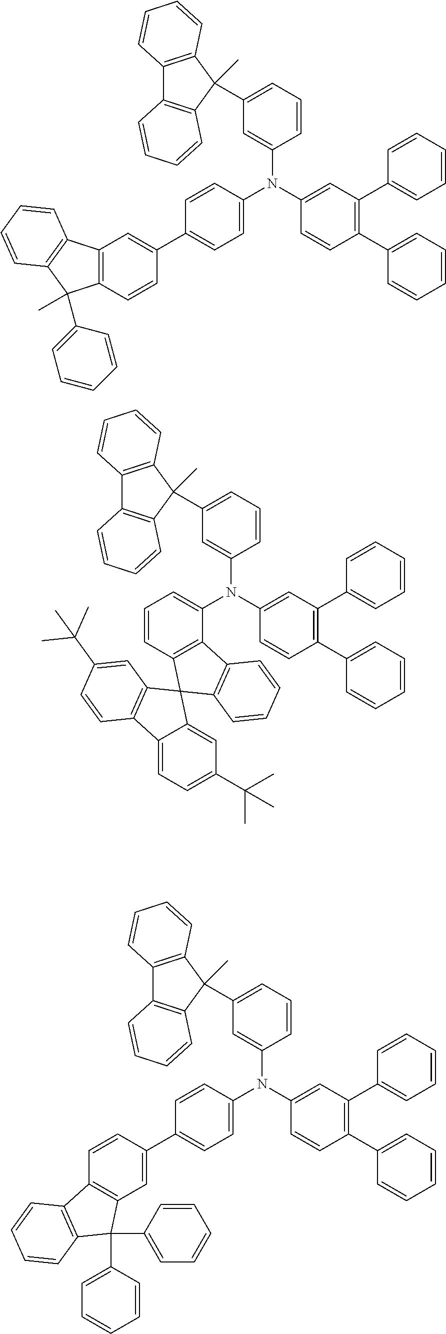

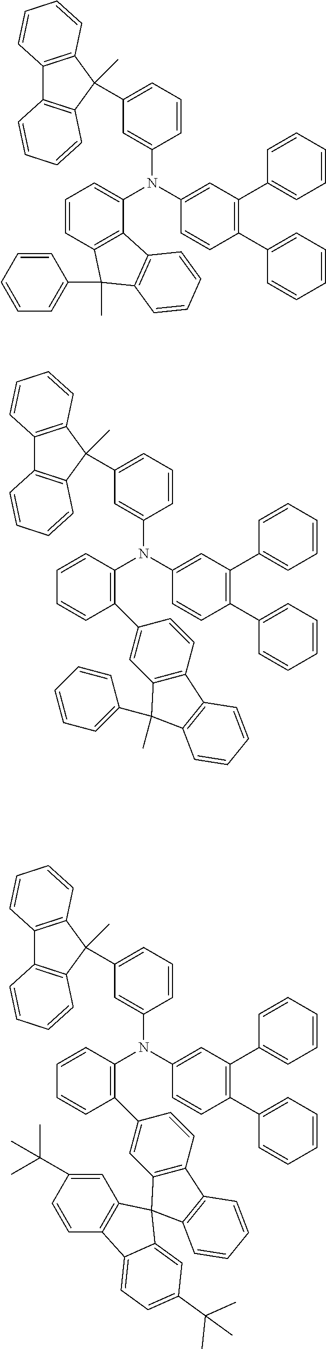 [SMILES: CC1(c2cccc(N(c3ccc(-c4ccccc4)c(-c4ccccc4)c3)c3cccc4c3-c3ccccc3C4(C)c3ccccc3)c2)c2ccccc2-c2ccccc21 ; CC1(c2cccc(N(c3ccc(-c4ccccc4)c(-c4ccccc4)c3)c3ccccc3-c3ccc4c(c3)C(C)(c3ccccc3)c3ccccc3-4)c2)c2ccccc2-c2ccccc21 ; CC(C)(C)c1ccc2c(c1)C1(c3ccccc3-c3ccc(-c4ccccc4N(c4cccc(C5(C)c6ccccc6-c6ccccc65)c4)c4ccc(-c5ccccc5)c(-c5ccccc5)c4)cc31)c1cc(C(C)(C)C)ccc1-2]

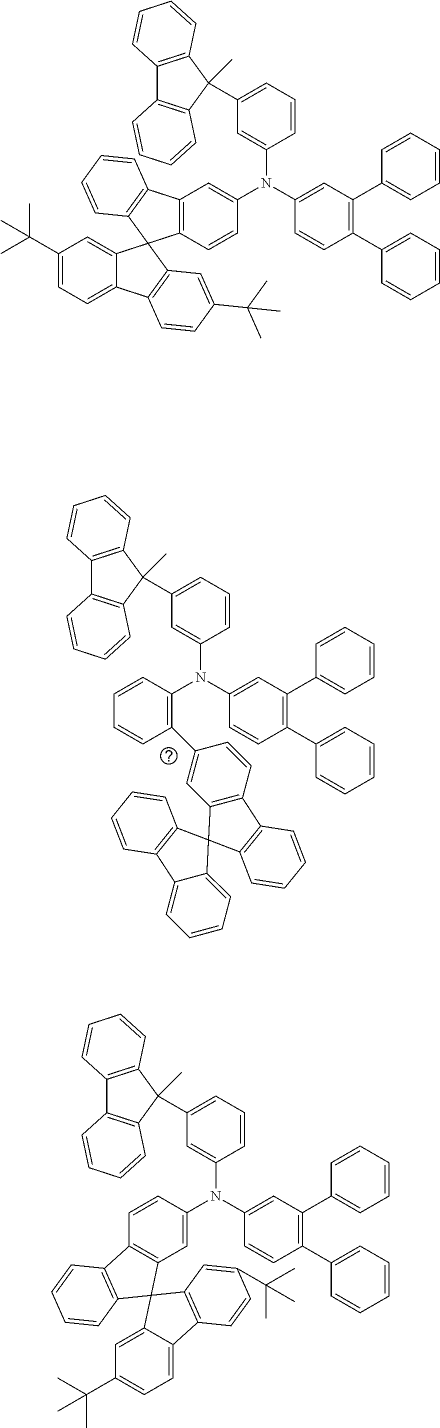 [SMILES: CC(C)(C)c1ccc2c(c1)C1(c3ccccc3-c3cc(N(c4cccc(C5(C)c6ccccc6-c6ccccc65)c4)c4ccc(-c5ccccc5)c(-c5ccccc5)c4)ccc31)c1cc(C(C)(C)C)ccc1-2 ; CC1(c2cccc(N(c3ccc(-c4ccccc4)c(-c4ccccc4)c3)c3ccccc3-c3ccc4c(c3)C3(c5ccccc5-c5ccccc53)c3ccccc3-4)c2)c2ccccc2-c2ccccc21 ; CC(C)(C)c1ccc2c(c1)C1(c3ccccc3-c3ccc(N(c4cccc(C5(C)c6ccccc6-c6ccccc65)c4)c4ccc(-c5ccccc5)c(-c5ccccc5)c4)cc31)c1cc(C(C)(C)C)ccc1-2]

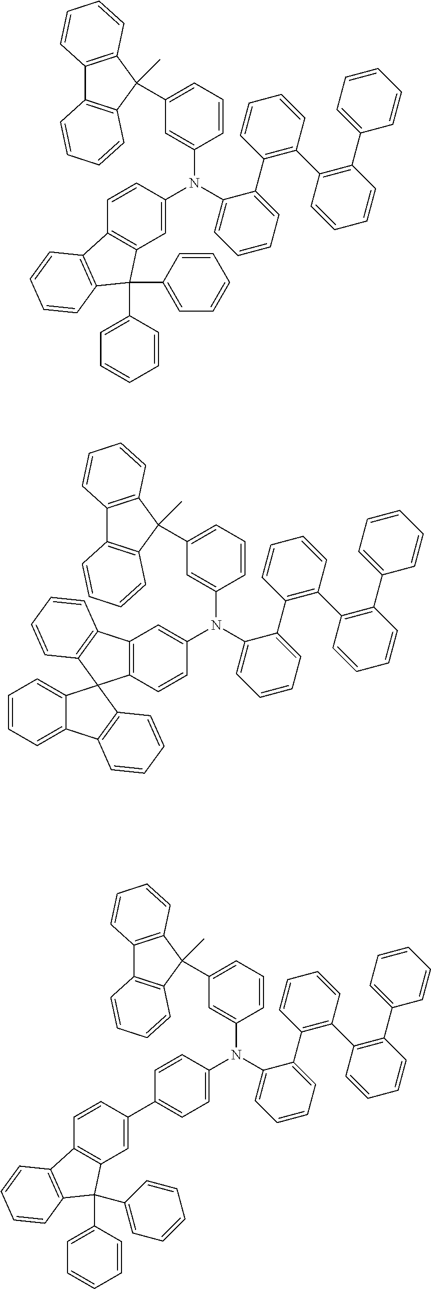 [SMILES: CC1(c2cccc(N(c3ccc4c(c3)C(c3ccccc3)(c3ccccc3)c3ccccc3-4)c3ccccc3-c3ccccc3-c3ccccc3-c3ccccc3)c2)c2ccccc2-c2ccccc21 ; CC1(c2cccc(N(c3ccc4c(c3)-c3ccccc3C43c4ccccc4-c4ccccc43)c3ccccc3-c3ccccc3-c3ccccc3-c3ccccc3)c2)c2ccccc2-c2ccccc21 ; CC1(c2cccc(N(c3ccc(-c4ccc5c(c4)C(c4ccccc4)(c4ccccc4)c4ccccc4-5)cc3)c3ccccc3-c3ccccc3-c3ccccc3-c3ccccc3)c2)c2ccccc2-c2ccccc21]

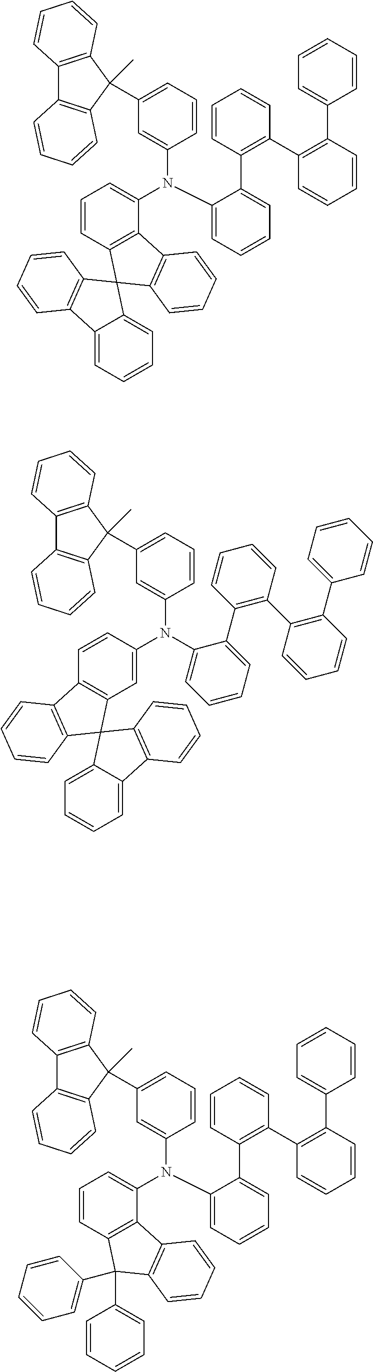 [SMILES: CC1(c2cccc(N(c3ccccc3-c3ccccc3-c3ccccc3-c3ccccc3)c3cccc4c3-c3ccccc3C43c4ccccc4-c4ccccc43)c2)c2ccccc2-c2ccccc21 ; CC1(c2cccc(N(c3ccc4c(c3)C3(c5ccccc5-c5ccccc53)c3ccccc3-4)c3ccccc3-c3ccccc3-c3ccccc3-c3ccccc3)c2)c2ccccc2-c2ccccc21 ; CC1(c2cccc(N(c3ccccc3-c3ccccc3-c3ccccc3-c3ccccc3)c3cccc4c3-c3ccccc3C4(c3ccccc3)c3ccccc3)c2)c2ccccc2-c2ccccc21]

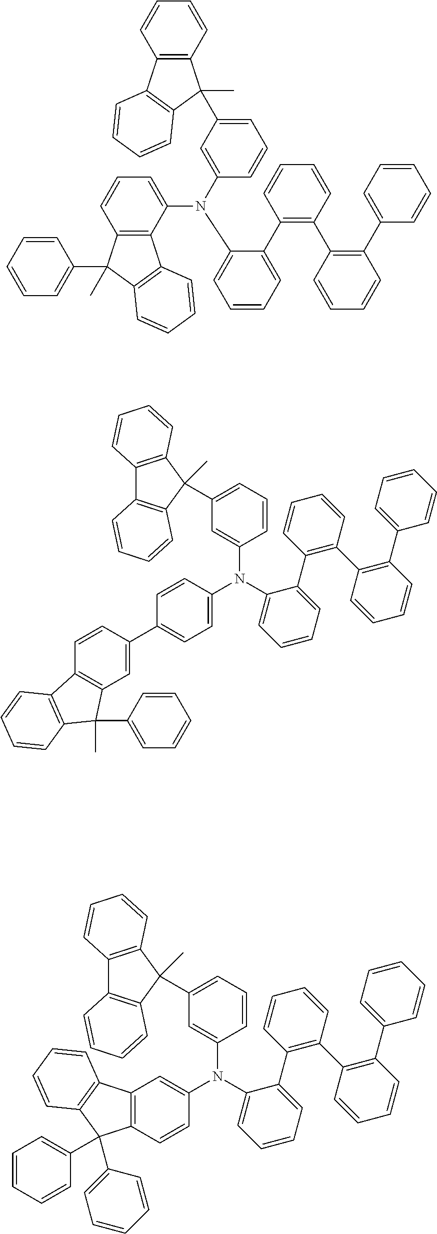 [SMILES: CC1(c2cccc(N(c3ccccc3-c3ccccc3-c3ccccc3-c3ccccc3)c3cccc4c3-c3ccccc3C4(C)c3ccccc3)c2)c2ccccc2-c2ccccc21 ; CC1(c2cccc(N(c3ccc(-c4ccc5c(c4)C(C)(c4ccccc4)c4ccccc4-5)cc3)c3ccccc3-c3ccccc3-c3ccccc3-c3ccccc3)c2)c2ccccc2-c2ccccc21 ; CC1(c2cccc(N(c3ccc4c(c3)-c3ccccc3C4(c3ccccc3)c3ccccc3)c3ccccc3-c3ccccc3-c3ccccc3-c3ccccc3)c2)c2ccccc2-c2ccccc21]

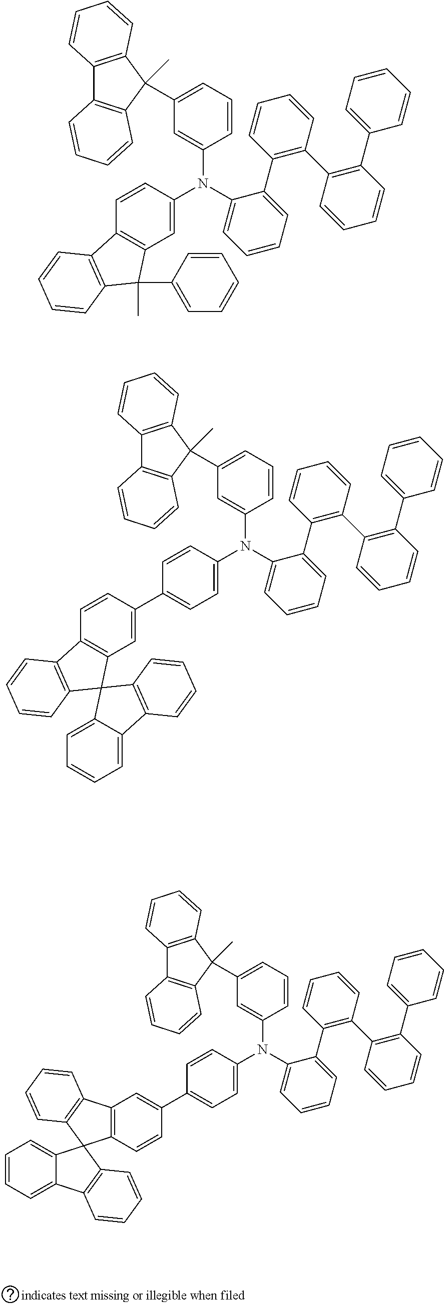 [SMILES: CC1(c2cccc(N(c3ccc4c(c3)C(C)(c3ccccc3)c3ccccc3-4)c3ccccc3-c3ccccc3-c3ccccc3-c3ccccc3)c2)c2ccccc2-c2ccccc21 ; CC1(c2cccc(N(c3ccc(-c4ccc5c(c4)C4(c6ccccc6-c6ccccc64)c4ccccc4-5)cc3)c3ccccc3-c3ccccc3-c3ccccc3-c3ccccc3)c2)c2ccccc2-c2ccccc21 ; CC1(c2cccc(N(c3ccc(-c4ccc5c(c4)-c4ccccc4C54c5ccccc5-c5ccccc54)cc3)c3ccccc3-c3ccccc3-c3ccccc3-c3ccccc3)c2)c2ccccc2-c2ccccc21]

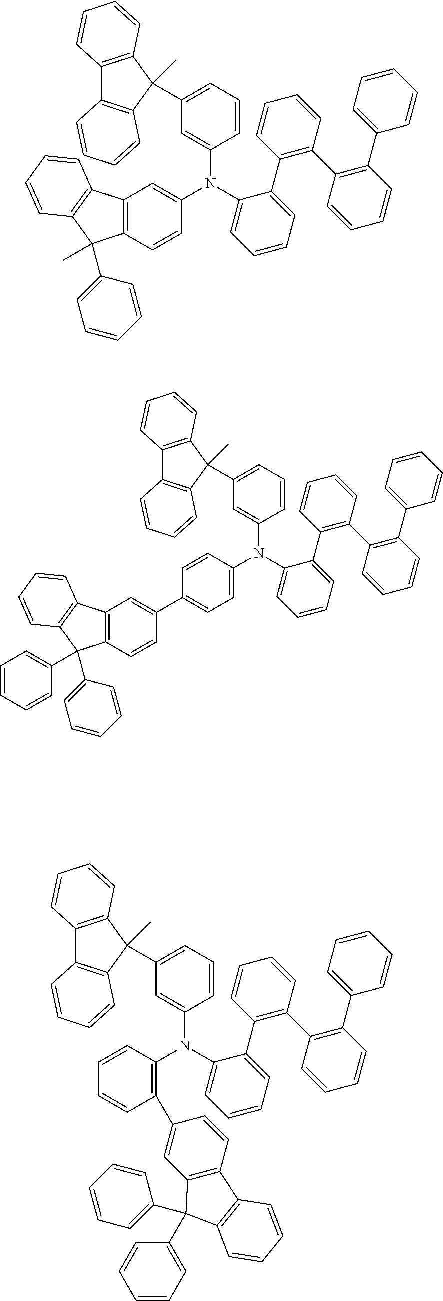 [SMILES: CC1(c2cccc(N(c3ccc4c(c3)-c3ccccc3C4(C)c3ccccc3)c3ccccc3-c3ccccc3-c3ccccc3-c3ccccc3)c2)c2ccccc2-c2ccccc21 ; CC1(c2cccc(N(c3ccc(-c4ccc5c(c4)-c4ccccc4C5(c4ccccc4)c4ccccc4)cc3)c3ccccc3-c3ccccc3-c3ccccc3-c3ccccc3)c2)c2ccccc2-c2ccccc21 ; CC1(c2cccc(N(c3ccccc3-c3ccc4c(c3)C(c3ccccc3)(c3ccccc3)c3ccccc3-4)c3ccccc3-c3ccccc3-c3ccccc3-c3ccccc3)c2)c2ccccc2-c2ccccc21]

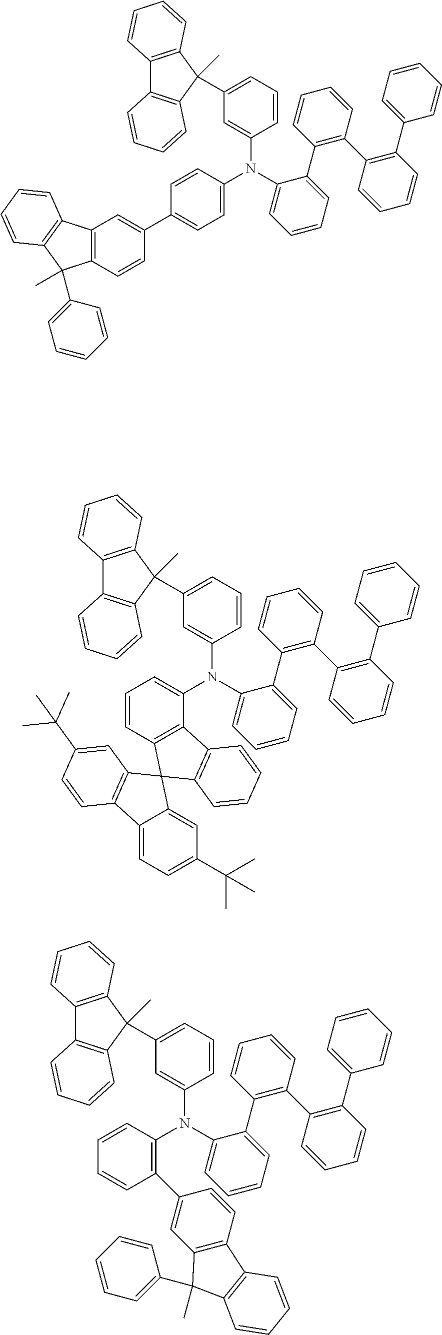 [SMILES: CC1(c2cccc(N(c3ccc(-c4ccc5c(c4)-c4ccccc4C5(C)c4ccccc4)cc3)c3ccccc3-c3ccccc3-c3ccccc3-c3ccccc3)c2)c2ccccc2-c2ccccc21 ; CC(C)(C)c1ccc2c(c1)C1(c3cc(C(C)(C)C)ccc3-2)c2ccccc2-c2c(N(c3cccc(C4(C)c5ccccc5-c5ccccc54)c3)c3ccccc3-c3ccccc3-c3ccccc3-c3ccccc3)cccc21 ; CC1(c2cccc(N(c3ccccc3-c3ccc4c(c3)C(C)(c3ccccc3)c3ccccc3-4)c3ccccc3-c3ccccc3-c3ccccc3-c3ccccc3)c2)c2ccccc2-c2ccccc21]

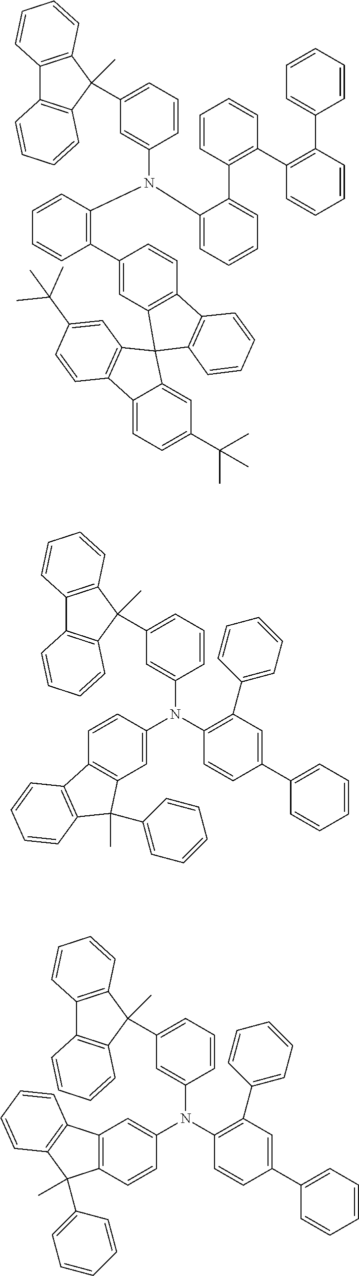 [SMILES: CC(C)(C)c1ccc2c(c1)C1(c3ccccc3-c3ccc(-c4ccccc4N(c4cccc(C5(C)c6ccccc6-c6ccccc65)c4)c4ccccc4-c4ccccc4-c4ccccc4-c4ccccc4)cc31)c1cc(C(C)(C)C)ccc1-2 ; CC1(c2cccc(N(c3ccc4c(c3)C(C)(c3ccccc3)c3ccccc3-4)c3ccc(-c4ccccc4)cc3-c3ccccc3)c2)c2ccccc2-c2ccccc21 ; CC1(c2cccc(N(c3ccc4c(c3)-c3ccccc3C4(C)c3ccccc3)c3ccc(-c4ccccc4)cc3-c3ccccc3)c2)c2ccccc2-c2ccccc21]

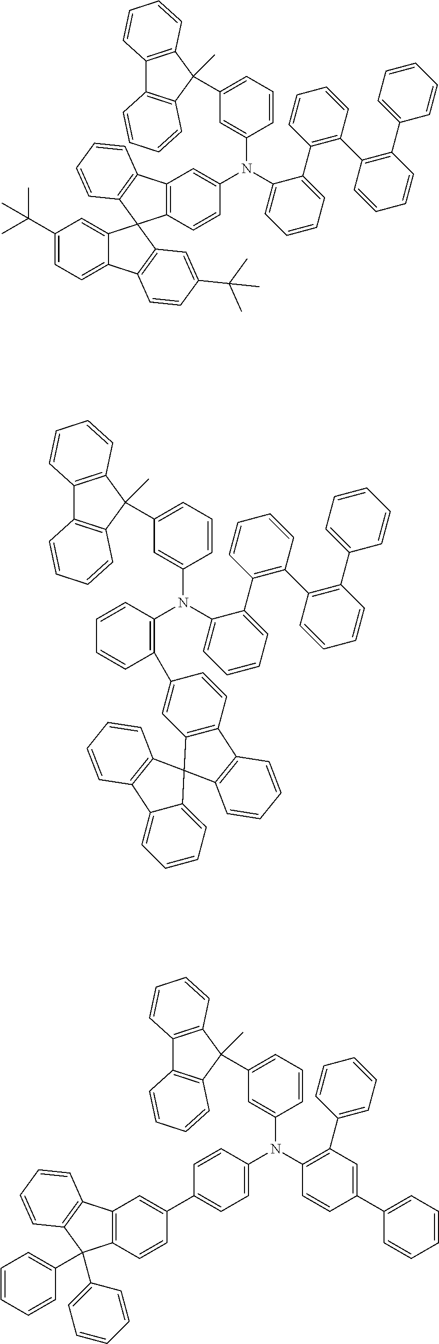 [SMILES: CC(C)(C)c1ccc2c(c1)C1(c3ccccc3-c3cc(N(c4cccc(C5(C)c6ccccc6-c6ccccc65)c4)c4ccccc4-c4ccccc4-c4ccccc4-c4ccccc4)ccc31)c1cc(C(C)(C)C)ccc1-2 ; CC1(c2cccc(N(c3ccccc3-c3ccc4c(c3)C3(c5ccccc5-c5ccccc53)c3ccccc3-4)c3ccccc3-c3ccccc3-c3ccccc3-c3ccccc3)c2)c2ccccc2-c2ccccc21 ; CC1(c2cccc(N(c3ccc(-c4ccc5c(c4)-c4ccccc4C5(c4ccccc4)c4ccccc4)cc3)c3ccc(-c4ccccc4)cc3-c3ccccc3)c2)c2ccccc2-c2ccccc21]

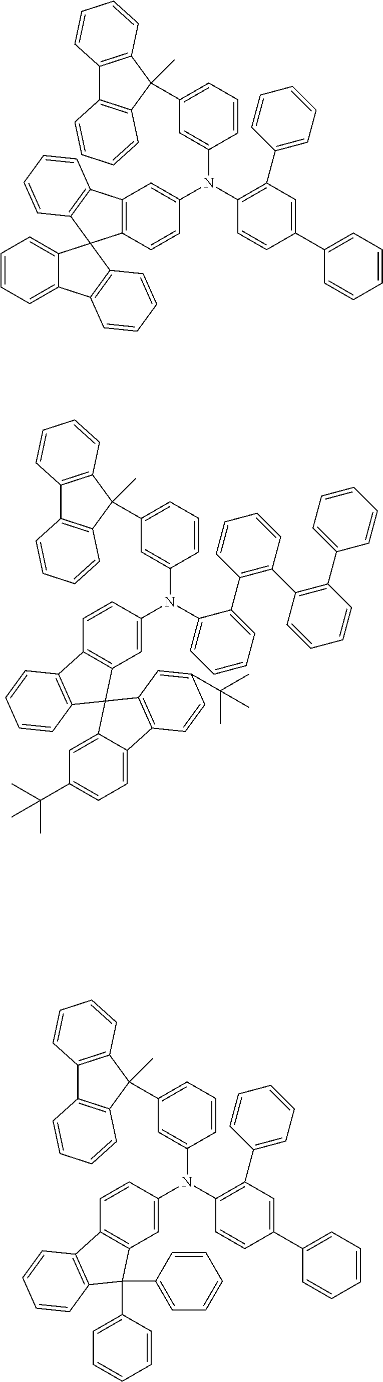 [SMILES: CC1(c2cccc(N(c3ccc4c(c3)-c3ccccc3C43c4ccccc4-c4ccccc43)c3ccc(-c4ccccc4)cc3-c3ccccc3)c2)c2ccccc2-c2ccccc21 ; CC(C)(C)c1ccc2c(c1)C1(c3ccccc3-c3ccc(N(c4cccc(C5(C)c6ccccc6-c6ccccc65)c4)c4ccccc4-c4ccccc4-c4ccccc4-c4ccccc4)cc31)c1cc(C(C)(C)C)ccc1-2 ; CC1(c2cccc(N(c3ccc4c(c3)C(c3ccccc3)(c3ccccc3)c3ccccc3-4)c3ccc(-c4ccccc4)cc3-c3ccccc3)c2)c2ccccc2-c2ccccc21]

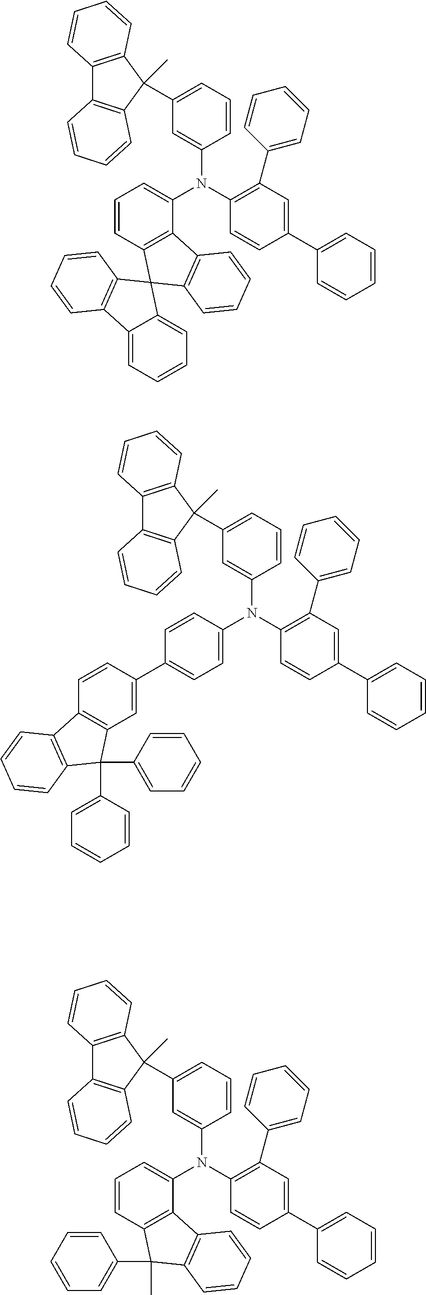 [SMILES: CC1(c2cccc(N(c3ccc(-c4ccccc4)cc3-c3ccccc3)c3cccc4c3-c3ccccc3C43c4ccccc4-c4ccccc43)c2)c2ccccc2-c2ccccc21 ; CC1(c2cccc(N(c3ccc(-c4ccc5c(c4)C(c4ccccc4)(c4ccccc4)c4ccccc4-5)cc3)c3ccc(-c4ccccc4)cc3-c3ccccc3)c2)c2ccccc2-c2ccccc21 ; CC1(c2cccc(N(c3ccc(-c4ccccc4)cc3-c3ccccc3)c3cccc4c3-c3ccccc3C4(C)c3ccccc3)c2)c2ccccc2-c2ccccc21]

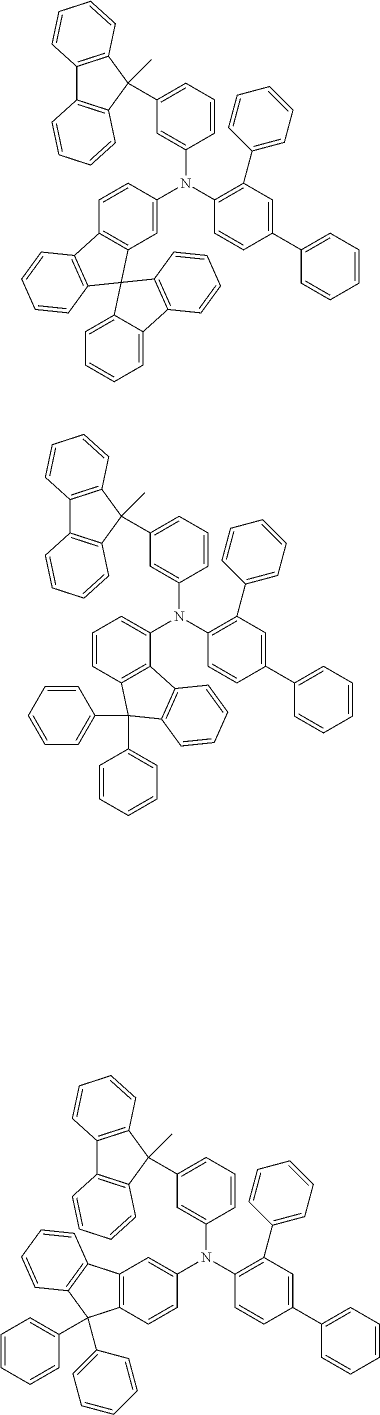 [SMILES: CC1(c2cccc(N(c3ccc4c(c3)C3(c5ccccc5-c5ccccc53)c3ccccc3-4)c3ccc(-c4ccccc4)cc3-c3ccccc3)c2)c2ccccc2-c2ccccc21 ; CC1(c2cccc(N(c3ccc(-c4ccccc4)cc3-c3ccccc3)c3cccc4c3-c3ccccc3C4(c3ccccc3)c3ccccc3)c2)c2ccccc2-c2ccccc21 ; CC1(c2cccc(N(c3ccc4c(c3)-c3ccccc3C4(c3ccccc3)c3ccccc3)c3ccc(-c4ccccc4)cc3-c3ccccc3)c2)c2ccccc2-c2ccccc21]

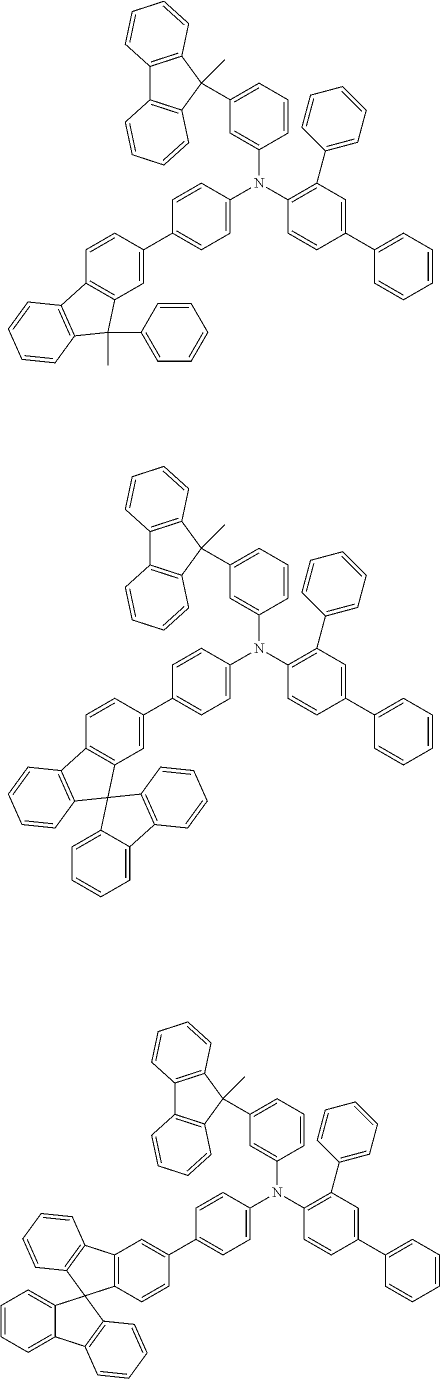 [SMILES: CC1(c2cccc(N(c3ccc(-c4ccc5c(c4)C(C)(c4ccccc4)c4ccccc4-5)cc3)c3ccc(-c4ccccc4)cc3-c3ccccc3)c2)c2ccccc2-c2ccccc21 ; CC1(c2cccc(N(c3ccc(-c4ccc5c(c4)C4(c6ccccc6-c6ccccc64)c4ccccc4-5)cc3)c3ccc(-c4ccccc4)cc3-c3ccccc3)c2)c2ccccc2-c2ccccc21 ; CC1(c2cccc(N(c3ccc(-c4ccc5c(c4)-c4ccccc4C54c5ccccc5-c5ccccc54)cc3)c3ccc(-c4ccccc4)cc3-c3ccccc3)c2)c2ccccc2-c2ccccc21]

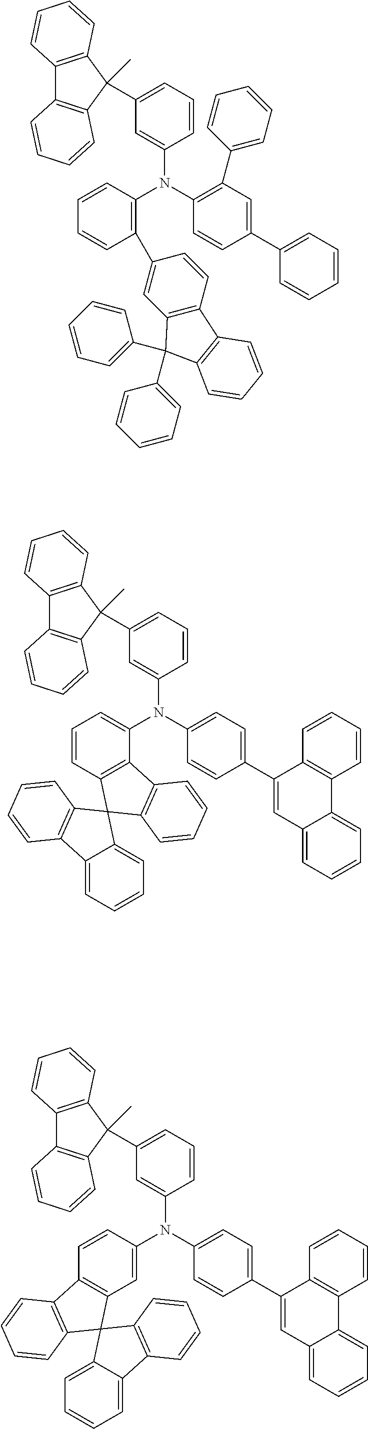 [SMILES: CC1(c2cccc(N(c3ccccc3-c3ccc4c(c3)C(c3ccccc3)(c3ccccc3)c3ccccc3-4)c3ccc(-c4ccccc4)cc3-c3ccccc3)c2)c2ccccc2-c2ccccc21 ; CC1(c2cccc(N(c3ccc(-c4cc5ccccc5c5ccccc45)cc3)c3cccc4c3-c3ccccc3C43c4ccccc4-c4ccccc43)c2)c2ccccc2-c2ccccc21 ; CC1(c2cccc(N(c3ccc(-c4cc5ccccc5c5ccccc45)cc3)c3ccc4c(c3)C3(c5ccccc5-c5ccccc53)c3ccccc3-4)c2)c2ccccc2-c2ccccc21]

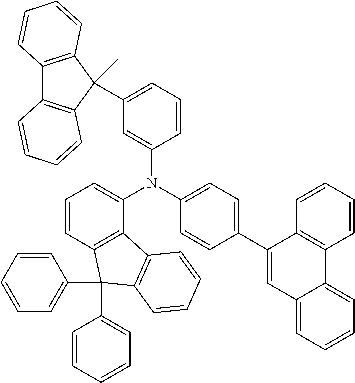 [SMILES: CC1(c2cccc(N(c3ccc(-c4cc5ccccc5c5ccccc45)cc3)c3cccc4c3-c3ccccc3C4(c3ccccc3)c3ccccc3)c2)c2ccccc2-c2ccccc21]

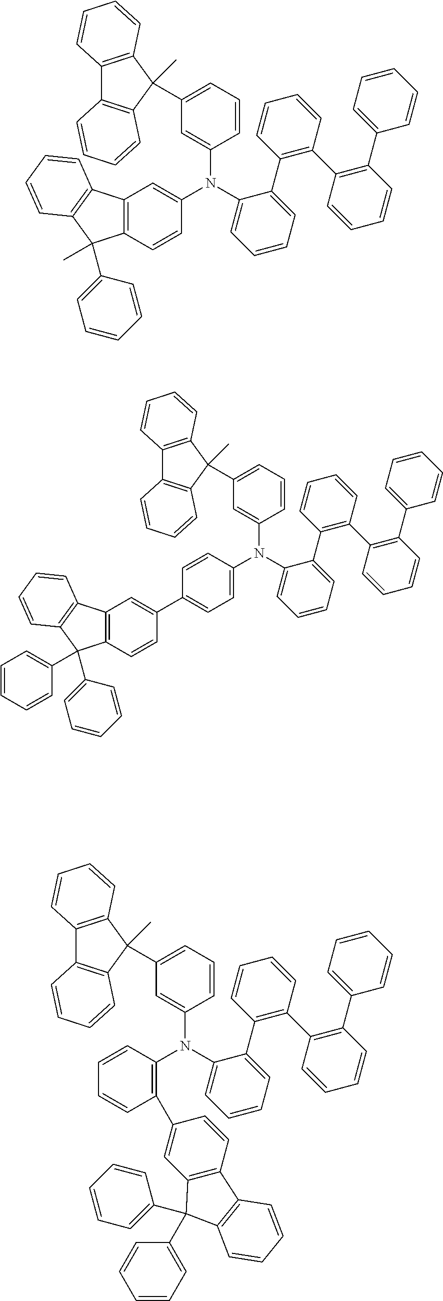 [SMILES: CC1(c2cccc(N(c3ccc4c(c3)-c3ccccc3C4(C)c3ccccc3)c3ccccc3-c3ccccc3-c3ccccc3-c3ccccc3)c2)c2ccccc2-c2ccccc21 ; CC1(c2cccc(N(c3ccc(-c4ccc5c(c4)-c4ccccc4C5(c4ccccc4)c4ccccc4)cc3)c3ccccc3-c3ccccc3-c3ccccc3-c3ccccc3)c2)c2ccccc2-c2ccccc21 ; CC1(c2cccc(N(c3ccccc3-c3ccc4c(c3)C(c3ccccc3)(c3ccccc3)c3ccccc3-4)c3ccccc3-c3ccccc3-c3ccccc3-c3ccccc3)c2)c2ccccc2-c2ccccc21]

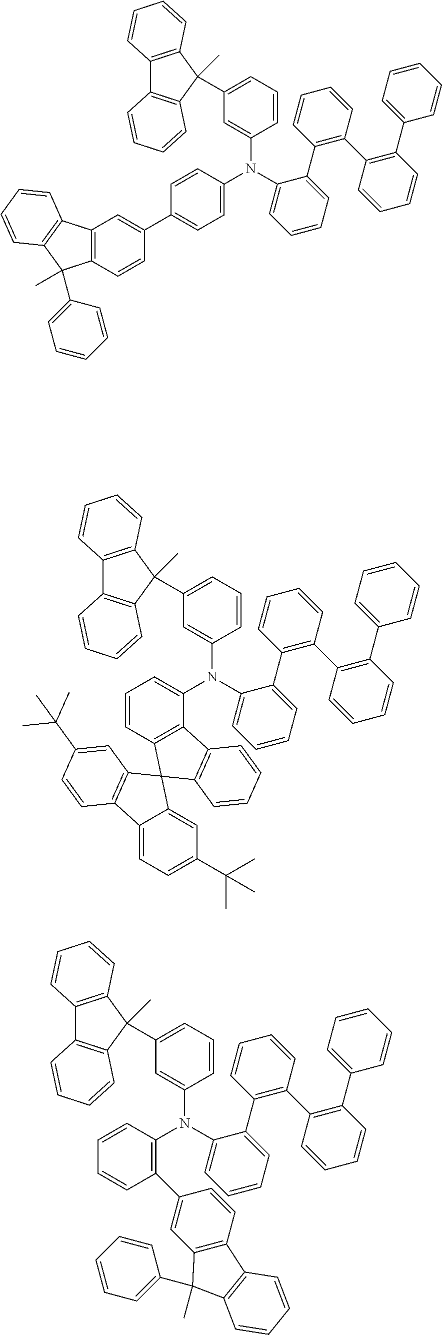 [SMILES: CC1(c2cccc(N(c3ccc(-c4ccc5c(c4)-c4ccccc4C5(C)c4ccccc4)cc3)c3ccccc3-c3ccccc3-c3ccccc3-c3ccccc3)c2)c2ccccc2-c2ccccc21 ; CC(C)(C)c1ccc2c(c1)C1(c3cc(C(C)(C)C)ccc3-2)c2ccccc2-c2c(N(c3cccc(C4(C)c5ccccc5-c5ccccc54)c3)c3ccccc3-c3ccccc3-c3ccccc3-c3ccccc3)cccc21 ; CC1(c2cccc(N(c3ccccc3-c3ccc4c(c3)C(C)(c3ccccc3)c3ccccc3-4)c3ccccc3-c3ccccc3-c3ccccc3-c3ccccc3)c2)c2ccccc2-c2ccccc21]

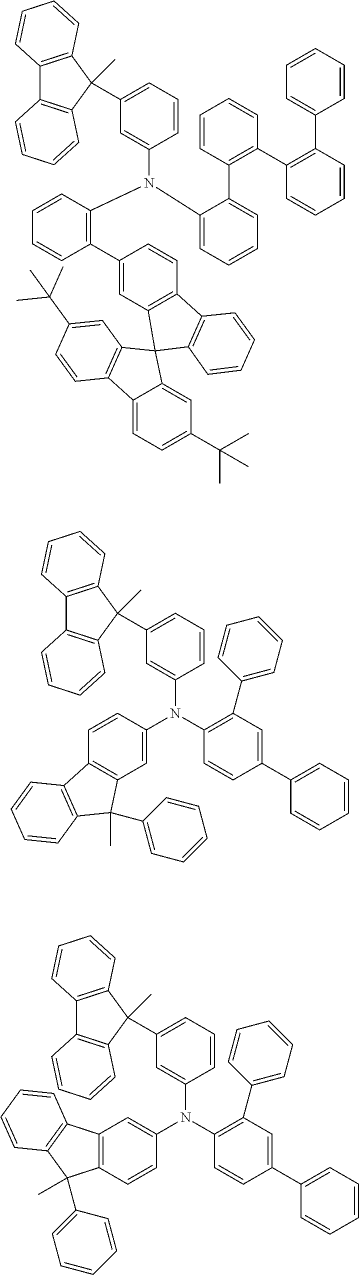 [SMILES: CC(C)(C)c1ccc2c(c1)C1(c3ccccc3-c3ccc(-c4ccccc4N(c4cccc(C5(C)c6ccccc6-c6ccccc65)c4)c4ccccc4-c4ccccc4-c4ccccc4-c4ccccc4)cc31)c1cc(C(C)(C)C)ccc1-2 ; CC1(c2cccc(N(c3ccc4c(c3)C(C)(c3ccccc3)c3ccccc3-4)c3ccc(-c4ccccc4)cc3-c3ccccc3)c2)c2ccccc2-c2ccccc21 ; CC1(c2cccc(N(c3ccc4c(c3)-c3ccccc3C4(C)c3ccccc3)c3ccc(-c4ccccc4)cc3-c3ccccc3)c2)c2ccccc2-c2ccccc21]

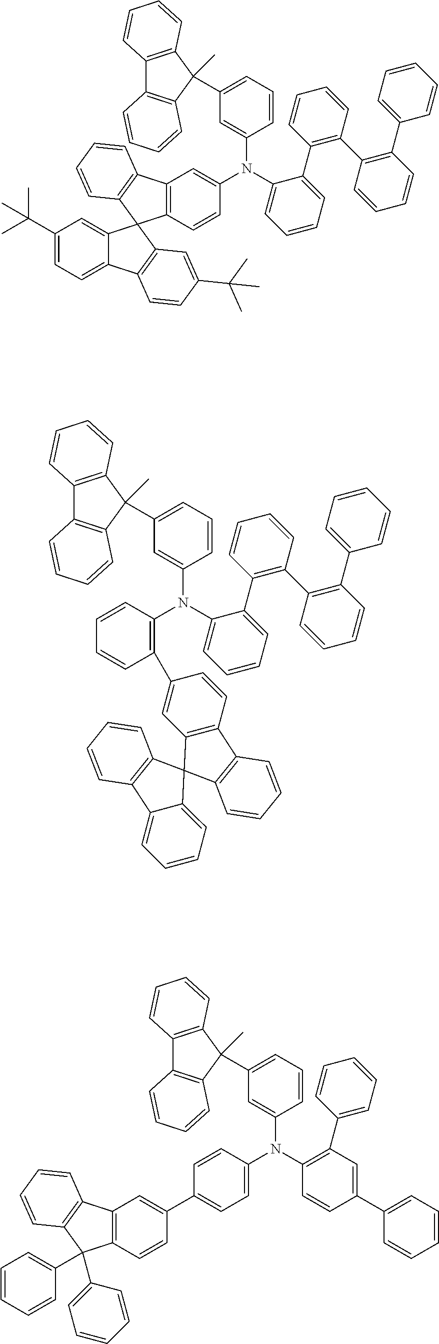 [SMILES: CC(C)(C)c1ccc2c(c1)C1(c3ccccc3-c3cc(N(c4cccc(C5(C)c6ccccc6-c6ccccc65)c4)c4ccccc4-c4ccccc4-c4ccccc4-c4ccccc4)ccc31)c1cc(C(C)(C)C)ccc1-2 ; CC1(c2cccc(N(c3ccccc3-c3ccc4c(c3)C3(c5ccccc5-c5ccccc53)c3ccccc3-4)c3ccccc3-c3ccccc3-c3ccccc3-c3ccccc3)c2)c2ccccc2-c2ccccc21 ; CC1(c2cccc(N(c3ccc(-c4ccc5c(c4)-c4ccccc4C5(c4ccccc4)c4ccccc4)cc3)c3ccc(-c4ccccc4)cc3-c3ccccc3)c2)c2ccccc2-c2ccccc21]

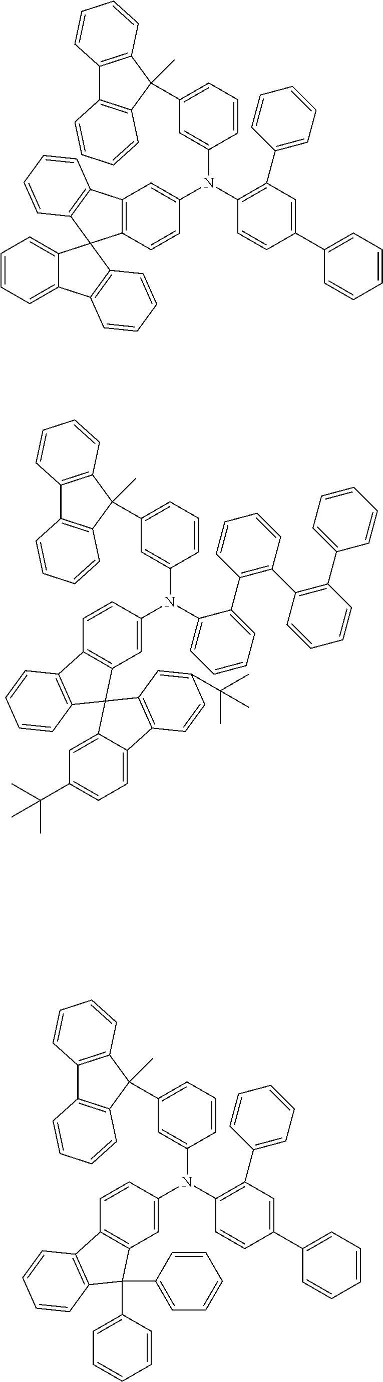 [SMILES: CC1(c2cccc(N(c3ccc4c(c3)-c3ccccc3C43c4ccccc4-c4ccccc43)c3ccc(-c4ccccc4)cc3-c3ccccc3)c2)c2ccccc2-c2ccccc21 ; CC(C)(C)c1ccc2c(c1)C1(c3ccccc3-c3ccc(N(c4cccc(C5(C)c6ccccc6-c6ccccc65)c4)c4ccccc4-c4ccccc4-c4ccccc4-c4ccccc4)cc31)c1cc(C(C)(C)C)ccc1-2 ; CC1(c2cccc(N(c3ccc4c(c3)C(c3ccccc3)(c3ccccc3)c3ccccc3-4)c3ccc(-c4ccccc4)cc3-c3ccccc3)c2)c2ccccc2-c2ccccc21]

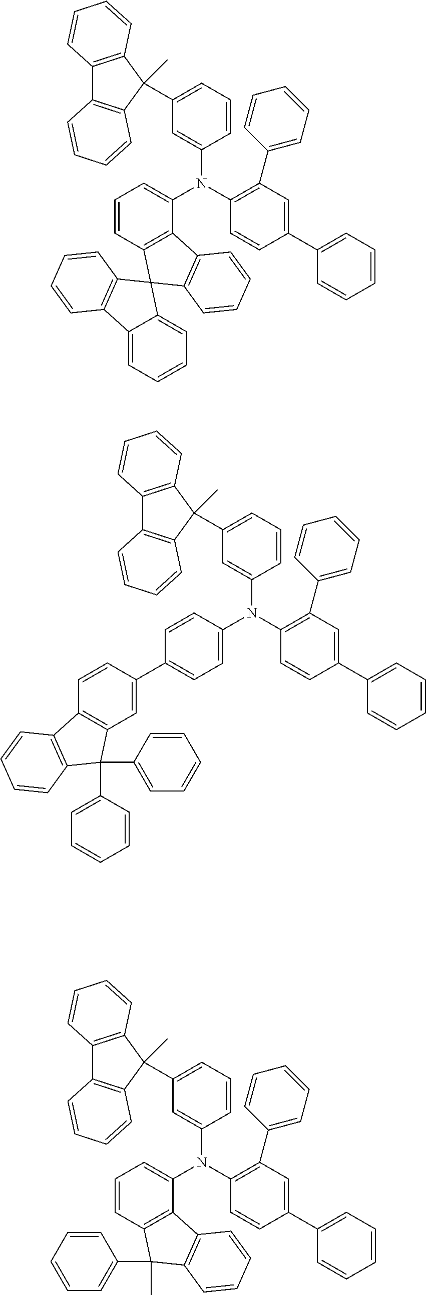 [SMILES: CC1(c2cccc(N(c3ccc(-c4ccccc4)cc3-c3ccccc3)c3cccc4c3-c3ccccc3C43c4ccccc4-c4ccccc43)c2)c2ccccc2-c2ccccc21 ; CC1(c2cccc(N(c3ccc(-c4ccc5c(c4)C(c4ccccc4)(c4ccccc4)c4ccccc4-5)cc3)c3ccc(-c4ccccc4)cc3-c3ccccc3)c2)c2ccccc2-c2ccccc21 ; CC1(c2cccc(N(c3ccc(-c4ccccc4)cc3-c3ccccc3)c3cccc4c3-c3ccccc3C4(C)c3ccccc3)c2)c2ccccc2-c2ccccc21]

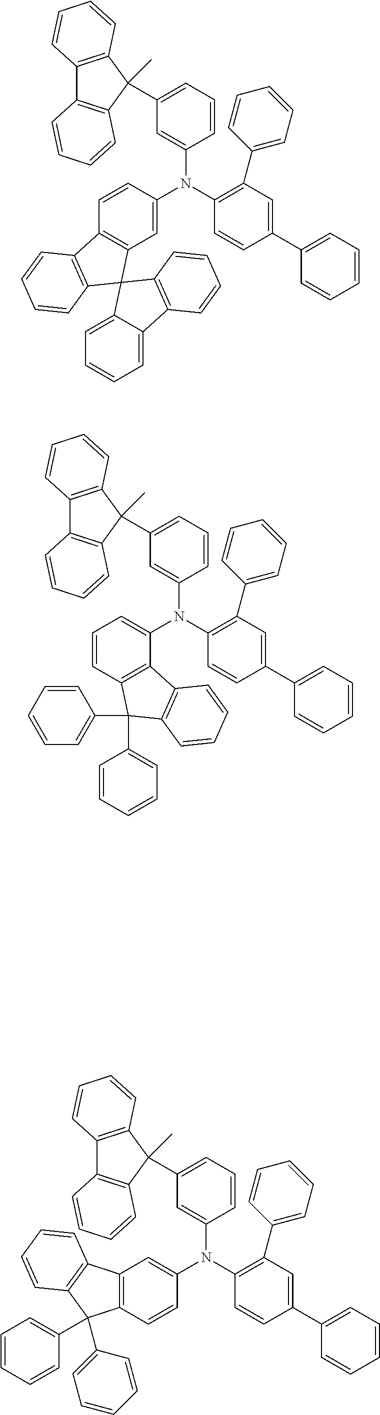 [SMILES: CC1(c2cccc(N(c3ccc4c(c3)C3(c5ccccc5-c5ccccc53)c3ccccc3-4)c3ccc(-c4ccccc4)cc3-c3ccccc3)c2)c2ccccc2-c2ccccc21 ; CC1(c2cccc(N(c3ccc(-c4ccccc4)cc3-c3ccccc3)c3cccc4c3-c3ccccc3C4(c3ccccc3)c3ccccc3)c2)c2ccccc2-c2ccccc21 ; CC1(c2cccc(N(c3ccc4c(c3)-c3ccccc3C4(c3ccccc3)c3ccccc3)c3ccc(-c4ccccc4)cc3-c3ccccc3)c2)c2ccccc2-c2ccccc21]

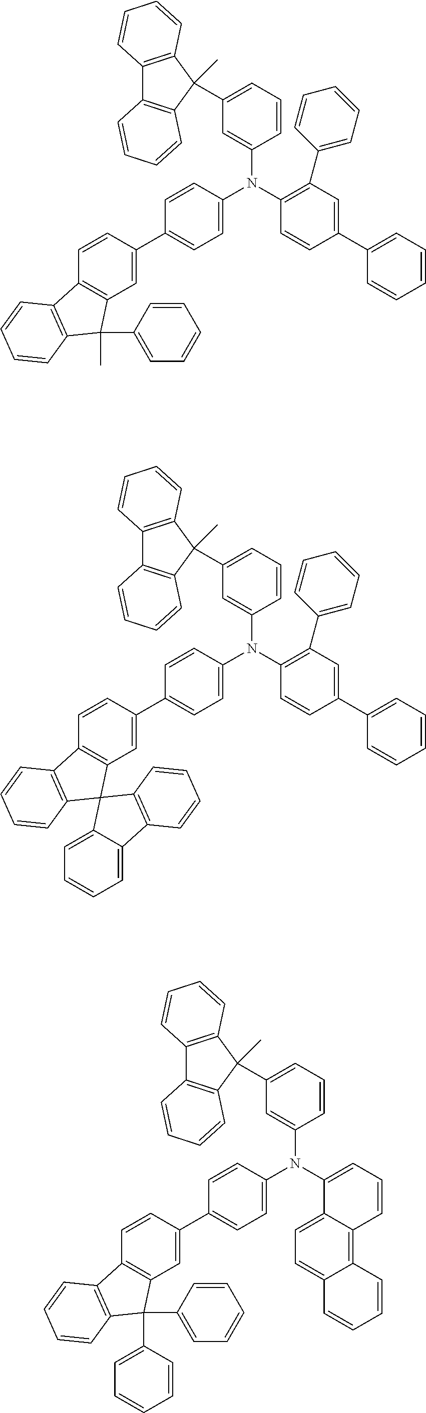 [SMILES: CC1(c2cccc(N(c3ccc(-c4ccc5c(c4)C(C)(c4ccccc4)c4ccccc4-5)cc3)c3ccc(-c4ccccc4)cc3-c3ccccc3)c2)c2ccccc2-c2ccccc21 ; CC1(c2cccc(N(c3ccc(-c4ccc5c(c4)C4(c6ccccc6-c6ccccc64)c4ccccc4-5)cc3)c3ccc(-c4ccccc4)cc3-c3ccccc3)c2)c2ccccc2-c2ccccc21 ; CC1(c2cccc(N(c3ccc(-c4ccc5c(c4)C(c4ccccc4)(c4ccccc4)c4ccccc4-5)cc3)c3cccc4c3ccc3ccccc34)c2)c2ccccc2-c2ccccc21]

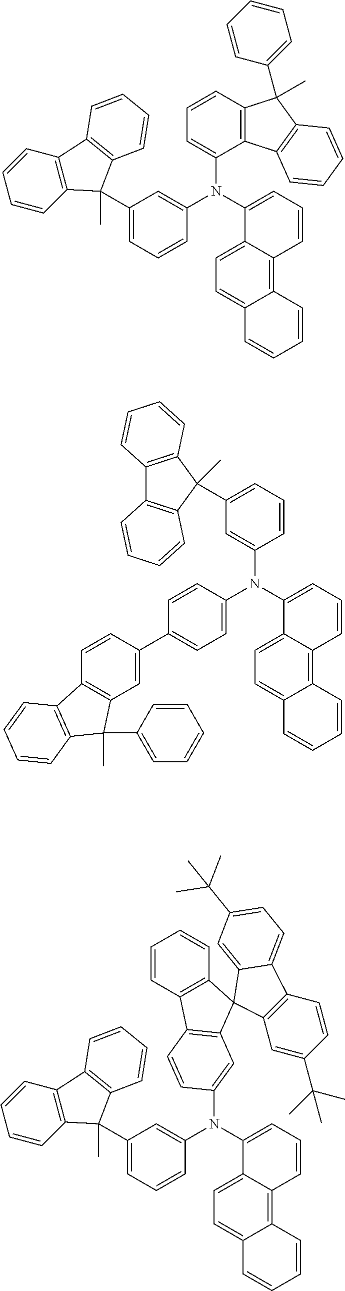 [SMILES: CC1(c2cccc(N(c3cccc4c3-c3ccccc3C4(C)c3ccccc3)c3cccc4c3ccc3ccccc34)c2)c2ccccc2-c2ccccc21 ; CC1(c2cccc(N(c3ccc(-c4ccc5c(c4)C(C)(c4ccccc4)c4ccccc4-5)cc3)c3cccc4c3ccc3ccccc34)c2)c2ccccc2-c2ccccc21 ; CC(C)(C)c1ccc2c(c1)C1(c3ccccc3-c3ccc(N(c4cccc(C5(C)c6ccccc6-c6ccccc65)c4)c4cccc5c4ccc4ccccc45)cc31)c1cc(C(C)(C)C)ccc1-2]

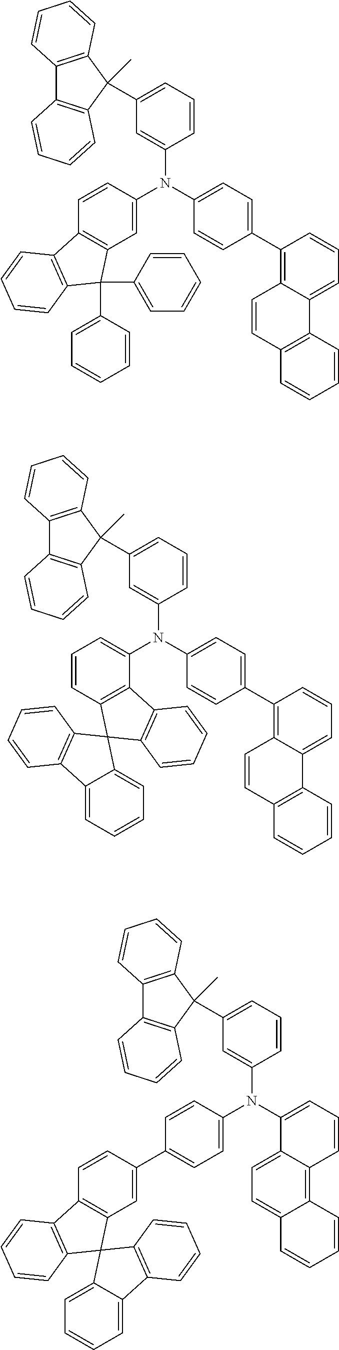 [SMILES: CC1(c2cccc(N(c3ccc(-c4cccc5c4ccc4ccccc45)cc3)c3ccc4c(c3)C(c3ccccc3)(c3ccccc3)c3ccccc3-4)c2)c2ccccc2-c2ccccc21 ; CC1(c2cccc(N(c3ccc(-c4cccc5c4ccc4ccccc45)cc3)c3cccc4c3-c3ccccc3C43c4ccccc4-c4ccccc43)c2)c2ccccc2-c2ccccc21 ; CC1(c2cccc(N(c3ccc(-c4ccc5c(c4)C4(c6ccccc6-c6ccccc64)c4ccccc4-5)cc3)c3cccc4c3ccc3ccccc34)c2)c2ccccc2-c2ccccc21]

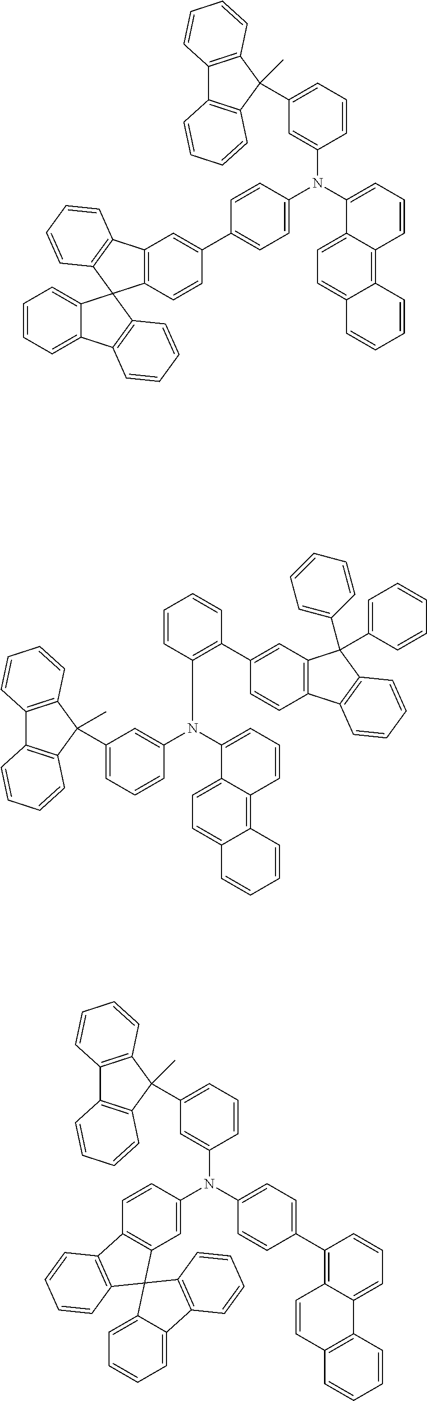 [SMILES: CC1(c2cccc(N(c3ccc(-c4ccc5c(c4)-c4ccccc4C54c5ccccc5-c5ccccc54)cc3)c3cccc4c3ccc3ccccc34)c2)c2ccccc2-c2ccccc21 ; CC1(c2cccc(N(c3ccccc3-c3ccc4c(c3)C(c3ccccc3)(c3ccccc3)c3ccccc3-4)c3cccc4c3ccc3ccccc34)c2)c2ccccc2-c2ccccc21 ; CC1(c2cccc(N(c3ccc(-c4cccc5c4ccc4ccccc45)cc3)c3ccc4c(c3)C3(c5ccccc5-c5ccccc53)c3ccccc3-4)c2)c2ccccc2-c2ccccc21]

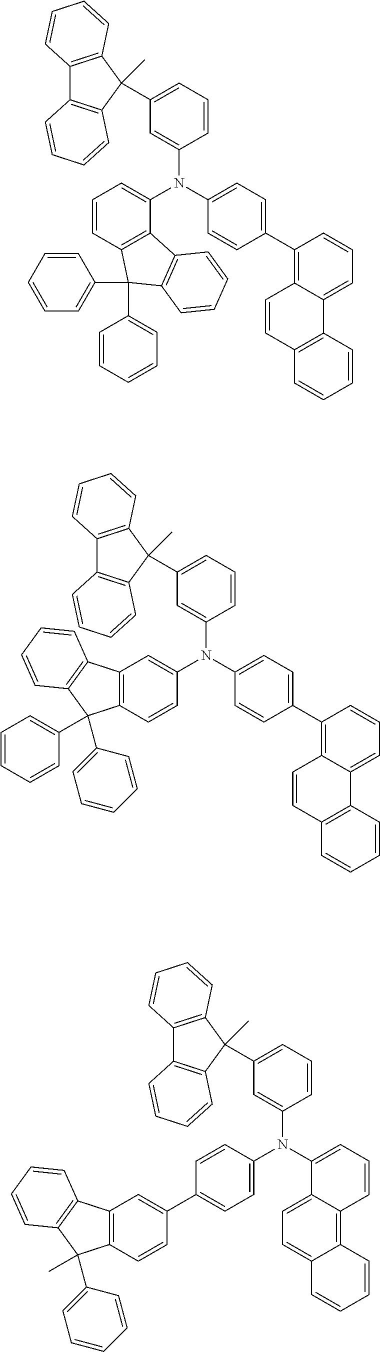 [SMILES: CC1(c2cccc(N(c3ccc(-c4cccc5c4ccc4ccccc45)cc3)c3cccc4c3-c3ccccc3C4(c3ccccc3)c3ccccc3)c2)c2ccccc2-c2ccccc21 ; CC1(c2cccc(N(c3ccc(-c4cccc5c4ccc4ccccc45)cc3)c3ccc4c(c3)-c3ccccc3C4(c3ccccc3)c3ccccc3)c2)c2ccccc2-c2ccccc21 ; CC1(c2cccc(N(c3ccc(-c4ccc5c(c4)-c4ccccc4C5(C)c4ccccc4)cc3)c3cccc4c3ccc3ccccc34)c2)c2ccccc2-c2ccccc21]

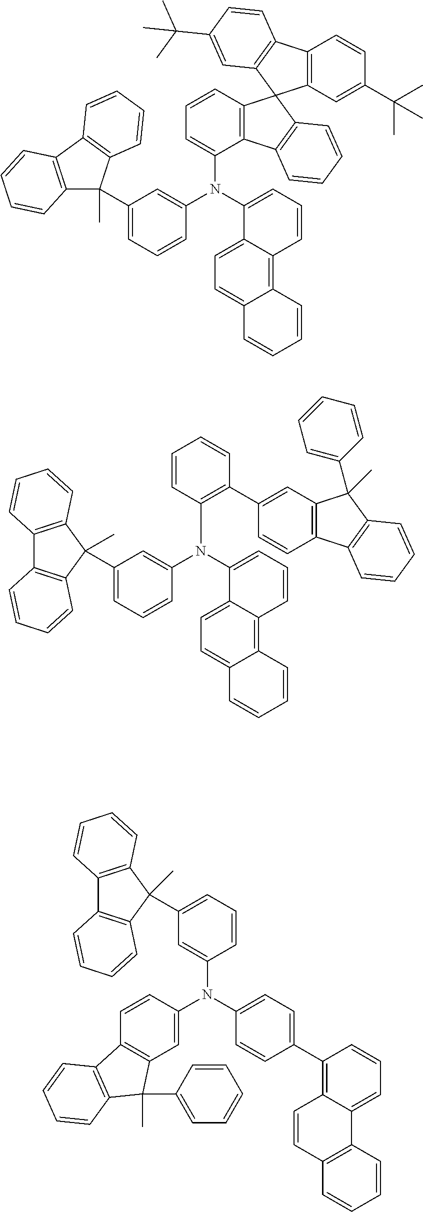 [SMILES: CC(C)(C)c1ccc2c(c1)C1(c3cc(C(C)(C)C)ccc3-2)c2ccccc2-c2c(N(c3cccc(C4(C)c5ccccc5-c5ccccc54)c3)c3cccc4c3ccc3ccccc34)cccc21 ; CC1(c2cccc(N(c3ccccc3-c3ccc4c(c3)C(C)(c3ccccc3)c3ccccc3-4)c3cccc4c3ccc3ccccc34)c2)c2ccccc2-c2ccccc21 ; CC1(c2cccc(N(c3ccc(-c4cccc5c4ccc4ccccc45)cc3)c3ccc4c(c3)C(C)(c3ccccc3)c3ccccc3-4)c2)c2ccccc2-c2ccccc21]

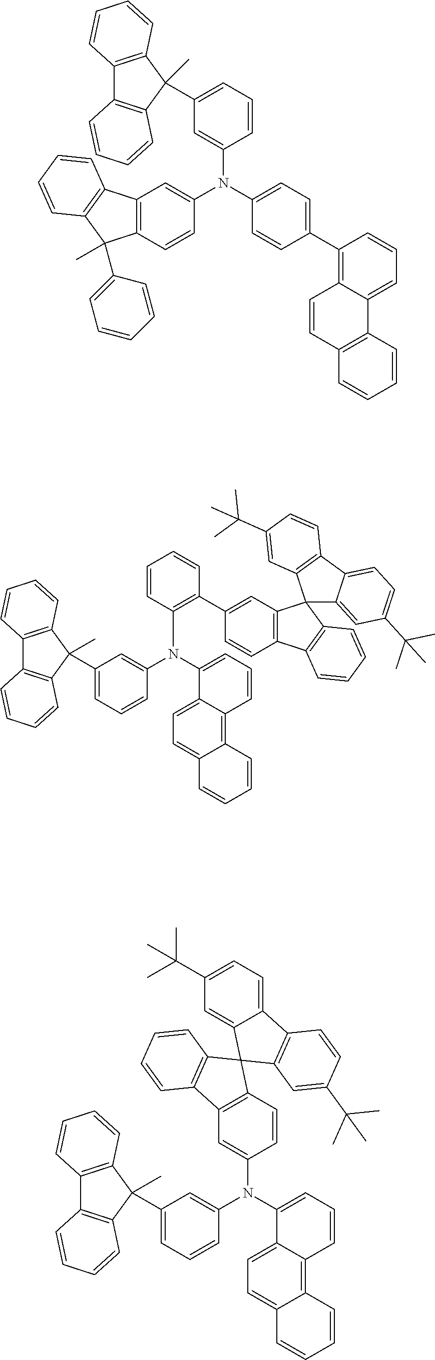 [SMILES: CC1(c2cccc(N(c3ccc(-c4cccc5c4ccc4ccccc45)cc3)c3ccc4c(c3)-c3ccccc3C4(C)c3ccccc3)c2)c2ccccc2-c2ccccc21 ; CC(C)(C)c1ccc2c(c1)C1(c3ccccc3-c3ccc(-c4ccccc4N(c4cccc(C5(C)c6ccccc6-c6ccccc65)c4)c4cccc5c4ccc4ccccc45)cc31)c1cc(C(C)(C)C)ccc1-2 ; CC(C)(C)c1ccc2c(c1)C1(c3ccccc3-c3cc(N(c4cccc(C5(C)c6ccccc6-c6ccccc65)c4)c4cccc5c4ccc4ccccc45)ccc31)c1cc(C(C)(C)C)ccc1-2]

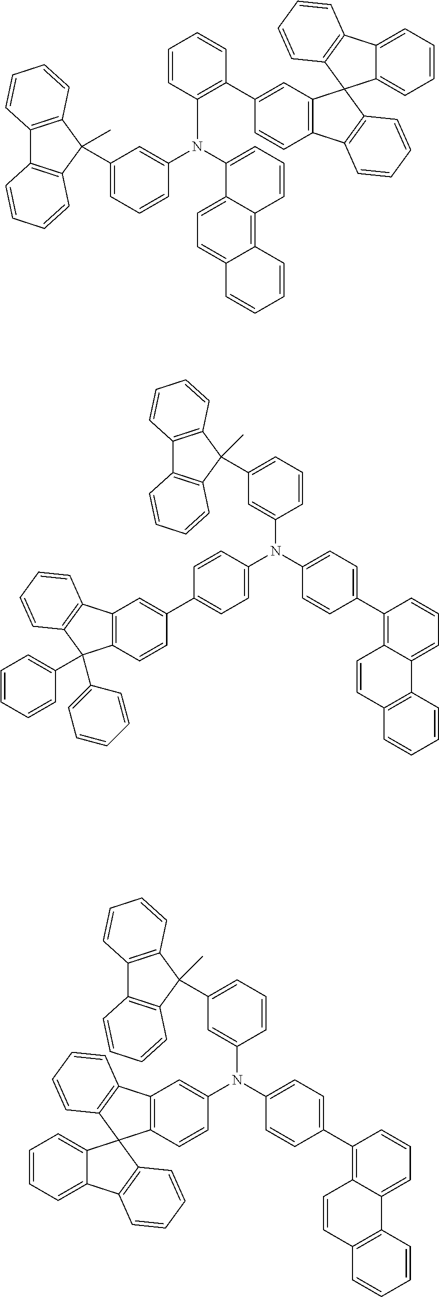 [SMILES: CC1(c2cccc(N(c3ccccc3-c3ccc4c(c3)C3(c5ccccc5-c5ccccc53)c3ccccc3-4)c3cccc4c3ccc3ccccc34)c2)c2ccccc2-c2ccccc21 ; CC1(c2cccc(N(c3ccc(-c4ccc5c(c4)-c4ccccc4C5(c4ccccc4)c4ccccc4)cc3)c3ccc(-c4cccc5c4ccc4ccccc45)cc3)c2)c2ccccc2-c2ccccc21 ; CC1(c2cccc(N(c3ccc(-c4cccc5c4ccc4ccccc45)cc3)c3ccc4c(c3)-c3ccccc3C43c4ccccc4-c4ccccc43)c2)c2ccccc2-c2ccccc21]

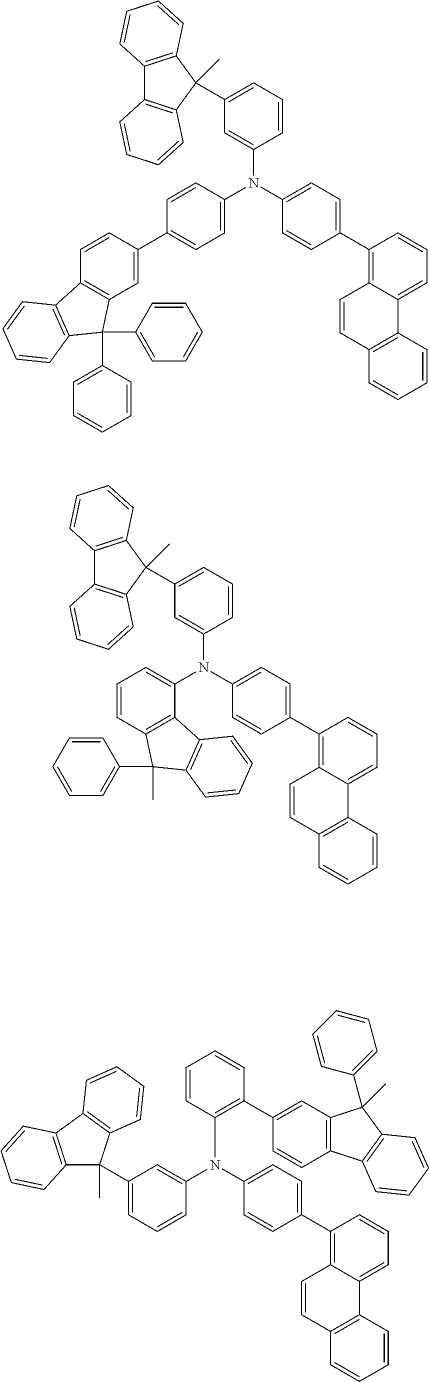 [SMILES: CC1(c2cccc(N(c3ccc(-c4ccc5c(c4)C(c4ccccc4)(c4ccccc4)c4ccccc4-5)cc3)c3ccc(-c4cccc5c4ccc4ccccc45)cc3)c2)c2ccccc2-c2ccccc21 ; CC1(c2cccc(N(c3ccc(-c4cccc5c4ccc4ccccc45)cc3)c3cccc4c3-c3ccccc3C4(C)c3ccccc3)c2)c2ccccc2-c2ccccc21 ; CC1(c2cccc(N(c3ccc(-c4cccc5c4ccc4ccccc45)cc3)c3ccccc3-c3ccc4c(c3)C(C)(c3ccccc3)c3ccccc3-4)c2)c2ccccc2-c2ccccc21]

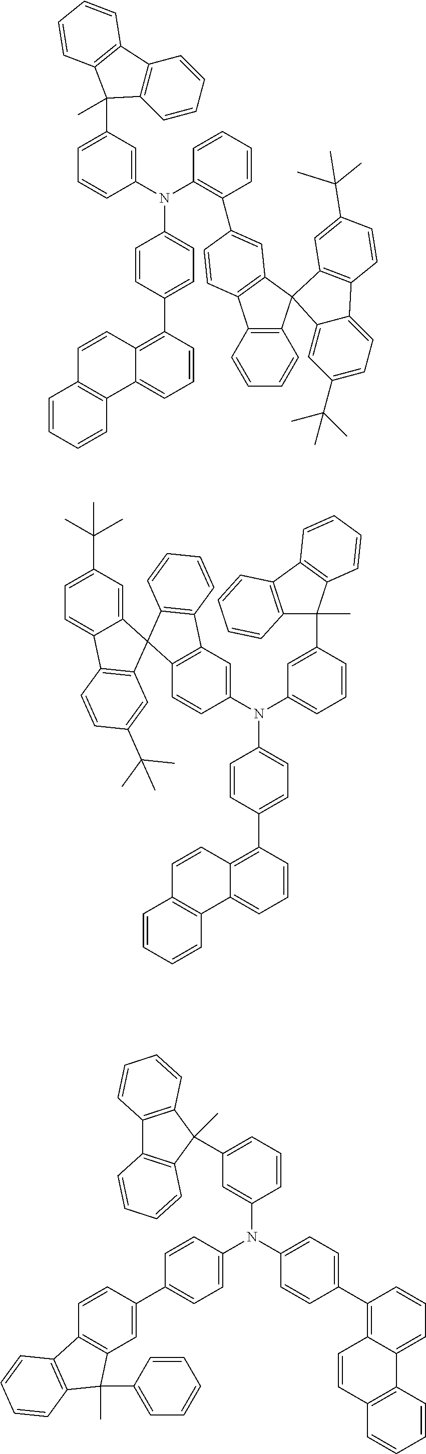 [SMILES: CC(C)(C)c1ccc2c(c1)C1(c3ccccc3-c3ccc(-c4ccccc4N(c4ccc(-c5cccc6c5ccc5ccccc56)cc4)c4cccc(C5(C)c6ccccc6-c6ccccc65)c4)cc31)c1cc(C(C)(C)C)ccc1-2 ; CC(C)(C)c1ccc2c(c1)C1(c3ccccc3-c3cc(N(c4ccc(-c5cccc6c5ccc5ccccc56)cc4)c4cccc(C5(C)c6ccccc6-c6ccccc65)c4)ccc31)c1cc(C(C)(C)C)ccc1-2 ; CC1(c2cccc(N(c3ccc(-c4ccc5c(c4)C(C)(c4ccccc4)c4ccccc4-5)cc3)c3ccc(-c4cccc5c4ccc4ccccc45)cc3)c2)c2ccccc2-c2ccccc21]

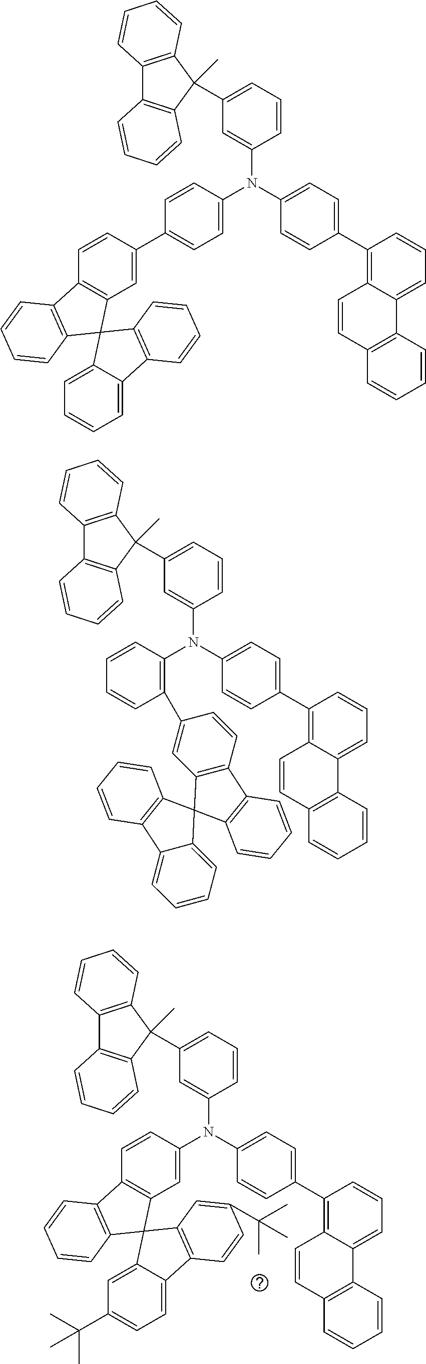

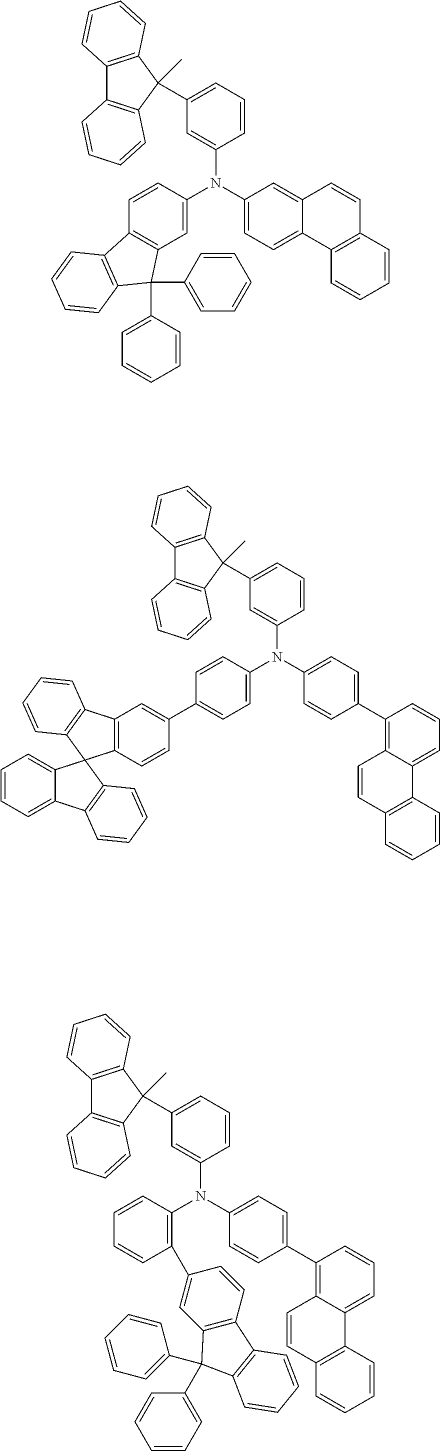 [SMILES: CC1(c2cccc(N(c3ccc4c(c3)C(c3ccccc3)(c3ccccc3)c3ccccc3-4)c3ccc4c(ccc5ccccc54)c3)c2)c2ccccc2-c2ccccc21 ; CC1(c2cccc(N(c3ccc(-c4ccc5c(c4)-c4ccccc4C54c5ccccc5-c5ccccc54)cc3)c3ccc(-c4cccc5c4ccc4ccccc45)cc3)c2)c2ccccc2-c2ccccc21 ; CC1(c2cccc(N(c3ccc(-c4cccc5c4ccc4ccccc45)cc3)c3ccccc3-c3ccc4c(c3)C(c3ccccc3)(c3ccccc3)c3ccccc3-4)c2)c2ccccc2-c2ccccc21]

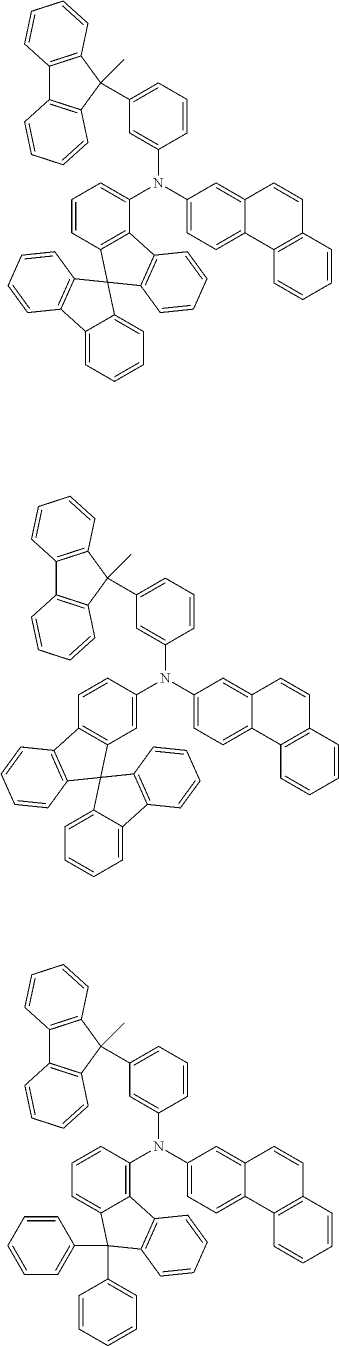 [SMILES: CC1(c2cccc(N(c3ccc4c(ccc5ccccc54)c3)c3cccc4c3-c3ccccc3C43c4ccccc4-c4ccccc43)c2)c2ccccc2-c2ccccc21 ; CC1(c2cccc(N(c3ccc4c(c3)C3(c5ccccc5-c5ccccc53)c3ccccc3-4)c3ccc4c(ccc5ccccc54)c3)c2)c2ccccc2-c2ccccc21 ; CC1(c2cccc(N(c3ccc4c(ccc5ccccc54)c3)c3cccc4c3-c3ccccc3C4(c3ccccc3)c3ccccc3)c2)c2ccccc2-c2ccccc21]

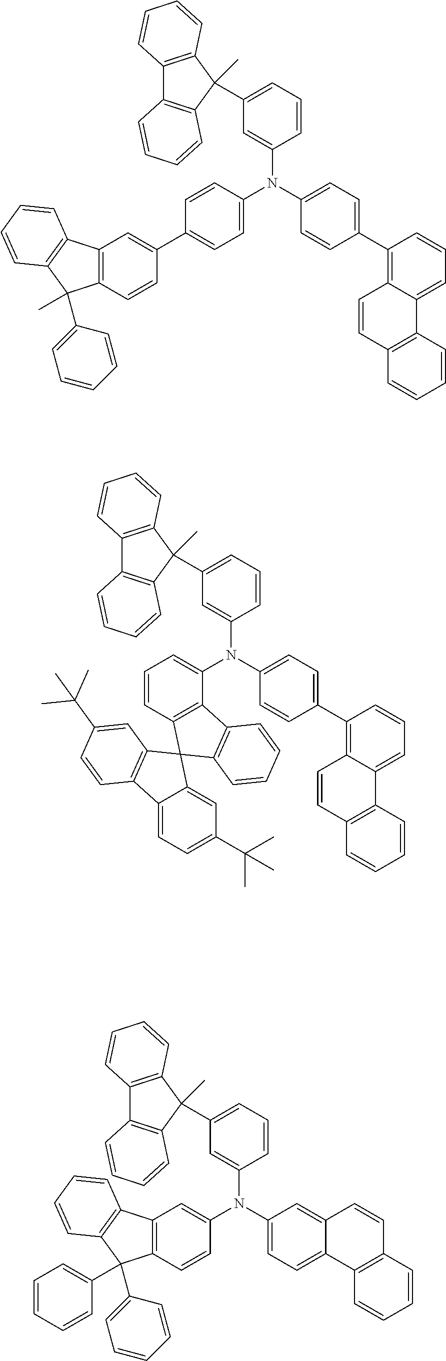 [SMILES: CC1(c2cccc(N(c3ccc(-c4ccc5c(c4)-c4ccccc4C5(C)c4ccccc4)cc3)c3ccc(-c4cccc5c4ccc4ccccc45)cc3)c2)c2ccccc2-c2ccccc21 ; CC(C)(C)c1ccc2c(c1)C1(c3cc(C(C)(C)C)ccc3-2)c2ccccc2-c2c(N(c3ccc(-c4cccc5c4ccc4ccccc45)cc3)c3cccc(C4(C)c5ccccc5-c5ccccc54)c3)cccc21 ; CC1(c2cccc(N(c3ccc4c(c3)-c3ccccc3C4(c3ccccc3)c3ccccc3)c3ccc4c(ccc5ccccc54)c3)c2)c2ccccc2-c2ccccc21]

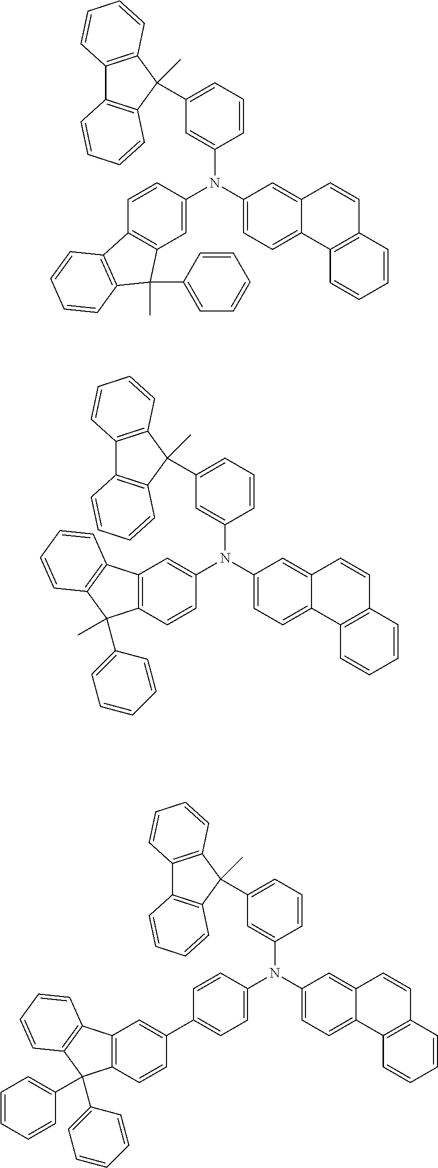 [SMILES: CC1(c2cccc(N(c3ccc4c(c3)C(C)(c3ccccc3)c3ccccc3-4)c3ccc4c(ccc5ccccc54)c3)c2)c2ccccc2-c2ccccc21 ; CC1(c2cccc(N(c3ccc4c(c3)-c3ccccc3C4(C)c3ccccc3)c3ccc4c(ccc5ccccc54)c3)c2)c2ccccc2-c2ccccc21 ; CC1(c2cccc(N(c3ccc(-c4ccc5c(c4)-c4ccccc4C5(c4ccccc4)c4ccccc4)cc3)c3ccc4c(ccc5ccccc54)c3)c2)c2ccccc2-c2ccccc21]

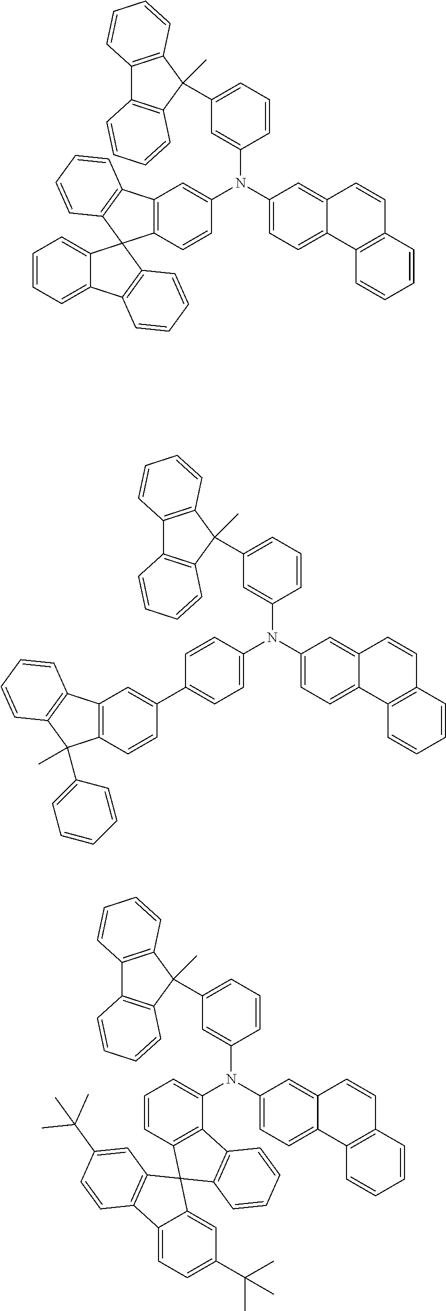 [SMILES: CC1(c2cccc(N(c3ccc4c(c3)-c3ccccc3C43c4ccccc4-c4ccccc43)c3ccc4c(ccc5ccccc54)c3)c2)c2ccccc2-c2ccccc21 ; CC1(c2cccc(N(c3ccc(-c4ccc5c(c4)-c4ccccc4C5(C)c4ccccc4)cc3)c3ccc4c(ccc5ccccc54)c3)c2)c2ccccc2-c2ccccc21 ; CC(C)(C)c1ccc2c(c1)C1(c3cc(C(C)(C)C)ccc3-2)c2ccccc2-c2c(N(c3cccc(C4(C)c5ccccc5-c5ccccc54)c3)c3ccc4c(ccc5ccccc54)c3)cccc21]

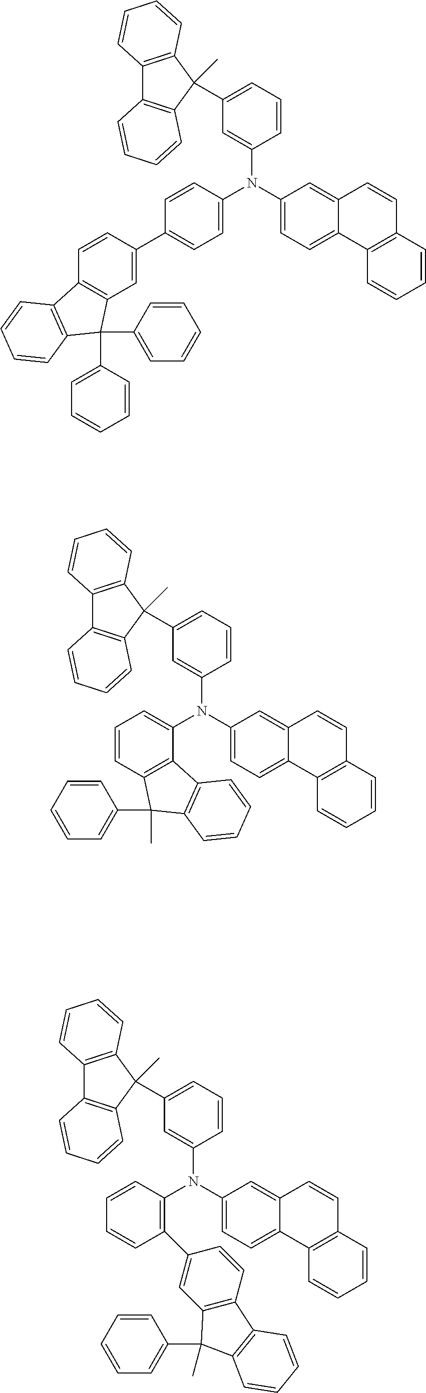 [SMILES: CC1(c2cccc(N(c3ccc(-c4ccc5c(c4)C(c4ccccc4)(c4ccccc4)c4ccccc4-5)cc3)c3ccc4c(ccc5ccccc54)c3)c2)c2ccccc2-c2ccccc21 ; CC1(c2cccc(N(c3ccc4c(ccc5ccccc54)c3)c3cccc4c3-c3ccccc3C4(C)c3ccccc3)c2)c2ccccc2-c2ccccc21 ; CC1(c2cccc(N(c3ccc4c(ccc5ccccc54)c3)c3ccccc3-c3ccc4c(c3)C(C)(c3ccccc3)c3ccccc3-4)c2)c2ccccc2-c2ccccc21]

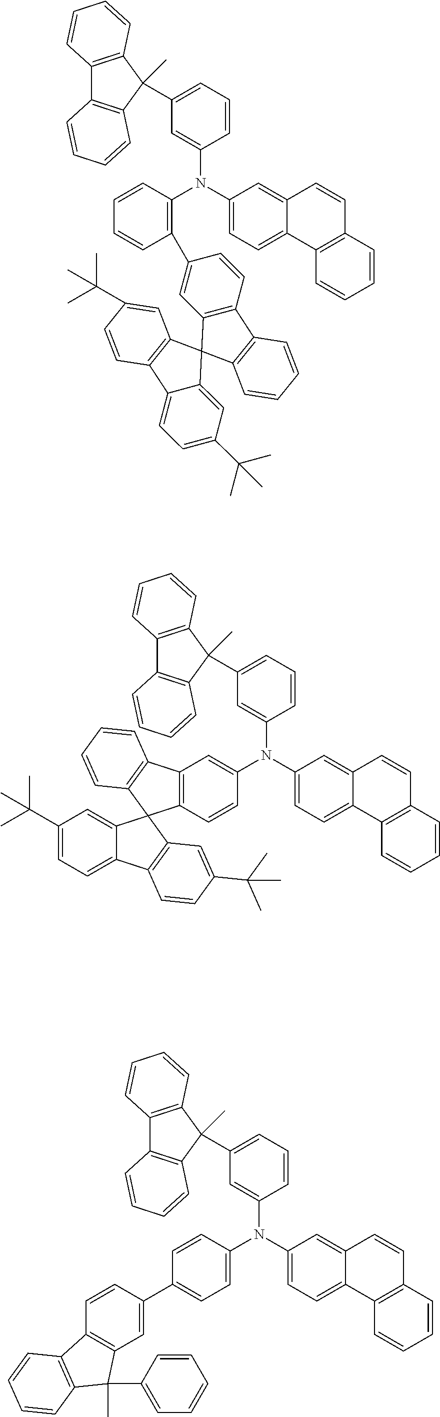 [SMILES: CC(C)(C)c1ccc2c(c1)C1(c3ccccc3-c3ccc(-c4ccccc4N(c4cccc(C5(C)c6ccccc6-c6ccccc65)c4)c4ccc5c(ccc6ccccc65)c4)cc31)c1cc(C(C)(C)C)ccc1-2 ; CC(C)(C)c1ccc2c(c1)C1(c3ccccc3-c3cc(N(c4cccc(C5(C)c6ccccc6-c6ccccc65)c4)c4ccc5c(ccc6ccccc65)c4)ccc31)c1cc(C(C)(C)C)ccc1-2 ; CC1(c2cccc(N(c3ccc(-c4ccc5c(c4)C(C)(c4ccccc4)c4ccccc4-5)cc3)c3ccc4c(ccc5ccccc54)c3)c2)c2ccccc2-c2ccccc21]

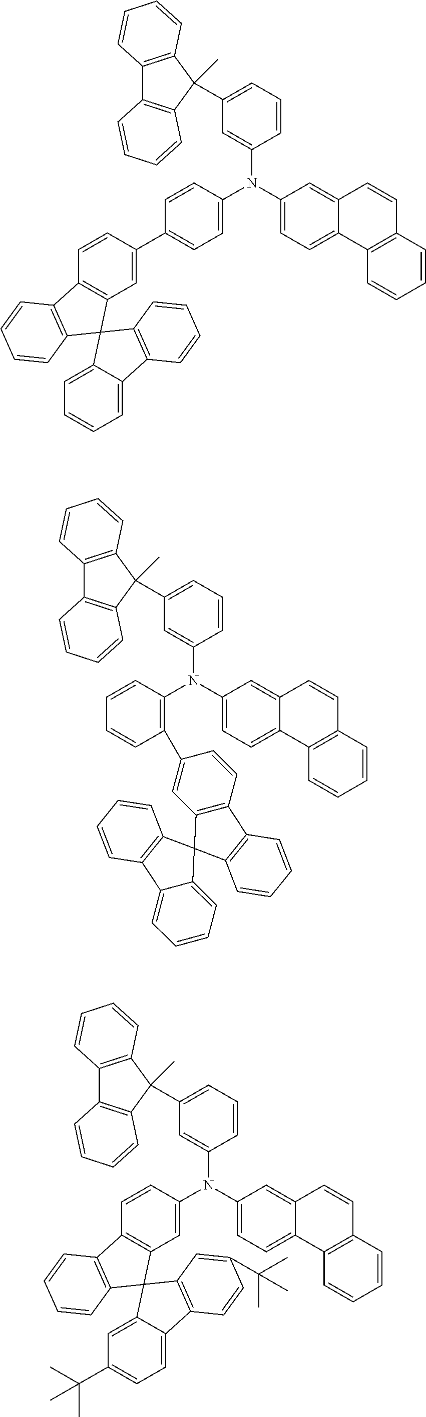 [SMILES: CC1(c2cccc(N(c3ccc(-c4ccc5c(c4)C4(c6ccccc6-c6ccccc64)c4ccccc4-5)cc3)c3ccc4c(ccc5ccccc54)c3)c2)c2ccccc2-c2ccccc21 ; CC1(c2cccc(N(c3ccc4c(ccc5ccccc54)c3)c3ccccc3-c3ccc4c(c3)C3(c5ccccc5-c5ccccc53)c3ccccc3-4)c2)c2ccccc2-c2ccccc21 ; CC(C)(C)c1ccc2c(c1)C1(c3ccccc3-c3ccc(N(c4cccc(C5(C)c6ccccc6-c6ccccc65)c4)c4ccc5c(ccc6ccccc65)c4)cc31)c1cc(C(C)(C)C)ccc1-2]

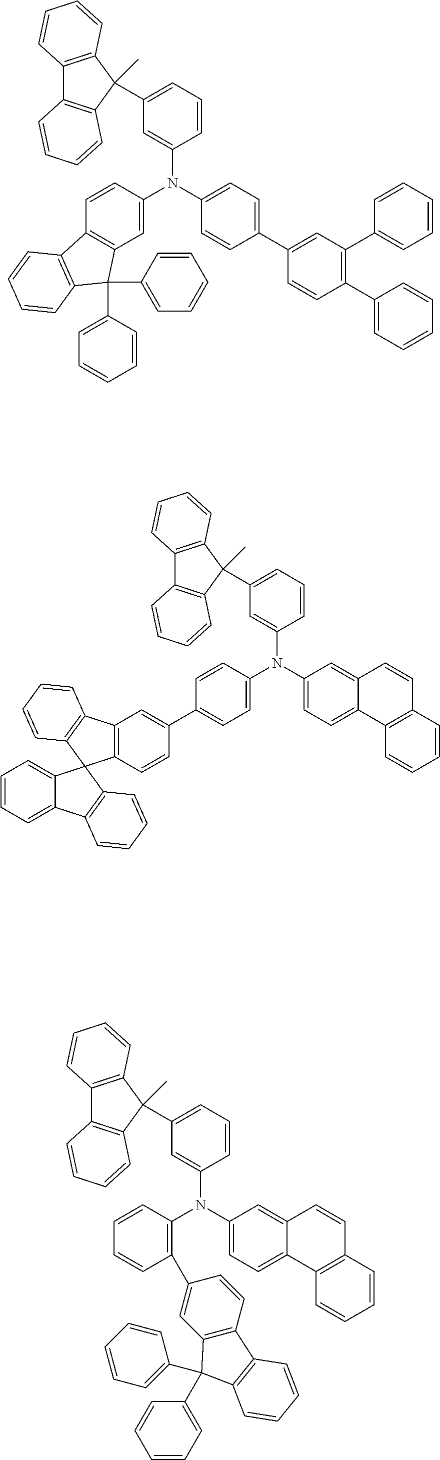 [SMILES: CC1(c2cccc(N(c3ccc(-c4ccc(-c5ccccc5)c(-c5ccccc5)c4)cc3)c3ccc4c(c3)C(c3ccccc3)(c3ccccc3)c3ccccc3-4)c2)c2ccccc2-c2ccccc21 ; CC1(c2cccc(N(c3ccc(-c4ccc5c(c4)-c4ccccc4C54c5ccccc5-c5ccccc54)cc3)c3ccc4c(ccc5ccccc54)c3)c2)c2ccccc2-c2ccccc21 ; CC1(c2cccc(N(c3ccc4c(ccc5ccccc54)c3)c3ccccc3-c3ccc4c(c3)C(c3ccccc3)(c3ccccc3)c3ccccc3-4)c2)c2ccccc2-c2ccccc21]

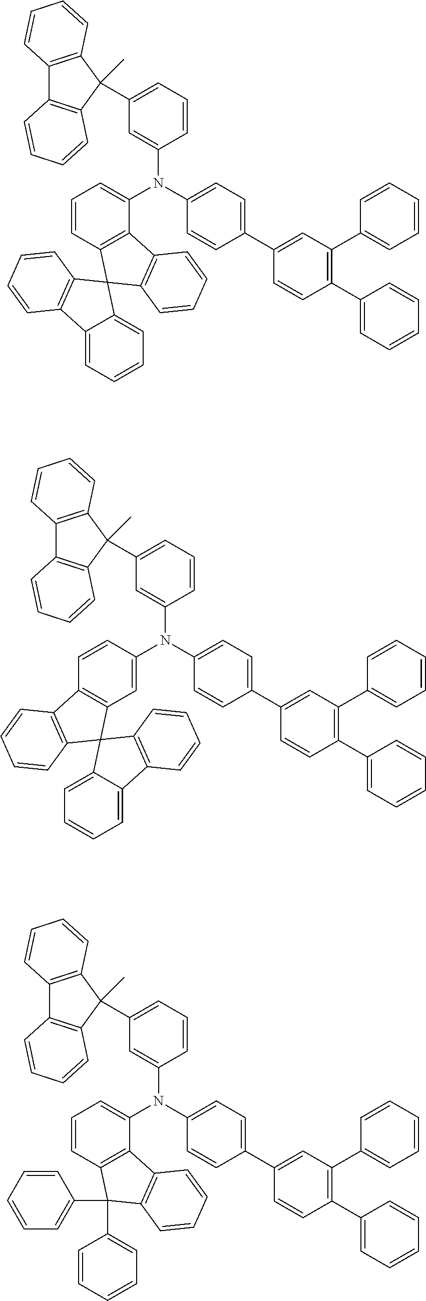 [SMILES: CC1(c2cccc(N(c3ccc(-c4ccc(-c5ccccc5)c(-c5ccccc5)c4)cc3)c3cccc4c3-c3ccccc3C43c4ccccc4-c4ccccc43)c2)c2ccccc2-c2ccccc21 ; CC1(c2cccc(N(c3ccc(-c4ccc(-c5ccccc5)c(-c5ccccc5)c4)cc3)c3ccc4c(c3)C3(c5ccccc5-c5ccccc53)c3ccccc3-4)c2)c2ccccc2-c2ccccc21 ; CC1(c2cccc(N(c3ccc(-c4ccc(-c5ccccc5)c(-c5ccccc5)c4)cc3)c3cccc4c3-c3ccccc3C4(c3ccccc3)c3ccccc3)c2)c2ccccc2-c2ccccc21]

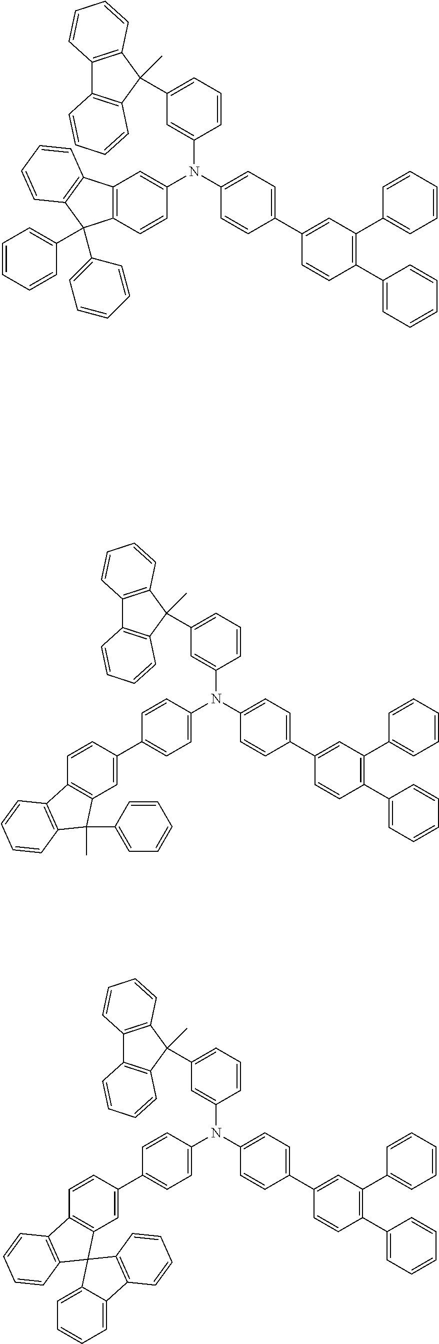 [SMILES: CC1(c2cccc(N(c3ccc(-c4ccc(-c5ccccc5)c(-c5ccccc5)c4)cc3)c3ccc4c(c3)-c3ccccc3C4(c3ccccc3)c3ccccc3)c2)c2ccccc2-c2ccccc21 ; CC1(c2cccc(N(c3ccc(-c4ccc(-c5ccccc5)c(-c5ccccc5)c4)cc3)c3ccc(-c4ccc5c(c4)C(C)(c4ccccc4)c4ccccc4-5)cc3)c2)c2ccccc2-c2ccccc21 ; CC1(c2cccc(N(c3ccc(-c4ccc(-c5ccccc5)c(-c5ccccc5)c4)cc3)c3ccc(-c4ccc5c(c4)C4(c6ccccc6-c6ccccc64)c4ccccc4-5)cc3)c2)c2ccccc2-c2ccccc21]

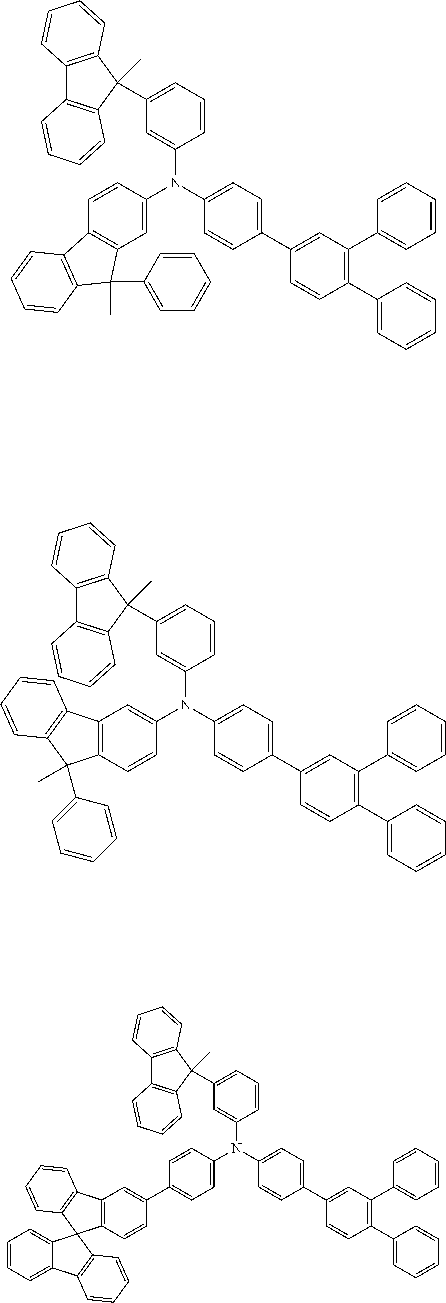 [SMILES: CC1(c2cccc(N(c3ccc(-c4ccc(-c5ccccc5)c(-c5ccccc5)c4)cc3)c3ccc4c(c3)C(C)(c3ccccc3)c3ccccc3-4)c2)c2ccccc2-c2ccccc21 ; CC1(c2cccc(N(c3ccc(-c4ccc(-c5ccccc5)c(-c5ccccc5)c4)cc3)c3ccc4c(c3)-c3ccccc3C4(C)c3ccccc3)c2)c2ccccc2-c2ccccc21 ; CC1(c2cccc(N(c3ccc(-c4ccc(-c5ccccc5)c(-c5ccccc5)c4)cc3)c3ccc(-c4ccc5c(c4)-c4ccccc4C54c5ccccc5-c5ccccc54)cc3)c2)c2ccccc2-c2ccccc21]

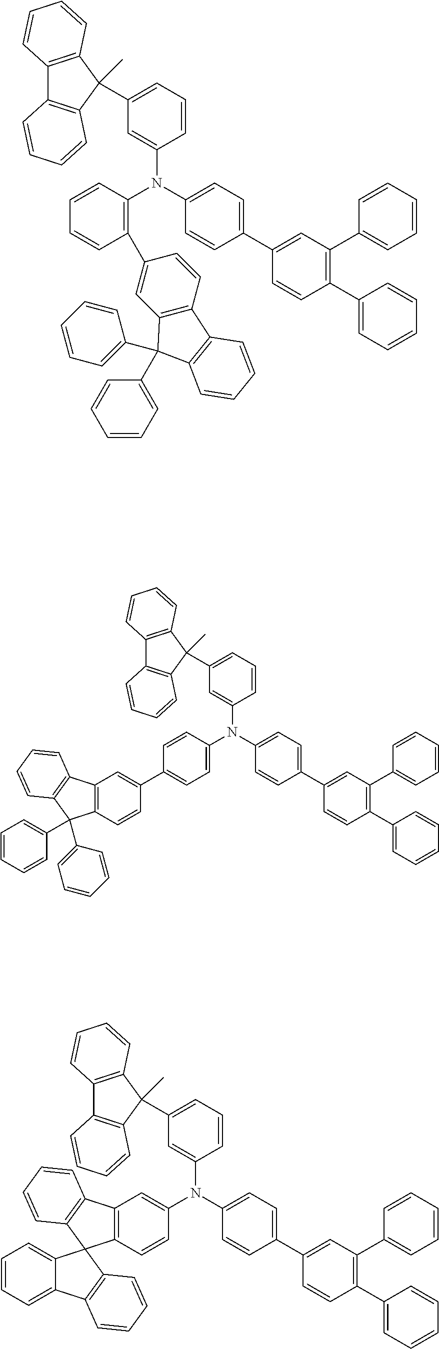 [SMILES: CC1(c2cccc(N(c3ccc(-c4ccc(-c5ccccc5)c(-c5ccccc5)c4)cc3)c3ccccc3-c3ccc4c(c3)C(c3ccccc3)(c3ccccc3)c3ccccc3-4)c2)c2ccccc2-c2ccccc21 ; CC1(c2cccc(N(c3ccc(-c4ccc(-c5ccccc5)c(-c5ccccc5)c4)cc3)c3ccc(-c4ccc5c(c4)-c4ccccc4C5(c4ccccc4)c4ccccc4)cc3)c2)c2ccccc2-c2ccccc21 ; CC1(c2cccc(N(c3ccc(-c4ccc(-c5ccccc5)c(-c5ccccc5)c4)cc3)c3ccc4c(c3)-c3ccccc3C43c4ccccc4-c4ccccc43)c2)c2ccccc2-c2ccccc21]

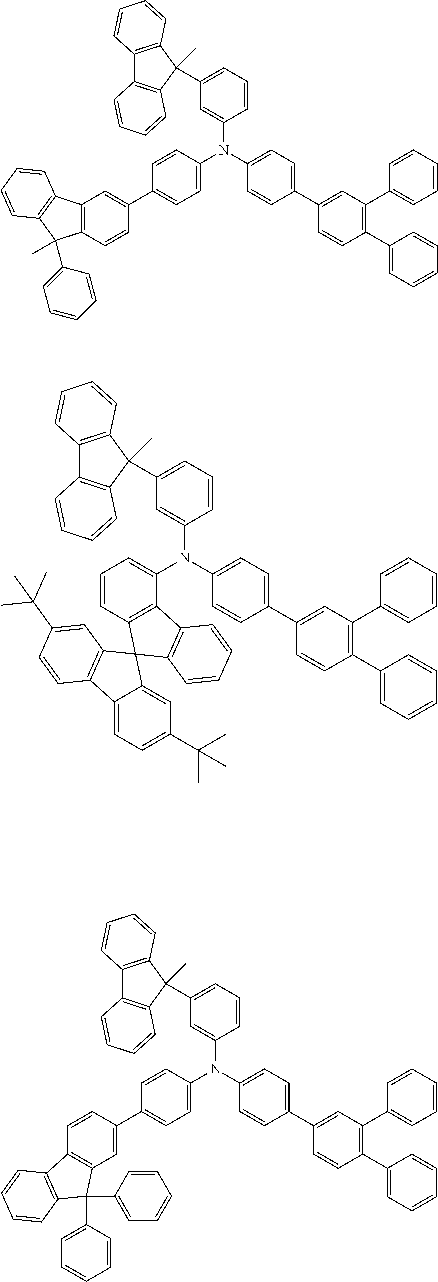 [SMILES: CC1(c2cccc(N(c3ccc(-c4ccc(-c5ccccc5)c(-c5ccccc5)c4)cc3)c3ccc(-c4ccc5c(c4)-c4ccccc4C5(C)c4ccccc4)cc3)c2)c2ccccc2-c2ccccc21 ; CC(C)(C)c1ccc2c(c1)C1(c3cc(C(C)(C)C)ccc3-2)c2ccccc2-c2c(N(c3ccc(-c4ccc(-c5ccccc5)c(-c5ccccc5)c4)cc3)c3cccc(C4(C)c5ccccc5-c5ccccc54)c3)cccc21 ; CC1(c2cccc(N(c3ccc(-c4ccc(-c5ccccc5)c(-c5ccccc5)c4)cc3)c3ccc(-c4ccc5c(c4)C(c4ccccc4)(c4ccccc4)c4ccccc4-5)cc3)c2)c2ccccc2-c2ccccc21]

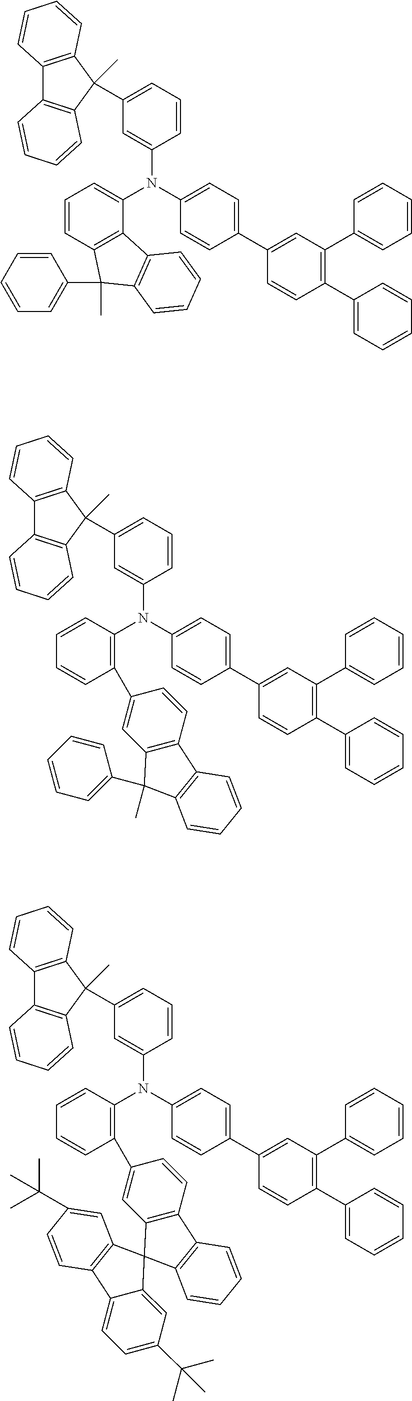 [SMILES: CC1(c2cccc(N(c3ccc(-c4ccc(-c5ccccc5)c(-c5ccccc5)c4)cc3)c3cccc4c3-c3ccccc3C4(C)c3ccccc3)c2)c2ccccc2-c2ccccc21 ; CC1(c2cccc(N(c3ccc(-c4ccc(-c5ccccc5)c(-c5ccccc5)c4)cc3)c3ccccc3-c3ccc4c(c3)C(C)(c3ccccc3)c3ccccc3-4)c2)c2ccccc2-c2ccccc21 ; CC(C)(C)c1ccc2c(c1)C1(c3ccccc3-c3ccc(-c4ccccc4N(c4ccc(-c5ccc(-c6ccccc6)c(-c6ccccc6)c5)cc4)c4cccc(C5(C)c6ccccc6-c6ccccc65)c4)cc31)c1cc(C(C)(C)C)ccc1-2]

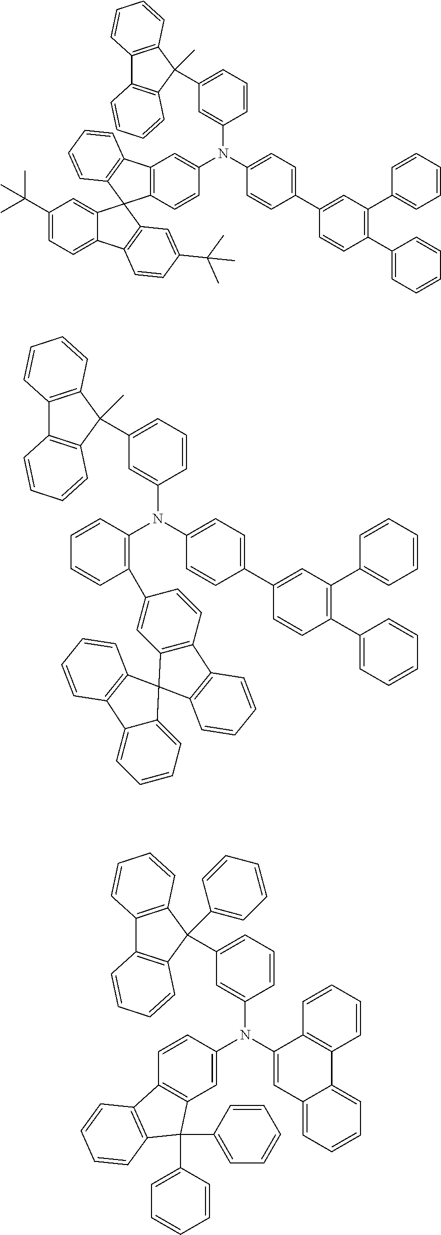 [SMILES: CC(C)(C)c1ccc2c(c1)C1(c3ccccc3-c3cc(N(c4ccc(-c5ccc(-c6ccccc6)c(-c6ccccc6)c5)cc4)c4cccc(C5(C)c6ccccc6-c6ccccc65)c4)ccc31)c1cc(C(C)(C)C)ccc1-2 ; CC1(c2cccc(N(c3ccc(-c4ccc(-c5ccccc5)c(-c5ccccc5)c4)cc3)c3ccccc3-c3ccc4c(c3)C3(c5ccccc5-c5ccccc53)c3ccccc3-4)c2)c2ccccc2-c2ccccc21 ; c1ccc(C2(c3cccc(N(c4ccc5c(c4)C(c4ccccc4)(c4ccccc4)c4ccccc4-5)c4cc5ccccc5c5ccccc45)c3)c3ccccc3-c3ccccc32)cc1]

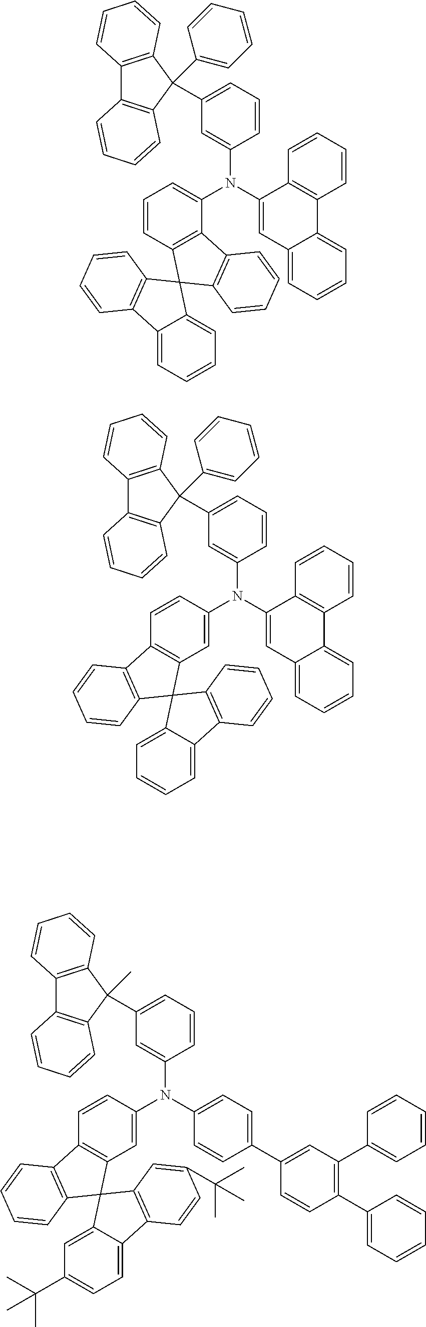 [SMILES: c1ccc(C2(c3cccc(N(c4cccc5c4-c4ccccc4C54c5ccccc5-c5ccccc54)c4cc5ccccc5c5ccccc45)c3)c3ccccc3-c3ccccc32)cc1 ; c1ccc(C2(c3cccc(N(c4ccc5c(c4)C4(c6ccccc6-c6ccccc64)c4ccccc4-5)c4cc5ccccc5c5ccccc45)c3)c3ccccc3-c3ccccc32)cc1 ; CC(C)(C)c1ccc2c(c1)C1(c3ccccc3-c3ccc(N(c4ccc(-c5ccc(-c6ccccc6)c(-c6ccccc6)c5)cc4)c4cccc(C5(C)c6ccccc6-c6ccccc65)c4)cc31)c1cc(C(C)(C)C)ccc1-2]

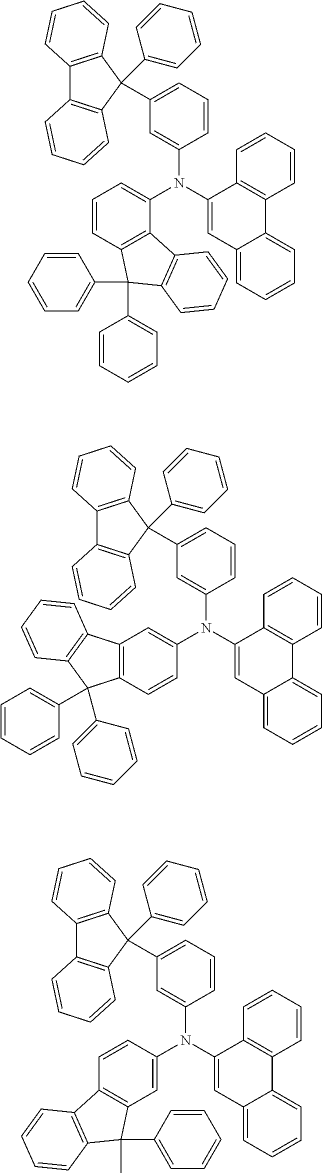 [SMILES: c1ccc(C2(c3cccc(N(c4cccc5c4-c4ccccc4C5(c4ccccc4)c4ccccc4)c4cc5ccccc5c5ccccc45)c3)c3ccccc3-c3ccccc32)cc1 ; c1ccc(C2(c3cccc(N(c4ccc5c(c4)-c4ccccc4C5(c4ccccc4)c4ccccc4)c4cc5ccccc5c5ccccc45)c3)c3ccccc3-c3ccccc32)cc1 ; CC1(c2ccccc2)c2ccccc2-c2ccc(N(c3cccc(C4(c5ccccc5)c5ccccc5-c5ccccc54)c3)c3cc4ccccc4c4ccccc34)cc21]

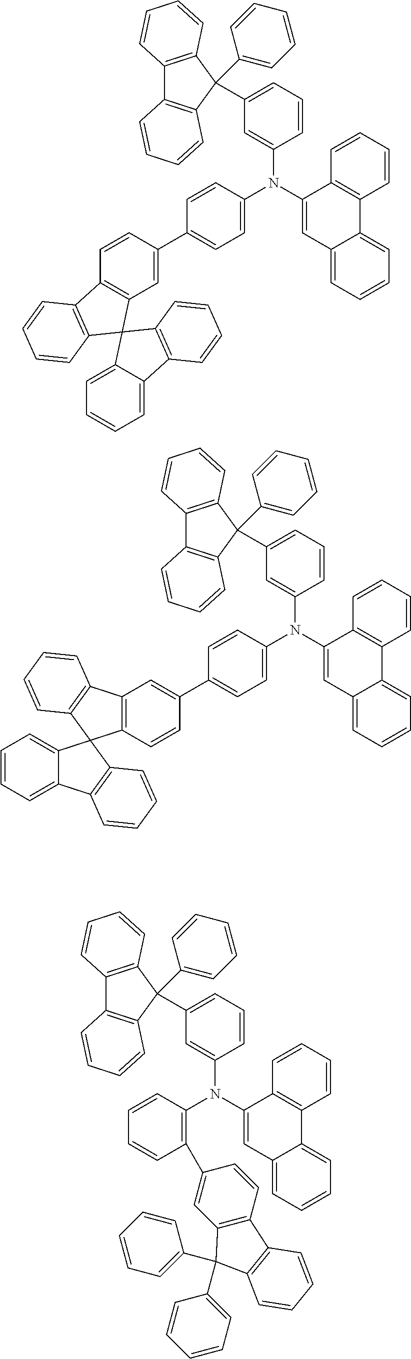 [SMILES: c1ccc(C2(c3cccc(N(c4ccc(-c5ccc6c(c5)C5(c7ccccc7-c7ccccc75)c5ccccc5-6)cc4)c4cc5ccccc5c5ccccc45)c3)c3ccccc3-c3ccccc32)cc1 ; c1ccc(C2(c3cccc(N(c4ccc(-c5ccc6c(c5)-c5ccccc5C65c6ccccc6-c6ccccc65)cc4)c4cc5ccccc5c5ccccc45)c3)c3ccccc3-c3ccccc32)cc1 ; c1ccc(C2(c3cccc(N(c4ccccc4-c4ccc5c(c4)C(c4ccccc4)(c4ccccc4)c4ccccc4-5)c4cc5ccccc5c5ccccc45)c3)c3ccccc3-c3ccccc32)cc1]

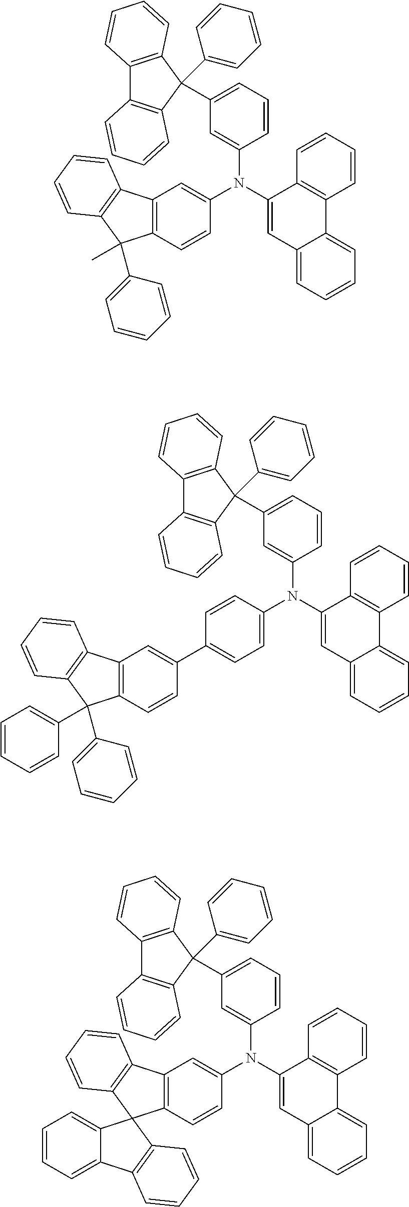 [SMILES: CC1(c2ccccc2)c2ccccc2-c2cc(N(c3cccc(C4(c5ccccc5)c5ccccc5-c5ccccc54)c3)c3cc4ccccc4c4ccccc34)ccc21 ; c1ccc(C2(c3cccc(N(c4ccc(-c5ccc6c(c5)-c5ccccc5C6(c5ccccc5)c5ccccc5)cc4)c4cc5ccccc5c5ccccc45)c3)c3ccccc3-c3ccccc32)cc1 ; c1ccc(C2(c3cccc(N(c4ccc5c(c4)-c4ccccc4C54c5ccccc5-c5ccccc54)c4cc5ccccc5c5ccccc45)c3)c3ccccc3-c3ccccc32)cc1]

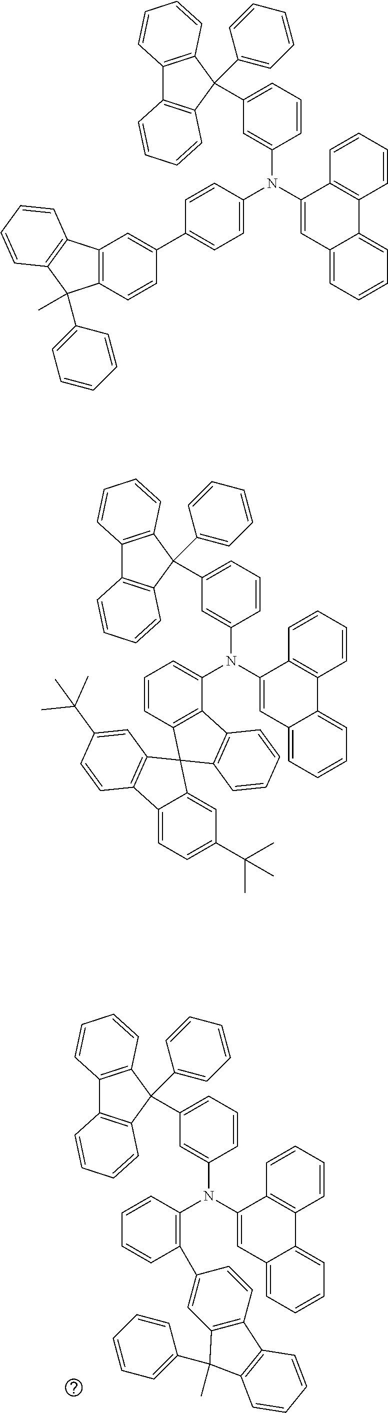 [SMILES: CC1(c2ccccc2)c2ccccc2-c2cc(-c3ccc(N(c4cccc(C5(c6ccccc6)c6ccccc6-c6ccccc65)c4)c4cc5ccccc5c5ccccc45)cc3)ccc21 ; CC(C)(C)c1ccc2c(c1)C1(c3cc(C(C)(C)C)ccc3-2)c2ccccc2-c2c(N(c3cccc(C4(c5ccccc5)c5ccccc5-c5ccccc54)c3)c3cc4ccccc4c4ccccc34)cccc21 ; CC1(c2ccccc2)c2ccccc2-c2ccc(-c3ccccc3N(c3cccc(C4(c5ccccc5)c5ccccc5-c5ccccc54)c3)c3cc4ccccc4c4ccccc34)cc21]

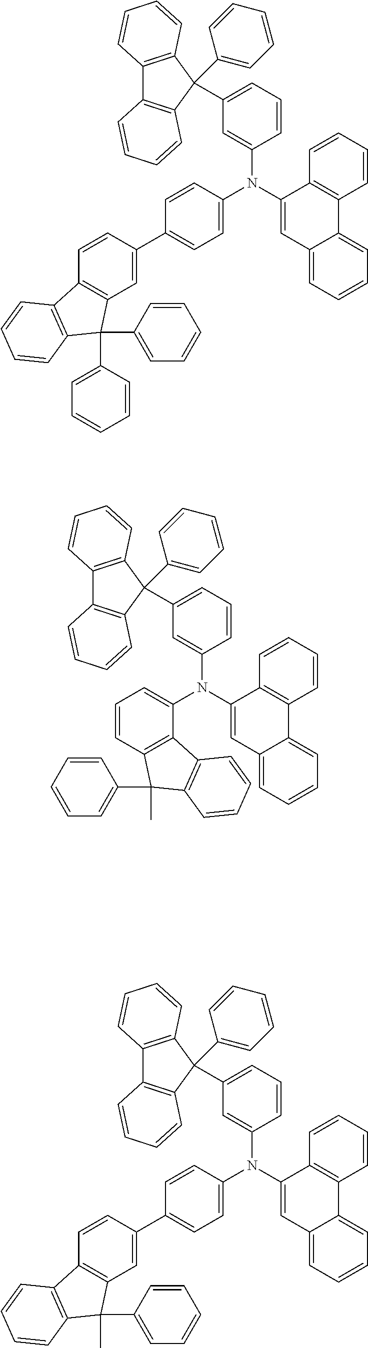 [SMILES: c1ccc(C2(c3cccc(N(c4ccc(-c5ccc6c(c5)C(c5ccccc5)(c5ccccc5)c5ccccc5-6)cc4)c4cc5ccccc5c5ccccc45)c3)c3ccccc3-c3ccccc32)cc1 ; CC1(c2ccccc2)c2ccccc2-c2c(N(c3cccc(C4(c5ccccc5)c5ccccc5-c5ccccc54)c3)c3cc4ccccc4c4ccccc34)cccc21 ; CC1(c2ccccc2)c2ccccc2-c2ccc(-c3ccc(N(c4cccc(C5(c6ccccc6)c6ccccc6-c6ccccc65)c4)c4cc5ccccc5c5ccccc45)cc3)cc21]

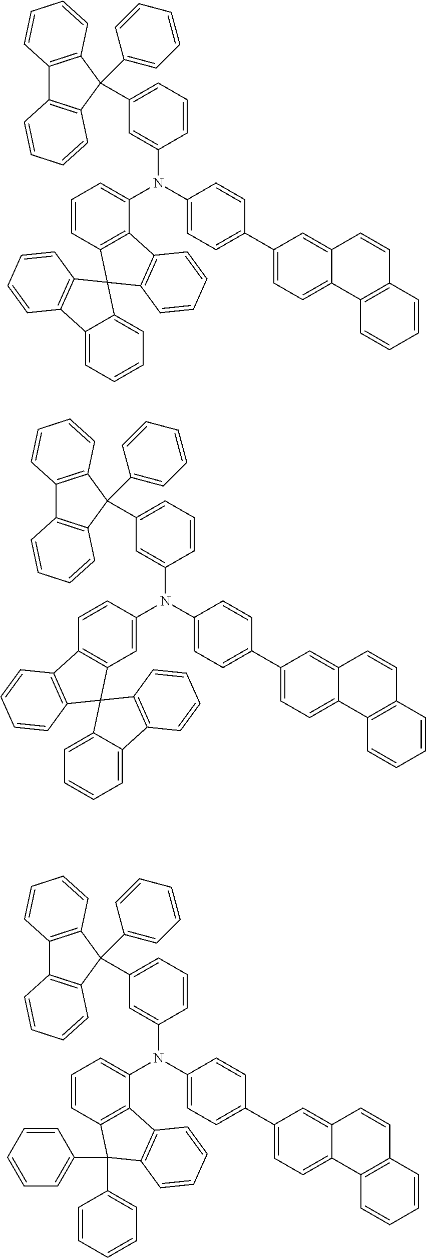 [SMILES: c1ccc(C2(c3cccc(N(c4ccc(-c5ccc6c(ccc7ccccc76)c5)cc4)c4cccc5c4-c4ccccc4C54c5ccccc5-c5ccccc54)c3)c3ccccc3-c3ccccc32)cc1 ; c1ccc(C2(c3cccc(N(c4ccc(-c5ccc6c(ccc7ccccc76)c5)cc4)c4ccc5c(c4)C4(c6ccccc6-c6ccccc64)c4ccccc4-5)c3)c3ccccc3-c3ccccc32)cc1 ; c1ccc(C2(c3cccc(N(c4ccc(-c5ccc6c(ccc7ccccc76)c5)cc4)c4cccc5c4-c4ccccc4C5(c4ccccc4)c4ccccc4)c3)c3ccccc3-c3ccccc32)cc1]

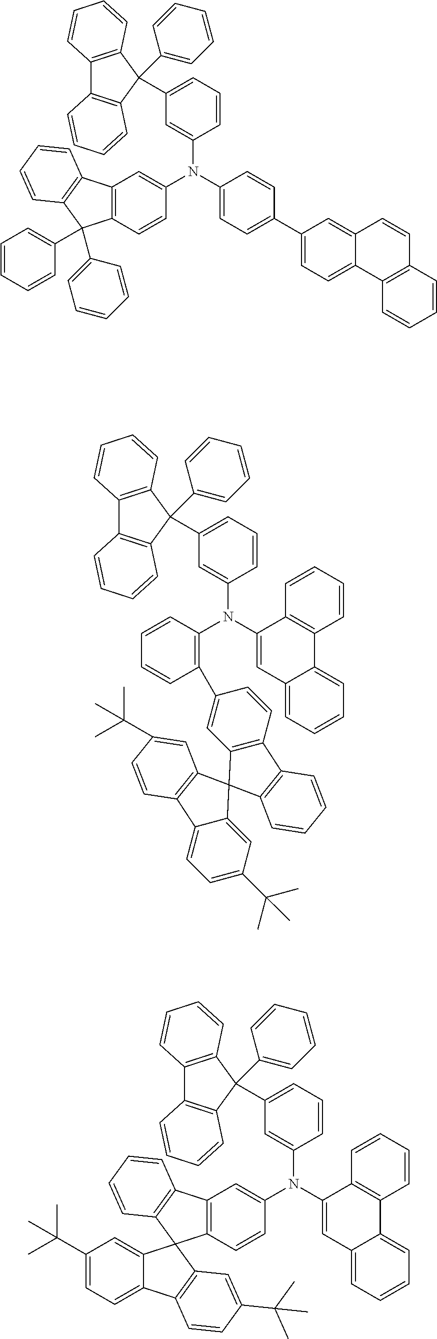 [SMILES: c1ccc(C2(c3cccc(N(c4ccc(-c5ccc6c(ccc7ccccc76)c5)cc4)c4ccc5c(c4)-c4ccccc4C5(c4ccccc4)c4ccccc4)c3)c3ccccc3-c3ccccc32)cc1 ; CC(C)(C)c1ccc2c(c1)C1(c3ccccc3-c3ccc(-c4ccccc4N(c4cccc(C5(c6ccccc6)c6ccccc6-c6ccccc65)c4)c4cc5ccccc5c5ccccc45)cc31)c1cc(C(C)(C)C)ccc1-2 ; CC(C)(C)c1ccc2c(c1)C1(c3ccccc3-c3cc(N(c4cccc(C5(c6ccccc6)c6ccccc6-c6ccccc65)c4)c4cc5ccccc5c5ccccc45)ccc31)c1cc(C(C)(C)C)ccc1-2]

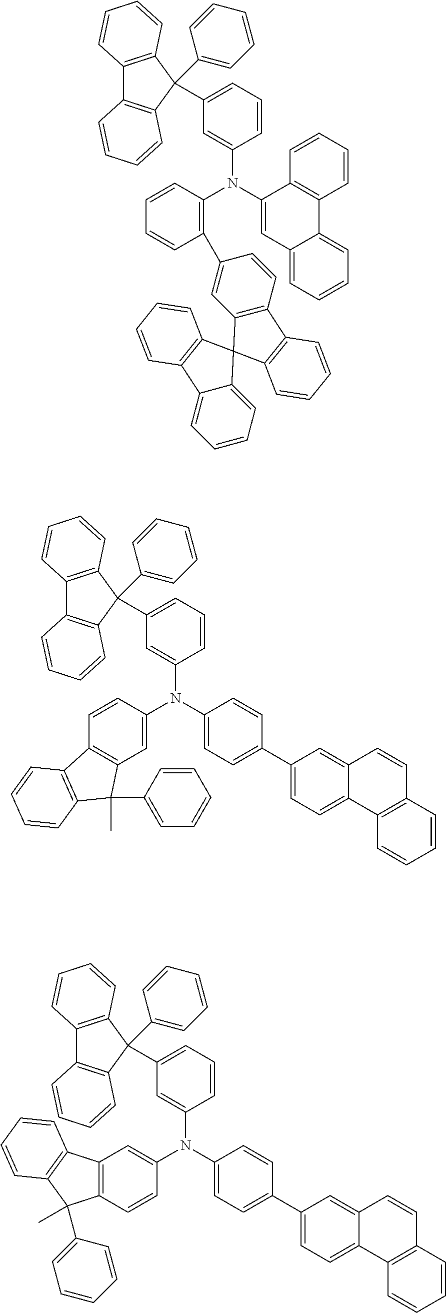 [SMILES: c1ccc(C2(c3cccc(N(c4ccccc4-c4ccc5c(c4)C4(c6ccccc6-c6ccccc64)c4ccccc4-5)c4cc5ccccc5c5ccccc45)c3)c3ccccc3-c3ccccc32)cc1 ; CC1(c2ccccc2)c2ccccc2-c2ccc(N(c3ccc(-c4ccc5c(ccc6ccccc65)c4)cc3)c3cccc(C4(c5ccccc5)c5ccccc5-c5ccccc54)c3)cc21 ; CC1(c2ccccc2)c2ccccc2-c2cc(N(c3ccc(-c4ccc5c(ccc6ccccc65)c4)cc3)c3cccc(C4(c5ccccc5)c5ccccc5-c5ccccc54)c3)ccc21]

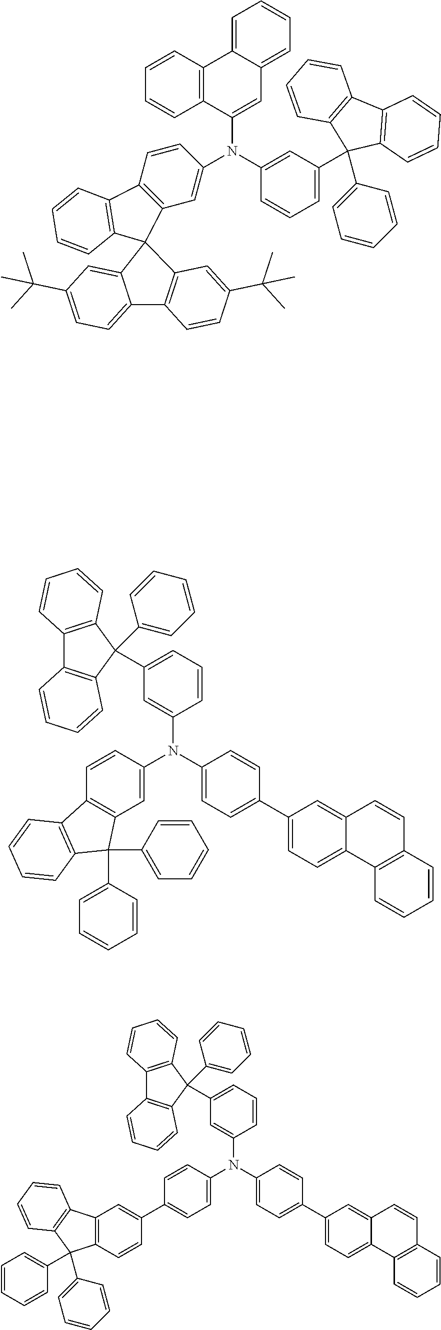 [SMILES: CC(C)(C)c1ccc2c(c1)C1(c3ccccc3-c3ccc(N(c4cccc(C5(c6ccccc6)c6ccccc6-c6ccccc65)c4)c4cc5ccccc5c5ccccc45)cc31)c1cc(C(C)(C)C)ccc1-2 ; c1ccc(C2(c3cccc(N(c4ccc(-c5ccc6c(ccc7ccccc76)c5)cc4)c4ccc5c(c4)C(c4ccccc4)(c4ccccc4)c4ccccc4-5)c3)c3ccccc3-c3ccccc32)cc1 ; c1ccc(C2(c3cccc(N(c4ccc(-c5ccc6c(c5)-c5ccccc5C6(c5ccccc5)c5ccccc5)cc4)c4ccc(-c5ccc6c(ccc7ccccc76)c5)cc4)c3)c3ccccc3-c3ccccc32)cc1]

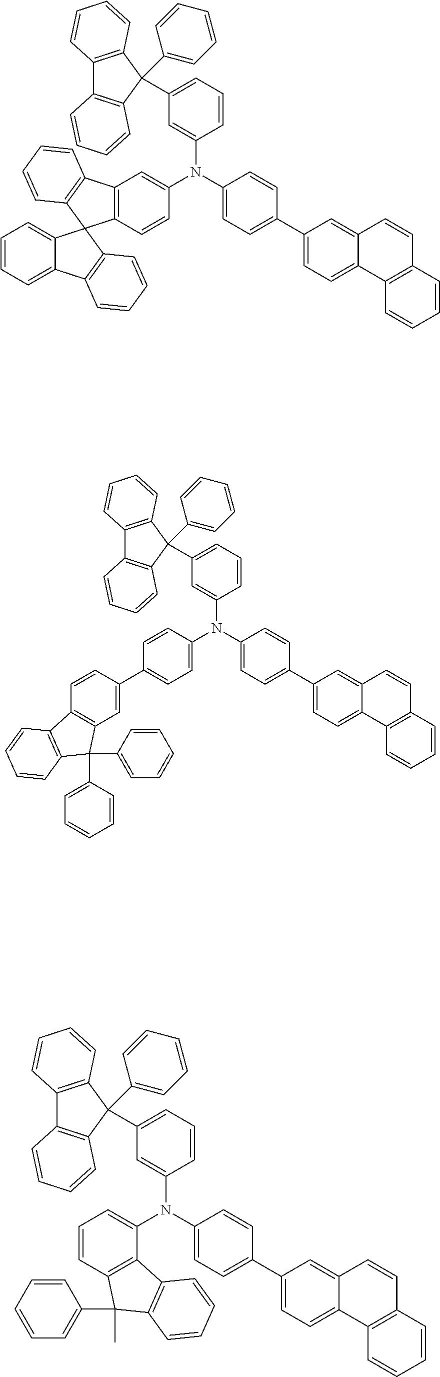 [SMILES: c1ccc(C2(c3cccc(N(c4ccc(-c5ccc6c(ccc7ccccc76)c5)cc4)c4ccc5c(c4)-c4ccccc4C54c5ccccc5-c5ccccc54)c3)c3ccccc3-c3ccccc32)cc1 ; c1ccc(C2(c3cccc(N(c4ccc(-c5ccc6c(c5)C(c5ccccc5)(c5ccccc5)c5ccccc5-6)cc4)c4ccc(-c5ccc6c(ccc7ccccc76)c5)cc4)c3)c3ccccc3-c3ccccc32)cc1 ; CC1(c2ccccc2)c2ccccc2-c2c(N(c3ccc(-c4ccc5c(ccc6ccccc65)c4)cc3)c3cccc(C4(c5ccccc5)c5ccccc5-c5ccccc54)c3)cccc21]

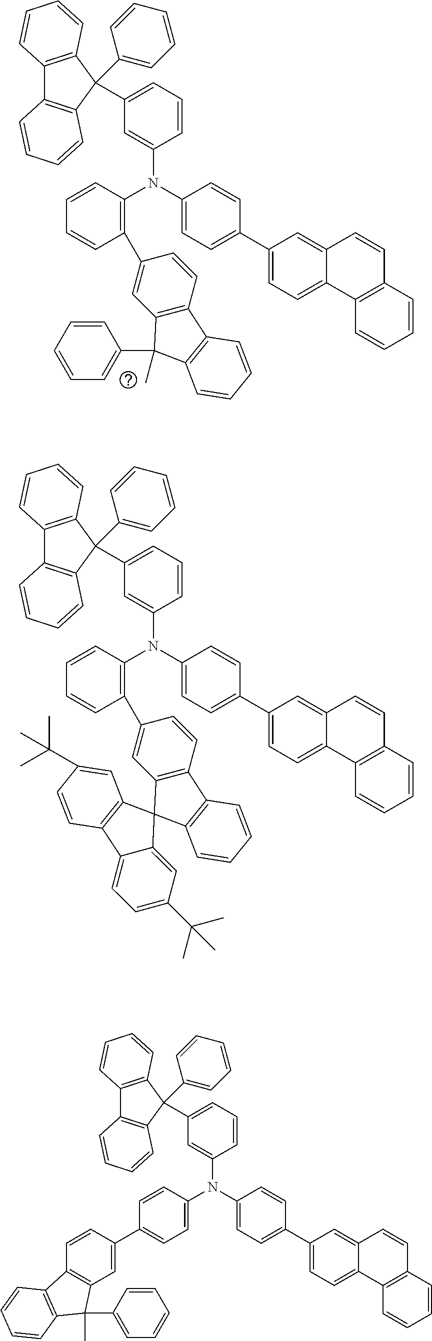 [SMILES: CC1(c2ccccc2)c2ccccc2-c2ccc(-c3ccccc3N(c3ccc(-c4ccc5c(ccc6ccccc65)c4)cc3)c3cccc(C4(c5ccccc5)c5ccccc5-c5ccccc54)c3)cc21 ; CC(C)(C)c1ccc2c(c1)C1(c3ccccc3-c3ccc(-c4ccccc4N(c4ccc(-c5ccc6c(ccc7ccccc76)c5)cc4)c4cccc(C5(c6ccccc6)c6ccccc6-c6ccccc65)c4)cc31)c1cc(C(C)(C)C)ccc1-2 ; CC1(c2ccccc2)c2ccccc2-c2ccc(-c3ccc(N(c4ccc(-c5ccc6c(ccc7ccccc76)c5)cc4)c4cccc(C5(c6ccccc6)c6ccccc6-c6ccccc65)c4)cc3)cc21]

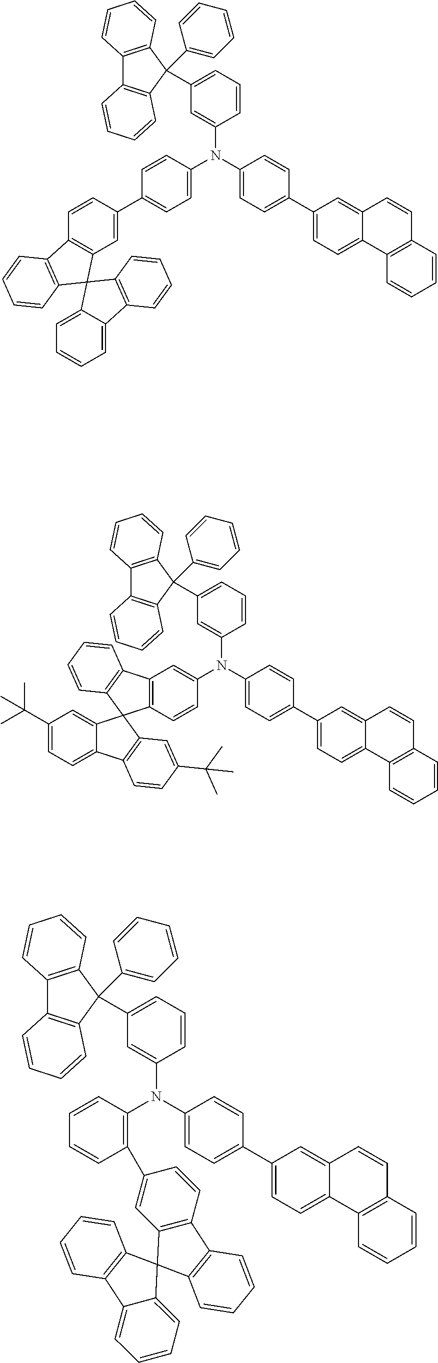 [SMILES: c1ccc(C2(c3cccc(N(c4ccc(-c5ccc6c(c5)C5(c7ccccc7-c7ccccc75)c5ccccc5-6)cc4)c4ccc(-c5ccc6c(ccc7ccccc76)c5)cc4)c3)c3ccccc3-c3ccccc32)cc1 ; CC(C)(C)c1ccc2c(c1)C1(c3ccccc3-c3cc(N(c4ccc(-c5ccc6c(ccc7ccccc76)c5)cc4)c4cccc(C5(c6ccccc6)c6ccccc6-c6ccccc65)c4)ccc31)c1cc(C(C)(C)C)ccc1-2 ; c1ccc(C2(c3cccc(N(c4ccc(-c5ccc6c(ccc7ccccc76)c5)cc4)c4ccccc4-c4ccc5c(c4)C4(c6ccccc6-c6ccccc64)c4ccccc4-5)c3)c3ccccc3-c3ccccc32)cc1]

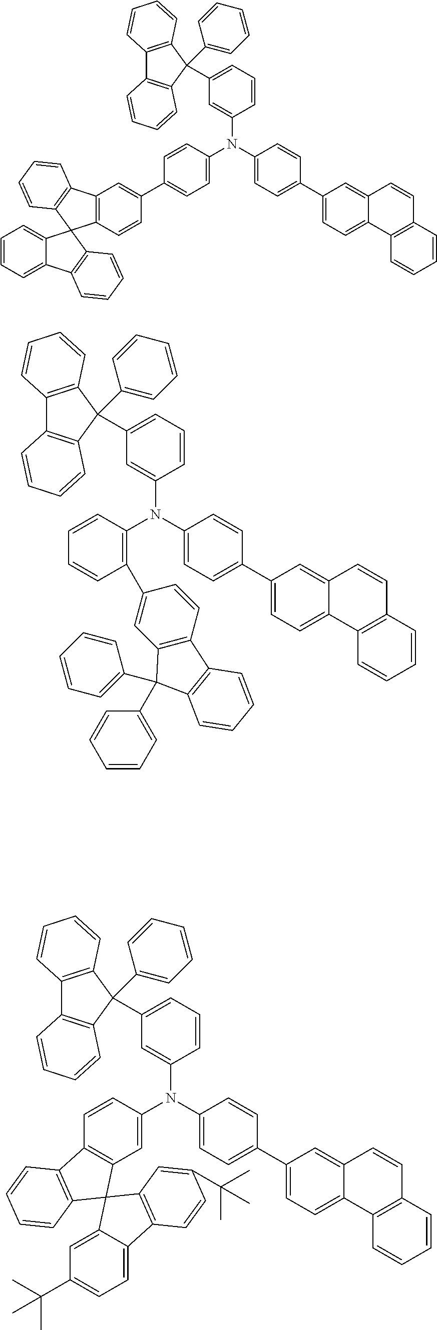

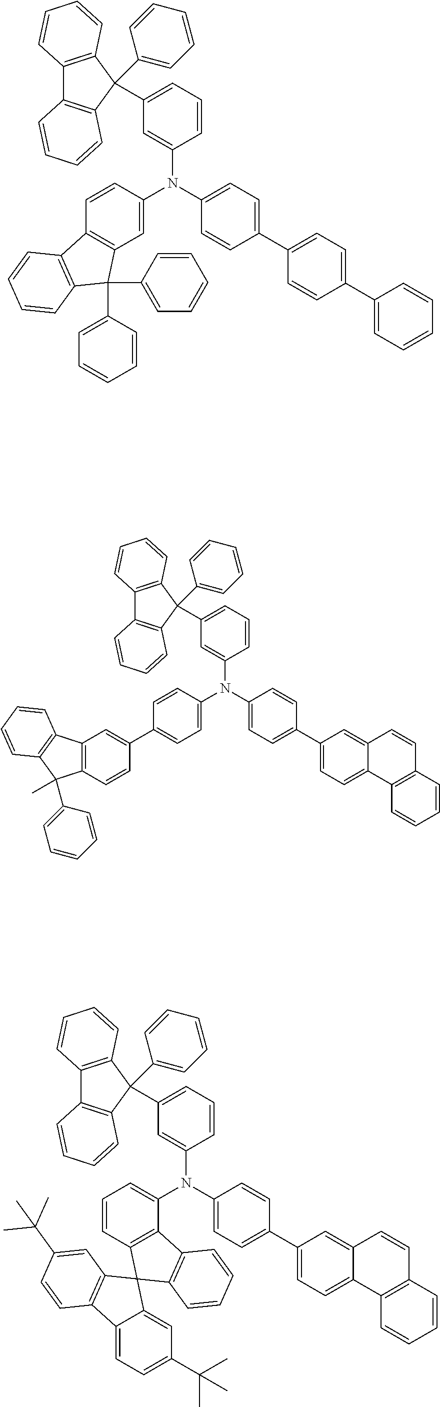 [SMILES: c1ccc(-c2ccc(-c3ccc(N(c4cccc(C5(c6ccccc6)c6ccccc6-c6ccccc65)c4)c4ccc5c(c4)C(c4ccccc4)(c4ccccc4)c4ccccc4-5)cc3)cc2)cc1 ; CC1(c2ccccc2)c2ccccc2-c2cc(-c3ccc(N(c4ccc(-c5ccc6c(ccc7ccccc76)c5)cc4)c4cccc(C5(c6ccccc6)c6ccccc6-c6ccccc65)c4)cc3)ccc21 ; CC(C)(C)c1ccc2c(c1)C1(c3cc(C(C)(C)C)ccc3-2)c2ccccc2-c2c(N(c3ccc(-c4ccc5c(ccc6ccccc65)c4)cc3)c3cccc(C4(c5ccccc5)c5ccccc5-c5ccccc54)c3)cccc21]

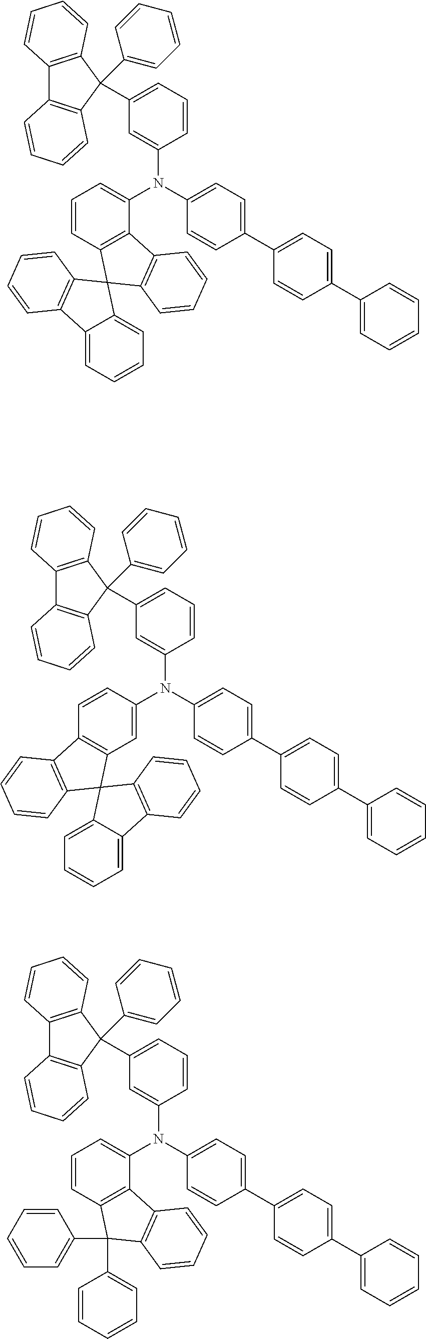 [SMILES: c1ccc(-c2ccc(-c3ccc(N(c4cccc(C5(c6ccccc6)c6ccccc6-c6ccccc65)c4)c4cccc5c4-c4ccccc4C54c5ccccc5-c5ccccc54)cc3)cc2)cc1 ; c1ccc(-c2ccc(-c3ccc(N(c4cccc(C5(c6ccccc6)c6ccccc6-c6ccccc65)c4)c4ccc5c(c4)C4(c6ccccc6-c6ccccc64)c4ccccc4-5)cc3)cc2)cc1 ; c1ccc(-c2ccc(-c3ccc(N(c4cccc(C5(c6ccccc6)c6ccccc6-c6ccccc65)c4)c4cccc5c4-c4ccccc4C5(c4ccccc4)c4ccccc4)cc3)cc2)cc1]

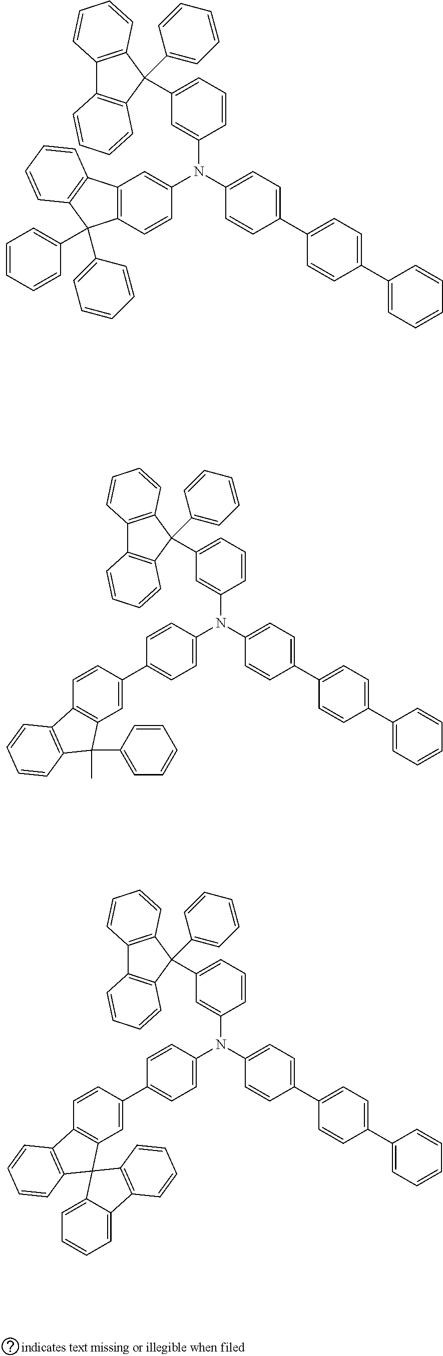 [SMILES: c1ccc(-c2ccc(-c3ccc(N(c4cccc(C5(c6ccccc6)c6ccccc6-c6ccccc65)c4)c4ccc5c(c4)-c4ccccc4C5(c4ccccc4)c4ccccc4)cc3)cc2)cc1 ; CC1(c2ccccc2)c2ccccc2-c2ccc(-c3ccc(N(c4ccc(-c5ccc(-c6ccccc6)cc5)cc4)c4cccc(C5(c6ccccc6)c6ccccc6-c6ccccc65)c4)cc3)cc21 ; c1ccc(-c2ccc(-c3ccc(N(c4ccc(-c5ccc6c(c5)C5(c7ccccc7-c7ccccc75)c5ccccc5-6)cc4)c4cccc(C5(c6ccccc6)c6ccccc6-c6ccccc65)c4)cc3)cc2)cc1]

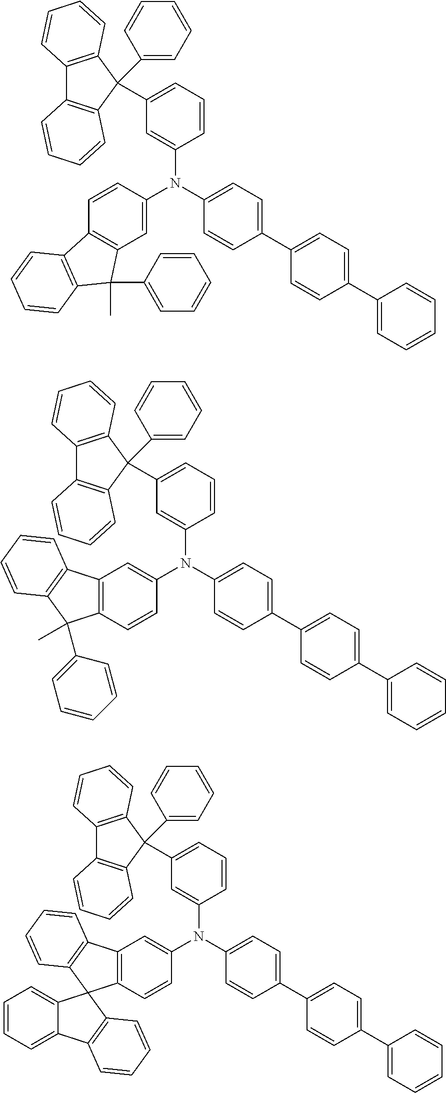 [SMILES: CC1(c2ccccc2)c2ccccc2-c2ccc(N(c3ccc(-c4ccc(-c5ccccc5)cc4)cc3)c3cccc(C4(c5ccccc5)c5ccccc5-c5ccccc54)c3)cc21 ; CC1(c2ccccc2)c2ccccc2-c2cc(N(c3ccc(-c4ccc(-c5ccccc5)cc4)cc3)c3cccc(C4(c5ccccc5)c5ccccc5-c5ccccc54)c3)ccc21 ; c1ccc(-c2ccc(-c3ccc(N(c4cccc(C5(c6ccccc6)c6ccccc6-c6ccccc65)c4)c4ccc5c(c4)-c4ccccc4C54c5ccccc5-c5ccccc54)cc3)cc2)cc1]

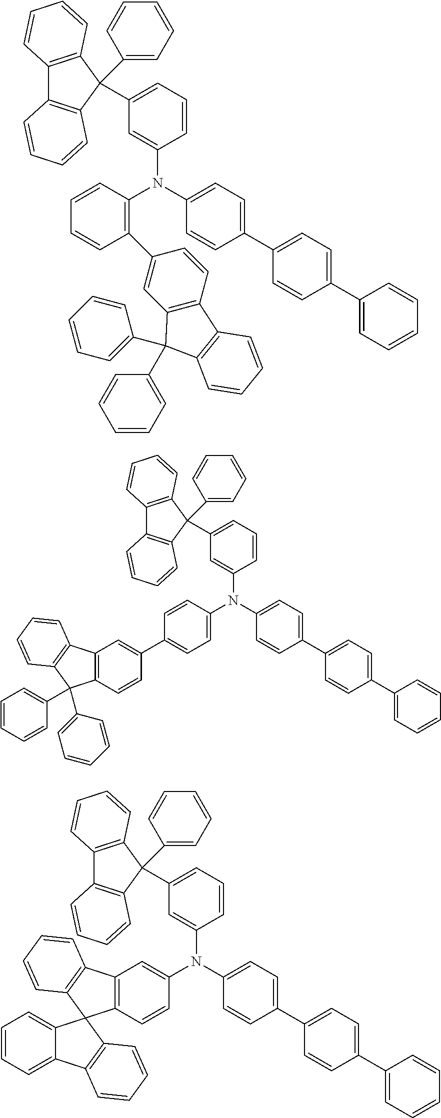

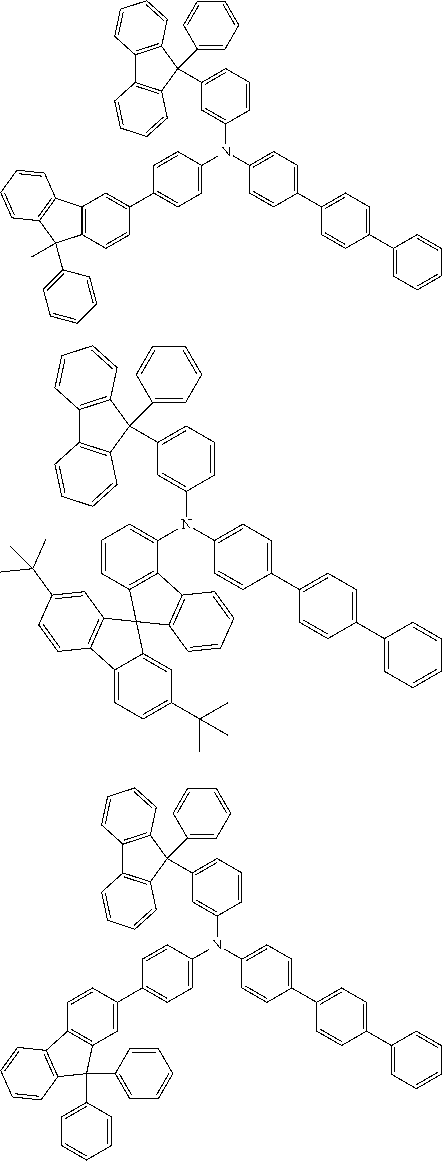

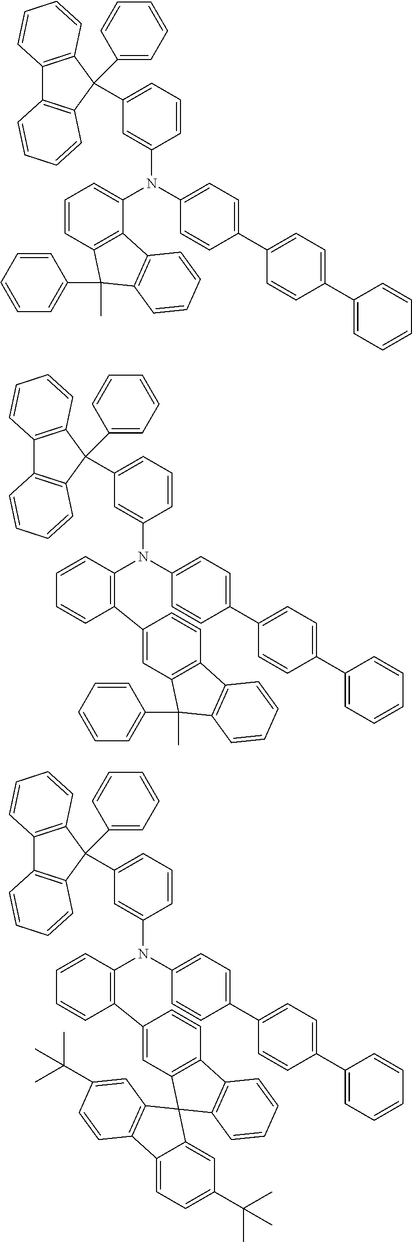

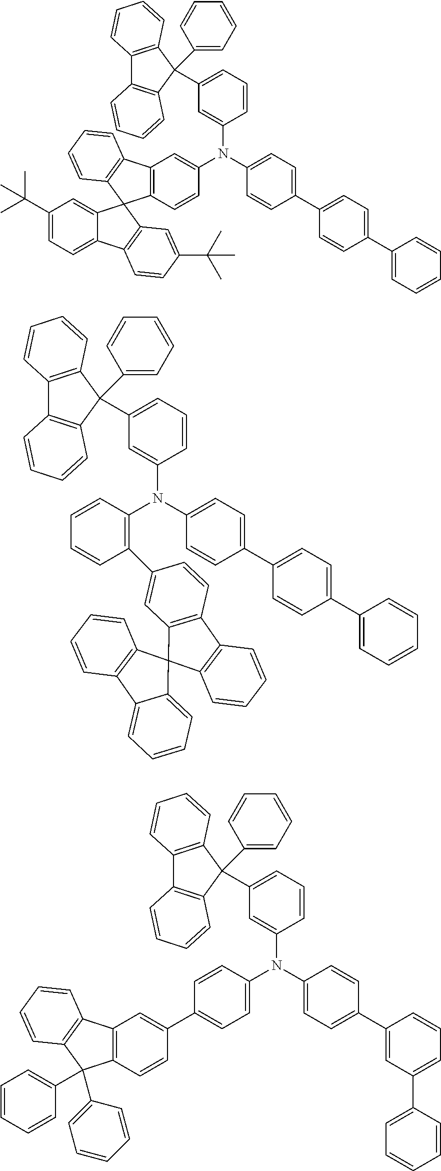

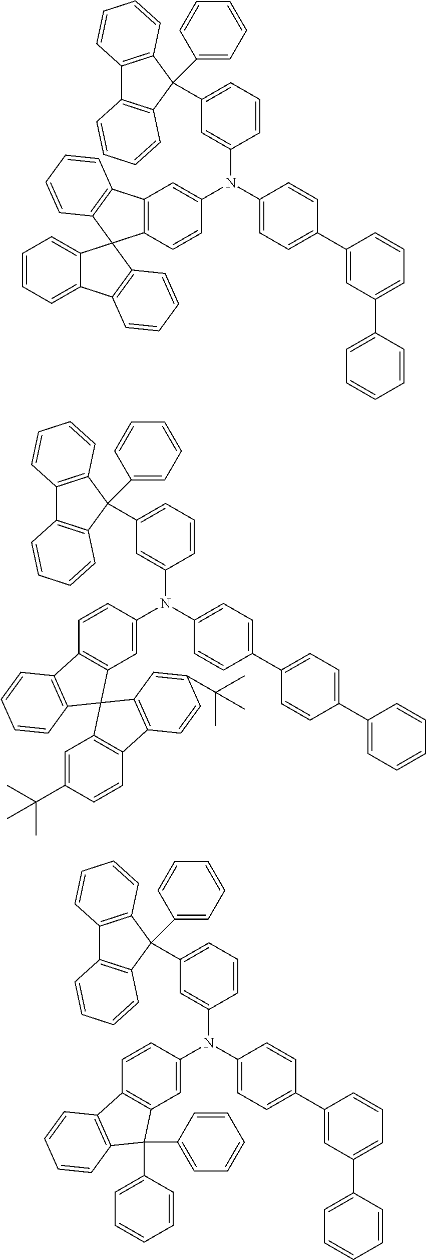 [SMILES: c1ccc(-c2cccc(-c3ccc(N(c4cccc(C5(c6ccccc6)c6ccccc6-c6ccccc65)c4)c4ccc5c(c4)-c4ccccc4C54c5ccccc5-c5ccccc54)cc3)c2)cc1 ; CC(C)(C)c1ccc2c(c1)C1(c3ccccc3-c3ccc(N(c4ccc(-c5ccc(-c6ccccc6)cc5)cc4)c4cccc(C5(c6ccccc6)c6ccccc6-c6ccccc65)c4)cc31)c1cc(C(C)(C)C)ccc1-2 ; c1ccc(-c2cccc(-c3ccc(N(c4cccc(C5(c6ccccc6)c6ccccc6-c6ccccc65)c4)c4ccc5c(c4)C(c4ccccc4)(c4ccccc4)c4ccccc4-5)cc3)c2)cc1]

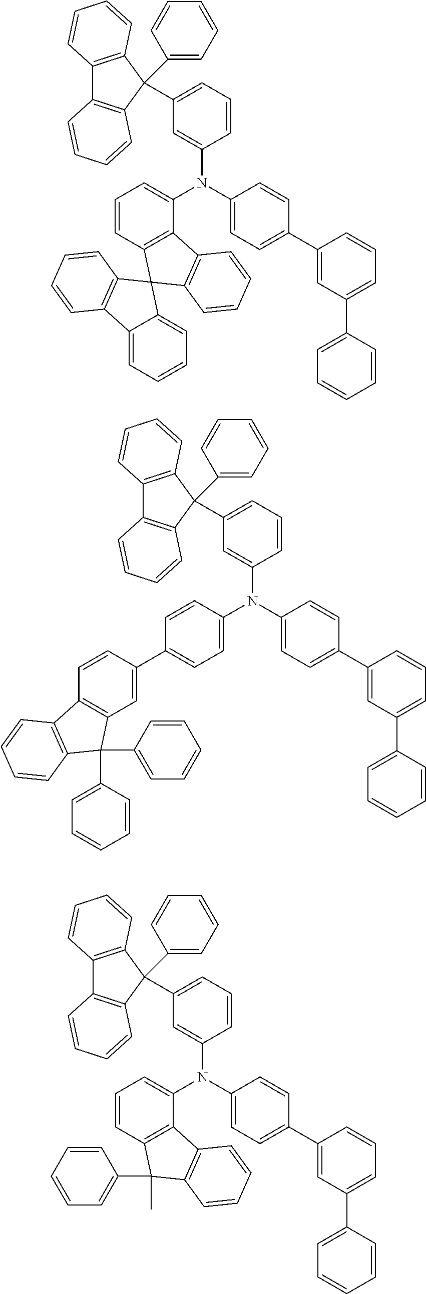

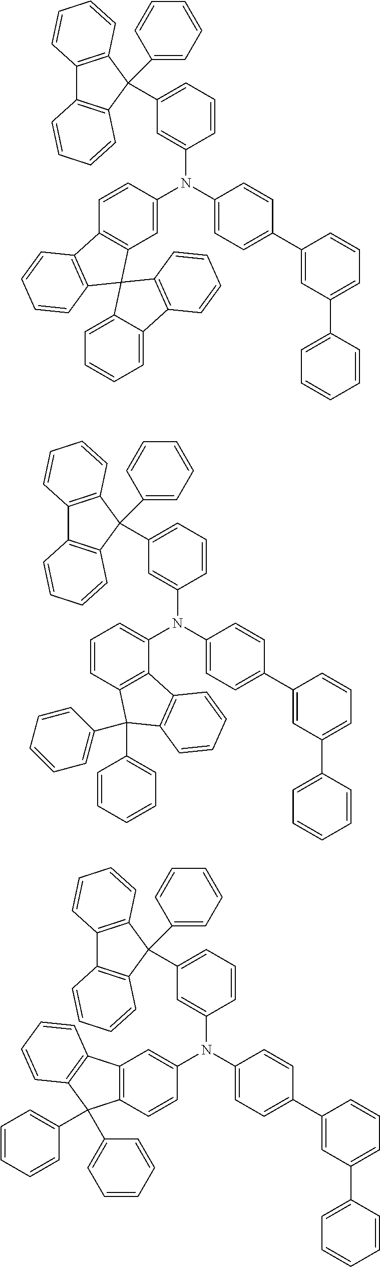 [SMILES: c1ccc(-c2cccc(-c3ccc(N(c4cccc(C5(c6ccccc6)c6ccccc6-c6ccccc65)c4)c4ccc5c(c4)C4(c6ccccc6-c6ccccc64)c4ccccc4-5)cc3)c2)cc1 ; c1ccc(-c2cccc(-c3ccc(N(c4cccc(C5(c6ccccc6)c6ccccc6-c6ccccc65)c4)c4cccc5c4-c4ccccc4C5(c4ccccc4)c4ccccc4)cc3)c2)cc1 ; c1ccc(-c2cccc(-c3ccc(N(c4cccc(C5(c6ccccc6)c6ccccc6-c6ccccc65)c4)c4ccc5c(c4)-c4ccccc4C5(c4ccccc4)c4ccccc4)cc3)c2)cc1]

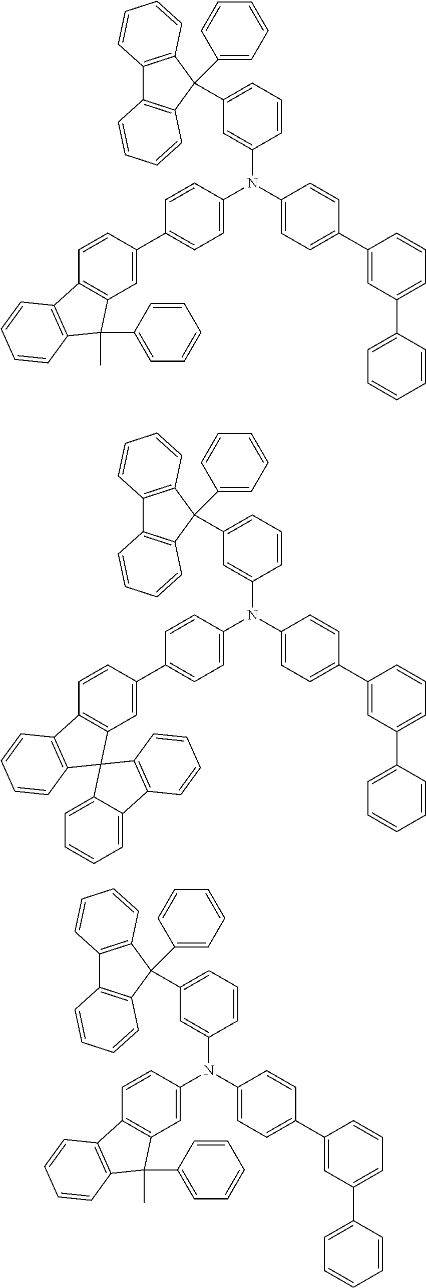

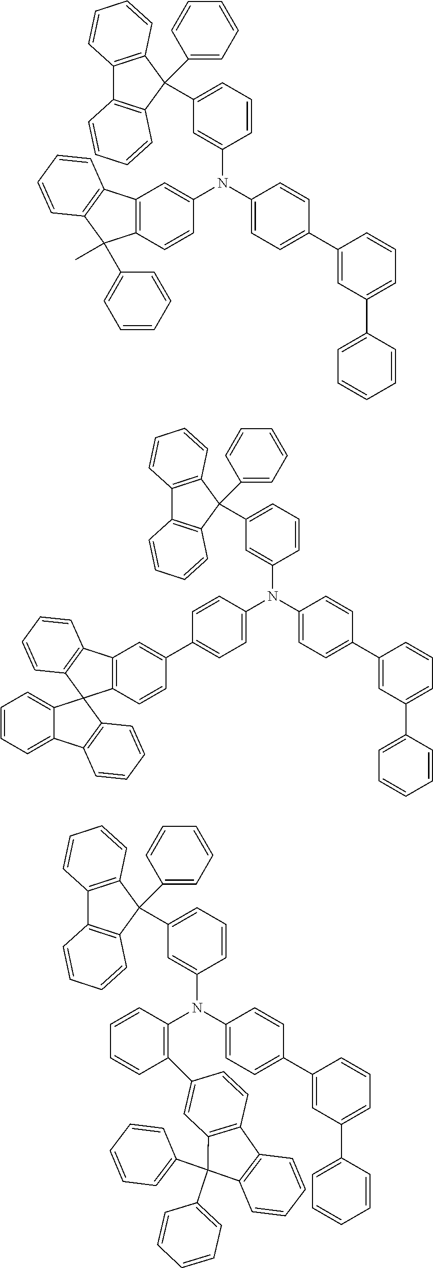 [SMILES: CC1(c2ccccc2)c2ccccc2-c2cc(N(c3ccc(-c4cccc(-c5ccccc5)c4)cc3)c3cccc(C4(c5ccccc5)c5ccccc5-c5ccccc54)c3)ccc21 ; c1ccc(-c2cccc(-c3ccc(N(c4ccc(-c5ccc6c(c5)-c5ccccc5C65c6ccccc6-c6ccccc65)cc4)c4cccc(C5(c6ccccc6)c6ccccc6-c6ccccc65)c4)cc3)c2)cc1 ; c1ccc(-c2cccc(-c3ccc(N(c4cccc(C5(c6ccccc6)c6ccccc6-c6ccccc65)c4)c4ccccc4-c4ccc5c(c4)C(c4ccccc4)(c4ccccc4)c4ccccc4-5)cc3)c2)cc1]

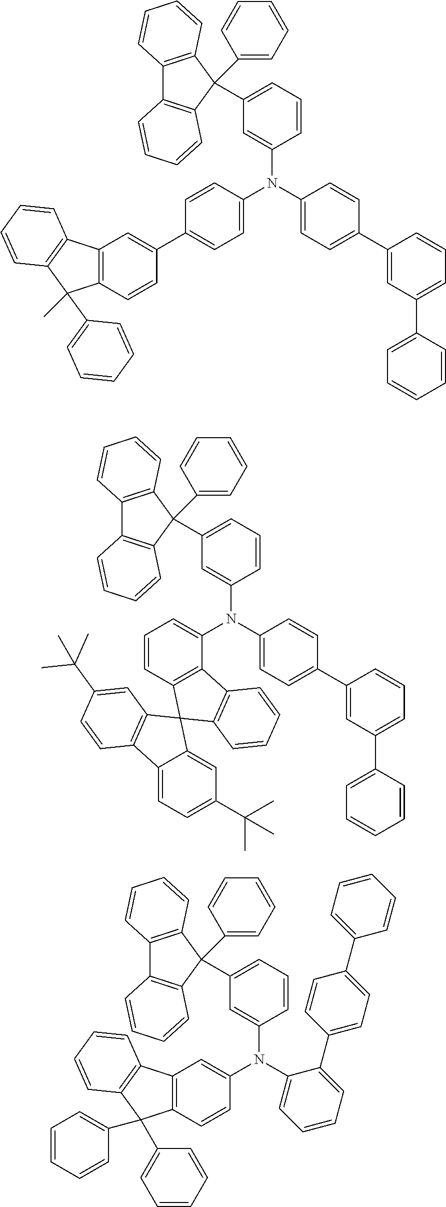

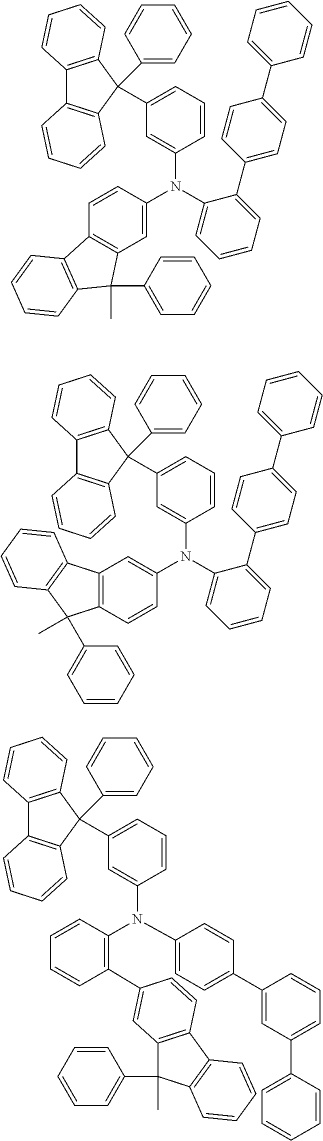

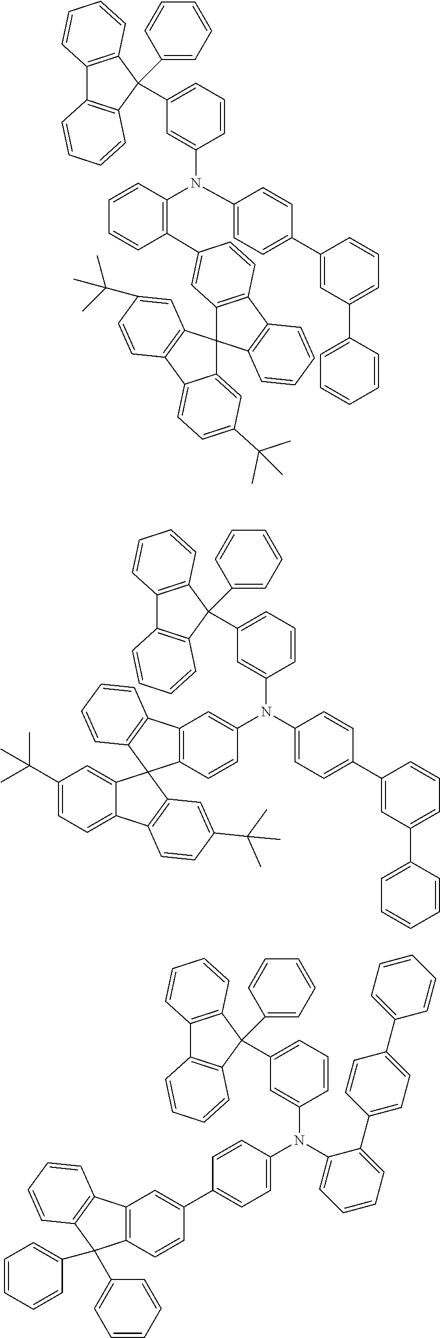

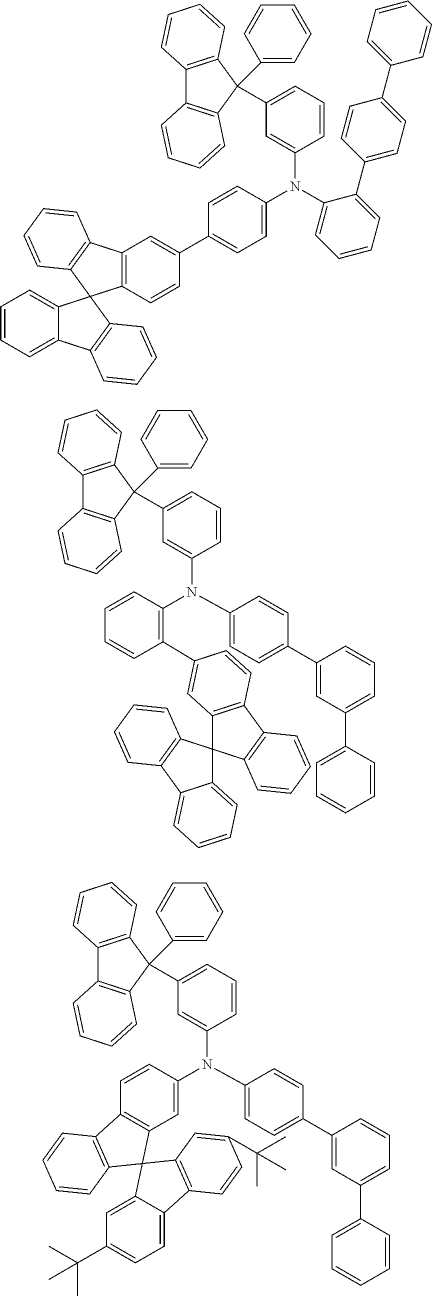

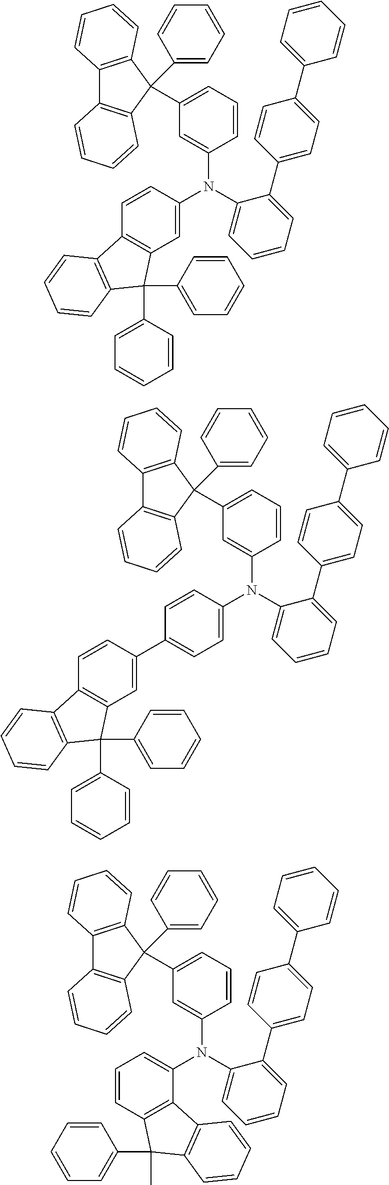

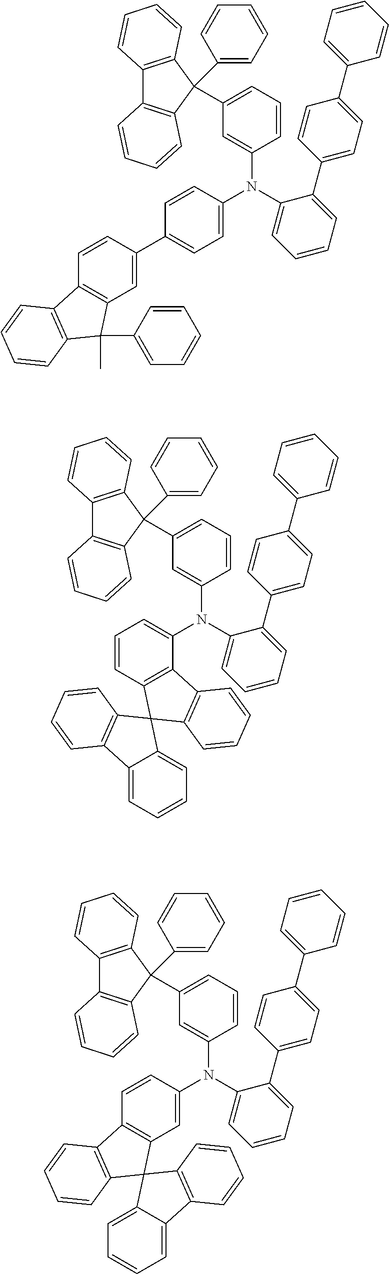 [SMILES: CC1(c2ccccc2)c2ccccc2-c2ccc(-c3ccc(N(c4cccc(C5(c6ccccc6)c6ccccc6-c6ccccc65)c4)c4ccccc4-c4ccc(-c5ccccc5)cc4)cc3)cc21 ; c1ccc(-c2ccc(-c3ccccc3N(c3cccc(C4(c5ccccc5)c5ccccc5-c5ccccc54)c3)c3cccc4c3-c3ccccc3C43c4ccccc4-c4ccccc43)cc2)cc1 ; c1ccc(-c2ccc(-c3ccccc3N(c3cccc(C4(c5ccccc5)c5ccccc5-c5ccccc54)c3)c3ccc4c(c3)C3(c5ccccc5-c5ccccc53)c3ccccc3-4)cc2)cc1]

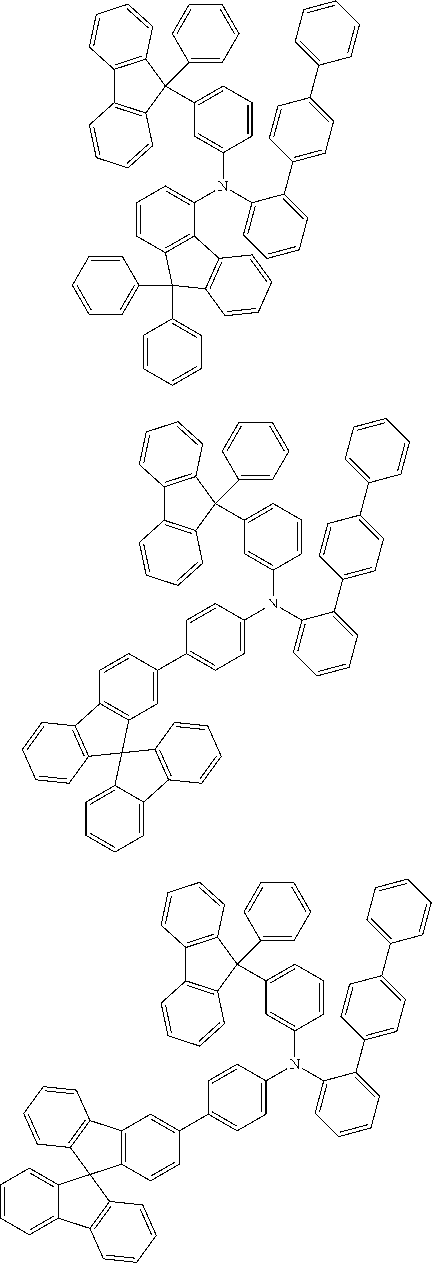

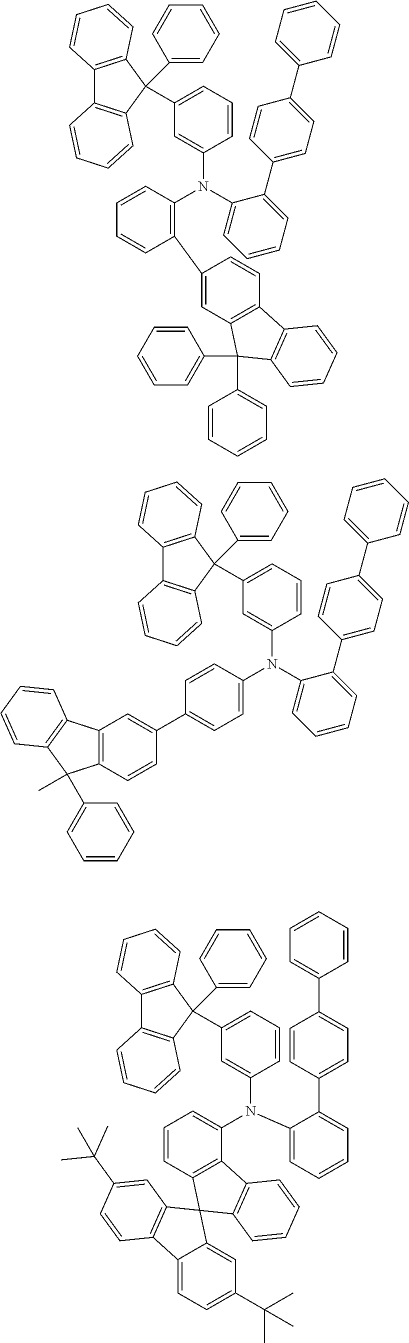

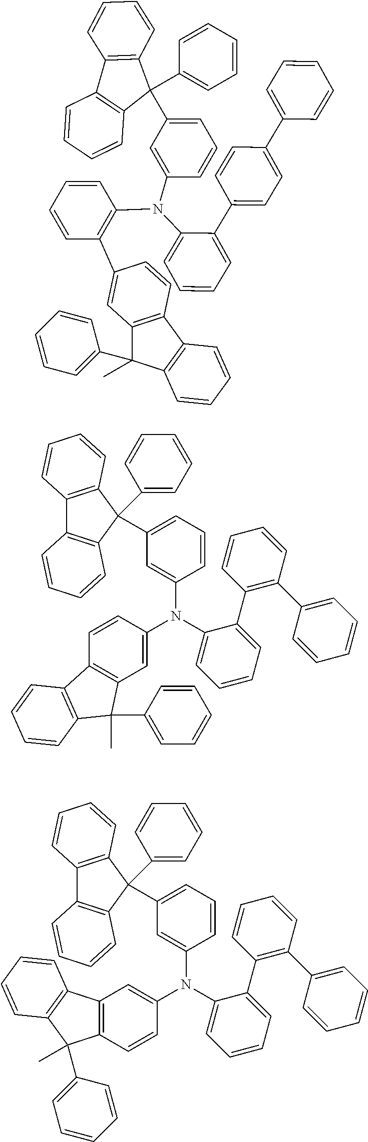

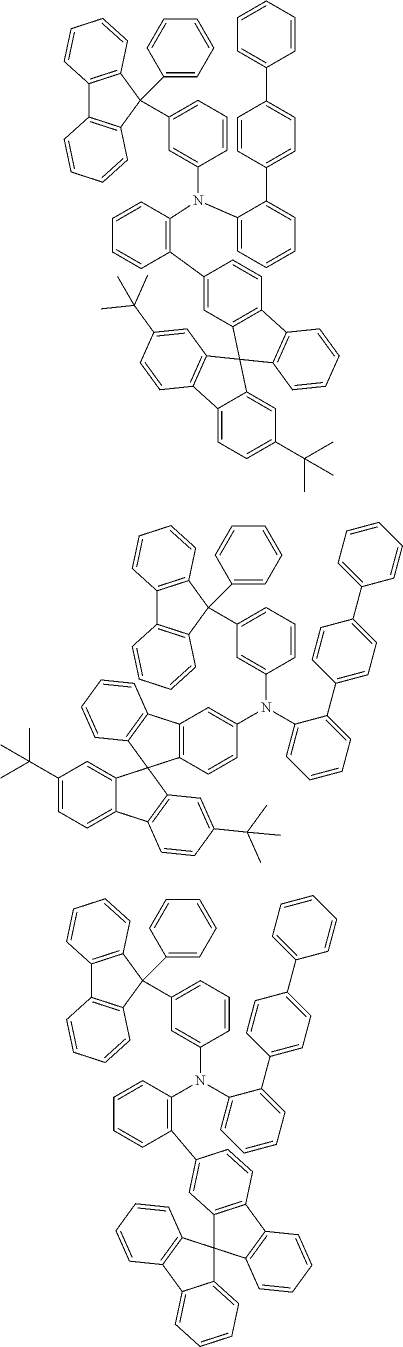

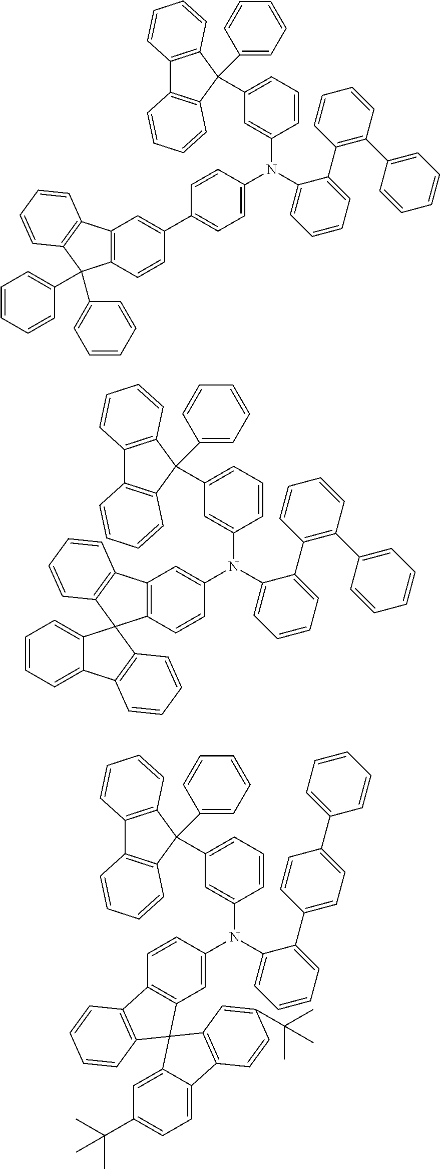

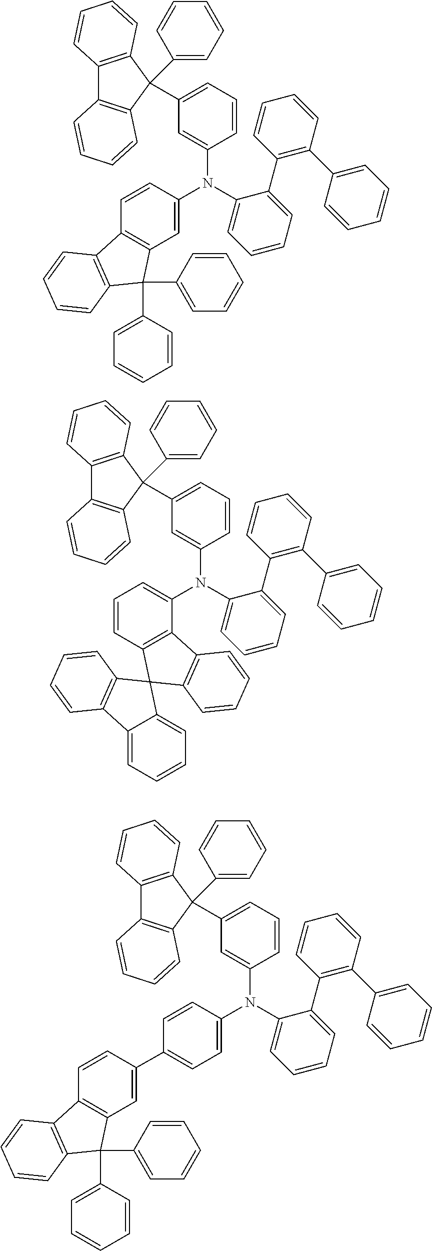

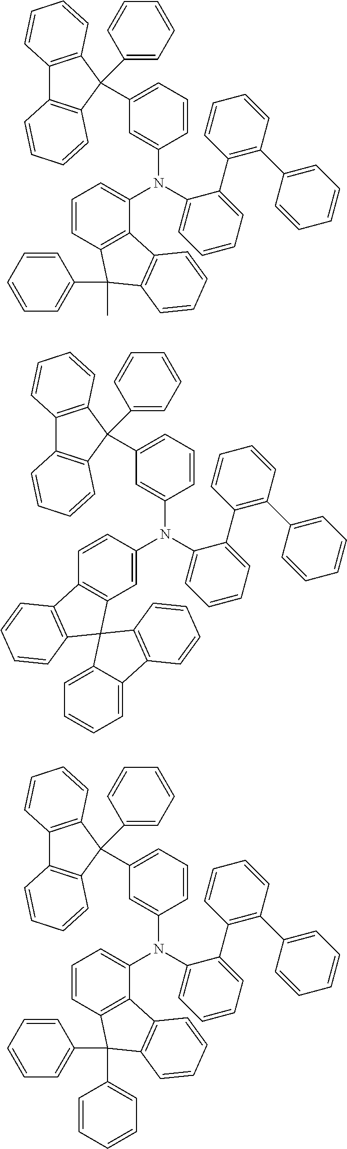

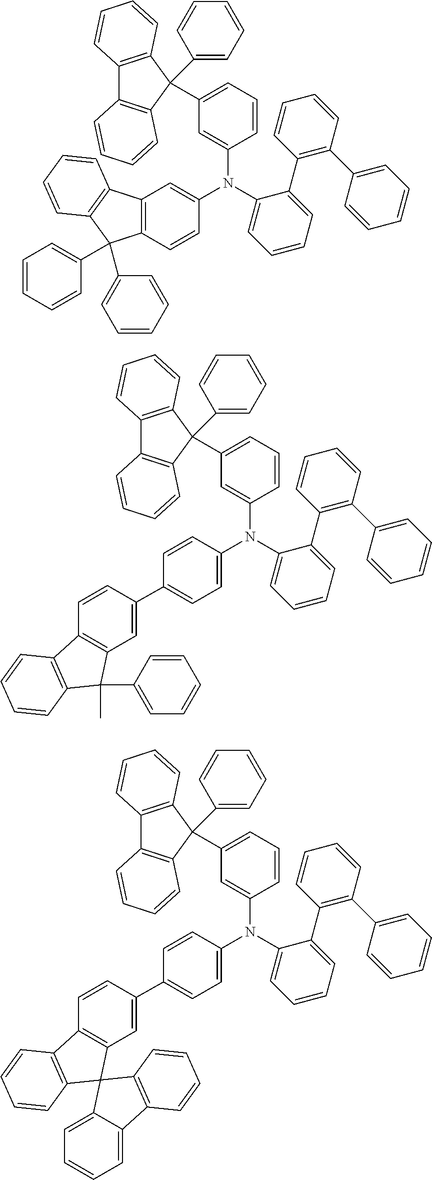

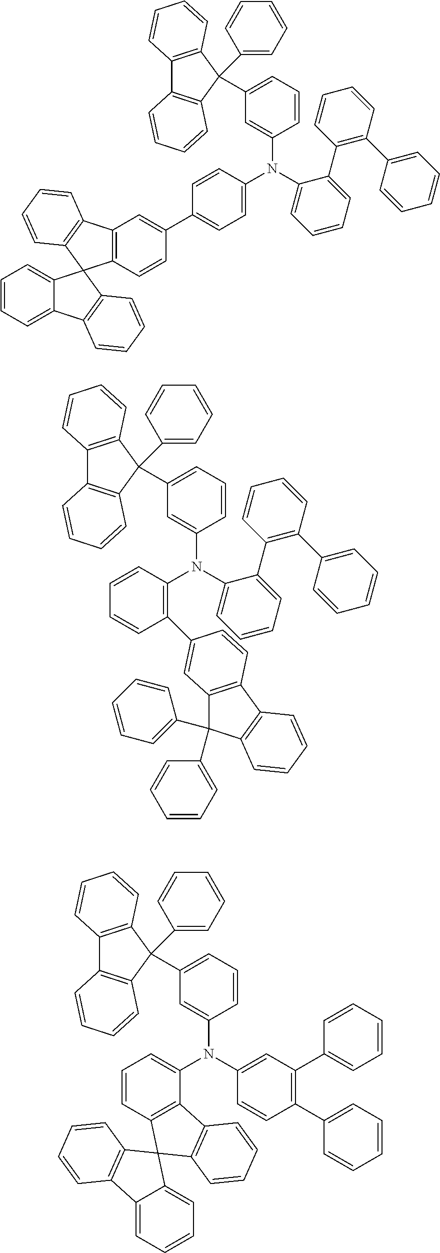

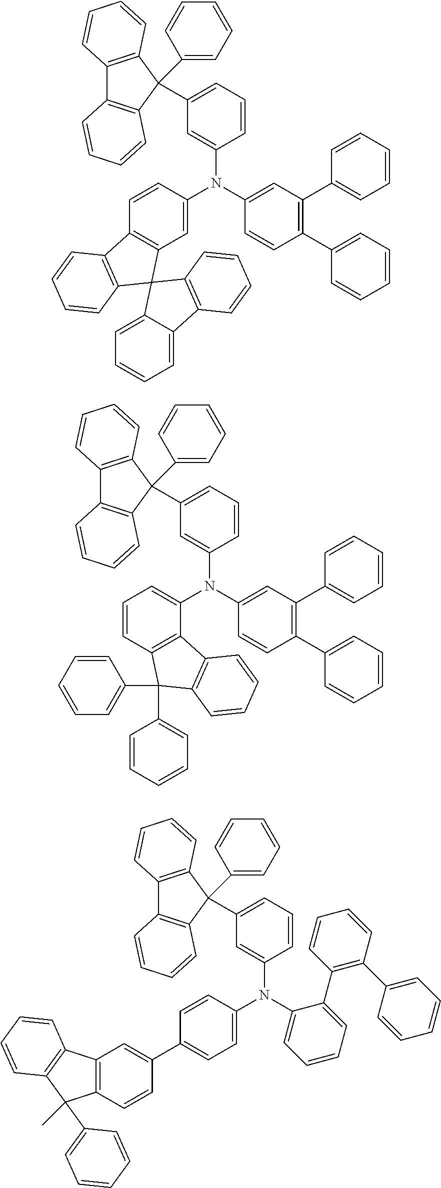

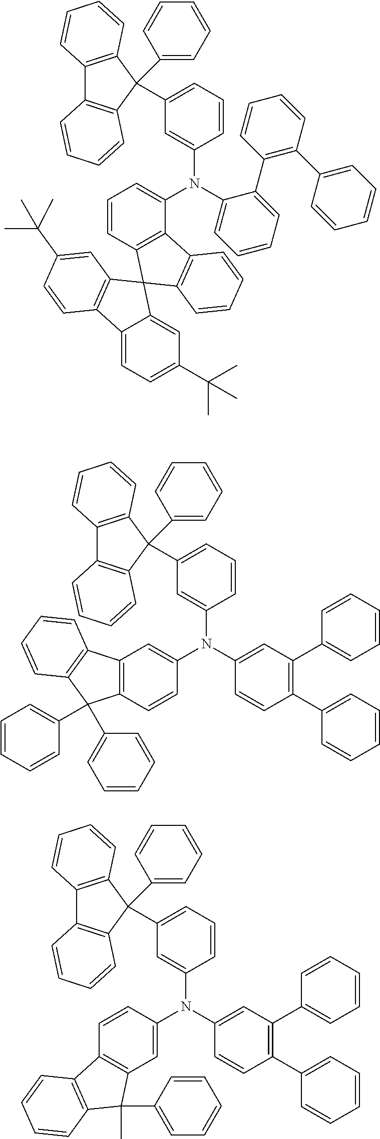

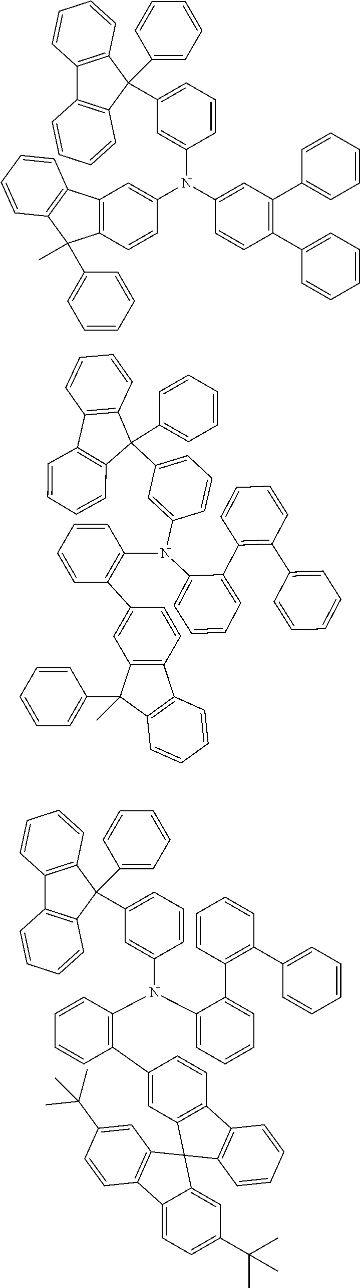

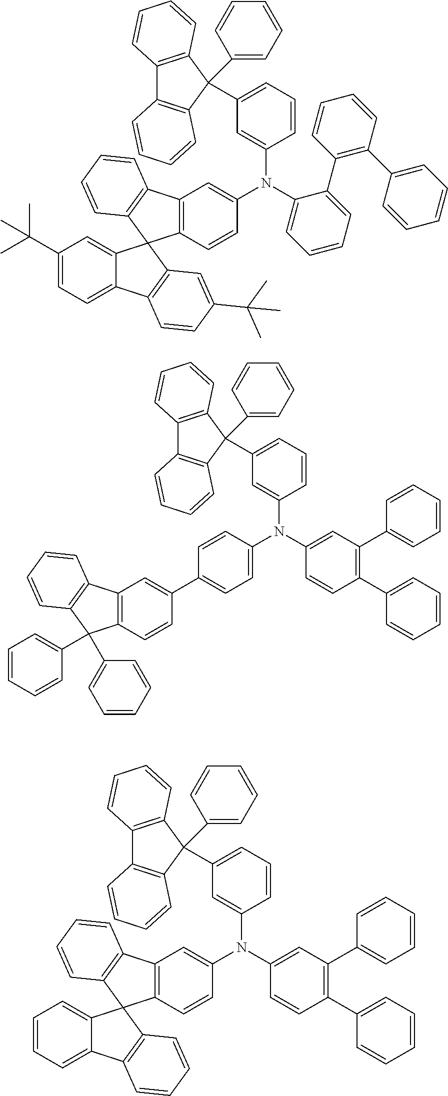

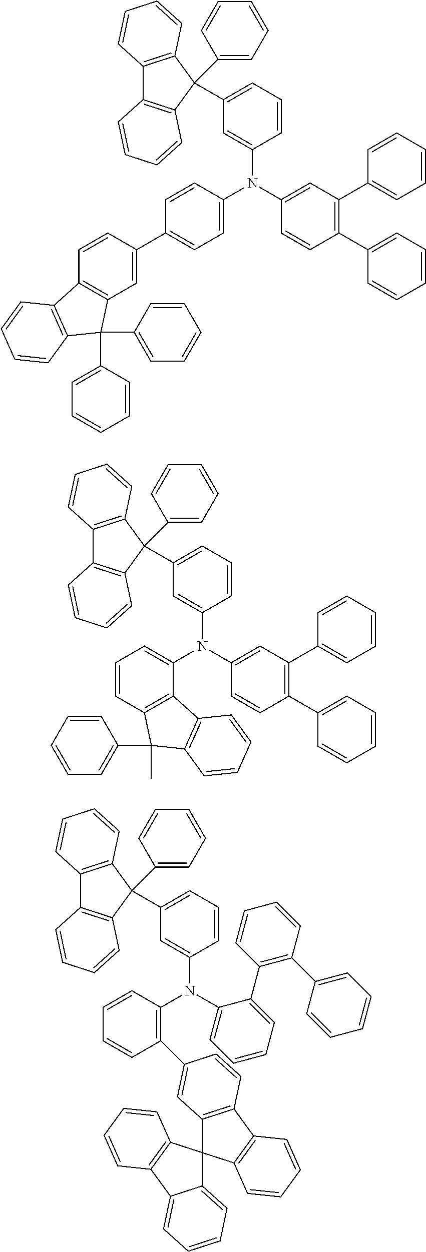

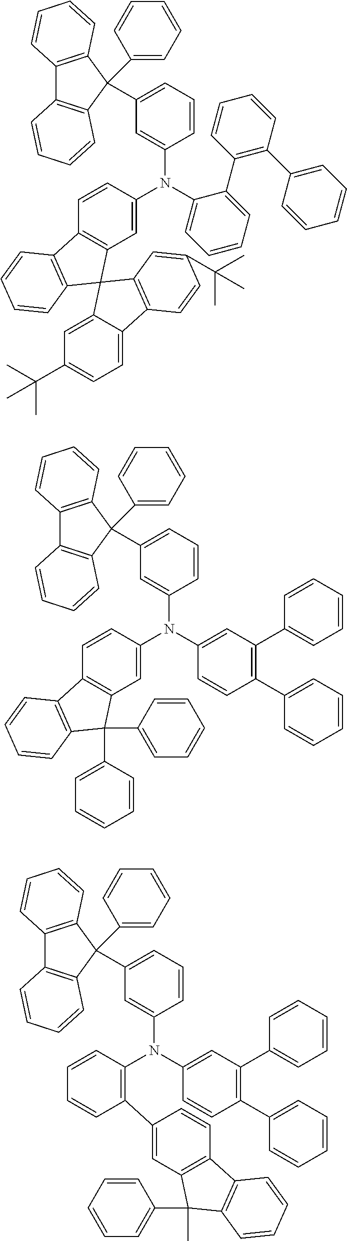

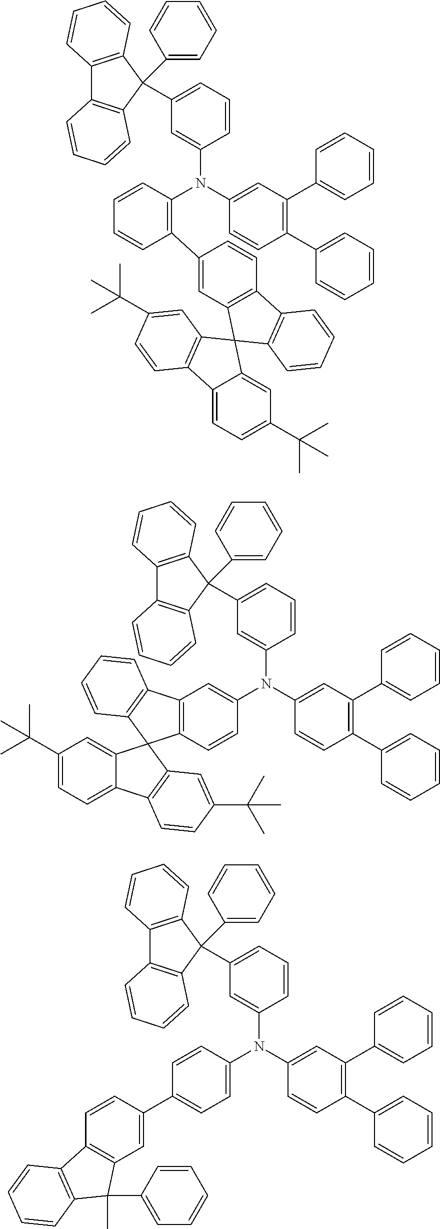

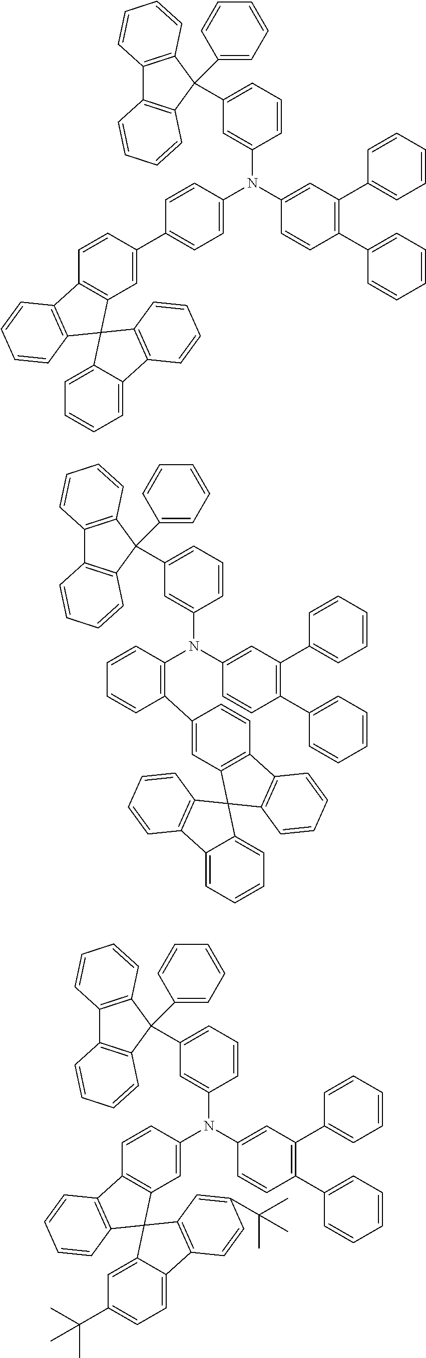

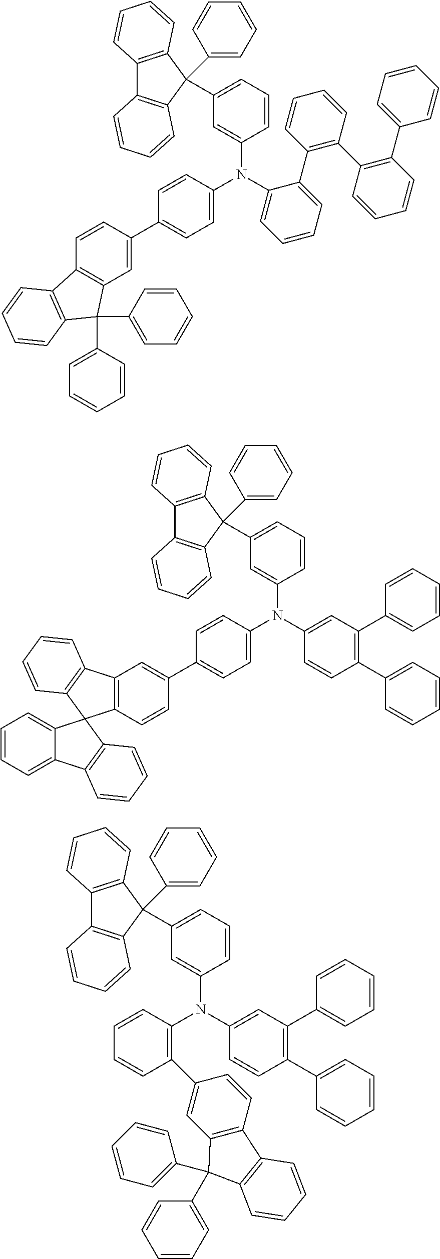

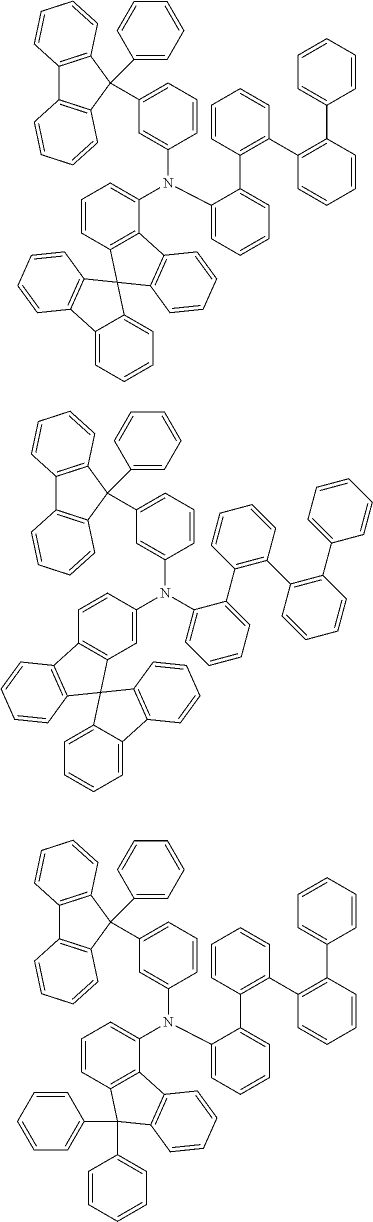

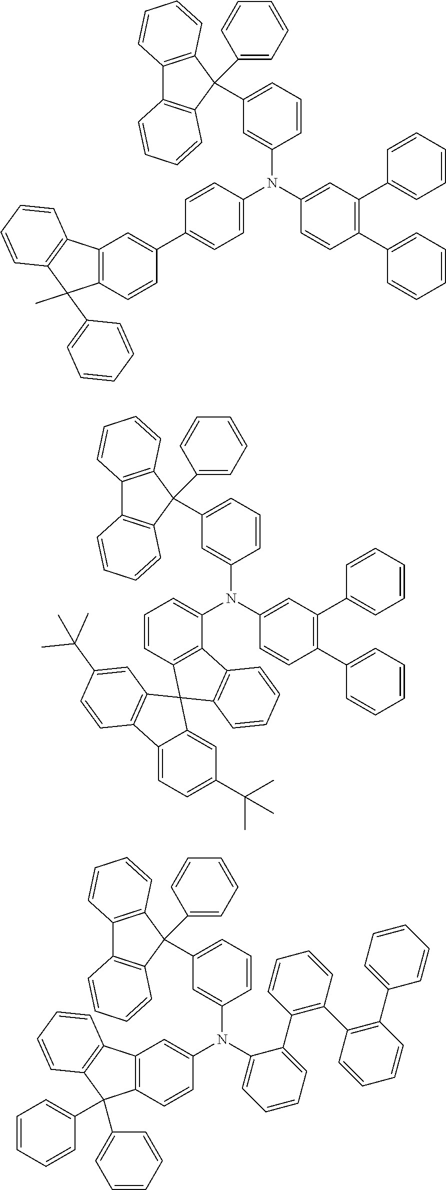

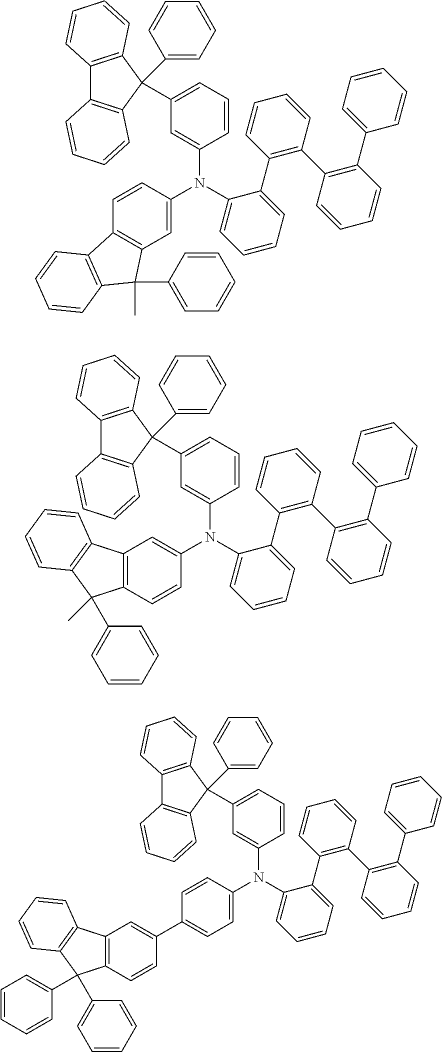

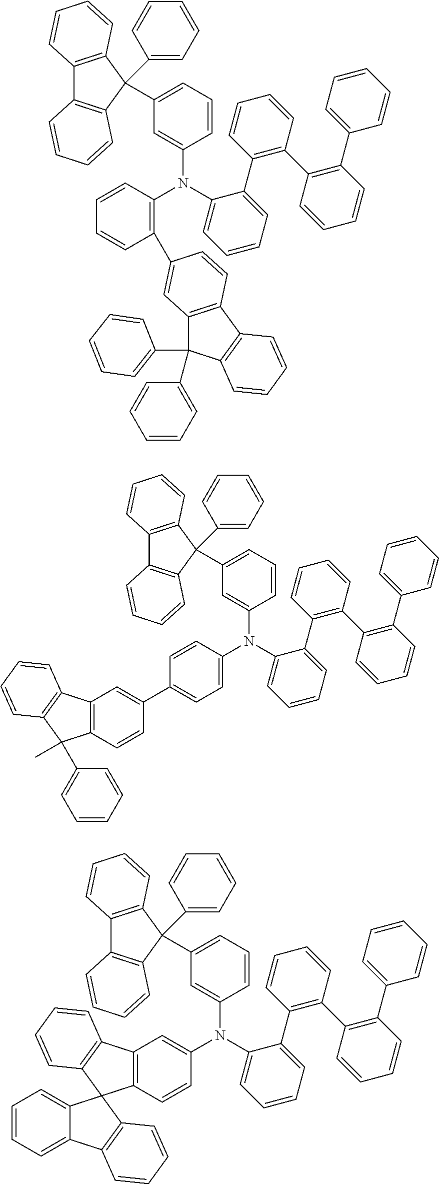

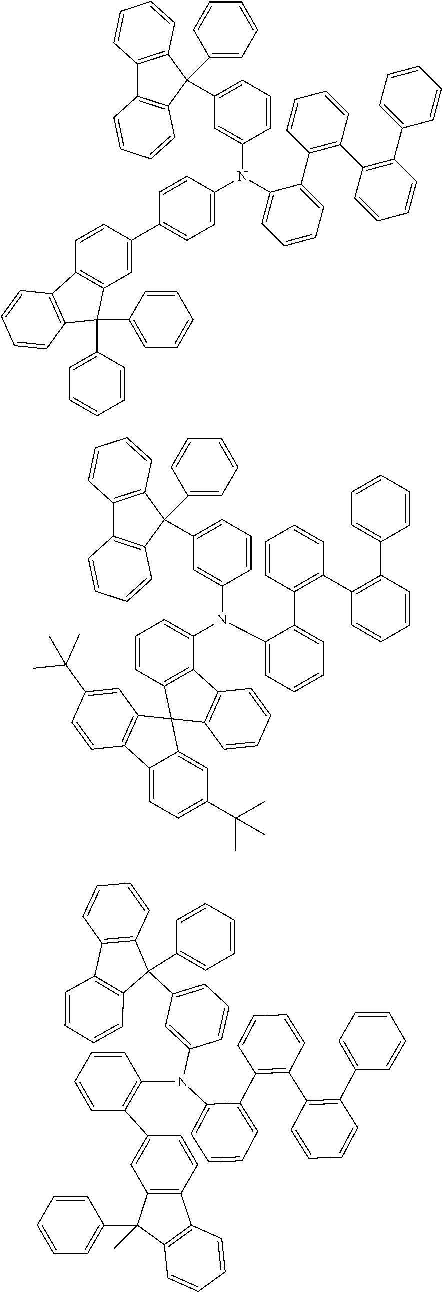

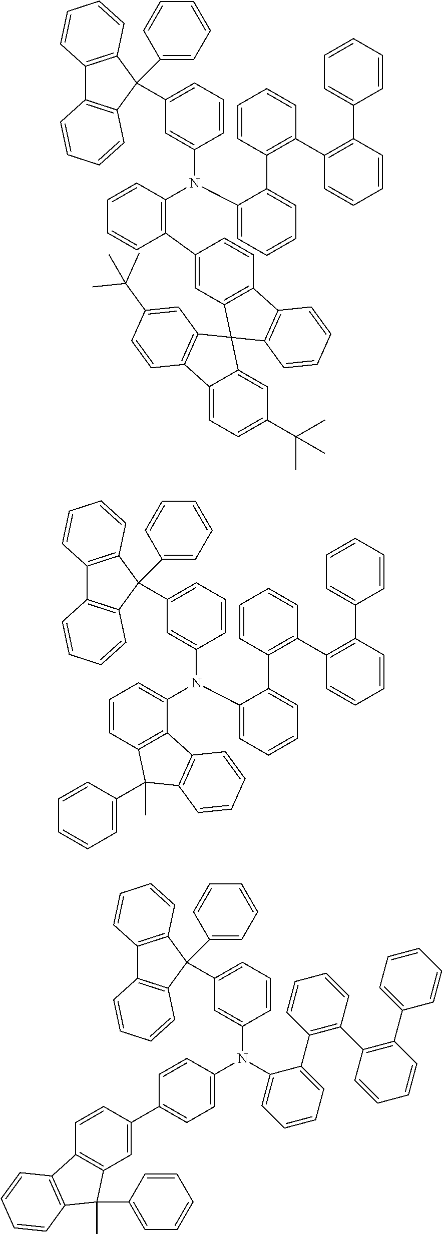 [SMILES: CC(C)(C)c1ccc2c(c1)C1(c3ccccc3-c3ccc(-c4ccccc4N(c4cccc(C5(c6ccccc6)c6ccccc6-c6ccccc65)c4)c4ccccc4-c4ccccc4-c4ccccc4-c4ccccc4)cc31)c1cc(C(C)(C)C)ccc1-2 ; CC1(c2ccccc2)c2ccccc2-c2c(N(c3cccc(C4(c5ccccc5)c5ccccc5-c5ccccc54)c3)c3ccccc3-c3ccccc3-c3ccccc3-c3ccccc3)cccc21 ; CC1(c2ccccc2)c2ccccc2-c2ccc(-c3ccc(N(c4cccc(C5(c6ccccc6)c6ccccc6-c6ccccc65)c4)c4ccccc4-c4ccccc4-c4ccccc4-c4ccccc4)cc3)cc21]

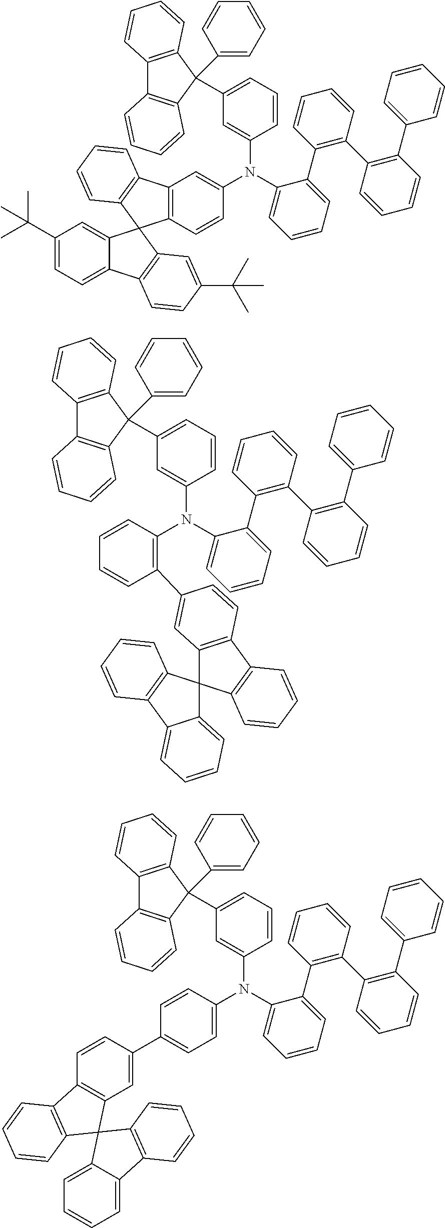

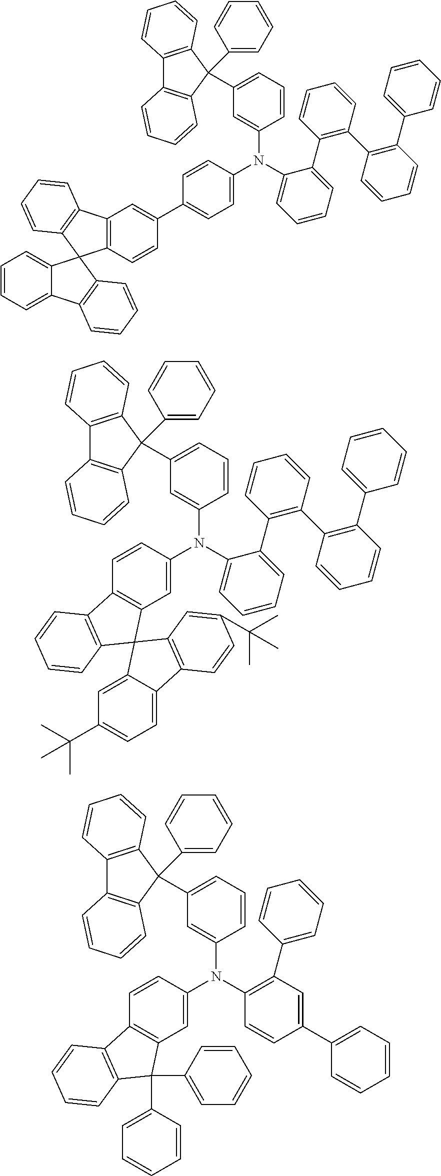

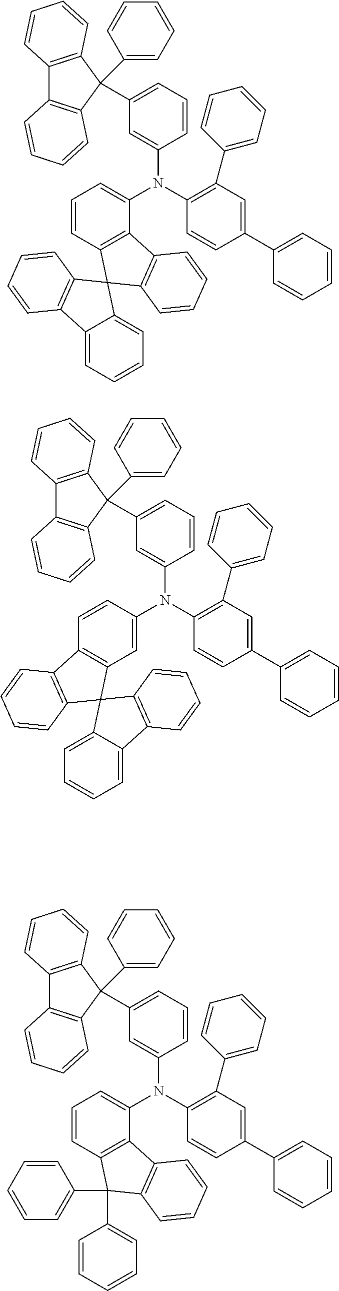

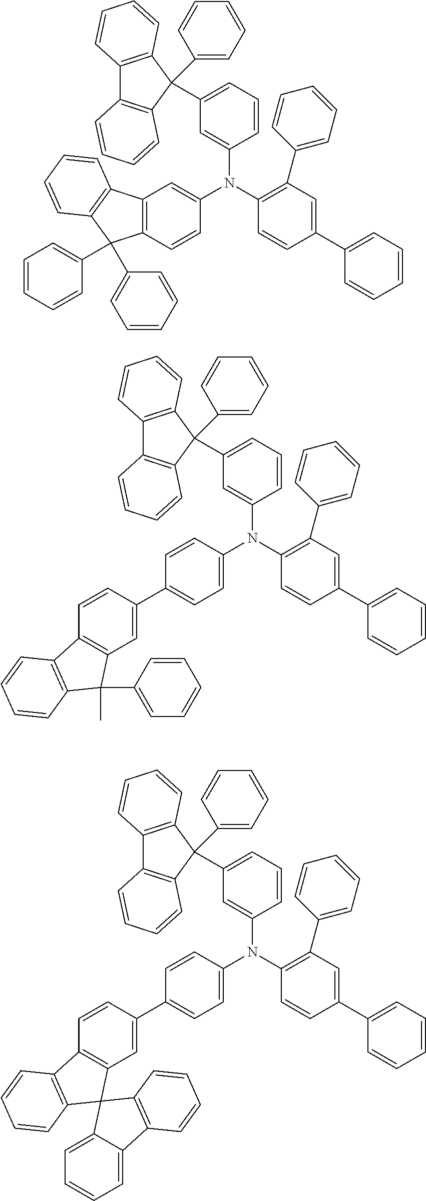

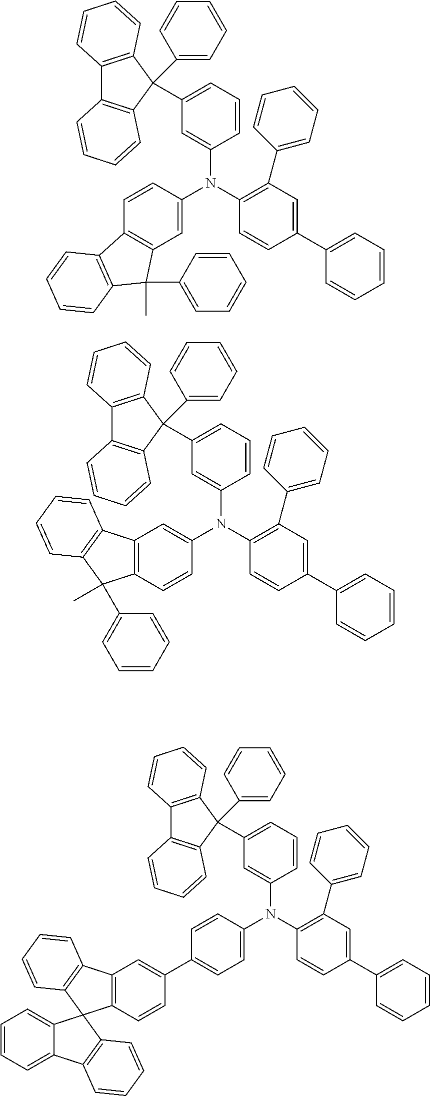

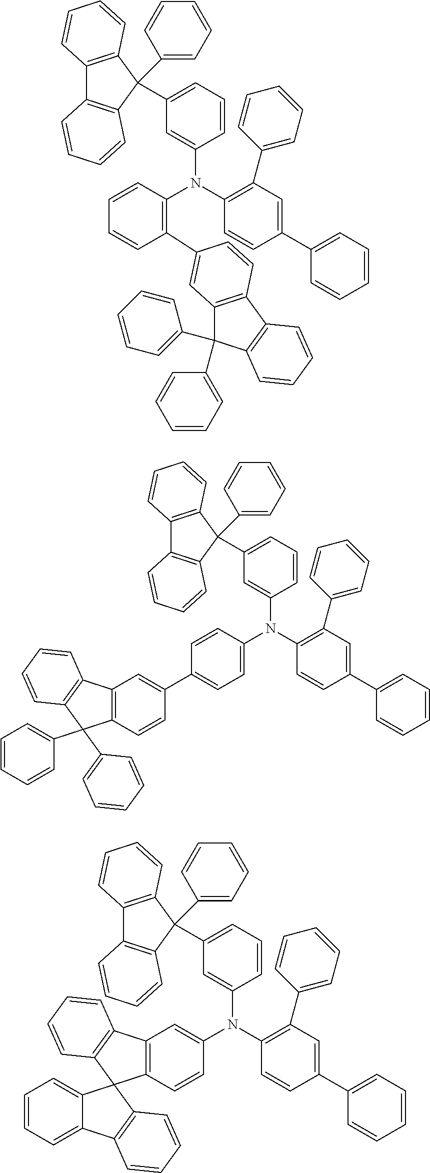

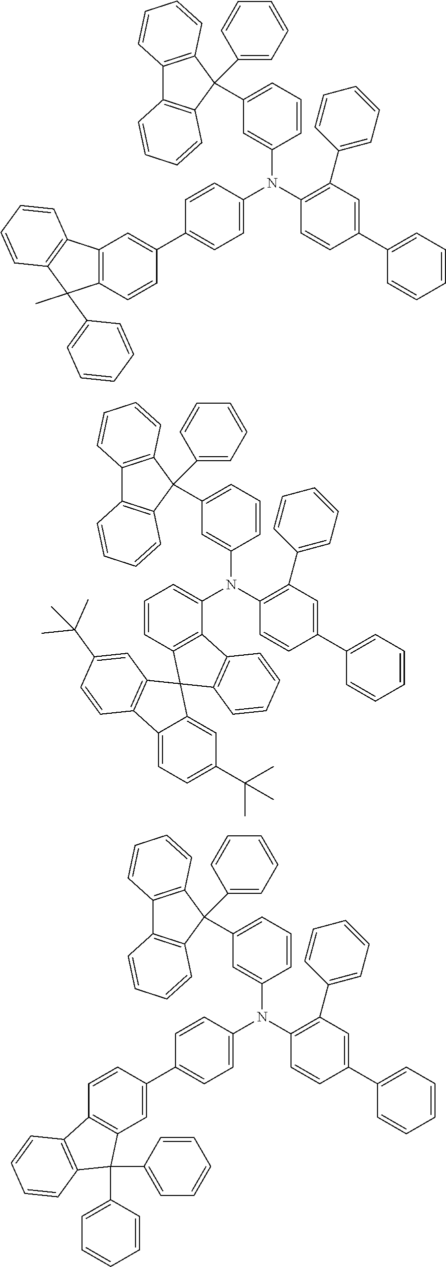

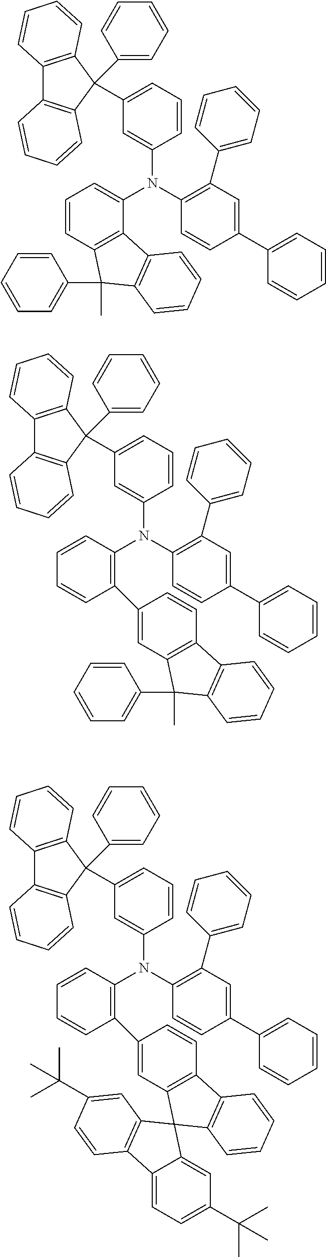

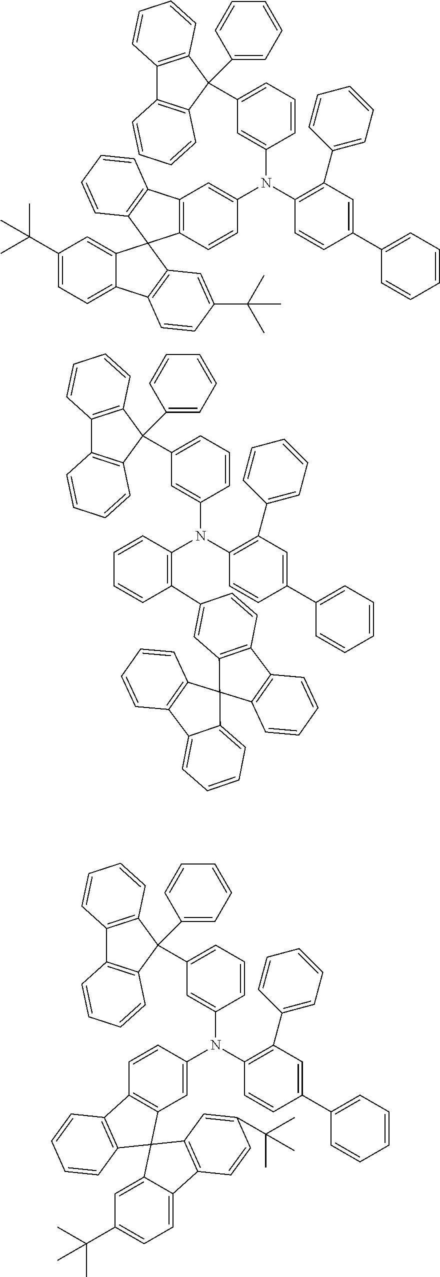

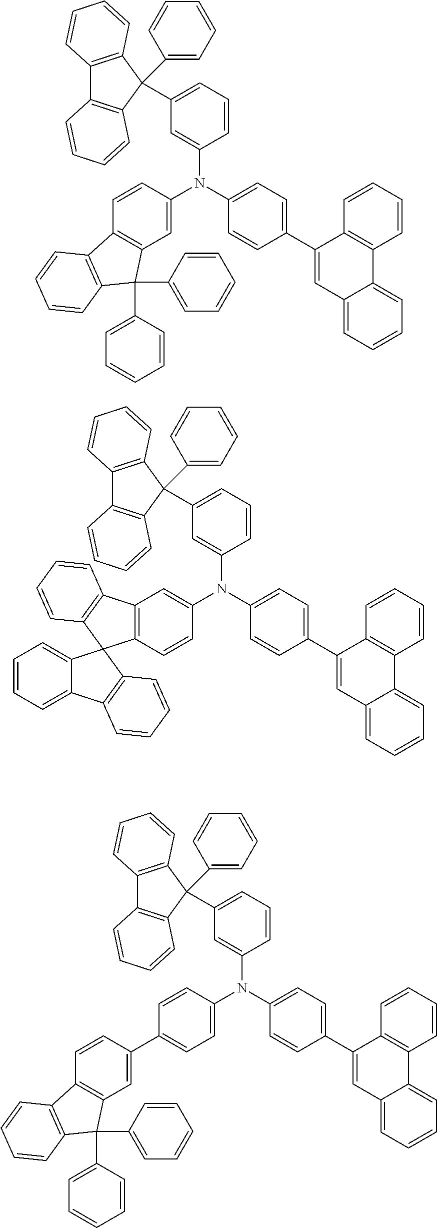

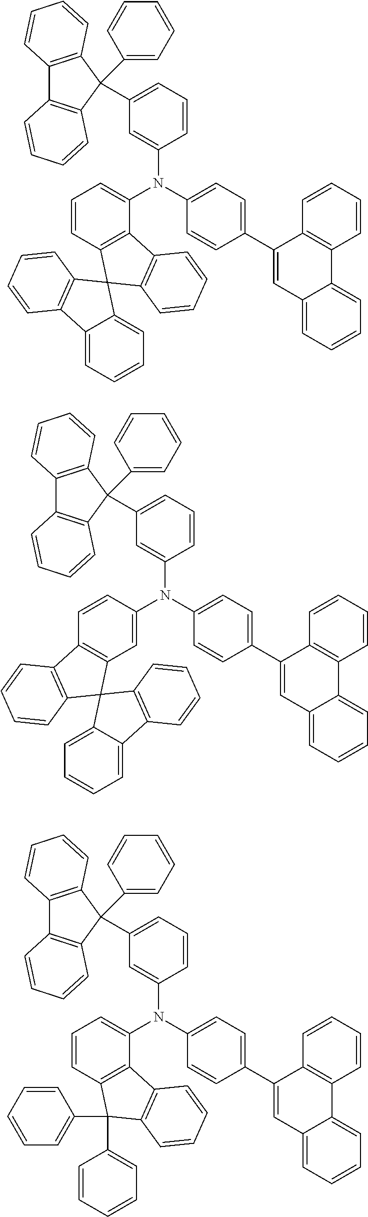

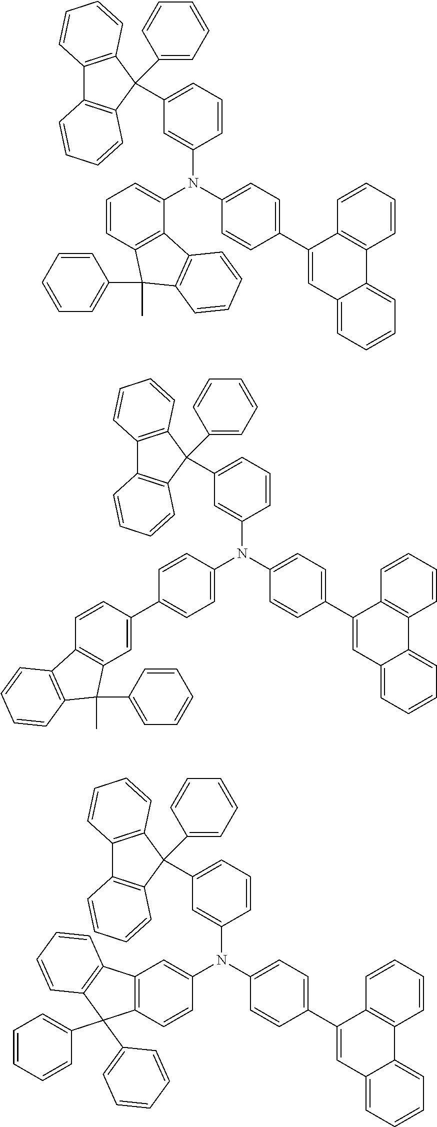 [SMILES: CC1(c2ccccc2)c2ccccc2-c2c(N(c3ccc(-c4cc5ccccc5c5ccccc45)cc3)c3cccc(C4(c5ccccc5)c5ccccc5-c5ccccc54)c3)cccc21 ; CC1(c2ccccc2)c2ccccc2-c2ccc(-c3ccc(N(c4ccc(-c5cc6ccccc6c6ccccc56)cc4)c4cccc(C5(c6ccccc6)c6ccccc6-c6ccccc65)c4)cc3)cc21 ; c1ccc(C2(c3cccc(N(c4ccc(-c5cc6ccccc6c6ccccc56)cc4)c4ccc5c(c4)-c4ccccc4C5(c4ccccc4)c4ccccc4)c3)c3ccccc3-c3ccccc32)cc1]

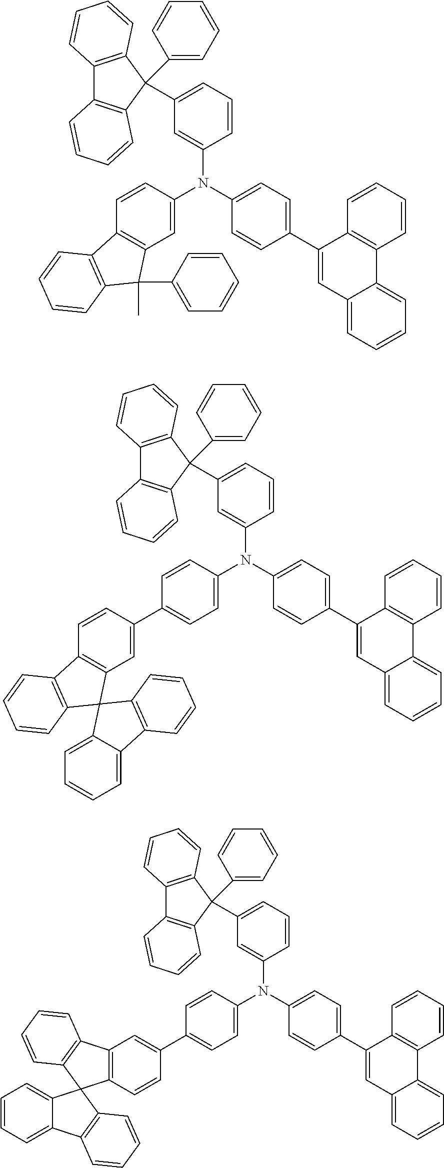 [SMILES: CC1(c2ccccc2)c2ccccc2-c2ccc(N(c3ccc(-c4cc5ccccc5c5ccccc45)cc3)c3cccc(C4(c5ccccc5)c5ccccc5-c5ccccc54)c3)cc21 ; c1ccc(C2(c3cccc(N(c4ccc(-c5ccc6c(c5)C5(c7ccccc7-c7ccccc75)c5ccccc5-6)cc4)c4ccc(-c5cc6ccccc6c6ccccc56)cc4)c3)c3ccccc3-c3ccccc32)cc1 ; c1ccc(C2(c3cccc(N(c4ccc(-c5ccc6c(c5)-c5ccccc5C65c6ccccc6-c6ccccc65)cc4)c4ccc(-c5cc6ccccc6c6ccccc56)cc4)c3)c3ccccc3-c3ccccc32)cc1]

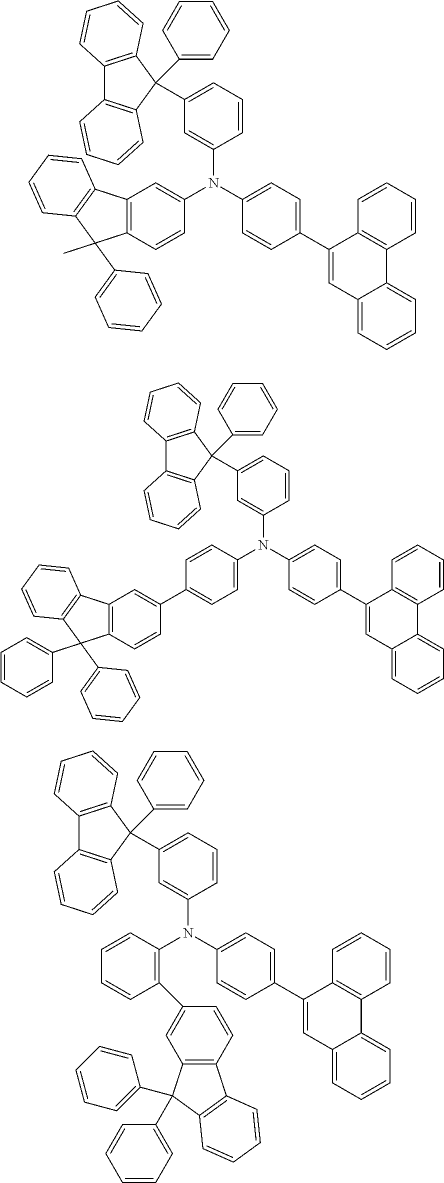

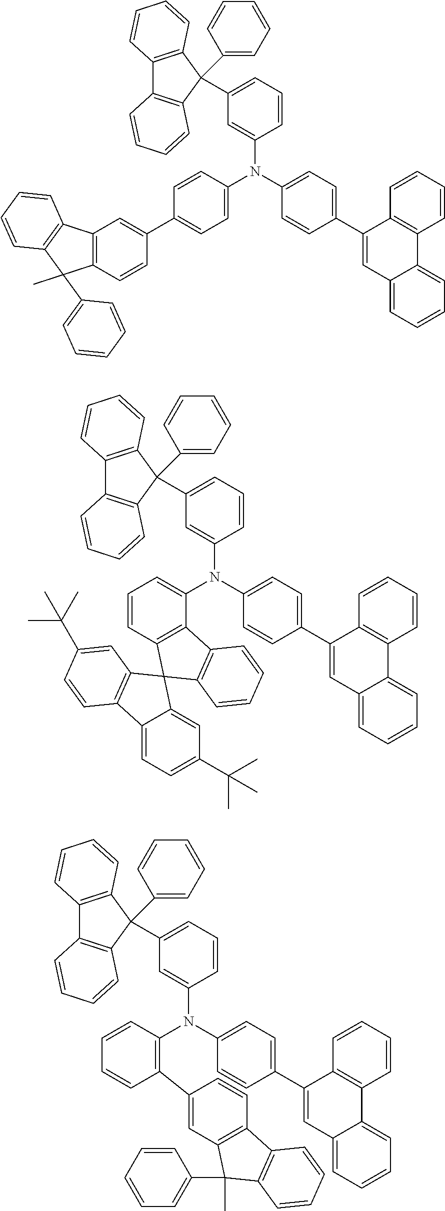

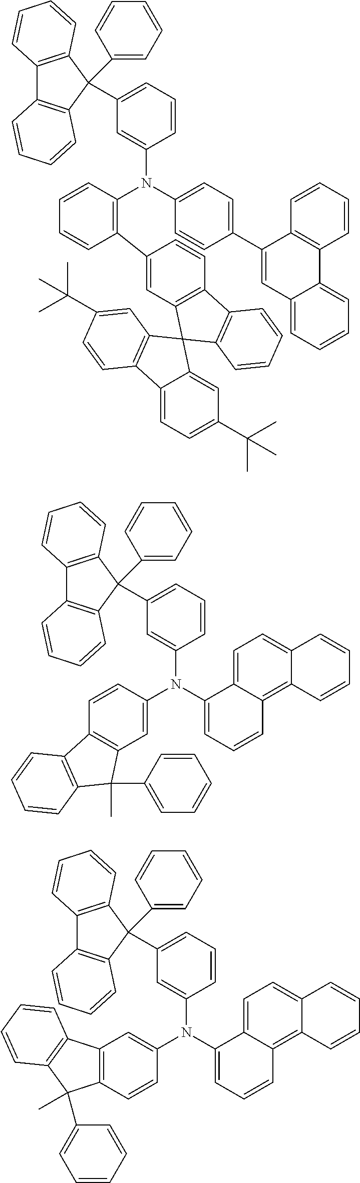

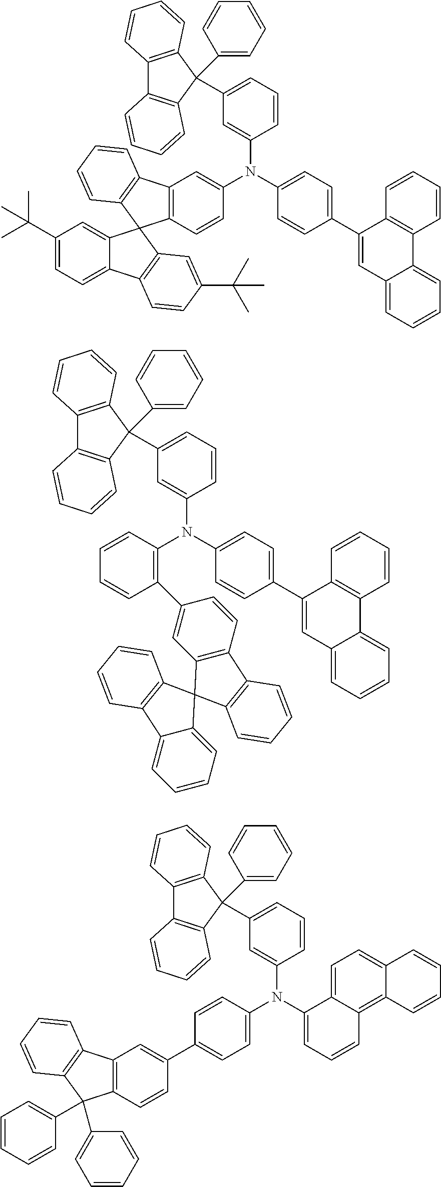

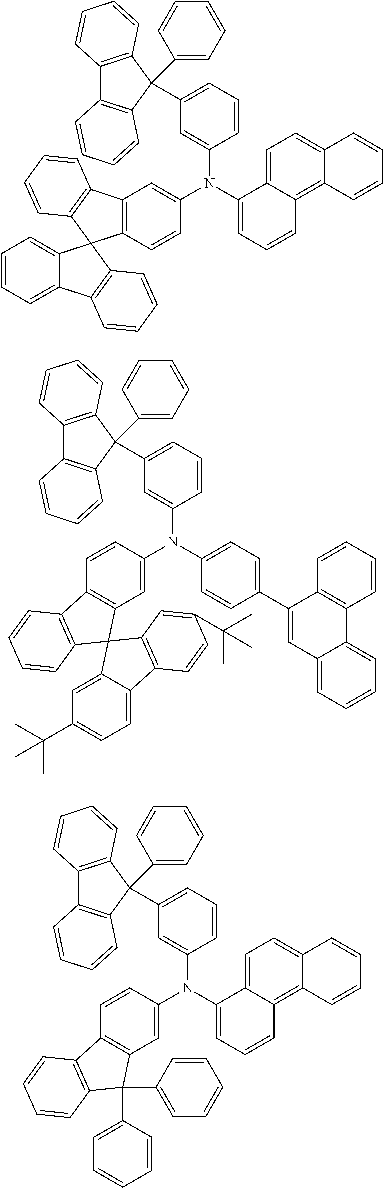

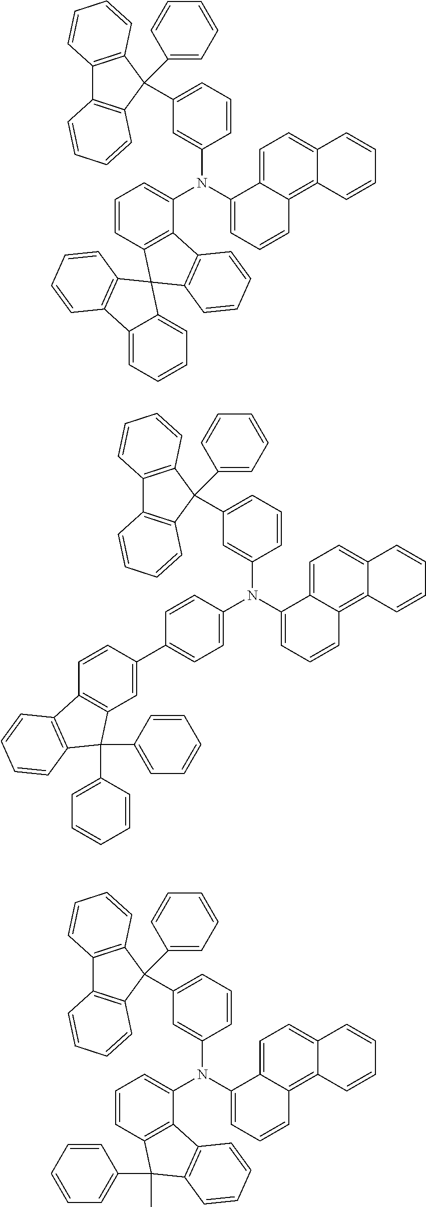

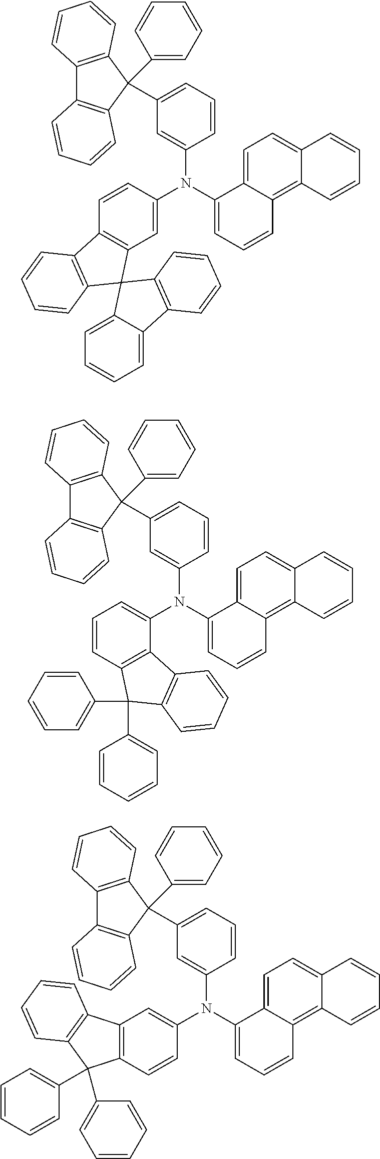

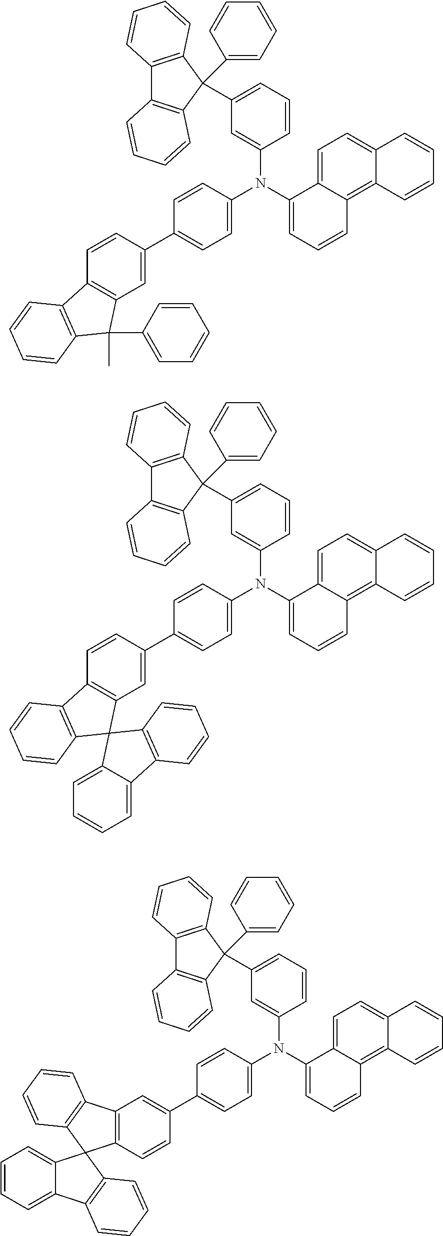

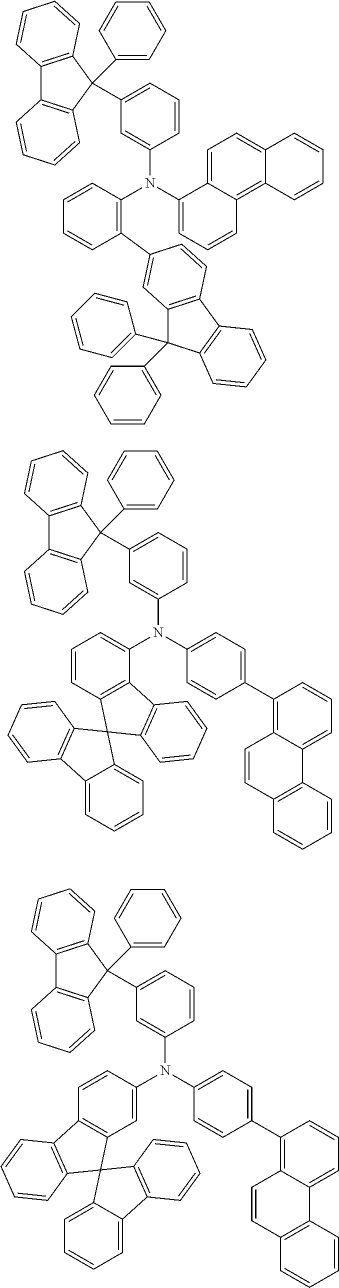

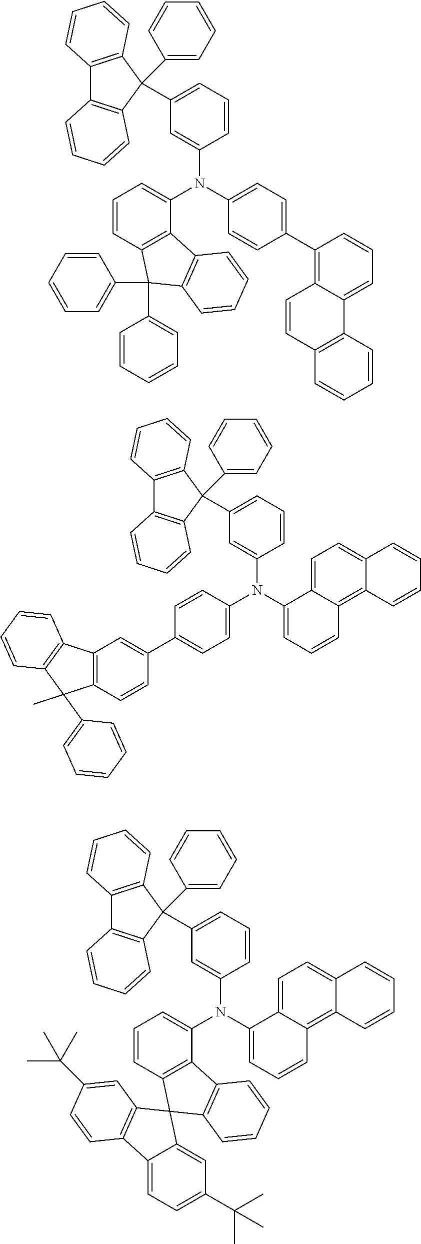

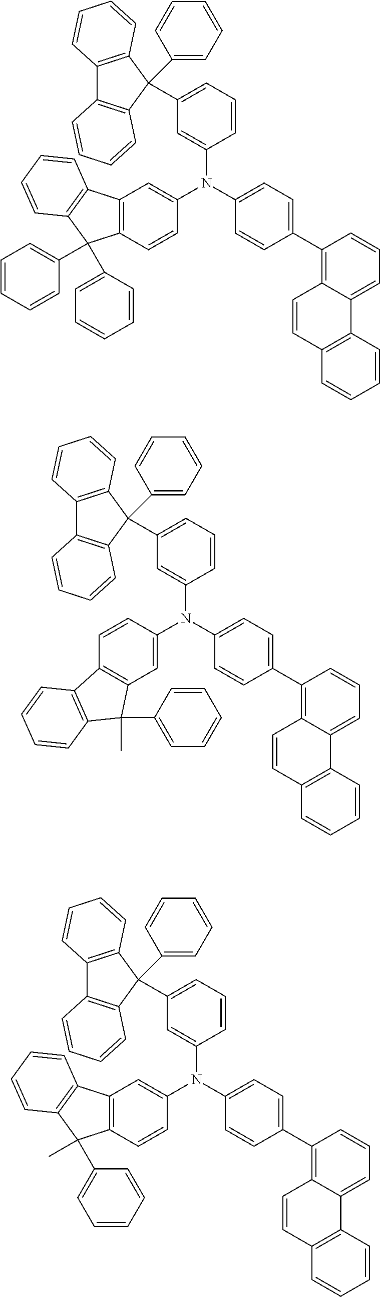 [SMILES: c1ccc(C2(c3cccc(N(c4ccc(-c5cccc6c5ccc5ccccc56)cc4)c4ccc5c(c4)-c4ccccc4C5(c4ccccc4)c4ccccc4)c3)c3ccccc3-c3ccccc32)cc1 ; CC1(c2ccccc2)c2ccccc2-c2ccc(N(c3ccc(-c4cccc5c4ccc4ccccc45)cc3)c3cccc(C4(c5ccccc5)c5ccccc5-c5ccccc54)c3)cc21 ; CC1(c2ccccc2)c2ccccc2-c2cc(N(c3ccc(-c4cccc5c4ccc4ccccc45)cc3)c3cccc(C4(c5ccccc5)c5ccccc5-c5ccccc54)c3)ccc21]

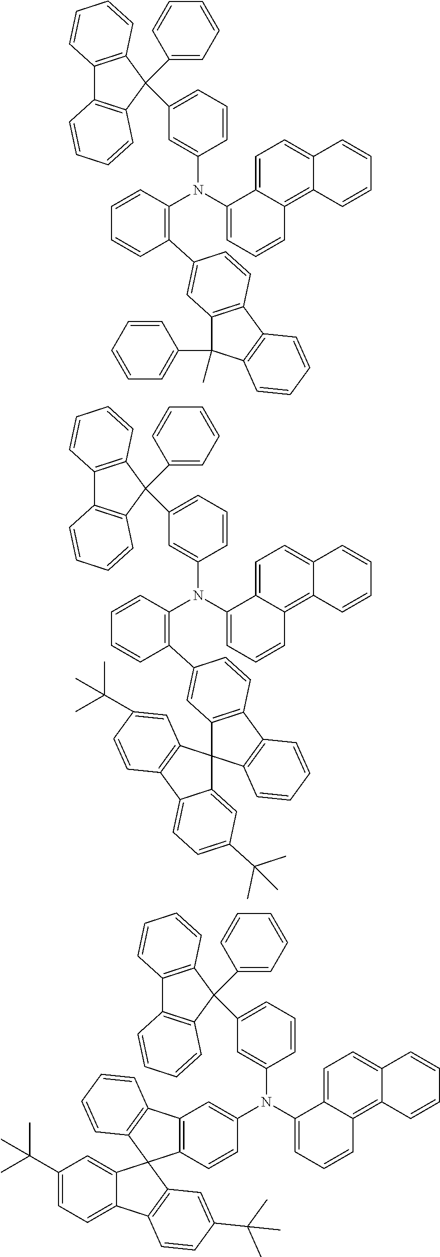

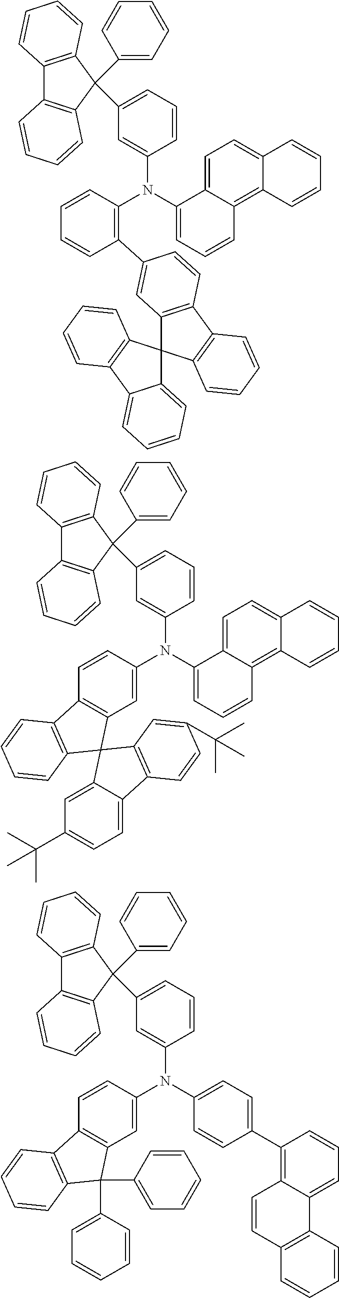

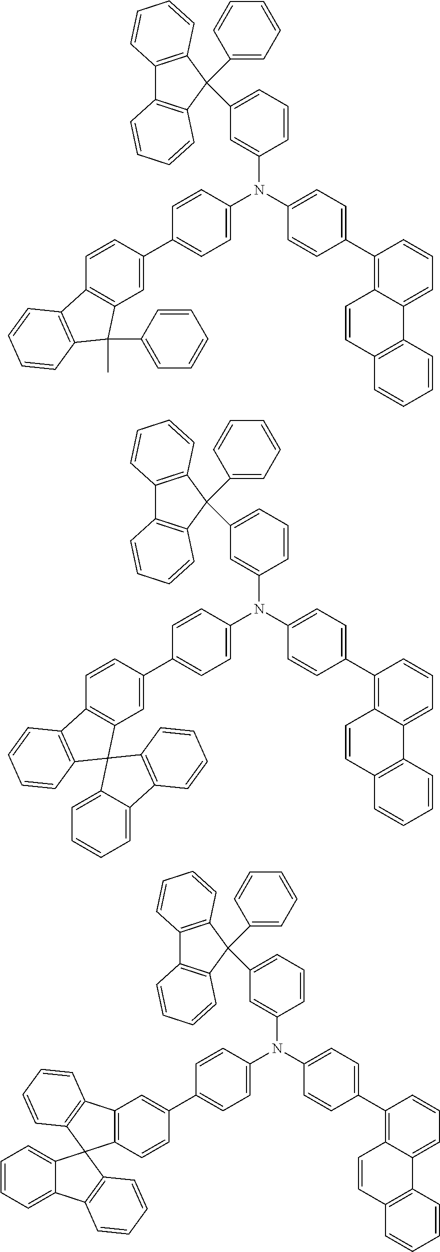 [SMILES: CC1(c2ccccc2)c2ccccc2-c2ccc(-c3ccc(N(c4ccc(-c5cccc6c5ccc5ccccc56)cc4)c4cccc(C5(c6ccccc6)c6ccccc6-c6ccccc65)c4)cc3)cc21 ; c1ccc(C2(c3cccc(N(c4ccc(-c5ccc6c(c5)C5(c7ccccc7-c7ccccc75)c5ccccc5-6)cc4)c4ccc(-c5cccc6c5ccc5ccccc56)cc4)c3)c3ccccc3-c3ccccc32)cc1 ; c1ccc(C2(c3cccc(N(c4ccc(-c5ccc6c(c5)-c5ccccc5C65c6ccccc6-c6ccccc65)cc4)c4ccc(-c5cccc6c5ccc5ccccc56)cc4)c3)c3ccccc3-c3ccccc32)cc1]

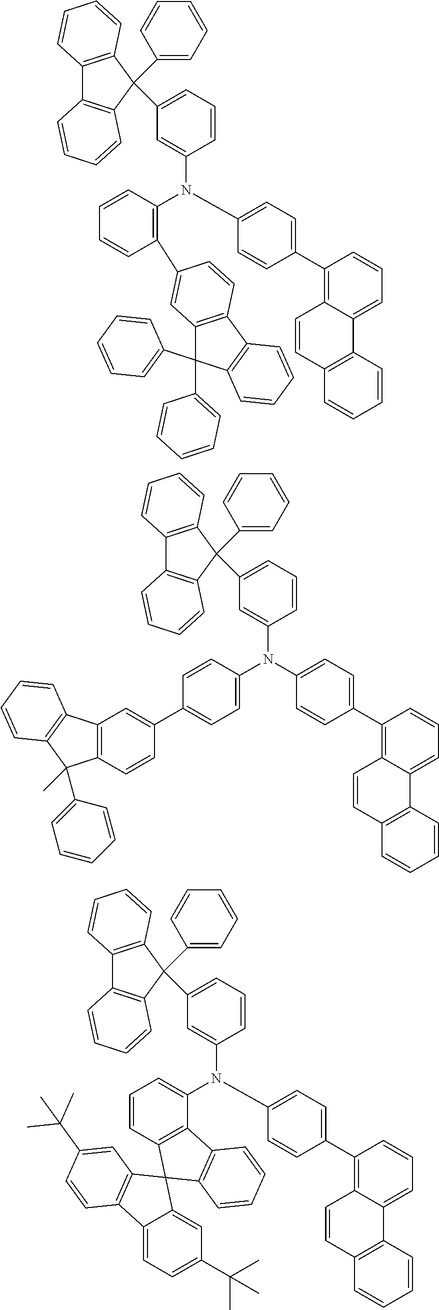

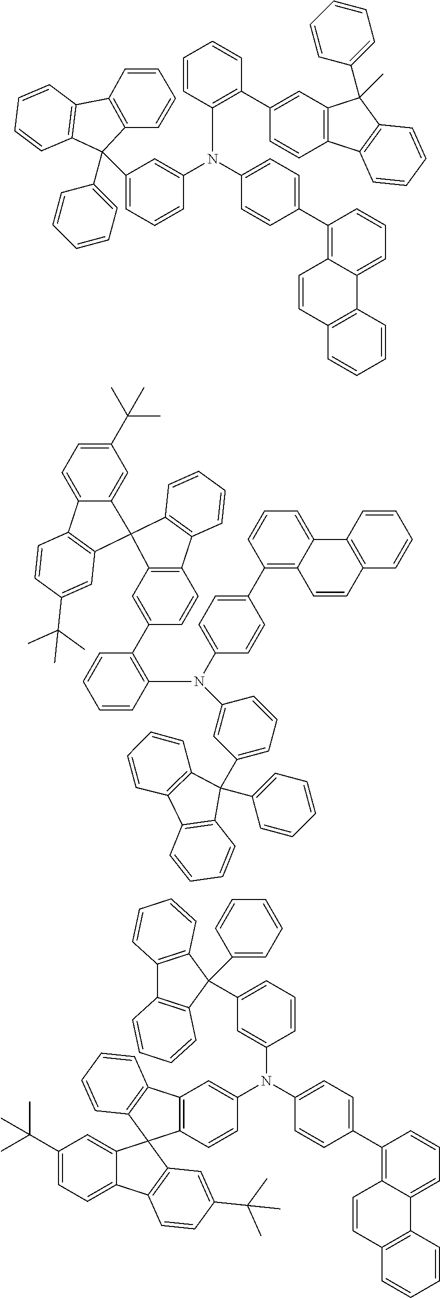

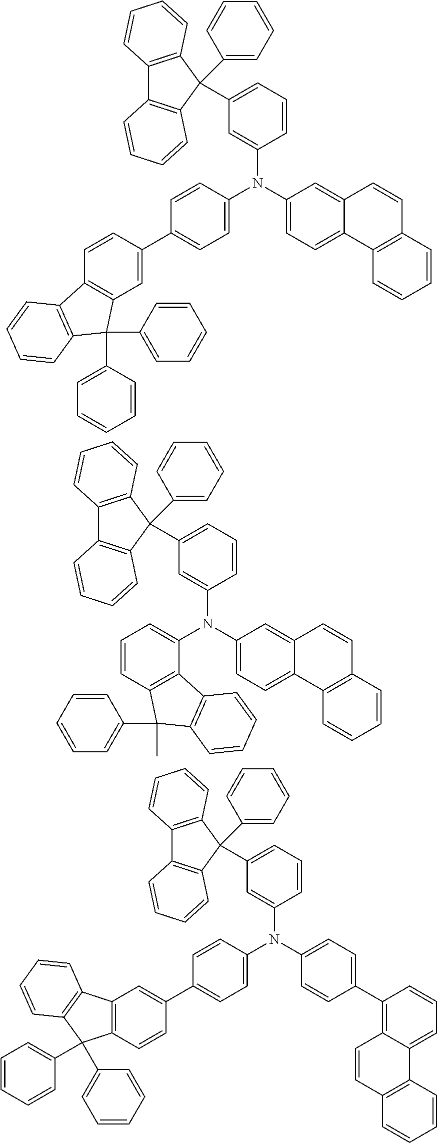

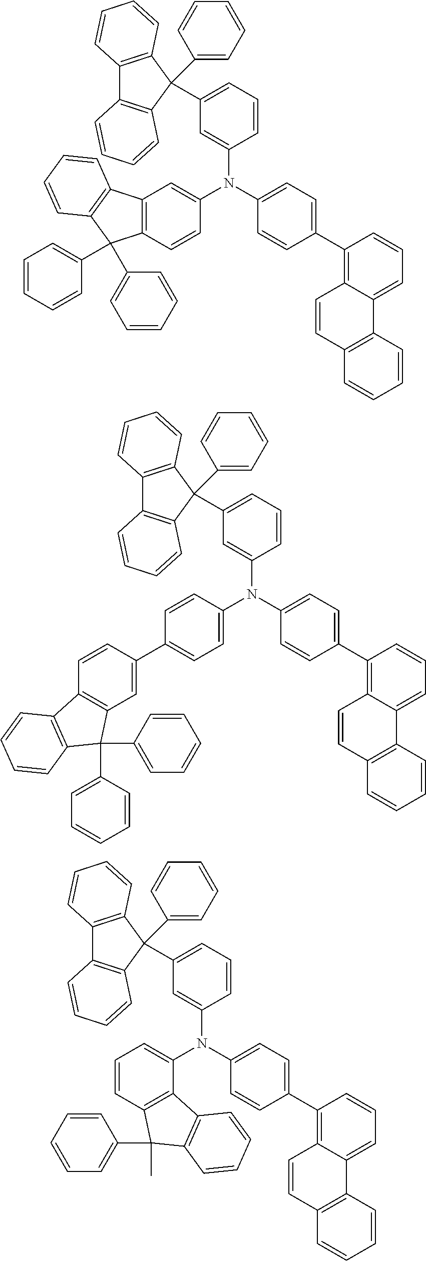

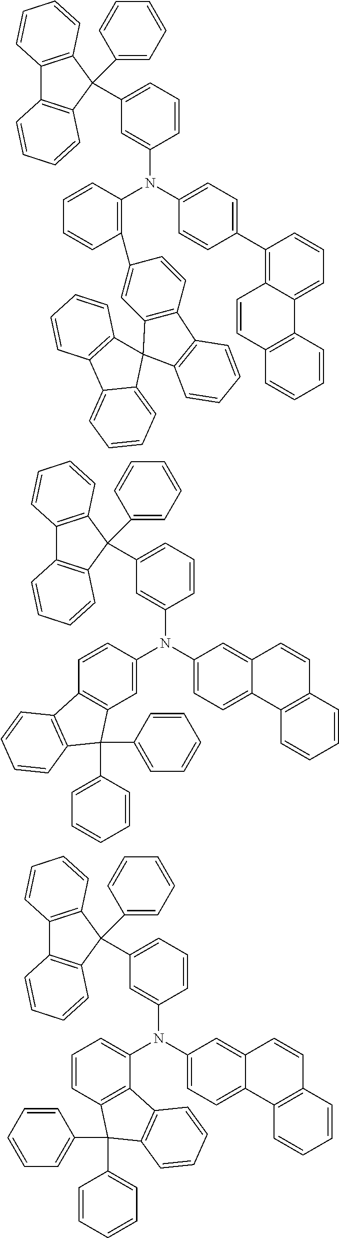

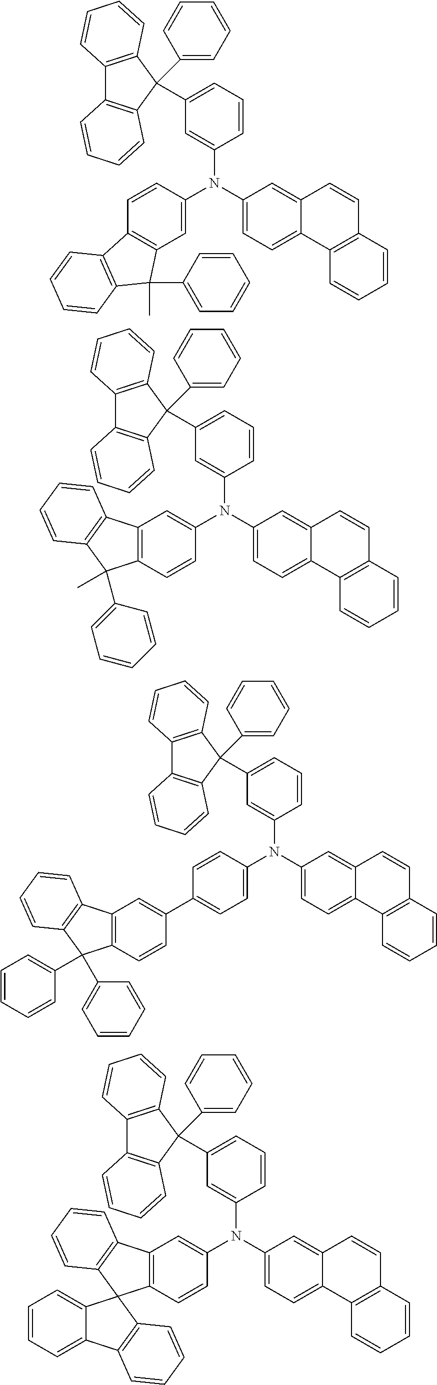

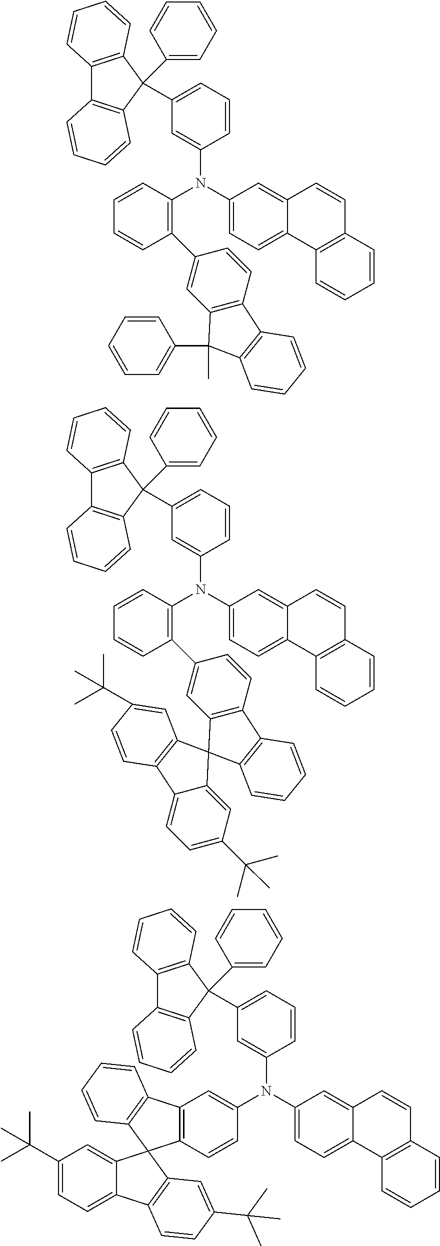

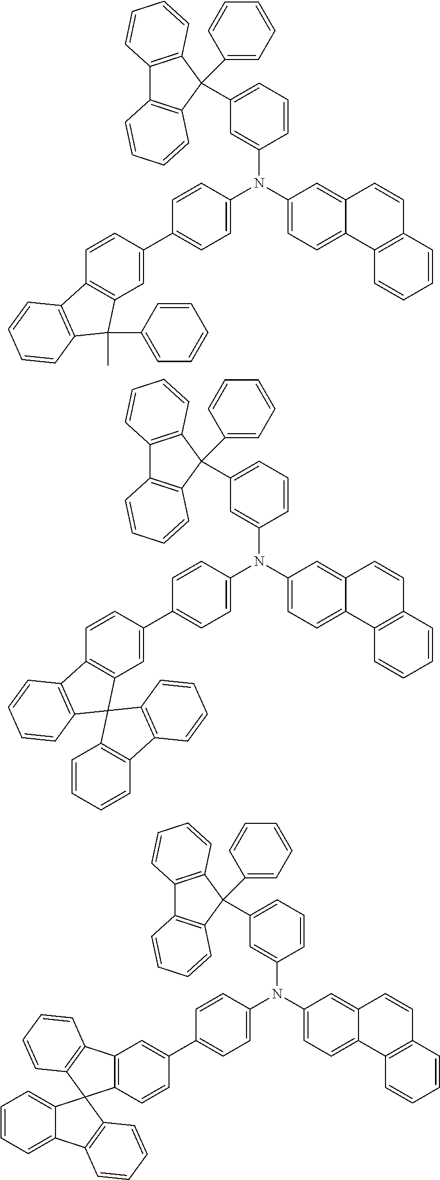

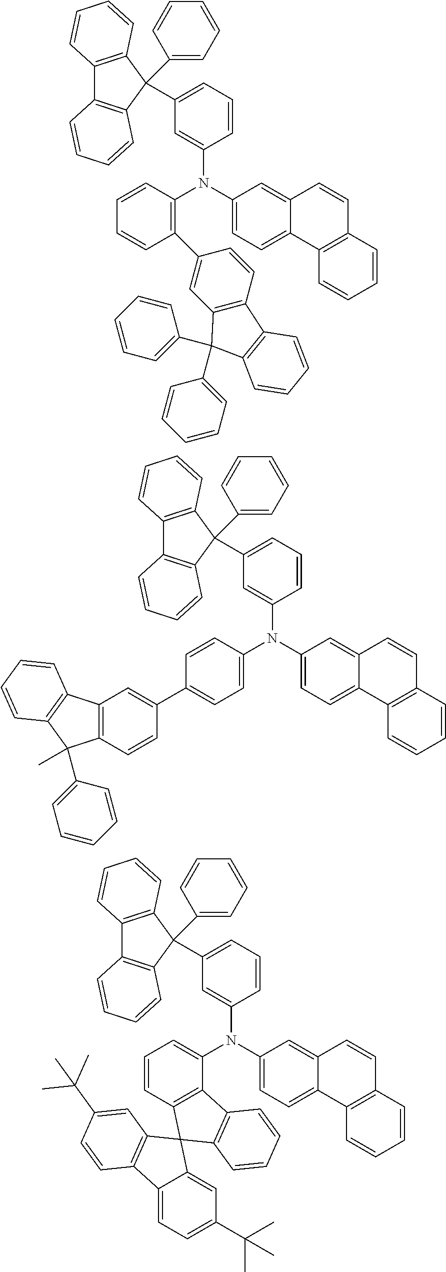

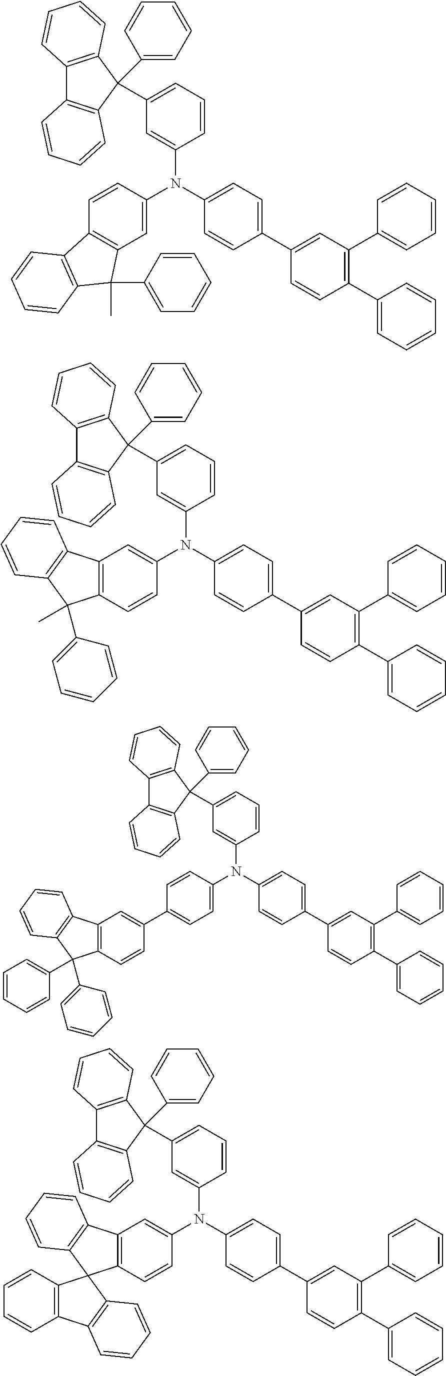

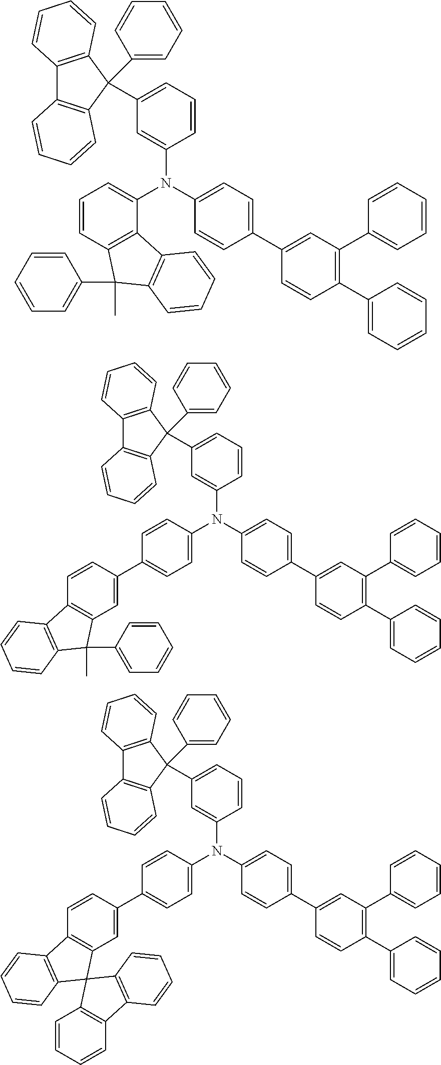

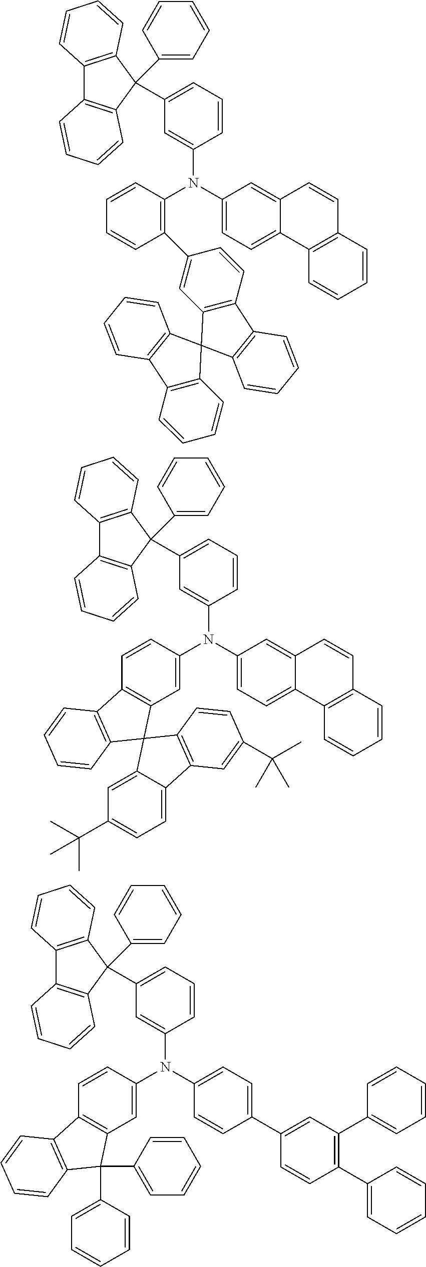

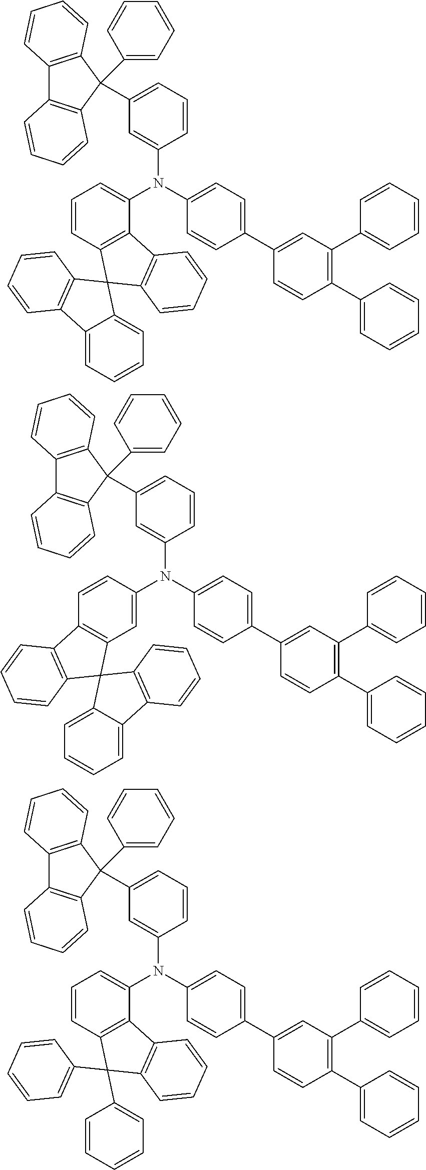

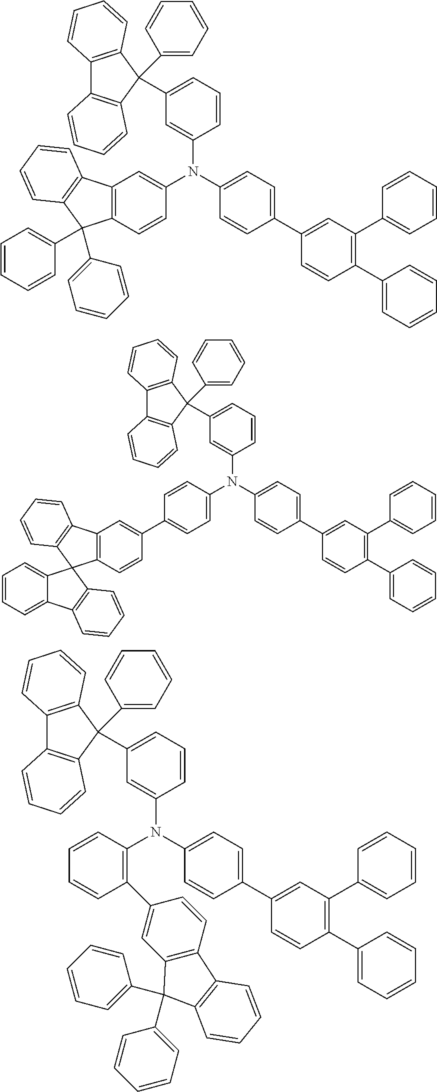

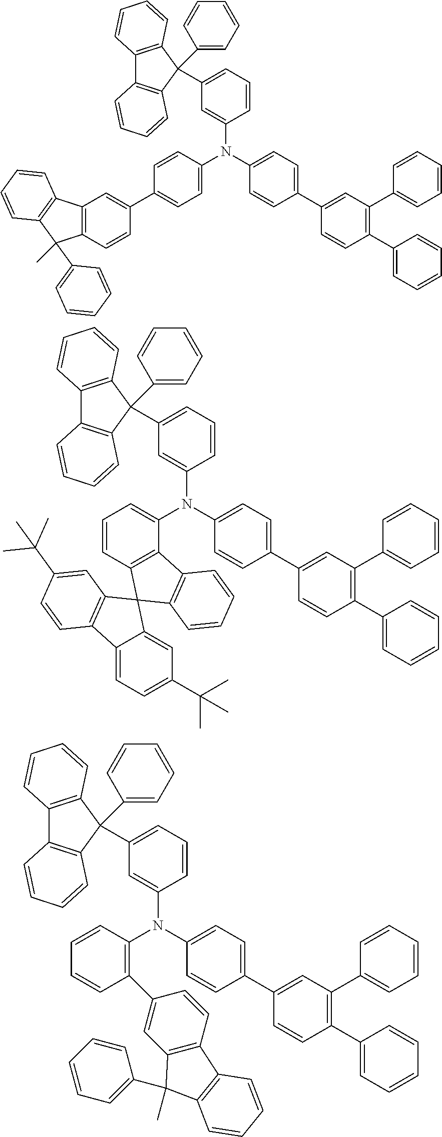

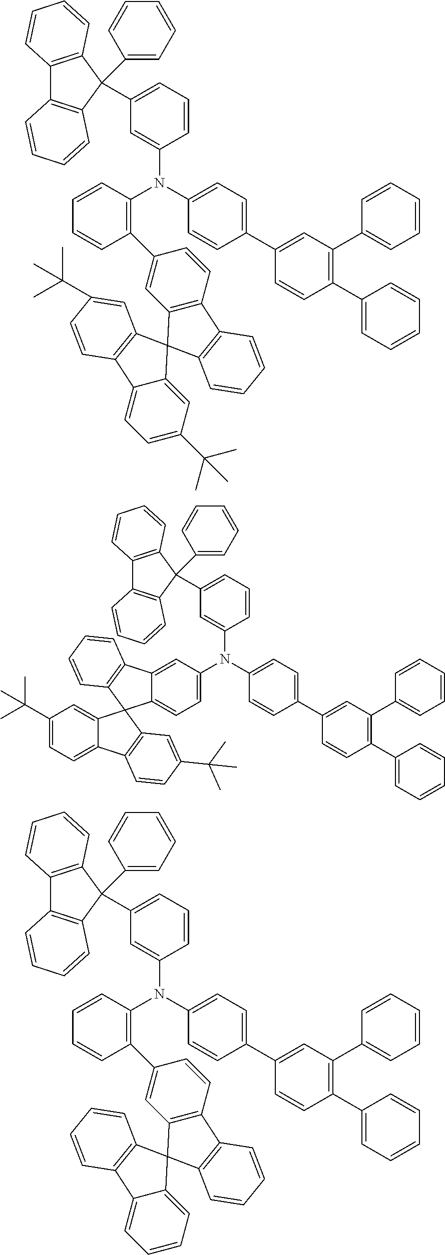

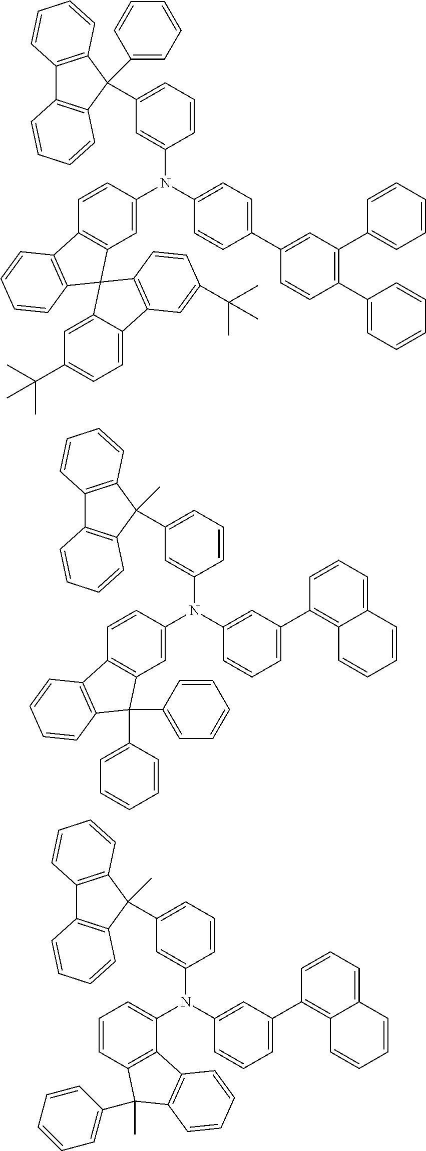

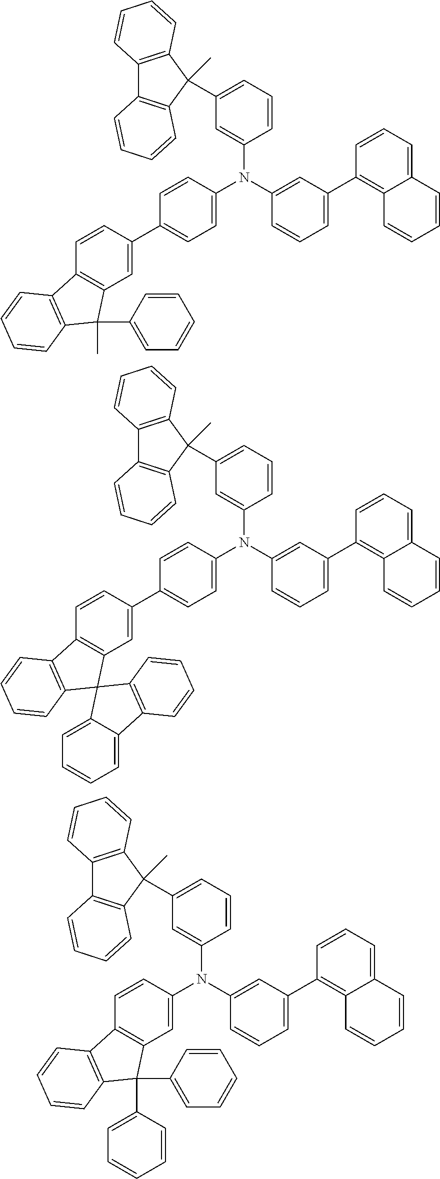

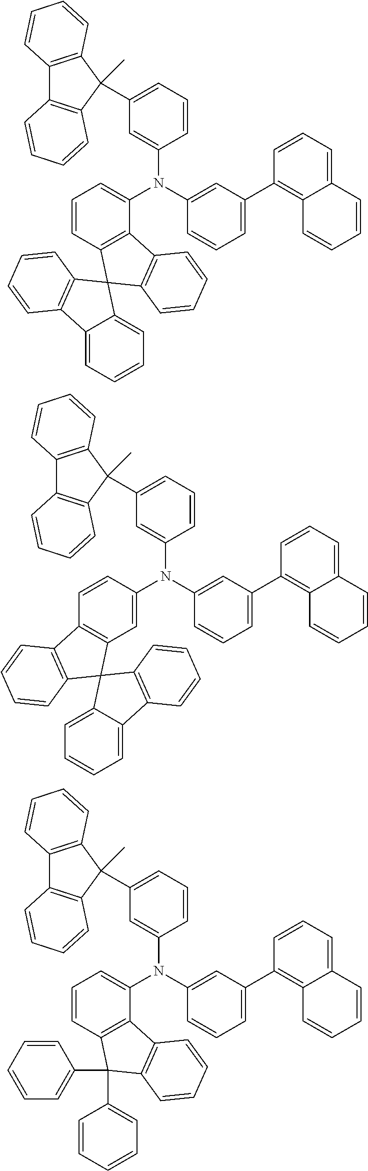

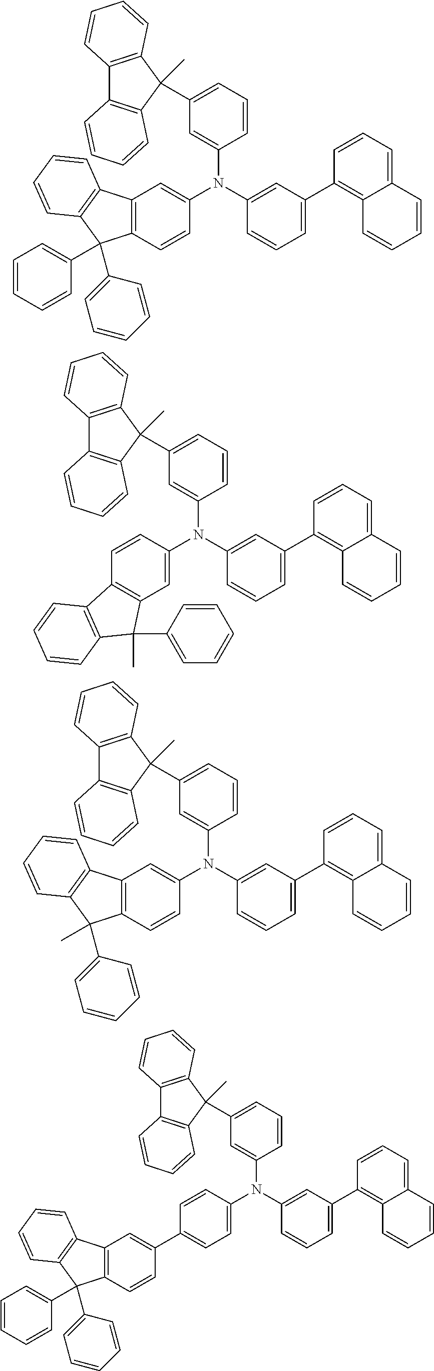

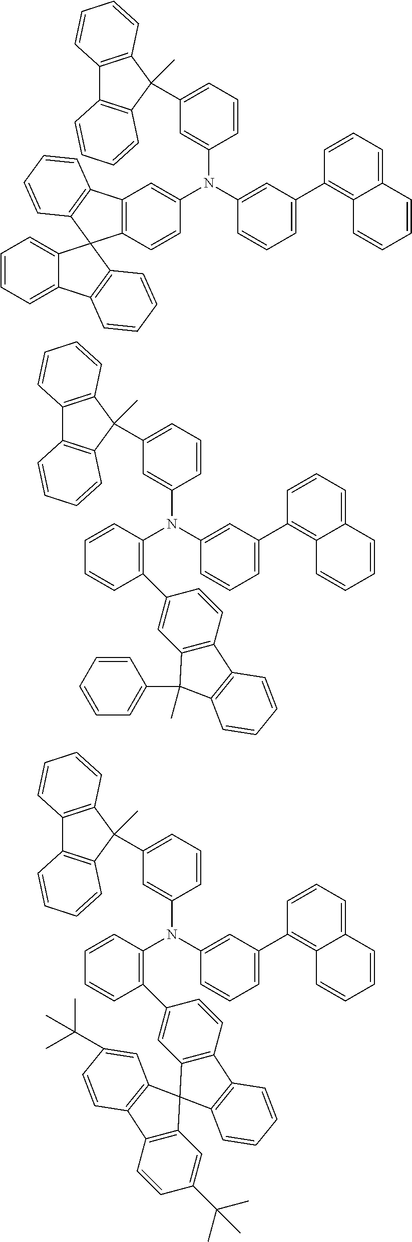

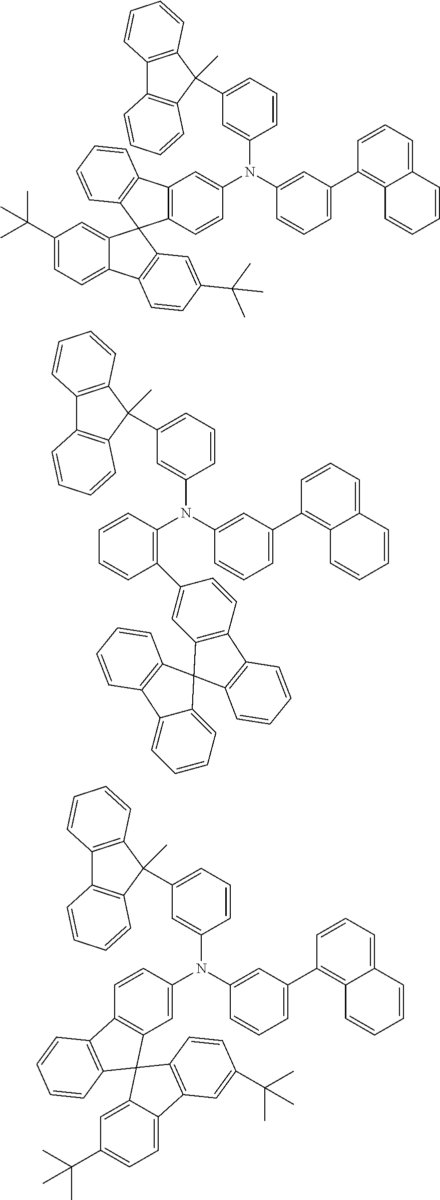 [SMILES: CC(C)(C)c1ccc2c(c1)C1(c3ccccc3-c3cc(N(c4cccc(-c5cccc6ccccc56)c4)c4cccc(C5(C)c6ccccc6-c6ccccc65)c4)ccc31)c1cc(C(C)(C)C)ccc1-2 ; CC1(c2cccc(N(c3cccc(-c4cccc5ccccc45)c3)c3ccccc3-c3ccc4c(c3)C3(c5ccccc5-c5ccccc53)c3ccccc3-4)c2)c2ccccc2-c2ccccc21 ; CC(C)(C)c1ccc2c(c1)-c1ccc(C(C)(C)C)cc1C21c2ccccc2-c2ccc(N(c3cccc(-c4cccc5ccccc45)c3)c3cccc(C4(C)c5ccccc5-c5ccccc54)c3)cc21]

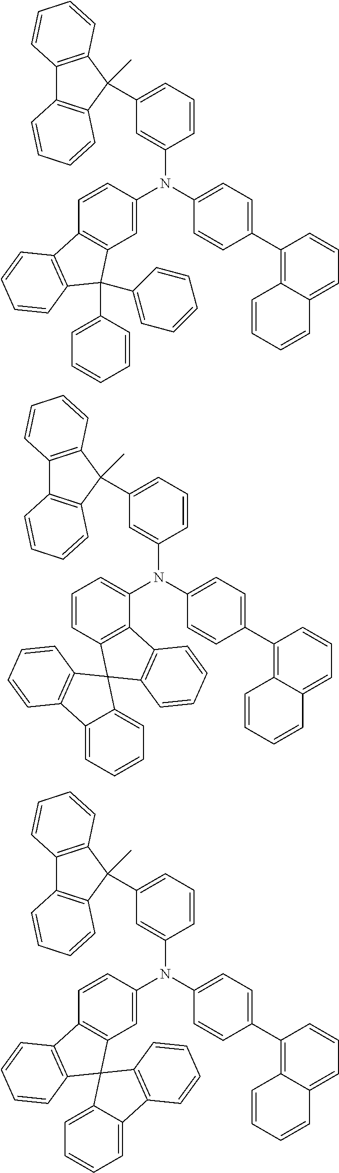

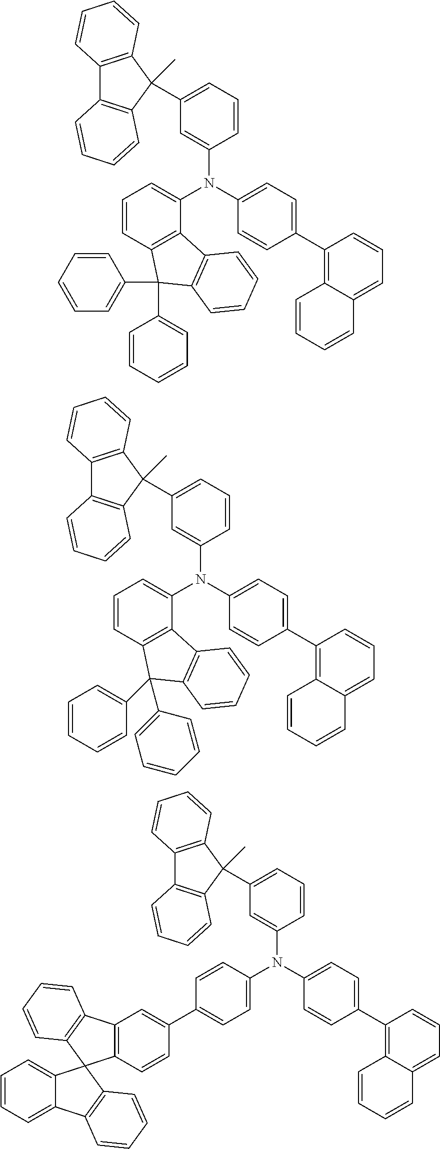

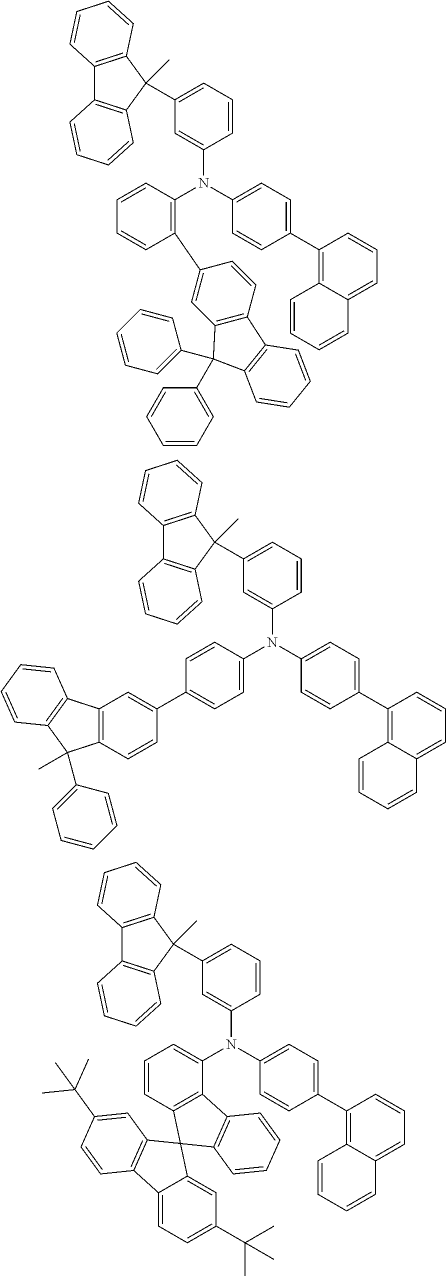

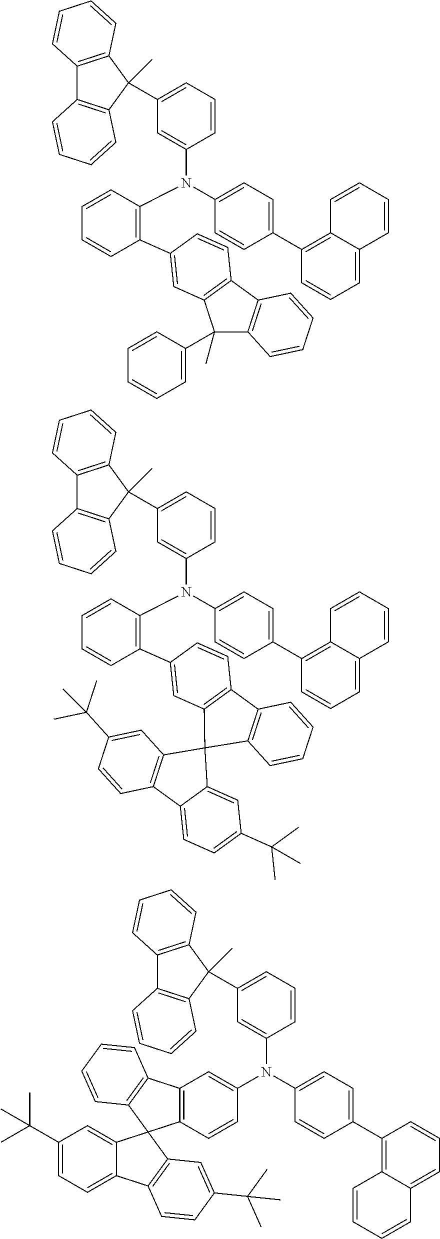

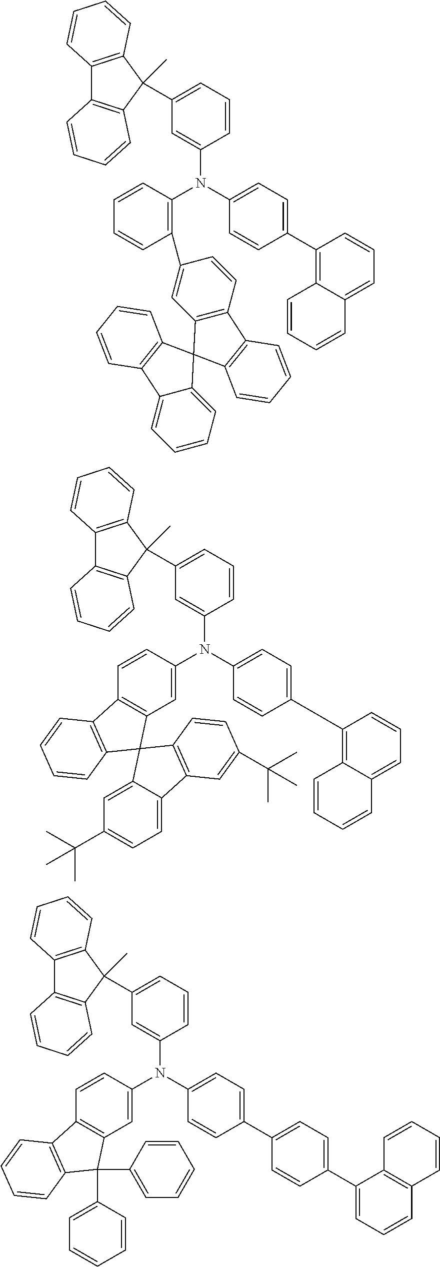

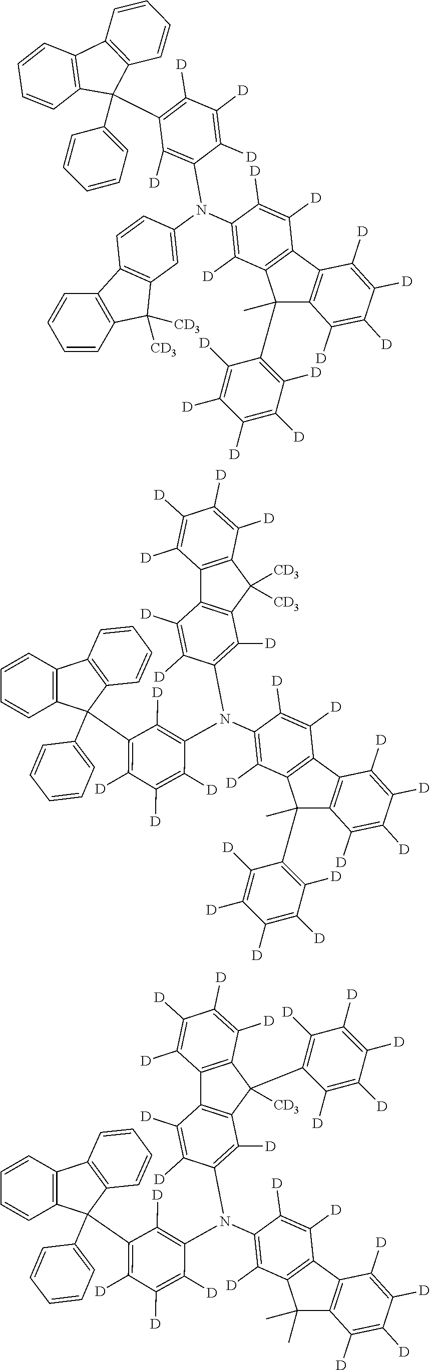

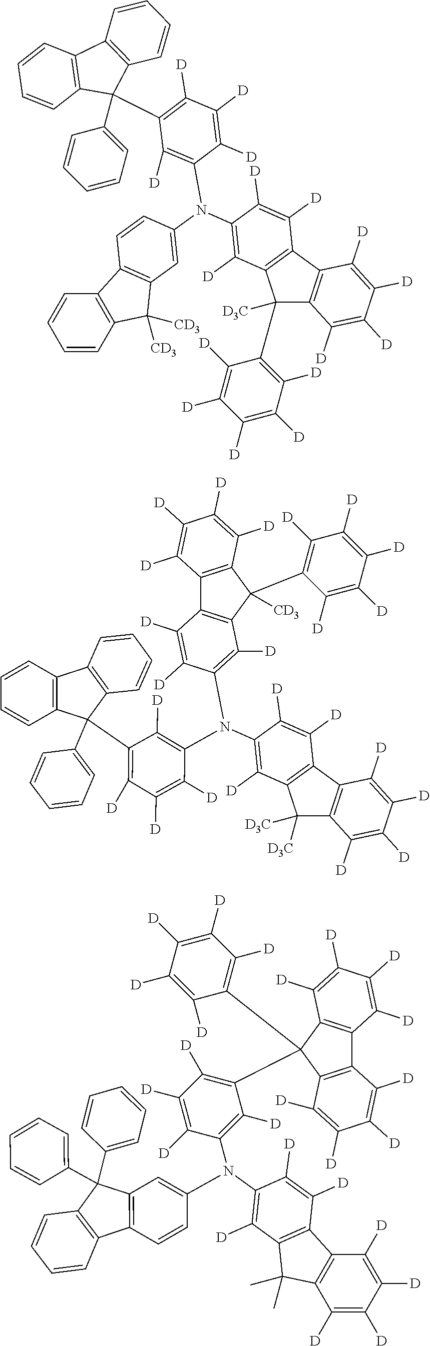

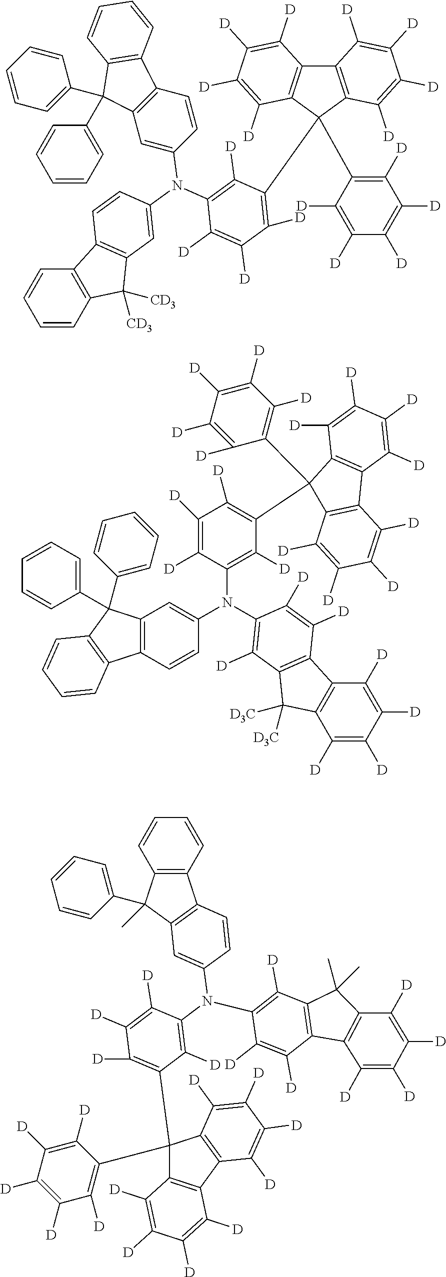

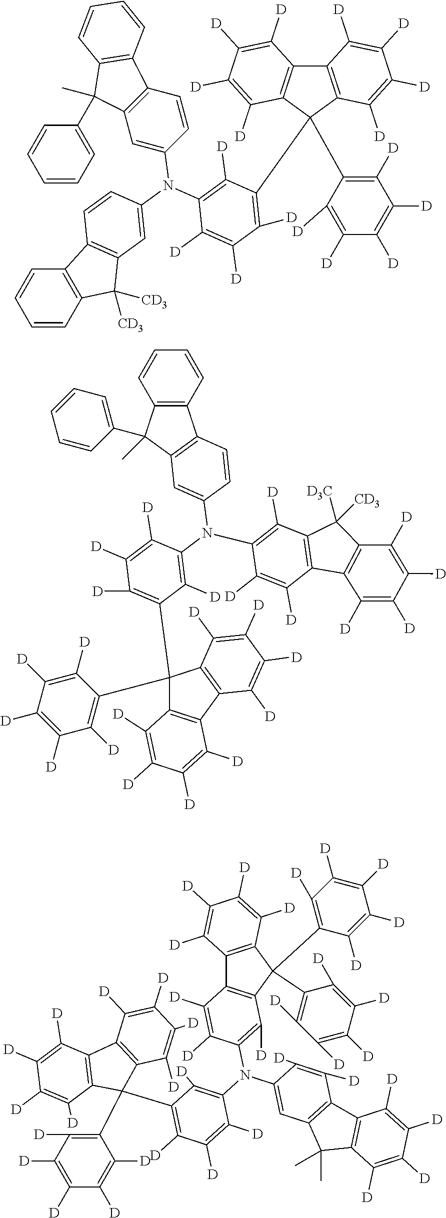

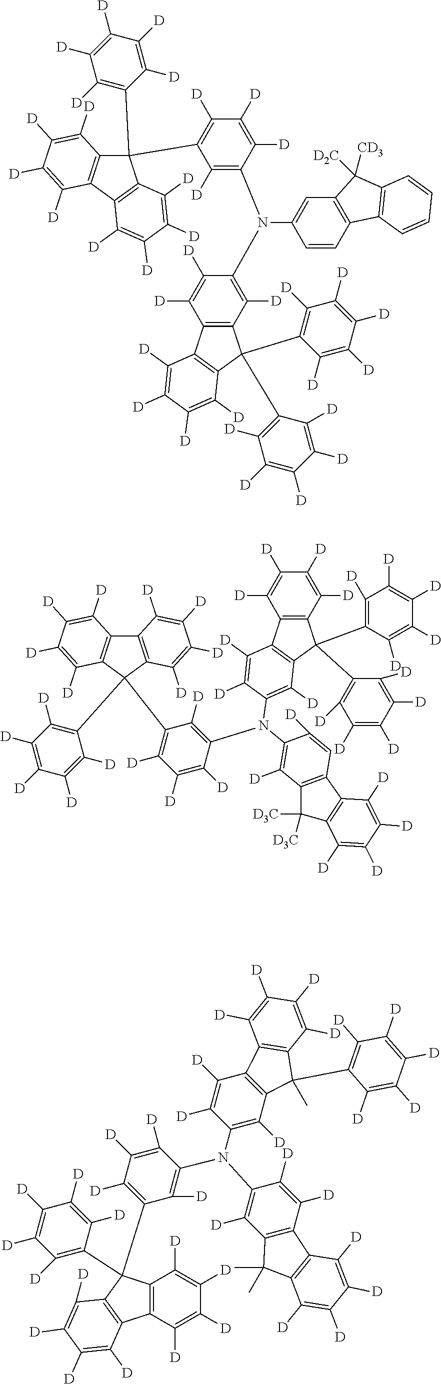

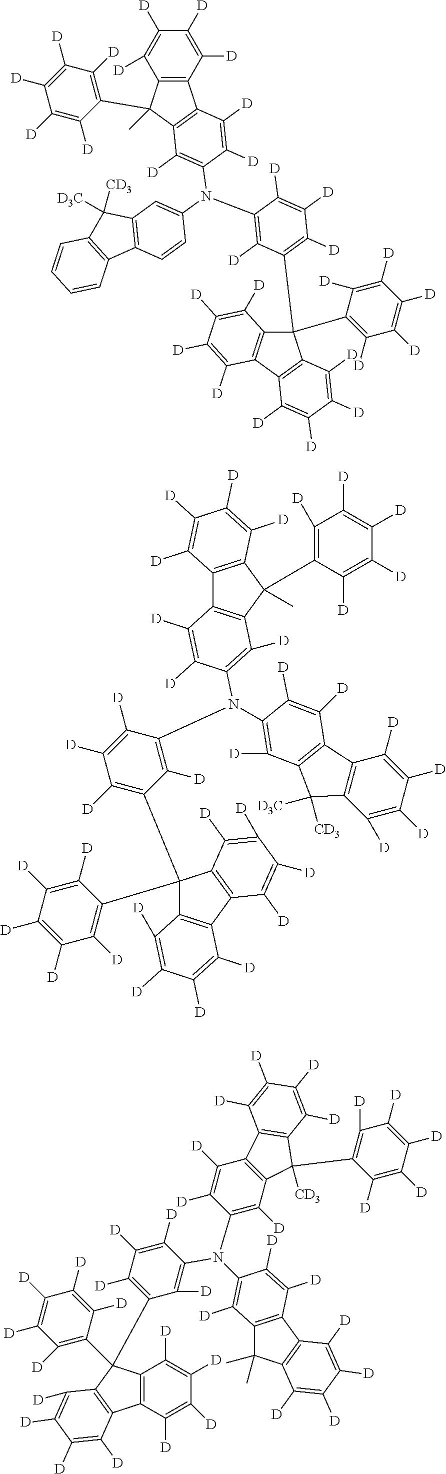

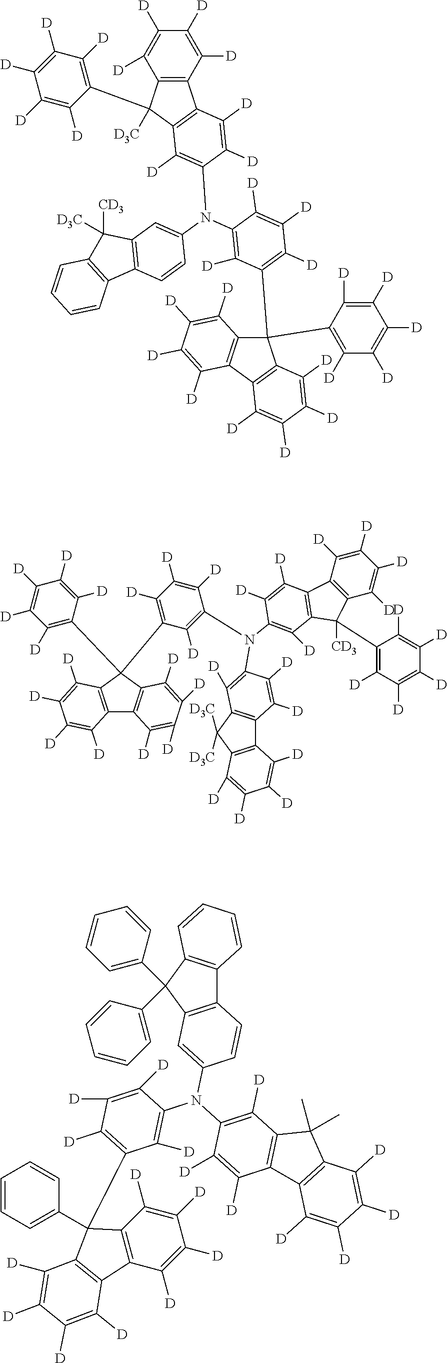

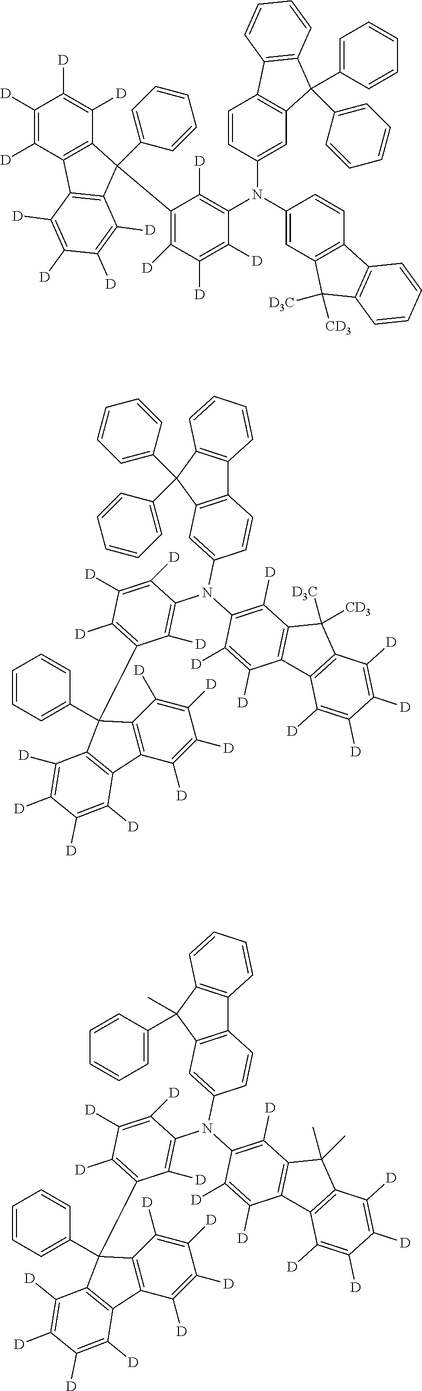

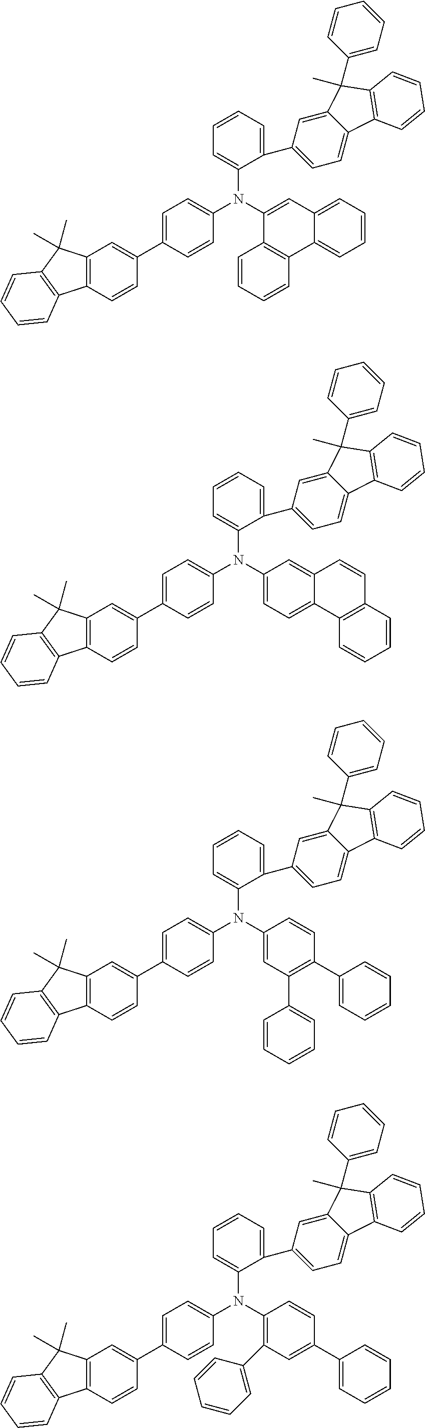 [SMILES: CC1(C)c2ccccc2-c2ccc(-c3ccc(N(c4ccccc4-c4ccc5c(c4)C(C)(c4ccccc4)c4ccccc4-5)c4cc5ccccc5c5ccccc45)cc3)cc21 ; CC1(C)c2ccccc2-c2ccc(-c3ccc(N(c4ccc5c(ccc6ccccc65)c4)c4ccccc4-c4ccc5c(c4)C(C)(c4ccccc4)c4ccccc4-5)cc3)cc21 ; CC1(C)c2ccccc2-c2ccc(-c3ccc(N(c4ccc(-c5ccccc5)c(-c5ccccc5)c4)c4ccccc4-c4ccc5c(c4)C(C)(c4ccccc4)c4ccccc4-5)cc3)cc21 ; CC1(C)c2ccccc2-c2ccc(-c3ccc(N(c4ccccc4-c4ccc5c(c4)C(C)(c4ccccc4)c4ccccc4-5)c4ccc(-c5ccccc5)cc4-c4ccccc4)cc3)cc21]

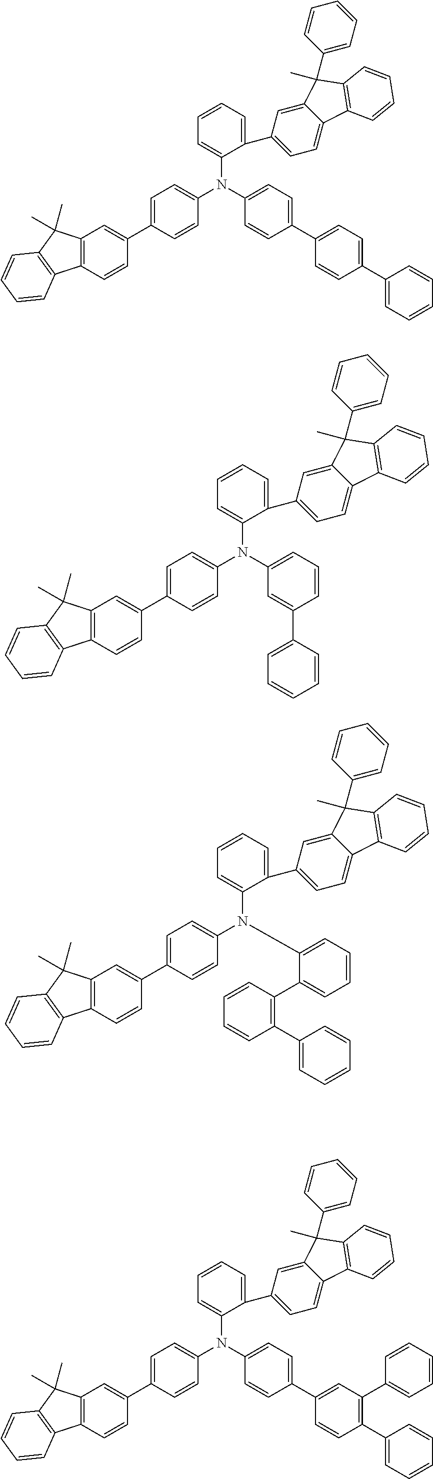 [SMILES: CC1(C)c2ccccc2-c2ccc(-c3ccc(N(c4ccc(-c5ccc(-c6ccccc6)cc5)cc4)c4ccccc4-c4ccc5c(c4)C(C)(c4ccccc4)c4ccccc4-5)cc3)cc21 ; CC1(C)c2ccccc2-c2ccc(-c3ccc(N(c4cccc(-c5ccccc5)c4)c4ccccc4-c4ccc5c(c4)C(C)(c4ccccc4)c4ccccc4-5)cc3)cc21 ; CC1(C)c2ccccc2-c2ccc(-c3ccc(N(c4ccccc4-c4ccc5c(c4)C(C)(c4ccccc4)c4ccccc4-5)c4ccccc4-c4ccccc4-c4ccccc4)cc3)cc21 ; CC1(C)c2ccccc2-c2ccc(-c3ccc(N(c4ccc(-c5ccc(-c6ccccc6)c(-c6ccccc6)c5)cc4)c4ccccc4-c4ccc5c(c4)C(C)(c4ccccc4)c4ccccc4-5)cc3)cc21]

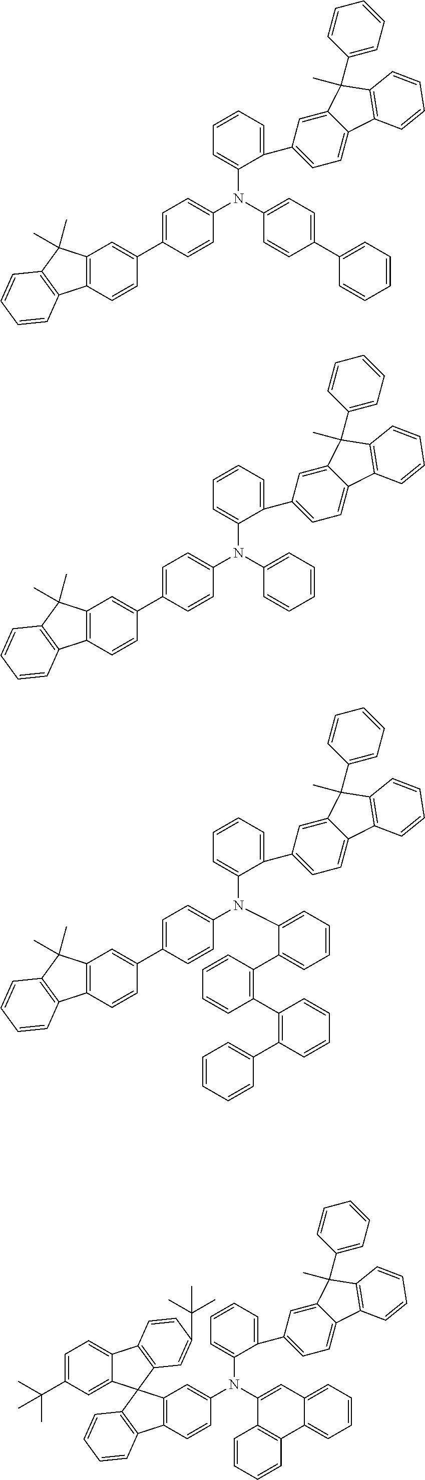 [SMILES: CC1(C)c2ccccc2-c2ccc(-c3ccc(N(c4ccc(-c5ccccc5)cc4)c4ccccc4-c4ccc5c(c4)C(C)(c4ccccc4)c4ccccc4-5)cc3)cc21 ; CC1(C)c2ccccc2-c2ccc(-c3ccc(N(c4ccccc4)c4ccccc4-c4ccc5c(c4)C(C)(c4ccccc4)c4ccccc4-5)cc3)cc21 ; CC1(C)c2ccccc2-c2ccc(-c3ccc(N(c4ccccc4-c4ccc5c(c4)C(C)(c4ccccc4)c4ccccc4-5)c4ccccc4-c4ccccc4-c4ccccc4-c4ccccc4)cc3)cc21 ; CC(C)(C)c1ccc2c(c1)C1(c3ccccc3-c3ccc(N(c4ccccc4-c4ccc5c(c4)C(C)(c4ccccc4)c4ccccc4-5)c4cc5ccccc5c5ccccc45)cc31)c1cc(C(C)(C)C)ccc1-2]

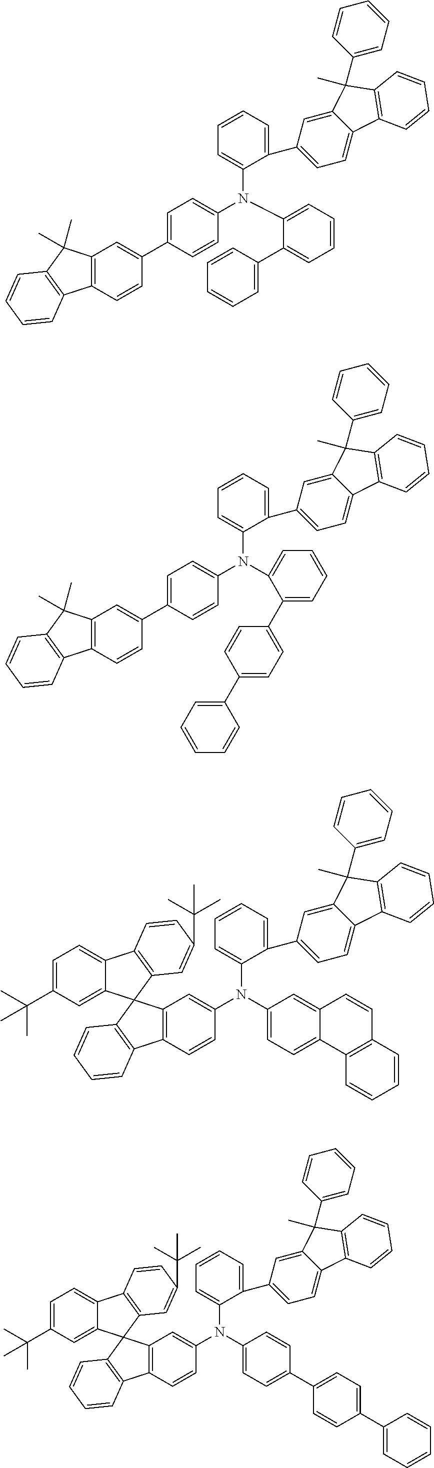 [SMILES: CC1(C)c2ccccc2-c2ccc(-c3ccc(N(c4ccccc4-c4ccccc4)c4ccccc4-c4ccc5c(c4)C(C)(c4ccccc4)c4ccccc4-5)cc3)cc21 ; CC1(C)c2ccccc2-c2ccc(-c3ccc(N(c4ccccc4-c4ccc(-c5ccccc5)cc4)c4ccccc4-c4ccc5c(c4)C(C)(c4ccccc4)c4ccccc4-5)cc3)cc21 ; CC(C)(C)c1ccc2c(c1)C1(c3ccccc3-c3ccc(N(c4ccc5c(ccc6ccccc65)c4)c4ccccc4-c4ccc5c(c4)C(C)(c4ccccc4)c4ccccc4-5)cc31)c1cc(C(C)(C)C)ccc1-2 ; CC(C)(C)c1ccc2c(c1)C1(c3ccccc3-c3ccc(N(c4ccc(-c5ccc(-c6ccccc6)cc5)cc4)c4ccccc4-c4ccc5c(c4)C(C)(c4ccccc4)c4ccccc4-5)cc31)c1cc(C(C)(C)C)ccc1-2]

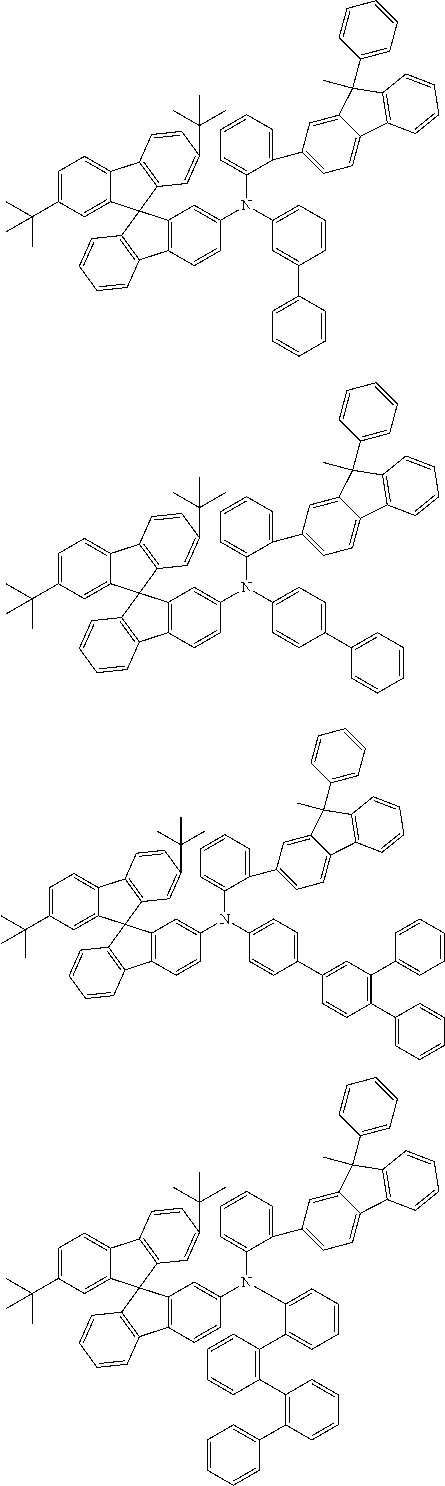

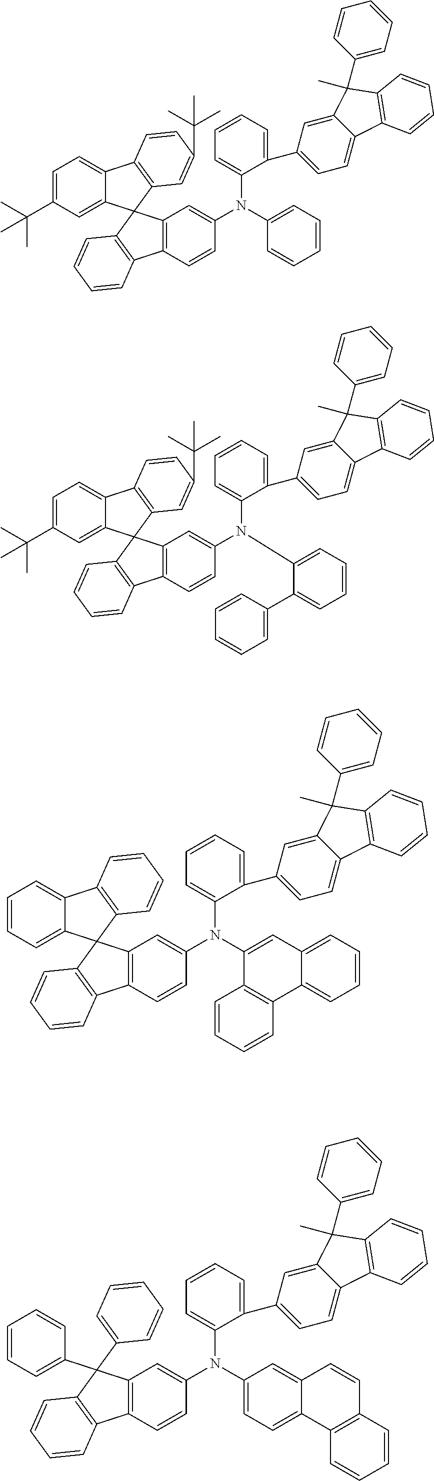 [SMILES: CC(C)(C)c1ccc2c(c1)C1(c3ccccc3-c3ccc(N(c4ccccc4)c4ccccc4-c4ccc5c(c4)C(C)(c4ccccc4)c4ccccc4-5)cc31)c1cc(C(C)(C)C)ccc1-2 ; CC(C)(C)c1ccc2c(c1)C1(c3ccccc3-c3ccc(N(c4ccccc4-c4ccccc4)c4ccccc4-c4ccc5c(c4)C(C)(c4ccccc4)c4ccccc4-5)cc31)c1cc(C(C)(C)C)ccc1-2 ; CC1(c2ccccc2)c2ccccc2-c2ccc(-c3ccccc3N(c3ccc4c(c3)C3(c5ccccc5-c5ccccc53)c3ccccc3-4)c3cc4ccccc4c4ccccc34)cc21 ; CC1(c2ccccc2)c2ccccc2-c2ccc(-c3ccccc3N(c3ccc4c(c3)C(c3ccccc3)(c3ccccc3)c3ccccc3-4)c3ccc4c(ccc5ccccc54)c3)cc21]

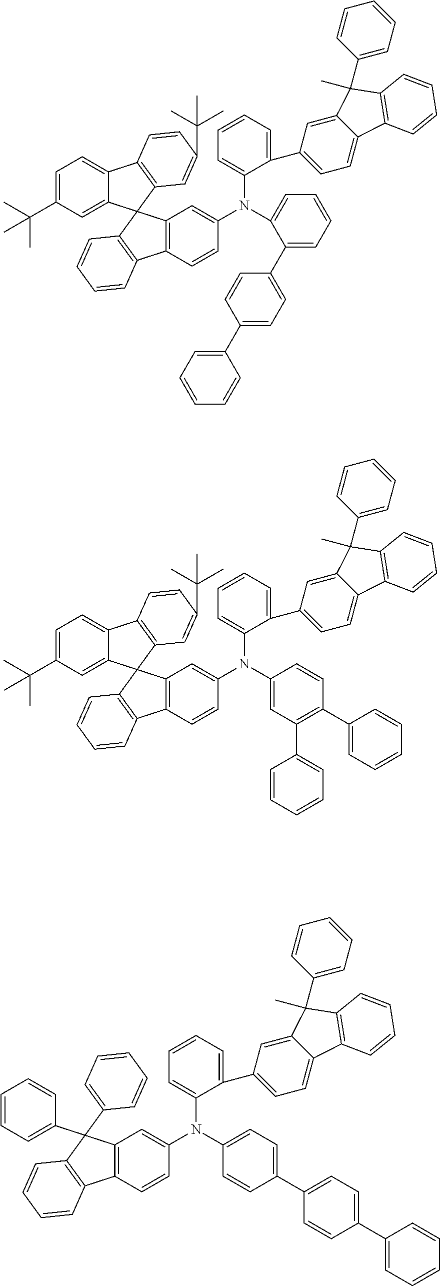 [SMILES: CC(C)(C)c1ccc2c(c1)C1(c3ccccc3-c3ccc(N(c4ccccc4-c4ccc(-c5ccccc5)cc4)c4ccccc4-c4ccc5c(c4)C(C)(c4ccccc4)c4ccccc4-5)cc31)c1cc(C(C)(C)C)ccc1-2 ; CC(C)(C)c1ccc2c(c1)C1(c3ccccc3-c3ccc(N(c4ccc(-c5ccccc5)c(-c5ccccc5)c4)c4ccccc4-c4ccc5c(c4)C(C)(c4ccccc4)c4ccccc4-5)cc31)c1cc(C(C)(C)C)ccc1-2 ; CC1(c2ccccc2)c2ccccc2-c2ccc(-c3ccccc3N(c3ccc(-c4ccc(-c5ccccc5)cc4)cc3)c3ccc4c(c3)C(c3ccccc3)(c3ccccc3)c3ccccc3-4)cc21]

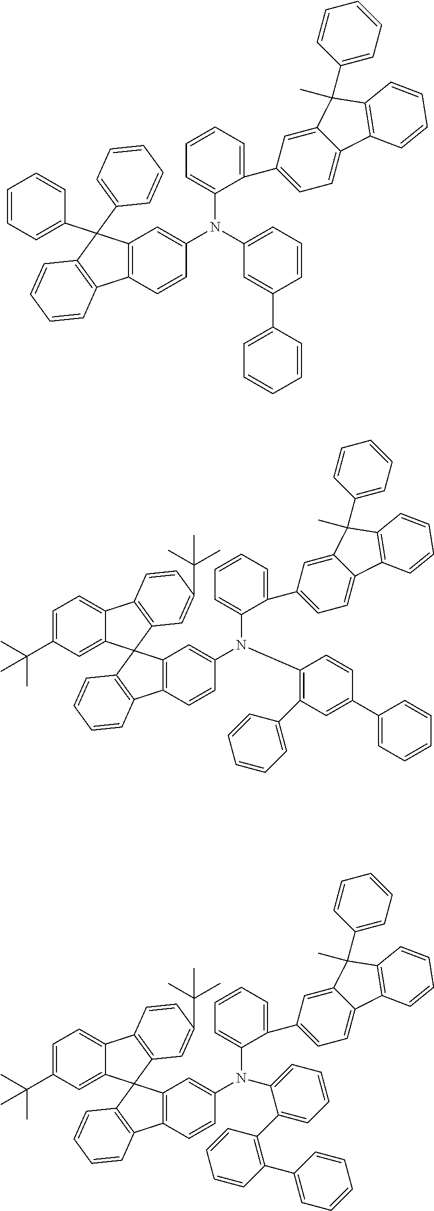 [SMILES: CC1(c2ccccc2)c2ccccc2-c2ccc(-c3ccccc3N(c3cccc(-c4ccccc4)c3)c3ccc4c(c3)C(c3ccccc3)(c3ccccc3)c3ccccc3-4)cc21 ; CC(C)(C)c1ccc2c(c1)C1(c3ccccc3-c3ccc(N(c4ccccc4-c4ccc5c(c4)C(C)(c4ccccc4)c4ccccc4-5)c4ccc(-c5ccccc5)cc4-c4ccccc4)cc31)c1cc(C(C)(C)C)ccc1-2 ; CC(C)(C)c1ccc2c(c1)C1(c3ccccc3-c3ccc(N(c4ccccc4-c4ccc5c(c4)C(C)(c4ccccc4)c4ccccc4-5)c4ccccc4-c4ccccc4-c4ccccc4)cc31)c1cc(C(C)(C)C)ccc1-2]

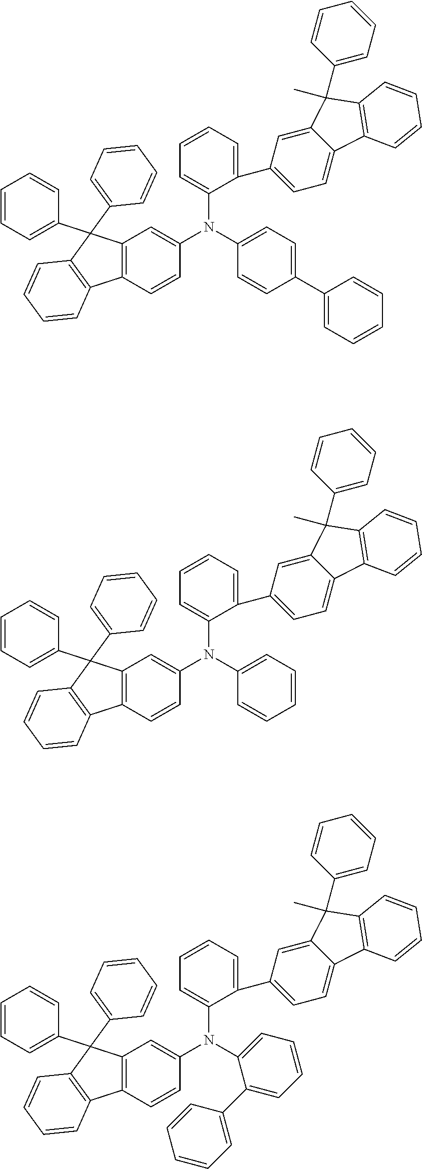 [SMILES: CC1(c2ccccc2)c2ccccc2-c2ccc(-c3ccccc3N(c3ccc(-c4ccccc4)cc3)c3ccc4c(c3)C(c3ccccc3)(c3ccccc3)c3ccccc3-4)cc21 ; CC1(c2ccccc2)c2ccccc2-c2ccc(-c3ccccc3N(c3ccccc3)c3ccc4c(c3)C(c3ccccc3)(c3ccccc3)c3ccccc3-4)cc21 ; CC1(c2ccccc2)c2ccccc2-c2ccc(-c3ccccc3N(c3ccc4c(c3)C(c3ccccc3)(c3ccccc3)c3ccccc3-4)c3ccccc3-c3ccccc3)cc21]

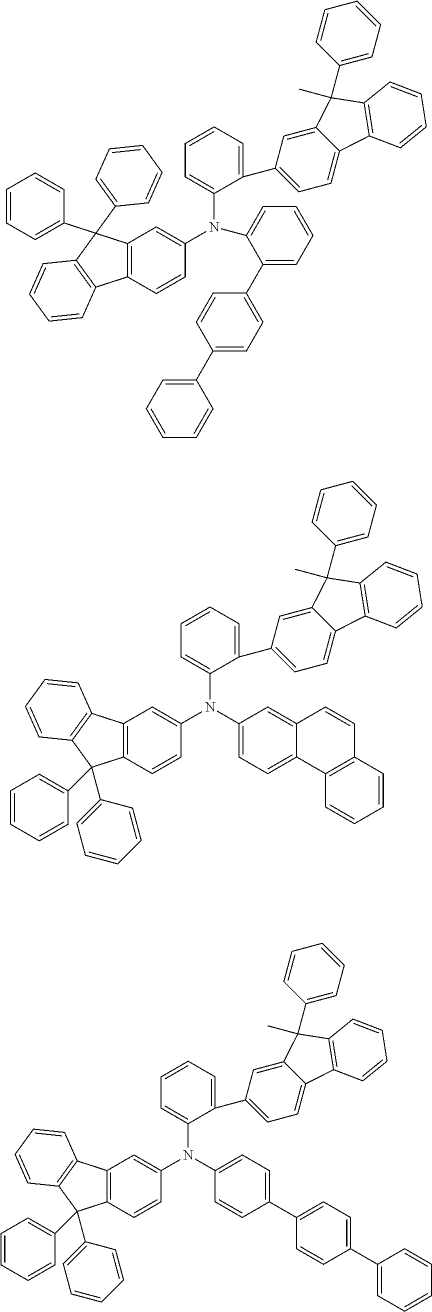 [SMILES: CC1(c2ccccc2)c2ccccc2-c2ccc(-c3ccccc3N(c3ccc4c(c3)C(c3ccccc3)(c3ccccc3)c3ccccc3-4)c3ccccc3-c3ccc(-c4ccccc4)cc3)cc21 ; CC1(c2ccccc2)c2ccccc2-c2ccc(-c3ccccc3N(c3ccc4c(c3)-c3ccccc3C4(c3ccccc3)c3ccccc3)c3ccc4c(ccc5ccccc54)c3)cc21 ; CC1(c2ccccc2)c2ccccc2-c2ccc(-c3ccccc3N(c3ccc(-c4ccc(-c5ccccc5)cc4)cc3)c3ccc4c(c3)-c3ccccc3C4(c3ccccc3)c3ccccc3)cc21]

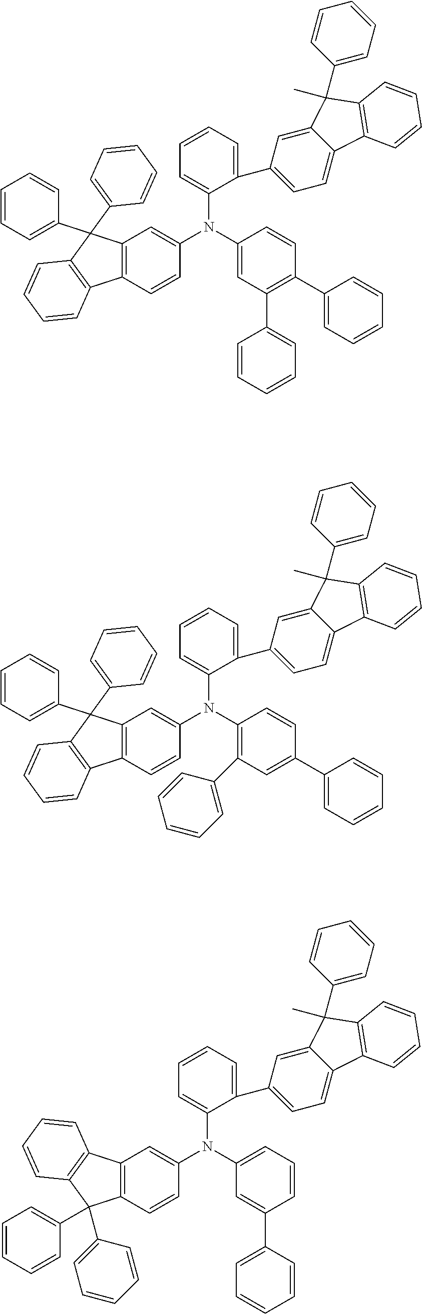 [SMILES: CC1(c2ccccc2)c2ccccc2-c2ccc(-c3ccccc3N(c3ccc(-c4ccccc4)c(-c4ccccc4)c3)c3ccc4c(c3)C(c3ccccc3)(c3ccccc3)c3ccccc3-4)cc21 ; CC1(c2ccccc2)c2ccccc2-c2ccc(-c3ccccc3N(c3ccc4c(c3)C(c3ccccc3)(c3ccccc3)c3ccccc3-4)c3ccc(-c4ccccc4)cc3-c3ccccc3)cc21 ; CC1(c2ccccc2)c2ccccc2-c2ccc(-c3ccccc3N(c3cccc(-c4ccccc4)c3)c3ccc4c(c3)-c3ccccc3C4(c3ccccc3)c3ccccc3)cc21]

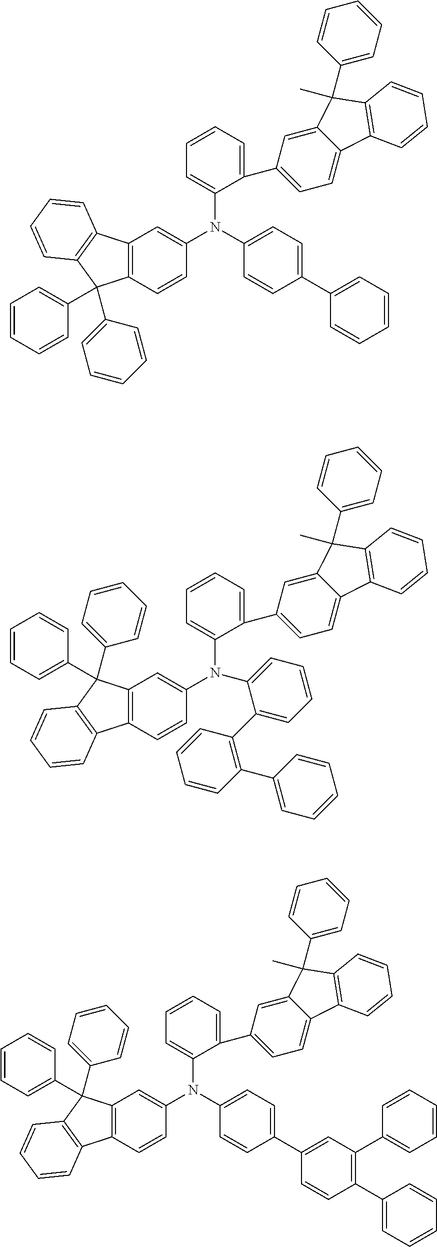 [SMILES: CC1(c2ccccc2)c2ccccc2-c2ccc(-c3ccccc3N(c3ccc(-c4ccccc4)cc3)c3ccc4c(c3)-c3ccccc3C4(c3ccccc3)c3ccccc3)cc21 ; CC1(c2ccccc2)c2ccccc2-c2ccc(-c3ccccc3N(c3ccc4c(c3)C(c3ccccc3)(c3ccccc3)c3ccccc3-4)c3ccccc3-c3ccccc3-c3ccccc3)cc21 ; CC1(c2ccccc2)c2ccccc2-c2ccc(-c3ccccc3N(c3ccc(-c4ccc(-c5ccccc5)c(-c5ccccc5)c4)cc3)c3ccc4c(c3)C(c3ccccc3)(c3ccccc3)c3ccccc3-4)cc21]

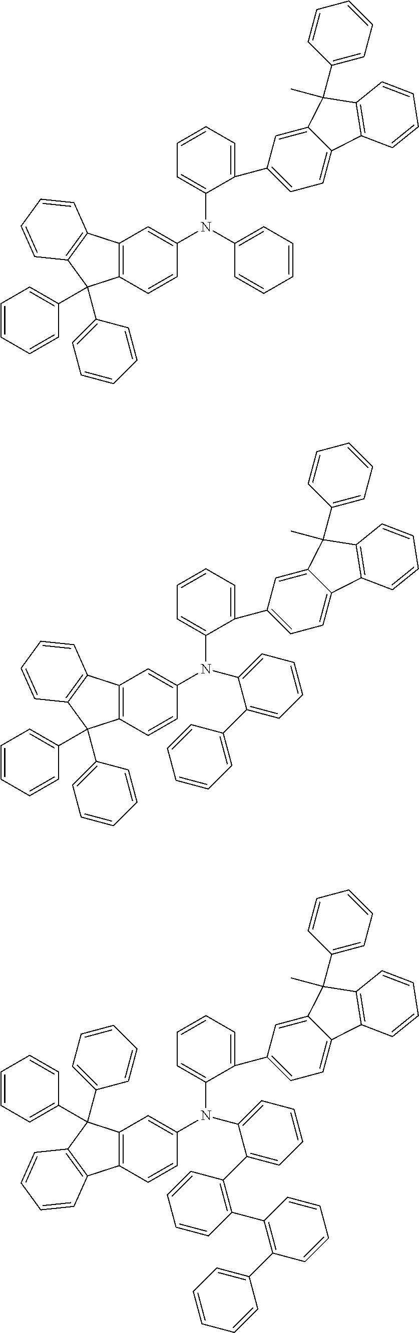 [SMILES: CC1(c2ccccc2)c2ccccc2-c2ccc(-c3ccccc3N(c3ccccc3)c3ccc4c(c3)-c3ccccc3C4(c3ccccc3)c3ccccc3)cc21 ; CC1(c2ccccc2)c2ccccc2-c2ccc(-c3ccccc3N(c3ccc4c(c3)-c3ccccc3C4(c3ccccc3)c3ccccc3)c3ccccc3-c3ccccc3)cc21 ; CC1(c2ccccc2)c2ccccc2-c2ccc(-c3ccccc3N(c3ccc4c(c3)C(c3ccccc3)(c3ccccc3)c3ccccc3-4)c3ccccc3-c3ccccc3-c3ccccc3-c3ccccc3)cc21]

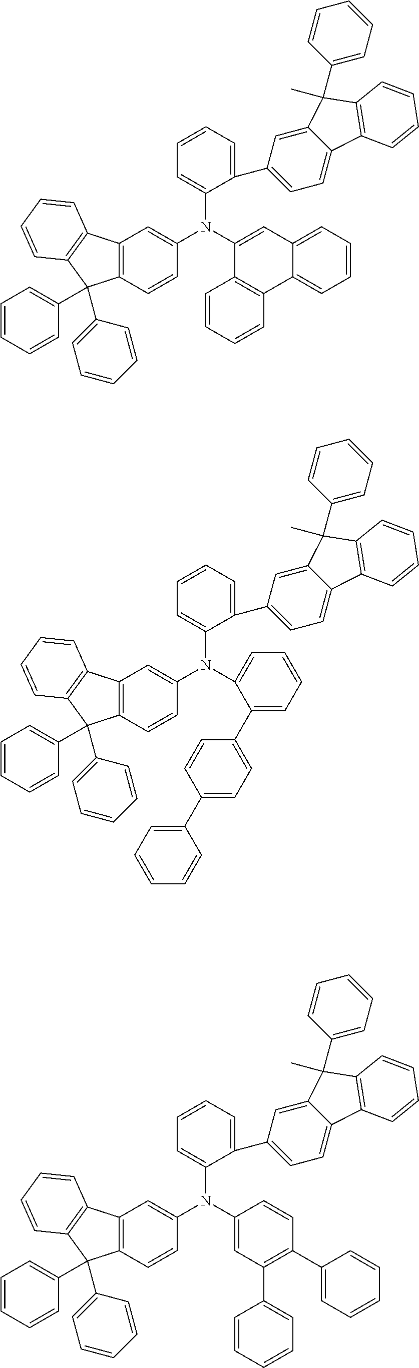 [SMILES: CC1(c2ccccc2)c2ccccc2-c2ccc(-c3ccccc3N(c3ccc4c(c3)-c3ccccc3C4(c3ccccc3)c3ccccc3)c3cc4ccccc4c4ccccc34)cc21 ; CC1(c2ccccc2)c2ccccc2-c2ccc(-c3ccccc3N(c3ccc4c(c3)-c3ccccc3C4(c3ccccc3)c3ccccc3)c3ccccc3-c3ccc(-c4ccccc4)cc3)cc21 ; CC1(c2ccccc2)c2ccccc2-c2ccc(-c3ccccc3N(c3ccc(-c4ccccc4)c(-c4ccccc4)c3)c3ccc4c(c3)-c3ccccc3C4(c3ccccc3)c3ccccc3)cc21]

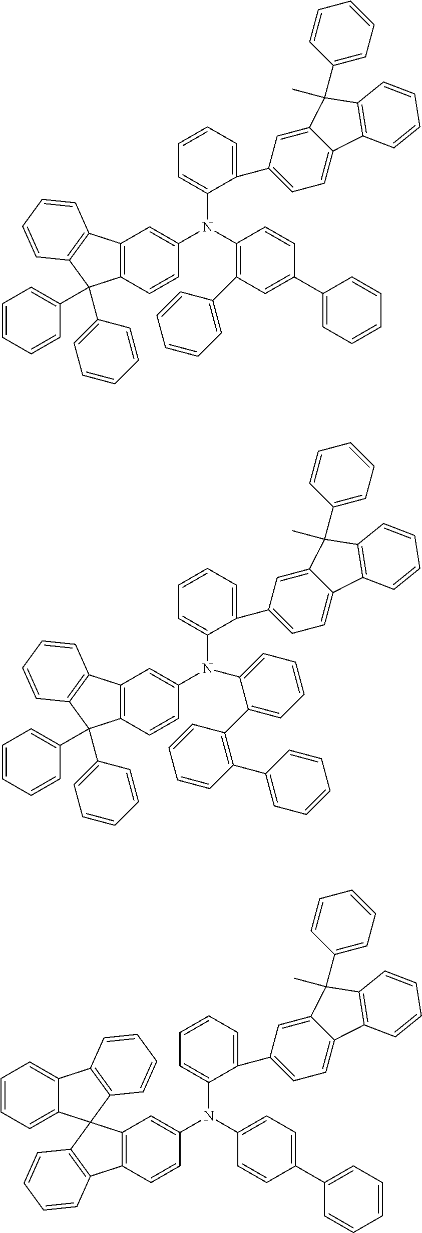 [SMILES: CC1(c2ccccc2)c2ccccc2-c2ccc(-c3ccccc3N(c3ccc4c(c3)-c3ccccc3C4(c3ccccc3)c3ccccc3)c3ccc(-c4ccccc4)cc3-c3ccccc3)cc21 ; CC1(c2ccccc2)c2ccccc2-c2ccc(-c3ccccc3N(c3ccc4c(c3)-c3ccccc3C4(c3ccccc3)c3ccccc3)c3ccccc3-c3ccccc3-c3ccccc3)cc21 ; CC1(c2ccccc2)c2ccccc2-c2ccc(-c3ccccc3N(c3ccc(-c4ccccc4)cc3)c3ccc4c(c3)C3(c5ccccc5-c5ccccc53)c3ccccc3-4)cc21]

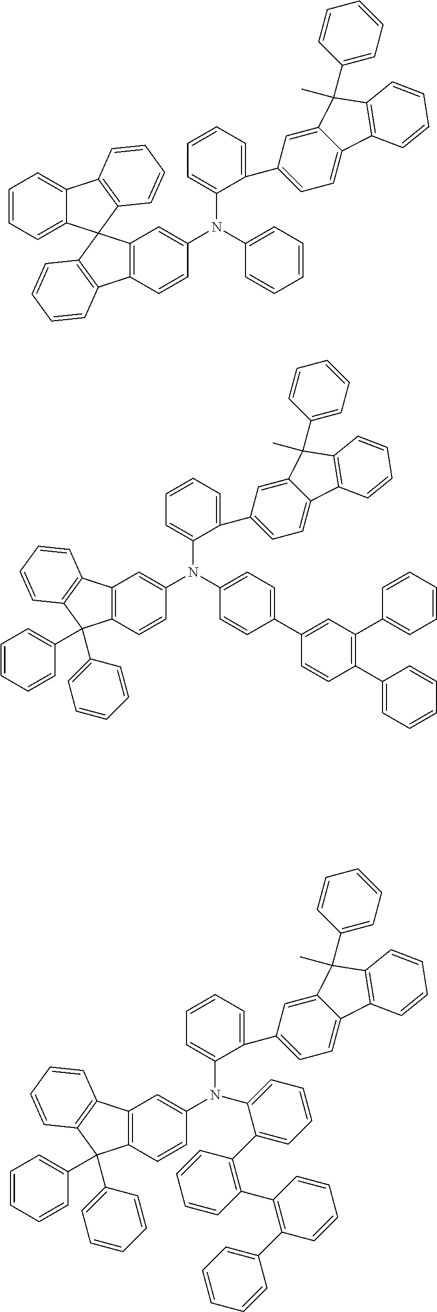 [SMILES: CC1(c2ccccc2)c2ccccc2-c2ccc(-c3ccccc3N(c3ccccc3)c3ccc4c(c3)C3(c5ccccc5-c5ccccc53)c3ccccc3-4)cc21 ; CC1(c2ccccc2)c2ccccc2-c2ccc(-c3ccccc3N(c3ccc(-c4ccc(-c5ccccc5)c(-c5ccccc5)c4)cc3)c3ccc4c(c3)-c3ccccc3C4(c3ccccc3)c3ccccc3)cc21 ; CC1(c2ccccc2)c2ccccc2-c2ccc(-c3ccccc3N(c3ccc4c(c3)-c3ccccc3C4(c3ccccc3)c3ccccc3)c3ccccc3-c3ccccc3-c3ccccc3-c3ccccc3)cc21]

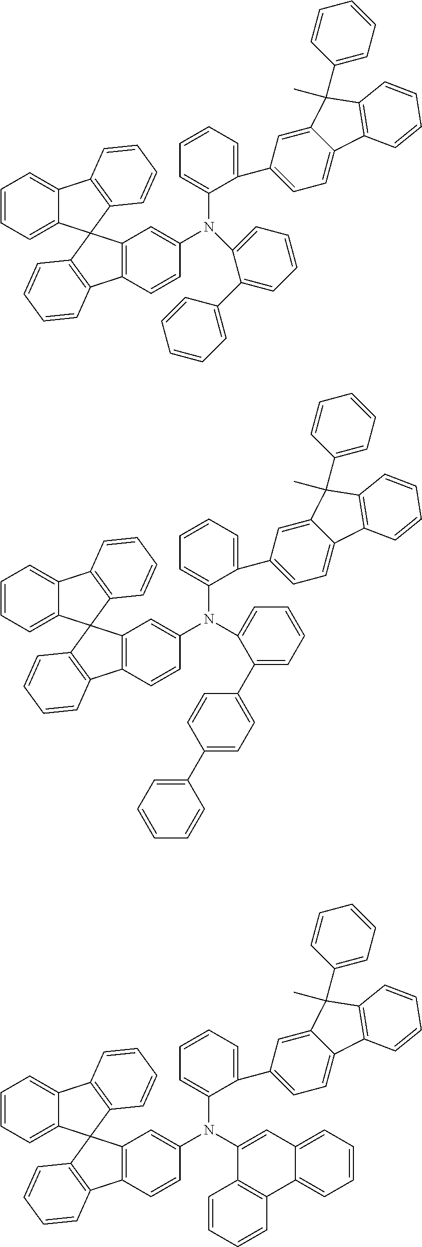 [SMILES: CC1(c2ccccc2)c2ccccc2-c2ccc(-c3ccccc3N(c3ccc4c(c3)C3(c5ccccc5-c5ccccc53)c3ccccc3-4)c3ccccc3-c3ccccc3)cc21 ; CC1(c2ccccc2)c2ccccc2-c2ccc(-c3ccccc3N(c3ccc4c(c3)C3(c5ccccc5-c5ccccc53)c3ccccc3-4)c3ccccc3-c3ccc(-c4ccccc4)cc3)cc21 ; CC1(c2ccccc2)c2ccccc2-c2ccc(-c3ccccc3N(c3ccc4c(c3)C3(c5ccccc5-c5ccccc53)c3ccccc3-4)c3cc4ccccc4c4ccccc34)cc21]

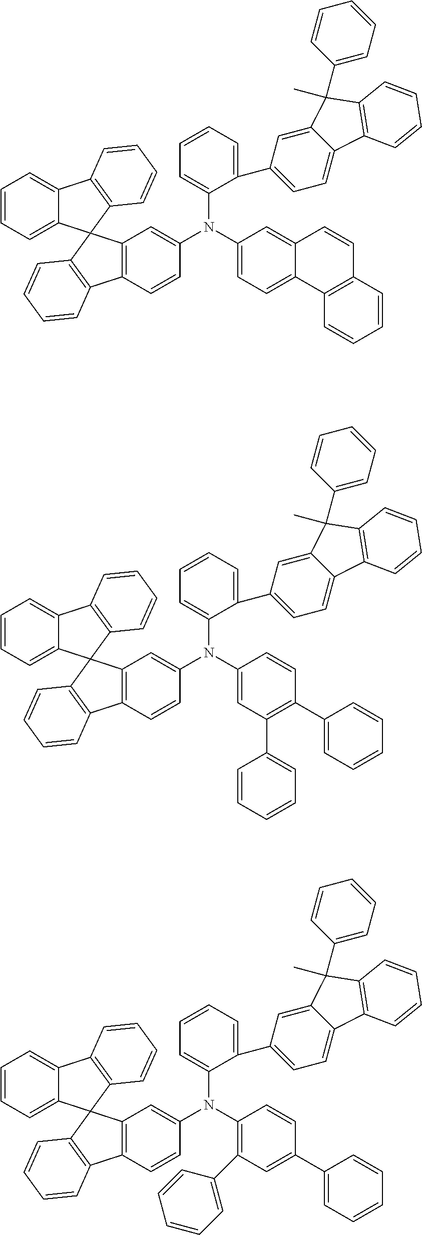 [SMILES: CC1(c2ccccc2)c2ccccc2-c2ccc(-c3ccccc3N(c3ccc4c(c3)C3(c5ccccc5-c5ccccc53)c3ccccc3-4)c3ccc4c(ccc5ccccc54)c3)cc21 ; CC1(c2ccccc2)c2ccccc2-c2ccc(-c3ccccc3N(c3ccc(-c4ccccc4)c(-c4ccccc4)c3)c3ccc4c(c3)C3(c5ccccc5-c5ccccc53)c3ccccc3-4)cc21 ; CC1(c2ccccc2)c2ccccc2-c2ccc(-c3ccccc3N(c3ccc4c(c3)C3(c5ccccc5-c5ccccc53)c3ccccc3-4)c3ccc(-c4ccccc4)cc3-c3ccccc3)cc21]

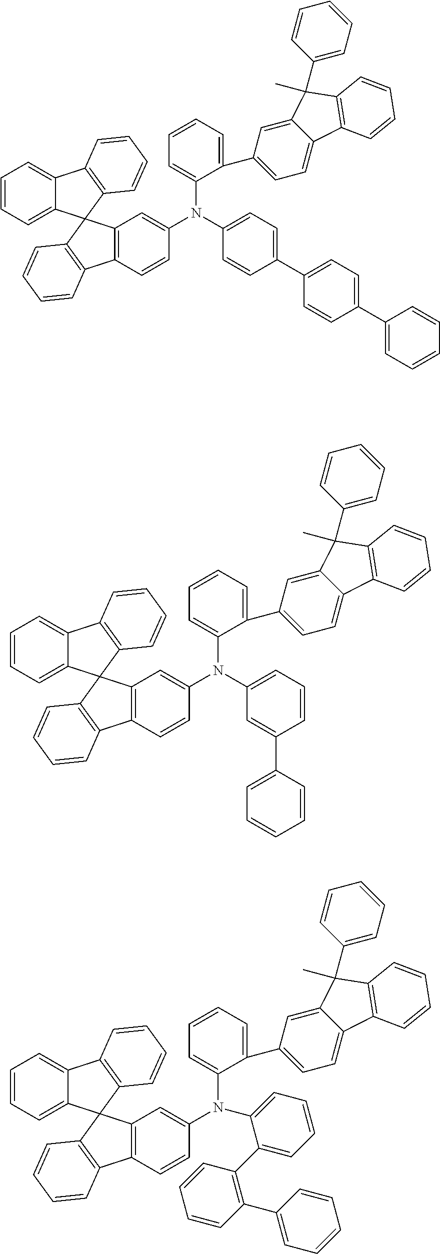 [SMILES: CC1(c2ccccc2)c2ccccc2-c2ccc(-c3ccccc3N(c3ccc(-c4ccc(-c5ccccc5)cc4)cc3)c3ccc4c(c3)C3(c5ccccc5-c5ccccc53)c3ccccc3-4)cc21 ; CC1(c2ccccc2)c2ccccc2-c2ccc(-c3ccccc3N(c3cccc(-c4ccccc4)c3)c3ccc4c(c3)C3(c5ccccc5-c5ccccc53)c3ccccc3-4)cc21 ; CC1(c2ccccc2)c2ccccc2-c2ccc(-c3ccccc3N(c3ccc4c(c3)C3(c5ccccc5-c5ccccc53)c3ccccc3-4)c3ccccc3-c3ccccc3-c3ccccc3)cc21]

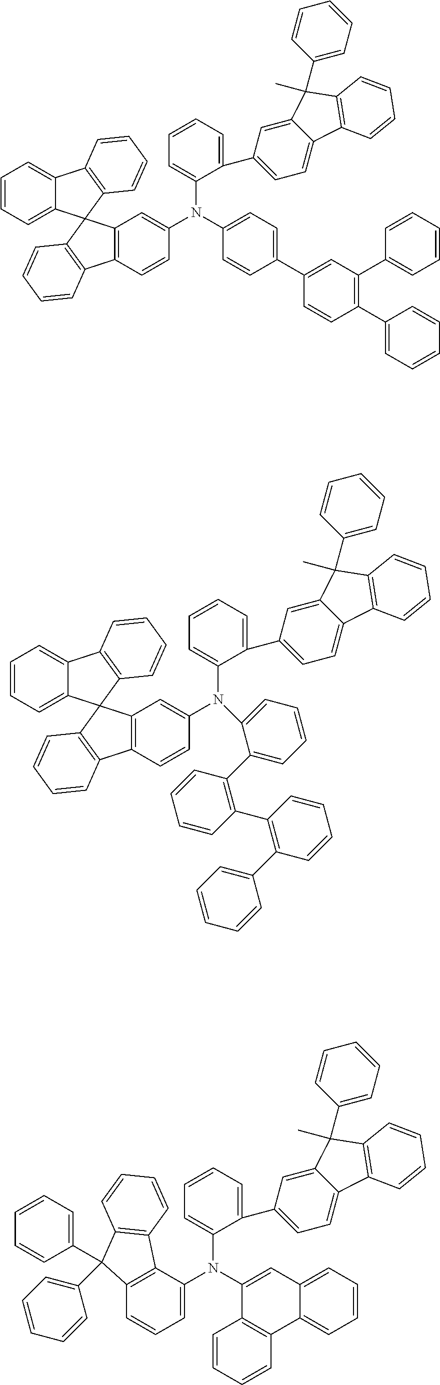 [SMILES: CC1(c2ccccc2)c2ccccc2-c2ccc(-c3ccccc3N(c3ccc(-c4ccc(-c5ccccc5)c(-c5ccccc5)c4)cc3)c3ccc4c(c3)C3(c5ccccc5-c5ccccc53)c3ccccc3-4)cc21 ; CC1(c2ccccc2)c2ccccc2-c2ccc(-c3ccccc3N(c3ccc4c(c3)C3(c5ccccc5-c5ccccc53)c3ccccc3-4)c3ccccc3-c3ccccc3-c3ccccc3-c3ccccc3)cc21 ; CC1(c2ccccc2)c2ccccc2-c2ccc(-c3ccccc3N(c3cccc4c3-c3ccccc3C4(c3ccccc3)c3ccccc3)c3cc4ccccc4c4ccccc34)cc21]

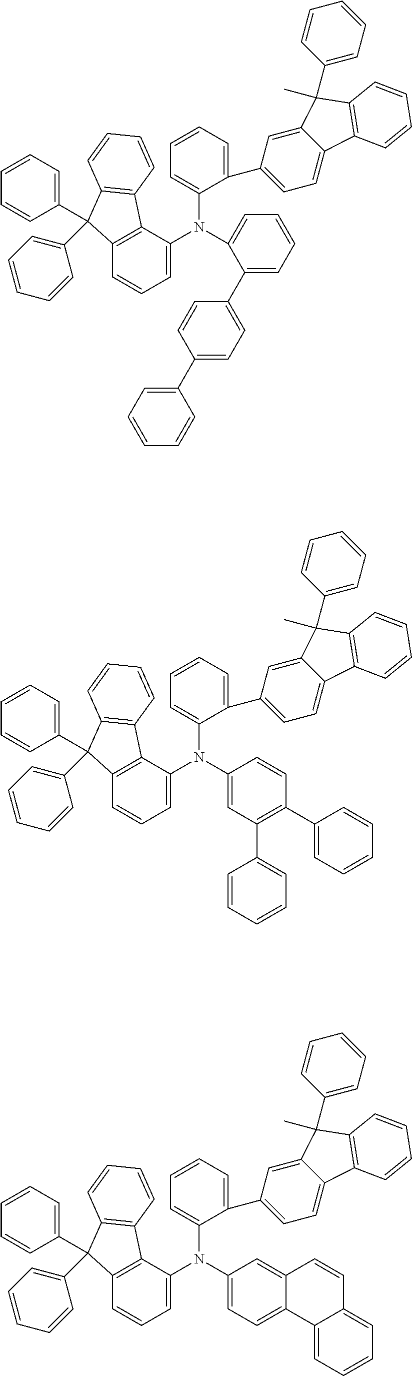 [SMILES: CC1(c2ccccc2)c2ccccc2-c2ccc(-c3ccccc3N(c3ccccc3-c3ccc(-c4ccccc4)cc3)c3cccc4c3-c3ccccc3C4(c3ccccc3)c3ccccc3)cc21 ; CC1(c2ccccc2)c2ccccc2-c2ccc(-c3ccccc3N(c3ccc(-c4ccccc4)c(-c4ccccc4)c3)c3cccc4c3-c3ccccc3C4(c3ccccc3)c3ccccc3)cc21 ; CC1(c2ccccc2)c2ccccc2-c2ccc(-c3ccccc3N(c3ccc4c(ccc5ccccc54)c3)c3cccc4c3-c3ccccc3C4(c3ccccc3)c3ccccc3)cc21]

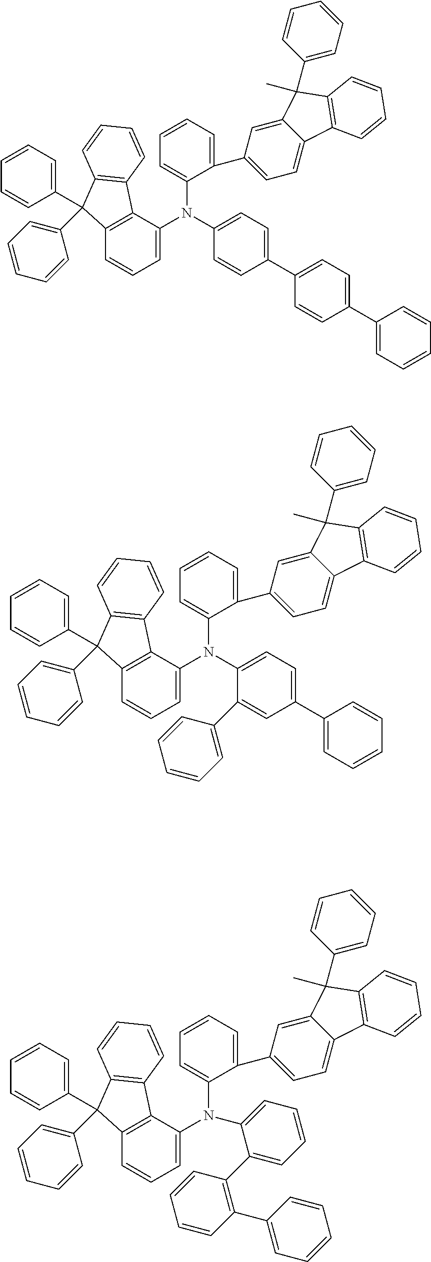 [SMILES: CC1(c2ccccc2)c2ccccc2-c2ccc(-c3ccccc3N(c3ccc(-c4ccc(-c5ccccc5)cc4)cc3)c3cccc4c3-c3ccccc3C4(c3ccccc3)c3ccccc3)cc21 ; CC1(c2ccccc2)c2ccccc2-c2ccc(-c3ccccc3N(c3ccc(-c4ccccc4)cc3-c3ccccc3)c3cccc4c3-c3ccccc3C4(c3ccccc3)c3ccccc3)cc21 ; CC1(c2ccccc2)c2ccccc2-c2ccc(-c3ccccc3N(c3ccccc3-c3ccccc3-c3ccccc3)c3cccc4c3-c3ccccc3C4(c3ccccc3)c3ccccc3)cc21]

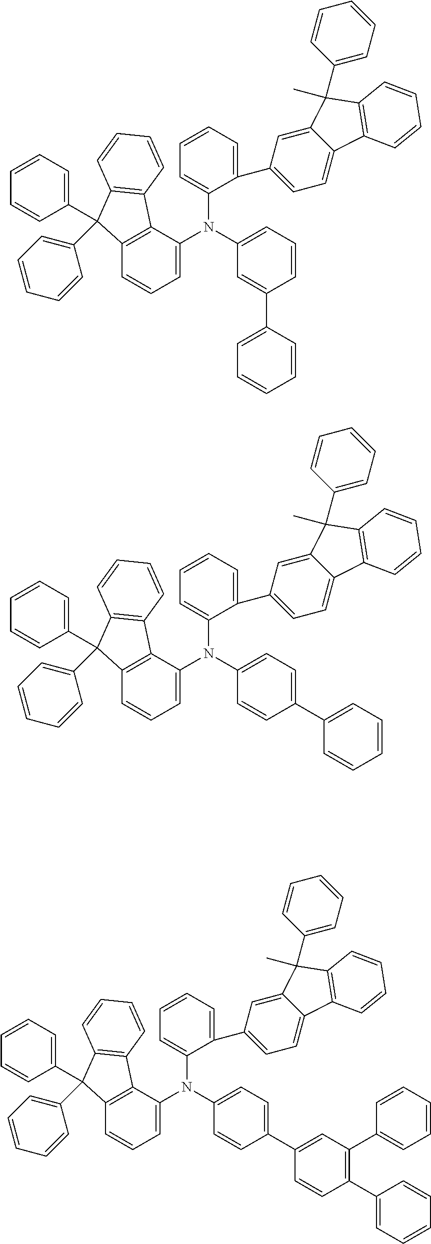 [SMILES: CC1(c2ccccc2)c2ccccc2-c2ccc(-c3ccccc3N(c3cccc(-c4ccccc4)c3)c3cccc4c3-c3ccccc3C4(c3ccccc3)c3ccccc3)cc21 ; CC1(c2ccccc2)c2ccccc2-c2ccc(-c3ccccc3N(c3ccc(-c4ccccc4)cc3)c3cccc4c3-c3ccccc3C4(c3ccccc3)c3ccccc3)cc21 ; CC1(c2ccccc2)c2ccccc2-c2ccc(-c3ccccc3N(c3ccc(-c4ccc(-c5ccccc5)c(-c5ccccc5)c4)cc3)c3cccc4c3-c3ccccc3C4(c3ccccc3)c3ccccc3)cc21]

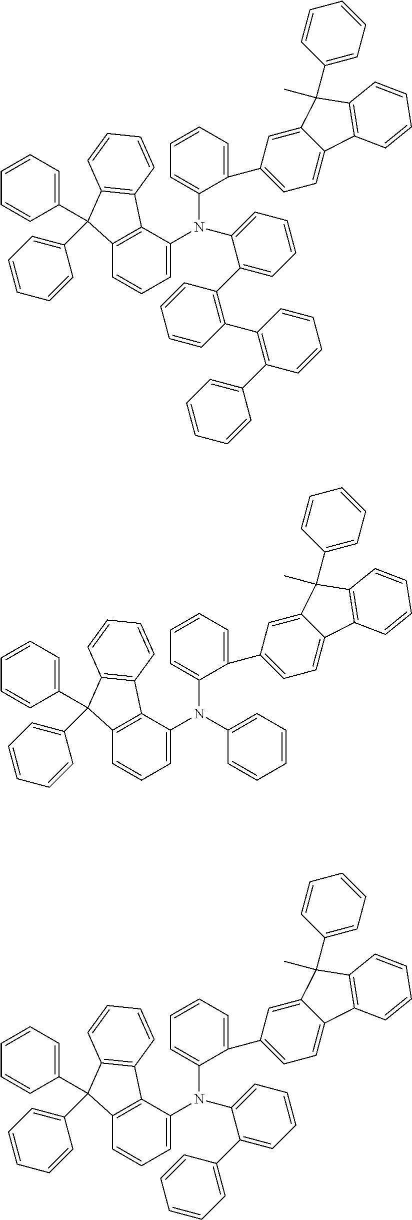 [SMILES: CC1(c2ccccc2)c2ccccc2-c2ccc(-c3ccccc3N(c3ccccc3-c3ccccc3-c3ccccc3-c3ccccc3)c3cccc4c3-c3ccccc3C4(c3ccccc3)c3ccccc3)cc21 ; CC1(c2ccccc2)c2ccccc2-c2ccc(-c3ccccc3N(c3ccccc3)c3cccc4c3-c3ccccc3C4(c3ccccc3)c3ccccc3)cc21 ; CC1(c2ccccc2)c2ccccc2-c2ccc(-c3ccccc3N(c3ccccc3-c3ccccc3)c3cccc4c3-c3ccccc3C4(c3ccccc3)c3ccccc3)cc21]

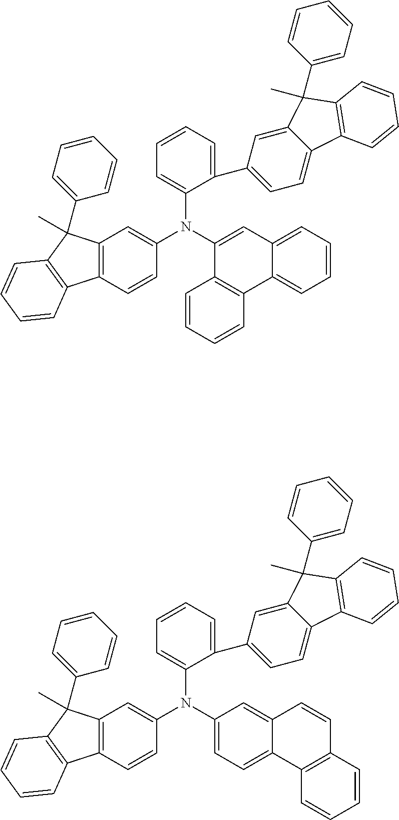 [SMILES: CC1(c2ccccc2)c2ccccc2-c2ccc(-c3ccccc3N(c3ccc4c(c3)C(C)(c3ccccc3)c3ccccc3-4)c3cc4ccccc4c4ccccc34)cc21 ; CC1(c2ccccc2)c2ccccc2-c2ccc(-c3ccccc3N(c3ccc4c(c3)C(C)(c3ccccc3)c3ccccc3-4)c3ccc4c(ccc5ccccc54)c3)cc21]

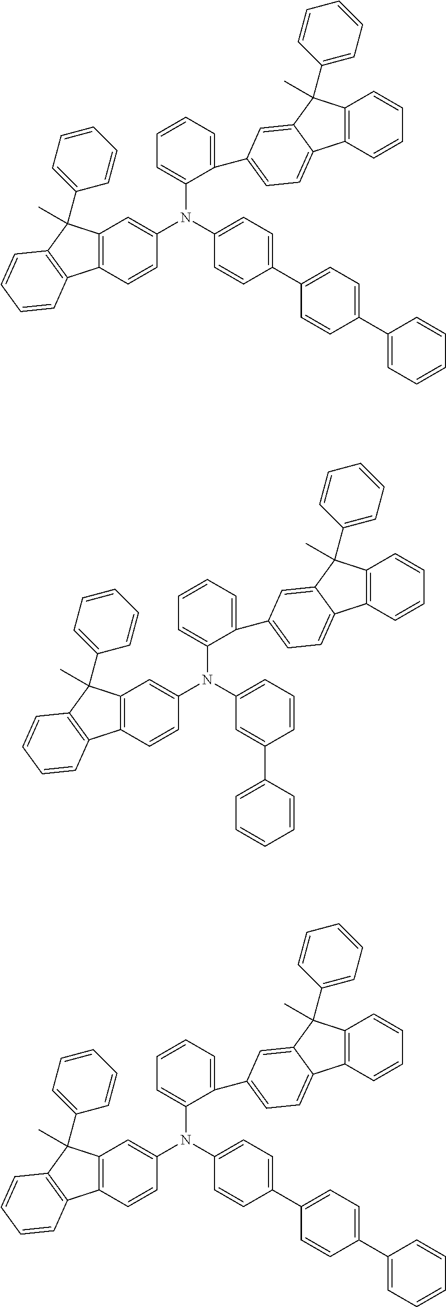 [SMILES: CC1(c2ccccc2)c2ccccc2-c2ccc(-c3ccccc3N(c3ccc(-c4ccc(-c5ccccc5)cc4)cc3)c3ccc4c(c3)C(C)(c3ccccc3)c3ccccc3-4)cc21 ; CC1(c2ccccc2)c2ccccc2-c2ccc(-c3ccccc3N(c3cccc(-c4ccccc4)c3)c3ccc4c(c3)C(C)(c3ccccc3)c3ccccc3-4)cc21 ; CC1(c2ccccc2)c2ccccc2-c2ccc(-c3ccccc3N(c3ccc(-c4ccc(-c5ccccc5)cc4)cc3)c3ccc4c(c3)C(C)(c3ccccc3)c3ccccc3-4)cc21]

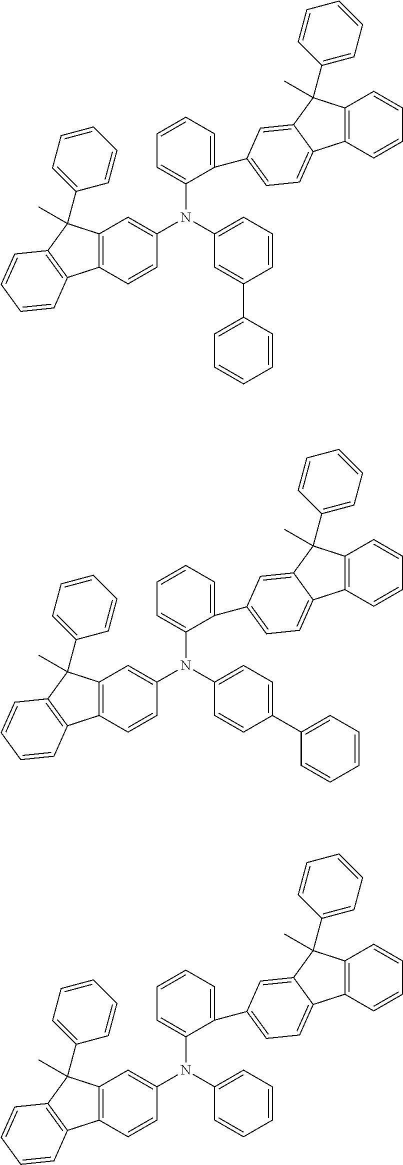 [SMILES: CC1(c2ccccc2)c2ccccc2-c2ccc(-c3ccccc3N(c3cccc(-c4ccccc4)c3)c3ccc4c(c3)C(C)(c3ccccc3)c3ccccc3-4)cc21 ; CC1(c2ccccc2)c2ccccc2-c2ccc(-c3ccccc3N(c3ccc(-c4ccccc4)cc3)c3ccc4c(c3)C(C)(c3ccccc3)c3ccccc3-4)cc21 ; CC1(c2ccccc2)c2ccccc2-c2ccc(-c3ccccc3N(c3ccccc3)c3ccc4c(c3)C(C)(c3ccccc3)c3ccccc3-4)cc21]

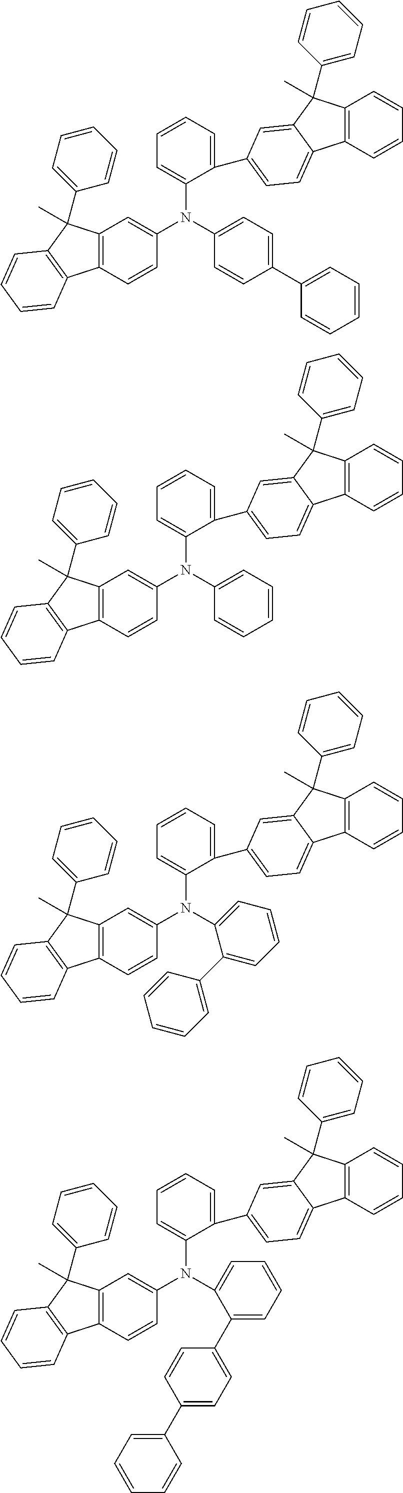

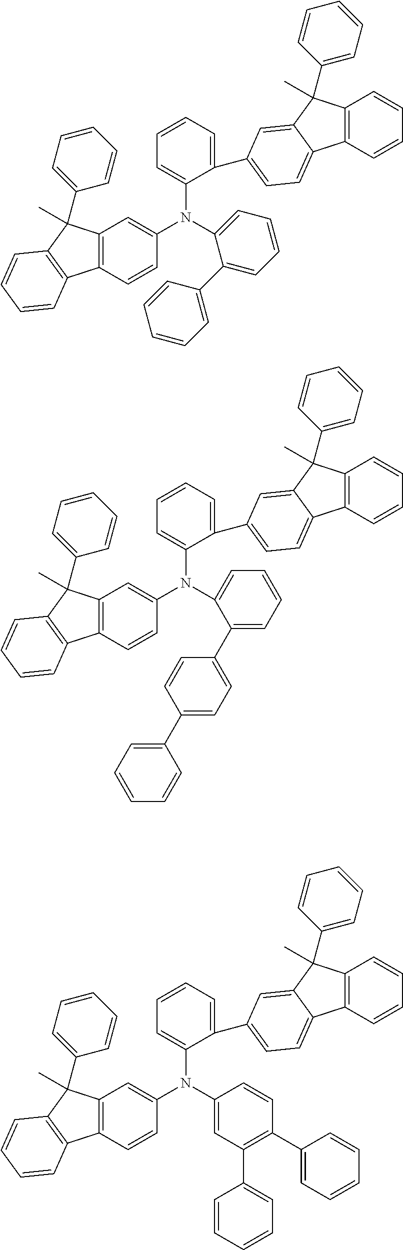 [SMILES: CC1(c2ccccc2)c2ccccc2-c2ccc(-c3ccccc3N(c3ccc4c(c3)C(C)(c3ccccc3)c3ccccc3-4)c3ccccc3-c3ccccc3)cc21 ; CC1(c2ccccc2)c2ccccc2-c2ccc(-c3ccccc3N(c3ccc4c(c3)C(C)(c3ccccc3)c3ccccc3-4)c3ccccc3-c3ccc(-c4ccccc4)cc3)cc21 ; CC1(c2ccccc2)c2ccccc2-c2ccc(-c3ccccc3N(c3ccc(-c4ccccc4)c(-c4ccccc4)c3)c3ccc4c(c3)C(C)(c3ccccc3)c3ccccc3-4)cc21]

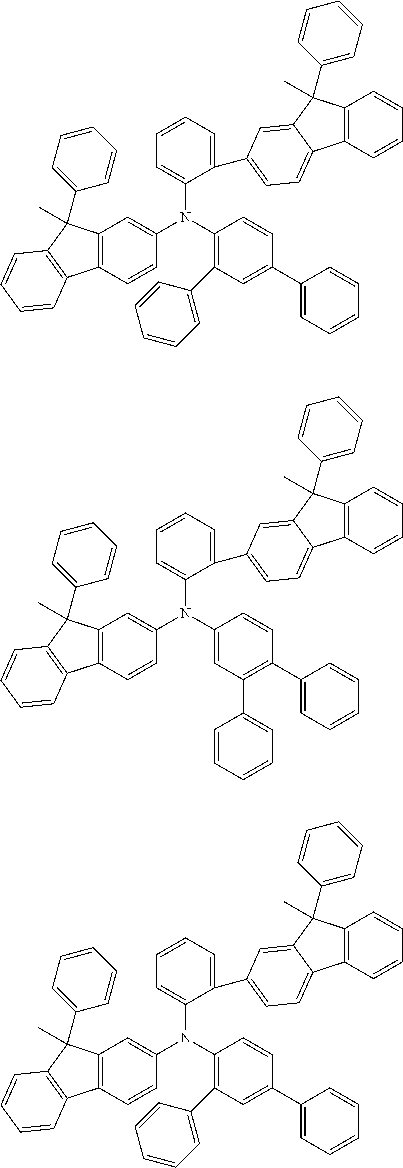 [SMILES: CC1(c2ccccc2)c2ccccc2-c2ccc(-c3ccccc3N(c3ccc4c(c3)C(C)(c3ccccc3)c3ccccc3-4)c3ccc(-c4ccccc4)cc3-c3ccccc3)cc21 ; CC1(c2ccccc2)c2ccccc2-c2ccc(-c3ccccc3N(c3ccc(-c4ccccc4)c(-c4ccccc4)c3)c3ccc4c(c3)C(C)(c3ccccc3)c3ccccc3-4)cc21 ; CC1(c2ccccc2)c2ccccc2-c2ccc(-c3ccccc3N(c3ccc4c(c3)C(C)(c3ccccc3)c3ccccc3-4)c3ccc(-c4ccccc4)cc3-c3ccccc3)cc21]

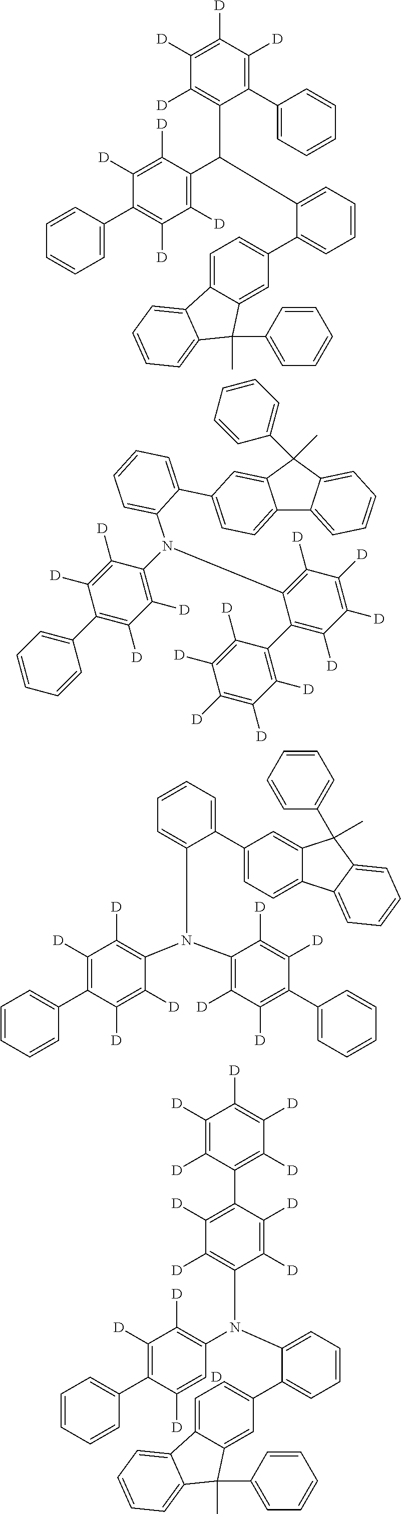

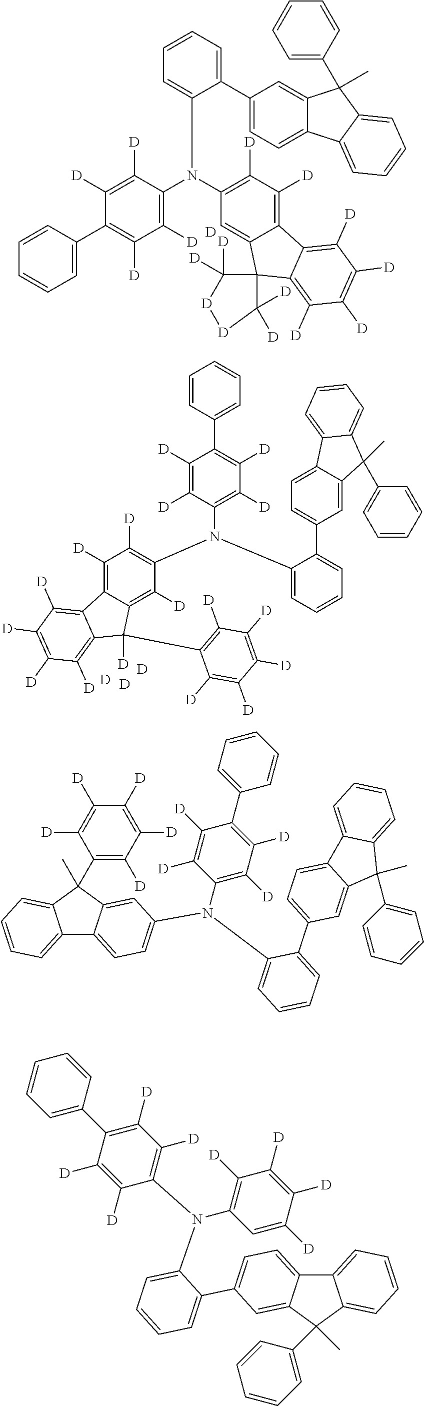

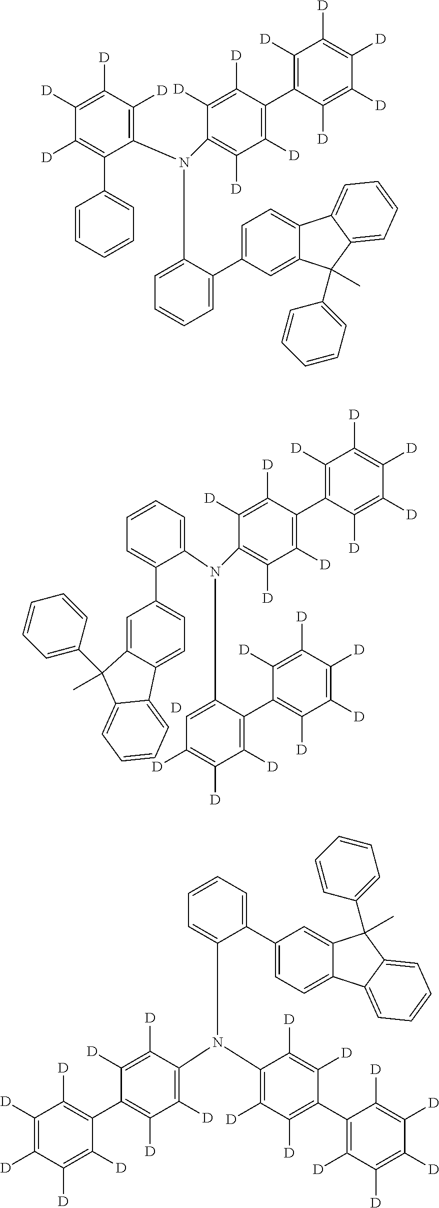

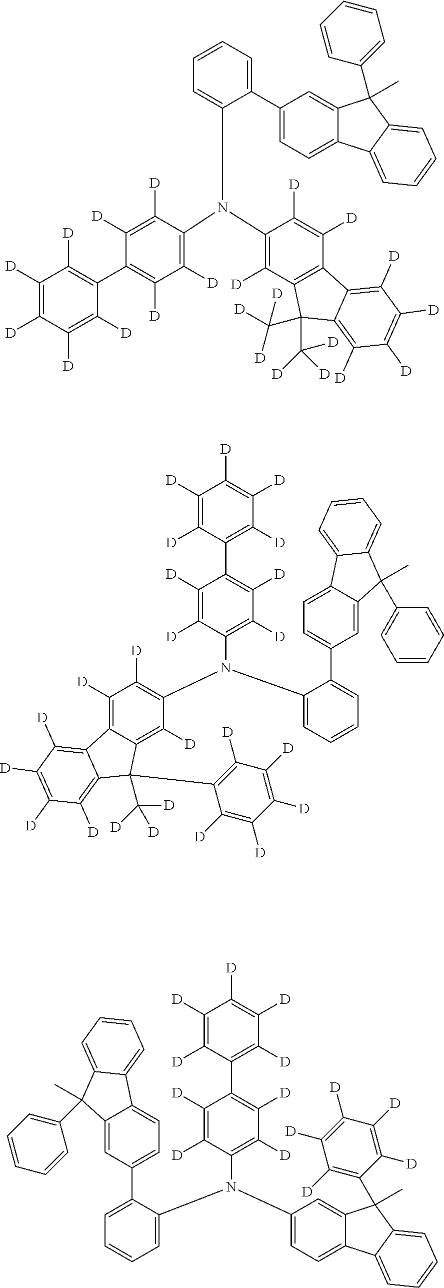

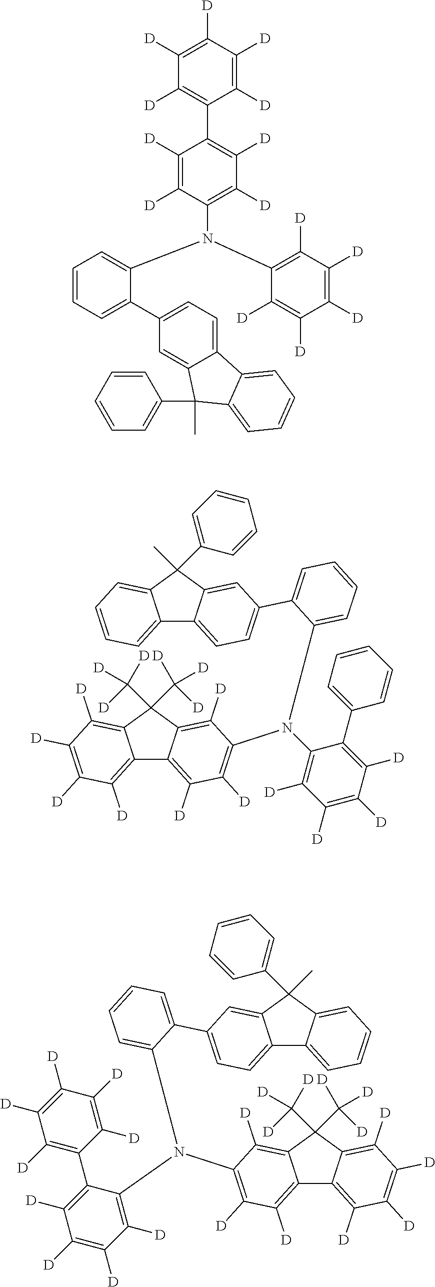

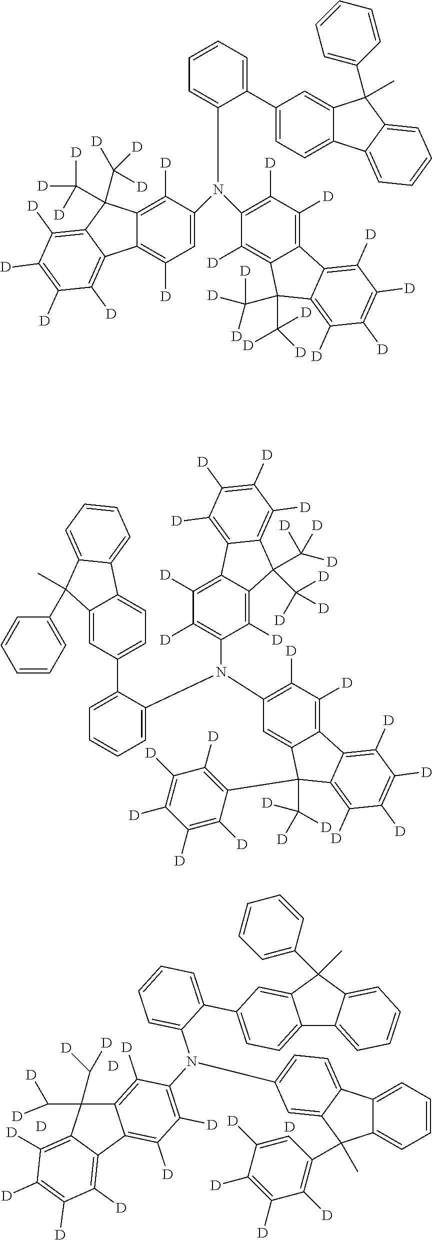

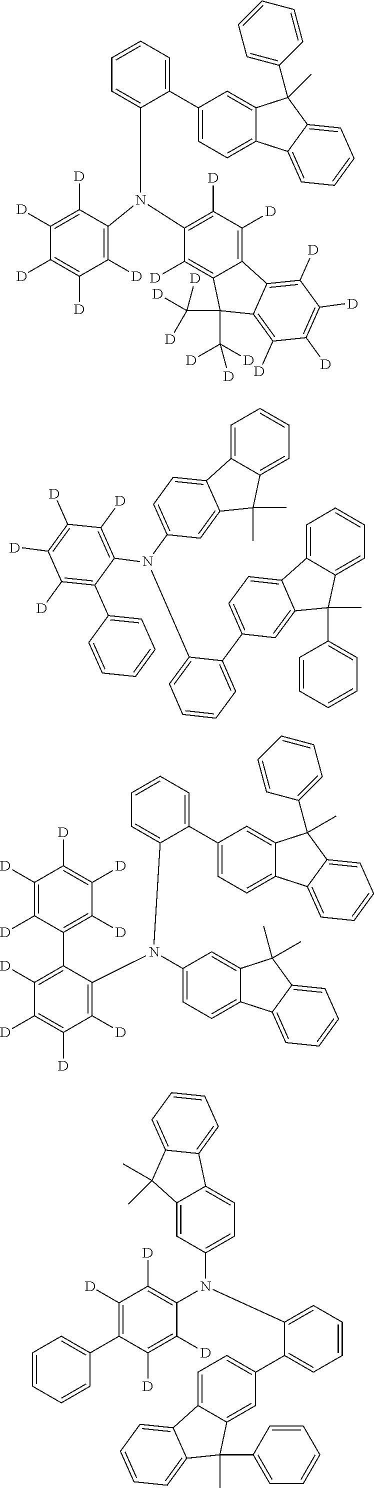

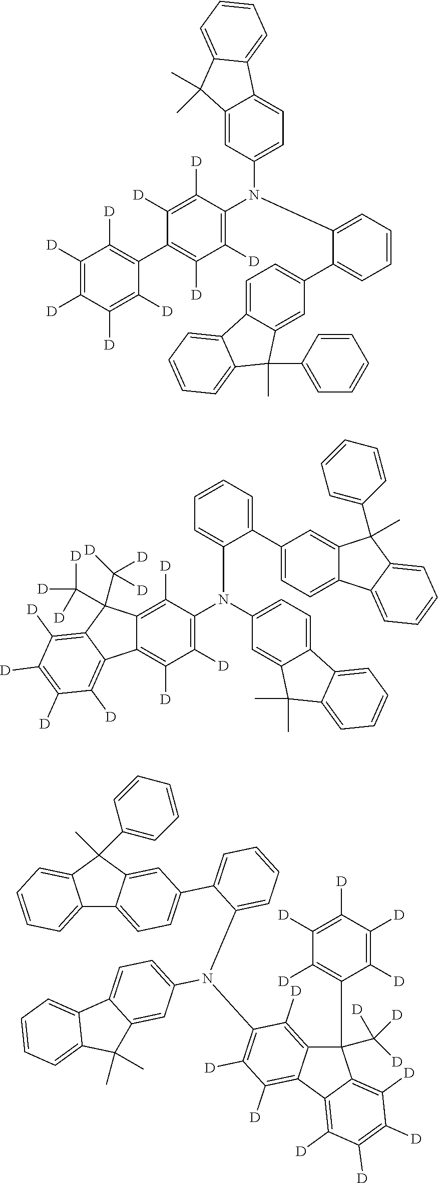

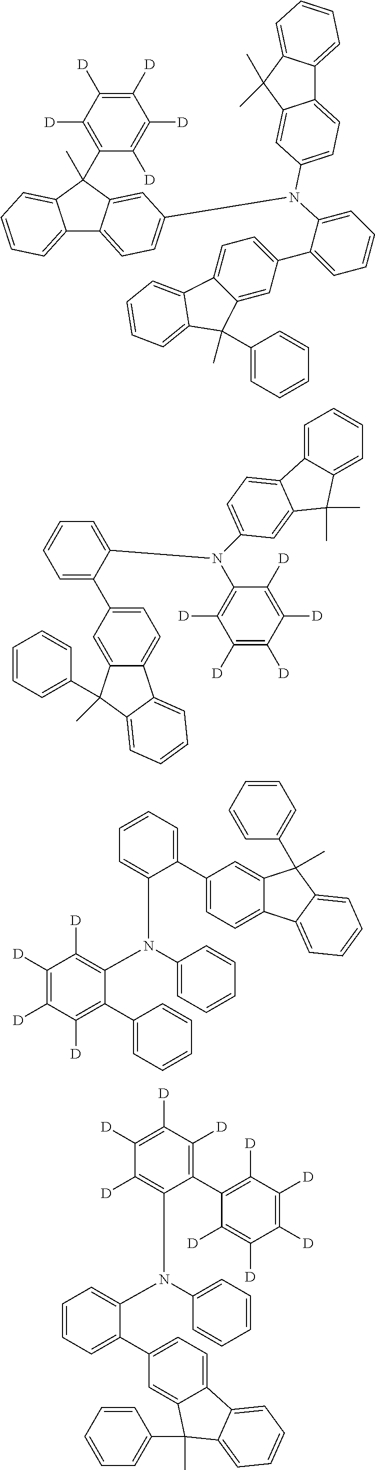

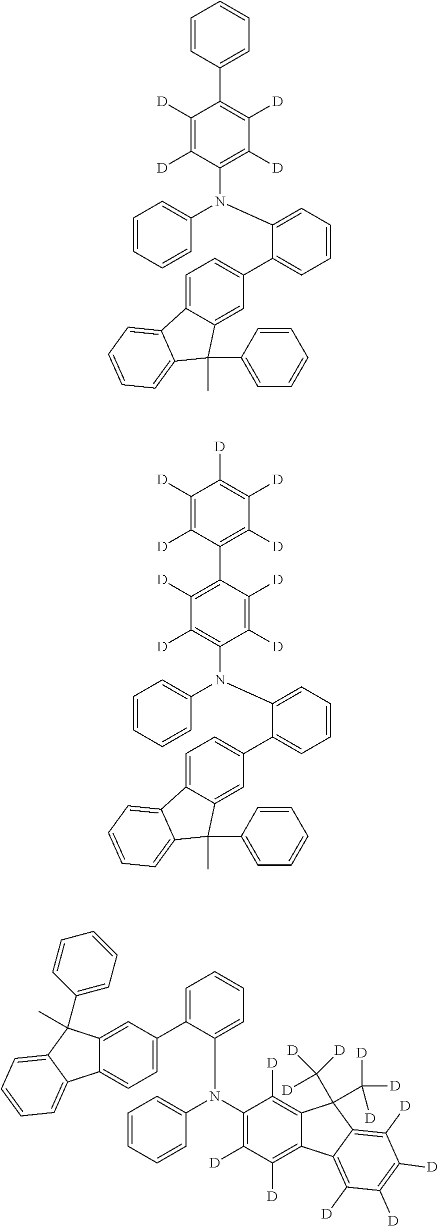 [SMILES: [2H]c1c([2H])c(N(c2ccccc2)c2ccccc2-c2ccc3c(c2)C(C)(c2ccccc2)c2ccccc2-3)c([2H])c([2H])c1-c1ccccc1 ; [2H]c1c([2H])c([2H])c(-c2c([2H])c([2H])c(N(c3ccccc3)c3ccccc3-c3ccc4c(c3)C(C)(c3ccccc3)c3ccccc3-4)c([2H])c2[2H])c([2H])c1[2H] ; [2H]c1c([2H])c([2H])c2c(c1[2H])-c1c([2H])c([2H])c(N(c3ccccc3)c3ccccc3-c3ccc4c(c3)C(C)(c3ccccc3)c3ccccc3-4)c([2H])c1C2(C([2H])([2H])[2H])C([2H])([2H])[2H]]

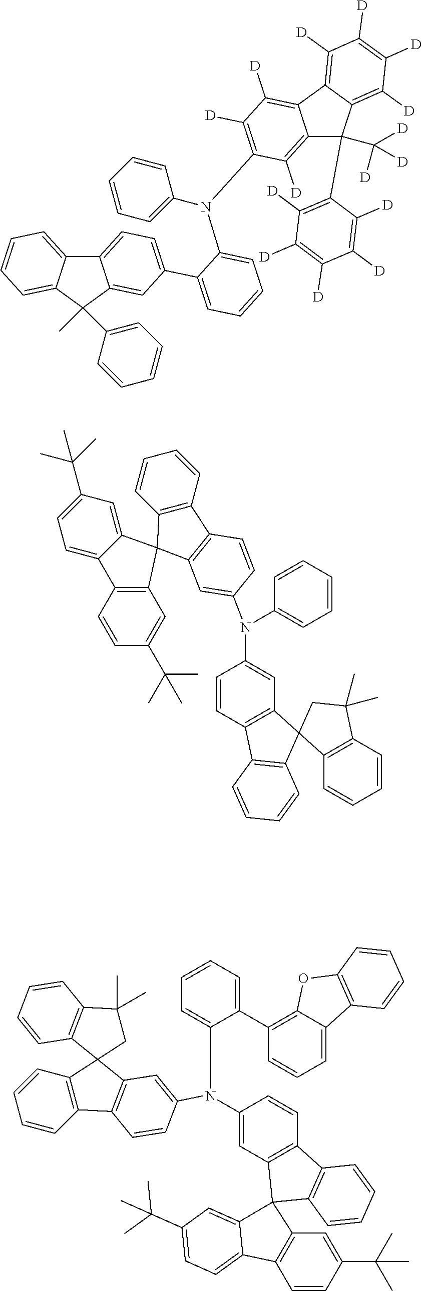 [SMILES: [2H]c1c([2H])c([2H])c(C2(C([2H])([2H])[2H])c3c([2H])c([2H])c([2H])c([2H])c3-c3c([2H])c([2H])c(N(c4ccccc4)c4ccccc4-c4ccc5c(c4)C(C)(c4ccccc4)c4ccccc4-5)c([2H])c32)c([2H])c1[2H] ; CC(C)(C)c1ccc2c(c1)C1(c3ccccc3-c3ccc(N(c4ccccc4)c4ccc5c(c4)C4(CC(C)(C)c6ccccc64)c4ccccc4-5)cc31)c1cc(C(C)(C)C)ccc1-2 ; CC(C)(C)c1ccc2c(c1)C1(c3ccccc3-c3ccc(N(c4ccc5c(c4)C4(CC(C)(C)c6ccccc64)c4ccccc4-5)c4ccccc4-c4cccc5c4oc4ccccc45)cc31)c1cc(C(C)(C)C)ccc1-2]

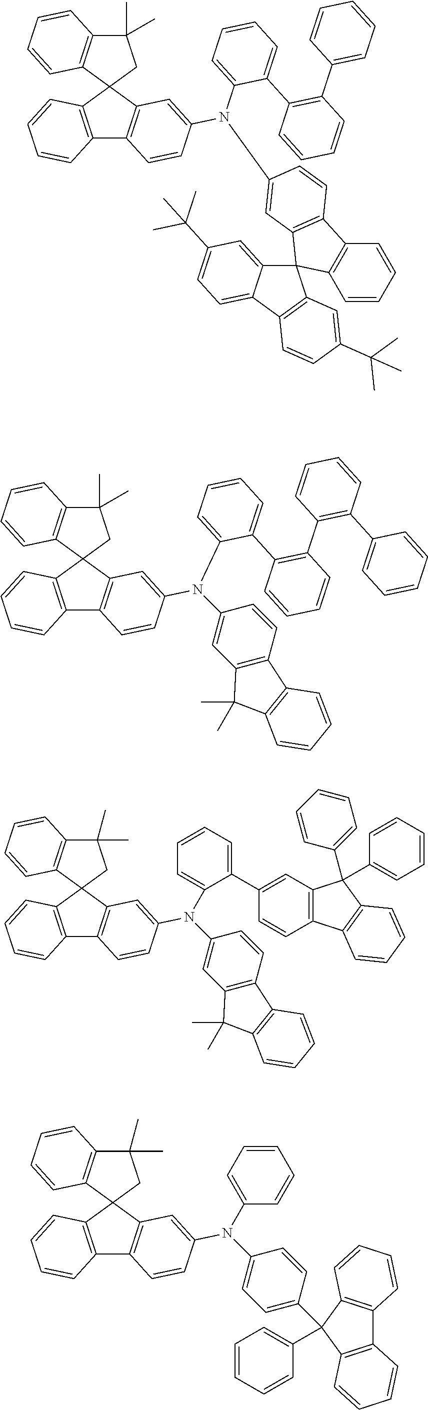

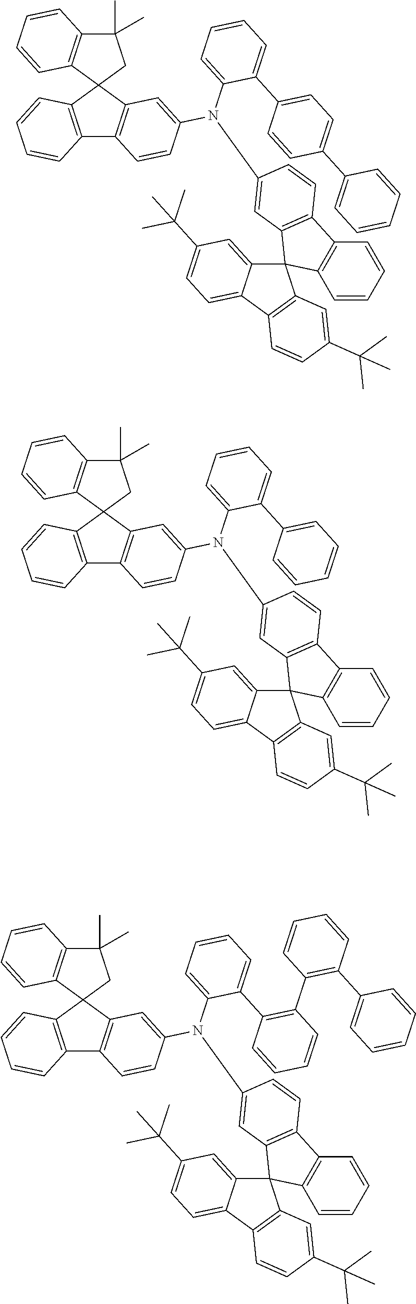 [SMILES: CC(C)(C)c1ccc2c(c1)C1(c3ccccc3-c3ccc(N(c4ccc5c(c4)C4(CC(C)(C)c6ccccc64)c4ccccc4-5)c4ccccc4-c4ccc(-c5ccccc5)cc4)cc31)c1cc(C(C)(C)C)ccc1-2 ; CC(C)(C)c1ccc2c(c1)C1(c3ccccc3-c3ccc(N(c4ccc5c(c4)C4(CC(C)(C)c6ccccc64)c4ccccc4-5)c4ccccc4-c4ccccc4)cc31)c1cc(C(C)(C)C)ccc1-2 ; CC(C)(C)c1ccc2c(c1)C1(c3ccccc3-c3ccc(N(c4ccc5c(c4)C4(CC(C)(C)c6ccccc64)c4ccccc4-5)c4ccccc4-c4ccccc4-c4ccccc4-c4ccccc4)cc31)c1cc(C(C)(C)C)ccc1-2]

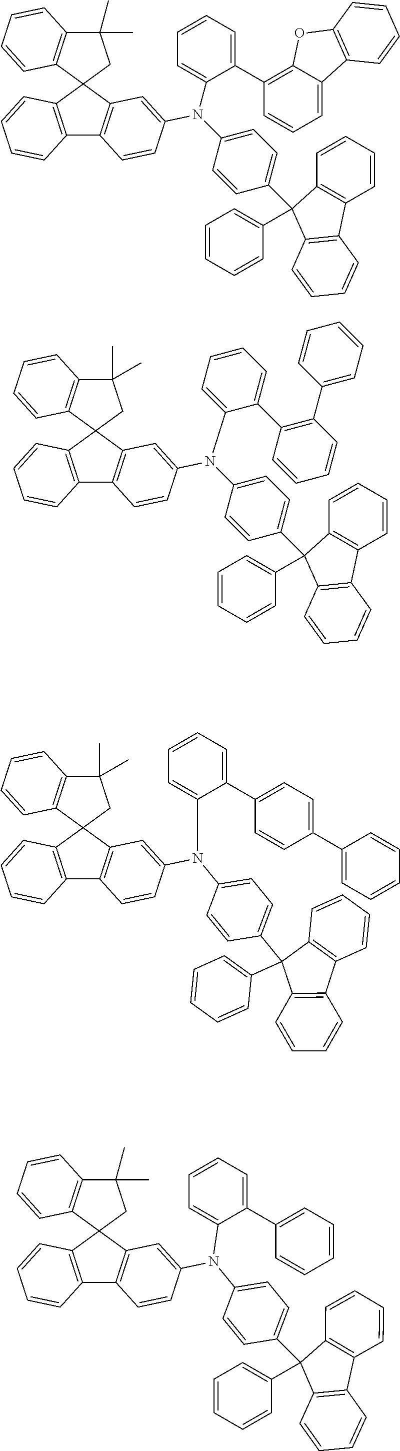

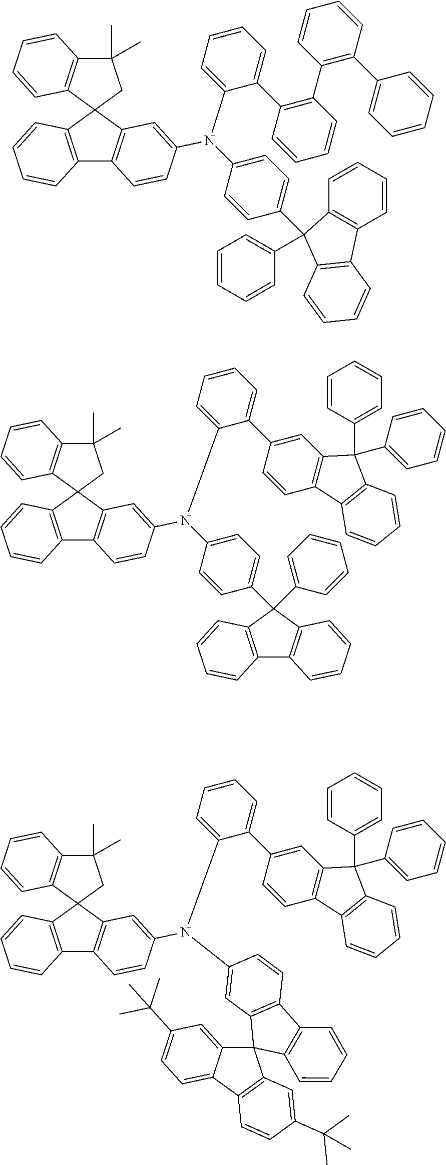

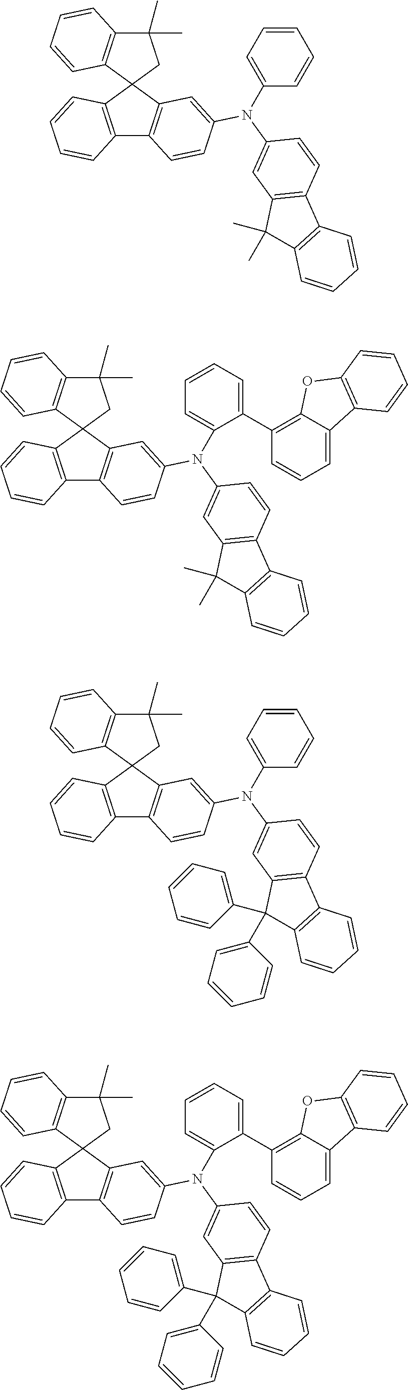 [SMILES: CC1(C)CC2(c3ccccc3-c3ccc(N(c4ccccc4)c4ccc5c(c4)C(C)(C)c4ccccc4-5)cc32)c2ccccc21 ; CC1(C)CC2(c3ccccc3-c3ccc(N(c4ccc5c(c4)C(C)(C)c4ccccc4-5)c4ccccc4-c4cccc5c4oc4ccccc45)cc32)c2ccccc21 ; CC1(C)CC2(c3ccccc3-c3ccc(N(c4ccccc4)c4ccc5c(c4)C(c4ccccc4)(c4ccccc4)c4ccccc4-5)cc32)c2ccccc21 ; CC1(C)CC2(c3ccccc3-c3ccc(N(c4ccc5c(c4)C(c4ccccc4)(c4ccccc4)c4ccccc4-5)c4ccccc4-c4cccc5c4oc4ccccc45)cc32)c2ccccc21]

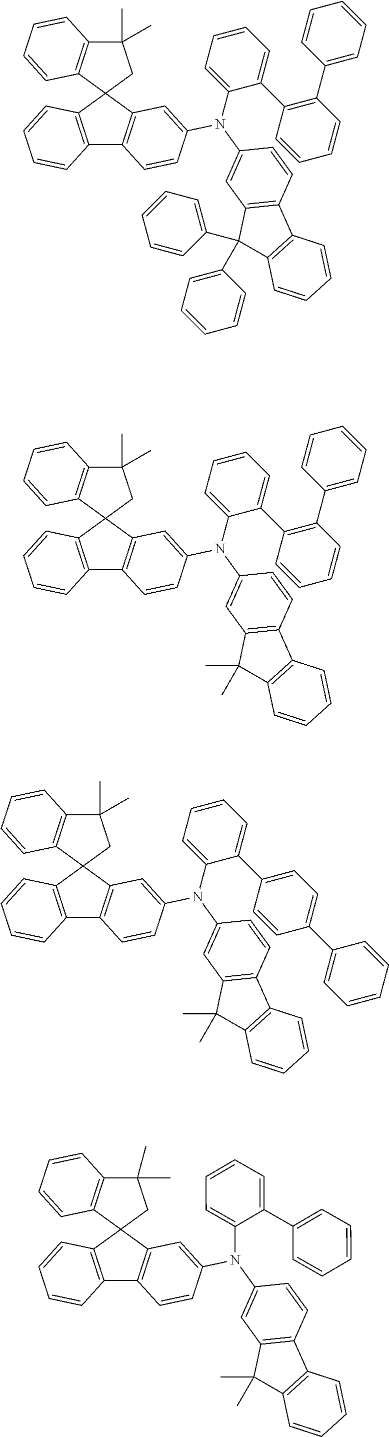 [SMILES: CC1(C)CC2(c3ccccc3-c3ccc(N(c4ccc5c(c4)C(c4ccccc4)(c4ccccc4)c4ccccc4-5)c4ccccc4-c4ccccc4-c4ccccc4)cc32)c2ccccc21 ; CC1(C)CC2(c3ccccc3-c3ccc(N(c4ccc5c(c4)C(C)(C)c4ccccc4-5)c4ccccc4-c4ccccc4-c4ccccc4)cc32)c2ccccc21 ; CC1(C)CC2(c3ccccc3-c3ccc(N(c4ccc5c(c4)C(C)(C)c4ccccc4-5)c4ccccc4-c4ccc(-c5ccccc5)cc4)cc32)c2ccccc21 ; CC1(C)CC2(c3ccccc3-c3ccc(N(c4ccc5c(c4)C(C)(C)c4ccccc4-5)c4ccccc4-c4ccccc4)cc32)c2ccccc21]

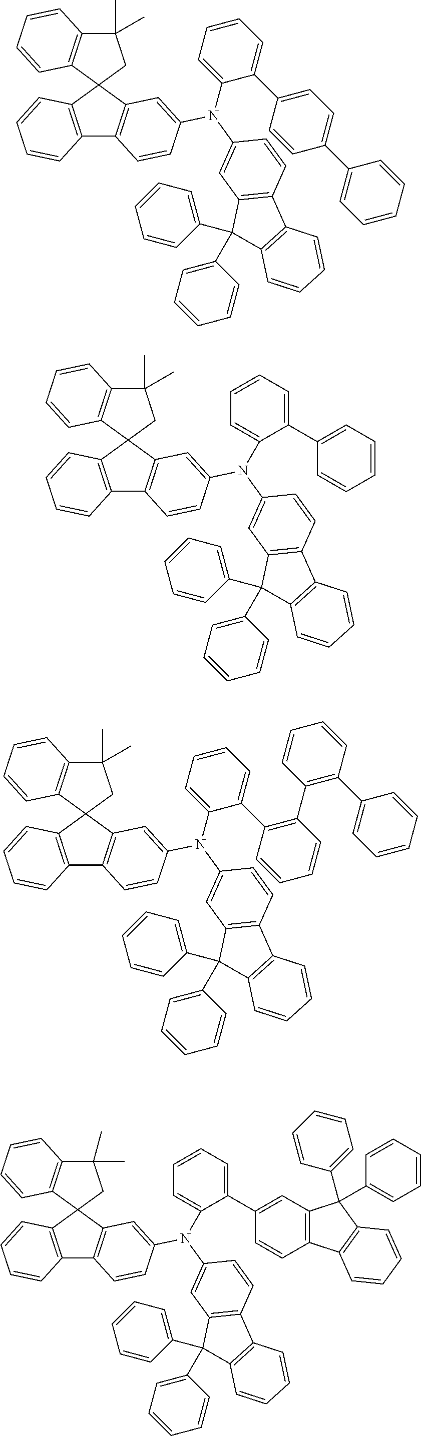 [SMILES: CC1(C)CC2(c3ccccc3-c3ccc(N(c4ccc5c(c4)C(c4ccccc4)(c4ccccc4)c4ccccc4-5)c4ccccc4-c4ccc(-c5ccccc5)cc4)cc32)c2ccccc21 ; CC1(C)CC2(c3ccccc3-c3ccc(N(c4ccc5c(c4)C(c4ccccc4)(c4ccccc4)c4ccccc4-5)c4ccccc4-c4ccccc4)cc32)c2ccccc21 ; CC1(C)CC2(c3ccccc3-c3ccc(N(c4ccc5c(c4)C(c4ccccc4)(c4ccccc4)c4ccccc4-5)c4ccccc4-c4ccccc4-c4ccccc4-c4ccccc4)cc32)c2ccccc21 ; CC1(C)CC2(c3ccccc3-c3ccc(N(c4ccc5c(c4)C(c4ccccc4)(c4ccccc4)c4ccccc4-5)c4ccccc4-c4ccc5c(c4)C(c4ccccc4)(c4ccccc4)c4ccccc4-5)cc32)c2ccccc21]

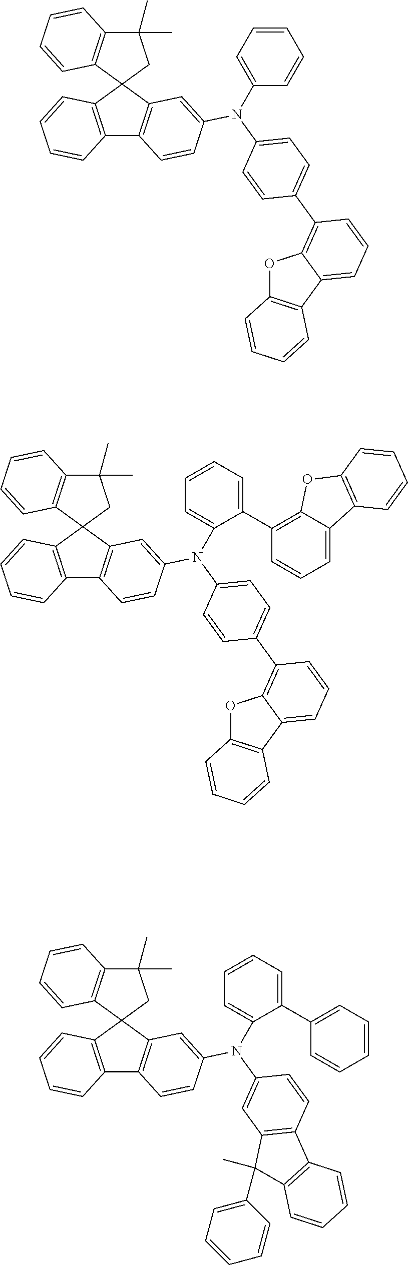 [SMILES: CC1(C)CC2(c3ccccc3-c3ccc(N(c4ccccc4)c4ccc(-c5cccc6c5oc5ccccc56)cc4)cc32)c2ccccc21 ; CC1(C)CC2(c3ccccc3-c3ccc(N(c4ccc(-c5cccc6c5oc5ccccc56)cc4)c4ccccc4-c4cccc5c4oc4ccccc45)cc32)c2ccccc21 ; CC1(C)CC2(c3ccccc3-c3ccc(N(c4ccc5c(c4)C(C)(c4ccccc4)c4ccccc4-5)c4ccccc4-c4ccccc4)cc32)c2ccccc21]

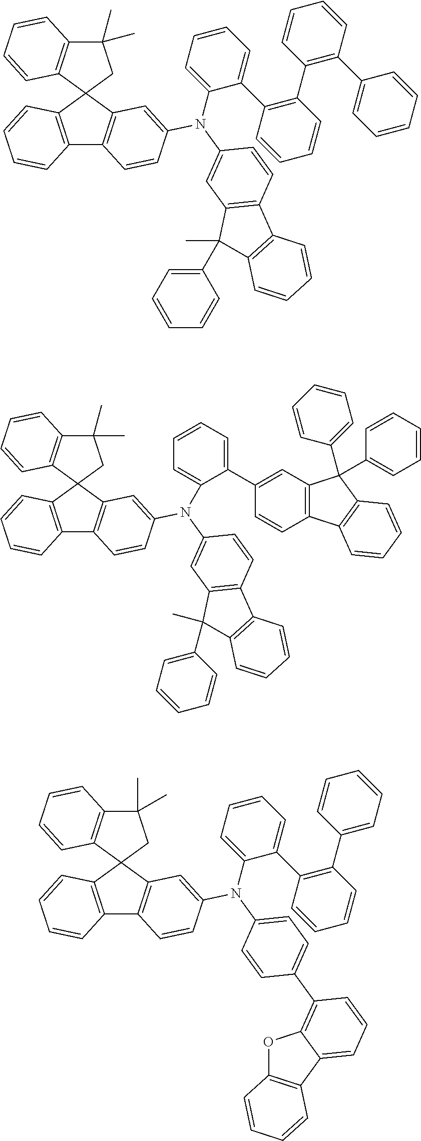 [SMILES: CC1(C)CC2(c3ccccc3-c3ccc(N(c4ccc5c(c4)C(C)(c4ccccc4)c4ccccc4-5)c4ccccc4-c4ccccc4-c4ccccc4-c4ccccc4)cc32)c2ccccc21 ; CC1(C)CC2(c3ccccc3-c3ccc(N(c4ccc5c(c4)C(C)(c4ccccc4)c4ccccc4-5)c4ccccc4-c4ccc5c(c4)C(c4ccccc4)(c4ccccc4)c4ccccc4-5)cc32)c2ccccc21 ; CC1(C)CC2(c3ccccc3-c3ccc(N(c4ccc(-c5cccc6c5oc5ccccc56)cc4)c4ccccc4-c4ccccc4-c4ccccc4)cc32)c2ccccc21]

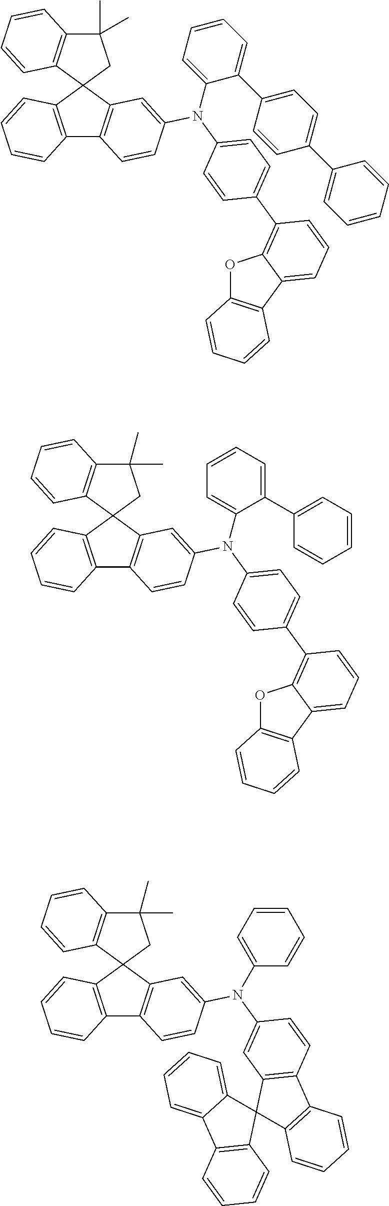 [SMILES: CC1(C)CC2(c3ccccc3-c3ccc(N(c4ccc(-c5cccc6c5oc5ccccc56)cc4)c4ccccc4-c4ccc(-c5ccccc5)cc4)cc32)c2ccccc21 ; CC1(C)CC2(c3ccccc3-c3ccc(N(c4ccc(-c5cccc6c5oc5ccccc56)cc4)c4ccccc4-c4ccccc4)cc32)c2ccccc21 ; CC1(C)CC2(c3ccccc3-c3ccc(N(c4ccccc4)c4ccc5c(c4)C4(c6ccccc6-c6ccccc64)c4ccccc4-5)cc32)c2ccccc21]

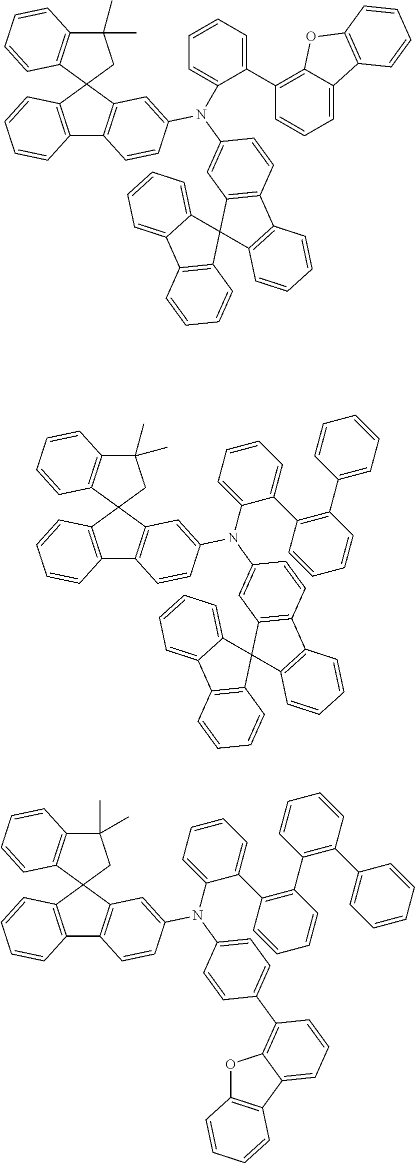 [SMILES: CC1(C)CC2(c3ccccc3-c3ccc(N(c4ccc5c(c4)C4(c6ccccc6-c6ccccc64)c4ccccc4-5)c4ccccc4-c4cccc5c4oc4ccccc45)cc32)c2ccccc21 ; CC1(C)CC2(c3ccccc3-c3ccc(N(c4ccc5c(c4)C4(c6ccccc6-c6ccccc64)c4ccccc4-5)c4ccccc4-c4ccccc4-c4ccccc4)cc32)c2ccccc21 ; CC1(C)CC2(c3ccccc3-c3ccc(N(c4ccc(-c5cccc6c5oc5ccccc56)cc4)c4ccccc4-c4ccccc4-c4ccccc4-c4ccccc4)cc32)c2ccccc21]

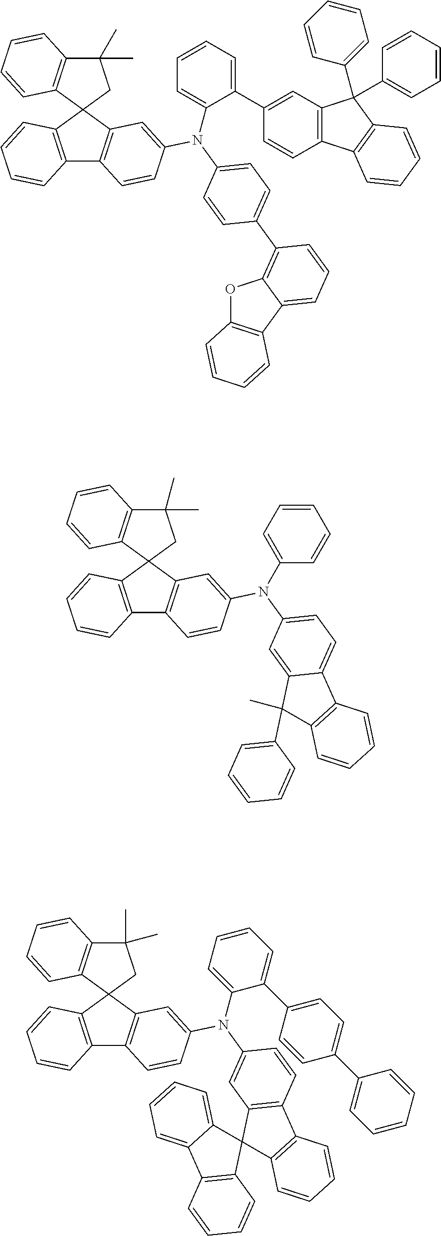 [SMILES: CC1(C)CC2(c3ccccc3-c3ccc(N(c4ccc(-c5cccc6c5oc5ccccc56)cc4)c4ccccc4-c4ccc5c(c4)C(c4ccccc4)(c4ccccc4)c4ccccc4-5)cc32)c2ccccc21 ; CC1(C)CC2(c3ccccc3-c3ccc(N(c4ccccc4)c4ccc5c(c4)C(C)(c4ccccc4)c4ccccc4-5)cc32)c2ccccc21 ; CC1(C)CC2(c3ccccc3-c3ccc(N(c4ccc5c(c4)C4(c6ccccc6-c6ccccc64)c4ccccc4-5)c4ccccc4-c4ccc(-c5ccccc5)cc4)cc32)c2ccccc21]

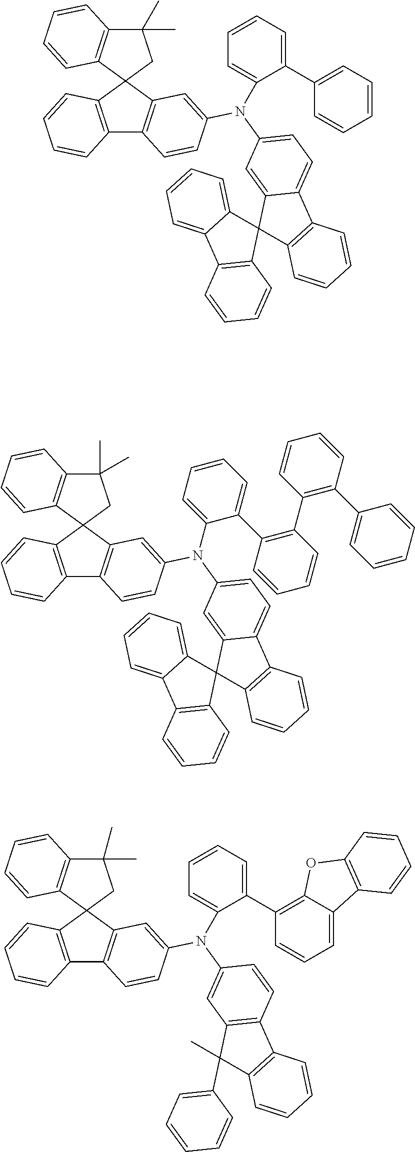 [SMILES: CC1(C)CC2(c3ccccc3-c3ccc(N(c4ccc5c(c4)C4(c6ccccc6-c6ccccc64)c4ccccc4-5)c4ccccc4-c4ccccc4)cc32)c2ccccc21 ; CC1(C)CC2(c3ccccc3-c3ccc(N(c4ccc5c(c4)C4(c6ccccc6-c6ccccc64)c4ccccc4-5)c4ccccc4-c4ccccc4-c4ccccc4-c4ccccc4)cc32)c2ccccc21 ; CC1(C)CC2(c3ccccc3-c3ccc(N(c4ccc5c(c4)C(C)(c4ccccc4)c4ccccc4-5)c4ccccc4-c4cccc5c4oc4ccccc45)cc32)c2ccccc21]

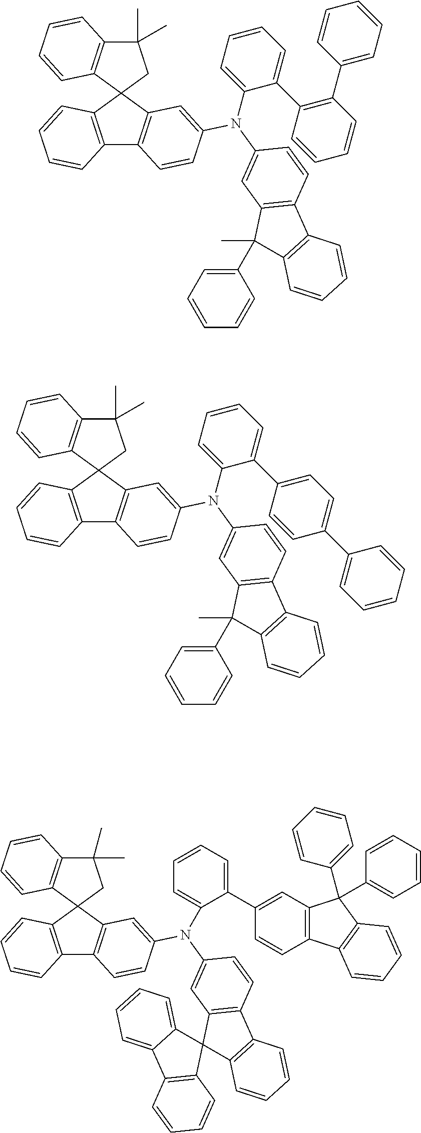 [SMILES: CC1(C)CC2(c3ccccc3-c3ccc(N(c4ccc5c(c4)C(C)(c4ccccc4)c4ccccc4-5)c4ccccc4-c4ccccc4-c4ccccc4)cc32)c2ccccc21 ; CC1(C)CC2(c3ccccc3-c3ccc(N(c4ccc5c(c4)C(C)(c4ccccc4)c4ccccc4-5)c4ccccc4-c4ccc(-c5ccccc5)cc4)cc32)c2ccccc21 ; CC1(C)CC2(c3ccccc3-c3ccc(N(c4ccc5c(c4)C4(c6ccccc6-c6ccccc64)c4ccccc4-5)c4ccccc4-c4ccc5c(c4)C(c4ccccc4)(c4ccccc4)c4ccccc4-5)cc32)c2ccccc21]

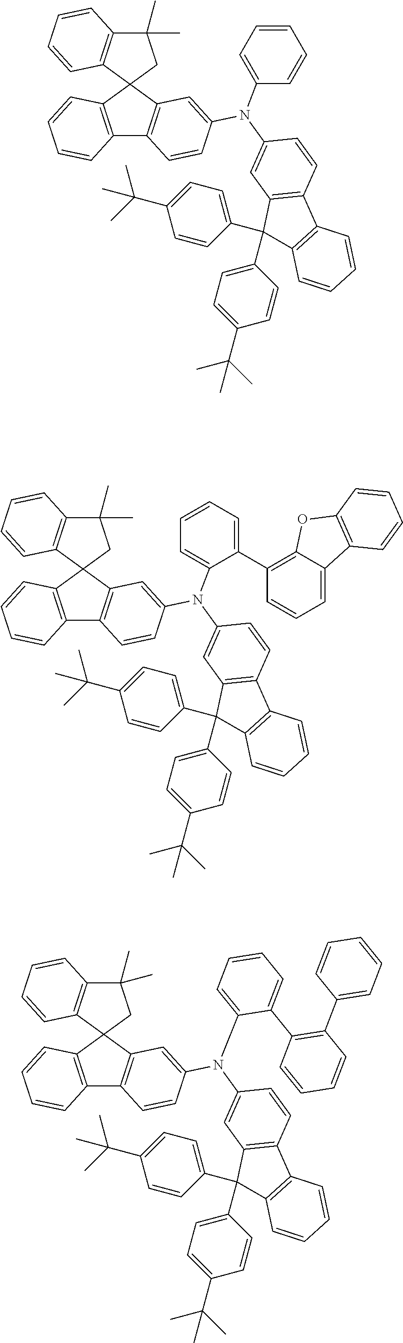 [SMILES: CC(C)(C)c1ccc(C2(c3ccc(C(C)(C)C)cc3)c3ccccc3-c3ccc(N(c4ccccc4)c4ccc5c(c4)C4(CC(C)(C)c6ccccc64)c4ccccc4-5)cc32)cc1 ; CC(C)(C)c1ccc(C2(c3ccc(C(C)(C)C)cc3)c3ccccc3-c3ccc(N(c4ccc5c(c4)C4(CC(C)(C)c6ccccc64)c4ccccc4-5)c4ccccc4-c4cccc5c4oc4ccccc45)cc32)cc1 ; CC(C)(C)c1ccc(C2(c3ccc(C(C)(C)C)cc3)c3ccccc3-c3ccc(N(c4ccc5c(c4)C4(CC(C)(C)c6ccccc64)c4ccccc4-5)c4ccccc4-c4ccccc4-c4ccccc4)cc32)cc1]

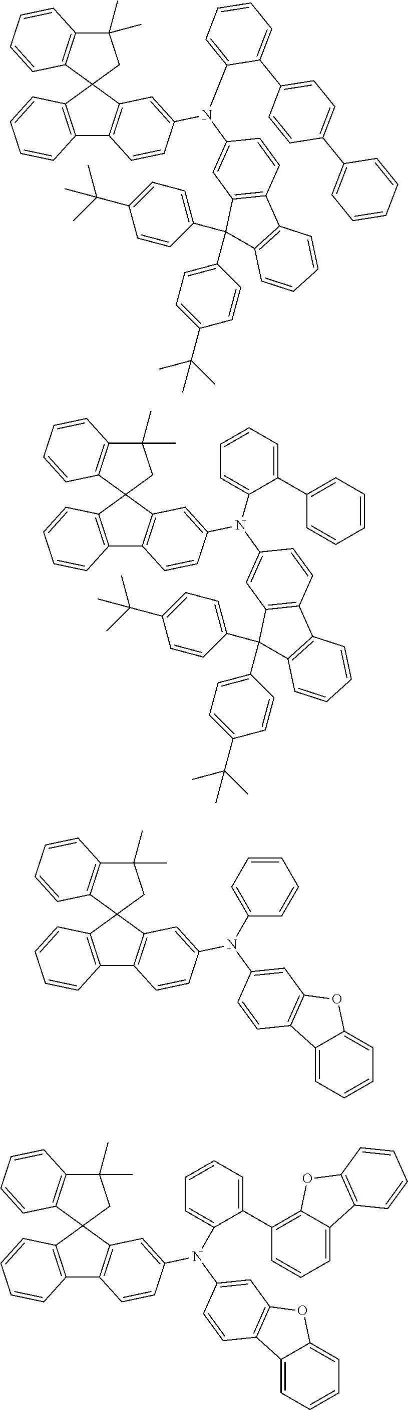

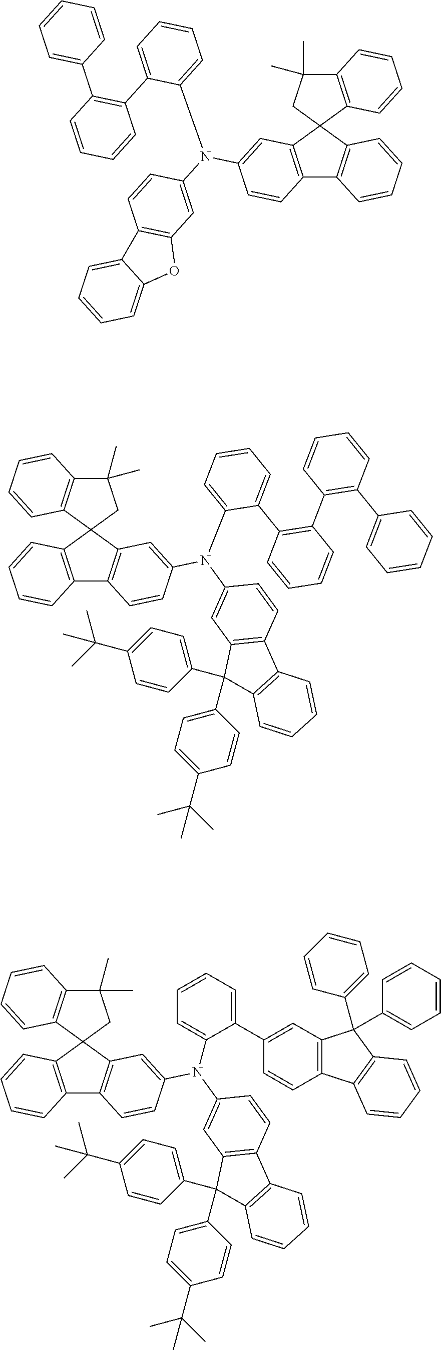 [SMILES: CC1(C)CC2(c3ccccc3-c3ccc(N(c4ccc5c(c4)oc4ccccc45)c4ccccc4-c4ccccc4-c4ccccc4)cc32)c2ccccc21 ; CC(C)(C)c1ccc(C2(c3ccc(C(C)(C)C)cc3)c3ccccc3-c3ccc(N(c4ccc5c(c4)C4(CC(C)(C)c6ccccc64)c4ccccc4-5)c4ccccc4-c4ccccc4-c4ccccc4-c4ccccc4)cc32)cc1 ; CC(C)(C)c1ccc(C2(c3ccc(C(C)(C)C)cc3)c3ccccc3-c3ccc(N(c4ccc5c(c4)C4(CC(C)(C)c6ccccc64)c4ccccc4-5)c4ccccc4-c4ccc5c(c4)C(c4ccccc4)(c4ccccc4)c4ccccc4-5)cc32)cc1]

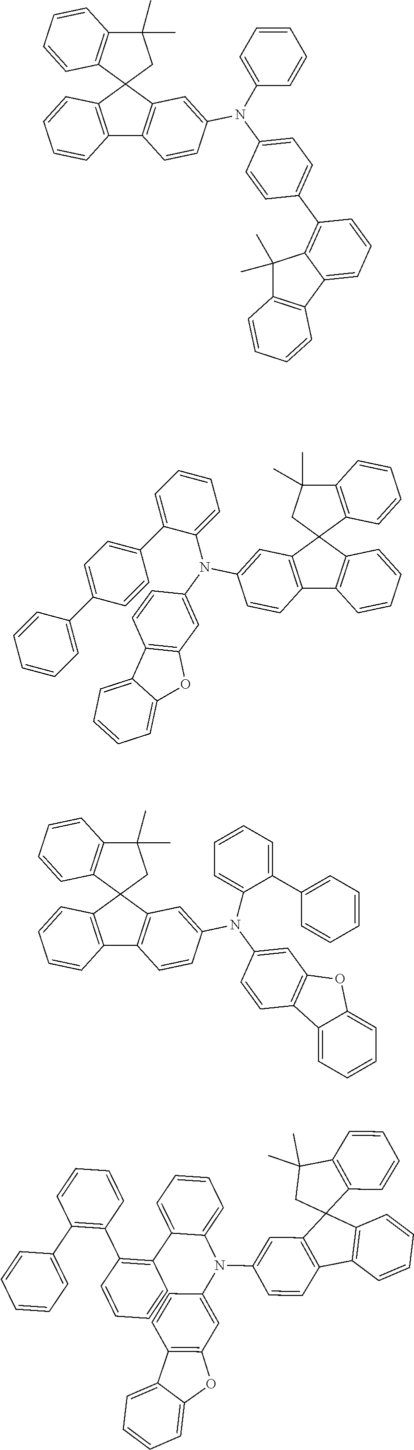 [SMILES: CC1(C)CC2(c3ccccc3-c3ccc(N(c4ccccc4)c4ccc(-c5cccc6c5C(C)(C)c5ccccc5-6)cc4)cc32)c2ccccc21 ; CC1(C)CC2(c3ccccc3-c3ccc(N(c4ccc5c(c4)oc4ccccc45)c4ccccc4-c4ccc(-c5ccccc5)cc4)cc32)c2ccccc21 ; CC1(C)CC2(c3ccccc3-c3ccc(N(c4ccc5c(c4)oc4ccccc45)c4ccccc4-c4ccccc4)cc32)c2ccccc21 ; CC1(C)CC2(c3ccccc3-c3ccc(N(c4ccc5c(c4)oc4ccccc45)c4ccccc4-c4ccccc4-c4ccccc4-c4ccccc4)cc32)c2ccccc21]

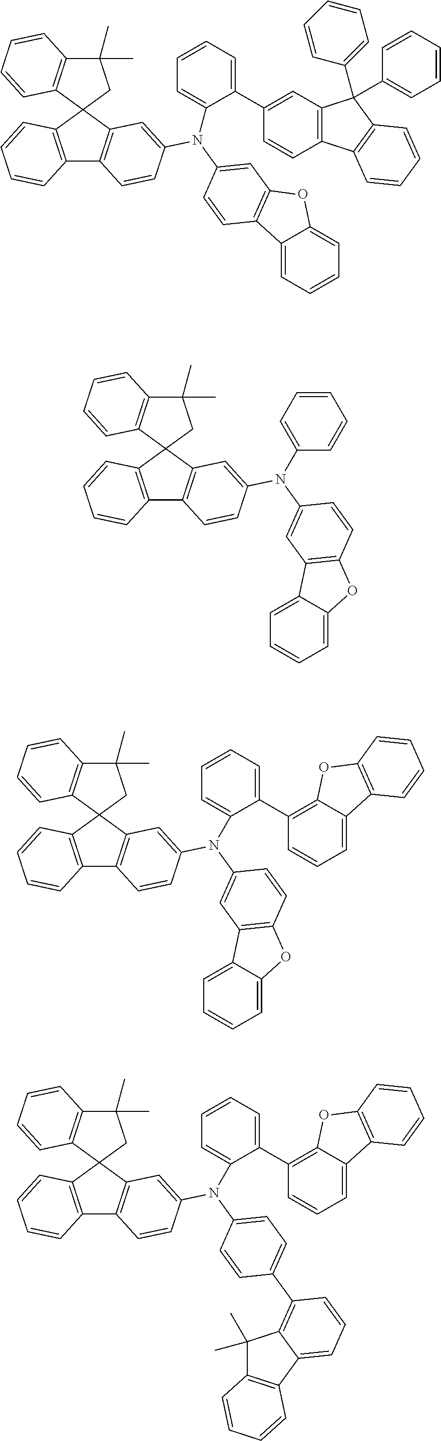 [SMILES: CC1(C)CC2(c3ccccc3-c3ccc(N(c4ccc5c(c4)oc4ccccc45)c4ccccc4-c4ccc5c(c4)C(c4ccccc4)(c4ccccc4)c4ccccc4-5)cc32)c2ccccc21 ; CC1(C)CC2(c3ccccc3-c3ccc(N(c4ccccc4)c4ccc5oc6ccccc6c5c4)cc32)c2ccccc21 ; CC1(C)CC2(c3ccccc3-c3ccc(N(c4ccc5oc6ccccc6c5c4)c4ccccc4-c4cccc5c4oc4ccccc45)cc32)c2ccccc21 ; CC1(C)CC2(c3ccccc3-c3ccc(N(c4ccc(-c5cccc6c5C(C)(C)c5ccccc5-6)cc4)c4ccccc4-c4cccc5c4oc4ccccc45)cc32)c2ccccc21]

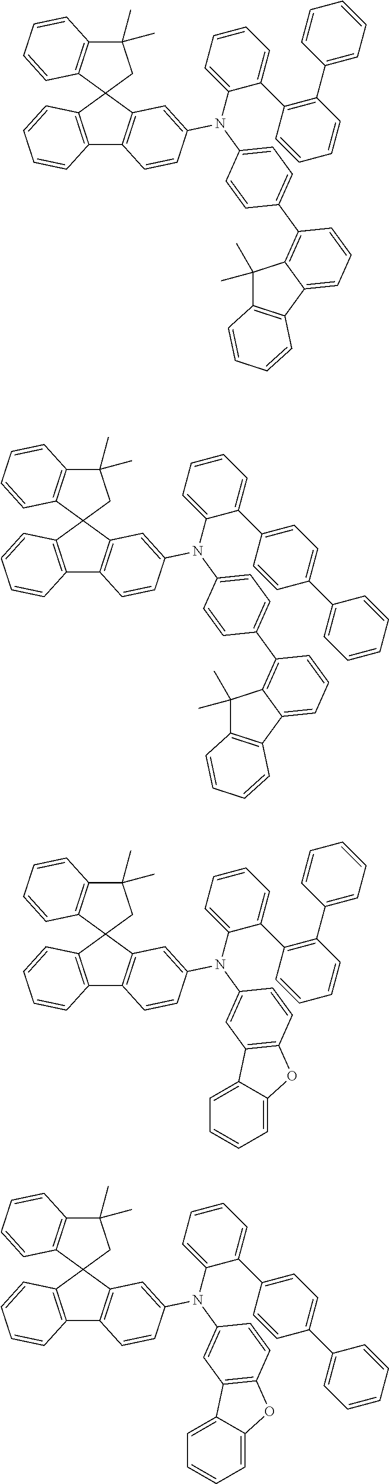 [SMILES: CC1(C)CC2(c3ccccc3-c3ccc(N(c4ccc(-c5cccc6c5C(C)(C)c5ccccc5-6)cc4)c4ccccc4-c4ccccc4-c4ccccc4)cc32)c2ccccc21 ; CC1(C)CC2(c3ccccc3-c3ccc(N(c4ccc(-c5cccc6c5C(C)(C)c5ccccc5-6)cc4)c4ccccc4-c4ccc(-c5ccccc5)cc4)cc32)c2ccccc21 ; CC1(C)CC2(c3ccccc3-c3ccc(N(c4ccc5oc6ccccc6c5c4)c4ccccc4-c4ccccc4-c4ccccc4)cc32)c2ccccc21 ; CC1(C)CC2(c3ccccc3-c3ccc(N(c4ccc5oc6ccccc6c5c4)c4ccccc4-c4ccc(-c5ccccc5)cc4)cc32)c2ccccc21]

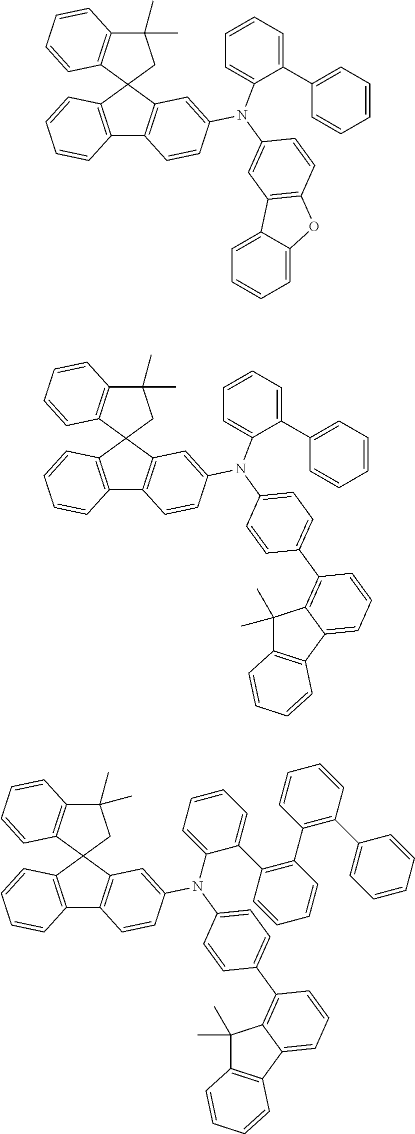 [SMILES: CC1(C)CC2(c3ccccc3-c3ccc(N(c4ccc5oc6ccccc6c5c4)c4ccccc4-c4ccccc4)cc32)c2ccccc21 ; CC1(C)CC2(c3ccccc3-c3ccc(N(c4ccc(-c5cccc6c5C(C)(C)c5ccccc5-6)cc4)c4ccccc4-c4ccccc4)cc32)c2ccccc21 ; CC1(C)CC2(c3ccccc3-c3ccc(N(c4ccc(-c5cccc6c5C(C)(C)c5ccccc5-6)cc4)c4ccccc4-c4ccccc4-c4ccccc4-c4ccccc4)cc32)c2ccccc21]

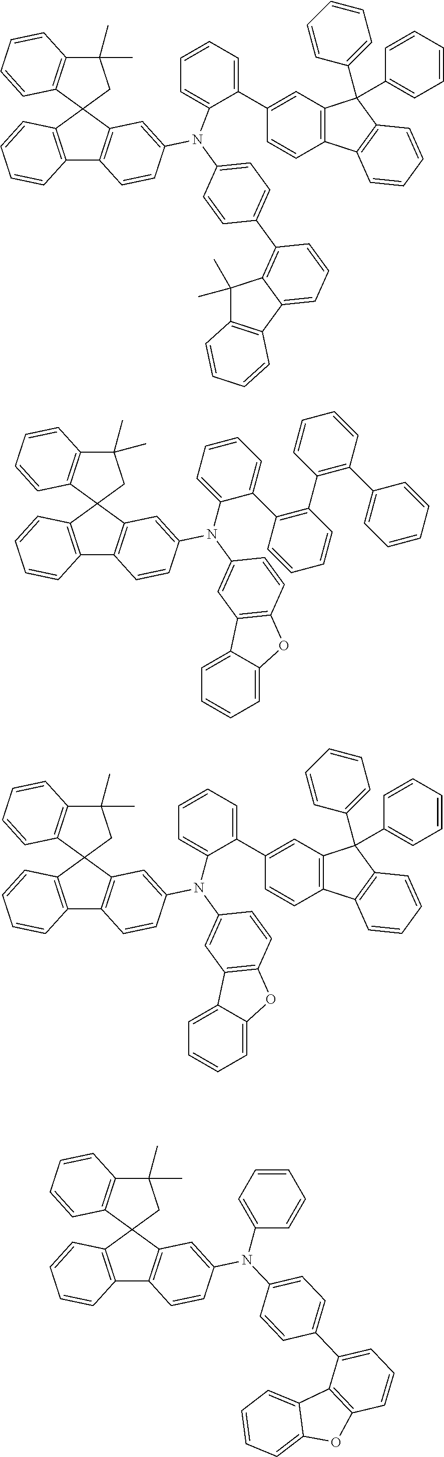 [SMILES: CC1(C)CC2(c3ccccc3-c3ccc(N(c4ccc(-c5cccc6c5C(C)(C)c5ccccc5-6)cc4)c4ccccc4-c4ccc5c(c4)C(c4ccccc4)(c4ccccc4)c4ccccc4-5)cc32)c2ccccc21 ; CC1(C)CC2(c3ccccc3-c3ccc(N(c4ccc5oc6ccccc6c5c4)c4ccccc4-c4ccccc4-c4ccccc4-c4ccccc4)cc32)c2ccccc21 ; CC1(C)CC2(c3ccccc3-c3ccc(N(c4ccc5oc6ccccc6c5c4)c4ccccc4-c4ccc5c(c4)C(c4ccccc4)(c4ccccc4)c4ccccc4-5)cc32)c2ccccc21 ; CC1(C)CC2(c3ccccc3-c3ccc(N(c4ccccc4)c4ccc(-c5cccc6oc7ccccc7c56)cc4)cc32)c2ccccc21]

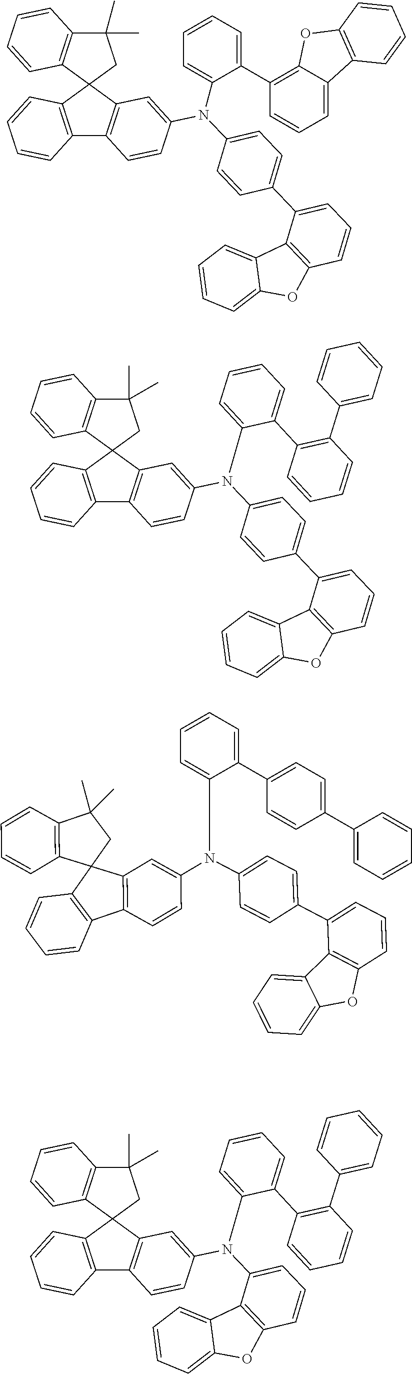 [SMILES: CC1(C)CC2(c3ccccc3-c3ccc(N(c4ccc(-c5cccc6oc7ccccc7c56)cc4)c4ccccc4-c4cccc5c4oc4ccccc45)cc32)c2ccccc21 ; CC1(C)CC2(c3ccccc3-c3ccc(N(c4ccc(-c5cccc6oc7ccccc7c56)cc4)c4ccccc4-c4ccccc4-c4ccccc4)cc32)c2ccccc21 ; CC1(C)CC2(c3ccccc3-c3ccc(N(c4ccc(-c5cccc6oc7ccccc7c56)cc4)c4ccccc4-c4ccc(-c5ccccc5)cc4)cc32)c2ccccc21 ; CC1(C)CC2(c3ccccc3-c3ccc(N(c4ccccc4-c4ccccc4-c4ccccc4)c4cccc5oc6ccccc6c45)cc32)c2ccccc21]

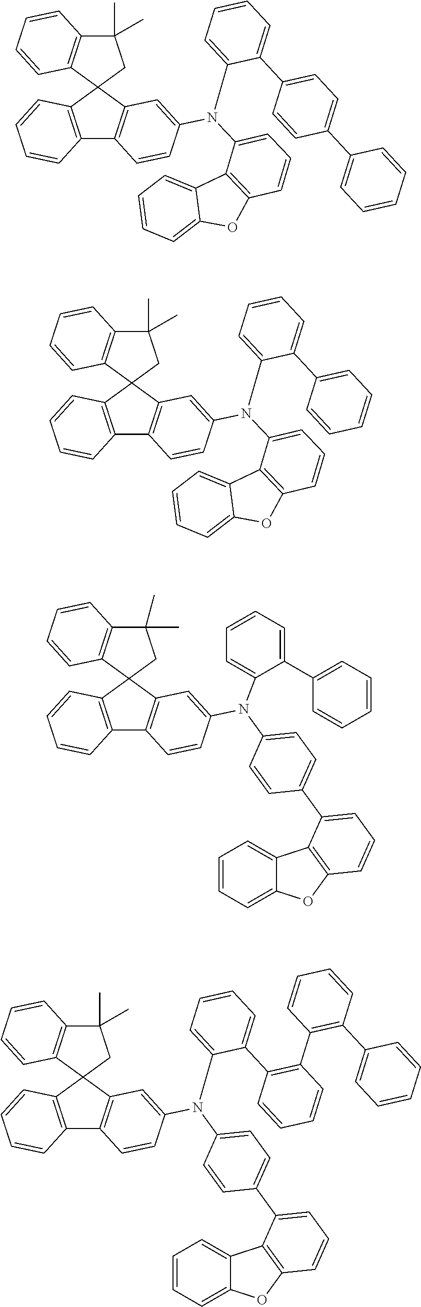

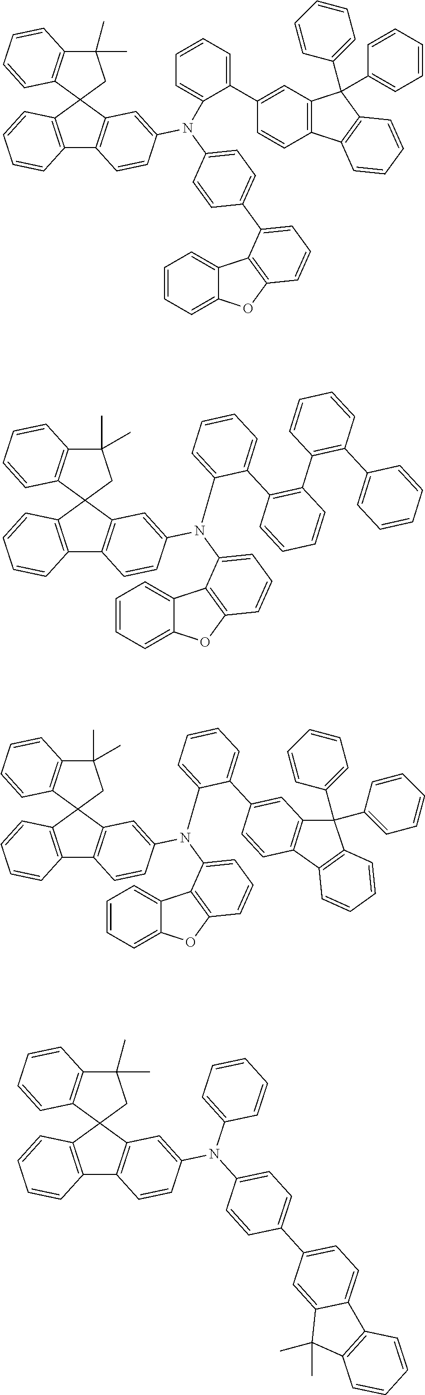

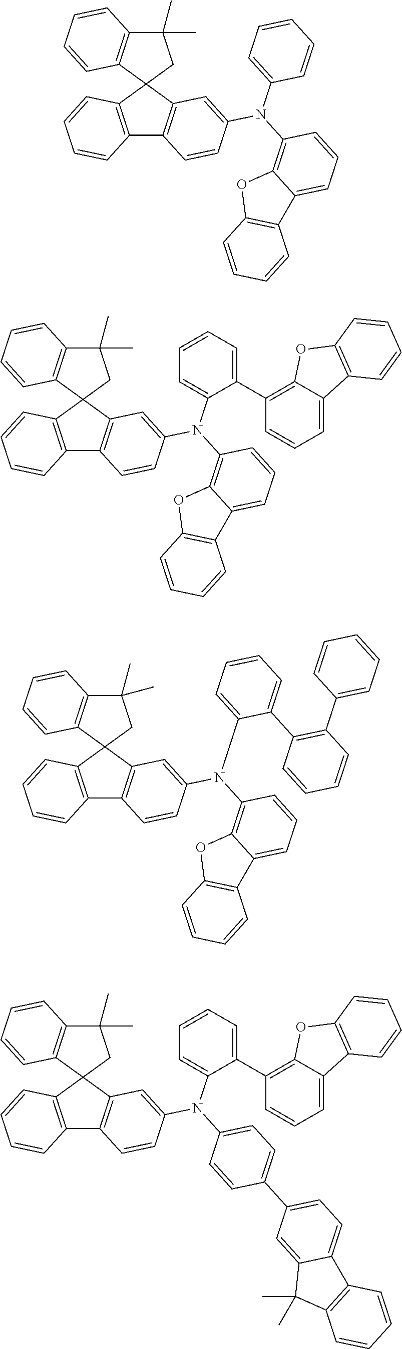 [SMILES: CC1(C)CC2(c3ccccc3-c3ccc(N(c4ccccc4)c4cccc5c4oc4ccccc45)cc32)c2ccccc21 ; CC1(C)CC2(c3ccccc3-c3ccc(N(c4ccccc4-c4cccc5c4oc4ccccc45)c4cccc5c4oc4ccccc45)cc32)c2ccccc21 ; CC1(C)CC2(c3ccccc3-c3ccc(N(c4ccccc4-c4ccccc4-c4ccccc4)c4cccc5c4oc4ccccc45)cc32)c2ccccc21 ; CC1(C)CC2(c3ccccc3-c3ccc(N(c4ccc(-c5ccc6c(c5)C(C)(C)c5ccccc5-6)cc4)c4ccccc4-c4cccc5c4oc4ccccc45)cc32)c2ccccc21]

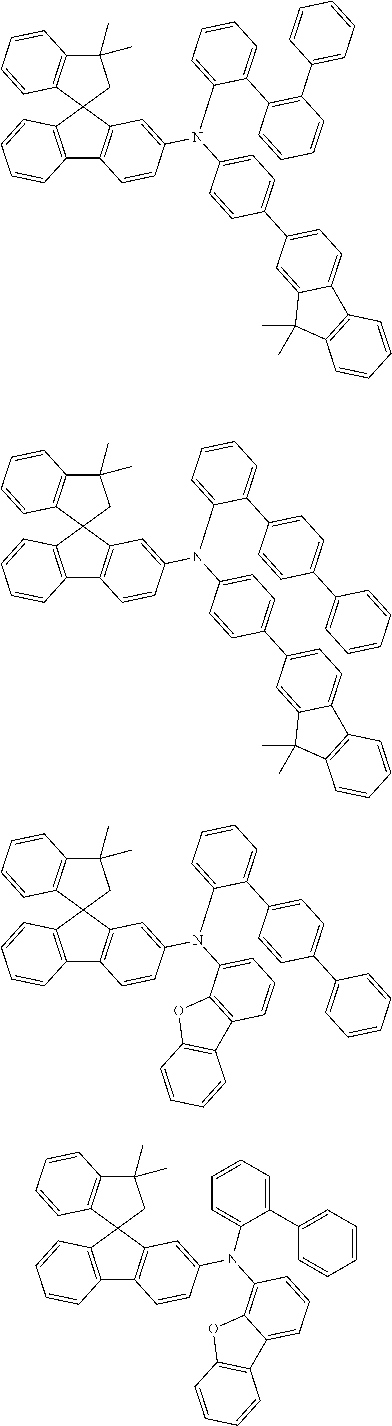 [SMILES: CC1(C)CC2(c3ccccc3-c3ccc(N(c4ccc(-c5ccc6c(c5)C(C)(C)c5ccccc5-6)cc4)c4ccccc4-c4ccccc4-c4ccccc4)cc32)c2ccccc21 ; CC1(C)CC2(c3ccccc3-c3ccc(N(c4ccc(-c5ccc6c(c5)C(C)(C)c5ccccc5-6)cc4)c4ccccc4-c4ccc(-c5ccccc5)cc4)cc32)c2ccccc21 ; CC1(C)CC2(c3ccccc3-c3ccc(N(c4ccccc4-c4ccc(-c5ccccc5)cc4)c4cccc5c4oc4ccccc45)cc32)c2ccccc21 ; CC1(C)CC2(c3ccccc3-c3ccc(N(c4ccccc4-c4ccccc4)c4cccc5c4oc4ccccc45)cc32)c2ccccc21]

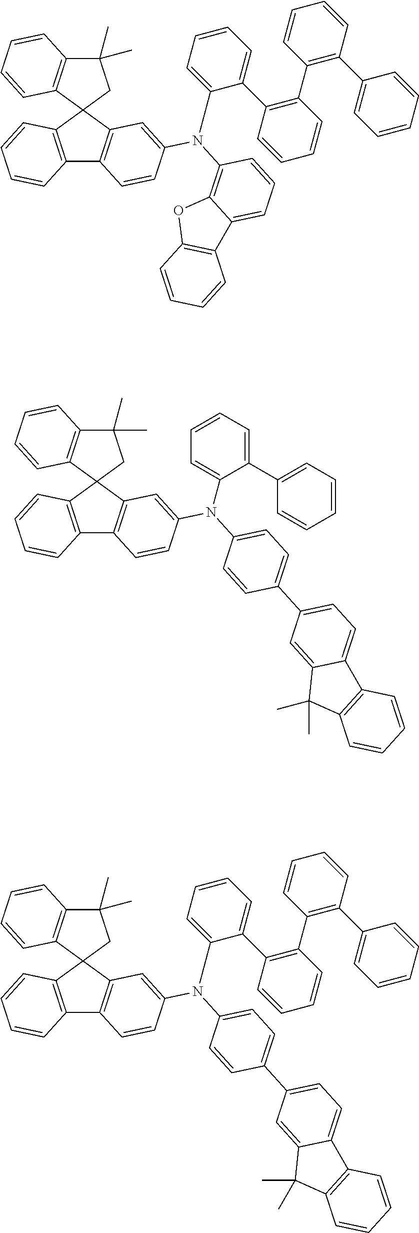 [SMILES: CC1(C)CC2(c3ccccc3-c3ccc(N(c4ccccc4-c4ccccc4-c4ccccc4-c4ccccc4)c4cccc5c4oc4ccccc45)cc32)c2ccccc21 ; CC1(C)CC2(c3ccccc3-c3ccc(N(c4ccc(-c5ccc6c(c5)C(C)(C)c5ccccc5-6)cc4)c4ccccc4-c4ccccc4)cc32)c2ccccc21 ; CC1(C)CC2(c3ccccc3-c3ccc(N(c4ccc(-c5ccc6c(c5)C(C)(C)c5ccccc5-6)cc4)c4ccccc4-c4ccccc4-c4ccccc4-c4ccccc4)cc32)c2ccccc21]

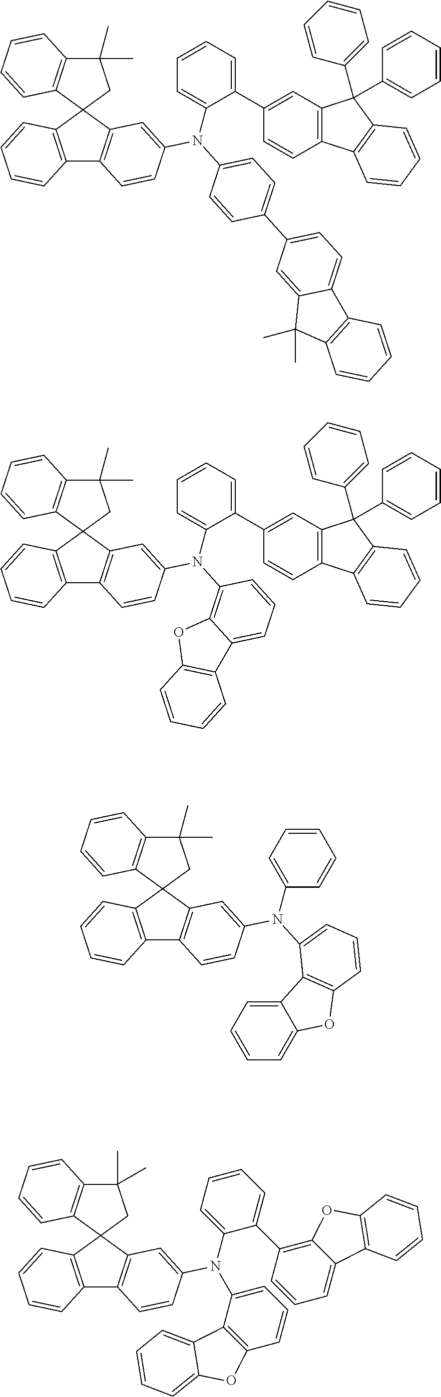 [SMILES: CC1(C)CC2(c3ccccc3-c3ccc(N(c4ccc(-c5ccc6c(c5)C(C)(C)c5ccccc5-6)cc4)c4ccccc4-c4ccc5c(c4)C(c4ccccc4)(c4ccccc4)c4ccccc4-5)cc32)c2ccccc21 ; CC1(C)CC2(c3ccccc3-c3ccc(N(c4ccccc4-c4ccc5c(c4)C(c4ccccc4)(c4ccccc4)c4ccccc4-5)c4cccc5c4oc4ccccc45)cc32)c2ccccc21 ; CC1(C)CC2(c3ccccc3-c3ccc(N(c4ccccc4)c4cccc5oc6ccccc6c45)cc32)c2ccccc21 ; CC1(C)CC2(c3ccccc3-c3ccc(N(c4ccccc4-c4cccc5c4oc4ccccc45)c4cccc5oc6ccccc6c45)cc32)c2ccccc21]

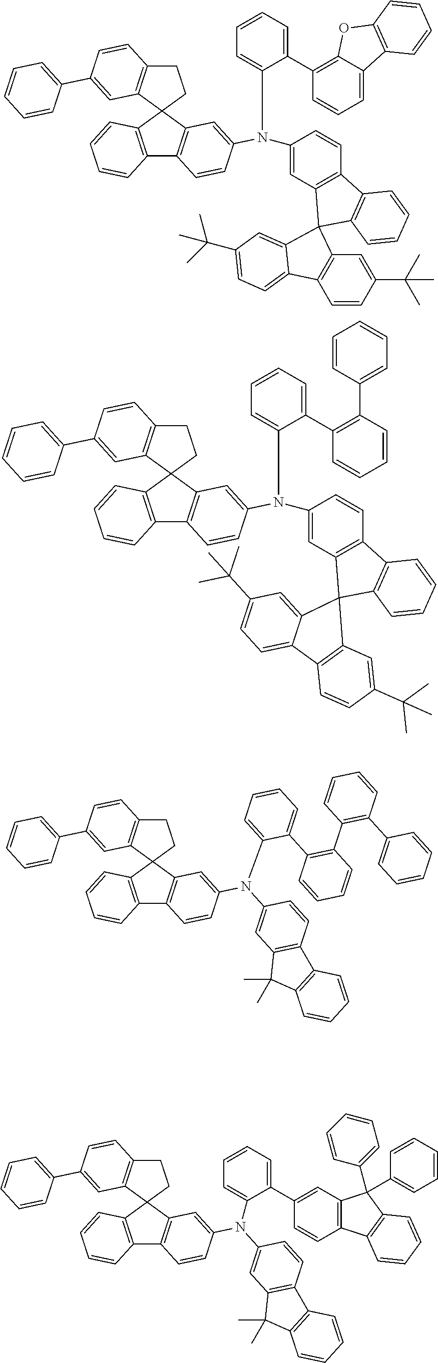

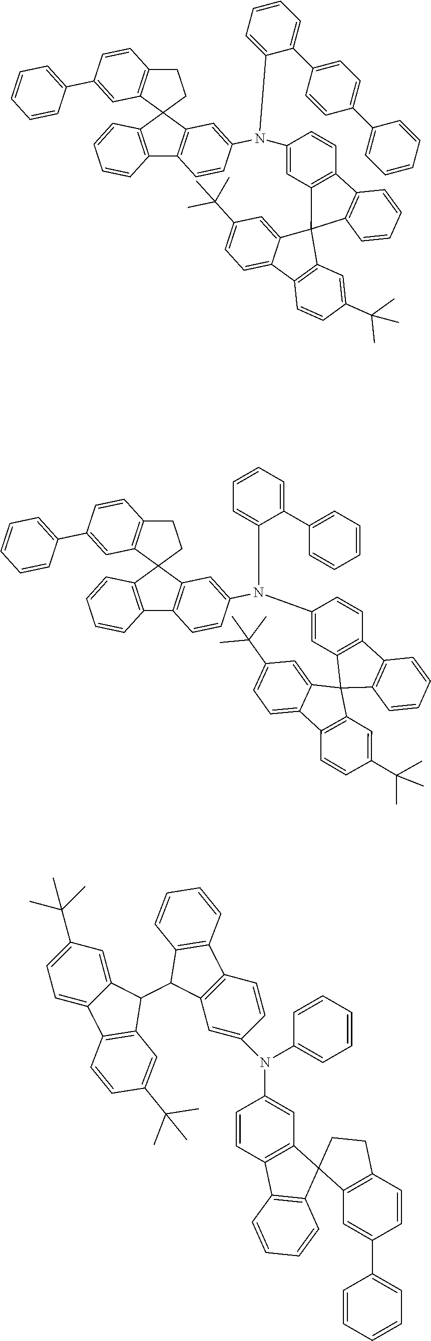 [SMILES: CC(C)(C)c1ccc2c(c1)C1(c3ccccc3-c3ccc(N(c4ccc5c(c4)C4(CCc6ccc(-c7ccccc7)cc64)c4ccccc4-5)c4ccccc4-c4ccc(-c5ccccc5)cc4)cc31)c1cc(C(C)(C)C)ccc1-2 ; CC(C)(C)c1ccc2c(c1)C1(c3ccccc3-c3ccc(N(c4ccc5c(c4)C4(CCc6ccc(-c7ccccc7)cc64)c4ccccc4-5)c4ccccc4-c4ccccc4)cc31)c1cc(C(C)(C)C)ccc1-2 ; CC(C)(C)c1ccc2c(c1)C(C1c3ccccc3-c3ccc(N(c4ccccc4)c4ccc5c(c4)C4(CCc6ccc(-c7ccccc7)cc64)c4ccccc4-5)cc31)c1cc(C(C)(C)C)ccc1-2]

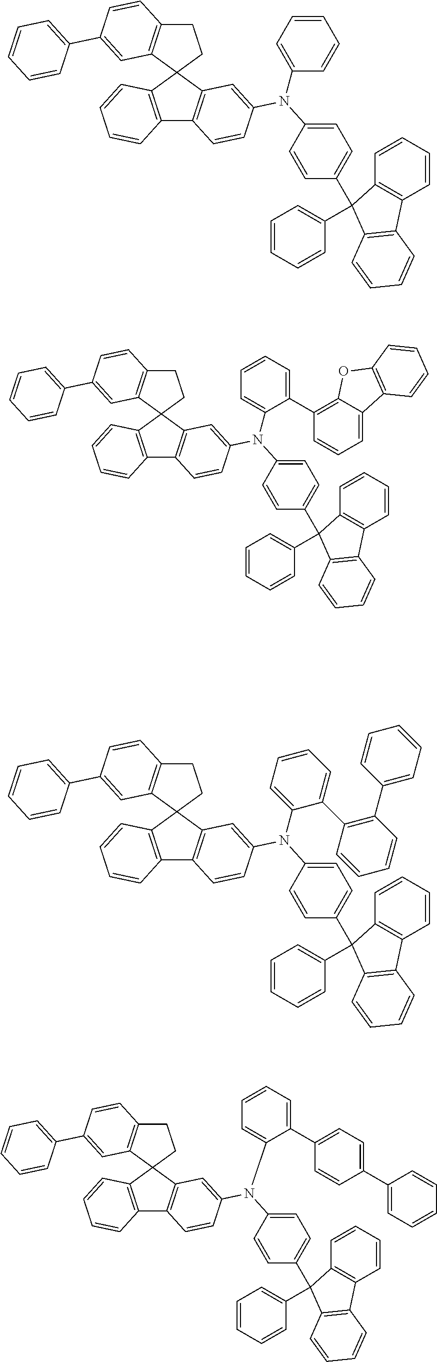 [SMILES: c1ccc(-c2ccc3c(c2)C2(CC3)c3ccccc3-c3ccc(N(c4ccccc4)c4ccc(C5(c6ccccc6)c6ccccc6-c6ccccc65)cc4)cc32)cc1 ; c1ccc(-c2ccc3c(c2)C2(CC3)c3ccccc3-c3ccc(N(c4ccc(C5(c6ccccc6)c6ccccc6-c6ccccc65)cc4)c4ccccc4-c4cccc5c4oc4ccccc45)cc32)cc1 ; c1ccc(-c2ccc3c(c2)C2(CC3)c3ccccc3-c3ccc(N(c4ccc(C5(c6ccccc6)c6ccccc6-c6ccccc65)cc4)c4ccccc4-c4ccccc4-c4ccccc4)cc32)cc1 ; c1ccc(-c2ccc(-c3ccccc3N(c3ccc(C4(c5ccccc5)c5ccccc5-c5ccccc54)cc3)c3ccc4c(c3)C3(CCc5ccc(-c6ccccc6)cc53)c3ccccc3-4)cc2)cc1]

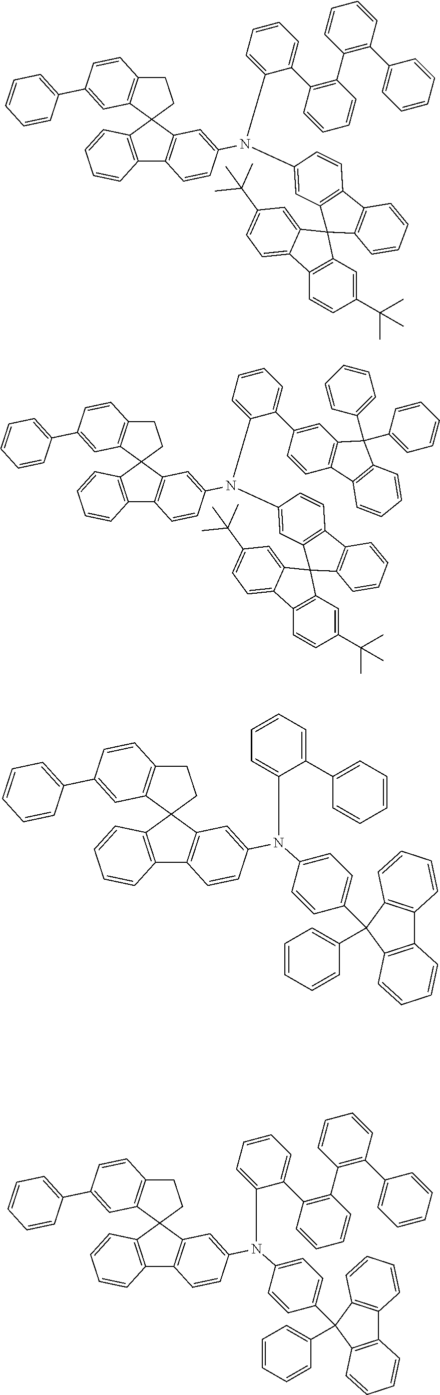

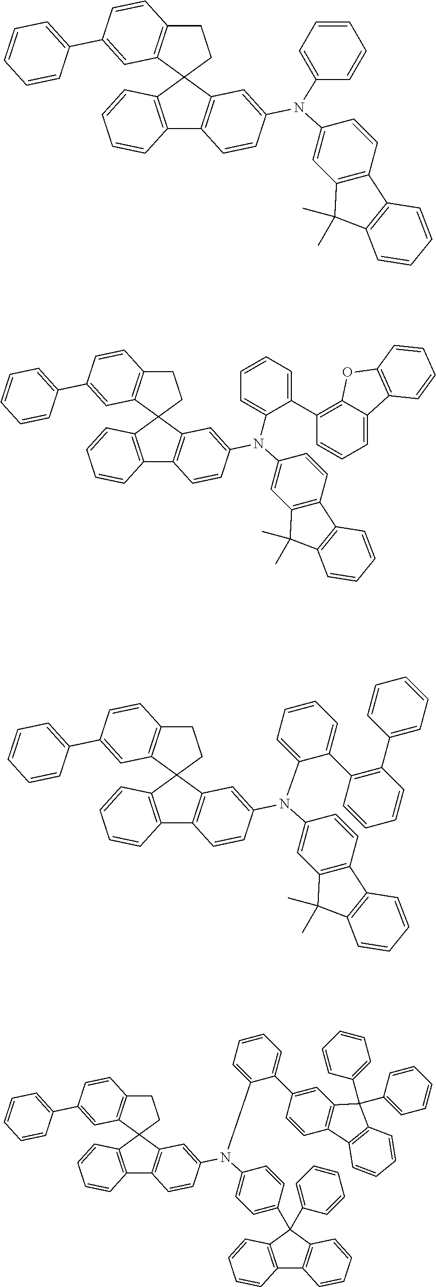 [SMILES: CC1(C)c2ccccc2-c2ccc(N(c3ccccc3)c3ccc4c(c3)C3(CCc5ccc(-c6ccccc6)cc53)c3ccccc3-4)cc21 ; CC1(C)c2ccccc2-c2ccc(N(c3ccc4c(c3)C3(CCc5ccc(-c6ccccc6)cc53)c3ccccc3-4)c3ccccc3-c3cccc4c3oc3ccccc34)cc21 ; CC1(C)c2ccccc2-c2ccc(N(c3ccc4c(c3)C3(CCc5ccc(-c6ccccc6)cc53)c3ccccc3-4)c3ccccc3-c3ccccc3-c3ccccc3)cc21 ; c1ccc(-c2ccc3c(c2)C2(CC3)c3ccccc3-c3ccc(N(c4ccc(C5(c6ccccc6)c6ccccc6-c6ccccc65)cc4)c4ccccc4-c4ccc5c(c4)C(c4ccccc4)(c4ccccc4)c4ccccc4-5)cc32)cc1]

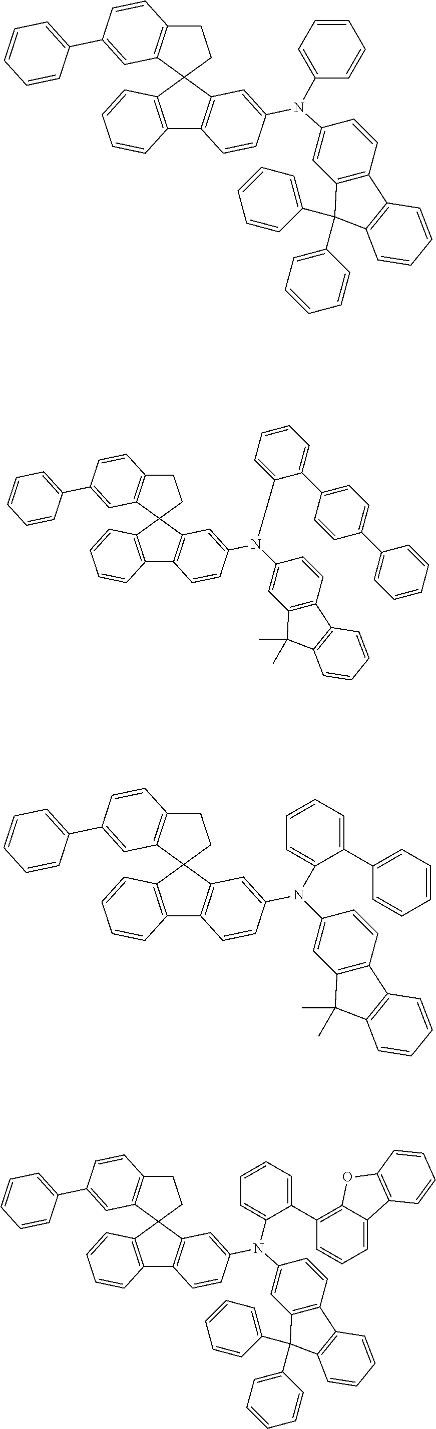

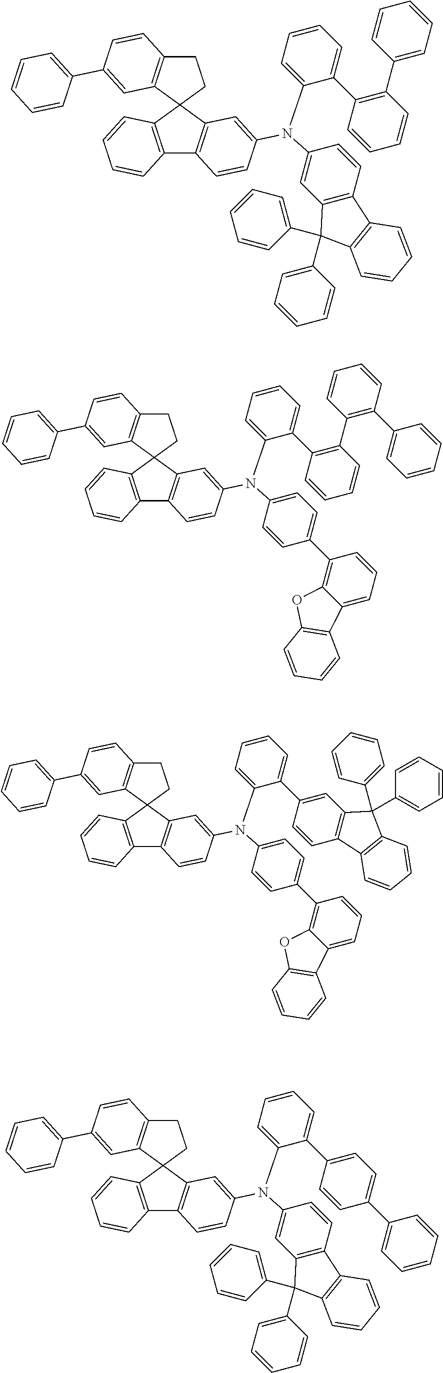

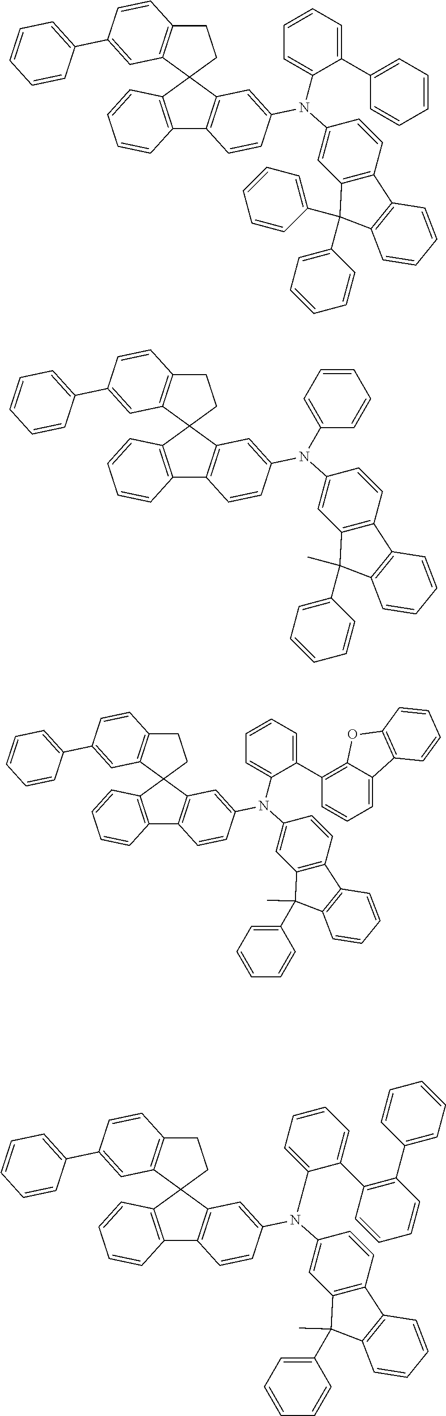 [SMILES: c1ccc(-c2ccc3c(c2)C2(CC3)c3ccccc3-c3ccc(N(c4ccc5c(c4)C(c4ccccc4)(c4ccccc4)c4ccccc4-5)c4ccccc4-c4ccccc4)cc32)cc1 ; CC1(c2ccccc2)c2ccccc2-c2ccc(N(c3ccccc3)c3ccc4c(c3)C3(CCc5ccc(-c6ccccc6)cc53)c3ccccc3-4)cc21 ; CC1(c2ccccc2)c2ccccc2-c2ccc(N(c3ccc4c(c3)C3(CCc5ccc(-c6ccccc6)cc53)c3ccccc3-4)c3ccccc3-c3cccc4c3oc3ccccc34)cc21 ; CC1(c2ccccc2)c2ccccc2-c2ccc(N(c3ccc4c(c3)C3(CCc5ccc(-c6ccccc6)cc53)c3ccccc3-4)c3ccccc3-c3ccccc3-c3ccccc3)cc21]

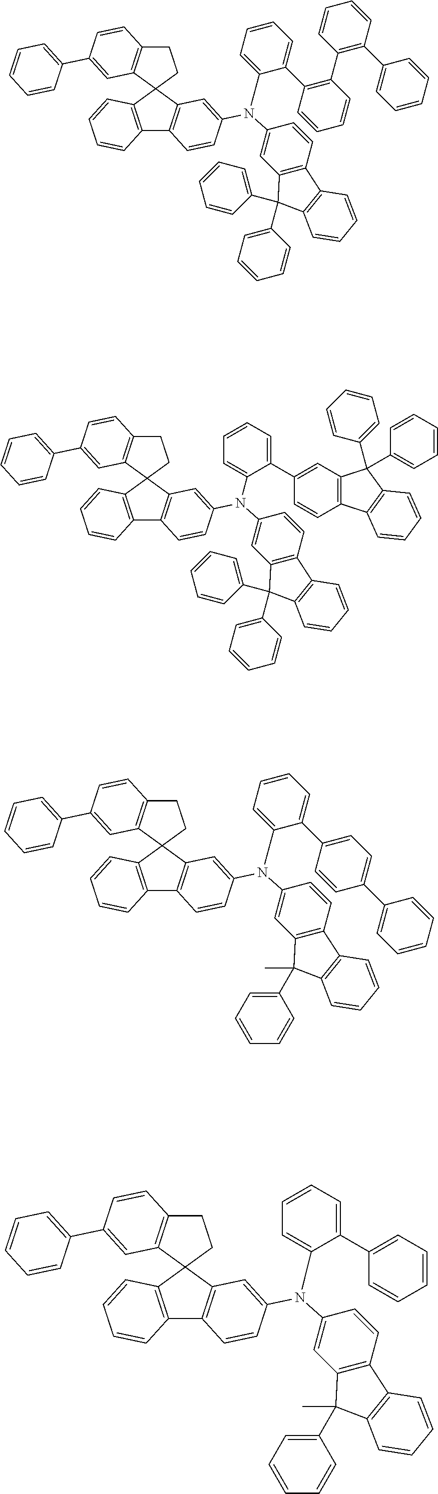 [SMILES: c1ccc(-c2ccc3c(c2)C2(CC3)c3ccccc3-c3ccc(N(c4ccc5c(c4)C(c4ccccc4)(c4ccccc4)c4ccccc4-5)c4ccccc4-c4ccccc4-c4ccccc4-c4ccccc4)cc32)cc1 ; c1ccc(-c2ccc3c(c2)C2(CC3)c3ccccc3-c3ccc(N(c4ccc5c(c4)C(c4ccccc4)(c4ccccc4)c4ccccc4-5)c4ccccc4-c4ccc5c(c4)C(c4ccccc4)(c4ccccc4)c4ccccc4-5)cc32)cc1 ; CC1(c2ccccc2)c2ccccc2-c2ccc(N(c3ccc4c(c3)C3(CCc5ccc(-c6ccccc6)cc53)c3ccccc3-4)c3ccccc3-c3ccc(-c4ccccc4)cc3)cc21 ; CC1(c2ccccc2)c2ccccc2-c2ccc(N(c3ccc4c(c3)C3(CCc5ccc(-c6ccccc6)cc53)c3ccccc3-4)c3ccccc3-c3ccccc3)cc21]

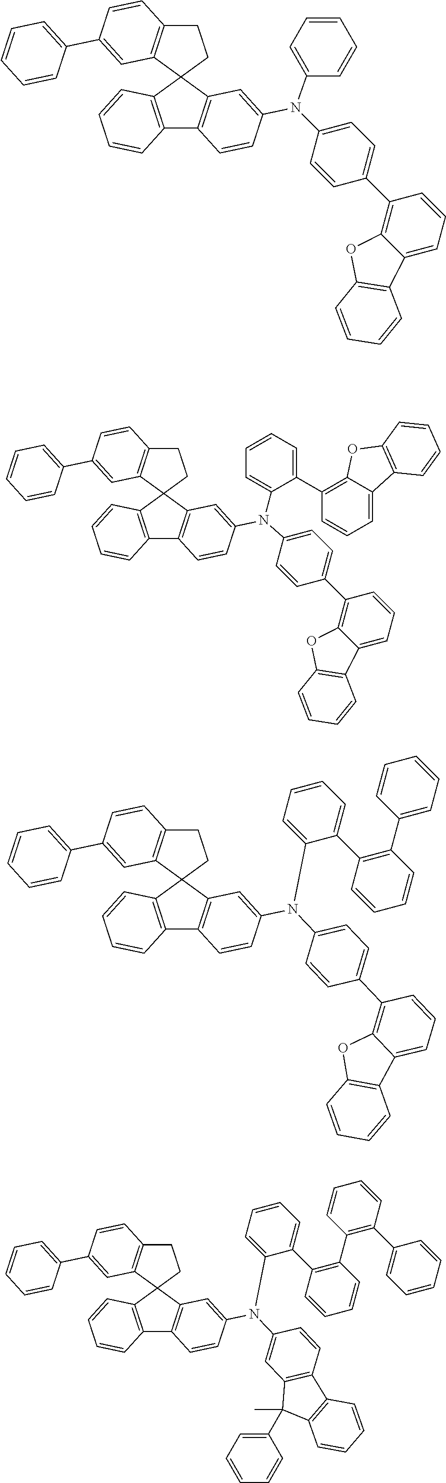 [SMILES: c1ccc(-c2ccc3c(c2)C2(CC3)c3ccccc3-c3ccc(N(c4ccccc4)c4ccc(-c5cccc6c5oc5ccccc56)cc4)cc32)cc1 ; c1ccc(-c2ccc3c(c2)C2(CC3)c3ccccc3-c3ccc(N(c4ccc(-c5cccc6c5oc5ccccc56)cc4)c4ccccc4-c4cccc5c4oc4ccccc45)cc32)cc1 ; c1ccc(-c2ccc3c(c2)C2(CC3)c3ccccc3-c3ccc(N(c4ccc(-c5cccc6c5oc5ccccc56)cc4)c4ccccc4-c4ccccc4-c4ccccc4)cc32)cc1 ; CC1(c2ccccc2)c2ccccc2-c2ccc(N(c3ccc4c(c3)C3(CCc5ccc(-c6ccccc6)cc53)c3ccccc3-4)c3ccccc3-c3ccccc3-c3ccccc3-c3ccccc3)cc21]

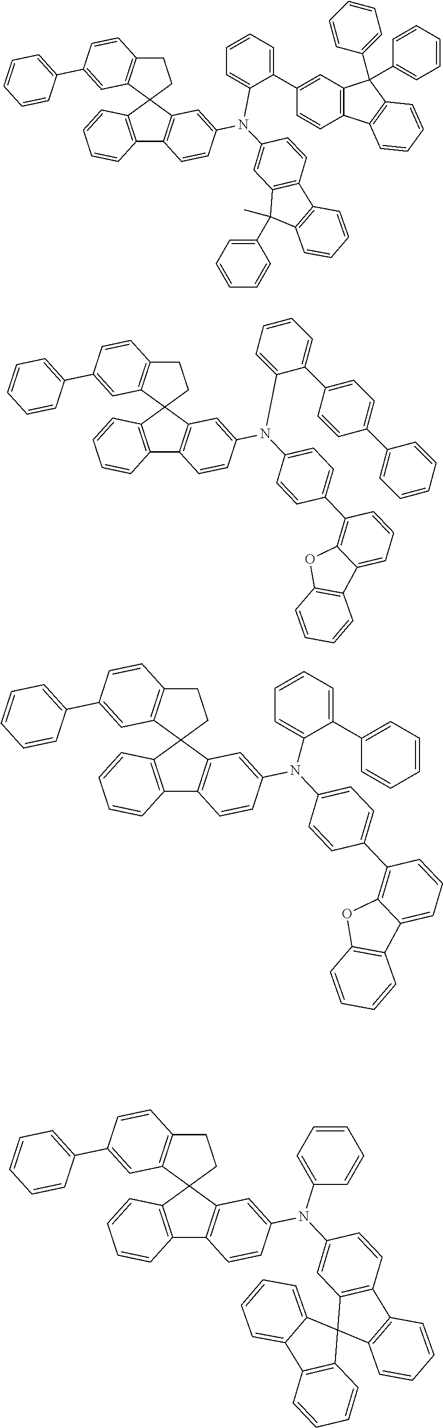

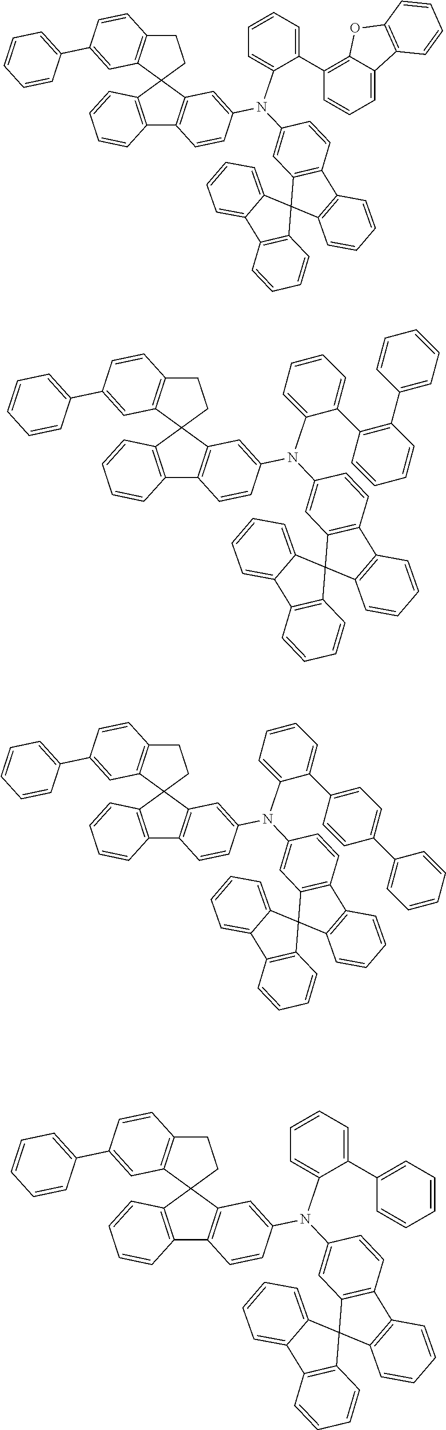 [SMILES: c1ccc(-c2ccc3c(c2)C2(CC3)c3ccccc3-c3ccc(N(c4ccc5c(c4)C4(c6ccccc6-c6ccccc64)c4ccccc4-5)c4ccccc4-c4cccc5c4oc4ccccc45)cc32)cc1 ; c1ccc(-c2ccc3c(c2)C2(CC3)c3ccccc3-c3ccc(N(c4ccc5c(c4)C4(c6ccccc6-c6ccccc64)c4ccccc4-5)c4ccccc4-c4ccccc4-c4ccccc4)cc32)cc1 ; c1ccc(-c2ccc(-c3ccccc3N(c3ccc4c(c3)C3(CCc5ccc(-c6ccccc6)cc53)c3ccccc3-4)c3ccc4c(c3)C3(c5ccccc5-c5ccccc53)c3ccccc3-4)cc2)cc1 ; c1ccc(-c2ccc3c(c2)C2(CC3)c3ccccc3-c3ccc(N(c4ccc5c(c4)C4(c6ccccc6-c6ccccc64)c4ccccc4-5)c4ccccc4-c4ccccc4)cc32)cc1]

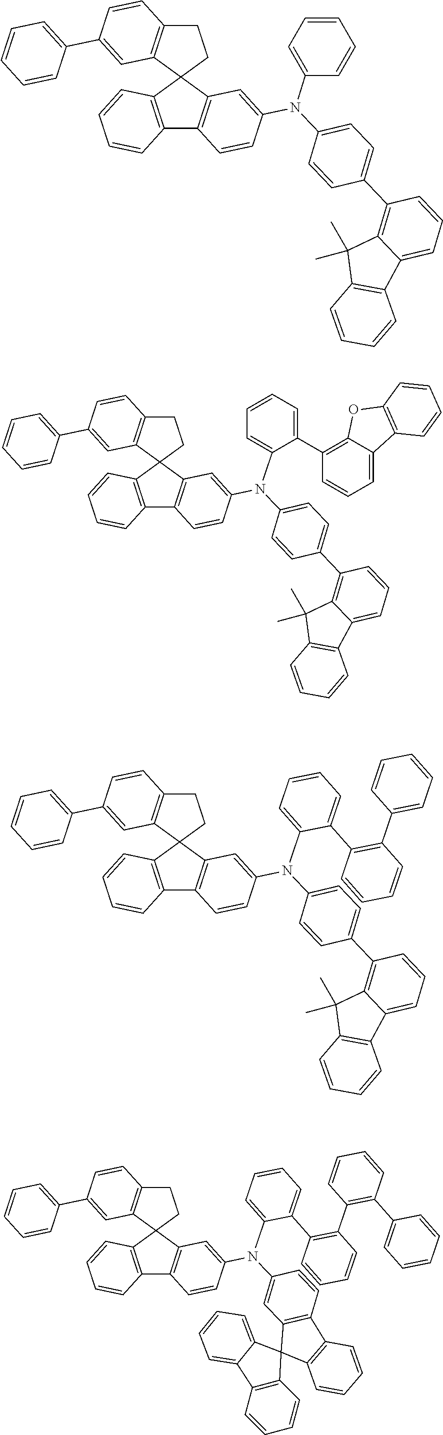 [SMILES: CC1(C)c2ccccc2-c2cccc(-c3ccc(N(c4ccccc4)c4ccc5c(c4)C4(CCc6ccc(-c7ccccc7)cc64)c4ccccc4-5)cc3)c21 ; CC1(C)c2ccccc2-c2cccc(-c3ccc(N(c4ccc5c(c4)C4(CCc6ccc(-c7ccccc7)cc64)c4ccccc4-5)c4ccccc4-c4cccc5c4oc4ccccc45)cc3)c21 ; CC1(C)c2ccccc2-c2cccc(-c3ccc(N(c4ccc5c(c4)C4(CCc6ccc(-c7ccccc7)cc64)c4ccccc4-5)c4ccccc4-c4ccccc4-c4ccccc4)cc3)c21 ; c1ccc(-c2ccc3c(c2)C2(CC3)c3ccccc3-c3ccc(N(c4ccc5c(c4)C4(c6ccccc6-c6ccccc64)c4ccccc4-5)c4ccccc4-c4ccccc4-c4ccccc4-c4ccccc4)cc32)cc1]

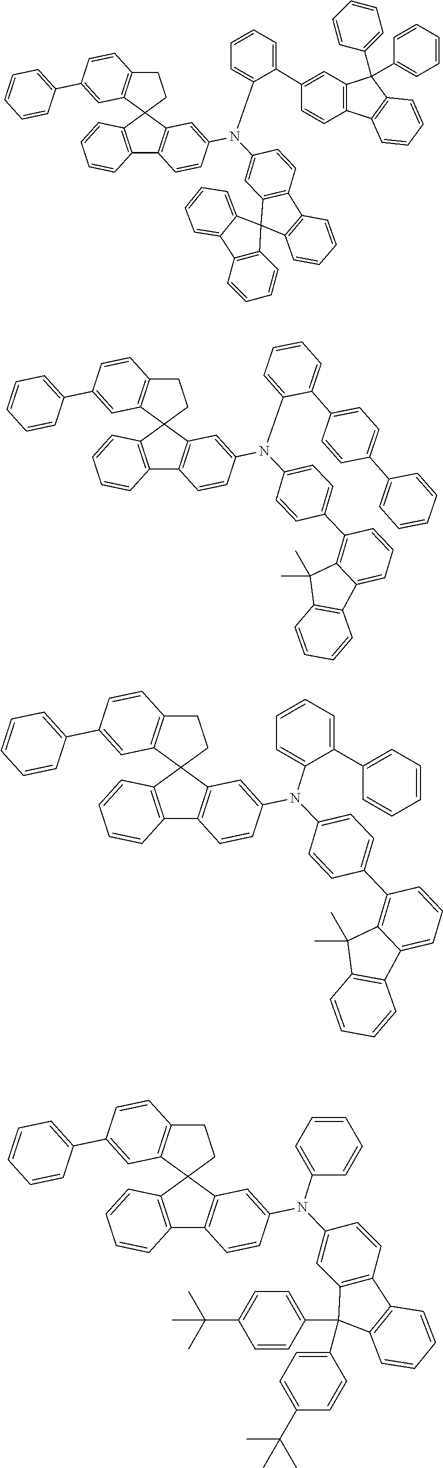 [SMILES: c1ccc(-c2ccc3c(c2)C2(CC3)c3ccccc3-c3ccc(N(c4ccc5c(c4)C4(c6ccccc6-c6ccccc64)c4ccccc4-5)c4ccccc4-c4ccc5c(c4)C(c4ccccc4)(c4ccccc4)c4ccccc4-5)cc32)cc1 ; CC1(C)c2ccccc2-c2cccc(-c3ccc(N(c4ccc5c(c4)C4(CCc6ccc(-c7ccccc7)cc64)c4ccccc4-5)c4ccccc4-c4ccc(-c5ccccc5)cc4)cc3)c21 ; CC1(C)c2ccccc2-c2cccc(-c3ccc(N(c4ccc5c(c4)C4(CCc6ccc(-c7ccccc7)cc64)c4ccccc4-5)c4ccccc4-c4ccccc4)cc3)c21 ; CC(C)(C)c1ccc(C2(c3ccc(C(C)(C)C)cc3)c3ccccc3-c3ccc(N(c4ccccc4)c4ccc5c(c4)C4(CCc6ccc(-c7ccccc7)cc64)c4ccccc4-5)cc32)cc1]

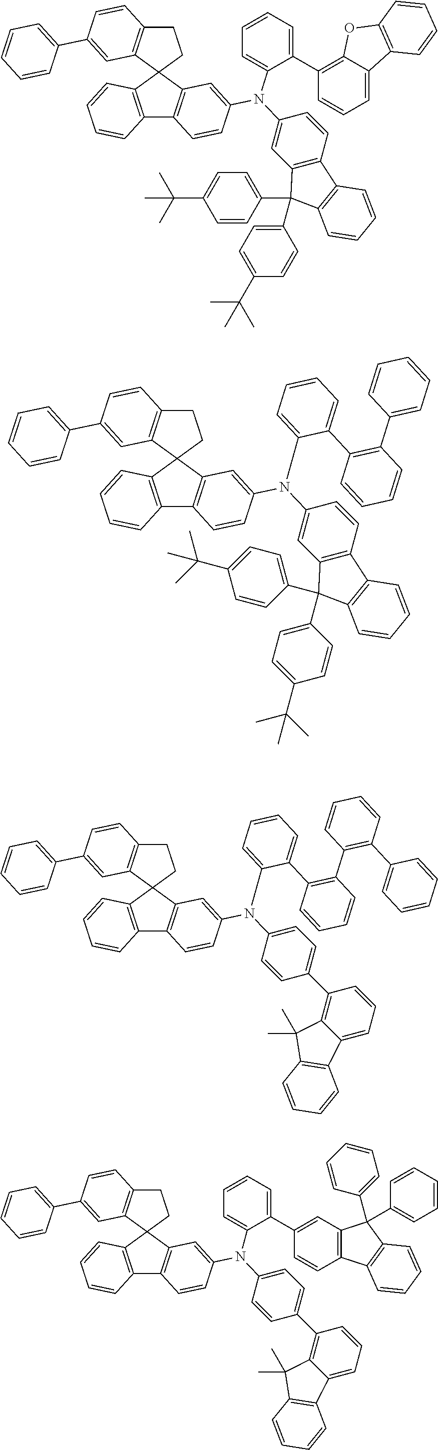

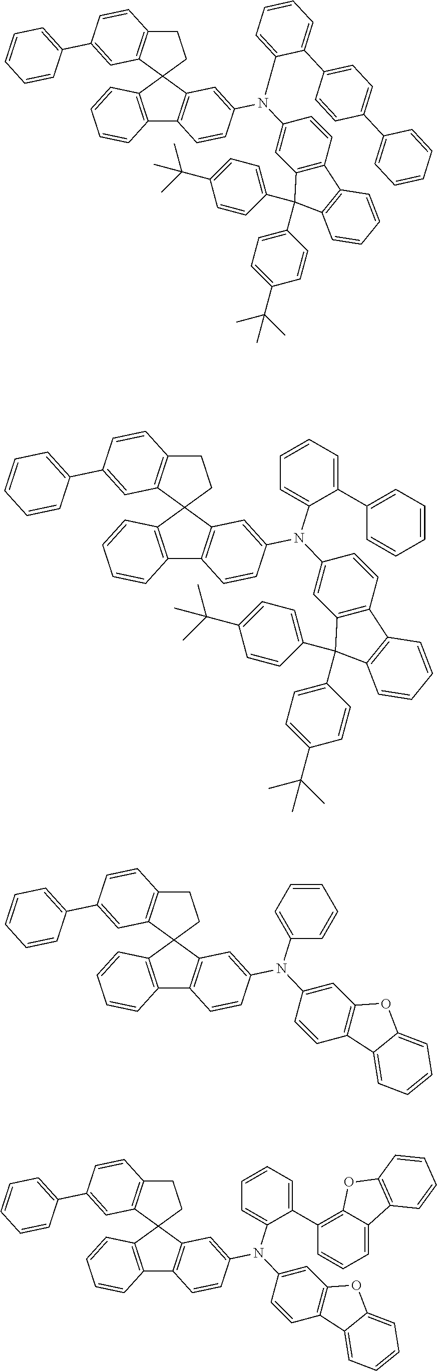 [SMILES: CC(C)(C)c1ccc(C2(c3ccc(C(C)(C)C)cc3)c3ccccc3-c3ccc(N(c4ccc5c(c4)C4(CCc6ccc(-c7ccccc7)cc64)c4ccccc4-5)c4ccccc4-c4ccc(-c5ccccc5)cc4)cc32)cc1 ; CC(C)(C)c1ccc(C2(c3ccc(C(C)(C)C)cc3)c3ccccc3-c3ccc(N(c4ccc5c(c4)C4(CCc6ccc(-c7ccccc7)cc64)c4ccccc4-5)c4ccccc4-c4ccccc4)cc32)cc1 ; c1ccc(-c2ccc3c(c2)C2(CC3)c3ccccc3-c3ccc(N(c4ccccc4)c4ccc5c(c4)oc4ccccc45)cc32)cc1 ; c1ccc(-c2ccc3c(c2)C2(CC3)c3ccccc3-c3ccc(N(c4ccc5c(c4)oc4ccccc45)c4ccccc4-c4cccc5c4oc4ccccc45)cc32)cc1]

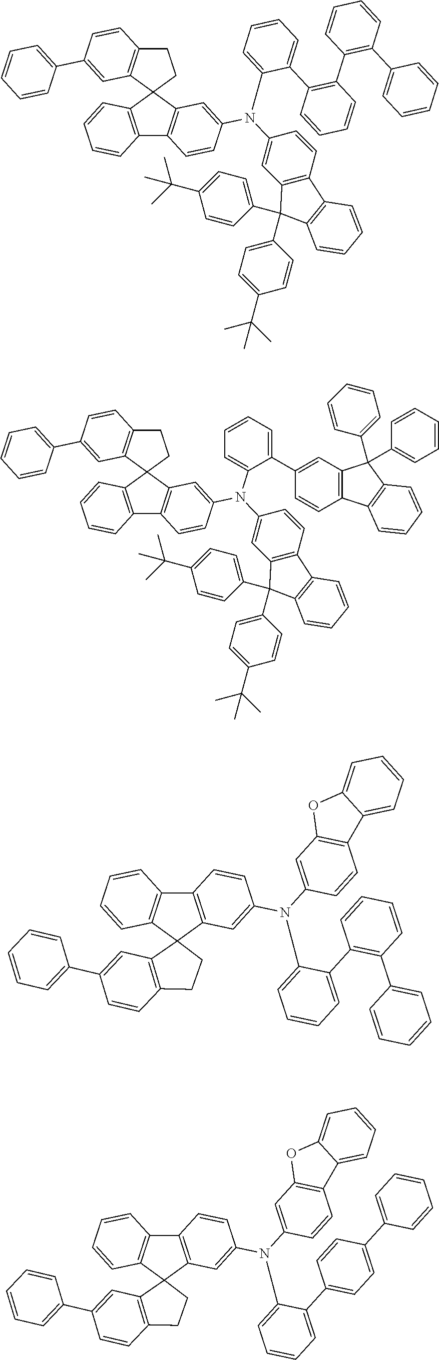

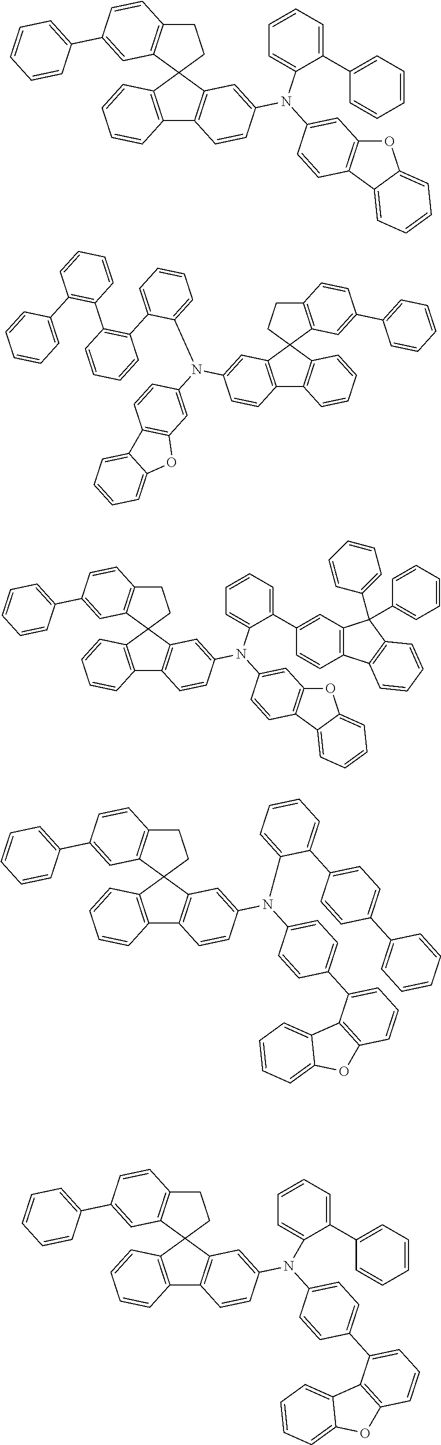

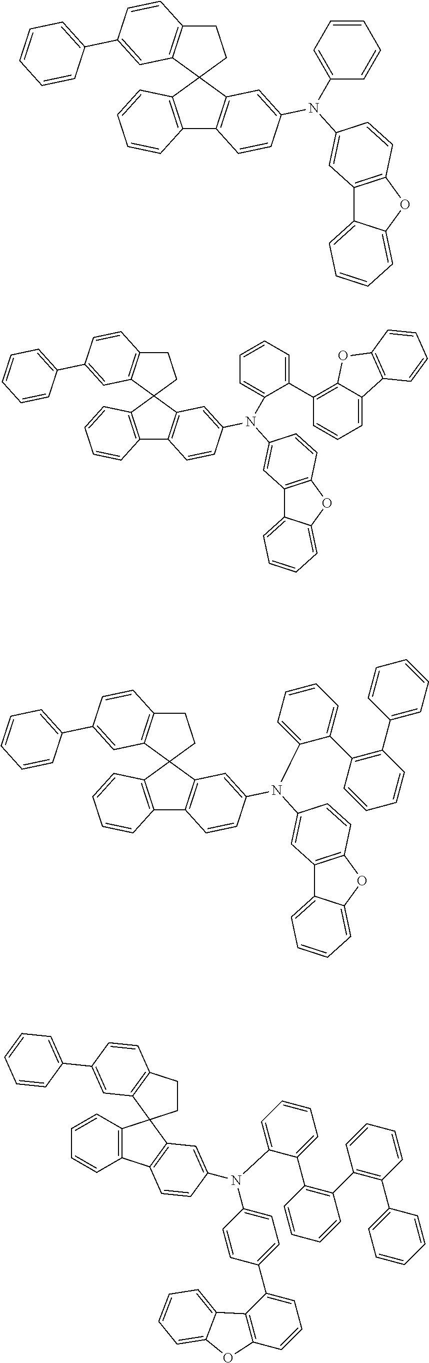 [SMILES: c1ccc(-c2ccc3c(c2)C2(CC3)c3ccccc3-c3ccc(N(c4ccccc4)c4ccc5oc6ccccc6c5c4)cc32)cc1 ; c1ccc(-c2ccc3c(c2)C2(CC3)c3ccccc3-c3ccc(N(c4ccc5oc6ccccc6c5c4)c4ccccc4-c4cccc5c4oc4ccccc45)cc32)cc1 ; c1ccc(-c2ccc3c(c2)C2(CC3)c3ccccc3-c3ccc(N(c4ccc5oc6ccccc6c5c4)c4ccccc4-c4ccccc4-c4ccccc4)cc32)cc1 ; c1ccc(-c2ccc3c(c2)C2(CC3)c3ccccc3-c3ccc(N(c4ccc(-c5cccc6oc7ccccc7c56)cc4)c4ccccc4-c4ccccc4-c4ccccc4-c4ccccc4)cc32)cc1]

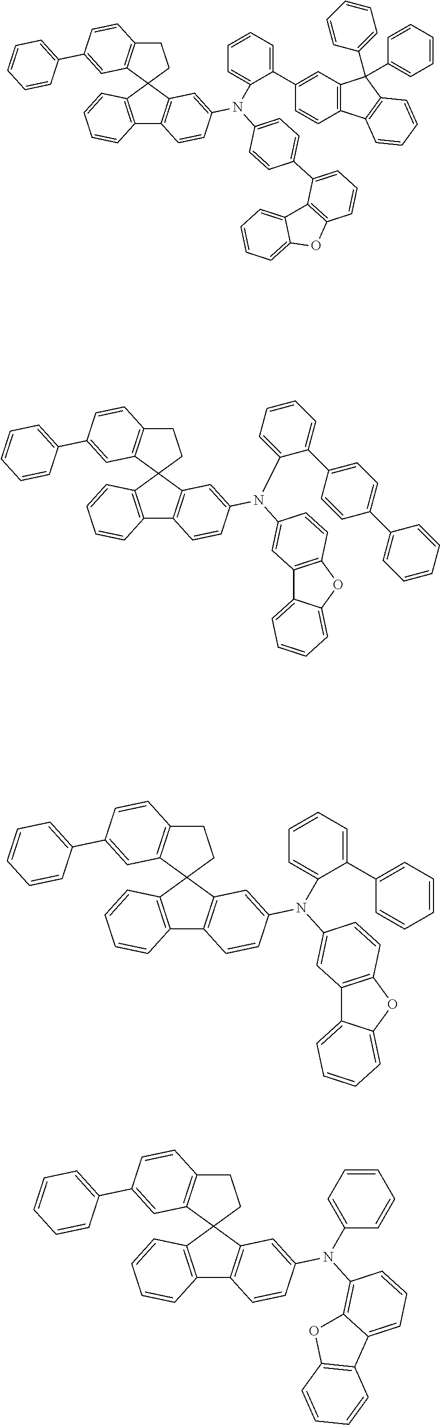 [SMILES: c1ccc(-c2ccc3c(c2)C2(CC3)c3ccccc3-c3ccc(N(c4ccc(-c5cccc6oc7ccccc7c56)cc4)c4ccccc4-c4ccc5c(c4)C(c4ccccc4)(c4ccccc4)c4ccccc4-5)cc32)cc1 ; c1ccc(-c2ccc(-c3ccccc3N(c3ccc4c(c3)C3(CCc5ccc(-c6ccccc6)cc53)c3ccccc3-4)c3ccc4oc5ccccc5c4c3)cc2)cc1 ; c1ccc(-c2ccc3c(c2)C2(CC3)c3ccccc3-c3ccc(N(c4ccc5oc6ccccc6c5c4)c4ccccc4-c4ccccc4)cc32)cc1 ; c1ccc(-c2ccc3c(c2)C2(CC3)c3ccccc3-c3ccc(N(c4ccccc4)c4cccc5c4oc4ccccc45)cc32)cc1]

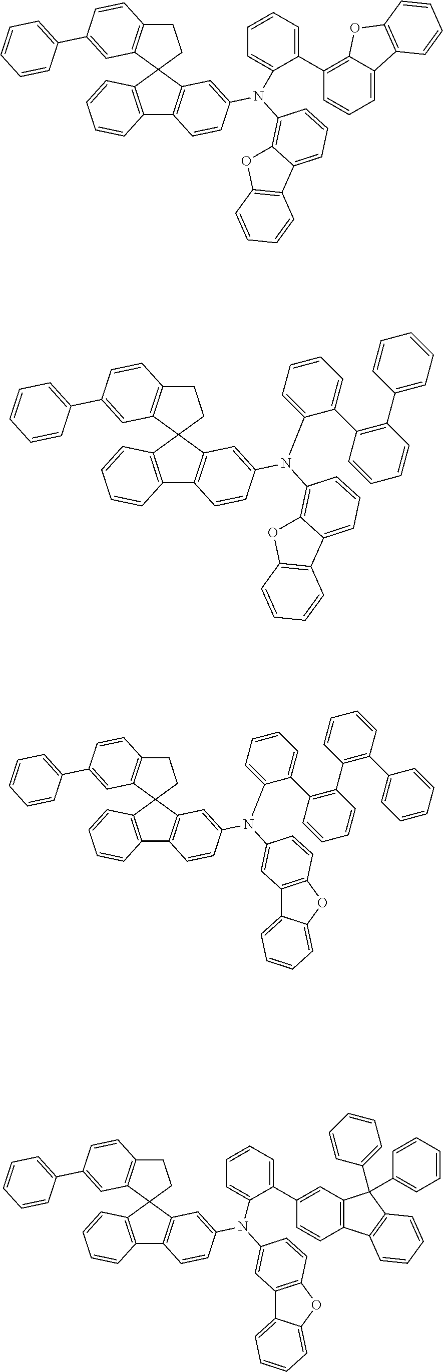 [SMILES: c1ccc(-c2ccc3c(c2)C2(CC3)c3ccccc3-c3ccc(N(c4ccccc4-c4cccc5c4oc4ccccc45)c4cccc5c4oc4ccccc45)cc32)cc1 ; c1ccc(-c2ccc3c(c2)C2(CC3)c3ccccc3-c3ccc(N(c4ccccc4-c4ccccc4-c4ccccc4)c4cccc5c4oc4ccccc45)cc32)cc1 ; c1ccc(-c2ccc3c(c2)C2(CC3)c3ccccc3-c3ccc(N(c4ccc5oc6ccccc6c5c4)c4ccccc4-c4ccccc4-c4ccccc4-c4ccccc4)cc32)cc1 ; c1ccc(-c2ccc3c(c2)C2(CC3)c3ccccc3-c3ccc(N(c4ccc5oc6ccccc6c5c4)c4ccccc4-c4ccc5c(c4)C(c4ccccc4)(c4ccccc4)c4ccccc4-5)cc32)cc1]

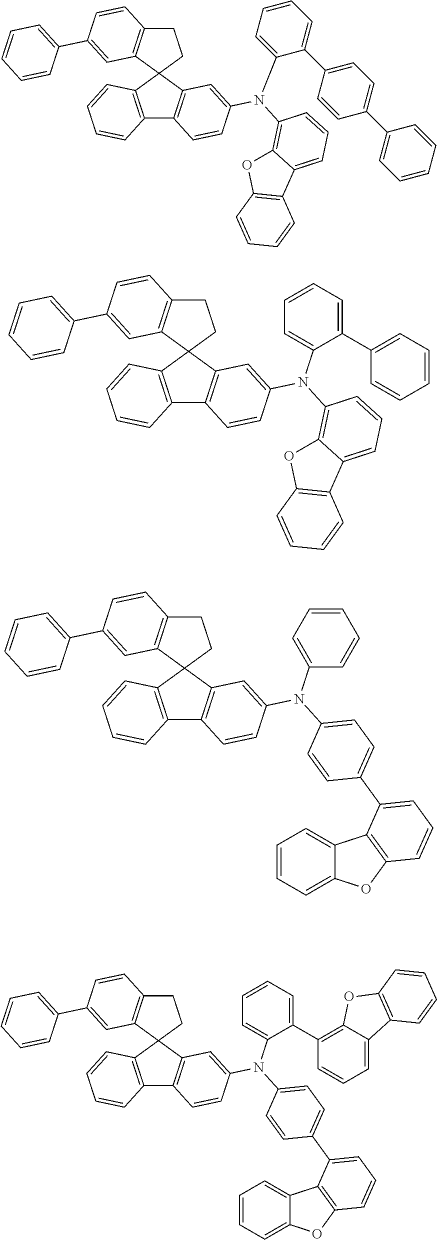 [SMILES: c1ccc(-c2ccc(-c3ccccc3N(c3ccc4c(c3)C3(CCc5ccc(-c6ccccc6)cc53)c3ccccc3-4)c3cccc4c3oc3ccccc34)cc2)cc1 ; c1ccc(-c2ccc3c(c2)C2(CC3)c3ccccc3-c3ccc(N(c4ccccc4-c4ccccc4)c4cccc5c4oc4ccccc45)cc32)cc1 ; c1ccc(-c2ccc3c(c2)C2(CC3)c3ccccc3-c3ccc(N(c4ccccc4)c4ccc(-c5cccc6oc7ccccc7c56)cc4)cc32)cc1 ; c1ccc(-c2ccc3c(c2)C2(CC3)c3ccccc3-c3ccc(N(c4ccc(-c5cccc6oc7ccccc7c56)cc4)c4ccccc4-c4cccc5c4oc4ccccc45)cc32)cc1]

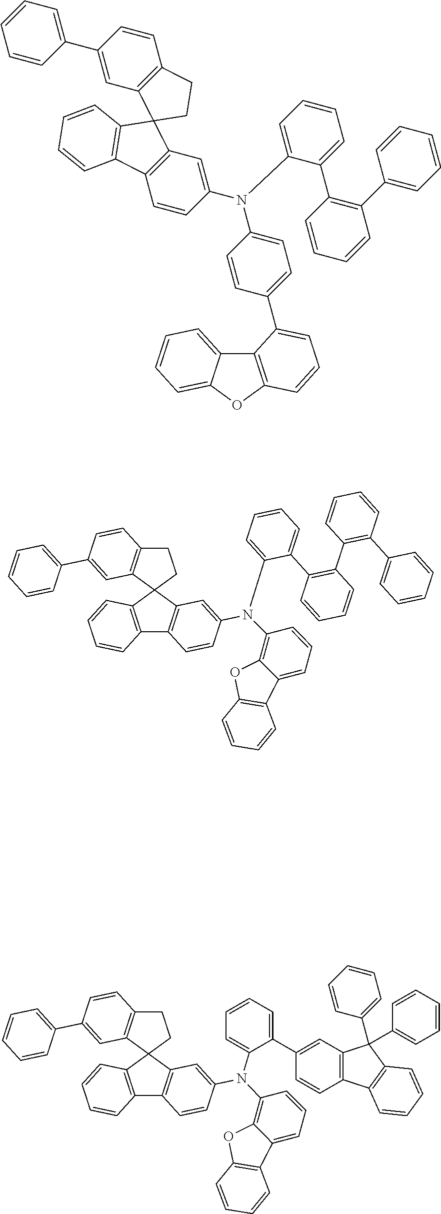 [SMILES: c1ccc(-c2ccc3c(c2)C2(CC3)c3ccccc3-c3ccc(N(c4ccc(-c5cccc6oc7ccccc7c56)cc4)c4ccccc4-c4ccccc4-c4ccccc4)cc32)cc1 ; c1ccc(-c2ccc3c(c2)C2(CC3)c3ccccc3-c3ccc(N(c4ccccc4-c4ccccc4-c4ccccc4-c4ccccc4)c4cccc5c4oc4ccccc45)cc32)cc1 ; c1ccc(-c2ccc3c(c2)C2(CC3)c3ccccc3-c3ccc(N(c4ccccc4-c4ccc5c(c4)C(c4ccccc4)(c4ccccc4)c4ccccc4-5)c4cccc5c4oc4ccccc45)cc32)cc1]

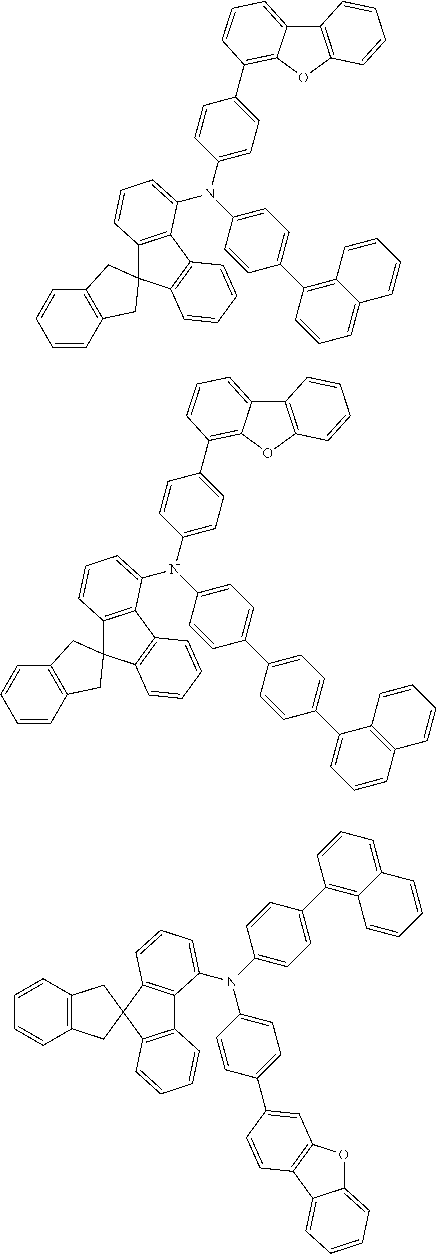

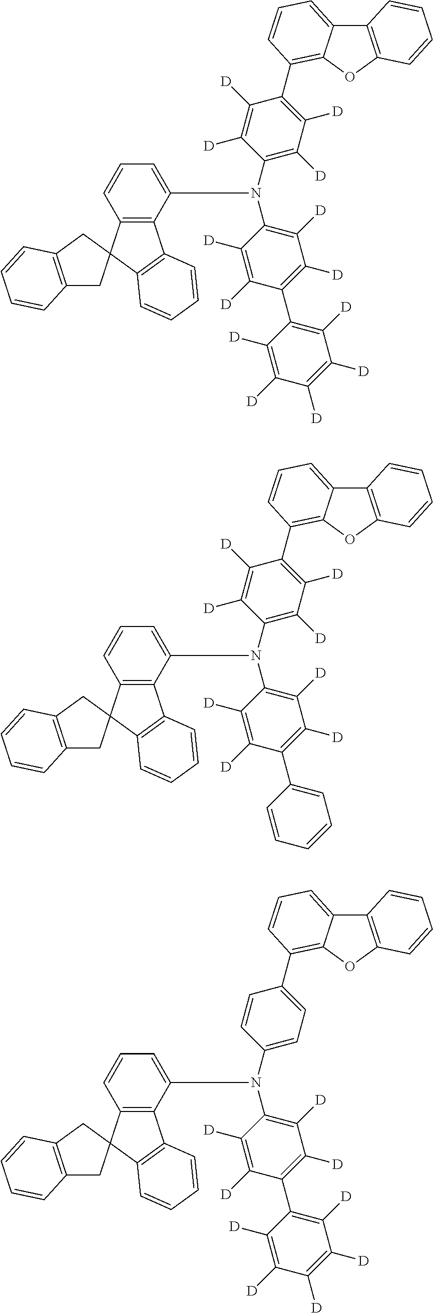

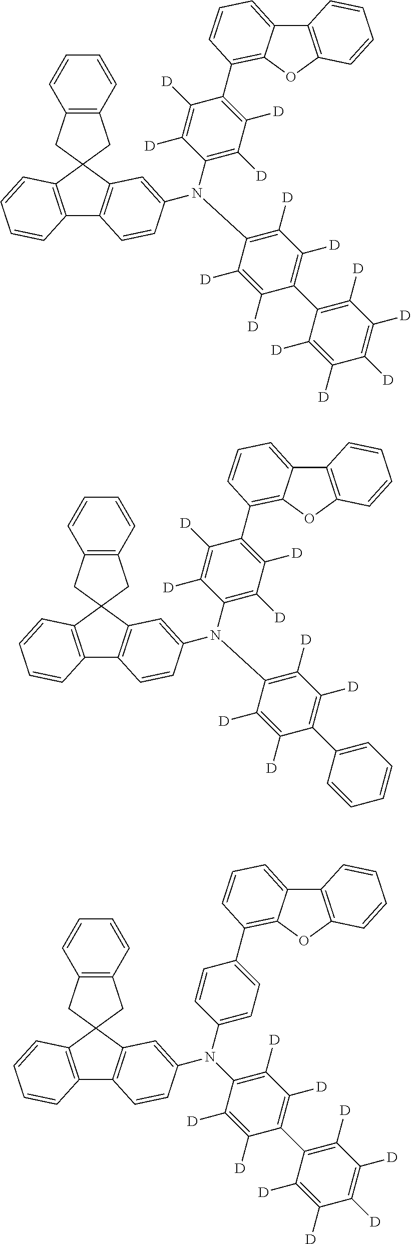 [SMILES: [2H]c1c([2H])c([2H])c(-c2c([2H])c([2H])c(N(c3ccc4c(c3)C3(Cc5ccccc5C3)c3ccccc3-4)c3c([2H])c([2H])c(-c4cccc5c4oc4ccccc45)c([2H])c3[2H])c([2H])c2[2H])c([2H])c1[2H] ; [2H]c1c([2H])c(N(c2ccc3c(c2)C2(Cc4ccccc4C2)c2ccccc2-3)c2c([2H])c([2H])c(-c3cccc4c3oc3ccccc34)c([2H])c2[2H])c([2H])c([2H])c1-c1ccccc1 ; [2H]c1c([2H])c([2H])c(-c2c([2H])c([2H])c(N(c3ccc(-c4cccc5c4oc4ccccc45)cc3)c3ccc4c(c3)C3(Cc5ccccc5C3)c3ccccc3-4)c([2H])c2[2H])c([2H])c1[2H]]

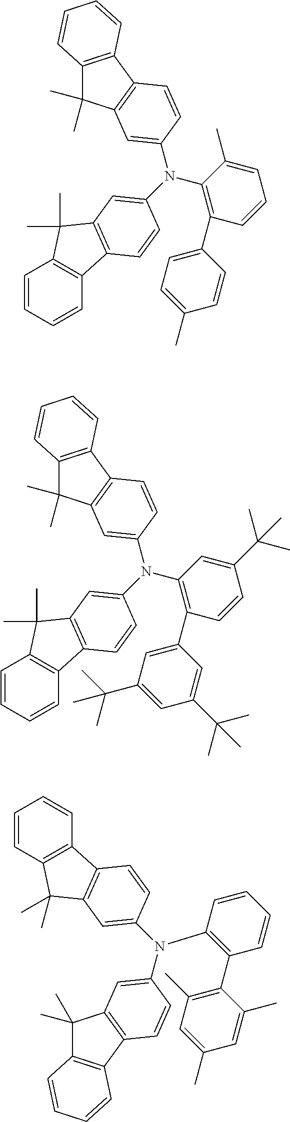 [SMILES: Cc1ccc(-c2cccc(C)c2N(c2ccc3c(c2)C(C)(C)c2ccccc2-3)c2ccc3c(c2)C(C)(C)c2ccccc2-3)cc1 ; CC(C)(C)c1cc(-c2ccc(C(C)(C)C)cc2N(c2ccc3c(c2)C(C)(C)c2ccccc2-3)c2ccc3c(c2)C(C)(C)c2ccccc2-3)cc(C(C)(C)C)c1 ; Cc1cc(C)c(-c2ccccc2N(c2ccc3c(c2)C(C)(C)c2ccccc2-3)c2ccc3c(c2)C(C)(C)c2ccccc2-3)c(C)c1]

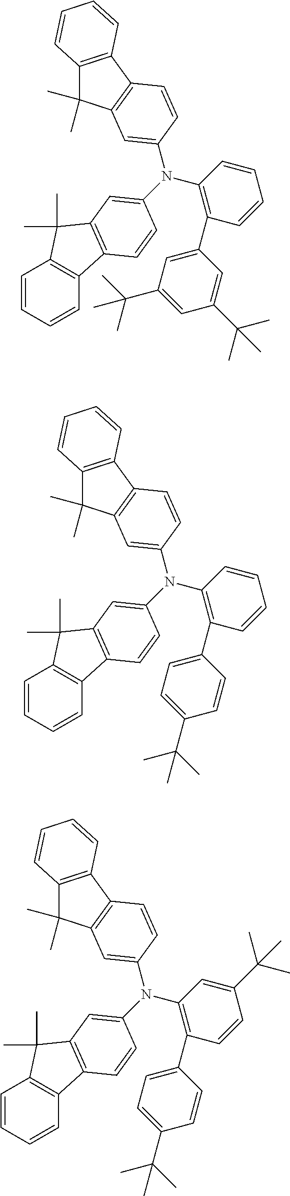 [SMILES: CC(C)(C)c1cc(-c2ccccc2N(c2ccc3c(c2)C(C)(C)c2ccccc2-3)c2ccc3c(c2)C(C)(C)c2ccccc2-3)cc(C(C)(C)C)c1 ; CC(C)(C)c1ccc(-c2ccccc2N(c2ccc3c(c2)C(C)(C)c2ccccc2-3)c2ccc3c(c2)C(C)(C)c2ccccc2-3)cc1 ; CC(C)(C)c1ccc(-c2ccc(C(C)(C)C)cc2N(c2ccc3c(c2)C(C)(C)c2ccccc2-3)c2ccc3c(c2)C(C)(C)c2ccccc2-3)cc1]

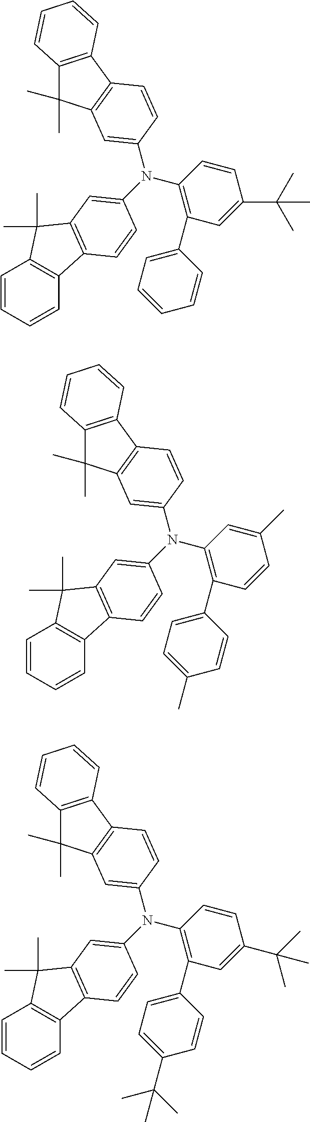 [SMILES: CC(C)(C)c1ccc(N(c2ccc3c(c2)C(C)(C)c2ccccc2-3)c2ccc3c(c2)C(C)(C)c2ccccc2-3)c(-c2ccccc2)c1 ; Cc1ccc(-c2ccc(C)cc2N(c2ccc3c(c2)C(C)(C)c2ccccc2-3)c2ccc3c(c2)C(C)(C)c2ccccc2-3)cc1 ; CC(C)(C)c1ccc(-c2cc(C(C)(C)C)ccc2N(c2ccc3c(c2)C(C)(C)c2ccccc2-3)c2ccc3c(c2)C(C)(C)c2ccccc2-3)cc1]

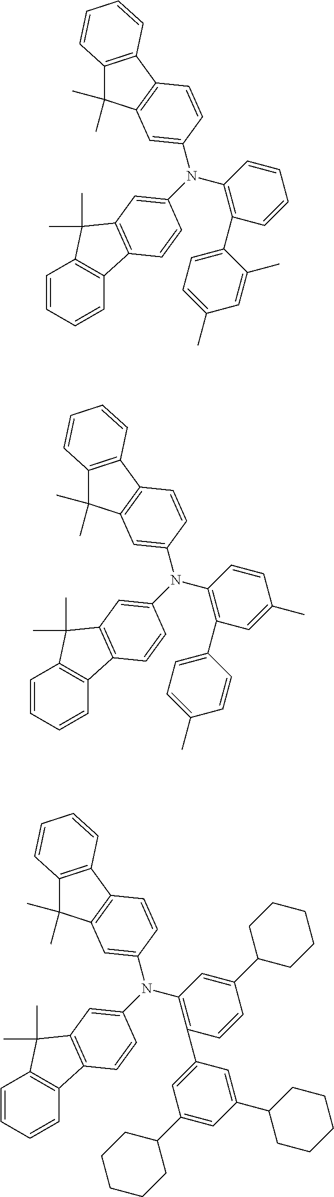 [SMILES: Cc1ccc(-c2ccccc2N(c2ccc3c(c2)C(C)(C)c2ccccc2-3)c2ccc3c(c2)C(C)(C)c2ccccc2-3)c(C)c1 ; Cc1ccc(-c2cc(C)ccc2N(c2ccc3c(c2)C(C)(C)c2ccccc2-3)c2ccc3c(c2)C(C)(C)c2ccccc2-3)cc1 ; CC1(C)c2ccccc2-c2ccc(N(c3ccc4c(c3)C(C)(C)c3ccccc3-4)c3cc(C4CCCCC4)ccc3-c3cc(C4CCCCC4)cc(C4CCCCC4)c3)cc21]

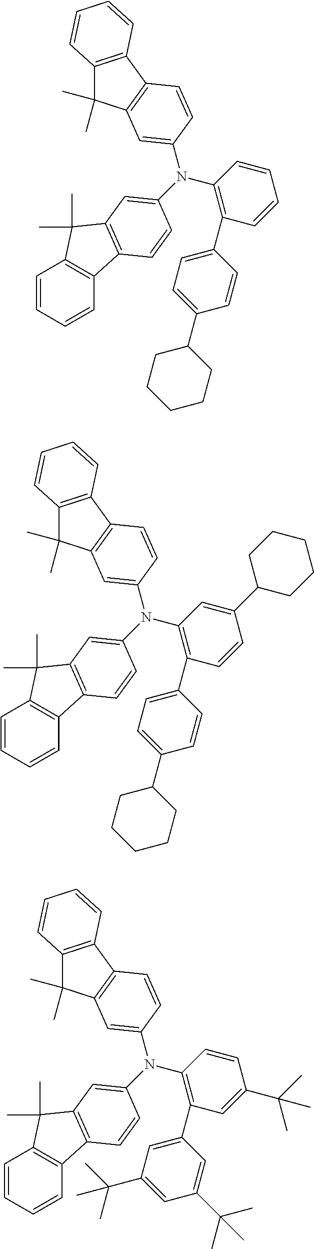 [SMILES: CC1(C)c2ccccc2-c2ccc(N(c3ccc4c(c3)C(C)(C)c3ccccc3-4)c3ccccc3-c3ccc(C4CCCCC4)cc3)cc21 ; CC1(C)c2ccccc2-c2ccc(N(c3ccc4c(c3)C(C)(C)c3ccccc3-4)c3cc(C4CCCCC4)ccc3-c3ccc(C4CCCCC4)cc3)cc21 ; CC(C)(C)c1cc(-c2cc(C(C)(C)C)ccc2N(c2ccc3c(c2)C(C)(C)c2ccccc2-3)c2ccc3c(c2)C(C)(C)c2ccccc2-3)cc(C(C)(C)C)c1]

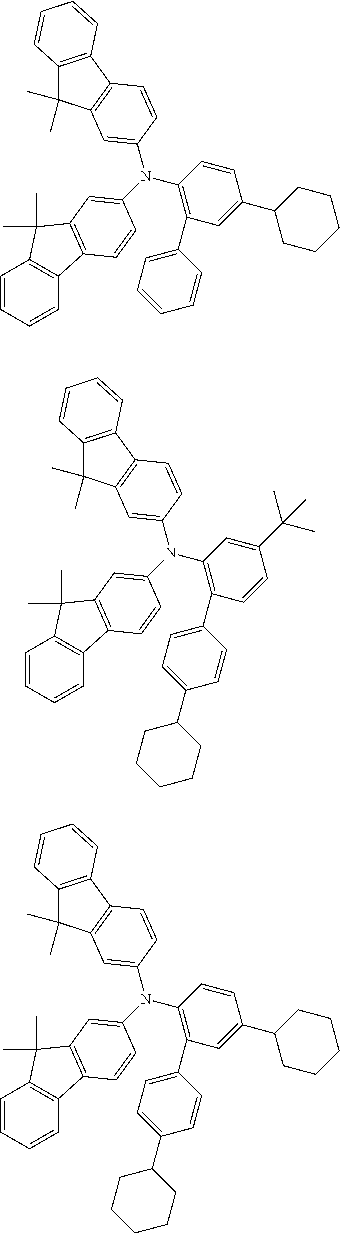 [SMILES: CC1(C)c2ccccc2-c2ccc(N(c3ccc4c(c3)C(C)(C)c3ccccc3-4)c3ccc(C4CCCCC4)cc3-c3ccccc3)cc21 ; CC(C)(C)c1ccc(-c2ccc(C3CCCCC3)cc2)c(N(c2ccc3c(c2)C(C)(C)c2ccccc2-3)c2ccc3c(c2)C(C)(C)c2ccccc2-3)c1 ; CC1(C)c2ccccc2-c2ccc(N(c3ccc4c(c3)C(C)(C)c3ccccc3-4)c3ccc(C4CCCCC4)cc3-c3ccc(C4CCCCC4)cc3)cc21]

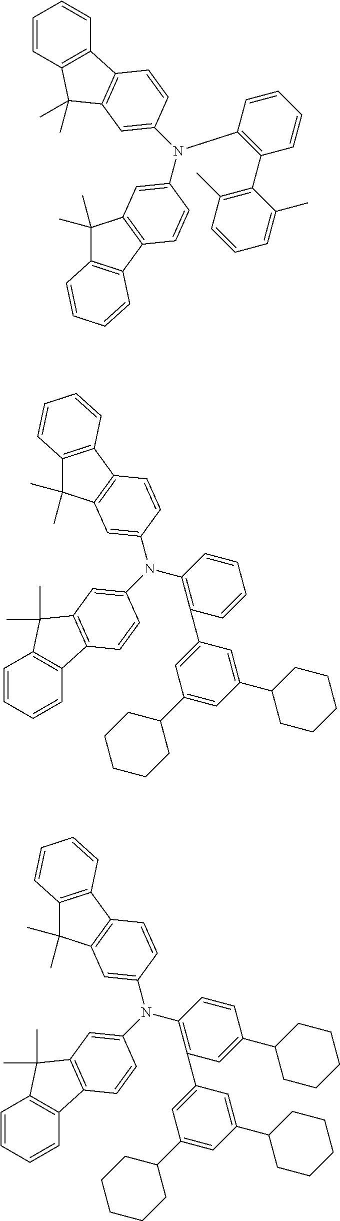 [SMILES: Cc1cccc(C)c1-c1ccccc1N(c1ccc2c(c1)C(C)(C)c1ccccc1-2)c1ccc2c(c1)C(C)(C)c1ccccc1-2 ; CC1(C)c2ccccc2-c2ccc(N(c3ccc4c(c3)C(C)(C)c3ccccc3-4)c3ccccc3-c3cc(C4CCCCC4)cc(C4CCCCC4)c3)cc21 ; CC1(C)c2ccccc2-c2ccc(N(c3ccc4c(c3)C(C)(C)c3ccccc3-4)c3ccc(C4CCCCC4)cc3-c3cc(C4CCCCC4)cc(C4CCCCC4)c3)cc21]

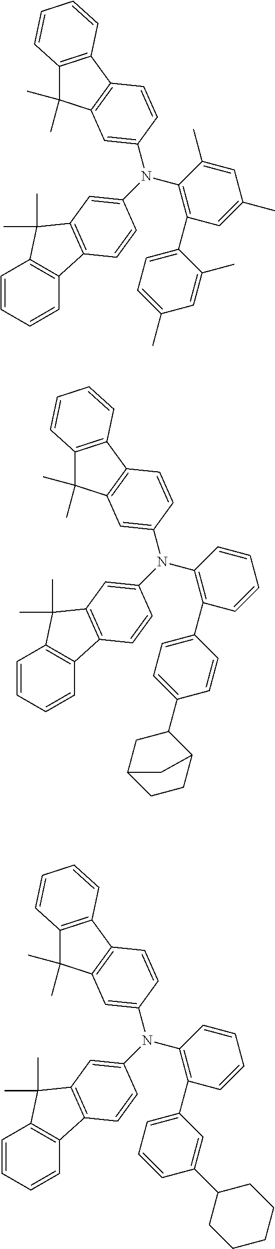 [SMILES: Cc1ccc(-c2cc(C)cc(C)c2N(c2ccc3c(c2)C(C)(C)c2ccccc2-3)c2ccc3c(c2)C(C)(C)c2ccccc2-3)c(C)c1 ; CC1(C)c2ccccc2-c2ccc(N(c3ccc4c(c3)C(C)(C)c3ccccc3-4)c3ccccc3-c3ccc(C4CC5CCC4C5)cc3)cc21 ; CC1(C)c2ccccc2-c2ccc(N(c3ccc4c(c3)C(C)(C)c3ccccc3-4)c3ccccc3-c3cccc(C4CCCCC4)c3)cc21]

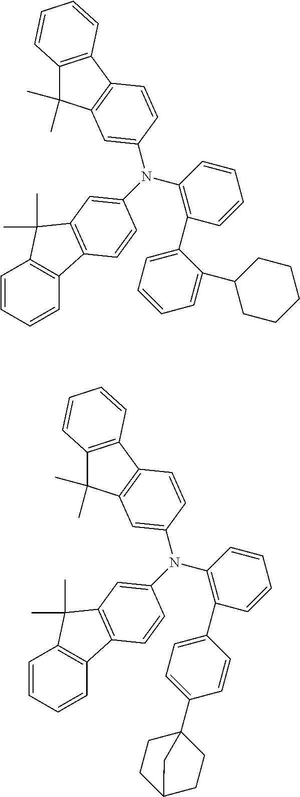 [SMILES: CC1(C)c2ccccc2-c2ccc(N(c3ccc4c(c3)C(C)(C)c3ccccc3-4)c3ccccc3-c3ccccc3C3CCCCC3)cc21 ; CC1(C)c2ccccc2-c2ccc(N(c3ccc4c(c3)C(C)(C)c3ccccc3-4)c3ccccc3-c3ccc(C45CCC(CC4)C5)cc3)cc21]

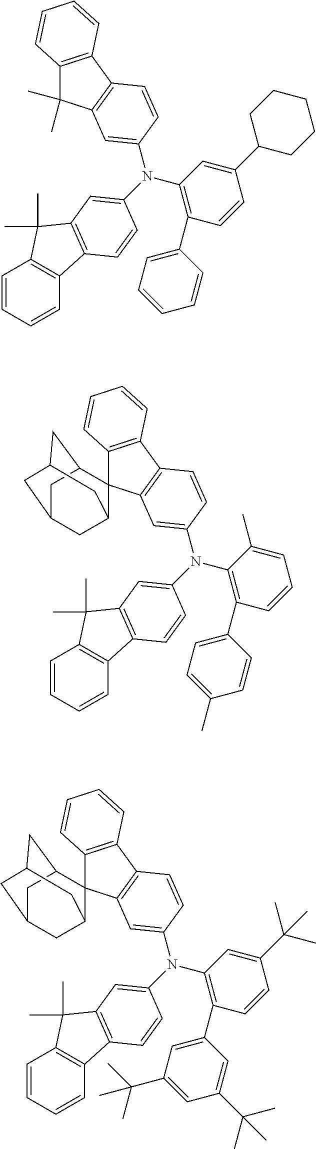 [SMILES: CC1(C)c2ccccc2-c2ccc(N(c3ccc4c(c3)C(C)(C)c3ccccc3-4)c3cc(C4CCCCC4)ccc3-c3ccccc3)cc21 ; Cc1ccc(-c2cccc(C)c2N(c2ccc3c(c2)C(C)(C)c2ccccc2-3)c2ccc3c(c2)C2(c4ccccc4-3)C3CC4CC(C3)CC2C4)cc1 ; CC(C)(C)c1cc(-c2ccc(C(C)(C)C)cc2N(c2ccc3c(c2)C(C)(C)c2ccccc2-3)c2ccc3c(c2)C2(c4ccccc4-3)C3CC4CC(C3)CC2C4)cc(C(C)(C)C)c1]

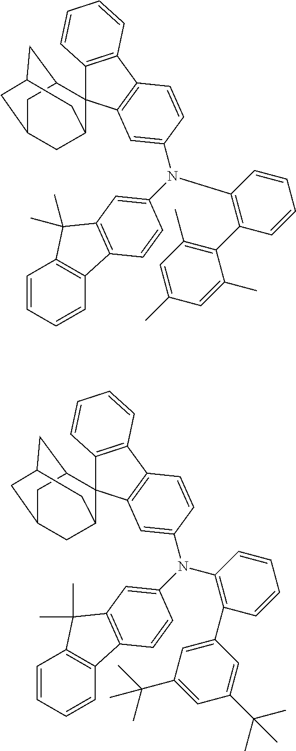 [SMILES: Cc1cc(C)c(-c2ccccc2N(c2ccc3c(c2)C(C)(C)c2ccccc2-3)c2ccc3c(c2)C2(c4ccccc4-3)C3CC4CC(C3)CC2C4)c(C)c1 ; CC(C)(C)c1cc(-c2ccccc2N(c2ccc3c(c2)C(C)(C)c2ccccc2-3)c2ccc3c(c2)C2(c4ccccc4-3)C3CC4CC(C3)CC2C4)cc(C(C)(C)C)c1]

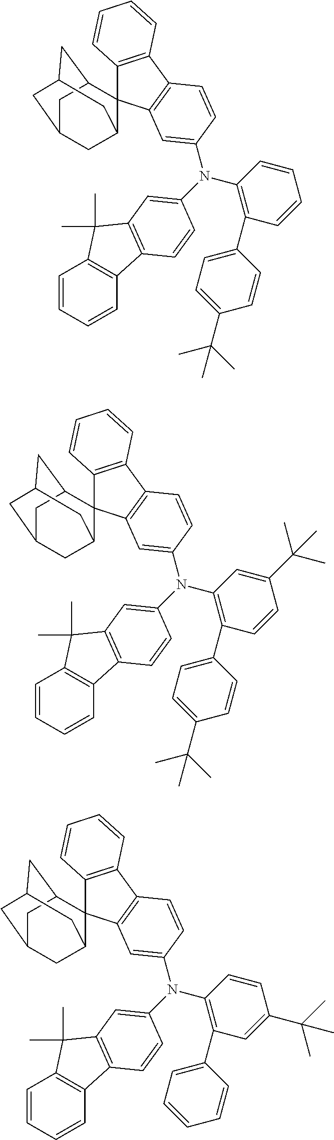 [SMILES: CC(C)(C)c1ccc(-c2ccccc2N(c2ccc3c(c2)C(C)(C)c2ccccc2-3)c2ccc3c(c2)C2(c4ccccc4-3)C3CC4CC(C3)CC2C4)cc1 ; CC(C)(C)c1ccc(-c2ccc(C(C)(C)C)cc2N(c2ccc3c(c2)C(C)(C)c2ccccc2-3)c2ccc3c(c2)C2(c4ccccc4-3)C3CC4CC(C3)CC2C4)cc1 ; CC(C)(C)c1ccc(N(c2ccc3c(c2)C(C)(C)c2ccccc2-3)c2ccc3c(c2)C2(c4ccccc4-3)C3CC4CC(C3)CC2C4)c(-c2ccccc2)c1]

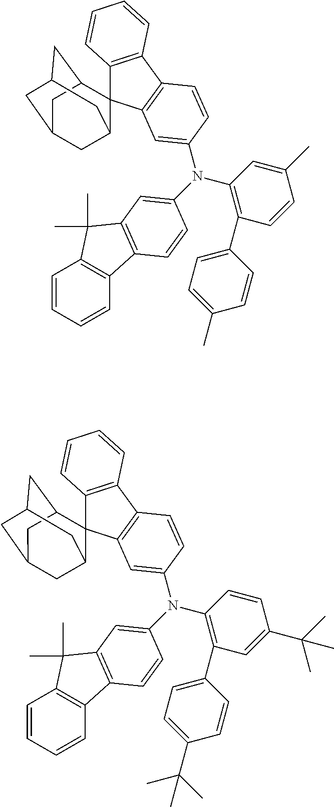 [SMILES: Cc1ccc(-c2ccc(C)cc2N(c2ccc3c(c2)C(C)(C)c2ccccc2-3)c2ccc3c(c2)C2(c4ccccc4-3)C3CC4CC(C3)CC2C4)cc1 ; CC(C)(C)c1ccc(-c2cc(C(C)(C)C)ccc2N(c2ccc3c(c2)C(C)(C)c2ccccc2-3)c2ccc3c(c2)C2(c4ccccc4-3)C3CC4CC(C3)CC2C4)cc1]

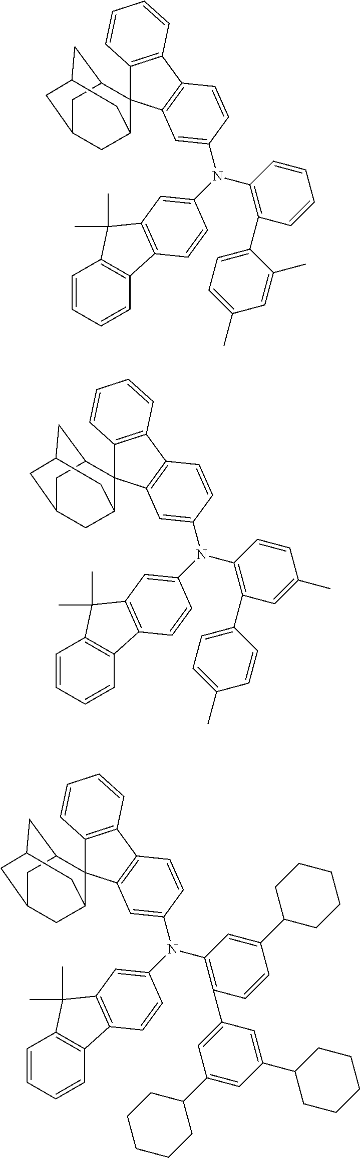 [SMILES: Cc1ccc(-c2ccccc2N(c2ccc3c(c2)C(C)(C)c2ccccc2-3)c2ccc3c(c2)C2(c4ccccc4-3)C3CC4CC(C3)CC2C4)c(C)c1 ; Cc1ccc(-c2cc(C)ccc2N(c2ccc3c(c2)C(C)(C)c2ccccc2-3)c2ccc3c(c2)C2(c4ccccc4-3)C3CC4CC(C3)CC2C4)cc1 ; CC1(C)c2ccccc2-c2ccc(N(c3ccc4c(c3)C3(c5ccccc5-4)C4CC5CC(C4)CC3C5)c3cc(C4CCCCC4)ccc3-c3cc(C4CCCCC4)cc(C4CCCCC4)c3)cc21]

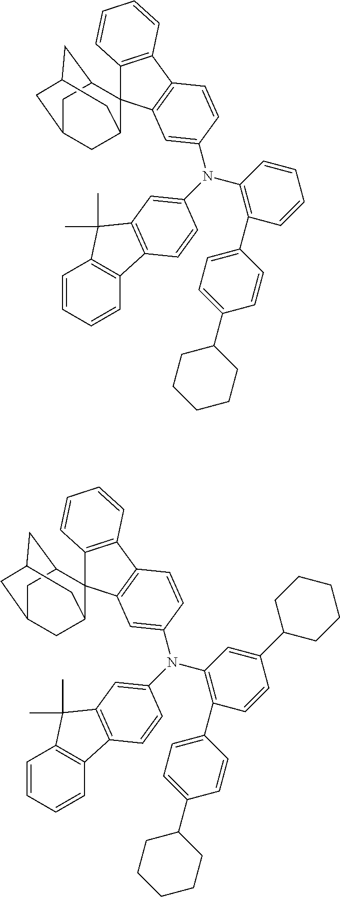 [SMILES: CC1(C)c2ccccc2-c2ccc(N(c3ccc4c(c3)C3(c5ccccc5-4)C4CC5CC(C4)CC3C5)c3ccccc3-c3ccc(C4CCCCC4)cc3)cc21 ; CC1(C)c2ccccc2-c2ccc(N(c3ccc4c(c3)C3(c5ccccc5-4)C4CC5CC(C4)CC3C5)c3cc(C4CCCCC4)ccc3-c3ccc(C4CCCCC4)cc3)cc21]

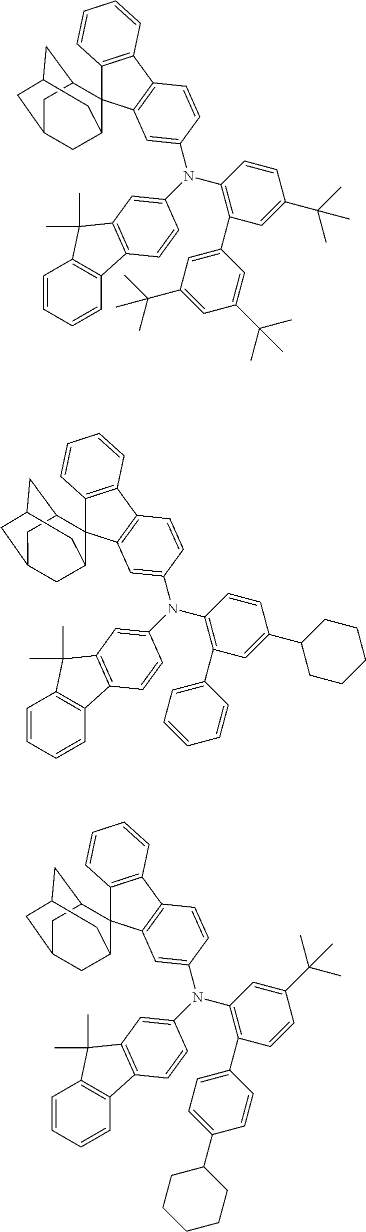 [SMILES: CC(C)(C)c1cc(-c2cc(C(C)(C)C)ccc2N(c2ccc3c(c2)C(C)(C)c2ccccc2-3)c2ccc3c(c2)C2(c4ccccc4-3)C3CC4CC(C3)CC2C4)cc(C(C)(C)C)c1 ; CC1(C)c2ccccc2-c2ccc(N(c3ccc4c(c3)C3(c5ccccc5-4)C4CC5CC(C4)CC3C5)c3ccc(C4CCCCC4)cc3-c3ccccc3)cc21 ; CC(C)(C)c1ccc(-c2ccc(C3CCCCC3)cc2)c(N(c2ccc3c(c2)C(C)(C)c2ccccc2-3)c2ccc3c(c2)C2(c4ccccc4-3)C3CC4CC(C3)CC2C4)c1]

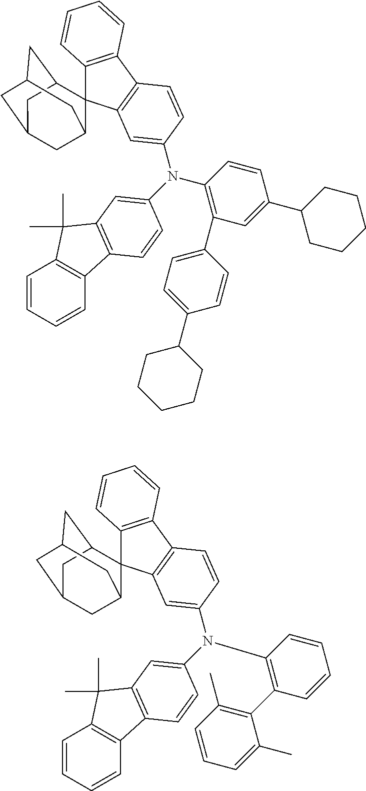 [SMILES: CC1(C)c2ccccc2-c2ccc(N(c3ccc4c(c3)C3(c5ccccc5-4)C4CC5CC(C4)CC3C5)c3ccc(C4CCCCC4)cc3-c3ccc(C4CCCCC4)cc3)cc21 ; Cc1cccc(C)c1-c1ccccc1N(c1ccc2c(c1)C(C)(C)c1ccccc1-2)c1ccc2c(c1)C1(c3ccccc3-2)C2CC3CC(C2)CC1C3]

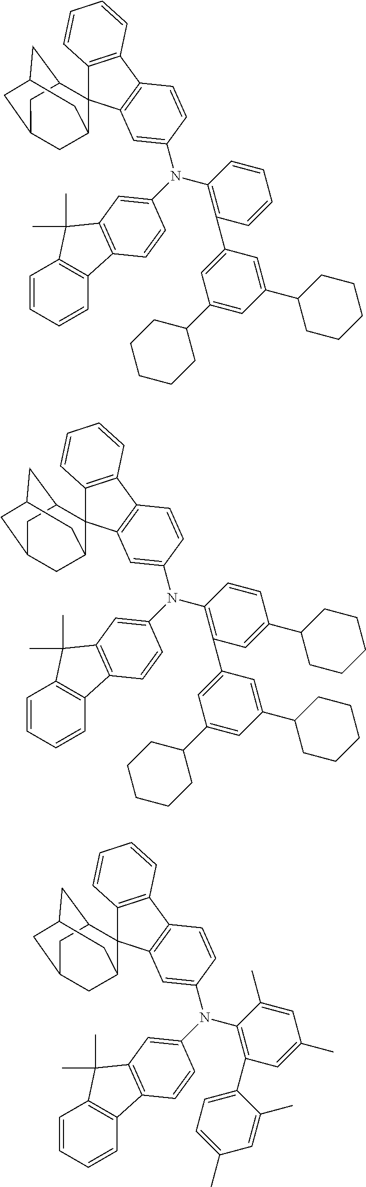

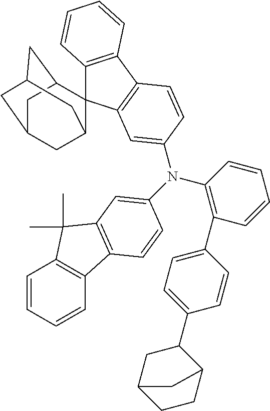 [SMILES: CC1(C)c2ccccc2-c2ccc(N(c3ccc4c(c3)C3(c5ccccc5-4)C4CC5CC(C4)CC3C5)c3ccccc3-c3ccc(C4CC5CCC4C5)cc3)cc21]

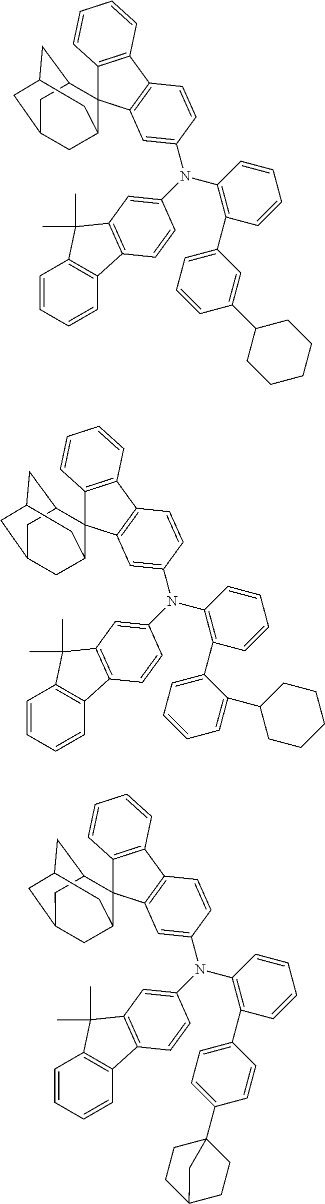 [SMILES: CC1(C)c2ccccc2-c2ccc(N(c3ccc4c(c3)C3(c5ccccc5-4)C4CC5CC(C4)CC3C5)c3ccccc3-c3cccc(C4CCCCC4)c3)cc21 ; CC1(C)c2ccccc2-c2ccc(N(c3ccc4c(c3)C3(c5ccccc5-4)C4CC5CC(C4)CC3C5)c3ccccc3-c3ccccc3C3CCCCC3)cc21 ; CC1(C)c2ccccc2-c2ccc(N(c3ccc4c(c3)C3(c5ccccc5-4)C4CC5CC(C4)CC3C5)c3ccccc3-c3ccc(C45CCC(CC4)C5)cc3)cc21]

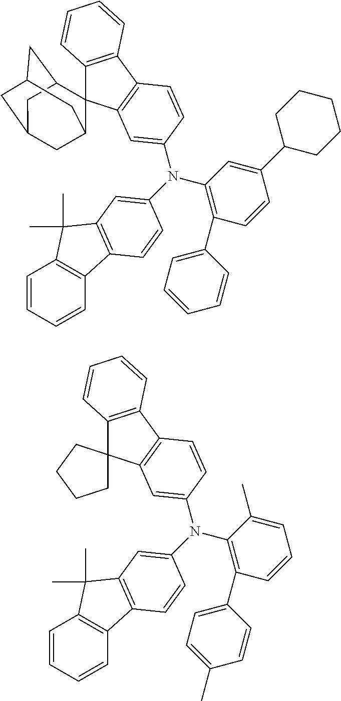 [SMILES: CC1(C)c2ccccc2-c2ccc(N(c3ccc4c(c3)C3(c5ccccc5-4)C4CC5CC(C4)CC3C5)c3cc(C4CCCCC4)ccc3-c3ccccc3)cc21 ; Cc1ccc(-c2cccc(C)c2N(c2ccc3c(c2)C(C)(C)c2ccccc2-3)c2ccc3c(c2)C2(CCCC2)c2ccccc2-3)cc1]

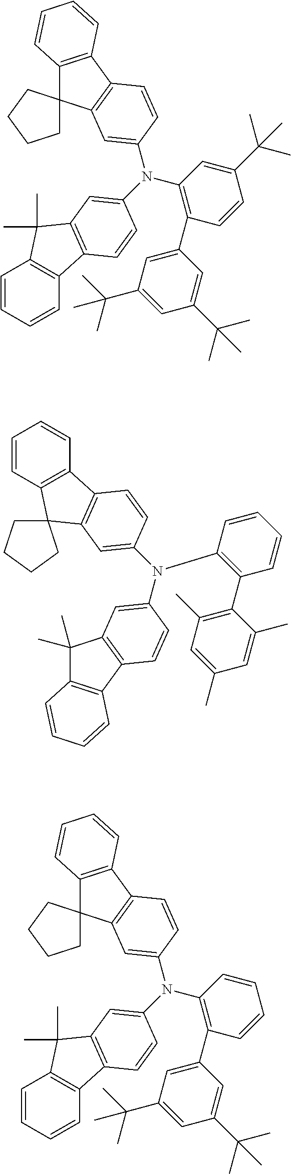 [SMILES: CC(C)(C)c1cc(-c2ccc(C(C)(C)C)cc2N(c2ccc3c(c2)C(C)(C)c2ccccc2-3)c2ccc3c(c2)C2(CCCC2)c2ccccc2-3)cc(C(C)(C)C)c1 ; Cc1cc(C)c(-c2ccccc2N(c2ccc3c(c2)C(C)(C)c2ccccc2-3)c2ccc3c(c2)C2(CCCC2)c2ccccc2-3)c(C)c1 ; CC(C)(C)c1cc(-c2ccccc2N(c2ccc3c(c2)C(C)(C)c2ccccc2-3)c2ccc3c(c2)C2(CCCC2)c2ccccc2-3)cc(C(C)(C)C)c1]

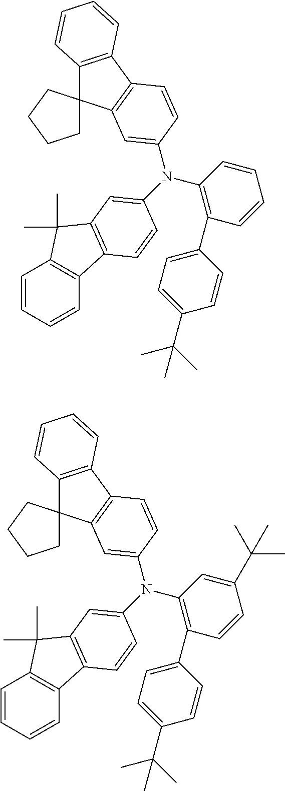 [SMILES: CC(C)(C)c1ccc(-c2ccccc2N(c2ccc3c(c2)C(C)(C)c2ccccc2-3)c2ccc3c(c2)C2(CCCC2)c2ccccc2-3)cc1 ; CC(C)(C)c1ccc(-c2ccc(C(C)(C)C)cc2N(c2ccc3c(c2)C(C)(C)c2ccccc2-3)c2ccc3c(c2)C2(CCCC2)c2ccccc2-3)cc1]

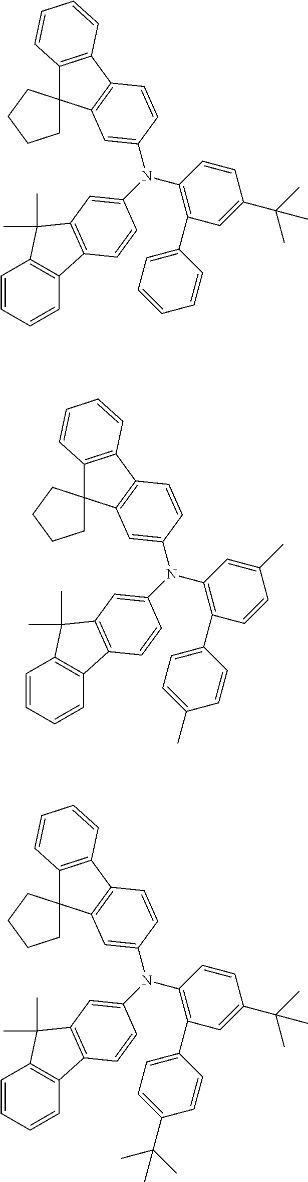 [SMILES: CC(C)(C)c1ccc(N(c2ccc3c(c2)C(C)(C)c2ccccc2-3)c2ccc3c(c2)C2(CCCC2)c2ccccc2-3)c(-c2ccccc2)c1 ; Cc1ccc(-c2ccc(C)cc2N(c2ccc3c(c2)C(C)(C)c2ccccc2-3)c2ccc3c(c2)C2(CCCC2)c2ccccc2-3)cc1 ; CC(C)(C)c1ccc(-c2cc(C(C)(C)C)ccc2N(c2ccc3c(c2)C(C)(C)c2ccccc2-3)c2ccc3c(c2)C2(CCCC2)c2ccccc2-3)cc1]

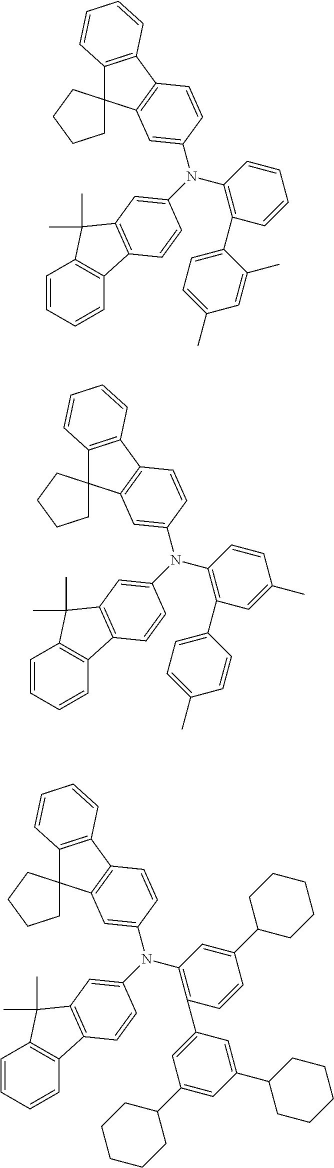 [SMILES: Cc1ccc(-c2ccccc2N(c2ccc3c(c2)C(C)(C)c2ccccc2-3)c2ccc3c(c2)C2(CCCC2)c2ccccc2-3)c(C)c1 ; Cc1ccc(-c2cc(C)ccc2N(c2ccc3c(c2)C(C)(C)c2ccccc2-3)c2ccc3c(c2)C2(CCCC2)c2ccccc2-3)cc1 ; CC1(C)c2ccccc2-c2ccc(N(c3ccc4c(c3)C3(CCCC3)c3ccccc3-4)c3cc(C4CCCCC4)ccc3-c3cc(C4CCCCC4)cc(C4CCCCC4)c3)cc21]

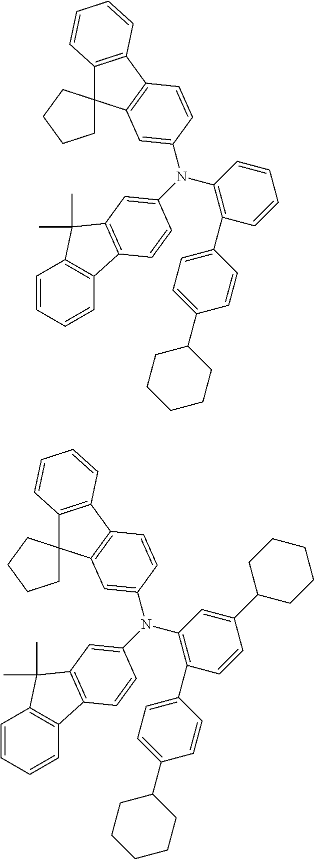 [SMILES: CC1(C)c2ccccc2-c2ccc(N(c3ccc4c(c3)C3(CCCC3)c3ccccc3-4)c3ccccc3-c3ccc(C4CCCCC4)cc3)cc21 ; CC1(C)c2ccccc2-c2ccc(N(c3ccc4c(c3)C3(CCCC3)c3ccccc3-4)c3cc(C4CCCCC4)ccc3-c3ccc(C4CCCCC4)cc3)cc21]

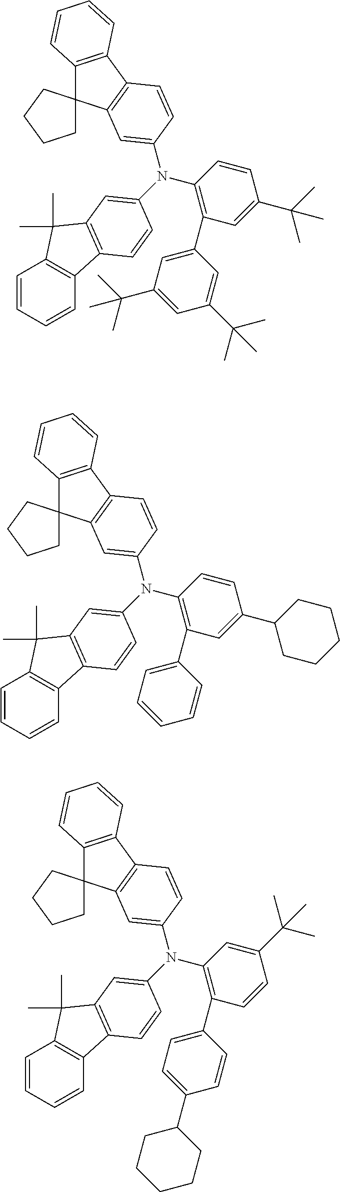 [SMILES: CC(C)(C)c1cc(-c2cc(C(C)(C)C)ccc2N(c2ccc3c(c2)C(C)(C)c2ccccc2-3)c2ccc3c(c2)C2(CCCC2)c2ccccc2-3)cc(C(C)(C)C)c1 ; CC1(C)c2ccccc2-c2ccc(N(c3ccc4c(c3)C3(CCCC3)c3ccccc3-4)c3ccc(C4CCCCC4)cc3-c3ccccc3)cc21 ; CC(C)(C)c1ccc(-c2ccc(C3CCCCC3)cc2)c(N(c2ccc3c(c2)C(C)(C)c2ccccc2-3)c2ccc3c(c2)C2(CCCC2)c2ccccc2-3)c1]

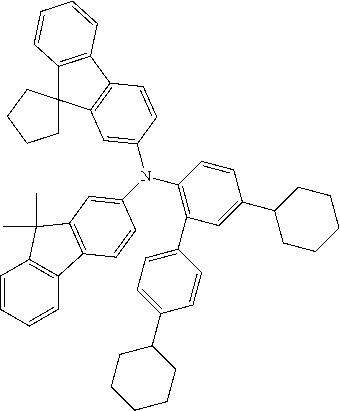 [SMILES: CC1(C)c2ccccc2-c2ccc(N(c3ccc4c(c3)C3(CCCC3)c3ccccc3-4)c3ccc(C4CCCCC4)cc3-c3ccc(C4CCCCC4)cc3)cc21]

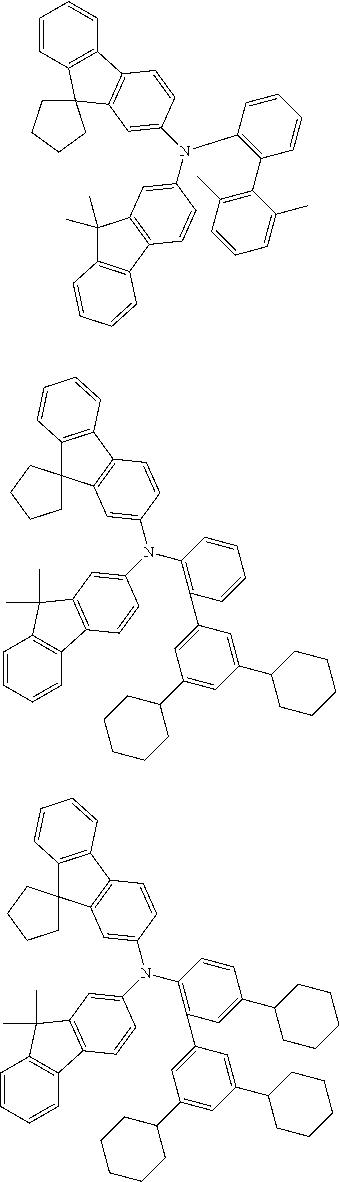 [SMILES: Cc1cccc(C)c1-c1ccccc1N(c1ccc2c(c1)C(C)(C)c1ccccc1-2)c1ccc2c(c1)C1(CCCC1)c1ccccc1-2 ; CC1(C)c2ccccc2-c2ccc(N(c3ccc4c(c3)C3(CCCC3)c3ccccc3-4)c3ccccc3-c3cc(C4CCCCC4)cc(C4CCCCC4)c3)cc21 ; CC1(C)c2ccccc2-c2ccc(N(c3ccc4c(c3)C3(CCCC3)c3ccccc3-4)c3ccc(C4CCCCC4)cc3-c3cc(C4CCCCC4)cc(C4CCCCC4)c3)cc21]

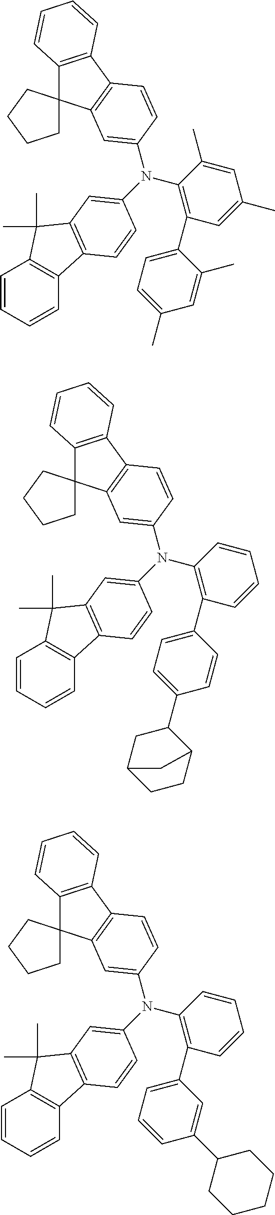 [SMILES: Cc1ccc(-c2cc(C)cc(C)c2N(c2ccc3c(c2)C(C)(C)c2ccccc2-3)c2ccc3c(c2)C2(CCCC2)c2ccccc2-3)c(C)c1 ; CC1(C)c2ccccc2-c2ccc(N(c3ccc4c(c3)C3(CCCC3)c3ccccc3-4)c3ccccc3-c3ccc(C4CC5CCC4C5)cc3)cc21 ; CC1(C)c2ccccc2-c2ccc(N(c3ccc4c(c3)C3(CCCC3)c3ccccc3-4)c3ccccc3-c3cccc(C4CCCCC4)c3)cc21]

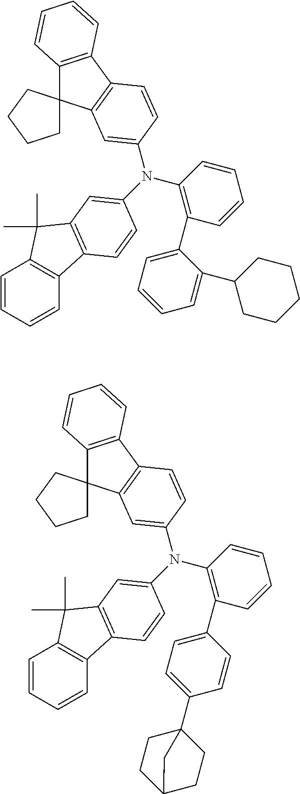 [SMILES: CC1(C)c2ccccc2-c2ccc(N(c3ccc4c(c3)C3(CCCC3)c3ccccc3-4)c3ccccc3-c3ccccc3C3CCCCC3)cc21 ; CC1(C)c2ccccc2-c2ccc(N(c3ccc4c(c3)C3(CCCC3)c3ccccc3-4)c3ccccc3-c3ccc(C45CCC(CC4)C5)cc3)cc21]

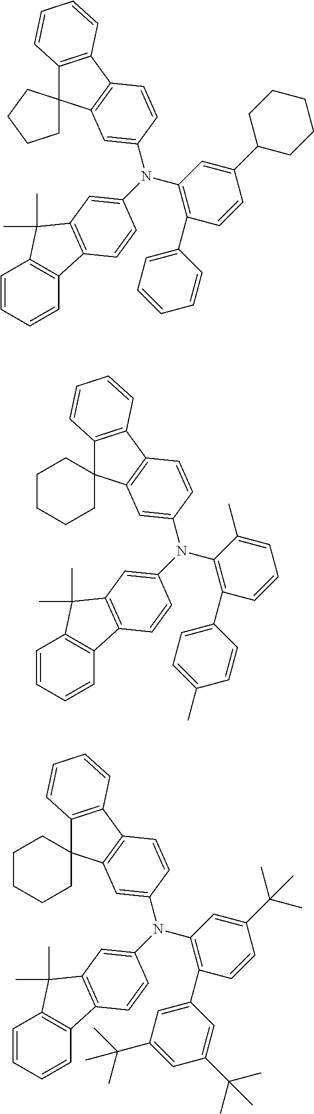 [SMILES: CC1(C)c2ccccc2-c2ccc(N(c3ccc4c(c3)C3(CCCC3)c3ccccc3-4)c3cc(C4CCCCC4)ccc3-c3ccccc3)cc21 ; Cc1ccc(-c2cccc(C)c2N(c2ccc3c(c2)C(C)(C)c2ccccc2-3)c2ccc3c(c2)C2(CCCCC2)c2ccccc2-3)cc1 ; CC(C)(C)c1cc(-c2ccc(C(C)(C)C)cc2N(c2ccc3c(c2)C(C)(C)c2ccccc2-3)c2ccc3c(c2)C2(CCCCC2)c2ccccc2-3)cc(C(C)(C)C)c1]

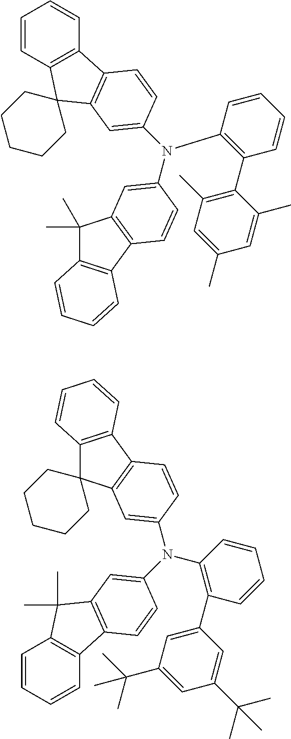 [SMILES: Cc1cc(C)c(-c2ccccc2N(c2ccc3c(c2)C(C)(C)c2ccccc2-3)c2ccc3c(c2)C2(CCCCC2)c2ccccc2-3)c(C)c1 ; CC(C)(C)c1cc(-c2ccccc2N(c2ccc3c(c2)C(C)(C)c2ccccc2-3)c2ccc3c(c2)C2(CCCCC2)c2ccccc2-3)cc(C(C)(C)C)c1]

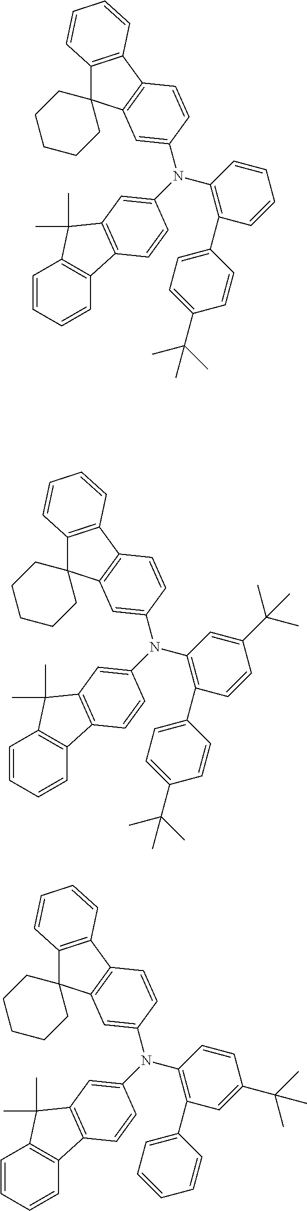 [SMILES: CC(C)(C)c1ccc(-c2ccccc2N(c2ccc3c(c2)C(C)(C)c2ccccc2-3)c2ccc3c(c2)C2(CCCCC2)c2ccccc2-3)cc1 ; CC(C)(C)c1ccc(-c2ccc(C(C)(C)C)cc2N(c2ccc3c(c2)C(C)(C)c2ccccc2-3)c2ccc3c(c2)C2(CCCCC2)c2ccccc2-3)cc1 ; CC(C)(C)c1ccc(N(c2ccc3c(c2)C(C)(C)c2ccccc2-3)c2ccc3c(c2)C2(CCCCC2)c2ccccc2-3)c(-c2ccccc2)c1]

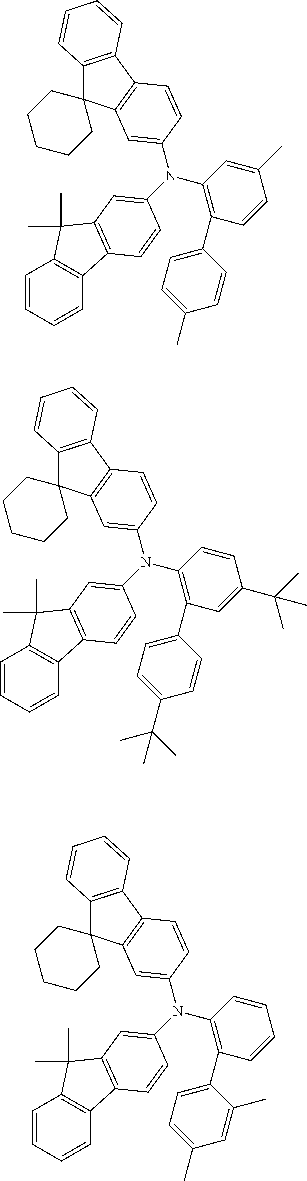 [SMILES: Cc1ccc(-c2ccc(C)cc2N(c2ccc3c(c2)C(C)(C)c2ccccc2-3)c2ccc3c(c2)C2(CCCCC2)c2ccccc2-3)cc1 ; CC(C)(C)c1ccc(-c2cc(C(C)(C)C)ccc2N(c2ccc3c(c2)C(C)(C)c2ccccc2-3)c2ccc3c(c2)C2(CCCCC2)c2ccccc2-3)cc1 ; Cc1ccc(-c2ccccc2N(c2ccc3c(c2)C(C)(C)c2ccccc2-3)c2ccc3c(c2)C2(CCCCC2)c2ccccc2-3)c(C)c1]

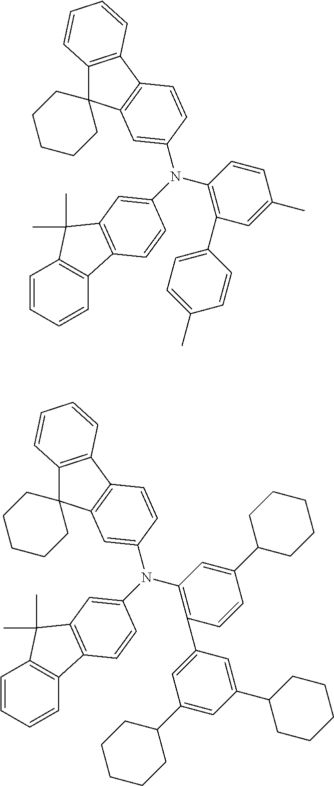 [SMILES: Cc1ccc(-c2cc(C)ccc2N(c2ccc3c(c2)C(C)(C)c2ccccc2-3)c2ccc3c(c2)C2(CCCCC2)c2ccccc2-3)cc1 ; CC1(C)c2ccccc2-c2ccc(N(c3ccc4c(c3)C3(CCCCC3)c3ccccc3-4)c3cc(C4CCCCC4)ccc3-c3cc(C4CCCCC4)cc(C4CCCCC4)c3)cc21]

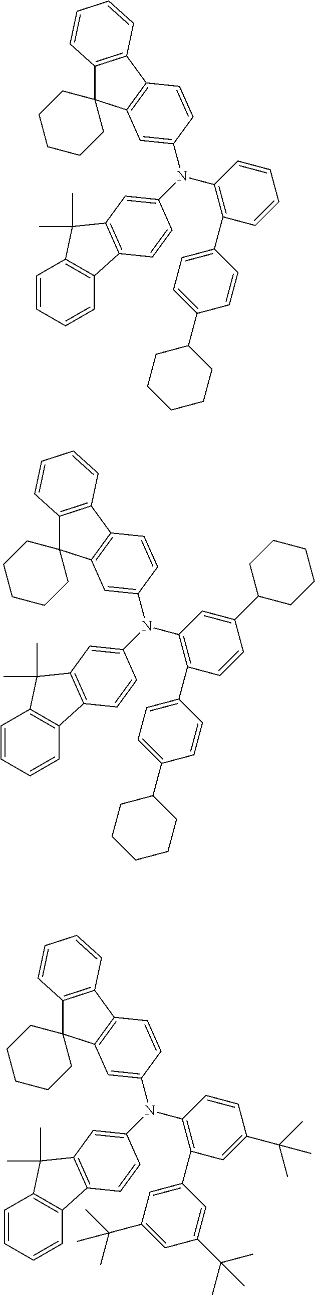 [SMILES: CC1(C)c2ccccc2-c2ccc(N(c3ccc4c(c3)C3(CCCCC3)c3ccccc3-4)c3ccccc3-c3ccc(C4CCCCC4)cc3)cc21 ; CC1(C)c2ccccc2-c2ccc(N(c3ccc4c(c3)C3(CCCCC3)c3ccccc3-4)c3cc(C4CCCCC4)ccc3-c3ccc(C4CCCCC4)cc3)cc21 ; CC(C)(C)c1cc(-c2cc(C(C)(C)C)ccc2N(c2ccc3c(c2)C(C)(C)c2ccccc2-3)c2ccc3c(c2)C2(CCCCC2)c2ccccc2-3)cc(C(C)(C)C)c1]

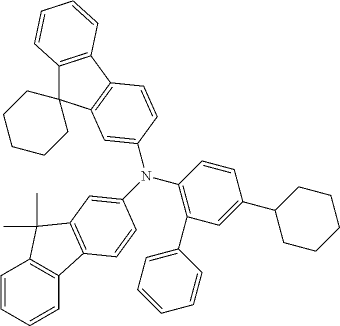 [SMILES: CC1(C)c2ccccc2-c2ccc(N(c3ccc4c(c3)C3(CCCCC3)c3ccccc3-4)c3ccc(C4CCCCC4)cc3-c3ccccc3)cc21]

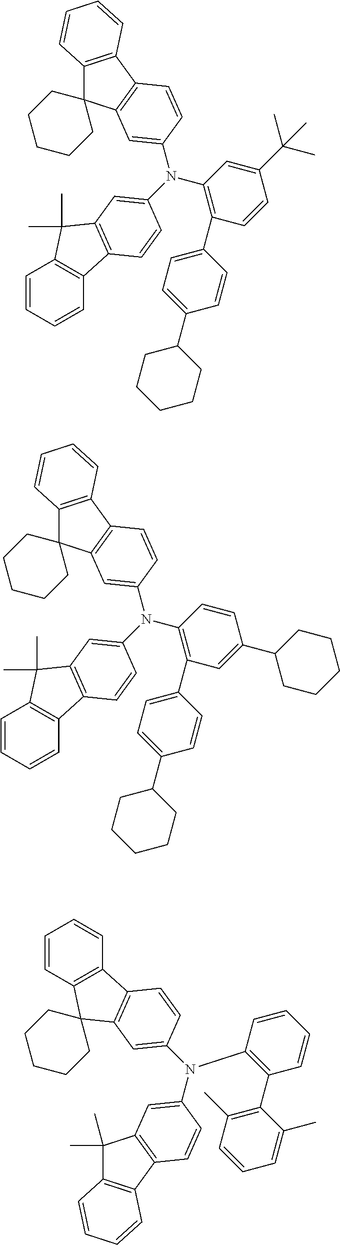 [SMILES: CC(C)(C)c1ccc(-c2ccc(C3CCCCC3)cc2)c(N(c2ccc3c(c2)C(C)(C)c2ccccc2-3)c2ccc3c(c2)C2(CCCCC2)c2ccccc2-3)c1 ; CC1(C)c2ccccc2-c2ccc(N(c3ccc4c(c3)C3(CCCCC3)c3ccccc3-4)c3ccc(C4CCCCC4)cc3-c3ccc(C4CCCCC4)cc3)cc21 ; Cc1cccc(C)c1-c1ccccc1N(c1ccc2c(c1)C(C)(C)c1ccccc1-2)c1ccc2c(c1)C1(CCCCC1)c1ccccc1-2]

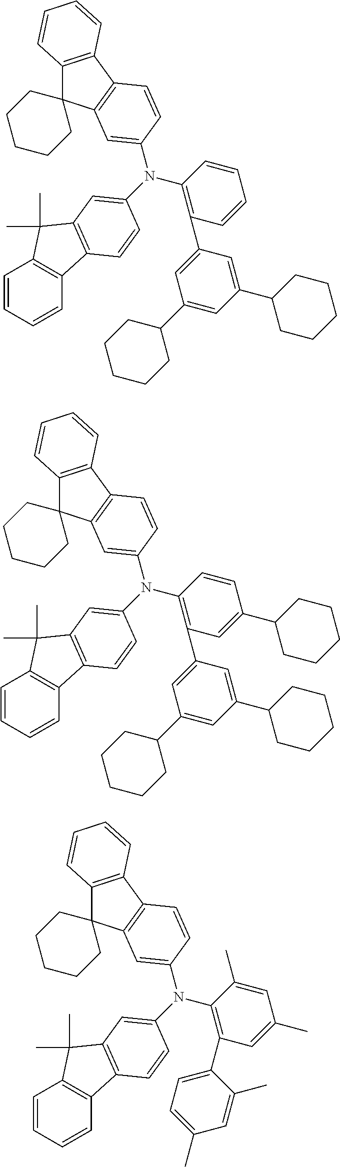

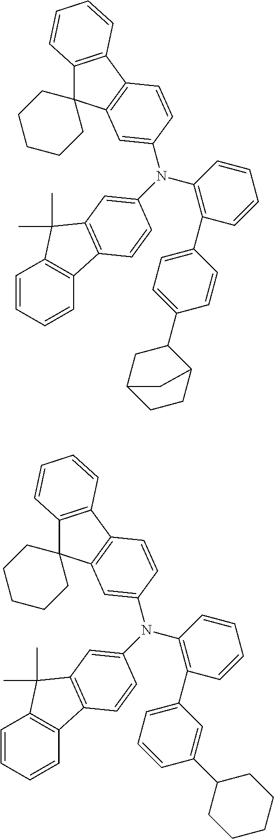 [SMILES: CC1(C)c2ccccc2-c2ccc(N(c3ccc4c(c3)C3(CCCCC3)c3ccccc3-4)c3ccccc3-c3ccc(C4CC5CCC4C5)cc3)cc21 ; CC1(C)c2ccccc2-c2ccc(N(c3ccc4c(c3)C3(CCCCC3)c3ccccc3-4)c3ccccc3-c3cccc(C4CCCCC4)c3)cc21]

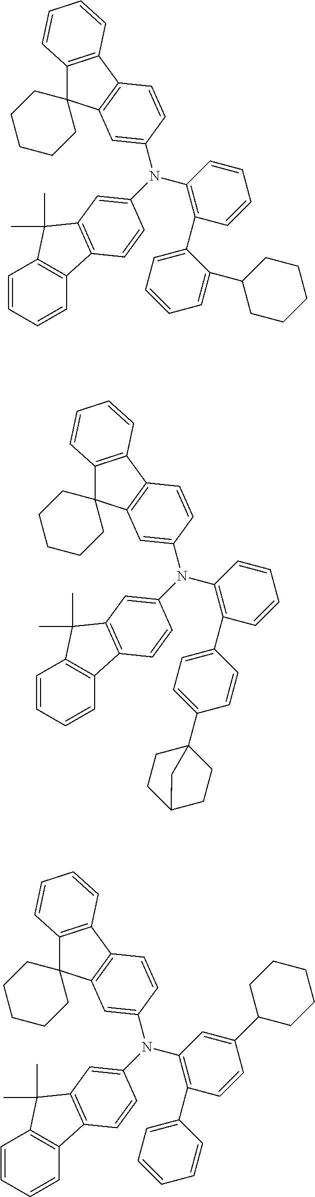 [SMILES: CC1(C)c2ccccc2-c2ccc(N(c3ccc4c(c3)C3(CCCCC3)c3ccccc3-4)c3ccccc3-c3ccccc3C3CCCCC3)cc21 ; CC1(C)c2ccccc2-c2ccc(N(c3ccc4c(c3)C3(CCCCC3)c3ccccc3-4)c3ccccc3-c3ccc(C45CCC(CC4)C5)cc3)cc21 ; CC1(C)c2ccccc2-c2ccc(N(c3ccc4c(c3)C3(CCCCC3)c3ccccc3-4)c3cc(C4CCCCC4)ccc3-c3ccccc3)cc21]

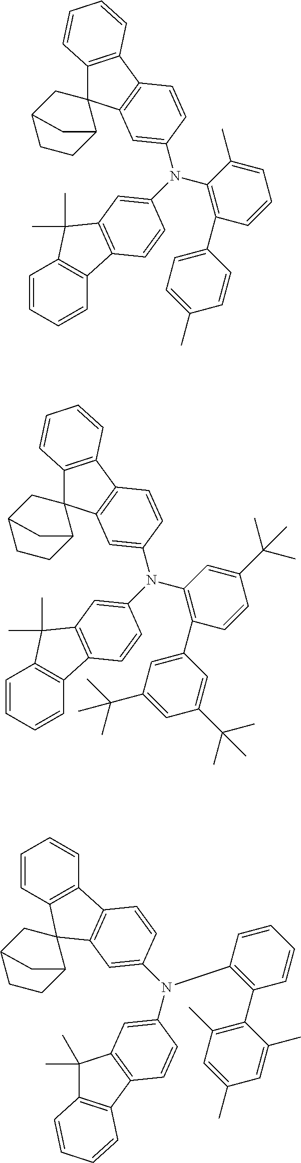 [SMILES: Cc1ccc(-c2cccc(C)c2N(c2ccc3c(c2)C(C)(C)c2ccccc2-3)c2ccc3c(c2)C2(CC4CCC2C4)c2ccccc2-3)cc1 ; CC(C)(C)c1cc(-c2ccc(C(C)(C)C)cc2N(c2ccc3c(c2)C(C)(C)c2ccccc2-3)c2ccc3c(c2)C2(CC4CCC2C4)c2ccccc2-3)cc(C(C)(C)C)c1 ; Cc1cc(C)c(-c2ccccc2N(c2ccc3c(c2)C(C)(C)c2ccccc2-3)c2ccc3c(c2)C2(CC4CCC2C4)c2ccccc2-3)c(C)c1]

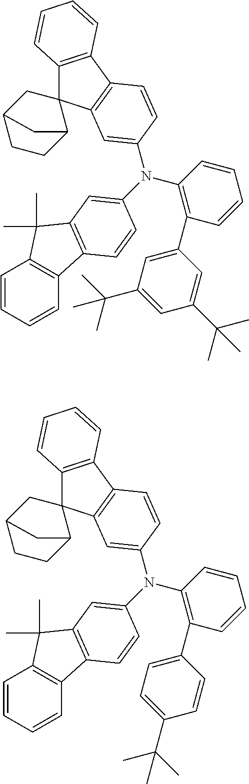 [SMILES: CC(C)(C)c1cc(-c2ccccc2N(c2ccc3c(c2)C(C)(C)c2ccccc2-3)c2ccc3c(c2)C2(CC4CCC2C4)c2ccccc2-3)cc(C(C)(C)C)c1 ; CC(C)(C)c1ccc(-c2ccccc2N(c2ccc3c(c2)C(C)(C)c2ccccc2-3)c2ccc3c(c2)C2(CC4CCC2C4)c2ccccc2-3)cc1]

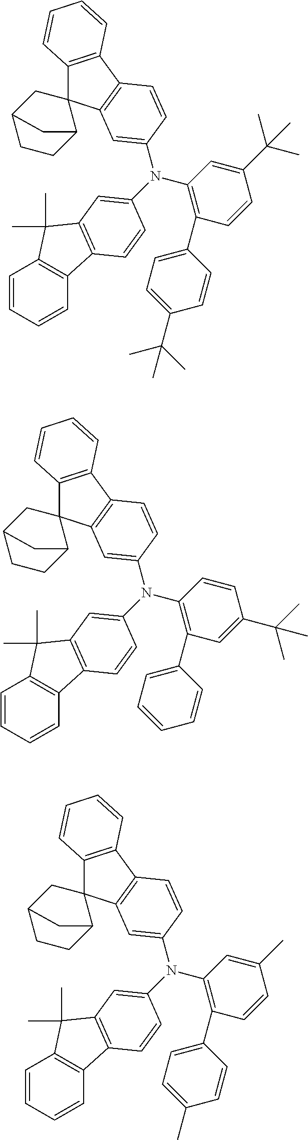 [SMILES: CC(C)(C)c1ccc(-c2ccc(C(C)(C)C)cc2N(c2ccc3c(c2)C(C)(C)c2ccccc2-3)c2ccc3c(c2)C2(CC4CCC2C4)c2ccccc2-3)cc1 ; CC(C)(C)c1ccc(N(c2ccc3c(c2)C(C)(C)c2ccccc2-3)c2ccc3c(c2)C2(CC4CCC2C4)c2ccccc2-3)c(-c2ccccc2)c1 ; Cc1ccc(-c2ccc(C)cc2N(c2ccc3c(c2)C(C)(C)c2ccccc2-3)c2ccc3c(c2)C2(CC4CCC2C4)c2ccccc2-3)cc1]

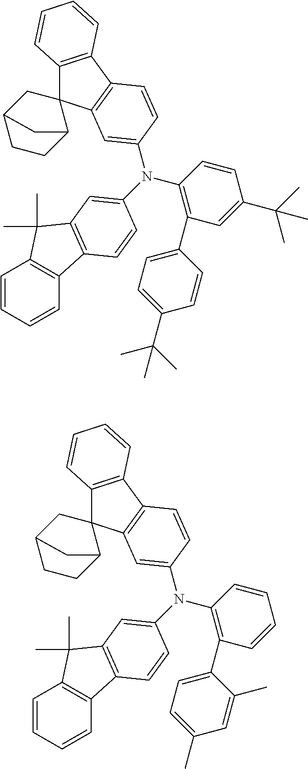 [SMILES: CC(C)(C)c1ccc(-c2cc(C(C)(C)C)ccc2N(c2ccc3c(c2)C(C)(C)c2ccccc2-3)c2ccc3c(c2)C2(CC4CCC2C4)c2ccccc2-3)cc1 ; Cc1ccc(-c2ccccc2N(c2ccc3c(c2)C(C)(C)c2ccccc2-3)c2ccc3c(c2)C2(CC4CCC2C4)c2ccccc2-3)c(C)c1]

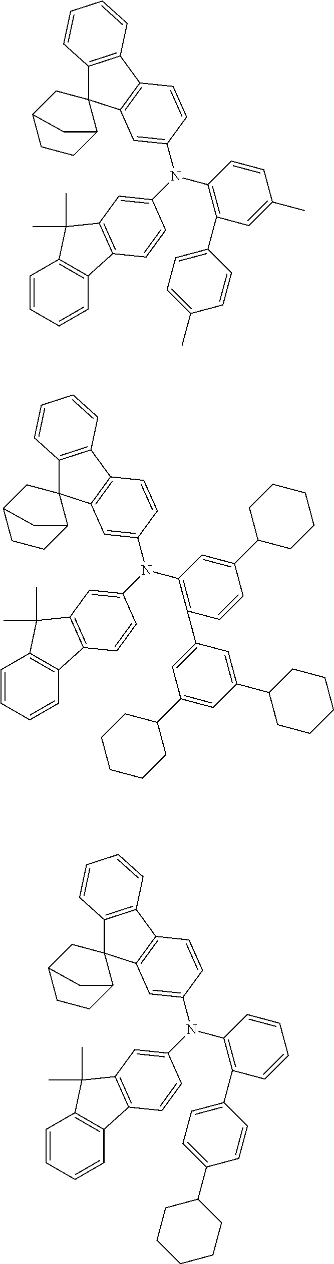 [SMILES: Cc1ccc(-c2cc(C)ccc2N(c2ccc3c(c2)C(C)(C)c2ccccc2-3)c2ccc3c(c2)C2(CC4CCC2C4)c2ccccc2-3)cc1 ; CC1(C)c2ccccc2-c2ccc(N(c3ccc4c(c3)C3(CC5CCC3C5)c3ccccc3-4)c3cc(C4CCCCC4)ccc3-c3cc(C4CCCCC4)cc(C4CCCCC4)c3)cc21 ; CC1(C)c2ccccc2-c2ccc(N(c3ccc4c(c3)C3(CC5CCC3C5)c3ccccc3-4)c3ccccc3-c3ccc(C4CCCCC4)cc3)cc21]

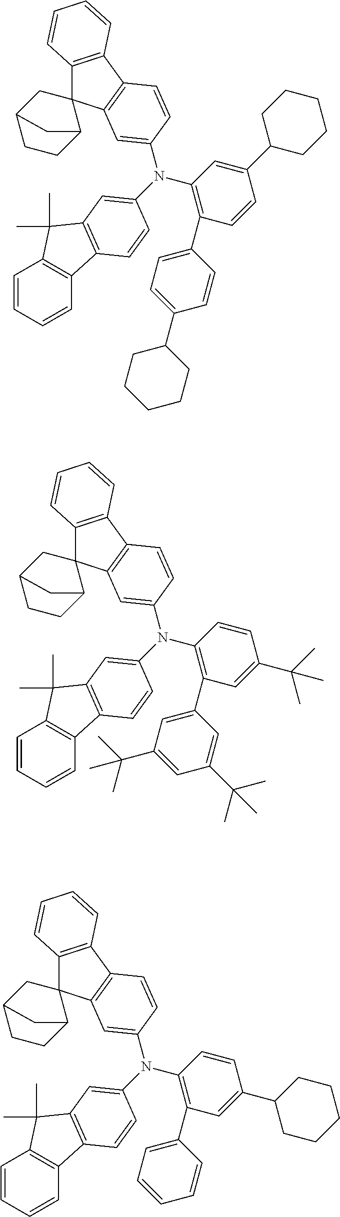 [SMILES: CC1(C)c2ccccc2-c2ccc(N(c3ccc4c(c3)C3(CC5CCC3C5)c3ccccc3-4)c3cc(C4CCCCC4)ccc3-c3ccc(C4CCCCC4)cc3)cc21 ; CC(C)(C)c1cc(-c2cc(C(C)(C)C)ccc2N(c2ccc3c(c2)C(C)(C)c2ccccc2-3)c2ccc3c(c2)C2(CC4CCC2C4)c2ccccc2-3)cc(C(C)(C)C)c1 ; CC1(C)c2ccccc2-c2ccc(N(c3ccc4c(c3)C3(CC5CCC3C5)c3ccccc3-4)c3ccc(C4CCCCC4)cc3-c3ccccc3)cc21]

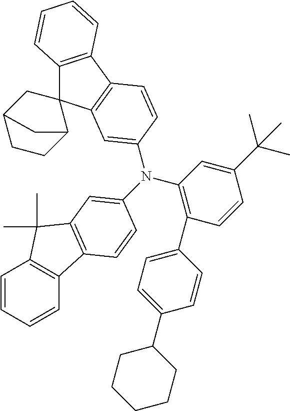 [SMILES: CC(C)(C)c1ccc(-c2ccc(C3CCCCC3)cc2)c(N(c2ccc3c(c2)C(C)(C)c2ccccc2-3)c2ccc3c(c2)C2(CC4CCC2C4)c2ccccc2-3)c1]

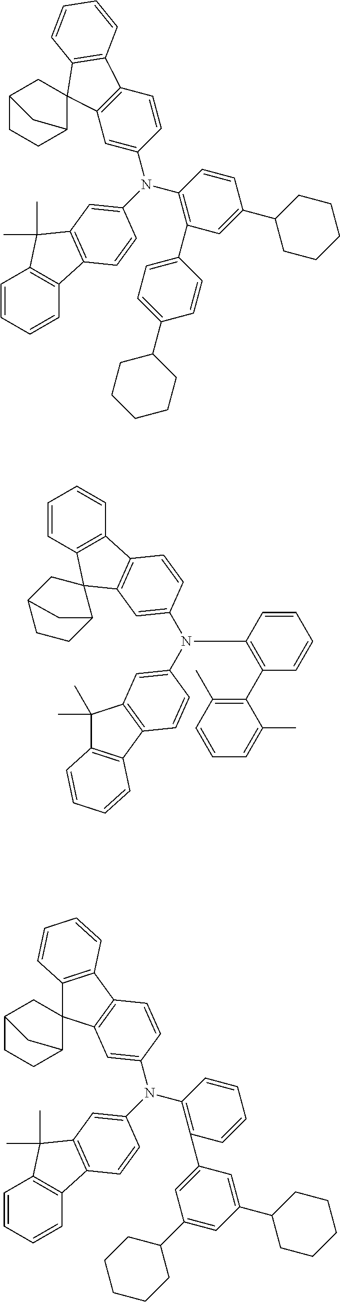 [SMILES: CC1(C)c2ccccc2-c2ccc(N(c3ccc4c(c3)C3(CC5CCC3C5)c3ccccc3-4)c3ccc(C4CCCCC4)cc3-c3ccc(C4CCCCC4)cc3)cc21 ; Cc1cccc(C)c1-c1ccccc1N(c1ccc2c(c1)C(C)(C)c1ccccc1-2)c1ccc2c(c1)C1(CC3CCC1C3)c1ccccc1-2 ; CC1(C)c2ccccc2-c2ccc(N(c3ccc4c(c3)C3(CC5CCC3C5)c3ccccc3-4)c3ccccc3-c3cc(C4CCCCC4)cc(C4CCCCC4)c3)cc21]

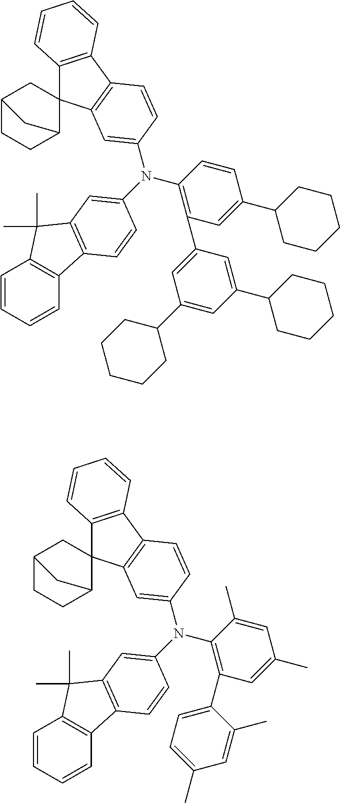 [SMILES: CC1(C)c2ccccc2-c2ccc(N(c3ccc4c(c3)C3(CC5CCC3C5)c3ccccc3-4)c3ccc(C4CCCCC4)cc3-c3cc(C4CCCCC4)cc(C4CCCCC4)c3)cc21 ; Cc1ccc(-c2cc(C)cc(C)c2N(c2ccc3c(c2)C(C)(C)c2ccccc2-3)c2ccc3c(c2)C2(CC4CCC2C4)c2ccccc2-3)c(C)c1]

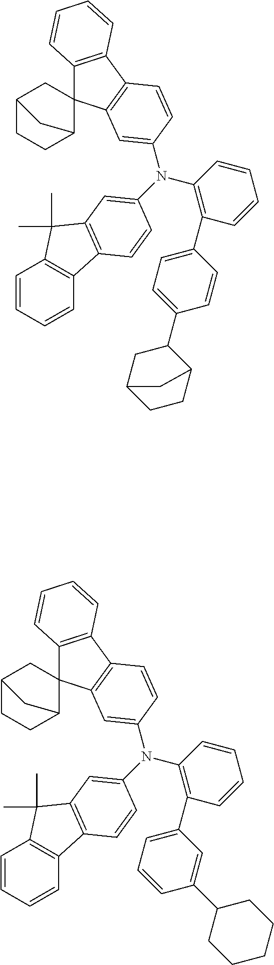 [SMILES: CC1(C)c2ccccc2-c2ccc(N(c3ccc4c(c3)C3(CC5CCC3C5)c3ccccc3-4)c3ccccc3-c3ccc(C4CC5CCC4C5)cc3)cc21 ; CC1(C)c2ccccc2-c2ccc(N(c3ccc4c(c3)C3(CC5CCC3C5)c3ccccc3-4)c3ccccc3-c3cccc(C4CCCCC4)c3)cc21]

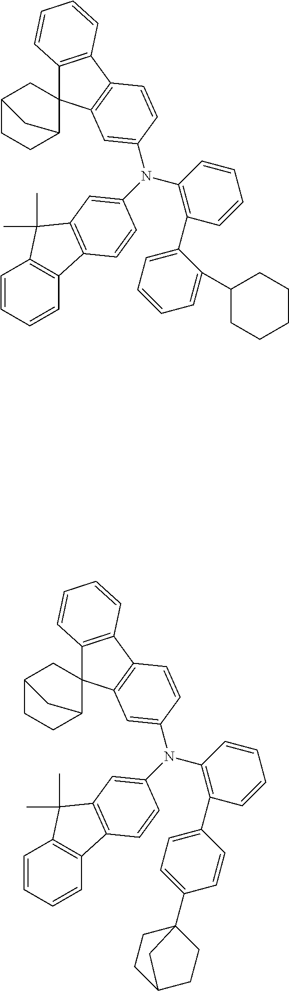 [SMILES: CC1(C)c2ccccc2-c2ccc(N(c3ccc4c(c3)C3(CC5CCC3C5)c3ccccc3-4)c3ccccc3-c3ccccc3C3CCCCC3)cc21 ; CC1(C)c2ccccc2-c2ccc(N(c3ccc4c(c3)C3(CC5CCC3C5)c3ccccc3-4)c3ccccc3-c3ccc(C45CCC(CC4)C5)cc3)cc21]

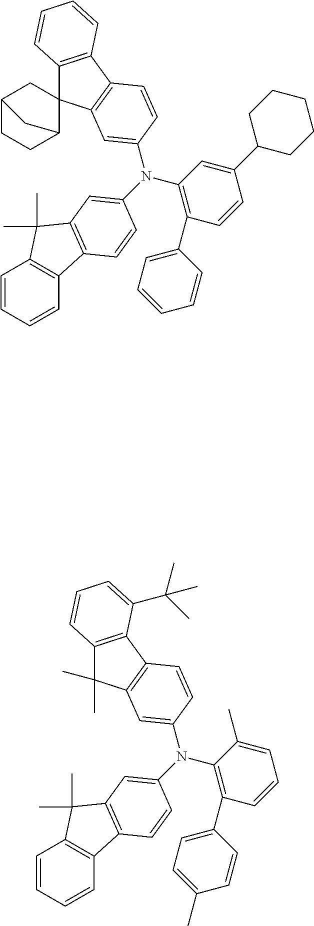 [SMILES: CC1(C)c2ccccc2-c2ccc(N(c3ccc4c(c3)C3(CC5CCC3C5)c3ccccc3-4)c3cc(C4CCCCC4)ccc3-c3ccccc3)cc21 ; Cc1ccc(-c2cccc(C)c2N(c2ccc3c(c2)C(C)(C)c2ccccc2-3)c2ccc3c(c2)C(C)(C)c2cccc(C(C)(C)C)c2-3)cc1]

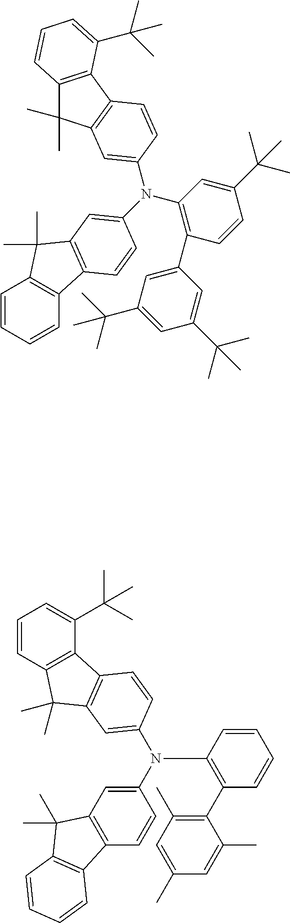 [SMILES: CC(C)(C)c1cc(-c2ccc(C(C)(C)C)cc2N(c2ccc3c(c2)C(C)(C)c2ccccc2-3)c2ccc3c(c2)C(C)(C)c2cccc(C(C)(C)C)c2-3)cc(C(C)(C)C)c1 ; Cc1cc(C)c(-c2ccccc2N(c2ccc3c(c2)C(C)(C)c2ccccc2-3)c2ccc3c(c2)C(C)(C)c2cccc(C(C)(C)C)c2-3)c(C)c1]

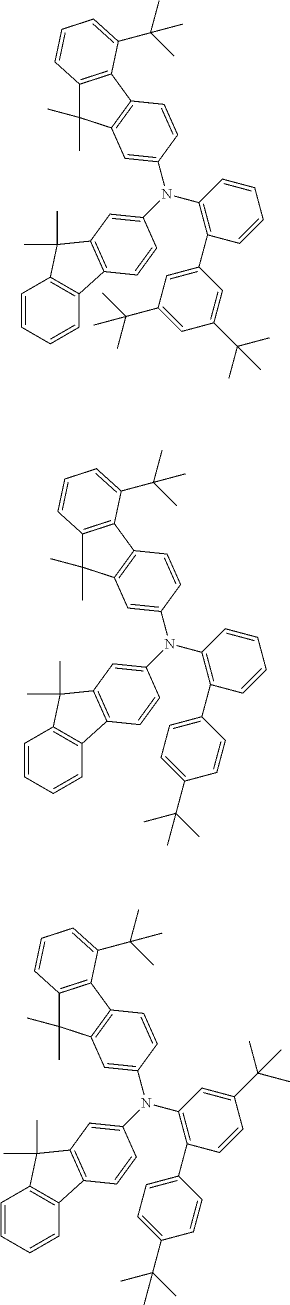 [SMILES: CC(C)(C)c1cc(-c2ccccc2N(c2ccc3c(c2)C(C)(C)c2ccccc2-3)c2ccc3c(c2)C(C)(C)c2cccc(C(C)(C)C)c2-3)cc(C(C)(C)C)c1 ; CC(C)(C)c1ccc(-c2ccccc2N(c2ccc3c(c2)C(C)(C)c2ccccc2-3)c2ccc3c(c2)C(C)(C)c2cccc(C(C)(C)C)c2-3)cc1 ; CC(C)(C)c1ccc(-c2ccc(C(C)(C)C)cc2N(c2ccc3c(c2)C(C)(C)c2ccccc2-3)c2ccc3c(c2)C(C)(C)c2cccc(C(C)(C)C)c2-3)cc1]

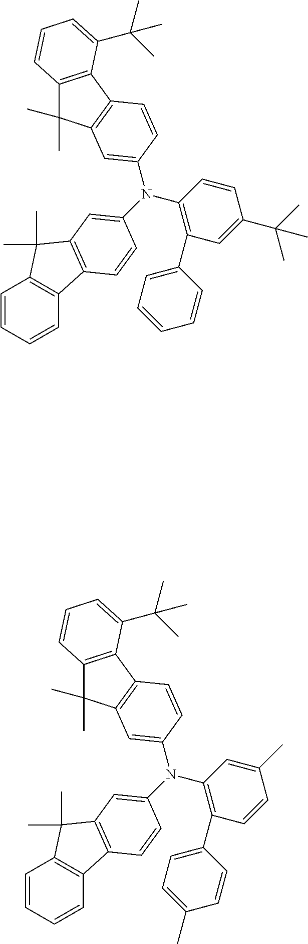 [SMILES: CC(C)(C)c1ccc(N(c2ccc3c(c2)C(C)(C)c2ccccc2-3)c2ccc3c(c2)C(C)(C)c2cccc(C(C)(C)C)c2-3)c(-c2ccccc2)c1 ; Cc1ccc(-c2ccc(C)cc2N(c2ccc3c(c2)C(C)(C)c2ccccc2-3)c2ccc3c(c2)C(C)(C)c2cccc(C(C)(C)C)c2-3)cc1]

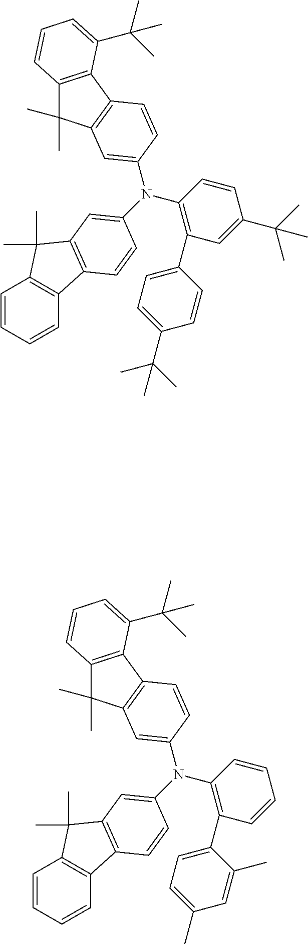 [SMILES: CC(C)(C)c1ccc(-c2cc(C(C)(C)C)ccc2N(c2ccc3c(c2)C(C)(C)c2ccccc2-3)c2ccc3c(c2)C(C)(C)c2cccc(C(C)(C)C)c2-3)cc1 ; Cc1ccc(-c2ccccc2N(c2ccc3c(c2)C(C)(C)c2ccccc2-3)c2ccc3c(c2)C(C)(C)c2cccc(C(C)(C)C)c2-3)c(C)c1]

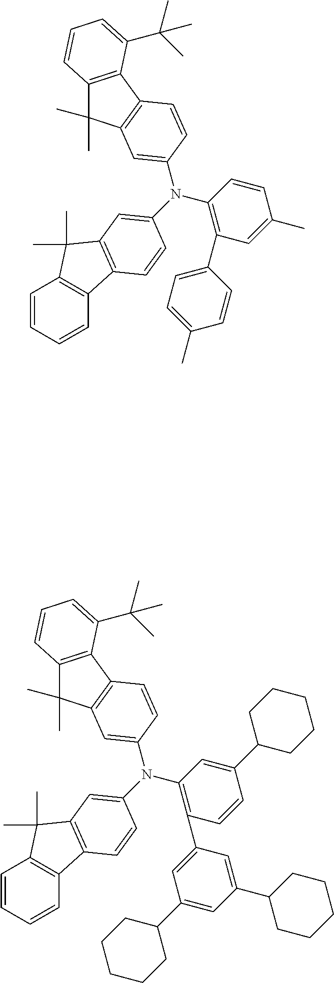 [SMILES: Cc1ccc(-c2cc(C)ccc2N(c2ccc3c(c2)C(C)(C)c2ccccc2-3)c2ccc3c(c2)C(C)(C)c2cccc(C(C)(C)C)c2-3)cc1 ; CC(C)(C)c1cccc2c1-c1ccc(N(c3ccc4c(c3)C(C)(C)c3ccccc3-4)c3cc(C4CCCCC4)ccc3-c3cc(C4CCCCC4)cc(C4CCCCC4)c3)cc1C2(C)C]

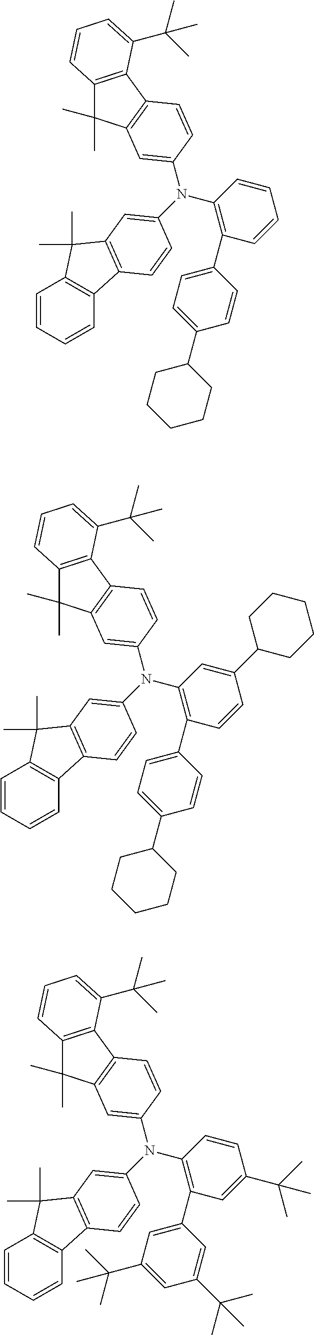

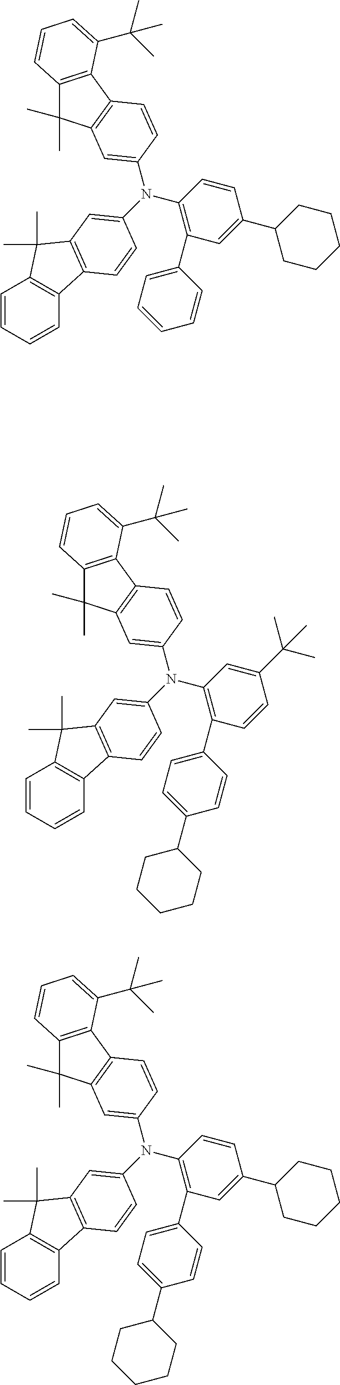 [SMILES: CC(C)(C)c1cccc2c1-c1ccc(N(c3ccc4c(c3)C(C)(C)c3ccccc3-4)c3ccc(C4CCCCC4)cc3-c3ccccc3)cc1C2(C)C ; CC(C)(C)c1ccc(-c2ccc(C3CCCCC3)cc2)c(N(c2ccc3c(c2)C(C)(C)c2ccccc2-3)c2ccc3c(c2)C(C)(C)c2cccc(C(C)(C)C)c2-3)c1 ; CC(C)(C)c1cccc2c1-c1ccc(N(c3ccc4c(c3)C(C)(C)c3ccccc3-4)c3ccc(C4CCCCC4)cc3-c3ccc(C4CCCCC4)cc3)cc1C2(C)C]

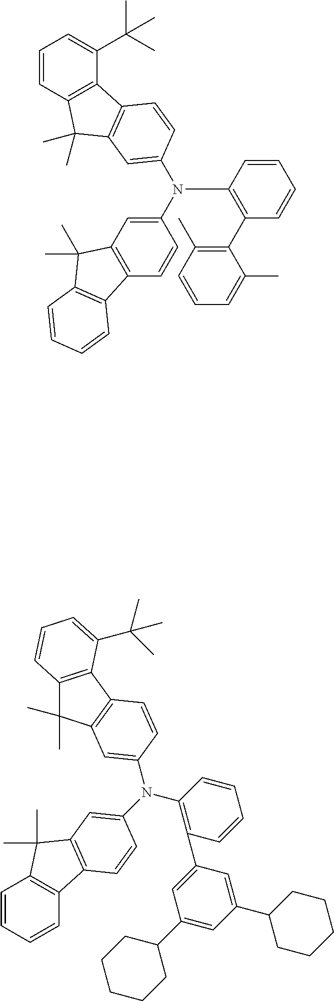 [SMILES: Cc1cccc(C)c1-c1ccccc1N(c1ccc2c(c1)C(C)(C)c1ccccc1-2)c1ccc2c(c1)C(C)(C)c1cccc(C(C)(C)C)c1-2 ; CC(C)(C)c1cccc2c1-c1ccc(N(c3ccc4c(c3)C(C)(C)c3ccccc3-4)c3ccccc3-c3cc(C4CCCCC4)cc(C4CCCCC4)c3)cc1C2(C)C]

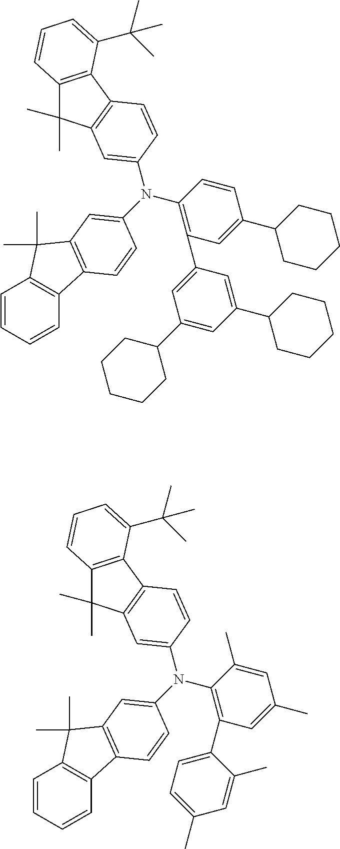 [SMILES: CC(C)(C)c1cccc2c1-c1ccc(N(c3ccc4c(c3)C(C)(C)c3ccccc3-4)c3ccc(C4CCCCC4)cc3-c3cc(C4CCCCC4)cc(C4CCCCC4)c3)cc1C2(C)C ; Cc1ccc(-c2cc(C)cc(C)c2N(c2ccc3c(c2)C(C)(C)c2ccccc2-3)c2ccc3c(c2)C(C)(C)c2cccc(C(C)(C)C)c2-3)c(C)c1]

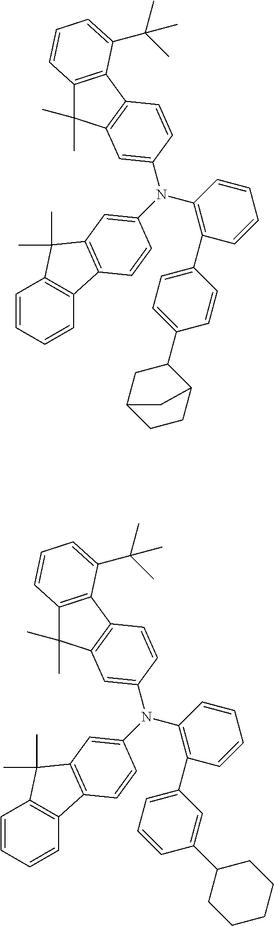 [SMILES: CC(C)(C)c1cccc2c1-c1ccc(N(c3ccc4c(c3)C(C)(C)c3ccccc3-4)c3ccccc3-c3ccc(C4CC5CCC4C5)cc3)cc1C2(C)C ; CC(C)(C)c1cccc2c1-c1ccc(N(c3ccc4c(c3)C(C)(C)c3ccccc3-4)c3ccccc3-c3cccc(C4CCCCC4)c3)cc1C2(C)C]

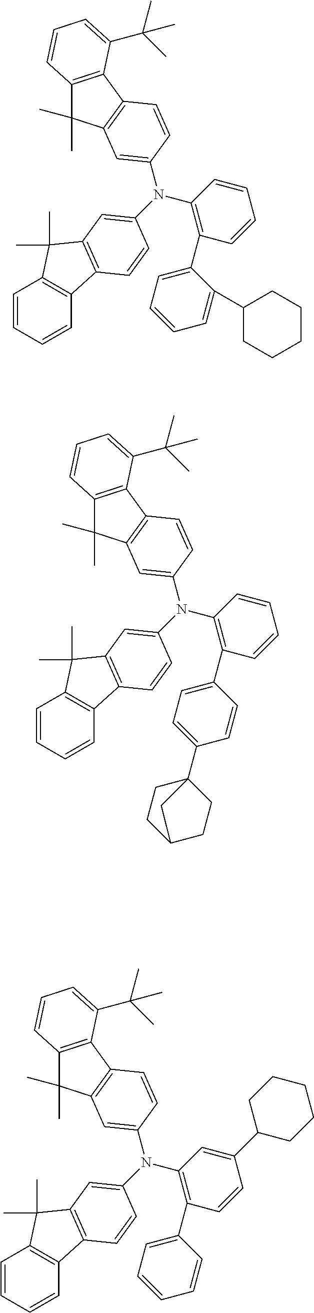 [SMILES: CC(C)(C)c1cccc2c1-c1ccc(N(c3ccc4c(c3)C(C)(C)c3ccccc3-4)c3ccccc3-c3ccccc3C3CCCCC3)cc1C2(C)C ; CC(C)(C)c1cccc2c1-c1ccc(N(c3ccc4c(c3)C(C)(C)c3ccccc3-4)c3ccccc3-c3ccc(C45CCC(CC4)C5)cc3)cc1C2(C)C ; CC(C)(C)c1cccc2c1-c1ccc(N(c3ccc4c(c3)C(C)(C)c3ccccc3-4)c3cc(C4CCCCC4)ccc3-c3ccccc3)cc1C2(C)C]

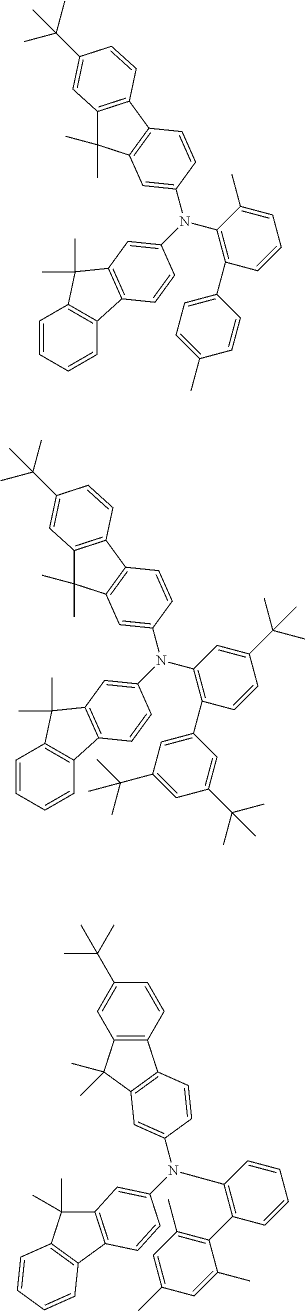 [SMILES: Cc1ccc(-c2cccc(C)c2N(c2ccc3c(c2)C(C)(C)c2ccccc2-3)c2ccc3c(c2)C(C)(C)c2cc(C(C)(C)C)ccc2-3)cc1 ; CC(C)(C)c1cc(-c2ccc(C(C)(C)C)cc2N(c2ccc3c(c2)C(C)(C)c2ccccc2-3)c2ccc3c(c2)C(C)(C)c2cc(C(C)(C)C)ccc2-3)cc(C(C)(C)C)c1 ; Cc1cc(C)c(-c2ccccc2N(c2ccc3c(c2)C(C)(C)c2ccccc2-3)c2ccc3c(c2)C(C)(C)c2cc(C(C)(C)C)ccc2-3)c(C)c1]

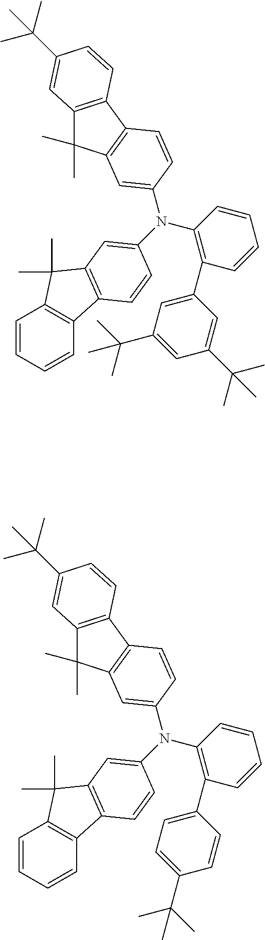

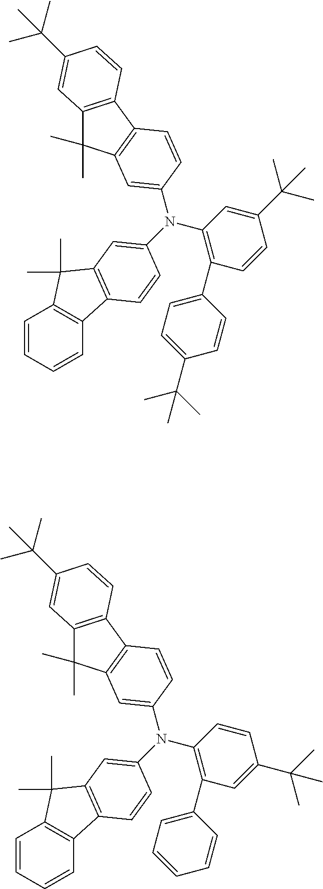

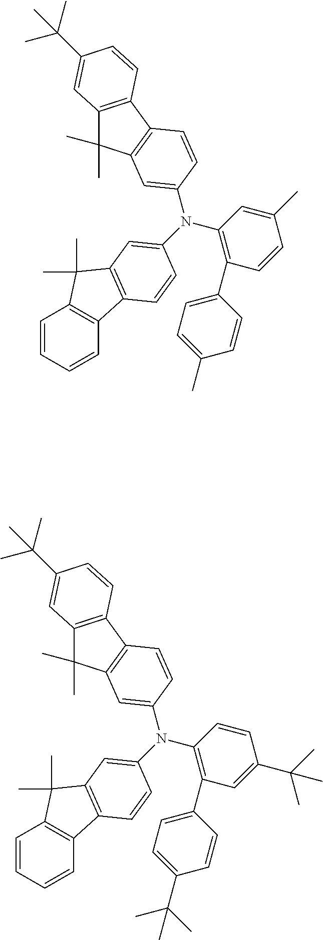

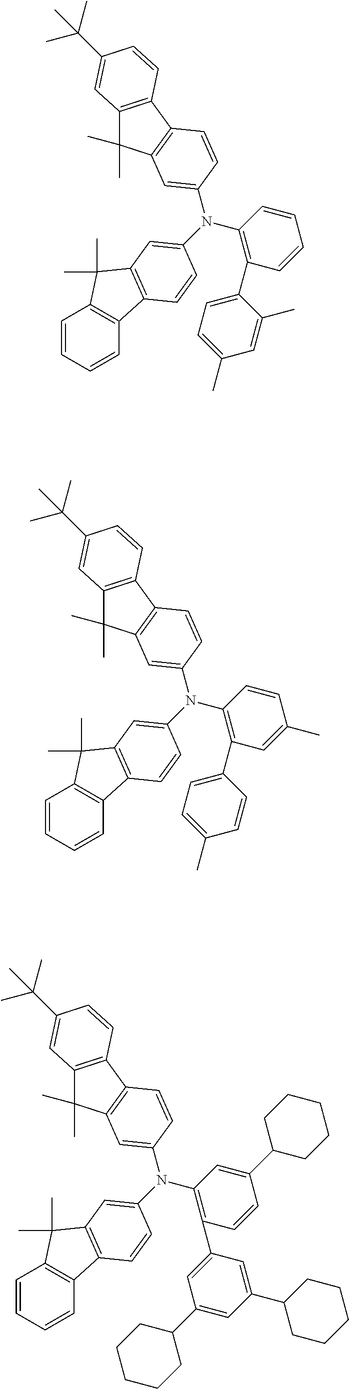

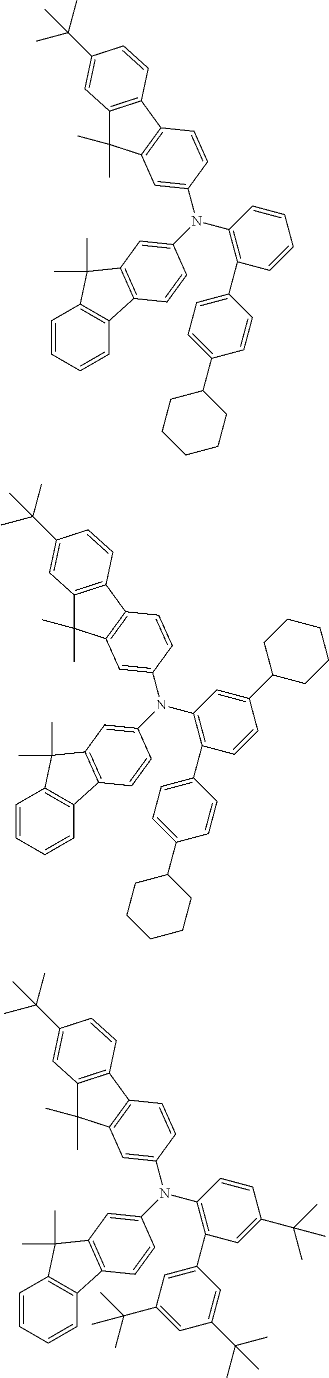 [SMILES: CC(C)(C)c1ccc2c(c1)C(C)(C)c1cc(N(c3ccc4c(c3)C(C)(C)c3ccccc3-4)c3ccccc3-c3ccc(C4CCCCC4)cc3)ccc1-2 ; CC(C)(C)c1ccc2c(c1)C(C)(C)c1cc(N(c3ccc4c(c3)C(C)(C)c3ccccc3-4)c3cc(C4CCCCC4)ccc3-c3ccc(C4CCCCC4)cc3)ccc1-2 ; CC(C)(C)c1cc(-c2cc(C(C)(C)C)ccc2N(c2ccc3c(c2)C(C)(C)c2ccccc2-3)c2ccc3c(c2)C(C)(C)c2cc(C(C)(C)C)ccc2-3)cc(C(C)(C)C)c1]

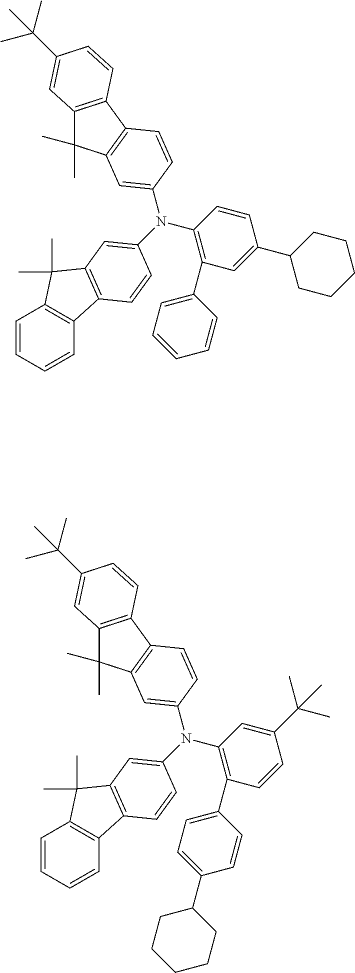 [SMILES: CC(C)(C)c1ccc2c(c1)C(C)(C)c1cc(N(c3ccc4c(c3)C(C)(C)c3ccccc3-4)c3ccc(C4CCCCC4)cc3-c3ccccc3)ccc1-2 ; CC(C)(C)c1ccc(-c2ccc(C3CCCCC3)cc2)c(N(c2ccc3c(c2)C(C)(C)c2ccccc2-3)c2ccc3c(c2)C(C)(C)c2cc(C(C)(C)C)ccc2-3)c1]

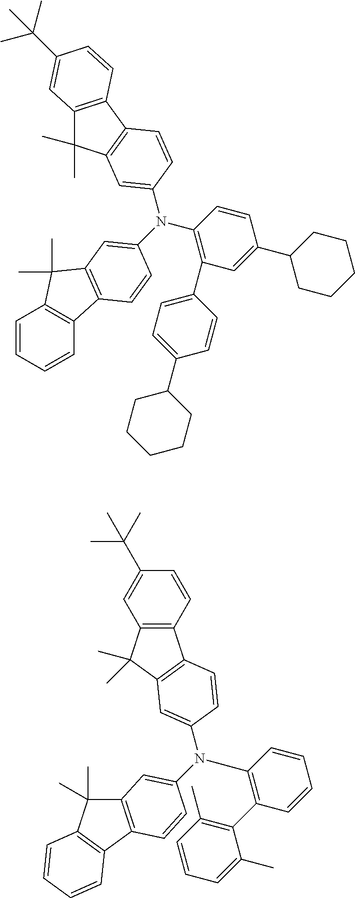 [SMILES: CC(C)(C)c1ccc2c(c1)C(C)(C)c1cc(N(c3ccc4c(c3)C(C)(C)c3ccccc3-4)c3ccc(C4CCCCC4)cc3-c3ccc(C4CCCCC4)cc3)ccc1-2 ; Cc1cccc(C)c1-c1ccccc1N(c1ccc2c(c1)C(C)(C)c1ccccc1-2)c1ccc2c(c1)C(C)(C)c1cc(C(C)(C)C)ccc1-2]

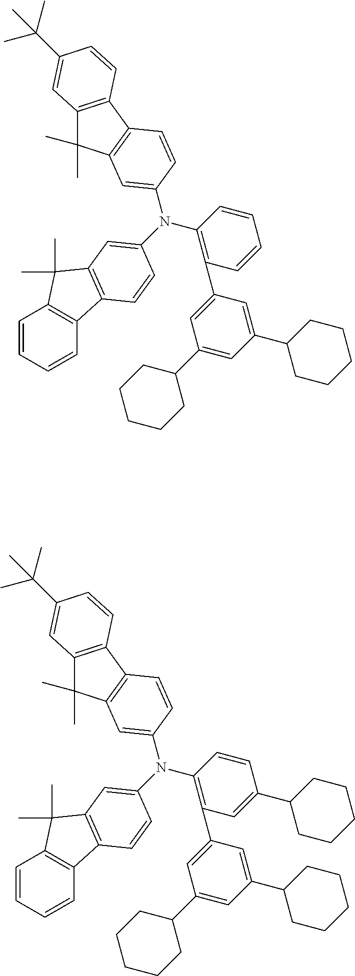 [SMILES: CC(C)(C)c1ccc2c(c1)C(C)(C)c1cc(N(c3ccc4c(c3)C(C)(C)c3ccccc3-4)c3ccccc3-c3cc(C4CCCCC4)cc(C4CCCCC4)c3)ccc1-2 ; CC(C)(C)c1ccc2c(c1)C(C)(C)c1cc(N(c3ccc4c(c3)C(C)(C)c3ccccc3-4)c3ccc(C4CCCCC4)cc3-c3cc(C4CCCCC4)cc(C4CCCCC4)c3)ccc1-2]

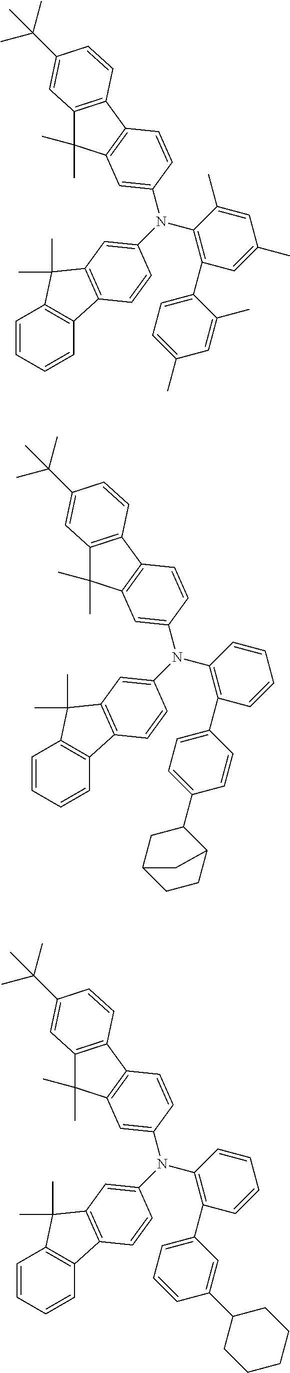

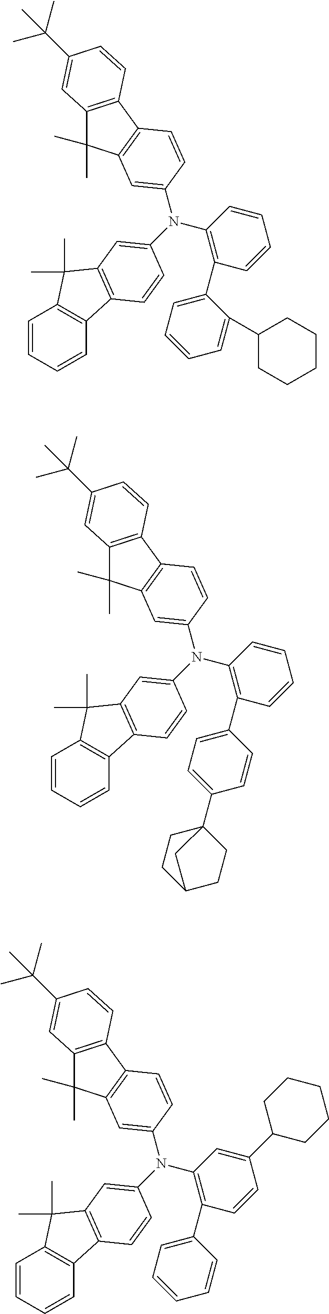 [SMILES: CC(C)(C)c1ccc2c(c1)C(C)(C)c1cc(N(c3ccc4c(c3)C(C)(C)c3ccccc3-4)c3ccccc3-c3ccccc3C3CCCCC3)ccc1-2 ; CC(C)(C)c1ccc2c(c1)C(C)(C)c1cc(N(c3ccc4c(c3)C(C)(C)c3ccccc3-4)c3ccccc3-c3ccc(C45CCC(CC4)C5)cc3)ccc1-2 ; CC(C)(C)c1ccc2c(c1)C(C)(C)c1cc(N(c3ccc4c(c3)C(C)(C)c3ccccc3-4)c3cc(C4CCCCC4)ccc3-c3ccccc3)ccc1-2]

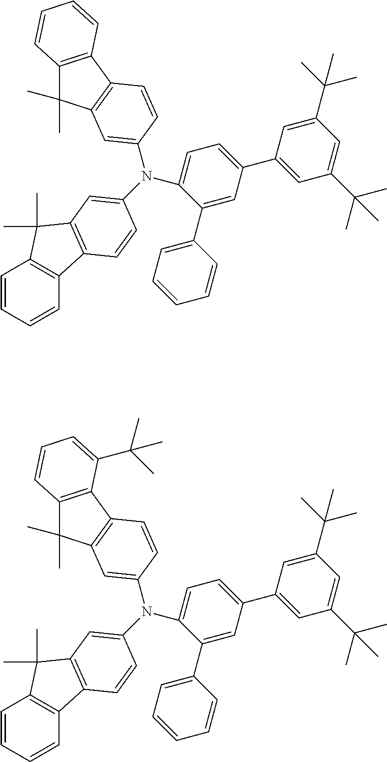 [SMILES: CC(C)(C)c1cc(-c2ccc(N(c3ccc4c(c3)C(C)(C)c3ccccc3-4)c3ccc4c(c3)C(C)(C)c3ccccc3-4)c(-c3ccccc3)c2)cc(C(C)(C)C)c1 ; CC(C)(C)c1cc(-c2ccc(N(c3ccc4c(c3)C(C)(C)c3ccccc3-4)c3ccc4c(c3)C(C)(C)c3cccc(C(C)(C)C)c3-4)c(-c3ccccc3)c2)cc(C(C)(C)C)c1]

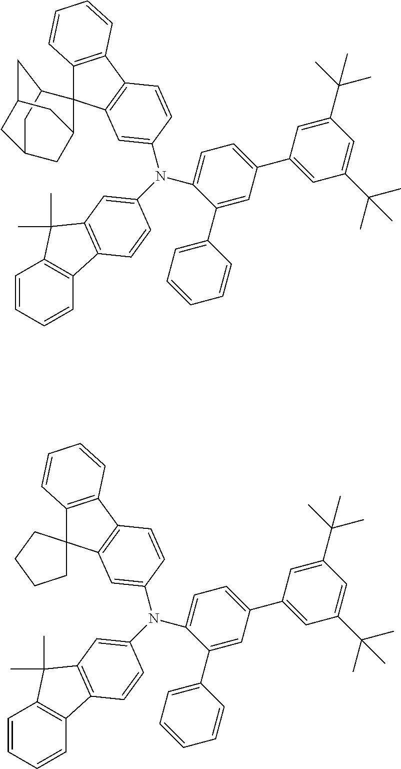 [SMILES: CC(C)(C)c1cc(-c2ccc(N(c3ccc4c(c3)C(C)(C)c3ccccc3-4)c3ccc4c(c3)C3(c5ccccc5-4)C4CC5CC(C4)CC3C5)c(-c3ccccc3)c2)cc(C(C)(C)C)c1 ; CC(C)(C)c1cc(-c2ccc(N(c3ccc4c(c3)C(C)(C)c3ccccc3-4)c3ccc4c(c3)C3(CCCC3)c3ccccc3-4)c(-c3ccccc3)c2)cc(C(C)(C)C)c1]

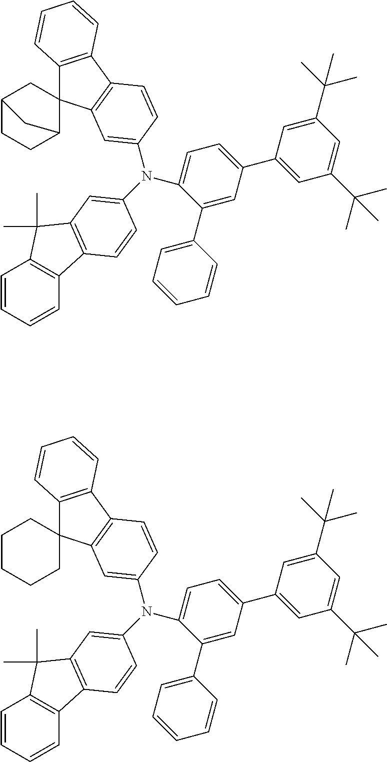 [SMILES: CC(C)(C)c1cc(-c2ccc(N(c3ccc4c(c3)C(C)(C)c3ccccc3-4)c3ccc4c(c3)C3(CC5CCC3C5)c3ccccc3-4)c(-c3ccccc3)c2)cc(C(C)(C)C)c1 ; CC(C)(C)c1cc(-c2ccc(N(c3ccc4c(c3)C(C)(C)c3ccccc3-4)c3ccc4c(c3)C3(CCCCC3)c3ccccc3-4)c(-c3ccccc3)c2)cc(C(C)(C)C)c1]

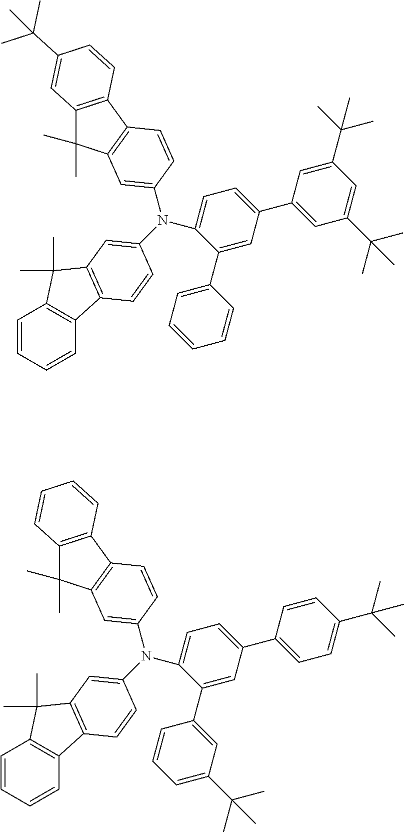 [SMILES: CC(C)(C)c1cc(-c2ccc(N(c3ccc4c(c3)C(C)(C)c3ccccc3-4)c3ccc4c(c3)C(C)(C)c3cc(C(C)(C)C)ccc3-4)c(-c3ccccc3)c2)cc(C(C)(C)C)c1 ; CC(C)(C)c1ccc(-c2ccc(N(c3ccc4c(c3)C(C)(C)c3ccccc3-4)c3ccc4c(c3)C(C)(C)c3ccccc3-4)c(-c3cccc(C(C)(C)C)c3)c2)cc1]

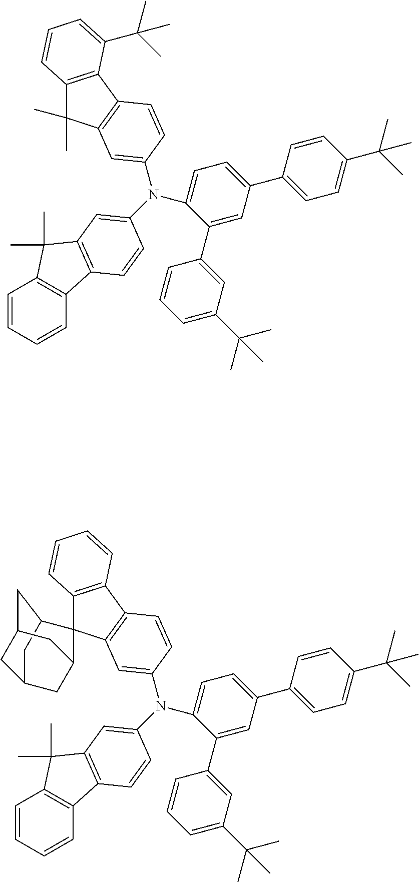 [SMILES: CC(C)(C)c1ccc(-c2ccc(N(c3ccc4c(c3)C(C)(C)c3ccccc3-4)c3ccc4c(c3)C(C)(C)c3cccc(C(C)(C)C)c3-4)c(-c3cccc(C(C)(C)C)c3)c2)cc1 ; CC(C)(C)c1ccc(-c2ccc(N(c3ccc4c(c3)C(C)(C)c3ccccc3-4)c3ccc4c(c3)C3(c5ccccc5-4)C4CC5CC(C4)CC3C5)c(-c3cccc(C(C)(C)C)c3)c2)cc1]

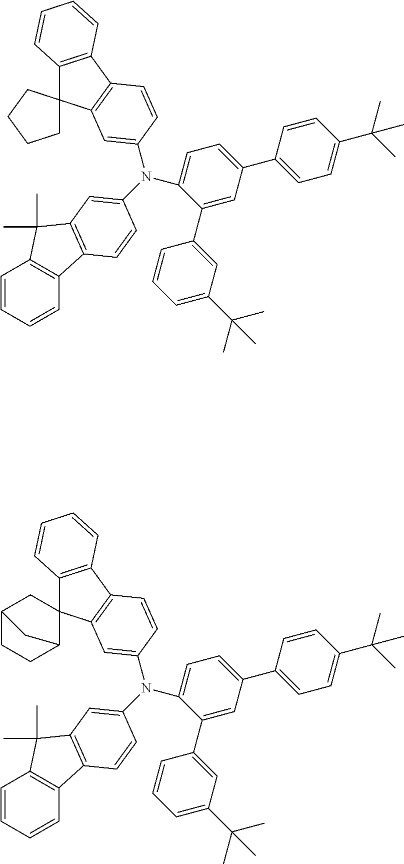 [SMILES: CC(C)(C)c1ccc(-c2ccc(N(c3ccc4c(c3)C(C)(C)c3ccccc3-4)c3ccc4c(c3)C3(CCCC3)c3ccccc3-4)c(-c3cccc(C(C)(C)C)c3)c2)cc1 ; CC(C)(C)c1ccc(-c2ccc(N(c3ccc4c(c3)C(C)(C)c3ccccc3-4)c3ccc4c(c3)C3(CC5CCC3C5)c3ccccc3-4)c(-c3cccc(C(C)(C)C)c3)c2)cc1]

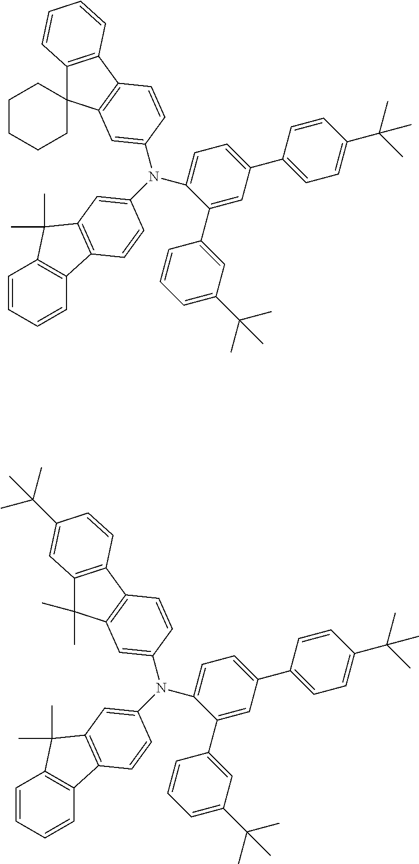

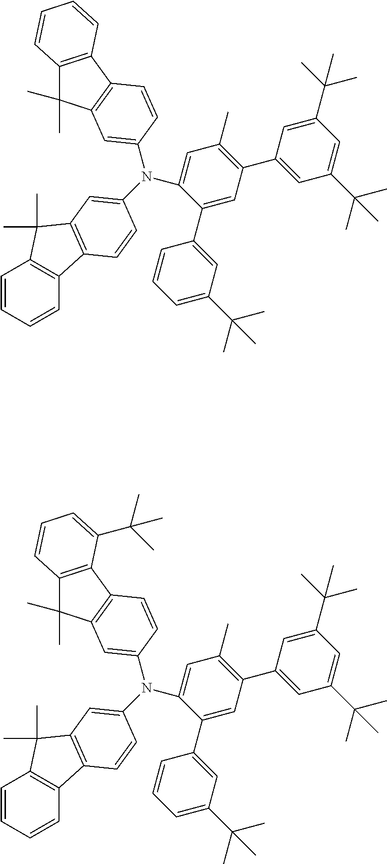 [SMILES: Cc1cc(N(c2ccc3c(c2)C(C)(C)c2ccccc2-3)c2ccc3c(c2)C(C)(C)c2ccccc2-3)c(-c2cccc(C(C)(C)C)c2)cc1-c1cc(C(C)(C)C)cc(C(C)(C)C)c1 ; Cc1cc(N(c2ccc3c(c2)C(C)(C)c2ccccc2-3)c2ccc3c(c2)C(C)(C)c2cccc(C(C)(C)C)c2-3)c(-c2cccc(C(C)(C)C)c2)cc1-c1cc(C(C)(C)C)cc(C(C)(C)C)c1]

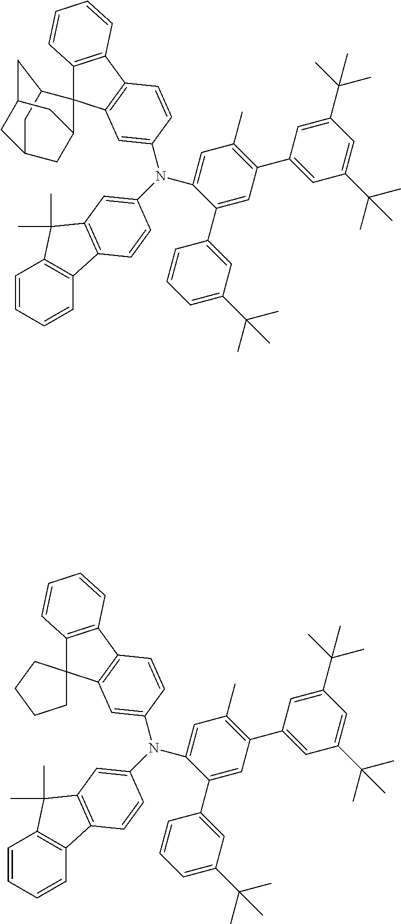 [SMILES: Cc1cc(N(c2ccc3c(c2)C(C)(C)c2ccccc2-3)c2ccc3c(c2)C2(c4ccccc4-3)C3CC4CC(C3)CC2C4)c(-c2cccc(C(C)(C)C)c2)cc1-c1cc(C(C)(C)C)cc(C(C)(C)C)c1 ; Cc1cc(N(c2ccc3c(c2)C(C)(C)c2ccccc2-3)c2ccc3c(c2)C2(CCCC2)c2ccccc2-3)c(-c2cccc(C(C)(C)C)c2)cc1-c1cc(C(C)(C)C)cc(C(C)(C)C)c1]

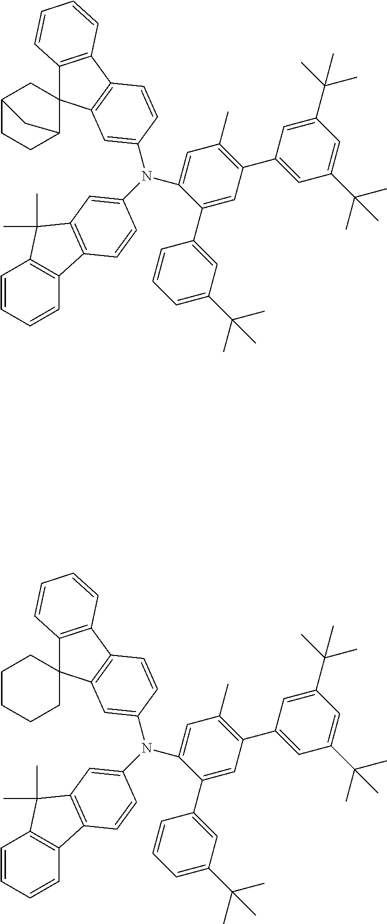 [SMILES: Cc1cc(N(c2ccc3c(c2)C(C)(C)c2ccccc2-3)c2ccc3c(c2)C2(CC4CCC2C4)c2ccccc2-3)c(-c2cccc(C(C)(C)C)c2)cc1-c1cc(C(C)(C)C)cc(C(C)(C)C)c1 ; Cc1cc(N(c2ccc3c(c2)C(C)(C)c2ccccc2-3)c2ccc3c(c2)C2(CCCCC2)c2ccccc2-3)c(-c2cccc(C(C)(C)C)c2)cc1-c1cc(C(C)(C)C)cc(C(C)(C)C)c1]

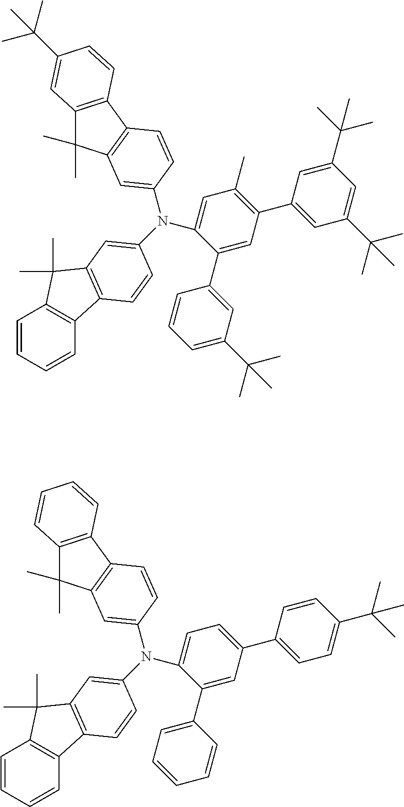 [SMILES: Cc1cc(N(c2ccc3c(c2)C(C)(C)c2ccccc2-3)c2ccc3c(c2)C(C)(C)c2cc(C(C)(C)C)ccc2-3)c(-c2cccc(C(C)(C)C)c2)cc1-c1cc(C(C)(C)C)cc(C(C)(C)C)c1 ; CC(C)(C)c1ccc(-c2ccc(N(c3ccc4c(c3)C(C)(C)c3ccccc3-4)c3ccc4c(c3)C(C)(C)c3ccccc3-4)c(-c3ccccc3)c2)cc1]

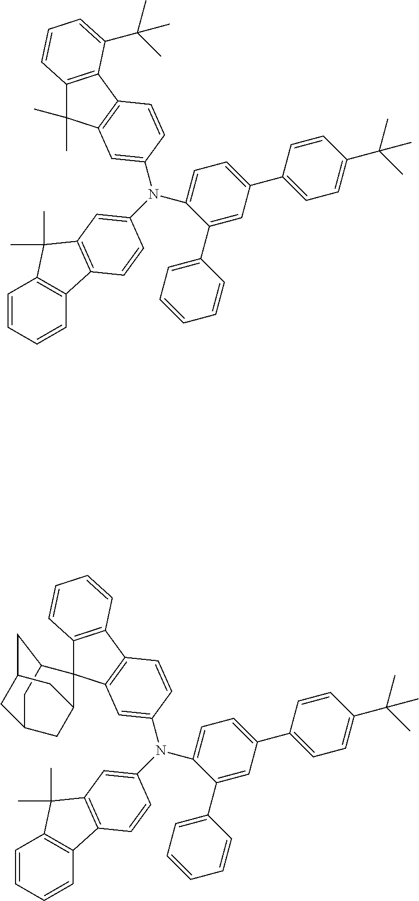 [SMILES: CC(C)(C)c1ccc(-c2ccc(N(c3ccc4c(c3)C(C)(C)c3ccccc3-4)c3ccc4c(c3)C(C)(C)c3cccc(C(C)(C)C)c3-4)c(-c3ccccc3)c2)cc1 ; CC(C)(C)c1ccc(-c2ccc(N(c3ccc4c(c3)C(C)(C)c3ccccc3-4)c3ccc4c(c3)C3(c5ccccc5-4)C4CC5CC(C4)CC3C5)c(-c3ccccc3)c2)cc1]

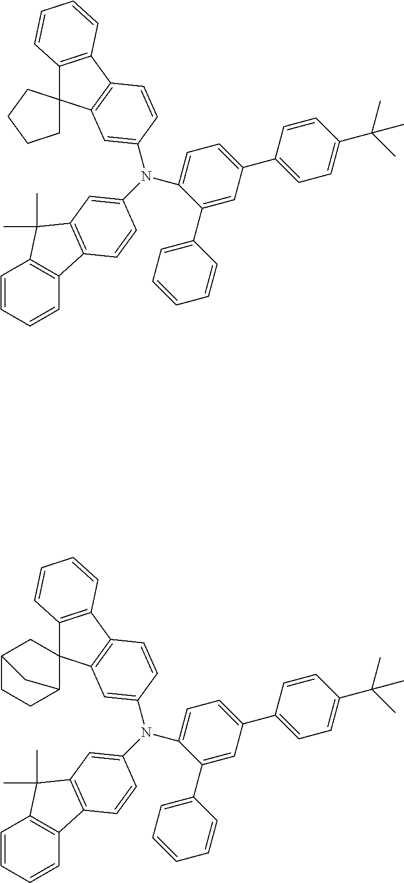 [SMILES: CC(C)(C)c1ccc(-c2ccc(N(c3ccc4c(c3)C(C)(C)c3ccccc3-4)c3ccc4c(c3)C3(CCCC3)c3ccccc3-4)c(-c3ccccc3)c2)cc1 ; CC(C)(C)c1ccc(-c2ccc(N(c3ccc4c(c3)C(C)(C)c3ccccc3-4)c3ccc4c(c3)C3(CC5CCC3C5)c3ccccc3-4)c(-c3ccccc3)c2)cc1]

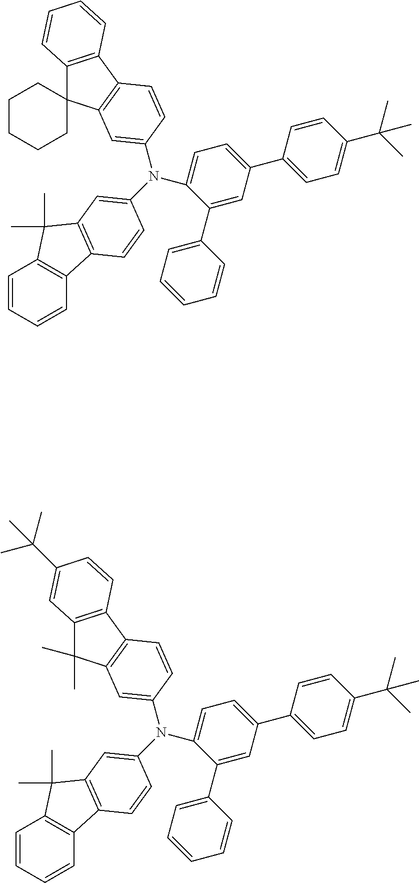

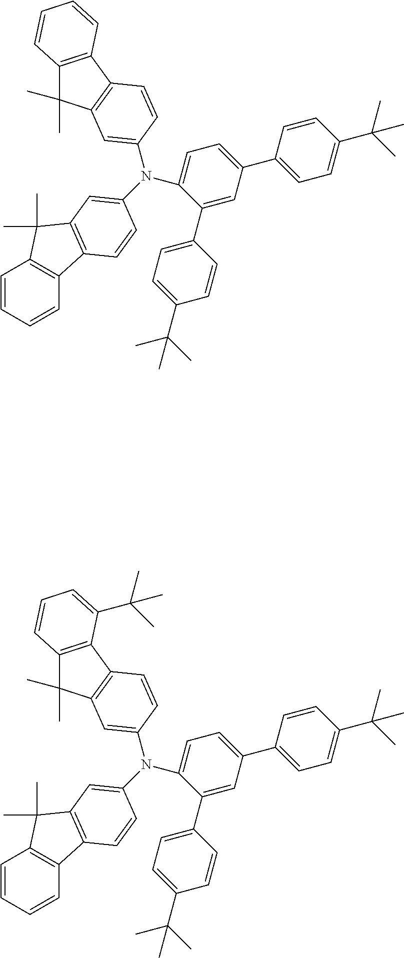 [SMILES: CC(C)(C)c1ccc(-c2ccc(N(c3ccc4c(c3)C(C)(C)c3ccccc3-4)c3ccc4c(c3)C(C)(C)c3ccccc3-4)c(-c3ccc(C(C)(C)C)cc3)c2)cc1 ; CC(C)(C)c1ccc(-c2ccc(N(c3ccc4c(c3)C(C)(C)c3ccccc3-4)c3ccc4c(c3)C(C)(C)c3cccc(C(C)(C)C)c3-4)c(-c3ccc(C(C)(C)C)cc3)c2)cc1]

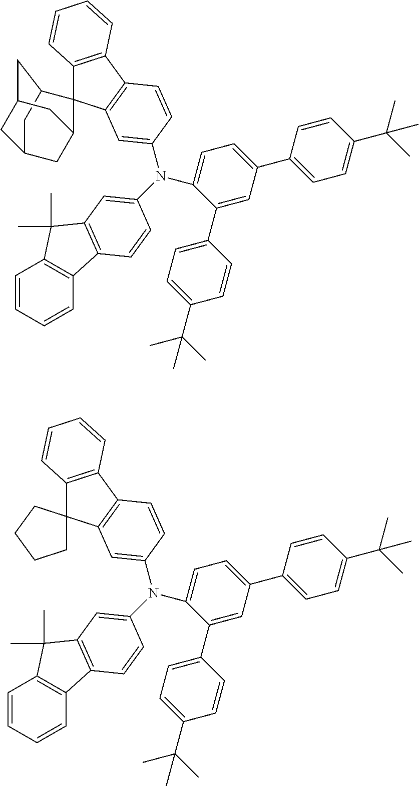 [SMILES: CC(C)(C)c1ccc(-c2ccc(N(c3ccc4c(c3)C(C)(C)c3ccccc3-4)c3ccc4c(c3)C3(c5ccccc5-4)C4CC5CC(C4)CC3C5)c(-c3ccc(C(C)(C)C)cc3)c2)cc1 ; CC(C)(C)c1ccc(-c2ccc(N(c3ccc4c(c3)C(C)(C)c3ccccc3-4)c3ccc4c(c3)C3(CCCC3)c3ccccc3-4)c(-c3ccc(C(C)(C)C)cc3)c2)cc1]

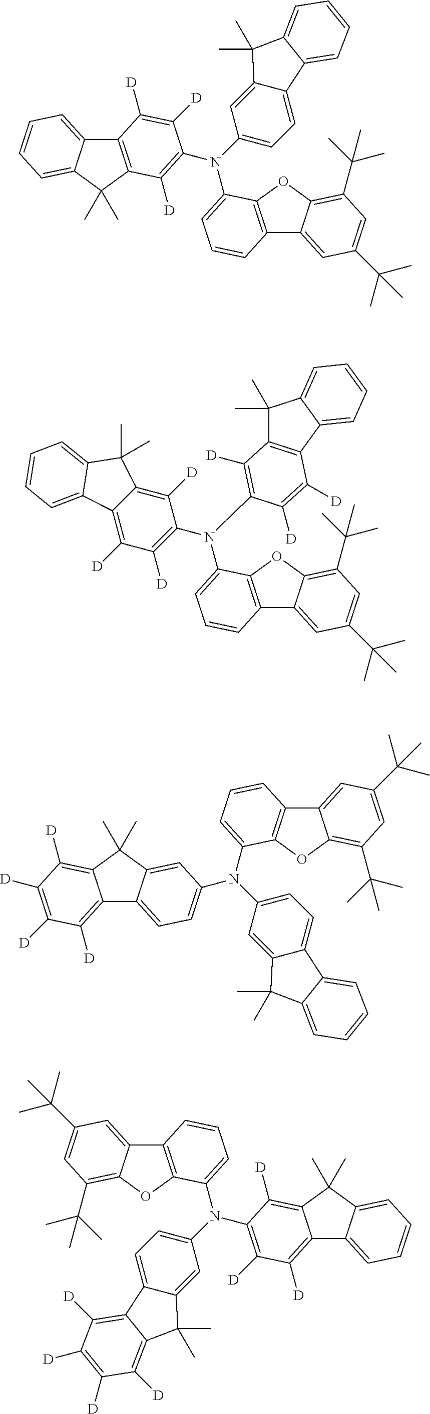

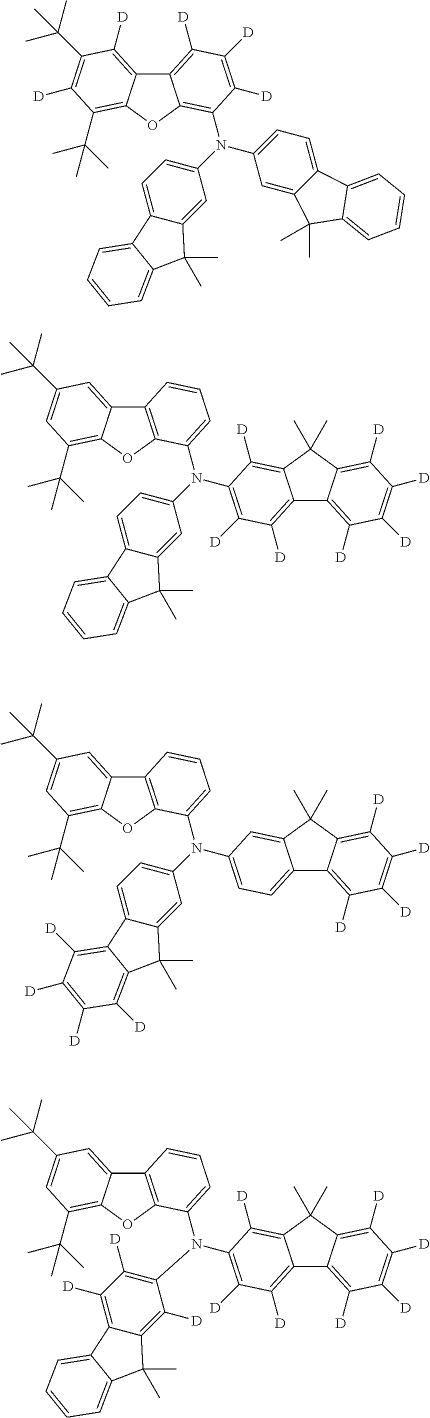

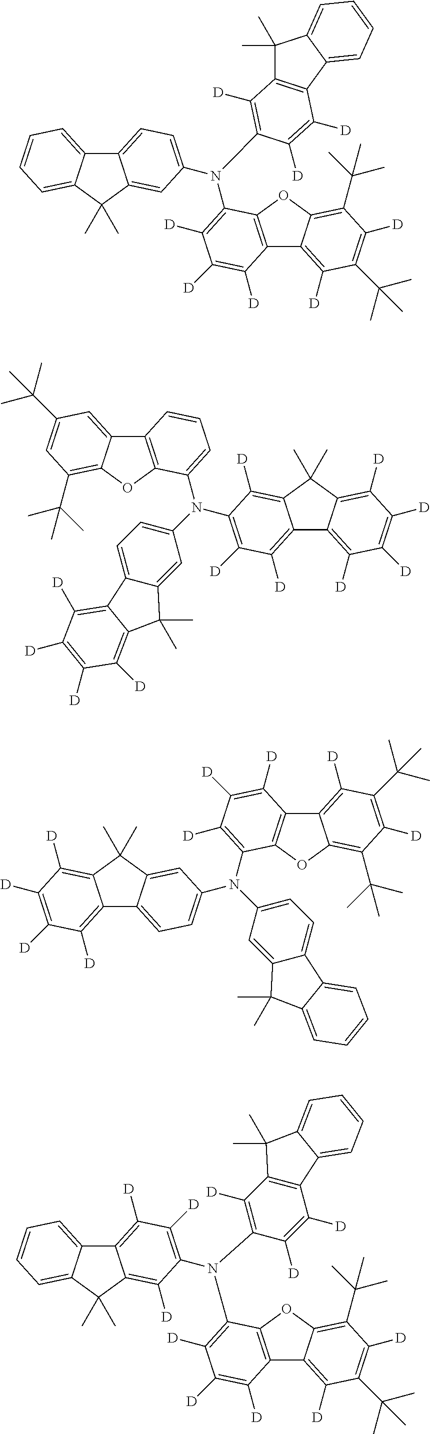

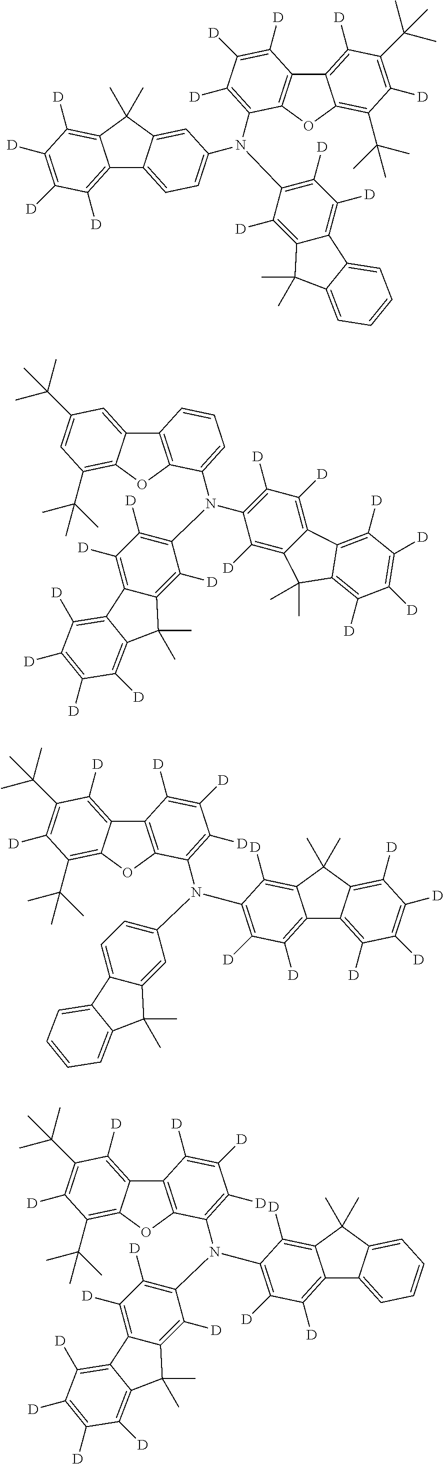

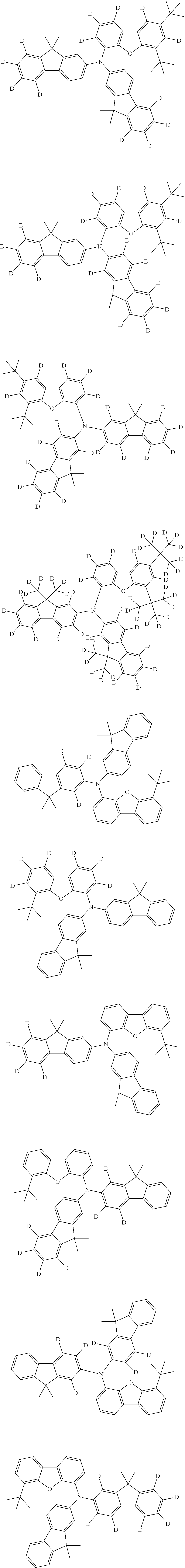

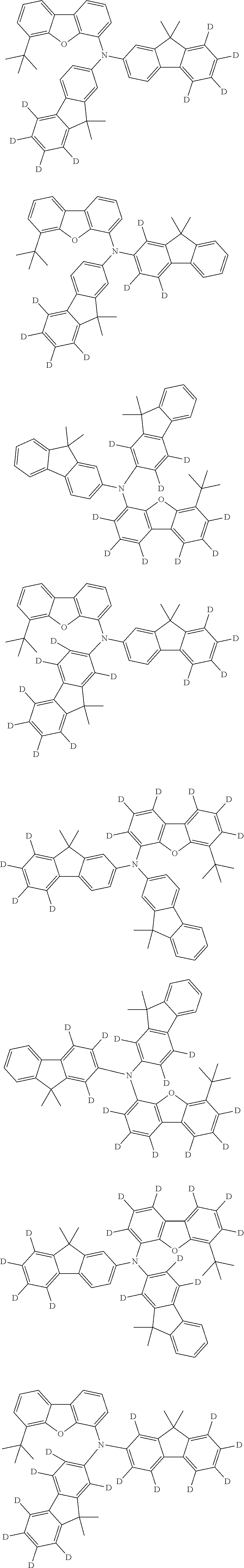

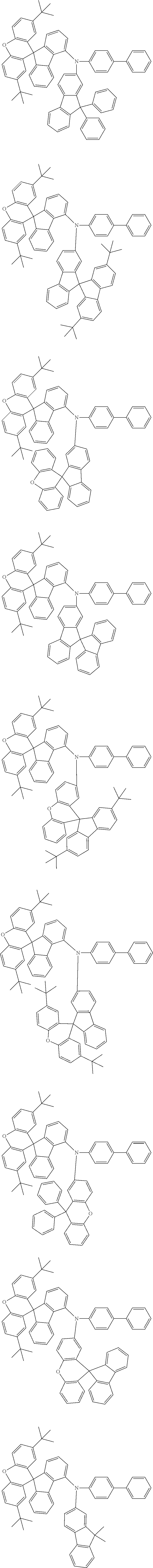

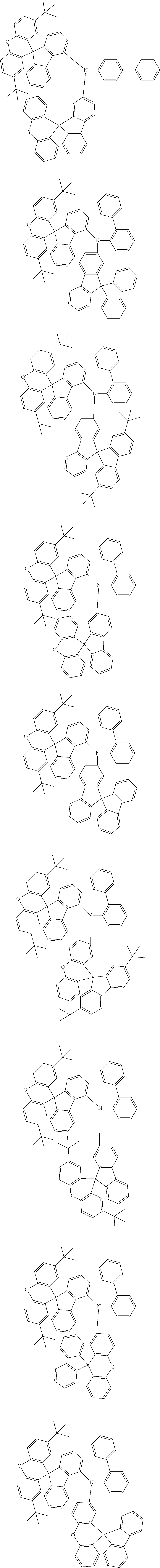

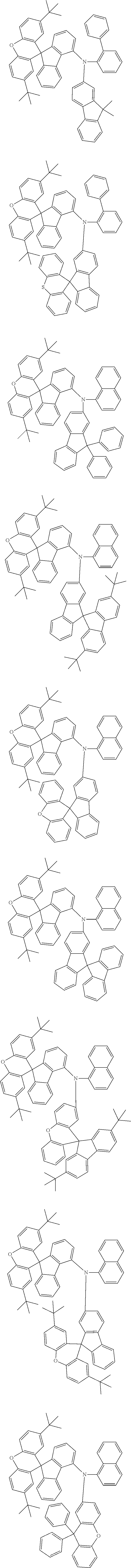

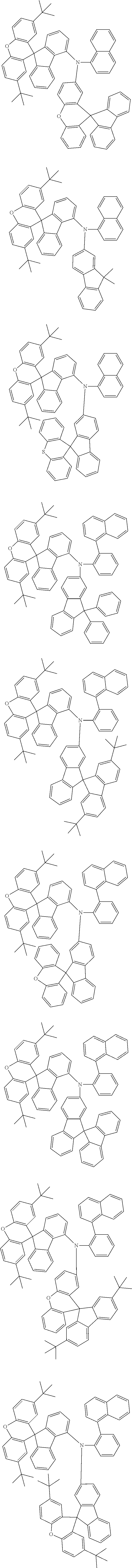

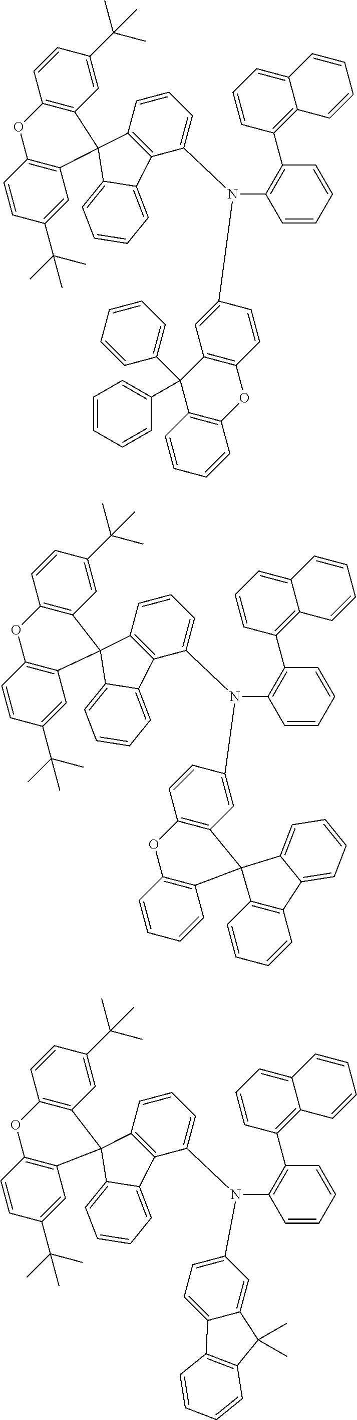 [SMILES: CC(C)(C)c1ccc2c(c1)C1(c3cc(C(C)(C)C)ccc3O2)c2ccccc2-c2c(N(c3ccc4c(c3)C(c3ccccc3)(c3ccccc3)c3ccccc3O4)c3ccccc3-c3cccc4ccccc34)cccc21 ; CC(C)(C)c1ccc2c(c1)C1(c3cc(C(C)(C)C)ccc3O2)c2ccccc2-c2c(N(c3ccc4c(c3)C3(c5ccccc5O4)c4ccccc4-c4ccccc43)c3ccccc3-c3cccc4ccccc34)cccc21 ; CC(C)(C)c1ccc2c(c1)C1(c3cc(C(C)(C)C)ccc3O2)c2ccccc2-c2c(N(c3ccc4c(c3)C(C)(C)c3ccccc3-4)c3ccccc3-c3cccc4ccccc34)cccc21]

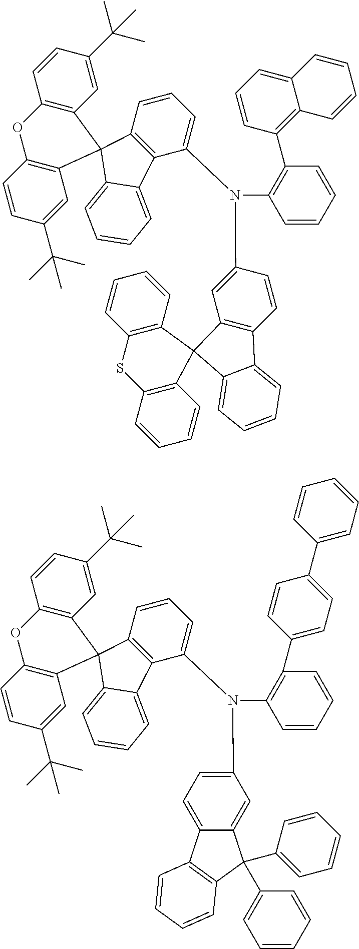 [SMILES: CC(C)(C)c1ccc2c(c1)C1(c3cc(C(C)(C)C)ccc3O2)c2ccccc2-c2c(N(c3ccc4c(c3)C3(c5ccccc5Sc5ccccc53)c3ccccc3-4)c3ccccc3-c3cccc4ccccc34)cccc21 ; CC(C)(C)c1ccc2c(c1)C1(c3cc(C(C)(C)C)ccc3O2)c2ccccc2-c2c(N(c3ccc4c(c3)C(c3ccccc3)(c3ccccc3)c3ccccc3-4)c3ccccc3-c3ccc(-c4ccccc4)cc3)cccc21]

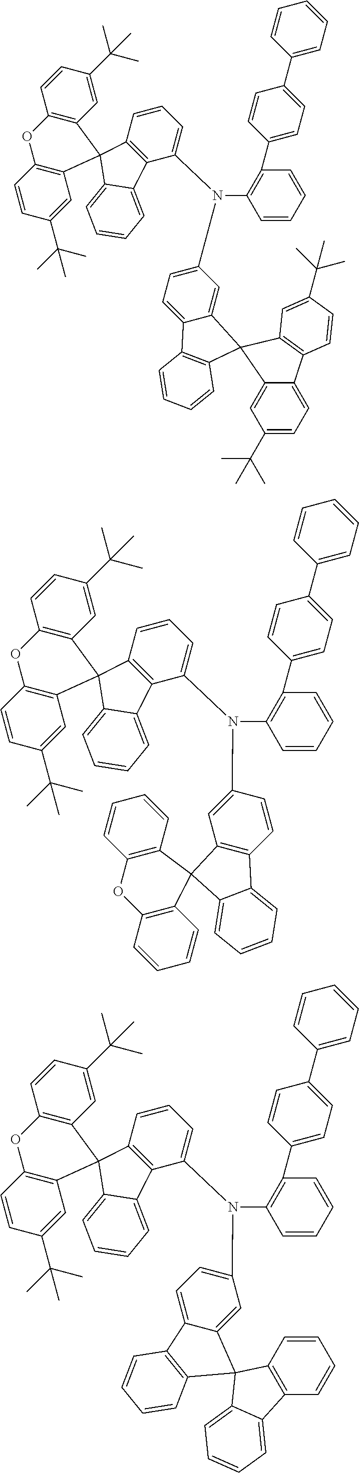

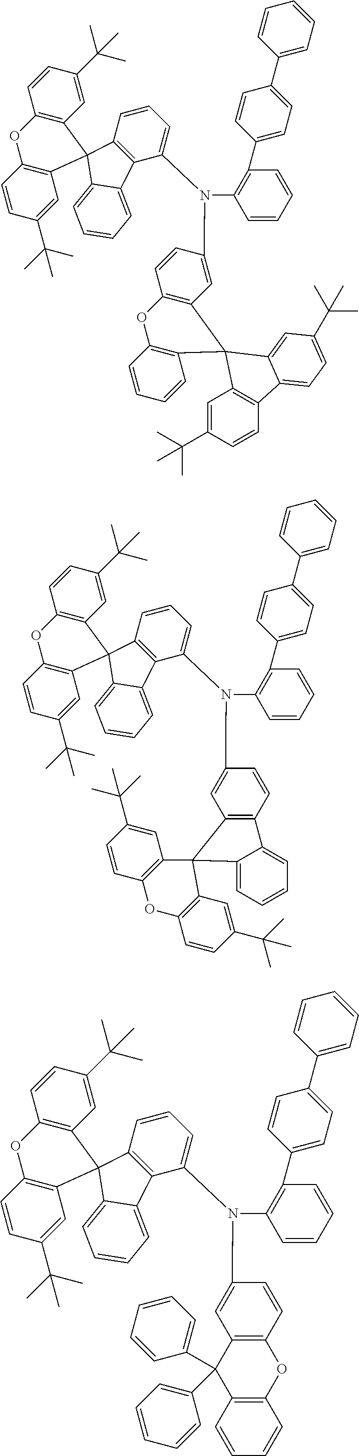 [SMILES: CC(C)(C)c1ccc2c(c1)C1(c3cc(C(C)(C)C)ccc3O2)c2ccccc2-c2c(N(c3ccc4c(c3)C3(c5ccccc5O4)c4cc(C(C)(C)C)ccc4-c4ccc(C(C)(C)C)cc43)c3ccccc3-c3ccc(-c4ccccc4)cc3)cccc21 ; CC(C)(C)c1ccc2c(c1)C1(c3cc(C(C)(C)C)ccc3O2)c2ccccc2-c2ccc(N(c3ccccc3-c3ccc(-c4ccccc4)cc3)c3cccc4c3-c3ccccc3C43c4cc(C(C)(C)C)ccc4Oc4ccc(C(C)(C)C)cc43)cc21 ; CC(C)(C)c1ccc2c(c1)C1(c3cc(C(C)(C)C)ccc3O2)c2ccccc2-c2c(N(c3ccc4c(c3)C(c3ccccc3)(c3ccccc3)c3ccccc3O4)c3ccccc3-c3ccc(-c4ccccc4)cc3)cccc21]

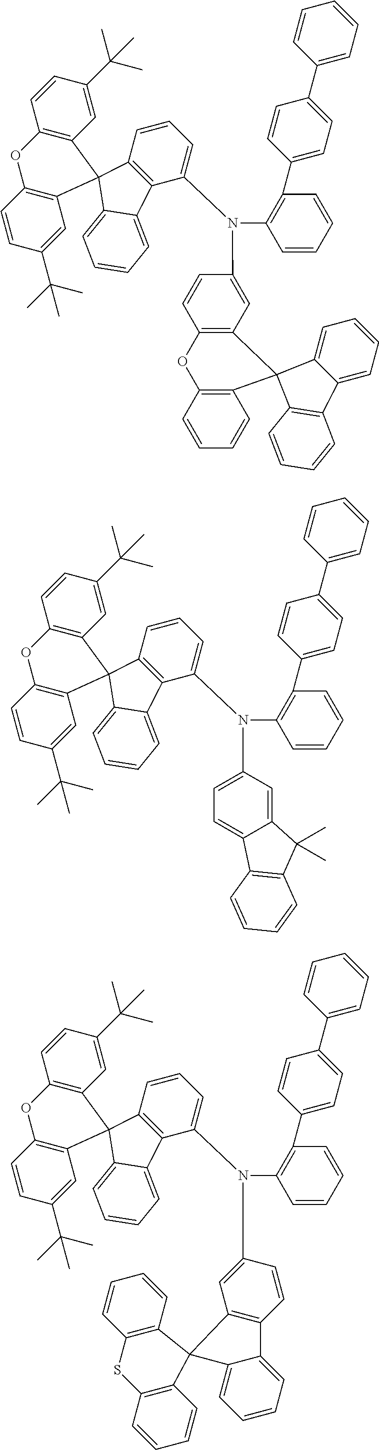

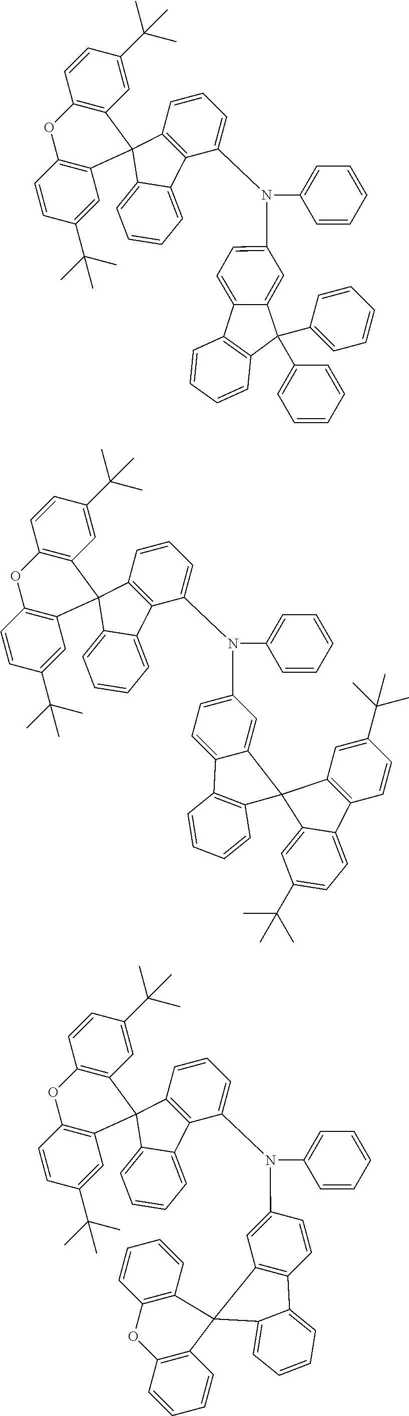 [SMILES: CC(C)(C)c1ccc2c(c1)C1(c3cc(C(C)(C)C)ccc3O2)c2ccccc2-c2c(N(c3ccccc3)c3ccc4c(c3)C(c3ccccc3)(c3ccccc3)c3ccccc3-4)cccc21 ; CC(C)(C)c1ccc2c(c1)C1(c3cc(C(C)(C)C)ccc3O2)c2ccccc2-c2c(N(c3ccccc3)c3ccc4c(c3)C3(c5ccccc5-4)c4cc(C(C)(C)C)ccc4-c4ccc(C(C)(C)C)cc43)cccc21 ; CC(C)(C)c1ccc2c(c1)C1(c3cc(C(C)(C)C)ccc3O2)c2ccccc2-c2c(N(c3ccccc3)c3ccc4c(c3)C3(c5ccccc5Oc5ccccc53)c3ccccc3-4)cccc21]

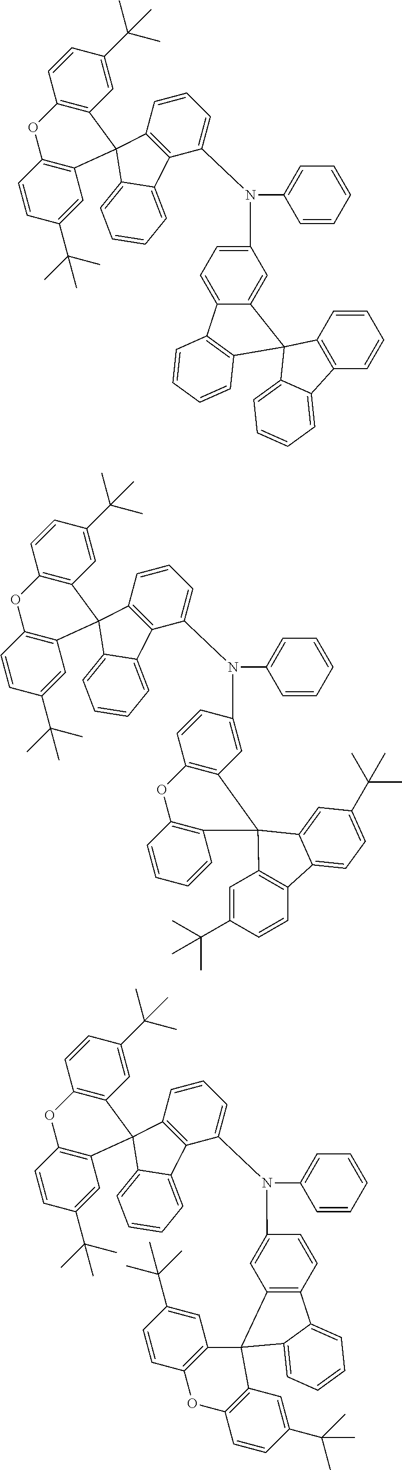

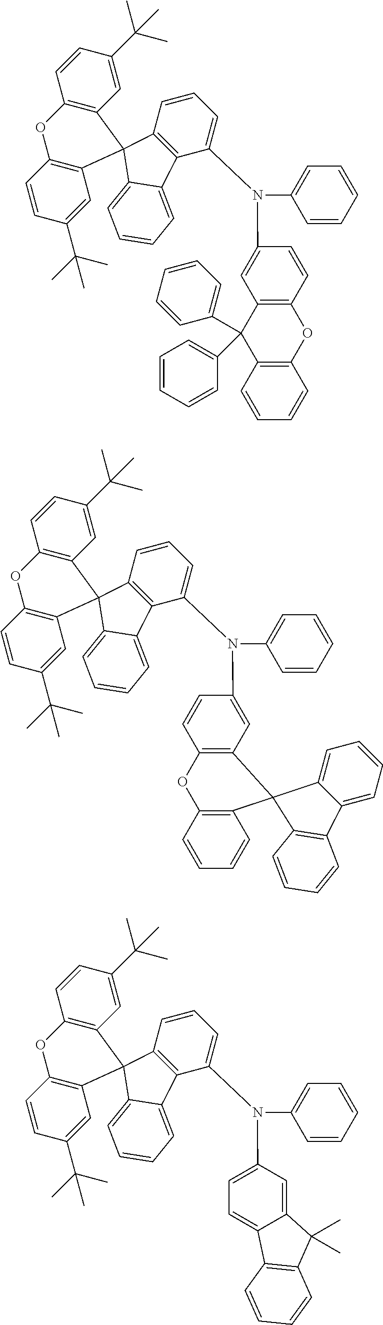 [SMILES: CC(C)(C)c1ccc2c(c1)C1(c3cc(C(C)(C)C)ccc3O2)c2ccccc2-c2c(N(c3ccccc3)c3ccc4c(c3)C(c3ccccc3)(c3ccccc3)c3ccccc3O4)cccc21 ; CC(C)(C)c1ccc2c(c1)C1(c3cc(C(C)(C)C)ccc3O2)c2ccccc2-c2c(N(c3ccccc3)c3ccc4c(c3)C3(c5ccccc5O4)c4ccccc4-c4ccccc43)cccc21 ; CC(C)(C)c1ccc2c(c1)C1(c3cc(C(C)(C)C)ccc3O2)c2ccccc2-c2c(N(c3ccccc3)c3ccc4c(c3)C(C)(C)c3ccccc3-4)cccc21]

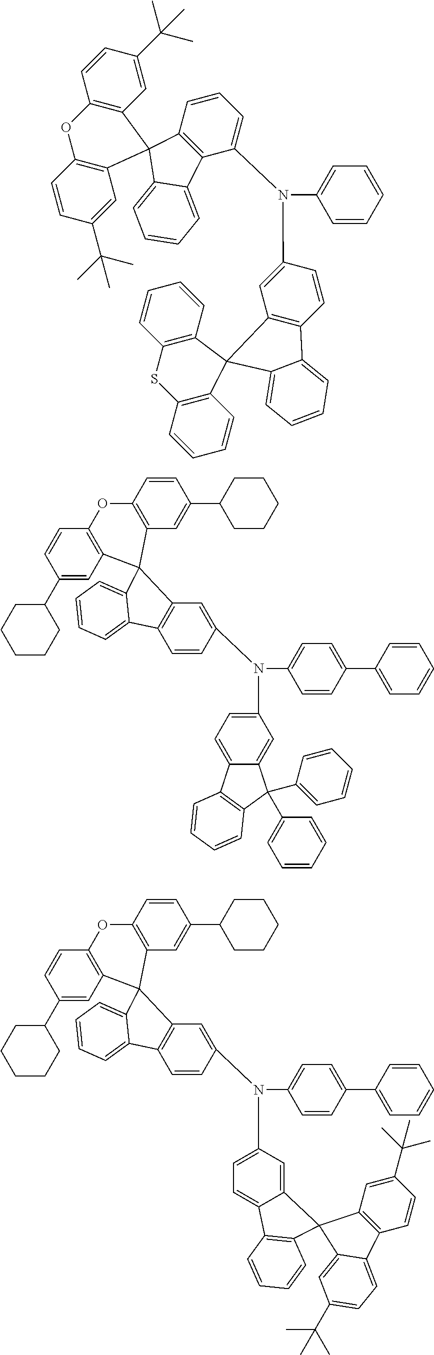

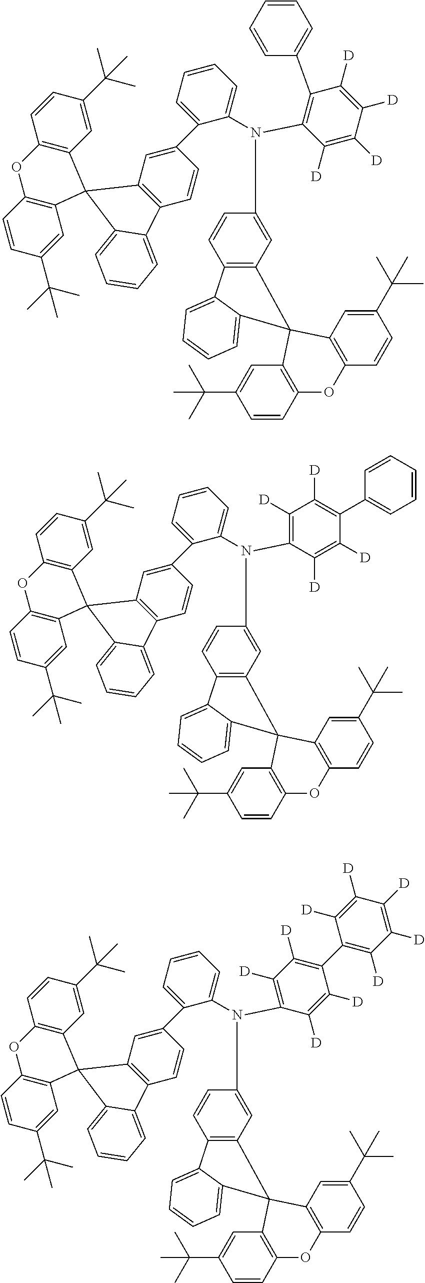

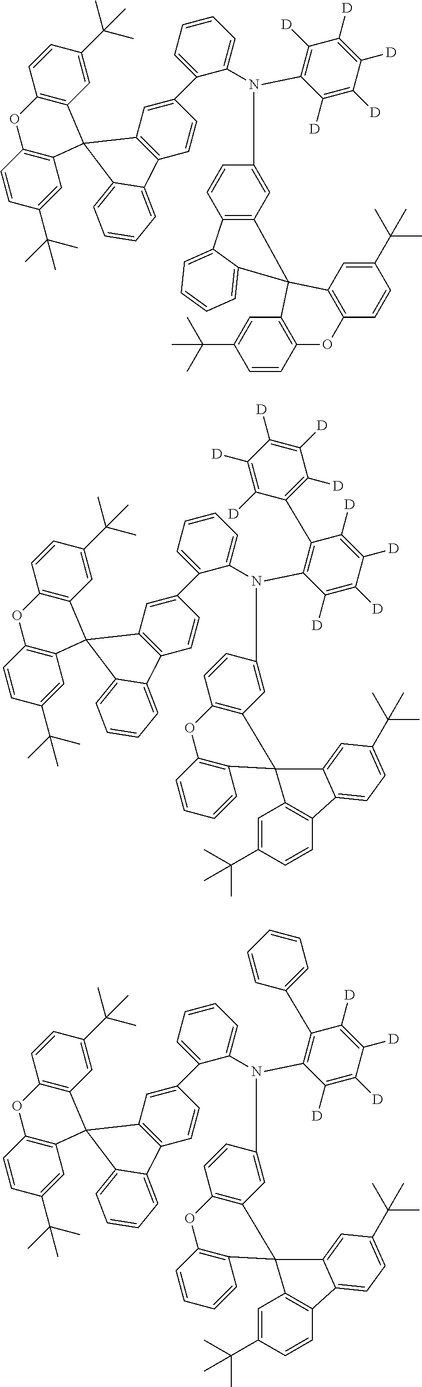

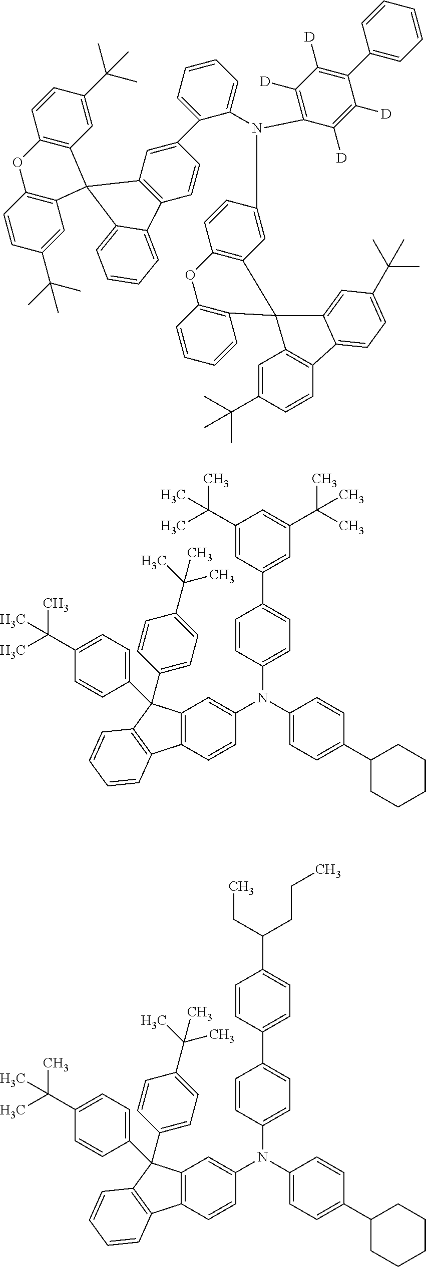

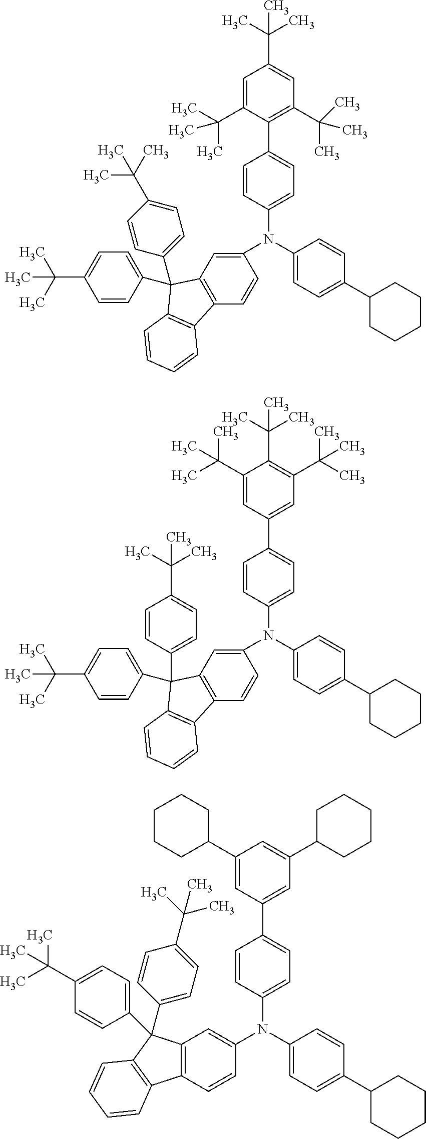

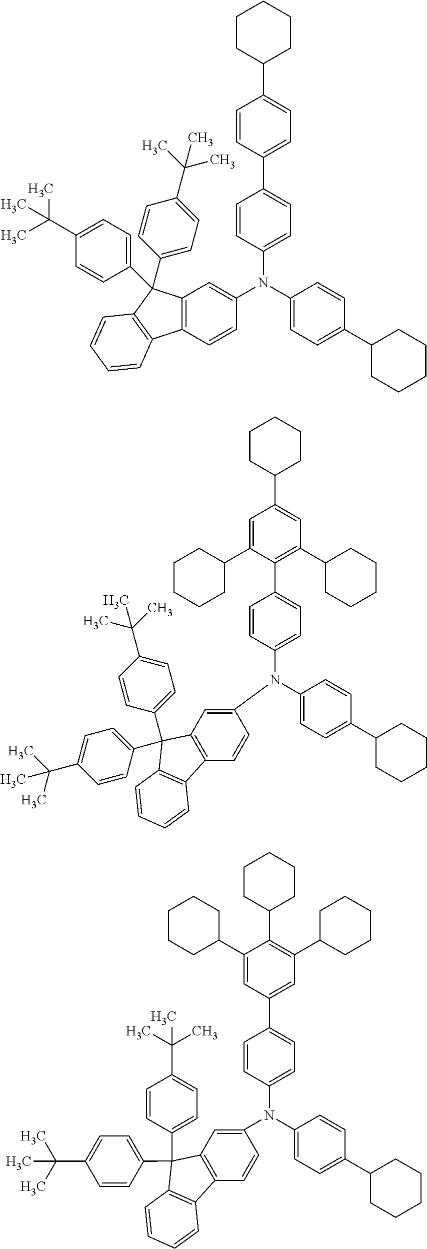 [SMILES: CC(C)(C)c1ccc(C2(c3ccc(C(C)(C)C)cc3)c3ccccc3-c3ccc(N(c4ccc(-c5ccc(C6CCCCC6)cc5)cc4)c4ccc(C5CCCCC5)cc4)cc32)cc1 ; CC(C)(C)c1ccc(C2(c3ccc(C(C)(C)C)cc3)c3ccccc3-c3ccc(N(c4ccc(-c5c(C6CCCCC6)cc(C6CCCCC6)cc5C5CCCCC5)cc4)c4ccc(C5CCCCC5)cc4)cc32)cc1 ; CC(C)(C)c1ccc(C2(c3ccc(C(C)(C)C)cc3)c3ccccc3-c3ccc(N(c4ccc(-c5cc(C6CCCCC6)c(C6CCCCC6)c(C6CCCCC6)c5)cc4)c4ccc(C5CCCCC5)cc4)cc32)cc1]

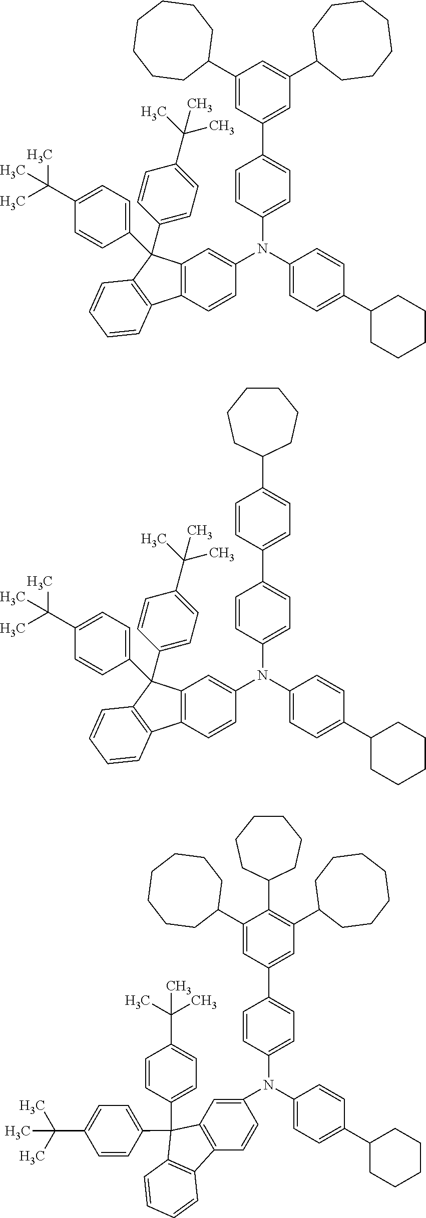 [SMILES: CC(C)(C)c1ccc(C2(c3ccc(C(C)(C)C)cc3)c3ccccc3-c3ccc(N(c4ccc(-c5cc(C6CCCCCCC6)cc(C6CCCCCCC6)c5)cc4)c4ccc(C5CCCCC5)cc4)cc32)cc1 ; CC(C)(C)c1ccc(C2(c3ccc(C(C)(C)C)cc3)c3ccccc3-c3ccc(N(c4ccc(-c5ccc(C6CCCCCC6)cc5)cc4)c4ccc(C5CCCCC5)cc4)cc32)cc1 ; CC(C)(C)c1ccc(C2(c3ccc(C(C)(C)C)cc3)c3ccccc3-c3ccc(N(c4ccc(-c5cc(C6CCCCCCC6)c(C6CCCCCC6)c(C6CCCCCCC6)c5)cc4)c4ccc(C5CCCCC5)cc4)cc32)cc1]

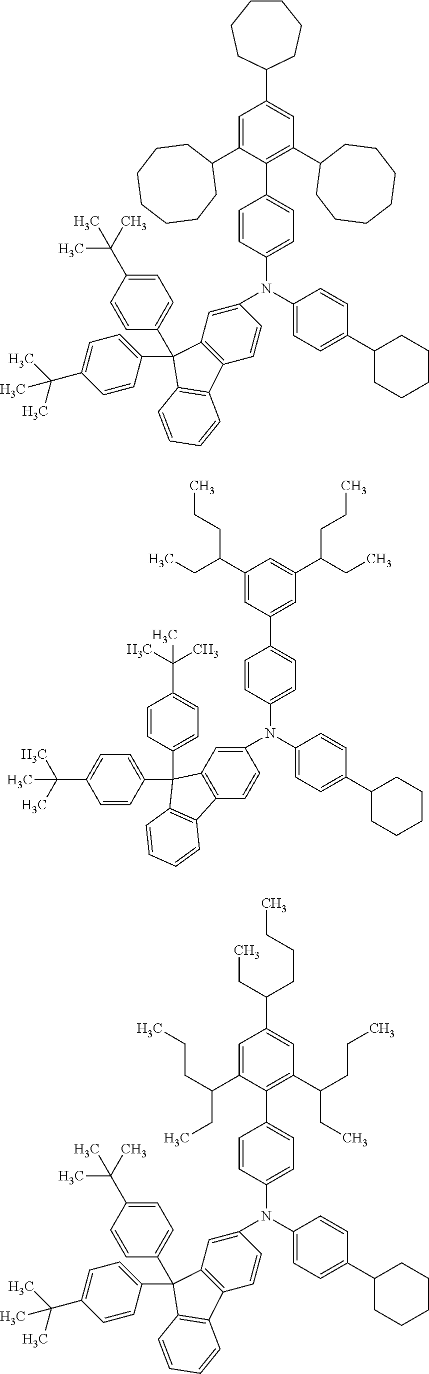

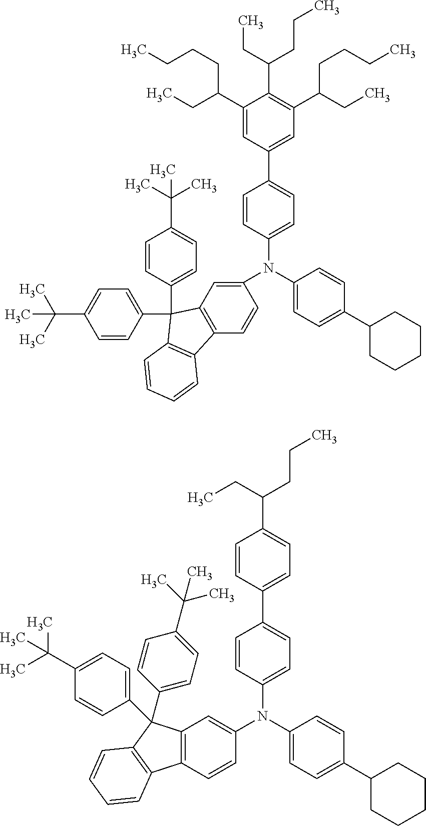 [SMILES: CCCCC(CC)c1cc(-c2ccc(N(c3ccc(C4CCCCC4)cc3)c3ccc4c(c3)C(c3ccc(C(C)(C)C)cc3)(c3ccc(C(C)(C)C)cc3)c3ccccc3-4)cc2)cc(C(CC)CCCC)c1C(CC)CCC ; CCCC(CC)c1ccc(-c2ccc(N(c3ccc(C4CCCCC4)cc3)c3ccc4c(c3)C(c3ccc(C(C)(C)C)cc3)(c3ccc(C(C)(C)C)cc3)c3ccccc3-4)cc2)cc1]

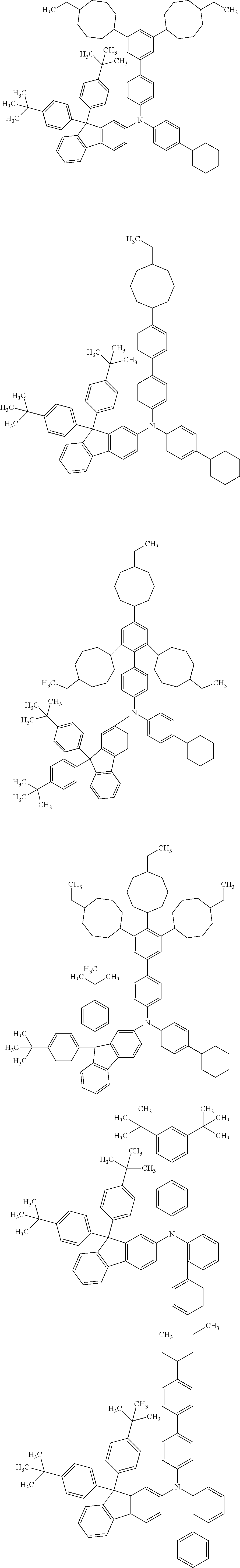

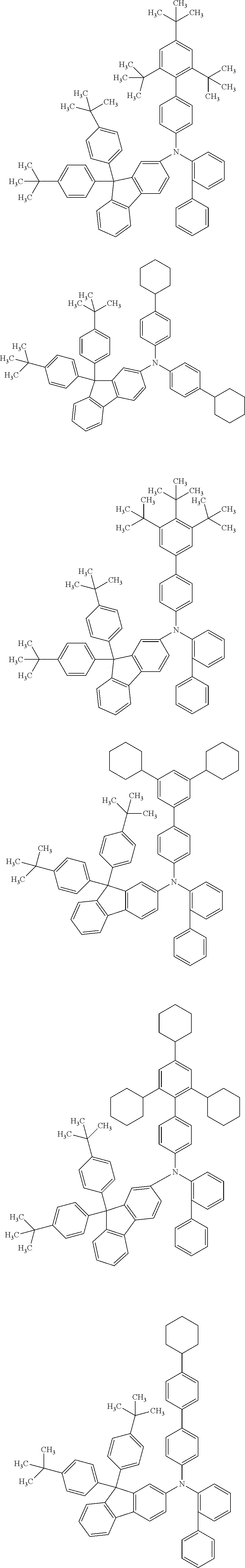

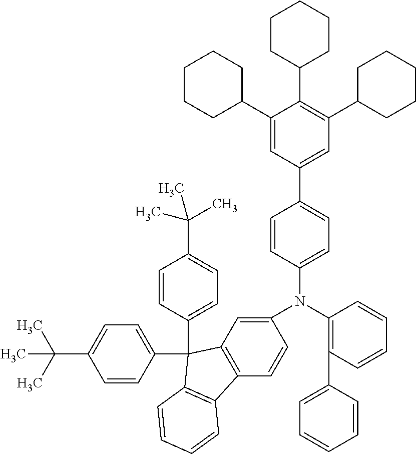 [SMILES: CC(C)(C)c1ccc(C2(c3ccc(C(C)(C)C)cc3)c3ccccc3-c3ccc(N(c4ccc(-c5cc(C6CCCCC6)c(C6CCCCC6)c(C6CCCCC6)c5)cc4)c4ccccc4-c4ccccc4)cc32)cc1]

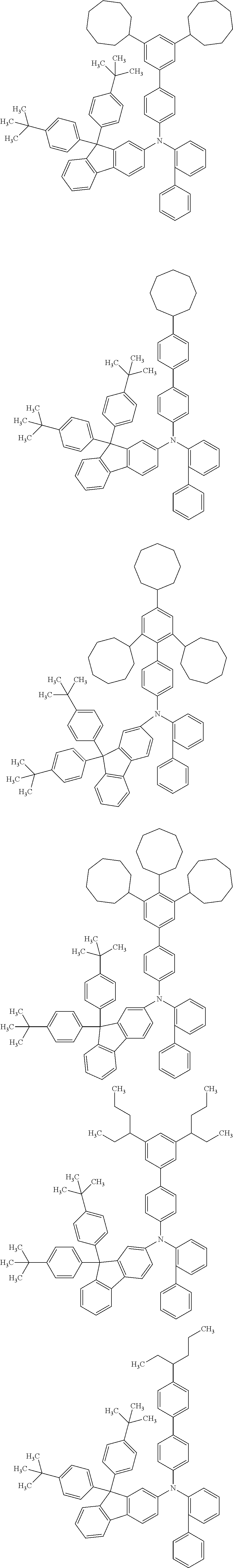

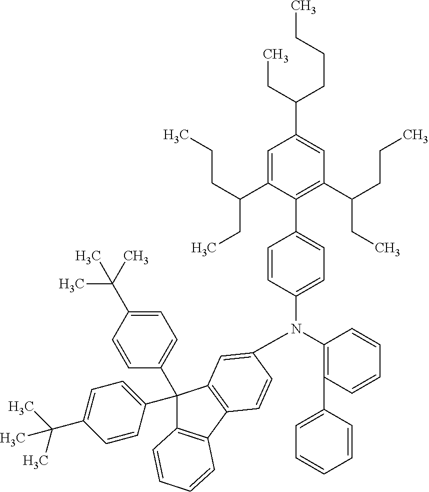 [SMILES: CCCCC(CC)c1cc(C(CC)CCC)c(-c2ccc(N(c3ccc4c(c3)C(c3ccc(C(C)(C)C)cc3)(c3ccc(C(C)(C)C)cc3)c3ccccc3-4)c3ccccc3-c3ccccc3)cc2)c(C(CC)CCC)c1]

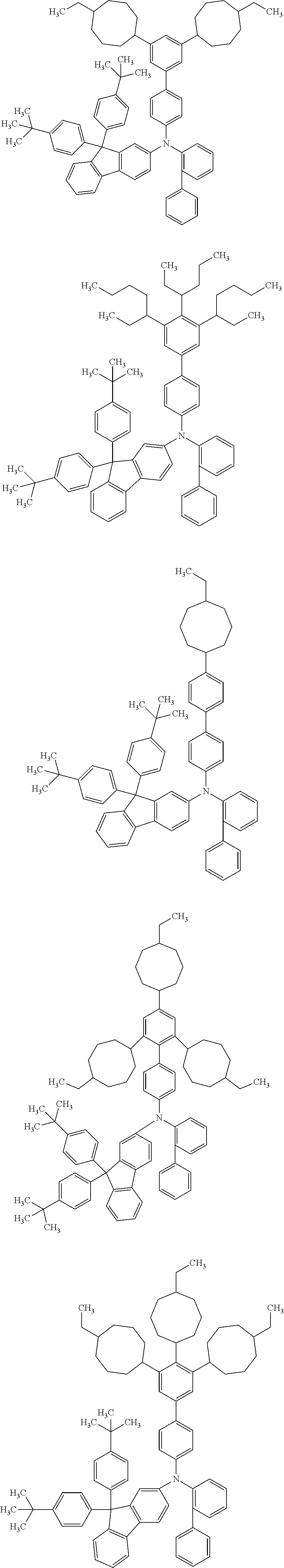

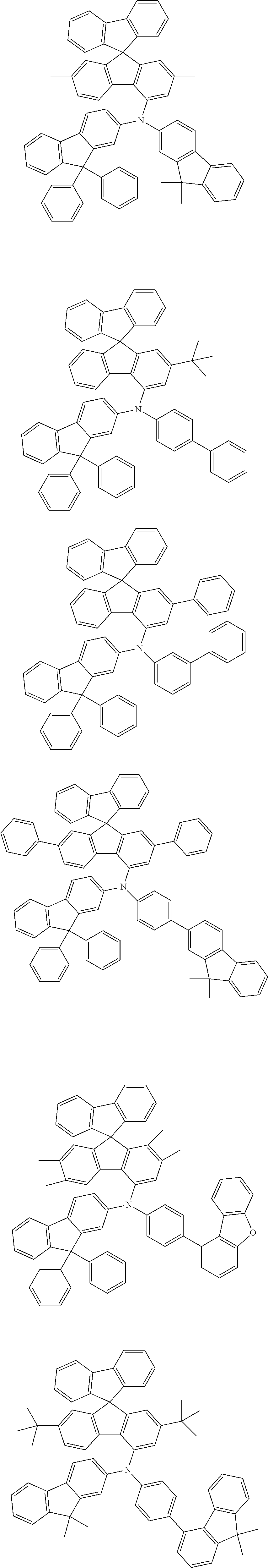

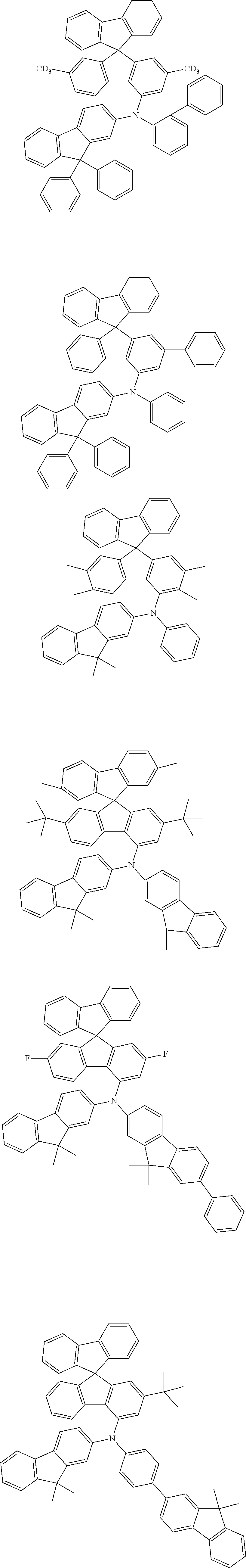

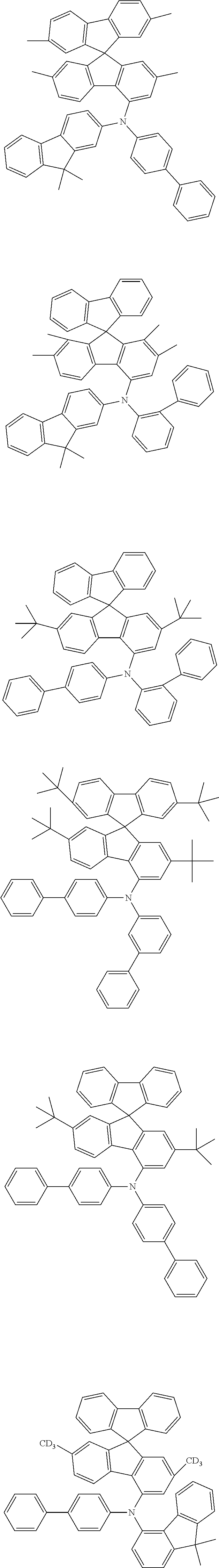

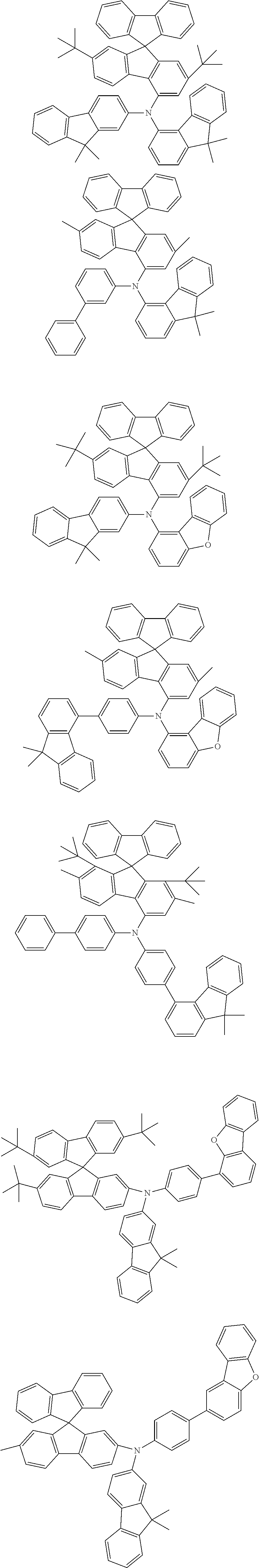

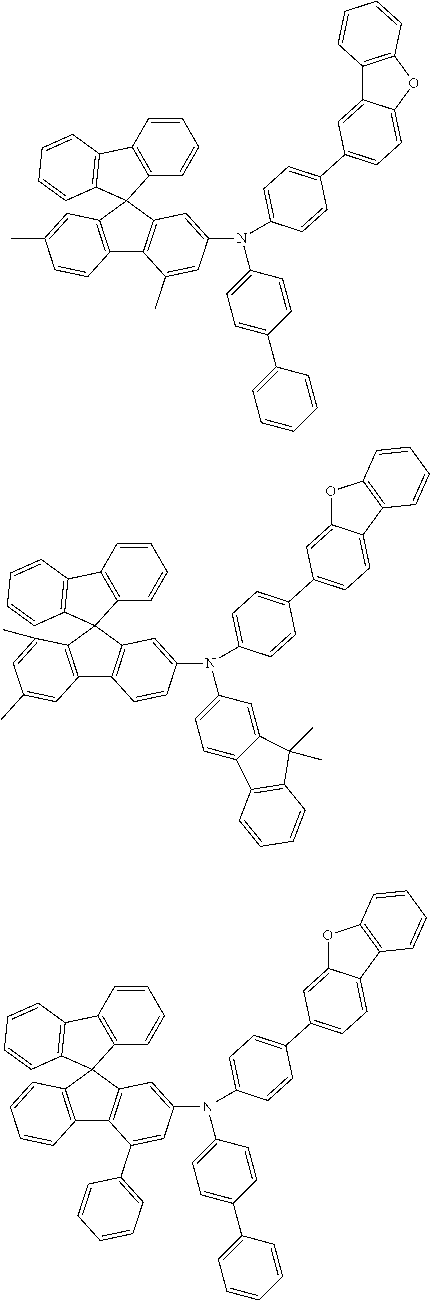 [SMILES: Cc1ccc2c(c1)C1(c3ccccc3-c3ccccc31)c1cc(N(c3ccc(-c4ccccc4)cc3)c3ccc(-c4ccc5oc6ccccc6c5c4)cc3)cc(C)c1-2 ; Cc1cc(C)c2c(c1)-c1ccc(N(c3ccc(-c4ccc5c(c4)oc4ccccc45)cc3)c3ccc4c(c3)C(C)(C)c3ccccc3-4)cc1C21c2ccccc2-c2ccccc21 ; c1ccc(-c2ccc(N(c3ccc(-c4ccc5c(c4)oc4ccccc45)cc3)c3cc(-c4ccccc4)c4c(c3)C3(c5ccccc5-c5ccccc53)c3ccccc3-4)cc2)cc1]

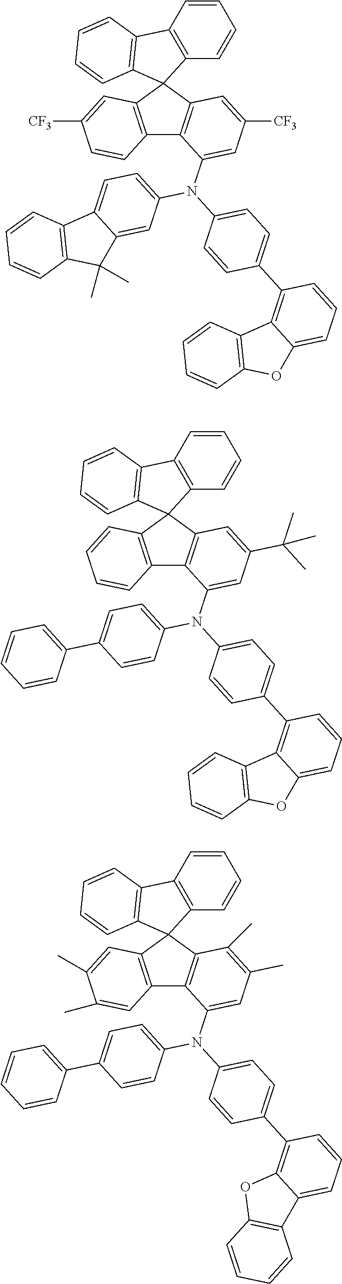

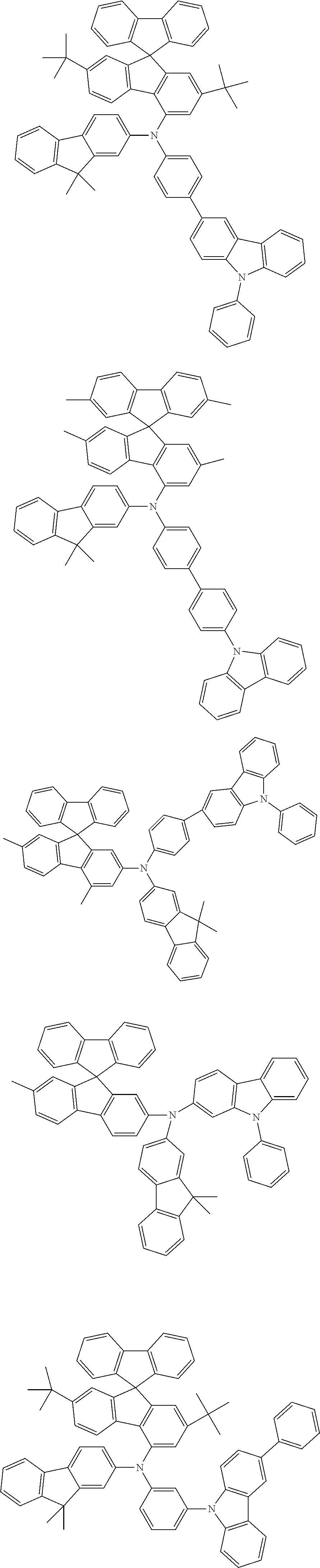

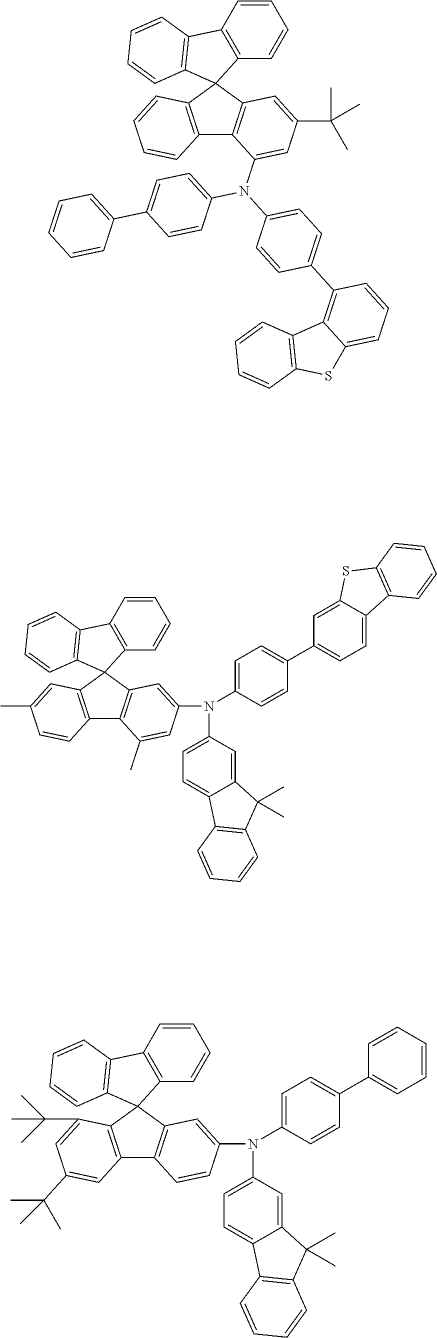 [SMILES: CC(C)(C)c1cc(N(c2ccc(-c3ccccc3)cc2)c2ccc(-c3cccc4sc5ccccc5c34)cc2)c2c(c1)C1(c3ccccc3-c3ccccc31)c1ccccc1-2 ; Cc1ccc2c(c1)C1(c3ccccc3-c3ccccc31)c1cc(N(c3ccc(-c4ccc5c(c4)sc4ccccc45)cc3)c3ccc4c(c3)C(C)(C)c3ccccc3-4)cc(C)c1-2 ; CC(C)(C)c1cc2c(c(C(C)(C)C)c1)C1(c3ccccc3-c3ccccc31)c1cc(N(c3ccc(-c4ccccc4)cc3)c3ccc4c(c3)C(C)(C)c3ccccc3-4)ccc1-2]

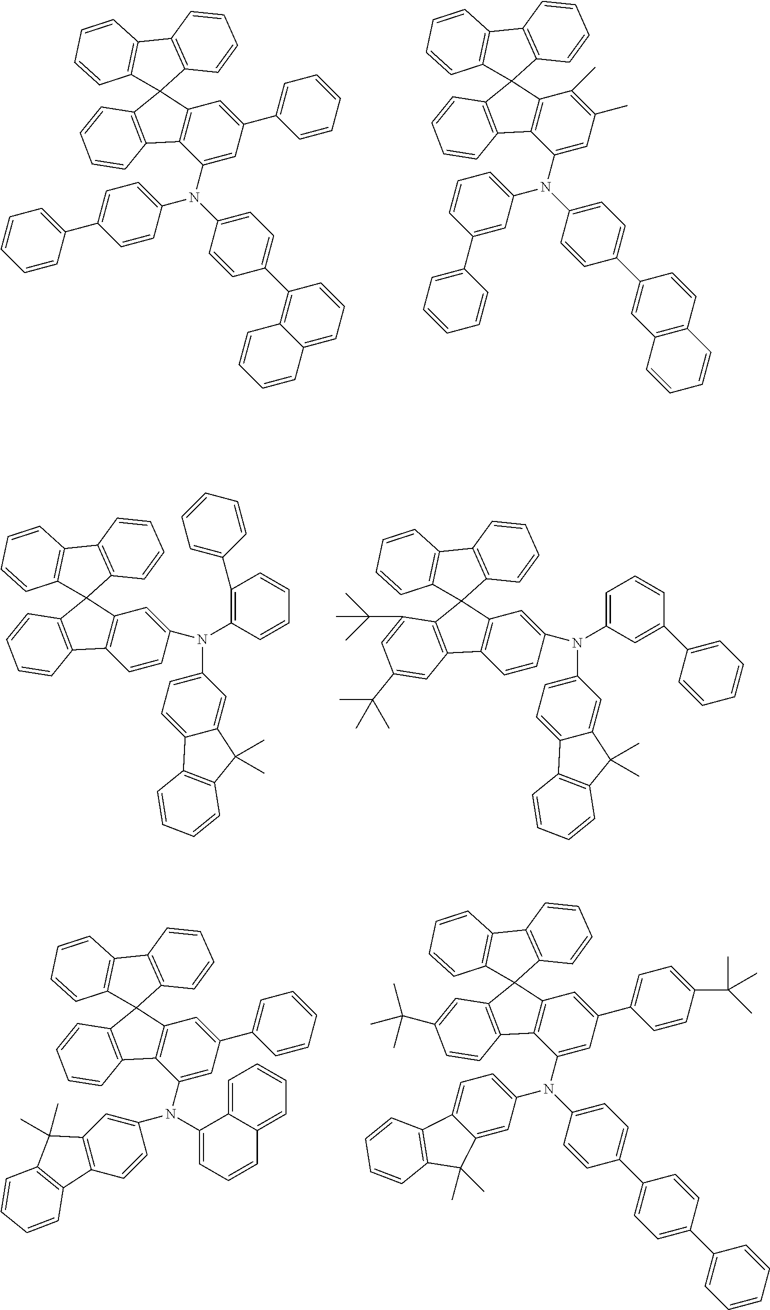

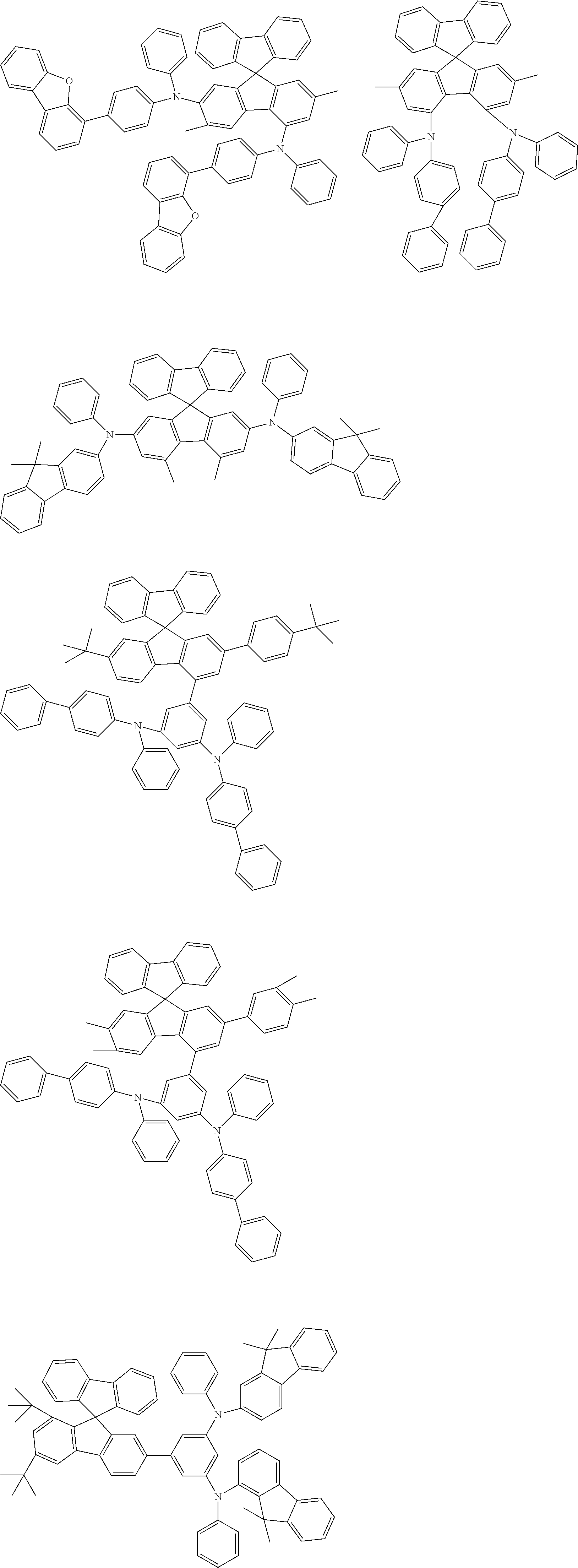

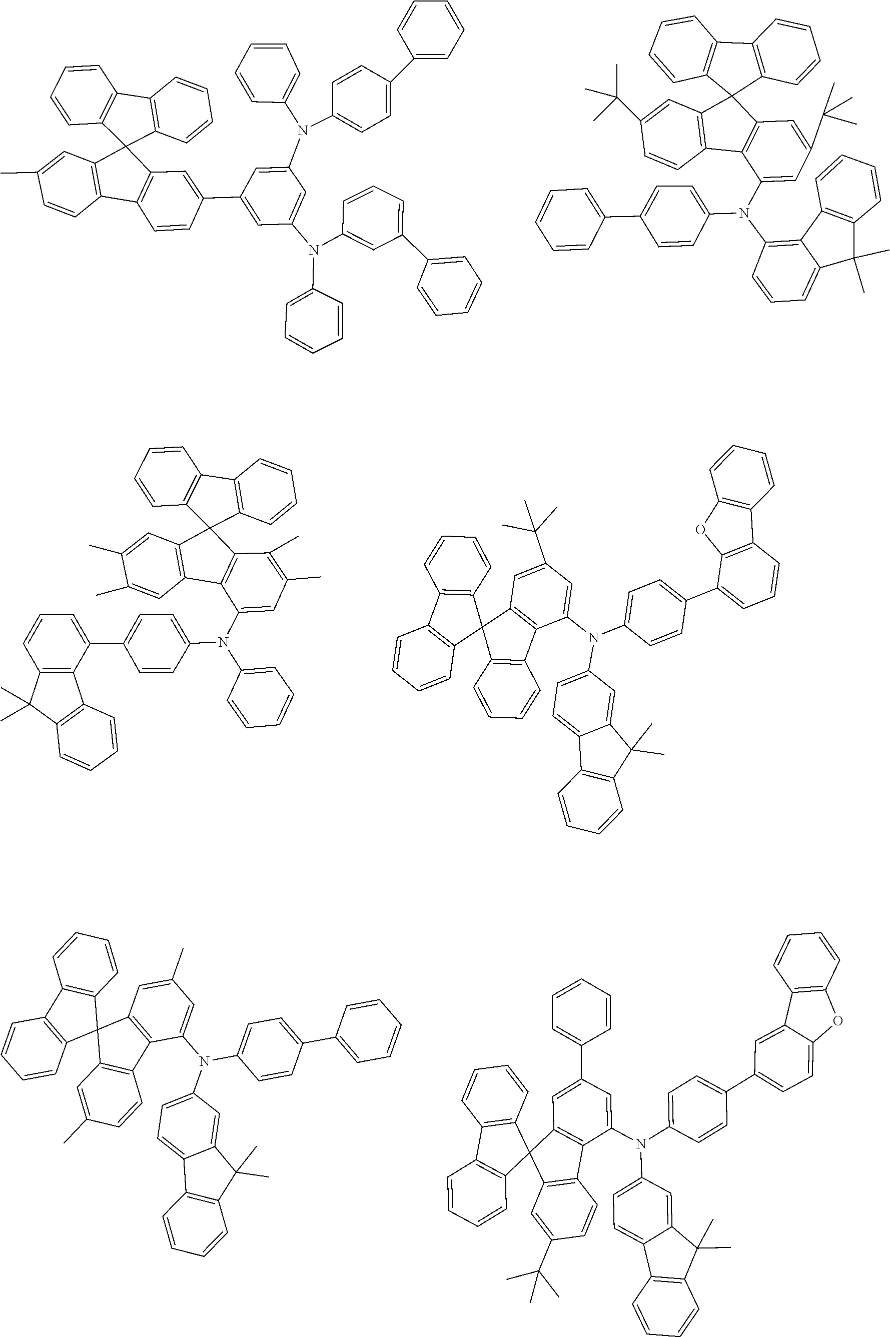

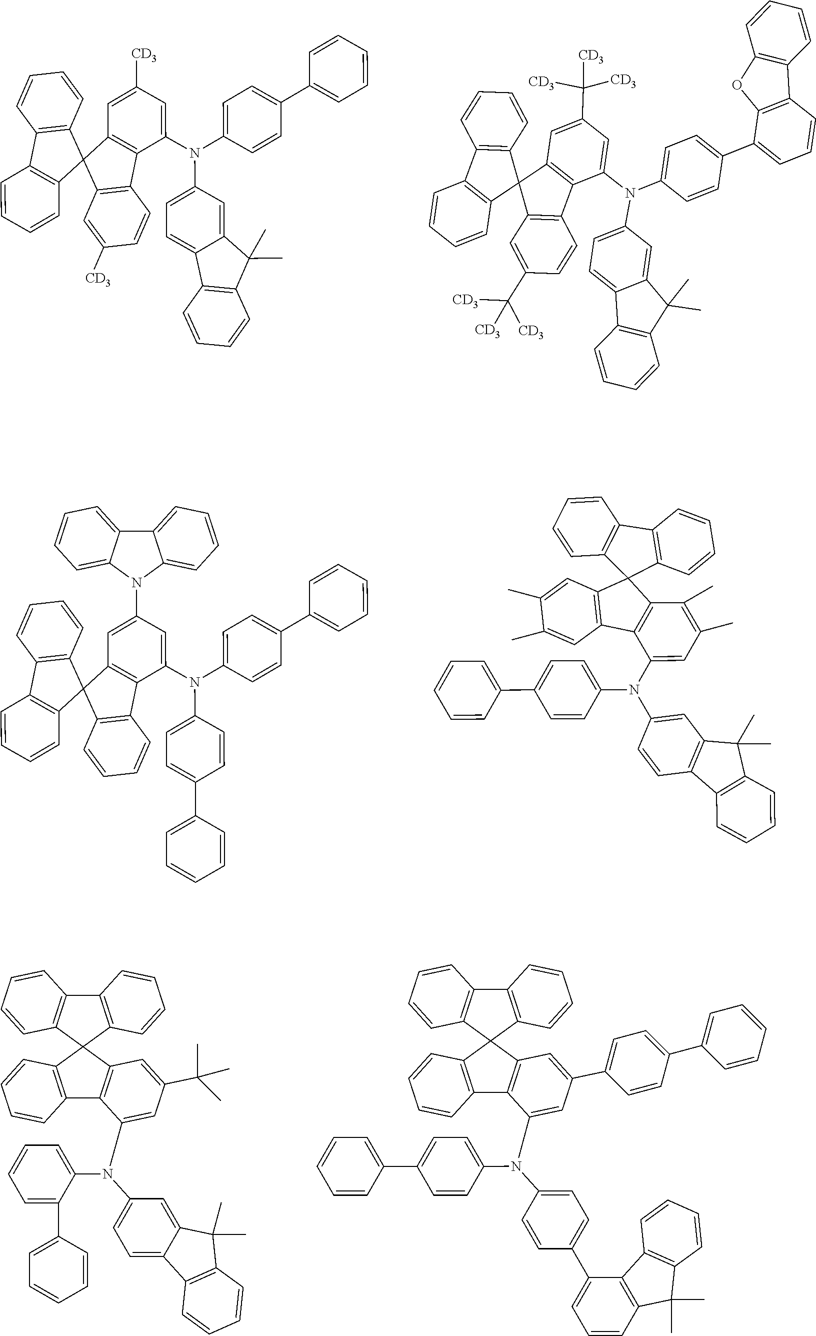

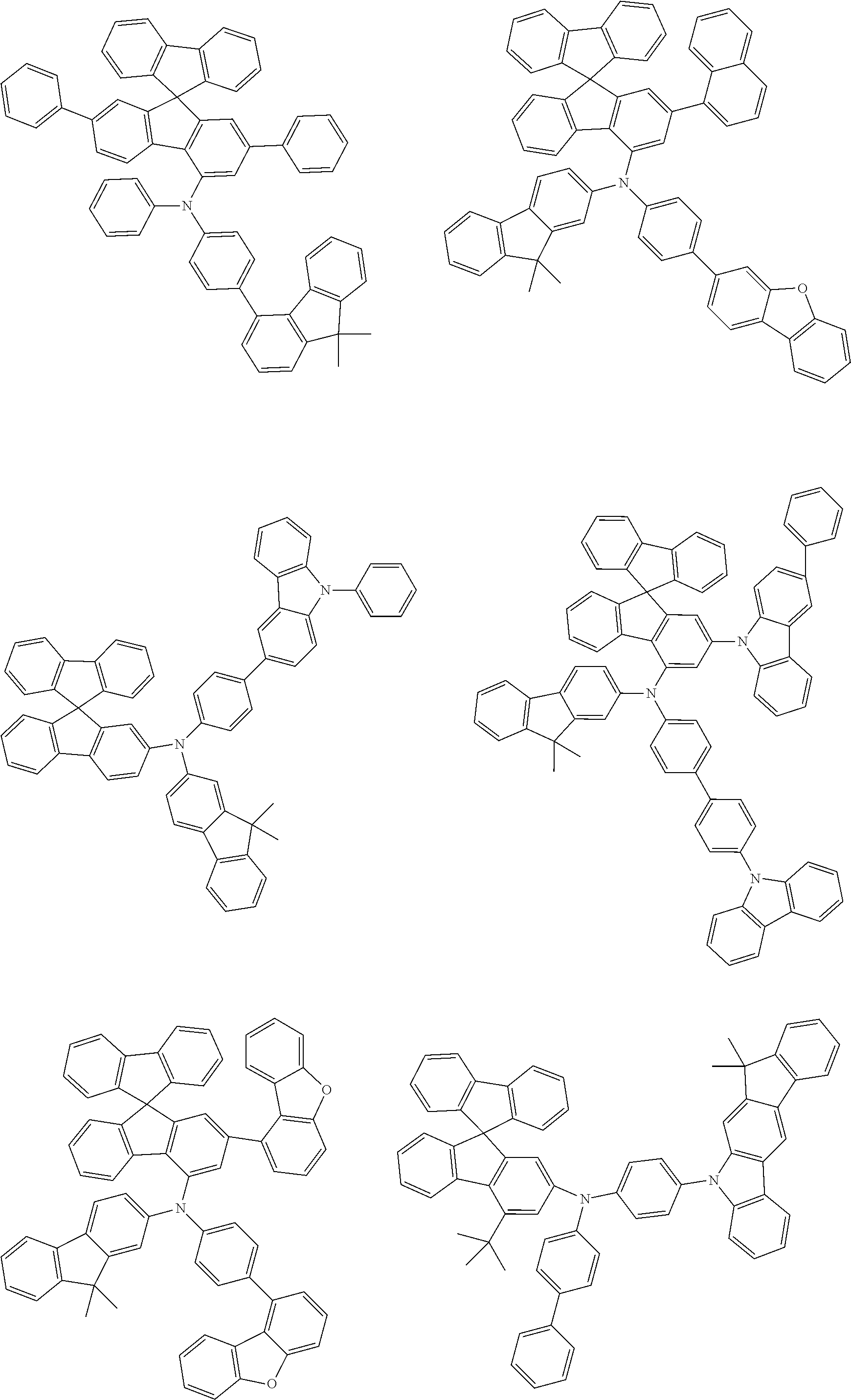

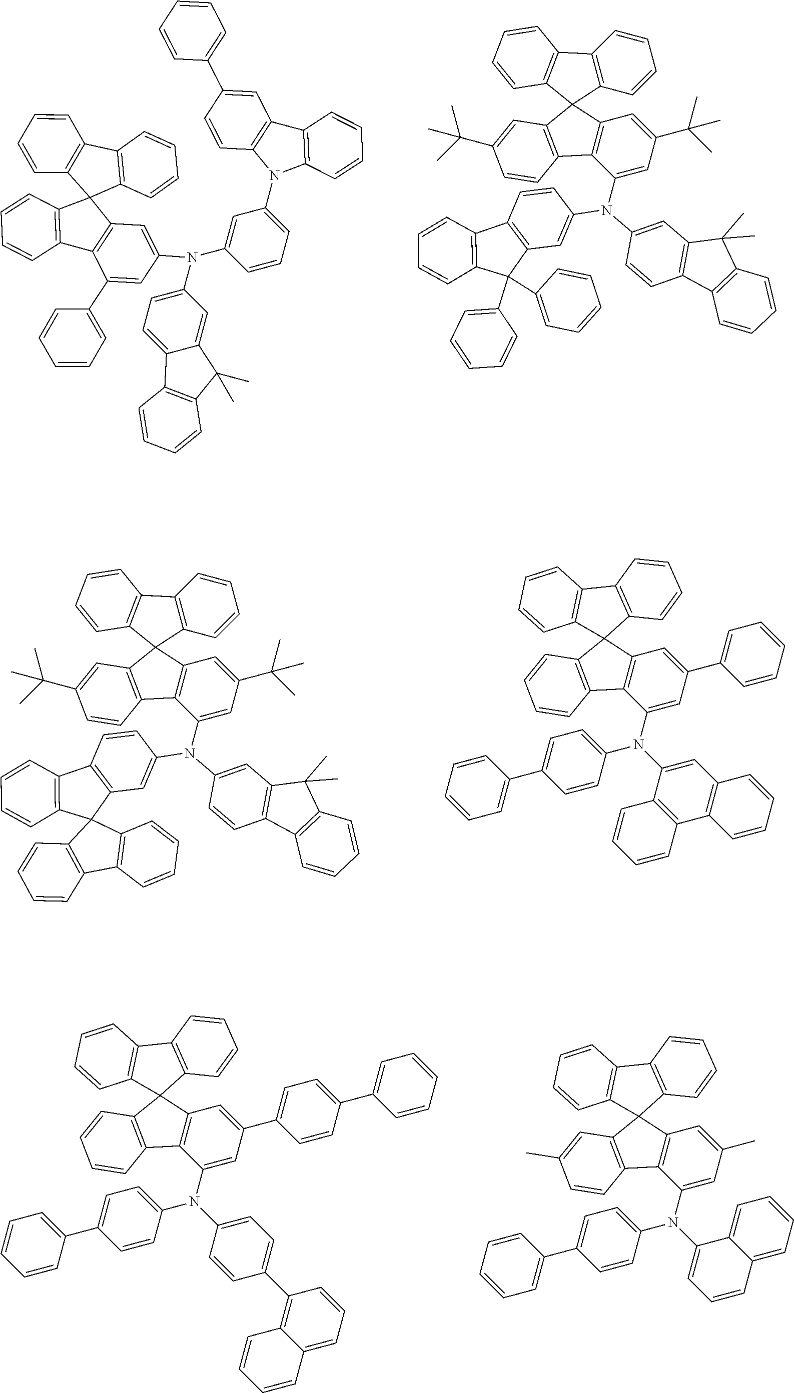

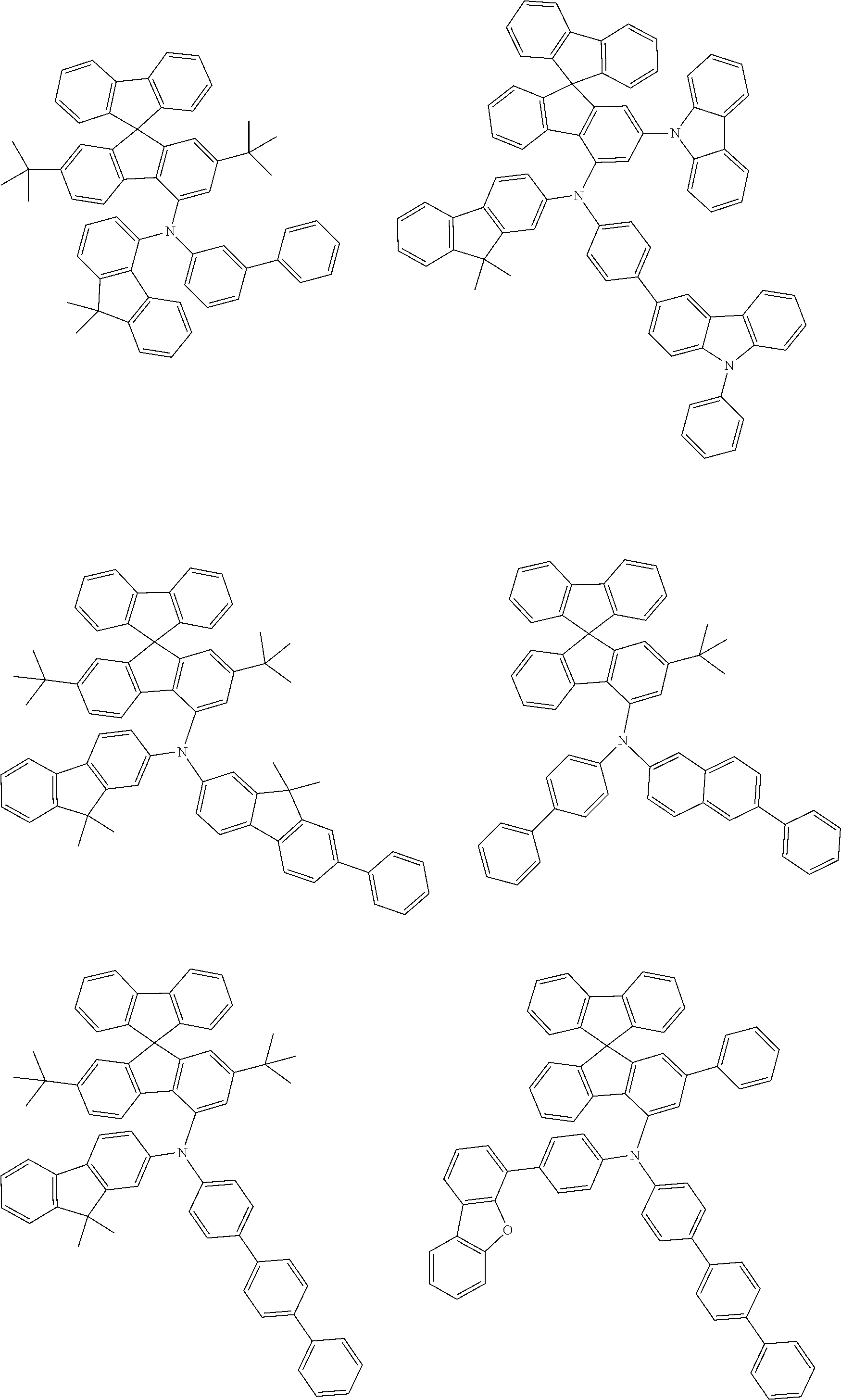

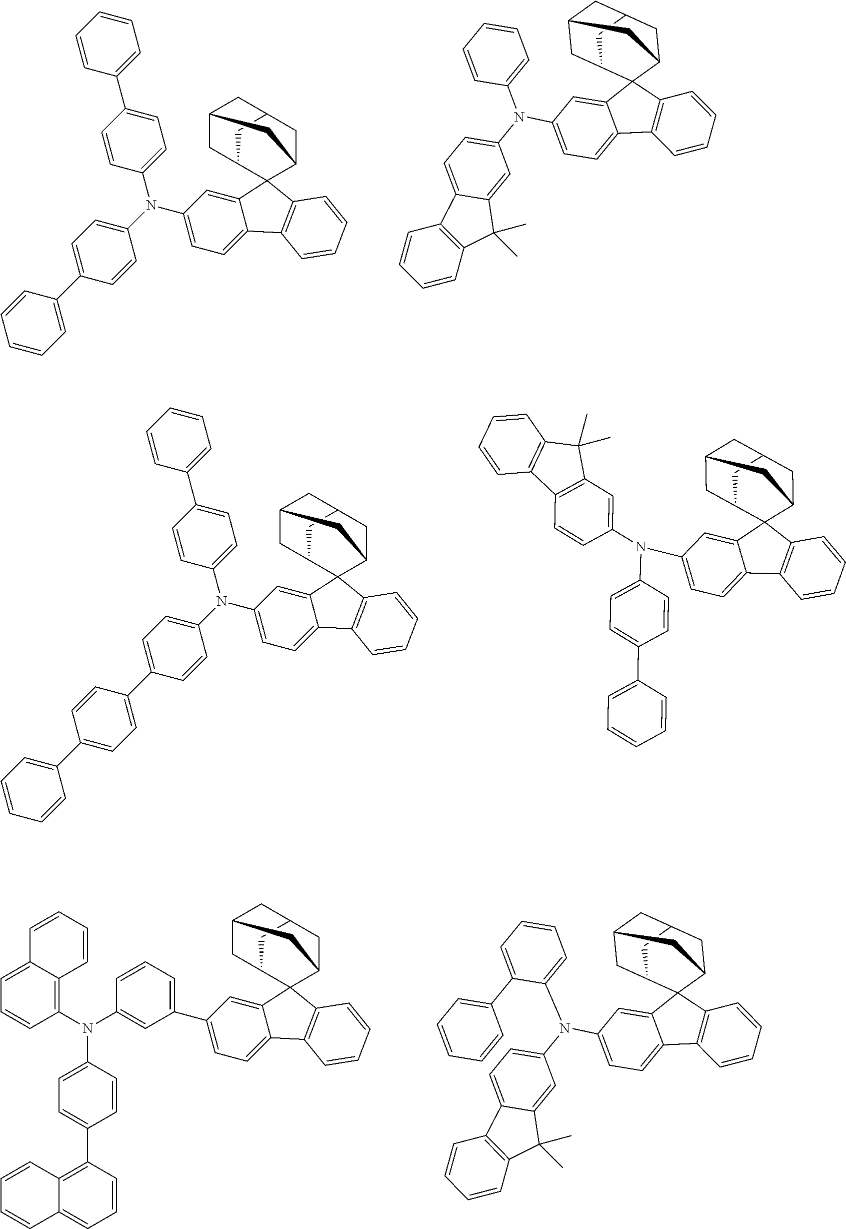

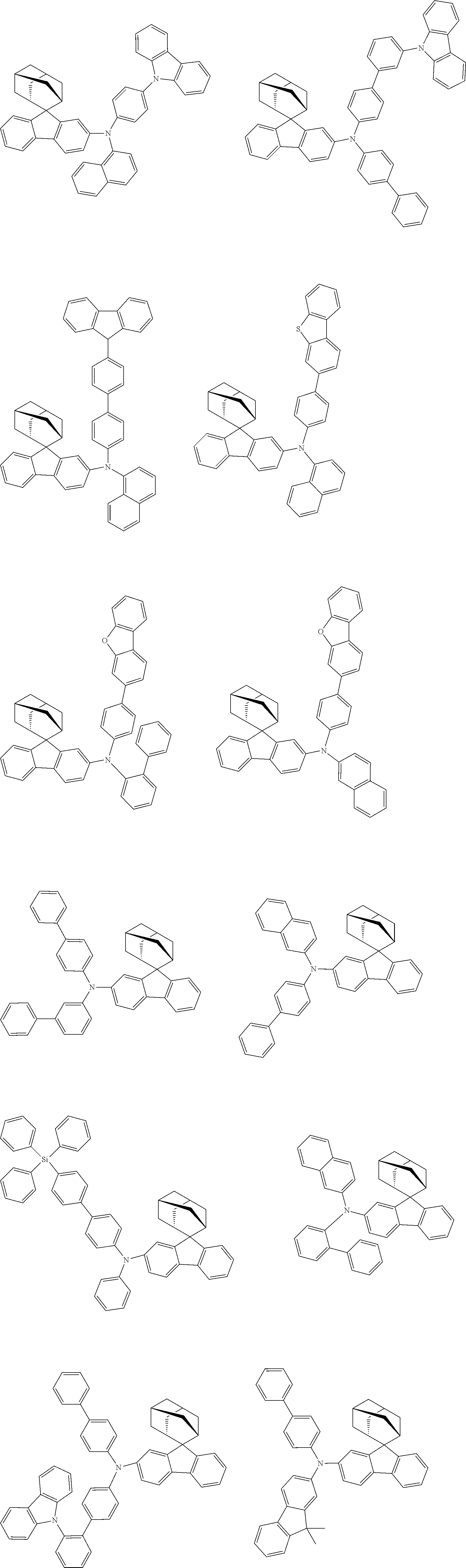

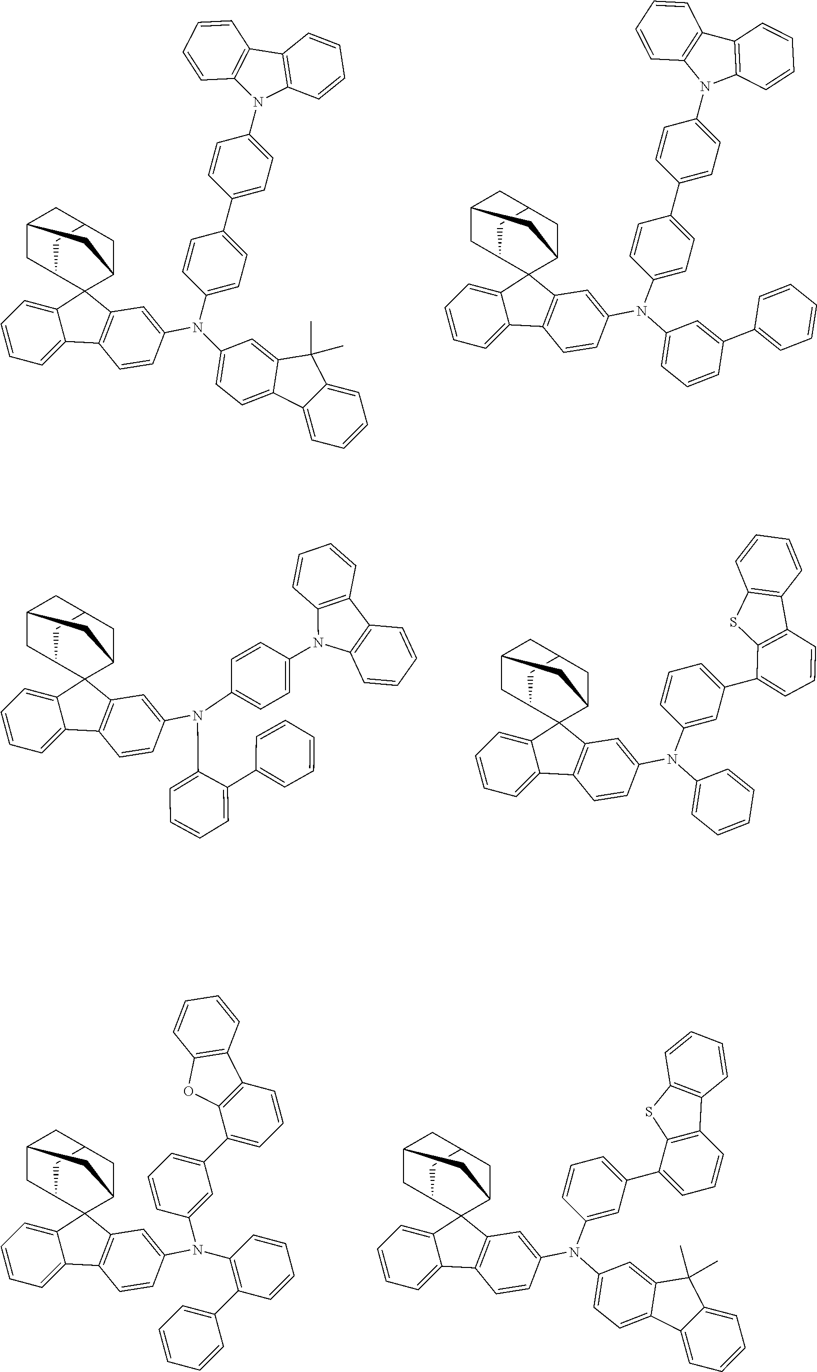

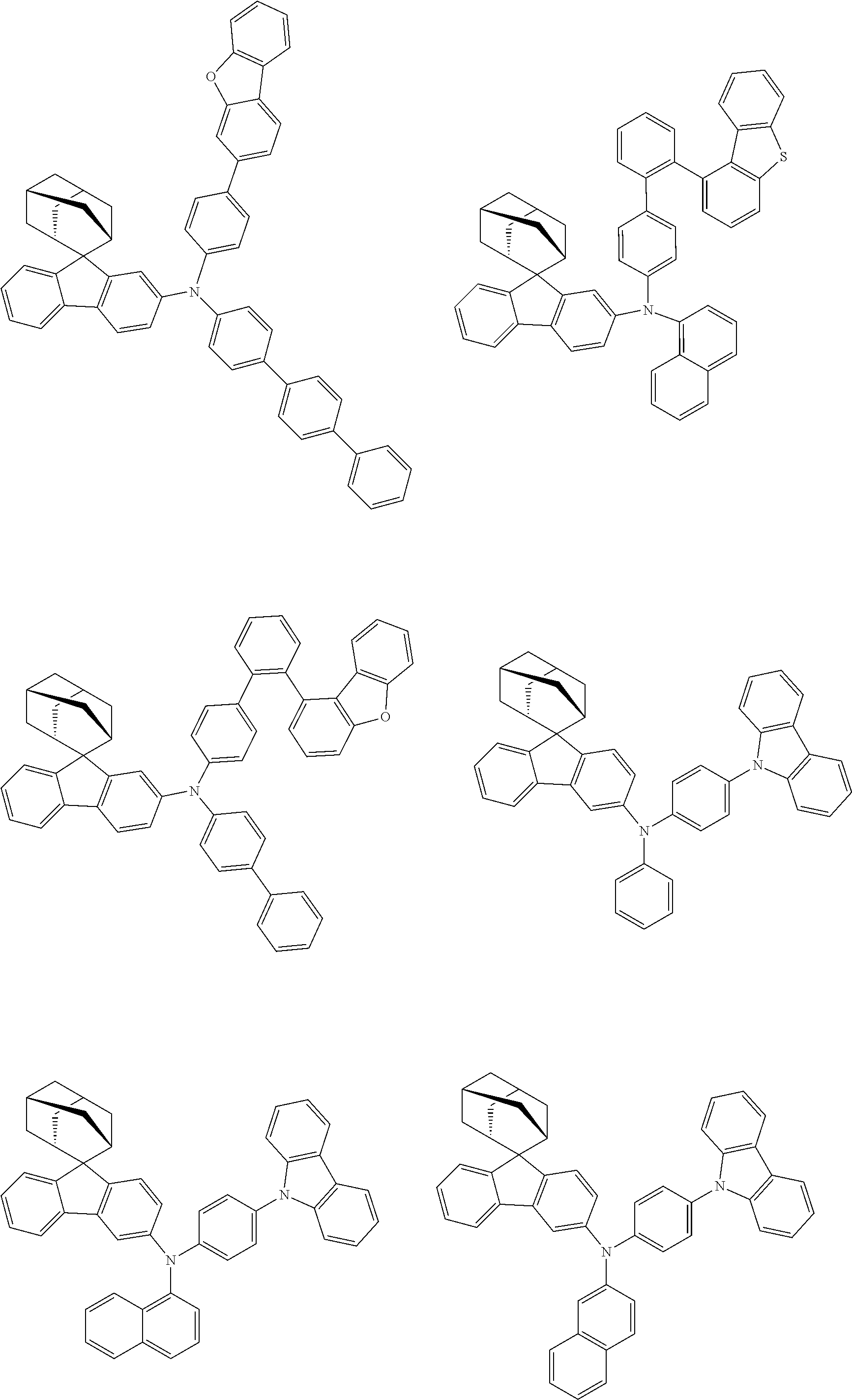

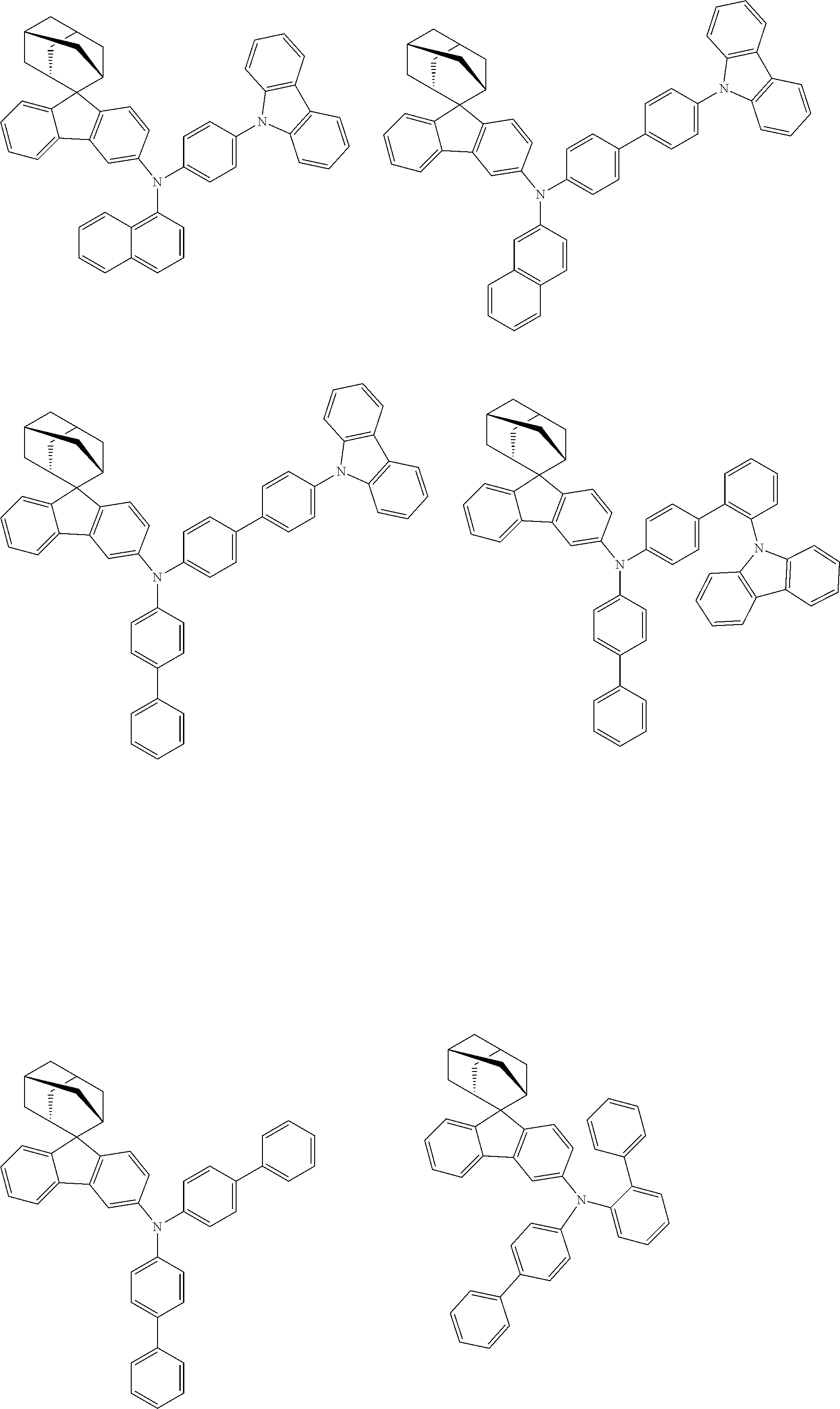

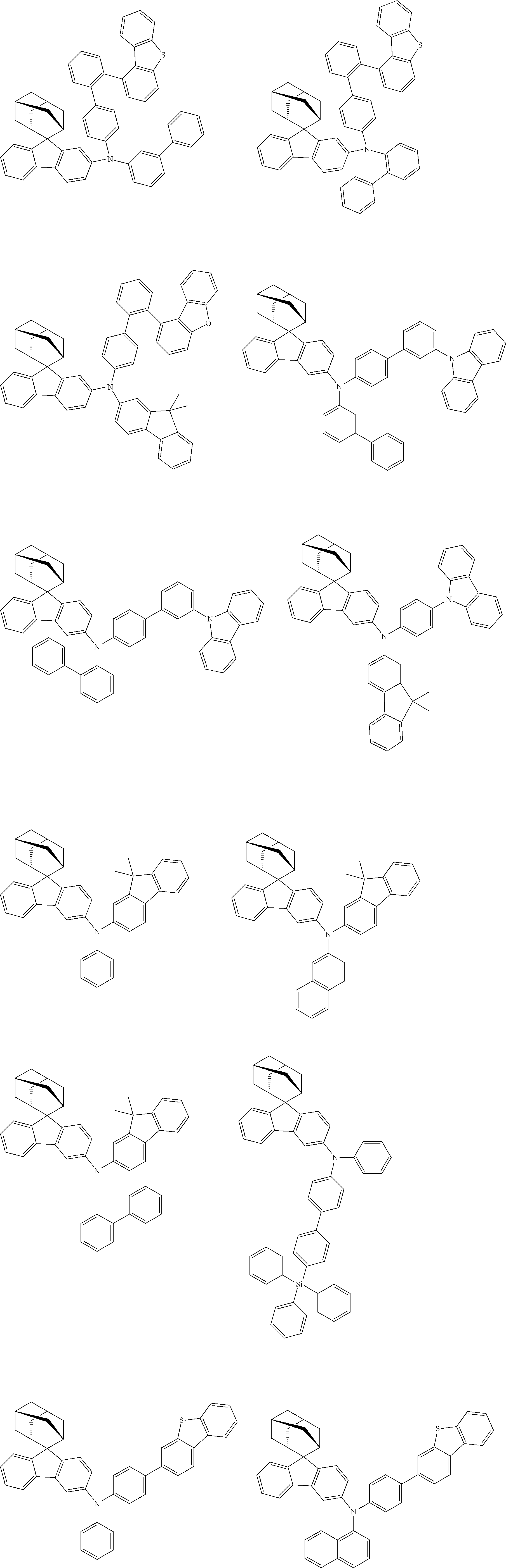

### Hole Transporting Layer

The hole transporting layer is a layer containing a substance exhibiting a high hole transportability.

In an exemplary arrangement of the organic EL device according to the first exemplary embodiment, the hole transporting layers (e.g., the first hole transporting layer and the second hole transporting layer) may contain a compound different from the above-described hole transporting zone material. “The compound contained in the hole transporting layer” may be at least one compound selected from the group consisting of an aromatic amine compound, carbazole derivative, anthracene derivative, and the like. Specifically, for instance, an aromatic amine compound such as 4,4′-bis[N-(1-naphthyl)-N-phenylamino]biphenyl (abbreviation: NPB), N,N′-bis(3-methylphenyl)-N,N′-diphenyl-[1,1′-biphenyl]-4,4′-diamine (abbreviation: TPD), 4-phenyl-4′-(9-phenylfluorene-9-yl)triphenylamine (abbreviation: BAFLP), 4,4′-bis[N-(9,9-dimethylfluorene-2-yl)-N-phenylamino]biphenyl (abbreviation: DFLDPBi), 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), and 4,4′-bis[N-(spiro-9,9′-bifluorene-2-yl)-N-phenylamino]biphenyl (abbreviation: BSPB) is usable. The above-described substances mostly have a hole mobility of 10⁻⁶ cm²/(V·s) or more.

For the hole transporting layer, a carbazole derivative such as CBP, CzPA, and PCzPA and an anthracene derivative such as t-BuDNA, DNA, and DPAnth may be used. A high polymer compound such as poly(N-vinylcarbazole) (abbreviation: PVK) and poly(4-vinyltriphenylamine) (abbreviation: PVTPA) is also usable.

However, in addition to the above substances, any substance exhibiting a higher hole transportability than an electron transportability may be used. It should be noted that the layer containing the substance exhibiting a high hole transportability may be not only a single layer but also a laminate of two or more layers formed of the above substance(s).

In an exemplary arrangement of the organic EL device according to the first exemplary embodiment, the hole transporting zone may include a single hole transporting layer or may include two or more hole transporting layers.

### Specific Examples of Other Hole Transporting Zone Material

Specific examples of a hole transporting zone material other than the above-described hole transporting zone material include the following compounds. However, the invention is by no means limited to the specific examples of the hole transporting zone material.

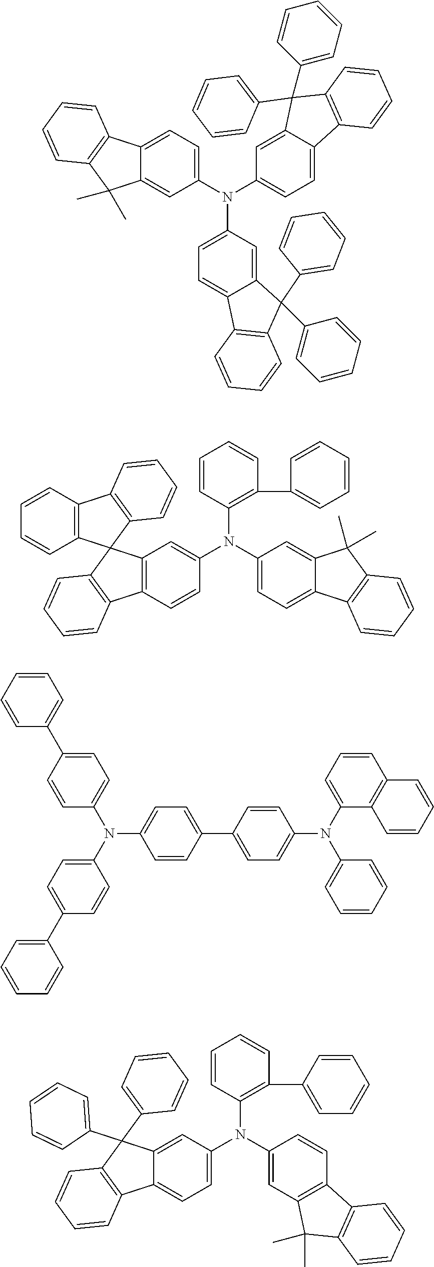

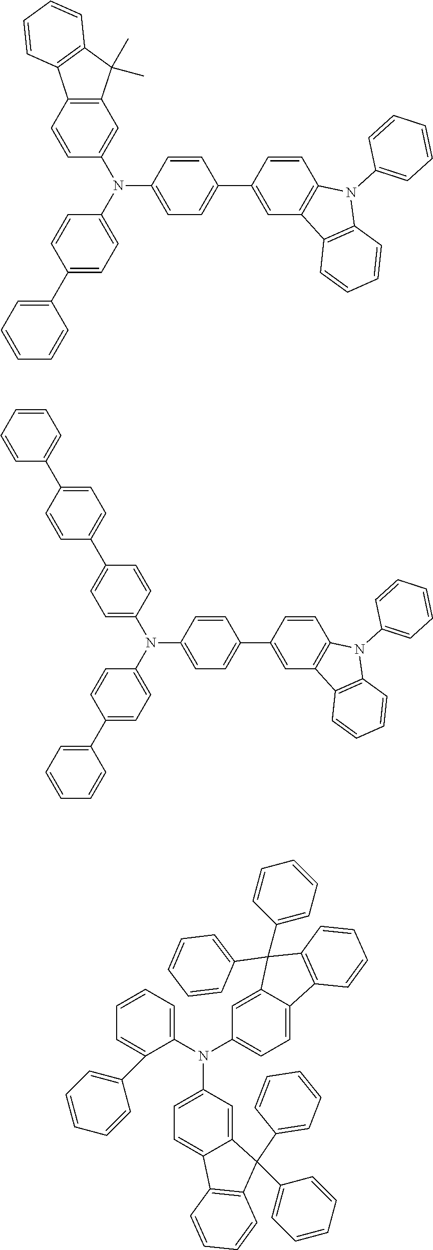 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1 ; c1ccc(-c2ccccc2N(c2ccc3c(c2)C(c2ccccc2)(c2ccccc2)c2ccccc2-3)c2ccc3c(c2)C(c2ccccc2)(c2ccccc2)c2ccccc2-3)cc1]

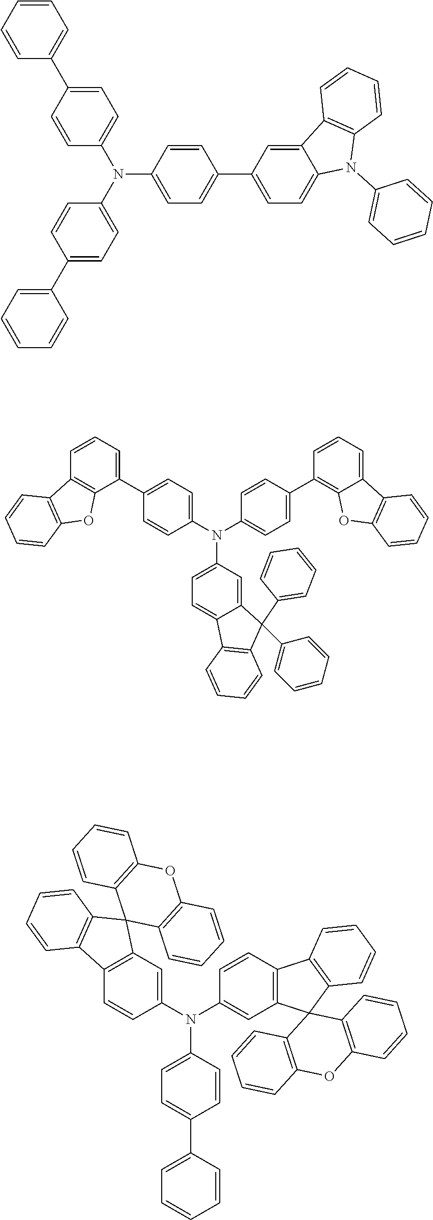 [SMILES: c1ccc(-c2ccc(N(c3ccc(-c4ccccc4)cc3)c3ccc(-c4ccc5c(c4)c4ccccc4n5-c4ccccc4)cc3)cc2)cc1 ; c1ccc(C2(c3ccccc3)c3ccccc3-c3ccc(N(c4ccc(-c5cccc6c5oc5ccccc56)cc4)c4ccc(-c5cccc6c5oc5ccccc56)cc4)cc32)cc1 ; c1ccc(-c2ccc(N(c3ccc4c(c3)C3(c5ccccc5Oc5ccccc53)c3ccccc3-4)c3ccc4c(c3)C3(c5ccccc5Oc5ccccc53)c3ccccc3-4)cc2)cc1]

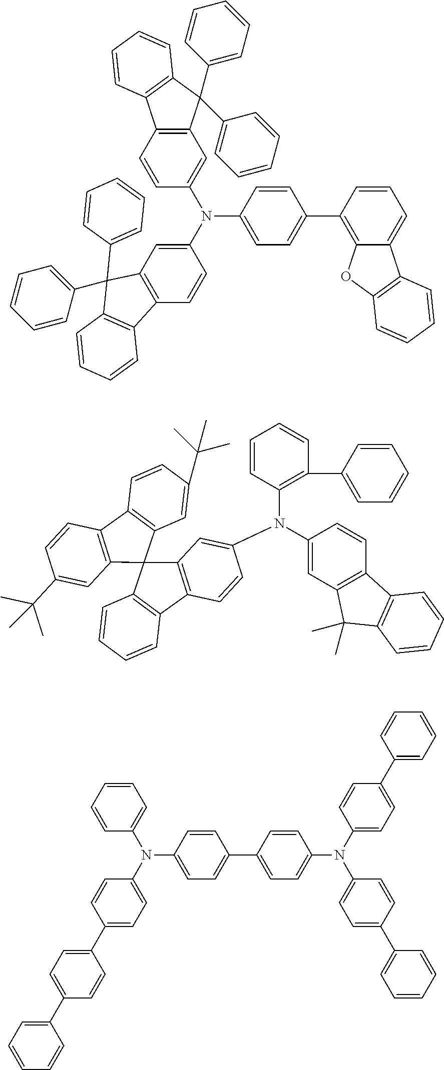 [SMILES: c1ccc(C2(c3ccccc3)c3ccccc3-c3ccc(N(c4ccc(-c5cccc6c5oc5ccccc56)cc4)c4ccc5c(c4)C(c4ccccc4)(c4ccccc4)c4ccccc4-5)cc32)cc1 ; CC(C)(C)c1ccc2c(c1)C1(c3ccccc3-c3ccc(N(c4ccc5c(c4)C(C)(C)c4ccccc4-5)c4ccccc4-c4ccccc4)cc31)c1cc(C(C)(C)C)ccc1-2 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

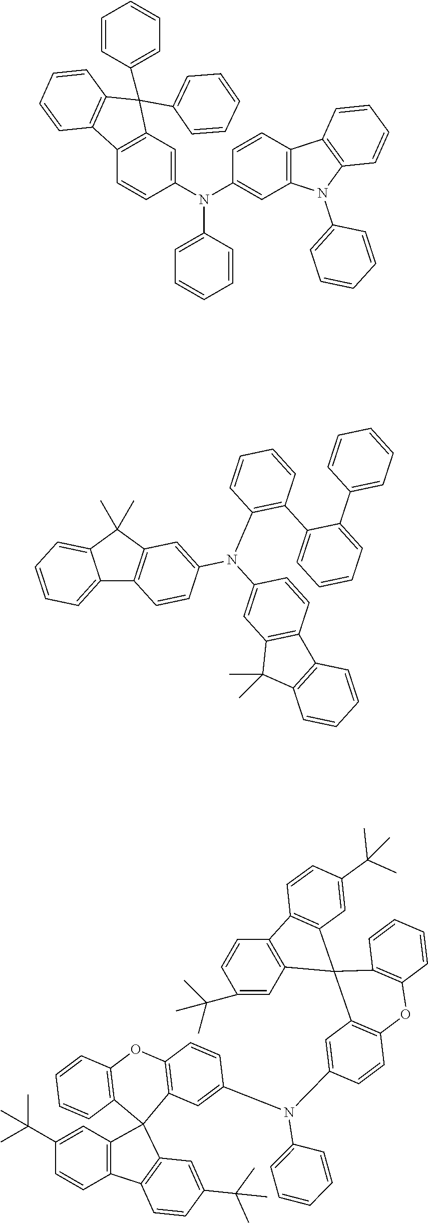 [SMILES: c1ccc(N(c2ccc3c(c2)C(c2ccccc2)(c2ccccc2)c2ccccc2-3)c2ccc3c4ccccc4n(-c4ccccc4)c3c2)cc1 ; CC1(C)c2ccccc2-c2ccc(N(c3ccc4c(c3)C(C)(C)c3ccccc3-4)c3ccccc3-c3ccccc3-c3ccccc3)cc21 ; CC(C)(C)c1ccc2c(c1)C1(c3ccccc3Oc3ccc(N(c4ccccc4)c4ccc5c(c4)C4(c6ccccc6O5)c5cc(C(C)(C)C)ccc5-c5ccc(C(C)(C)C)cc54)cc31)c1cc(C(C)(C)C)ccc1-2]

### Electron Blocking Layer

The electron blocking layer is preferably a layer that transports holes and blocks electrons from reaching a layer close to the anode (e.g., hole transporting layer) beyond the electron blocking layer.

In an exemplary arrangement of the organic EL device according to the first exemplary embodiment, the first emitting unit includes the first electron blocking layer and the second emitting unit includes the second electron blocking layer.

In an exemplary arrangement of the organic EL device of the first exemplary embodiment, the compound contained in the electron blocking layer (e.g., the first electron blocking layer and the second electron blocking layer) is the hole transporting zone material.

In an exemplary arrangement of the organic EL device according to the first exemplary embodiment, “the compound contained in the electron blocking layer” is a compound represented by the formula (B1) or (B100).

In an exemplary arrangement of the organic EL device according to the first exemplary embodiment, “the compound contained in the electron blocking layer” is, for instance, a known compound used for the electron blocking layer and is at least one compound selected from the group consisting of an aromatic amine compound and a carbazole derivative. Alternatively, “the compound contained in the electron blocking layer” may be a monoamine compound having one substituted or unsubstituted amino group in a molecule. Alternatively, “the compound contained in the electron blocking layer” may be a compound having a substituted or unsubstituted carbazolyl group and one substituted or unsubstituted amino group in a molecule.

The electron blocking layer may block excitons generated in the emitting layer from being transferred to a layer(s) close to the anode (e.g., the hole transporting layer and the hole injecting layer) beyond the electron blocking layer, in order to prevent excitation energy from leaking out from the emitting layer toward neighboring layer(s).

### Hole Injecting Layer

In an exemplary arrangement of the organic EL device according to the first exemplary embodiment, the hole injecting layer is disposed between the anode and an emitting zone or between a charge generating zone and an emitting zone closer to the cathode than this charge generating zone.

The hole injecting layer is a layer containing a highly hole-injectable substance. Examples of the highly hole-injectable substance include molybdenum oxide, titanium oxide, vanadium oxide, rhenium oxide, ruthenium oxide, chrome oxide, zirconium oxide, hafnium oxide, tantalum oxide, silver oxide, tungsten oxide, and manganese oxide.

In addition, the examples of the highly hole-injectable substance include aromatic amine compounds, which are low-molecule organic compounds, such as 4,4′,4″-tris(N,N-diphenylamino)triphenylamine (abbreviation: TDATA), 4,4′,4″-tris[N-(3-methylphenyl)-N-phenylamino]triphenylamine (abbreviation: MTDATA), 4,4′-bis[N-(4-diphenylaminophenyl)-N-phenylamino]biphenyl (abbreviation: DPAB), 4,4′-bis(N-{4-[N′-(3-methylphenyl)-N′-phenylamino]phenyl}-N-phenylamino) biphenyl (abbreviation: DNTPD), 1,3,5-tris[N-(4-diphenylaminophenyl)-N-phenylamino]benzene (abbreviation: DPA3B), 3-[N-(9-phenylcarbazole-3-yl)-N-phenylamino]-9-phenylcarbazole (abbreviation: PCzPCA1), 3,6-bis[N-(9-phenylcarbazole-3-yl)-N-phenylamino]-9-phenylcarbazole (abbreviation: PCzPCA2), and 3-[N-(1-naphthyl)-N-(9-phenylcarbazole-3-yl)amino]-9-phenylcarbazole (abbreviation: PCzPCN1).

In addition, a high polymer compound (e.g., oligomer, dendrimer and polymer) is usable as the highly hole-injectable substance. Examples of the high-molecule compound include poly(N-vinylcarbazole) (abbreviation: PVK), poly(4-vinyltriphenylamine) (abbreviation: PVTPA), poly[N-(4-{N′-[4-(4-diphenylamino)phenyl]phenyl-N′-phenylamino}phenyl) methacrylamide] (abbreviation: PTPDMA), and poly[N,N′-bis(4-butylphenyl)-N,N′-bis(phenyl)benzidine] (abbreviation: Poly-TPD). Moreover, an acid-added high polymer compound such as poly(3,4-ethylenedioxythiophene)/poly(styrene sulfonic acid) (PEDOT/PSS) and polyaniline/poly(styrene sulfonic acid) (PAni/PSS) are also usable.

In an exemplary arrangement of the organic EL device according to the exemplary embodiment, the compounds usable for the hole transporting layer (the hole transporting zone material) are also usable for the hole injecting layer. In this case, the hole Injecting layer preferably contains the hole transporting zone material and an acceptor material.

### Acceptor Material

The acceptor material has at least one of a first cyclic structure represented by a formula (P11) below or a second cyclic structure represented by a formula (P12).

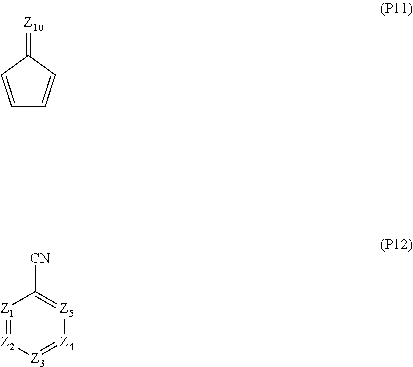

The first cyclic structure represented by the formula (P11) is fused, in a molecule of the acceptor material, to at least one cyclic structure of a substituted or unsubstituted aromatic hydrocarbon ring having 6 to 50 ring carbon atoms or a substituted or unsubstituted heterocycle having 5 to 50 ring atoms, and a structure represented by ═Z₁₀ is represented by a formula (P11a), (P11b), (P11c), (P11d), (P11e), (P11f), (P11g), (P11h), (P11i), (P11j), (P11k) or (P11m) below.

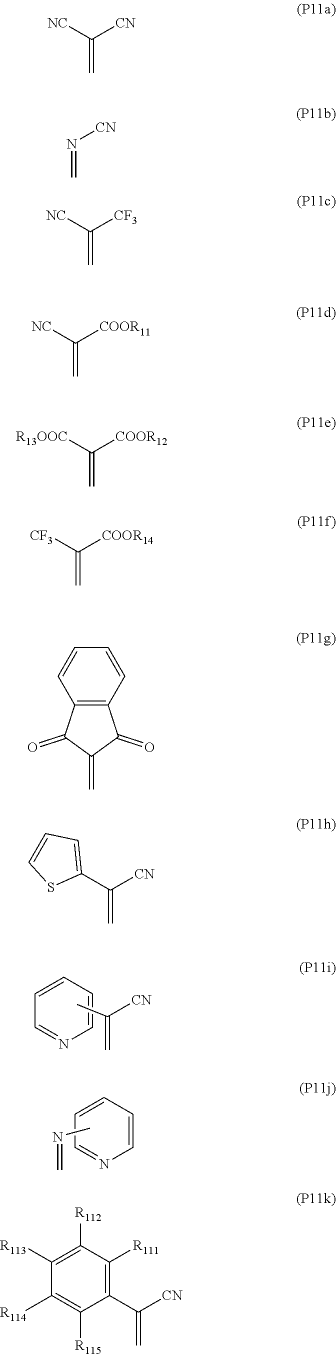

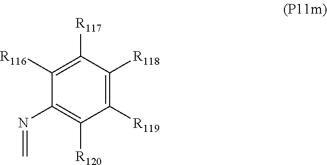

In the formula (P11a), (P11b), (P11c), (P11d), (P11e), (P11f), (P11g), (P11h), (P11i), (P11j), (P11k) or (P11m):
R₁₁ to R₁₄ and R₁₁₁ to R₁₂₀ are each independently a hydrogen atom, a halogen atom, a hydroxy group, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted aryl group having 6 to 50 ring carbon atoms, or a substituted or unsubstituted heterocyclic group having 5 to 50 ring atoms.

In the formula (P12), Z₁ to Z₅ are each independently a nitrogen atom, a carbon atom bonded to R₁₅, or a carbon atom bonded to another atom in a molecule of the acceptor material;
at least one of Z₁ to Z₅ is a carbon atom bonded to another atom in the molecule of the acceptor material;
R₁₅ is selected from the group consisting of a hydrogen atom, a halogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a substituted or unsubstituted aryl group having 6 to 50 ring carbon atoms, a substituted or unsubstituted heterocyclic group having 5 to 50 ring atoms, a group represented by —Si(R₉₀₁)(R₉₀₂)(R₉₀₃), a group represented by —O—(R₉₀₄), a group represented by —S—(R₉₀₅), a group represented by —N(R₉₀₆)(R₉₀₇), a substituted or unsubstituted alkenyl group having 2 to 50 carbon atoms, a substituted or unsubstituted aralkyl group having 7 to 50 carbon atoms, a carboxy group, a substituted or unsubstituted ester group, a substituted or unsubstituted carbamoyl group, a nitro group, and a substituted or unsubstituted siloxanyl group; and
when a plurality of R₁₅ are present, the plurality of R₁₅ are mutually the same or different.

In the acceptor material, R₉₀₁ to R₉₀₇ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of Roos are mutually the same or different;
when a plurality of R₉₀₄ are present, the plurality of R₉₀₄ are mutually the same or different;
when a plurality of R₉₀₅ are present, the plurality of R₉₀₅ are mutually the same or different;
when a plurality of R₉₀₆ are present, the plurality of R₉₀₆ are mutually the same or different; and
when a plurality of R₉₀₇ are present, the plurality of R₉₀₇ are mutually the same or different.

In an exemplary arrangement of the organic EL device according to the exemplary embodiment, the acceptor material has at least one cyano group.

In an exemplary arrangement of the organic EL device according to the exemplary embodiment, the hole injecting layer contains the hole transporting zone material, the acceptor material and the hole transporting zone material are mutually different, and a content of the acceptor material in the hole injecting layer is less than 50 mass %.

In an exemplary arrangement of the organic EL device according to the exemplary embodiment, the content of the acceptor material in the hole injecting layer is 10 mass % or less or 5 mass % or less.

In an exemplary arrangement of the organic EL device according to the exemplary embodiment, the content of the acceptor material in the hole injecting layer is 1 mass % or more or 3 mass % or less.

In an exemplary arrangement of the organic EL device according to the exemplary embodiment, in a case where the hole injecting layer contains the acceptor material and the hole transporting zone material, a content of the hole transporting zone material in the hole injecting layer is preferably 40 mass % or more, more preferably 45 mass % or more, and still more preferably 50 mass % or more. The content of the hole transporting zone material in the hole injecting layer is preferably 99.5 mass % or less. The total of the content of the acceptor material and the content of the hole transporting zone material in the hole injecting layer is 100 mass % or less.

An ester group herein is at least one group selected from the group consisting of an alkyl ester group and an aryl ester group.

An alkyl ester group herein is represented, for instance, by —C(═O)OR^{E}. R^{E} is exemplified by a substituted or unsubstituted alkyl group having 1 to 50 carbon atoms (preferably 1 to 10 carbon atoms).

An aryl ester group herein is represented, for instance, by —C(═O)OR^{Ar}. R^{Ar} is exemplified by a substituted or unsubstituted aryl group having 6 to 30 ring carbon atoms.

A siloxanyl group herein, which is a silicon compound group through an ether bond, is exemplified by a trimethylsiloxanyl group.

A carbamoyl group herein is represented by —CONH₂. A substituted carbamoyl group herein is represented, for instance, by —CONH—Ar^{C} or —CONH—R^{C}. Ar^{C} is, for instance, at least one group selected from the group consisting of a substituted or unsubstituted aryl group having 6 to 50 ring carbon atoms (preferably 6 to 10 ring carbon atoms) and a heterocyclic group having 5 to 50 ring atoms (preferably 5 to 14 ring atoms). Ar^{C} may be a group in which a substituted or unsubstituted aryl group having 6 to 50 ring carbon atoms is bonded to a substituted or unsubstituted heterocyclic group having 5 to 50 ring atoms. R^{C} is exemplified by a substituted or unsubstituted alkyl group having 1 to 50 carbon atoms (preferably 1 to 6 carbon atoms).

In the acceptor material, the groups specified to be “substituted or unsubstituted” are also each preferably an “unsubstituted” group.

### Specific Examples of Acceptor Material

Specific examples of the acceptor material include the following compounds. However, the invention is by no means limited to the specific examples.

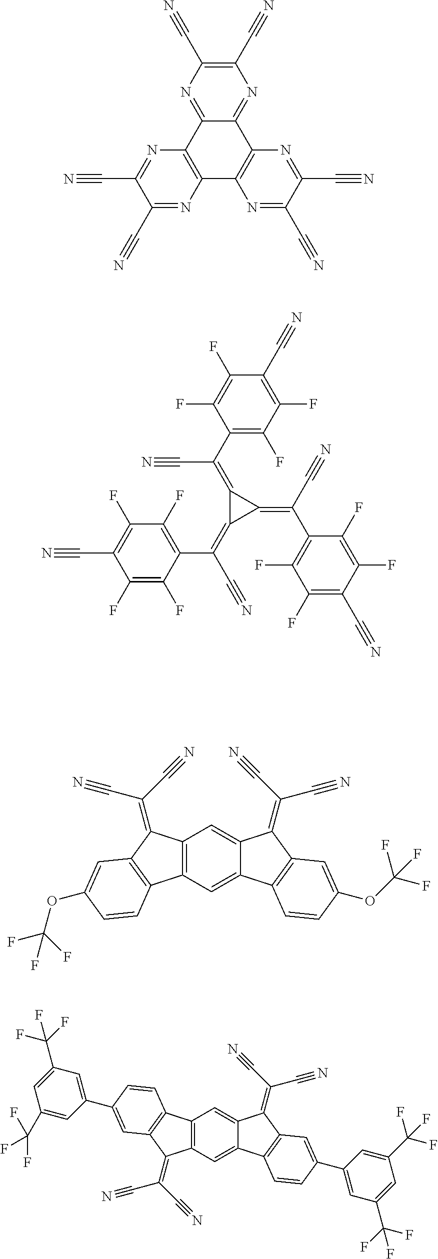 [SMILES: N#Cc1nc2c3nc(C#N)c(C#N)nc3c3nc(C#N)c(C#N)nc3c2nc1C#N ; N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; N#CC(C#N)=C1c2cc(OC(F)(F)F)ccc2-c2cc3c(cc21)C(=C(C#N)C#N)c1cc(OC(F)(F)F)ccc1-3 ; N#CC(C#N)=C1c2cc(-c3cc(C(F)(F)F)cc(C(F)(F)F)c3)ccc2-c2cc3c(cc21)-c1ccc(-c2cc(C(F)(F)F)cc(C(F)(F)F)c2)cc1C3=C(C#N)C#N]

### Other Arrangements of Organic EL Device

Arrangements of the organic EL devices will be further described below.

### Substrate

The substrate is used as a support for the organic EL device. For instance, glass, quartz, plastics and the like are usable for the substrate. A flexible substrate is also usable. The flexible substrate is a bendable substrate, which is exemplified by a plastic substrate. Examples of the material for the plastic substrate include polycarbonate, polyarylate, polyethersulfone, polypropylene, polyester, polyvinyl fluoride, polyvinyl chloride, polyimide, and polyethylene naphthalate. Further, an inorganic vapor deposition film is also usable.

### Anode

Metal, an alloy, an electrically conductive compound, a mixture thereof, or the like having a large work function (specifically, 4.0 eV or more) is preferably used as the anode formed on the substrate. Specific examples of the material include indium tin oxide (ITO), indium oxide-tin oxide containing silicon or silicon oxide, indium oxide-zinc oxide, indium oxide containing tungsten oxide and zinc oxide, and graphene. In addition, gold (Au), platinum (Pt), nickel (Ni), tungsten (W), chrome (Cr), molybdenum (Mo), iron (Fe), cobalt (Co), copper (Cu), palladium (Pd), titanium (Ti), and nitrides of a metallic material (e.g., titanium nitride) are usable.

The material is typically formed into a film by a sputtering method. For instance, the indium oxide-zinc oxide can be formed into a film by the sputtering method using a target in which zinc oxide in a range from 1 mass % to 10 mass % is added to indium oxide. Moreover, for instance, the indium oxide containing tungsten oxide and zinc oxide can be formed by the sputtering method using a target in which tungsten oxide in a range from 0.5 mass % to 5 mass % and zinc oxide in a range from 0.1 mass % to 1 mass % are added to indium oxide. In addition, the anode may be formed by a vacuum deposition method, a coating method, an inkjet method, a spin coating method or the like.

Among the EL layers formed on the anode, since the hole injecting layer adjacent to the anode is formed of a composite material into which holes are easily injectable irrespective of the work function of the anode, a material usable as an electrode material (e.g., metal, an alloy, an electroconductive compound, a mixture thereof, and the elements belonging to the group 1 or 2 of the periodic table) is also usable for the anode.

A material having a small work function such as elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), and alloys including the rare earth metal are also usable for the anode. It should be noted that the vacuum deposition method and the sputtering method are usable for forming the anode using the alkali metal, alkaline earth metal and the alloy thereof. Further, when a silver paste is used for the anode, the coating method and the inkjet method are usable.

In a case of a bottom emission type organic EL device, the anode is a light-transmissive electrode that allows light to travel therethrough. The light-transmissive electrode is preferably made of a light-transmissive or semi-transmissive metallic material that transmits light emitted from the emitting layer. Herein, the light-transmissive or semi-transmissive property means the property of allowing 50% or more (preferably 80% or more) of the light emitted from the emitting layer to transmit. The light-transmissive or semi-transmissive metallic material can be selected in use as needed from the above materials listed in the description regarding the anode. The light-transmissive or semi-transmissive metallic material may be materials listed as ones used for a later-described conductive layer (or a transparent conductive layer).

In a case of a top emission type organic EL device, the anode is a light-reflective electrode having a light-reflective layer. The light-reflective layer is preferably made of a metallic material having light reflectivity. Herein, the light reflectivity means the property of reflecting 50% or more (preferably 80% or more) of the light emitted from the emitting layer. The metallic material having light reflectivity can be selected in use as needed from the above materials listed in the description about the anode.

Examples of the metallic material used for the light-reflective layer include: a single-component material of any metal selected from the group consisting of A1, Ag, Ta, Zn, Mo, W, Ni, Cr and the like or an alloy material having any metal selected from this group as a main component (preferably 50 mass % or more with respect to the total); an amorphous alloy selected from the group consisting of NiP, NiB, CrP, CrB and the like; and a microcrystalline alloy selected from the group consisting of NiAl, silver alloys and the like.

As the metallic material used for the light-reflective layer, at least one alloy selected from the group consisting of APC (an alloy of silver, palladium and copper), ARA (an alloy of silver, rubidium and gold), MoCr (an alloy of molybdenum and chromium) and NiCr (an alloy of nickel and chromium) may be used.

The light-reflective layer may be a single layer or plural layers.

The anode as the light-reflective electrode may consist of the reflective layer, but may have a multilayer structure having the light-reflective layer and a conductive layer (preferably a transparent conductive layer). In a case where the anode has the light-reflective layer and the conductive layer, the conductive layer is preferably disposed between the light-reflective layer and a layer (e.g., the hole injecting layer or the hole transporting layer) included in the hole transporting zone. The anode may have a multilayer structure having the light-reflective layer between two conductive layers (a first conductive layer and a second conductive layer). In a case of such a multilayer structure, the first conductive layer and the second conductive layer may be made using the same material or different materials.

A material used for the conductive layer can be selected as needed from the above materials listed in the description regarding the anode. It is also possible to use metal, an alloy, an electroconductive compound, a mixture thereof, or the like having a large work function (specifically, 4.0 eV or more) for the conductive layer (transparent conductive layer) as a transparent electrode.

For instance, an alkali metal such as lithium (Li) and cesium (Cs), an alkaline earth metal such as magnesium (Mg), calcium (Ca) and strontium (Sr), an alloy (e.g., MgAg and AlLi) containing at least one selected from the group consisting of the alkali metal and the alkaline earth metal, a rare earth metal such as europium (Eu) and ytterbium (Yb), an alloy containing at least one selected from the rare earth metal are also usable for the conductive layer.

### Cathode

It is preferable to use metal, an alloy, an electroconductive compound, a mixture thereof, or the like having a small work function (specifically, 3.8 eV or less) for the cathode. Examples of the material for the cathode include elements belonging to Groups 1 and 2 in the periodic table of the elements, specifically, an alkali metal such as lithium (Li) and cesium (Cs), an alkaline earth metal such as magnesium (Mg), calcium (Ca) and strontium (Sr), alloys (e.g., MgAg and AlLi) including the alkali metal or the alkaline earth metal, a rare earth metal such as europium (Eu) and ytterbium (Yb), and alloys including the rare earth metal.

It should be noted that the vacuum deposition method and the sputtering method are usable for forming the cathode using the alkali metal, alkaline earth metal and the alloy thereof. Further, when a silver paste is used for the cathode, the coating method and the inkjet method are usable.

By providing the electron injecting layer, various conductive materials such as Al, Ag, ITO, graphene, and indium oxide-tin oxide containing silicon or silicon oxide may be used for forming the cathode regardless of the work function. The conductive materials can be formed into a film using the sputtering method, inkjet method, spin coating method and the like.

In a case of a bottom emission type organic EL device, the cathode is a light-reflective electrode. The light-reflective electrode is preferably made of a metallic material having light reflectivity. The metallic material having light reflectivity can be selected in use as needed from the above materials listed in the description regarding the cathode. The metallic material having light reflectivity may be materials listed as ones used for the above-described light-reflective layer.

In a case of a top emission type organic EL device, the cathode is a light-transmissive electrode that allows light to travel therethrough. The light-transmissive electrode is preferably made of a light-transmissive or semi-transmissive metallic material that transmits light emitted from the emitting layer. Herein, the light-transmissive or semi-transmissive property means the property of allowing 50% or more (preferably 80% or more) of the light emitted from the emitting layer to transmit. The light-transmissive or semi-transmissive metallic material can be selected in use as needed from the above materials listed in the description regarding the cathode. The light-transmissive or semi-transmissive metallic material may be materials listed as ones used for the above-described conductive layer (or a transparent conductive layer).

### Capping Layer

In a case of a top emission type organic EL device, the organic EL device usually includes a capping layer on the top of the cathode. The capping layer may contain, for instance, at least one compound selected from the group consisting of a high polymer compound, metal oxide, metal fluoride, metal boride, silicon nitride, and silicon compound (silicon oxide or the like). The capping layer may contain, for instance, at least one compound selected from the group consisting of an aromatic amine derivative, an anthracene derivative, a pyrene derivative, a fluorene derivative, and a dibenzofuran derivative. In addition, a laminate in which layers containing these substances are layered can also be used as the capping layer.

The organic EL device according to the exemplary embodiment may be a bottom emission type organic EL device. The organic EL device according to the exemplary embodiment may be a top emission type organic EL device.

In a case of a bottom emission type organic EL device, it is preferable that the anode is a light-transmissive electrode that allows light to travel therethrough and the cathode is a light-reflective layer capable of reflecting light.

In a case of a top emission type organic EL device, it is preferable that the anode is a light-reflective layer capable of reflecting light and the cathode is a light-transmissive electrode that allows light to travel therethrough.

### Electron Transporting Layer

The electron transporting layer is a layer containing a highly electron-transportable substance. Examples of “the compound contained in the electron transporting layer” include 1) a metal complex such as an aluminum complex, beryllium complex, and zinc complex, 2) a hetero aromatic compound such as imidazole derivative, benzimidazole derivative, azine derivative, carbazole derivative, and phenanthroline derivative, and 3) a high polymer compound. Specifically, as a low-molecule organic compound, for instance, a metal complex such as Alq, tris(4-methyl-8-quinolinolato)aluminum (abbreviation: Almq₃), bis(10-hydroxybenzo[h]quinolinato)beryllium (abbreviation: BeBq₂), BAlq, Znq, ZnPBO and ZnBTZ is usable. In addition to the metal complex, a heteroaromatic compound such as 2-(4-biphenylyl)-5-(4-tert-butylphenyl)-1,3,4-oxadiazole (abbreviation: PBD), 1,3-bis[5-(ptert-butylphenyl)-1,3,4-oxadiazole-2-yl]benzene (abbreviation: OXD-7), 3-(4-tert-butylphenyl)-4-phenyl-5-(4-biphenylyl)-1,2,4-triazole (abbreviation: TAZ), 3-(4-tert-butylphenyl)-4-(4-ethylphenyl)-5-(4-biphenylyl)-1,2,4-triazole (abbreviation: p-EtTAZ), bathophenanthroline (abbreviation: BPhen), bathocuproine (abbreviation: BCP), and 4,4′-bis(5-methylbenzoxazole-2-yl) stilbene (abbreviation: BzOs) is also usable. The above-described substances mostly have an electron mobility of 10⁻⁶ cm²/V·s or more. It should be noted that any substance other than the above substance may be used for the electron transporting layer as long as the substance exhibits a higher electron transportability than the hole transportability. It should be noted that the electron transporting layer may be a single layer or a laminate of two or more layers formed of the above substance(s).

Further, a high polymer compound is usable for the electron transporting layer. For instance, poly[(9,9-dihexylfluorene-2,7-diyl)-co-(pyridine-3,5-diyl)] (abbreviation: PF-Py), and poly[(9,9-dioctylfluorene-2,7-diyl)-co-(2,2′-bipyridine-6,6′-diyl)] (abbreviation: PF-BPy) are usable.

### Hole Blocking Layer

The hole blocking layer is preferably a layer transporting electrons and blocking holes from reaching a layer close to the cathode (e.g., electron transporting layer) beyond the hole blocking layer. “The compound contained in the hole blocking layer” is exemplified by a compound used in a known hole blocking layer. The compound contained in the hole blocking layer is preferably at least one compound selected from the group consisting of a metal complex, a heteroaromatic compound, and a high polymer compound. The compound contained in the hole blocking layer may be at least one compound selected from the group consisting of an imidazole derivative, benzimidazole derivative, azine derivative, carbazole derivative, and phenanthroline derivative.

In order to prevent excitation energy from leaking out from the emitting layer toward neighboring layer(s), the hole blocking layer is also preferably a layer blocking excitons generated in the emitting layer from being transferred to a layer(s) closer to the cathode (e.g., the electron transporting layer and the electron injecting layer) beyond the hole blocking layer.

### Electron Injecting Layer

The electron injecting layer is a layer containing a highly electron-injectable substance. Examples of a material for the electron injecting layer include an alkali metal, alkaline earth metal and a compound thereof, examples of which include lithium (Li), cesium (Cs), calcium (Ca), lithium fluoride (LiF), cesium fluoride (CsF), calcium fluoride (CaF₂), and lithium oxide (LiOx). In addition, the alkali metal, alkaline earth metal or the compound thereof may be added to the substance exhibiting the electron transportability in use. Specifically, for instance, magnesium (Mg) added to Alq may be used. In this case, the electrons can be more efficiently injected from the cathode.

Alternatively, the electron injecting layer may be provided by a composite material in a form of a mixture of the organic compound and the electron donor. Such a composite material exhibits excellent electron injectability and electron transportability since electrons are generated in the organic compound by the electron donor. In this case, the organic compound is preferably a material excellent in transporting the generated electrons. Specifically, the above examples (e.g., the metal complex and the hetero aromatic compound) of the substance forming the electron transporting layer are usable. As the electron donor, any substance exhibiting electron donating property to the organic compound is usable. Specifically, the electron donor is preferably alkali metal, alkaline earth metal and rare earth metal such as lithium, cesium, magnesium, calcium, erbium and ytterbium. The electron donor is also preferably alkali metal oxide and alkaline earth metal oxide such as lithium oxide, calcium oxide, and barium oxide. Moreover, a Lewis base such as magnesium oxide is also usable. Further, the organic compound such as tetrathiafulvalene (abbreviation: TTF) is also usable.

### Examples of Schematic Arrangements of Organic EL Device

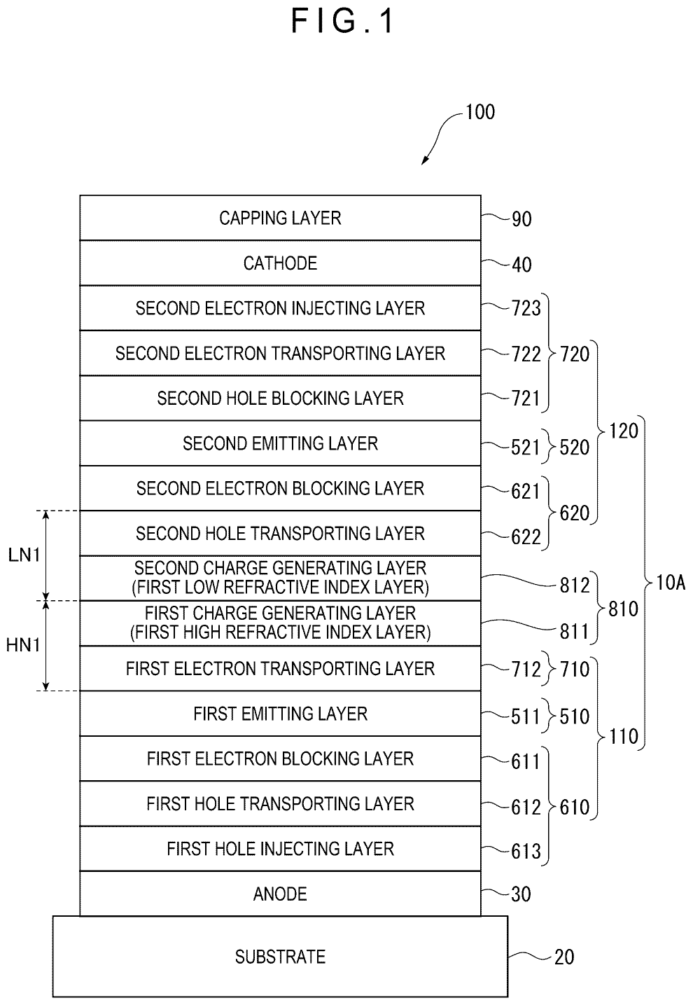

FIG. 1 schematically illustrates an exemplary arrangement of the organic EL device according to the exemplary embodiment. An organic EL device 100 includes a substrate 20, an anode 30, a cathode 40, and an organic layer 10A provided between the anode 30 and the cathode 40. The organic layer 10A includes a first emitting unit 110, a first charge generating zone 810, and a second emitting unit 120 in this order from the anode 30. The first emitting unit 110, the first charge generating zone 810, and the second emitting unit 120 are disposed in this order from the anode 30. The organic EL device 100 includes a high refractive index zone HN1 and a low refractive index zone LN1 in the organic layer 10A. The organic EL device 100 includes a capping layer 90 on a surface of the cathode 40 opposite from the second emitting unit 120.

The first emitting unit 110 includes a first hole transporting zone 610, a first emitting zone 510, and a first electron transporting zone 710 in this order from the anode 30. The hole transporting zone 610 includes a first hole injecting layer 613, a first hole transporting layer 612, and a first electron blocking layer 611 in this order from the anode 30. The first emitting zone 510 includes a first emitting layer 511. The first electron transporting zone 710 includes a first electron transporting layer 712.

The first charge generating zone 810 includes a first charge generating layer 811 and a second charge generating layer 812 in this order from the first emitting unit 110.

The second emitting unit 120 includes a second hole transporting zone 620, a second emitting zone 520, and a second electron transporting zone 720 in this order from the first charge generating zone 810. The second hole transporting zone 620 includes a second hole transporting layer 622 and a second electron blocking layer 621 in this order from the first charge generating zone 810. The second emitting zone 520 includes a second emitting layer 521. The second electron transporting zone 720 includes a second hole blocking layer 721, a second electron transporting layer 722, and a second electron injecting layer 723 in this order from the second emitting zone 520.

In a case illustrated in FIG. 1, the high refractive index zone HN1 includes the first charge generating layer 811 and the first electron transporting layer 712 which are the high refractive index layers. The low refractive index zone LN1 includes the second charge generating layer 812 and the second hole transporting layer 622 which are the low refractive index layers. The first charge generating layer 811 of the two high refractive index layers corresponds to the first high refractive index layer. The second charge generating layer 812 of the two low refractive index layers corresponds to the first low refractive index layer. The first charge generating layer 811 (first high refractive index layer) is in direct contact with the second charge generating layer 812 (first low refractive index layer).

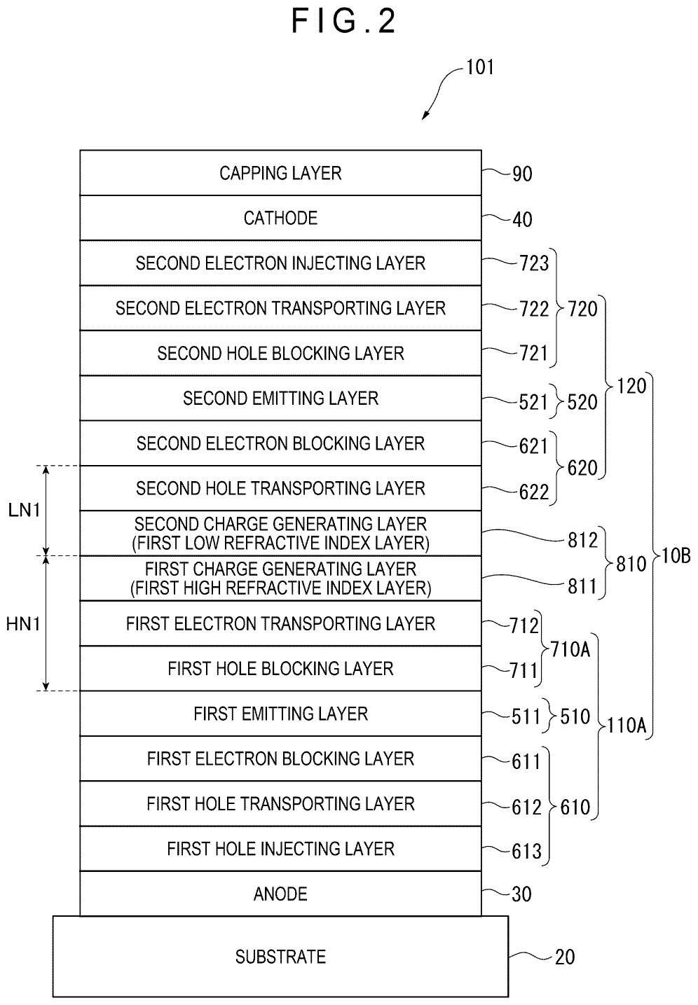

FIG. 2 schematically illustrates another exemplary arrangement of the organic EL device according to the exemplary embodiment.

An organic EL device 101 includes the substrate 20, the anode 30, the cathode 40, and an organic layer 10B provided between the anode 30 and the cathode 40. The organic layer 10B includes a first emitting unit 110A, the first charge generating zone 810, and the second emitting unit 120 in this order from the anode 30. The first emitting unit 110A, the first charge generating zone 810, and the second emitting unit 120 are disposed in this order from the anode 30. The organic EL device 101 includes the high refractive index zone HN1 and the low refractive index zone LN1 in the organic layer 10B. The organic EL device 101 includes the capping layer 90 on a surface of the cathode 40 opposite from the second emitting unit 120.

The first emitting unit 110A includes the first hole transporting zone 610, the first emitting zone 510, and a first electron transporting zone 710A in this order from the anode 30. The hole transporting zone 610 includes the first hole injecting layer 613, the first hole transporting layer 612, and the first electron blocking layer 611 in this order from the anode 30. The first emitting zone 510 includes the first emitting layer 511. The first electron transporting zone 710A includes a first hole blocking layer 711 and the first electron transporting layer 712 in this order from the anode 30.

The first charge generating zone 810 includes the first charge generating layer 811 and the second charge generating layer 812 in this order from the first emitting unit 110A.

The second emitting unit 120 includes the second hole transporting zone 620, the second emitting zone 520, and the second electron transporting zone 720 in this order from the first charge generating zone 810. The second hole transporting zone 620 includes a second hole transporting layer 622 and a second electron blocking layer 621 in this order from the first charge generating zone 810. The second emitting zone 520 includes a second emitting layer 521. The second electron transporting zone 720 includes a second hole blocking layer 721, a second electron transporting layer 722, and a second electron injecting layer 723 in this order from the second emitting zone 520.

In a case illustrated in FIG. 2, the high refractive index zone HN1 includes the first hole blocking layer 711, the first electron transporting layer 712, and the first charge generating layer 811 which are the high refractive index layers. The low refractive index zone LN1 includes the second charge generating layer 812 and the second hole transporting layer 622 which are the low refractive index layers. The first charge generating layer 811 of the three high refractive index layers corresponds to the first high refractive index layer. The second charge generating layer 812 of the two low refractive index layers corresponds to the first low refractive index layer. The first charge generating layer 811 (first high refractive index layer) is in direct contact with the second charge generating layer 812 (first low refractive index layer).

The invention is not limited to the exemplary arrangements of the organic EL device illustrated in FIGS. 1 and 2.

### Layer Formation Method(s)

A method of forming each layer of the organic EL device in the exemplary embodiment is subject to no limitation except for the above particular description. However, known methods of dry film-forming such as vacuum deposition, sputtering, plasma or ion plating and wet film-forming such as spin coating, dipping, flow coating or ink-jet are applicable.

In an exemplary arrangement of the organic EL device of the exemplary embodiment, a layer containing multiple types of substances may be formed, for instance, by co-deposition using multiple types of compounds and the like, by vapor-deposition using a mixture (premixed mixture) of multiple types of compounds and the like mixed in advance, or by coating using a mixture of multiple types of compounds mixed in advance. The mixture prepared by mixing multiple types of compounds in advance may be a powder. The mixture prepared by mixing multiple types of compounds in advance may be a solution. A method of mixing multiple types of compounds and the like in advance is occasionally referred to as premix. A premix method, which is not particularly limited, enables adjustment of a vapor-deposition ratio of compounds and the like forming a mixture premixed, by adjusting substituents or the like of the compounds forming the mixture to adjust a molecular weight of the compounds, or by adjusting a mixing ratio of the compounds.

### Film Thickness

In the organic EL device according to the exemplary embodiment, the film thickness of each layer of the organic compound layer is not limited unless otherwise specified in the above. The film thickness of each layer of the organic compound layer of the organic EL device usually preferably ranges from several nanometers to 1 μm because in general an excessively small film thickness is likely to cause defects (e.g. pin holes) and an excessively large film thickness leads to the necessity of applying high voltage and consequent reduction in efficiency.

### Emission Wavelength of Organic EL Device

The organic EL device according to an exemplary arrangement of the exemplary embodiment exhibits blue light emission, green light emission, red light mission, or white light emission.

Herein, the blue light emission refers to light emission in which the maximum peak wavelength of an emission spectrum is in a range from 430 nm to 480 nm.

Herein, the green light emission refers to light emission in which the maximum peak wavelength of an emission spectrum is in a range from 500 nm to 560 nm.

Herein, the red light emission refers to light emission in which the maximum peak wavelength of an emission spectrum is in a range from 600 nm to 660 nm.

The maximum peak wavelength is a peak wavelength of the emission spectrum exhibiting the maximum luminous intensity.

In an exemplary arrangement of the organic EL device according to the exemplary embodiment, the maximum peak wavelength of light emitted from the organic EL device is in a range from 430 nm to 480 nm.

In an exemplary arrangement of the organic EL device according to the exemplary embodiment, the maximum peak wavelength of light emitted from the organic EL device is in a range from 500 nm to 560 nm.

In an exemplary arrangement of the organic EL device according to the exemplary embodiment, the maximum peak wavelength of light emitted from the organic EL device is in a range from 600 nm to 660 nm.

The maximum peak wavelength of light emitted from the organic EL device when being driven is measured as follows. Voltage is applied on the organic EL device such that a current density becomes 10 mA/cm², where spectral radiance spectrum is measured by a spectroradiometer CS-2000 (manufactured by Konica Minolta, Inc.). A peak wavelength of an emission spectrum, at which the luminous intensity of the resultant spectral radiance spectrum is at the maximum, is measured and defined as the maximum peak wavelength (unit: nm).

In an exemplary arrangement of the organic EL device according to the first exemplary embodiment, a plurality of emitting units each independently emit blue light, red light, or green light. When each of the emitting units of the organic EL device according to the first exemplary embodiment emits green light, red light, or blue light, the maximum peak wavelength of light emitted from each emitting unit is the same as the maximum peak wavelength of the corresponding green light, red light or blue light emitted from the organic EL device.

The maximum peak wavelength of light emitted by each emitting unit of the organic EL device when driven can be measured in the same manner as the measurement method of the maximum peak wavelength of the organic EL device, for instance, by applying the measurement method to a device arrangement with a measurement target emitting unit (i.e., the emitting unit(s) other than the measurement target emitting unit are excluded).

### Second Exemplary Embodiment

### Electronic Device

An electronic device according to a second exemplary embodiment includes the organic electroluminescence device according to the exemplary embodiment described herein. Examples of the electronic device include a display device and a light-emitting unit. Examples of the display device include a display component (e.g., an organic EL panel module), TV, mobile phone, tablet and personal computer. Examples of the light-emitting unit include an illuminator and a vehicle light. The light-emitting apparatus also can be used for a display device, for instance, as a backlight of the display device.

### Modification of Embodiments

The scope of the invention is not limited by the above exemplary embodiments but includes any modification and improvement as long as such modification and improvement are compatible with the invention.

For instance, the number of emitting layers is not limited to one or two, and more than two emitting layers may be layered. Any other emitting layer(s) than one emitting layer may be a fluorescent layer or may be a phosphorescent layer with use of emission caused by electron transfer from the triplet state directly to the ground state.

The specific structure, shape, and the like of the components in the invention may be designed in any manner as long as an object of the invention can be achieved.

### EXAMPLES

The invention will be described in further detail with reference to Examples. The invention is by no means limited to these Examples.

### Compounds

Structures of compounds, which are contained in the high refractive index layer, used for producing organic EL devices in Examples 1 to 3 and Comparatives 1 to 3 are shown below.

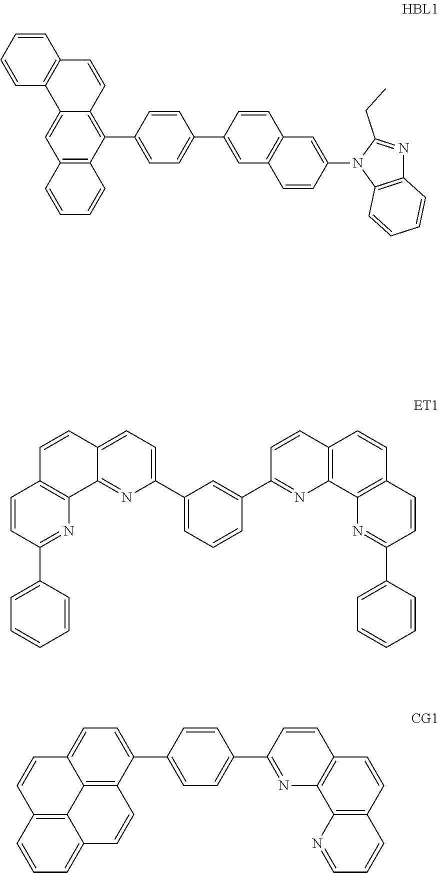 [SMILES: CCc1nc2ccccc2n1-c1ccc2cc(-c3ccc(-c4c5ccccc5cc5c4ccc4ccccc45)cc3)ccc2c1 ; c1ccc(-c2ccc3ccc4ccc(-c5cccc(-c6ccc7ccc8ccc(-c9ccccc9)nc8c7n6)c5)nc4c3n2)cc1 ; c1cnc2c(c1)ccc1ccc(-c3ccc(-c4ccc5ccc6cccc7ccc4c5c67)cc3)nc12]

Structures of compounds, which are contained in the low refractive index layer, used for producing organic EL devices in Examples 1 to 3 and Comparatives 2 to 3 are shown below.

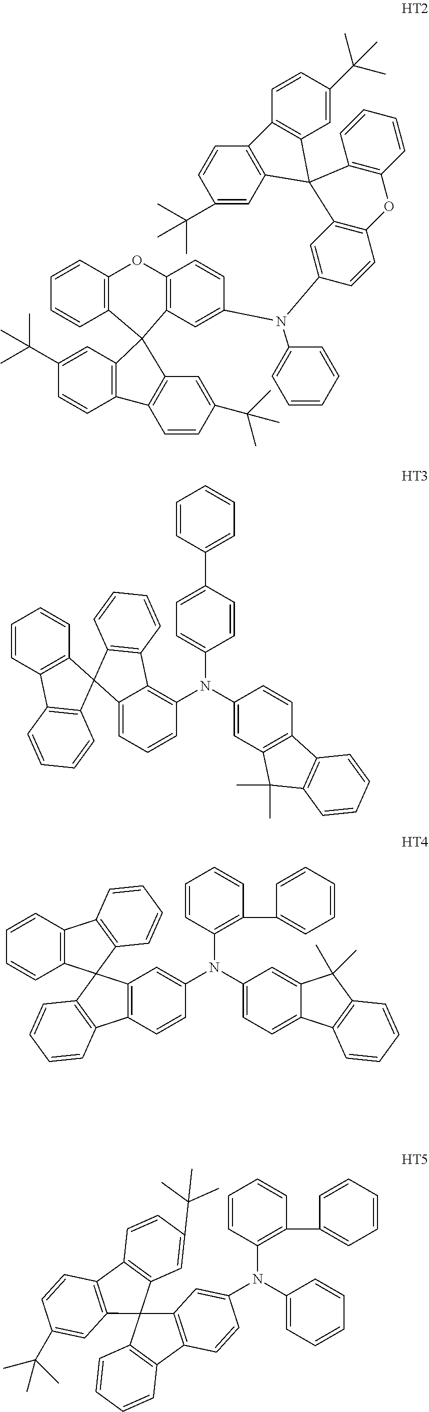 [SMILES: CC(C)(C)c1ccc2c(c1)C1(c3ccccc3Oc3ccc(N(c4ccccc4)c4ccc5c(c4)C4(c6ccccc6O5)c5cc(C(C)(C)C)ccc5-c5ccc(C(C)(C)C)cc54)cc31)c1cc(C(C)(C)C)ccc1-2 ; CC1(C)c2ccccc2-c2ccc(N(c3ccc(-c4ccccc4)cc3)c3cccc4c3-c3ccccc3C43c4ccccc4-c4ccccc43)cc21 ; CC1(C)c2ccccc2-c2ccc(N(c3ccc4c(c3)C3(c5ccccc5-c5ccccc53)c3ccccc3-4)c3ccccc3-c3ccccc3)cc21 ; CC(C)(C)c1ccc2c(c1)C1(c3ccccc3-c3ccc(N(c4ccccc4)c4ccccc4-c4ccccc4)cc31)c1cc(C(C)(C)C)ccc1-2]

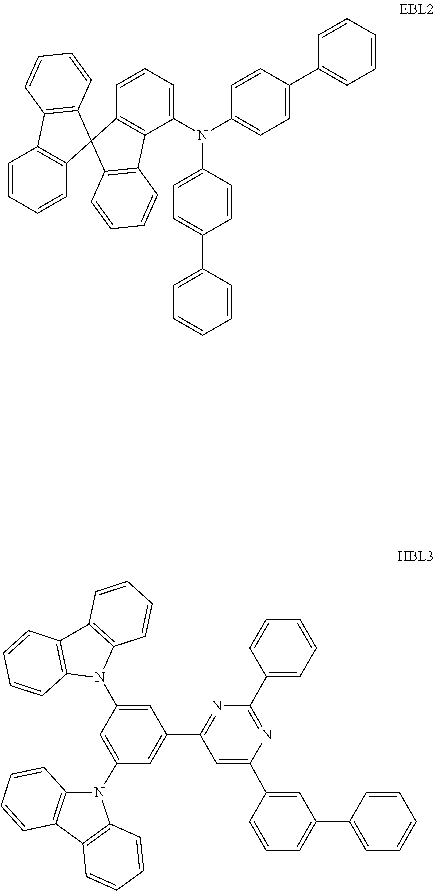 [SMILES: c1ccc(-c2ccc(N(c3ccc(-c4ccccc4)cc3)c3cccc4c3-c3ccccc3C43c4ccccc4-c4ccccc43)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1]

Structures of comparative compounds used for producing organic EL devices in Comparatives 1 to 3 are shown below.

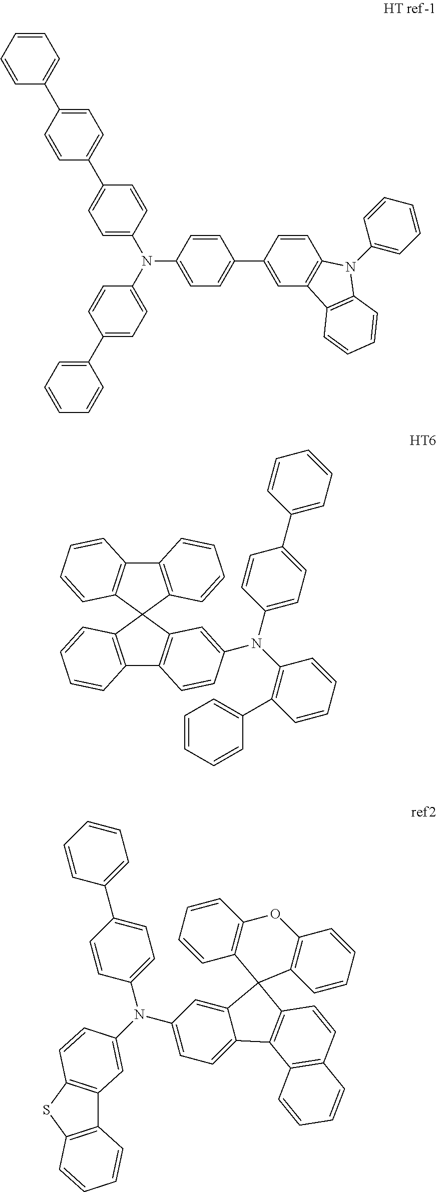 [SMILES: c1ccc(-c2ccc(-c3ccc(N(c4ccc(-c5ccccc5)cc4)c4ccc(-c5ccc6c(c5)c5ccccc5n6-c5ccccc5)cc4)cc3)cc2)cc1 ; c1ccc(-c2ccc(N(c3ccc4c(c3)C3(c5ccccc5-c5ccccc53)c3ccccc3-4)c3ccccc3-c3ccccc3)cc2)cc1 ; c1ccc(-c2ccc(N(c3ccc4c(c3)C3(c5ccccc5Oc5ccccc53)c3ccc5ccccc5c3-4)c3ccc4sc5ccccc5c4c3)cc2)cc1]

Structures of other compounds used for producing organic EL devices in Examples 1 to 3 and Comparatives 1 to 3 are shown below.

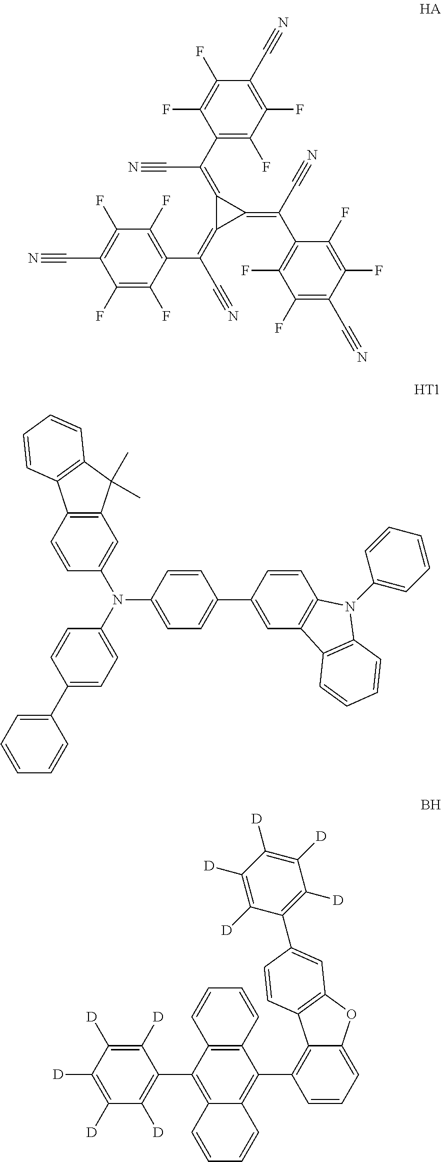 [SMILES: N#CC(=C1C(=C(C#N)c2c(F)c(F)c(C#N)c(F)c2F)C1=C(C#N)c1c(F)c(F)c(C#N)c(F)c1F)c1c(F)c(F)c(C#N)c(F)c1F ; CC1(C)c2ccccc2-c2ccc(N(c3ccc(-c4ccccc4)cc3)c3ccc(-c4ccc5c(c4)c4ccccc4n5-c4ccccc4)cc3)cc21 ; [2H]c1c([2H])c([2H])c(-c2ccc3c(c2)oc2cccc(-c4c5ccccc5c(-c5c([2H])c([2H])c([2H])c([2H])c5[2H])c5ccccc45)c23)c([2H])c1[2H]]

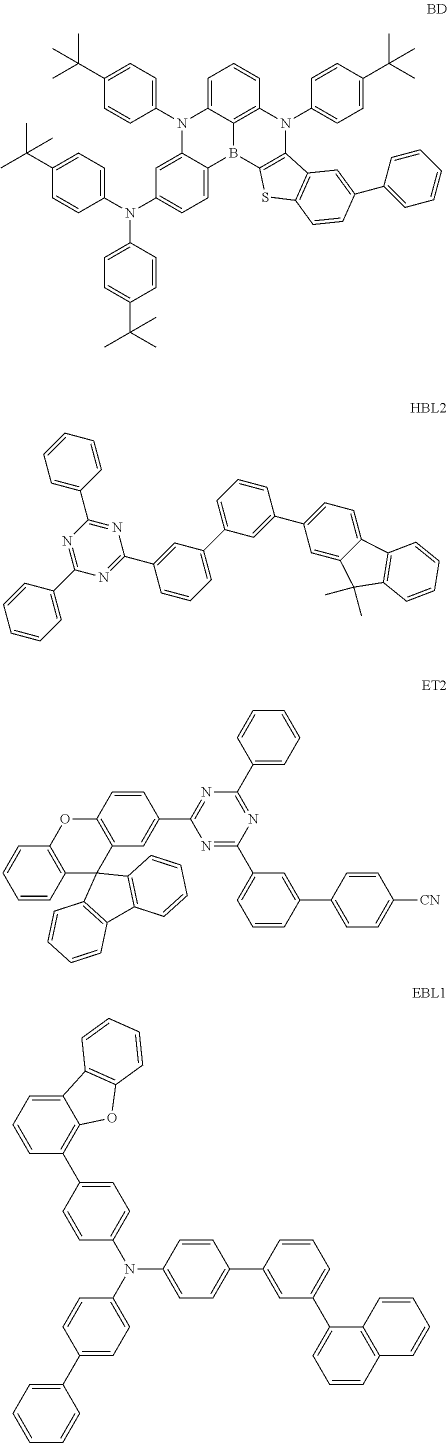 [SMILES: CC(C)(C)c1ccc(N(c2ccc(C(C)(C)C)cc2)c2ccc3c(c2)N(c2ccc(C(C)(C)C)cc2)c2cccc4c2B3c2sc3ccc(-c5ccccc5)cc3c2N4c2ccc(C(C)(C)C)cc2)cc1 ; CC1(C)c2ccccc2-c2ccc(-c3cccc(-c4cccc(-c5nc(-c6ccccc6)nc(-c6ccccc6)n5)c4)c3)cc21 ; N#Cc1ccc(-c2cccc(-c3nc(-c4ccccc4)nc(-c4ccc5c(c4)C4(c6ccccc6O5)c5ccccc5-c5ccccc54)n3)c2)cc1 ; c1ccc(-c2ccc(N(c3ccc(-c4cccc(-c5cccc6ccccc56)c4)cc3)c3ccc(-c4cccc5c4oc4ccccc45)cc3)cc2)cc1]

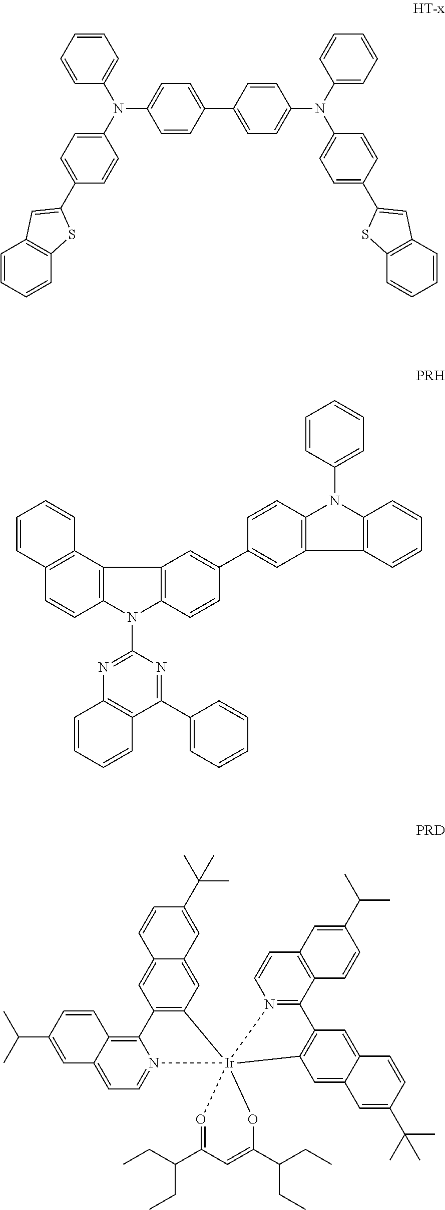

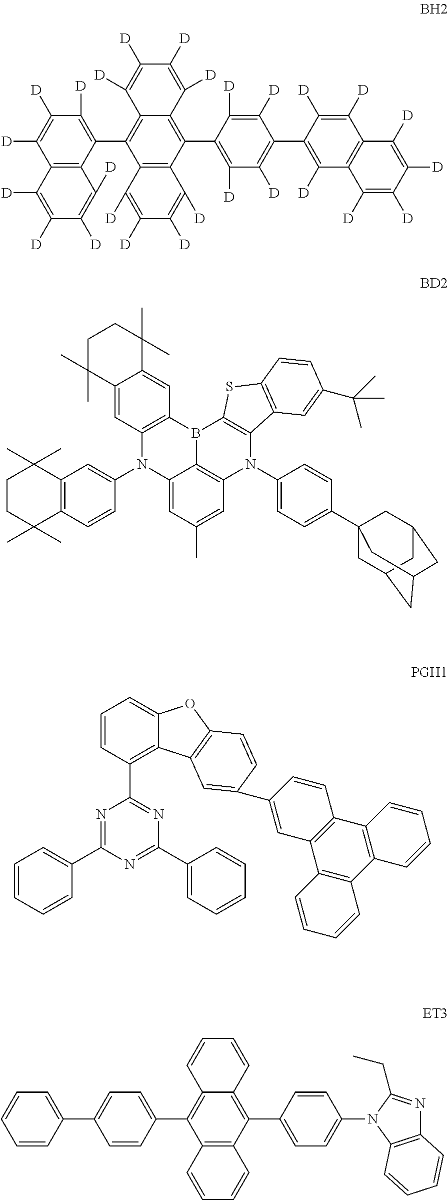

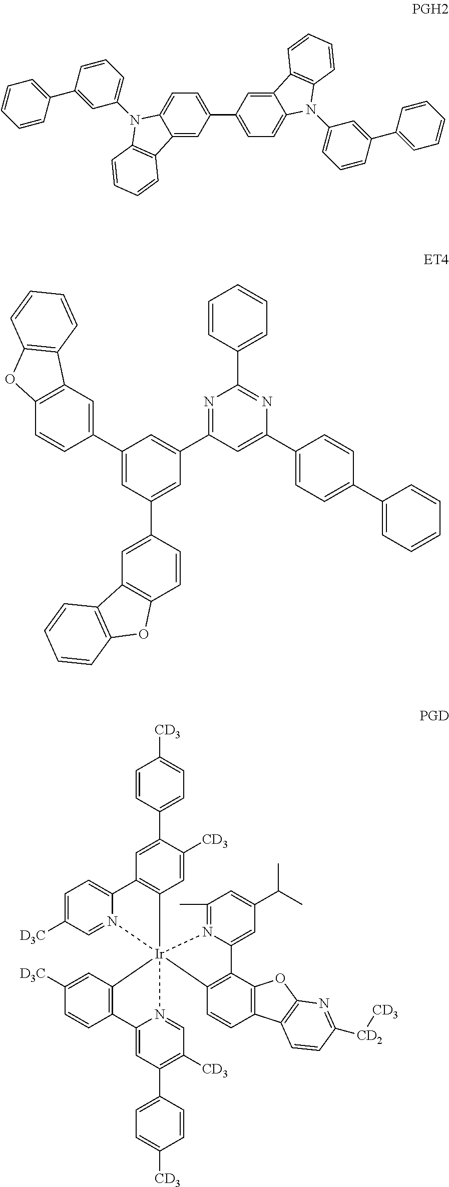

### Production of Organic EL Devices

Organic EL devices were produced and evaluated as follows.

### Example 1

A device-producing substrate was prepared by layering a metallic Ag layer as a reflective layer and an ITO layer as a transparent conductive layer having a thickness of 10 nm in this order on a glass substrate (25 mm×75 mm×0.7 mm thick). In this device-producing substrate, the metallic Ag layer and the ITO layer form a conductive material layer. Subsequently, using typical lithography technology, the conductive material layer was patterned by etching using a resist pattern as a mask, thereby forming the lower electrode (anode).

### First Emitting Unit

A compound HT1 and a compound HA were co-deposited in a manner to cover the lower electrode (anode) to form a 10-nm-thick first hole injecting layer. Ratios of the compound HT1 and the compound HA in the first hole injecting layer were 97 mass % and 3 mass %, respectively.

The compound HT1 was vapor-deposited on the first hole injecting layer to form a 25-nm-thick first hole transporting layer.

Next, a compound EBL1 was vapor-deposited on the first hole transporting layer to form a 5-nm-thick first electron blocking layer.

A compound BH as the first host material and a compound BD as the first luminescent compound were co-deposited on the first electron blocking layer to form a 19-nm-thick first emitting layer. Ratios of the compound BH and the compound BD in the first emitting layer were 99 mass % and 1 mass %, respectively.

A compound HBL1 was vapor-deposited on the first emitting layer to form a 15-nm-thick first electron transporting layer.

A first emitting unit was thus formed by including the first hole injecting layer, the first hole transporting layer, the first electron blocking layer, the first emitting layer, and the first electron transporting layer.

### First Charge Generating Zone

A compound ET1 and ytterbium (Yb) were co-deposited on the first electron transporting layer of the first emitting unit to form a 7.5-nm-thick first charge generating layer. The ratios of the compound ET1 and Yb in the first charge generating layer were 97.5 mass % and 2.5 mass %, respectively.

A compound HT2 and the compound HA were co-deposited on the first charge generating layer to form a 10-nm-thick second charge generating layer. The ratios of the compound HT2 and the compound HA in the second charge generating layer were 93 mass % and 7 mass %, respectively.

A first charge generating zone was thus formed including the first charge generating layer and the second charge generating layer.

### Second Emitting Unit

The compound HT2 was vapor-deposited on the second charge generating layer in the charge generating zone to form a 40-nm-thick second hole transporting layer.

Next, a compound EBL1 was vapor-deposited on the second hole transporting layer to form a 5-nm-thick second electron blocking layer.

The compound BH as the second host material and the compound BD as the second luminescent compound were co-deposited on the second electron blocking layer to form a 19-nm-thick second emitting layer. Ratios of the compound BH and the compound BD in the second emitting layer were 99 mass % and 1 mass %, respectively.

A compound HBL2 was vapor-deposited on the second emitting layer to form a 5-nm-thick second hole blocking layer.

A compound ET2 and Liq were co-deposited on the second hole blocking layer to form a 31-nm-thick second electron transporting layer. The ratios of the compound ET2 and Liq in the second electron transporting layer were both 50 mass %. Liq is an abbreviation of (8-quinolinolato)lithium.

Ytterbium (Yb) was vapor-deposited on the second electron transporting layer to form a 1-nm-thick second electron injecting layer.

A second emitting unit was thus formed by including the second hole transporting layer, the second electron blocking layer, the second emitting layer, the second hole blocking layer, the second electron transporting layer, and the second electron injecting layer.

Next, Mg and Ag were co-deposited on the second electron injecting layer of the second emitting unit at a mixing ratio (mass % ratio) of 10%:90% to form an upper electrode (cathode) formed of a semitransparent MgAg alloy with a total film thickness of 13 nm.

Next, a compound HT-x was vapor-deposited over the entire surface of the upper electrode (cathode) to form a 65-nm-thick capping layer.

A top emission type organic EL device in Example 1 was thus produced.

In the organic EL device in Example 1, the first electron transporting layer and the first charge generating layer form a high refractive index zone, and the second charge generating layer and the second hole transporting layer form a low refractive index zone. In Example 1, the first charge generating layer corresponds to the first high refractive index layer and the second charge generating layer corresponds to the first low refractive index layer.

A device arrangement of the organic EL device in Example 1 is roughly shown as follows.

Ag/ITO (10)/HT1:HA (10, 97%:3%)/HT₁ (25)/EBL1 (5)/BH:BD (19, 99%:1%)/HBL1 (15)/ET1:Yb (7.5, 97.5%:2.5%)/HT2:HA (10, 93%:7%)/HT2 (40)/EBL1 (5)/BH:BD (19, 99%:1%)/HBL2 (5)/ET2:Liq (31, 50%:50%)/Yb (1)/Mg:Ag (13, 10%:90%)/HT-x (65)

### Comparative 1

An organic EL device in Comparative 1 was produced in the same manner as in Example 1 except that the compound HT2 used for the second charge generating layer in Example 1 was replaced with a compound HT ref-1 listed in Table 1 and the compound HT2 used for the second hole transporting layer was replaced with the compound HT ref-1 listed in Table 1.

### Example 2

In Example 2, an organic EL device was produced including a red emitting unit (first emitting unit), a blue emitting unit (second emitting unit), a green emitting unit (third emitting unit), and a blue emitting unit (fourth emitting unit) disposed in this order from the anode toward the cathode.

### Red Emitting Unit (First Emitting Unit)

A glass substrate (size: 25 mm×75 mm×1.1 mm thick, produced by Geomatec Co., Ltd.) having an ITO transparent electrode (anode) was ultrasonic-cleaned in isopropyl alcohol for five minutes, and then UV-ozone-cleaned for one minute. The film thickness of the ITO was 130 nm.

After the glass substrate having the transparent electrode line was cleaned, the glass substrate was mounted on a substrate holder of a vacuum deposition apparatus. Firstly, a compound HT3 and the compound HA were co-deposited on a surface of the glass substrate where the transparent electrode line was provided in a manner to cover the transparent electrode, thereby forming a 10-nm-thick first hole injecting layer. Ratios of the compound HT3 and the compound HA in the first hole injecting layer were 95 mass % and 5 mass %, respectively.

The compound HT3 was vapor-deposited on the first hole injecting layer to form a 40-nm-thick first hole transporting layer.

A compound PRH as the first host material and a compound PRD as the first luminescent compound were co-deposited on the first hole transporting layer to form a 30-nm-thick first emitting layer. Ratios of the compound PRH and the compound PRD in the first emitting layer were 96 mass % and 4 mass %, respectively.

A compound ET3 was vapor-deposited on the first emitting layer to form a 15-nm-thick first electron transporting layer.

The red emitting unit was thus formed by including the first hole injecting layer, the first hole transporting layer, the first emitting layer, and the first electron transporting layer.

### First Charge Generating Zone

A compound CG1 and lithium (Li) were co-deposited on the first electron transporting layer of the first emitting unit to form a 20-nm-thick first charge generating layer. The ratios of the compound CG1 and Li in the first charge generating layer were 96 mass % and 4 mass %, respectively.

A compound HT4, a compound HT5 and the compound HA were co-deposited on the first charge generating layer to form a 10-nm-thick second charge generating layer. The ratios of the compound HT4, the compound HT5 and the compound HA in the second charge generating layer were 42.5 mass %, 42.5 mass %, 15 mass %, respectively.

A first charge generating zone was thus formed including the first charge generating layer and the second charge generating layer.

### Blue Emitting Unit (Second Emitting Unit)

The compound HT4 and the compound HT5 were co-deposited on the second charge generating layer in the first charge generating zone to form a 50-nm-thick second hole transporting layer. The ratios of the compound HT4 and the compound HT5 in the second hole transporting layer were both 50 mass %.

Next, a compound EBL2 was vapor-deposited on the second hole transporting layer to form a 15-nm-thick second electron blocking layer.

A compound BH2 as the second host material and a compound BD2 as the second luminescent compound were co-deposited on the second electron blocking layer to form a 20-nm-thick second emitting layer. The ratios of the compound BH2 and the compound BD2 in the second emitting layer were 98 mass % and 2 mass %, respectively.

A compound HBL3 was vapor-deposited on the second emitting layer to form a 10-nm-thick second electron transporting layer.

The blue emitting unit was thus formed by including the second hole transporting layer, the second electron blocking layer, the second emitting layer, and the second electron transporting layer.

### Second Charge Generating Zone

The compound CG1 and lithium (Li) were co-deposited on the second electron transporting layer of the second emitting unit to form a 15-nm-thick first charge generating layer. The ratios of the compound CG1 and Li in the first charge generating layer were 96 mass % and 4 mass %, respectively.

The compound HT3 and the compound HA were co-deposited on the first charge generating layer to form a 10-nm-thick second charge generating layer. The ratios of the compound HT3 and the compound HA in the second charge generating layer were 85 mass % and 15 mass %, respectively.

A second charge generating zone was thus formed including the first charge generating layer and the second charge generating layer.

### Green Emitting Unit (Third Emitting Unit)

The compound HT3 (third hole transporting zone material) was vapor-deposited on the second charge generating layer in the second charge generating zone to form a 11-nm-thick third hole transporting layer. The compound HT3 is referred to as a third hole transporting zone material.

A compound PGH1 as the third host material and a compound PGD as the third luminescent compound were co-deposited on the third hole transporting layer to form a 30-nm-thick third emitting layer. The ratios of the compound PGH1, the compound PGH2, and the compound PGD in the third emitting layer were 46 mass %, 46 mass %, 8 mass %, respectively.

The compound ET3 was vapor-deposited on the third emitting layer to form a 15-nm-thick third electron transporting layer.

The green emitting unit was thus formed by including the third hole transporting layer, the third emitting layer, and the third electron transporting layer.

### Third Charge Generating Zone

The compound CG1 and lithium (Li) were co-deposited on the third electron transporting layer of the third emitting unit to form a 20-nm-thick first charge generating layer. The ratios of the compound CG1 and Li in the first charge generating layer were 96 mass % and 4 mass %, respectively.

The compound HT3 and the compound HA were co-deposited on the first charge generating layer to form a 10-nm-thick second charge generating layer. The ratios of the compound HT3 and the compound HA in the second charge generating layer were 85 mass % and 15 mass %, respectively.

A third charge generating zone was thus formed including the first charge generating layer and the second charge generating layer.

### Blue Emitting Unit (Fourth Emitting Unit)

The compound HT3 was vapor-deposited on the second charge generating layer in the third charge generating zone to form an 80-nm-thick fourth hole transporting layer.

Next, the compound EBL2 was vapor-deposited on the fourth hole transporting layer to form a 10-nm-thick fourth electron blocking layer. The compound HT3 and the compound EBL2 are referred to as a fourth hole transporting zone material.

Next, the compound BH2 as a fourth host material and the compound BD2 as a fourth luminescent compound were co-deposited on the fourth electron blocking layer to form a 20-nm-thick fourth emitting layer. The ratios of the compound BH2 and the compound BD2 in the fourth emitting layer were 98 mass % and 2 mass %, respectively.

The compound ET3 and the compound ET4 were co-deposited on the fourth emitting layer to form a 29-nm-thick fourth electron transporting layer. The ratios of the compound ET3 and the compound ET4 in the fourth electron transporting layer were both 50 mass %.

The fourth emitting unit was thus formed by including the fourth hole transporting layer, the fourth electron blocking layer, the fourth emitting layer, and the fourth electron transporting layer.

LiF was vapor-deposited on the fourth electron transporting layer to form a 1-nm-thick fourth electron injecting layer.

The blue emitting unit was thus formed by including the fourth hole transporting layer, the fourth electron blocking layer, the fourth emitting layer, the fourth electron transporting layer, and the fourth electron injecting layer.

Next, metal aluminum (A1) was vapor-deposited on the fourth electron injecting layer in the fourth emitting unit to form an 80-nm-thick metal A1 cathode.

An organic EL device in Example 2 was thus produced.

In the organic EL device in Example 2, the first charge generating layer in the first charge generating zone forms a high refractive index zone. The second charge generating layer in the first charge generating zone, and the second hole transporting layer and the second electron blocking layer in the blue emitting unit form a low refractive index zone.

The first charge generating layer in the second charge generating zone forms a high refractive index zone. The second charge generating layer in the second charge generating zone and the third hole transporting layer in the green emitting unit form a low refractive index zone.

The first charge generating layer in the third charge generating zone forms a high refractive index zone. The second charge generating layer in the third charge generating zone, and the fourth hole transporting layer and the fourth electron blocking layer in the blue emitting unit form a low refractive index zone.

A device arrangement of the organic EL device in Example 2 is roughly shown as follows.
[anode] ITO(130)/
[red emitting unit] HT3:HA (10, 95%:5%)/HT3 (40)/PRH:PRD (30, 96%:4%)/ET3(15)/
[first charge generating zone] CG1Li (20, 96%:4%)/HT4:HT5:HA (10, 42.5%:42.5%:15%)/
[blue emitting unit] HT4:HT5 (50, 50%:50%)/EBL2(15)/BH2:BD2(20, 98%:2%)/HBL3(10)/
[second charge generating zone] CG1:Li (15, 96%:4%)/HT3:HA (10, 85%:15%)/
[green emitting unit] HT3(11)/PGH1:PGH2:PGD (30, 46%:46%:8%)/ET3(15)/
[third charge generating zone] CG1:Li (20, 96%:4%)/HT3:HA (10, 85%:15%)/
[blue emitting unit] HT3 (80)/EBL2 (10)/BH2:BD2 (20, 98%:2%)/ET3:ET4 (29, 50%:50%)/LiF(1)/
[cathode] Al(80)

Numerals in parentheses in the above device arrangement represent a film thickness (unit: nm). Similarly, in the above device arrangement, for instance, the numerals (95%:5%) represented by percentage in the same parentheses indicate a ratio (mass %) between the compound HT3 and the compound HA in the first hole injecting layer. The numerals (42.5%:42.5%:15%) represented by percentage in the same parentheses indicate a ratio (mass %) between the compound HT4, the compound HT5, and the compound HA in the second charge generating layer in the first charge generating zone. Similar notations apply to the description other than the above.

### Example 3

An organic EL device in Example 3 was produced in the same manner as in Example 2 except that the compound CG1 used for the first charge generating layer in the first charge generating zone, the first charge generating layer in the second charge generating zone, and the first charge generating layer in the third charge generating zone was replaced with the compound ET1 listed in Table 2.

A device arrangement of the organic EL device in Example 3 is roughly shown as follows.
[anode] ITO (130)/
[red emitting unit] HT3:HA (10, 95%:5%)/HT3(40)/PRH:PRD (30, 96%:4%)/ET3 (15)/
[first charge generating zone] ET1:Li (20, 96%:4%)/HT4:HT5:HA (10, 42.5%:42.5%:15%)/
[blue emitting unit] HT4:HT5 (50, 50%:50%)/EBL2 (15)/BH2:BD2 (20, 98%:2%)/HBL3(10)/
[second charge generating zone] ET1:Li (15, 96%:4%)/HT3:HA (10, 85%:15%)/
[green emitting unit] HT3 (11)/PGH1:PGH2:PGD (30, 46%:46%:8%)/ET3(15)/
[third charge generating zone] ET1:Li (20, 96%:4%)/HT3:HA (10, 85%:15%)/
[blue emitting unit] HT3 (80)/EBL2 (10)/BH2:BD2 (20, 98%:2%)/ET3:ET4 (29, 50%:50%)/LiF(1)/
[cathode] Al(80)

### Comparative 2

An organic EL device in Comparative 2 was produced in the same manner as in Example 2 except that the compounds HT4 and HT5 used for the second charge generating layer in the first charge generating zone and the second hole transporting layer in Example 2 were replaced with a compound ref2 listed in Table 2 and the compound HT3 used for the second charge generating layer in the third charge generating zone and the fourth hole transporting layer was replaced with the compound ref2 listed in Table 2. The ratios of the compound ref2 and the compound HA in the second charge generating layer in the first charge generating zone were 85 mass % and 15 mass %, respectively.

A device arrangement of the organic EL device in Comparative 2 is roughly shown as follows.
[anode] ITO(130)/
[red emitting unit] HT3:HA (10, 95%:5%)/HT3 (40)/PRH:PRD (30, 96%:4%)/ET3(15)/
[first charge generating zone] CG1:Li (20, 96%:4%)/ref2:HA (10, 85%:15%)/
[blue emitting unit] ref2 (50)/EBL2 (15)/BH2:BD2 (20, 98%:2%)/HBL3(10)/
[second charge generating zone] CG1:Li (15, 96%:4%)/HT3:HA (10, 85%:15%)/
[green emitting unit] HT3 (11)/PGH1:PGH2:PGD (30, 46%:46%:8%)/ET3(15)/
[third charge generating zone] CG1:Li (20, 96%:4%)/ref2:HA (10, 85%:15%)/
[blue emitting unit] ref2 (80)/EBL2 (10)/BH2:BD2 (20, 98%:2%)/ET3:ET4 (29, 50%:50%)/LiF(1)/
[cathode] Al(80)

### Comparative 3

An organic EL device in Comparative 3 was produced in the same manner as in Example 3 except that the compounds HT4 and HT5 used for the second charge generating layer in the first charge generating zone and the second hole transporting layer in Example 3 were replaced with the compounds HT6 and ref2 listed in Table 2 and the compound HT3 used for the second charge generating layer in the third charge generating zone and the fourth hole transporting layer was replaced with the compounds HT3 and ref2 listed in Table 2. The ratios of the compound HT3, the compound ref2 and the compound HA in the second charge generating layer in the third charge generating zone were 42.5 mass %, 42.5 mass %, 15 mass %, respectively. The ratios of the compound HT3 and the compound ref2 in the fourth hole transporting layer were both 50 mass %.

A device arrangement of the organic EL device in Comparative 3 is roughly shown as follows.
[anode] ITO (130)/
[red emitting unit] HT3:HA (10, 95%:5%)/HT3(40)/PRH:PRD (30, 96%:4%)/ET3 (15)/
[first charge generating zone] ET1:Li (20, 96%:4%)/HT6:ref2:HA (10, 42.5%:42.5%:15%)/
[blue emitting unit] HT6:ref2 (50, 50%:50%)/EBL2 (15)/BH2:BD2 (20, 98%:2%)/HBL3 (10)/
[second charge generating zone] ET1:Li (15, 96%:4%)/HT3:HA (10, 85%:15%)/
[green emitting unit] HT3 (11)/PGH1:PGH2:PGD (30, 46%:46%:8%)/ET3 (15)/
[third charge generating zone] ET1:Li (20, 96%:4%)/HT3:ref2:HA (10, 42.5%:42.5%:15%)/
[blue emitting unit] Ht3:ref2 (80, 50%:50%)/EBL2 (10)/BH2:BD2 (20, 98%:2%)/ET3:ET4 (29, 50%:50%)/LiF(1)/
[cathode] Al(80)

### Evaluation of Organic EL Devices

The organic EL devices produced were evaluated as follows. Tables 1 and 2 show evaluation results. Tables 1 to 3 show the refractive indices and triplet energies T₁ of the compounds used in each Example.

### External Quantum Efficiency EQE

Voltage was applied to the organic EL devices such that a current density was 10 mA/cm², where spectral radiance spectrum was measured with a spectroradiometer CS-2000 (produced by Konica Minolta, Inc.). The external quantum efficiency EQE (unit: %) was calculated based on the obtained spectral radiance spectra, assuming that the spectra was provided under a Lambertian radiation. Tables 1 and 2 show the relative values of EQE.

The relative values of EQE in Example 1 and Comparative 1 were calculated based on EQE in Example 1 and Comparative 1 according to a numerical formula (Numerical Formula X1) below. A unit of the relative value of EQE is denoted by %.

The relative values of EQE in Examples 2 and 3 and Comparatives 2 and 3 were calculated based on EQE in Examples 2 and 3 and Comparatives 2 and 3 according to a numerical formula (Numerical Formula X2) below.

$$EQE ( relative value ) = ( EQE of each Example / EQE of Comparative 1 ) \times 100 \qquad ( Numerical Formula X1 )$$

$$EQE ( relative value ) = ( EQE of each Example / EQE of Example 3 ) \times 100 \qquad ( Numerical Formula X2 )$$

TABLE 1

| | | | | High refractive index zone | | | | | |
|---|---|---|---|---|---|---|---|---|---|
| | | | | | | | First charge generating layer | | |
| | First emitting zone | | | First electron transporting | | | (first high refractive index layer) | | |
| | First emitting layer | | | layer film thickness: 15 nm | | | film thickness: 7.5 nm | | |
| | First host | | | first electron transporting | | | Second organic | | |
| | material | | First luminescent | zone material | | | material | | |
| | | T₁ | compound | | T₁ | Refractive | | Refractive | Metal |
| | Name | [eV] | Name | Name | [eV] | index | Name | index NM² | Name |
| Ex. 1 | BH | 1.85 | BD | HBL1 | 2.07 | 1.95 | ET1 | 1.90 | Yb |
| Comp. 1 | BH | 1.85 | BD | HBL1 | 2.07 | 1.95 | ET1 | 1.90 | Yb |

| | Low refractive index zone | | | | | |
|---|---|---|---|---|---|---|
| | Second charge generating layer | | | | | |
| | (first low refractive index layer) | | | second hole transporting | | |
| | film thickness: 10 nm | | | layer film thickness: 40 nm | | Device |
| | First organic | | | Second hole transporting | | evaluation |
| | material | | Acceptor | zone material | | EQE |
| | | Refractive | material | | Refractive | (relative |
| | Name | index NM¹ | Name | Name | index | value) |
| Ex. 1 | HT2 | 1.68 | HA | HT2 | 1.68 | 105% |
| Comp. 1 | HT | 2.00 | HA | HT | 2.00 | 100% |
| | Ref-1 | | | Ref-1 | | |

In the organic EL device in Example 1, the high refractive index zone including two high refractive index layers (the first electron transporting layer and the first charge generating layer) and the low refractive index zone including two low refractive index layers (the second charge generating layer and the second hole transporting layer) are disposed between the first emitting layer in the first emitting unit and the second emitting layer in the second emitting unit. The first charge generating layer that is the first high refractive index layer was in direct contact with the second charge generating layer that is the first low refractive index layer. The refractive index NM₂ of the second organic material contained in the first high refractive index layer is larger than the refractive index NM₁ of the first organic material contained in the first low refractive index layer (the numerical formula (Numerical Formula N1)). A total film thickness of the two high refractive index layers contained in the high refractive index zone is 20 nm or more. According to the organic EL device in Example 1 having such high refractive index zone and low refractive index zone as the above, light extraction efficiency was improved, resulting in improvement in external quantum efficiency.

The organic EL device in Comparative 1 was one in which the first organic material (compound HT2) contained in the two low refractive index layers (the second charge generating layer and the second hole transporting layer) in Example 1 was replaced with the compound HT ref-1. Since the organic EL device did not satisfy the relationship of the numerical formula (Numerical Formula N1), light extraction efficiency was less improved and external quantum efficiency was also lower than in Example 1.

TABLE 2

| | | | | | Low refractive index zone | | | | | | | | | | | | |
|---|---|---|---|---|---|---|---|---|---|---|---|---|---|---|---|---|---|
| | | | | | | | | | | | | | High refractive | | | | |
| | | High refractive index | | | | | | Second hole | | Second | | | index zone | | | | |
| | | zone | | | | | | transporting | | electron | | | First charge | | | | |
| | | First charge | | | Second charge | | | layer | | blocking layer | | | generating layer | | | Low refractive index zone | |
| | | generating layer | | | generating layer | | | film thickness: | | film thickness: | | | film thickness: | | | Second charge | |
| | First emitting | (first high refractive | | | (first low refractive | | | 50 nm | | 15 nm | | Second emitting | 15 nm | | | generating layer | |
| | zone | index layer) | | | index layer) | | | Second hole | | Second hole | | zone | First charge | | | film thickness: | |
| | First emitting | film thickness: 20 nm | | | film thickness: 10 nm | | | transporting | | transporting | | Second emitting | generating | | | 10 nm | |
| | layer | Second organic | | | First organic | | Acceptor | zone material | | zone material | | layer | zone | | | Second charge | |
| | Host/ Dopant | material | | Metal | material | | material | | Refractive | | Refractive | Host/ Dopant | material | | Metal | generating zone material | |
| | Name | Name | NM₂ | Name | Name | NM₁ | Name | Name | index | Name | index | Name | Name | NM₂ | Name | Name | NM₁ |
| Ex. 2 | PRH | CG1 | 1.99 | Li | HT4 | 1.83 | HA | HT4 | 1.83 | EBL2 | 1.85 | BH2 | CG1 | 1.99 | Li | HT3 | 1.86 |
| | PRD | | | | HT5 | 1.77 | | HT5 | 1.77 | | | BD2 | | | | | |
| | PRH | ET1 | 1.90 | Li | HT4 | 1.83 | HA | HT4 | 1.83 | EBL2 | 1.85 | BH2 | ET1 | 1.90 | Li | HT3 | 1.86 |
| Ex. 3 | PRD | | | | HT5 | 1.77 | | HT5 | 1.77 | | | BD2 | | | | | |
| Comp. 2 | PRH | CG1 | 1.99 | Li | Ref2 | 2.00 | HA | Ref2 | 2.00 | EBL2 | 1.85 | BH2 | CG1 | 1.99 | Li | HT3 | 1.86 |
| | PRD | | | | | | | | | | | BD2 | | | | | |
| Comp. 3 | PRH | ET1 | 1.90 | Li | HT6 | 1.84 | HA | HT6 | 1.84 | EBL2 | 1.85 | BH2 | ET1 | 1.90 | Li | HT3 | 1.86 |
| | PRD | | | | Ref2 | 2.00 | | Ref2 | 2.00 | | | BD2 | | | | | |

| | | | | | High refractive | | | | | | | | | | | |
|---|---|---|---|---|---|---|---|---|---|---|---|---|---|---|---|---|
| | Low refractive index zone | | | | index zone | | | Low refractive index zone | | | | | | | | |
| | | Third hole | | Third | First charge | | | | | | Fourth hole | | | | Fourth | |
| | | transporting layer | | emitting | generating layer | | | | | | transporting | | Fourth electron | | emitting | |
| | Second charge | film thickness: | | zone | film thickness: | | | Second charge | | | layer film | | blocking layer | | zone | |
| | generating layer | 11 nm | | Third | 15 nm | | | generating layer | | | thickness: | | film thickness: | | Fourth | |
| | film thickness: | Third hole | | emitting | First charge | | | film thickness: | | | 80 nm | | 10 nm | | emitting | Device |
| | 10 nm | transporting | | layer | generating | | | 10 nm | | | Fourth hole transporting | | Fourth hole transporting | | layer | evaluation |
| | Acceptor | zone material | | Host/ | zone | | | Second charge | | Acceptor | zone material | | zone material | | Host/ | (relative |
| | material | | Refractive | Dopant | material | | Metal | generating zone material | | material | | Refractive | | Refractive | Dopant | value) |
| | Name | Name | index | Name | Name | NM₂ | Name | Name | NM₁ | Name | Name | index | Name | index | Name | EQE |
| Ex. 2 | HA | HT3 | 1.86 | PGH1 | CG1 | 1.99 | Li | HT3 | 1.86 | HA | HT3 | 1.86 | EBL2 | 1.85 | BH2 | 101% |
| | | | | PGH2 | | | | | | | | | | | BD2 | |
| | HA | HT3 | 1.86 | PGH1 | ET1 | 1.90 | Li | HT3 | 1.86 | HA | HT3 | 1.86 | EBL2 | 1.85 | BH2 | 100% |
| Ex. 3 | | | | PGH2 | | | | | | | | | | | BD2 | |
| | | | | PGD | | | | | | | | | | | | |
| Comp. 2 | HA | HT3 | 1.86 | PGH1 | CG1 | 1.99 | Li | Ref2 | 2.00 | HA | Ref2 | 2.00 | EBL2 | 1.85 | BH2 | 95% |
| | | | | PGH2 | | | | | | | | | | | BD2 | |
| | | | | PGD | | | | | | | | | | | | |
| Comp. 3 | HA | HT3 | 1.86 | PGH1 | ET1 | 1.90 | Li | HT3 | 1.86 | HA | HT3 | 1.86 | EBL2 | 1.85 | BH2 | 97% |
| | | | | PGH2 | | | | Ref2 | 2.00 | | Ref2 | 2.00 | | | BD2 | |
| | | | | PGD | | | | | | | | | | | | |

In the organic EL devices in Examples 2 and 3, the high refractive index zone including one high refractive index layer (the first charge generating layer) and the low refractive index zone including three low refractive index layers (the second charge generating layer, the second hole transporting layer, and the second electron blocking layer) are disposed between the first emitting layer in the first emitting unit and the second emitting layer in the second emitting unit. The first charge generating layer that is the first high refractive index layer is in direct contact with the second charge generating layer that is the first low refractive index layer.

The refractive index NM₂ of the second organic material (the compound CG1 in Example 2 and the compound ET1 in Example 3) contained in the first high refractive index layer is larger than the refractive index NM₁ of the first organic material (the compounds HT4 and HT5) contained in the first low refractive index layer (the numerical formula (Numerical Formula N1)). A total film thickness of the one high refractive index layer contained in the high refractive index zone is 20 nm or more.

Further, the organic EL devices in Examples 2 and 3 satisfy the following requirements.

(Requirement 1) The high refractive index zone including one high refractive index layer (the first charge generating layer) and the low refractive index zone including two low refractive index layers (the second charge generating layer and the third hole transporting layer) are disposed between the second emitting layer in the second emitting unit and the third emitting layer in the third emitting unit. The high refractive index zone is in direct contact with the low refractive index zone.

(Requirement 2) The high refractive index zone including one high refractive index layer (the first charge generating layer) and the low refractive index zone including three low refractive index layers (the second charge generating layer, the fourth hole transporting layer, and the fourth electron blocking layer) are disposed between the third emitting layer in the third emitting unit and the fourth emitting layer in the fourth emitting unit. The high refractive index zone is in direct contact with the low refractive index zone.

The organic EL devices in Examples 2 and 3 having such high refractive index zone and low refractive index zone as the above exhibited luminous efficiency improved more than those in Comparatives 2 and 3.

Due to not satisfying the numerical formula (Numerical Formula N1), the organic EL devices in Comparatives 2 and 3 exhibited lower luminous efficiency that those in Examples 2 and 3.

The second charge generating layer in the first charge generating zone in Comparative 3 contains two types of organic materials (the compounds HT6 and ref2) at a ratio of 1:1 (mass scale) as the first organic material. A content of the acceptor material (compound HA) in the second charge generating layer of the first charge generating zone is not taken into account due to being 15 mass %. The refractive index of the second charge generating layer is considered to be (1.86+2.00)/2=1.92.

Therefore, in Comparative 3, the refractive index NM₂ of the second organic material (compound ET1) can be said to be smaller than the refractive index NM₁ of the first organic material (compounds HT6 and ref2). Similarly, the refractive index of the organic material (compound ET1) contained in the first charge generating layer of the third charge generating zone can be said to be smaller than the refractive index of the organic material (compounds HT3 and ref2) contained in the second charge generating layer.

### Evaluation on Compounds

### Triplet Energy T₁

A measurement target compound was dissolved in EPA (diethylether:isopentane:ethanol=5:5:2 in volume ratio) at a concentration of 10 μmol/L, and the obtained solution is put in a quartz cell to provide a measurement sample. A phosphorescence spectrum (ordinate axis: phosphorescent luminous intensity, abscissa axis: wavelength) of the measurement sample was measured at a low temperature (77K). A tangent was drawn to the rise of the phosphorescence spectrum close to the short-wavelength region. An energy amount was calculated by a conversion equation (F1) below on a basis of a wavelength value λ_{edge} [nm] at an intersection of the tangent and the abscissa axis. The calculated energy amount was defined as triplet energy T₁. It should be noted that the triplet energy T₁ may have an error of about plus or minus 0.02 eV depending on measurement conditions.

$$Conversion Equation ( F 1 ) : {T}_{1} [ eV ] = 1239 \text{.85} / {λ}_{e d g e}$$

The tangent to the rise of the phosphorescence spectrum close to the short-wavelength region is drawn as follows. While moving on a curve of the phosphorescence spectrum from the short-wavelength region to the local maximum value closest to the short-wavelength region among the local maximum values of the phosphorescence spectrum, a tangent is checked at each point on the curve toward the long-wavelength of the phosphorescence spectrum. An inclination of the tangent is increased along the rise of the curve (i.e., a value of the ordinate axis is increased). A tangent drawn at a point of the local maximum inclination (i.e., a tangent at an inflection point) is defined as the tangent to the rise of the phosphorescence spectrum close to the short-wavelength region.

A local maximum point where a peak intensity is 15% or less of the maximum peak intensity of the spectrum is not counted as the above-mentioned local maximum peak intensity closest to the short-wavelength region. The tangent drawn at a point that is closest to the local maximum peak intensity closest to the short-wavelength region and where the inclination of the curve is the local maximum is defined as a tangent to the rise of the phosphorescence spectrum close to the short-wavelength region.

For phosphorescence measurement, a spectrophotofluorometer body F-4500 manufactured by Hitachi High-Technologies Corporation was used.

TABLE 3

| Compound | T₁ [eV] |
|---|---|
| BH | 1.85 |
| BH2 | 1.93 |
| PRH | 2.24 |
| PGH1 | 2.82 |
| PGH2 | 2.87 |

### Refractive Index

Refractive indices of the materials (compounds) contained in the layers forming the high refractive index zone and the low refractive index zone were measured as follows.

A measurement target material was vacuum-deposited on a glass substrate to form a film having an approximately 50 nm thickness. Using a spectroscopic ellipsometer (M-2000UI, produced by J. A. Woollam Co., Inc. (US)), the obtained sample film was irradiated with incident light (from ultraviolet light through visible light to near-infrared light) every 5 degrees in a measurement angle range of 45 degrees to 75 degrees to measure change in a deflection state of the light reflected on the sample surface. In order to improve the measurement accuracy of the extinction coefficient, a transmission spectrum in a substrate normal direction (direction perpendicular to a surface of the substrate of the organic EL device) was also measured by M-2000UI. Similarly, the same measurement was performed also on the glass substrate on which no measurement target material was vapor-deposited. The obtained measurement information was fitted using analysis software (Complete EASE) produced by J. A. Woollam Co., Inc.

Refractive indices in an in-plane direction and a normal direction, extinction coefficients in the in-plane direction and the normal direction, and an order parameter of an organic film formed on the substrate were calculated under fitting conditions of using an anisotropic model rotationally symmetric about one axis and setting a parameter MSE indicating a mean square error in said analysis software to be 3.0 or less. A peak close to the long-wavelength region of the extinction coefficient (in-plane direction) was defined as S1, and the order parameter was calculated by a peak wavelength of S1. As fitting conditions for the glass substrate, an isotropic model was used.

Typically, a film formed by vacuum-depositing a low molecular material on the substrate is rotationally symmetric about one axis extending along the substrate normal direction. When an angle formed by the substrate normal direction and a molecular axis in a thin film formed on the substrate is defined as θ and the extinction coefficients in a substrate parallel direction (Ordinary direction) and a substrate perpendicular direction (Extra-Ordinary direction) obtained by performing the variable-angle spectroscopic ellipsometry measurement on the thin film are respectively defined as ko and ke, S′ represented by a formula below is the order parameter.

$$\begin{matrix}S ’ = 1 - < cos 2 θ >= 2 ko / ( ke + 2 k o ) = 2 / 3 ( 1 - S ) \\ S = ( 1 / 2 ) < 3 cos 2 θ - 1 >= ( k e - ko ) / ( ke + 2 k o )\end{matrix}$$

An evaluation method of the molecular orientation is a publicly known method, and details thereof are described in Organic Electronics, volume 10, page 127 (2009). Further, the method for forming the thin film is a vacuum deposition method.

The order parameter S′ obtained by the variable-angle spectroscopic ellipsometry measurement is 1.0 when all the molecules are oriented in parallel with the substrate. When molecules are random without being oriented, the order parameter S′ is 0.66.

Herein, a value at 2.7 eV in the substrate parallel direction (Ordinary direction), from among the values measured above, is defined as a refractive index of the measurement target material. The refractive index at 2.7 eV corresponds to a refractive index at 460 nm. Herein, the refractive index at 2.7 eV in the substrate parallel direction (Ordinary direction) may be represented by n_{ORD} and the refractive index at 2.7 eV (460 nm) in the substrate perpendicular direction (Extra-Ordinary direction) may be represented by n_{EXT}.

When a layer contains a plurality of compounds, a refractive index of the layer, the layer being a film formed by co-depositing the plurality of compounds as the measurement target material on the glass substrate or a film formed by vapor-depositing a mixture containing the plurality of compounds as the measurement target material, was measured using a spectroscopic ellipsometer in the same manner as above.

### Maximum Fluorescence Peak Wavelength λ_{FL}

A measurement target compound was dissolved in toluene to prepare a solution at 5.0×10⁻⁶ mol/L. The obtained solution was put into a quartz cell (light path length: 1.0 cm). Using a fluorescence spectrometer “spectrophotofluorometer FP-8300” (produced by JASCO Corporation), the solution was excited at 400 nm, where a maximum fluorescence peak wavelength λ_{FL} (unit: nm) was measured.

The maximum fluorescence peak wavelength λ_{FL} of the compound BD was 456 nm.

The maximum fluorescence peak wavelength λ_{FL} of the compound BD2 was 459 nm.

### Maximum Phosphorescence Peak Wavelength (PH-Peak)

A maximum peak wavelength of a phosphorescent compound was measured as follows. A luminescent compound (i.e., a measurement target) and a host material in the emitting layer containing the luminescent compound were co-deposited at the same ratio as in the emitting layer on a quartz substrate to form a 50-nm-thick film thereon. Using a spectrophotofluorometer F-7000 (manufactured by Hitachi High-Tech Science Corporation), an emission spectrum of the film by photoexcitation was measured. A peak wavelength of an emission spectrum, a luminous intensity of which was the maximum, was measured and defined as the maximum peak wavelength λ_{PH} (unit: nm) of the phosphorescent compound.

The maximum phosphorescence peak wavelength λ_{PH} of the compound PRD was 626 nm.

The maximum phosphorescence peak wavelength λ_{PH} of the compound PGD was 528 nm.

What is claimed is:

1. An organic electroluminescence device comprising:
an anode, a cathode, and two or more emitting units disposed between the anode and the cathode, wherein
the two or more emitting units at least includes a first emitting unit and a second emitting unit,
the first emitting unit and the second emitting unit are disposed in this order toward the cathode from the anode,
the first emitting unit includes a first emitting zone,
the second emitting unit includes a second emitting zone,
a high refractive index zone including one or more high refractive index layers and a low refractive index zone including one or more low refractive index layers are disposed between the first emitting zone and the second emitting zone,
the high refractive index zone is in direct contact with the low refractive index zone,
a total film thickness of the one or more high refractive index layers included in the high refractive index zone is 20 nm or more,
the high refractive index zone includes a first high refractive index layer as the high refractive index layer in direct contact with the low refractive index zone,
the low refractive index zone includes a first low refractive index layer as the low refractive index layer in direct contact with the first high refractive index layer,
the first low refractive index layer contains a first organic material having a refractive index NM₁,
the first high refractive index layer contains a second organic material having a refractive index NM₂,
at least one of the one or more high refractive index layers contains a third organic material and at least one selected from the group consisting of metal and a metal compound,
the third organic material and the second organic material are mutually the same or different, and
the refractive index NM₁ of the first organic material and the refractive index NM₂ of the second organic material satisfy a relationship of a numerical formula (Numerical Formula N1) below,
$$N {M}_{2} > {NM}_{1} . \qquad ( Numerical Formula N 1 )$$

2. The organic electroluminescence device according to claim 1, wherein the refractive index NM₁ of the first organic material and the refractive index NM₂ of the second organic material satisfy a relationship of a numerical formula below (Numerical Formula N2),
$$N {M}_{2} - {NM}_{1} > 0.04 . \qquad ( Numerical Formula N 2 )$$

3. The organic electroluminescence device according to claim 1, wherein the refractive index NM₁ of the first organic material and the refractive index NM₂ of the second organic material satisfy a relationship of a numerical formula below (Numerical Formula N3),
$$N {M}_{2} - {NM}_{1} > 0.07 . \qquad ( Numerical Formula N 3 )$$

4. The organic electroluminescence device according to claim 1, wherein
charge generating zones are respectively disposed between the two or more emitting units, and
the charge generating zones each independently include at least one charge generating layer.

5. The organic electroluminescence device according to claim 4, wherein at least one of the charge generating zones include two or more charge generating layers.

6. The organic electroluminescence device according to claim 4, wherein
a first charge generating zone is disposed between the first emitting unit and the second emitting unit, and
the first charge generating zone at least includes a first charge generating layer.

7. The organic electroluminescence device according to claim 6, wherein the first charge generating layer is the first high refractive index layer.

8. The organic electroluminescence device according to claim 6, wherein
a first electron transporting zone is disposed between the first emitting zone and the first charge generating layer, and
the first electron transporting zone includes one or more layers.

9. The organic electroluminescence device according to claim 8, wherein each of the one or more layers included in the first electron transporting zone is the high refractive index layer.

10. The organic electroluminescence device according to claim 8, wherein
the first electron transporting zone includes a first electron transporting layer, and
the first charge generating layer is in direct contact with the first electron transporting layer.

11. The organic electroluminescence device according to claim 9, wherein the first electron transporting layer is the high refractive index layer.

12. The organic electroluminescence device according to claim 10, wherein a total of a film thickness of the first electron transporting layer and a film thickness of the first charge generating layer is 20 nm or more.

13. The organic electroluminescence device according to claim 10, wherein
the first emitting zone includes a first emitting layer,
the first emitting layer contains a first host material,
the first electron transporting layer includes a first electron transporting zone material, and
a triplet energy T₁(H1) of the first host material and a triplet energy T₁(E1) of the first electron transporting zone material satisfy a relationship of a numerical formula (Numerical Formula 1) below,
$${T}_{1} ( E 1 ) > {T}_{1} ( H 1 ) . \qquad ( Numerical Formula 1 )$$

14. The organic electroluminescence device according to claim 13, wherein the first emitting layer is in direct contact with the first electron transporting layer.

15. The organic electroluminescence device according to claim 10, wherein the first electron transporting zone further includes a first hole blocking layer between the first electron transporting layer and the first emitting zone.

16. The organic electroluminescence device according to claim 15, wherein the first hole blocking layer is the high refractive index layer.

17. The organic electroluminescence device according to claim 15, wherein the first hole blocking layer contains a first electron transporting zone material.

18. The organic electroluminescence device according to claim 6, wherein
the first charge generating zone further includes a second charge generating layer, and
the second charge generating layer is disposed between the first charge generating layer and the second emitting zone.

19. The organic electroluminescence device according to claim 18, wherein the first charge generating layer is in direct contact with the second charge generating layer.

20. The organic electroluminescence device according to claim 18, wherein a second hole transporting layer is disposed between the second charge generating layer and the second emitting zone.

21. The organic electroluminescence device according to claim 20, wherein the second hole transporting layer is the low refractive index layer.

22. The organic electroluminescence device according to claim 18, wherein the second charge generating layer is the first low refractive index layer.

23. The organic electroluminescence device according to claim 1, wherein the refractive index NM₁ of the first organic material is 1.87 or less.

24. The organic electroluminescence device according to claim 1, wherein the refractive index NM₁ of the first organic material is 1.83 or less.

25. The organic electroluminescence device according to claim 1, wherein the refractive index NM₂ of the second organic material is more than 1.87.

26. The organic electroluminescence device according to claim 1, wherein the refractive index NM₂ of the second organic material is 1.89 or more.

27. The organic electroluminescence device according to claim 1, wherein the total film thickness of the one or more high refractive index layers included in the high refractive index zone is smaller than a total film thickness of the one or more low refractive index layers included in the low refractive index zone.

28. The organic electroluminescence device according to claim 1, wherein a total film thickness of the one or more low refractive index layers included in the low refractive index zone is 40 nm or more.

29. The organic electroluminescence device according to claim 1, wherein the total film thickness of the one or more high refractive index layers included in the high refractive index zone is 30 nm or less.

30. The organic electroluminescence device according to claim 1, wherein at least one of the one or more low refractive index layers contains a compound represented by a formula (B100) below, 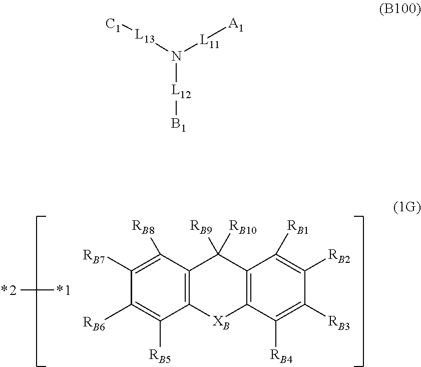
where, in the formula (B100):
L₁₁, L₁₂, and L₁₃ are each independently a single bond, a substituted or unsubstituted arylene group having 6 to 50 ring carbon atoms, a substituted or unsubstituted divalent heterocyclic group having 5 to 50 ring atoms, or a divalent group formed by bonding two groups selected from the group consisting of a substituted or unsubstituted arylene group having 6 to 50 ring carbon atoms and a substituted or unsubstituted divalent heterocyclic group having 5 to 50 ring atoms;
A₁, B₁, and C₁ are each independently a substituted or unsubstituted aryl group having 6 to 50 ring carbon atoms, a substituted or unsubstituted heterocyclic group having 5 to 50 ring atoms, a group represented by —Si(R_{C1})(R_{C2})(R_{C3}), or a group represented by the formula (1G);
at least one of A₁, B₁, and C₁ is a group represented by the formula (1G);
R_{C1}, R_{C2}, and R_{C3} are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R_{C1} are present, the plurality of R_{C1} are mutually the same or different;
when a plurality of R_{C2} are present, the plurality of R_{C2} are mutually the same or different; and
when a plurality of R_{C3} are present, the plurality of R_{C3} are mutually the same or different,
in the formula (1G):
X_{B} is a single bond, an oxygen atom, a sulfur atom, N(R_{B11}), or C(R_{B12})(R_{B13});
when a plurality of X_{B} are present, the plurality of X_{B} are mutually the same or different;
when X_{B} is C(R_{B12})(R_{B13}), a combination of R_{B12} and R_{B13} are mutually bonded to form a substituted or unsubstituted monocyclic ring, mutually bonded to form a substituted or unsubstituted fused ring, or not mutually bonded;
one of R_{B1}, R_{B2}, R_{B3}, R_{B4}, R_{B5}, R_{B6}, R_{B7}, R_{B8}, R_{B9}, R_{B10}, R_{B11}, R_{B12}, and R_{B13} is a single bond to *1;
R_{B1}, R_{B2}, R_{B3}, R_{B4}, R_{B5}, R_{B6}, R_{B7}, R_{B8}, and R_{B11} not being the single bond to *1 are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
a combination of R_{B9} and R_{B10} are mutually bonded to form a substituted or unsubstituted monocyclic ring, mutually bonded to form a substituted or unsubstituted fused ring, or not mutually bonded;
R_{B9}, R_{B10}, R_{B12}, and R_{B13} not being the single bond to *1, forming neither the substituted or unsubstituted monocyclic ring nor the substituted or unsubstituted fused ring are each independently a substituted or unsubstituted alkyl group having 1 to 50 carbon atoms, a substituted or unsubstituted cycloalkyl group having 3 to 50 ring carbon atoms, or a substituted or unsubstituted aryl group having 6 to 50 ring carbon atoms;
*2 is a bonding position to L₁₁, L₁₂, or L₁₃; and
when two or more groups represented by the formula (1G) are present, the two or more groups represented by the formula (1G) are mutually the same or different,
in the compound represented by the formula (B100), R₉₀₁, R₉₀₂, R₉₀₃, and R₉₀₄ are each independently a hydrogen atom, a substituted or unsubstituted alkyl group having 1 to 50 carbon atoms, a substituted or unsubstituted cycloalkyl group having 3 to 50 ring carbon atoms, a substituted or unsubstituted aryl group having 6 to 50 ring carbon atoms, or a substituted or unsubstituted heterocyclic group having 5 to 50 ring atoms;
when a plurality of R₉₀₁ are present, the plurality of R₉₀₁ are mutually the same or different;
when a plurality of R₉₀₂ are present, the plurality of R₉₀₂ are mutually the same or different;
when a plurality of R₉₀₃ are present, the plurality of Roos are mutually the same or different; and
when a plurality of R₉₀₄ are present, the plurality of R₉₀₄ are mutually the same or different.

31. The organic electroluminescence device according to claim 30, wherein the first organic material is a compound represented by the formula (B100).

32. The organic electroluminescence device according to claim 30, wherein the group represented by the formula (1G) is a group represented by any formula selected from the group consisting of formulae (11G), (12G), and (13G) below, 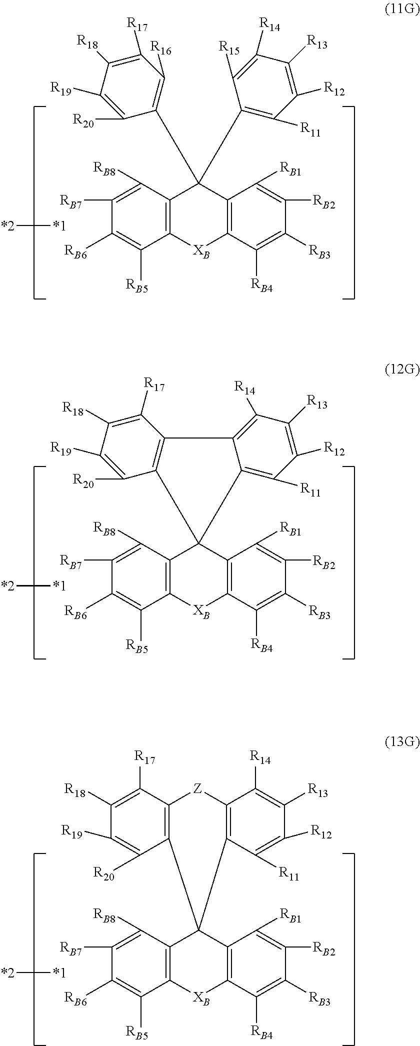
where, in the formulae (11G), (12G), and (13G):
X_{B}, R_{B1}, R_{B2}, R_{B3}, R_{B4}, R_{B5}, R_{B6}, R_{B7}, R_{B8}, *1, and *2 respectively represent the same as X_{B}, R_{B1}, R_{B2}, R_{B3}, R_{B4}, R_{B5}, R_{B6}, R_{B7}, R_{B8}, *1, and *2 in the formula (1G);
R₁₁, R₁₂, R₁₃, R₁₄, R₁₅, R₁₆, R₁₇, R₁₈, R₁₉, and R₂₀ are each independently a hydrogen atom, a cyano group, a substituted or unsubstituted alkyl group having 1 to 50 carbon atoms, a substituted or unsubstituted alkyl halide group having 1 to 50 carbon atoms, a substituted or unsubstituted cycloalkyl group having 3 to 50 ring carbon atoms, a group represented by —Si(R₉₀₁)(R₉₀₂)(R₉₀₃), a group represented by —O—(R₉₀₄), a substituted or unsubstituted aryl group having 6 to 50 ring carbon atoms, or a substituted or unsubstituted heterocyclic group having 5 to 50 ring atoms;
Z is an oxygen atom, a sulfur atom, or C(R_{Z1})(R_{Z2});
R_{Z1} and R_{Z2} are each independently a substituted or unsubstituted alkyl group having 1 to 50 carbon atoms, a substituted or unsubstituted cycloalkyl group having 3 to 50 ring carbon atoms, or a substituted or unsubstituted aryl group having 6 to 50 ring carbon atoms; and
R₉₀₁, R₉₀₂, R₉₀₃, and R₉₀₄ respectively represent the same as R₉₀₁, R₉₀₂, R₉₀₃, and R₉₀₄ in the formula (1G).

33. The organic electroluminescence device according to claim 32, wherein R₁₁, R₁₂, R₁₃, R₁₄, R₁₅, R₁₆, R₁₇, R₁₈, R₁₉, and R₂₀ are each independently a hydrogen atom, a substituted or unsubstituted alkyl group having 1 to 18 carbon atoms, a substituted or unsubstituted aryl group having 6 to 18 ring carbon atoms, or a substituted or unsubstituted heterocyclic group having 5 to 18 ring atoms.

34. The organic electroluminescence device according to claim 32, wherein two of A₁, B₁, and C₁ are each a group represented by the formula (12G).

35. The organic electroluminescence device according to claim 30, wherein X_{B} is a single bond or an oxygen atom.

36. The organic electroluminescence device according to claim 1, wherein
the first emitting zone includes a first luminescent compound,
the second emitting zone includes a second luminescent compound,
the first luminescent compound and the second luminescent compound are mutually the same or different, and
one or both of the first luminescent compound and the second luminescent compound are a compound that emits light having a maximum peak wavelength of 500 nm or less.

37. The organic electroluminescence device according to claim 1, wherein the two or more emitting units further includes a third emitting unit.

38. An electronic device comprising the organic electroluminescence device according to claim 1.
